(19) United States
(12) Patent Application Publication
(10) Pub. No.: US 2026/0182137 A1
(43) Pub. Date: Jun. 25, 2026

(54) COMPOSITION FOR ORGANIC MATERIAL LAYER OF ORGANIC LIGHT EMITTING DEVICE, ORGANIC LIGHT EMITTING DEVICE COMPRISING SAME AND METHOD FOR MANUFACTURING ORGANIC LIGHT EMITTING DEVICE

(71) Applicant: LT MATERIALS CO.,LTD., Yongin-si (KR)

(72) Inventors: Eun-Ji IM, Yongin-si (KR); Geon-Yu PARK, Yongin-si (KR); Young-Seok NO, Yongin-si (KR); Dong-Jun KIM, Yongin-si (KR); Dae-Hyuk CHOI, Yongin-si (KR)

(21) Appl. No.: 19/422,437

(22) Filed: Dec. 17, 2025

(30) Foreign Application Priority Data
Dec. 19, 2024 (KR) 10-2024-0190812

(51) Int. Cl. H10K 50/11; C09K 11/06; H10K 85/60

(52) U.S. Cl. CPC H10K 50/11; C09K 11/06; H10K 85/622; H10K 85/626; H10K 85/654; H10K 85/6572; H10K 85/6574; H10K 85/6576; C09K 2211/1062

(57) ABSTRACT

Provided are a composition for an organic material layer of an organic light emitting device, an organic light emitting device including the same, and a method for manufacturing an organic light emitting device. When used in an organic light emitting device, the composition for an organic material layer of an organic light emitting device can lower the driving voltage of the device, improve the light emitting efficiency, and improve the lifetime characteristics of the device.

### CROSS-REFERENCE TO RELATED APPLICATIONS

This application claims priority to and the benefit of Korean Patent Application No. 10-2024-0190812 filed in the Korean Intellectual Property Office on Dec. 19, 2024, the entire contents of which are incorporated herein by reference.

### TECHNICAL FIELD

The present specification relates to a composition for an organic material layer of an organic light emitting device, an organic light emitting device including the same, and a method for manufacturing an organic light emitting device.

### BACKGROUND ART

An electroluminescence device is a kind of self-emitting type display device, and has an advantage in that the viewing angle is wide, the contrast is excellent, and the response speed is fast. An organic light emitting device has a structure in which an organic thin film is disposed between two electrodes. When a voltage is applied to an organic light emitting device having the structure, electrons and holes injected from the two electrodes combine with each other in an organic thin film to make a pair, and then, emit light while being extinguished. The organic thin film may be composed of a single layer or multiple layers, if necessary.

A material for the organic thin film may have a light emitting function, if necessary. For example, as the material for the organic thin film, it is also possible to use a compound, which may itself constitute a light emitting layer alone, or it is also possible to use a compound, which may serve as a host or a dopant of a host-dopant-based light emitting layer. In addition, as a material for the organic thin film, it is also possible to use a compound, which may play a role such as a hole injection, hole transfer, electron blocking, hole blocking, electron transfer or electron injection.

In order to improve the performance, lifetime, or efficiency of the organic light emitting device, there is a continuous need for developing a material for an organic thin film.

### RELATED ART DOCUMENTS

### Patent Documents

(Patent Document 1) U.S. Pat. No. 4,356,429

### SUMMARY OF THE INVENTION

The present invention has been made in an effort to provide a composition for an organic material layer of an organic light emitting device, an organic light emitting device including the same, and a method for manufacturing an organic light emitting device.

An exemplary embodiment of the present invention provides a composition for an organic material layer of an organic light emitting device, which includes a first compound of the following Chemical Formula 1 and a second compound of the following Chemical Formula 2.

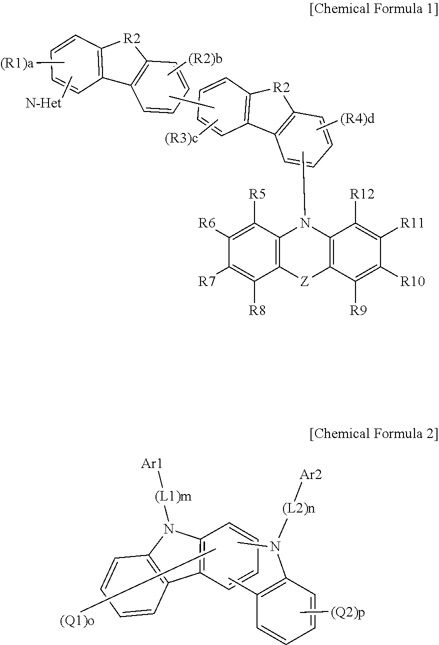

In Chemical Formula 1,
X1 and X2 are the same as or different from each other, and are each independently O; or S,
N-Het is a heteroaryl group having 1 to 60 carbon atoms, which is substituted or unsubstituted and includes one or more C═N bonds,
Z is a direct bond; O; S; C(Ra)(Rb); or N(Rc),
Ra to Rc are the same as or different from each other, and are each independently a substituted or unsubstituted alkyl group having 1 to 10 carbon atoms; or a substituted or unsubstituted aryl group having 6 to 20 carbon atoms,
R1 to R4 are the same as or different from each other, and are each independently hydrogen; deuterium; a halogen group; a cyano group; a substituted or unsubstituted aryl group having 6 to 60 carbon atoms; or a substituted or unsubstituted heteroaryl group having 2 to 60 carbon atoms,
R5 to R12 are the same as or different from each other, and are each independently hydrogen; deuterium; a halogen group; a cyano group; a substituted or unsubstituted aryl group having 6 to 60 carbon atoms; or a substituted or unsubstituted heteroaryl group having 2 to 60 carbon atoms, or are bonded to an adjacent group to form a substituted or unsubstituted ring, and
a to d are each an integer from 0 to 3, and when a to d are each 2 or higher, substituents in the parenthesis are the same or different,
in Chemical Formula 2,
L1 and L2 are the same as or different from each other, and are each independently a direct bond; a substituted or unsubstituted arylene group having 6 to 60 carbon atoms; or a substituted or unsubstituted heteroarylene group having 6 to 60 carbon atoms,
m and n are each an integer from 1 to 3, and when m and n are each 2 or higher, substituents in the parenthesis are the same or different,
Ar1 and Ar2 are the same as or different from each other, and are each independently a substituted or unsubstituted aryl group having 6 to 60 carbon atoms; or a substituted or unsubstituted heteroaryl group having 2 to 60 carbon atoms,
Q1 and Q2 are the same as or different from each other, and are each independently hydrogen; deuterium; a halogen group; a cyano group; a substituted or unsubstituted alkyl group having 1 to 60 carbon atoms; a substituted or unsubstituted alkenyl group having 2 to 60 carbon atoms; a substituted or unsubstituted alkynyl group having 2 to 60 carbon atoms; a substituted or unsubstituted alkoxy group having 1 to 60 carbon atoms; a substituted or unsubstituted cycloalkyl group having 3 to 60 carbon atoms; a substituted or unsubstituted heterocycloalkyl group having 2 to 60 carbon atoms; a substituted or unsubstituted aryl group having 6 to 60 carbon atoms; or a substituted or unsubstituted heteroaryl group having 2 to 60 carbon atoms, and
is an integer from 0 to 6, p is an integer from 0 to 4, and when o and p are each 2 or higher, substituents in the parenthesis are the same or different.

Another exemplary embodiment provides an organic light emitting device including: a first electrode; a second electrode; and an organic material layer having one or more layers provided between the first electrode and the second electrode, in which one or more layers of the organic material layer include the composition for an organic material layer of an organic light emitting device.

Yet another exemplary embodiment provides a method for manufacturing an organic light emitting device, the method including: preparing a substrate; forming a first electrode on the substrate; forming an organic material layer having one or more layers on the first electrode; and forming a second electrode on the organic material layer, in which the forming of the organic material layer includes forming an organic material layer having one or more layers using the composition for an organic material layer of an organic light emitting device.

When used in an organic light emitting device, the composition for an organic material layer of an organic light emitting device described in the present specification can lower the driving voltage of the device, improve the light emitting efficiency, and improve the lifetime characteristics of the device.

The first compound represented by Chemical Formula 1 of the present invention is a compound consisting of an N-Het substituent that withdraws electrons, a carbazole (derivative) substituent that pushes electrons, and two hetero rings (dibenzofuran/dibenzothiophene) that link a donor and an acceptor.

The carbazole (derivative) substituent substituted at the end of the first compound represented by Chemical Formula 1 can widely delocalize the HOMO orbital by changing the bonding position of N, thereby increasing the mobility and stability of holes.

In addition, the first compound represented by Chemical Formula 1 has an N-Het substituent substituted with dibenzofuran or dibenzothiophene, which can affect the LUMO orbital, and the LUMO level of the compound can be adjusted depending on the substitution position.

Therefore, the mobility and stabilization of holes and electrons are improved by changing the bonding positions of the donors and acceptors in the hetero ring, thereby increasing efficiency and lifetime.

The second compound represented by Chemical Formula 2 of the present invention is based on an indolocarbazole-based core that exhibits strong hole injection characteristics, and when used together with the first compound that has electron injection adjusting characteristics, the second compound has low driving voltage, high efficiency, and long lifetime characteristics while both electrons and holes are properly injected.

### BRIEF DESCRIPTION OF THE DRAWINGS

FIGS. 1 to 3 are views each exemplarily illustrating a stacking structure of an organic light emitting device according to an exemplary embodiment of the present specification.

### DETAILED DESCRIPTION

Hereinafter, the present specification will be described in more detail.

When one part “includes” one constituent element in the present specification, unless otherwise specifically described, this does not mean that another constituent element is excluded, but means that another constituent element may be further included.

In the present specification, “N to N′” means N or more and N′ or less.

In the present specification,

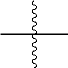

of a chemical formula means a position to which a constituent element is bonded.

The term “substitution” means that a hydrogen atom bonded to a carbon atom or nitrogen atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present specification, “substituted or unsubstituted” means being unsubstituted or substituted with one or more substituents selected from the group consisting of deuterium; a halogen group; a cyano group; a C1 to C60 alkyl group; a C2 to C60 alkenyl group; a C2 to C60 alkynyl group; a C1 to C60 haloalkyl group; a C1 to C60 alkoxy group; a C6 to C60 aryloxy group; a C1 to C60 alkylthioxy group; a C6 to C60 arylthioxy group; a C1 to C60 alkylsulfoxy group; a C6 to C60 arylsulfoxy group; a C3 to C60 cycloalkyl group; a C2 to C60 heterocycloalkyl group; a C6 to C60 aryl group; a C2 to C60 heteroaryl group; a silyl group; a phosphine oxide group; and an amine group, or a substituent to which two or more substituents selected among the substituents are linked.

In the present specification, “when a substituent is not indicated in the structure of a chemical formula or compound” means that a hydrogen atom is bonded to a carbon atom. However, since deuterium (²H) is an isotope of hydrogen, some hydrogen atoms may be deuterium.

In an exemplary embodiment of the present application, “when a substituent is not indicated in the structure of a chemical formula or compound” may mean that all the positions that may be reached by the substituent are hydrogen or deuterium. That is, deuterium is an isotope of hydrogen, and some hydrogen atoms may be deuterium which is an isotope, and in this case, the deuterium content may be 0% to 100%, and the deuterium content may be expressed as a deuterium substitution rate.

In an exemplary embodiment of the present application, in “the case where a substituent is not indicated in the structure of a chemical formula or compound”, when the content of deuterium is 0%, the content of hydrogen is 100%, and all the substituents do not explicitly exclude deuterium such as hydrogen, hydrogen and deuterium may be mixed and used in the compound.

In an exemplary embodiment of the present application, deuterium is one of the isotopes of hydrogen, is an element that has a deuteron composed of one proton and one neutron as a nucleus, and may be represented by hydrogen-2, and the element symbol may also be expressed as D or ²H.

In an exemplary embodiment of the present application, the isotope means an atom with the same atomic number (Z), but different mass numbers (A), and may also be interpreted as an element which has the same number of protons, but different number of neutrons.

In an exemplary embodiment of the present application, when the total number of substituents of a basic compound is defined as T1 and the number of specific substituents among the substituents is defined as T2, the substitution rate T % of the specific substituent may be defined as T2/T1×100=T %.

That is, in an example, a deuterium substitution rate of 20% in a phenyl group represented by

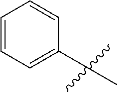 [SMILES: *c1ccccc1]

may be represented by 20% when the total number of substituents that the phenyl group can have is 5 (T1 in the formula) and the number of deuterium atoms among the substituents is 1 (T2 in the formula). That is, a deuterium substitution rate of 20% in the phenyl group may be represented by the following structural formula.

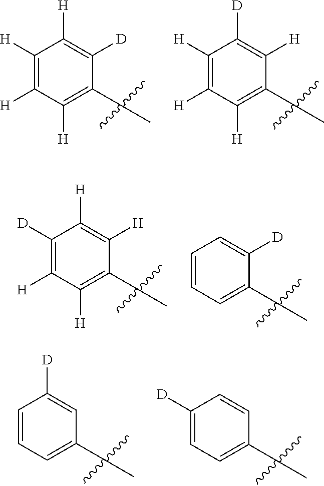 [SMILES: *c1ccccc1[2H] ; *c1cccc([2H])c1 ; *c1ccc([2H])cc1 ; *c1ccccc1[2H] ; *c1cccc([2H])c1 ; *c1ccc([2H])cc1]

Further, in an exemplary embodiment of the present application, “a phenyl group having a deuterium substitution rate of 0%” may mean a phenyl group that does not include a deuterium atom as a substituent, that is, has five hydrogen atoms.

In the present specification, the halogen may be fluorine, chlorine, bromine or iodine.

In the present specification, an alkyl group includes a straight-chain or branched-chain having 1 to 60 carbon atoms, and may be additionally substituted with another substituent. The number of carbon atoms of the alkyl group may be 1 to 60, specifically 1 to 40, and more specifically 1 to 20. Specific examples thereof include a methyl group, an ethyl group, a propyl group, an n-propyl group, an isopropyl group, a butyl group, an n-butyl group, an isobutyl group, a tert-butyl group, a sec-butyl group, a 1-methyl-butyl group, a 1-ethyl-butyl group, a pentyl group, an n-pentyl group, an isopentyl group, a neopentyl group, a tert-pentyl group, a hexyl group, an n-hexyl group, a 1-methylpentyl group, a 2-methylpentyl group, a 4-methyl-2-pentyl group, a 3,3-dimethylbutyl group, a 2-ethylbutyl group, a heptyl group, an n-heptyl group, a 1-methylhexyl group, an octyl group, an n-octyl group, a tert-octyl group, a 1-methylheptyl group, a 2-ethylhexyl group, a 2-propylpentyl group, an n-nonyl group, a 2,2-dimethylheptyl group, a 1-ethyl-propyl group, a 1,1-dimethyl-propyl group, an isohexyl group, a 2-methylpentyl group, a 4-methylhexyl group, a 5-methylhexyl group, and the like, but are not limited thereto.

In the present specification, an alkenyl group includes a straight-chain or branched-chain having 2 to 60 carbon atoms, and may be additionally substituted with another substituent. The number of carbon atoms of the alkenyl group may be 2 to 60, specifically 2 to 40, and more specifically 2 to 20. Specific examples thereof include a vinyl group, a 1-propenyl group, an isopropenyl group, a 1-butenyl group, a 2-butenyl group, a 3-butenyl group, a 1-pentenyl group, a 2-pentenyl group, a 3-pentenyl group, a 3-methyl-1-butenyl group, a 1,3-butadienyl group, an allyl group, a 1-phenylvinyl-1-yl group, a 2-phenylvinyl-1-yl group, a 2,2-diphenylvinyl-1-yl group, a 2-phenyl-2-(naphthyl-1-yl)vinyl-1-yl group, a 2,2-bis(diphenyl-1-yl)vinyl-1-yl group, a stilbenyl group, a styrenyl group, and the like, but are not limited thereto.

In the present specification, an alkynyl group includes a straight-chain or branched-chain having 2 to 60 carbon atoms, and may be additionally substituted with another substituent. The number of carbon atoms of the alkynyl group may be 2 to 60, specifically 2 to 40, and more specifically 2 to 20.

In the present specification, a haloalkyl group means an alkyl group substituted with a halogen group, and specific examples thereof include —CF₃, —CF₂CF₃, and the like, but are not limited thereto.

In the present specification, an alkoxy group is represented by —O(R101), and the above-described examples of the alkyl group may be applied to R101.

In the present specification, an aryloxy group is represented by —O(R102), and the above-described examples of the aryl group may be applied to R102.

In the present specification, an alkylthioxy group is represented by —S(R103), and the above-described examples of the alkyl group may be applied to R103.

In the present specification, an arylthioxy group is represented by —S(R104), and the above-described examples of the aryl group may be applied to R104.

In the present specification, an alkylsulfoxy group is represented by —S(=0)₂(R105), and the above-described examples of the alkyl group may be applied to R105.

In the present specification, an arylsulfoxy group is represented by —S(=0)₂(R106), and the above-described examples of the aryl group may be applied to R106.

In the present specification, a cycloalkyl group includes a monocycle or polycycle having 3 to 60 carbon atoms, and may be additionally substituted with another substituent. Here, the polycycle means a group in which a cycloalkyl group is directly linked to or fused with another cyclic group. Here, another cyclic group may also be a cycloalkyl group, but may also be another kind of cyclic group, for example, a heterocycloalkyl group, an aryl group, a heteroaryl group, and the like. The number of carbon atoms of the cycloalkyl group may be 3 to 60, specifically 3 to 40, and more specifically 5 to 20. Specific examples thereof include a cyclopropyl group, a cyclobutyl group, a cyclopentyl group, a 3-methylcyclopentyl group, a 2,3-dimethylcyclopentyl group, a cyclohexyl group, a 3-methylcyclohexyl group, a 4-methylcyclohexyl group, a 2,3-dimethylcyclohexyl group, a 3,4,5-trimethylcyclohexyl group, a 4-tert-butylcyclohexyl group, a cycloheptyl group, a cyclooctyl group, and the like, but are not limited thereto.

In the present specification, a heterocycloalkyl group includes 0, S, Se, N, or Si as a heteroatom, includes a monocycle or polycycle having 2 to 60 carbon atoms, and may be additionally substituted with another substituent. Here, the polycycle means a group in which a heterocycloalkyl group is directly linked to or fused with another cyclic group. Here, another cyclic group may also be a heterocycloalkyl group, but may also be another kind of cyclic group, for example, a cycloalkyl group, an aryl group, a heteroaryl group, and the like. The number of carbon atoms of the heterocycloalkyl group may be 2 to 60, specifically 2 to 40, and more specifically 3 to 20.

In the present specification, an aryl group includes a monocycle or polycycle having 6 to 60 carbon atoms, and may be additionally substituted with another substituent. Here, the polycycle means a group in which an aryl group is directly linked to or fused with another cyclic group. Here, another cyclic group may also be an aryl group, but may also be another kind of cyclic group, for example, a cycloalkyl group, a heterocycloalkyl group, a heteroaryl group, and the like. The aryl group includes a spiro group. The number of carbon atoms of the aryl group may be 6 to 60, specifically 6 to 40, and more specifically 6 to 25. Specific examples of the aryl group include a phenyl group, a biphenyl group, a terphenyl group, a naphthyl group, an anthryl group, a chrysenyl group, a phenanthrenyl group, a perylenyl group, a fluoranthenyl group, a triphenylenyl group, a phenalenyl group, a pyrenyl group, a tetracenyl group, a pentacenyl group, a fluorenyl group, an indenyl group, an acenaphthylenyl group, a benzofluorenyl group, a spirobifluorenyl group, a 2,3-dihydro-1H-indenyl group, a fused cyclic group thereof, and the like, but are not limited thereto.

In the present specification, the terphenyl group may be selected from the following structures.

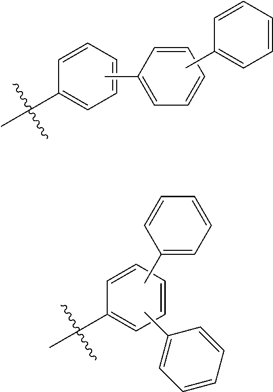

In the present specification, the fluorenyl group may be substituted, and adjacent substituents may be bonded to each other to form a ring.

When the fluorenyl group is substituted, the substituent may be the following structures, but is not limited thereto.

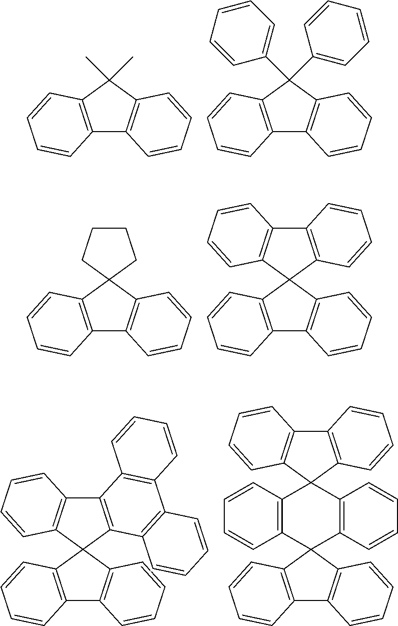

In the present specification, a heteroaryl group includes S, O, Se, N, or Si as a heteroatom, includes a monocycle or polycycle having 2 to 60 carbon atoms, and may be additionally substituted with another substituent. Here, the polycycle means a group in which a heteroaryl group is directly linked to or fused with another cyclic group. Here, another cyclic group may also be a heteroaryl group, but may also be another kind of cyclic group, for example, a cycloalkyl group, a heterocycloalkyl group, an aryl group, and the like. The number of carbon atoms of the heteroaryl group may be 2 to 60, specifically 2 to 40, and more specifically 3 to 25. Specific examples of the heteroaryl group include a pyridine group, a pyrrole group, a pyrimidine group, a pyridazine group, a furan group, a thiophene group, an imidazole group, a pyrazole group, an oxazole group, an isoxazole group, a thiazole group, an isothiazole group, a triazole group, a furazan group, an oxadiazole group, a thiadiazole group, a dithiazole group, a tetrazolyl group, a pyran group, a thiopyran group, a diazine group, an oxazine group, a thiazine group, a dioxin group, a triazine group, a tetrazine group, a quinoline group, an isoquinoline group, a quinazoline group, an isoquinazoline group, a quinozoline group, a naphthyridine group, an acridine group, a phenanthridine group, an imidazopyridine group, a diazanaphthalene group, a triazaindene group, an indole group, an indolizine group, a benzothiazole group, a benzoxazole group, a benzimidazole group, a benzothiophene group, a benzofuran group, a dibenzothiophene group, a dibenzofuran group, a carbazole group, a benzocarbazole group, a dibenzocarbazole group, a phenazine group, a dibenzosilole group, spirobi(dibenzosilole), a dihydrophenazine group, a phenoxazine group, a phenanthridine group, a thienyl group, an indolo[2,3-a]carbazole group, an indolo[2,3-b]carbazole group, an indoline group, a 10,11-dihydro-dibenzo[b,f]azepine group, a 9,10-dihydroacridine group, a phenanthrazine group, a phenothiazine group, a phthalazine group, a phenanthroline group, a naphthobenzofuran group, a naphthobenzothiophene group, a benzo[c][1,2,5]thiadiazole group, a 2,3-dihydrobenzo[b]thiophene group, a 2,3-dihydrobenzofuran group, a 5,10-dihydrodibenzo[b,e][1,4]azasiline group, a pyrazolo[1,5-c]quinazoline group, a pyrido[1,2-b]indazole group, a pyrido[1,2-a]imidazo[1,2-e]indoline group, a 5,11-dihydroindeno[1,2-b]carbazole group, and the like, but are not limited thereto.

In the present specification, a benzocarbazole group may be any one of the following structures.

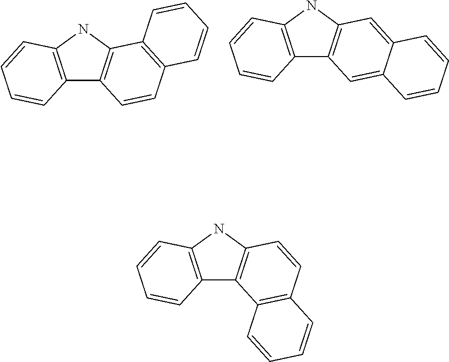

In the present specification, a dibenzocarbazole group may be any one of the following structures.

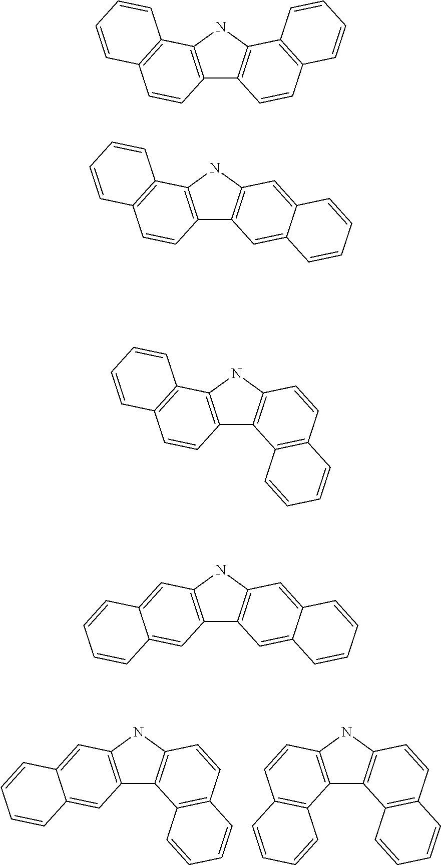

In the present specification, when the substituent is a carbazole group, a benzocarbazole group, or a dibenzocarbazole group, it means being bonded to the nitrogen or carbon of the carbazole group, the benzocarbazole group, or the dibenzocarbazole group.

In the present specification, when a carbazole group, a benzocarbazole group, or a dibenzocarbazole group is substituted, an additional substituent may be substituted at the nitrogen or carbon of the carbazole group, the benzocarbazole group, or the dibenzocarbazole group.

In the present specification, a naphthobenzofuran group may be any one of the following structures.

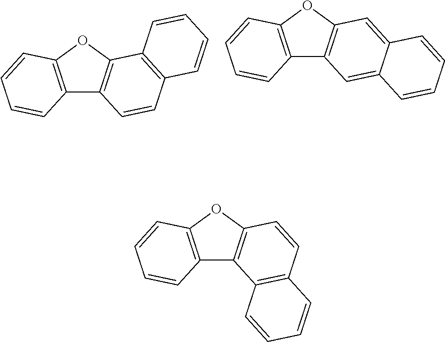

In the present specification, a naphthobenzothiophene group may be any one of the following structures.

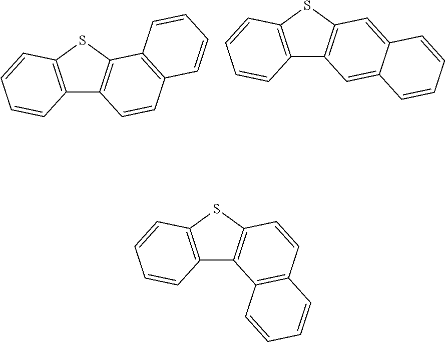

In the present specification, a silyl group includes Si and is a substituent to which the Si atom is directly linked as a radical, and is represented by —Si(R107)(R108)(R109), and R107 to R109 are the same as or different from each other, and may be each independently a substituent composed of at least one of hydrogen; deuterium; a halogen group; an alkyl group; an alkenyl group; an alkoxy group; a cycloalkyl group; a heterocycloalkyl group; an aryl group; and a heteroaryl group.

The silyl group may include an alkylsilyl group, an arylsilyl group, a heteroarylsilyl group, an alkylarylsilyl group, an arylheteroarylsilyl group, and the like, according to the substituent bonded to the Si element. An alkylsilyl group, an arylsilyl group, or a heteroarylsilyl group means that an alkyl group, an aryl group, or a heteroaryl group is substituted with the Si element of a silyl group, respectively, an alkylarylsilyl group means that an alkyl group and an aryl group are substituted with the Si element of a silyl group, and an arylheteroarylsilyl group means that an aryl group and a heteroaryl group are substituted with the Si element of a silyl group.

In the present, a triarylsilyl group means a silyl group substituted with three aryl groups. The number of carbon atoms of the aryl group may be 6 to 60, 6 to 30, or 6 to 20, and the number of carbon atoms of the triarylsilyl group may be 18 to 180, 18 to 90, or 18 to 40.

Specific examples of the silyl group include the following structures, but are not limited thereto.

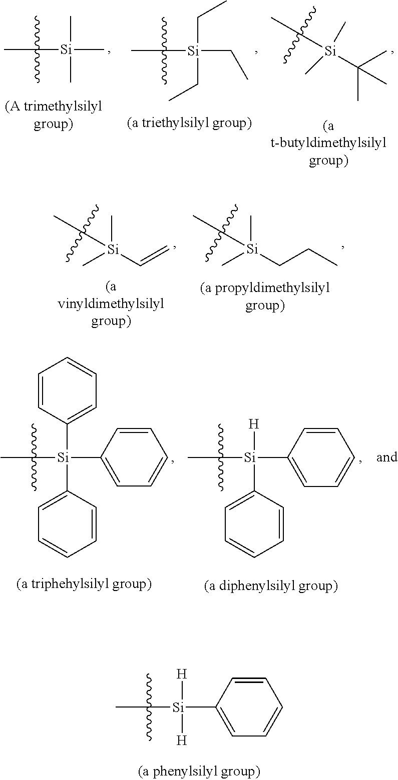

In the present specification, a phosphine oxide group is represented by —P(═O)(R110)(R111), and R110 and R111 are the same as or different from each other, and may be each independently a substituent composed of at least one of hydrogen; deuterium; a halogen group; an alkyl group; an alkenyl group; an alkoxy group; a cycloalkyl group; a heterocycloalkyl group; an aryl group; and a heteroaryl group. Specifically, the phosphine oxide group may be substituted with an alkyl group or an aryl group, and the above-described example may be applied to the alkyl group and the aryl group. Examples of the phosphine oxide group include a dimethylphosphine oxide group, a diphenylphosphine oxide group, dinaphthylphosphine oxide, and the like, but are not limited thereto.

In the present specification, an amine group is represented by —N(R112)(R113), and R112 and R113 are the same as or different from each other, and may be each independently a substituent composed of at least one of hydrogen; deuterium; a halogen group; an alkyl group; an alkenyl group; an alkoxy group; a cycloalkyl group; a heterocycloalkyl group; an aryl group; and a heteroaryl group. The amine group may be selected from the group consisting of —NH₂; a monoalkylamine group; a monoarylamine group; a monoheteroarylamine group; a dialkylamine group; a diarylamine group; a diheteroarylamine group; an alkylarylamine group; an alkylheteroarylamine group; and an arylheteroarylamine group, and the number of carbon atoms thereof is not particularly limited, but is preferably 1 to 30. Specific examples of the amine group include a methylamine group, a dimethylamine group, an ethylamine group, a diethylamine group, a phenylamine group, a naphthylamine group, a biphenylamine group, a dibiphenylamine group, an anthracenylamine group, a 9-methyl-anthracenylamine group, a diphenylamine group, a phenylnaphthylamine group, a ditolylamine group, a phenyltolylamine group, a triphenylamine group, a biphenylnaphthylamine group, a phenylbiphenylamine group, a biphenylfluorenylamine group, a phenyltriphenylenylamine group, a biphenyltriphenylenylamine group, and the like, but are not limited thereto.

In the present specification, the number of carbon atoms may be represented by Cn (n: an integer of 1 or greater). For example, when the number of carbon atoms is 1 to 10, the number of carbon atoms may be represented by C1 to C10.

An exemplary embodiment of the present specification provides a composition for an organic material layer of an organic light emitting device, including a first compound of the following Chemical Formula 1 and a second compound of the following Chemical Formula 2.

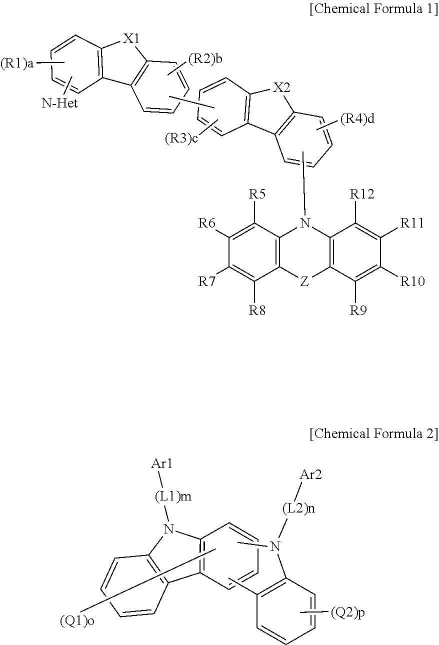

The definition of each substituent of Chemical Formulae 1 and 2 is the same as that described above.

Hereinafter, the first compound and the second compound will be specifically described.

### <First Compound (Chemical Formula 1)>

In an exemplary embodiment of the present specification, X1 and X2 may be O.

In an exemplary embodiment of the present specification, X1 may be S, and X2 may be O.

In an exemplary embodiment of the present specification, X1 may be O, and X2 may be S.

In an exemplary embodiment of the present specification, X1 and X2 may be S.

In an exemplary embodiment of the present specification, the first compound (Chemical Formula 1) may be represented by any one of the following Chemical Formulae 1-1 to 1-4.

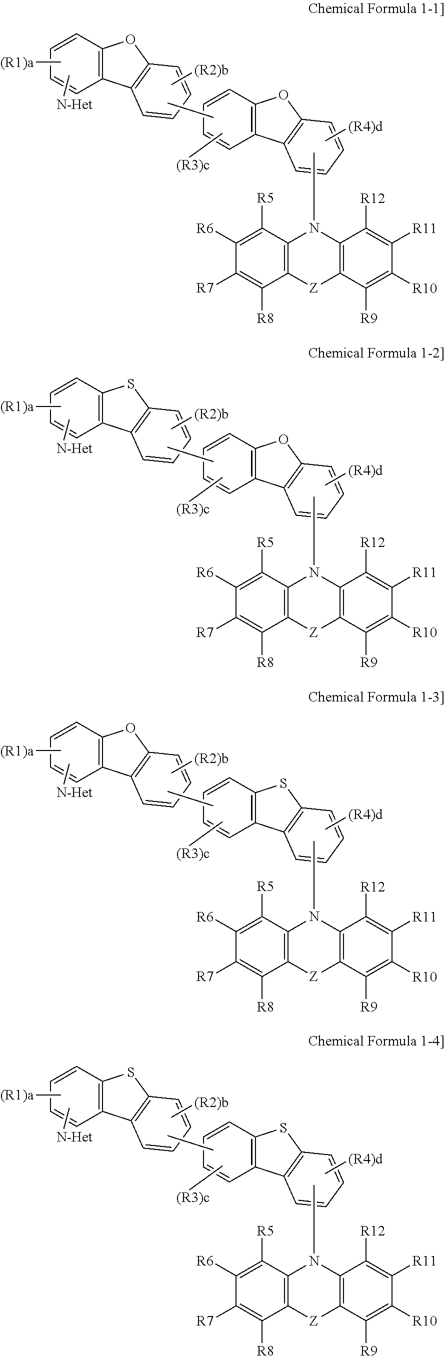

In Chemical Formulae 1-1 to 1-4,
the definition of each substituent is the same as the definition in Chemical Formula 1.

In an exemplary embodiment of the present specification, Z may be a direct bond.

In an exemplary embodiment of the present specification, Z may be O.

In an exemplary embodiment of the present specification, Z may be S.

In an exemplary embodiment of the present specification, Z is C(Ra)(Rb), and Ra and Rb are the same as or different from each other, and may be each independently a substituted or unsubstituted alkyl group having 1 to 10 carbon atoms; or a substituted or unsubstituted aryl group having 6 to 20 carbon atoms.

In an exemplary embodiment of the present specification, Z is N(Rc), and Rc may be a substituted or unsubstituted alkyl group having 1 to 10 carbon atoms; or a substituted or unsubstituted aryl group having 6 to 20 carbon atoms.

In an exemplary embodiment of the present specification, R5 to R12 are the same as or different from each other, and are each independently hydrogen; deuterium; a halogen group; a cyano group; a substituted or unsubstituted aryl group having 6 to 40 carbon atoms; or a substituted or unsubstituted heteroaryl group having 2 to 40 carbon atoms, or may be bonded to an adjacent group to form a substituted or unsubstituted ring.

In an exemplary embodiment of the present specification, R5 to R12 are the same as or different from each other, and are each independently hydrogen; deuterium; a substituted or unsubstituted aryl group having 6 to 20 carbon atoms; or a substituted or unsubstituted heteroaryl group having 2 to 20 carbon atoms, or may be bonded to an adjacent group to form a substituted or unsubstituted hydrocarbon ring, or a substituted or unsubstituted hetero ring.

In an exemplary embodiment of the present specification, R5 to R12 are the same as or different from each other, and are each independently hydrogen; deuterium; a substituted or unsubstituted phenyl group; or a substituted or unsubstituted carbazole group, or may be bonded to an adjacent group to form a substituted or unsubstituted indene ring, a substituted or unsubstituted benzofuran ring, a substituted or unsubstituted benzothiophene ring, or a substituted or unsubstituted indole ring.

In an exemplary embodiment of the present specification, the first compound (Chemical Formula 1) may be represented by any one of the following Chemical Formulae 1-A to 1-C.

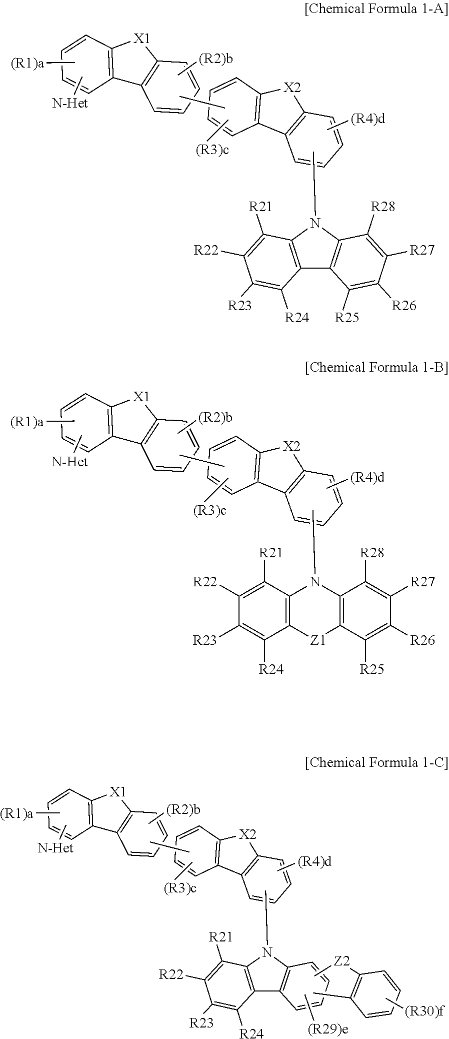

In Chemical Formulae 1-A to 1-C,
Z1 is C(Ra)(Rb); or N(Rc),
Z2 is O; S; C(Rd)(Re); or N(Rf),
Ra to Rf are the same as or different from each other, and are each independently a substituted or unsubstituted alkyl group having 1 to 10 carbon atoms; or a substituted or unsubstituted aryl group having 6 to 20 carbon atoms,
R21 to R30 are the same as or different from each other, and are each independently hydrogen; deuterium; a halogen group; a cyano group; a substituted or unsubstituted aryl group having 6 to 20 carbon atoms; or a substituted or unsubstituted heteroaryl group having 2 to 20 carbon atoms,
e is an integer from 0 to 2, when e is 2, a plurality of R29's are the same or different,
f is an integer from 0 to 4, and when f is each 2 or higher, a plurality of R30's are the same or different, and
the definitions of the other substituents are the same as the definitions in Chemical Formula 1.

In an exemplary embodiment of the present specification, Z1 is C(Ra)(Rb), and Ra and Rb are the same as or different from each other, and may be each independently a substituted or unsubstituted alkyl group having 1 to 10 carbon atoms.

In an exemplary embodiment of the present specification, Z2 is S; C(Rd)(Re); or N(Rf), and Rd to Rf are the same as or different from each other, and may be each independently a substituted or unsubstituted alkyl group having 1 to 10 carbon atoms; or a substituted or unsubstituted aryl group having 6 to 20 carbon atoms.

In an exemplary embodiment of the present specification, Z2 may be S.

In an exemplary embodiment of the present specification, Z2 is C(Rd)(Re), and Rd and Re are the same as or different from each other, and may be each independently a substituted or unsubstituted alkyl group having 1 to 10 carbon atoms.

In an exemplary embodiment of the present specification, Z2 is N(Rf), and Rf may be a substituted or unsubstituted aryl group having 6 to 20 carbon atoms.

In an exemplary embodiment of the present specification, R21 to R28 are the same as or different from each other, and may be each independently hydrogen; deuterium; a substituted or unsubstituted aryl group having 6 to 20 carbon atoms; or a substituted or unsubstituted heteroaryl group having 2 to 20 carbon atoms.

In an exemplary embodiment of the present specification, R21 to R28 are the same as or different from each other, and may be each independently hydrogen; deuterium; a substituted or unsubstituted phenyl group; or a substituted or unsubstituted carbazole group.

In an exemplary embodiment of the present specification, R21 to R28 are the same as or different from each other, and may be each independently hydrogen; deuterium; an aryl group having 6 to 20 carbon atoms, which is unsubstituted or substituted with deuterium; or a heteroaryl group having 2 to 20 carbon atoms, which is unsubstituted or substituted with an aryl group.

In an exemplary embodiment of the present specification, R21 to R28 are the same as or different from each other, and may be each independently hydrogen; deuterium; a phenyl group unsubstituted or substituted with deuterium; or a carbazole group unsubstituted or substituted with an aryl group.

In an exemplary embodiment of the present specification, R21 to R24 are the same as or different from each other, and may be each independently hydrogen; deuterium; or a substituted or unsubstituted aryl group having 6 to 20 carbon atoms.

In an exemplary embodiment of the present specification, R21 to R24 are the same as or different from each other, and may be each independently hydrogen; deuterium; or a substituted or unsubstituted phenyl group.

In an exemplary embodiment of the present specification, R21 to R24 are the same as or different from each other, and may be each independently hydrogen; deuterium; or an aryl group having 6 to 20 carbon atoms, which is unsubstituted or substituted with deuterium.

In an exemplary embodiment of the present specification, R21 to R24 are the same as or different from each other, and may be each independently hydrogen; deuterium; or a phenyl group unsubstituted or substituted with deuterium.

In an exemplary embodiment of the present specification, R25 to R28 are the same as or different from each other, and may be each independently hydrogen; deuterium; a substituted or unsubstituted aryl group having 6 to 20 carbon atoms; or a substituted or unsubstituted heteroaryl group having 2 to 20 carbon atoms.

In an exemplary embodiment of the present specification, R25 to R28 are the same as or different from each other, and may be each independently hydrogen; deuterium; a substituted or unsubstituted phenyl group; or a substituted or unsubstituted carbazole group.

In an exemplary embodiment of the present specification, R25 to R28 are the same as or different from each other, and may be each independently hydrogen; deuterium; an aryl group having 6 to 20 carbon atoms, which is unsubstituted or substituted with deuterium; or a heteroaryl group having 2 to 20 carbon atoms, which is unsubstituted or substituted with an aryl group.

In an exemplary embodiment of the present specification, R25 to R28 are the same as or different from each other, and may be each independently hydrogen; deuterium; a phenyl group unsubstituted or substituted with deuterium; or a carbazole group unsubstituted or substituted with an aryl group.

In an exemplary embodiment of the present specification, R29 and R30 are the same as or different from each other, and may be each independently hydrogen; or deuterium.

In an exemplary embodiment of the present specification, e may be 0 or 2.

In an exemplary embodiment of the present specification, e may be 2.

In an exemplary embodiment of the present specification, f may be 0 or 4.

In an exemplary embodiment of the present specification, f may be 4.

In an exemplary embodiment of the present specification, X1 and X2 of Chemical Formula 1-A are the same as or different from each other, and may be each independently O; or S.

In an exemplary embodiment of the present specification, X1 and X2 of Chemical Formula 1-B may be O.

In an exemplary embodiment of the present specification, X1 and X2 of Chemical Formula 1-C may be O.

In an exemplary embodiment of the present specification, the N-Het may be a heteroaryl group having 1 to 60 carbon atoms, which is substituted or unsubstituted and includes one or more C═N bonds.

In an exemplary embodiment of the present specification, the N-Het may be a heteroaryl group having 1 to 30 carbon atoms, which is substituted or unsubstituted and includes one or more C═N bonds.

In an exemplary embodiment of the present specification, the N-Het may be a heteroaryl group having 1 to 15 carbon atoms, which is substituted or unsubstituted and includes one or more C═N bonds.

In an exemplary embodiment of the present specification, the N-Het may be a heteroaryl group having 1 to 60 carbon atoms, which is substituted or unsubstituted and includes two or more C═N bonds.

In an exemplary embodiment of the present specification, the N-Het may be a heteroaryl group having 1 to 60 carbon atoms, which is substituted or unsubstituted and includes three or more C═N bonds.

In an exemplary embodiment of the present specification, the N-Het may be a heteroaryl group having 1 to 60 carbon atoms, which is substituted or unsubstituted and includes one to three C═N bonds.

In an exemplary embodiment of the present specification, the N-Het may be a heteroaryl group having 1 to 60 carbon atoms, which is substituted or unsubstituted and includes two to three C═N bonds.

In an exemplary embodiment of the present specification, the N-Het may be a heteroaryl group having 1 to 60 carbon atoms, which is substituted or unsubstituted and includes three C═N bonds.

In an exemplary embodiment of the present specification, the N-Het may be a substituted or unsubstituted pyridine group; a substituted or unsubstituted pyrimidine group; a substituted or unsubstituted triazine group; a substituted or unsubstituted quinoline group; a substituted or unsubstituted isoquinoline group; a substituted or unsubstituted quinazoline group; a substituted or unsubstituted benzimidazole group; a substituted or unsubstituted phenanthroline group; a substituted or unsubstituted benzofuropyrimidine group; or a substituted or unsubstituted benzothienopyrimidine group.

In an exemplary embodiment of the present specification, the N-Het may be a substituted or unsubstituted pyridine group; a substituted or unsubstituted pyrimidine group; a substituted or unsubstituted triazine group; or a substituted or unsubstituted phenanthroline group.

In an exemplary embodiment of the present specification, the N-Het may be a substituted or unsubstituted triazine group.

In an exemplary embodiment of the present specification, the N-Het is a pyridine group; a pyrimidine group; a triazine group; or a phenanthroline group, or may be further substituted with an aryl group having 6 to 60 carbon atoms, which is unsubstituted or substituted with deuterium.

In an exemplary embodiment of the present specification, the N-Het is a pyridine group; a pyrimidine group; a triazine group; or a phenanthroline group, or may be further substituted with an aryl group having 6 to 30 carbon atoms, which is unsubstituted or substituted with deuterium.

In an exemplary embodiment of the present specification, the N-Het is a pyridine group; a pyrimidine group; a triazine group; or a phenanthroline group, or may be further substituted with an aryl group having 6 to 20 carbon atoms, which is unsubstituted or substituted with deuterium.

In an exemplary embodiment of the present specification, the N-Het is a triazine group, and may be further substituted with an aryl group having 6 to 60 carbon atoms, which is unsubstituted or substituted with deuterium.

In an exemplary embodiment of the present specification, the N-Het is a triazine group, and may be further substituted with an aryl group having 6 to 30 carbon atoms, which is unsubstituted or substituted with deuterium.

In an exemplary embodiment of the present specification, the N-Het is a pyridine group; a pyrimidine group; a triazine group; or a phenanthroline group, or may be further substituted with an aryl group having 6 to 20 carbon atoms, which is unsubstituted or substituted with deuterium.

In an exemplary embodiment of the present specification, the N-Het of Chemical Formula 1-1 is a pyridine group; a pyrimidine group; or a triazine group, or may be further substituted with an aryl group having 6 to 60 carbon atoms, which is unsubstituted or substituted with deuterium.

In an exemplary embodiment of the present specification, the N-Het of Chemical Formula 1-1 is a pyridine group; a pyrimidine group; or a triazine group, and may be further substituted with a phenyl group unsubstituted or substituted with deuterium.

In an exemplary embodiment of the present specification, the N-Het of Chemical Formula 1-2 is a pyridine group; a pyrimidine group; a triazine group; or a phenanthroline group, and may be further substituted with an aryl group having 6 to 60 carbon atoms, which is unsubstituted or substituted with deuterium, a cyano group, or an alkyl group; or a heteroaryl group having 2 to 60 carbon atoms, which is unsubstituted or substituted with deuterium.

In an exemplary embodiment of the present specification, the N-Het of Chemical Formula 1-2 is a pyridine group; a triazine group; or a phenanthroline group, and may be further substituted with a phenyl group unsubstituted or substituted with deuterium or a cyano group; a dimethylfluorenyl group unsubstituted or substituted with deuterium; a dibenzofuran group unsubstituted or substituted with deuterium; a dibenzothiophene group unsubstituted or substituted with deuterium; or a pyridine group unsubstituted or substituted with deuterium.

In an exemplary embodiment of the present specification, the N-Het of Chemical Formula 1-3 is a pyridine group; a pyrimidine group; a triazine group; a benzimidazole group; a quinazoline group; a benzofuropyrimidine group; or a benzothienopyrimidine group, and may be further substituted with an aryl group having 6 to 60 carbon atoms, which is unsubstituted or substituted with one or more of deuterium, an alkyl group, and an aryl group; or a heteroaryl group having 2 to 60 carbon atoms, which is unsubstituted or substituted with one or more of deuterium and an aryl group.

In an exemplary embodiment of the present specification, the N-Het of Chemical Formula 1-3 is a triazine group; a benzimidazole group; a quinazoline group; a benzofuropyrimidine group; or a benzothienopyrimidine group, and may be further substituted with a phenyl group unsubstituted or substituted with deuterium; a dimethylfluorenyl group unsubstituted or substituted with deuterium; a diphenylfluorenyl group unsubstituted or substituted with deuterium; a spirobifluorenyl group unsubstituted or substituted with deuterium; or a dibenzofuran group unsubstituted or substituted with deuterium.

In an exemplary embodiment of the present specification, the N-Het of Chemical Formula 1-4 is a pyridine group; a pyrimidine group; a triazine group; a phenanthroline group; a quinoline group; an isoquinoline group; a quinazoline group; a benzofuropyrimidine group; or a benzothienopyrimidine group, and may be further substituted with deuterium; an aryl group having 6 to 60 carbon atoms, which is unsubstituted or substituted with deuterium; or a heteroaryl group having 2 to 60 carbon atoms, which is unsubstituted or substituted with deuterium.

In an exemplary embodiment of the present specification, the N-Het of Chemical Formula 1-4 is a pyridine group; a pyrimidine group; a triazine group; a phenanthroline group; a quinoline group; an isoquinoline group; a quinazoline group; a benzofuropyrimidine group; or a benzothienopyrimidine group, and may be further substituted with deuterium; a phenyl group unsubstituted or substituted with deuterium; a dibenzofuran group unsubstituted or substituted with deuterium; or a dibenzothiophene group unsubstituted or substituted with deuterium.

In an exemplary embodiment of the present specification, the first compound (Chemical Formula 1) may be represented by the following Chemical Formula 1-N.

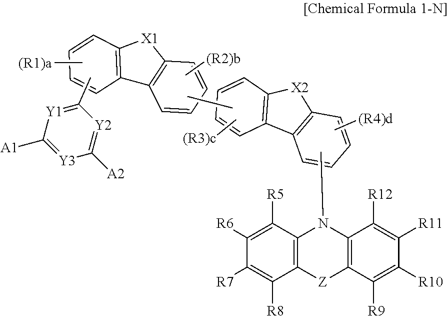

In Chemical Formula 1-N,
Y1 to Y3 are the same as or different from each other, and are each independently N or C(A3), and at least one thereof is N,
A1 to A3 are the same as or different from each other, and are each independently hydrogen; deuterium; a halogen group; a cyano group; a substituted or unsubstituted aryl group having 6 to 20 carbon atoms; or a substituted or unsubstituted heteroaryl group having 2 to 20 carbon atoms, and
the definitions of the other substituents are the same as the definitions in Chemical Formula 1.

In an exemplary embodiment of the present specification, Y1 to Y3 are the same as or different from each other, and are each independently N or C(A3), and at least two thereof may be N.

In an exemplary embodiment of the present specification, Y1 to Y3 may be N.

In an exemplary embodiment of the present specification, A1 and A2 are the same as or different from each other, and may be each independently a substituted or unsubstituted aryl group having 6 to 60 carbon atoms; or a substituted or unsubstituted heteroaryl group having 2 to 60 carbon atoms.

In an exemplary embodiment of the present specification, A1 and A2 are the same as or different from each other, and may be each independently a substituted or unsubstituted aryl group having 6 to 30 carbon atoms; or a substituted or unsubstituted heteroaryl group having 2 to 30 carbon atoms.

In an exemplary embodiment of the present specification, A1 and A2 are the same as or different from each other, and may be each independently a substituted or unsubstituted aryl group having 6 to 60 carbon atoms.

In an exemplary embodiment of the present specification, A1 and A2 are the same as or different from each other, and may be each independently a substituted or unsubstituted aryl group having 6 to 30 carbon atoms.

In an exemplary embodiment of the present specification, A1 and A2 are the same as or different from each other, and may be each independently a substituted or unsubstituted phenyl group; a substituted or unsubstituted fluorenyl group; a substituted or unsubstituted dibenzofuran group; a substituted or unsubstituted dibenzothiophene group; or a substituted or unsubstituted pyrimidine group.

In an exemplary embodiment of the present specification, A1 and A2 are the same as or different from each other, and may be each independently a substituted or unsubstituted phenyl group.

In an exemplary embodiment of the present specification, A1 and A2 are the same as or different from each other, and may be each independently an aryl group having 6 to 30 carbon atoms, which is unsubstituted or substituted with deuterium.

In an exemplary embodiment of the present specification, A1 and A2 are the same as or different from each other, and may be each independently a phenyl group unsubstituted or substituted with deuterium.

In an exemplary embodiment of the present specification, R1 to R4 are the same as or different from each other, and may be each independently hydrogen; deuterium; a halogen group; a cyano group; a substituted or unsubstituted aryl group having 6 to 40 carbon atoms; or a substituted or unsubstituted heteroaryl group having 2 to 40 carbon atoms.

In an exemplary embodiment of the present specification, R1 to R4 are the same as or different from each other, and may be each independently hydrogen; deuterium; a halogen group; a cyano group; a substituted or unsubstituted aryl group having 6 to 20 carbon atoms; or a substituted or unsubstituted heteroaryl group having 2 to 20 carbon atoms.

In an exemplary embodiment of the present specification, R1 to R4 are the same as or different from each other, and may be each independently hydrogen; deuterium; a substituted or unsubstituted aryl group having 6 to 20 carbon atoms; or a substituted or unsubstituted heteroaryl group having 2 to 20 carbon atoms.

In an exemplary embodiment of the present specification, R1 to R4 are the same as or different from each other, and may be each independently hydrogen; or deuterium.

In an exemplary embodiment of the present specification, the deuterium substitution rate of the first compound may be 0% to 100% based on the total hydrogen and deuterium.

In an exemplary embodiment of the present specification, the deuterium substitution rate of the first compound may be 0%, or 10% to 100%.

In an exemplary embodiment of the present specification, the deuterium substitution rate of the first compound may be 0%, or 15% to 100%.

In an exemplary embodiment of the present specification, the deuterium substitution rate of the first compound may be 0%, or 20% to 100%.

As used herein, the deuterium substitution rate refers to the ratio of the number of deuterium atoms to the total number of hydrogen atoms and deuterium atoms included in a specific structure (a partial structure or the entire structure of Chemical Formula 1, or a partial structure or the entire structure of Chemical Formula 2). For example, when a particular structure includes hydrogen atoms and 20 deuterium atoms, the deuterium substitution rate is 50% because the ratio of the 20 deuterium atoms to the total of 40 hydrogen and deuterium atoms is 50%.

In an exemplary embodiment of the present specification, when the deuterium substitution rate of the first compound satisfies the above range, the photochemical characteristics of a compound including deuterium and a compound not including deuterium are almost similar, but when the first compound is deposited on a thin film, the deuterium-containing material tends to be packed with a narrower intermolecular distance.

Accordingly, when an electron only device (EOD) and a hole only device (HOD) are manufactured and the current density thereof according to voltage is confirmed, it can be confirmed that the first compound including deuterium exhibits much more balanced charge transport characteristics than a compound which does not include deuterium in the same structure. Further, when the surface of a thin film is observed using an atomic force microscope (AFM), it can be confirmed that the thin film made of a compound including deuterium is deposited with a more uniform surface without any aggregated portion.

Additionally, since the single bond dissociation energy of carbon and deuterium is higher than the single bond dissociation energy of carbon and hydrogen, in the case of the first compound including deuterium, the stability of the total molecules is enhanced, so that there is an effect of improving the lifetime of the device.

In an exemplary embodiment of the present specification, the first compound may be represented by any one of the following compounds.

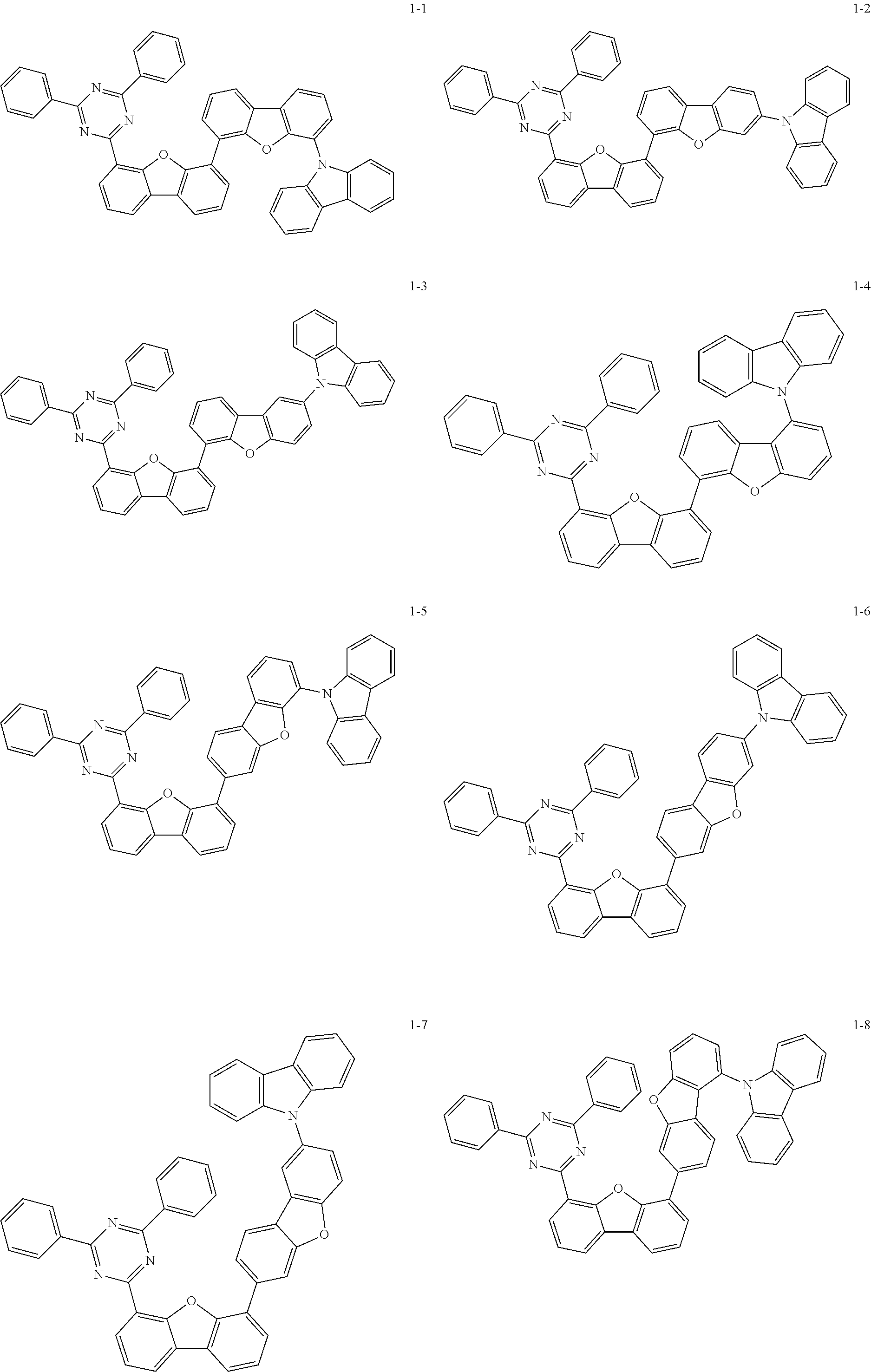

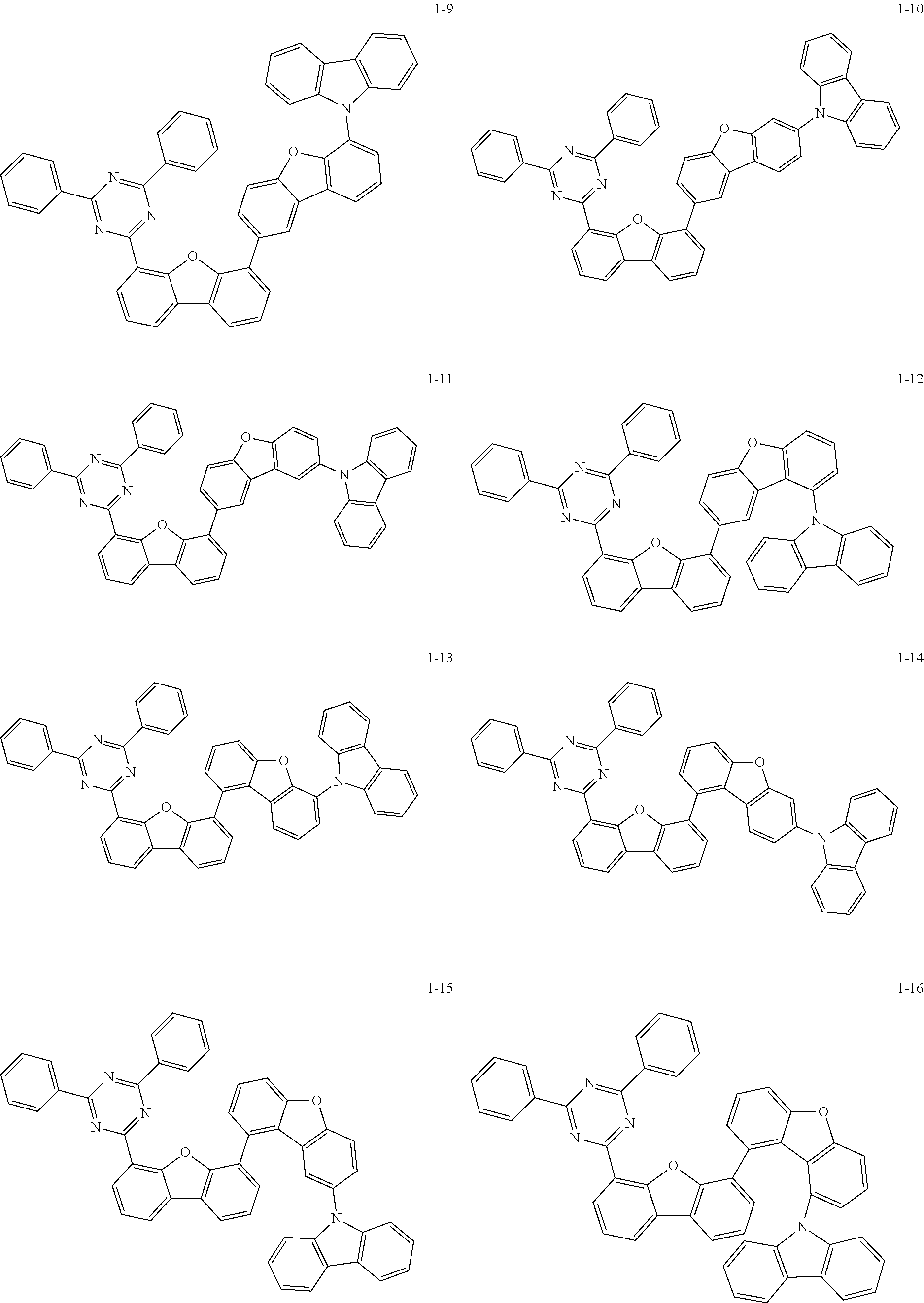

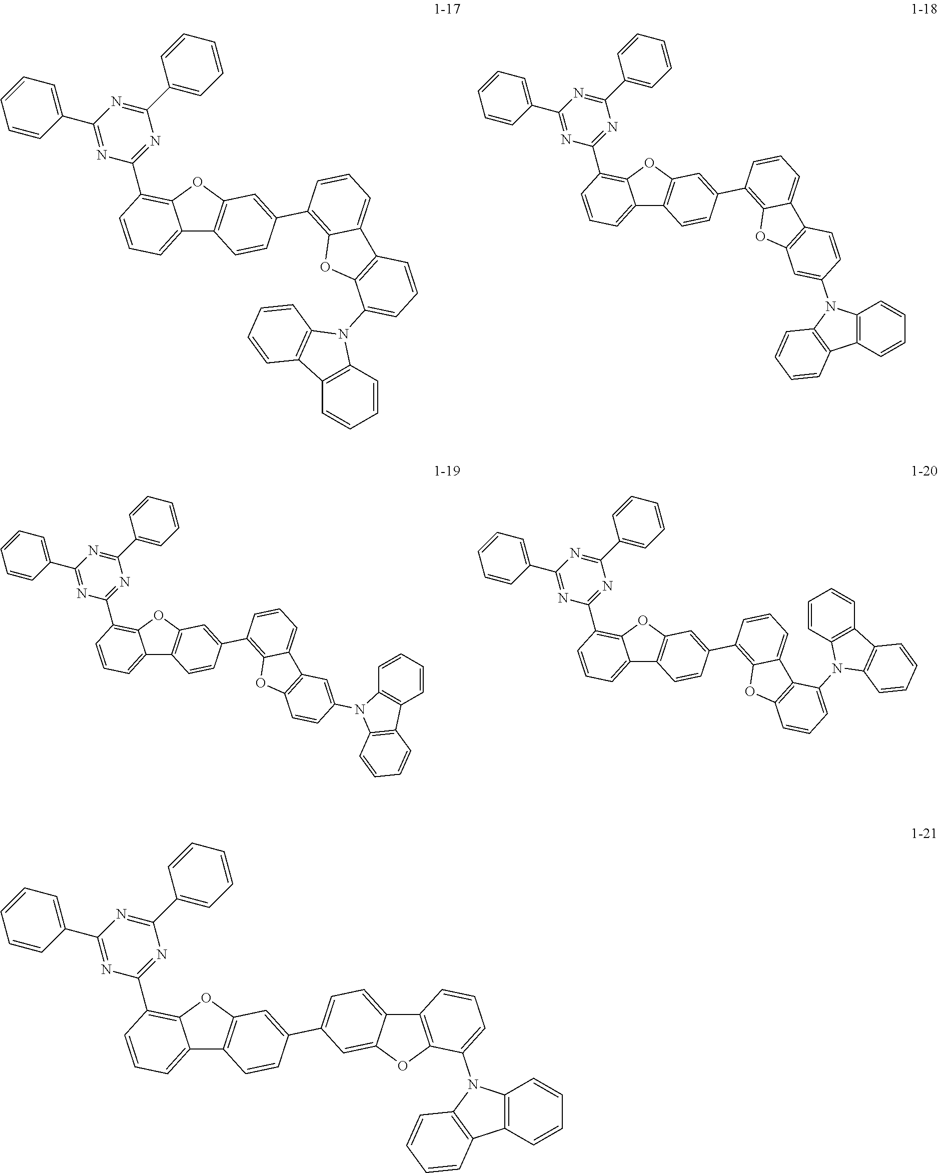 [SMILES: c1ccc(-c2nc(-c3ccccc3)nc(-c3cccc4c3oc3cc(-c5cccc6c5oc5c(-n7c8ccccc8c8ccccc87)cccc56)ccc34)n2)cc1 ; c1ccc(-c2nc(-c3ccccc3)nc(-c3cccc4c3oc3cc(-c5cccc6c5oc5cc(-n7c8ccccc8c8ccccc87)ccc56)ccc34)n2)cc1 ; c1ccc(-c2nc(-c3ccccc3)nc(-c3cccc4c3oc3cc(-c5cccc6c5oc5ccc(-n7c8ccccc8c8ccccc87)cc56)ccc34)n2)cc1 ; c1ccc(-c2nc(-c3ccccc3)nc(-c3cccc4c3oc3cc(-c5cccc6c5oc5cccc(-n7c8ccccc8c8ccccc87)c56)ccc34)n2)cc1 ; c1ccc(-c2nc(-c3ccccc3)nc(-c3cccc4c3oc3cc(-c5ccc6c(c5)oc5c(-n7c8ccccc8c8ccccc87)cccc56)ccc34)n2)cc1]

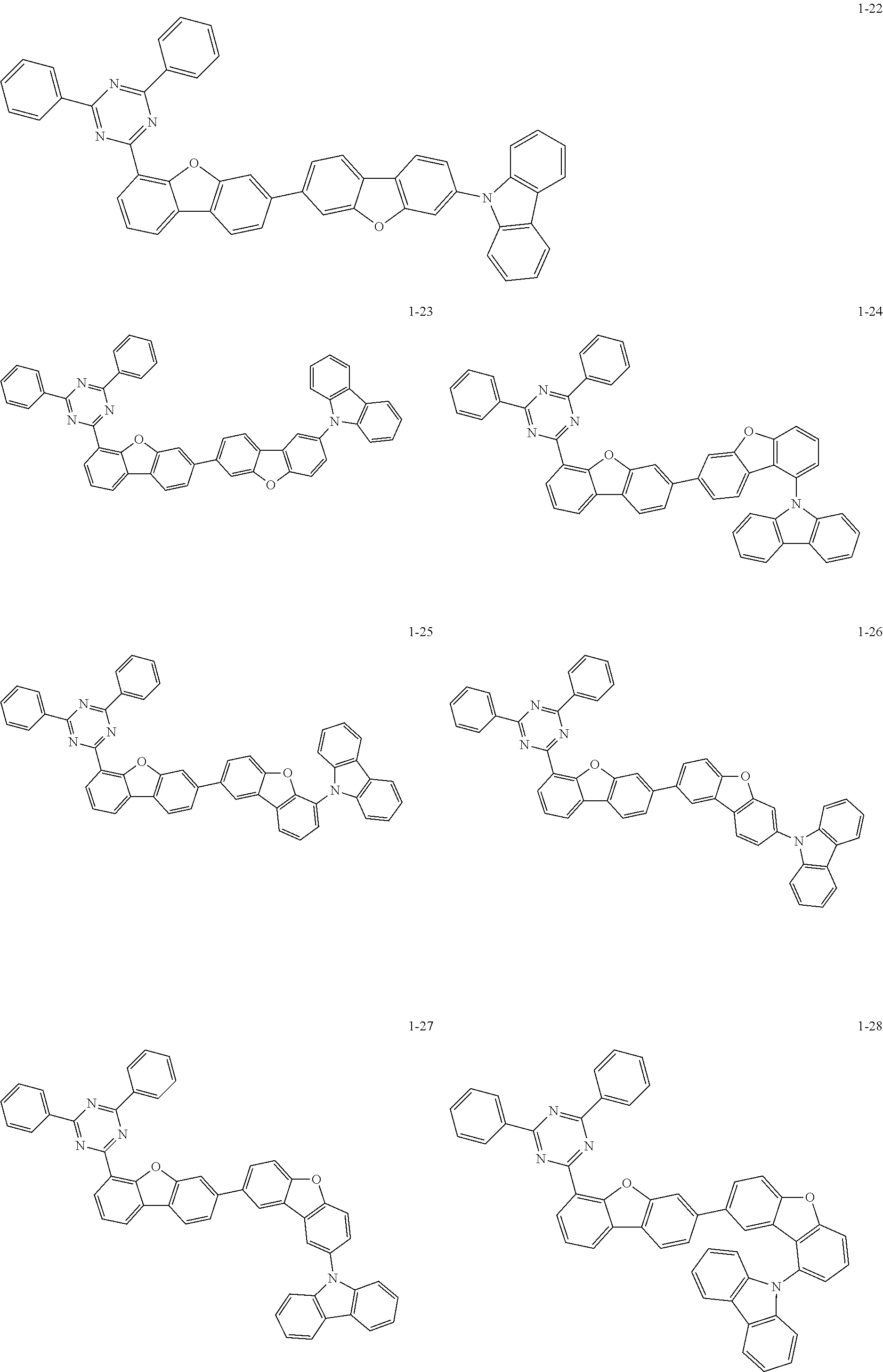

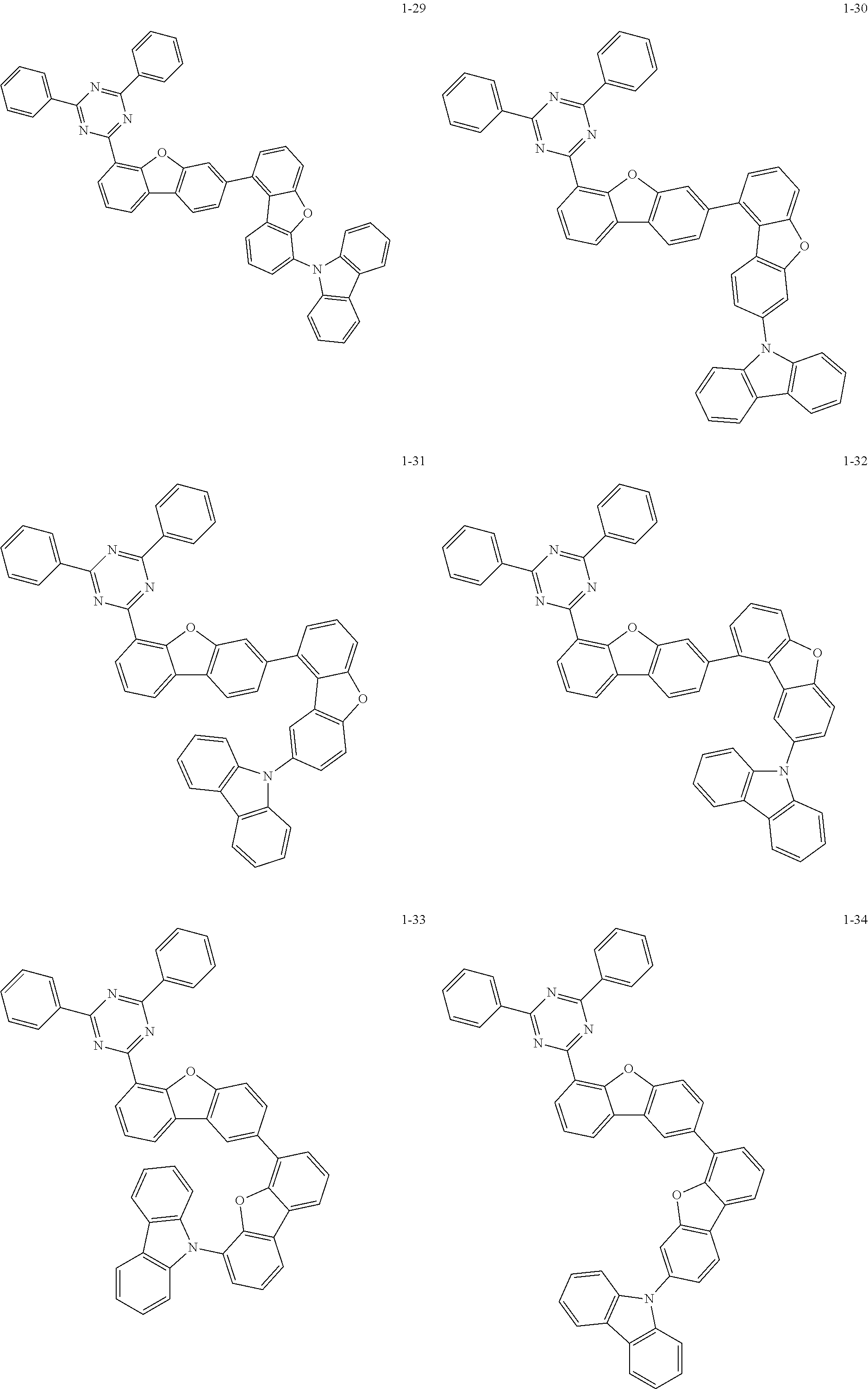

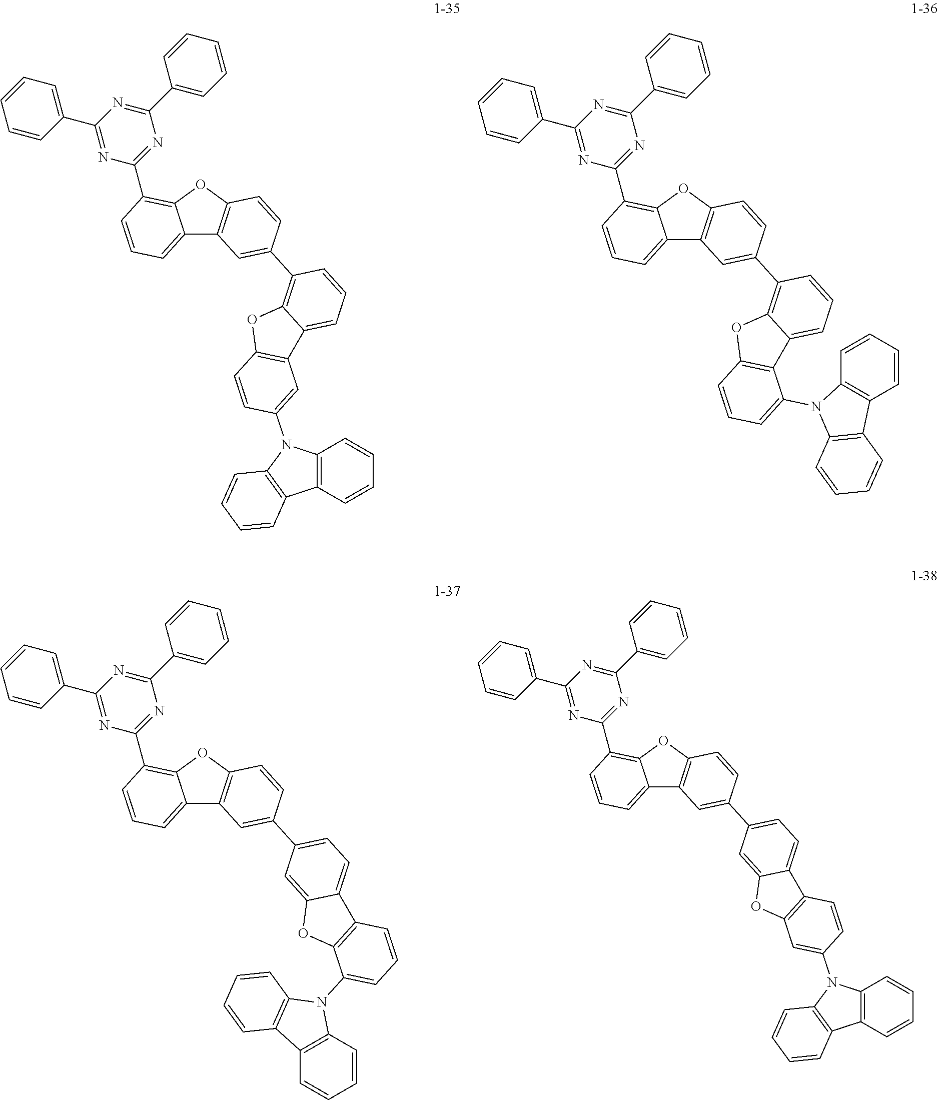 [SMILES: c1ccc(-c2nc(-c3ccccc3)nc(-c3cccc4c3oc3ccc(-c5cccc6c5oc5ccc(-n7c8ccccc8c8ccccc87)cc56)cc34)n2)cc1 ; c1ccc(-c2nc(-c3ccccc3)nc(-c3cccc4c3oc3ccc(-c5cccc6c5oc5cccc(-n7c8ccccc8c8ccccc87)c56)cc34)n2)cc1 ; c1ccc(-c2nc(-c3ccccc3)nc(-c3cccc4c3oc3ccc(-c5ccc6c(c5)oc5c(-n7c8ccccc8c8ccccc87)cccc56)cc34)n2)cc1 ; c1ccc(-c2nc(-c3ccccc3)nc(-c3cccc4c3oc3ccc(-c5ccc6c(c5)oc5cc(-n7c8ccccc8c8ccccc87)ccc56)cc34)n2)cc1]

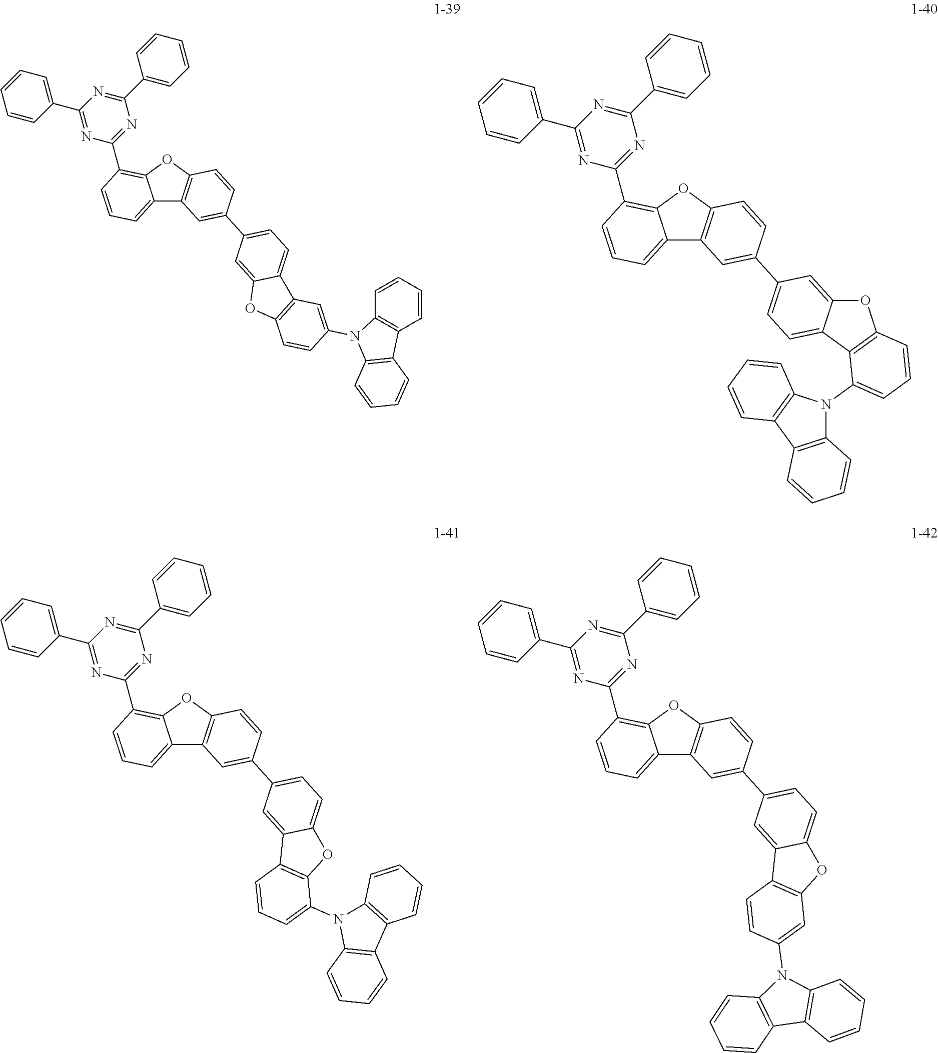 [SMILES: c1ccc(-c2nc(-c3ccccc3)nc(-c3cccc4c3oc3ccc(-c5ccc6c(c5)oc5ccc(-n7c8ccccc8c8ccccc87)cc56)cc34)n2)cc1 ; c1ccc(-c2nc(-c3ccccc3)nc(-c3cccc4c3oc3ccc(-c5ccc6c(c5)oc5cccc(-n7c8ccccc8c8ccccc87)c56)cc34)n2)cc1 ; c1ccc(-c2nc(-c3ccccc3)nc(-c3cccc4c3oc3ccc(-c5ccc6oc7c(-n8c9ccccc9c9ccccc98)cccc7c6c5)cc34)n2)cc1 ; c1ccc(-c2nc(-c3ccccc3)nc(-c3cccc4c3oc3ccc(-c5ccc6oc7cc(-n8c9ccccc9c9ccccc98)ccc7c6c5)cc34)n2)cc1]

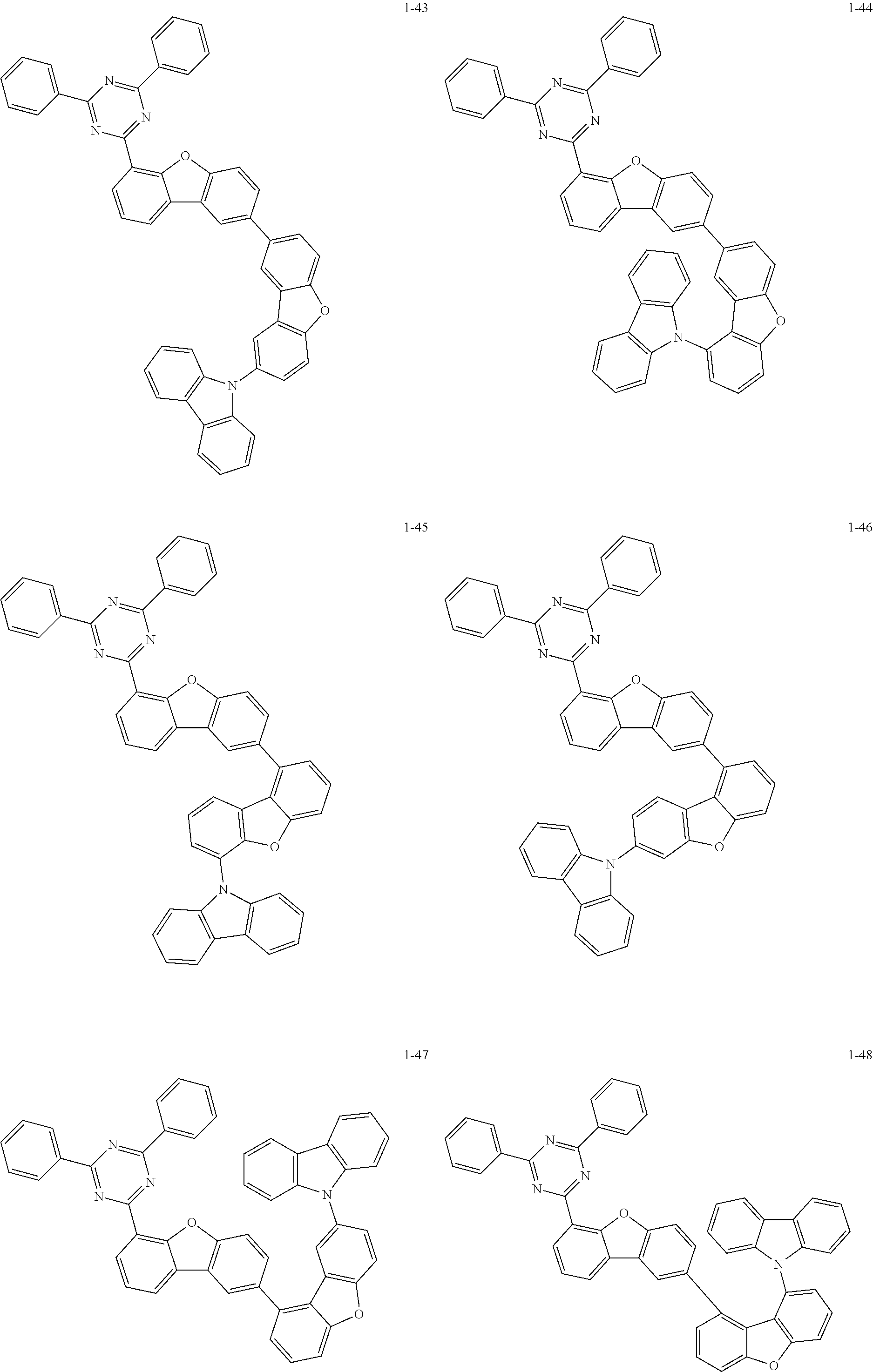

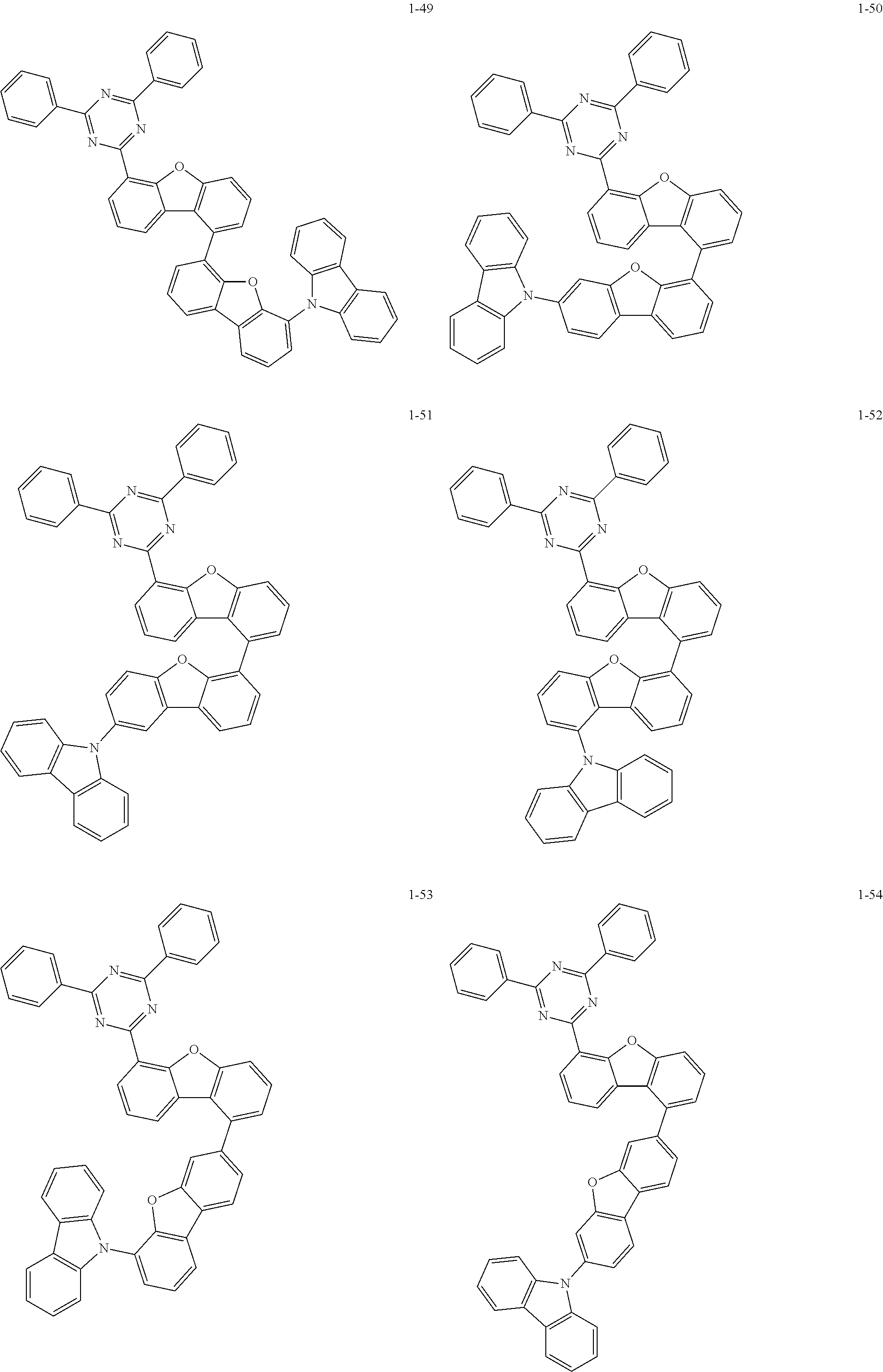

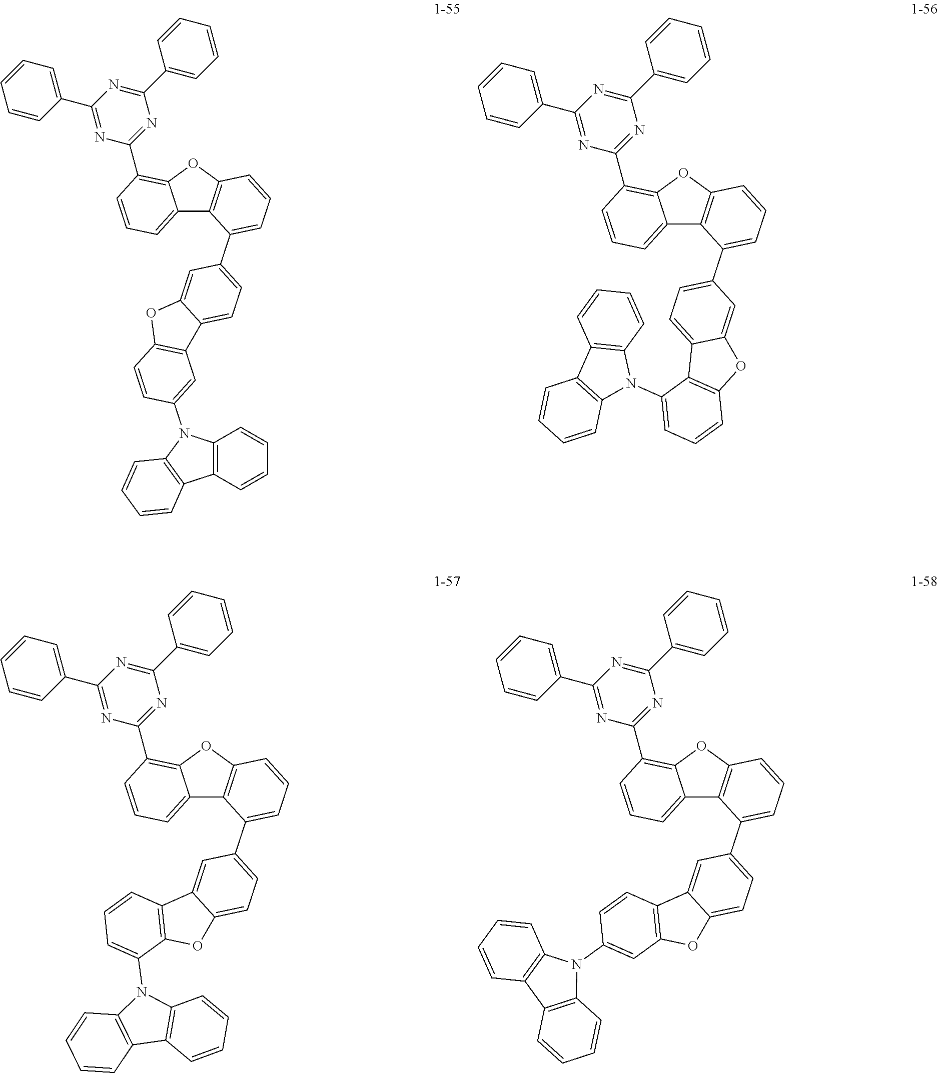 [SMILES: c1ccc(-c2nc(-c3ccccc3)nc(-c3cccc4c3oc3cccc(-c5ccc6c(c5)oc5ccc(-n7c8ccccc8c8ccccc87)cc56)c34)n2)cc1 ; c1ccc(-c2nc(-c3ccccc3)nc(-c3cccc4c3oc3cccc(-c5ccc6c(c5)oc5cccc(-n7c8ccccc8c8ccccc87)c56)c34)n2)cc1 ; c1ccc(-c2nc(-c3ccccc3)nc(-c3cccc4c3oc3cccc(-c5ccc6oc7c(-n8c9ccccc9c9ccccc98)cccc7c6c5)c34)n2)cc1 ; c1ccc(-c2nc(-c3ccccc3)nc(-c3cccc4c3oc3cccc(-c5ccc6oc7cc(-n8c9ccccc9c9ccccc98)ccc7c6c5)c34)n2)cc1]

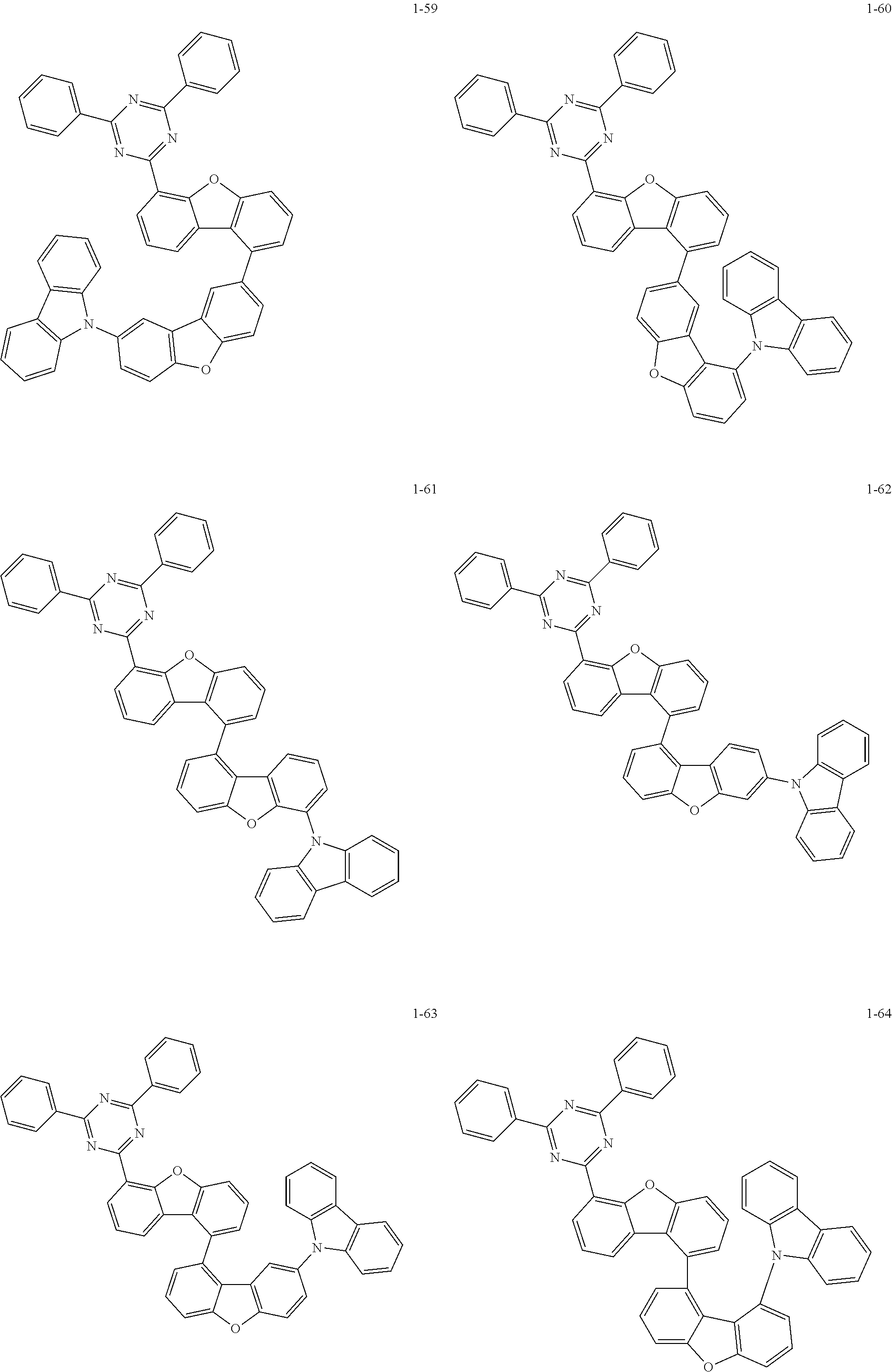

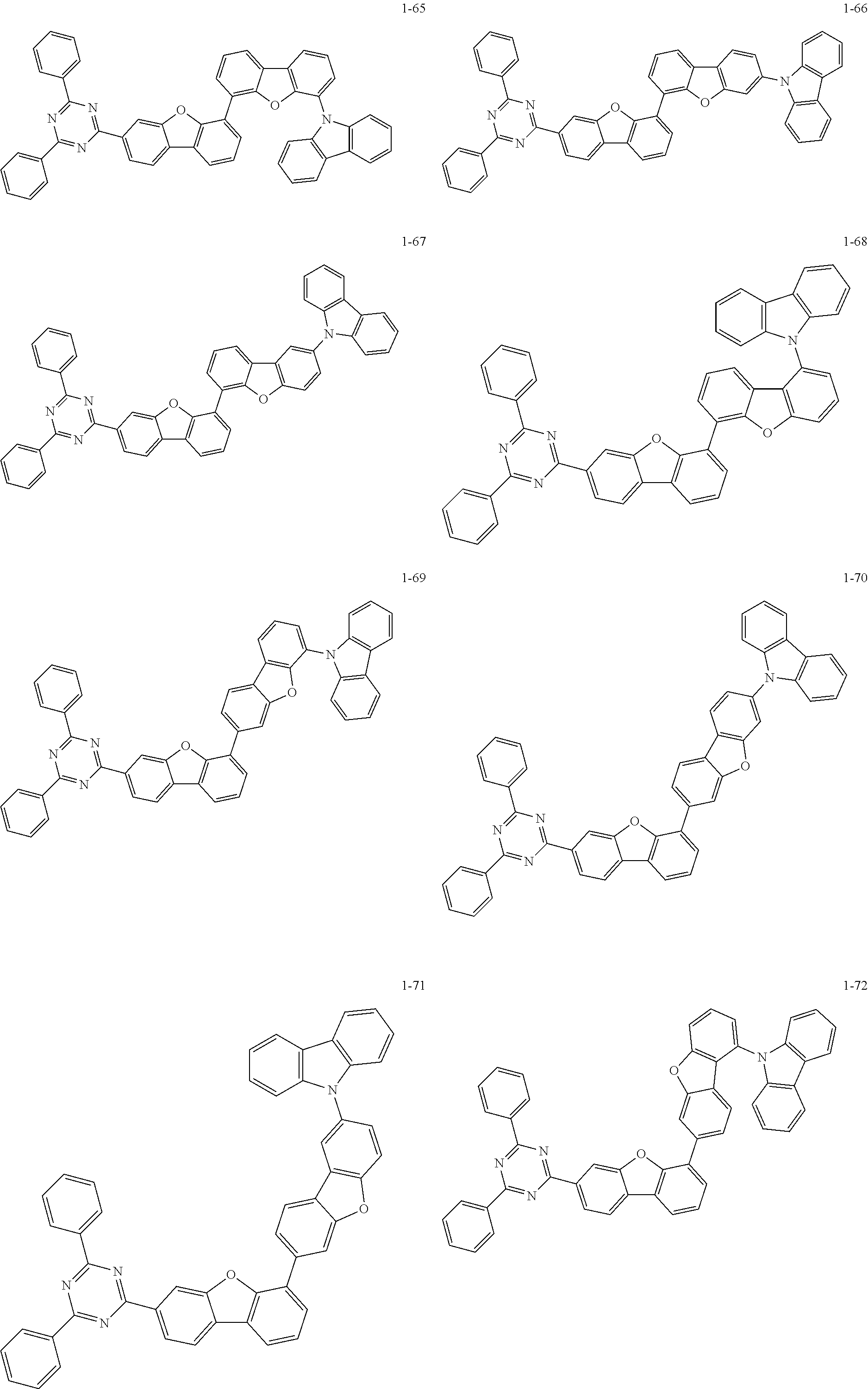

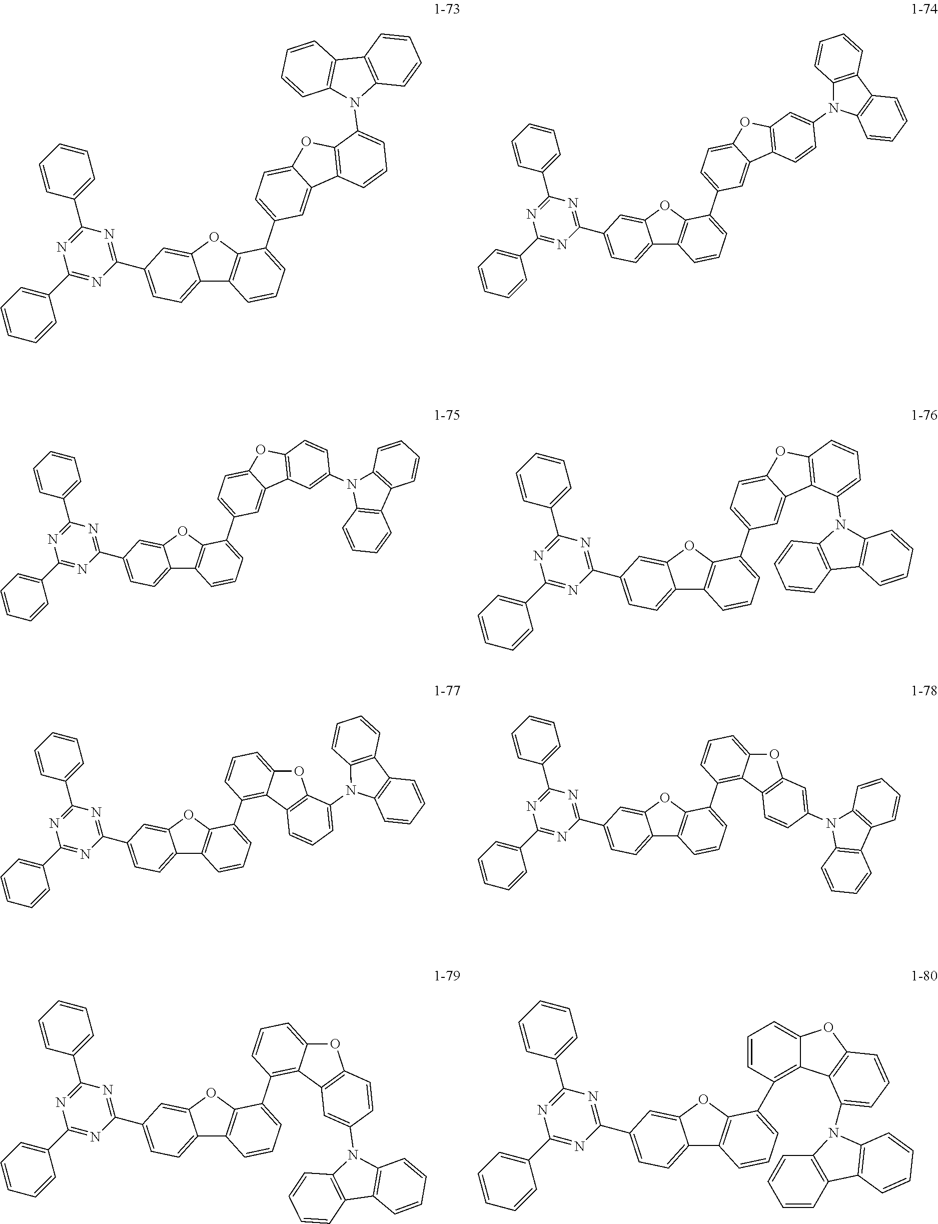

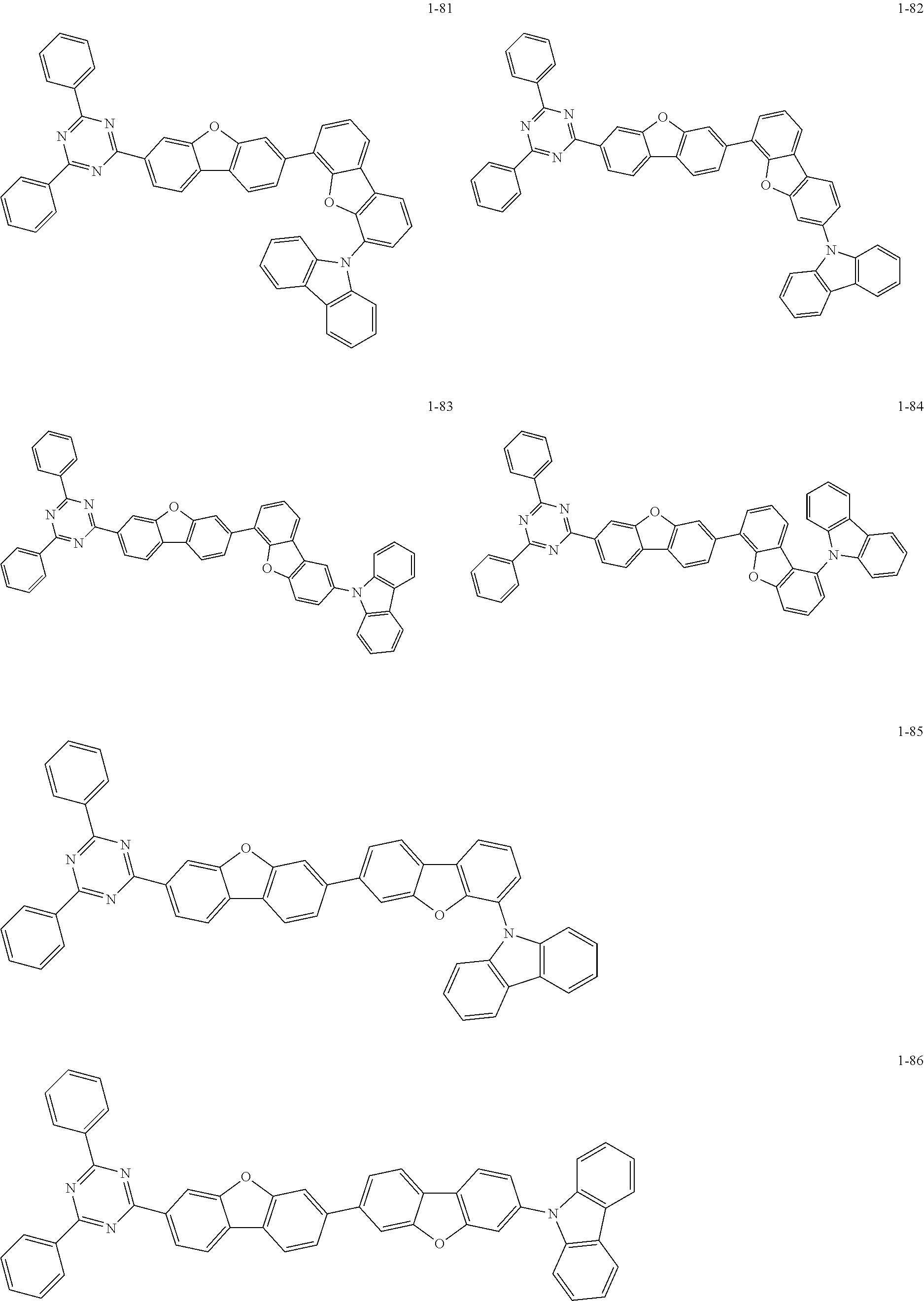

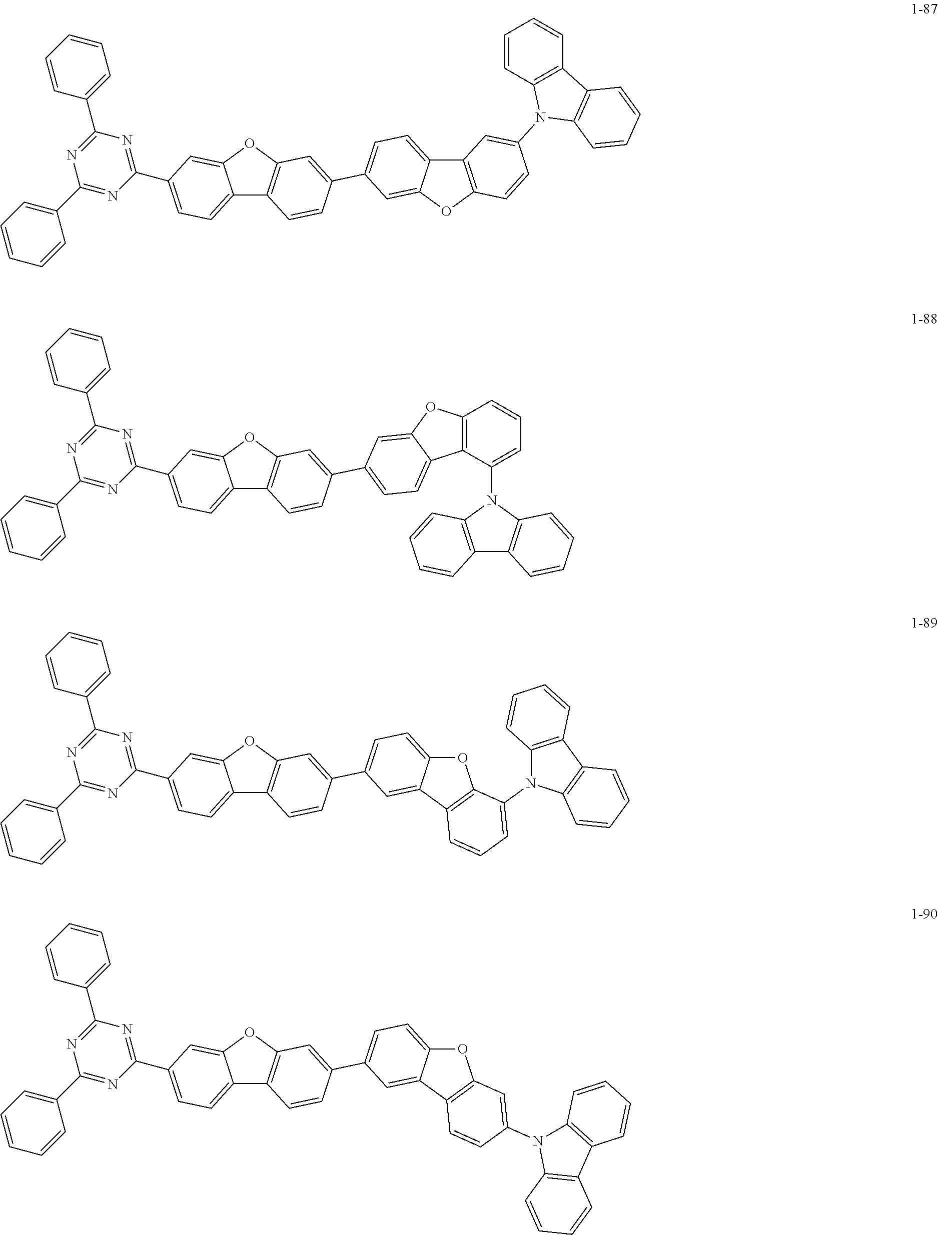 [SMILES: c1ccc(-c2nc(-c3ccccc3)nc(-c3ccc4c(c3)oc3cc(-c5ccc6c(c5)oc5ccc(-n7c8ccccc8c8ccccc87)cc56)ccc34)n2)cc1 ; c1ccc(-c2nc(-c3ccccc3)nc(-c3ccc4c(c3)oc3cc(-c5ccc6c(c5)oc5cccc(-n7c8ccccc8c8ccccc87)c56)ccc34)n2)cc1 ; c1ccc(-c2nc(-c3ccccc3)nc(-c3ccc4c(c3)oc3cc(-c5ccc6oc7c(-n8c9ccccc9c9ccccc98)cccc7c6c5)ccc34)n2)cc1 ; c1ccc(-c2nc(-c3ccccc3)nc(-c3ccc4c(c3)oc3cc(-c5ccc6oc7cc(-n8c9ccccc9c9ccccc98)ccc7c6c5)ccc34)n2)cc1]

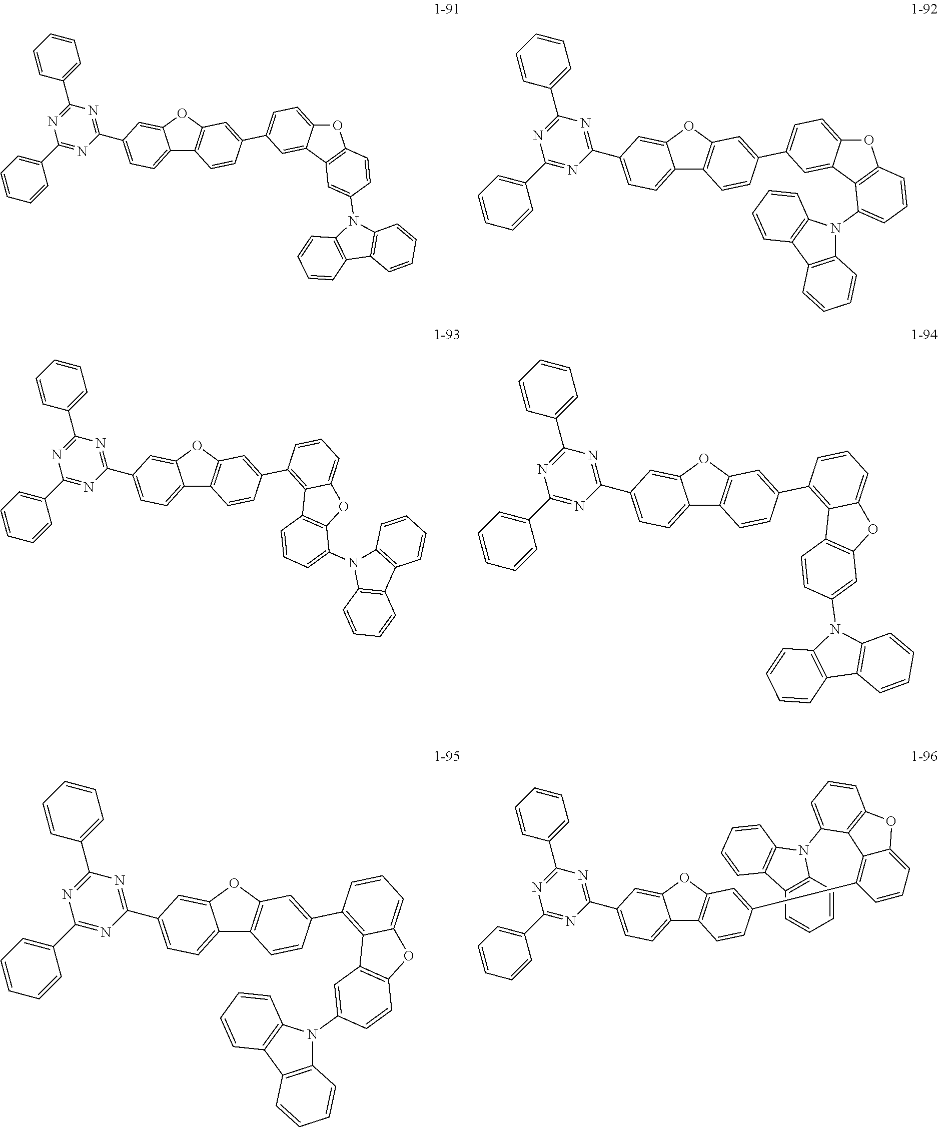

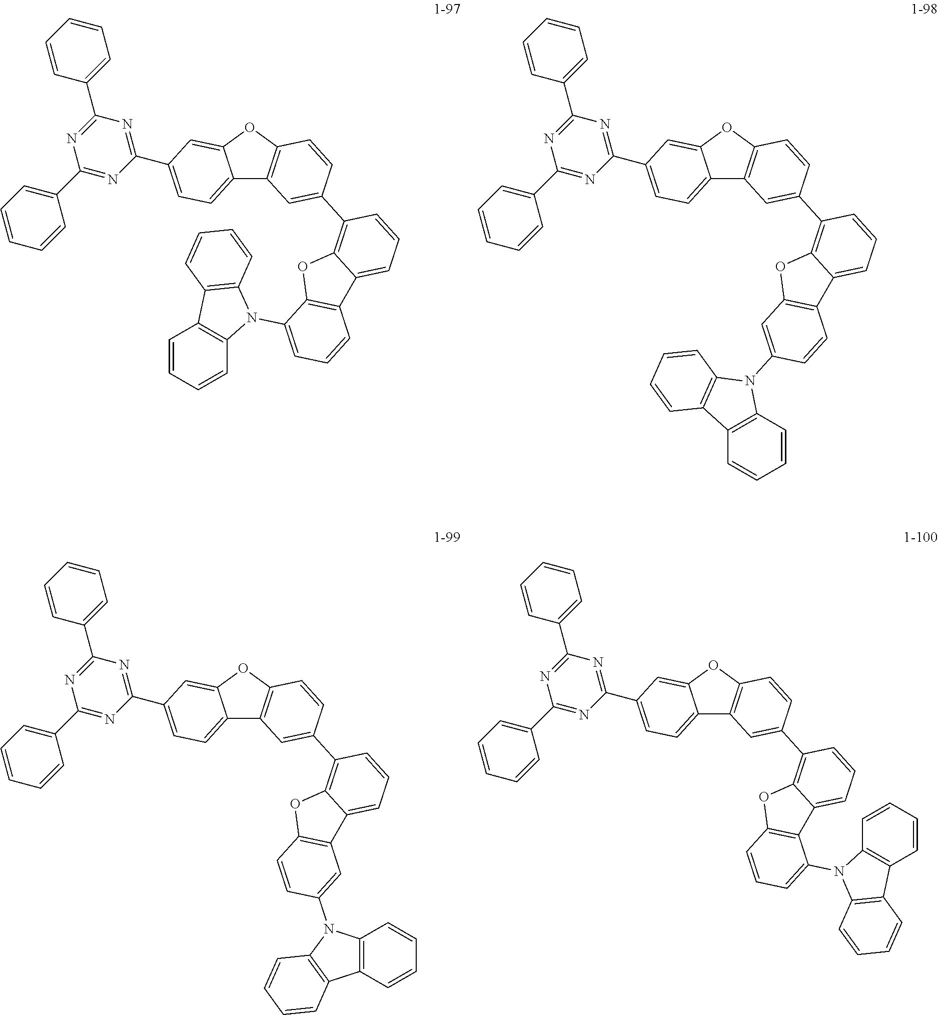 [SMILES: c1ccc(-c2nc(-c3ccccc3)nc(-c3ccc4c(c3)oc3ccc(-c5cccc6c5oc5c(-n7c8ccccc8c8ccccc87)cccc56)cc34)n2)cc1 ; c1ccc(-c2nc(-c3ccccc3)nc(-c3ccc4c(c3)oc3ccc(-c5cccc6c5oc5cc(-n7c8ccccc8c8ccccc87)ccc56)cc34)n2)cc1 ; c1ccc(-c2nc(-c3ccccc3)nc(-c3ccc4c(c3)oc3ccc(-c5cccc6c5oc5ccc(-n7c8ccccc8c8ccccc87)cc56)cc34)n2)cc1 ; c1ccc(-c2nc(-c3ccccc3)nc(-c3ccc4c(c3)oc3ccc(-c5cccc6c5oc5cccc(-n7c8ccccc8c8ccccc87)c56)cc34)n2)cc1]

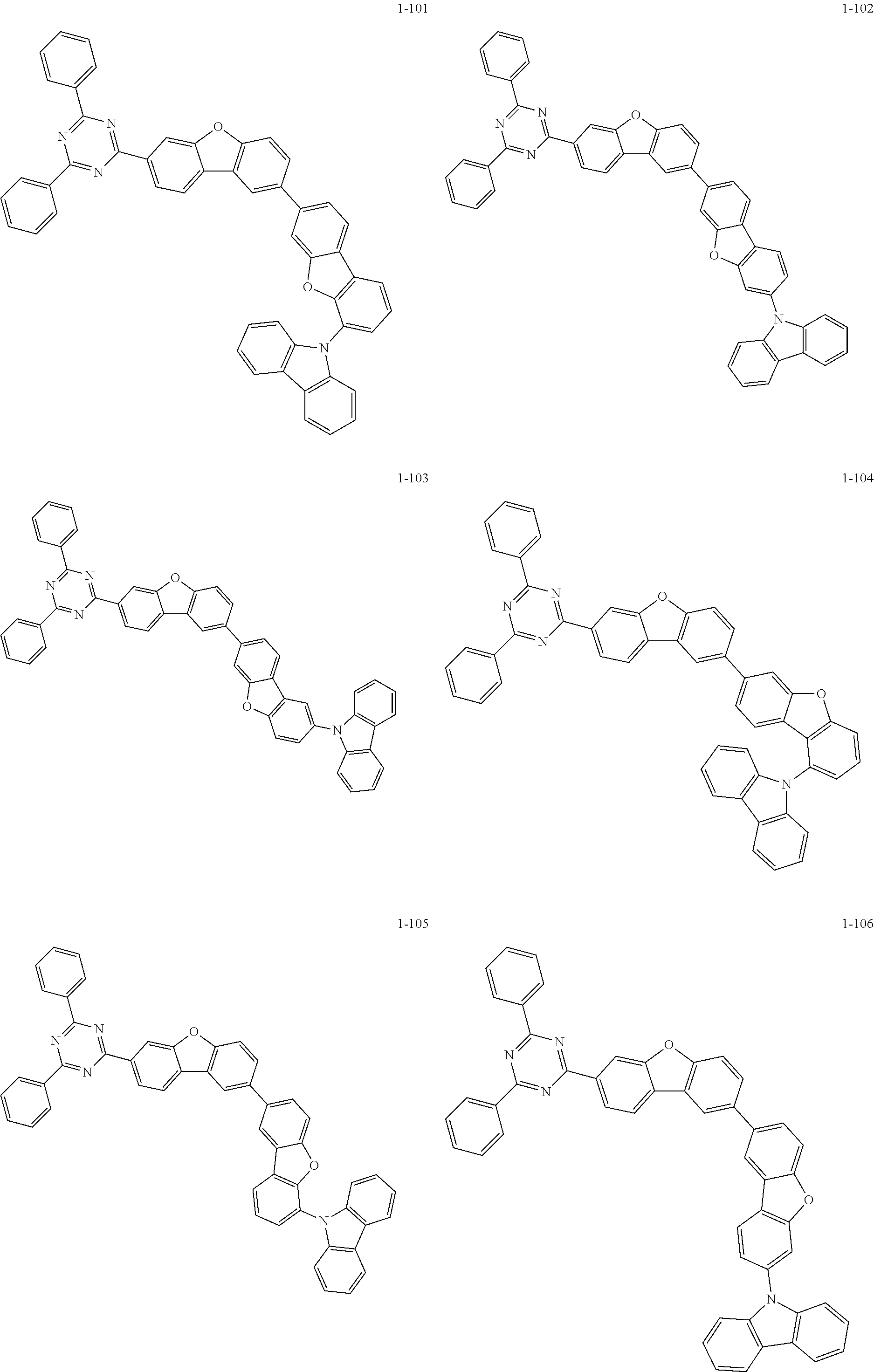

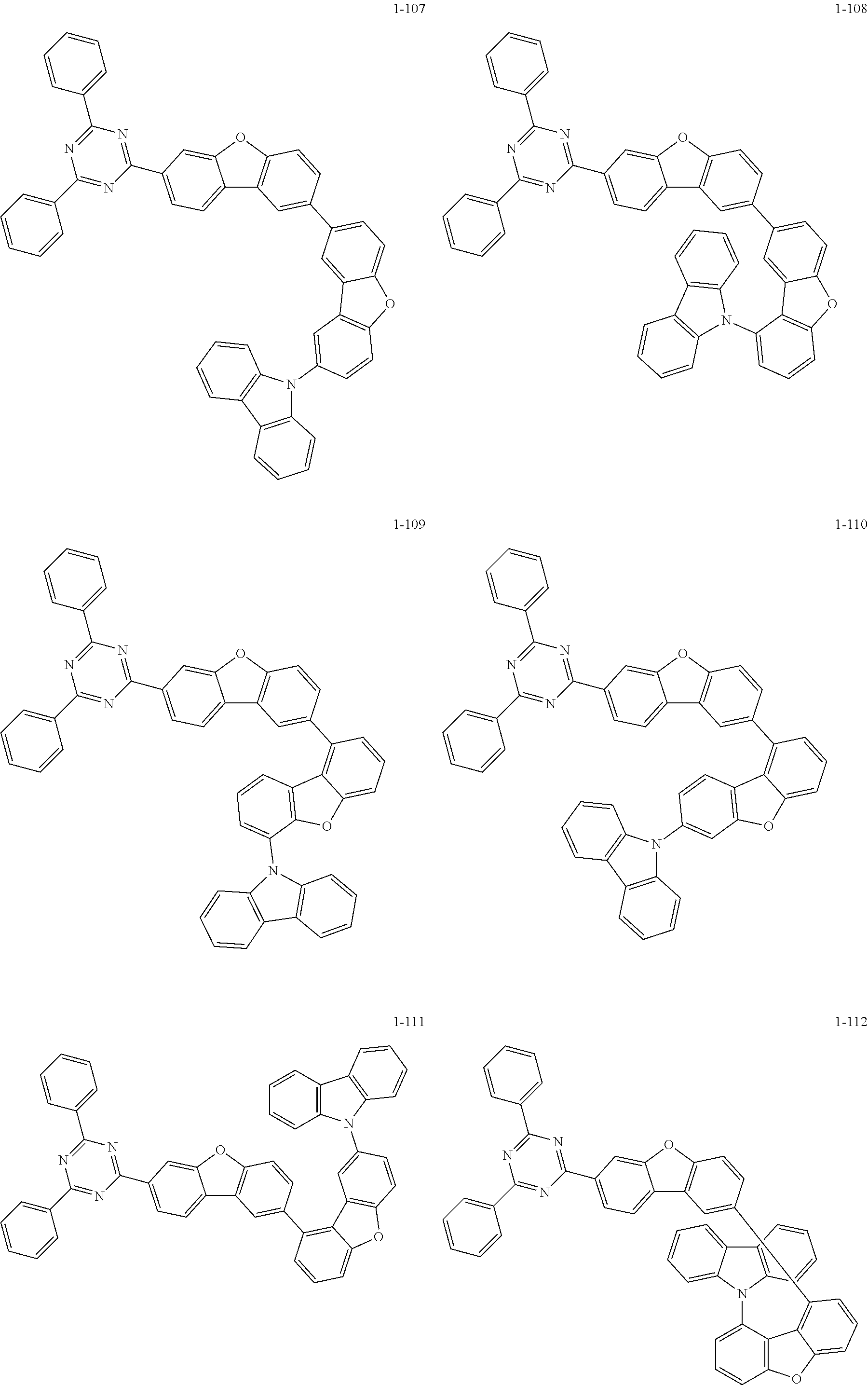

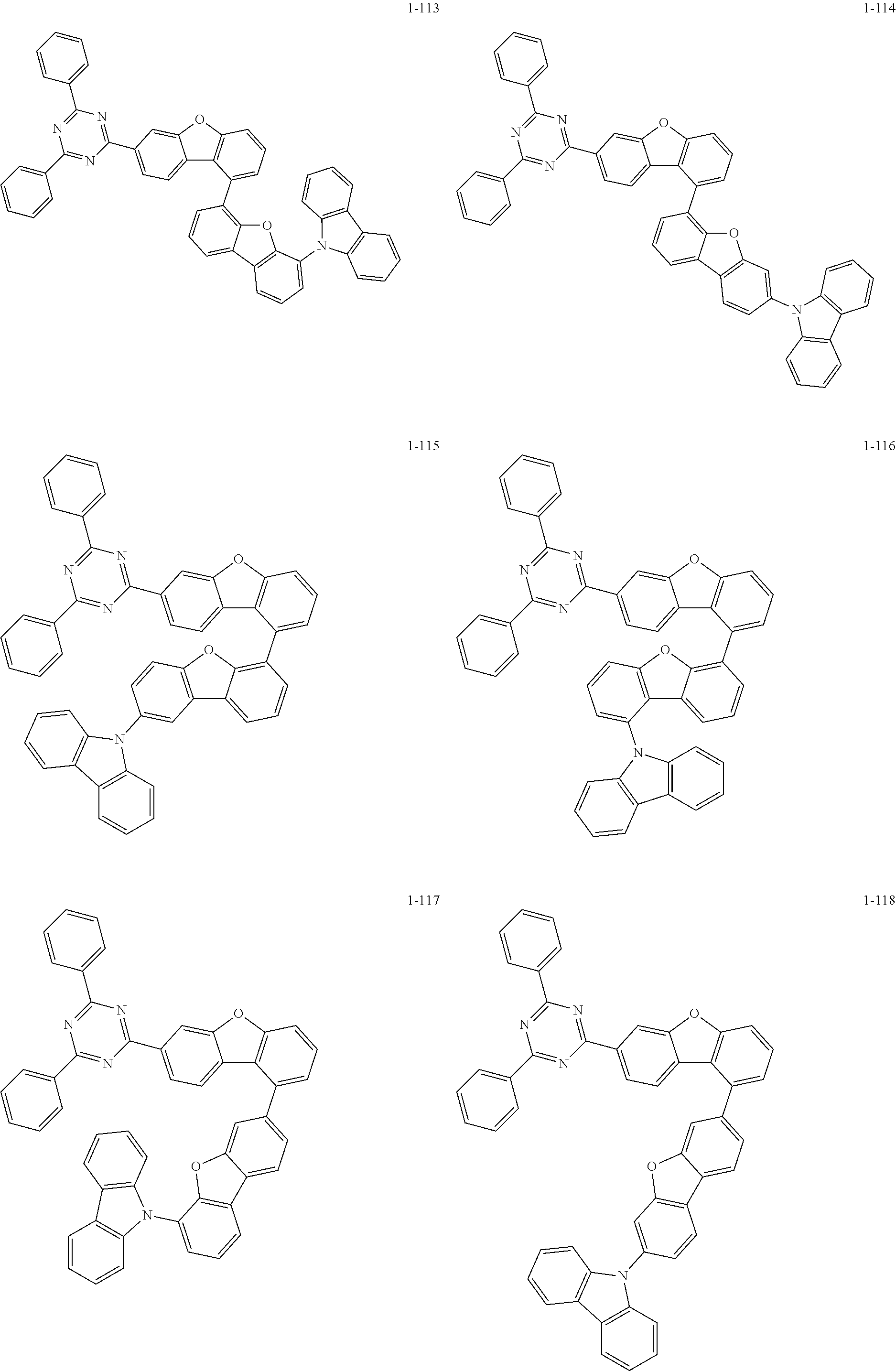

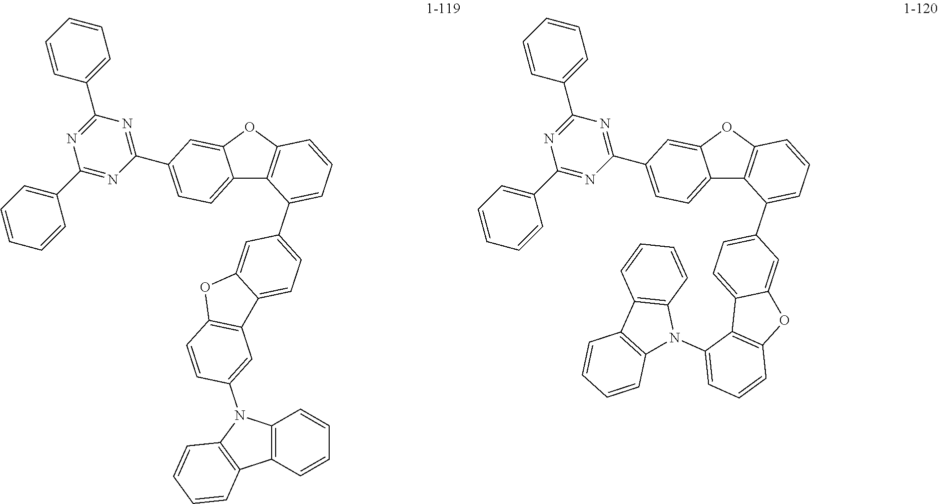 [SMILES: c1ccc(-c2nc(-c3ccccc3)nc(-c3ccc4c(c3)oc3cccc(-c5ccc6c(c5)oc5ccc(-n7c8ccccc8c8ccccc87)cc56)c34)n2)cc1 ; c1ccc(-c2nc(-c3ccccc3)nc(-c3ccc4c(c3)oc3cccc(-c5ccc6c(c5)oc5cccc(-n7c8ccccc8c8ccccc87)c56)c34)n2)cc1]

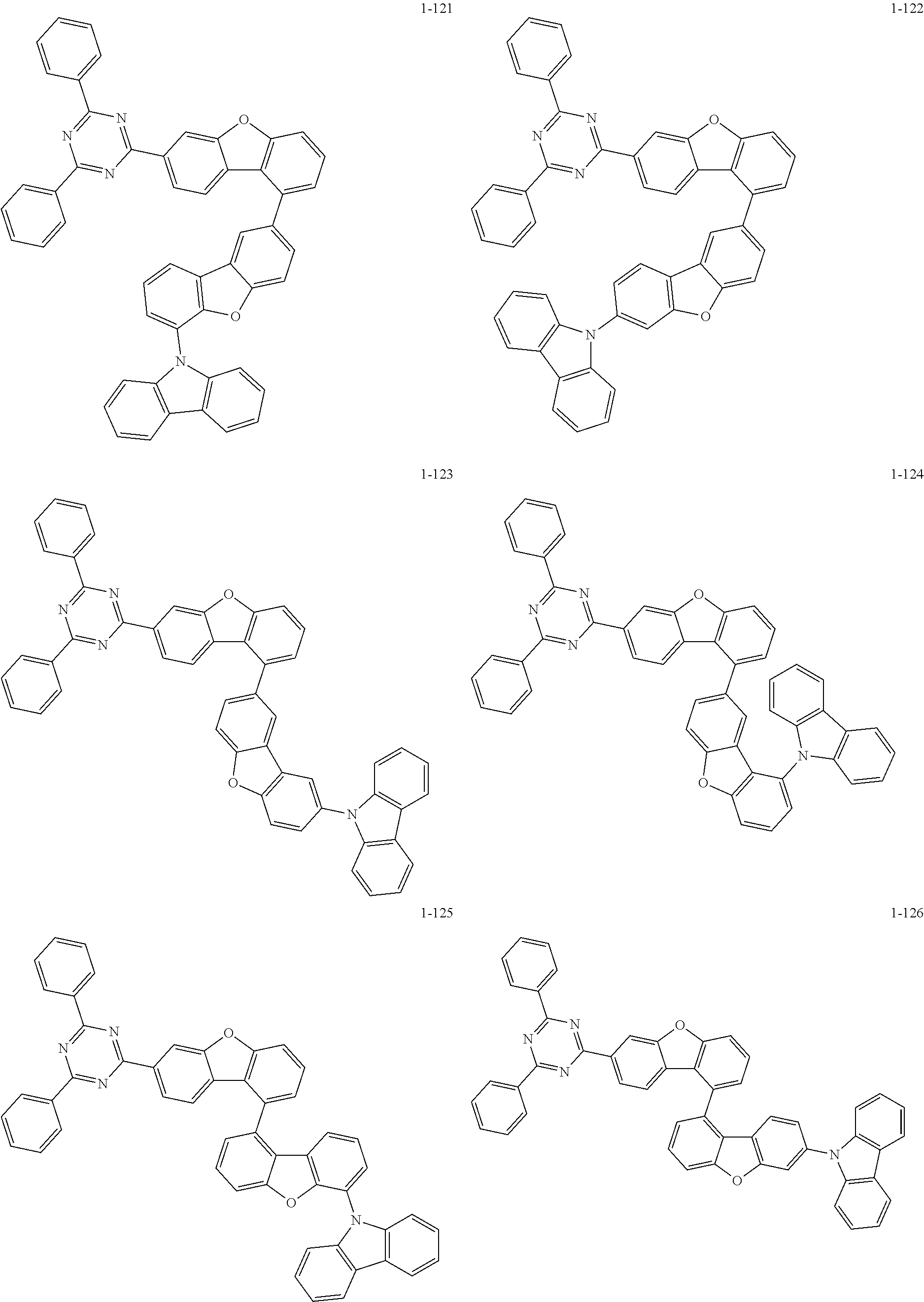

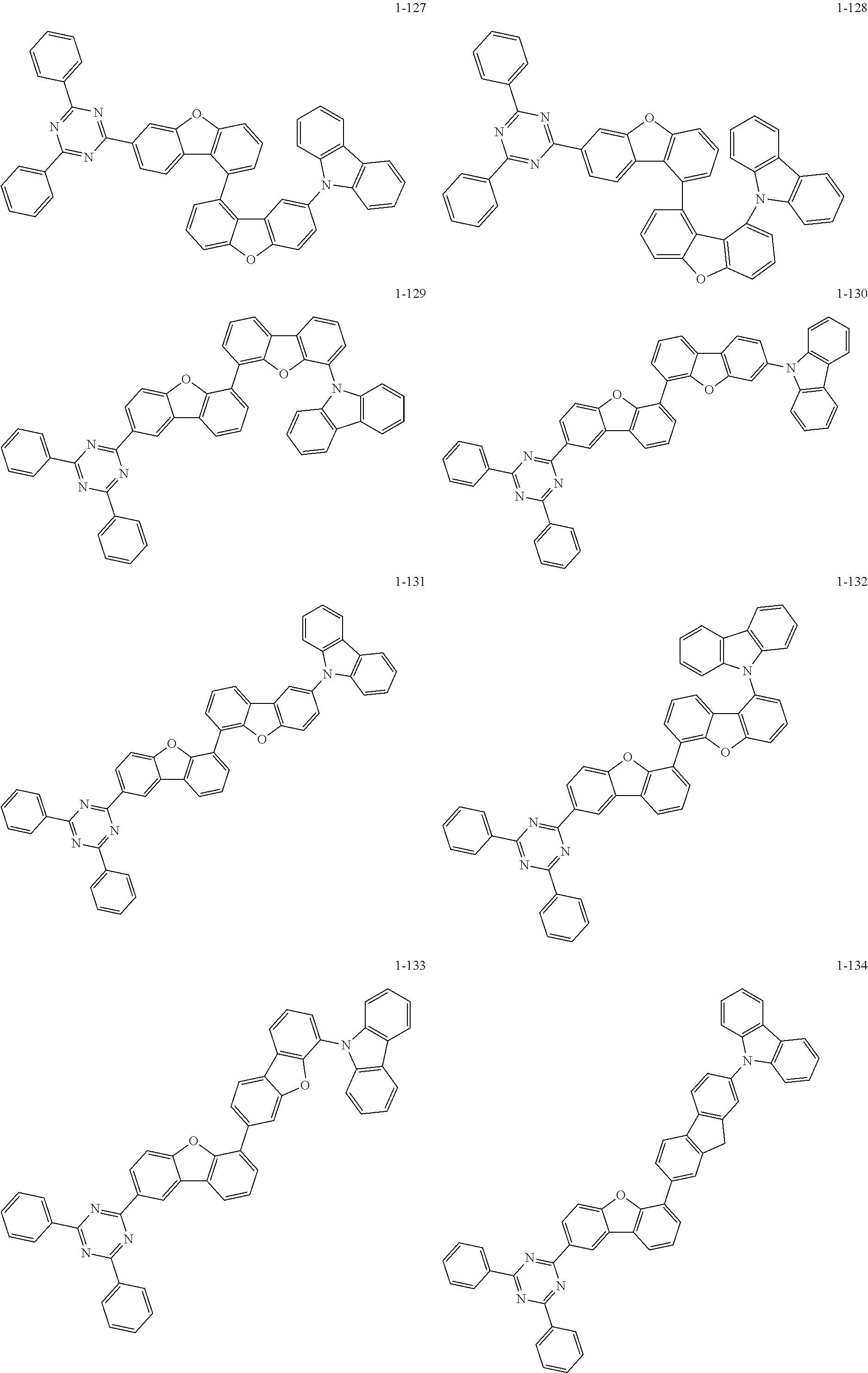

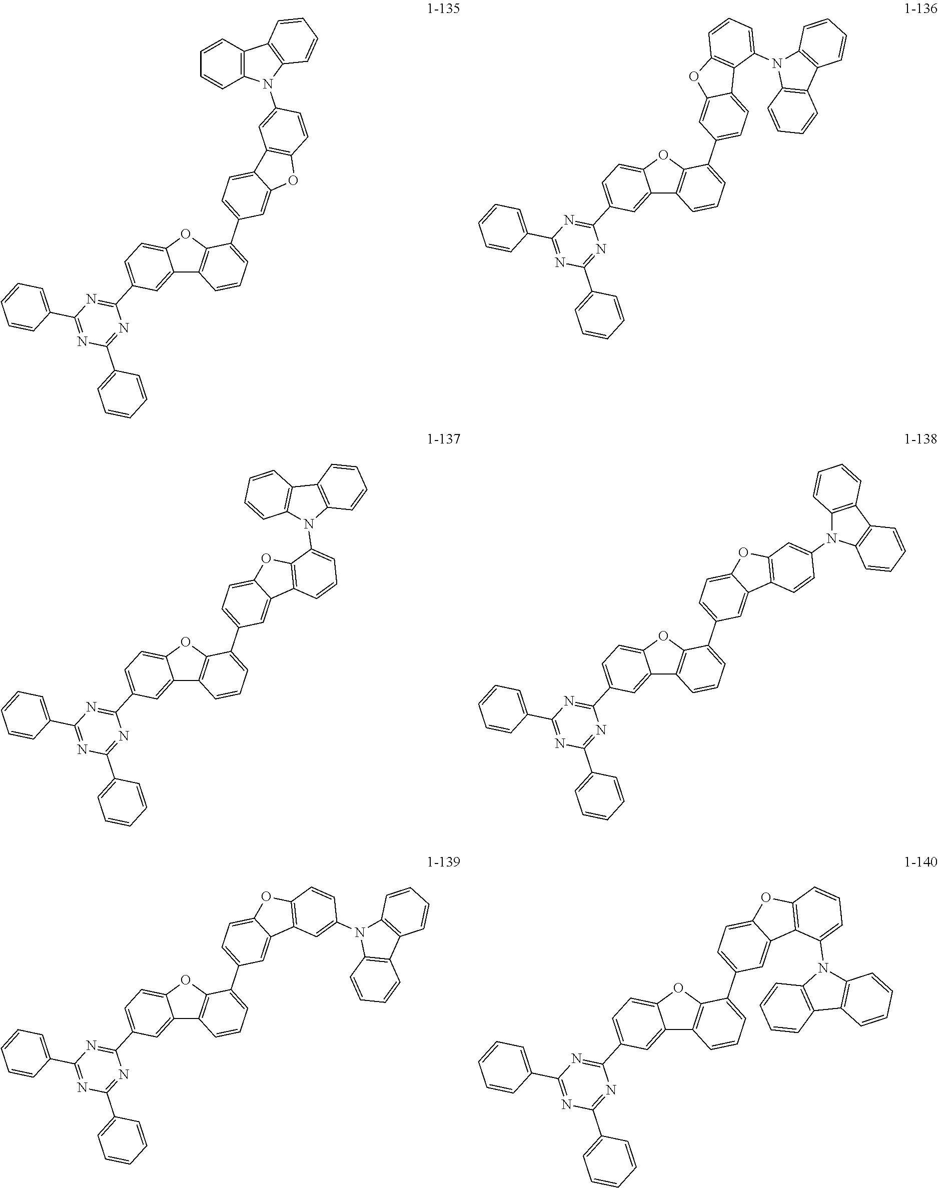

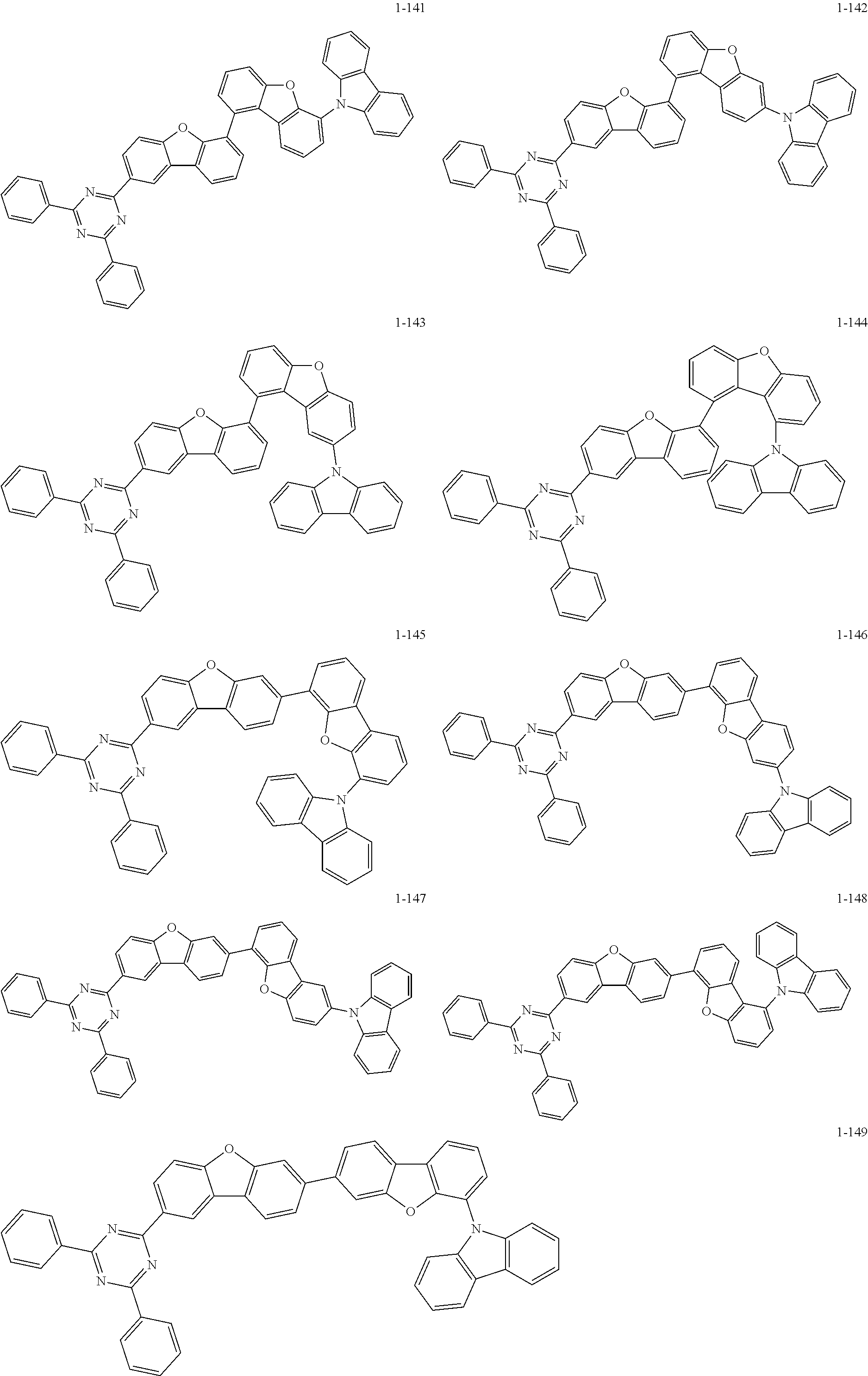

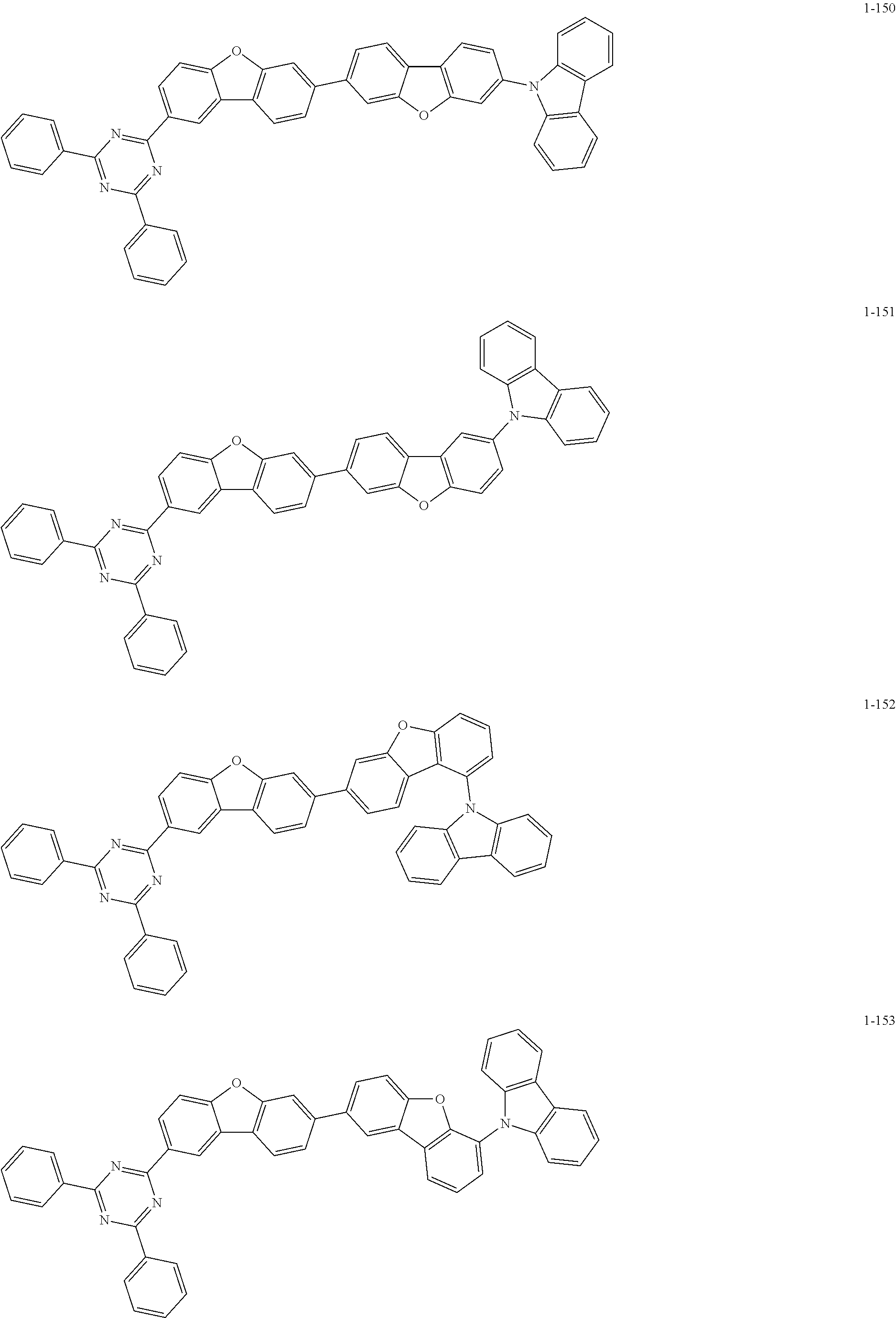 [SMILES: c1ccc(-c2nc(-c3ccccc3)nc(-c3ccc4oc5cc(-c6ccc7c(c6)oc6cc(-n8c9ccccc9c9ccccc98)ccc67)ccc5c4c3)n2)cc1 ; c1ccc(-c2nc(-c3ccccc3)nc(-c3ccc4oc5cc(-c6ccc7c(c6)oc6ccc(-n8c9ccccc9c9ccccc98)cc67)ccc5c4c3)n2)cc1 ; c1ccc(-c2nc(-c3ccccc3)nc(-c3ccc4oc5cc(-c6ccc7c(c6)oc6cccc(-n8c9ccccc9c9ccccc98)c67)ccc5c4c3)n2)cc1 ; c1ccc(-c2nc(-c3ccccc3)nc(-c3ccc4oc5cc(-c6ccc7oc8c(-n9c%10ccccc%10c%10ccccc%109)cccc8c7c6)ccc5c4c3)n2)cc1]

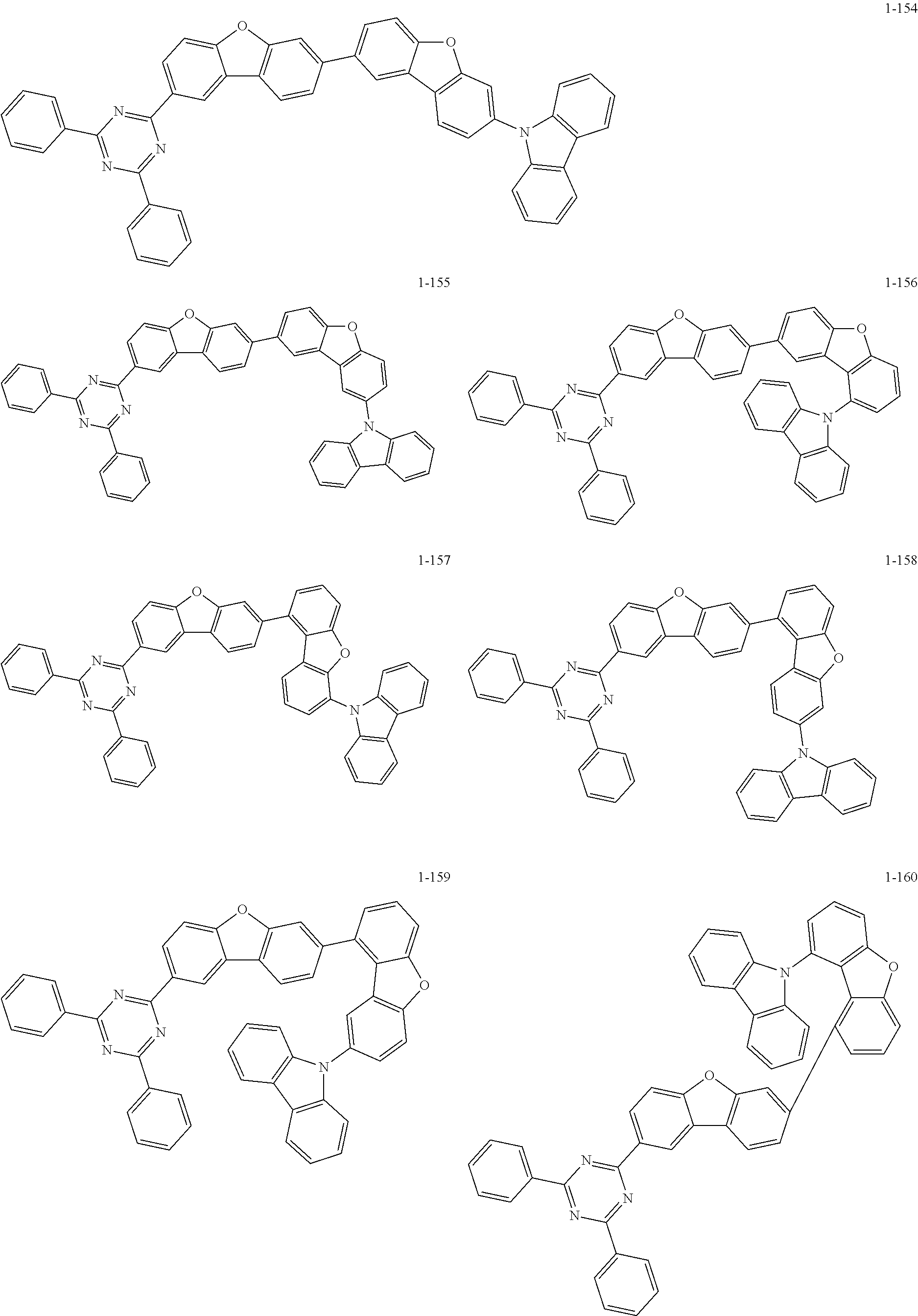

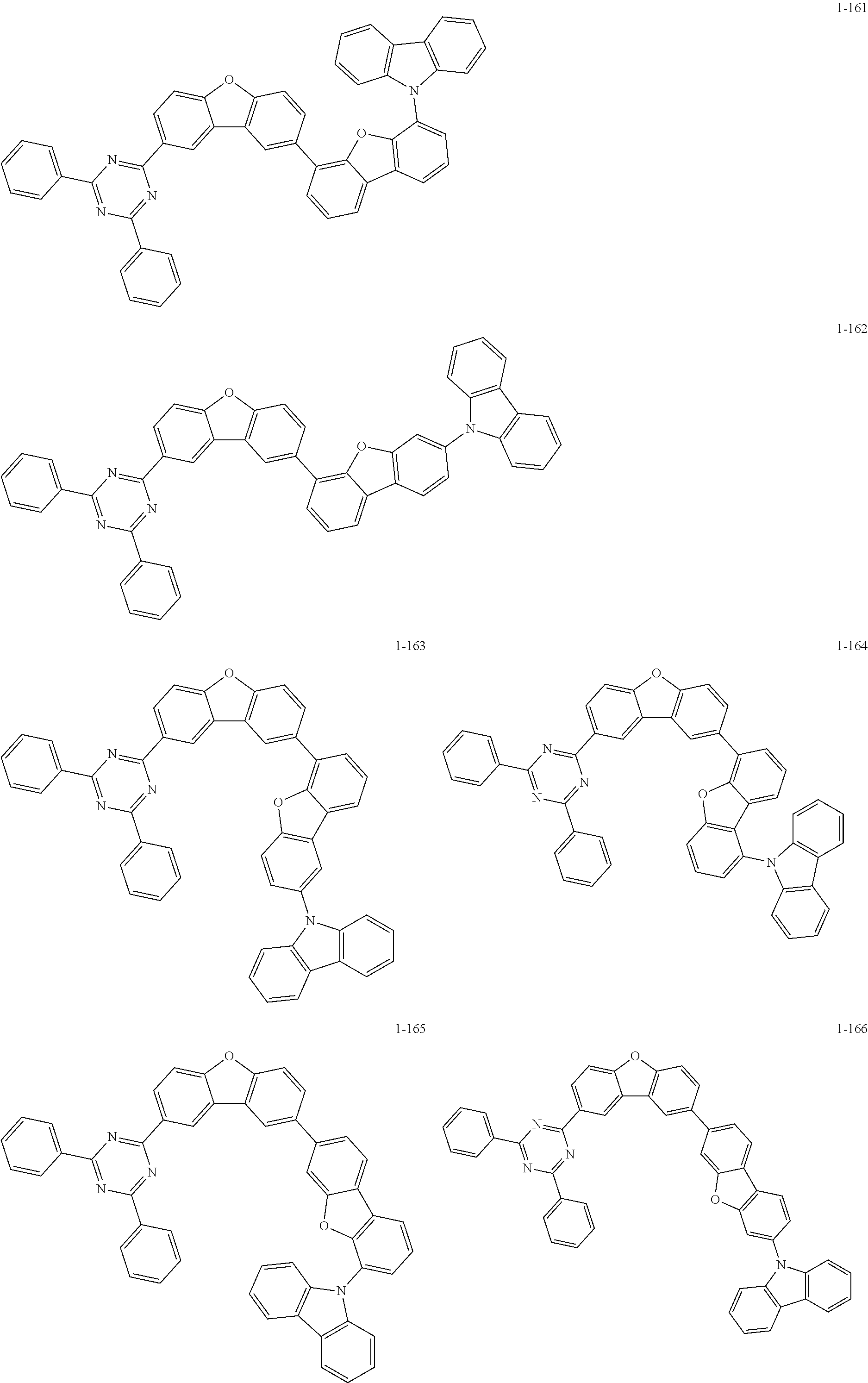

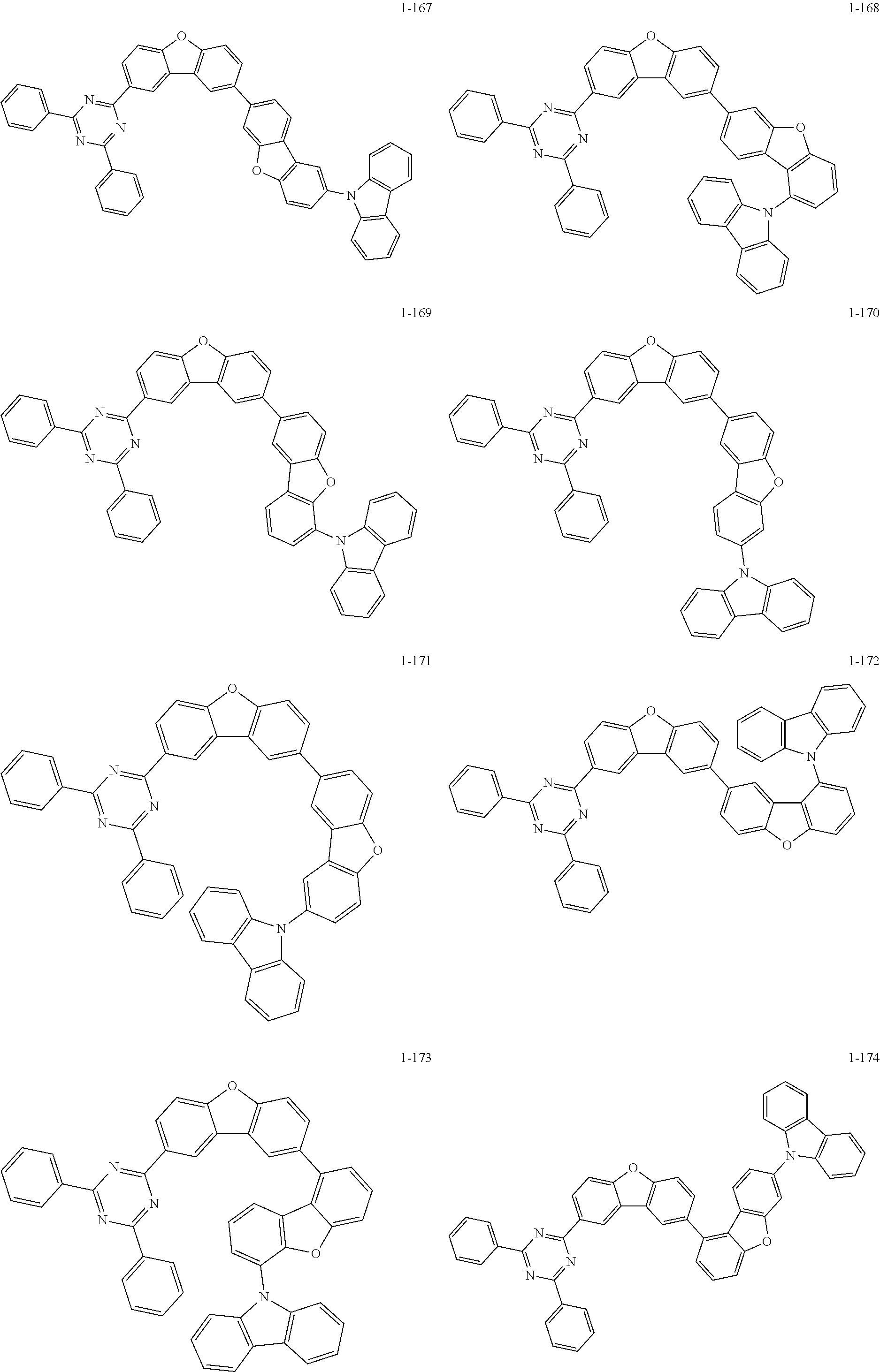

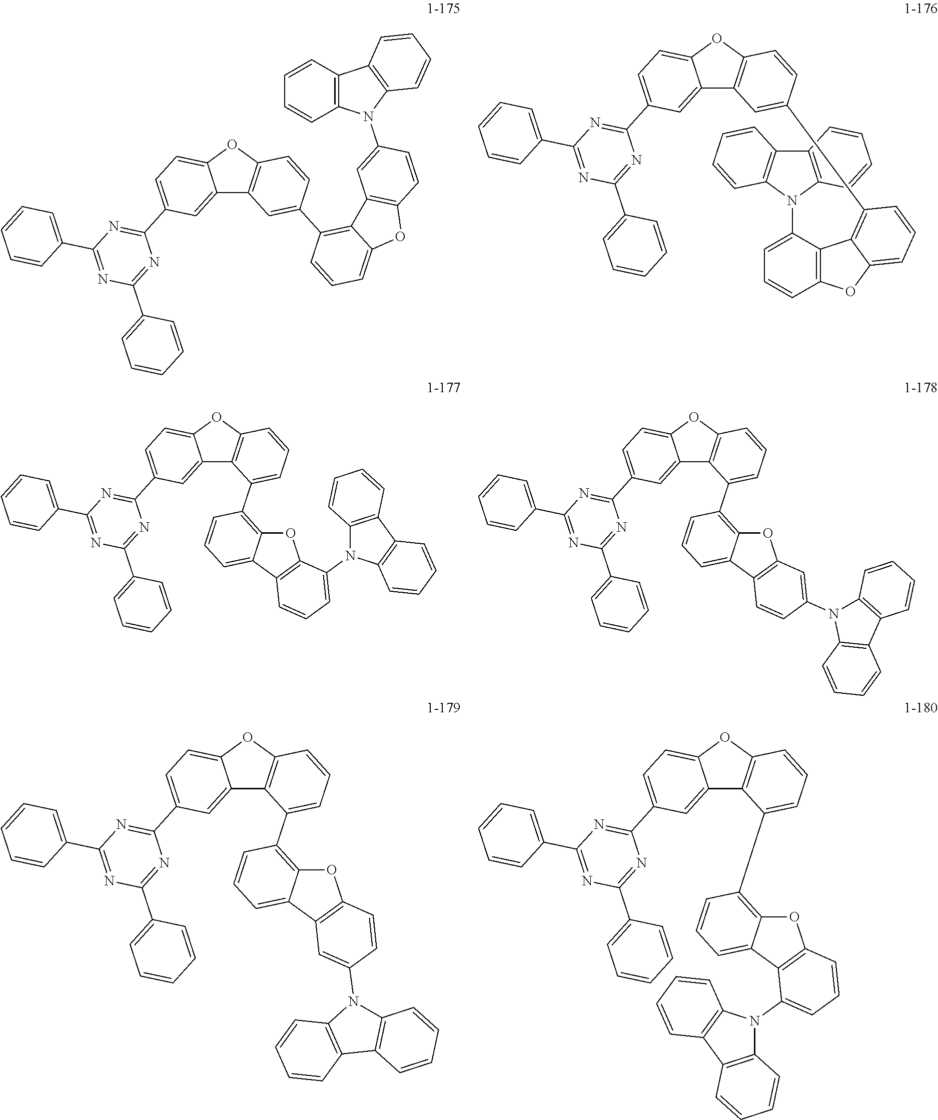

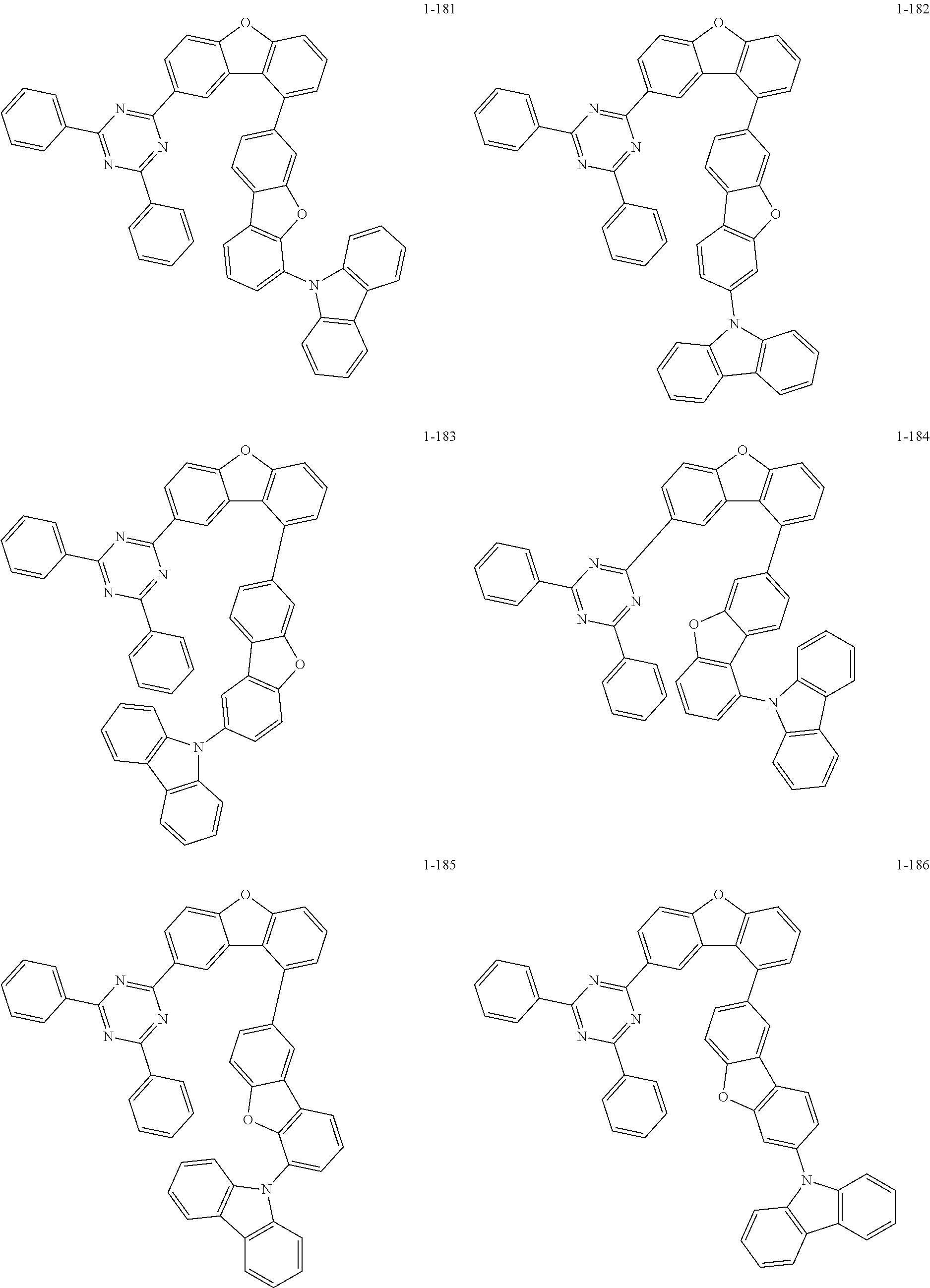

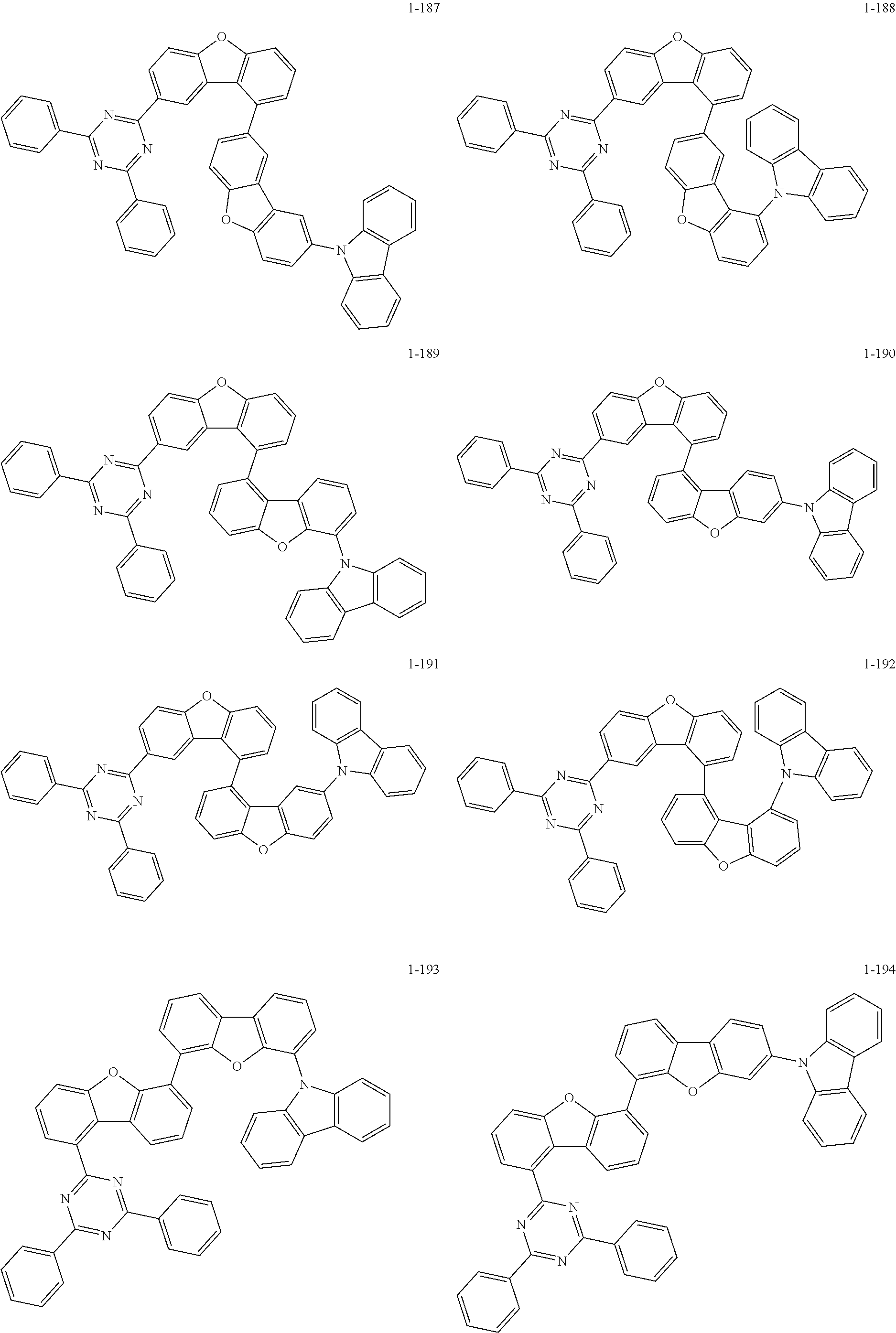

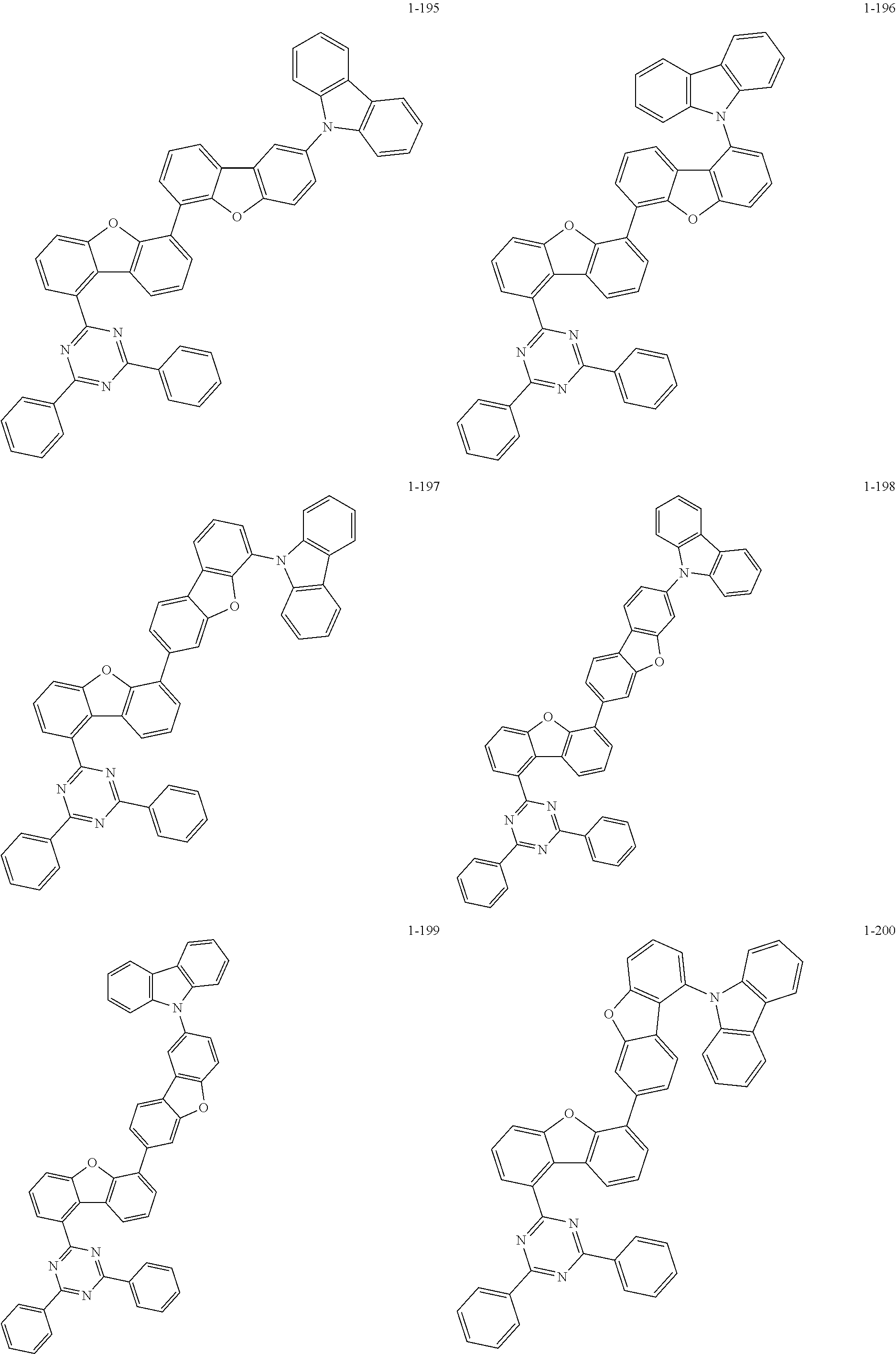

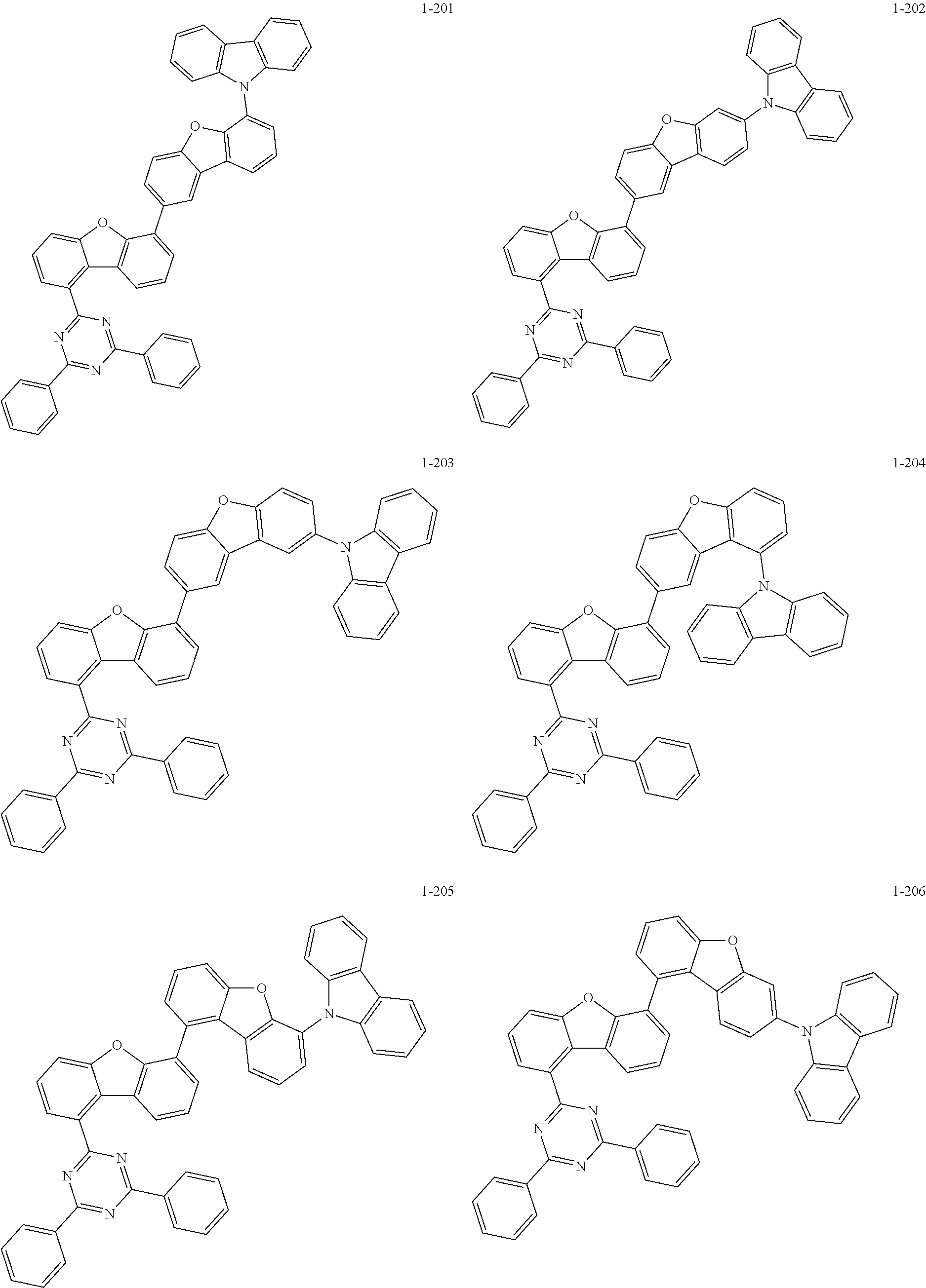

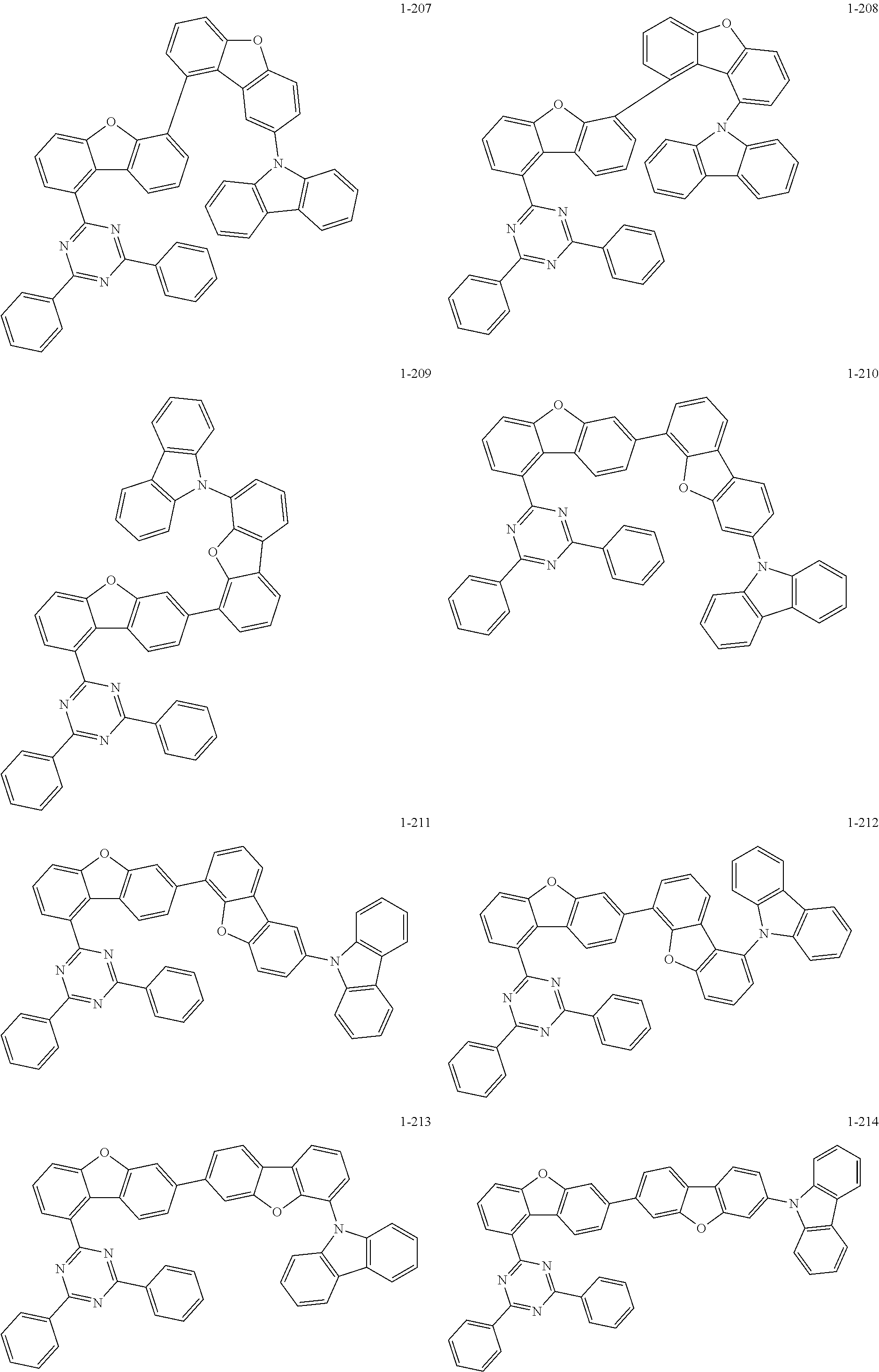

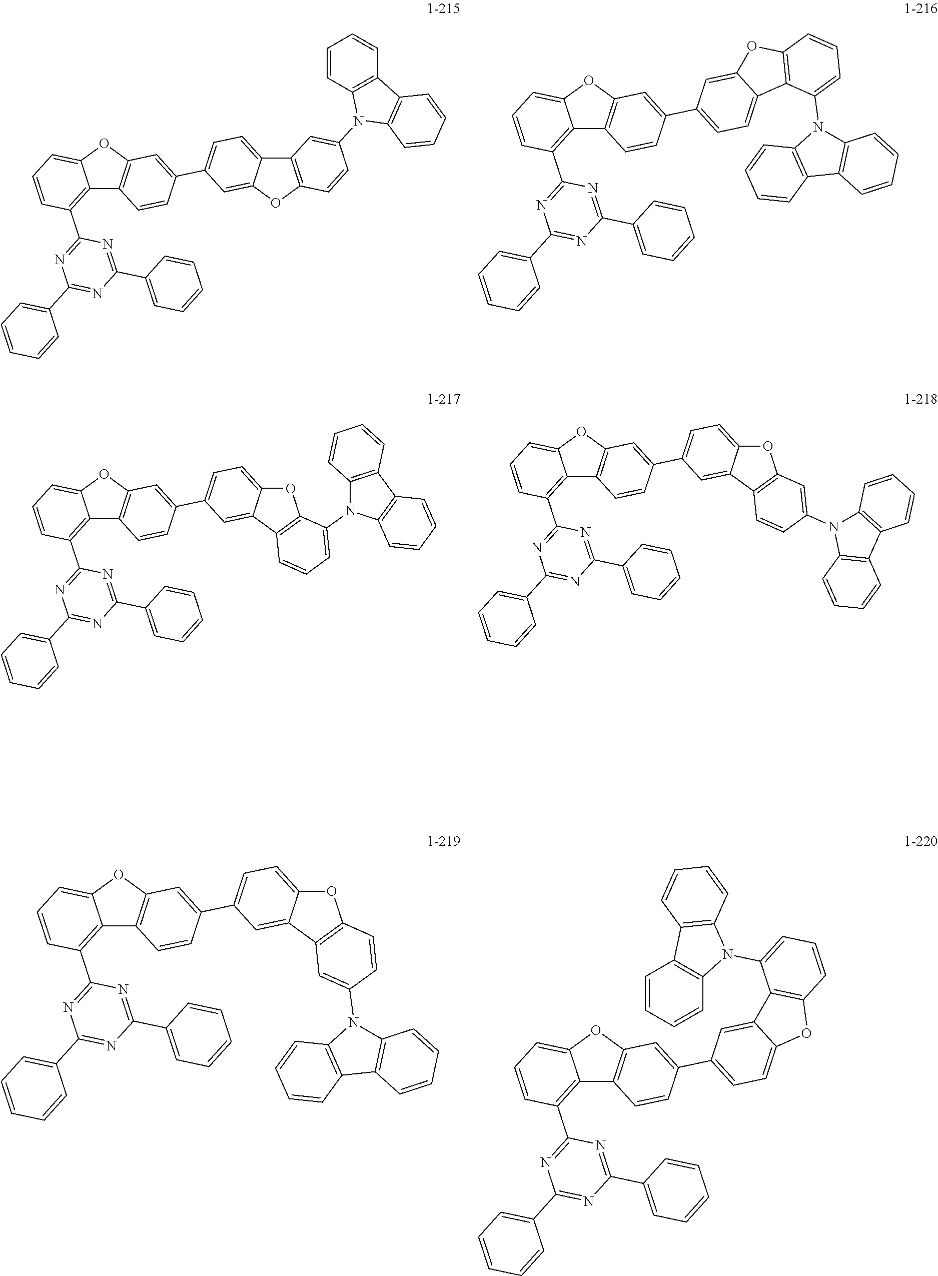

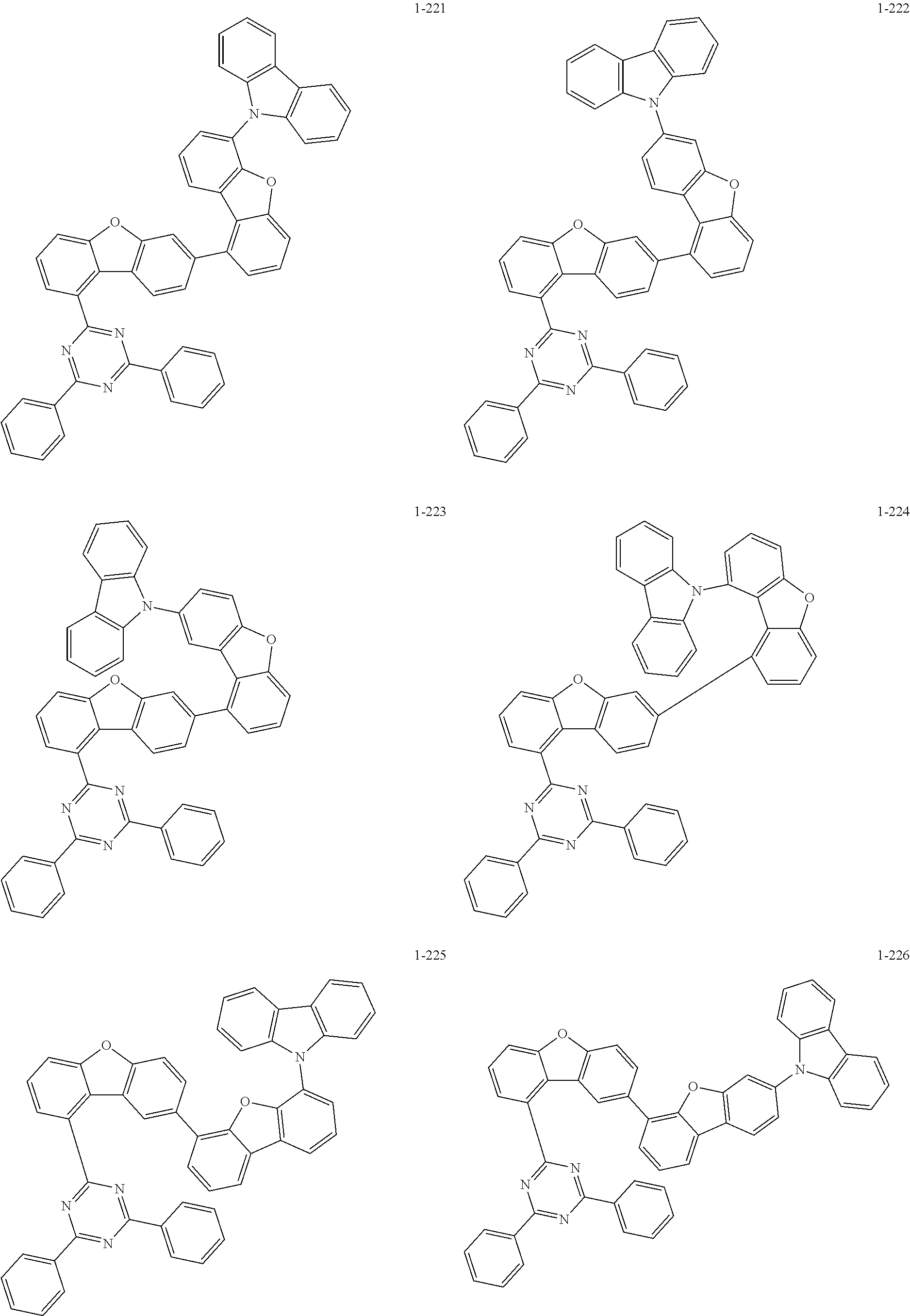

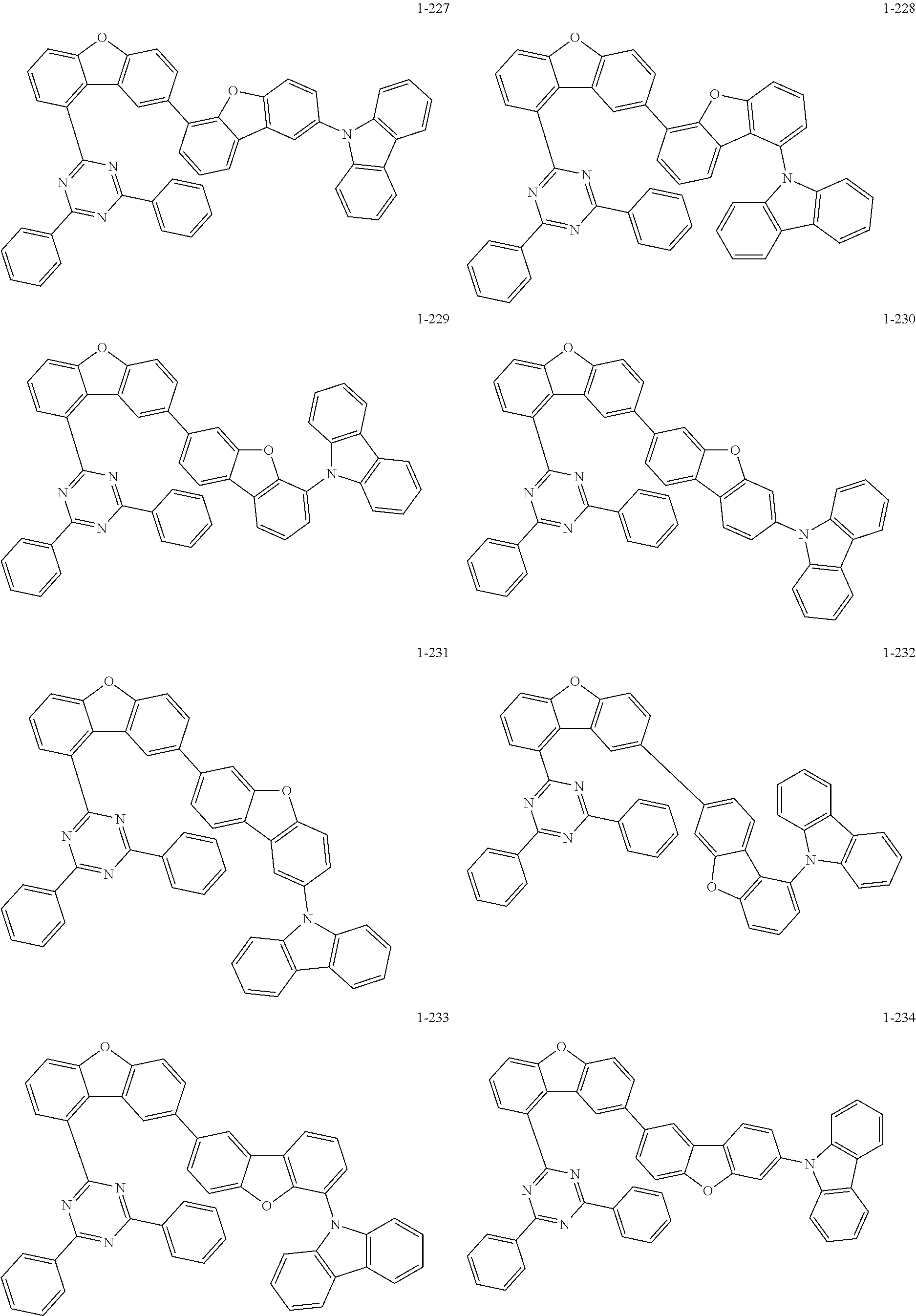

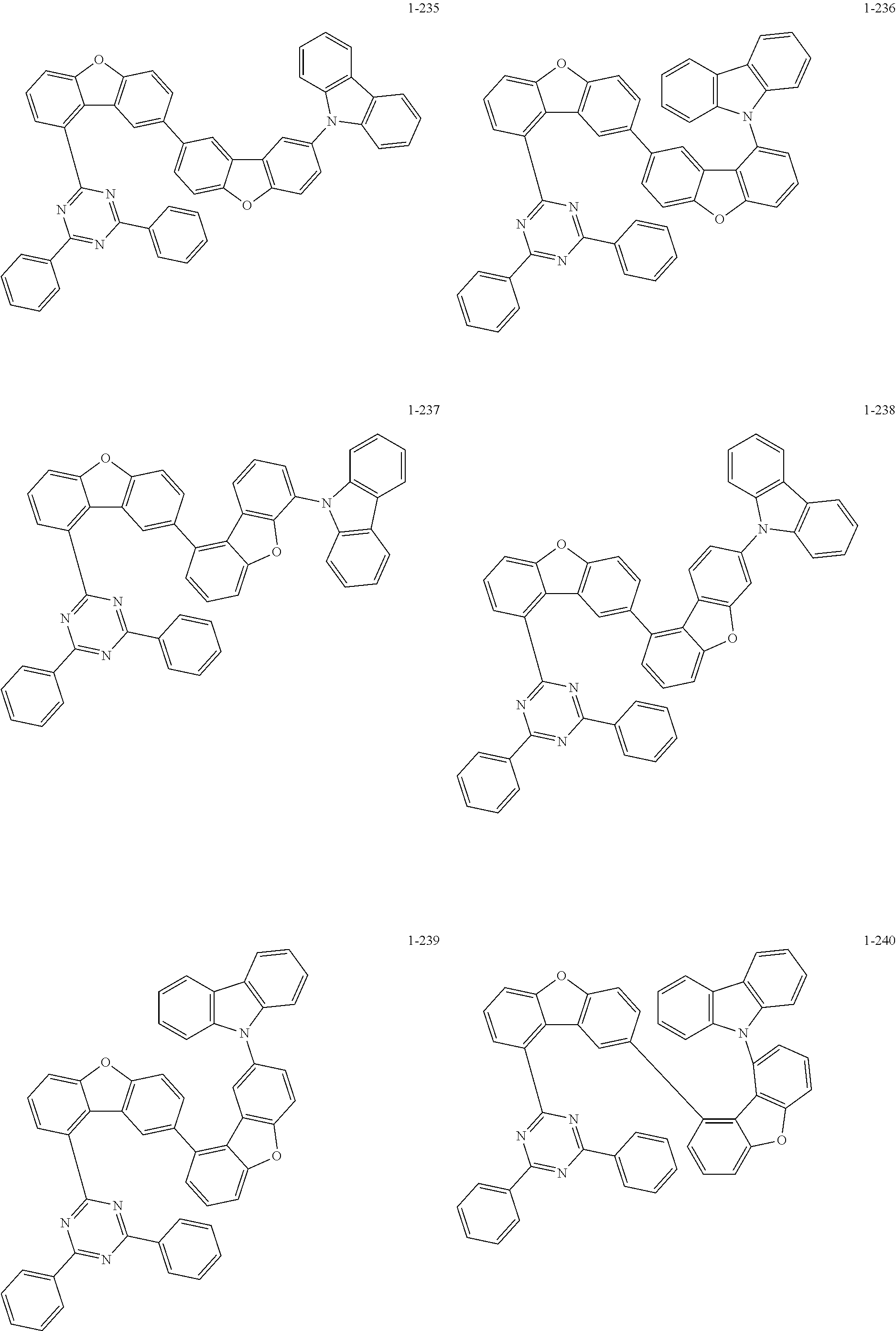

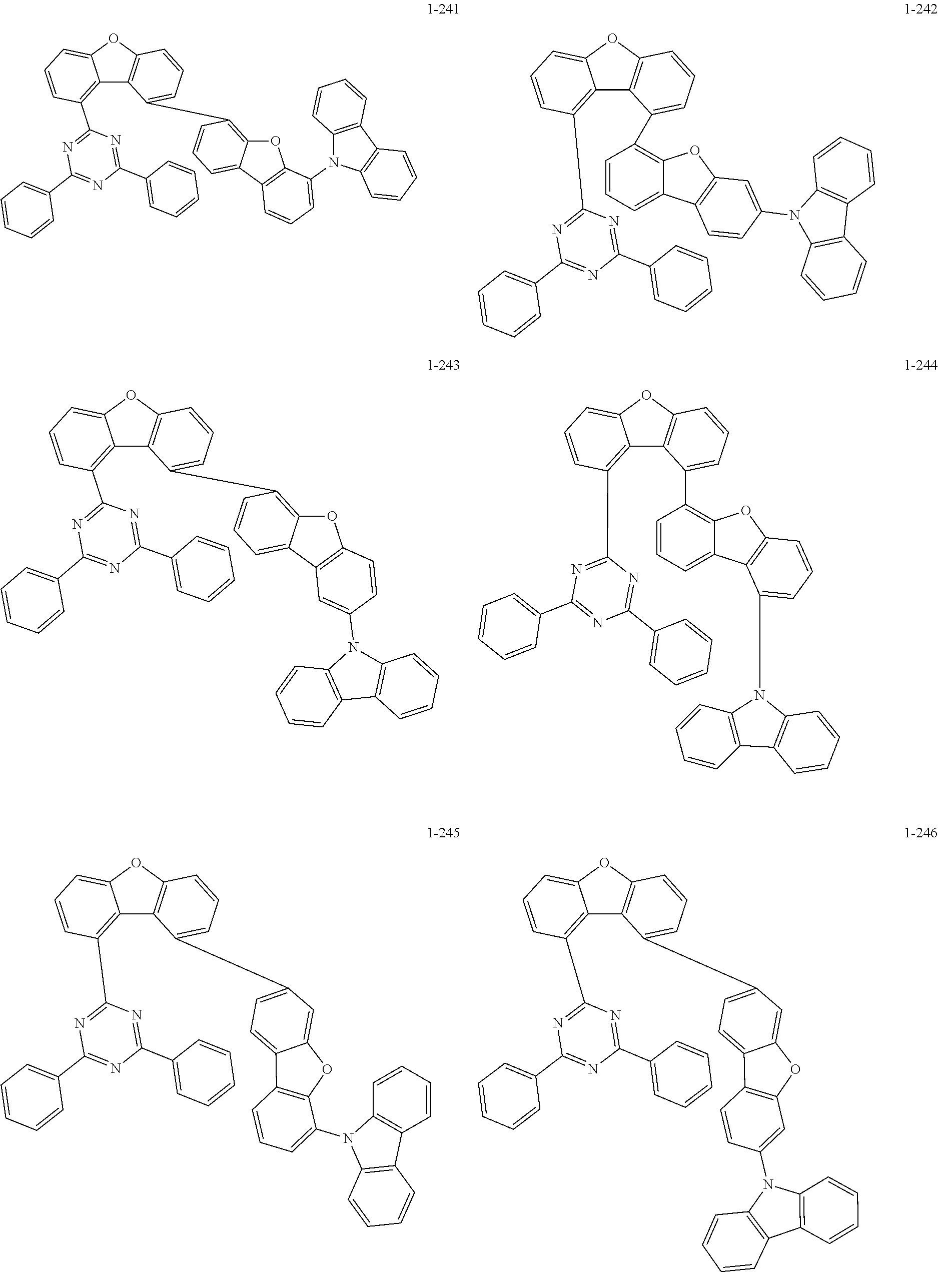

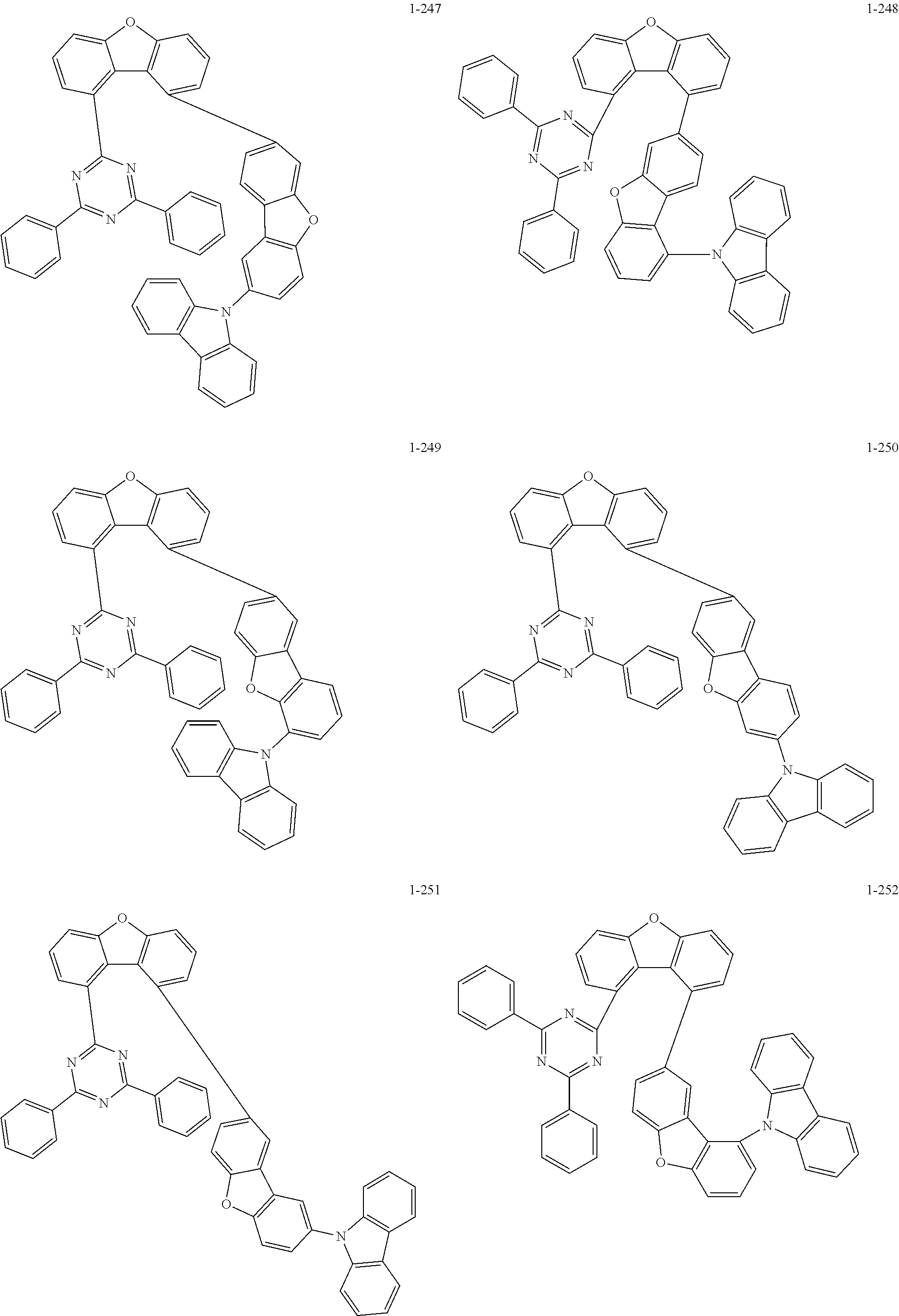

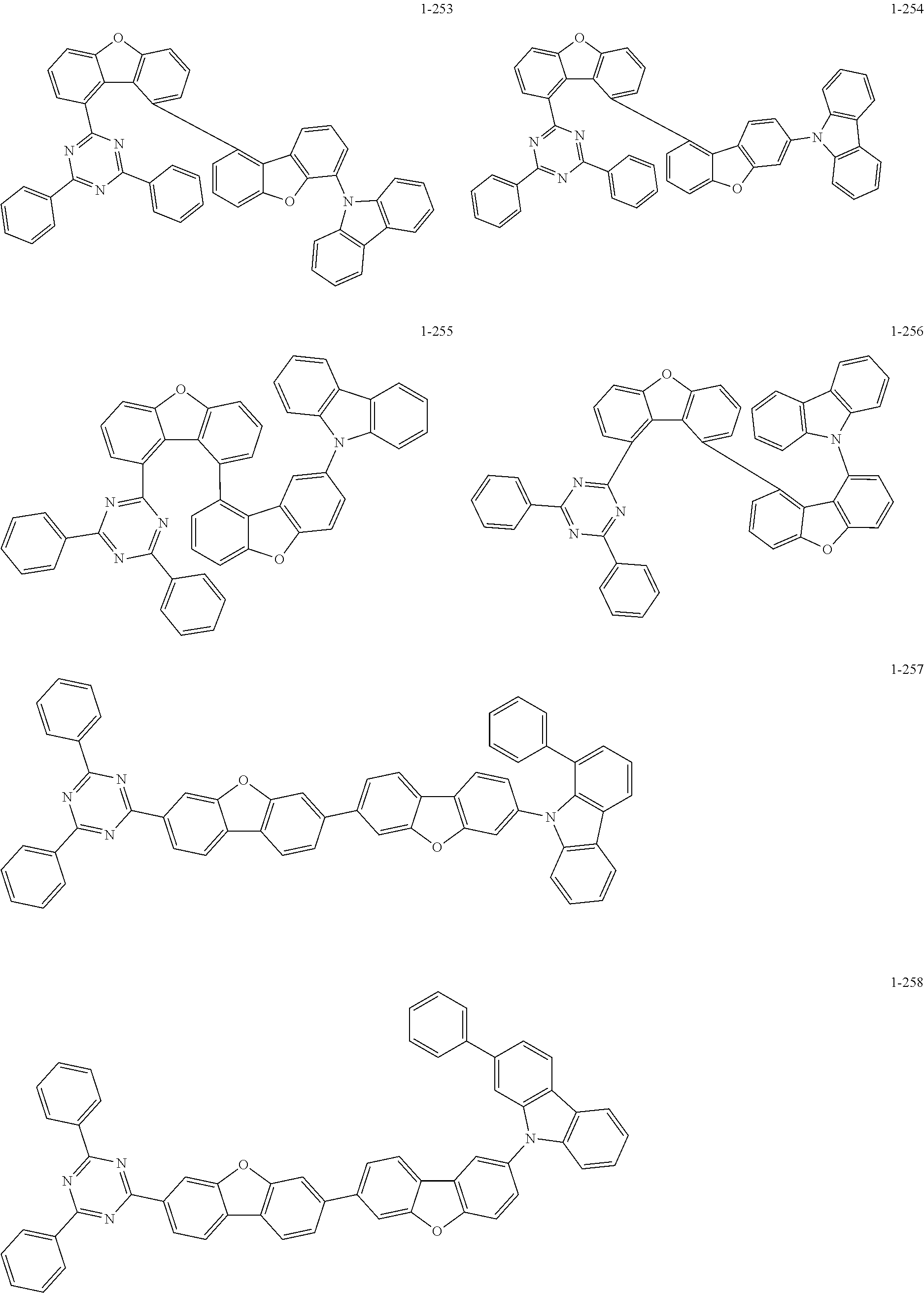

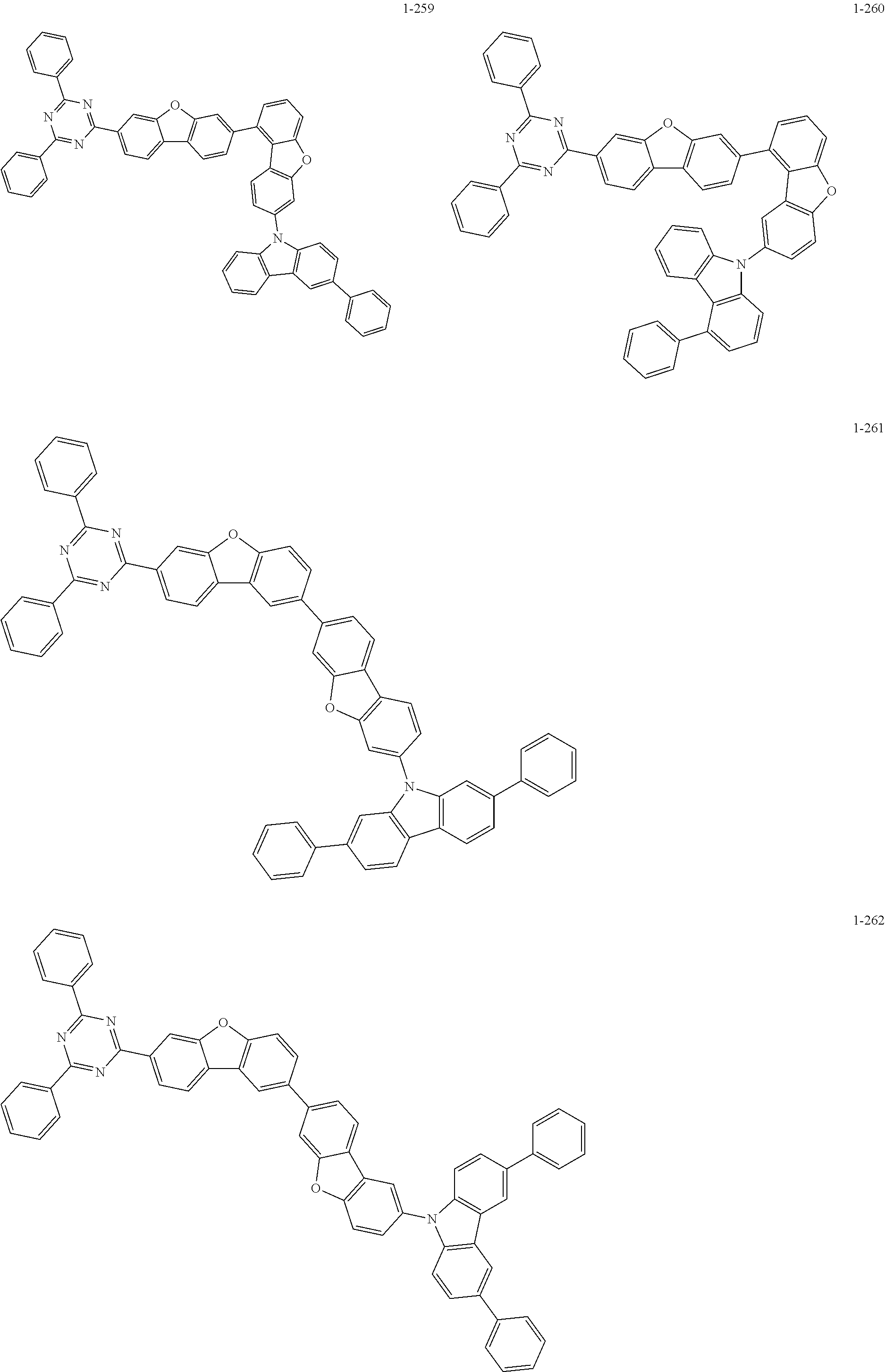 [SMILES: c1ccc(-c2ccc3c(c2)c2ccccc2n3-c2ccc3c(c2)oc2cccc(-c4ccc5c(c4)oc4cc(-c6nc(-c7ccccc7)nc(-c7ccccc7)n6)ccc45)c23)cc1 ; c1ccc(-c2nc(-c3ccccc3)nc(-c3ccc4c(c3)oc3cc(-c5cccc6oc7ccc(-n8c9ccccc9c9c(-c%10ccccc%10)cccc98)cc7c56)ccc34)n2)cc1 ; c1ccc(-c2ccc3c4ccc(-c5ccccc5)cc4n(-c4ccc5c(c4)oc4cc(-c6ccc7oc8cc(-c9nc(-c%10ccccc%10)nc(-c%10ccccc%10)n9)ccc8c7c6)ccc45)c3c2)cc1 ; c1ccc(-c2ccc3c(c2)c2cc(-c4ccccc4)ccc2n3-c2ccc3oc4cc(-c5ccc6oc7cc(-c8nc(-c9ccccc9)nc(-c9ccccc9)n8)ccc7c6c5)ccc4c3c2)cc1]

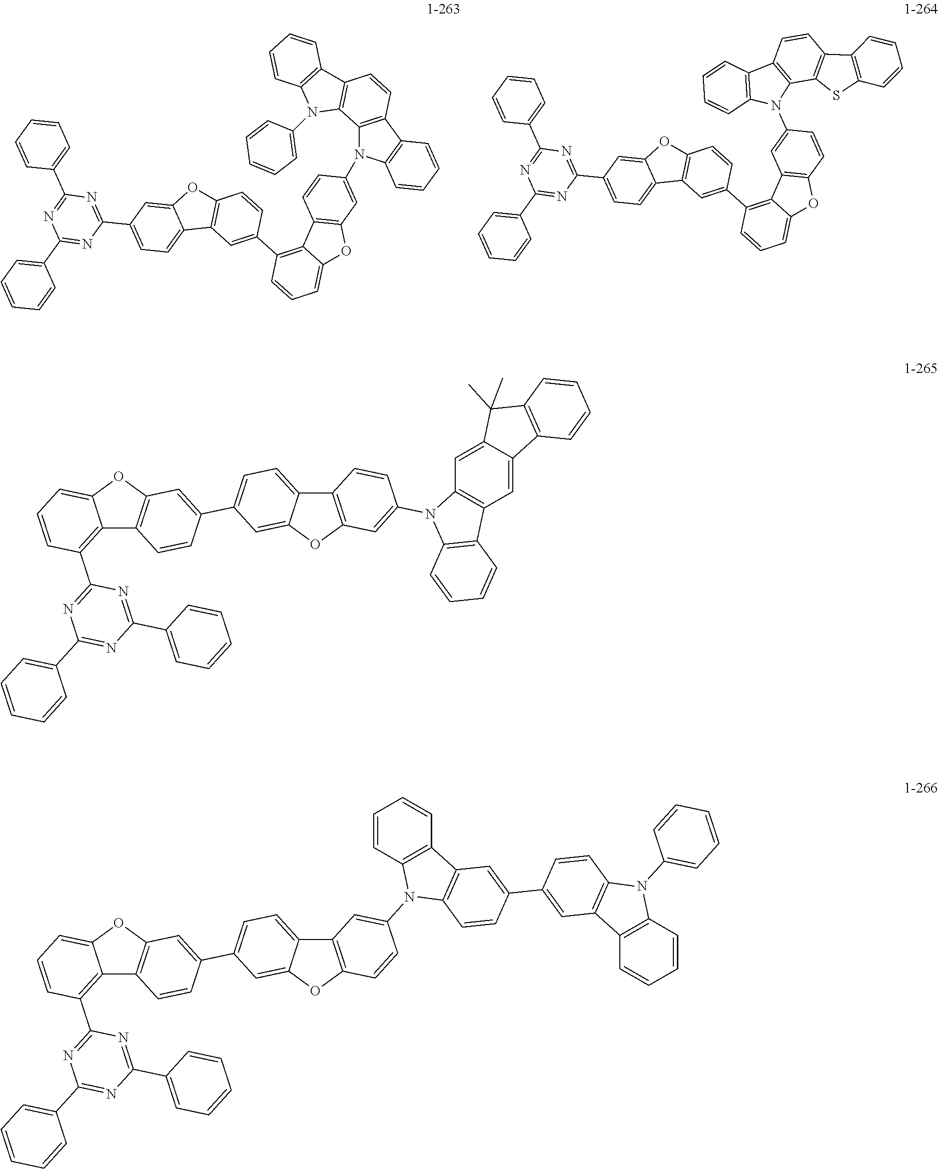

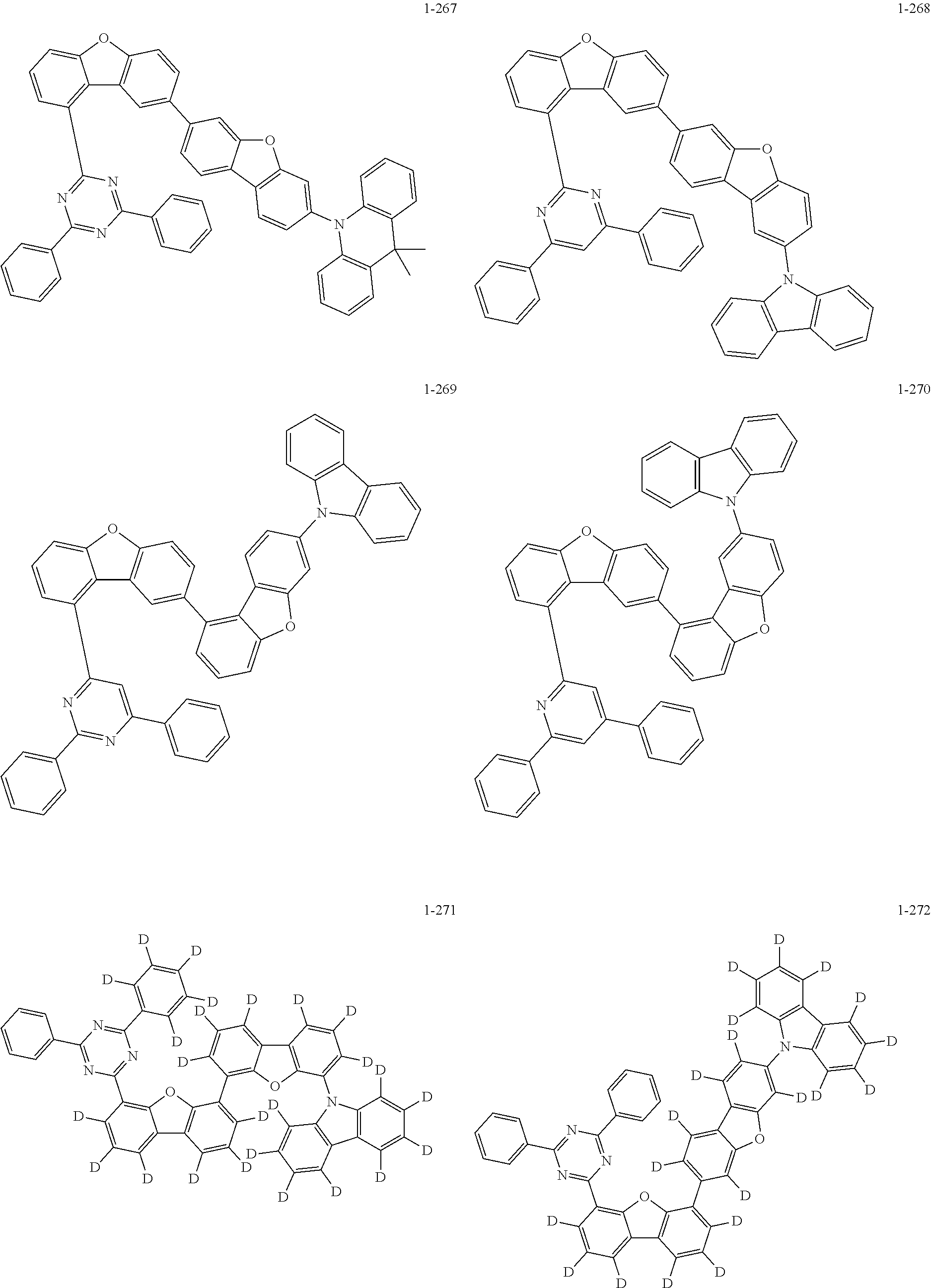

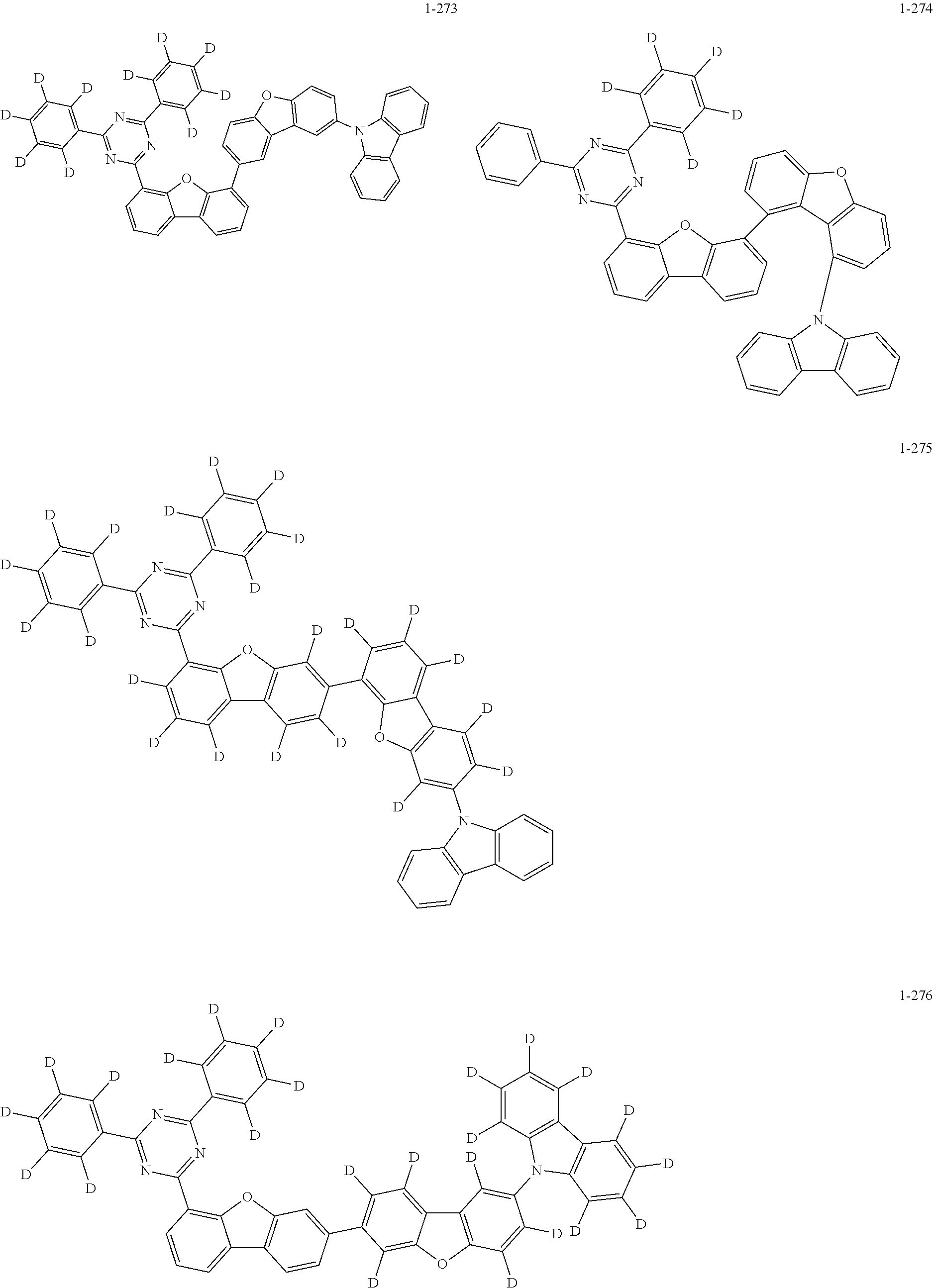

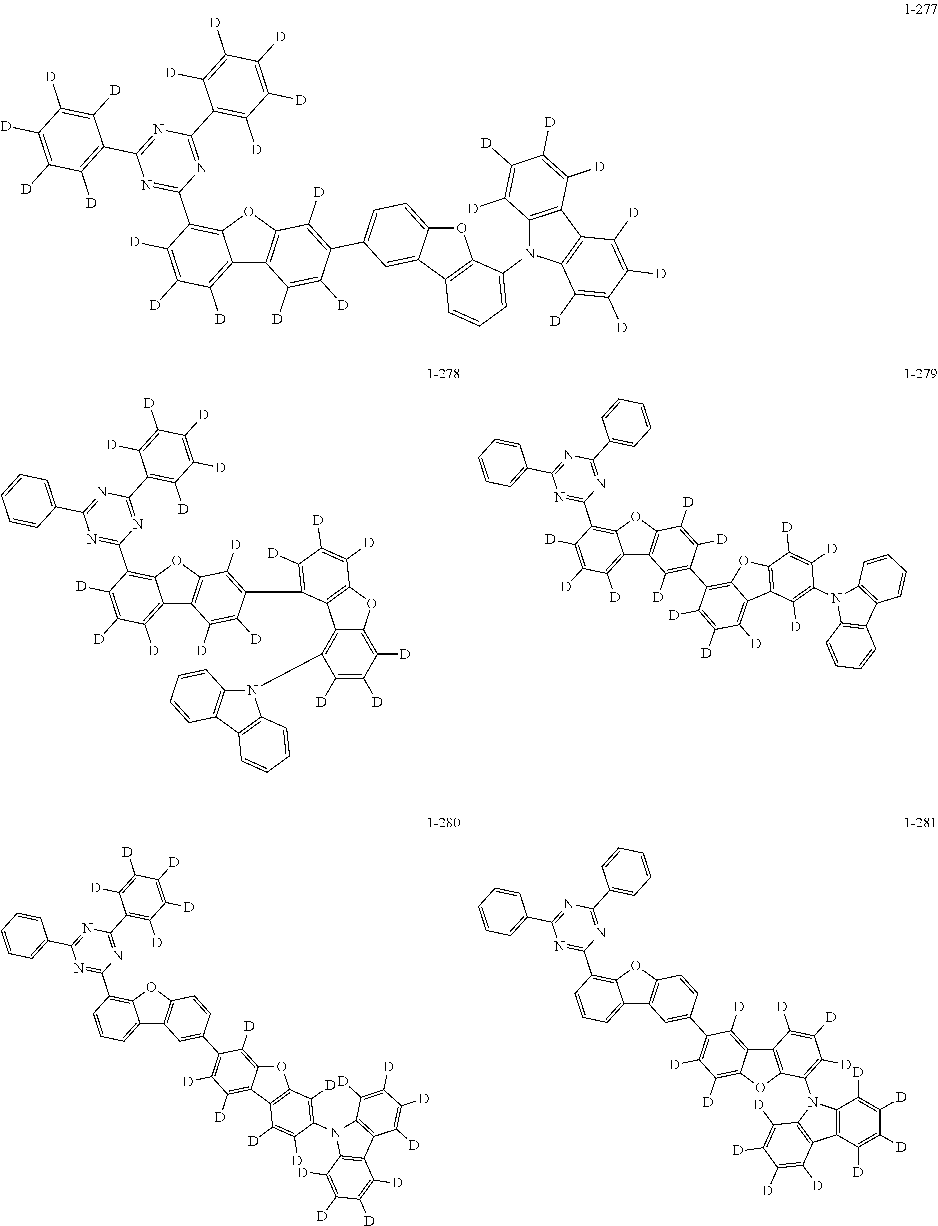

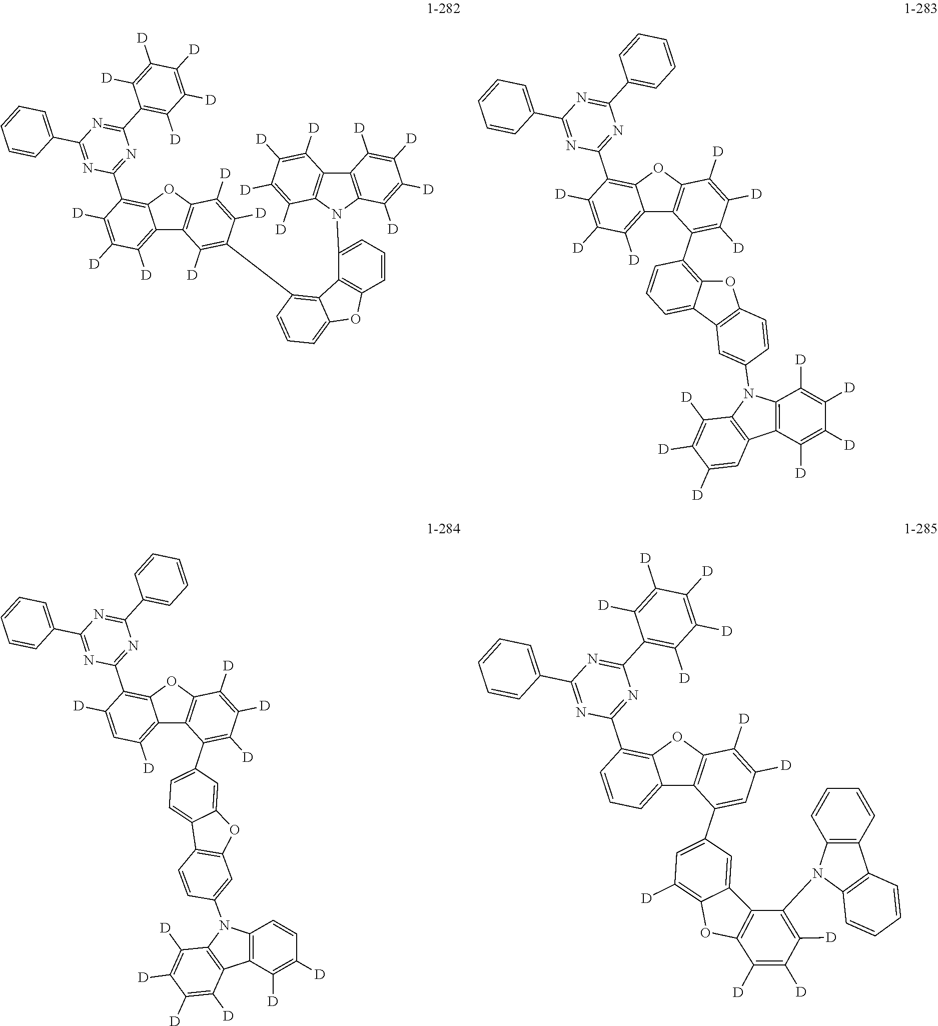

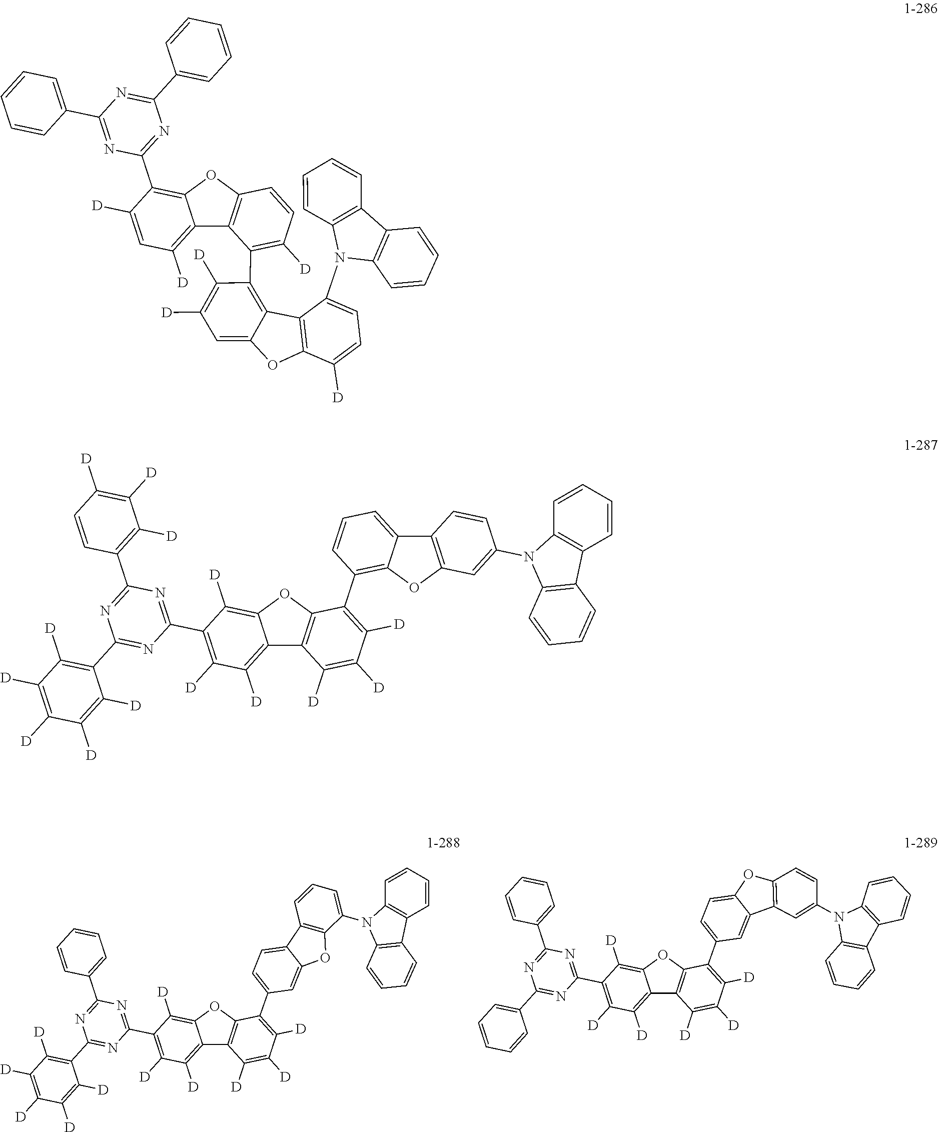

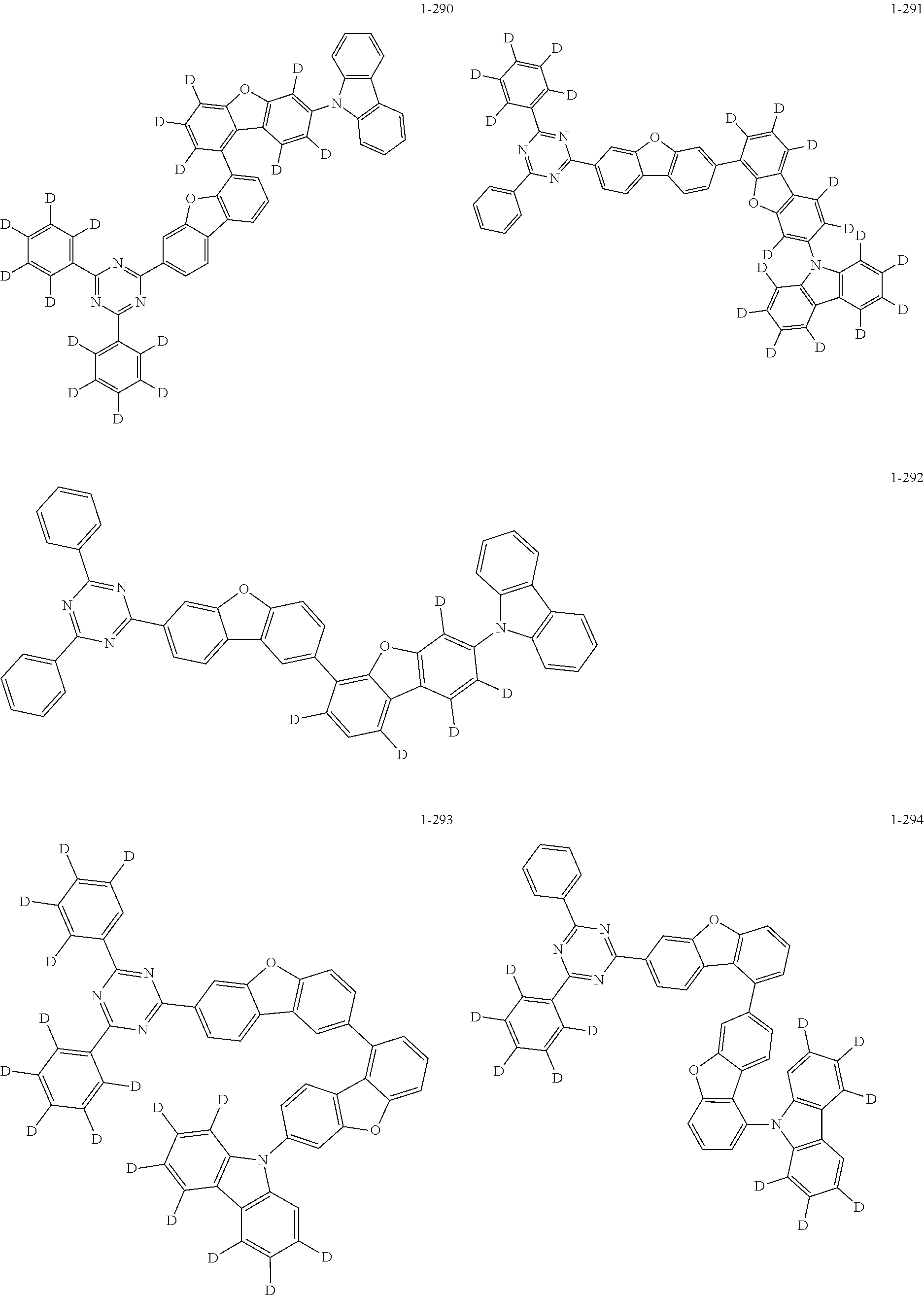

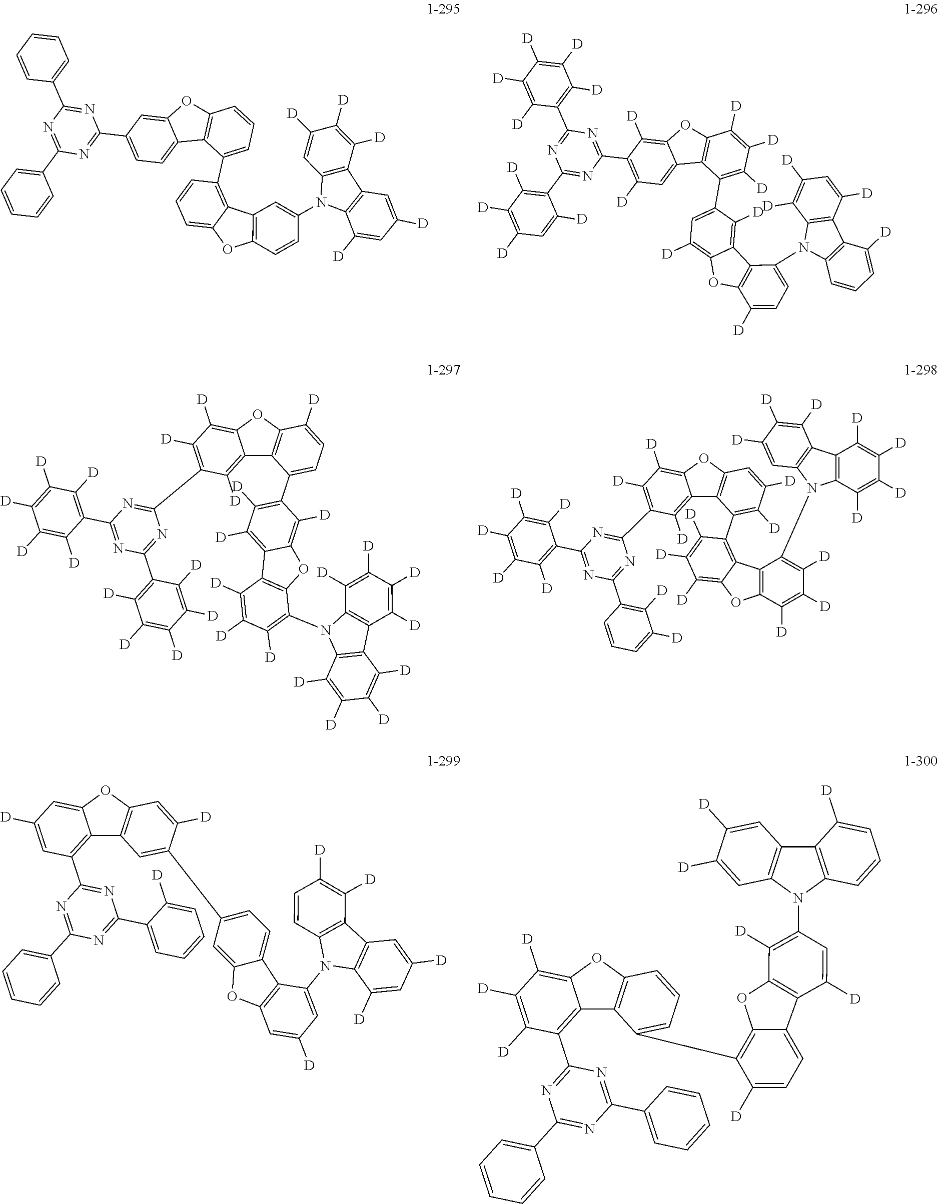

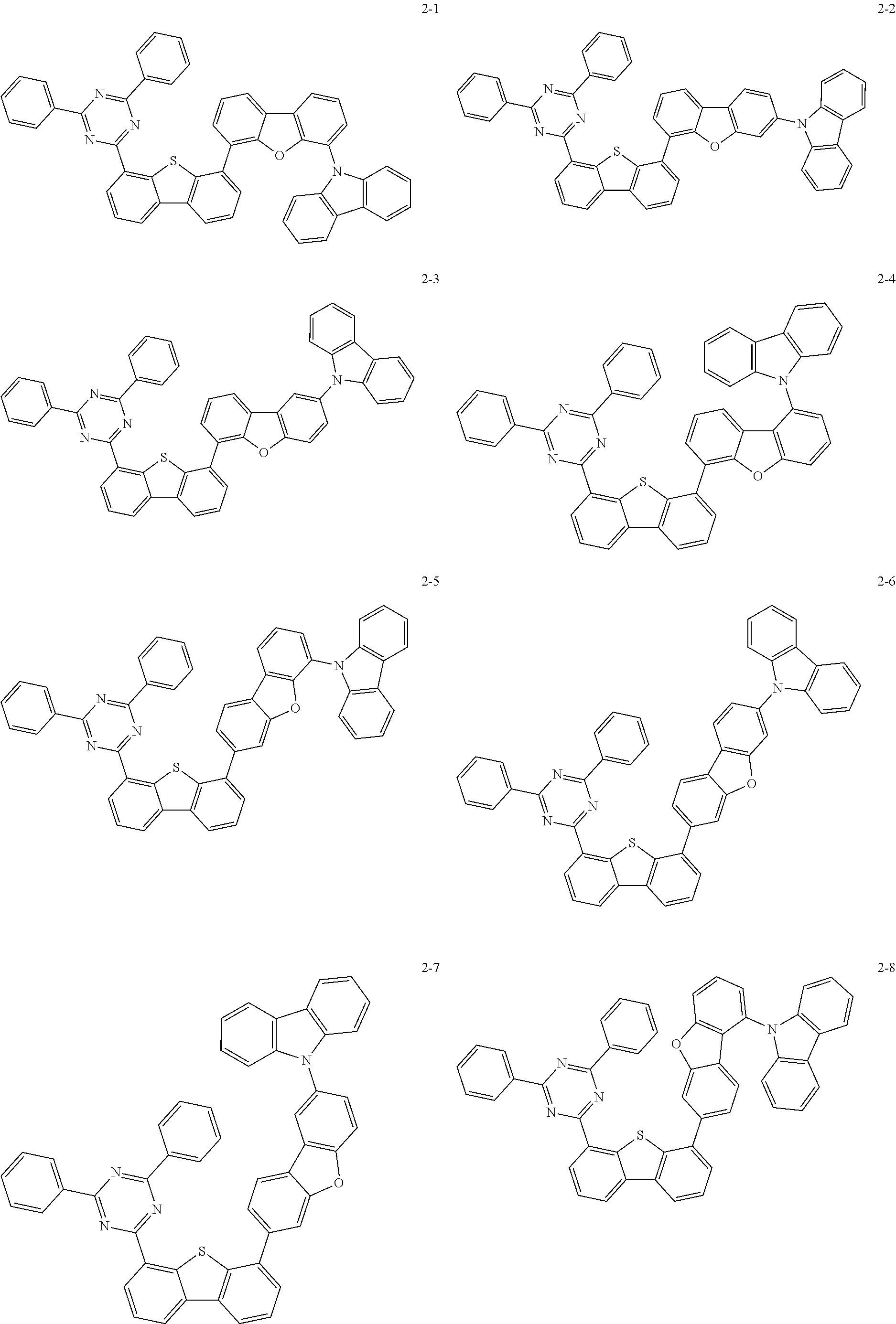

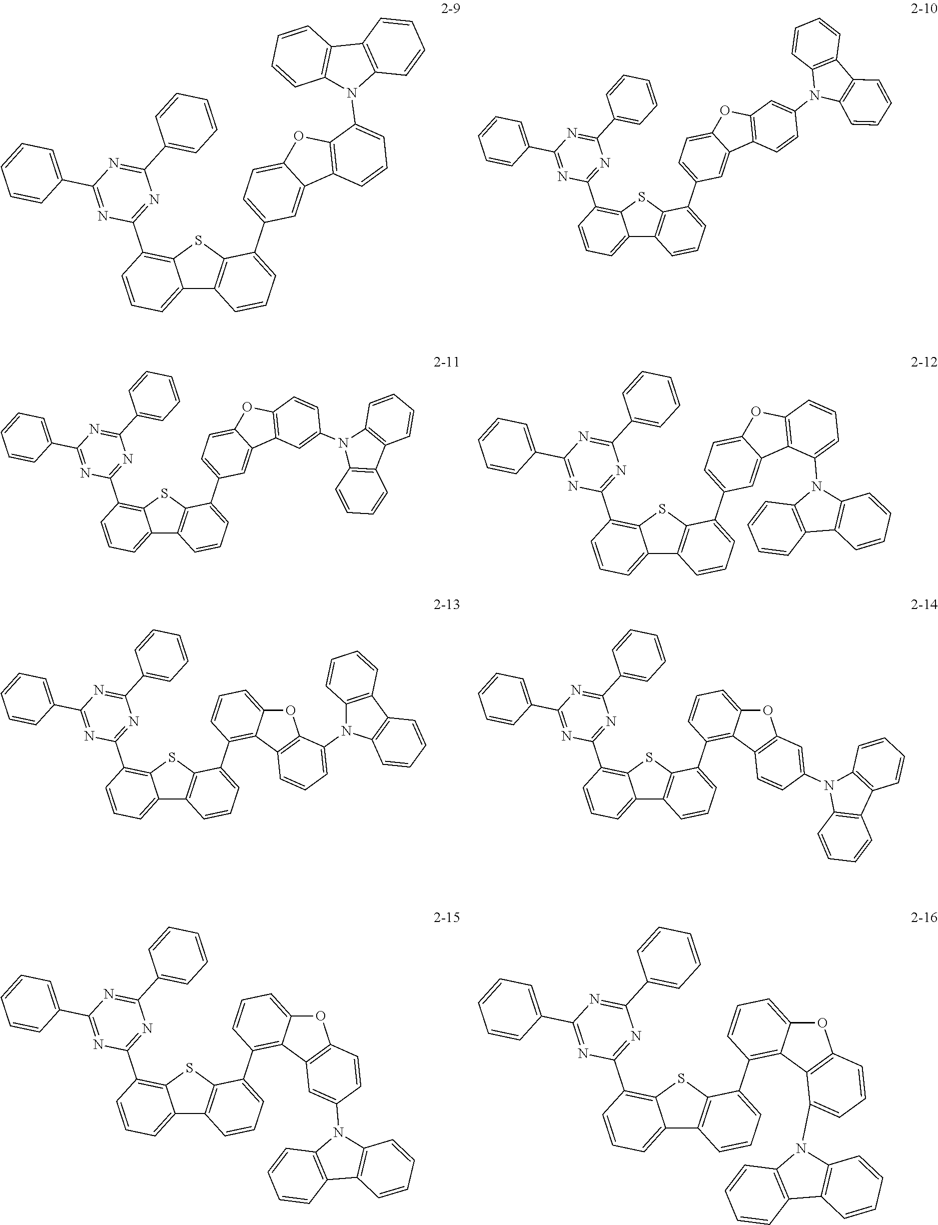

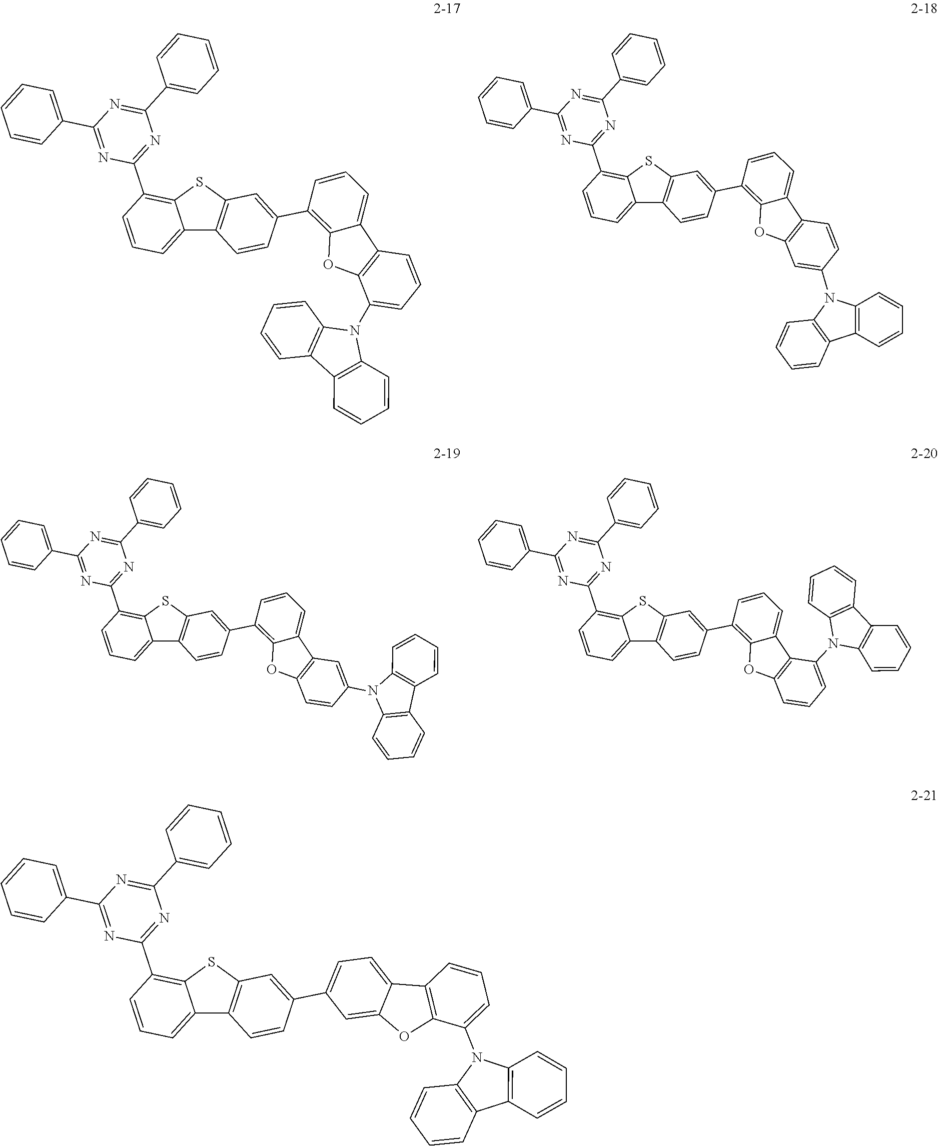 [SMILES: c1ccc(-c2nc(-c3ccccc3)nc(-c3cccc4c3sc3cc(-c5cccc6c5oc5c(-n7c8ccccc8c8ccccc87)cccc56)ccc34)n2)cc1 ; c1ccc(-c2nc(-c3ccccc3)nc(-c3cccc4c3sc3cc(-c5cccc6c5oc5cc(-n7c8ccccc8c8ccccc87)ccc56)ccc34)n2)cc1 ; c1ccc(-c2nc(-c3ccccc3)nc(-c3cccc4c3sc3cc(-c5cccc6c5oc5ccc(-n7c8ccccc8c8ccccc87)cc56)ccc34)n2)cc1 ; c1ccc(-c2nc(-c3ccccc3)nc(-c3cccc4c3sc3cc(-c5cccc6c5oc5cccc(-n7c8ccccc8c8ccccc87)c56)ccc34)n2)cc1 ; c1ccc(-c2nc(-c3ccccc3)nc(-c3cccc4c3sc3cc(-c5ccc6c(c5)oc5c(-n7c8ccccc8c8ccccc87)cccc56)ccc34)n2)cc1]

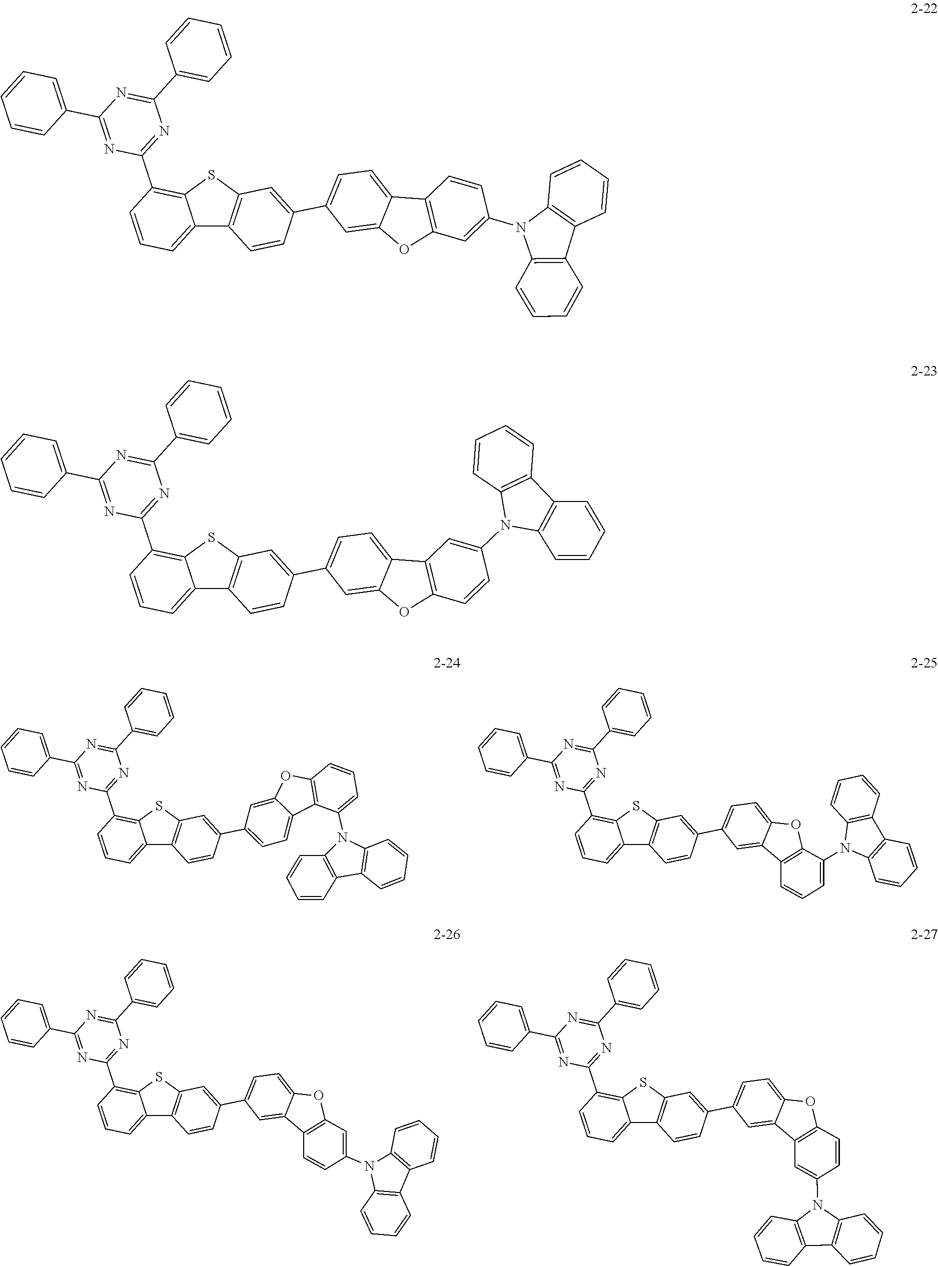

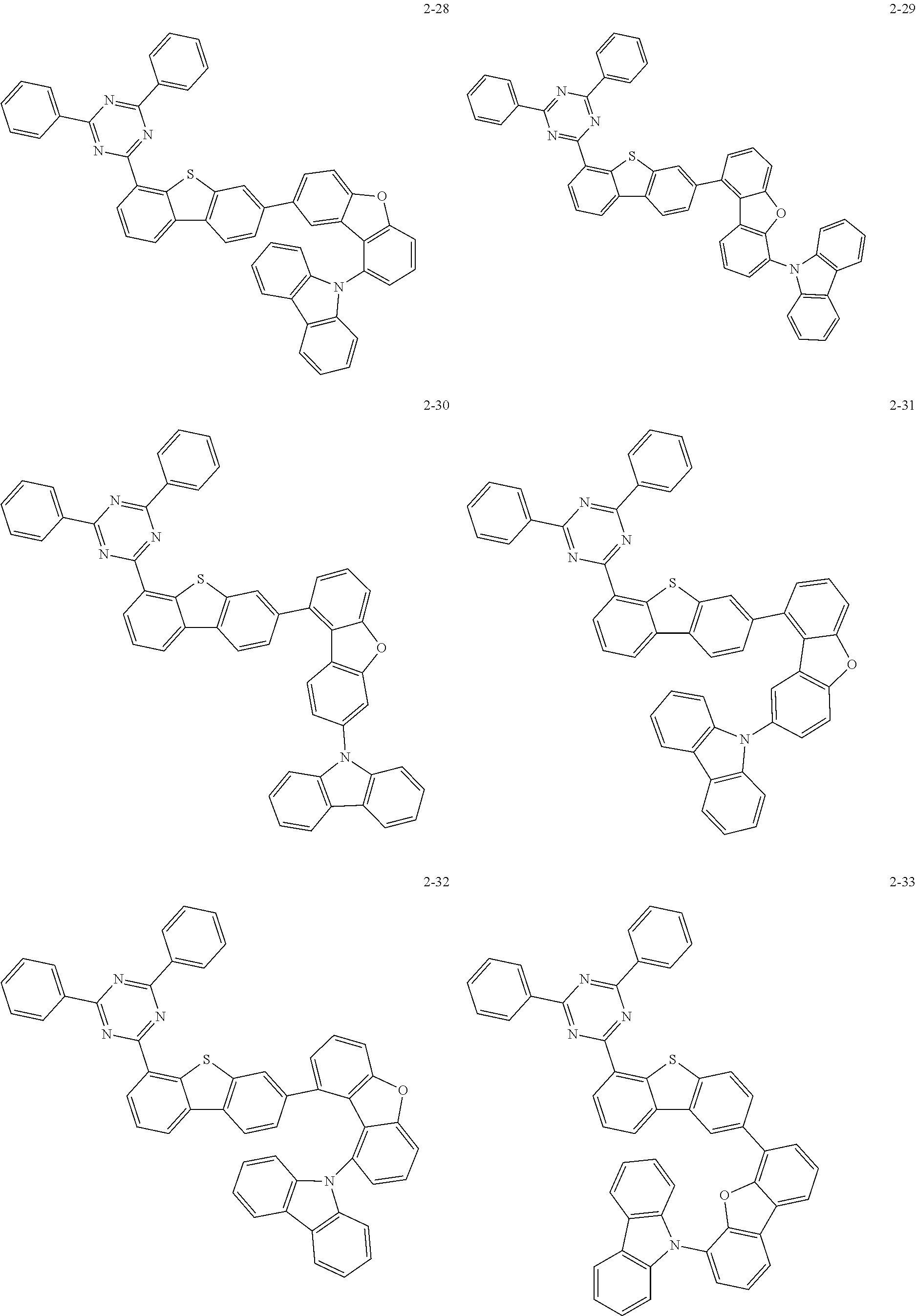

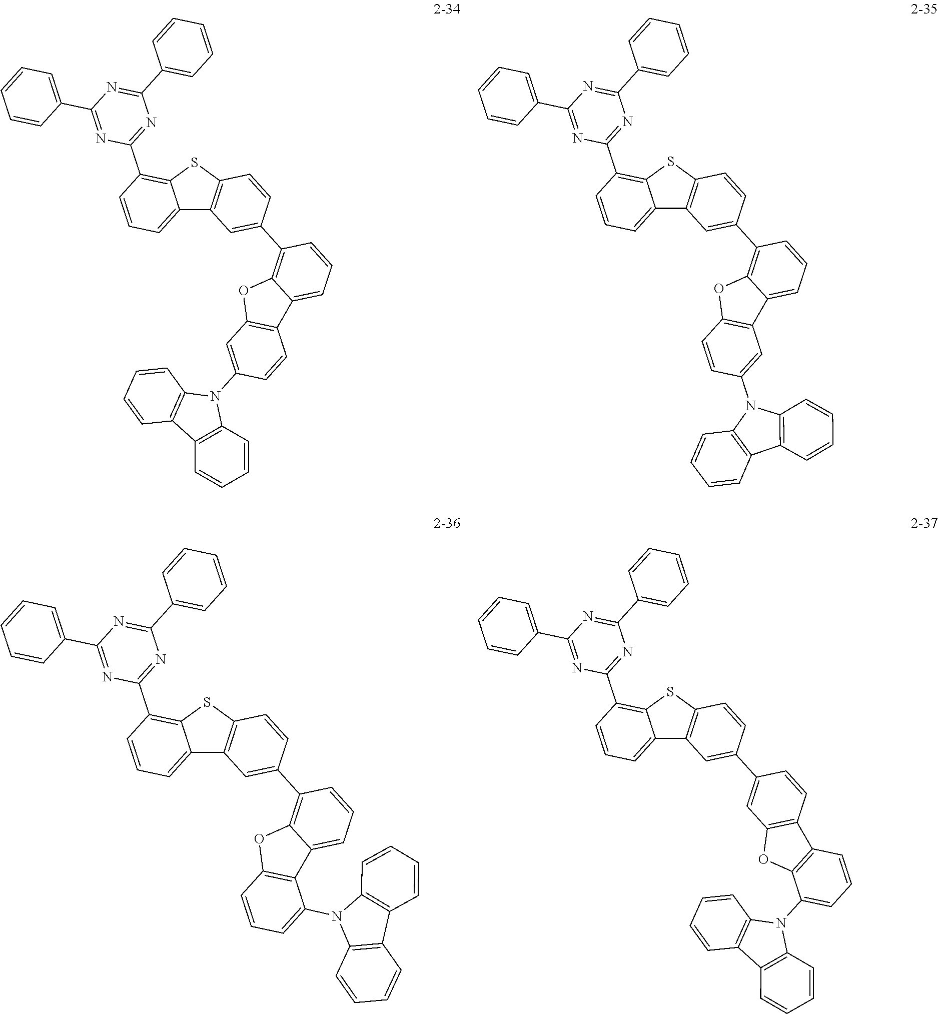 [SMILES: c1ccc(-c2nc(-c3ccccc3)nc(-c3cccc4c3sc3ccc(-c5cccc6c5oc5cc(-n7c8ccccc8c8ccccc87)ccc56)cc34)n2)cc1 ; c1ccc(-c2nc(-c3ccccc3)nc(-c3cccc4c3sc3ccc(-c5cccc6c5oc5ccc(-n7c8ccccc8c8ccccc87)cc56)cc34)n2)cc1 ; c1ccc(-c2nc(-c3ccccc3)nc(-c3cccc4c3sc3ccc(-c5cccc6c5oc5cccc(-n7c8ccccc8c8ccccc87)c56)cc34)n2)cc1 ; c1ccc(-c2nc(-c3ccccc3)nc(-c3cccc4c3sc3ccc(-c5ccc6c(c5)oc5c(-n7c8ccccc8c8ccccc87)cccc56)cc34)n2)cc1]

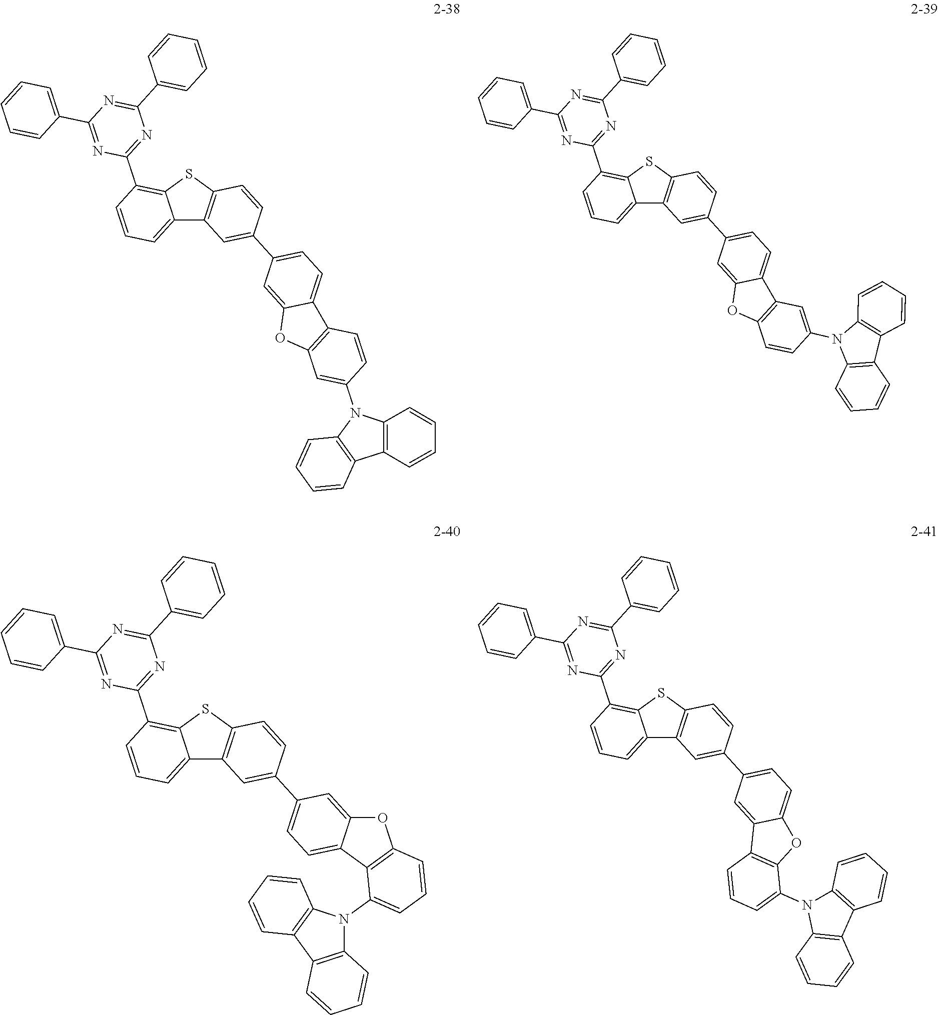 [SMILES: c1ccc(-c2nc(-c3ccccc3)nc(-c3cccc4c3sc3ccc(-c5ccc6c(c5)oc5cc(-n7c8ccccc8c8ccccc87)ccc56)cc34)n2)cc1 ; c1ccc(-c2nc(-c3ccccc3)nc(-c3cccc4c3sc3ccc(-c5ccc6c(c5)oc5ccc(-n7c8ccccc8c8ccccc87)cc56)cc34)n2)cc1 ; c1ccc(-c2nc(-c3ccccc3)nc(-c3cccc4c3sc3ccc(-c5ccc6c(c5)oc5cccc(-n7c8ccccc8c8ccccc87)c56)cc34)n2)cc1 ; c1ccc(-c2nc(-c3ccccc3)nc(-c3cccc4c3sc3ccc(-c5ccc6oc7c(-n8c9ccccc9c9ccccc98)cccc7c6c5)cc34)n2)cc1]

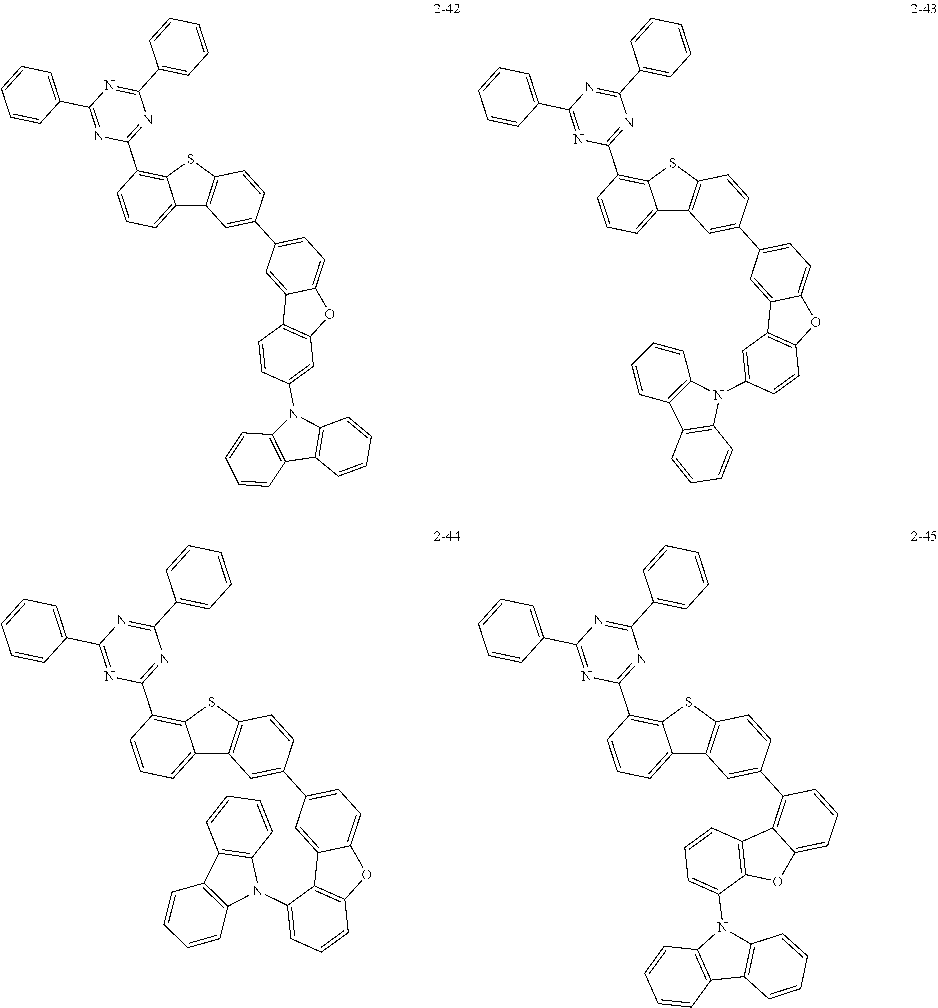 [SMILES: c1ccc(-c2nc(-c3ccccc3)nc(-c3cccc4c3sc3ccc(-c5ccc6oc7cc(-n8c9ccccc9c9ccccc98)ccc7c6c5)cc34)n2)cc1 ; c1ccc(-c2nc(-c3ccccc3)nc(-c3cccc4c3sc3ccc(-c5ccc6oc7ccc(-n8c9ccccc9c9ccccc98)cc7c6c5)cc34)n2)cc1 ; c1ccc(-c2nc(-c3ccccc3)nc(-c3cccc4c3sc3ccc(-c5ccc6oc7cccc(-n8c9ccccc9c9ccccc98)c7c6c5)cc34)n2)cc1 ; c1ccc(-c2nc(-c3ccccc3)nc(-c3cccc4c3sc3ccc(-c5cccc6oc7c(-n8c9ccccc9c9ccccc98)cccc7c56)cc34)n2)cc1]

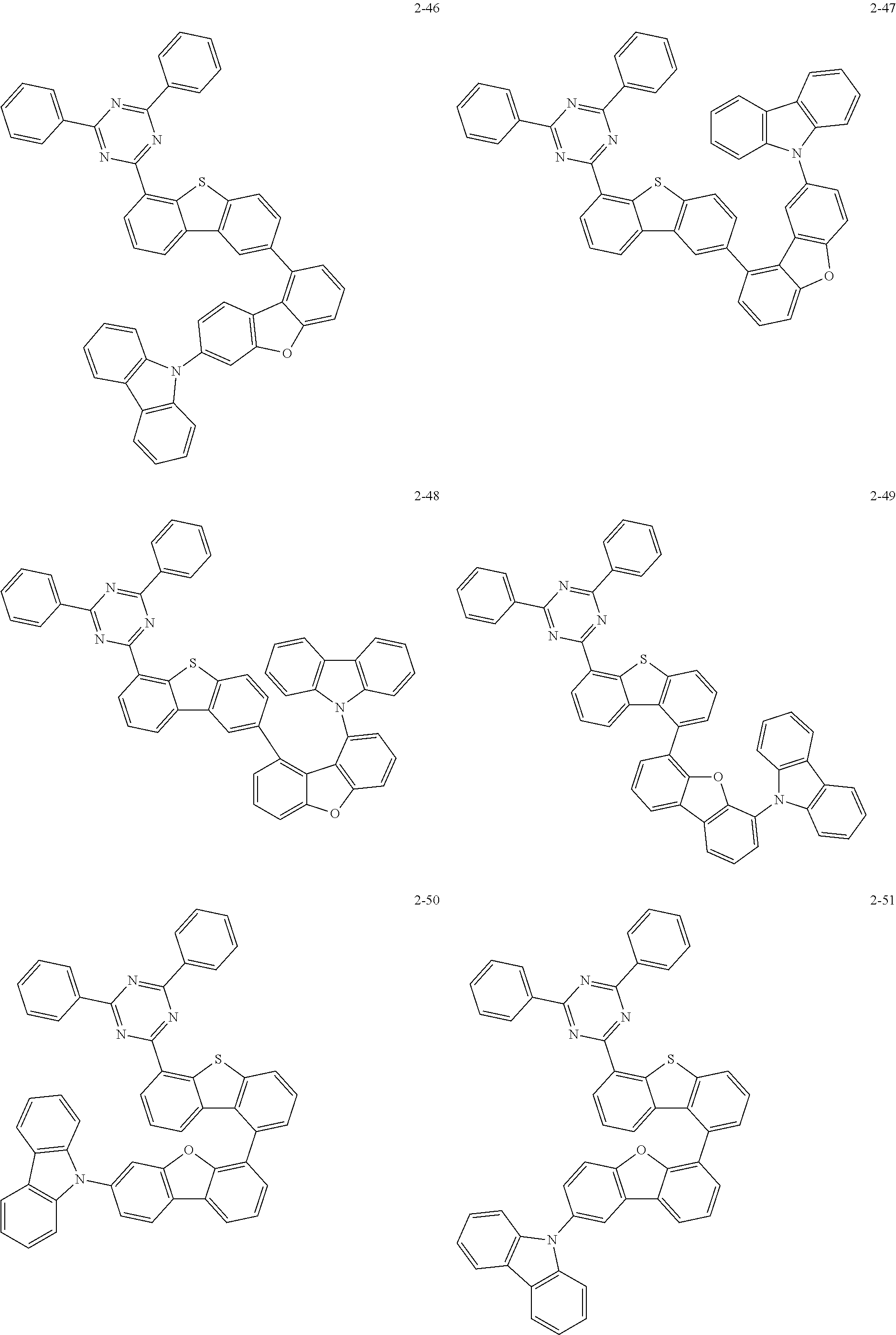

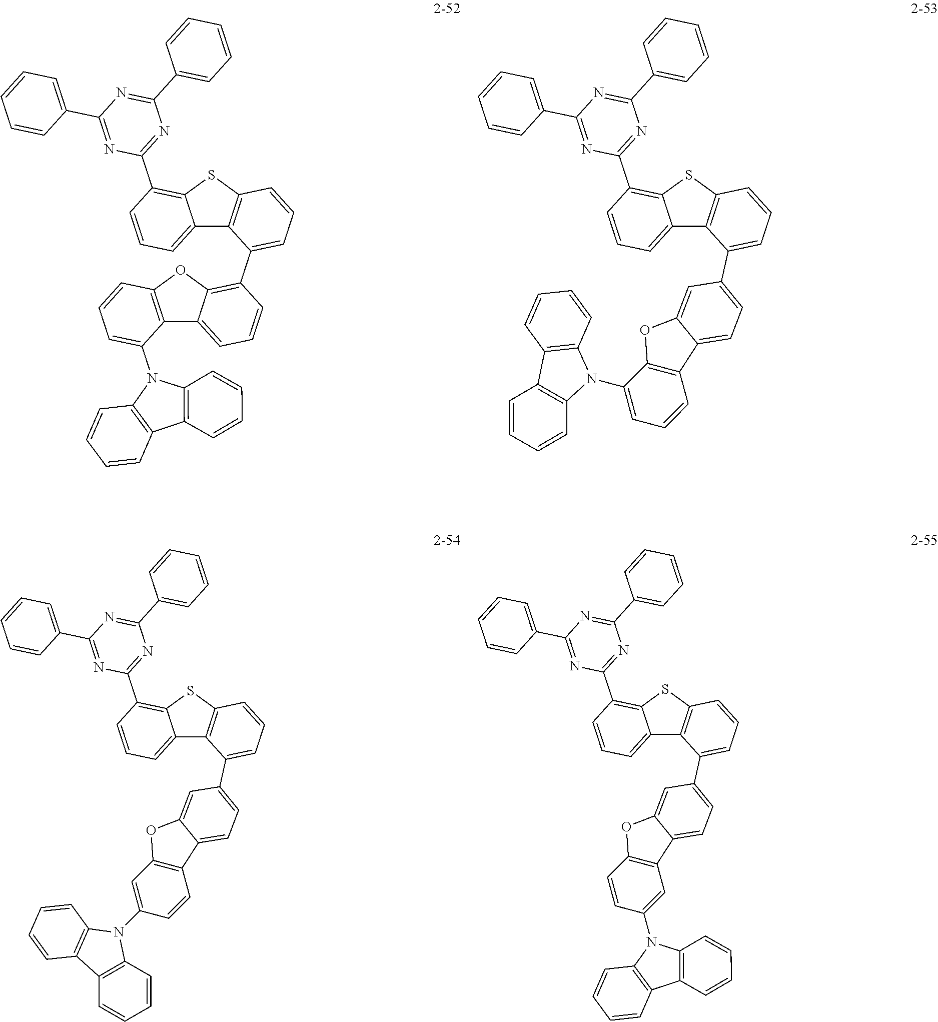

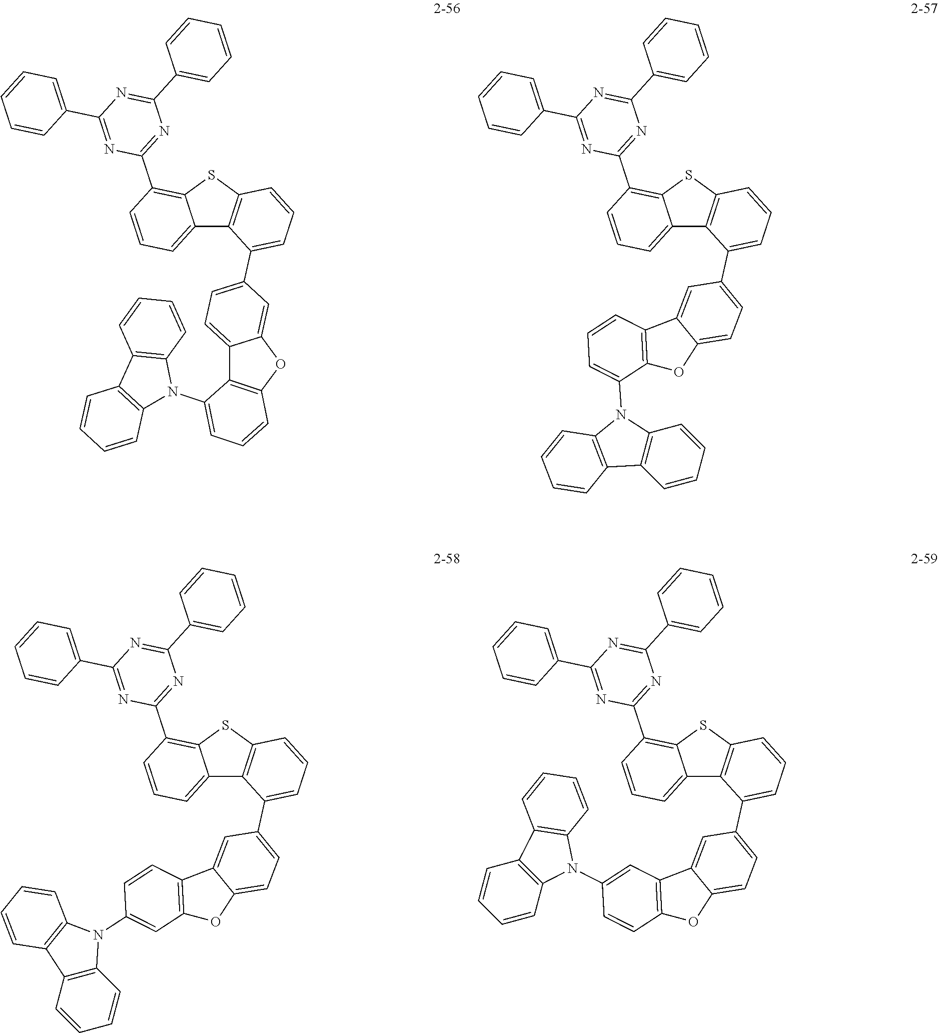

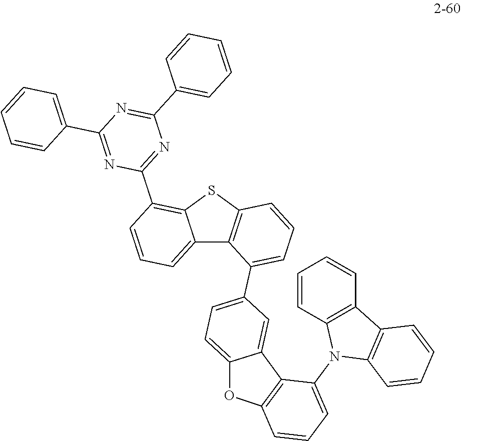

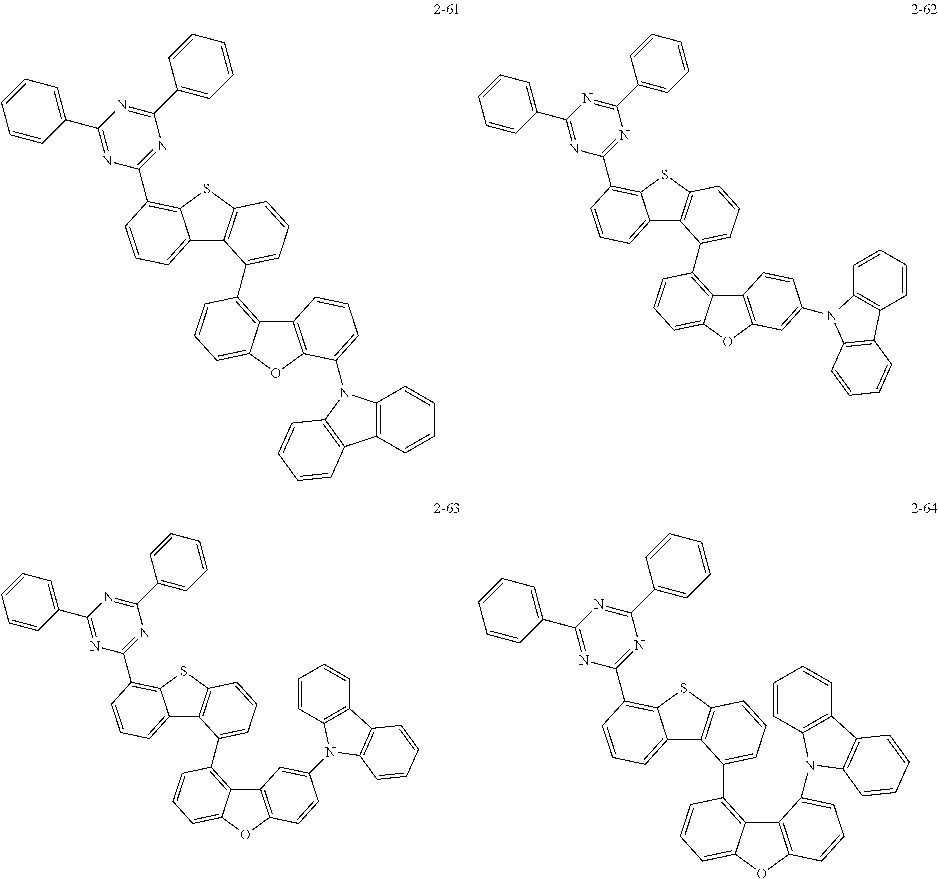 [SMILES: c1ccc(-c2nc(-c3ccccc3)nc(-c3cccc4c3sc3cccc(-c5cccc6oc7c(-n8c9ccccc9c9ccccc98)cccc7c56)c34)n2)cc1 ; c1ccc(-c2nc(-c3ccccc3)nc(-c3cccc4c3sc3cccc(-c5cccc6oc7cc(-n8c9ccccc9c9ccccc98)ccc7c56)c34)n2)cc1 ; c1ccc(-c2nc(-c3ccccc3)nc(-c3cccc4c3sc3cccc(-c5cccc6oc7ccc(-n8c9ccccc9c9ccccc98)cc7c56)c34)n2)cc1 ; c1ccc(-c2nc(-c3ccccc3)nc(-c3cccc4c3sc3cccc(-c5cccc6oc7cccc(-n8c9ccccc9c9ccccc98)c7c56)c34)n2)cc1]

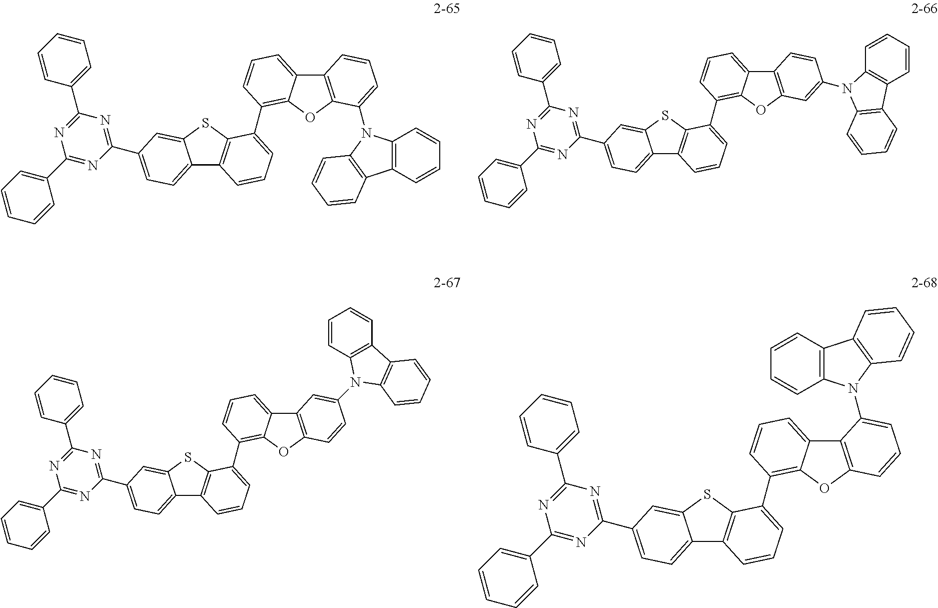 [SMILES: c1ccc(-c2nc(-c3ccccc3)nc(-c3ccc4c(c3)sc3c(-c5cccc6c5oc5c(-n7c8ccccc8c8ccccc87)cccc56)cccc34)n2)cc1 ; c1ccc(-c2nc(-c3ccccc3)nc(-c3ccc4c(c3)sc3c(-c5cccc6c5oc5cc(-n7c8ccccc8c8ccccc87)ccc56)cccc34)n2)cc1 ; c1ccc(-c2nc(-c3ccccc3)nc(-c3ccc4c(c3)sc3c(-c5cccc6c5oc5ccc(-n7c8ccccc8c8ccccc87)cc56)cccc34)n2)cc1 ; c1ccc(-c2nc(-c3ccccc3)nc(-c3ccc4c(c3)sc3c(-c5cccc6c5oc5cccc(-n7c8ccccc8c8ccccc87)c56)cccc34)n2)cc1]

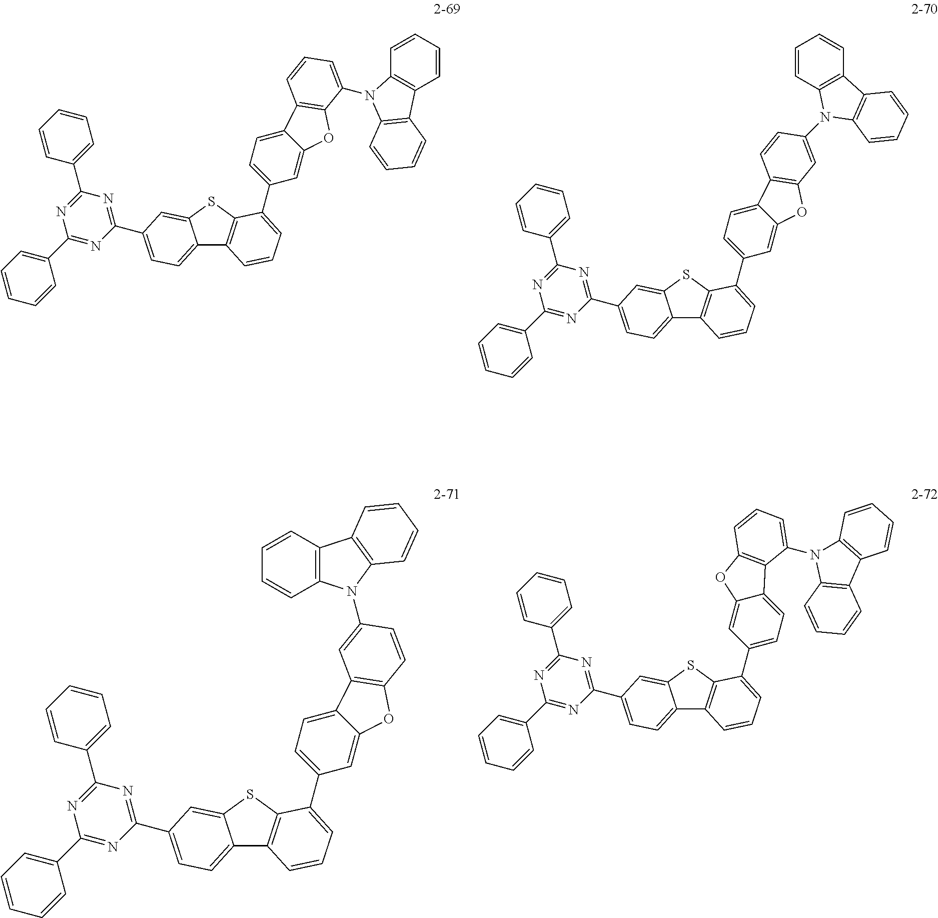 [SMILES: c1ccc(-c2nc(-c3ccccc3)nc(-c3ccc4c(c3)sc3c(-c5ccc6c(c5)oc5c(-n7c8ccccc8c8ccccc87)cccc56)cccc34)n2)cc1 ; c1ccc(-c2nc(-c3ccccc3)nc(-c3ccc4c(c3)sc3c(-c5ccc6c(c5)oc5cc(-n7c8ccccc8c8ccccc87)ccc56)cccc34)n2)cc1 ; c1ccc(-c2nc(-c3ccccc3)nc(-c3ccc4c(c3)sc3c(-c5ccc6c(c5)oc5ccc(-n7c8ccccc8c8ccccc87)cc56)cccc34)n2)cc1 ; c1ccc(-c2nc(-c3ccccc3)nc(-c3ccc4c(c3)sc3c(-c5ccc6c(c5)oc5cccc(-n7c8ccccc8c8ccccc87)c56)cccc34)n2)cc1]

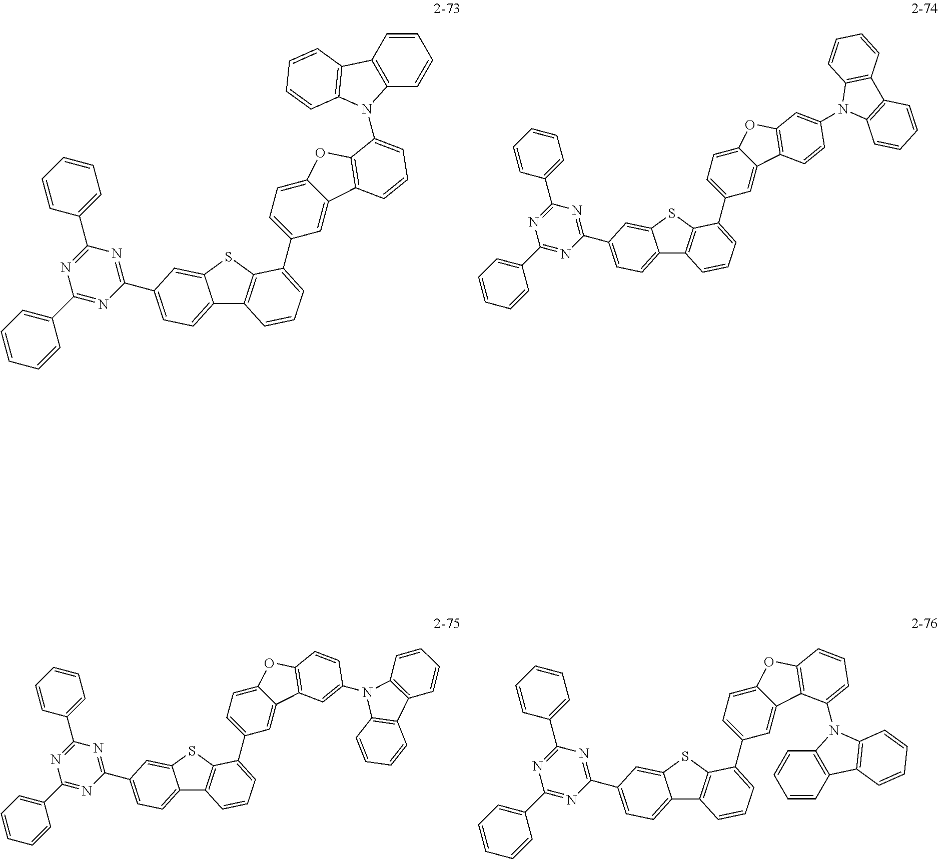 [SMILES: c1ccc(-c2nc(-c3ccccc3)nc(-c3ccc4c(c3)sc3c(-c5ccc6oc7c(-n8c9ccccc9c9ccccc98)cccc7c6c5)cccc34)n2)cc1 ; c1ccc(-c2nc(-c3ccccc3)nc(-c3ccc4c(c3)sc3c(-c5ccc6oc7cc(-n8c9ccccc9c9ccccc98)ccc7c6c5)cccc34)n2)cc1 ; c1ccc(-c2nc(-c3ccccc3)nc(-c3ccc4c(c3)sc3c(-c5ccc6oc7ccc(-n8c9ccccc9c9ccccc98)cc7c6c5)cccc34)n2)cc1 ; c1ccc(-c2nc(-c3ccccc3)nc(-c3ccc4c(c3)sc3c(-c5ccc6oc7cccc(-n8c9ccccc9c9ccccc98)c7c6c5)cccc34)n2)cc1]

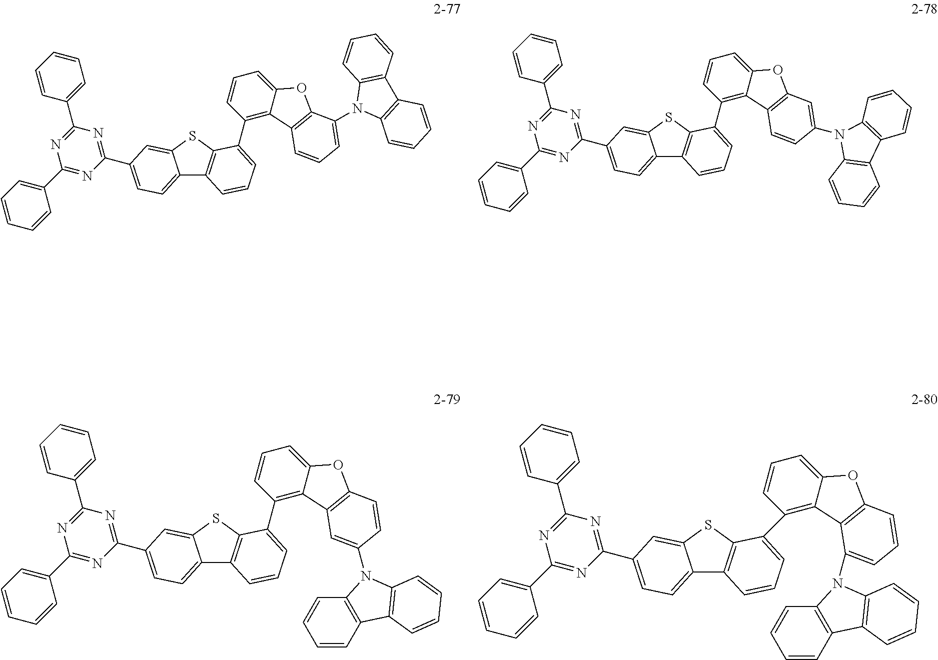

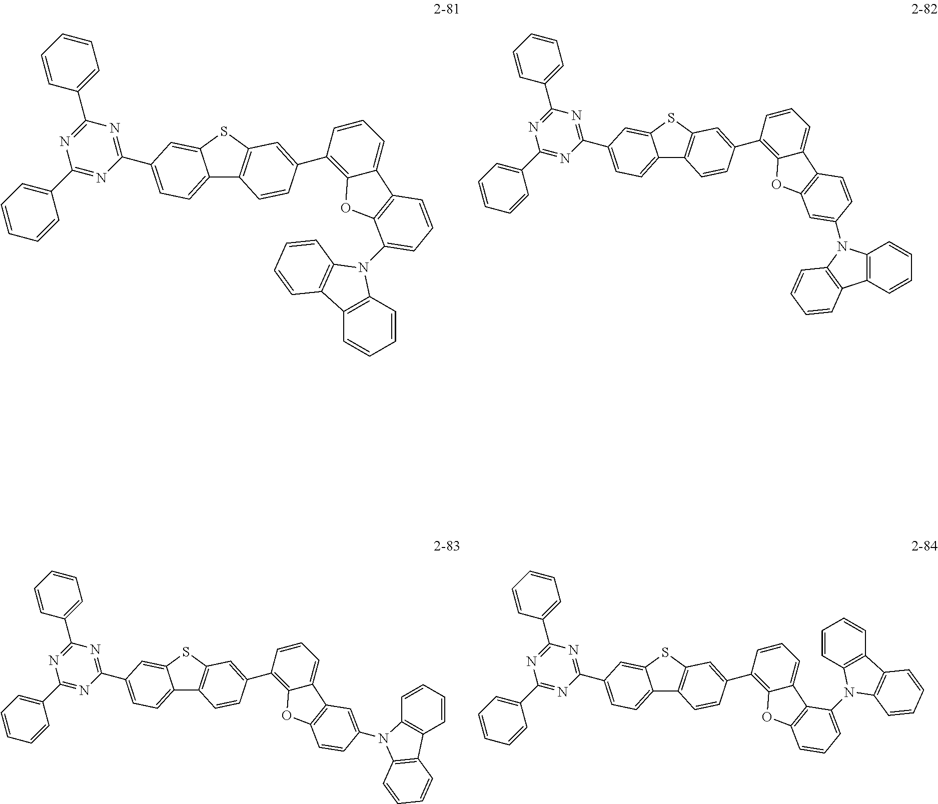

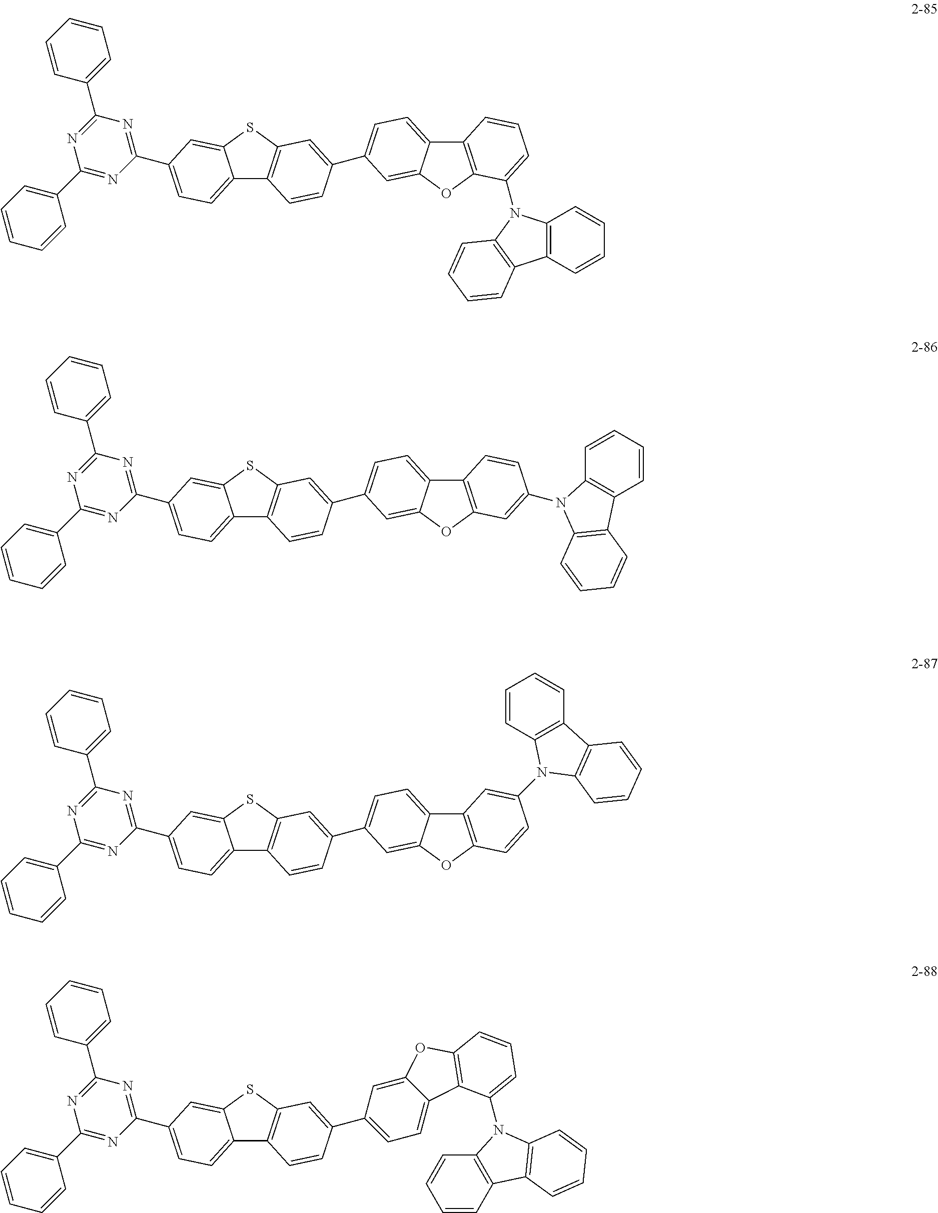 [SMILES: c1ccc(-c2nc(-c3ccccc3)nc(-c3ccc4c(c3)sc3cc(-c5ccc6c(c5)oc5c(-n7c8ccccc8c8ccccc87)cccc56)ccc34)n2)cc1 ; c1ccc(-c2nc(-c3ccccc3)nc(-c3ccc4c(c3)sc3cc(-c5ccc6c(c5)oc5cc(-n7c8ccccc8c8ccccc87)ccc56)ccc34)n2)cc1 ; c1ccc(-c2nc(-c3ccccc3)nc(-c3ccc4c(c3)sc3cc(-c5ccc6c(c5)oc5ccc(-n7c8ccccc8c8ccccc87)cc56)ccc34)n2)cc1 ; c1ccc(-c2nc(-c3ccccc3)nc(-c3ccc4c(c3)sc3cc(-c5ccc6c(c5)oc5cccc(-n7c8ccccc8c8ccccc87)c56)ccc34)n2)cc1]

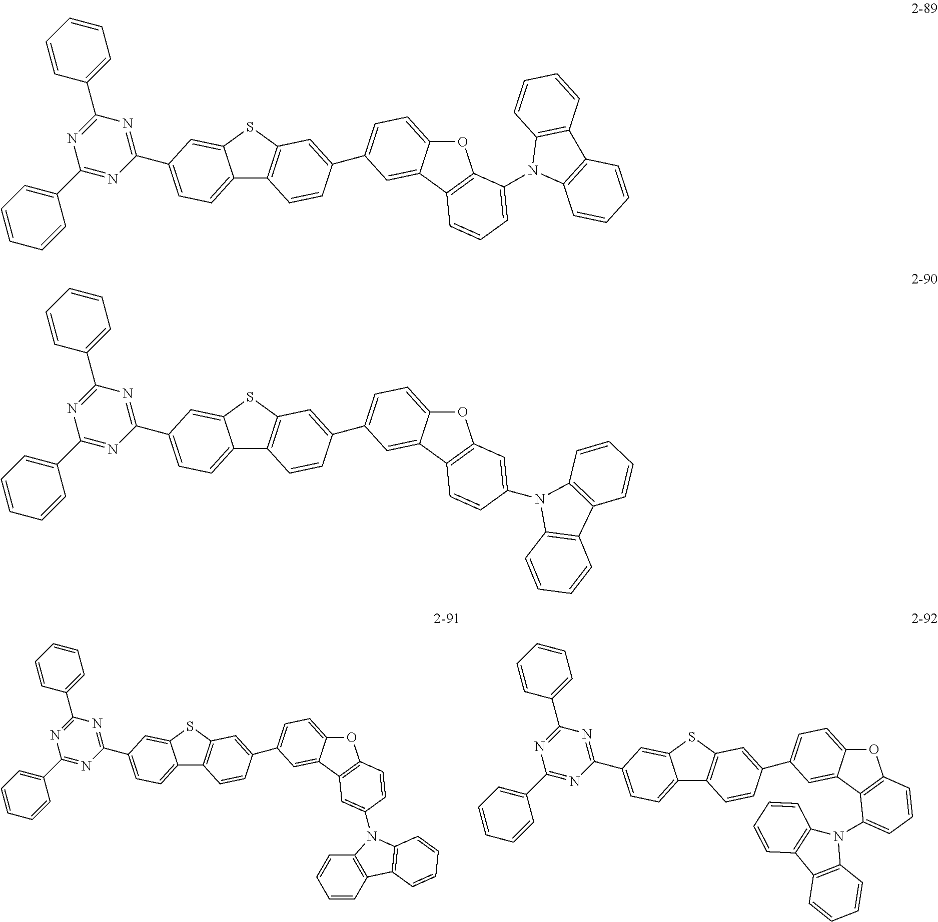 [SMILES: c1ccc(-c2nc(-c3ccccc3)nc(-c3ccc4c(c3)sc3cc(-c5ccc6oc7c(-n8c9ccccc9c9ccccc98)cccc7c6c5)ccc34)n2)cc1 ; c1ccc(-c2nc(-c3ccccc3)nc(-c3ccc4c(c3)sc3cc(-c5ccc6oc7cc(-n8c9ccccc9c9ccccc98)ccc7c6c5)ccc34)n2)cc1 ; c1ccc(-c2nc(-c3ccccc3)nc(-c3ccc4c(c3)sc3cc(-c5ccc6oc7ccc(-n8c9ccccc9c9ccccc98)cc7c6c5)ccc34)n2)cc1 ; c1ccc(-c2nc(-c3ccccc3)nc(-c3ccc4c(c3)sc3cc(-c5ccc6oc7cccc(-n8c9ccccc9c9ccccc98)c7c6c5)ccc34)n2)cc1]

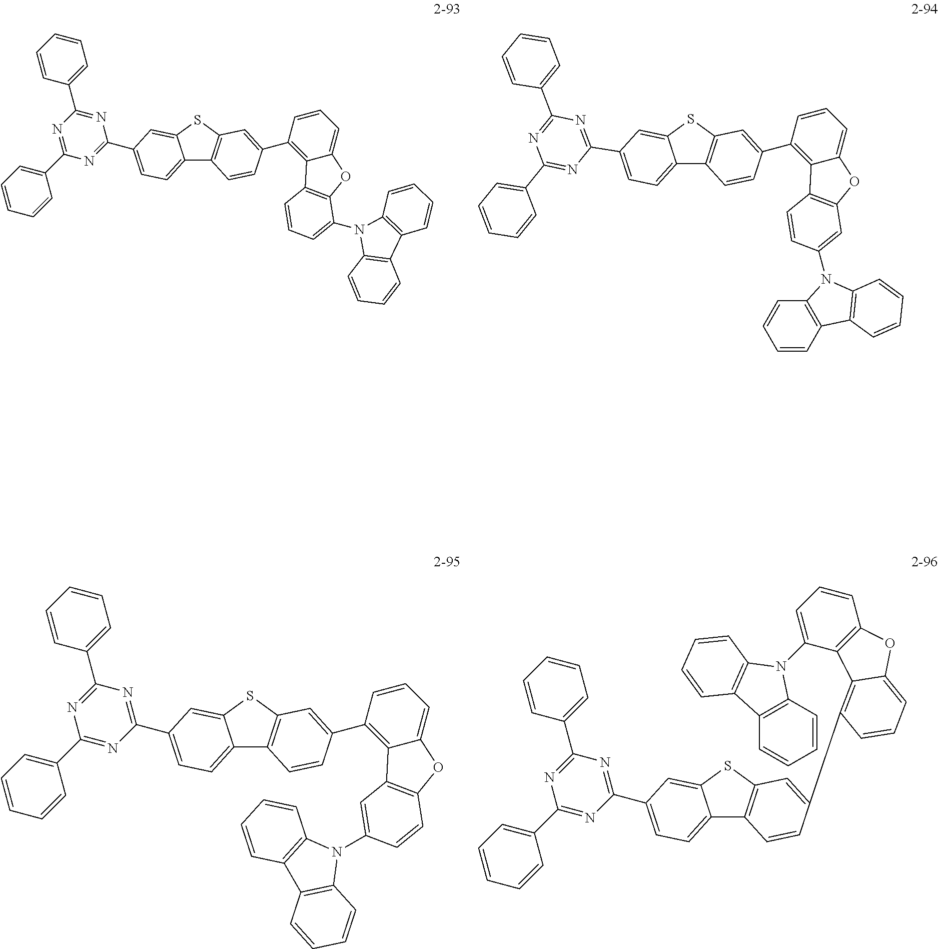 [SMILES: c1ccc(-c2nc(-c3ccccc3)nc(-c3ccc4c(c3)sc3cc(-c5cccc6oc7c(-n8c9ccccc9c9ccccc98)cccc7c56)ccc34)n2)cc1 ; c1ccc(-c2nc(-c3ccccc3)nc(-c3ccc4c(c3)sc3cc(-c5cccc6oc7cc(-n8c9ccccc9c9ccccc98)ccc7c56)ccc34)n2)cc1 ; c1ccc(-c2nc(-c3ccccc3)nc(-c3ccc4c(c3)sc3cc(-c5cccc6oc7ccc(-n8c9ccccc9c9ccccc98)cc7c56)ccc34)n2)cc1 ; c1ccc(-c2nc(-c3ccccc3)nc(-c3ccc4c(c3)sc3cc(-c5cccc6oc7cccc(-n8c9ccccc9c9ccccc98)c7c56)ccc34)n2)cc1]

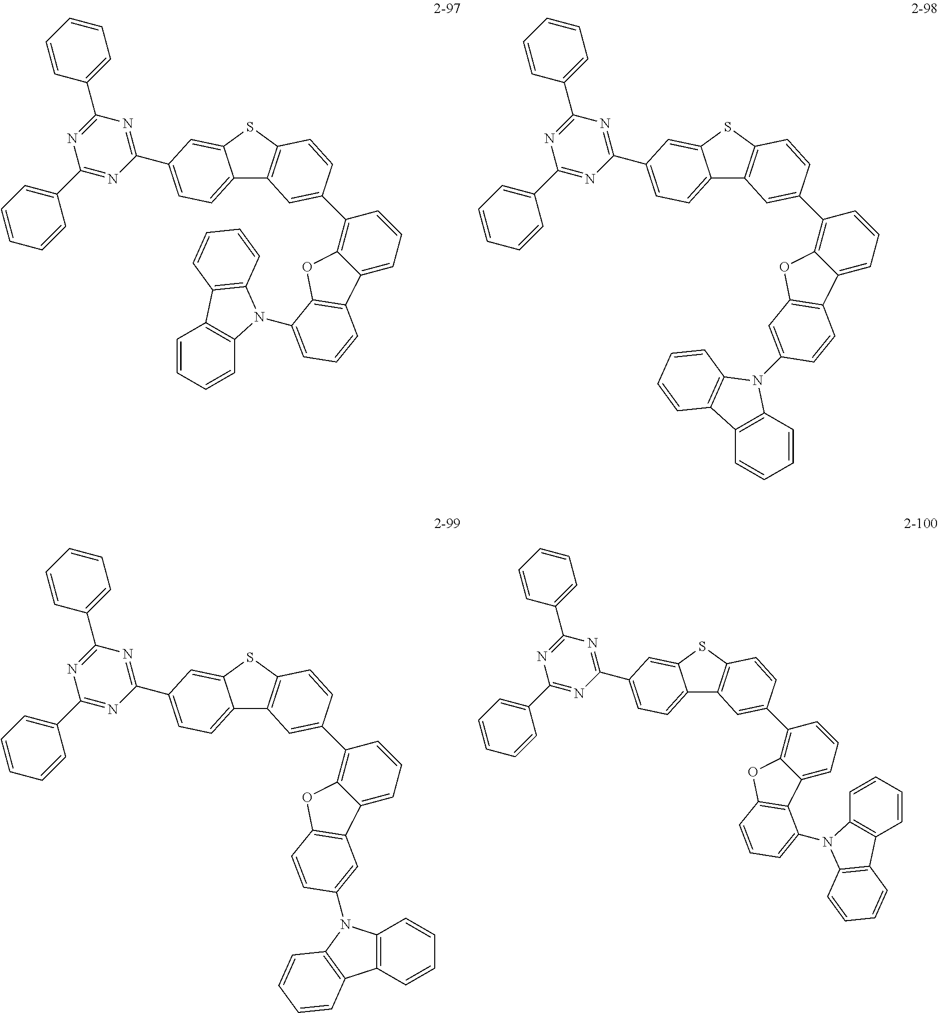 [SMILES: c1ccc(-c2nc(-c3ccccc3)nc(-c3ccc4c(c3)sc3ccc(-c5cccc6c5oc5c(-n7c8ccccc8c8ccccc87)cccc56)cc34)n2)cc1 ; c1ccc(-c2nc(-c3ccccc3)nc(-c3ccc4c(c3)sc3ccc(-c5cccc6c5oc5cc(-n7c8ccccc8c8ccccc87)ccc56)cc34)n2)cc1 ; c1ccc(-c2nc(-c3ccccc3)nc(-c3ccc4c(c3)sc3ccc(-c5cccc6c5oc5ccc(-n7c8ccccc8c8ccccc87)cc56)cc34)n2)cc1 ; c1ccc(-c2nc(-c3ccccc3)nc(-c3ccc4c(c3)sc3ccc(-c5cccc6c5oc5cccc(-n7c8ccccc8c8ccccc87)c56)cc34)n2)cc1]

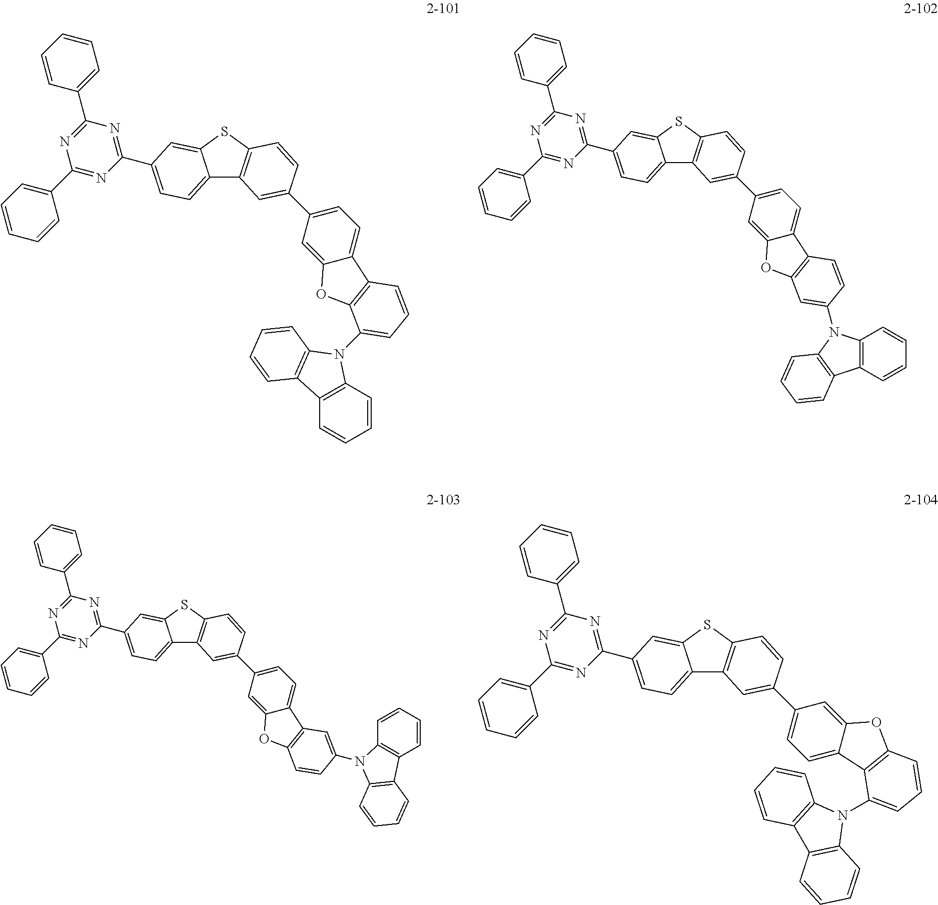 [SMILES: c1ccc(-c2nc(-c3ccccc3)nc(-c3ccc4c(c3)sc3ccc(-c5ccc6c(c5)oc5c(-n7c8ccccc8c8ccccc87)cccc56)cc34)n2)cc1 ; c1ccc(-c2nc(-c3ccccc3)nc(-c3ccc4c(c3)sc3ccc(-c5ccc6c(c5)oc5cc(-n7c8ccccc8c8ccccc87)ccc56)cc34)n2)cc1 ; c1ccc(-c2nc(-c3ccccc3)nc(-c3ccc4c(c3)sc3ccc(-c5ccc6c(c5)oc5ccc(-n7c8ccccc8c8ccccc87)cc56)cc34)n2)cc1 ; c1ccc(-c2nc(-c3ccccc3)nc(-c3ccc4c(c3)sc3ccc(-c5ccc6c(c5)oc5cccc(-n7c8ccccc8c8ccccc87)c56)cc34)n2)cc1]

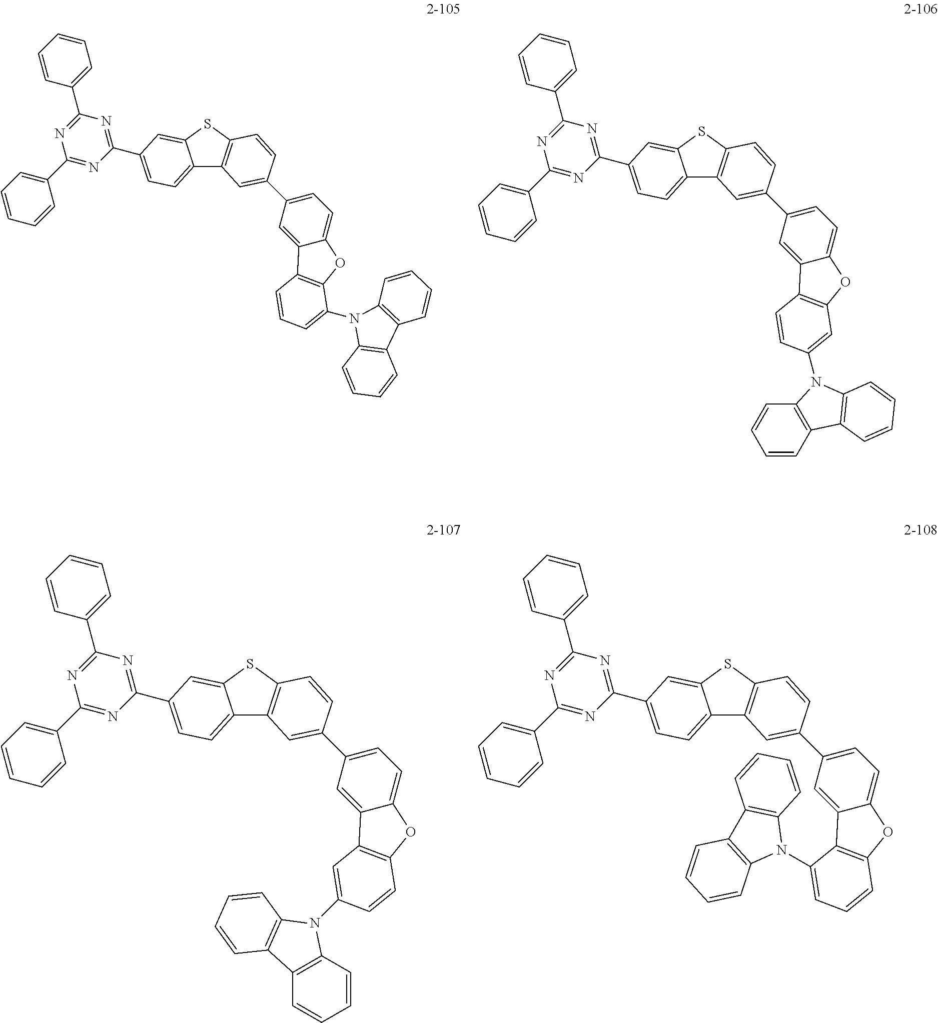 [SMILES: c1ccc(-c2nc(-c3ccccc3)nc(-c3ccc4c(c3)sc3ccc(-c5ccc6oc7c(-n8c9ccccc9c9ccccc98)cccc7c6c5)cc34)n2)cc1 ; c1ccc(-c2nc(-c3ccccc3)nc(-c3ccc4c(c3)sc3ccc(-c5ccc6oc7cc(-n8c9ccccc9c9ccccc98)ccc7c6c5)cc34)n2)cc1 ; c1ccc(-c2nc(-c3ccccc3)nc(-c3ccc4c(c3)sc3ccc(-c5ccc6oc7ccc(-n8c9ccccc9c9ccccc98)cc7c6c5)cc34)n2)cc1 ; c1ccc(-c2nc(-c3ccccc3)nc(-c3ccc4c(c3)sc3ccc(-c5ccc6oc7cccc(-n8c9ccccc9c9ccccc98)c7c6c5)cc34)n2)cc1]

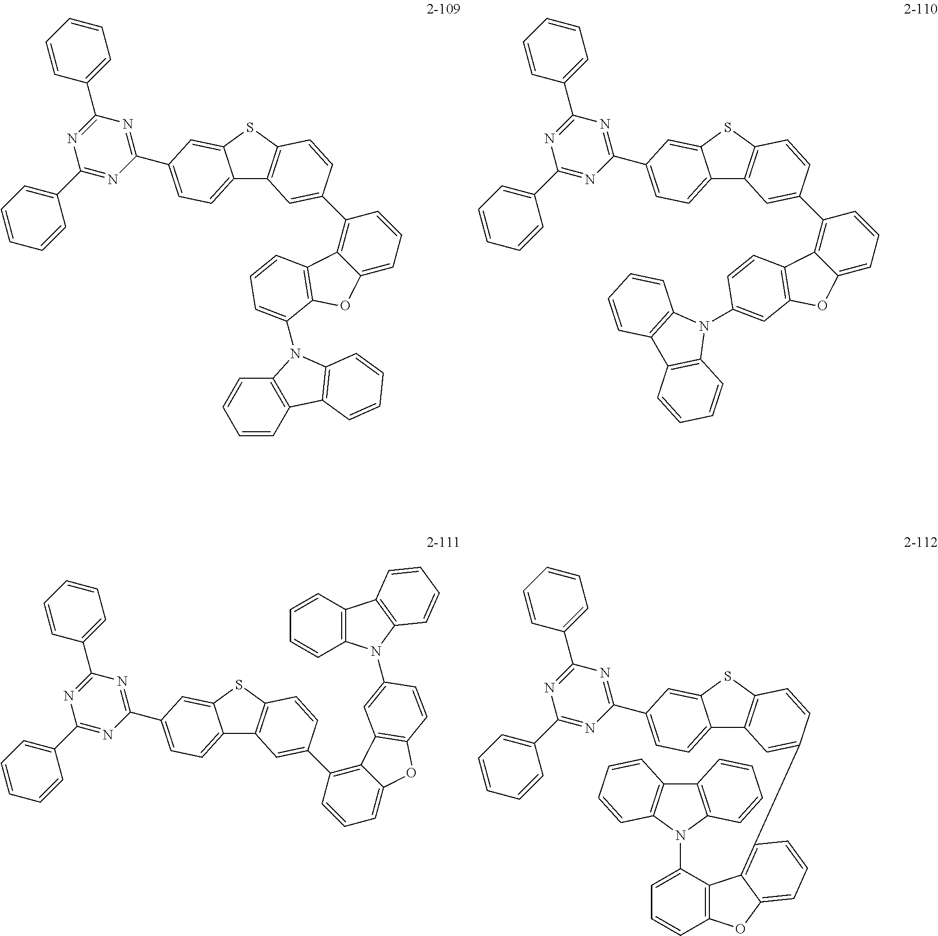 [SMILES: c1ccc(-c2nc(-c3ccccc3)nc(-c3ccc4c(c3)sc3ccc(-c5cccc6oc7c(-n8c9ccccc9c9ccccc98)cccc7c56)cc34)n2)cc1 ; c1ccc(-c2nc(-c3ccccc3)nc(-c3ccc4c(c3)sc3ccc(-c5cccc6oc7cc(-n8c9ccccc9c9ccccc98)ccc7c56)cc34)n2)cc1 ; c1ccc(-c2nc(-c3ccccc3)nc(-c3ccc4c(c3)sc3ccc(-c5cccc6oc7ccc(-n8c9ccccc9c9ccccc98)cc7c56)cc34)n2)cc1 ; c1ccc(-c2nc(-c3ccccc3)nc(-c3ccc4c(c3)sc3ccc(-c5cccc6oc7cccc(-n8c9ccccc9c9ccccc98)c7c56)cc34)n2)cc1]

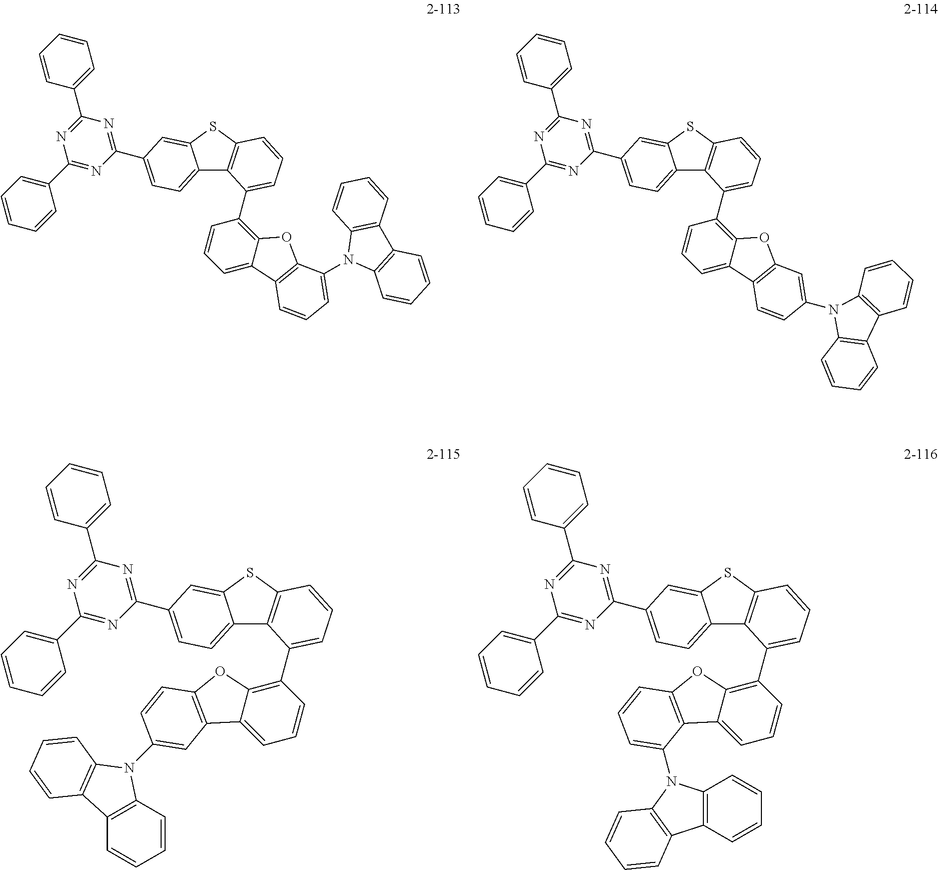 [SMILES: c1ccc(-c2nc(-c3ccccc3)nc(-c3ccc4c(c3)sc3cccc(-c5cccc6c5oc5c(-n7c8ccccc8c8ccccc87)cccc56)c34)n2)cc1 ; c1ccc(-c2nc(-c3ccccc3)nc(-c3ccc4c(c3)sc3cccc(-c5cccc6c5oc5cc(-n7c8ccccc8c8ccccc87)ccc56)c34)n2)cc1 ; c1ccc(-c2nc(-c3ccccc3)nc(-c3ccc4c(c3)sc3cccc(-c5cccc6c5oc5ccc(-n7c8ccccc8c8ccccc87)cc56)c34)n2)cc1 ; c1ccc(-c2nc(-c3ccccc3)nc(-c3ccc4c(c3)sc3cccc(-c5cccc6c5oc5cccc(-n7c8ccccc8c8ccccc87)c56)c34)n2)cc1]

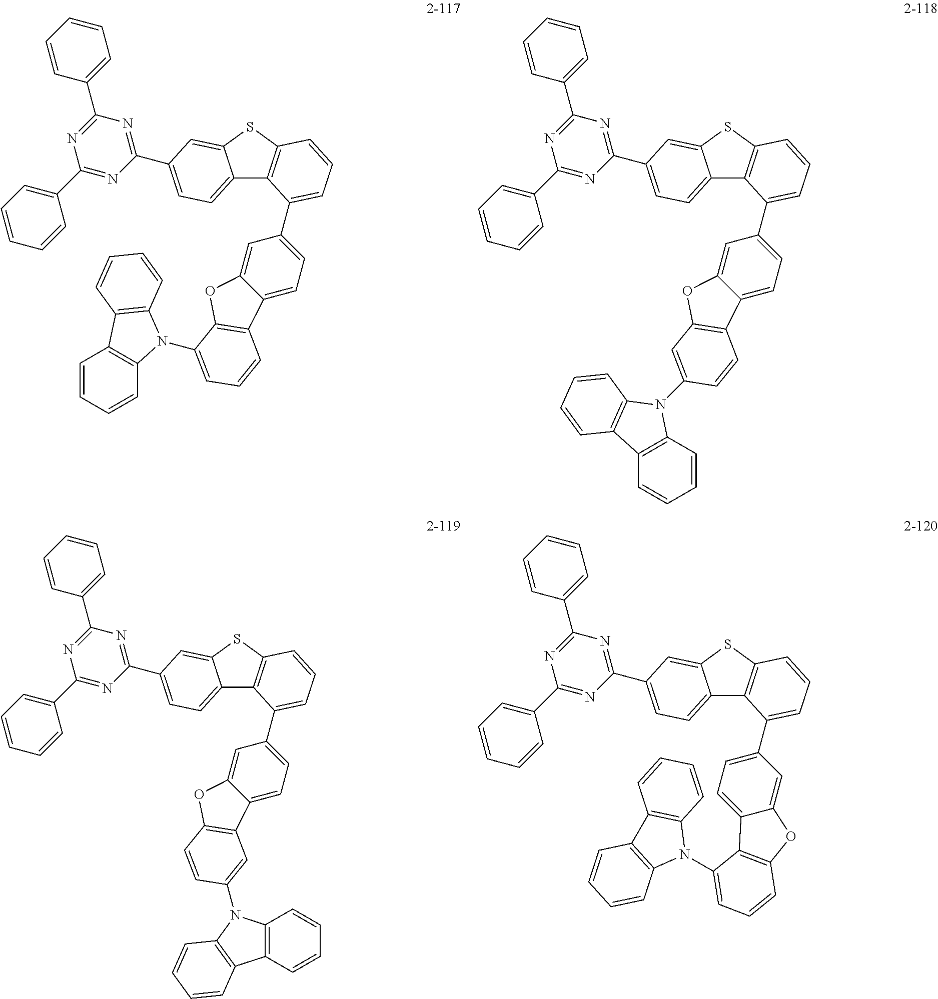 [SMILES: c1ccc(-c2nc(-c3ccccc3)nc(-c3ccc4c(c3)sc3cccc(-c5ccc6c(c5)oc5c(-n7c8ccccc8c8ccccc87)cccc56)c34)n2)cc1 ; c1ccc(-c2nc(-c3ccccc3)nc(-c3ccc4c(c3)sc3cccc(-c5ccc6c(c5)oc5cc(-n7c8ccccc8c8ccccc87)ccc56)c34)n2)cc1 ; c1ccc(-c2nc(-c3ccccc3)nc(-c3ccc4c(c3)sc3cccc(-c5ccc6c(c5)oc5ccc(-n7c8ccccc8c8ccccc87)cc56)c34)n2)cc1 ; c1ccc(-c2nc(-c3ccccc3)nc(-c3ccc4c(c3)sc3cccc(-c5ccc6c(c5)oc5cccc(-n7c8ccccc8c8ccccc87)c56)c34)n2)cc1]

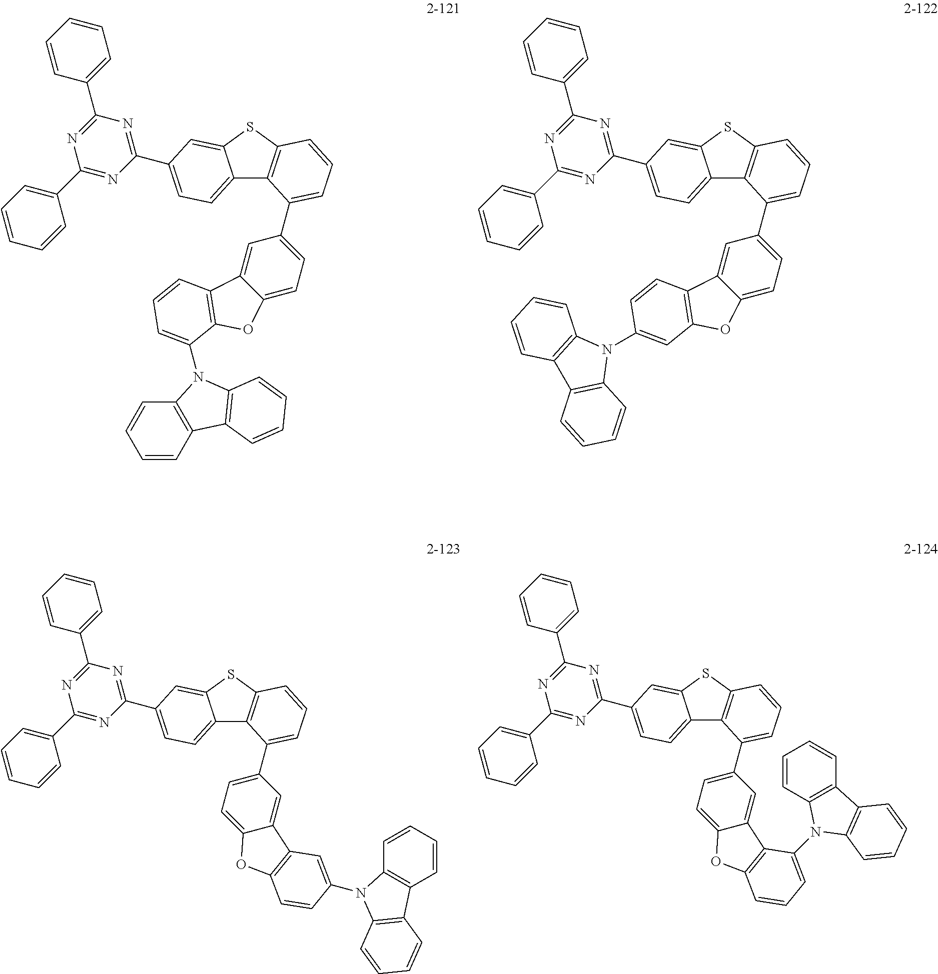 [SMILES: c1ccc(-c2nc(-c3ccccc3)nc(-c3ccc4c(c3)sc3cccc(-c5ccc6oc7c(-n8c9ccccc9c9ccccc98)cccc7c6c5)c34)n2)cc1 ; c1ccc(-c2nc(-c3ccccc3)nc(-c3ccc4c(c3)sc3cccc(-c5ccc6oc7cc(-n8c9ccccc9c9ccccc98)ccc7c6c5)c34)n2)cc1 ; c1ccc(-c2nc(-c3ccccc3)nc(-c3ccc4c(c3)sc3cccc(-c5ccc6oc7ccc(-n8c9ccccc9c9ccccc98)cc7c6c5)c34)n2)cc1 ; c1ccc(-c2nc(-c3ccccc3)nc(-c3ccc4c(c3)sc3cccc(-c5ccc6oc7cccc(-n8c9ccccc9c9ccccc98)c7c6c5)c34)n2)cc1]

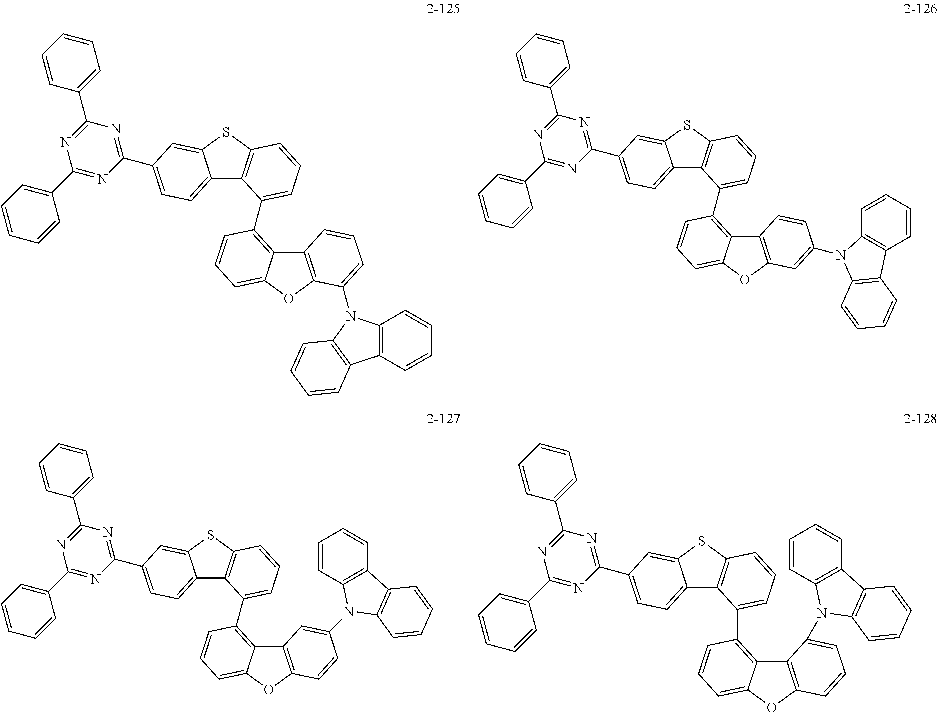 [SMILES: c1ccc(-c2nc(-c3ccccc3)nc(-c3ccc4c(c3)sc3cccc(-c5cccc6oc7c(-n8c9ccccc9c9ccccc98)cccc7c56)c34)n2)cc1 ; c1ccc(-c2nc(-c3ccccc3)nc(-c3ccc4c(c3)sc3cccc(-c5cccc6oc7cc(-n8c9ccccc9c9ccccc98)ccc7c56)c34)n2)cc1 ; c1ccc(-c2nc(-c3ccccc3)nc(-c3ccc4c(c3)sc3cccc(-c5cccc6oc7ccc(-n8c9ccccc9c9ccccc98)cc7c56)c34)n2)cc1 ; c1ccc(-c2nc(-c3ccccc3)nc(-c3ccc4c(c3)sc3cccc(-c5cccc6oc7cccc(-n8c9ccccc9c9ccccc98)c7c56)c34)n2)cc1]

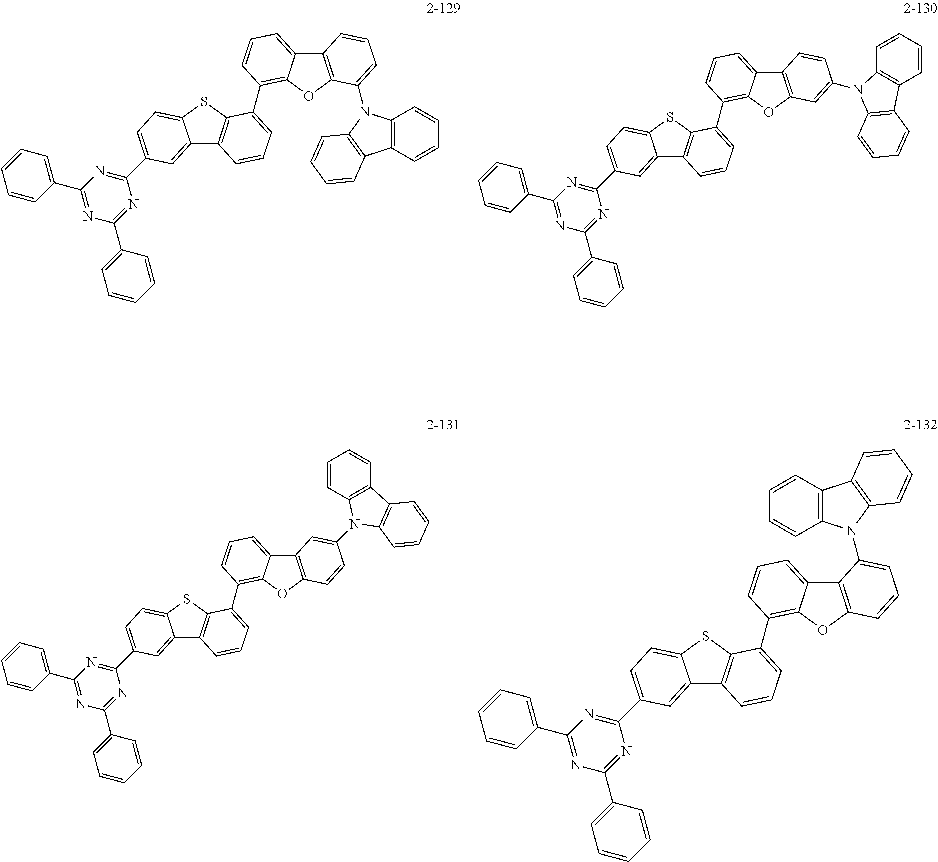 [SMILES: c1ccc(-c2nc(-c3ccccc3)nc(-c3ccc4sc5c(-c6cccc7c6oc6c(-n8c9ccccc9c9ccccc98)cccc67)cccc5c4c3)n2)cc1 ; c1ccc(-c2nc(-c3ccccc3)nc(-c3ccc4sc5c(-c6cccc7c6oc6cc(-n8c9ccccc9c9ccccc98)ccc67)cccc5c4c3)n2)cc1 ; c1ccc(-c2nc(-c3ccccc3)nc(-c3ccc4sc5c(-c6cccc7c6oc6ccc(-n8c9ccccc9c9ccccc98)cc67)cccc5c4c3)n2)cc1 ; c1ccc(-c2nc(-c3ccccc3)nc(-c3ccc4sc5c(-c6cccc7c6oc6cccc(-n8c9ccccc9c9ccccc98)c67)cccc5c4c3)n2)cc1]

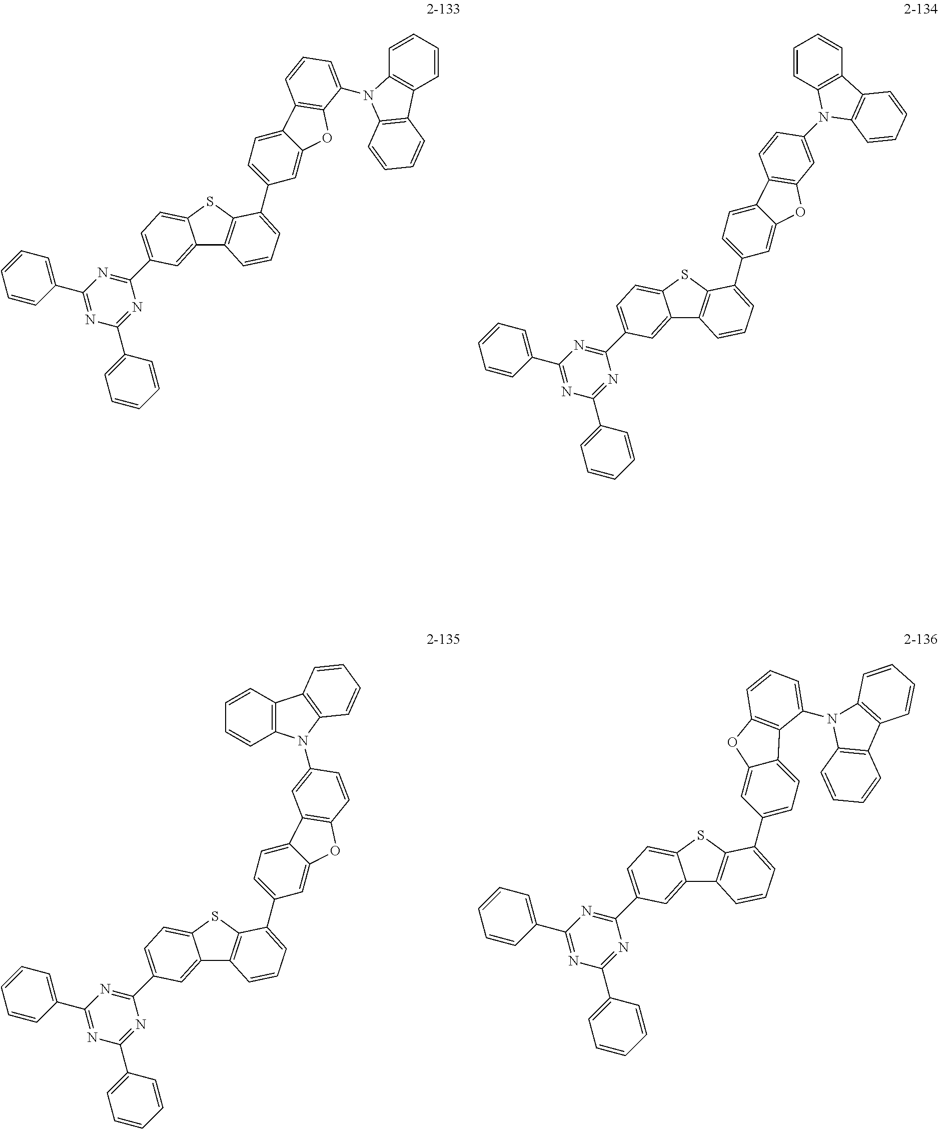 [SMILES: c1ccc(-c2nc(-c3ccccc3)nc(-c3ccc4sc5c(-c6ccc7c(c6)oc6c(-n8c9ccccc9c9ccccc98)cccc67)cccc5c4c3)n2)cc1 ; c1ccc(-c2nc(-c3ccccc3)nc(-c3ccc4sc5c(-c6ccc7c(c6)oc6cc(-n8c9ccccc9c9ccccc98)ccc67)cccc5c4c3)n2)cc1 ; c1ccc(-c2nc(-c3ccccc3)nc(-c3ccc4sc5c(-c6ccc7c(c6)oc6ccc(-n8c9ccccc9c9ccccc98)cc67)cccc5c4c3)n2)cc1 ; c1ccc(-c2nc(-c3ccccc3)nc(-c3ccc4sc5c(-c6ccc7c(c6)oc6cccc(-n8c9ccccc9c9ccccc98)c67)cccc5c4c3)n2)cc1]

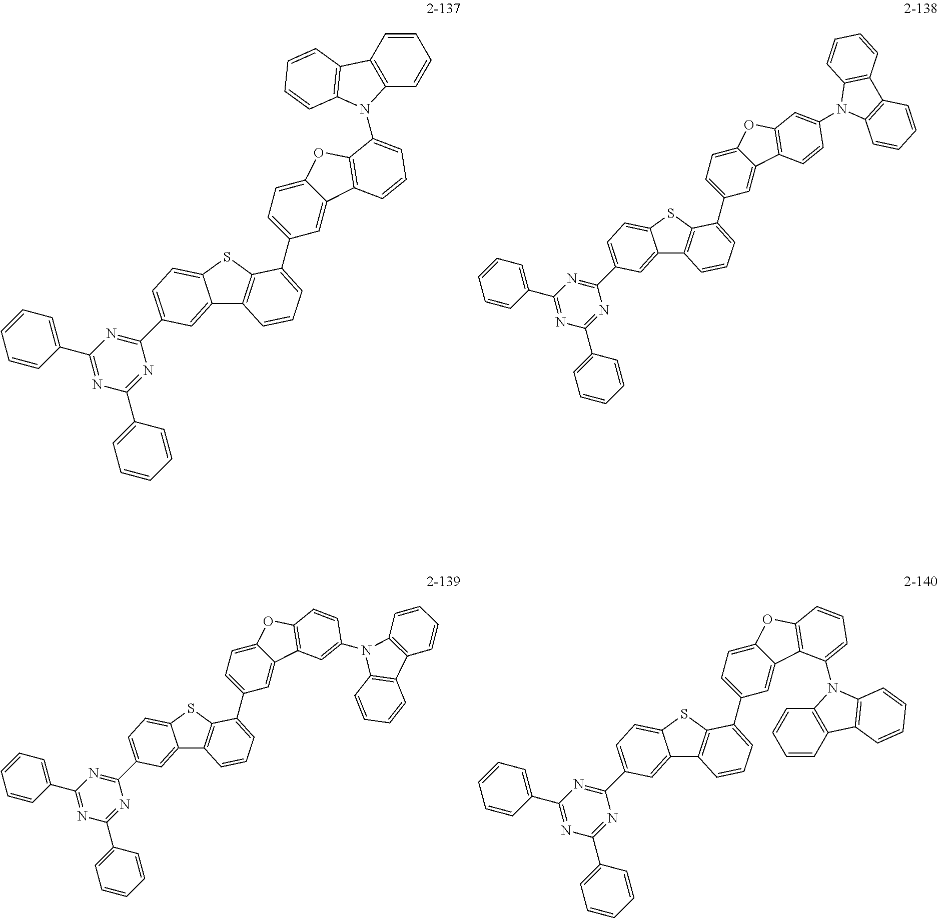 [SMILES: c1ccc(-c2nc(-c3ccccc3)nc(-c3ccc4sc5c(-c6ccc7oc8c(-n9c%10ccccc%10c%10ccccc%109)cccc8c7c6)cccc5c4c3)n2)cc1 ; c1ccc(-c2nc(-c3ccccc3)nc(-c3ccc4sc5c(-c6ccc7oc8cc(-n9c%10ccccc%10c%10ccccc%109)ccc8c7c6)cccc5c4c3)n2)cc1 ; c1ccc(-c2nc(-c3ccccc3)nc(-c3ccc4sc5c(-c6ccc7oc8ccc(-n9c%10ccccc%10c%10ccccc%109)cc8c7c6)cccc5c4c3)n2)cc1 ; c1ccc(-c2nc(-c3ccccc3)nc(-c3ccc4sc5c(-c6ccc7oc8cccc(-n9c%10ccccc%10c%10ccccc%109)c8c7c6)cccc5c4c3)n2)cc1]

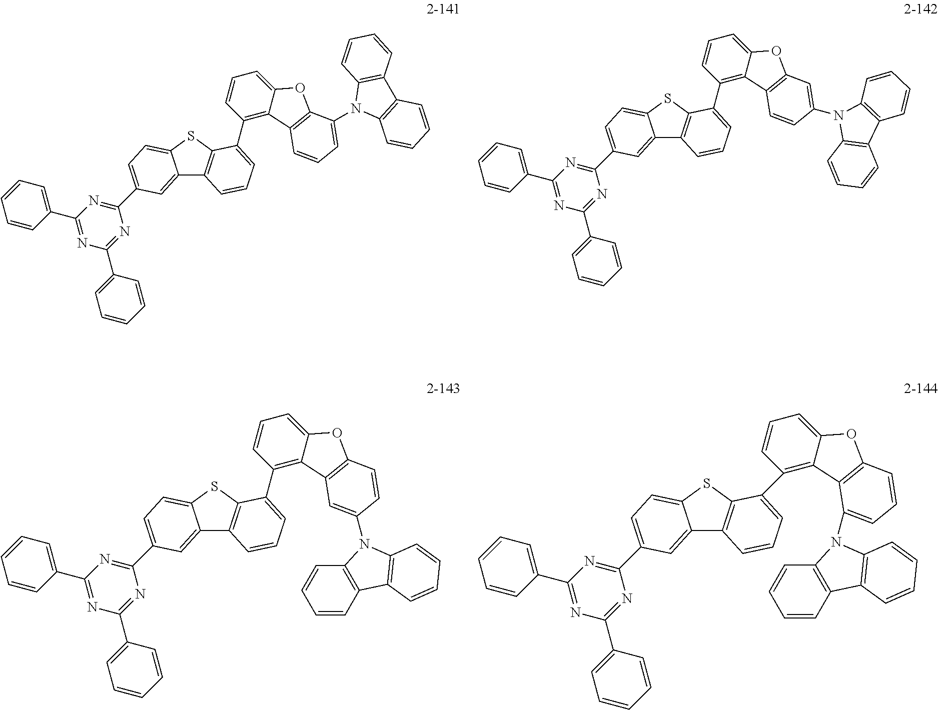 [SMILES: c1ccc(-c2nc(-c3ccccc3)nc(-c3ccc4sc5c(-c6cccc7oc8c(-n9c%10ccccc%10c%10ccccc%109)cccc8c67)cccc5c4c3)n2)cc1 ; c1ccc(-c2nc(-c3ccccc3)nc(-c3ccc4sc5c(-c6cccc7oc8cc(-n9c%10ccccc%10c%10ccccc%109)ccc8c67)cccc5c4c3)n2)cc1 ; c1ccc(-c2nc(-c3ccccc3)nc(-c3ccc4sc5c(-c6cccc7oc8ccc(-n9c%10ccccc%10c%10ccccc%109)cc8c67)cccc5c4c3)n2)cc1 ; c1ccc(-c2nc(-c3ccccc3)nc(-c3ccc4sc5c(-c6cccc7oc8cccc(-n9c%10ccccc%10c%10ccccc%109)c8c67)cccc5c4c3)n2)cc1]

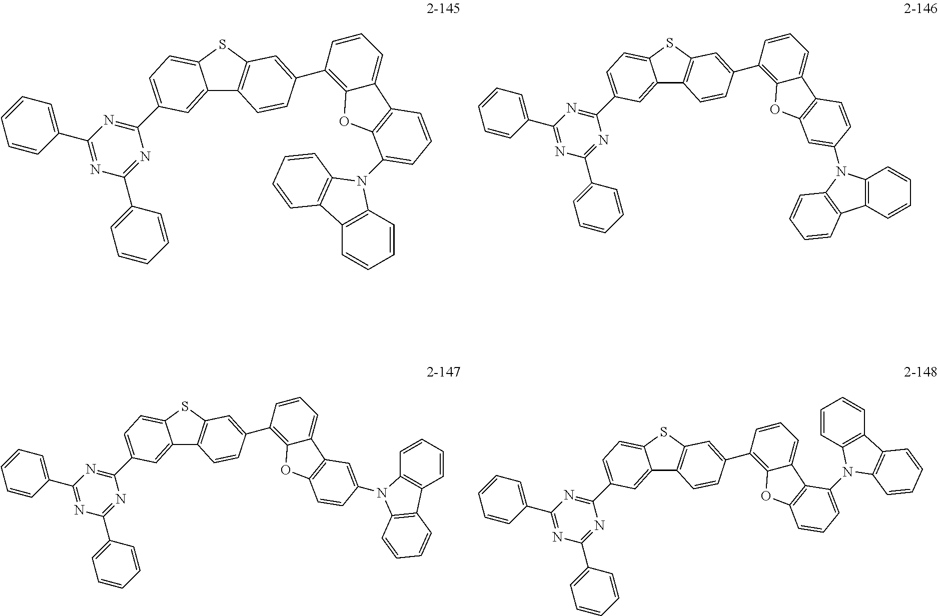 [SMILES: c1ccc(-c2nc(-c3ccccc3)nc(-c3ccc4sc5cc(-c6cccc7c6oc6c(-n8c9ccccc9c9ccccc98)cccc67)ccc5c4c3)n2)cc1 ; c1ccc(-c2nc(-c3ccccc3)nc(-c3ccc4sc5cc(-c6cccc7c6oc6cc(-n8c9ccccc9c9ccccc98)ccc67)ccc5c4c3)n2)cc1 ; c1ccc(-c2nc(-c3ccccc3)nc(-c3ccc4sc5cc(-c6cccc7c6oc6ccc(-n8c9ccccc9c9ccccc98)cc67)ccc5c4c3)n2)cc1 ; c1ccc(-c2nc(-c3ccccc3)nc(-c3ccc4sc5cc(-c6cccc7c6oc6cccc(-n8c9ccccc9c9ccccc98)c67)ccc5c4c3)n2)cc1]

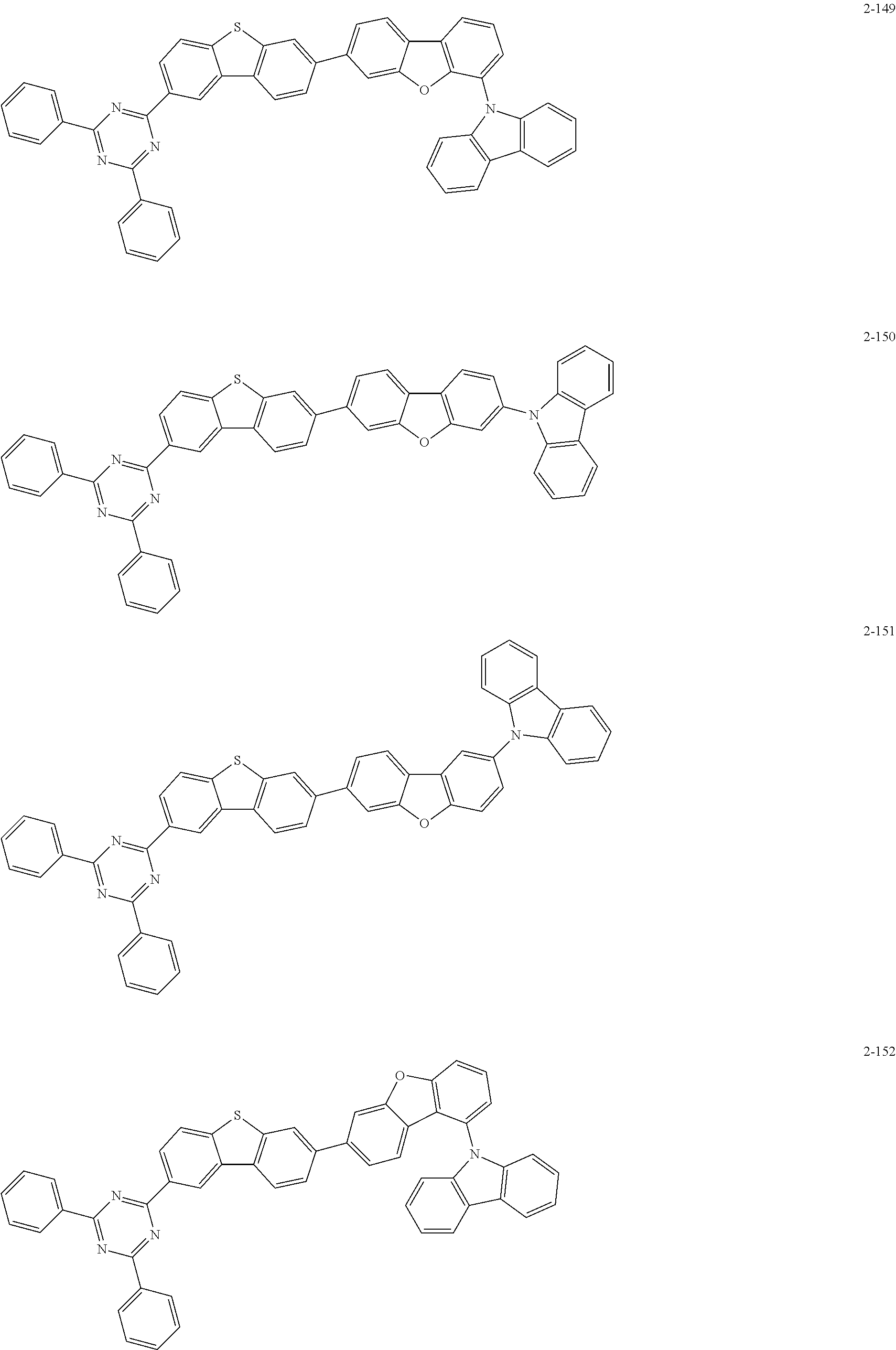 [SMILES: c1ccc(-c2nc(-c3ccccc3)nc(-c3ccc4sc5cc(-c6ccc7c(c6)oc6c(-n8c9ccccc9c9ccccc98)cccc67)ccc5c4c3)n2)cc1 ; c1ccc(-c2nc(-c3ccccc3)nc(-c3ccc4sc5cc(-c6ccc7c(c6)oc6cc(-n8c9ccccc9c9ccccc98)ccc67)ccc5c4c3)n2)cc1 ; c1ccc(-c2nc(-c3ccccc3)nc(-c3ccc4sc5cc(-c6ccc7c(c6)oc6ccc(-n8c9ccccc9c9ccccc98)cc67)ccc5c4c3)n2)cc1 ; c1ccc(-c2nc(-c3ccccc3)nc(-c3ccc4sc5cc(-c6ccc7c(c6)oc6cccc(-n8c9ccccc9c9ccccc98)c67)ccc5c4c3)n2)cc1]

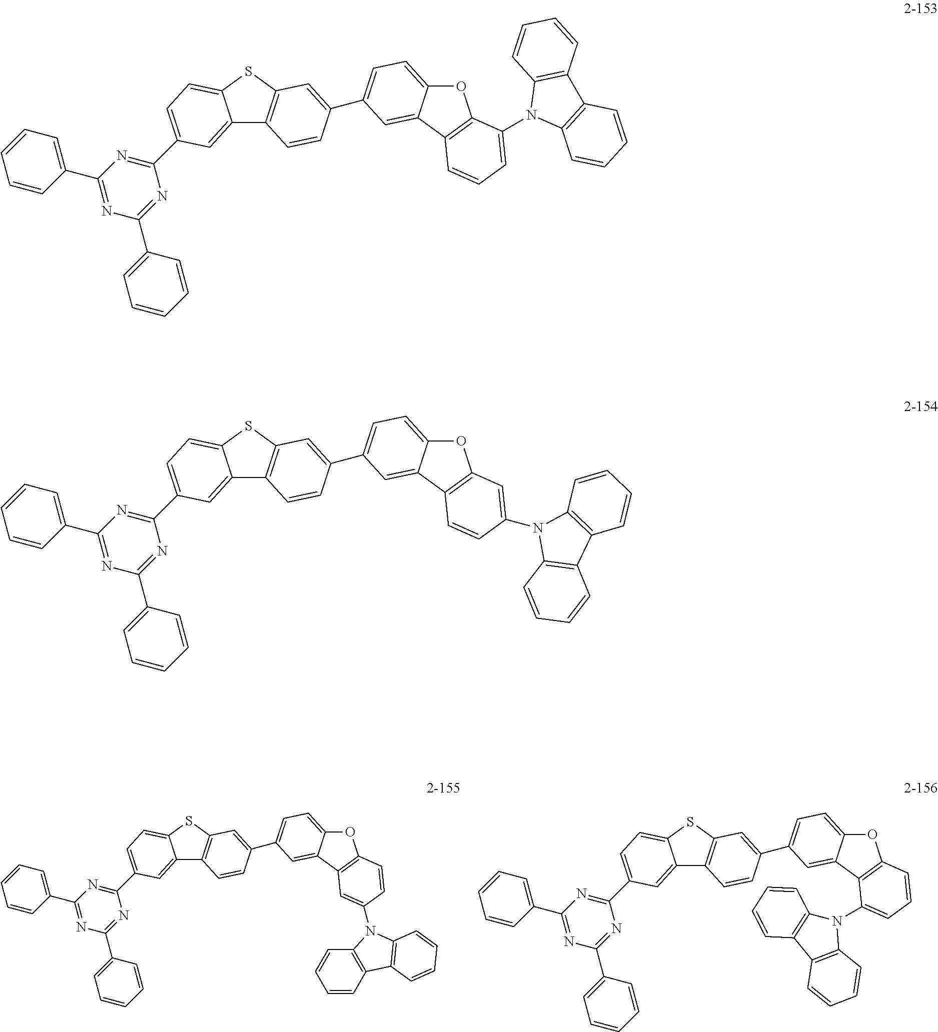 [SMILES: c1ccc(-c2nc(-c3ccccc3)nc(-c3ccc4sc5cc(-c6ccc7oc8c(-n9c%10ccccc%10c%10ccccc%109)cccc8c7c6)ccc5c4c3)n2)cc1 ; c1ccc(-c2nc(-c3ccccc3)nc(-c3ccc4sc5cc(-c6ccc7oc8cc(-n9c%10ccccc%10c%10ccccc%109)ccc8c7c6)ccc5c4c3)n2)cc1 ; c1ccc(-c2nc(-c3ccccc3)nc(-c3ccc4sc5cc(-c6ccc7oc8ccc(-n9c%10ccccc%10c%10ccccc%109)cc8c7c6)ccc5c4c3)n2)cc1 ; c1ccc(-c2nc(-c3ccccc3)nc(-c3ccc4sc5cc(-c6ccc7oc8cccc(-n9c%10ccccc%10c%10ccccc%109)c8c7c6)ccc5c4c3)n2)cc1]

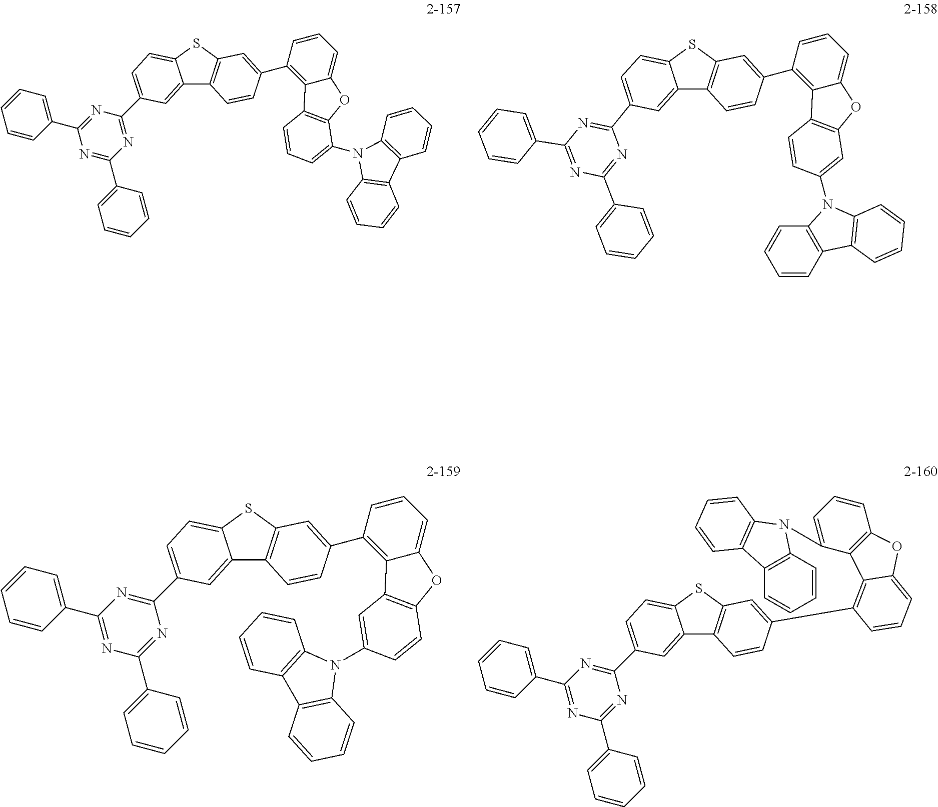 [SMILES: c1ccc(-c2nc(-c3ccccc3)nc(-c3ccc4sc5cc(-c6cccc7oc8c(-n9c%10ccccc%10c%10ccccc%109)cccc8c67)ccc5c4c3)n2)cc1 ; c1ccc(-c2nc(-c3ccccc3)nc(-c3ccc4sc5cc(-c6cccc7oc8cc(-n9c%10ccccc%10c%10ccccc%109)ccc8c67)ccc5c4c3)n2)cc1 ; c1ccc(-c2nc(-c3ccccc3)nc(-c3ccc4sc5cc(-c6cccc7oc8ccc(-n9c%10ccccc%10c%10ccccc%109)cc8c67)ccc5c4c3)n2)cc1 ; c1ccc(-c2nc(-c3ccccc3)nc(-c3ccc4sc5cc(-c6cccc7oc8cccc(-n9c%10ccccc%10c%10ccccc%109)c8c67)ccc5c4c3)n2)cc1]

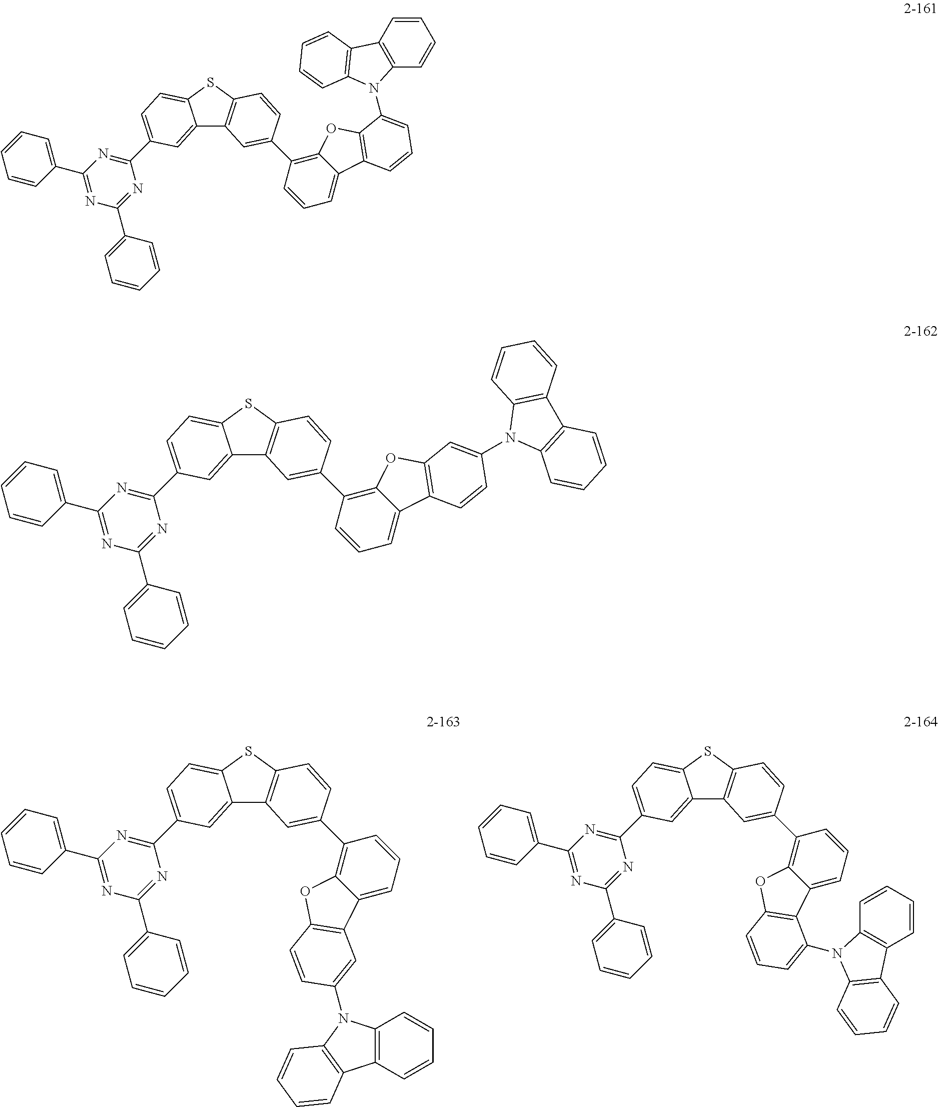 [SMILES: c1ccc(-c2nc(-c3ccccc3)nc(-c3ccc4sc5ccc(-c6cccc7c6oc6c(-n8c9ccccc9c9ccccc98)cccc67)cc5c4c3)n2)cc1 ; c1ccc(-c2nc(-c3ccccc3)nc(-c3ccc4sc5ccc(-c6cccc7c6oc6cc(-n8c9ccccc9c9ccccc98)ccc67)cc5c4c3)n2)cc1 ; c1ccc(-c2nc(-c3ccccc3)nc(-c3ccc4sc5ccc(-c6cccc7c6oc6ccc(-n8c9ccccc9c9ccccc98)cc67)cc5c4c3)n2)cc1 ; c1ccc(-c2nc(-c3ccccc3)nc(-c3ccc4sc5ccc(-c6cccc7c6oc6cccc(-n8c9ccccc9c9ccccc98)c67)cc5c4c3)n2)cc1]

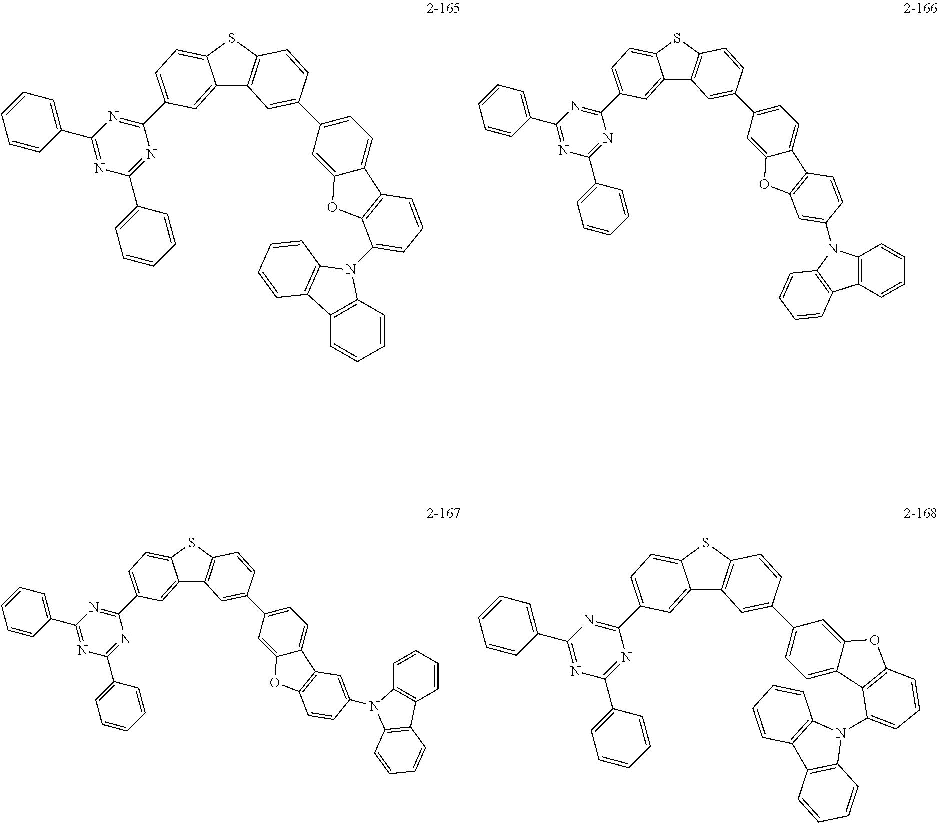 [SMILES: c1ccc(-c2nc(-c3ccccc3)nc(-c3ccc4sc5ccc(-c6ccc7c(c6)oc6c(-n8c9ccccc9c9ccccc98)cccc67)cc5c4c3)n2)cc1 ; c1ccc(-c2nc(-c3ccccc3)nc(-c3ccc4sc5ccc(-c6ccc7c(c6)oc6cc(-n8c9ccccc9c9ccccc98)ccc67)cc5c4c3)n2)cc1 ; c1ccc(-c2nc(-c3ccccc3)nc(-c3ccc4sc5ccc(-c6ccc7c(c6)oc6ccc(-n8c9ccccc9c9ccccc98)cc67)cc5c4c3)n2)cc1 ; c1ccc(-c2nc(-c3ccccc3)nc(-c3ccc4sc5ccc(-c6ccc7c(c6)oc6cccc(-n8c9ccccc9c9ccccc98)c67)cc5c4c3)n2)cc1]

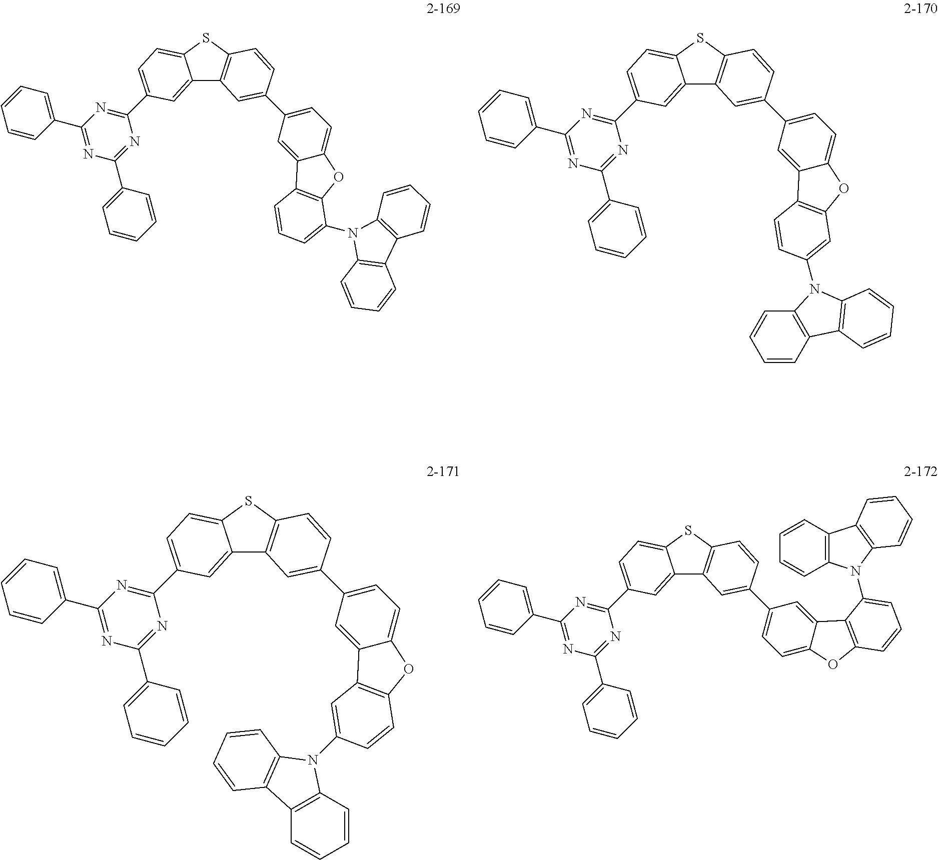 [SMILES: c1ccc(-c2nc(-c3ccccc3)nc(-c3ccc4sc5ccc(-c6ccc7oc8c(-n9c%10ccccc%10c%10ccccc%109)cccc8c7c6)cc5c4c3)n2)cc1 ; c1ccc(-c2nc(-c3ccccc3)nc(-c3ccc4sc5ccc(-c6ccc7oc8cc(-n9c%10ccccc%10c%10ccccc%109)ccc8c7c6)cc5c4c3)n2)cc1 ; c1ccc(-c2nc(-c3ccccc3)nc(-c3ccc4sc5ccc(-c6ccc7oc8ccc(-n9c%10ccccc%10c%10ccccc%109)cc8c7c6)cc5c4c3)n2)cc1 ; c1ccc(-c2nc(-c3ccccc3)nc(-c3ccc4sc5ccc(-c6ccc7oc8cccc(-n9c%10ccccc%10c%10ccccc%109)c8c7c6)cc5c4c3)n2)cc1]

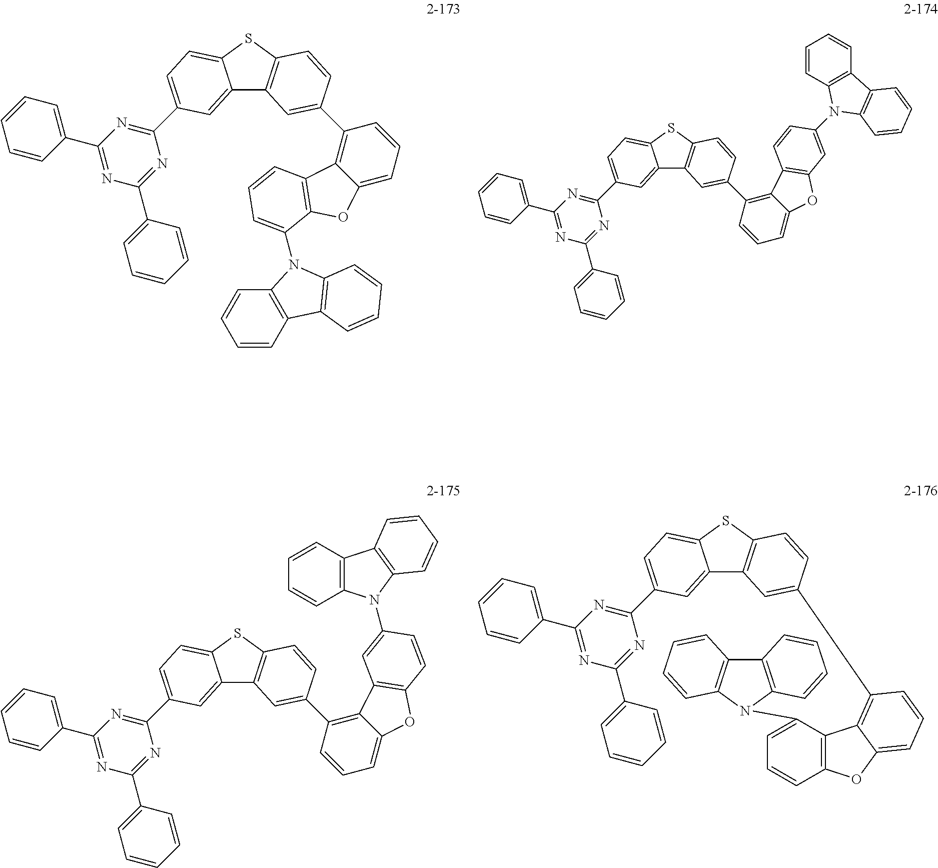 [SMILES: c1ccc(-c2nc(-c3ccccc3)nc(-c3ccc4sc5ccc(-c6cccc7oc8c(-n9c%10ccccc%10c%10ccccc%109)cccc8c67)cc5c4c3)n2)cc1 ; c1ccc(-c2nc(-c3ccccc3)nc(-c3ccc4sc5ccc(-c6cccc7oc8cc(-n9c%10ccccc%10c%10ccccc%109)ccc8c67)cc5c4c3)n2)cc1 ; c1ccc(-c2nc(-c3ccccc3)nc(-c3ccc4sc5ccc(-c6cccc7oc8ccc(-n9c%10ccccc%10c%10ccccc%109)cc8c67)cc5c4c3)n2)cc1 ; c1ccc(-c2nc(-c3ccccc3)nc(-c3ccc4sc5ccc(-c6cccc7oc8cccc(-n9c%10ccccc%10c%10ccccc%109)c8c67)cc5c4c3)n2)cc1]

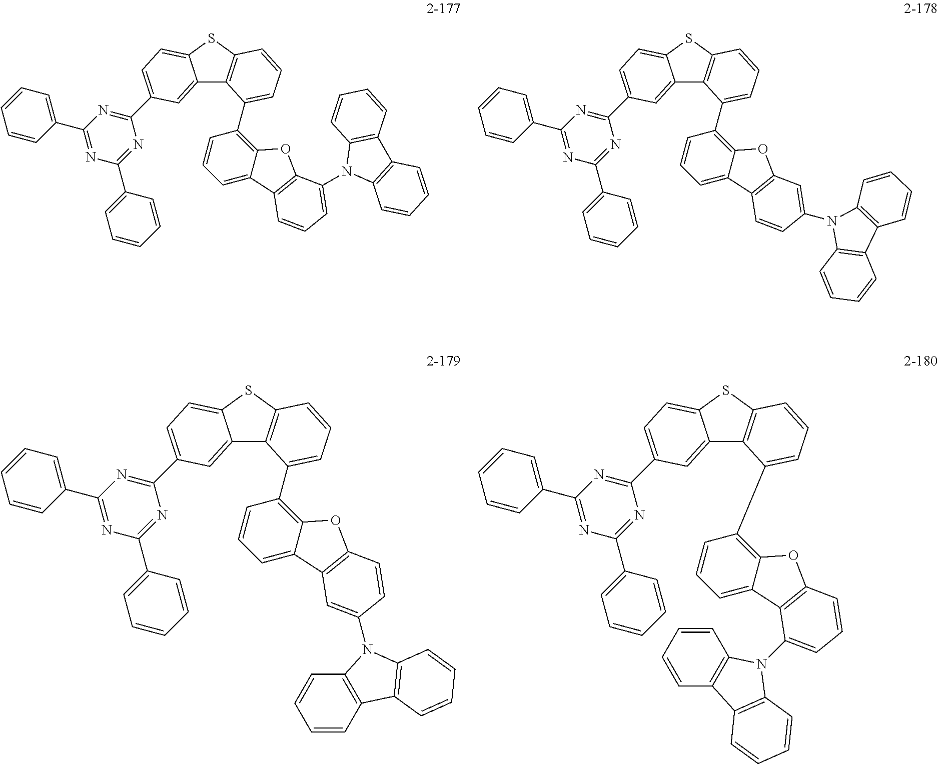 [SMILES: c1ccc(-c2nc(-c3ccccc3)nc(-c3ccc4sc5cccc(-c6cccc7c6oc6c(-n8c9ccccc9c9ccccc98)cccc67)c5c4c3)n2)cc1 ; c1ccc(-c2nc(-c3ccccc3)nc(-c3ccc4sc5cccc(-c6cccc7c6oc6cc(-n8c9ccccc9c9ccccc98)ccc67)c5c4c3)n2)cc1 ; c1ccc(-c2nc(-c3ccccc3)nc(-c3ccc4sc5cccc(-c6cccc7c6oc6ccc(-n8c9ccccc9c9ccccc98)cc67)c5c4c3)n2)cc1 ; c1ccc(-c2nc(-c3ccccc3)nc(-c3ccc4sc5cccc(-c6cccc7c6oc6cccc(-n8c9ccccc9c9ccccc98)c67)c5c4c3)n2)cc1]

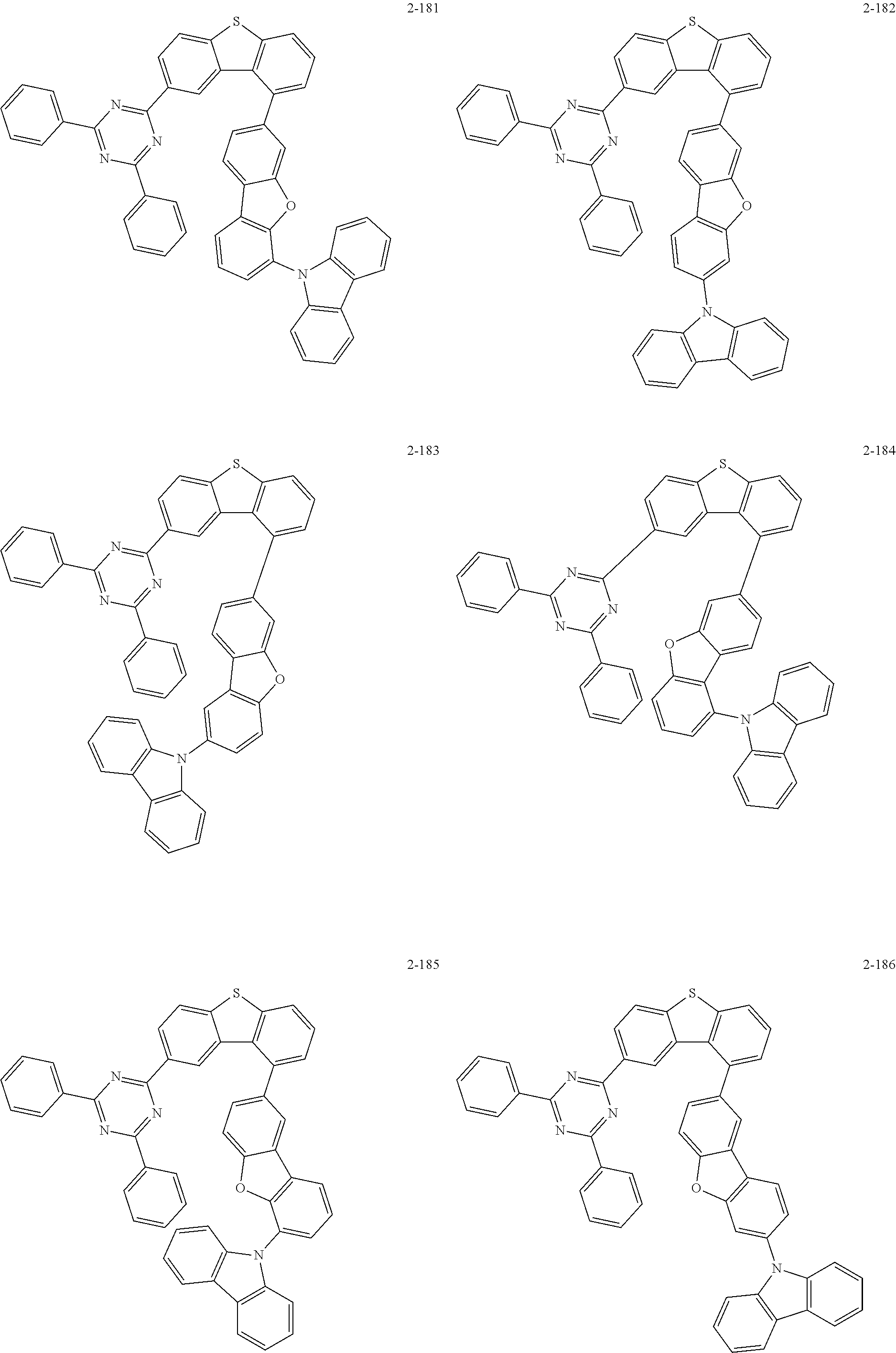

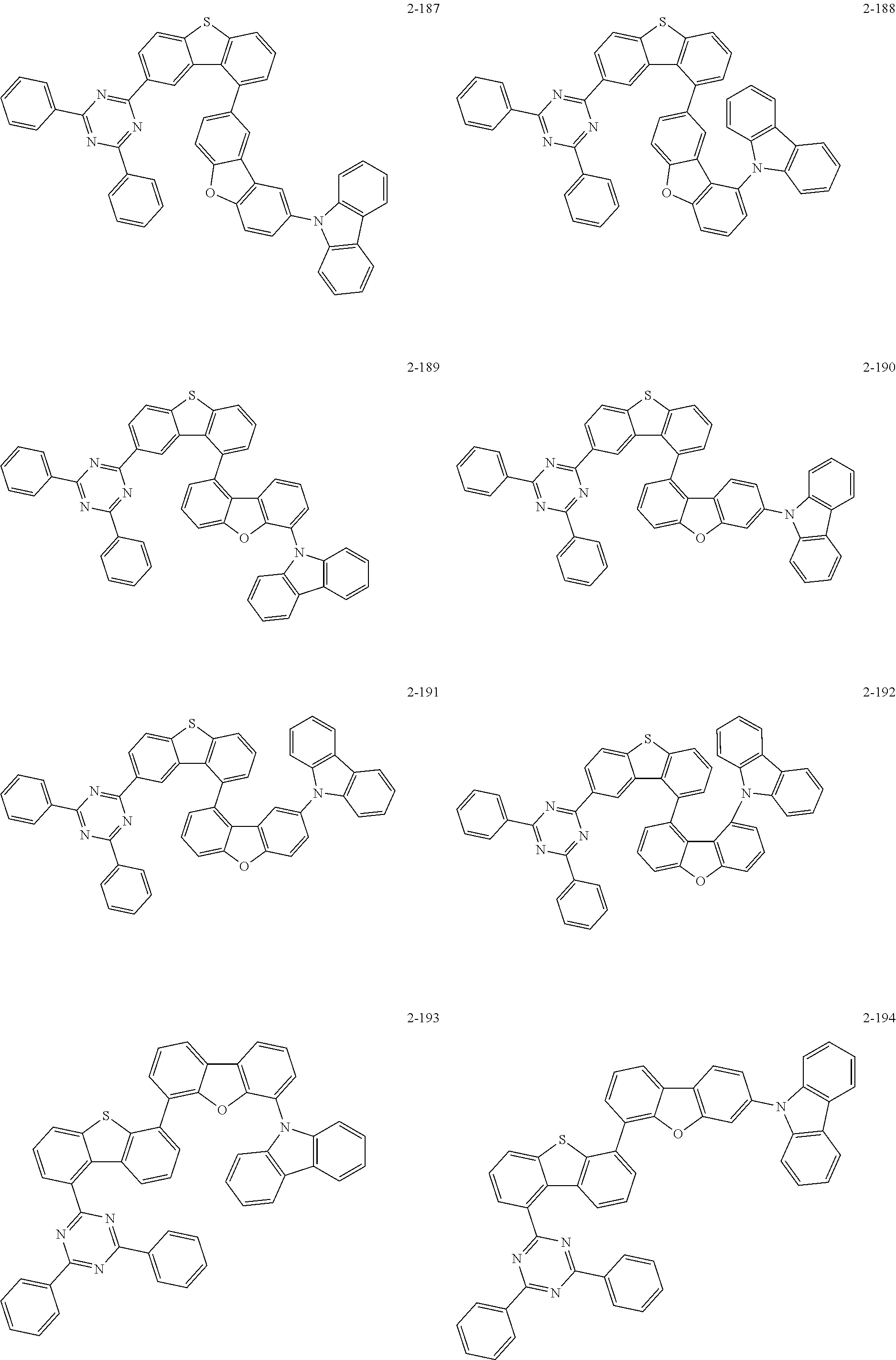

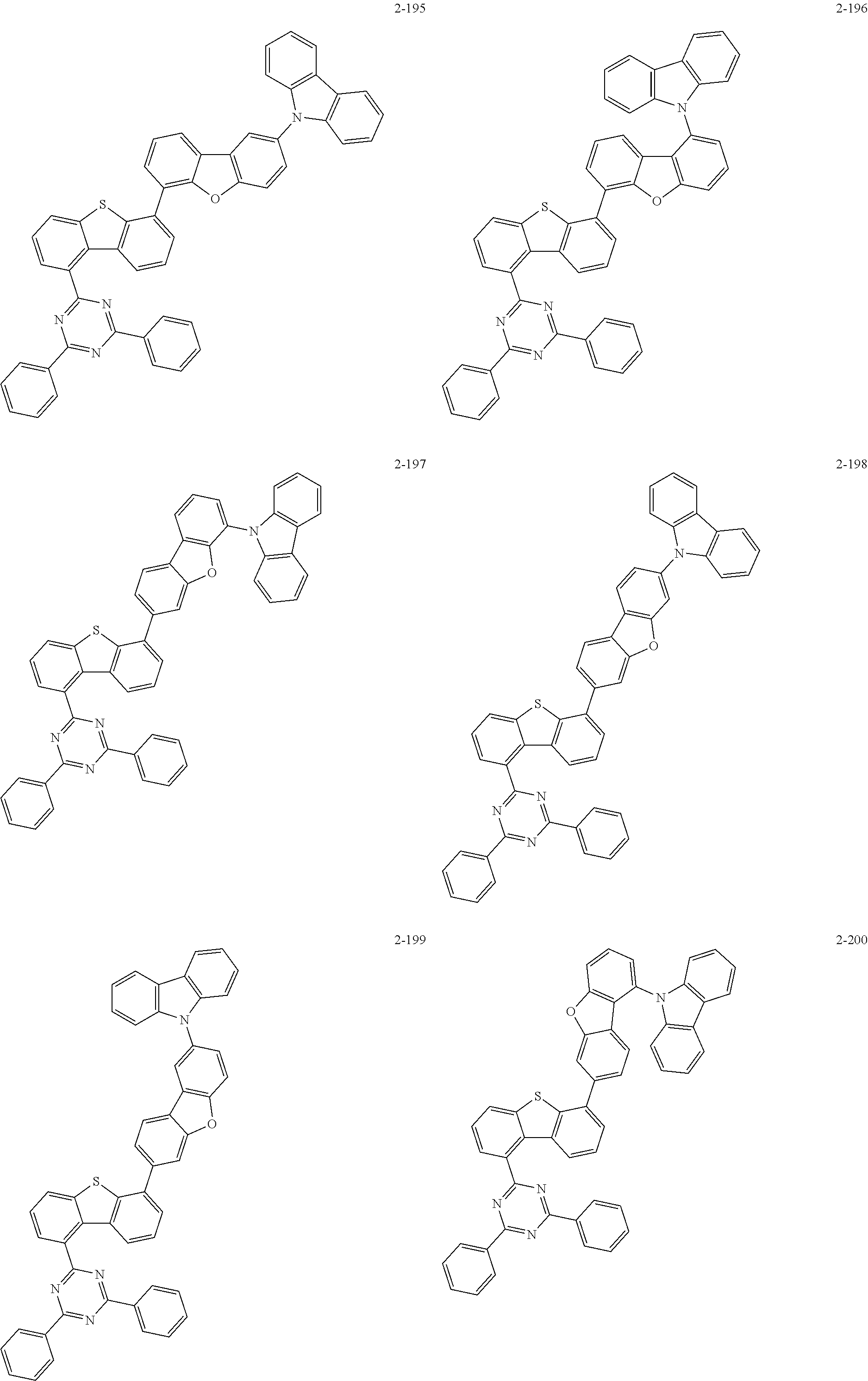

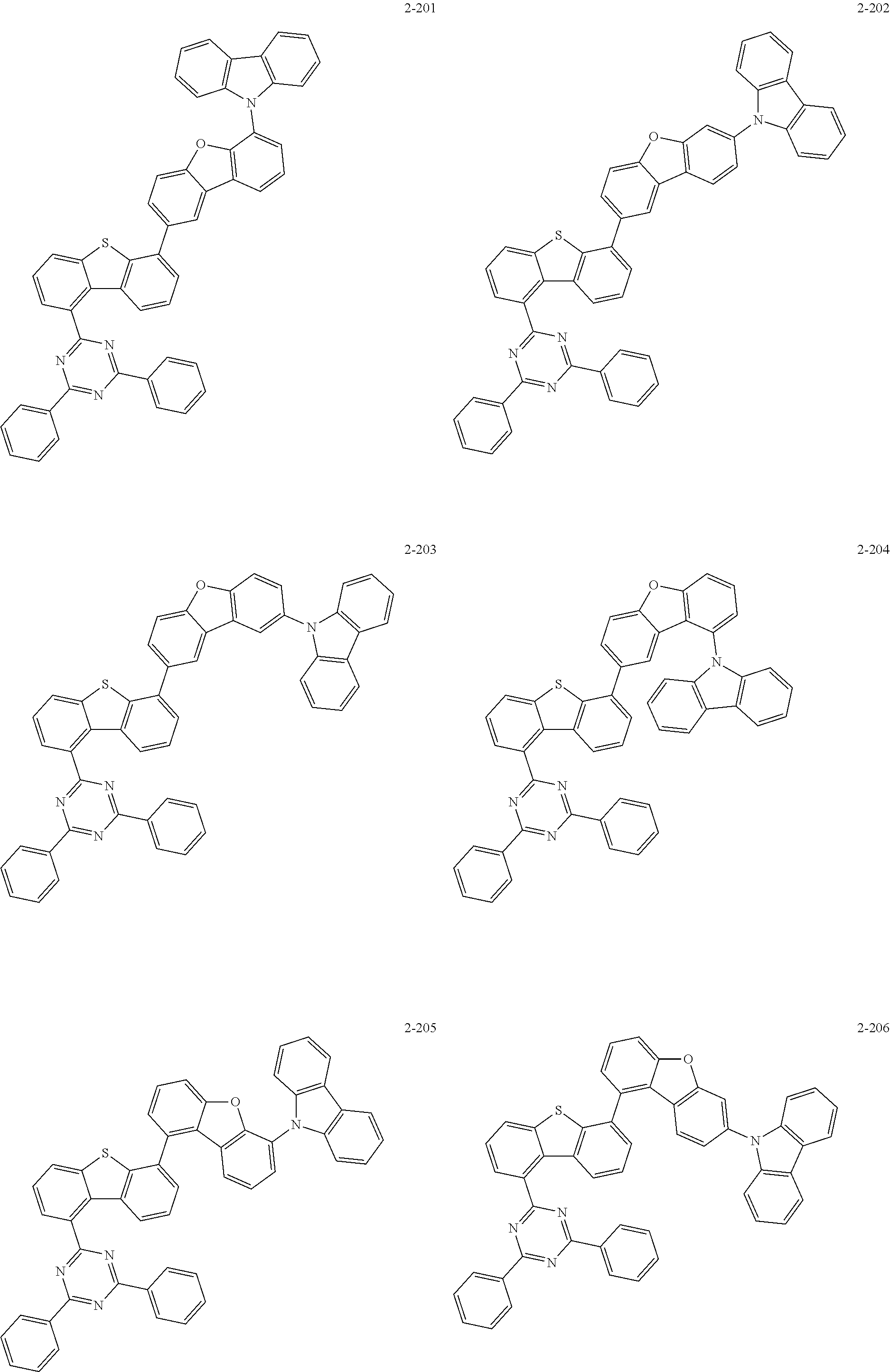

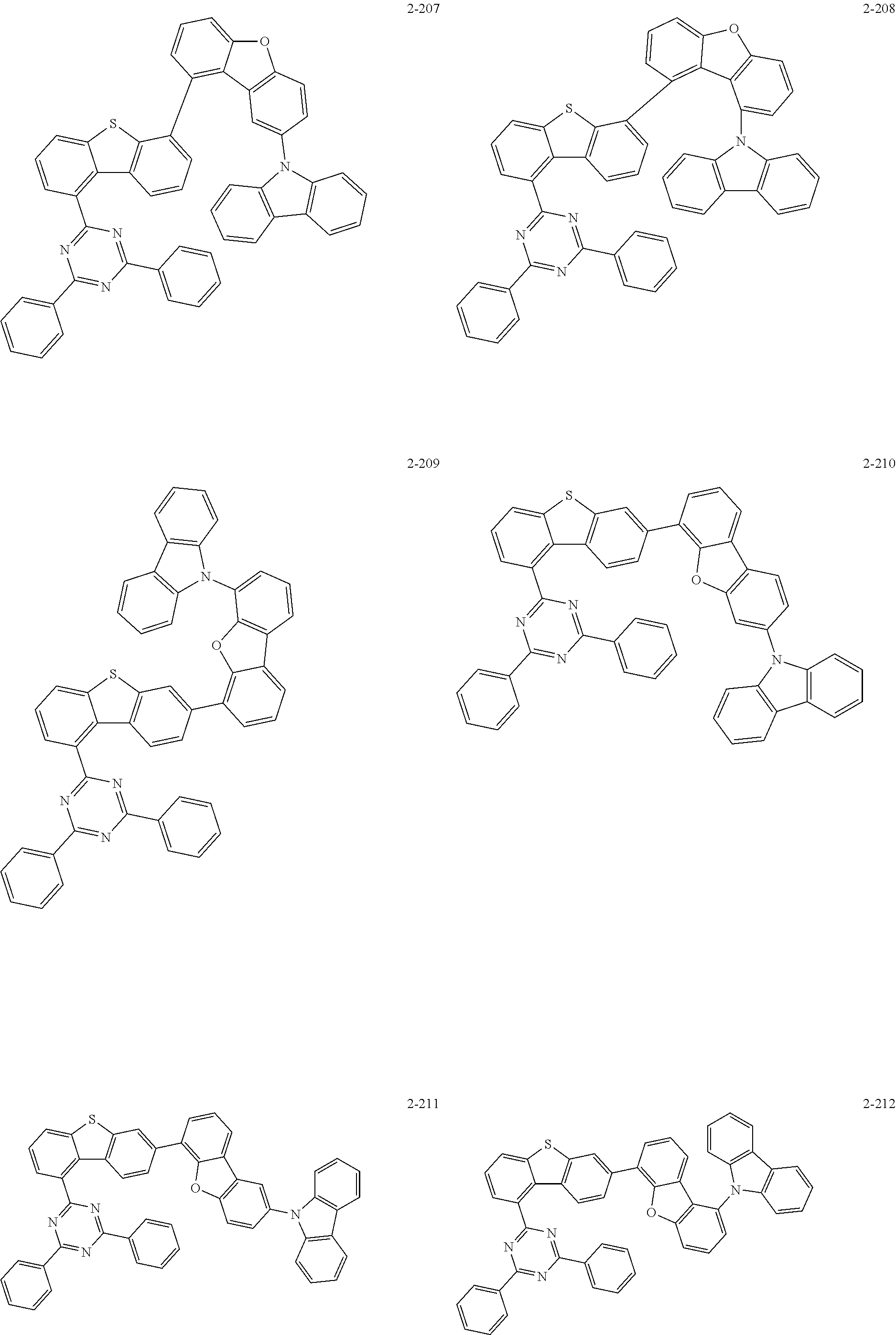

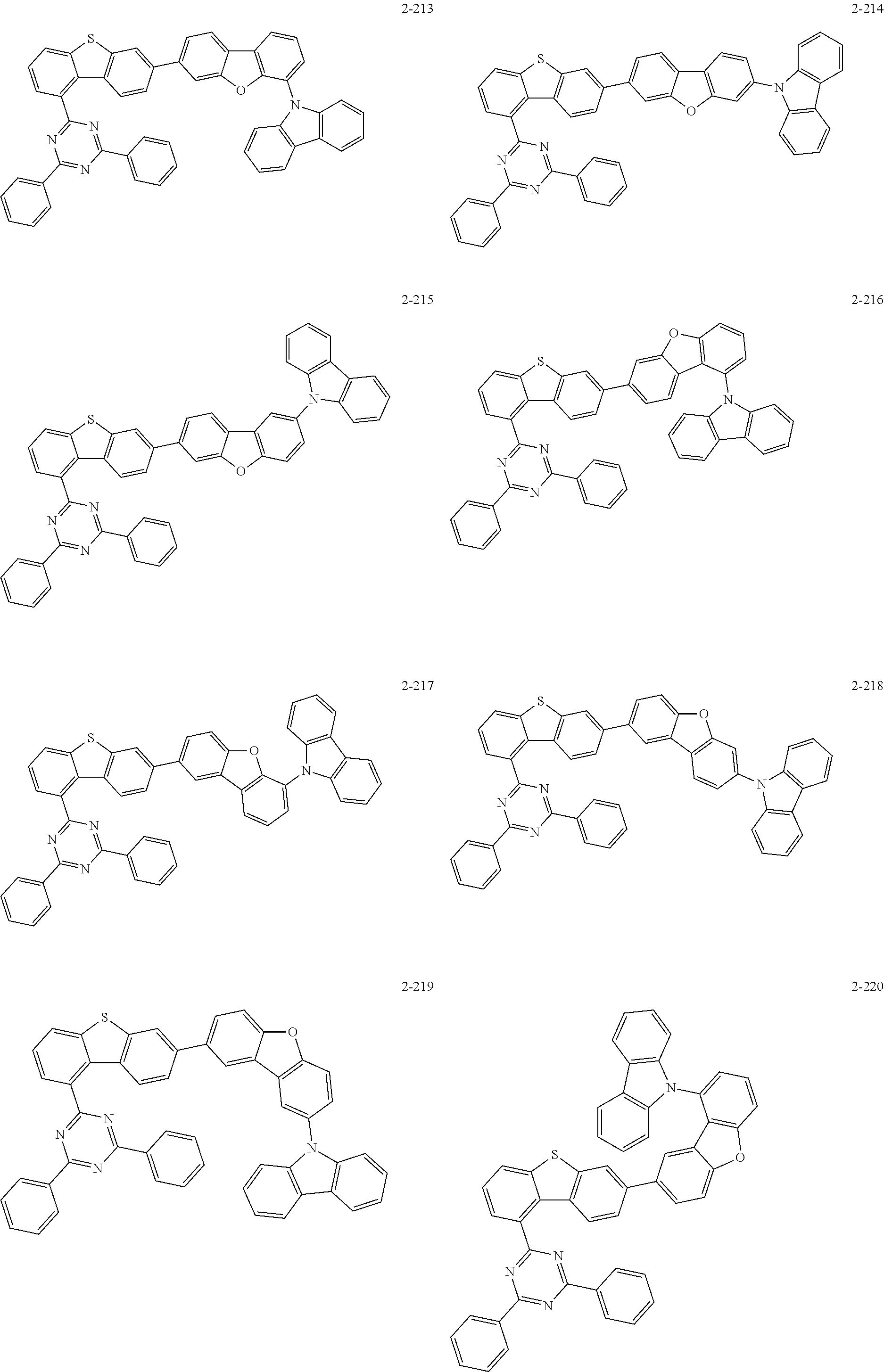

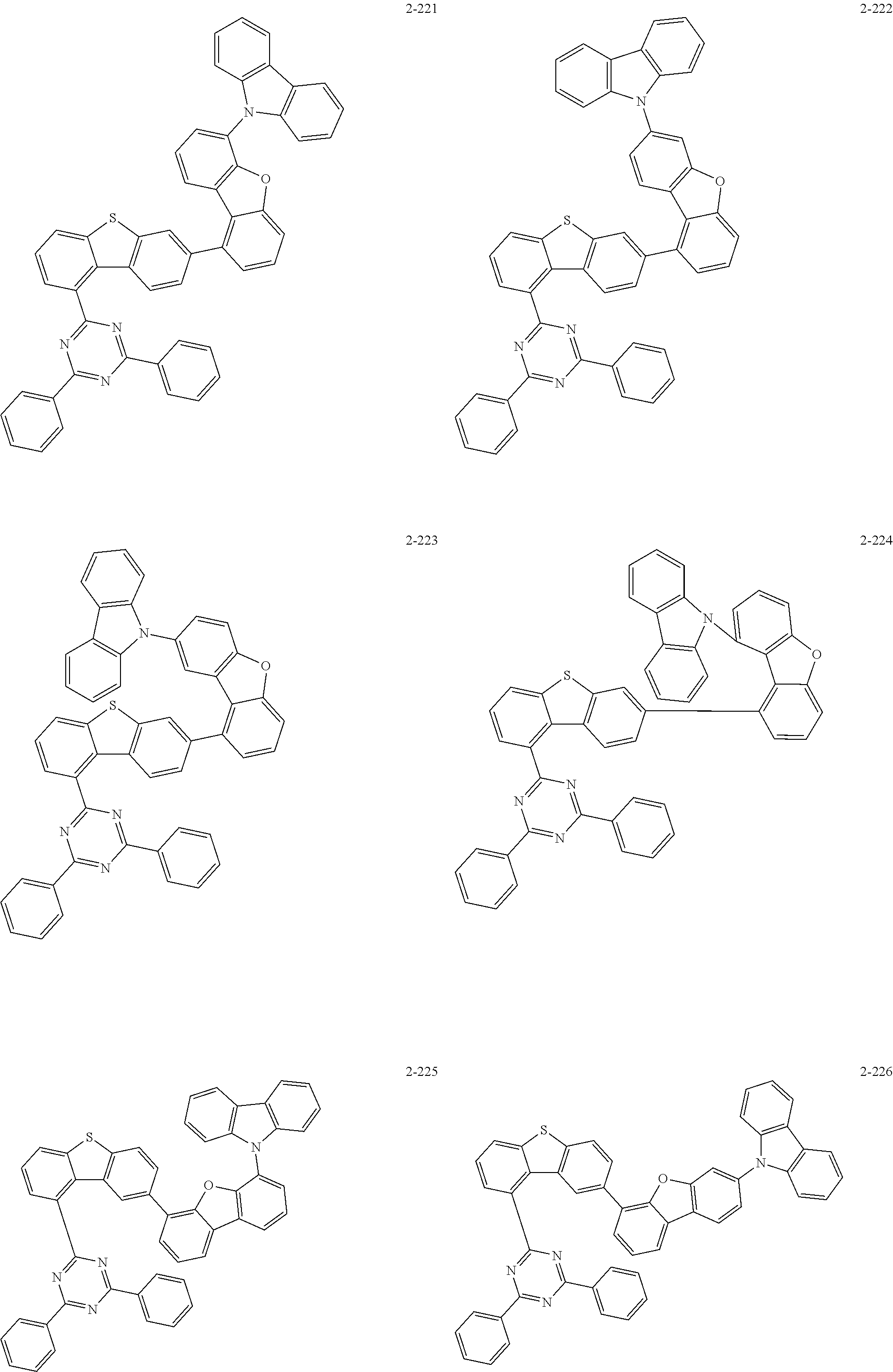

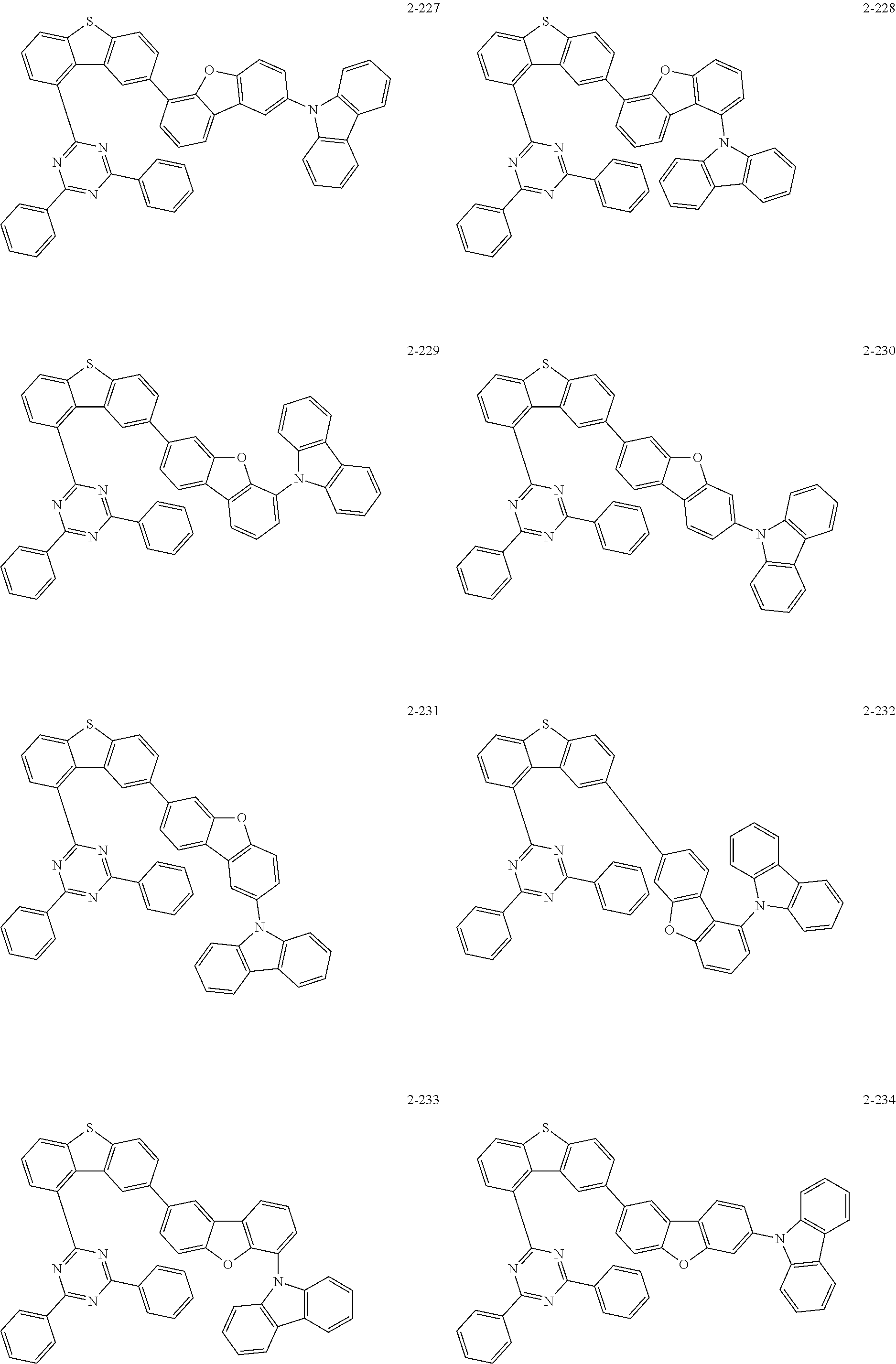

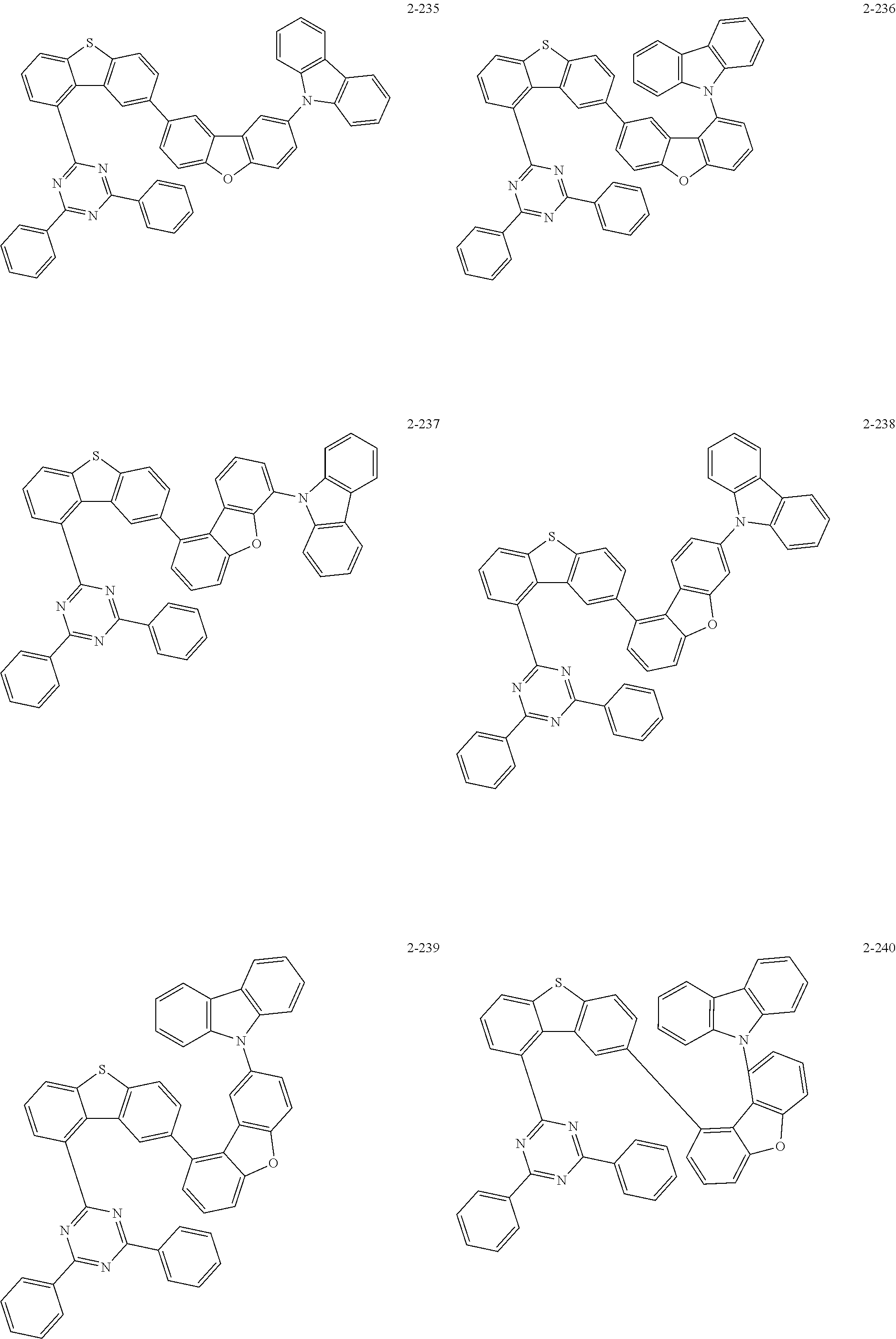

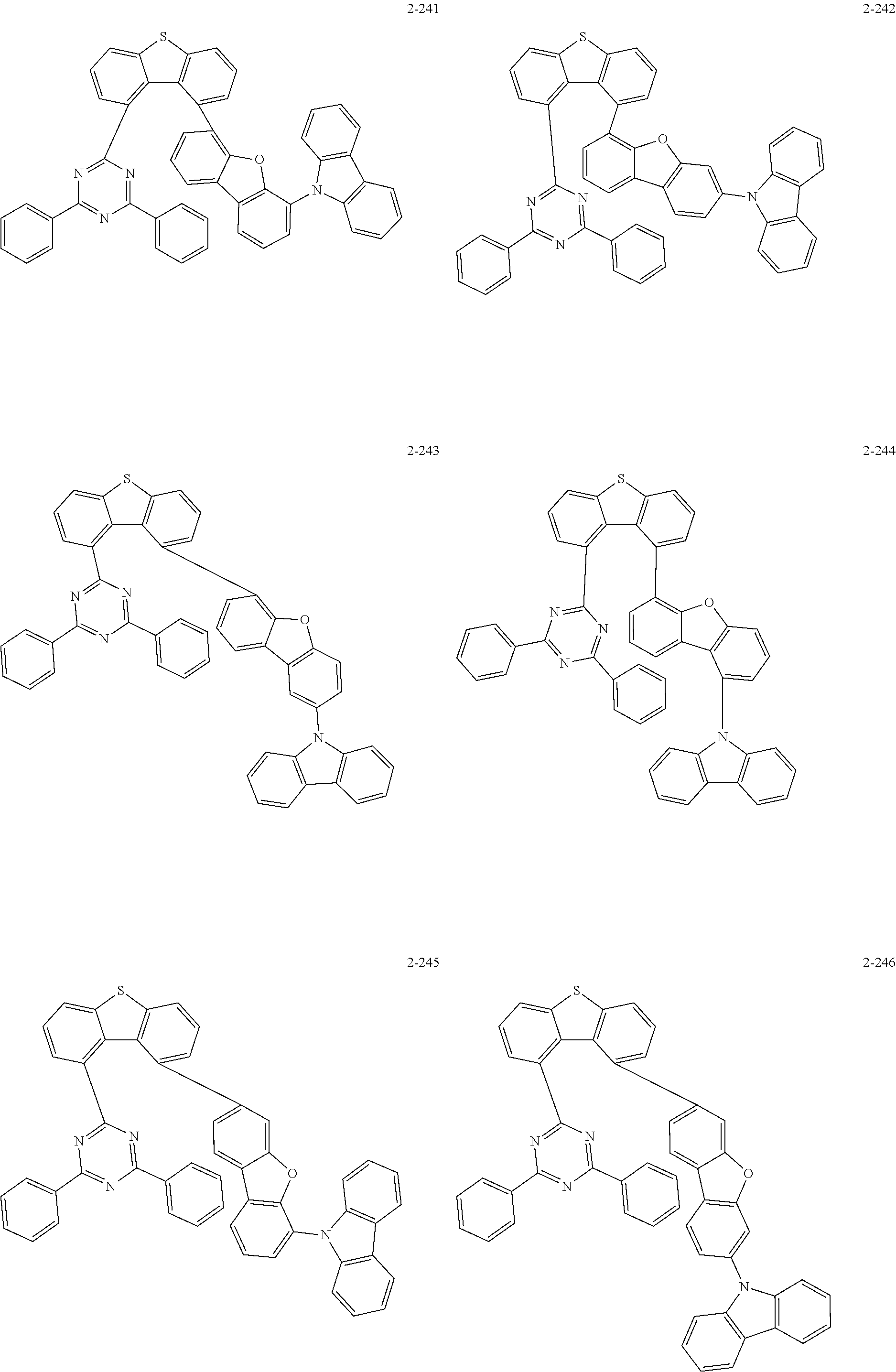

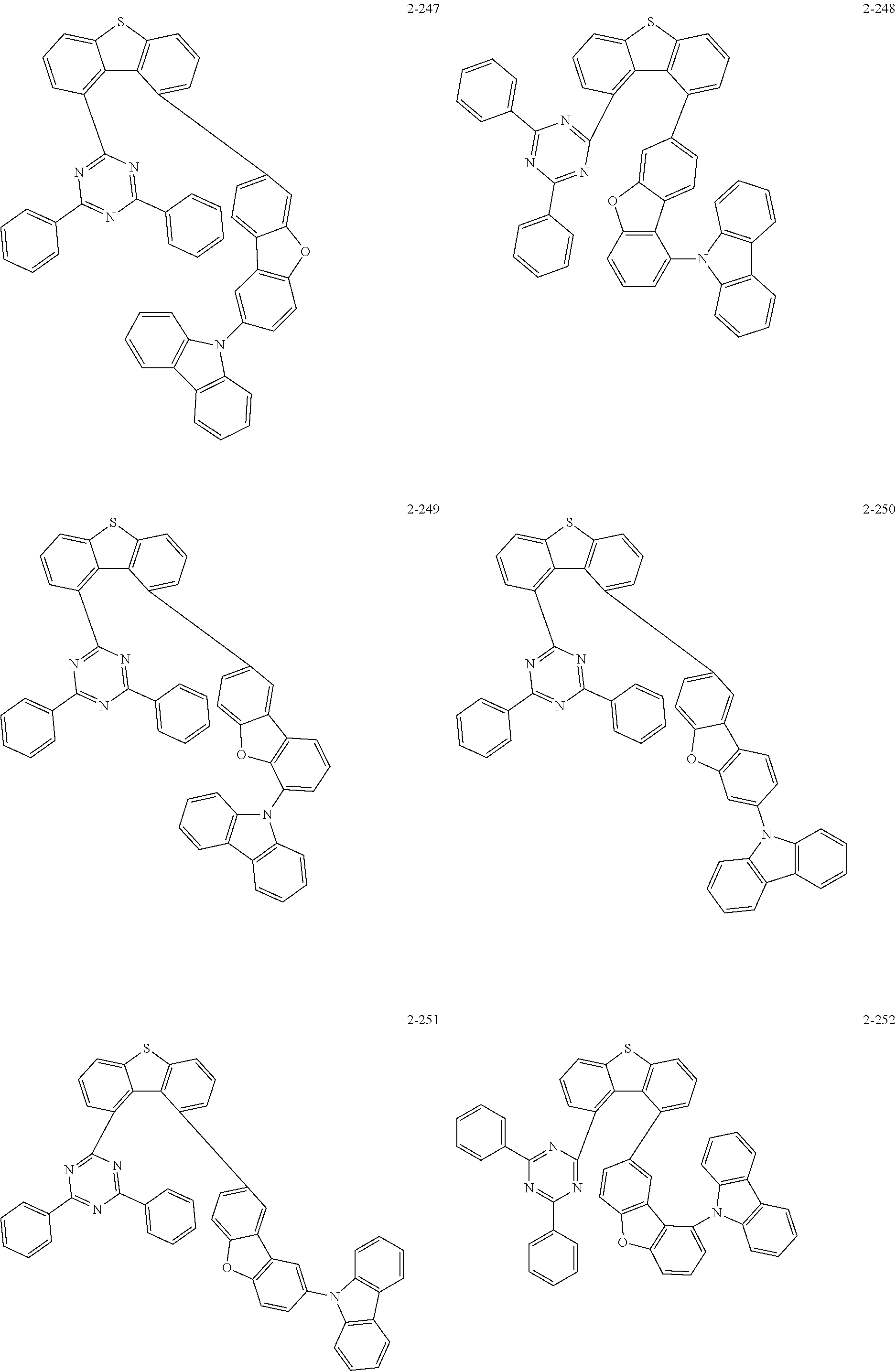

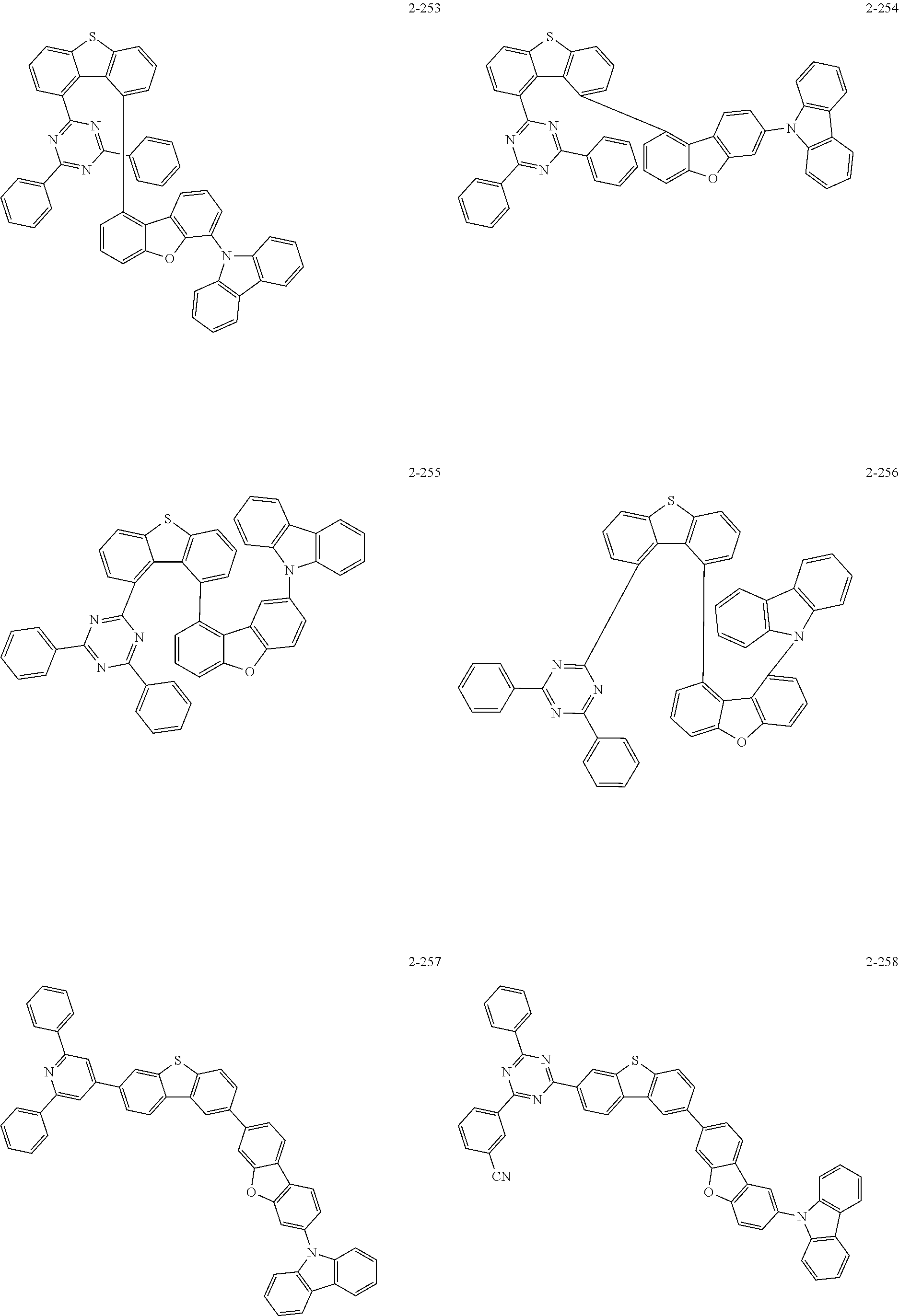

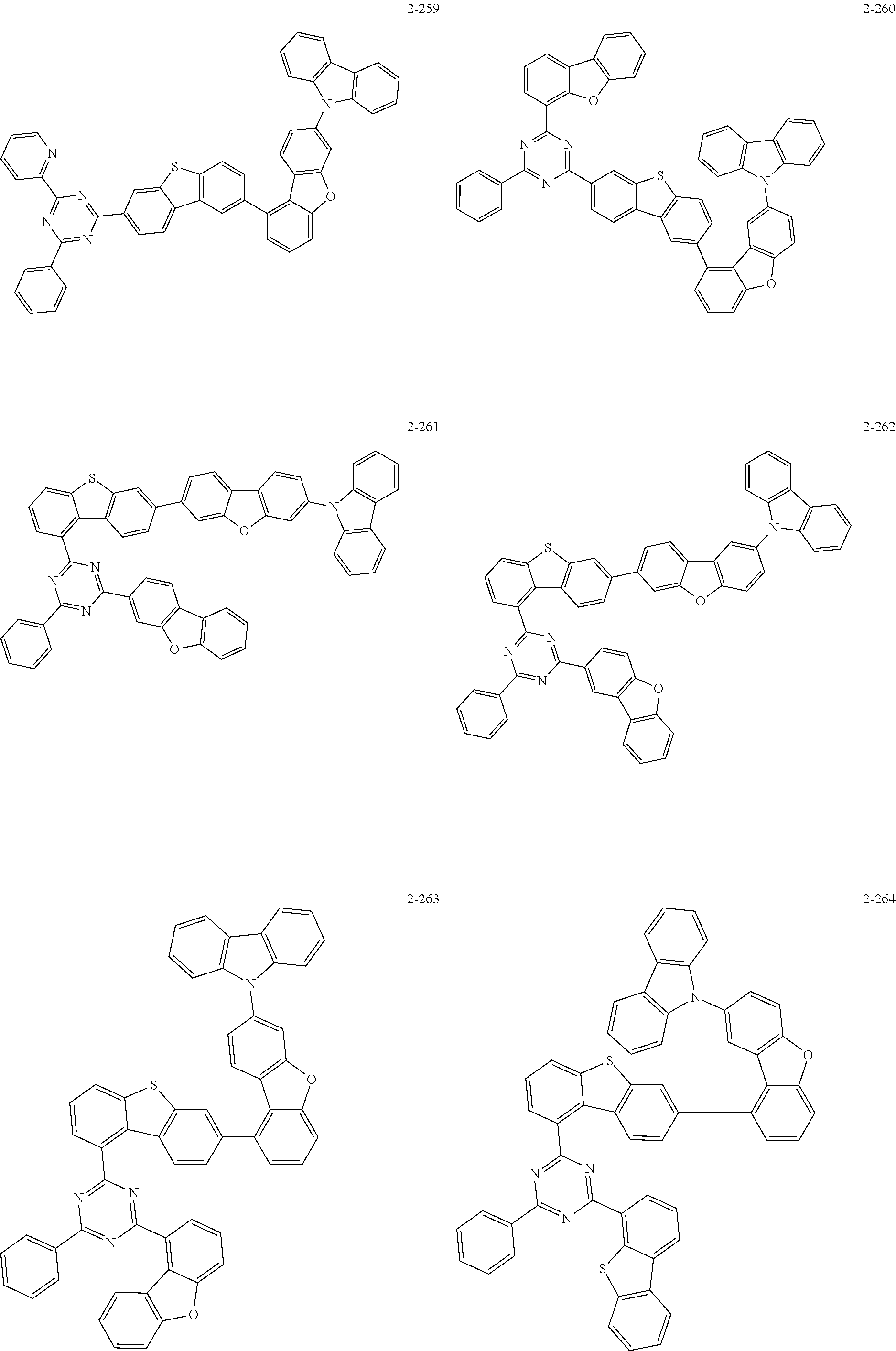

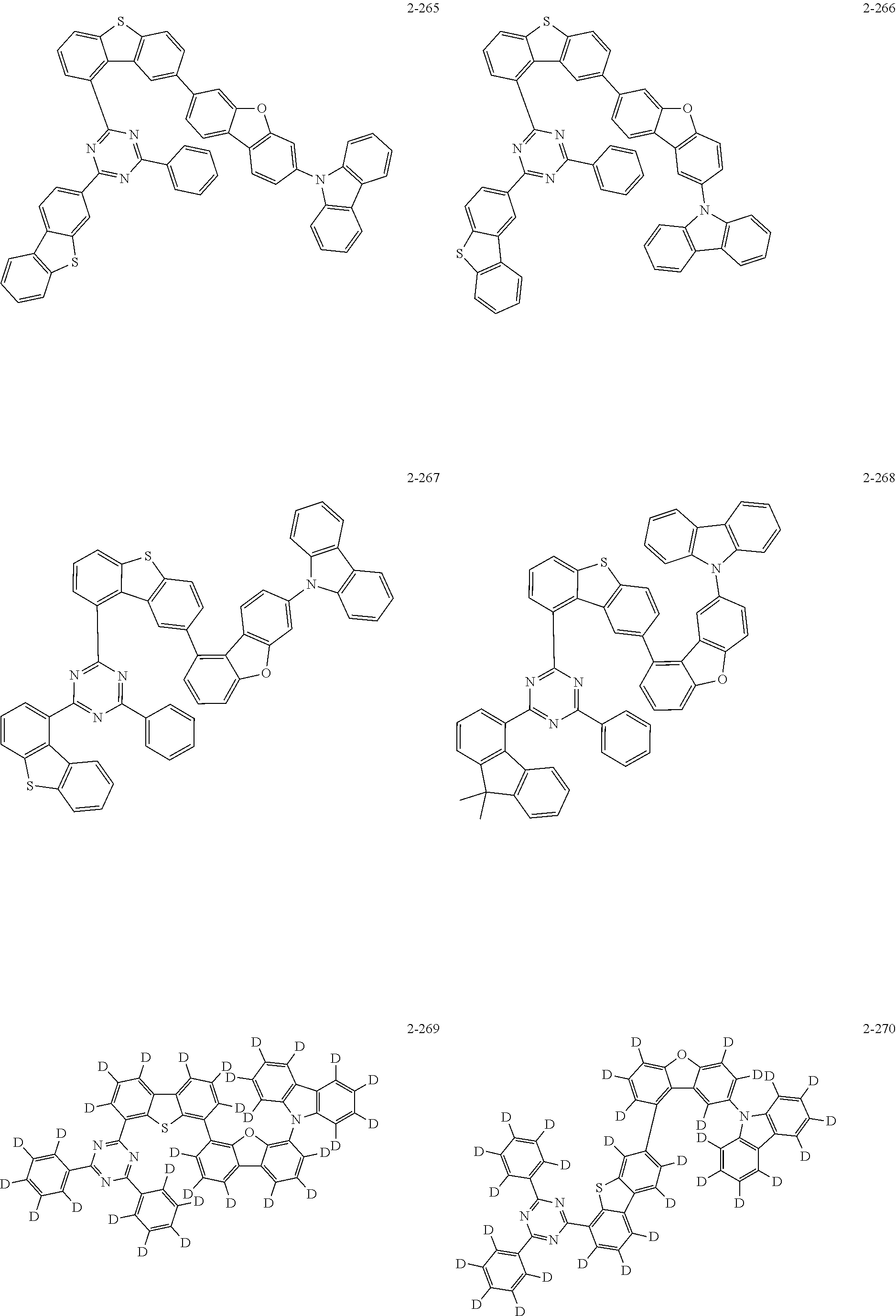

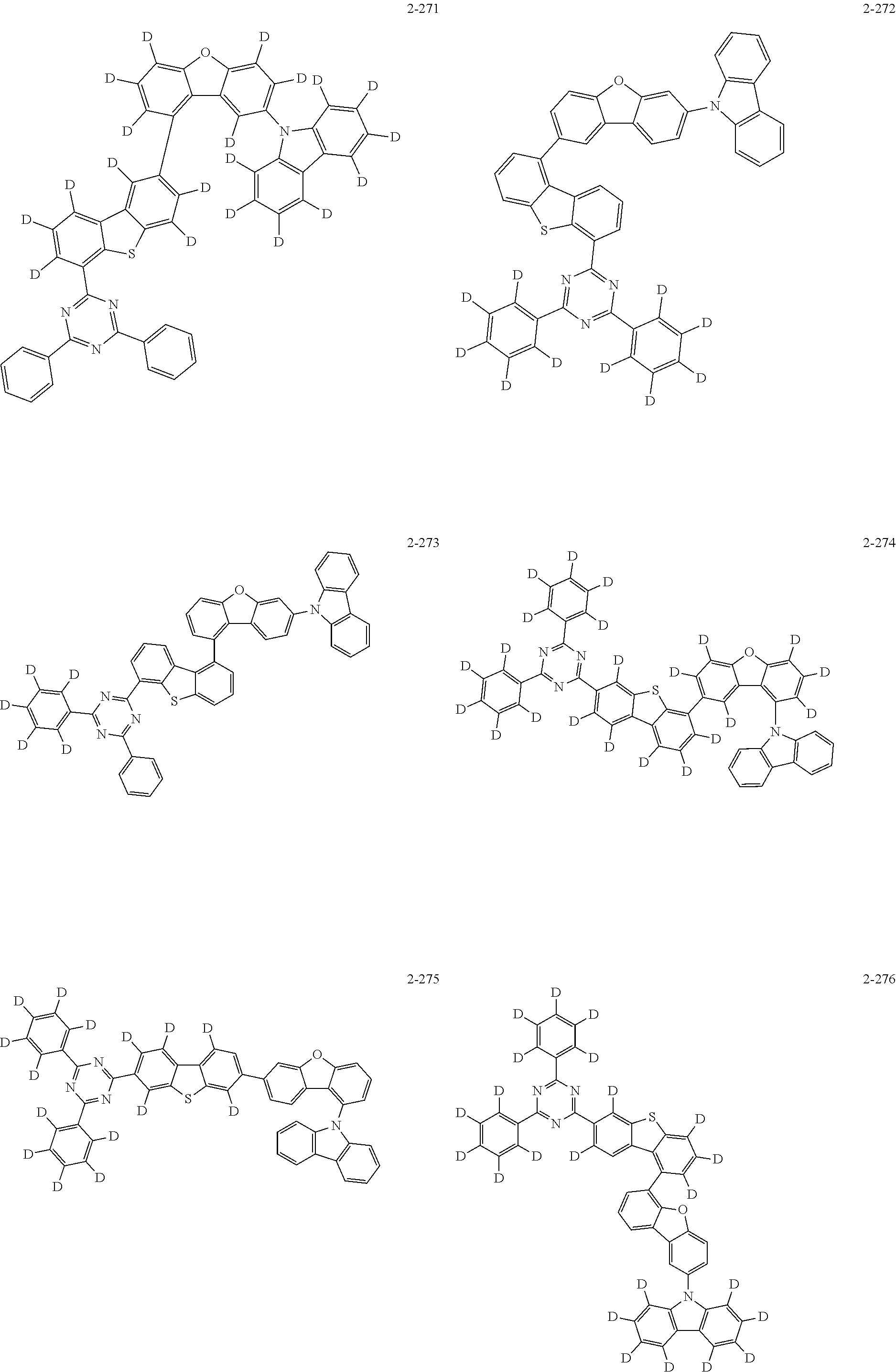

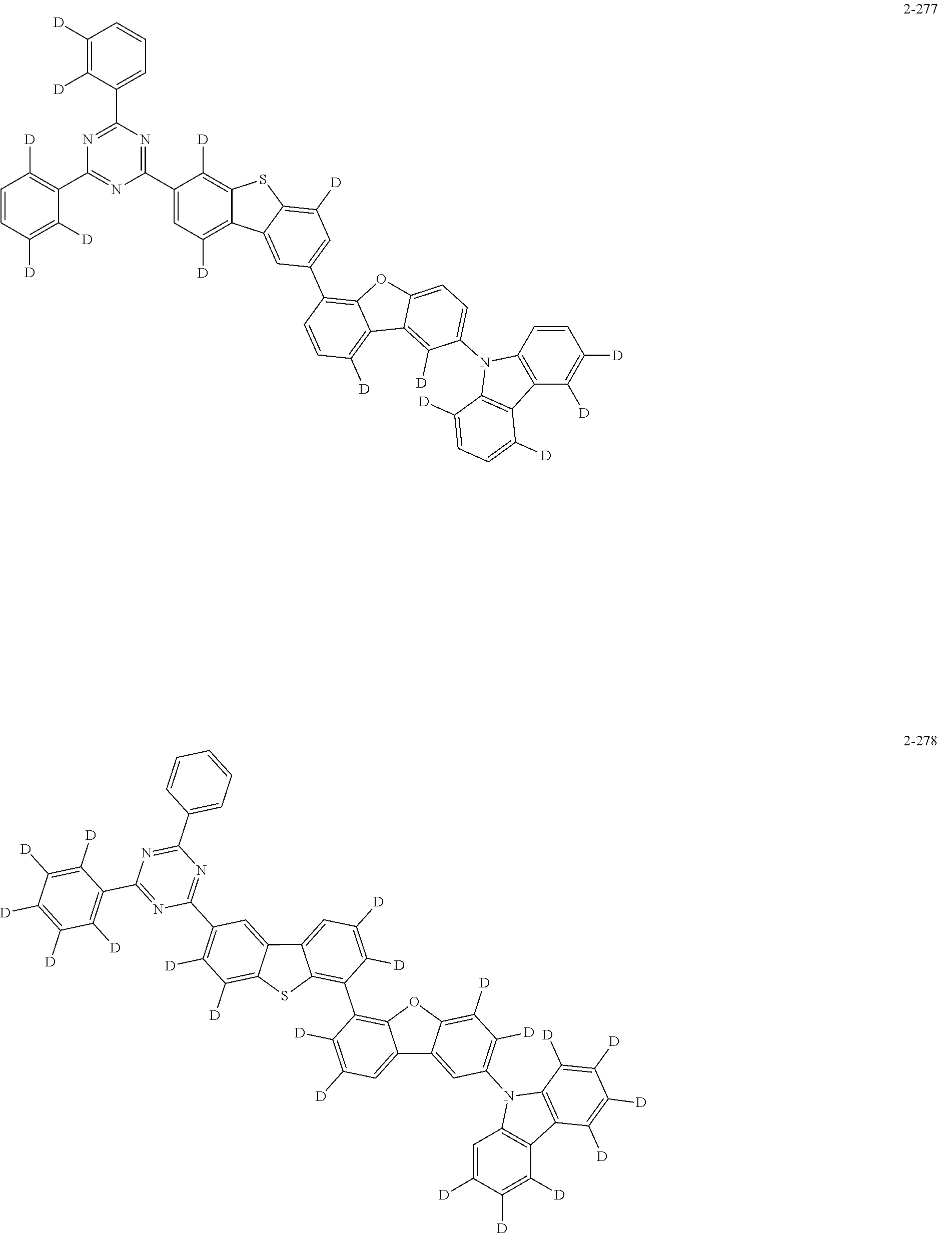 [SMILES: [2H]c1cccc(-c2nc(-c3cc([2H])c4c(sc5c([2H])cc(-c6ccc([2H])c7c6oc6ccc(-n8c9ccc([2H])c([2H])c9c9c([2H])ccc([2H])c98)c([2H])c67)cc54)c3[2H])nc(-c3c([2H])ccc([2H])c3[2H])n2)c1[2H] ; [2H]c1cc2c(oc3c([2H])c([2H])c(-n4c5cc([2H])c([2H])c([2H])c5c5c([2H])c([2H])c([2H])c([2H])c54)cc32)c(-c2c([2H])c([2H])cc3c2sc2c([2H])c([2H])c(-c4nc(-c5ccccc5)nc(-c5c([2H])c([2H])c([2H])c([2H])c5[2H])n4)cc23)c1[2H]]

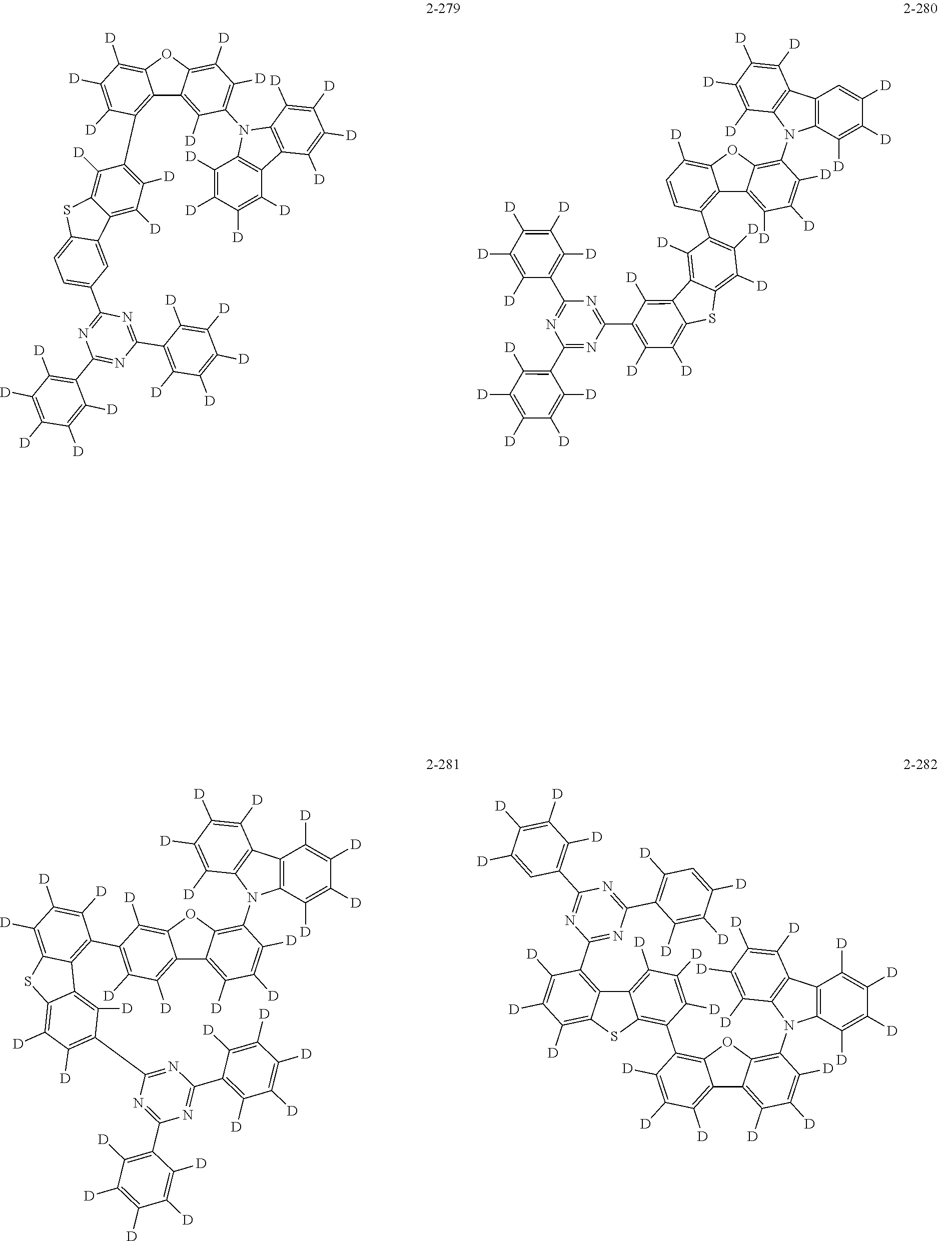

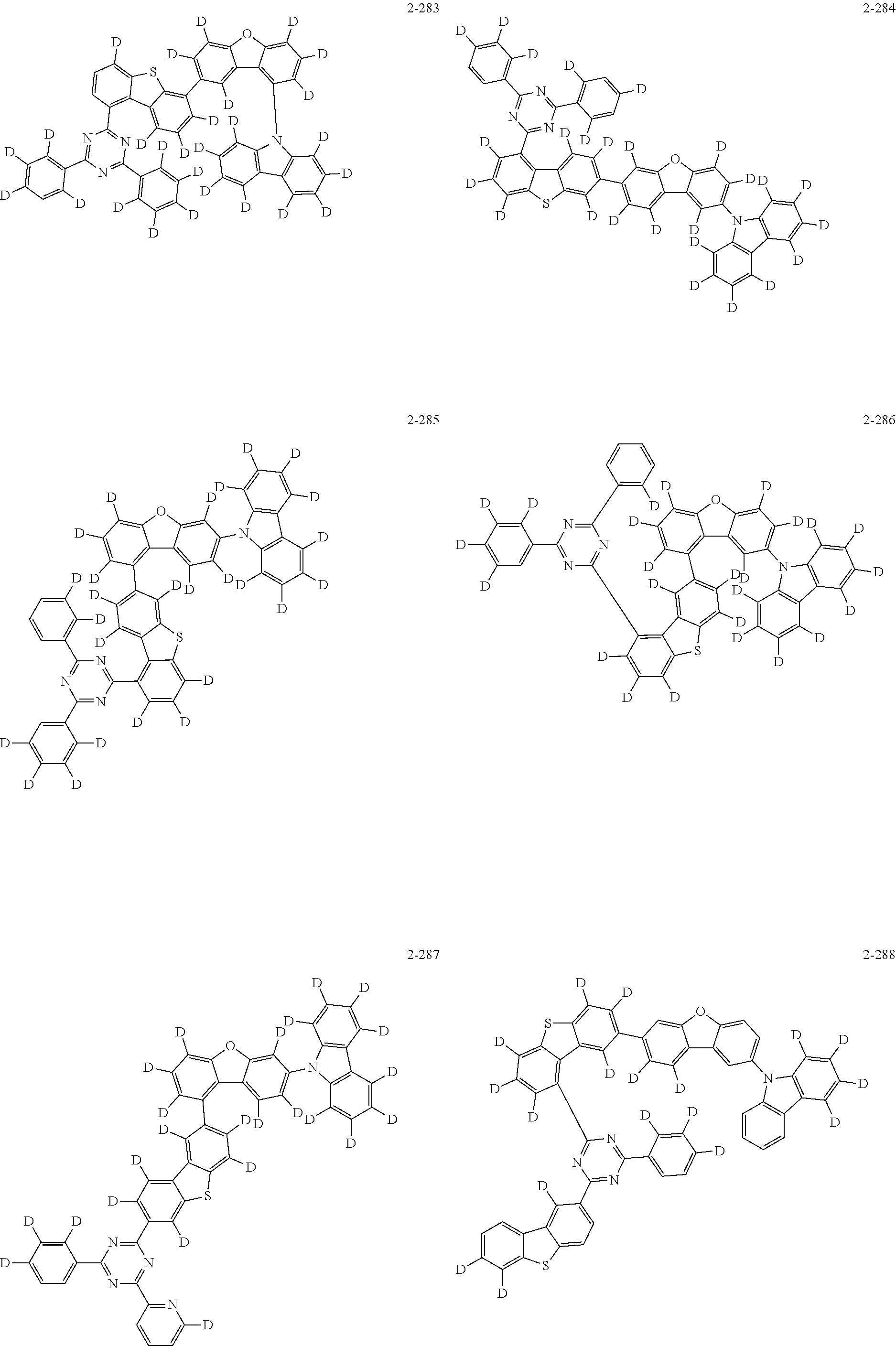

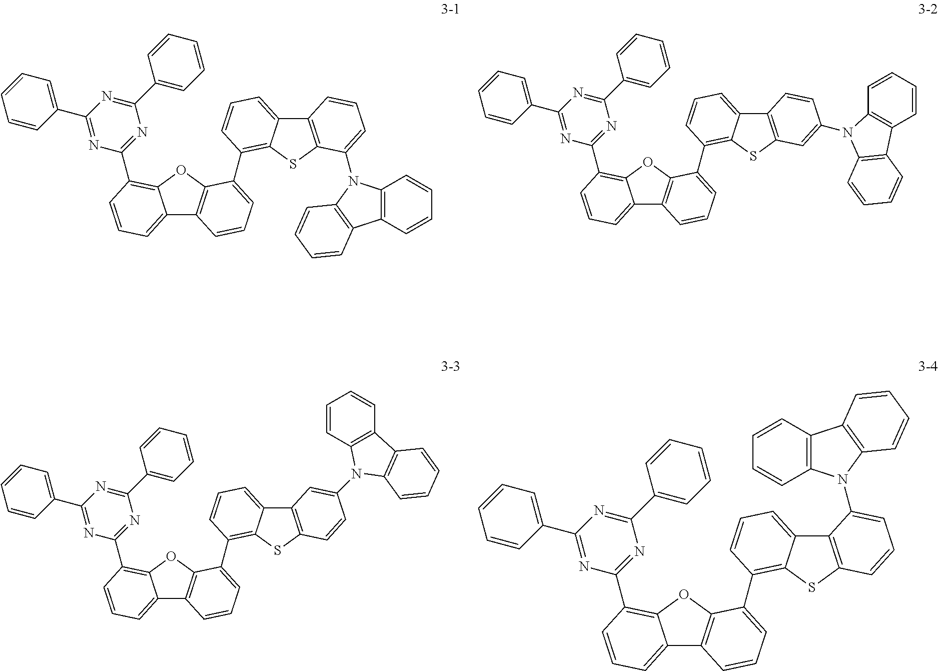 [SMILES: c1ccc(-c2nc(-c3ccccc3)nc(-c3cccc4c3oc3c(-c5cccc6c5sc5c(-n7c8ccccc8c8ccccc87)cccc56)cccc34)n2)cc1 ; c1ccc(-c2nc(-c3ccccc3)nc(-c3cccc4c3oc3c(-c5cccc6c5sc5cc(-n7c8ccccc8c8ccccc87)ccc56)cccc34)n2)cc1 ; c1ccc(-c2nc(-c3ccccc3)nc(-c3cccc4c3oc3c(-c5cccc6c5sc5ccc(-n7c8ccccc8c8ccccc87)cc56)cccc34)n2)cc1 ; c1ccc(-c2nc(-c3ccccc3)nc(-c3cccc4c3oc3c(-c5cccc6c5sc5cccc(-n7c8ccccc8c8ccccc87)c56)cccc34)n2)cc1]

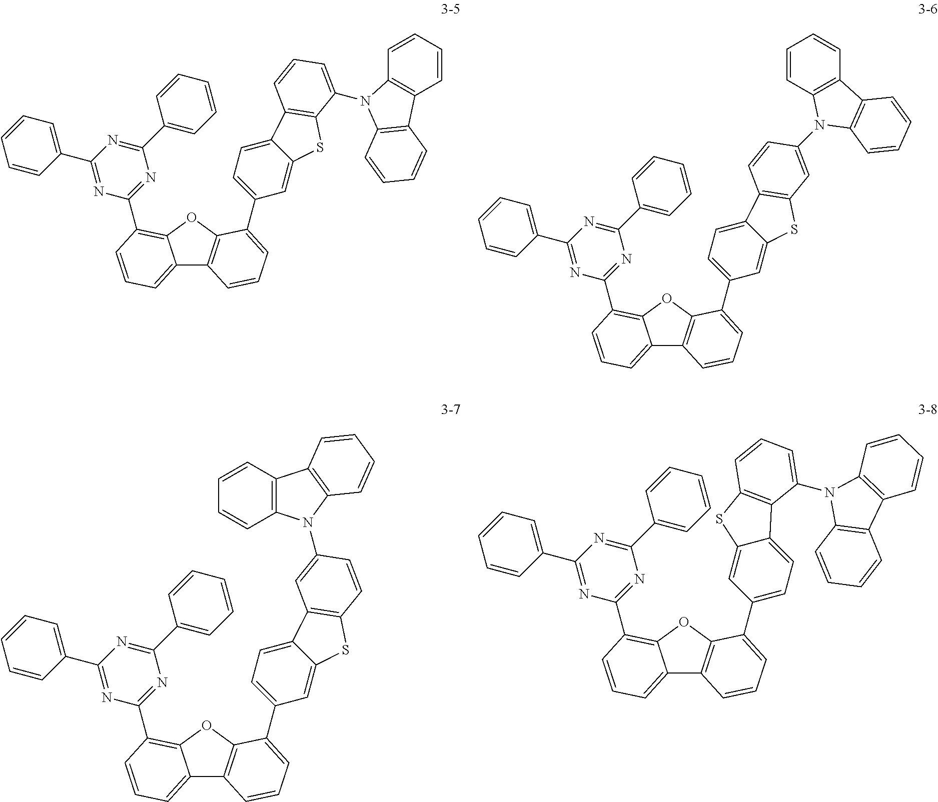 [SMILES: c1ccc(-c2nc(-c3ccccc3)nc(-c3cccc4c3oc3c(-c5ccc6c(c5)sc5c(-n7c8ccccc8c8ccccc87)cccc56)cccc34)n2)cc1 ; c1ccc(-c2nc(-c3ccccc3)nc(-c3cccc4c3oc3c(-c5ccc6c(c5)sc5cc(-n7c8ccccc8c8ccccc87)ccc56)cccc34)n2)cc1 ; c1ccc(-c2nc(-c3ccccc3)nc(-c3cccc4c3oc3c(-c5ccc6c(c5)sc5ccc(-n7c8ccccc8c8ccccc87)cc56)cccc34)n2)cc1 ; c1ccc(-c2nc(-c3ccccc3)nc(-c3cccc4c3oc3c(-c5ccc6c(c5)sc5cccc(-n7c8ccccc8c8ccccc87)c56)cccc34)n2)cc1]

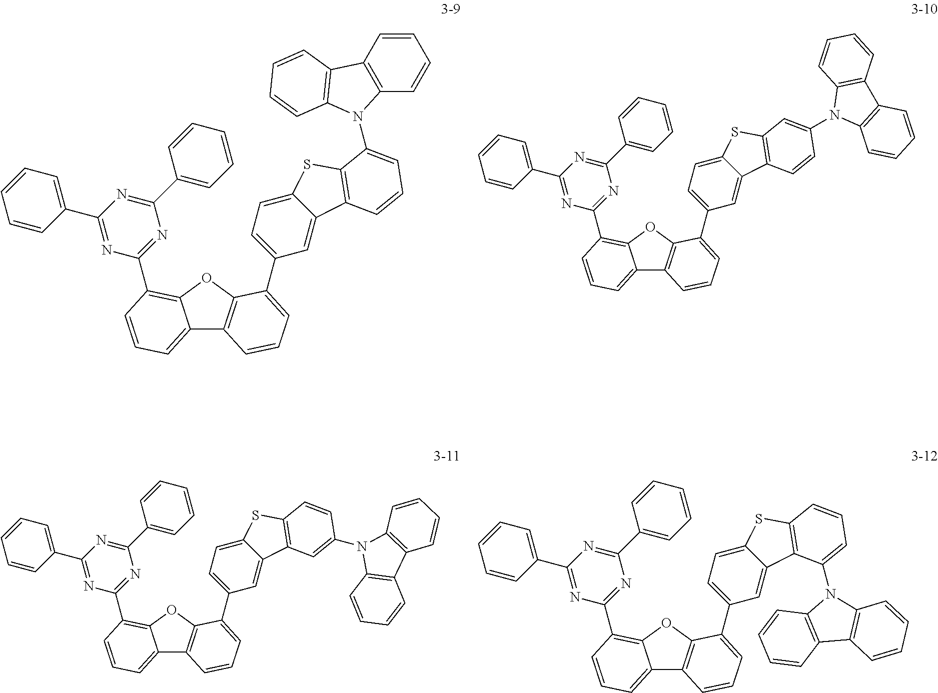 [SMILES: c1ccc(-c2nc(-c3ccccc3)nc(-c3cccc4c3oc3c(-c5ccc6sc7c(-n8c9ccccc9c9ccccc98)cccc7c6c5)cccc34)n2)cc1 ; c1ccc(-c2nc(-c3ccccc3)nc(-c3cccc4c3oc3c(-c5ccc6sc7cc(-n8c9ccccc9c9ccccc98)ccc7c6c5)cccc34)n2)cc1 ; c1ccc(-c2nc(-c3ccccc3)nc(-c3cccc4c3oc3c(-c5ccc6sc7ccc(-n8c9ccccc9c9ccccc98)cc7c6c5)cccc34)n2)cc1 ; c1ccc(-c2nc(-c3ccccc3)nc(-c3cccc4c3oc3c(-c5ccc6sc7cccc(-n8c9ccccc9c9ccccc98)c7c6c5)cccc34)n2)cc1]

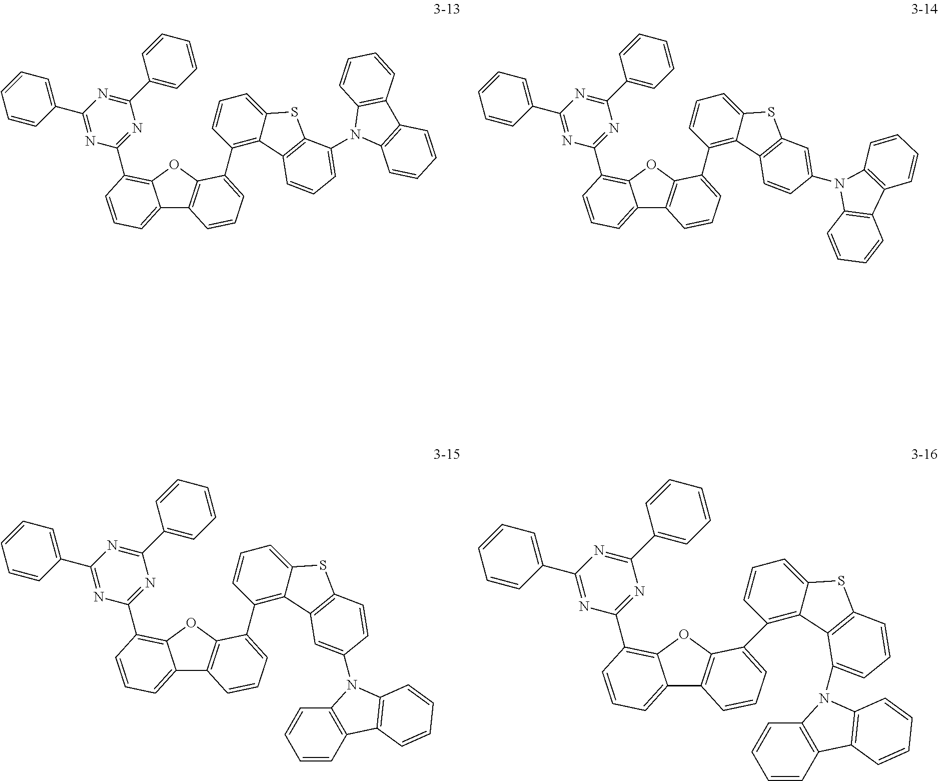 [SMILES: c1ccc(-c2nc(-c3ccccc3)nc(-c3cccc4c3oc3c(-c5cccc6sc7c(-n8c9ccccc9c9ccccc98)cccc7c56)cccc34)n2)cc1 ; c1ccc(-c2nc(-c3ccccc3)nc(-c3cccc4c3oc3c(-c5cccc6sc7cc(-n8c9ccccc9c9ccccc98)ccc7c56)cccc34)n2)cc1 ; c1ccc(-c2nc(-c3ccccc3)nc(-c3cccc4c3oc3c(-c5cccc6sc7ccc(-n8c9ccccc9c9ccccc98)cc7c56)cccc34)n2)cc1 ; c1ccc(-c2nc(-c3ccccc3)nc(-c3cccc4c3oc3c(-c5cccc6sc7cccc(-n8c9ccccc9c9ccccc98)c7c56)cccc34)n2)cc1]

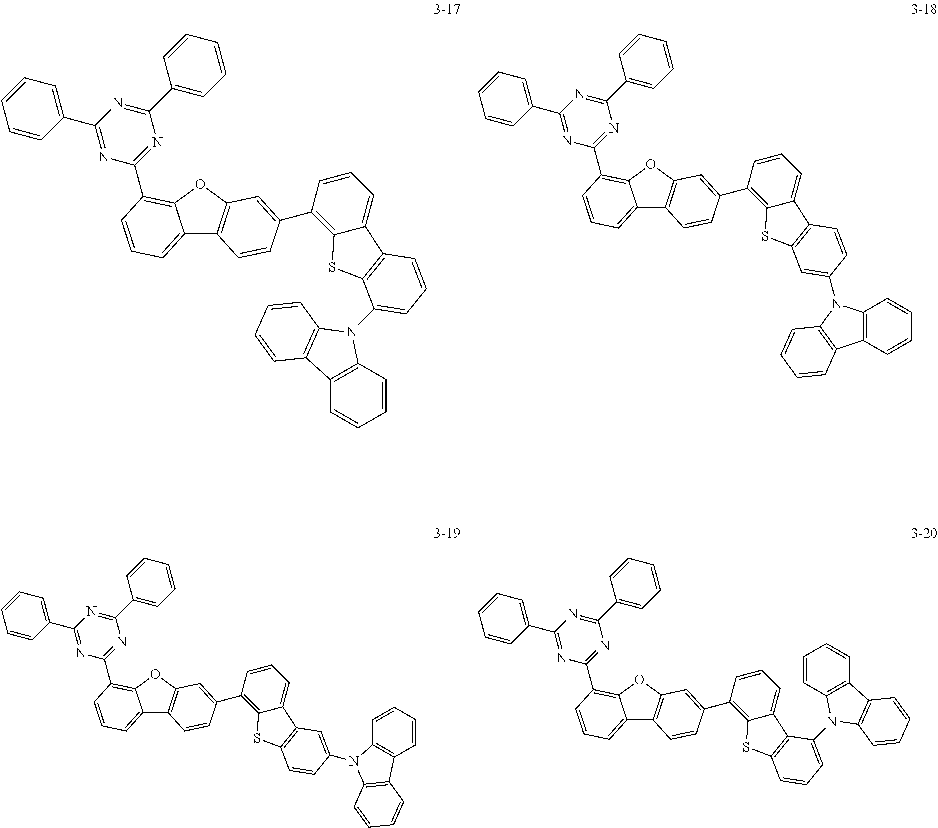 [SMILES: c1ccc(-c2nc(-c3ccccc3)nc(-c3cccc4c3oc3cc(-c5cccc6c5sc5c(-n7c8ccccc8c8ccccc87)cccc56)ccc34)n2)cc1 ; c1ccc(-c2nc(-c3ccccc3)nc(-c3cccc4c3oc3cc(-c5cccc6c5sc5cc(-n7c8ccccc8c8ccccc87)ccc56)ccc34)n2)cc1 ; c1ccc(-c2nc(-c3ccccc3)nc(-c3cccc4c3oc3cc(-c5cccc6c5sc5ccc(-n7c8ccccc8c8ccccc87)cc56)ccc34)n2)cc1 ; c1ccc(-c2nc(-c3ccccc3)nc(-c3cccc4c3oc3cc(-c5cccc6c5sc5cccc(-n7c8ccccc8c8ccccc87)c56)ccc34)n2)cc1]

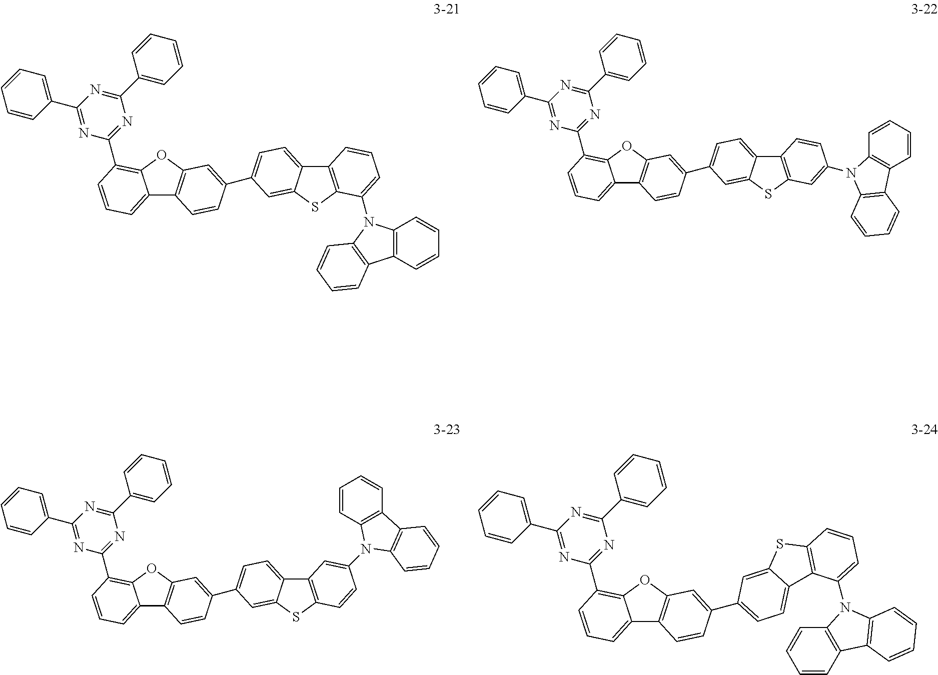 [SMILES: c1ccc(-c2nc(-c3ccccc3)nc(-c3cccc4c3oc3cc(-c5ccc6c(c5)sc5c(-n7c8ccccc8c8ccccc87)cccc56)ccc34)n2)cc1 ; c1ccc(-c2nc(-c3ccccc3)nc(-c3cccc4c3oc3cc(-c5ccc6c(c5)sc5cc(-n7c8ccccc8c8ccccc87)ccc56)ccc34)n2)cc1 ; c1ccc(-c2nc(-c3ccccc3)nc(-c3cccc4c3oc3cc(-c5ccc6c(c5)sc5ccc(-n7c8ccccc8c8ccccc87)cc56)ccc34)n2)cc1 ; c1ccc(-c2nc(-c3ccccc3)nc(-c3cccc4c3oc3cc(-c5ccc6c(c5)sc5cccc(-n7c8ccccc8c8ccccc87)c56)ccc34)n2)cc1]

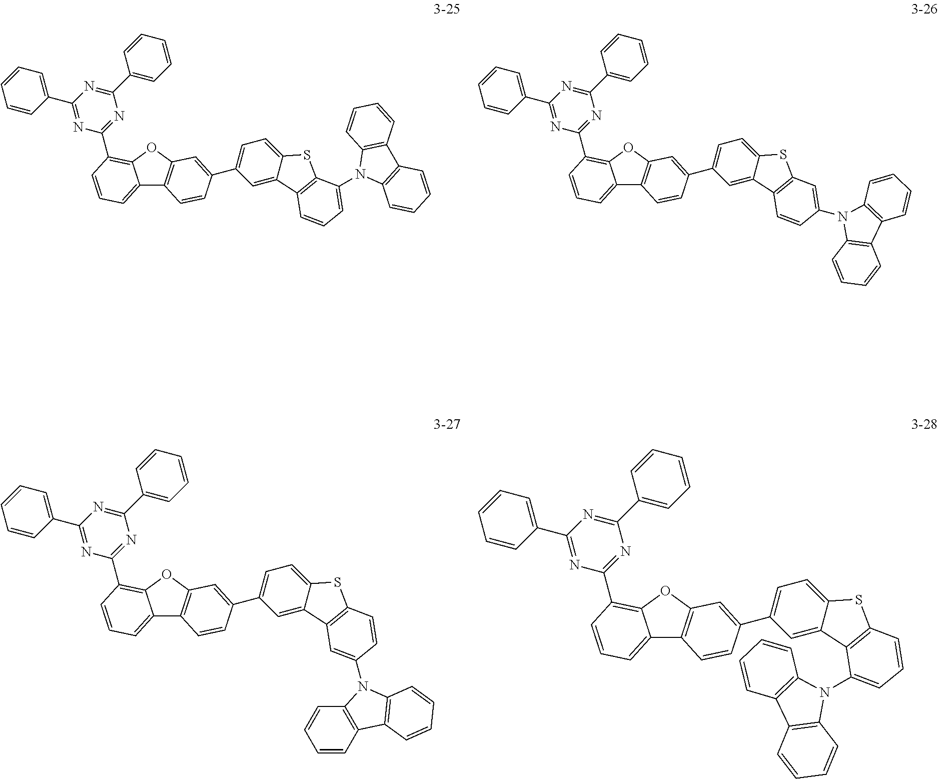 [SMILES: c1ccc(-c2nc(-c3ccccc3)nc(-c3cccc4c3oc3cc(-c5ccc6sc7c(-n8c9ccccc9c9ccccc98)cccc7c6c5)ccc34)n2)cc1 ; c1ccc(-c2nc(-c3ccccc3)nc(-c3cccc4c3oc3cc(-c5ccc6sc7cc(-n8c9ccccc9c9ccccc98)ccc7c6c5)ccc34)n2)cc1 ; c1ccc(-c2nc(-c3ccccc3)nc(-c3cccc4c3oc3cc(-c5ccc6sc7ccc(-n8c9ccccc9c9ccccc98)cc7c6c5)ccc34)n2)cc1 ; c1ccc(-c2nc(-c3ccccc3)nc(-c3cccc4c3oc3cc(-c5ccc6sc7cccc(-n8c9ccccc9c9ccccc98)c7c6c5)ccc34)n2)cc1]

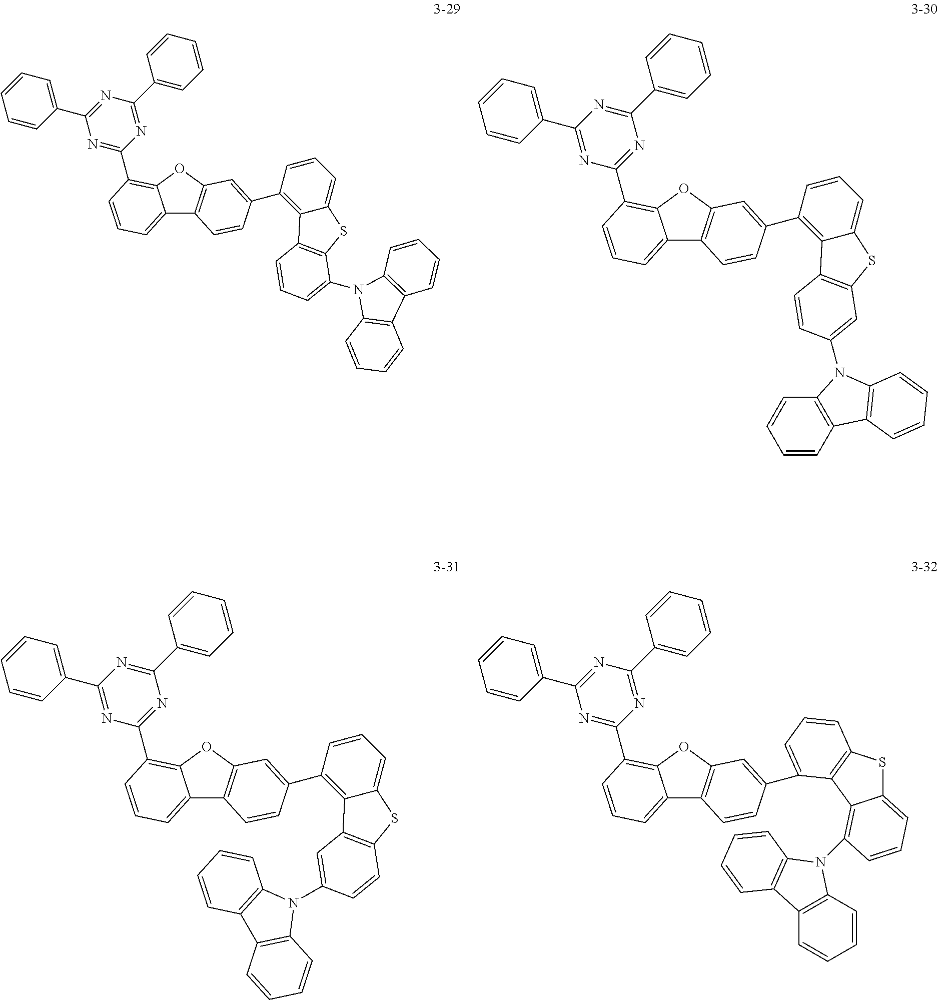 [SMILES: c1ccc(-c2nc(-c3ccccc3)nc(-c3cccc4c3oc3cc(-c5cccc6sc7c(-n8c9ccccc9c9ccccc98)cccc7c56)ccc34)n2)cc1 ; c1ccc(-c2nc(-c3ccccc3)nc(-c3cccc4c3oc3cc(-c5cccc6sc7cc(-n8c9ccccc9c9ccccc98)ccc7c56)ccc34)n2)cc1 ; c1ccc(-c2nc(-c3ccccc3)nc(-c3cccc4c3oc3cc(-c5cccc6sc7ccc(-n8c9ccccc9c9ccccc98)cc7c56)ccc34)n2)cc1 ; c1ccc(-c2nc(-c3ccccc3)nc(-c3cccc4c3oc3cc(-c5cccc6sc7cccc(-n8c9ccccc9c9ccccc98)c7c56)ccc34)n2)cc1]

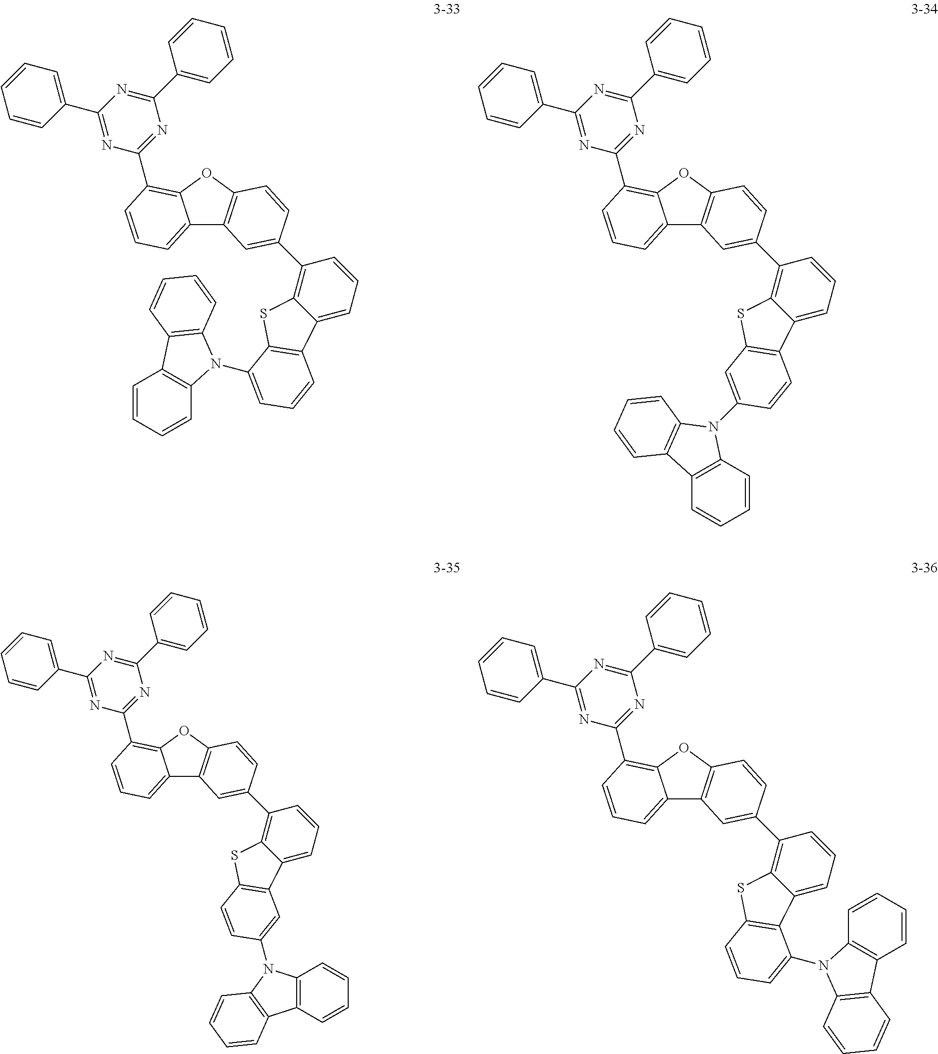 [SMILES: c1ccc(-c2nc(-c3ccccc3)nc(-c3cccc4c3oc3ccc(-c5cccc6c5sc5c(-n7c8ccccc8c8ccccc87)cccc56)cc34)n2)cc1 ; c1ccc(-c2nc(-c3ccccc3)nc(-c3cccc4c3oc3ccc(-c5cccc6c5sc5cc(-n7c8ccccc8c8ccccc87)ccc56)cc34)n2)cc1 ; c1ccc(-c2nc(-c3ccccc3)nc(-c3cccc4c3oc3ccc(-c5cccc6c5sc5ccc(-n7c8ccccc8c8ccccc87)cc56)cc34)n2)cc1 ; c1ccc(-c2nc(-c3ccccc3)nc(-c3cccc4c3oc3ccc(-c5cccc6c5sc5cccc(-n7c8ccccc8c8ccccc87)c56)cc34)n2)cc1]

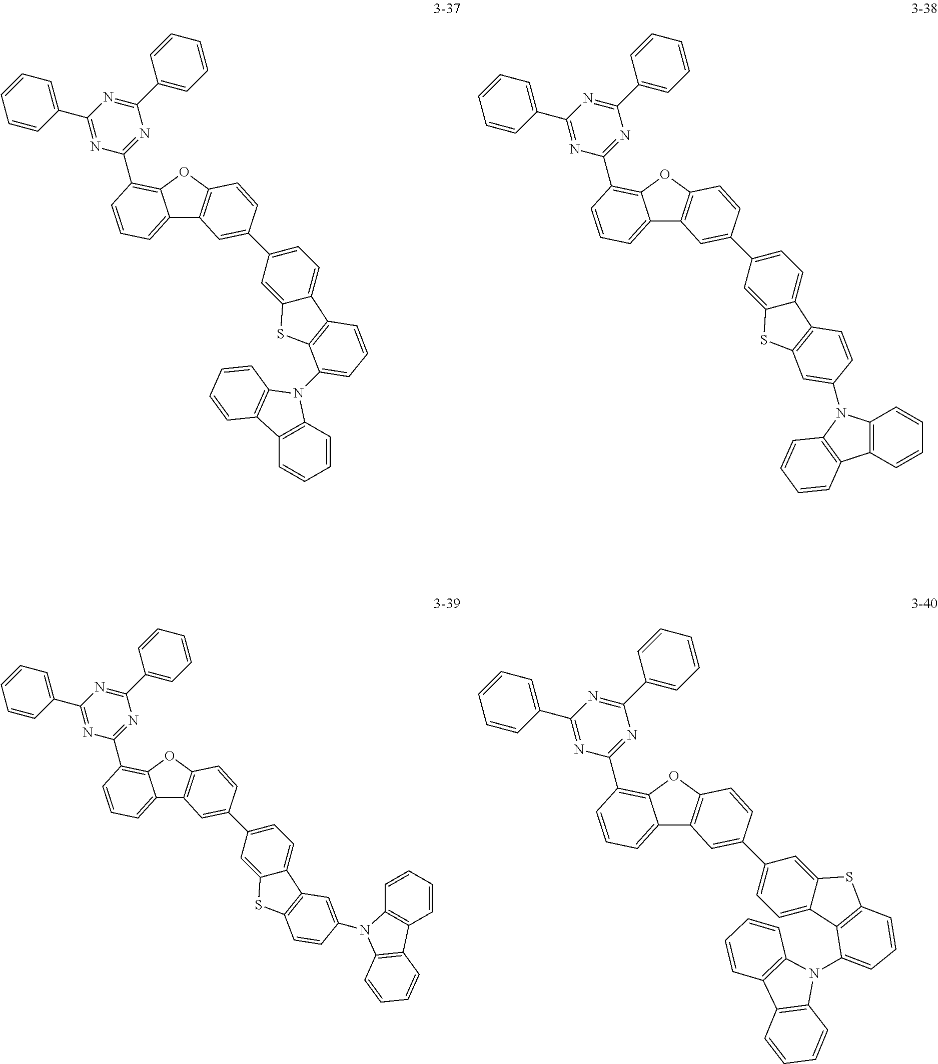 [SMILES: c1ccc(-c2nc(-c3ccccc3)nc(-c3cccc4c3oc3ccc(-c5ccc6c(c5)sc5c(-n7c8ccccc8c8ccccc87)cccc56)cc34)n2)cc1 ; c1ccc(-c2nc(-c3ccccc3)nc(-c3cccc4c3oc3ccc(-c5ccc6c(c5)sc5cc(-n7c8ccccc8c8ccccc87)ccc56)cc34)n2)cc1 ; c1ccc(-c2nc(-c3ccccc3)nc(-c3cccc4c3oc3ccc(-c5ccc6c(c5)sc5ccc(-n7c8ccccc8c8ccccc87)cc56)cc34)n2)cc1 ; c1ccc(-c2nc(-c3ccccc3)nc(-c3cccc4c3oc3ccc(-c5ccc6c(c5)sc5cccc(-n7c8ccccc8c8ccccc87)c56)cc34)n2)cc1]

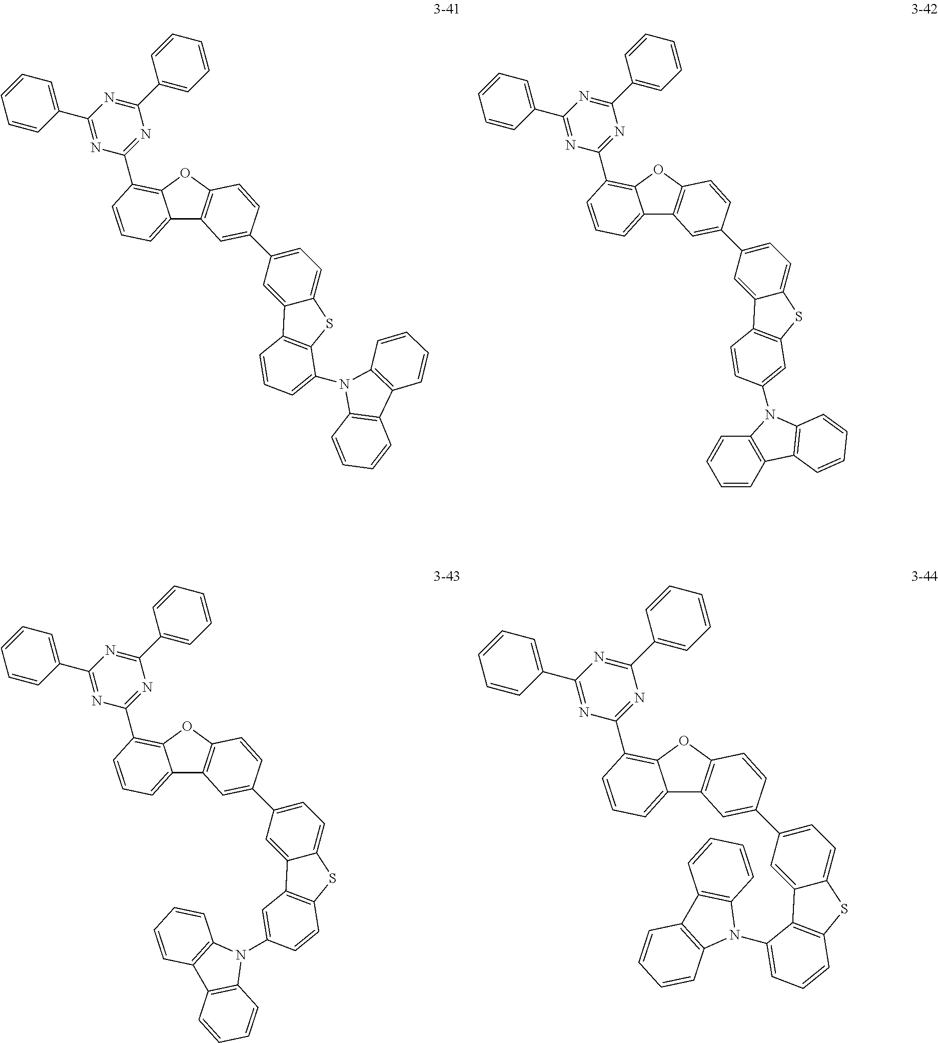 [SMILES: c1ccc(-c2nc(-c3ccccc3)nc(-c3cccc4c3oc3ccc(-c5ccc6sc7c(-n8c9ccccc9c9ccccc98)cccc7c6c5)cc34)n2)cc1 ; c1ccc(-c2nc(-c3ccccc3)nc(-c3cccc4c3oc3ccc(-c5ccc6sc7cc(-n8c9ccccc9c9ccccc98)ccc7c6c5)cc34)n2)cc1 ; c1ccc(-c2nc(-c3ccccc3)nc(-c3cccc4c3oc3ccc(-c5ccc6sc7ccc(-n8c9ccccc9c9ccccc98)cc7c6c5)cc34)n2)cc1 ; c1ccc(-c2nc(-c3ccccc3)nc(-c3cccc4c3oc3ccc(-c5ccc6sc7cccc(-n8c9ccccc9c9ccccc98)c7c6c5)cc34)n2)cc1]

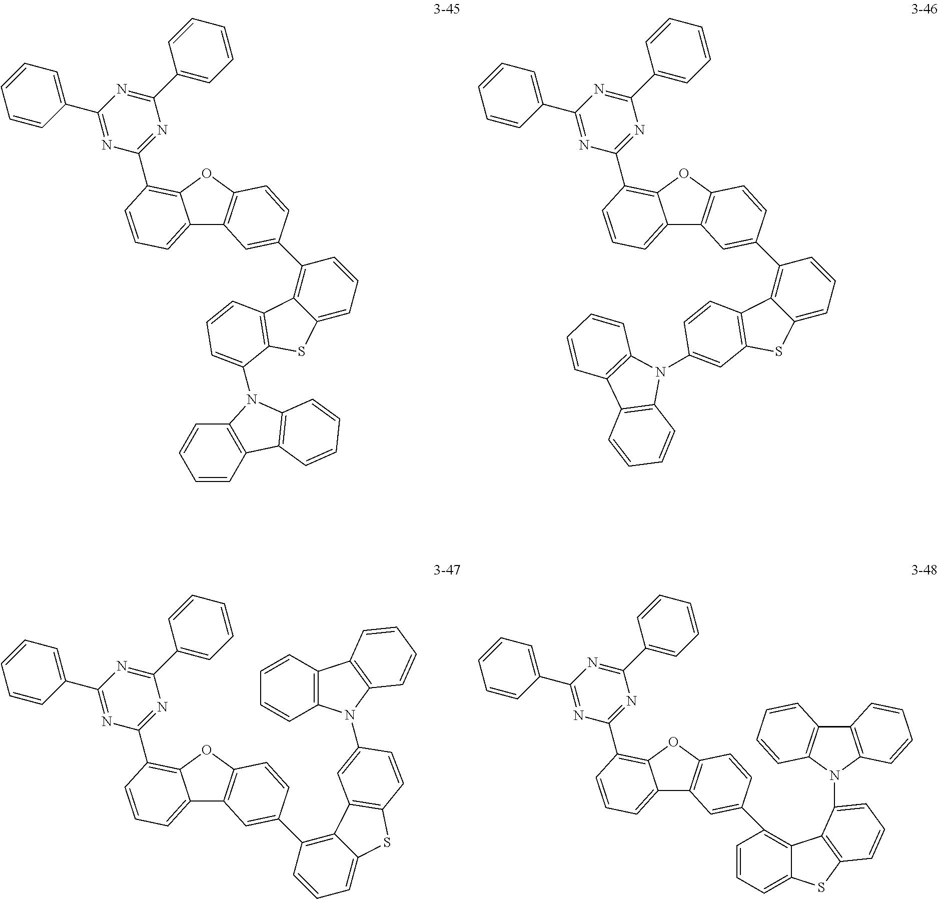 [SMILES: c1ccc(-c2nc(-c3ccccc3)nc(-c3cccc4c3oc3ccc(-c5cccc6sc7c(-n8c9ccccc9c9ccccc98)cccc7c56)cc34)n2)cc1 ; c1ccc(-c2nc(-c3ccccc3)nc(-c3cccc4c3oc3ccc(-c5cccc6sc7cc(-n8c9ccccc9c9ccccc98)ccc7c56)cc34)n2)cc1 ; c1ccc(-c2nc(-c3ccccc3)nc(-c3cccc4c3oc3ccc(-c5cccc6sc7ccc(-n8c9ccccc9c9ccccc98)cc7c56)cc34)n2)cc1 ; c1ccc(-c2nc(-c3ccccc3)nc(-c3cccc4c3oc3ccc(-c5cccc6sc7cccc(-n8c9ccccc9c9ccccc98)c7c56)cc34)n2)cc1]

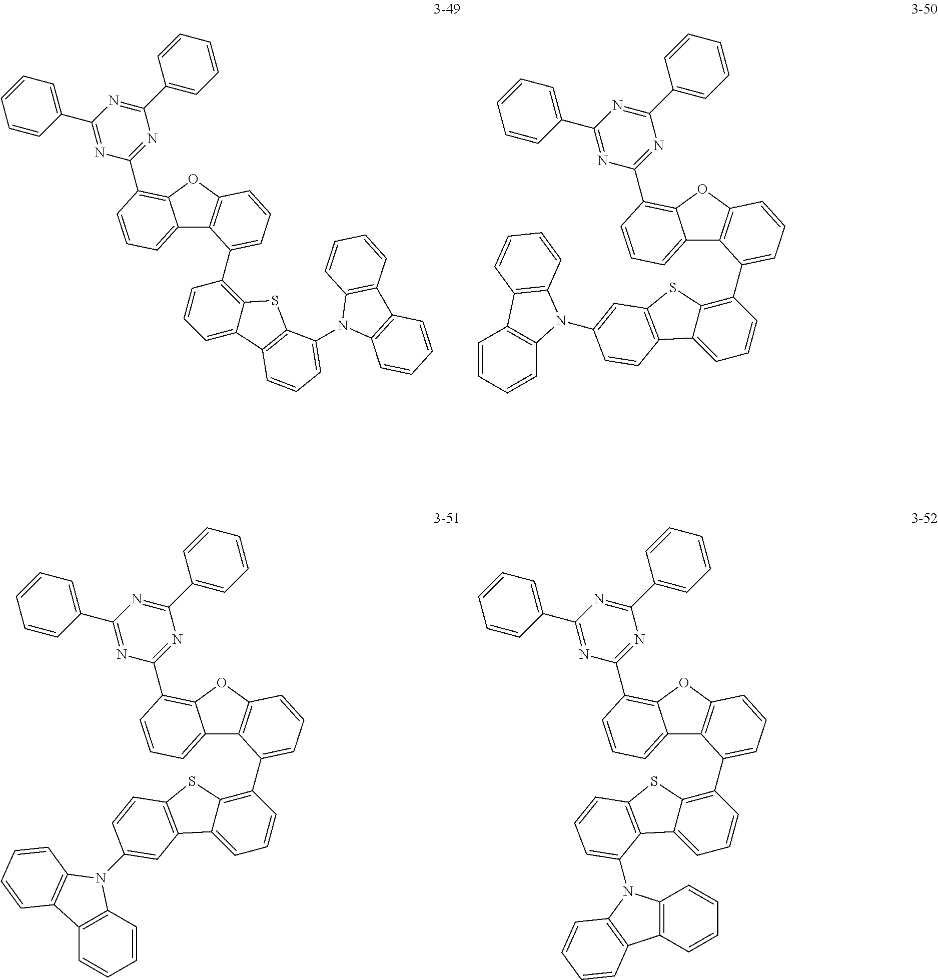 [SMILES: c1ccc(-c2nc(-c3ccccc3)nc(-c3cccc4c3oc3cccc(-c5cccc6c5sc5c(-n7c8ccccc8c8ccccc87)cccc56)c34)n2)cc1 ; c1ccc(-c2nc(-c3ccccc3)nc(-c3cccc4c3oc3cccc(-c5cccc6c5sc5cc(-n7c8ccccc8c8ccccc87)ccc56)c34)n2)cc1 ; c1ccc(-c2nc(-c3ccccc3)nc(-c3cccc4c3oc3cccc(-c5cccc6c5sc5ccc(-n7c8ccccc8c8ccccc87)cc56)c34)n2)cc1 ; c1ccc(-c2nc(-c3ccccc3)nc(-c3cccc4c3oc3cccc(-c5cccc6c5sc5cccc(-n7c8ccccc8c8ccccc87)c56)c34)n2)cc1]

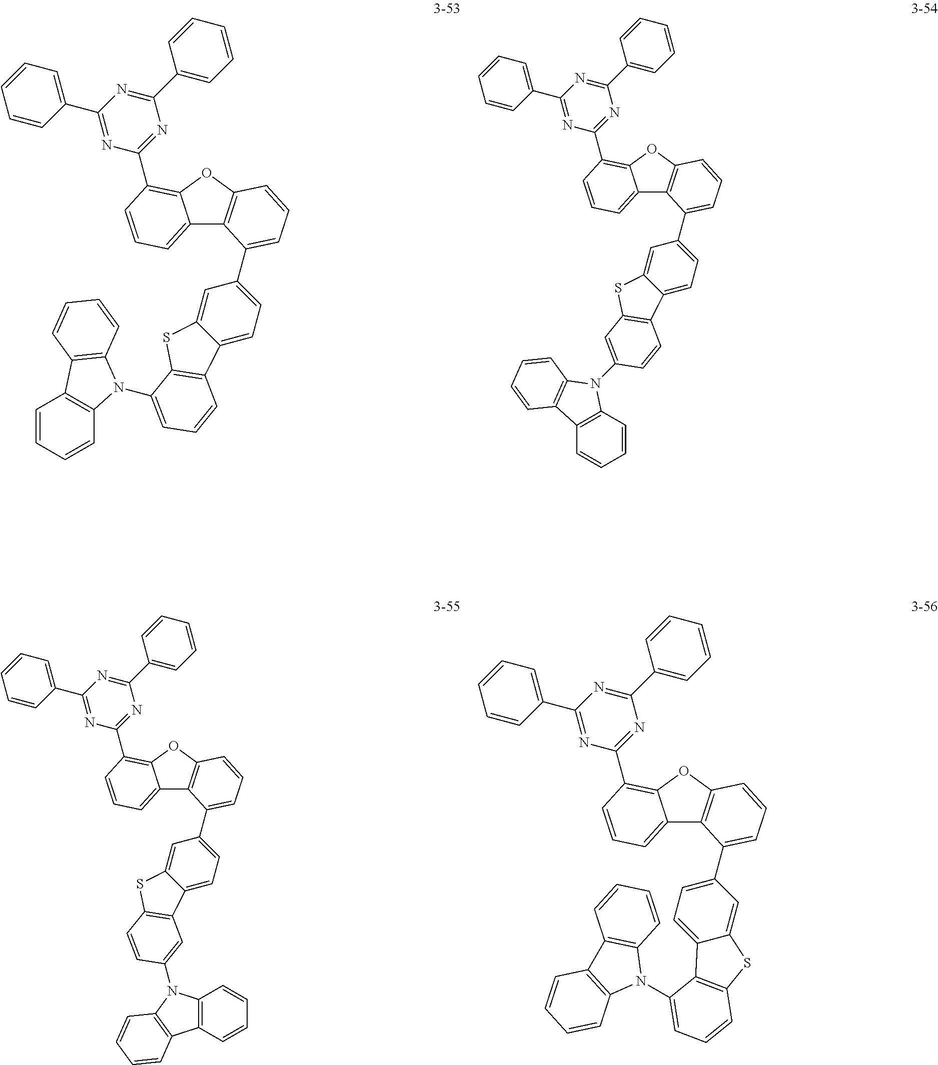 [SMILES: c1ccc(-c2nc(-c3ccccc3)nc(-c3cccc4c3oc3cccc(-c5ccc6c(c5)sc5c(-n7c8ccccc8c8ccccc87)cccc56)c34)n2)cc1 ; c1ccc(-c2nc(-c3ccccc3)nc(-c3cccc4c3oc3cccc(-c5ccc6c(c5)sc5cc(-n7c8ccccc8c8ccccc87)ccc56)c34)n2)cc1 ; c1ccc(-c2nc(-c3ccccc3)nc(-c3cccc4c3oc3cccc(-c5ccc6c(c5)sc5ccc(-n7c8ccccc8c8ccccc87)cc56)c34)n2)cc1 ; c1ccc(-c2nc(-c3ccccc3)nc(-c3cccc4c3oc3cccc(-c5ccc6c(c5)sc5cccc(-n7c8ccccc8c8ccccc87)c56)c34)n2)cc1]

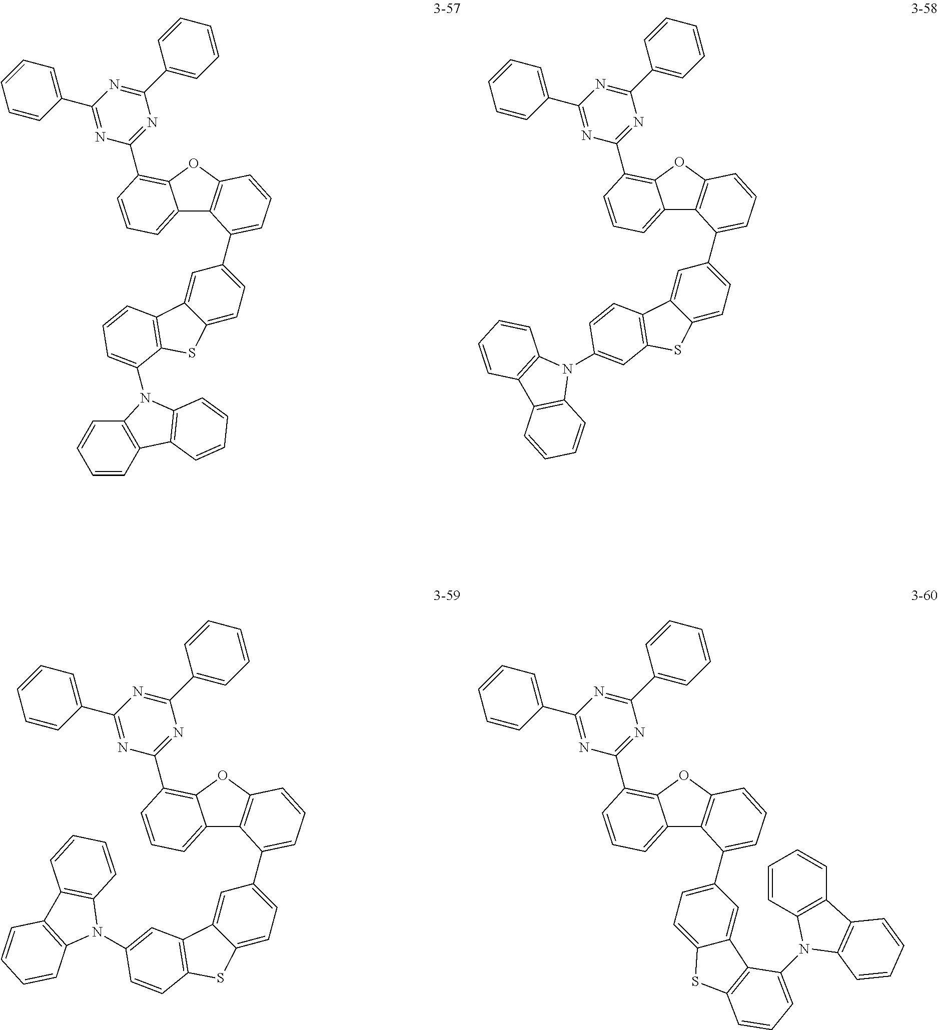 [SMILES: c1ccc(-c2nc(-c3ccccc3)nc(-c3cccc4c3oc3cccc(-c5ccc6sc7c(-n8c9ccccc9c9ccccc98)cccc7c6c5)c34)n2)cc1 ; c1ccc(-c2nc(-c3ccccc3)nc(-c3cccc4c3oc3cccc(-c5ccc6sc7cc(-n8c9ccccc9c9ccccc98)ccc7c6c5)c34)n2)cc1 ; c1ccc(-c2nc(-c3ccccc3)nc(-c3cccc4c3oc3cccc(-c5ccc6sc7ccc(-n8c9ccccc9c9ccccc98)cc7c6c5)c34)n2)cc1 ; c1ccc(-c2nc(-c3ccccc3)nc(-c3cccc4c3oc3cccc(-c5ccc6sc7cccc(-n8c9ccccc9c9ccccc98)c7c6c5)c34)n2)cc1]

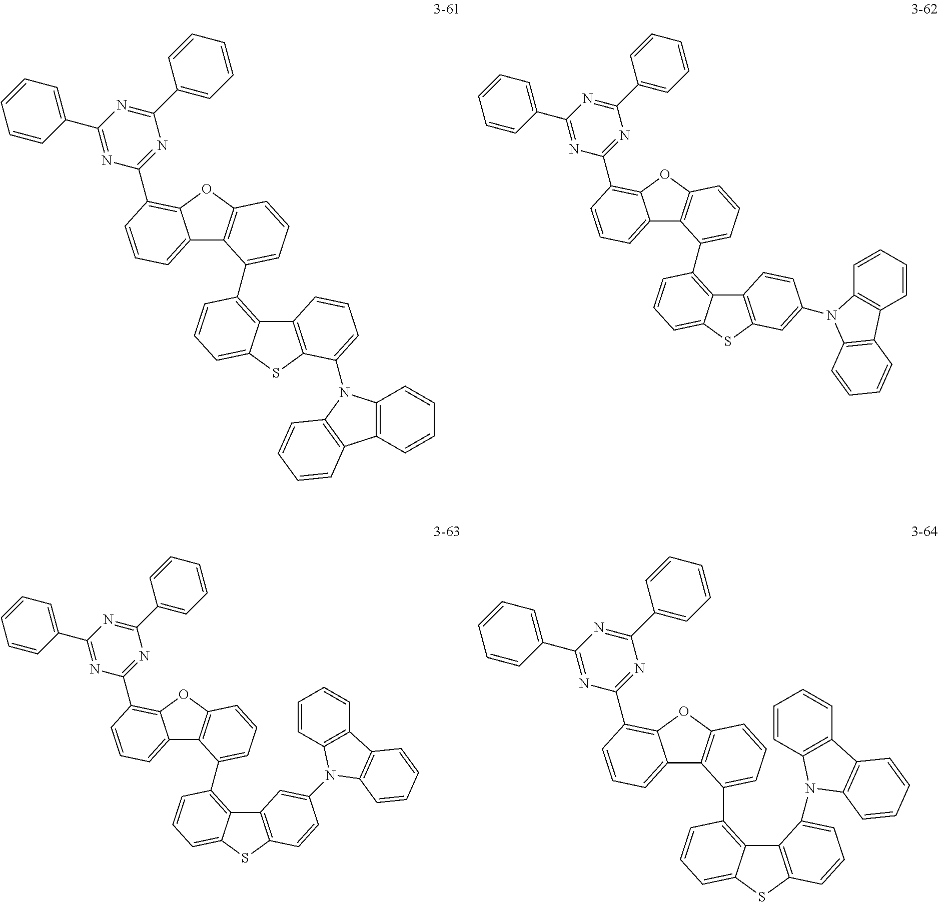 [SMILES: c1ccc(-c2nc(-c3ccccc3)nc(-c3cccc4c3oc3cccc(-c5cccc6sc7c(-n8c9ccccc9c9ccccc98)cccc7c56)c34)n2)cc1 ; c1ccc(-c2nc(-c3ccccc3)nc(-c3cccc4c3oc3cccc(-c5cccc6sc7cc(-n8c9ccccc9c9ccccc98)ccc7c56)c34)n2)cc1 ; c1ccc(-c2nc(-c3ccccc3)nc(-c3cccc4c3oc3cccc(-c5cccc6sc7ccc(-n8c9ccccc9c9ccccc98)cc7c56)c34)n2)cc1 ; c1ccc(-c2nc(-c3ccccc3)nc(-c3cccc4c3oc3cccc(-c5cccc6sc7cccc(-n8c9ccccc9c9ccccc98)c7c56)c34)n2)cc1]

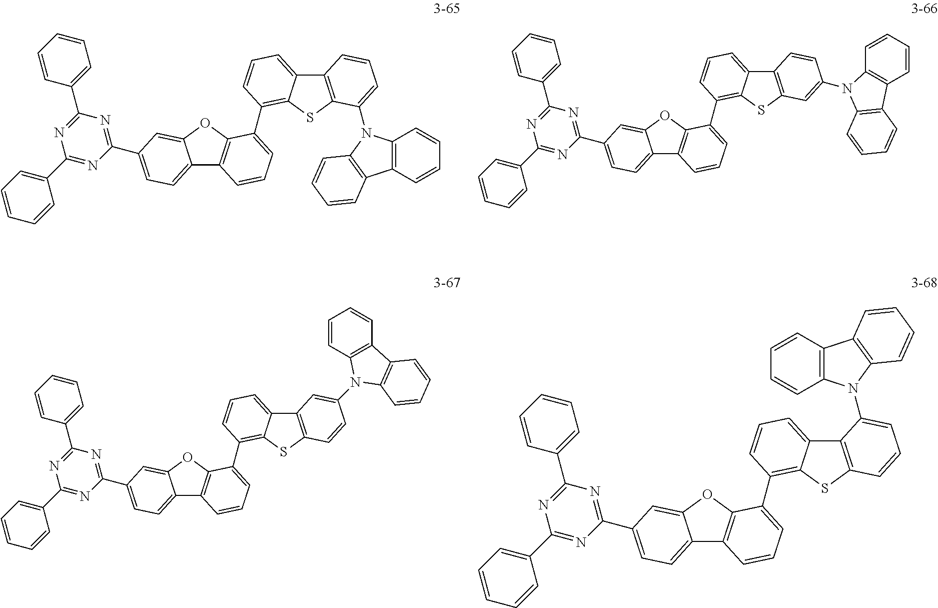 [SMILES: c1ccc(-c2nc(-c3ccccc3)nc(-c3ccc4c(c3)oc3c(-c5cccc6c5sc5c(-n7c8ccccc8c8ccccc87)cccc56)cccc34)n2)cc1 ; c1ccc(-c2nc(-c3ccccc3)nc(-c3ccc4c(c3)oc3c(-c5cccc6c5sc5cc(-n7c8ccccc8c8ccccc87)ccc56)cccc34)n2)cc1 ; c1ccc(-c2nc(-c3ccccc3)nc(-c3ccc4c(c3)oc3c(-c5cccc6c5sc5ccc(-n7c8ccccc8c8ccccc87)cc56)cccc34)n2)cc1 ; c1ccc(-c2nc(-c3ccccc3)nc(-c3ccc4c(c3)oc3c(-c5cccc6c5sc5cccc(-n7c8ccccc8c8ccccc87)c56)cccc34)n2)cc1]

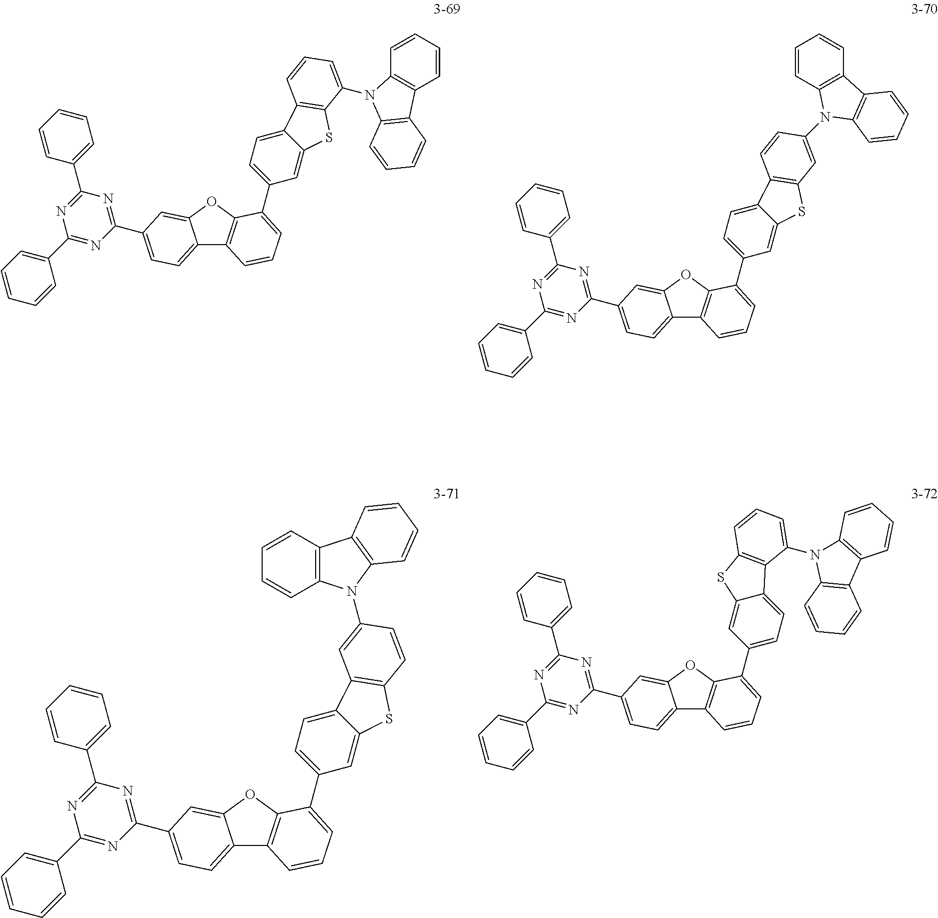 [SMILES: c1ccc(-c2nc(-c3ccccc3)nc(-c3ccc4c(c3)oc3c(-c5ccc6c(c5)sc5c(-n7c8ccccc8c8ccccc87)cccc56)cccc34)n2)cc1 ; c1ccc(-c2nc(-c3ccccc3)nc(-c3ccc4c(c3)oc3c(-c5ccc6c(c5)sc5cc(-n7c8ccccc8c8ccccc87)ccc56)cccc34)n2)cc1 ; c1ccc(-c2nc(-c3ccccc3)nc(-c3ccc4c(c3)oc3c(-c5ccc6c(c5)sc5ccc(-n7c8ccccc8c8ccccc87)cc56)cccc34)n2)cc1 ; c1ccc(-c2nc(-c3ccccc3)nc(-c3ccc4c(c3)oc3c(-c5ccc6c(c5)sc5cccc(-n7c8ccccc8c8ccccc87)c56)cccc34)n2)cc1]

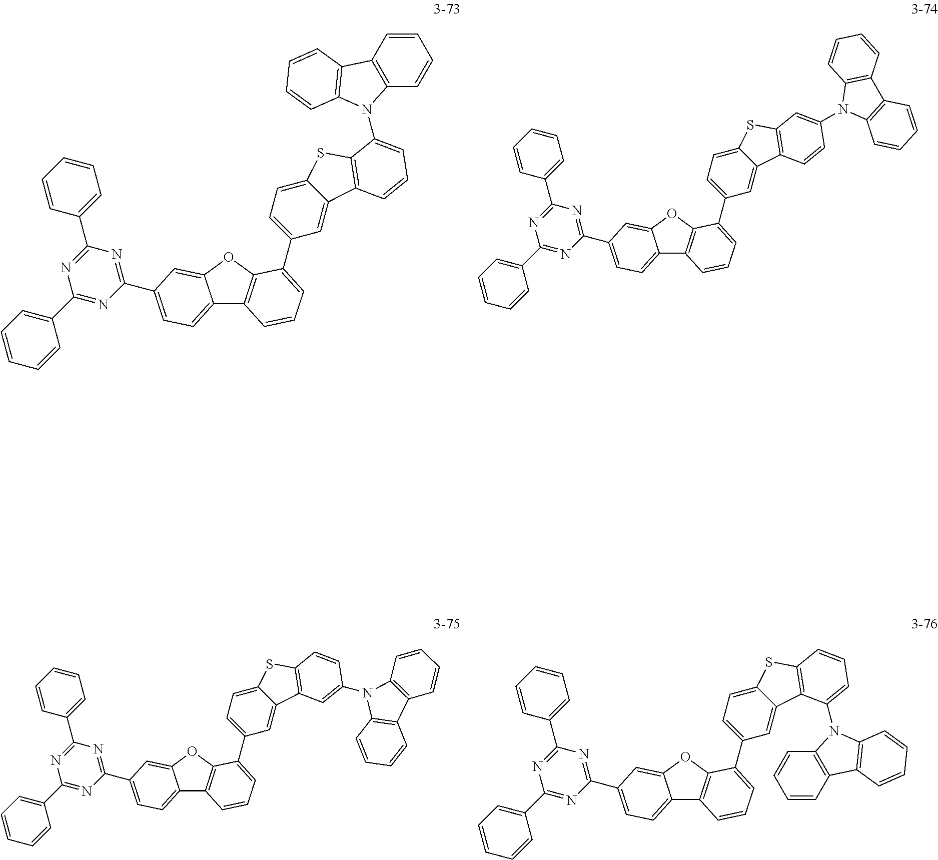 [SMILES: c1ccc(-c2nc(-c3ccccc3)nc(-c3ccc4c(c3)oc3c(-c5ccc6sc7c(-n8c9ccccc9c9ccccc98)cccc7c6c5)cccc34)n2)cc1 ; c1ccc(-c2nc(-c3ccccc3)nc(-c3ccc4c(c3)oc3c(-c5ccc6sc7cc(-n8c9ccccc9c9ccccc98)ccc7c6c5)cccc34)n2)cc1 ; c1ccc(-c2nc(-c3ccccc3)nc(-c3ccc4c(c3)oc3c(-c5ccc6sc7ccc(-n8c9ccccc9c9ccccc98)cc7c6c5)cccc34)n2)cc1 ; c1ccc(-c2nc(-c3ccccc3)nc(-c3ccc4c(c3)oc3c(-c5ccc6sc7cccc(-n8c9ccccc9c9ccccc98)c7c6c5)cccc34)n2)cc1]

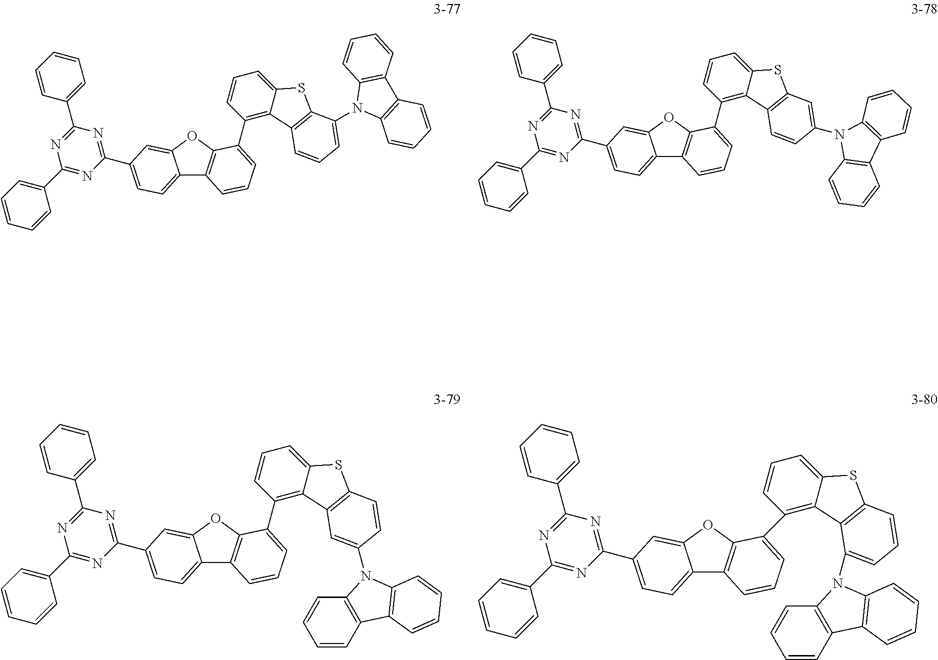

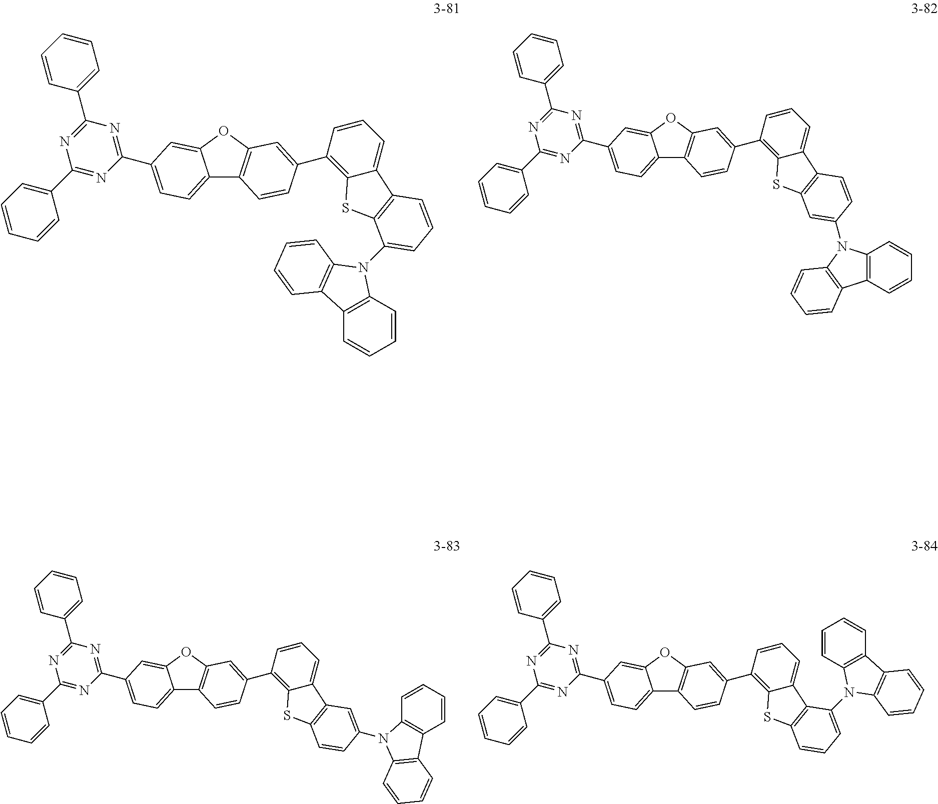

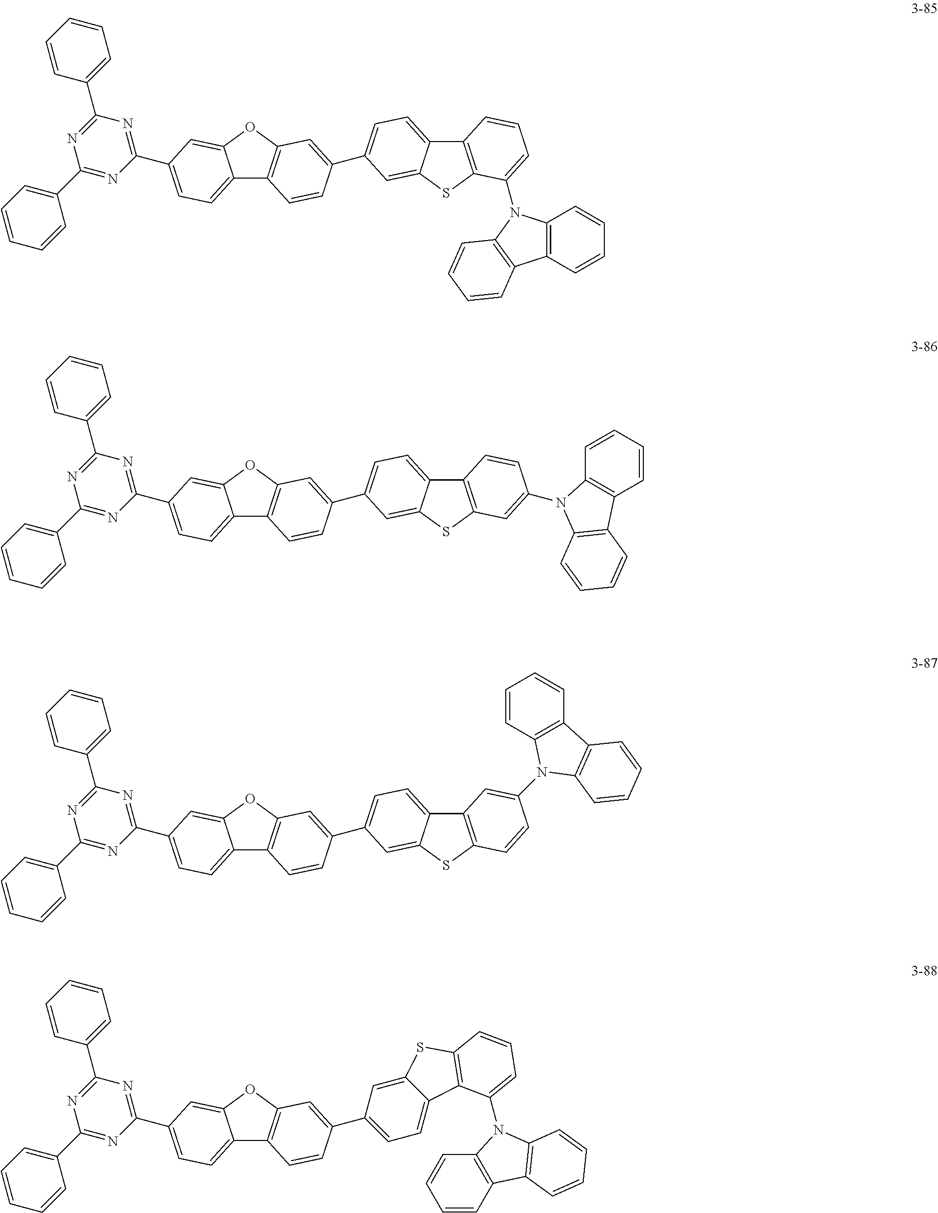 [SMILES: c1ccc(-c2nc(-c3ccccc3)nc(-c3ccc4c(c3)oc3cc(-c5ccc6c(c5)sc5c(-n7c8ccccc8c8ccccc87)cccc56)ccc34)n2)cc1 ; c1ccc(-c2nc(-c3ccccc3)nc(-c3ccc4c(c3)oc3cc(-c5ccc6c(c5)sc5cc(-n7c8ccccc8c8ccccc87)ccc56)ccc34)n2)cc1 ; c1ccc(-c2nc(-c3ccccc3)nc(-c3ccc4c(c3)oc3cc(-c5ccc6c(c5)sc5ccc(-n7c8ccccc8c8ccccc87)cc56)ccc34)n2)cc1 ; c1ccc(-c2nc(-c3ccccc3)nc(-c3ccc4c(c3)oc3cc(-c5ccc6c(c5)sc5cccc(-n7c8ccccc8c8ccccc87)c56)ccc34)n2)cc1]

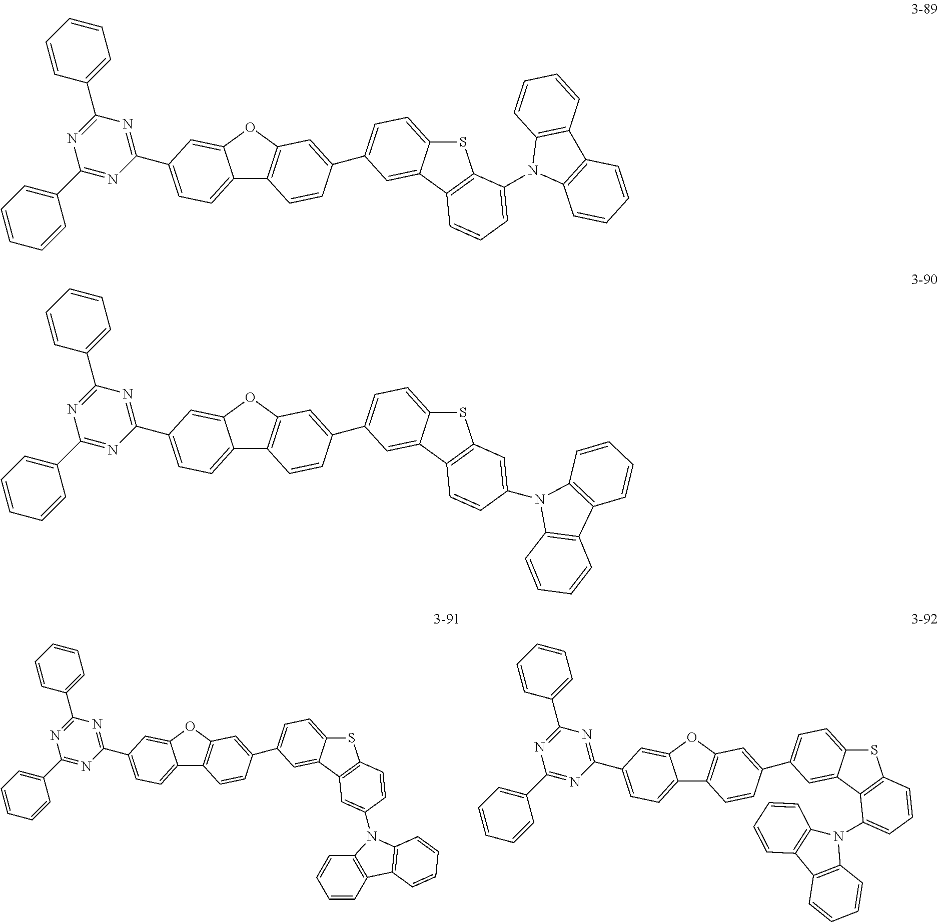 [SMILES: c1ccc(-c2nc(-c3ccccc3)nc(-c3ccc4c(c3)oc3cc(-c5ccc6sc7c(-n8c9ccccc9c9ccccc98)cccc7c6c5)ccc34)n2)cc1 ; c1ccc(-c2nc(-c3ccccc3)nc(-c3ccc4c(c3)oc3cc(-c5ccc6sc7cc(-n8c9ccccc9c9ccccc98)ccc7c6c5)ccc34)n2)cc1 ; c1ccc(-c2nc(-c3ccccc3)nc(-c3ccc4c(c3)oc3cc(-c5ccc6sc7ccc(-n8c9ccccc9c9ccccc98)cc7c6c5)ccc34)n2)cc1 ; c1ccc(-c2nc(-c3ccccc3)nc(-c3ccc4c(c3)oc3cc(-c5ccc6sc7cccc(-n8c9ccccc9c9ccccc98)c7c6c5)ccc34)n2)cc1]

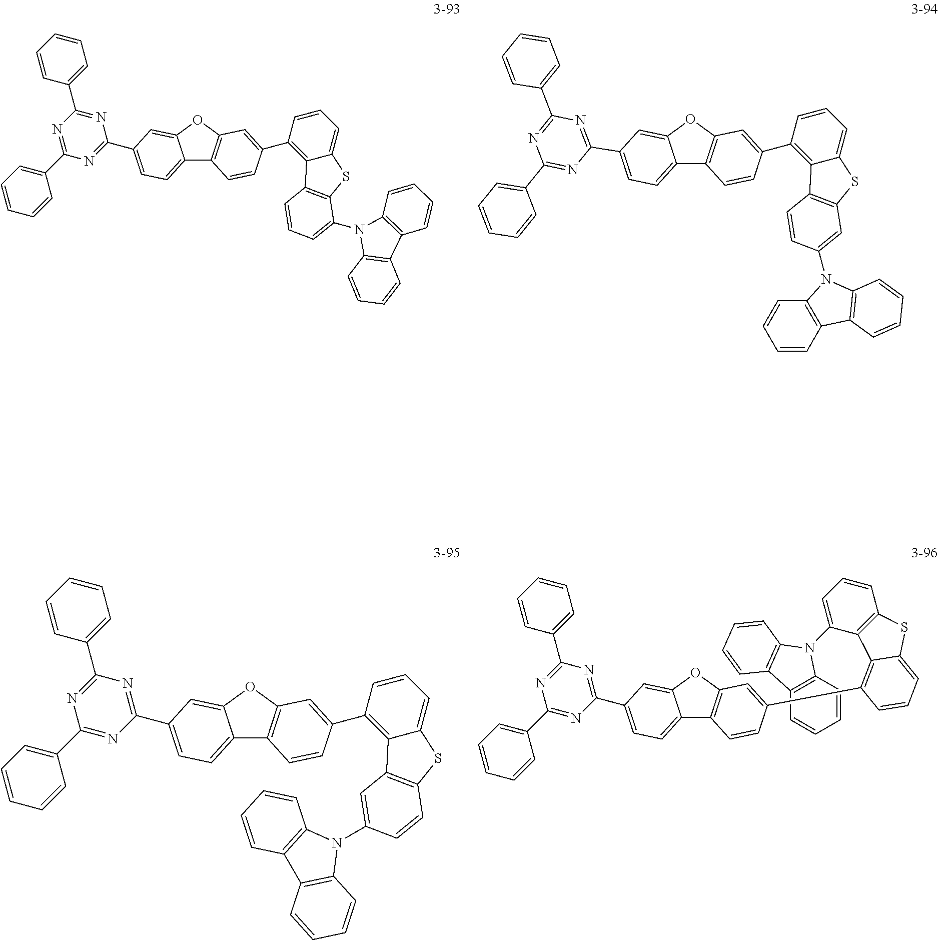 [SMILES: c1ccc(-c2nc(-c3ccccc3)nc(-c3ccc4c(c3)oc3cc(-c5cccc6sc7c(-n8c9ccccc9c9ccccc98)cccc7c56)ccc34)n2)cc1 ; c1ccc(-c2nc(-c3ccccc3)nc(-c3ccc4c(c3)oc3cc(-c5cccc6sc7cc(-n8c9ccccc9c9ccccc98)ccc7c56)ccc34)n2)cc1 ; c1ccc(-c2nc(-c3ccccc3)nc(-c3ccc4c(c3)oc3cc(-c5cccc6sc7ccc(-n8c9ccccc9c9ccccc98)cc7c56)ccc34)n2)cc1 ; c1ccc(-c2nc(-c3ccccc3)nc(-c3ccc4c(c3)oc3cc(-c5cccc6sc7cccc(-n8c9ccccc9c9ccccc98)c7c56)ccc34)n2)cc1]

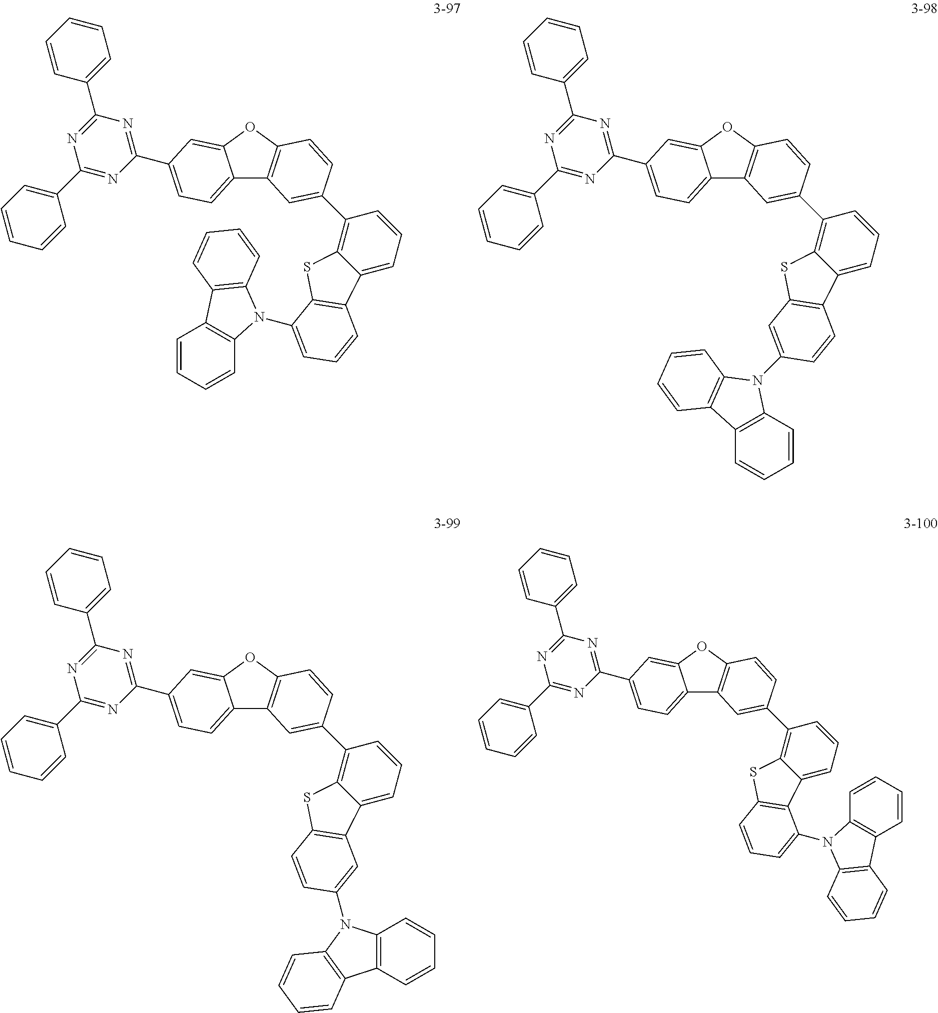 [SMILES: c1ccc(-c2nc(-c3ccccc3)nc(-c3ccc4c(c3)oc3ccc(-c5cccc6c5sc5c(-n7c8ccccc8c8ccccc87)cccc56)cc34)n2)cc1 ; c1ccc(-c2nc(-c3ccccc3)nc(-c3ccc4c(c3)oc3ccc(-c5cccc6c5sc5cc(-n7c8ccccc8c8ccccc87)ccc56)cc34)n2)cc1 ; c1ccc(-c2nc(-c3ccccc3)nc(-c3ccc4c(c3)oc3ccc(-c5cccc6c5sc5ccc(-n7c8ccccc8c8ccccc87)cc56)cc34)n2)cc1 ; c1ccc(-c2nc(-c3ccccc3)nc(-c3ccc4c(c3)oc3ccc(-c5cccc6c5sc5cccc(-n7c8ccccc8c8ccccc87)c56)cc34)n2)cc1]

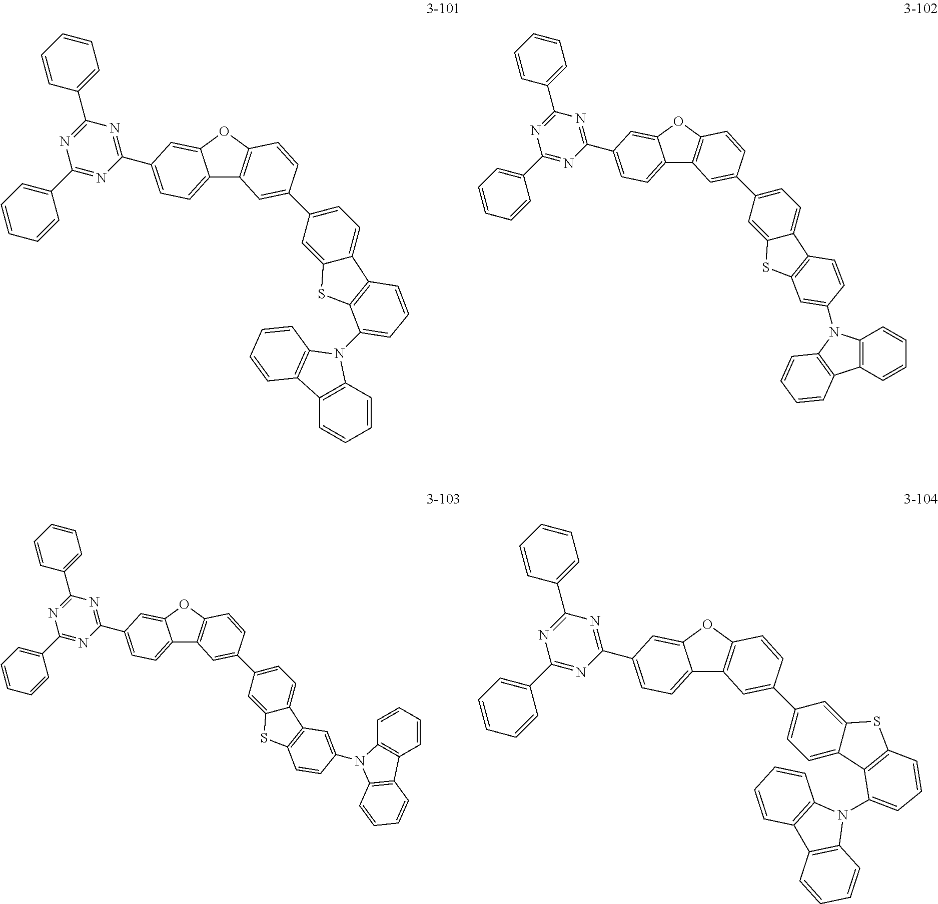 [SMILES: c1ccc(-c2nc(-c3ccccc3)nc(-c3ccc4c(c3)oc3ccc(-c5ccc6c(c5)sc5c(-n7c8ccccc8c8ccccc87)cccc56)cc34)n2)cc1 ; c1ccc(-c2nc(-c3ccccc3)nc(-c3ccc4c(c3)oc3ccc(-c5ccc6c(c5)sc5cc(-n7c8ccccc8c8ccccc87)ccc56)cc34)n2)cc1 ; c1ccc(-c2nc(-c3ccccc3)nc(-c3ccc4c(c3)oc3ccc(-c5ccc6c(c5)sc5ccc(-n7c8ccccc8c8ccccc87)cc56)cc34)n2)cc1 ; c1ccc(-c2nc(-c3ccccc3)nc(-c3ccc4c(c3)oc3ccc(-c5ccc6c(c5)sc5cccc(-n7c8ccccc8c8ccccc87)c56)cc34)n2)cc1]

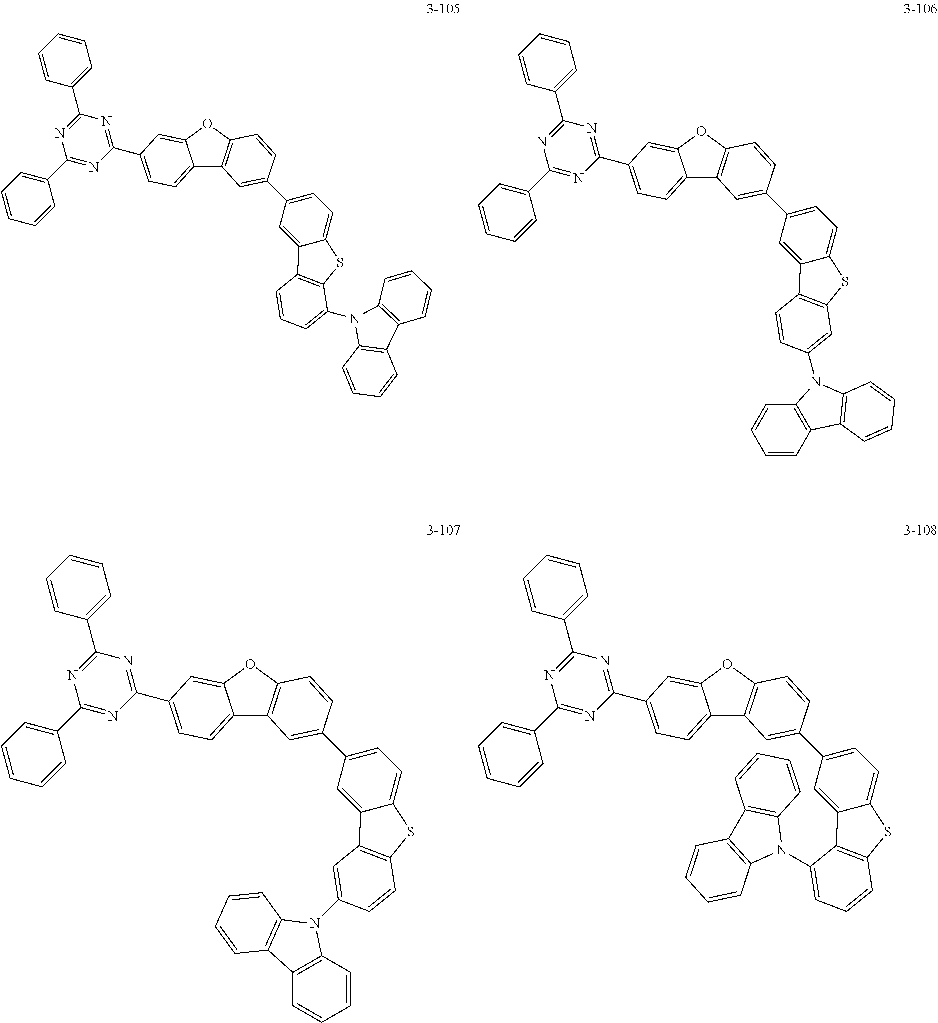 [SMILES: c1ccc(-c2nc(-c3ccccc3)nc(-c3ccc4c(c3)oc3ccc(-c5ccc6sc7c(-n8c9ccccc9c9ccccc98)cccc7c6c5)cc34)n2)cc1 ; c1ccc(-c2nc(-c3ccccc3)nc(-c3ccc4c(c3)oc3ccc(-c5ccc6sc7cc(-n8c9ccccc9c9ccccc98)ccc7c6c5)cc34)n2)cc1 ; c1ccc(-c2nc(-c3ccccc3)nc(-c3ccc4c(c3)oc3ccc(-c5ccc6sc7ccc(-n8c9ccccc9c9ccccc98)cc7c6c5)cc34)n2)cc1 ; c1ccc(-c2nc(-c3ccccc3)nc(-c3ccc4c(c3)oc3ccc(-c5ccc6sc7cccc(-n8c9ccccc9c9ccccc98)c7c6c5)cc34)n2)cc1]

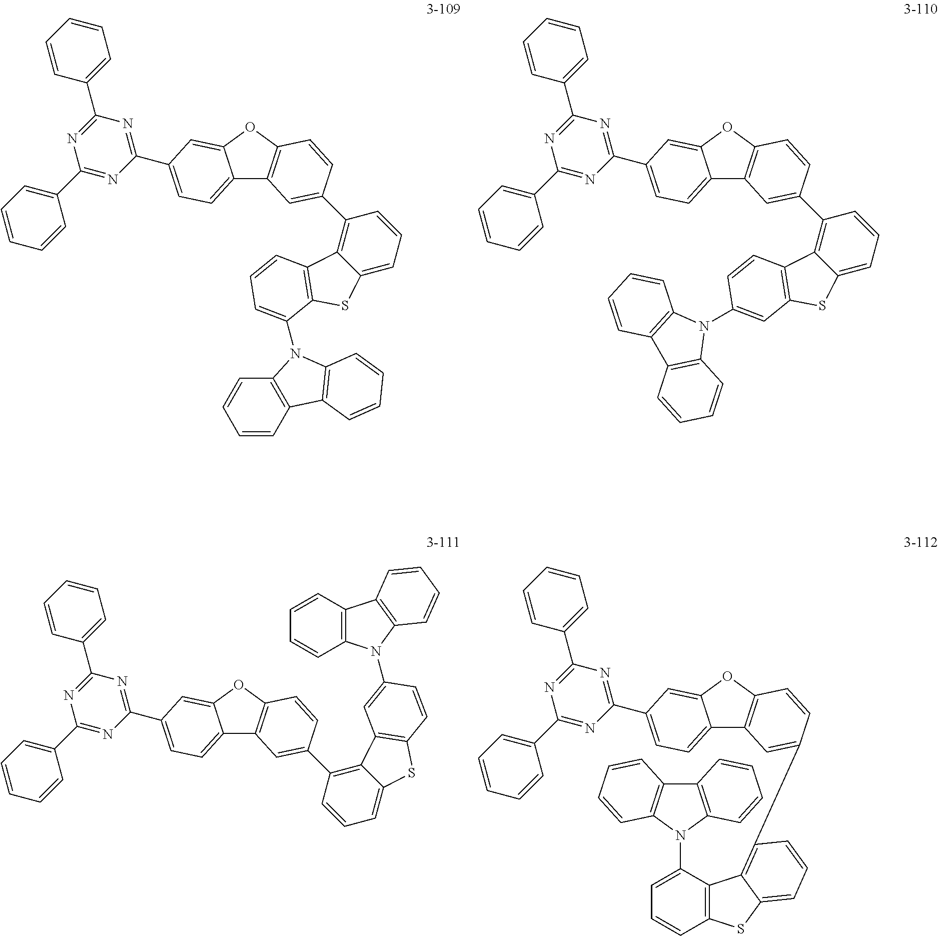 [SMILES: c1ccc(-c2nc(-c3ccccc3)nc(-c3ccc4c(c3)oc3ccc(-c5cccc6sc7c(-n8c9ccccc9c9ccccc98)cccc7c56)cc34)n2)cc1 ; c1ccc(-c2nc(-c3ccccc3)nc(-c3ccc4c(c3)oc3ccc(-c5cccc6sc7cc(-n8c9ccccc9c9ccccc98)ccc7c56)cc34)n2)cc1 ; c1ccc(-c2nc(-c3ccccc3)nc(-c3ccc4c(c3)oc3ccc(-c5cccc6sc7ccc(-n8c9ccccc9c9ccccc98)cc7c56)cc34)n2)cc1 ; c1ccc(-c2nc(-c3ccccc3)nc(-c3ccc4c(c3)oc3ccc(-c5cccc6sc7cccc(-n8c9ccccc9c9ccccc98)c7c56)cc34)n2)cc1]

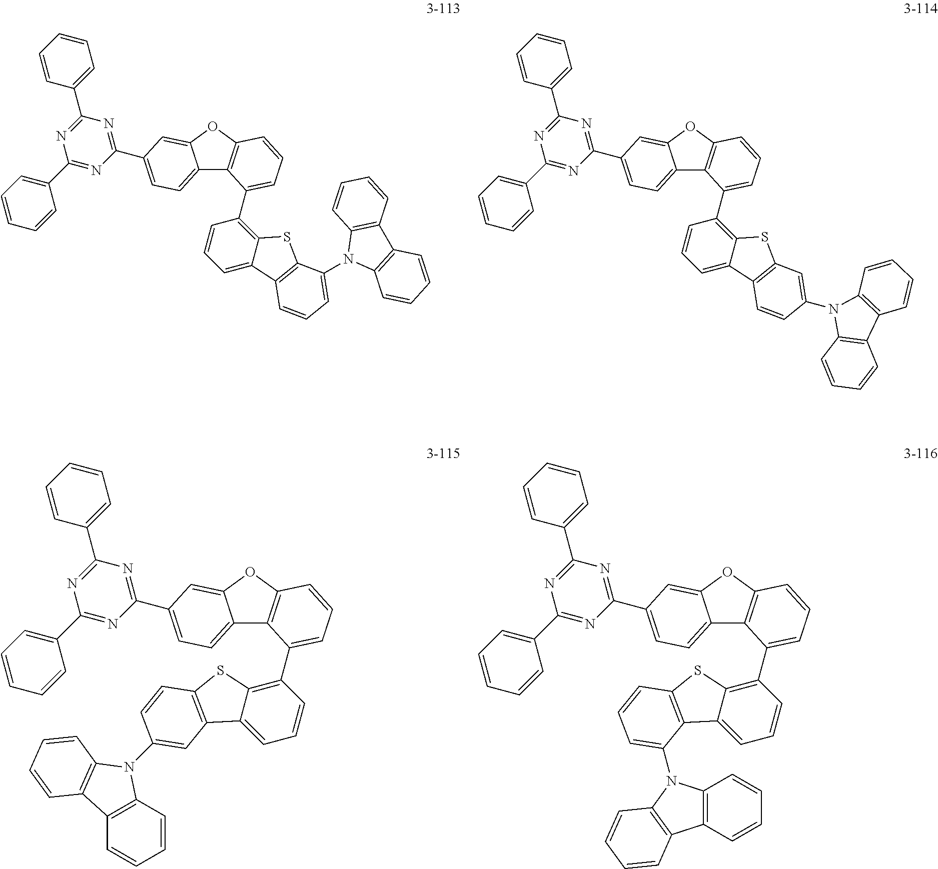 [SMILES: c1ccc(-c2nc(-c3ccccc3)nc(-c3ccc4c(c3)oc3cccc(-c5cccc6c5sc5c(-n7c8ccccc8c8ccccc87)cccc56)c34)n2)cc1 ; c1ccc(-c2nc(-c3ccccc3)nc(-c3ccc4c(c3)oc3cccc(-c5cccc6c5sc5cc(-n7c8ccccc8c8ccccc87)ccc56)c34)n2)cc1 ; c1ccc(-c2nc(-c3ccccc3)nc(-c3ccc4c(c3)oc3cccc(-c5cccc6c5sc5ccc(-n7c8ccccc8c8ccccc87)cc56)c34)n2)cc1 ; c1ccc(-c2nc(-c3ccccc3)nc(-c3ccc4c(c3)oc3cccc(-c5cccc6c5sc5cccc(-n7c8ccccc8c8ccccc87)c56)c34)n2)cc1]

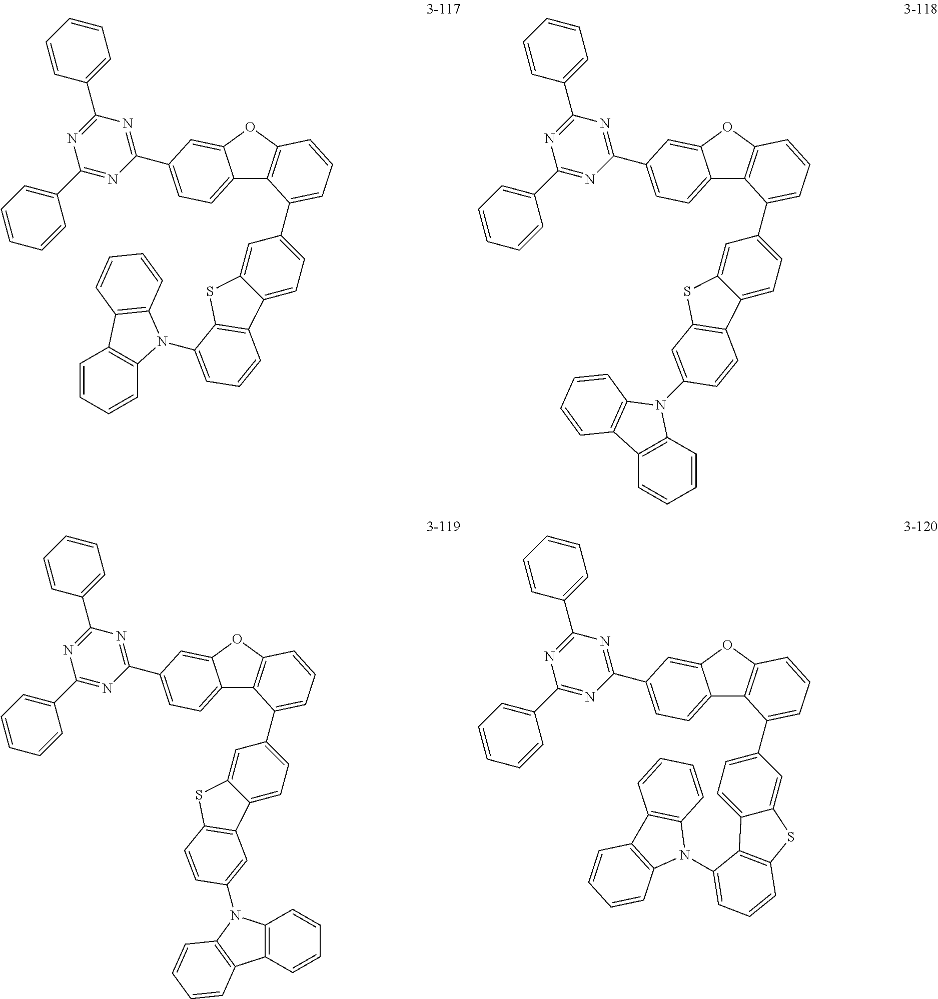 [SMILES: c1ccc(-c2nc(-c3ccccc3)nc(-c3ccc4c(c3)oc3cccc(-c5ccc6c(c5)sc5c(-n7c8ccccc8c8ccccc87)cccc56)c34)n2)cc1 ; c1ccc(-c2nc(-c3ccccc3)nc(-c3ccc4c(c3)oc3cccc(-c5ccc6c(c5)sc5cc(-n7c8ccccc8c8ccccc87)ccc56)c34)n2)cc1 ; c1ccc(-c2nc(-c3ccccc3)nc(-c3ccc4c(c3)oc3cccc(-c5ccc6c(c5)sc5ccc(-n7c8ccccc8c8ccccc87)cc56)c34)n2)cc1 ; c1ccc(-c2nc(-c3ccccc3)nc(-c3ccc4c(c3)oc3cccc(-c5ccc6c(c5)sc5cccc(-n7c8ccccc8c8ccccc87)c56)c34)n2)cc1]

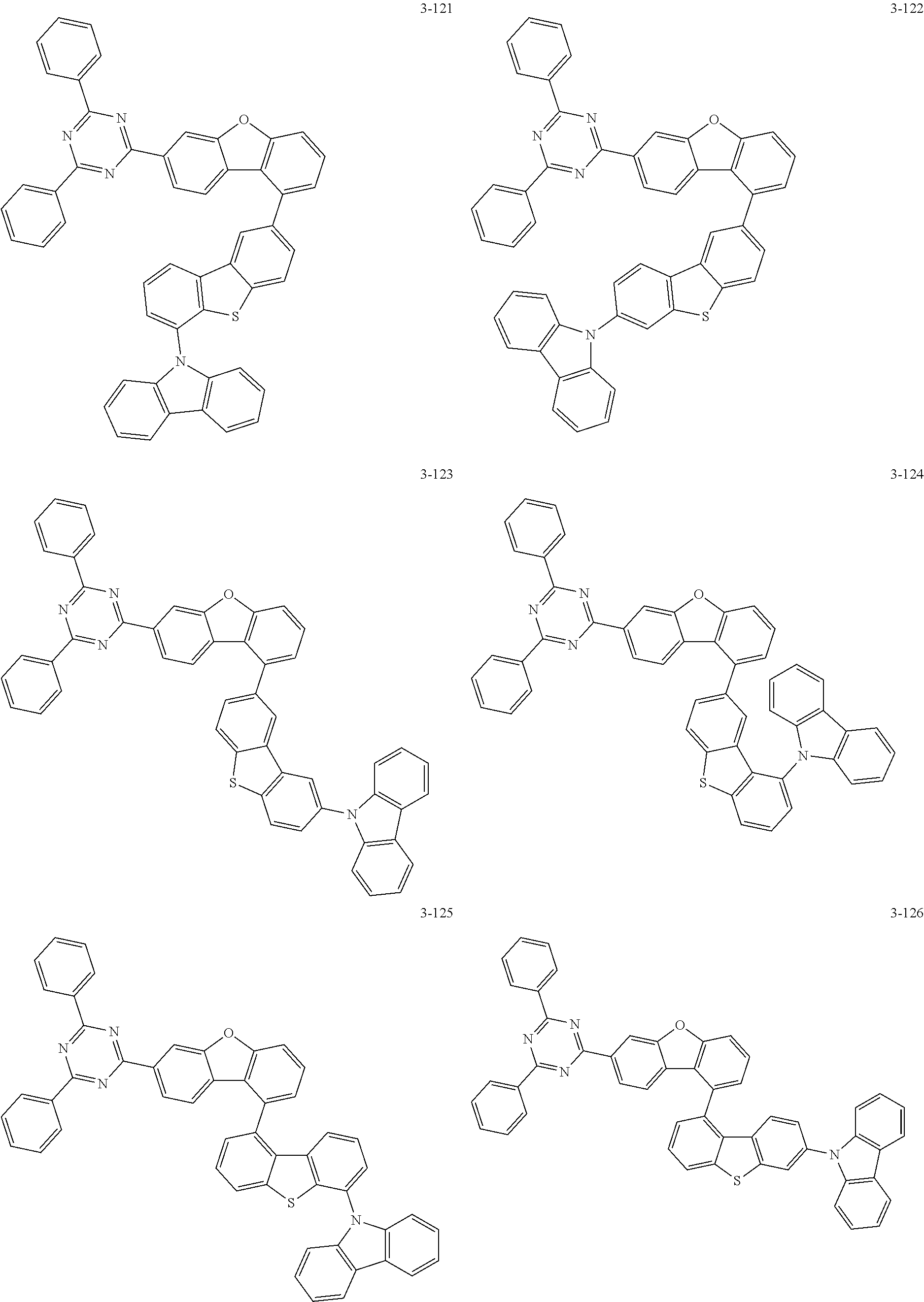

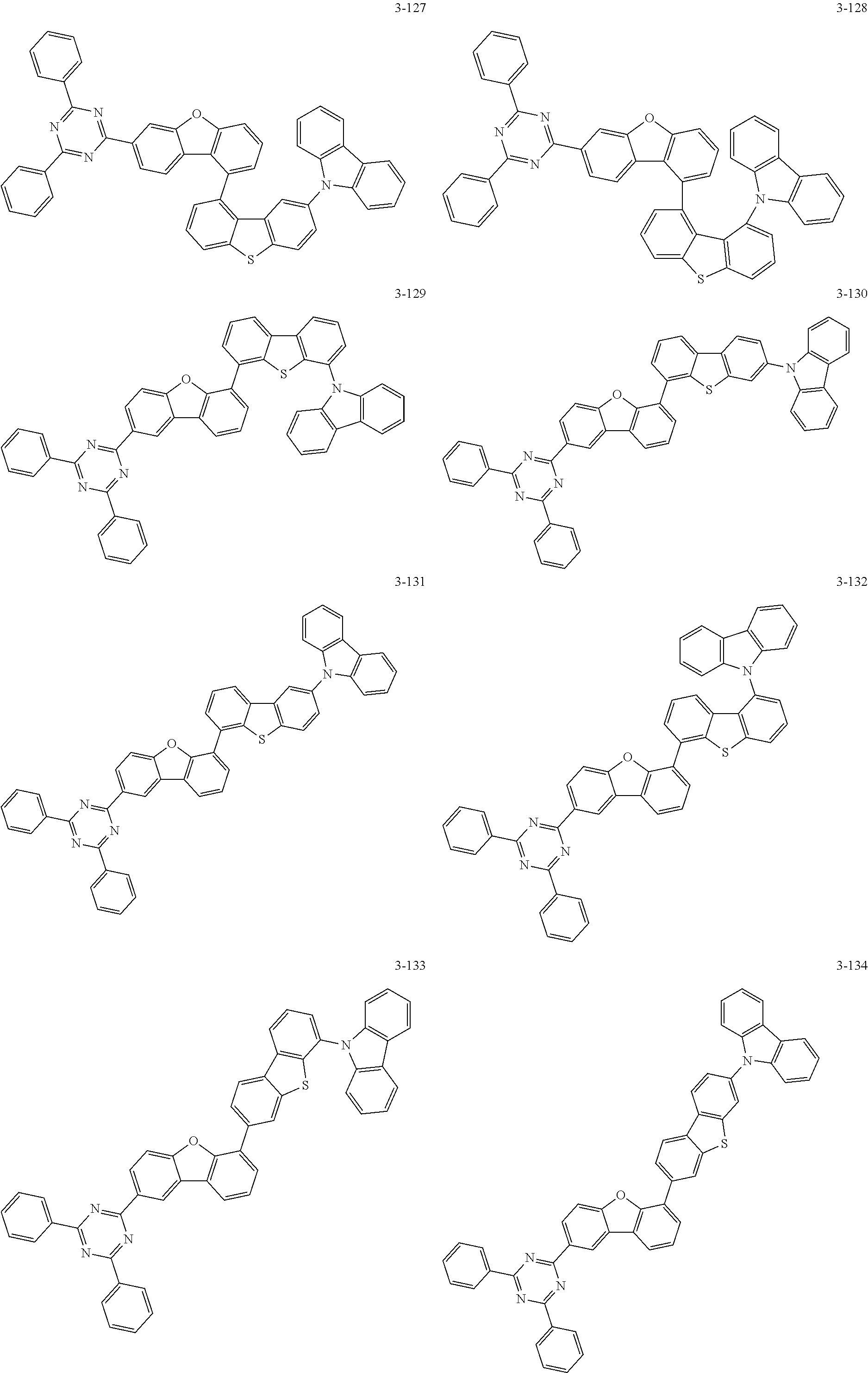

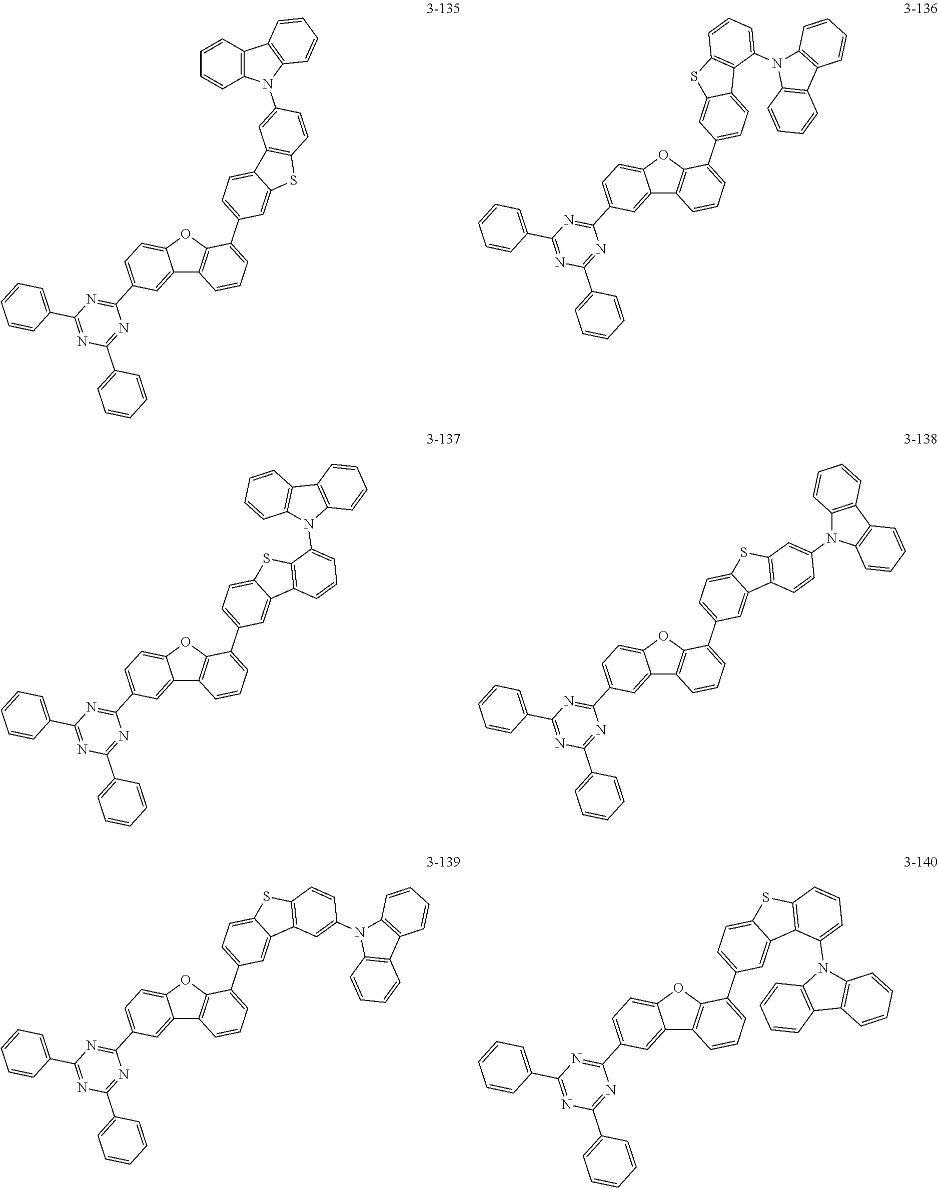

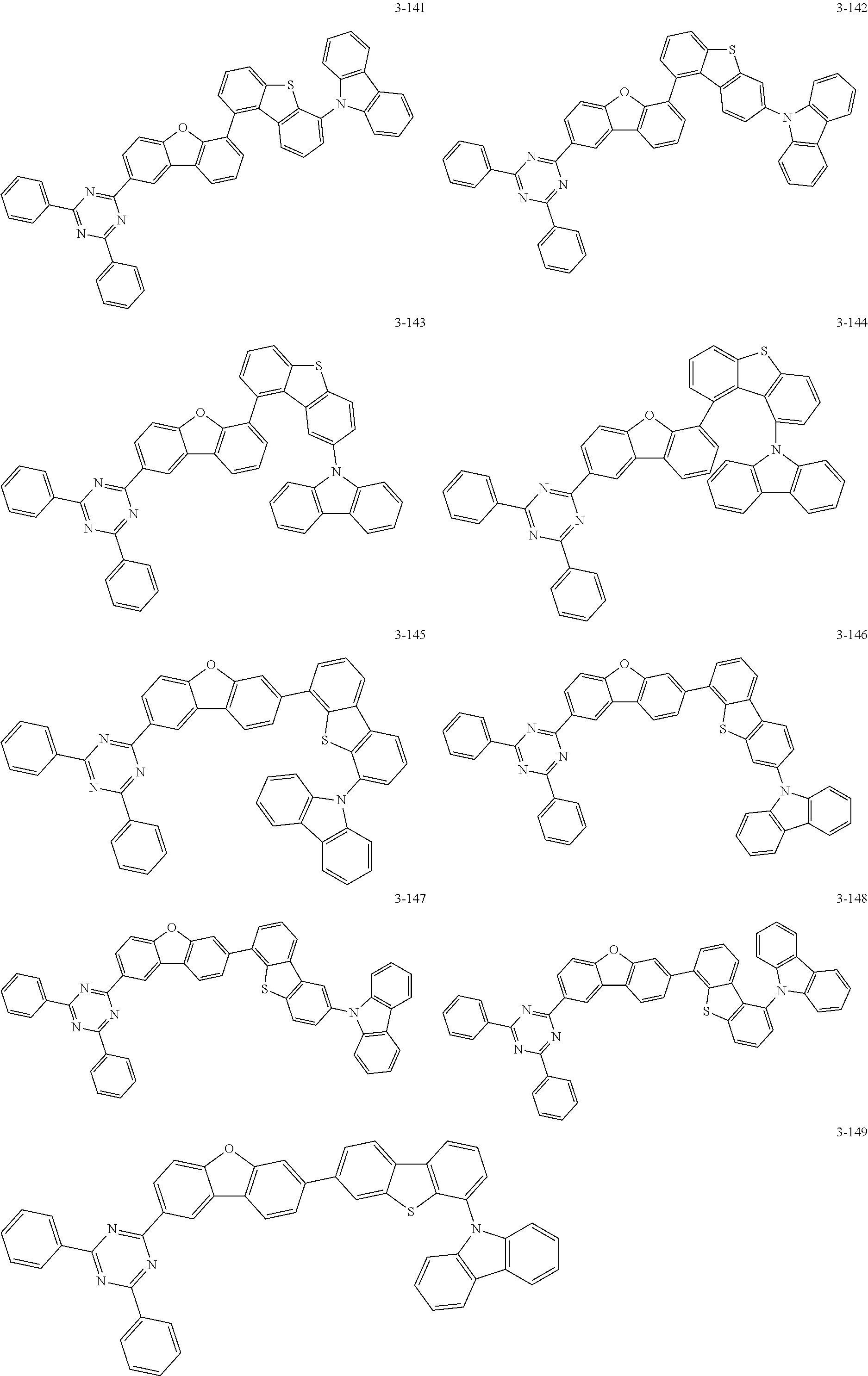

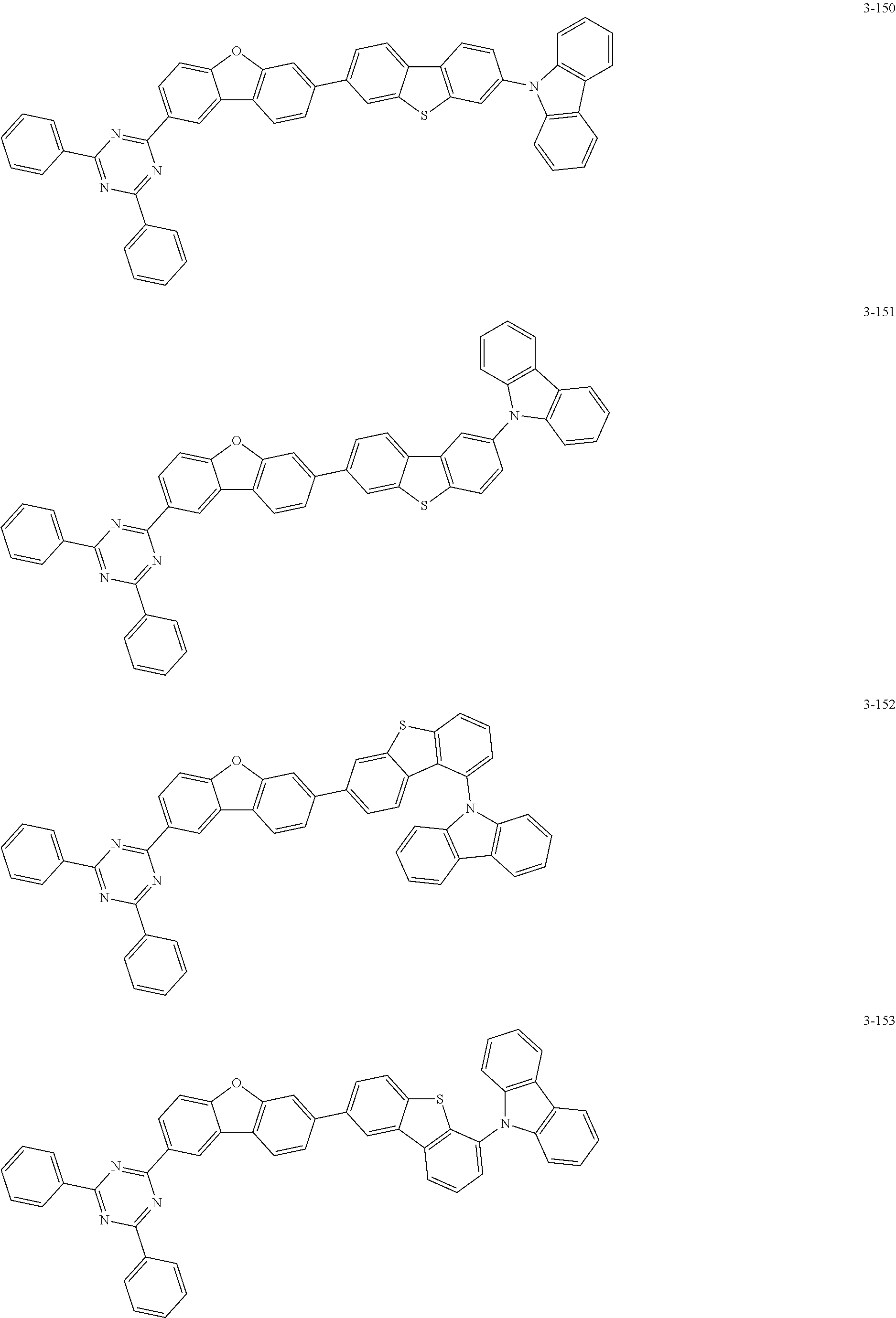 [SMILES: c1ccc(-c2nc(-c3ccccc3)nc(-c3ccc4oc5cc(-c6ccc7c(c6)sc6cc(-n8c9ccccc9c9ccccc98)ccc67)ccc5c4c3)n2)cc1 ; c1ccc(-c2nc(-c3ccccc3)nc(-c3ccc4oc5cc(-c6ccc7c(c6)sc6ccc(-n8c9ccccc9c9ccccc98)cc67)ccc5c4c3)n2)cc1 ; c1ccc(-c2nc(-c3ccccc3)nc(-c3ccc4oc5cc(-c6ccc7c(c6)sc6cccc(-n8c9ccccc9c9ccccc98)c67)ccc5c4c3)n2)cc1 ; c1ccc(-c2nc(-c3ccccc3)nc(-c3ccc4oc5cc(-c6ccc7sc8c(-n9c%10ccccc%10c%10ccccc%109)cccc8c7c6)ccc5c4c3)n2)cc1]

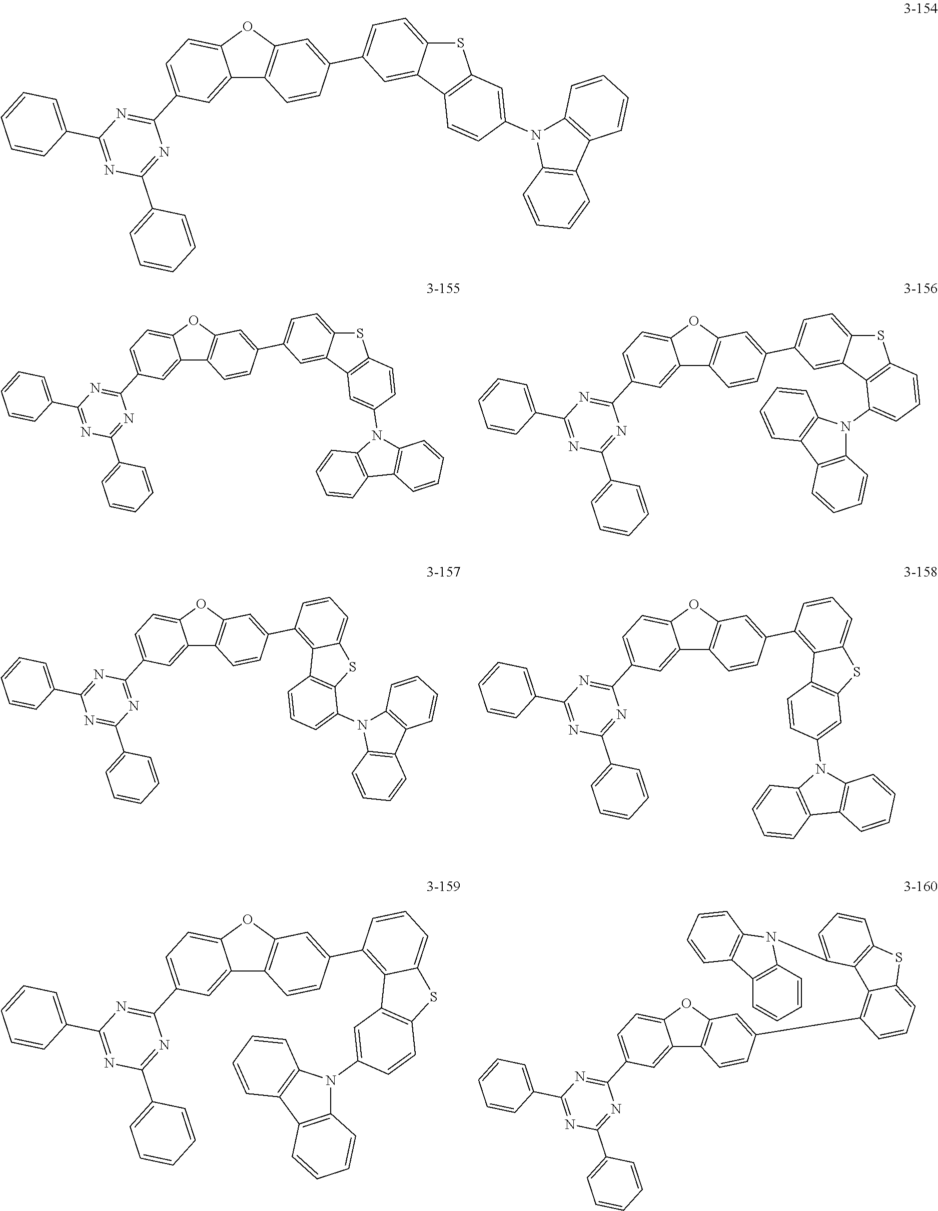

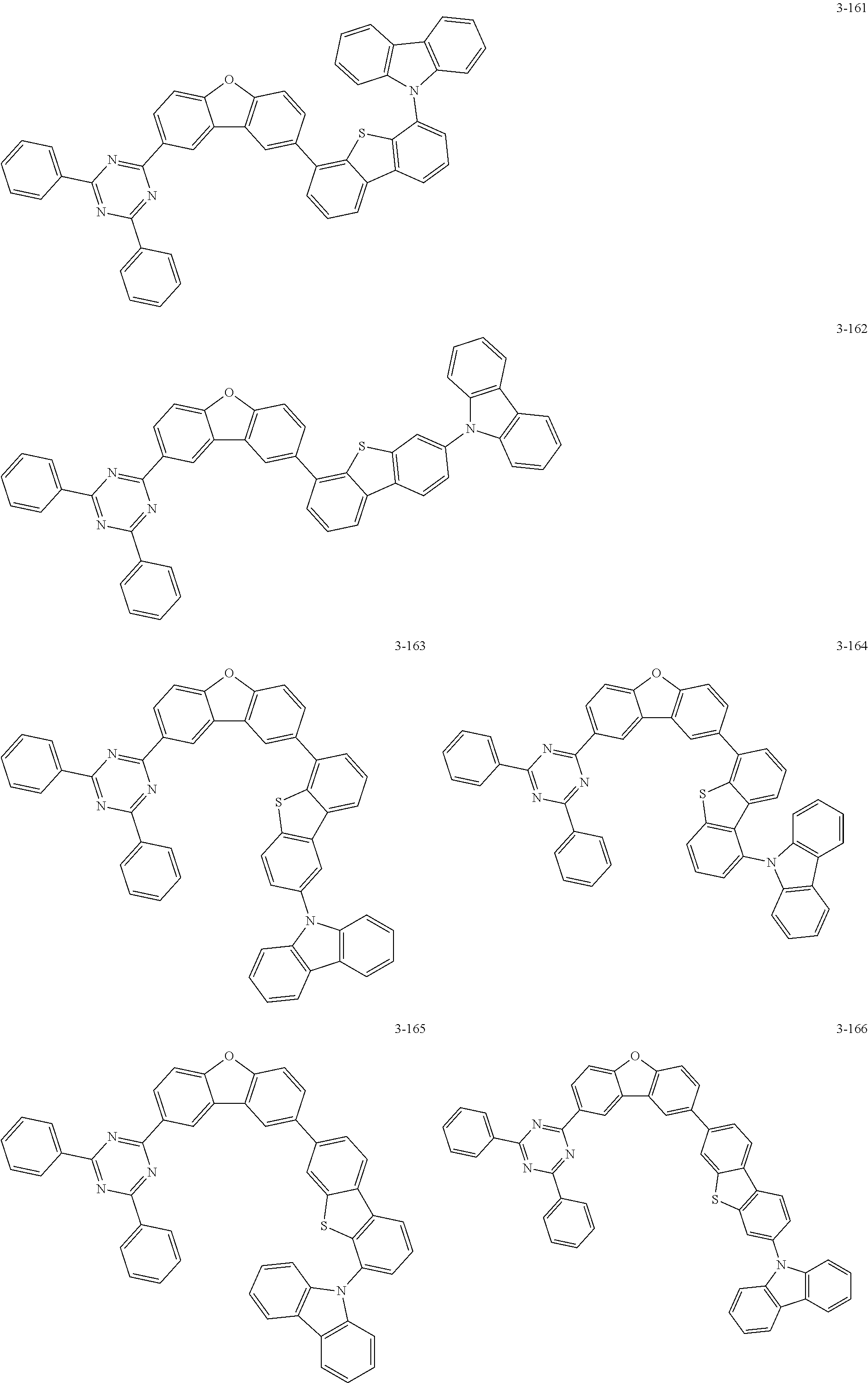

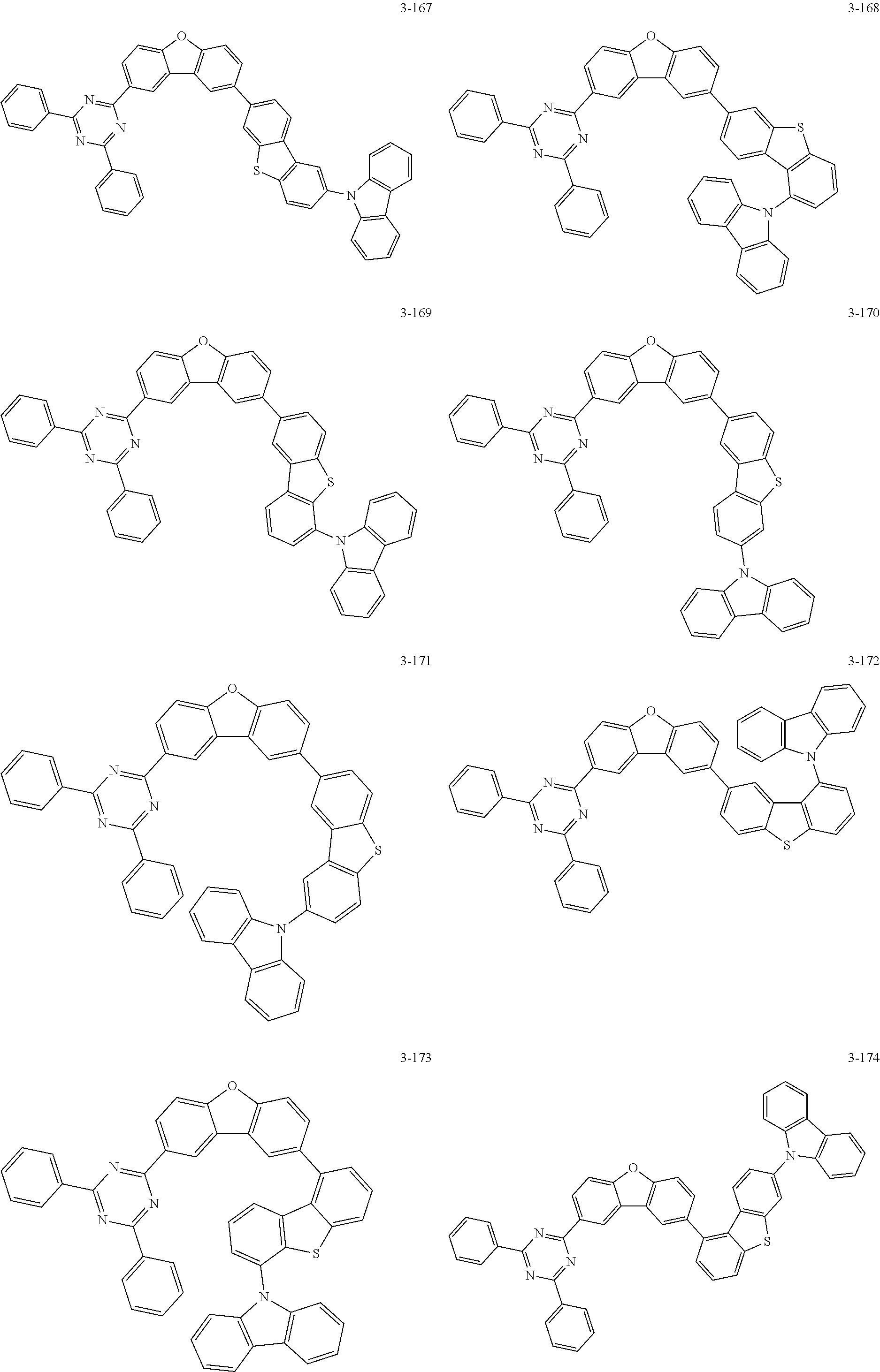

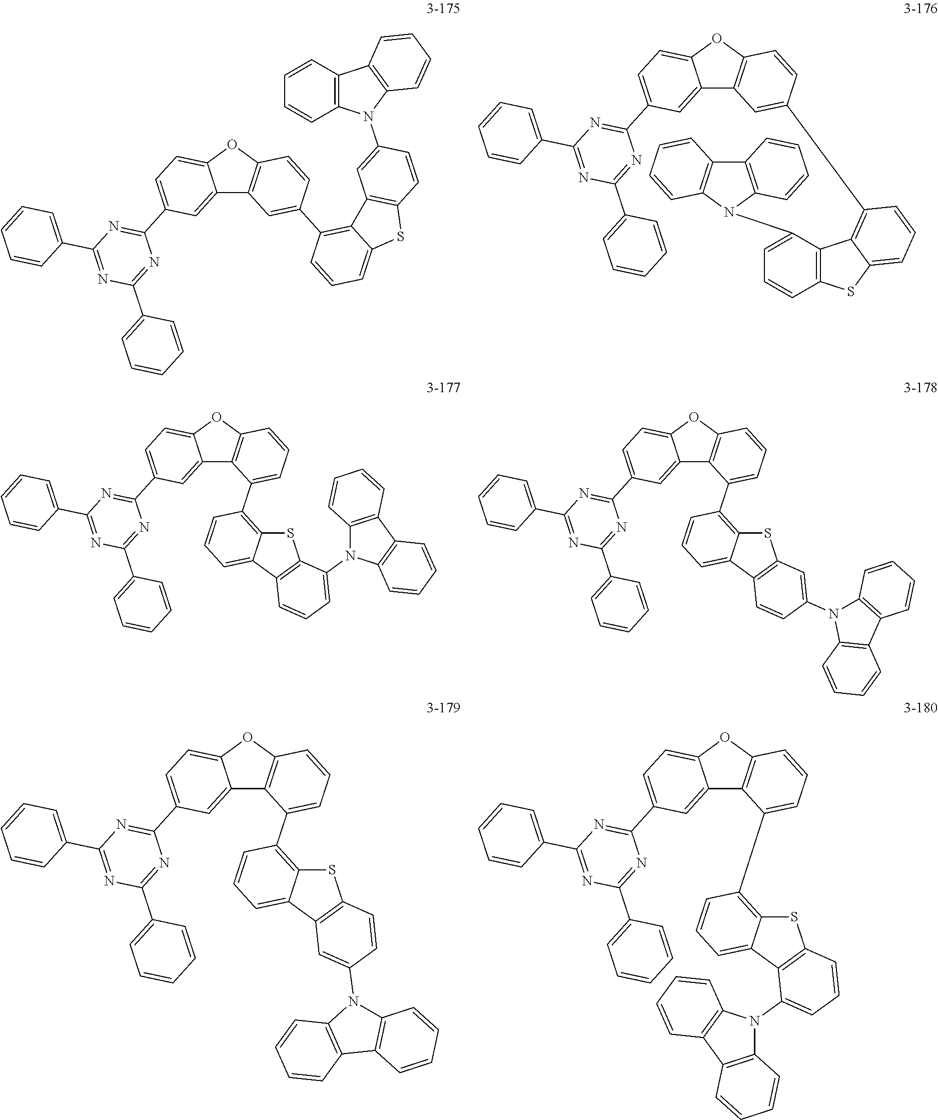

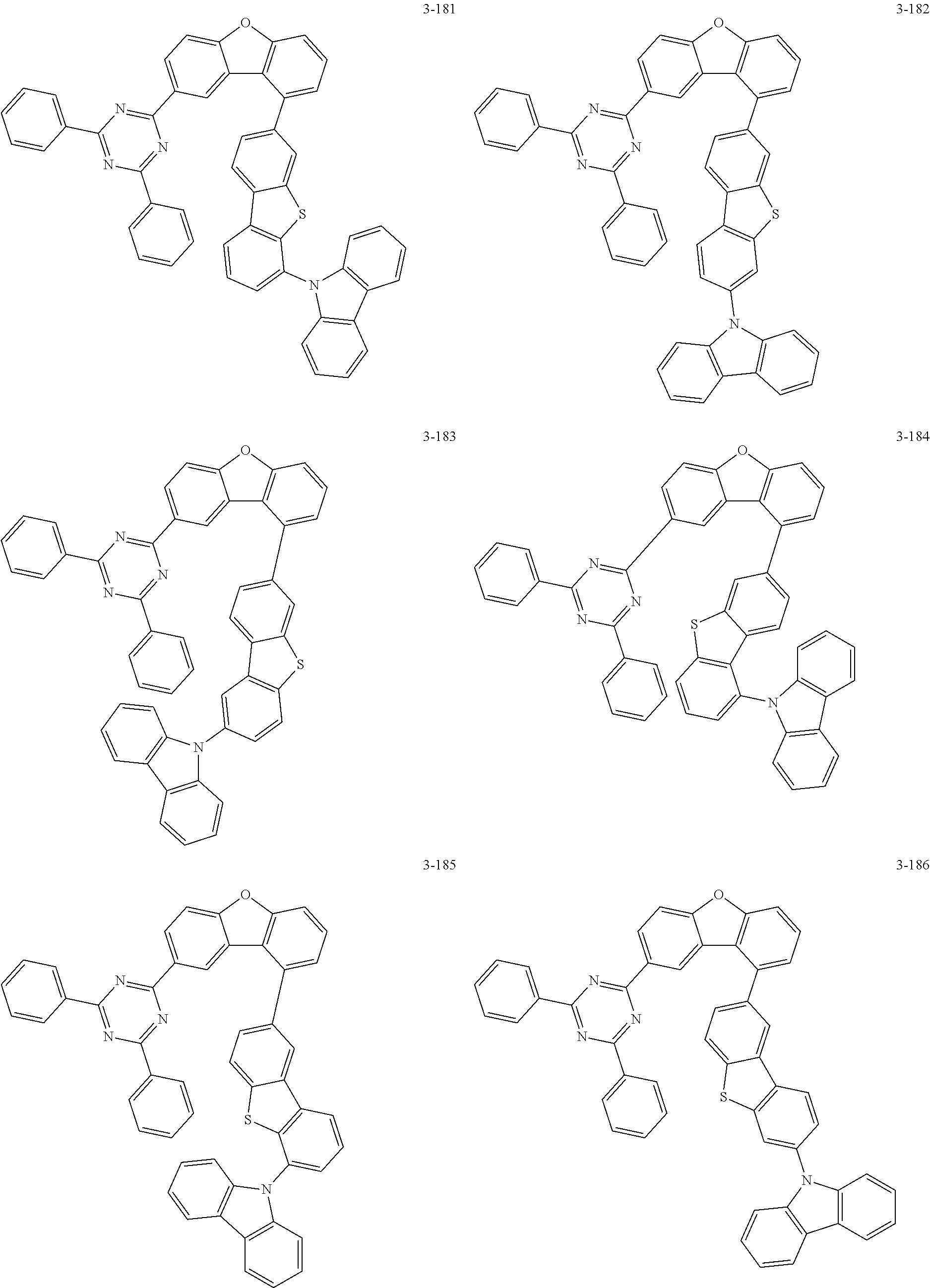

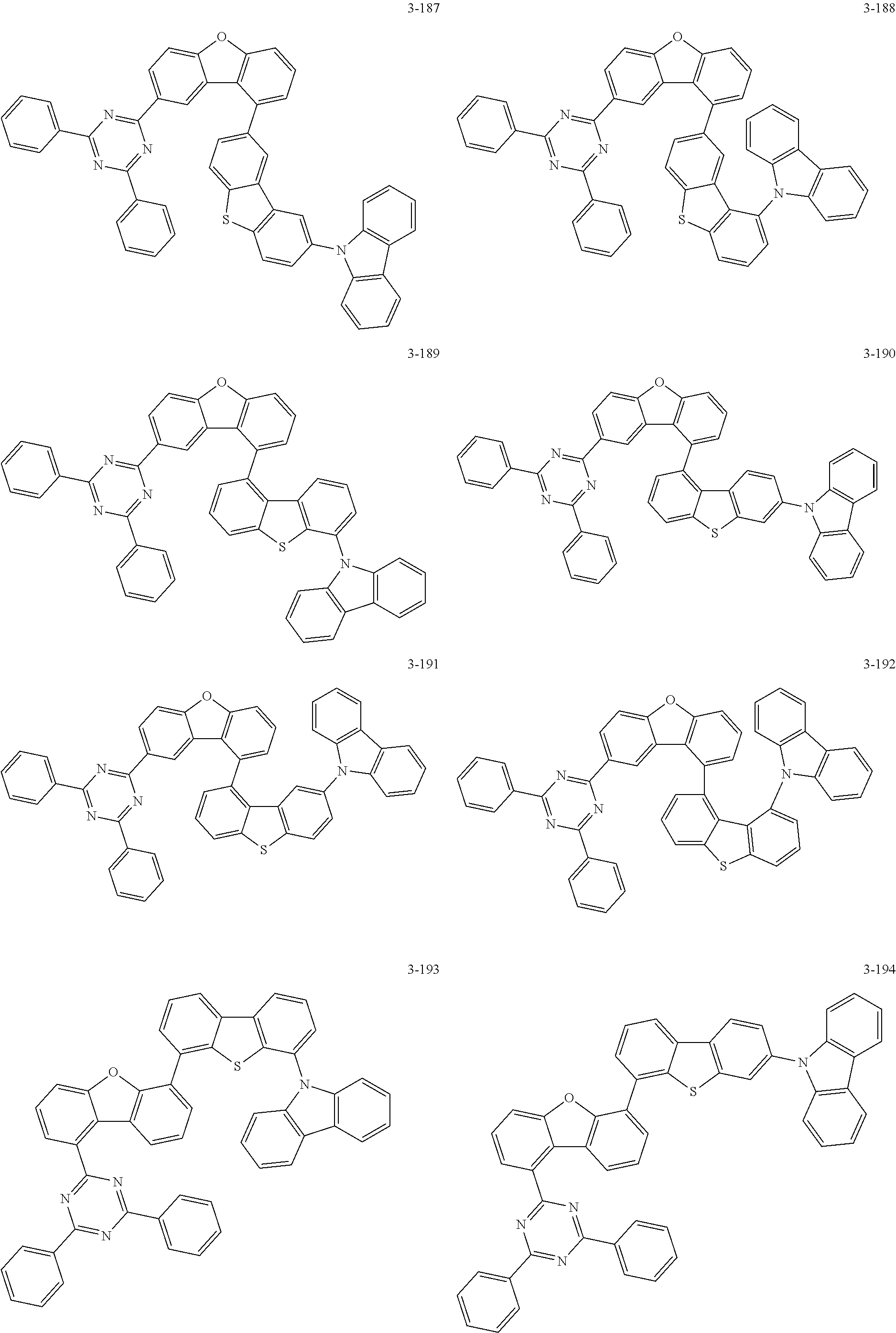

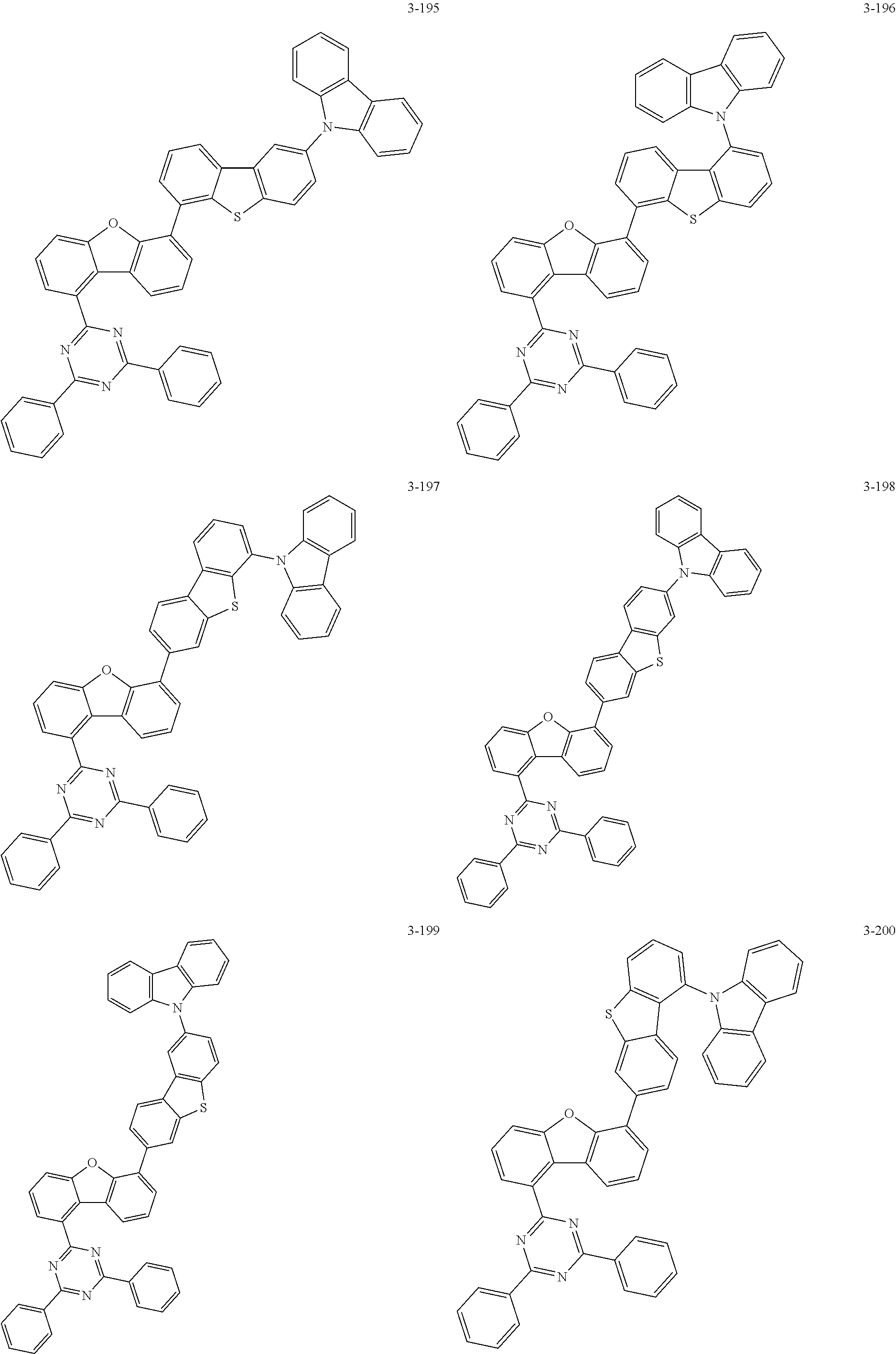

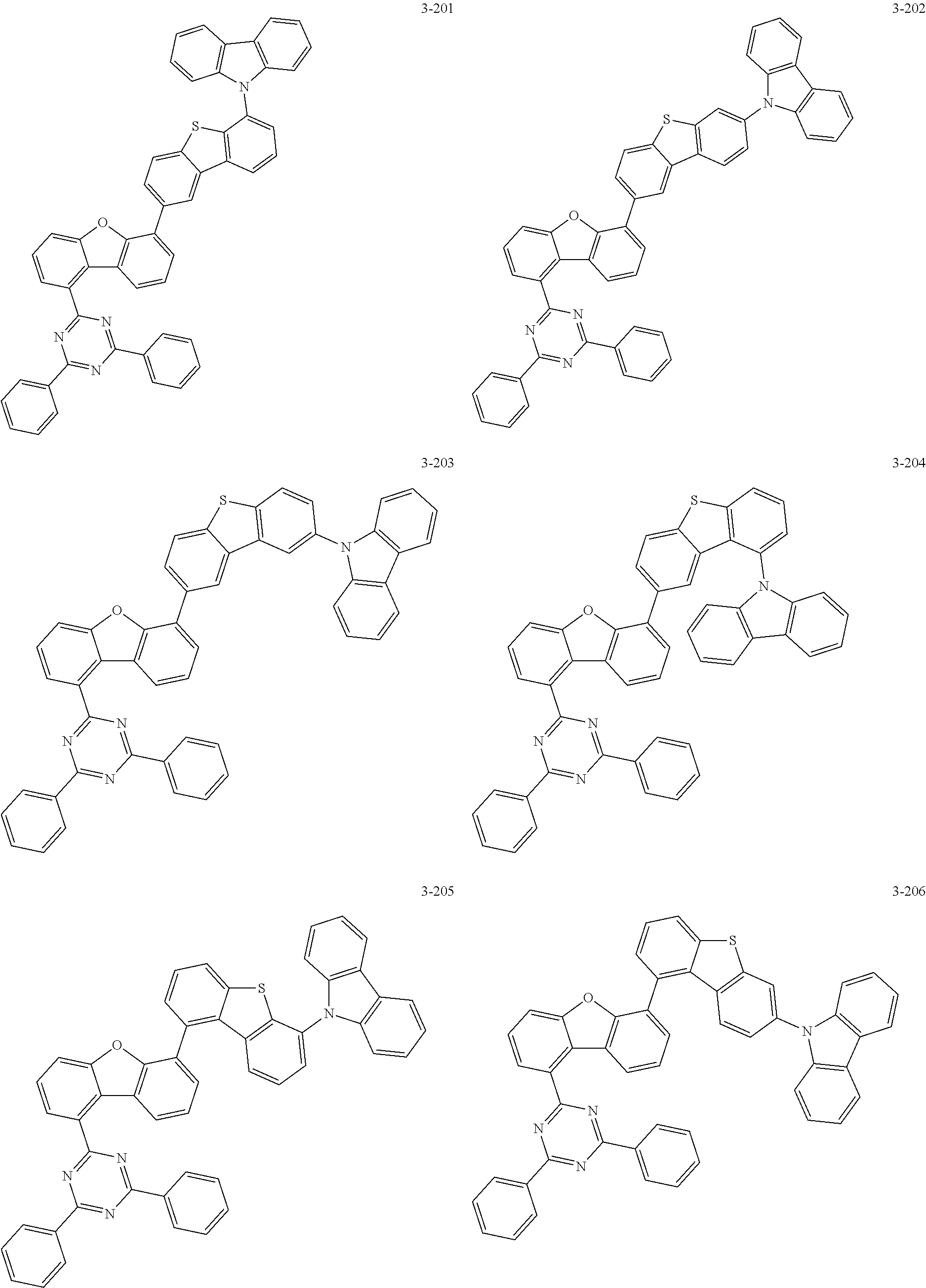

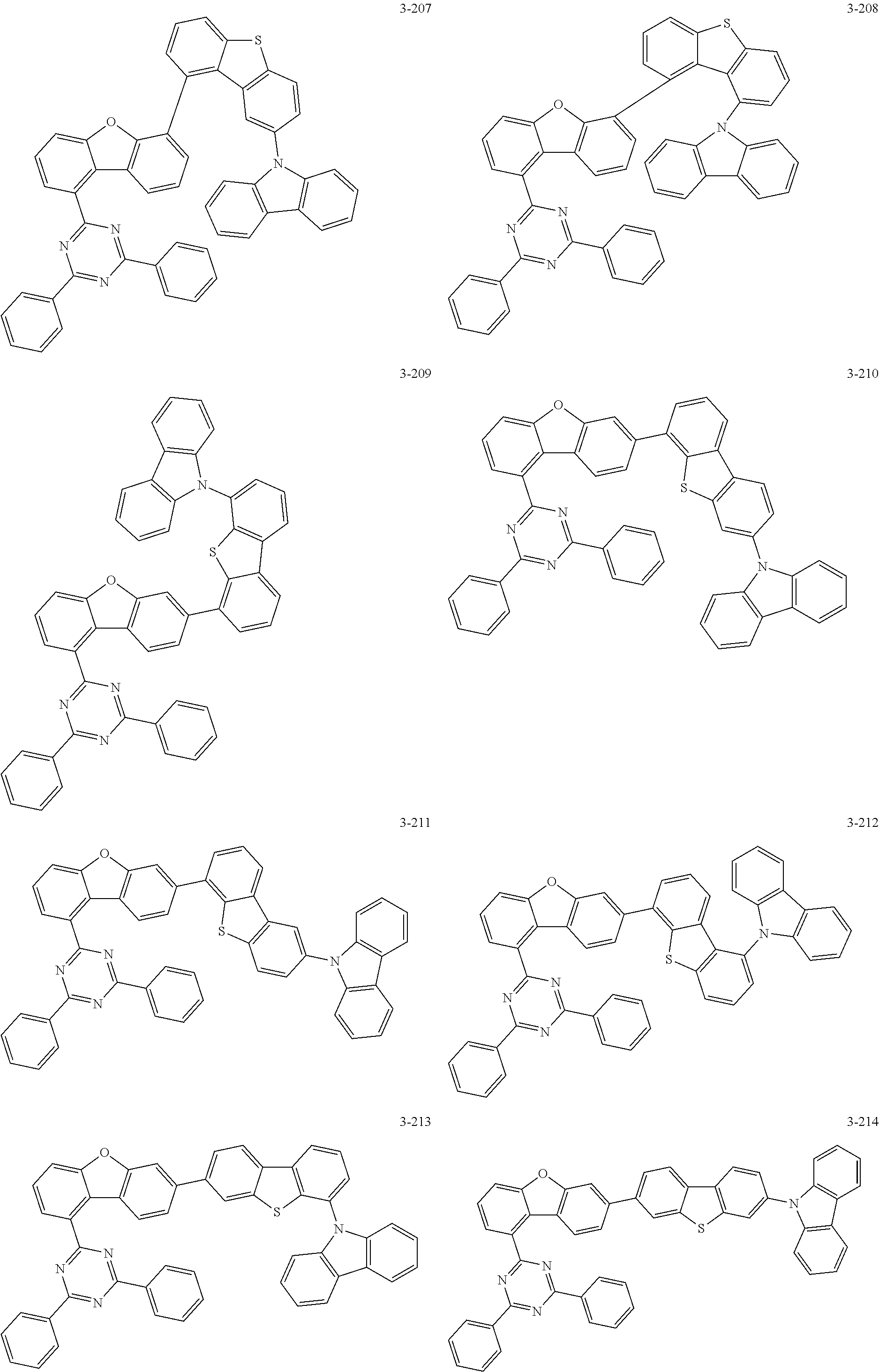

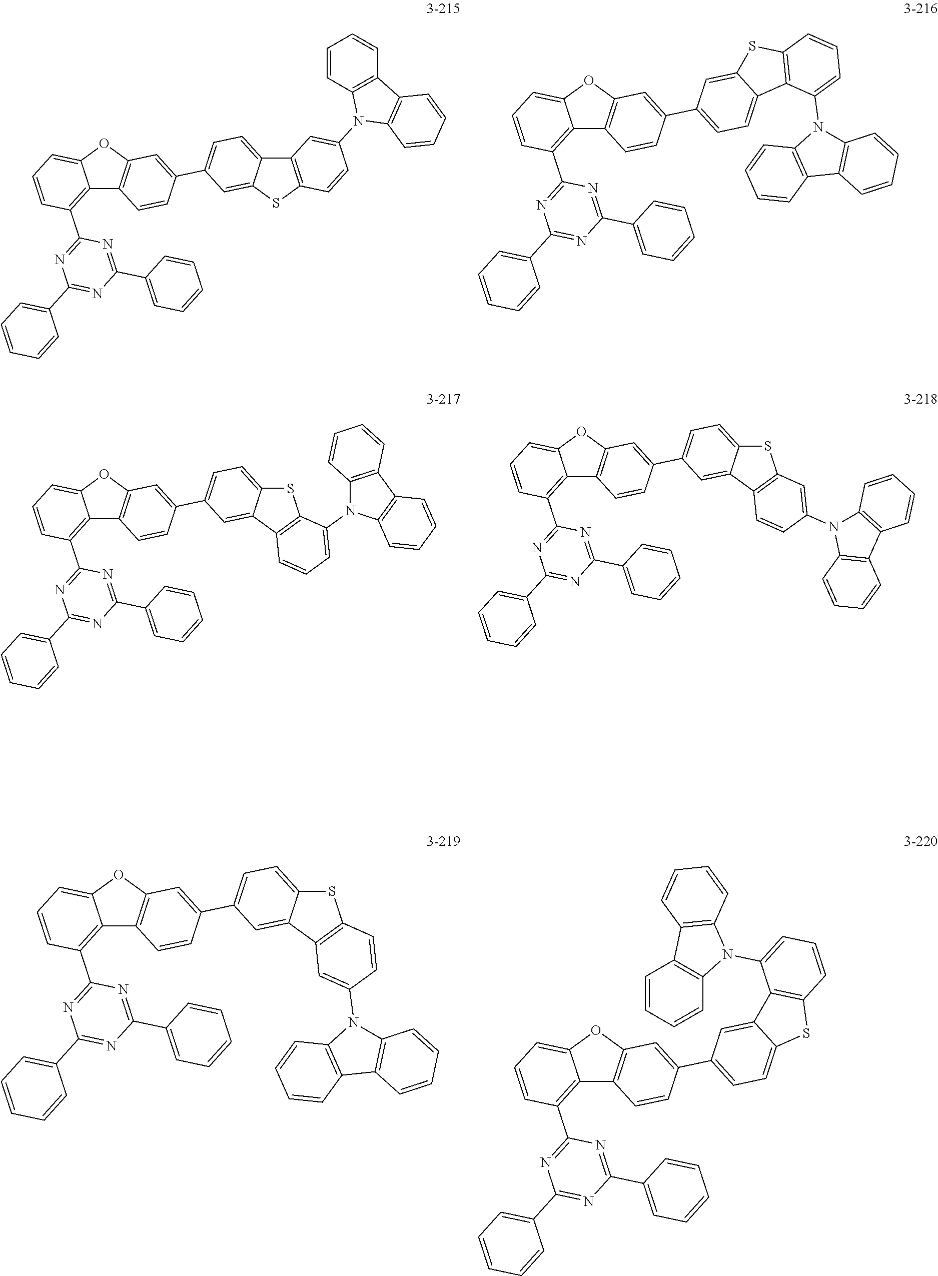

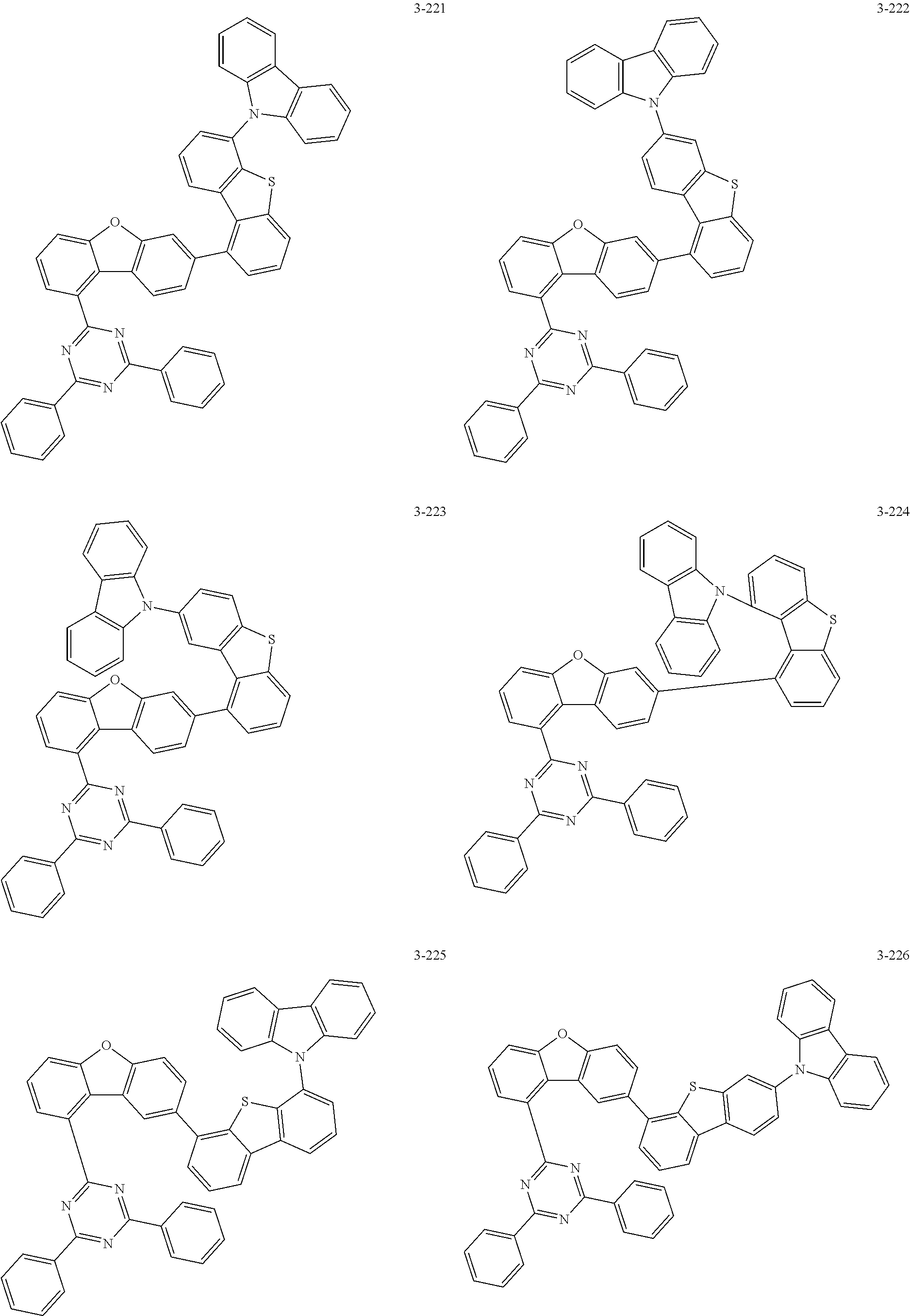

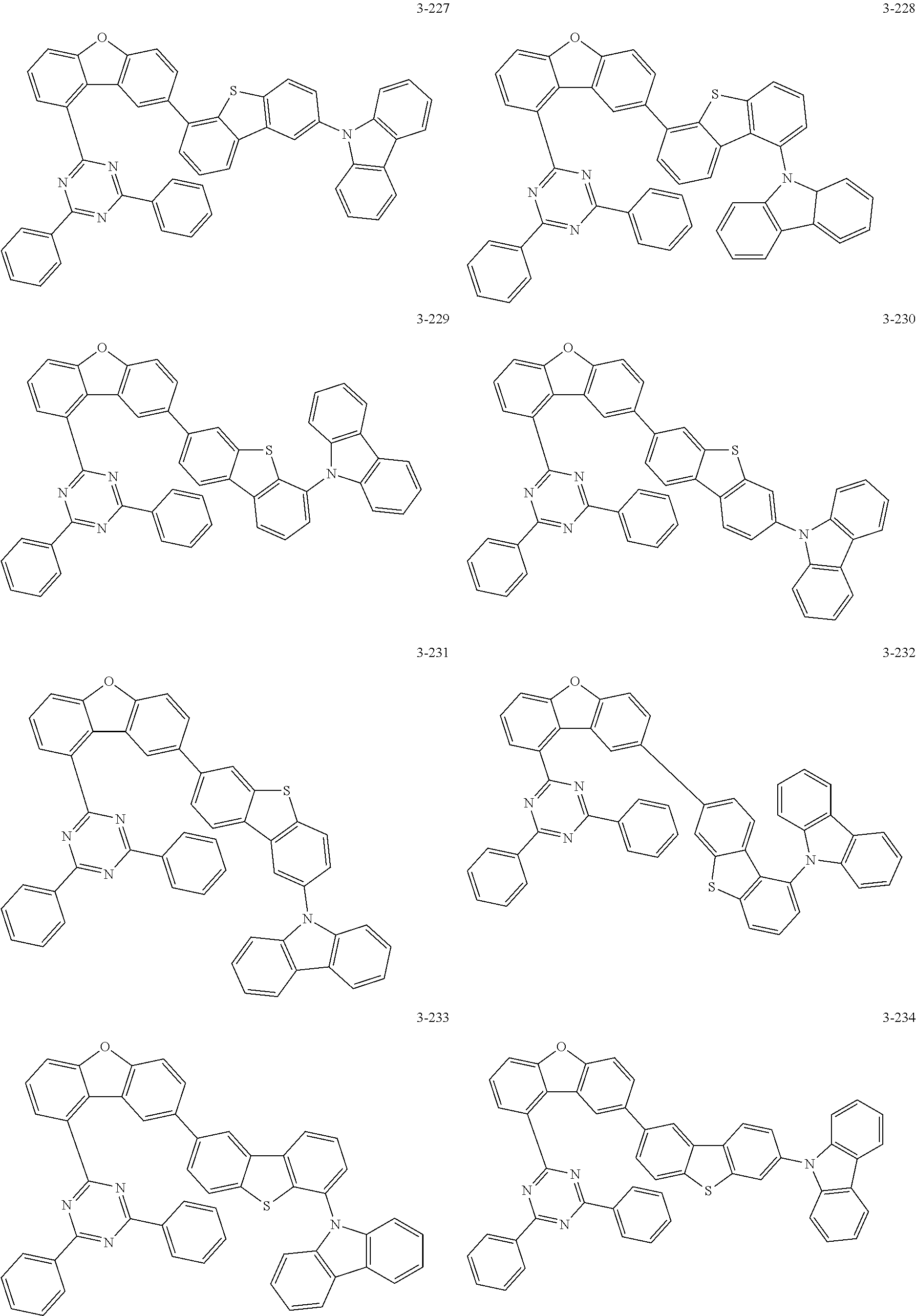

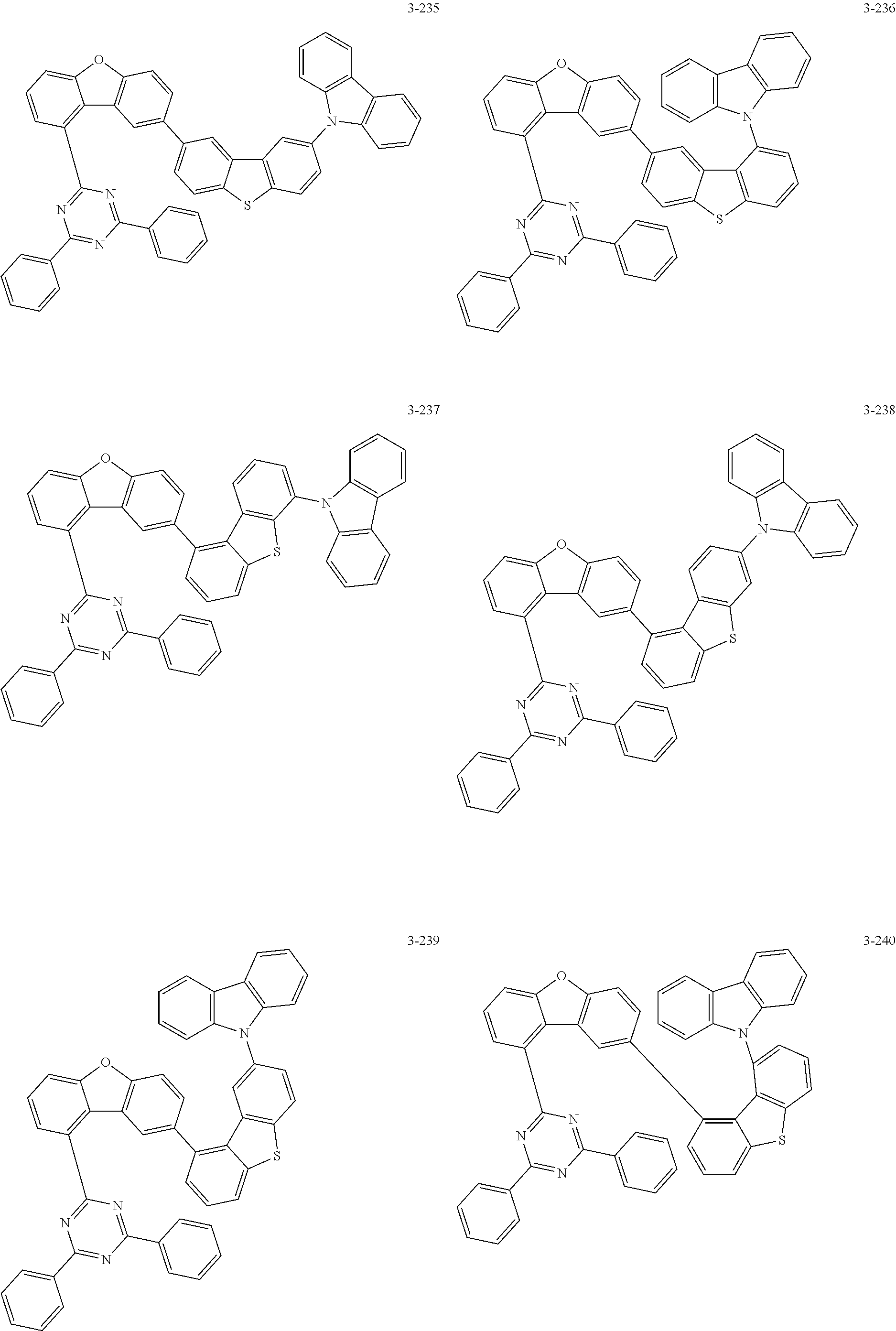

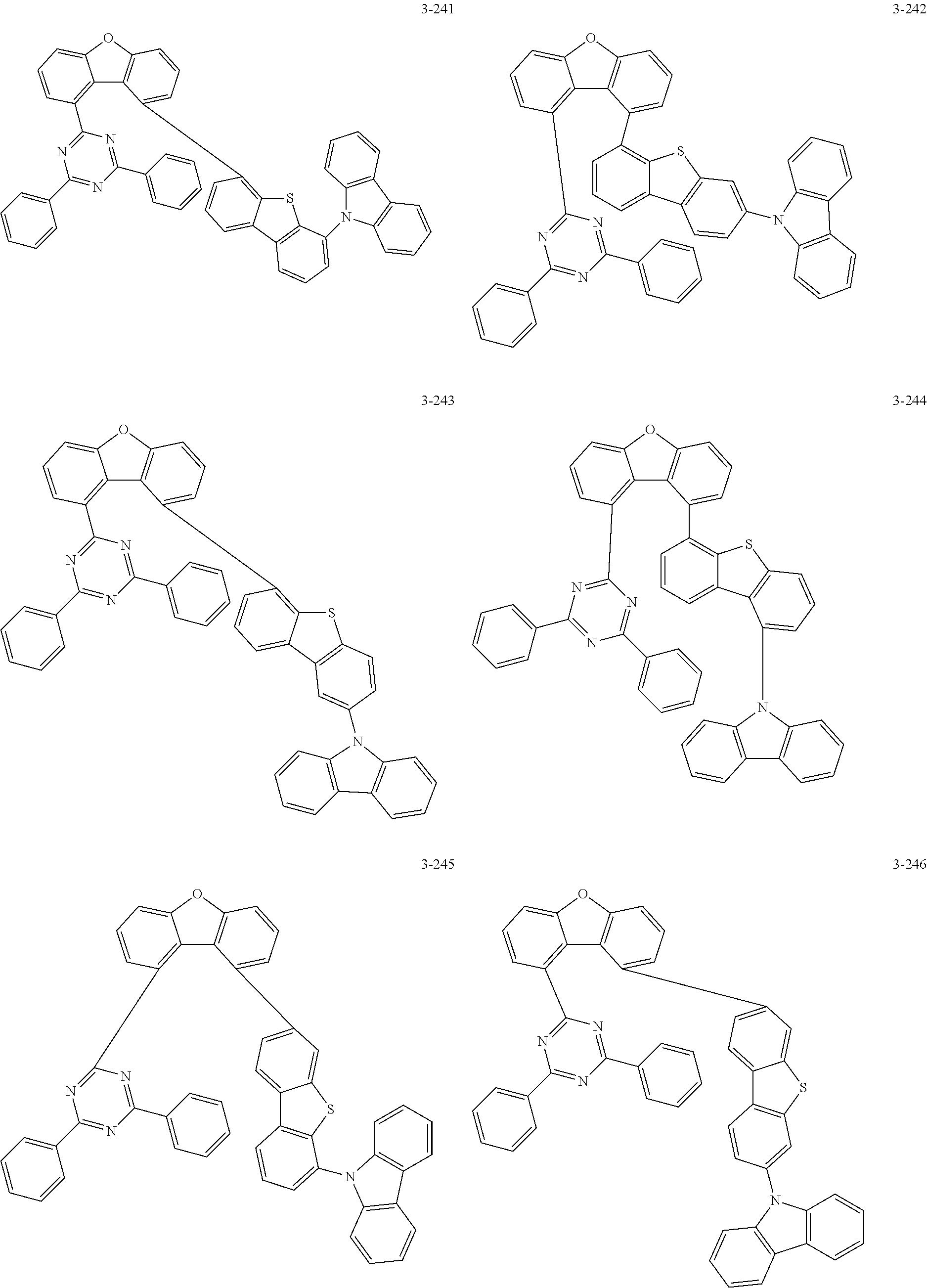

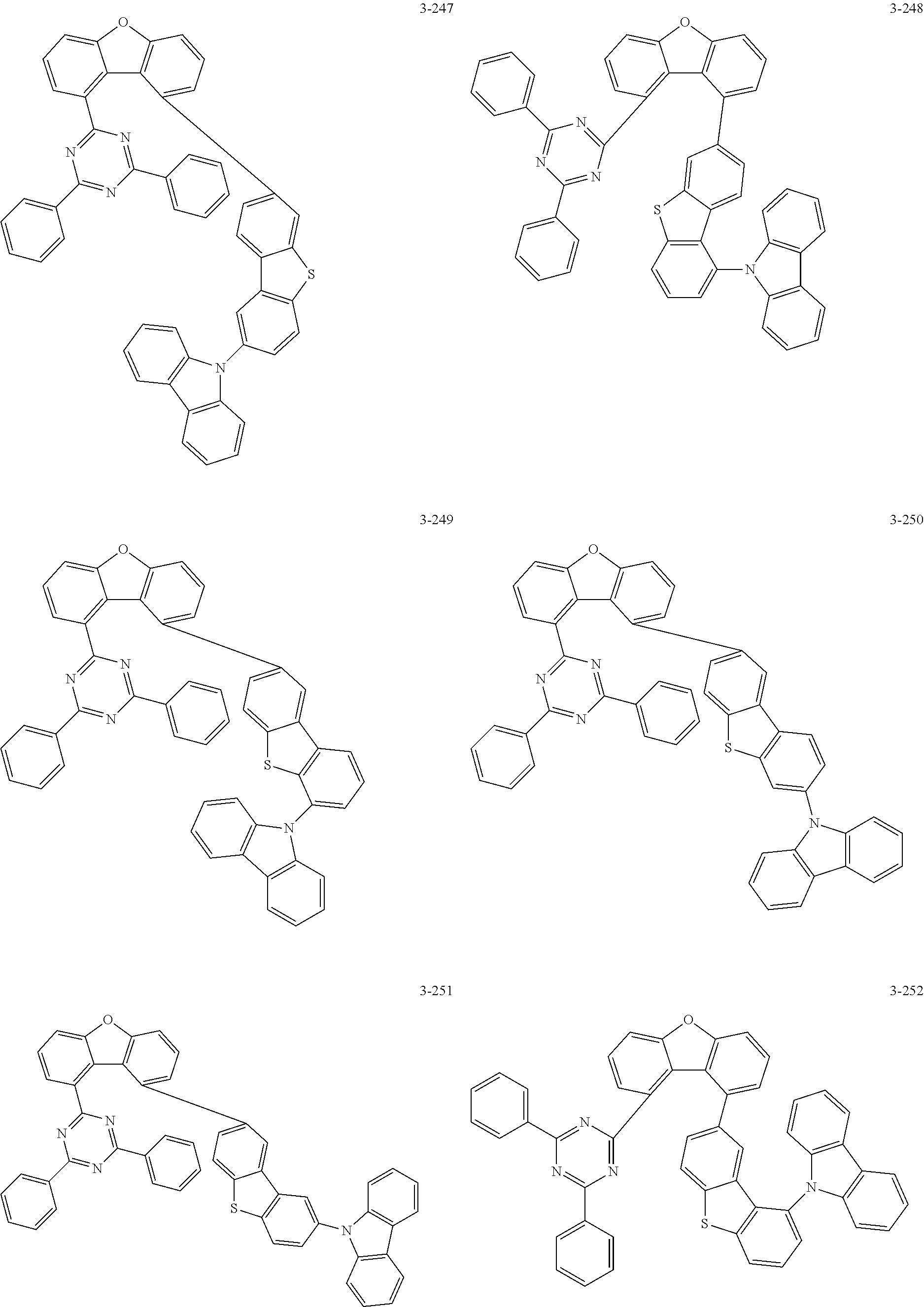

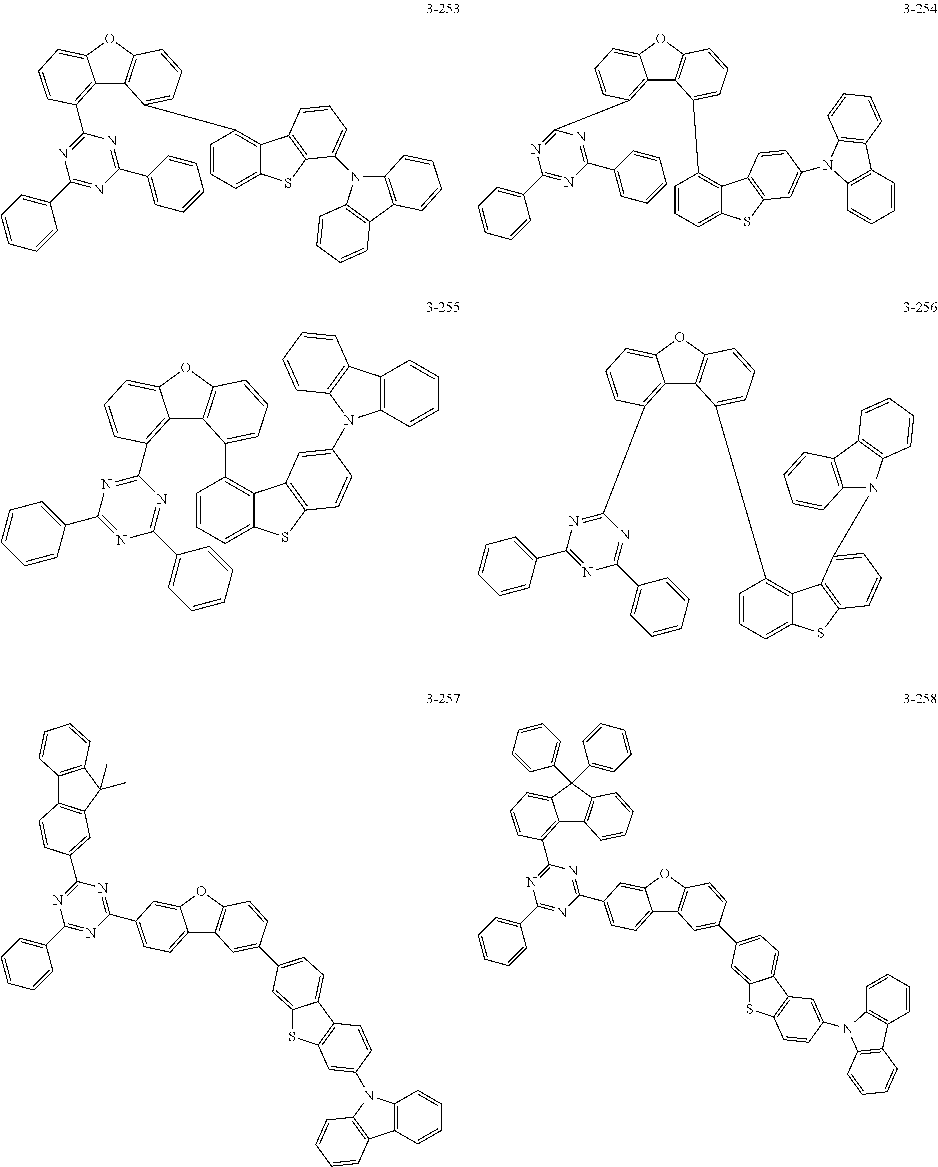

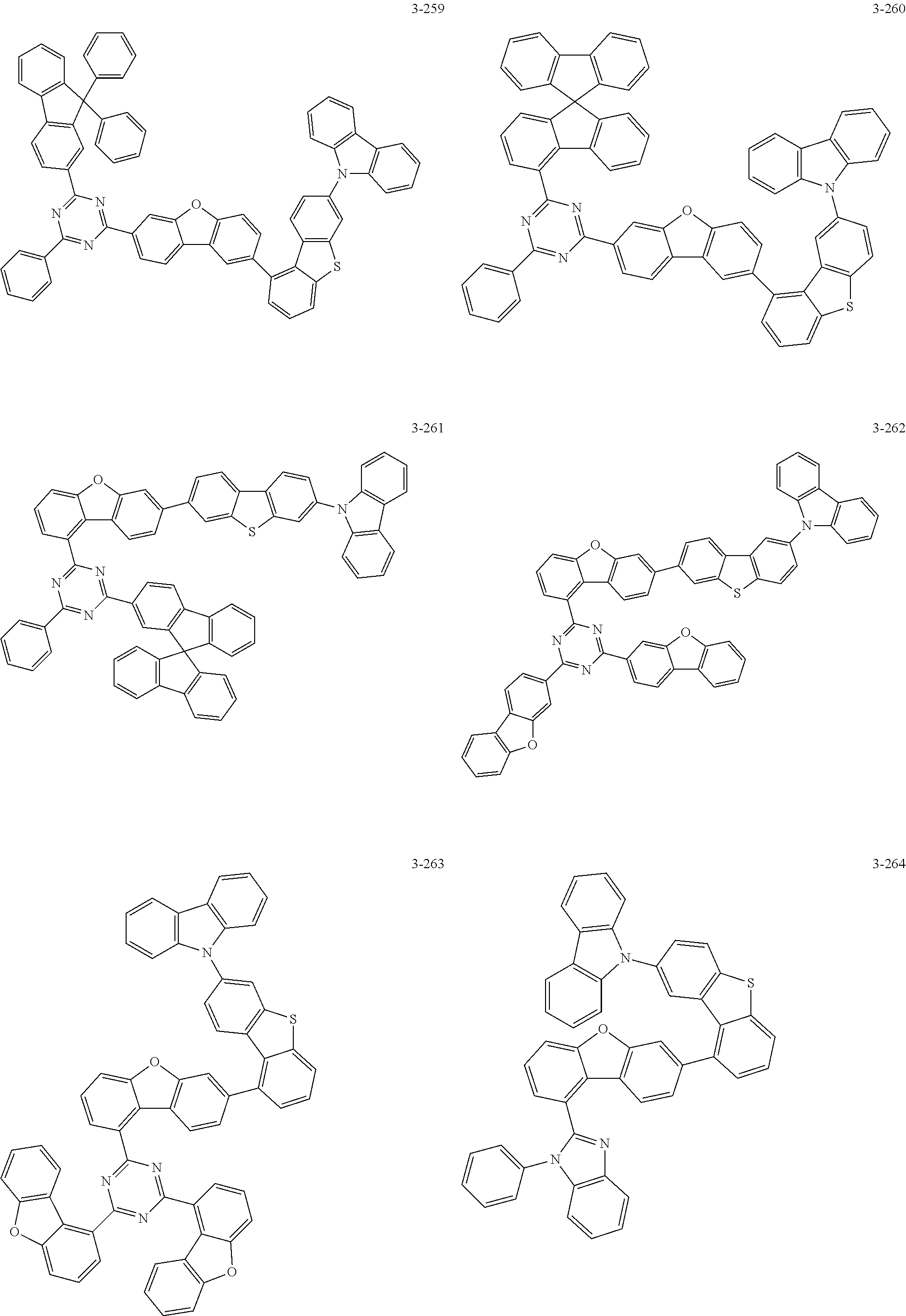

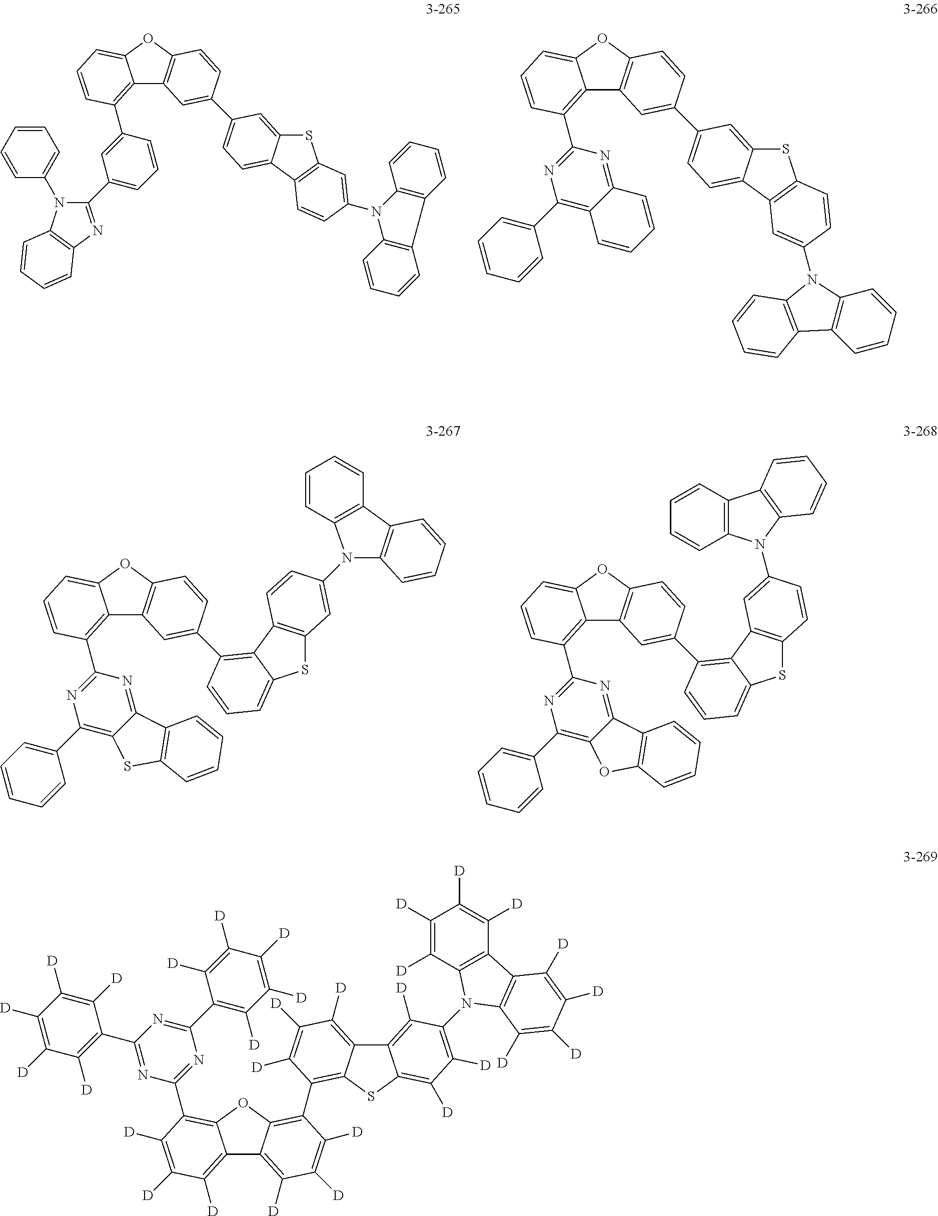

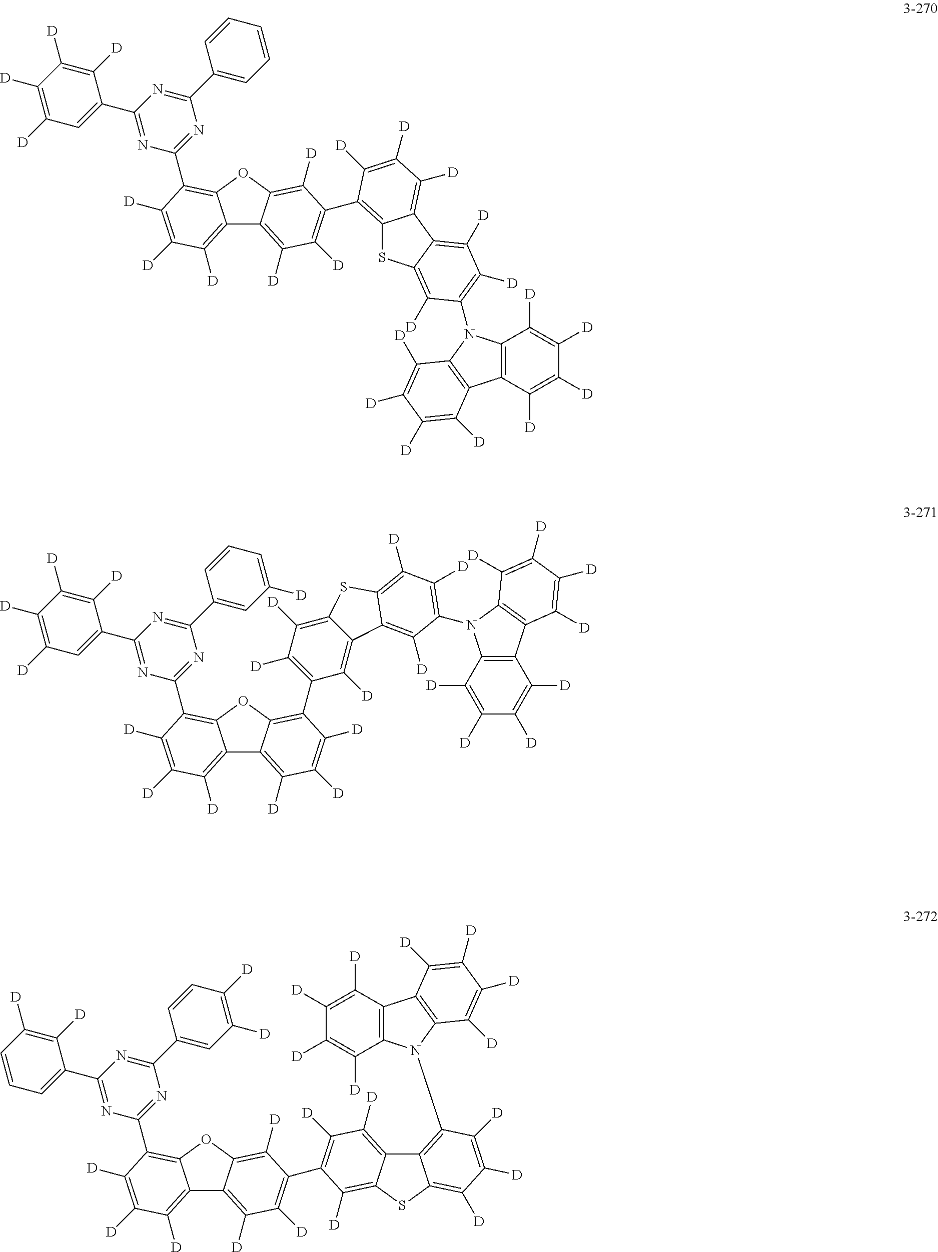

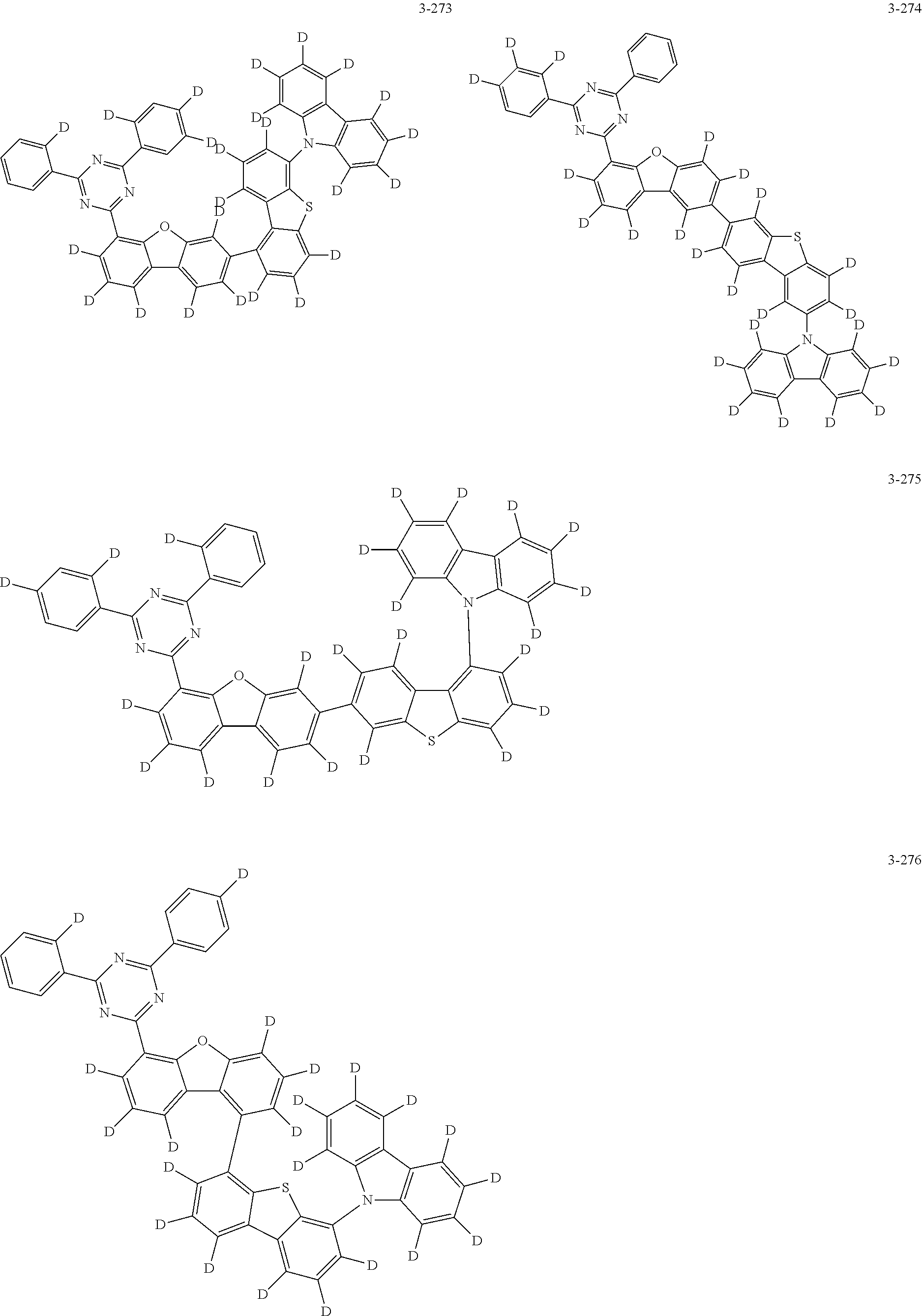

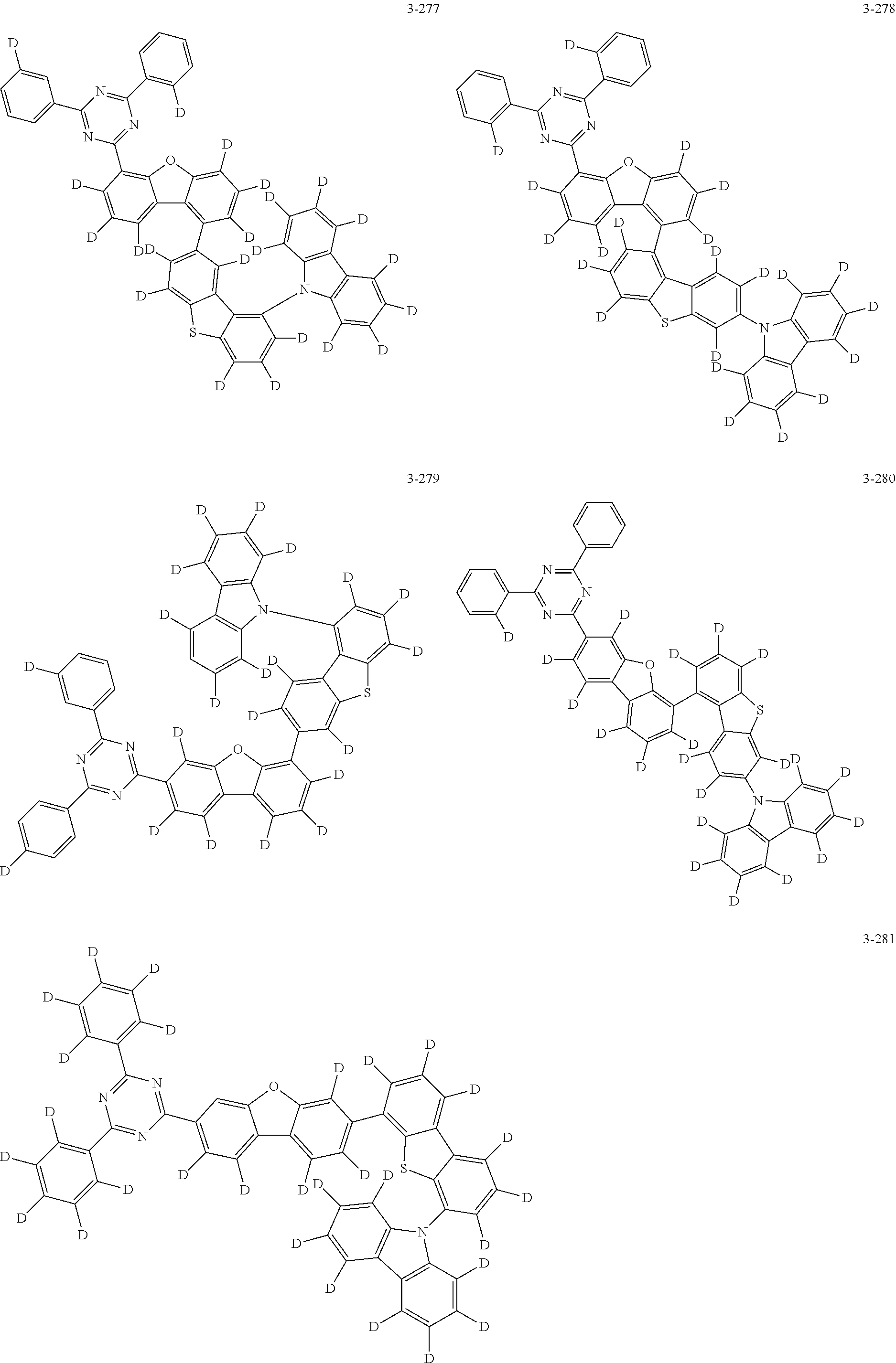

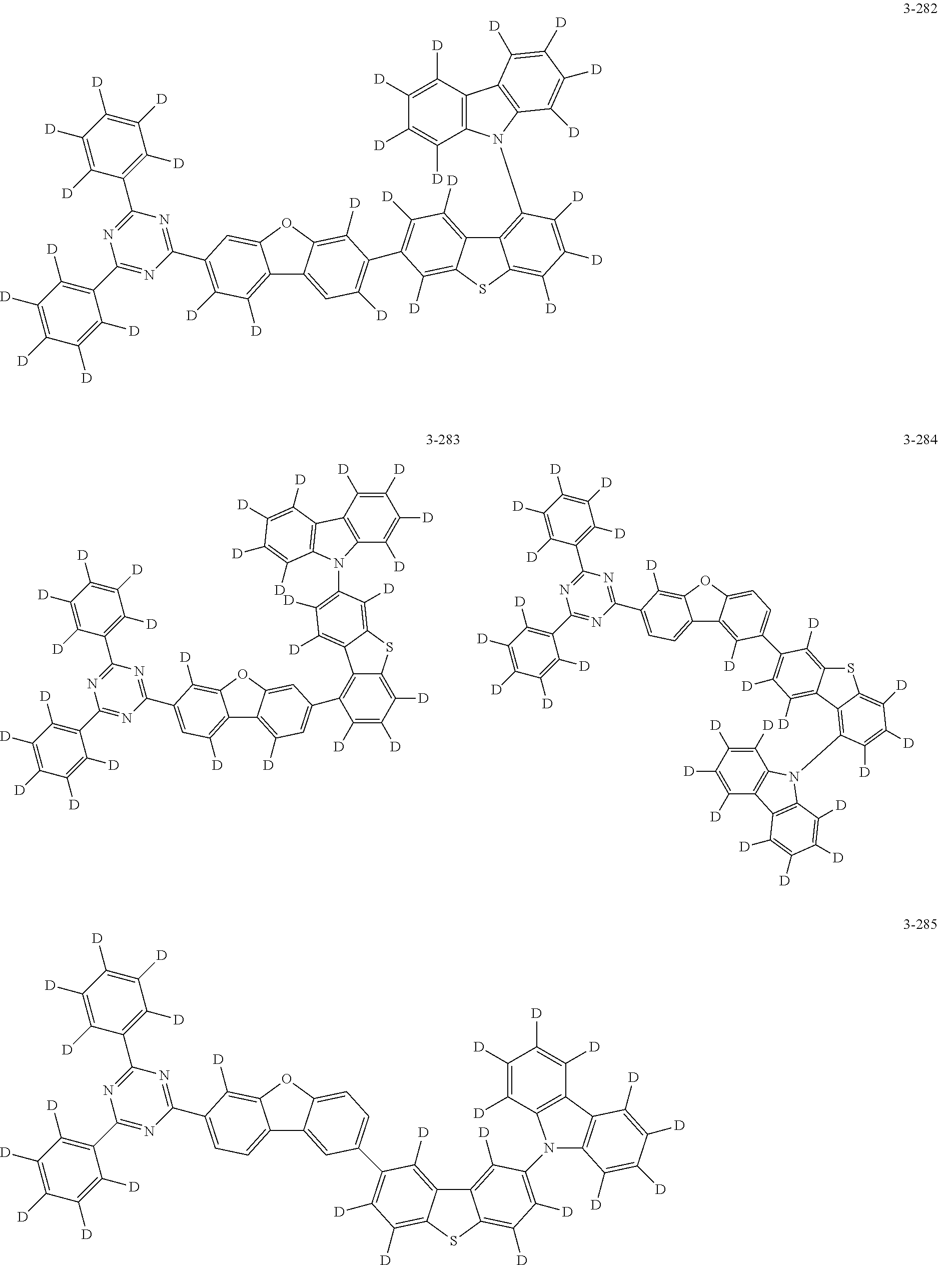

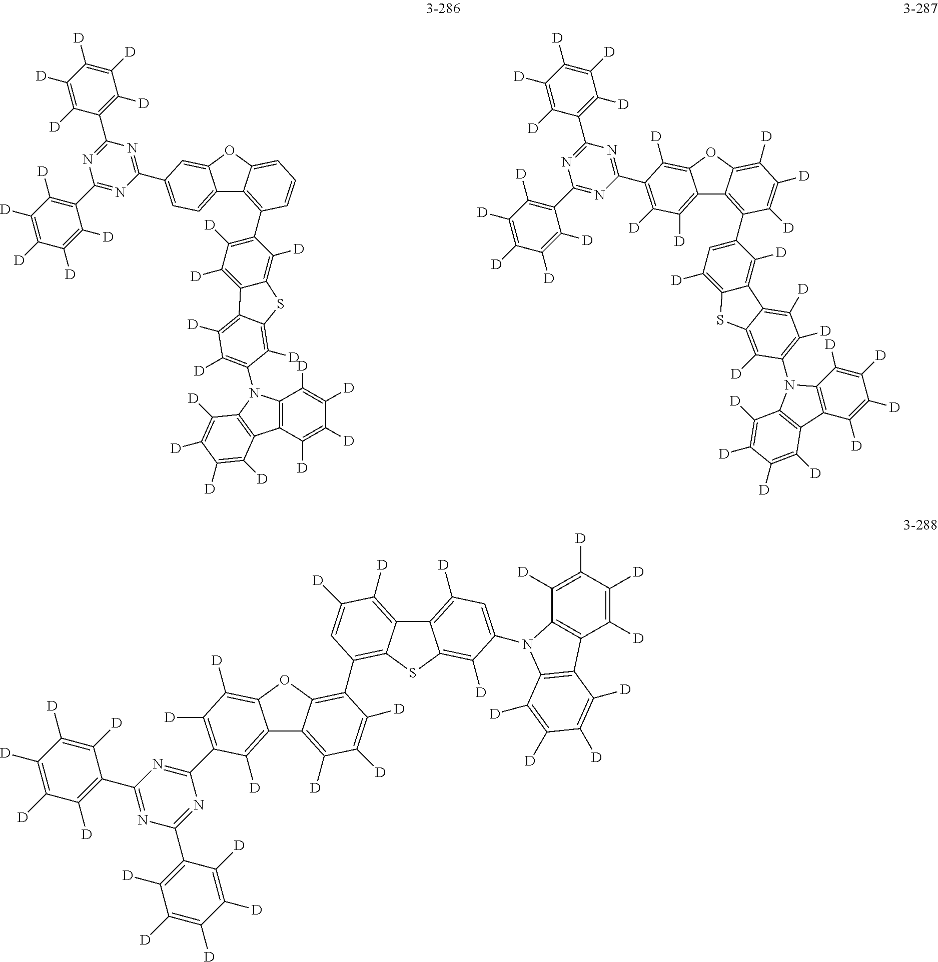

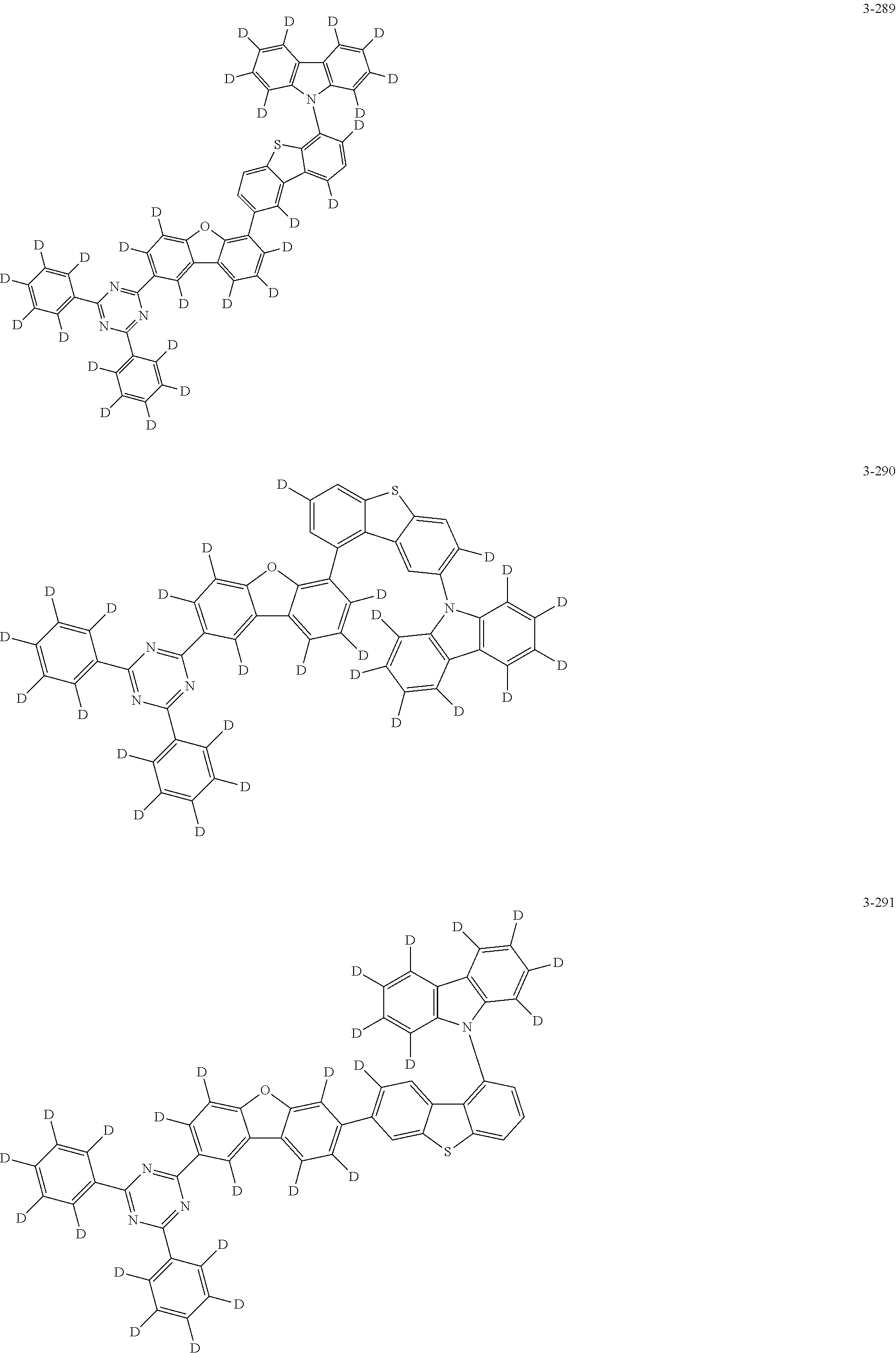

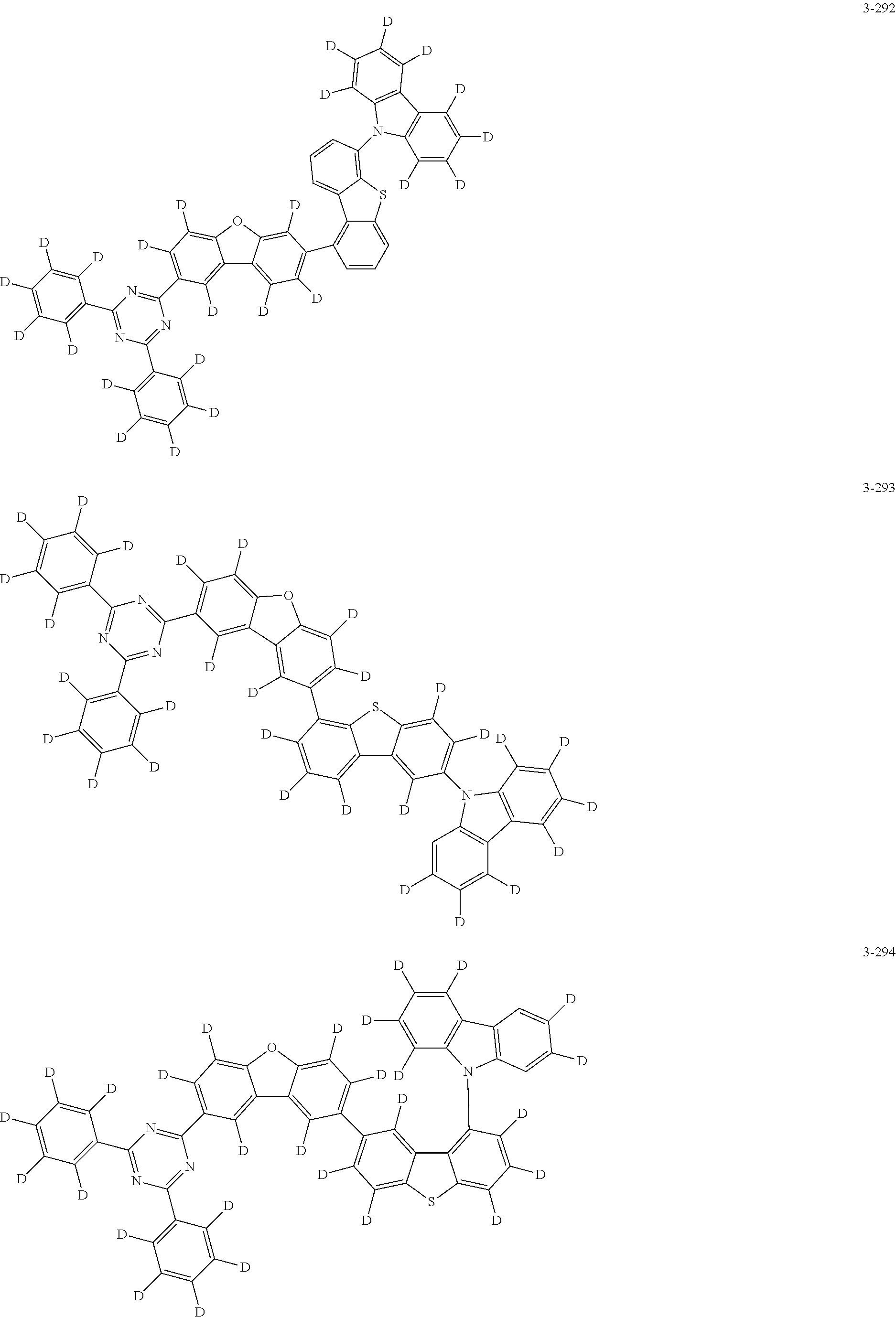

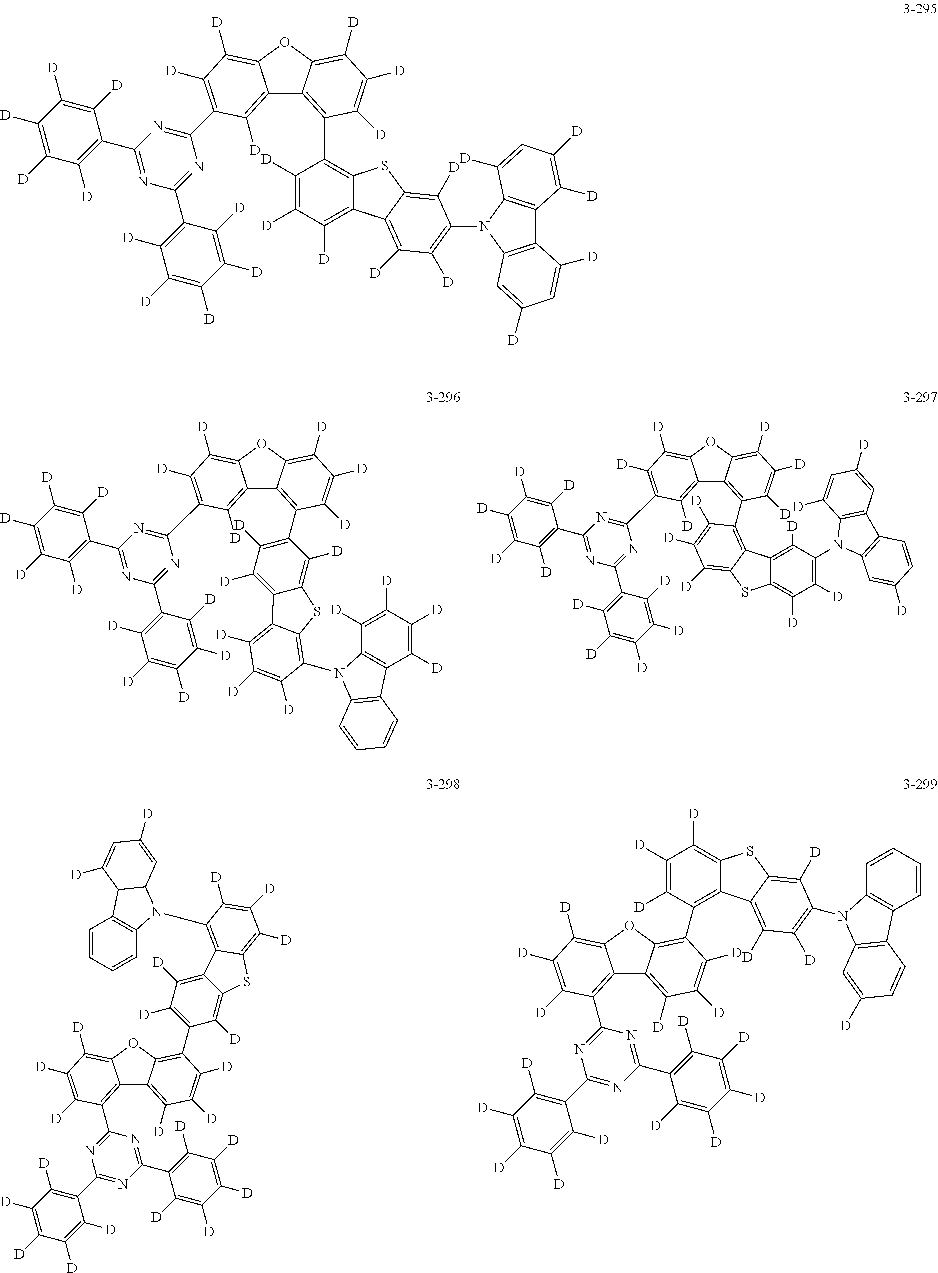

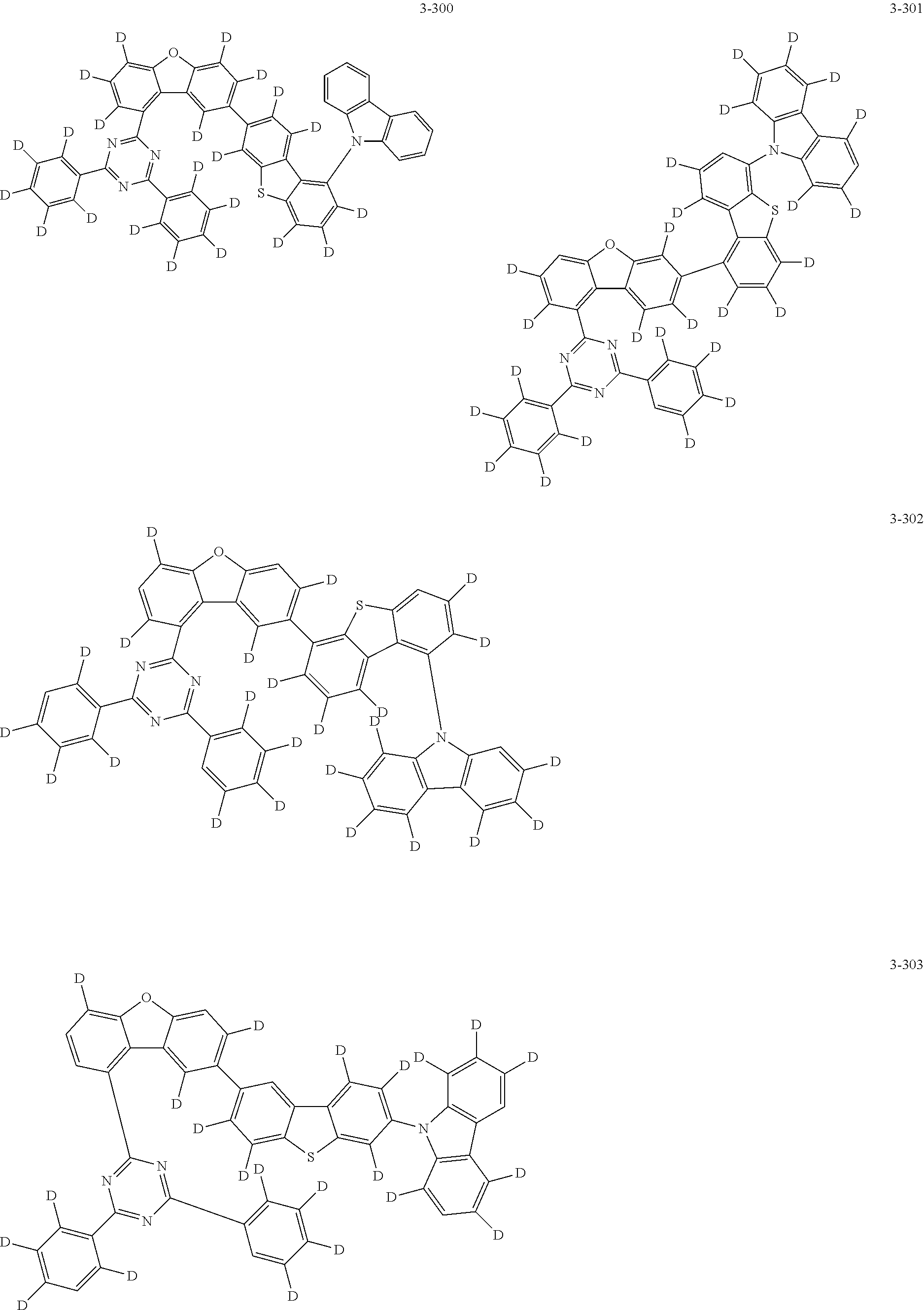

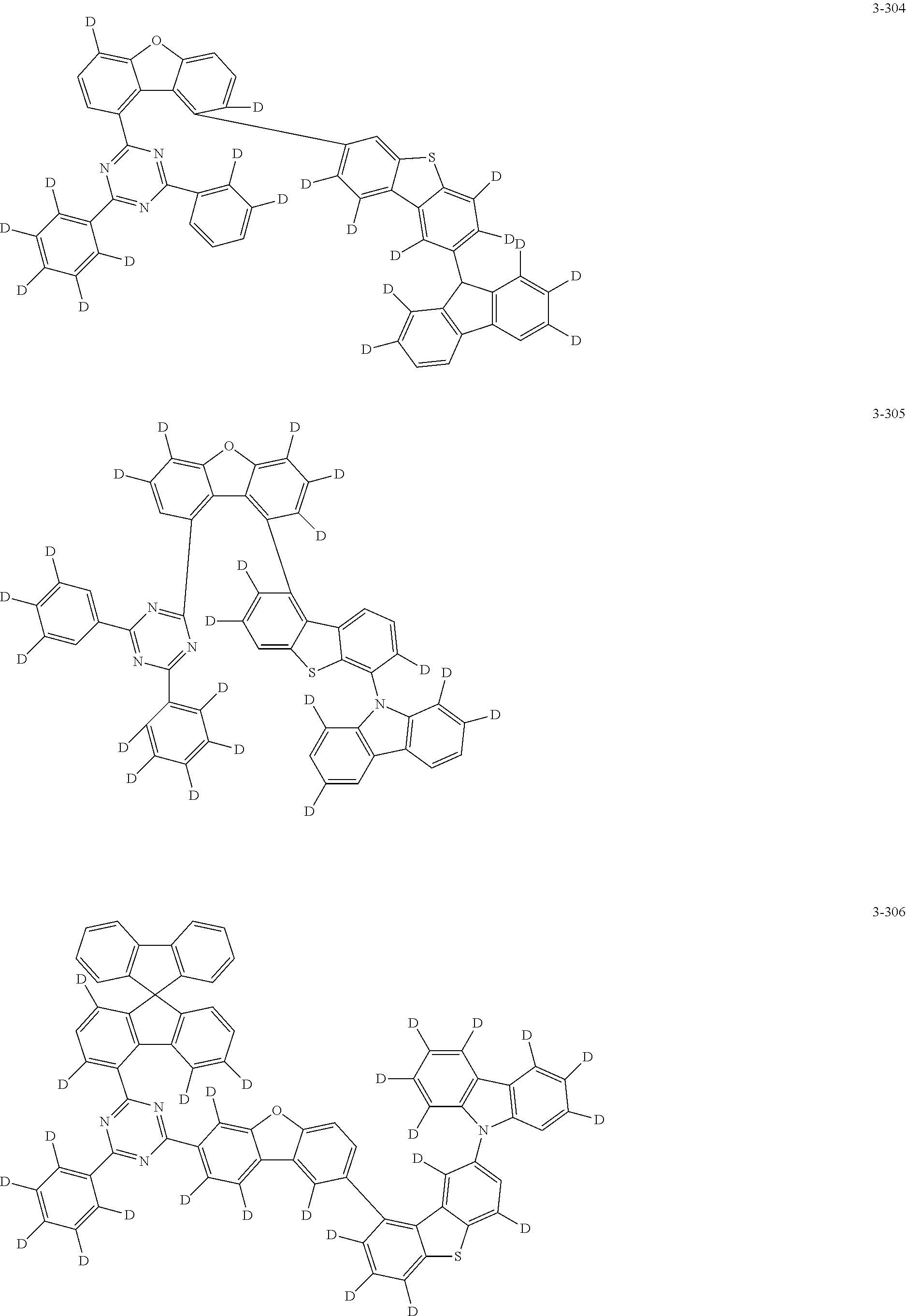

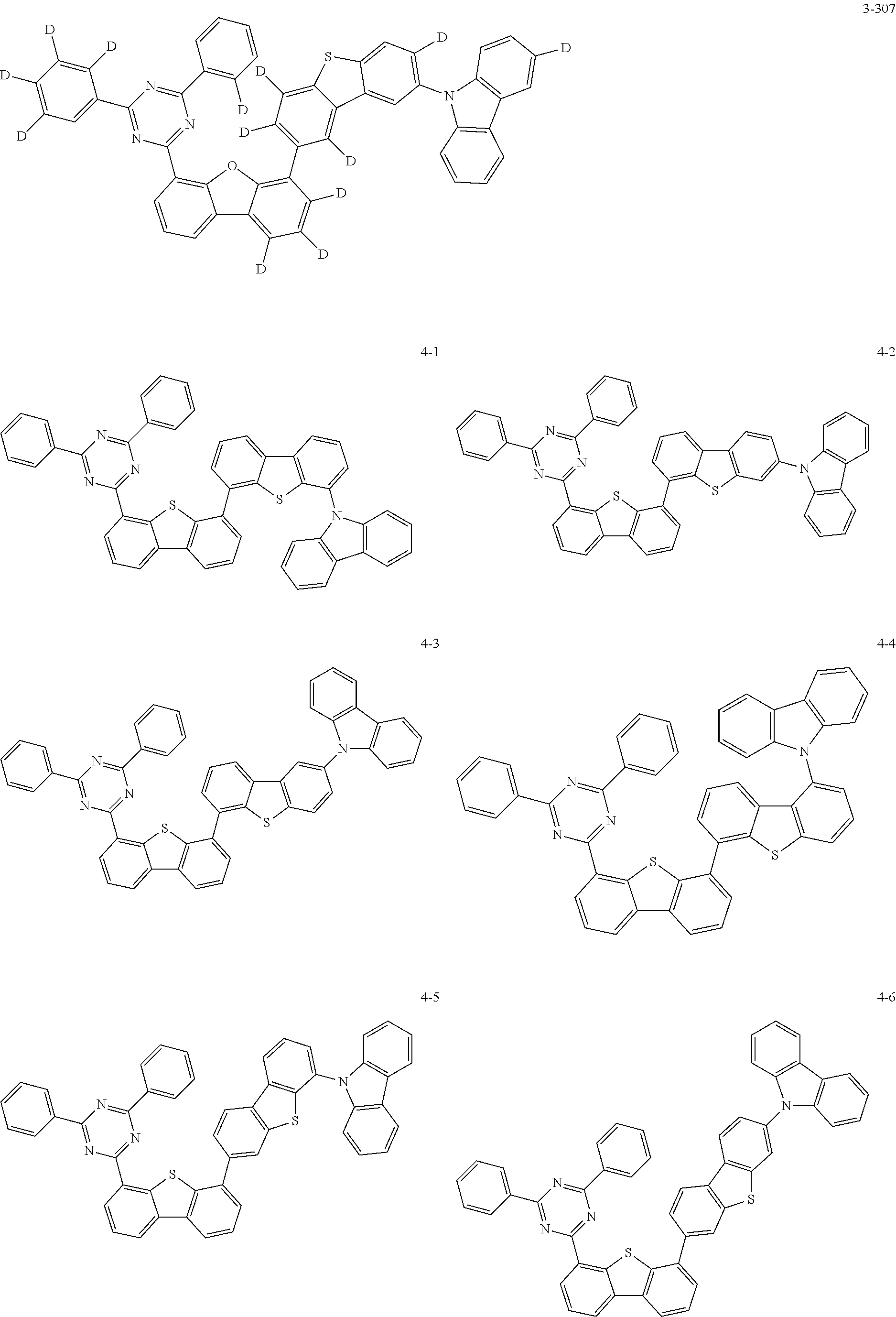

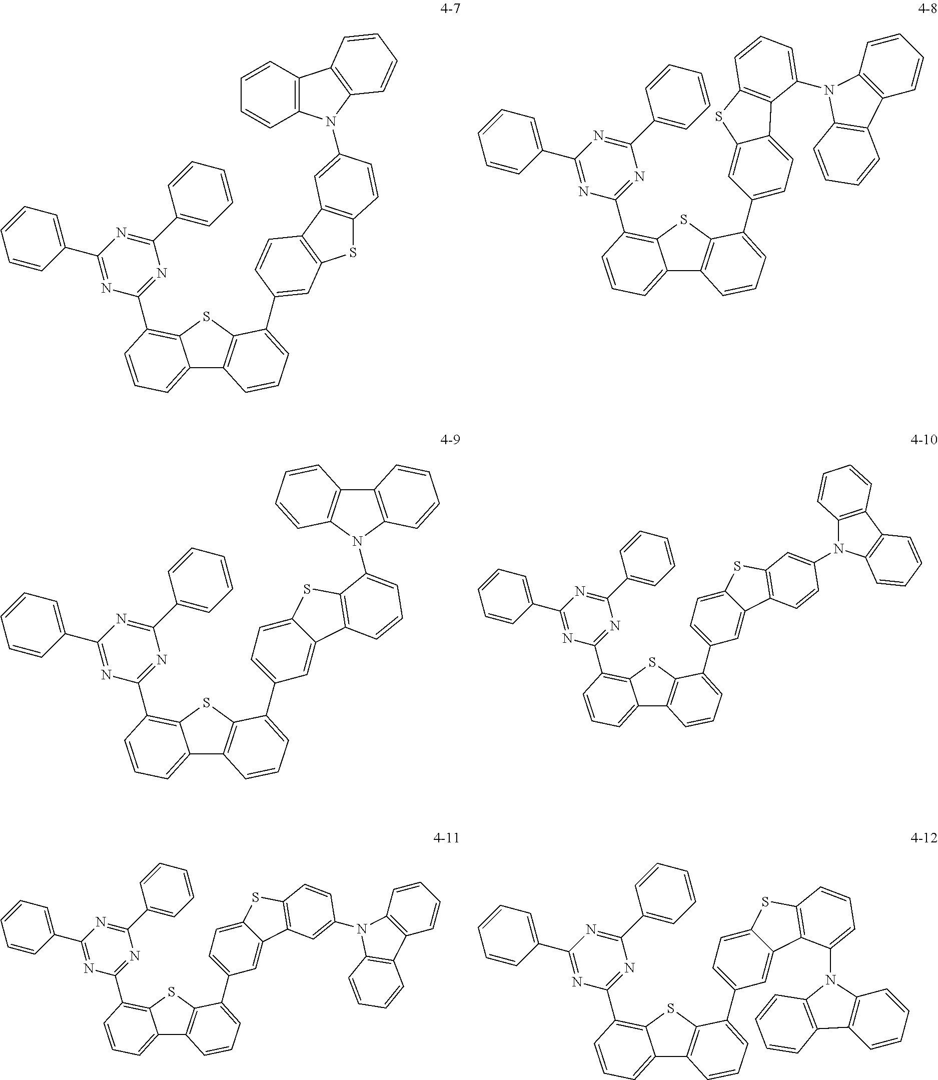

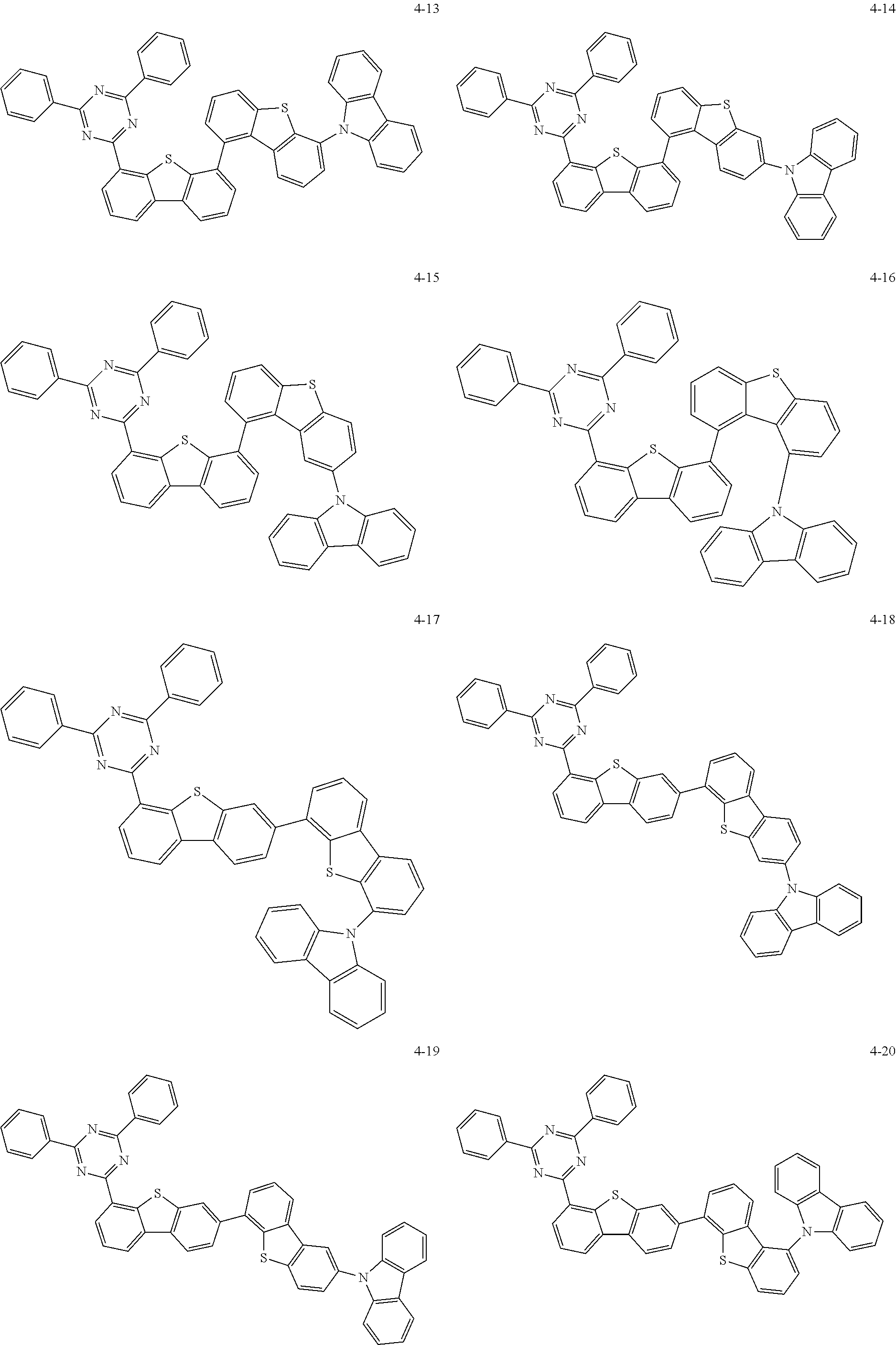

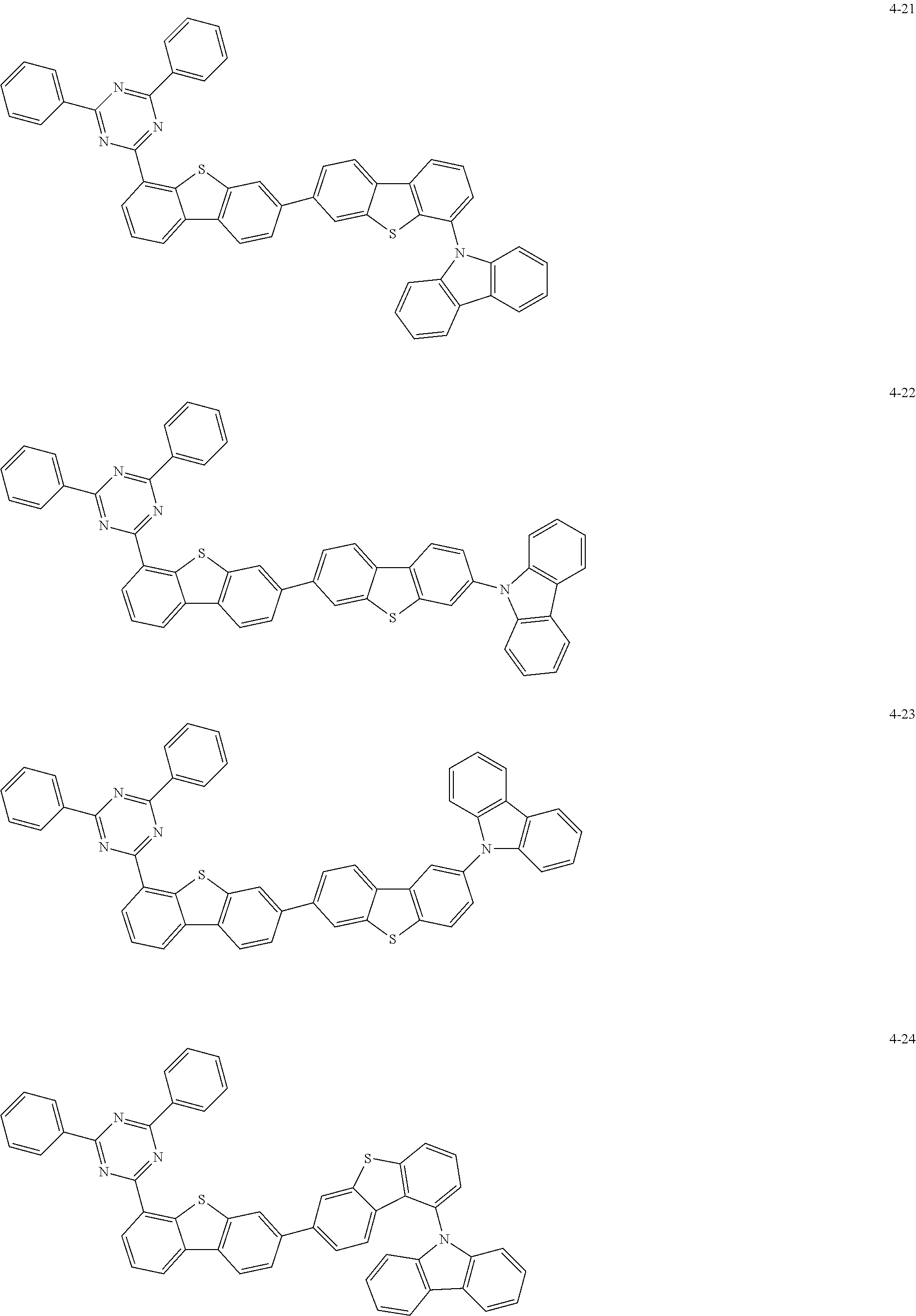 [SMILES: c1ccc(-c2nc(-c3ccccc3)nc(-c3cccc4c3sc3cc(-c5ccc6c(c5)sc5c(-n7c8ccccc8c8ccccc87)cccc56)ccc34)n2)cc1 ; c1ccc(-c2nc(-c3ccccc3)nc(-c3cccc4c3sc3cc(-c5ccc6c(c5)sc5cc(-n7c8ccccc8c8ccccc87)ccc56)ccc34)n2)cc1 ; c1ccc(-c2nc(-c3ccccc3)nc(-c3cccc4c3sc3cc(-c5ccc6c(c5)sc5ccc(-n7c8ccccc8c8ccccc87)cc56)ccc34)n2)cc1 ; c1ccc(-c2nc(-c3ccccc3)nc(-c3cccc4c3sc3cc(-c5ccc6c(c5)sc5cccc(-n7c8ccccc8c8ccccc87)c56)ccc34)n2)cc1]

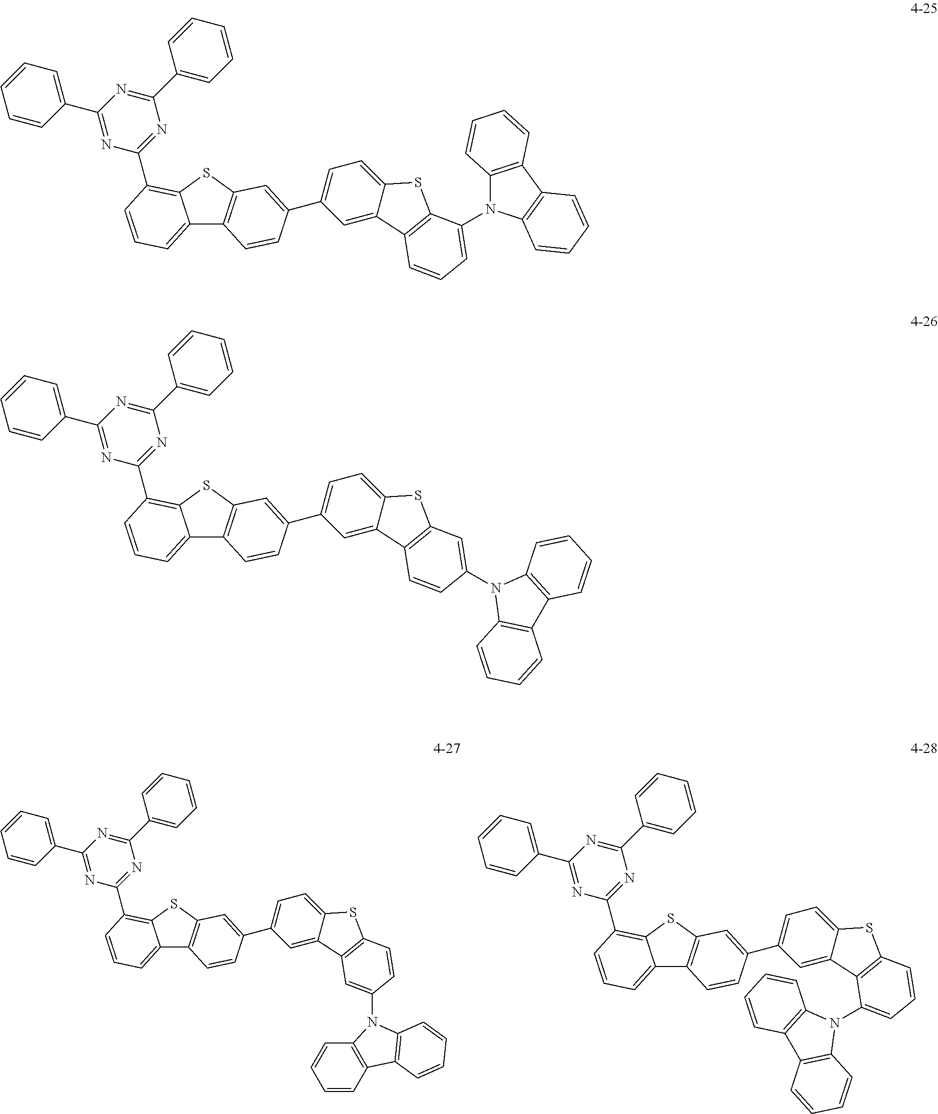 [SMILES: c1ccc(-c2nc(-c3ccccc3)nc(-c3cccc4c3sc3cc(-c5ccc6sc7c(-n8c9ccccc9c9ccccc98)cccc7c6c5)ccc34)n2)cc1 ; c1ccc(-c2nc(-c3ccccc3)nc(-c3cccc4c3sc3cc(-c5ccc6sc7cc(-n8c9ccccc9c9ccccc98)ccc7c6c5)ccc34)n2)cc1 ; c1ccc(-c2nc(-c3ccccc3)nc(-c3cccc4c3sc3cc(-c5ccc6sc7ccc(-n8c9ccccc9c9ccccc98)cc7c6c5)ccc34)n2)cc1 ; c1ccc(-c2nc(-c3ccccc3)nc(-c3cccc4c3sc3cc(-c5ccc6sc7cccc(-n8c9ccccc9c9ccccc98)c7c6c5)ccc34)n2)cc1]

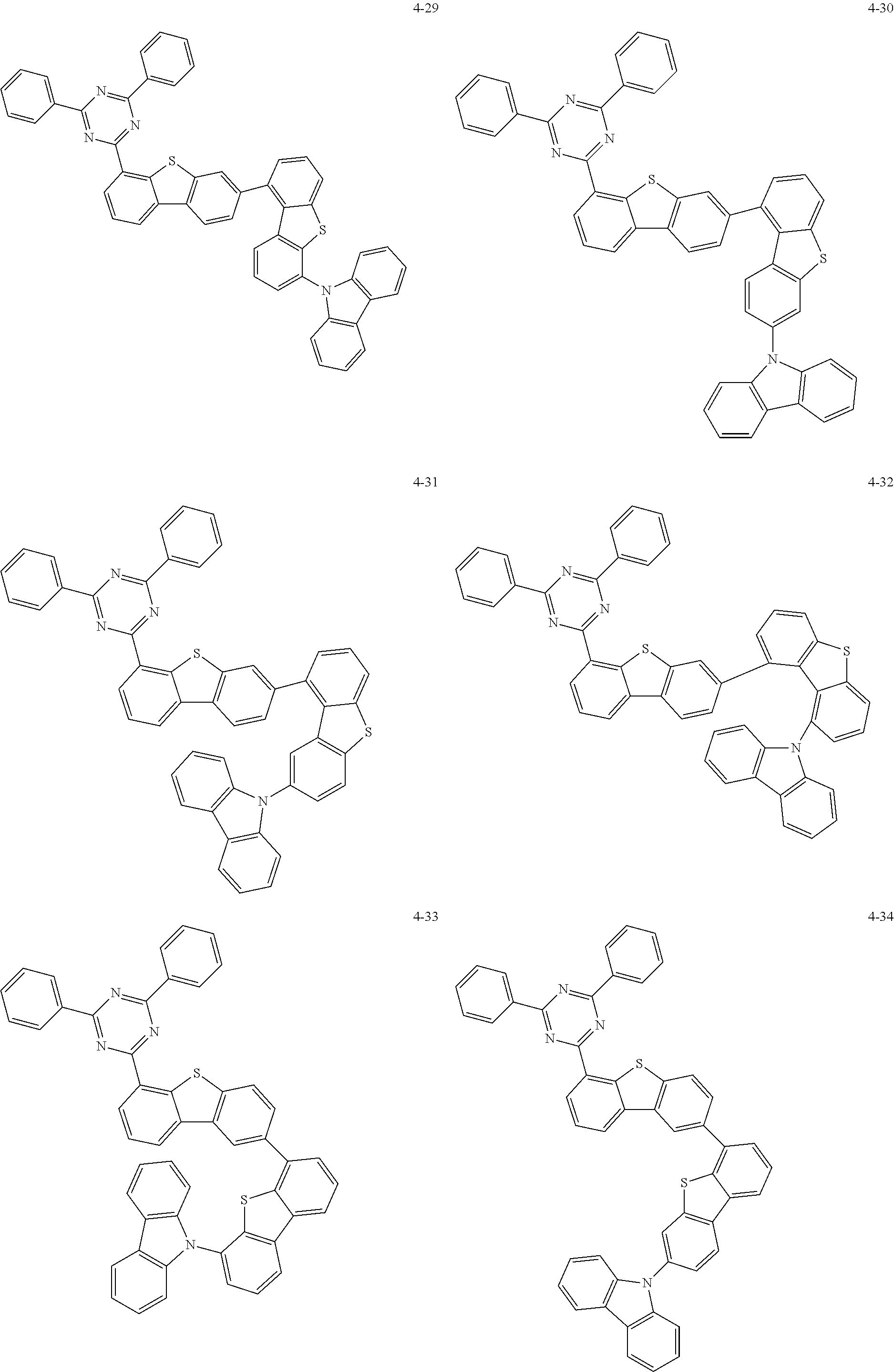

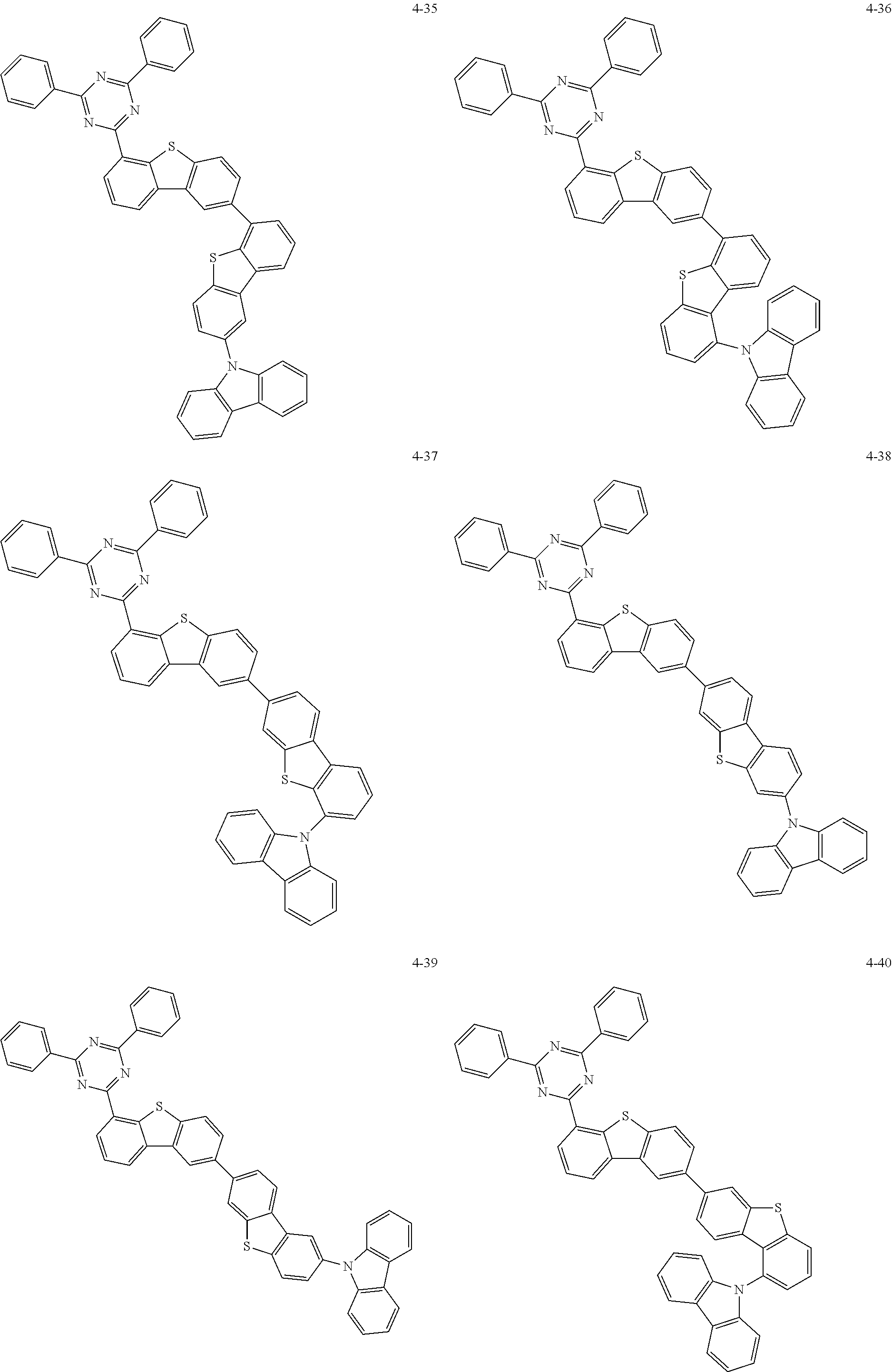

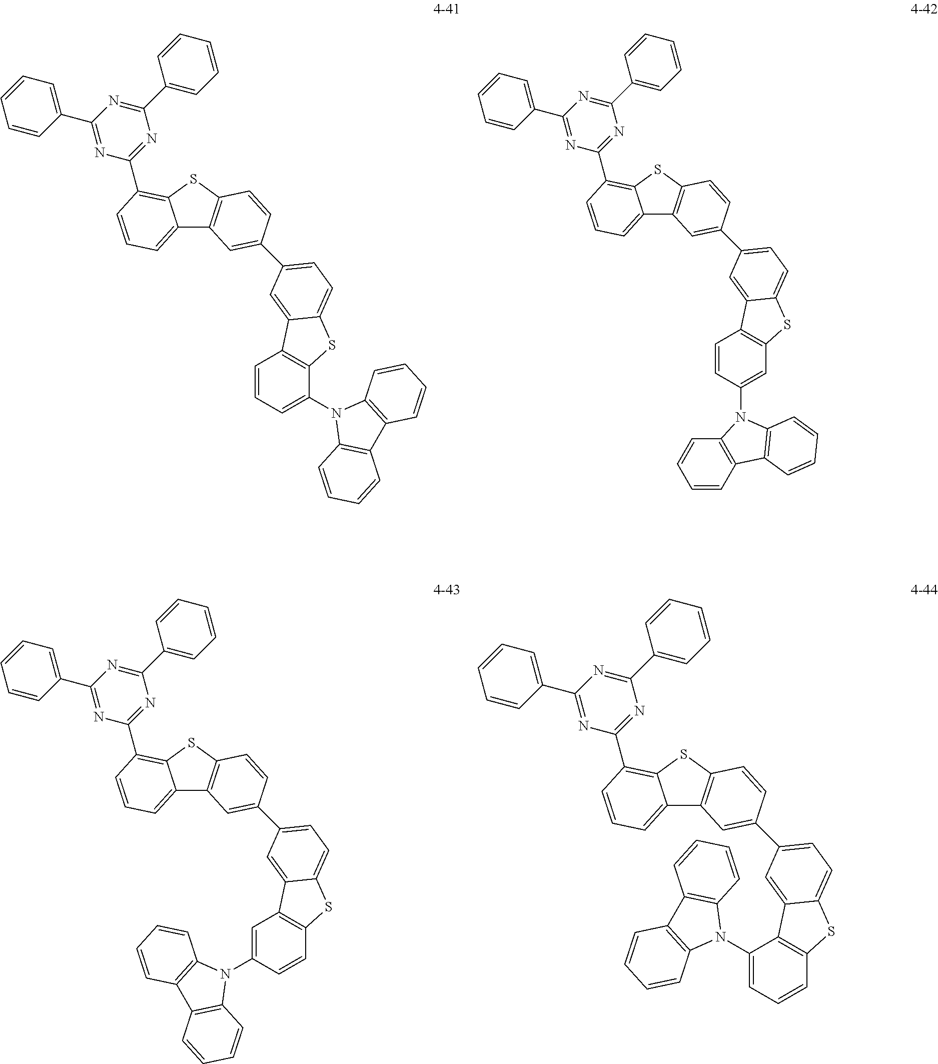 [SMILES: c1ccc(-c2nc(-c3ccccc3)nc(-c3cccc4c3sc3ccc(-c5ccc6sc7c(-n8c9ccccc9c9ccccc98)cccc7c6c5)cc34)n2)cc1 ; c1ccc(-c2nc(-c3ccccc3)nc(-c3cccc4c3sc3ccc(-c5ccc6sc7cc(-n8c9ccccc9c9ccccc98)ccc7c6c5)cc34)n2)cc1 ; c1ccc(-c2nc(-c3ccccc3)nc(-c3cccc4c3sc3ccc(-c5ccc6sc7ccc(-n8c9ccccc9c9ccccc98)cc7c6c5)cc34)n2)cc1 ; c1ccc(-c2nc(-c3ccccc3)nc(-c3cccc4c3sc3ccc(-c5ccc6sc7cccc(-n8c9ccccc9c9ccccc98)c7c6c5)cc34)n2)cc1]

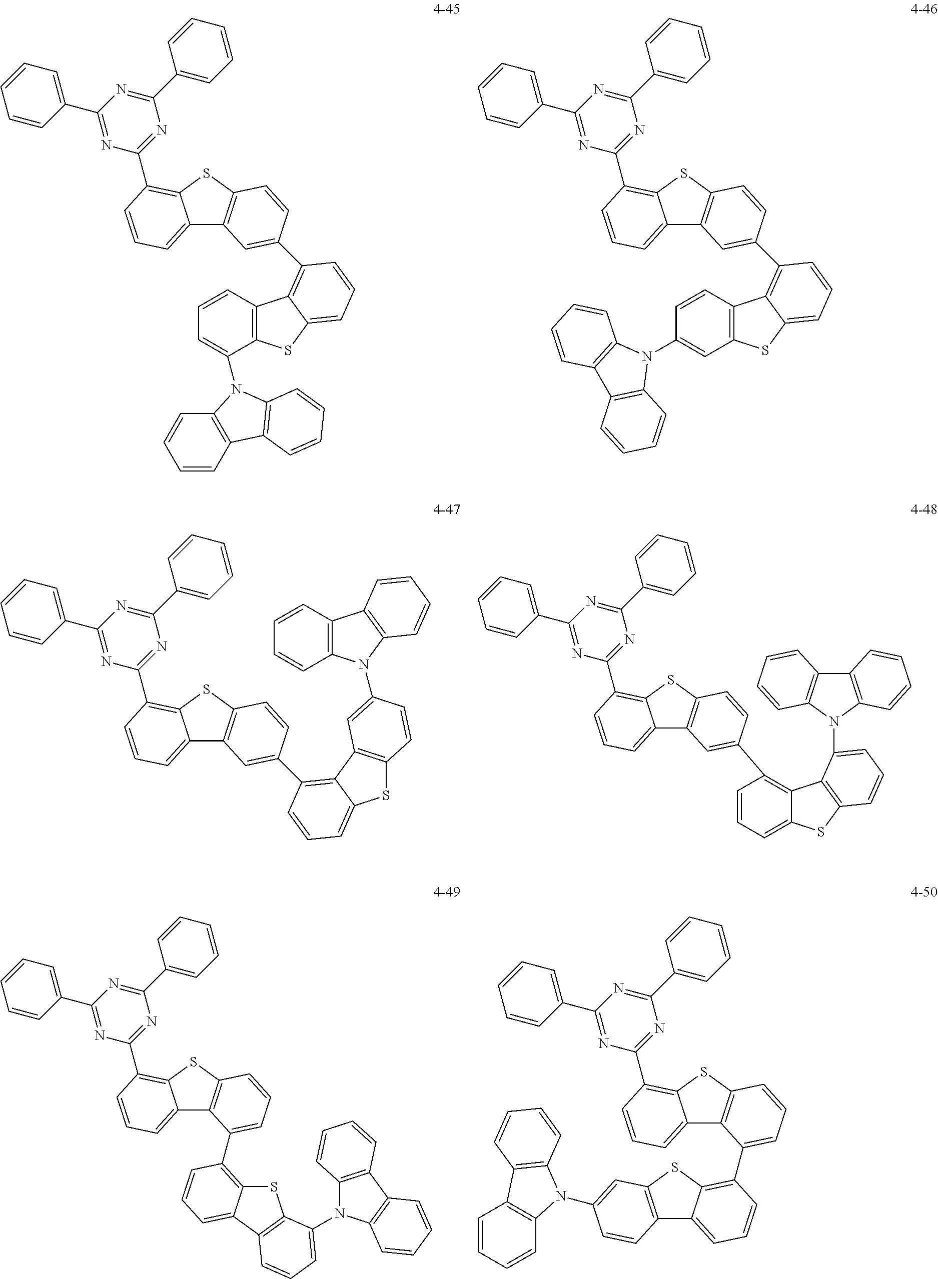

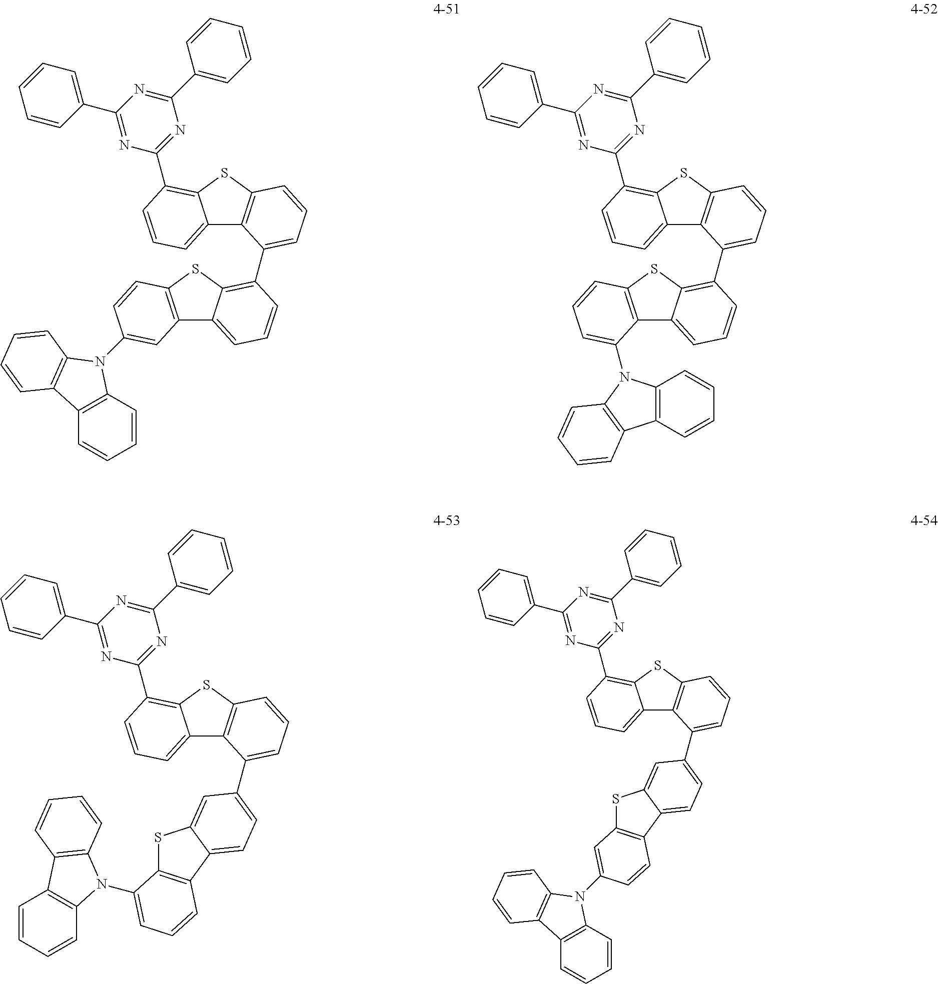 [SMILES: c1ccc(-c2nc(-c3ccccc3)nc(-c3cccc4c3sc3cccc(-c5cccc6c5sc5ccc(-n7c8ccccc8c8ccccc87)cc56)c34)n2)cc1 ; c1ccc(-c2nc(-c3ccccc3)nc(-c3cccc4c3sc3cccc(-c5cccc6c5sc5cccc(-n7c8ccccc8c8ccccc87)c56)c34)n2)cc1 ; c1ccc(-c2nc(-c3ccccc3)nc(-c3cccc4c3sc3cccc(-c5ccc6c(c5)sc5c(-n7c8ccccc8c8ccccc87)cccc56)c34)n2)cc1 ; c1ccc(-c2nc(-c3ccccc3)nc(-c3cccc4c3sc3cccc(-c5ccc6c(c5)sc5cc(-n7c8ccccc8c8ccccc87)ccc56)c34)n2)cc1]

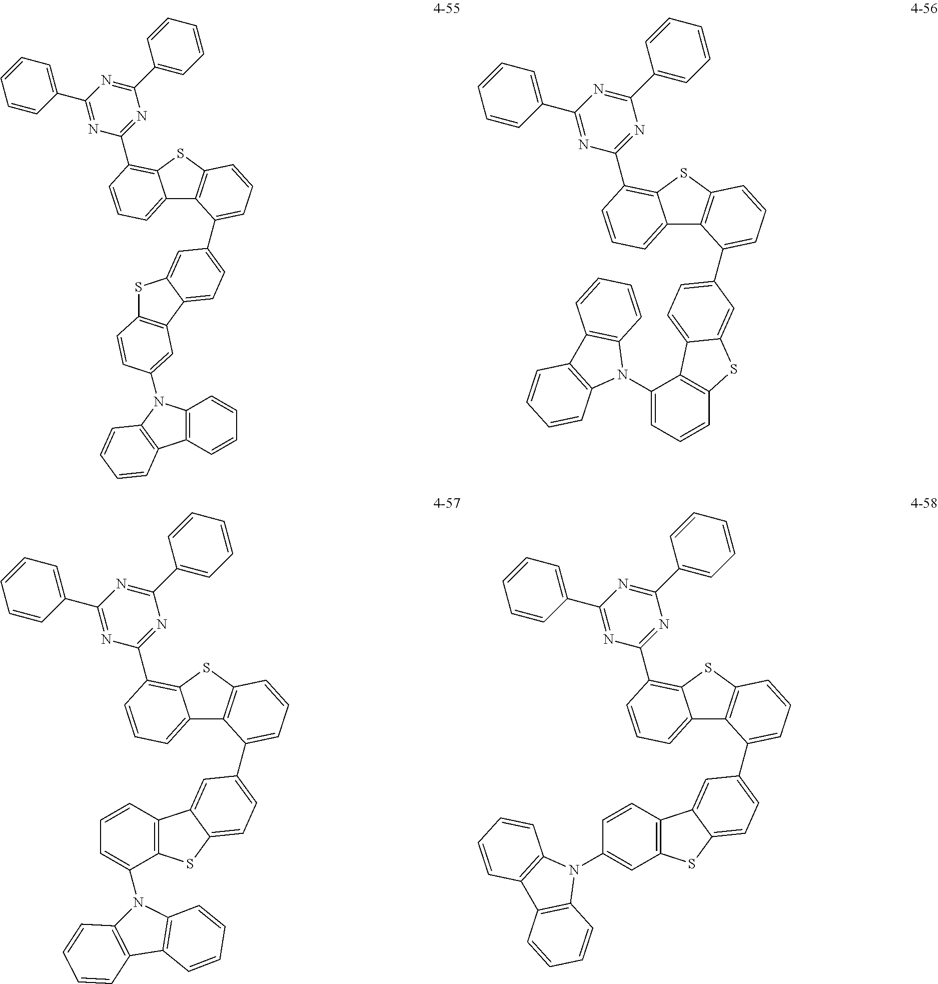 [SMILES: c1ccc(-c2nc(-c3ccccc3)nc(-c3cccc4c3sc3cccc(-c5ccc6c(c5)sc5ccc(-n7c8ccccc8c8ccccc87)cc56)c34)n2)cc1 ; c1ccc(-c2nc(-c3ccccc3)nc(-c3cccc4c3sc3cccc(-c5ccc6c(c5)sc5cccc(-n7c8ccccc8c8ccccc87)c56)c34)n2)cc1 ; c1ccc(-c2nc(-c3ccccc3)nc(-c3cccc4c3sc3cccc(-c5ccc6sc7c(-n8c9ccccc9c9ccccc98)cccc7c6c5)c34)n2)cc1 ; c1ccc(-c2nc(-c3ccccc3)nc(-c3cccc4c3sc3cccc(-c5ccc6sc7cc(-n8c9ccccc9c9ccccc98)ccc7c6c5)c34)n2)cc1]

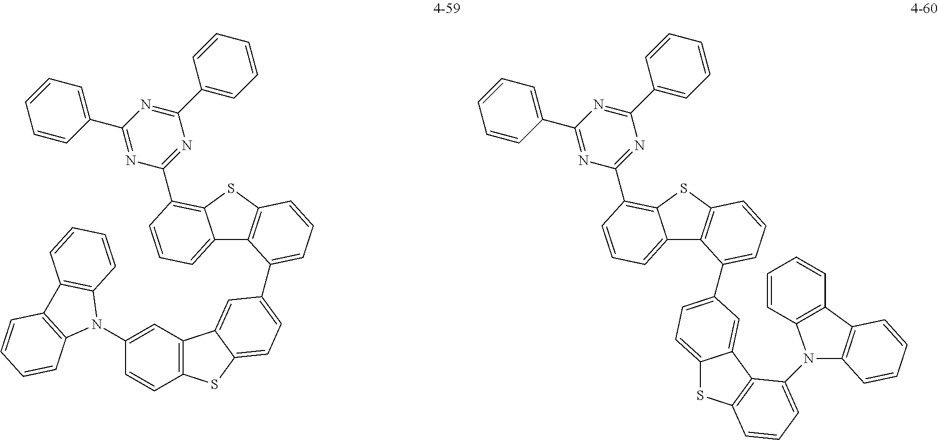 [SMILES: c1ccc(-c2nc(-c3ccccc3)nc(-c3cccc4c3sc3cccc(-c5ccc6sc7ccc(-n8c9ccccc9c9ccccc98)cc7c6c5)c34)n2)cc1 ; c1ccc(-c2nc(-c3ccccc3)nc(-c3cccc4c3sc3cccc(-c5ccc6sc7cccc(-n8c9ccccc9c9ccccc98)c7c6c5)c34)n2)cc1]

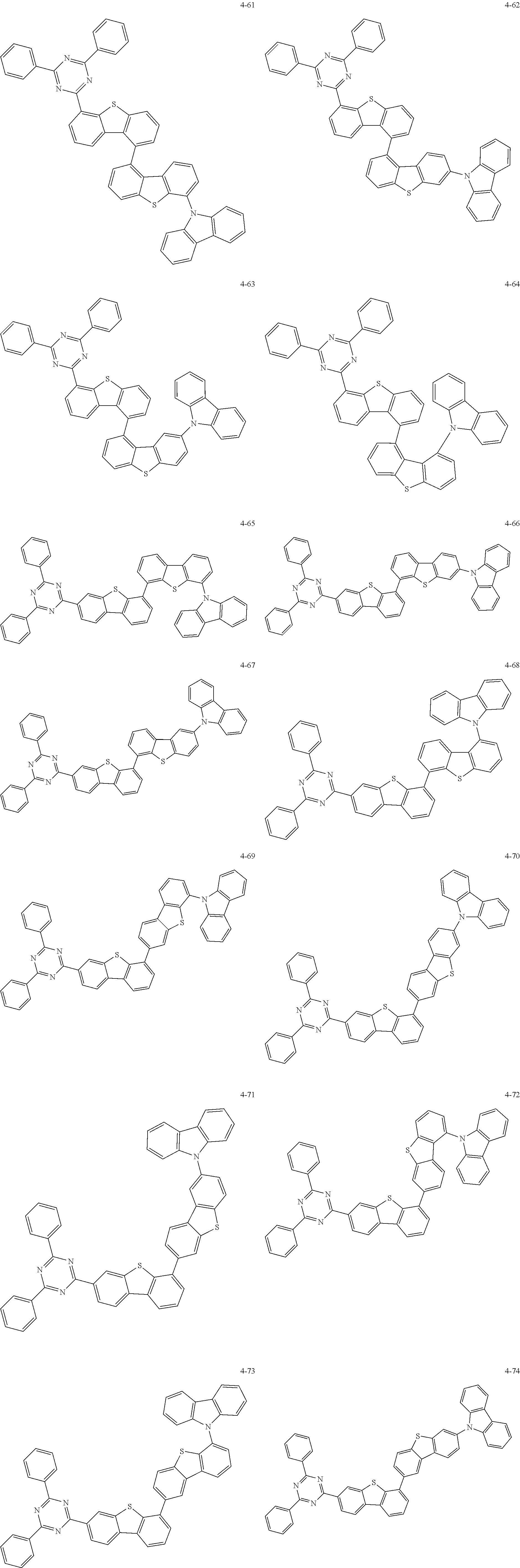

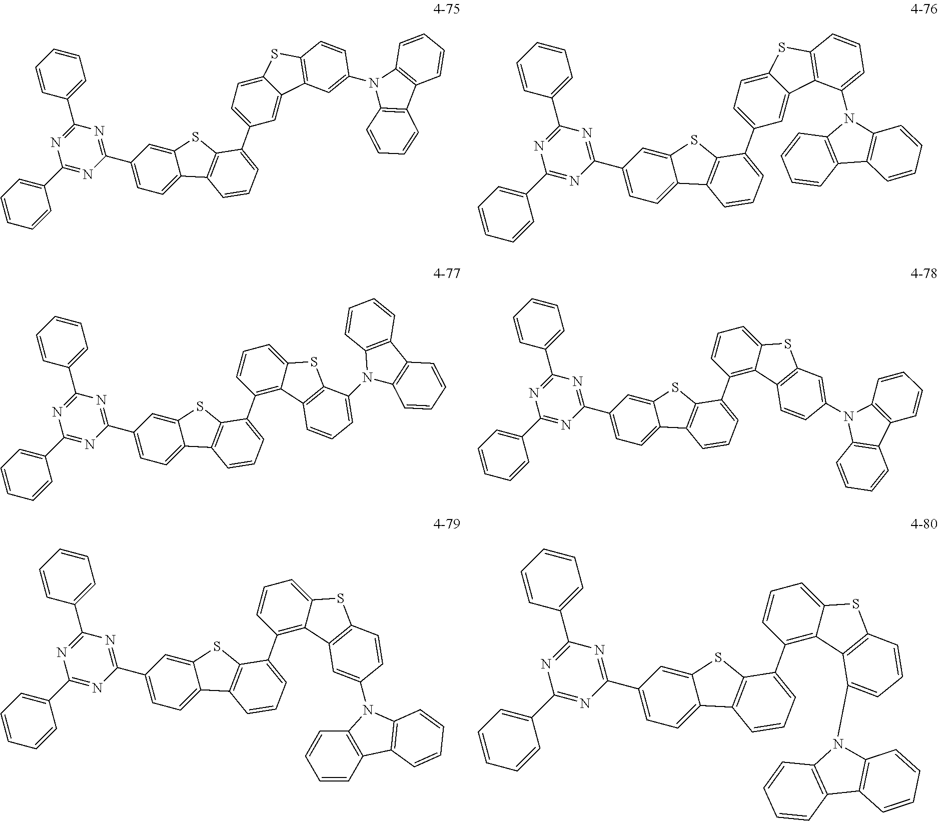

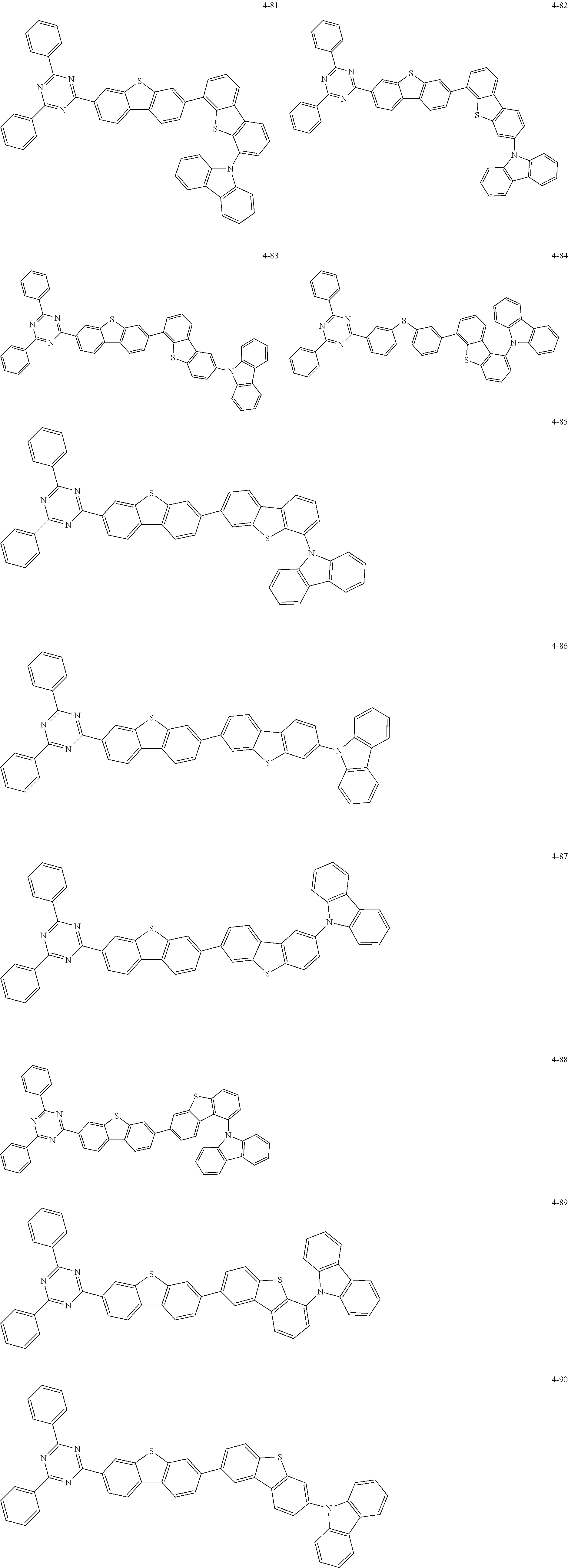

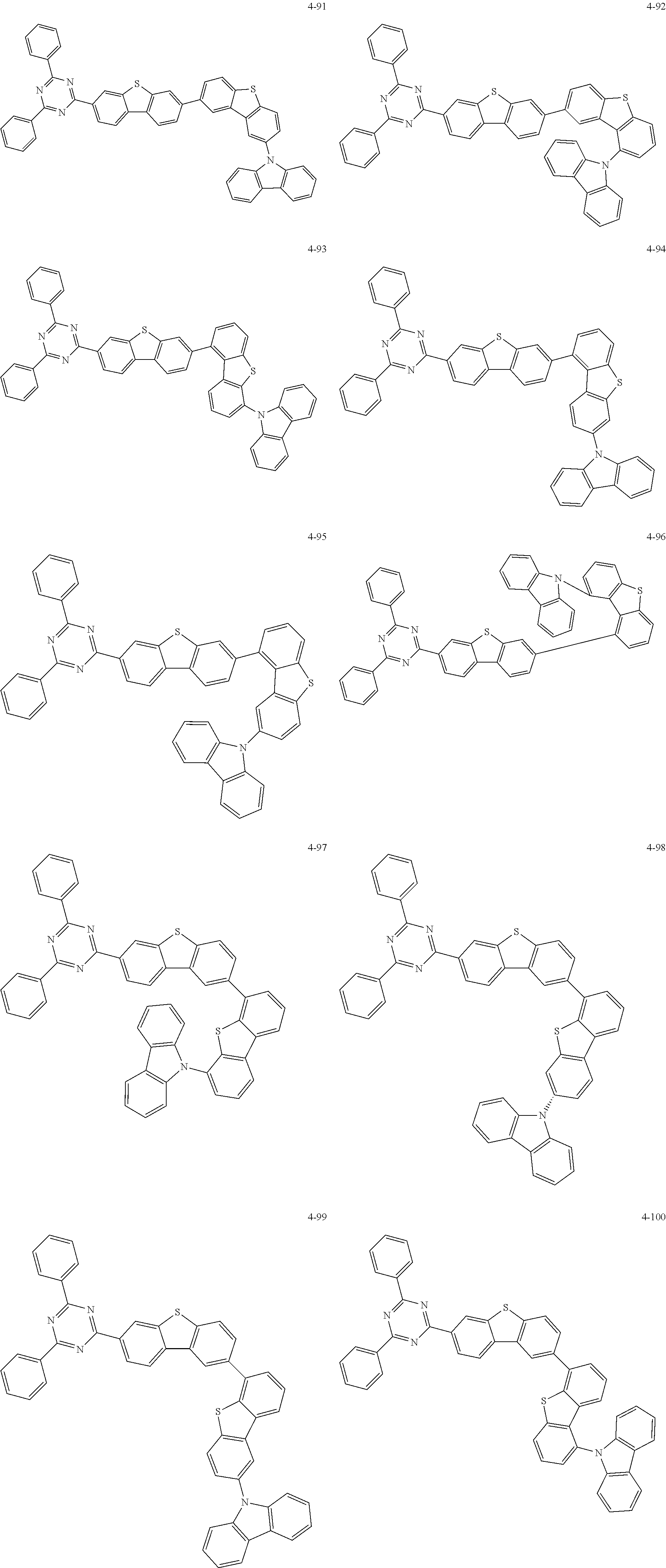

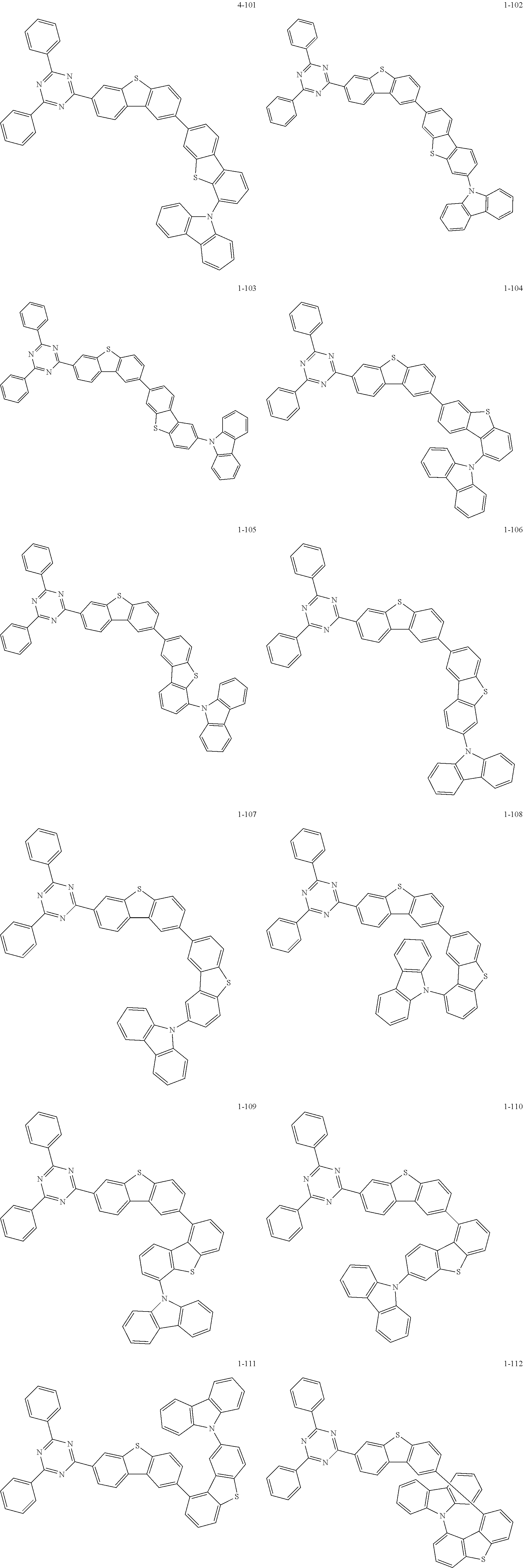

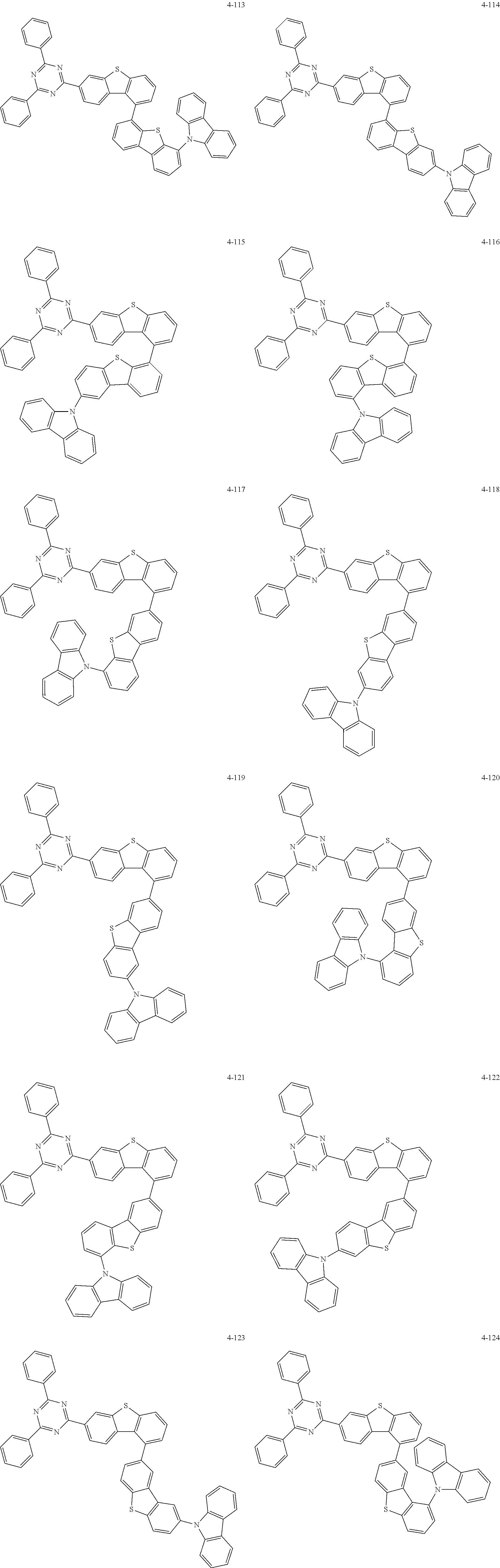

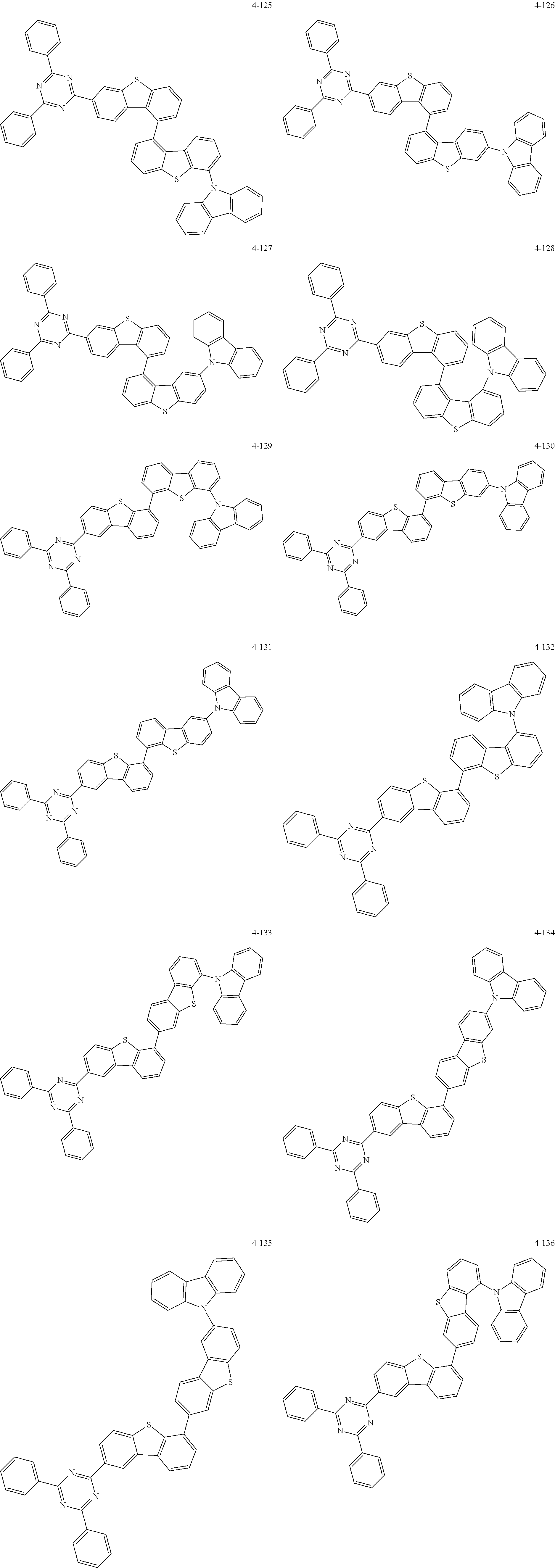

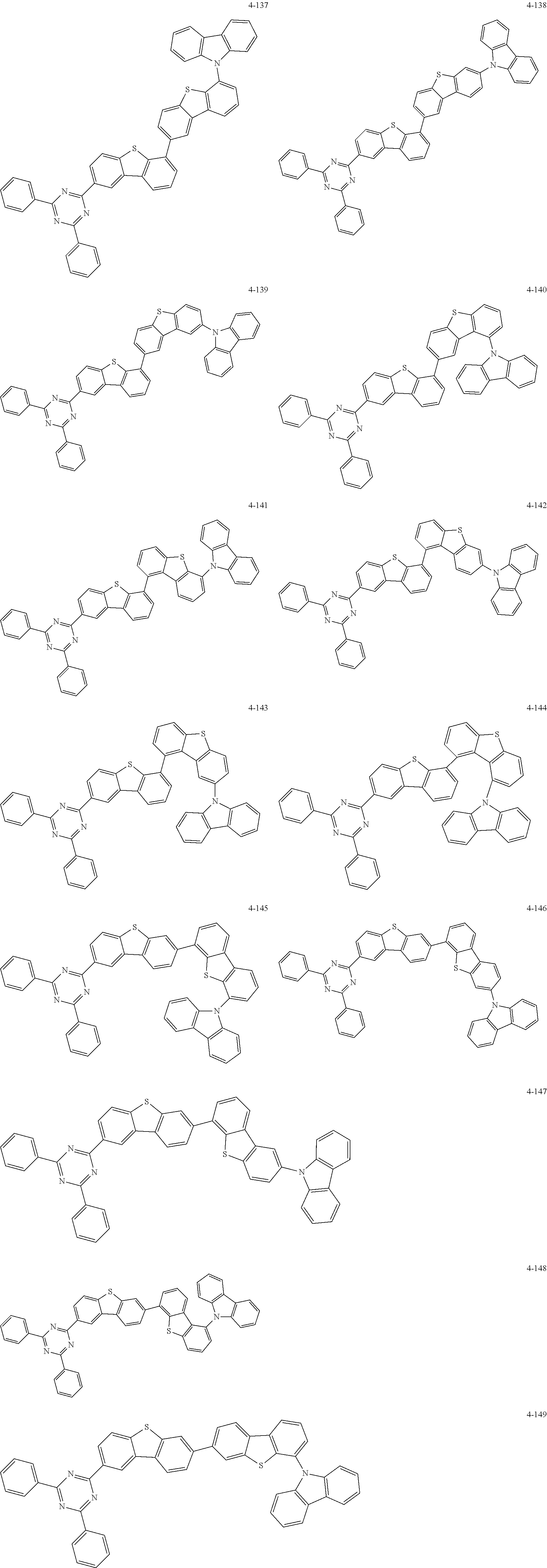

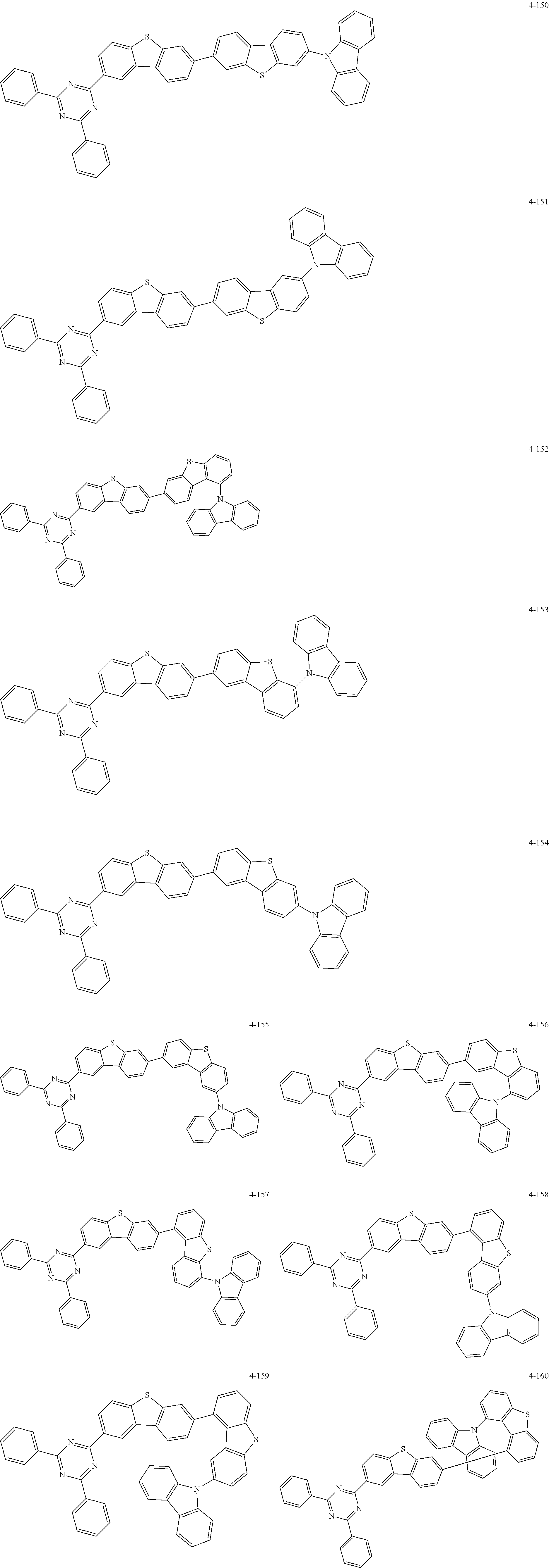

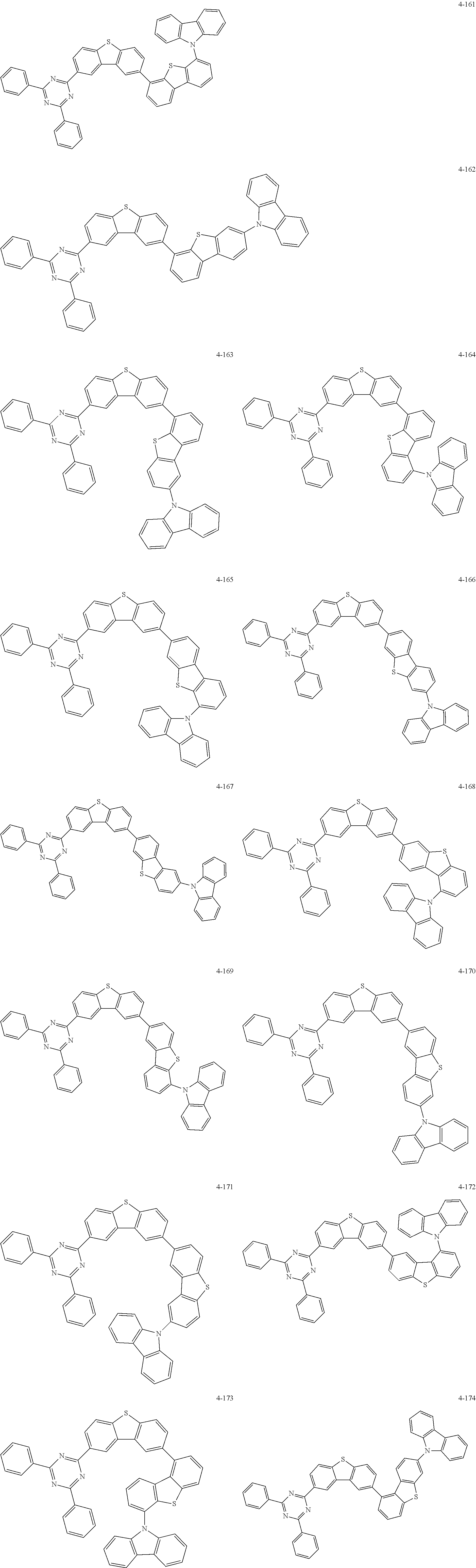

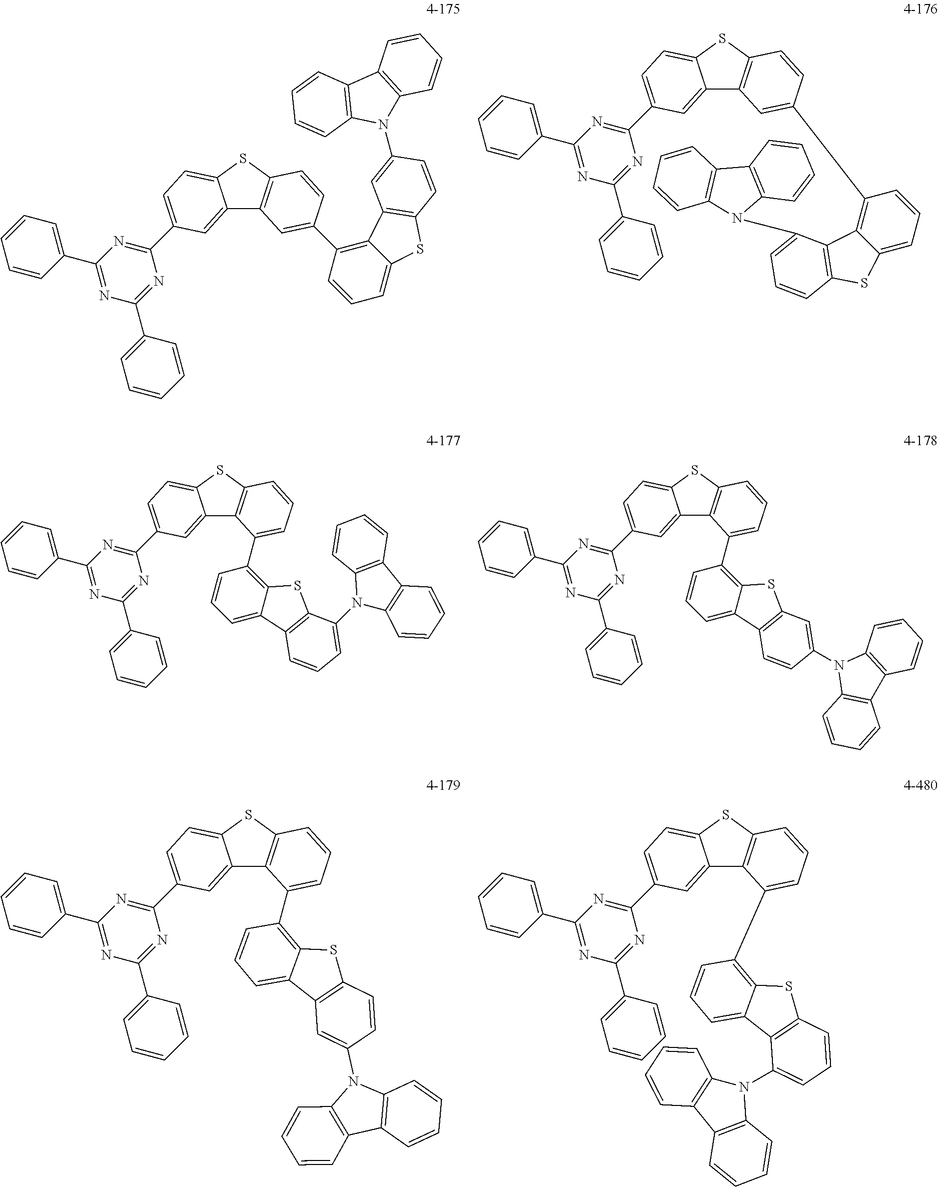

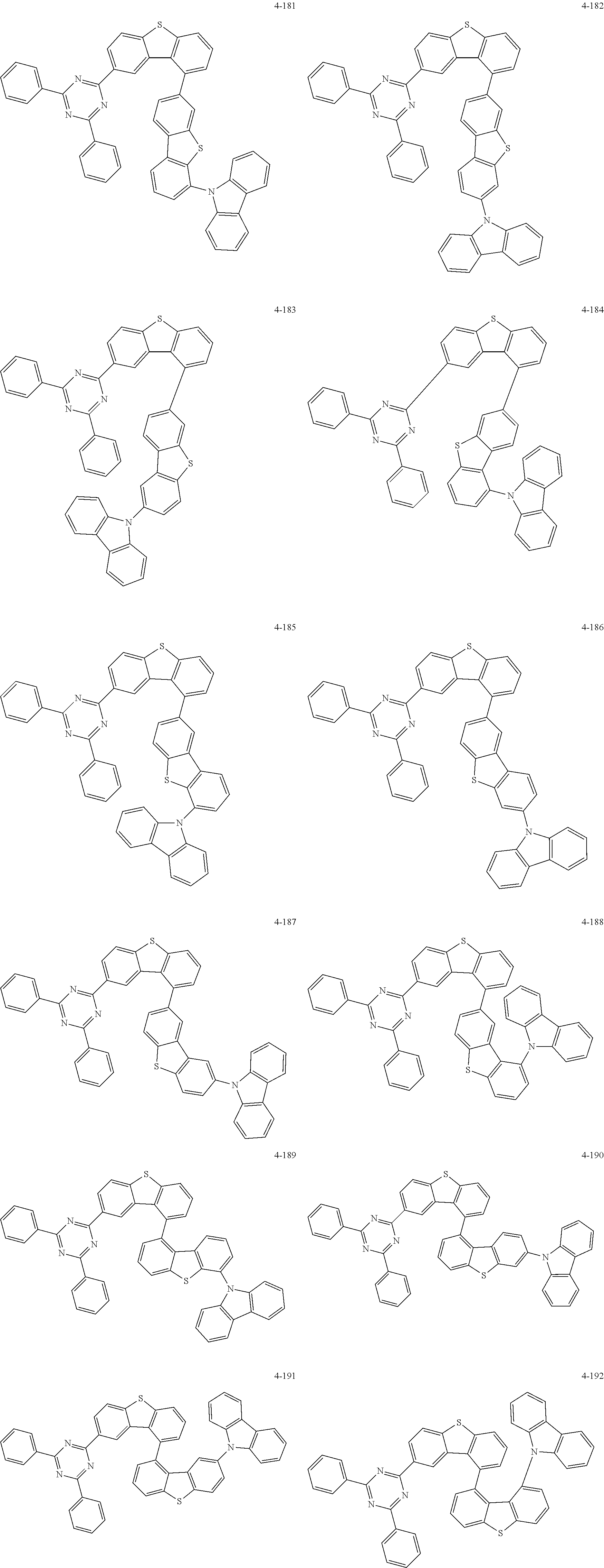

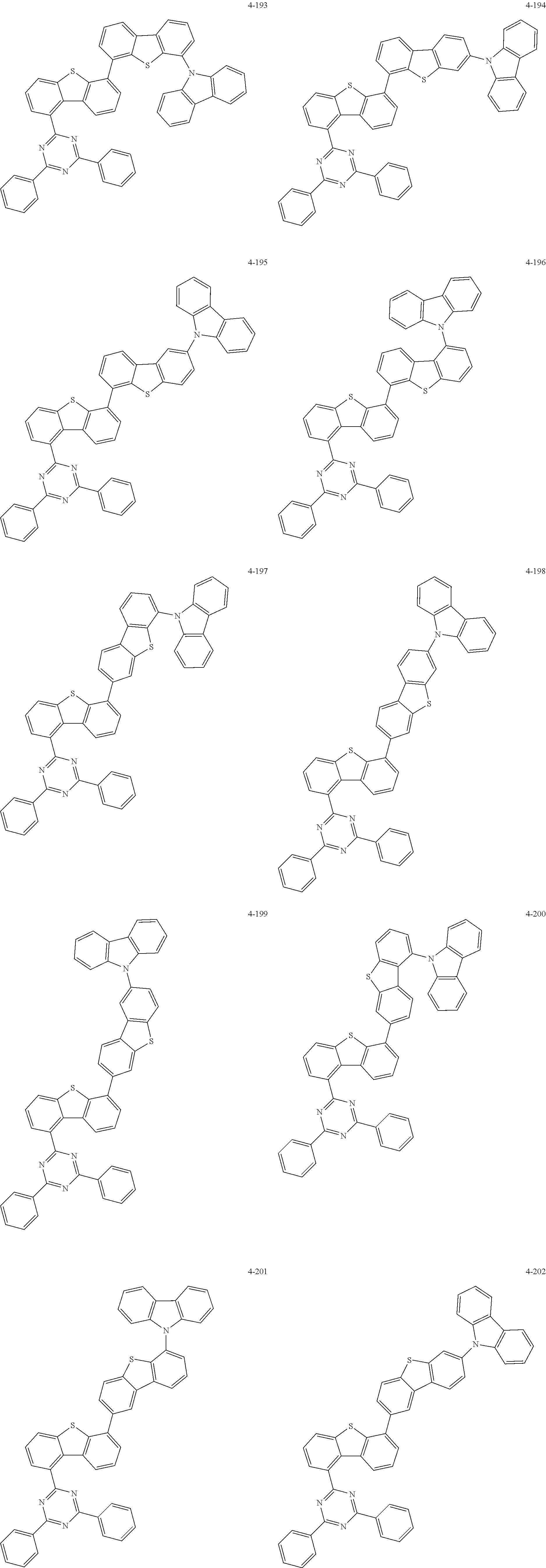

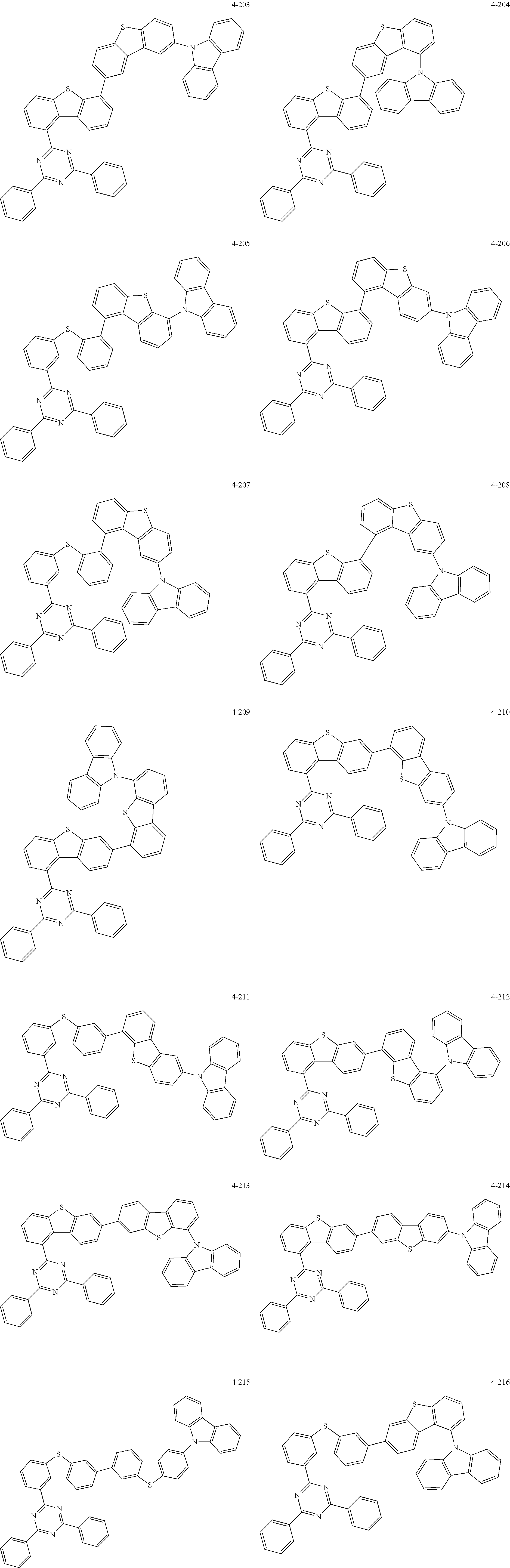

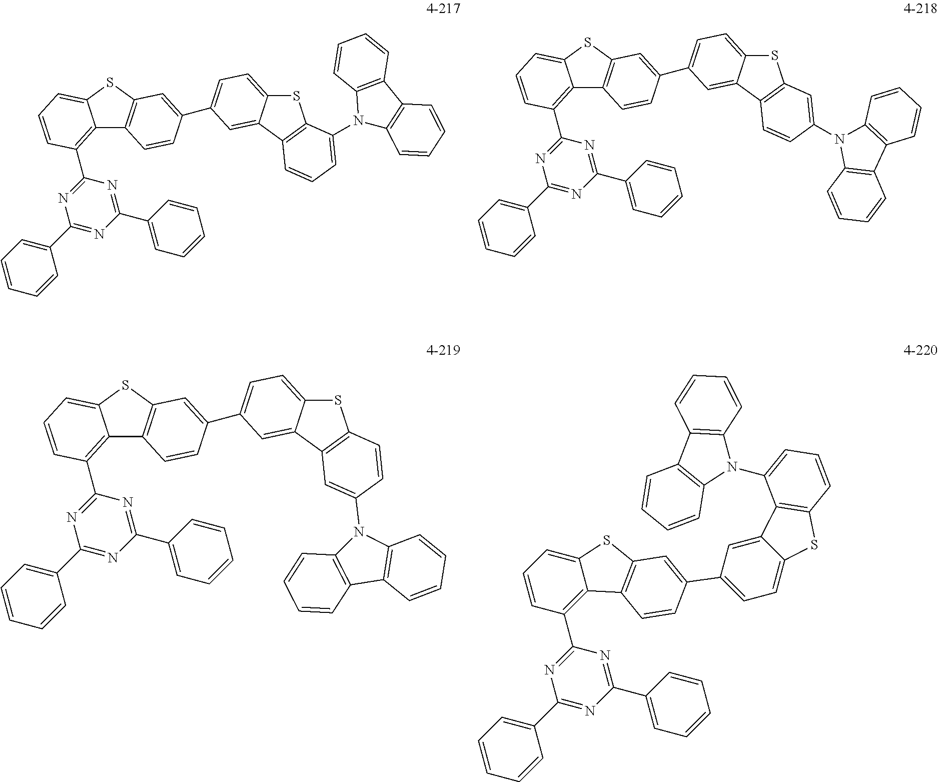 [SMILES: c1ccc(-c2nc(-c3ccccc3)nc(-c3cccc4sc5cc(-c6ccc7sc8c(-n9c%10ccccc%10c%10ccccc%109)cccc8c7c6)ccc5c34)n2)cc1 ; c1ccc(-c2nc(-c3ccccc3)nc(-c3cccc4sc5cc(-c6ccc7sc8cc(-n9c%10ccccc%10c%10ccccc%109)ccc8c7c6)ccc5c34)n2)cc1 ; c1ccc(-c2nc(-c3ccccc3)nc(-c3cccc4sc5cc(-c6ccc7sc8ccc(-n9c%10ccccc%10c%10ccccc%109)cc8c7c6)ccc5c34)n2)cc1 ; c1ccc(-c2nc(-c3ccccc3)nc(-c3cccc4sc5cc(-c6ccc7sc8cccc(-n9c%10ccccc%10c%10ccccc%109)c8c7c6)ccc5c34)n2)cc1]

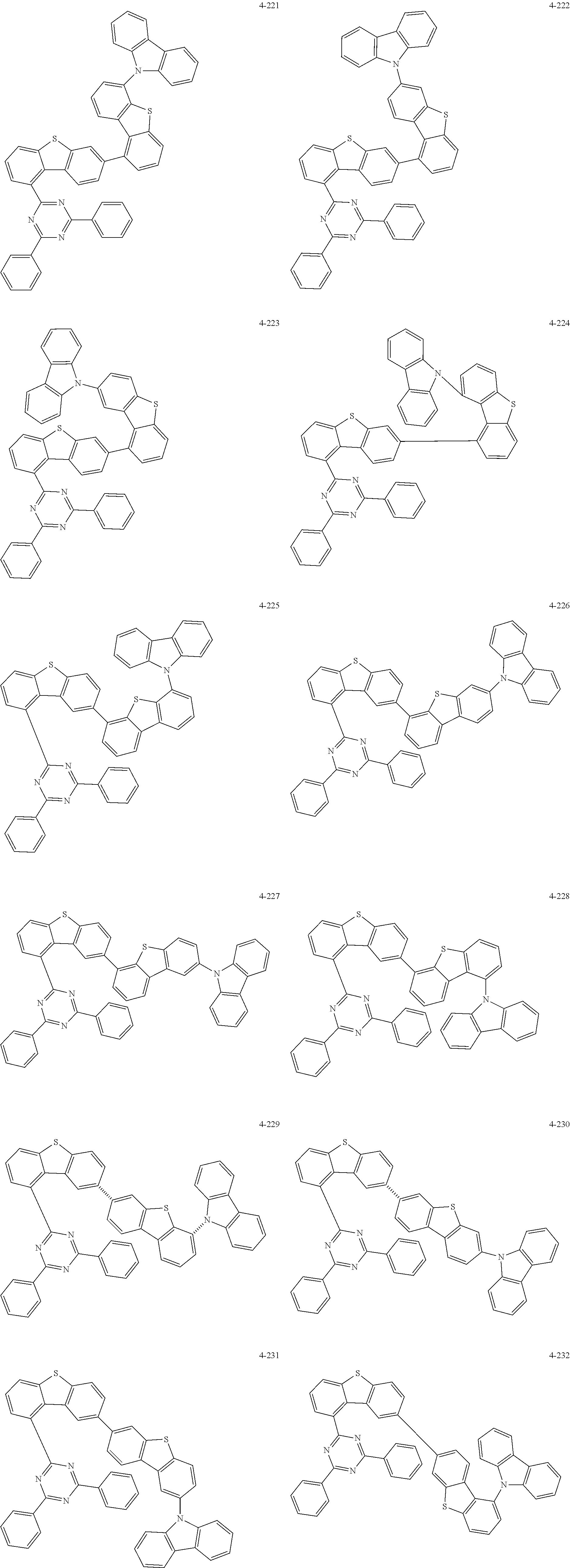

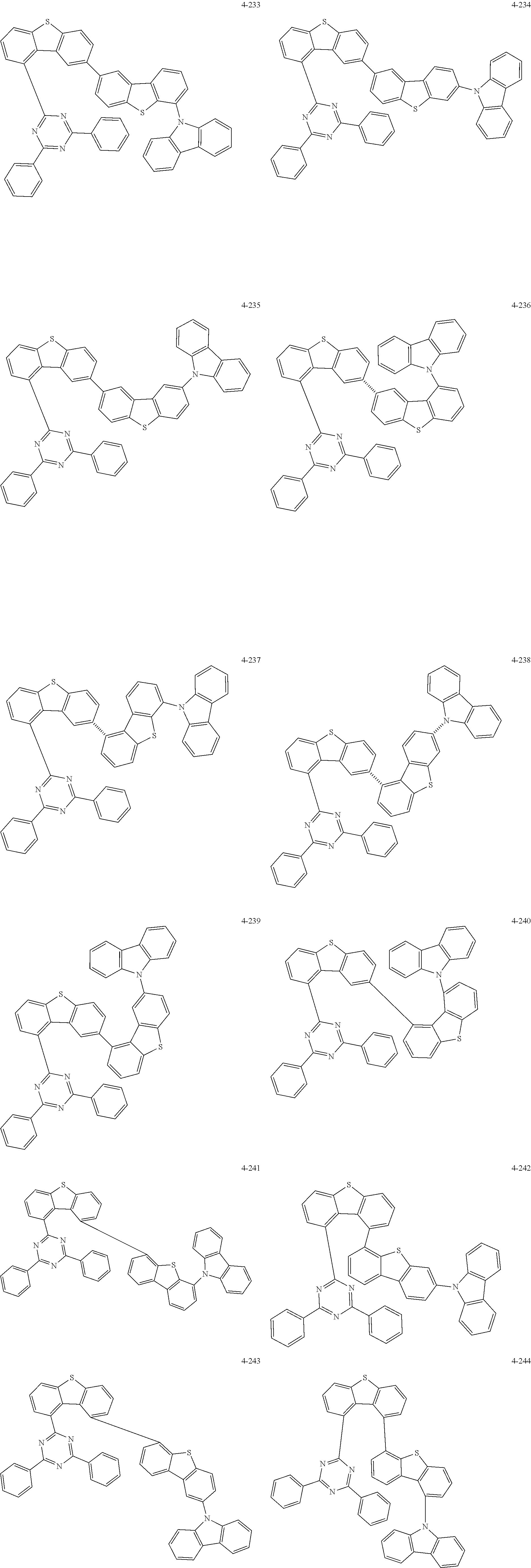

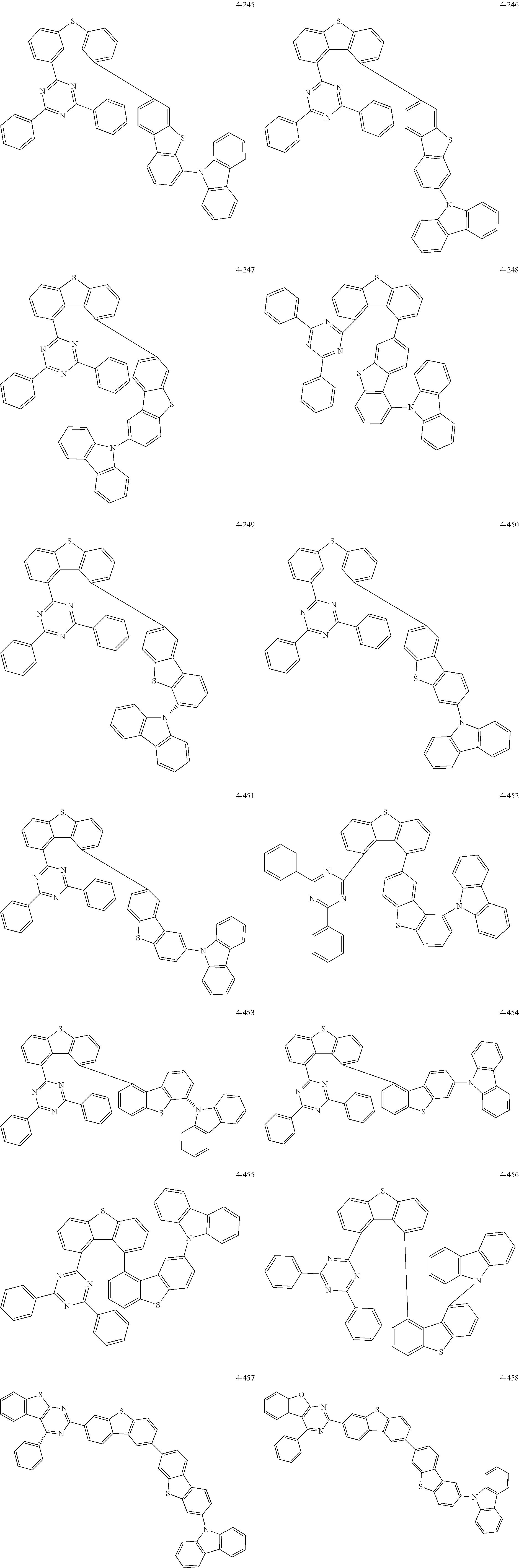

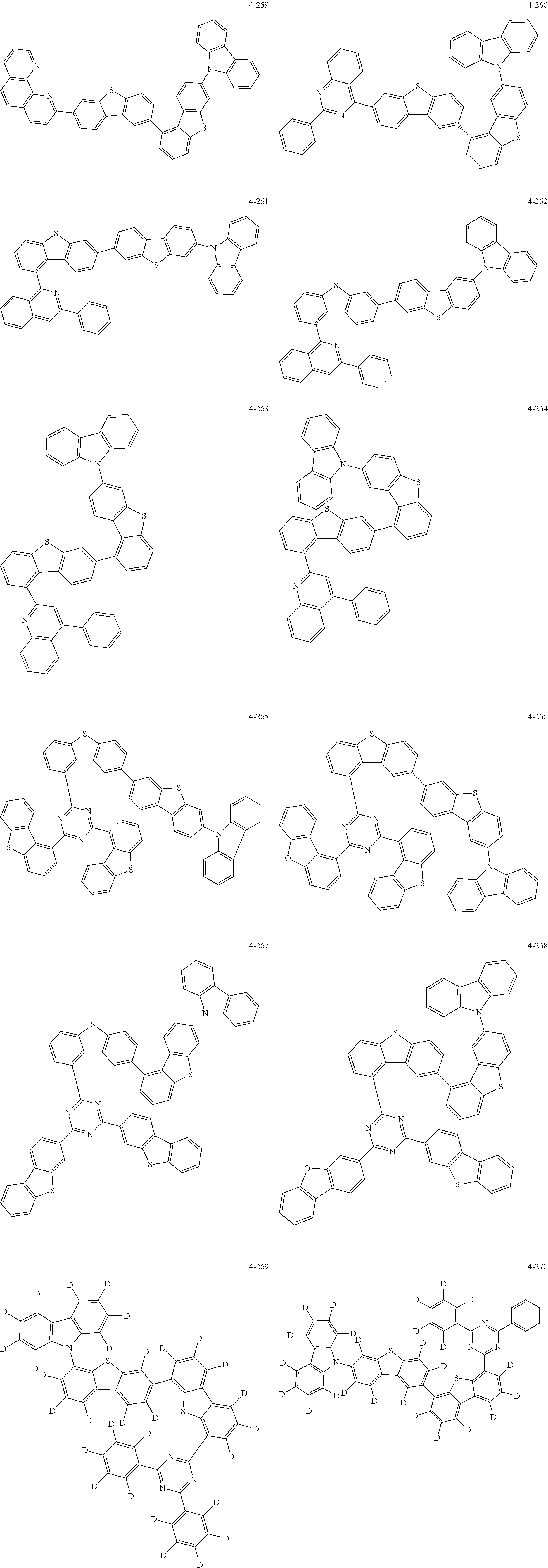

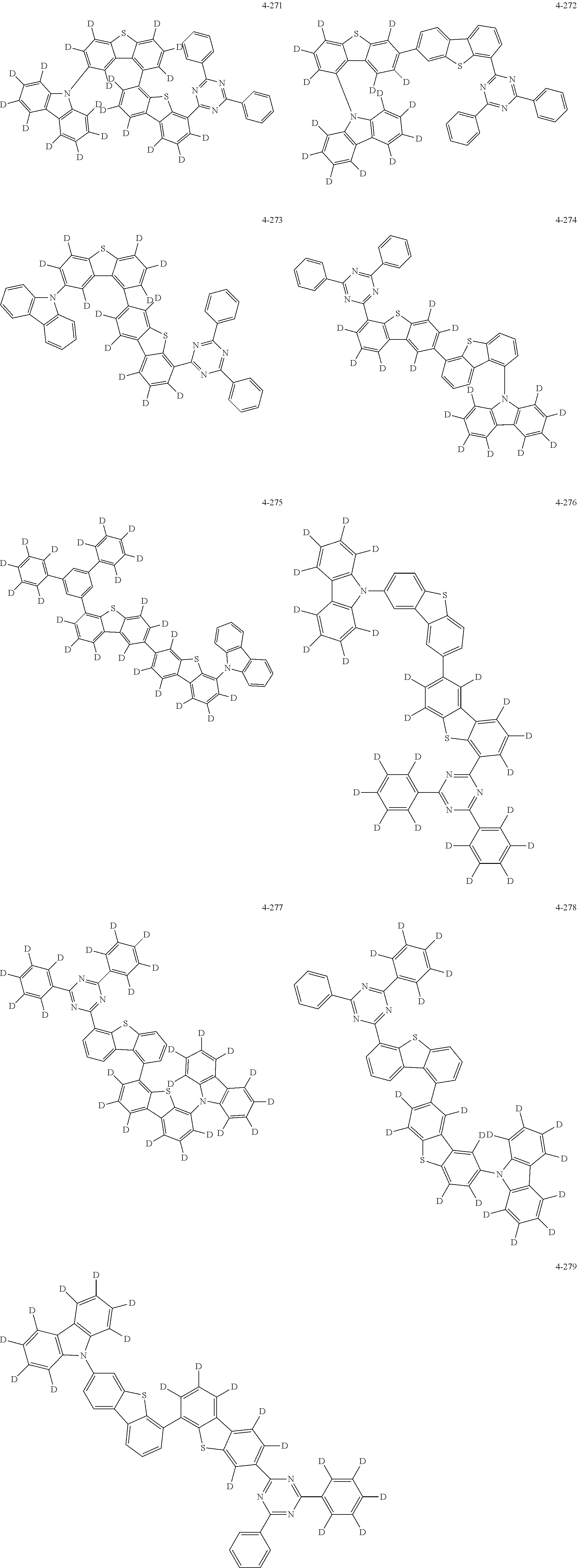

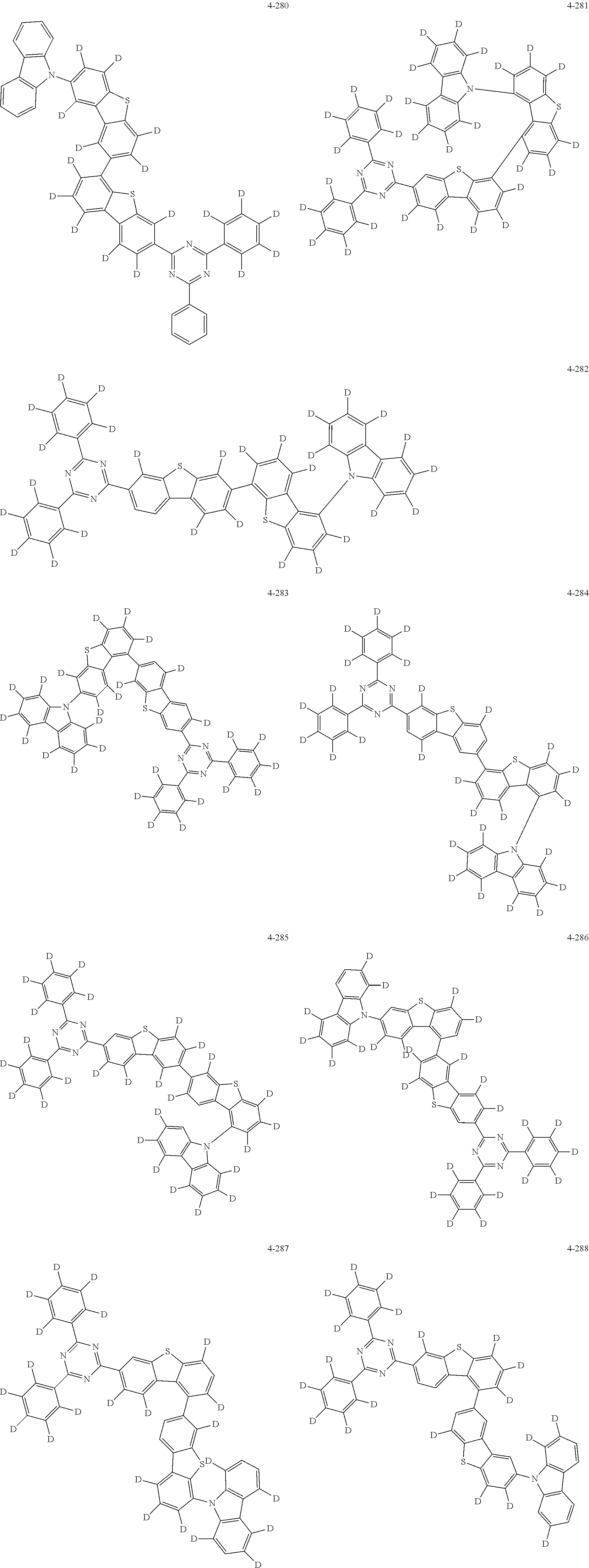

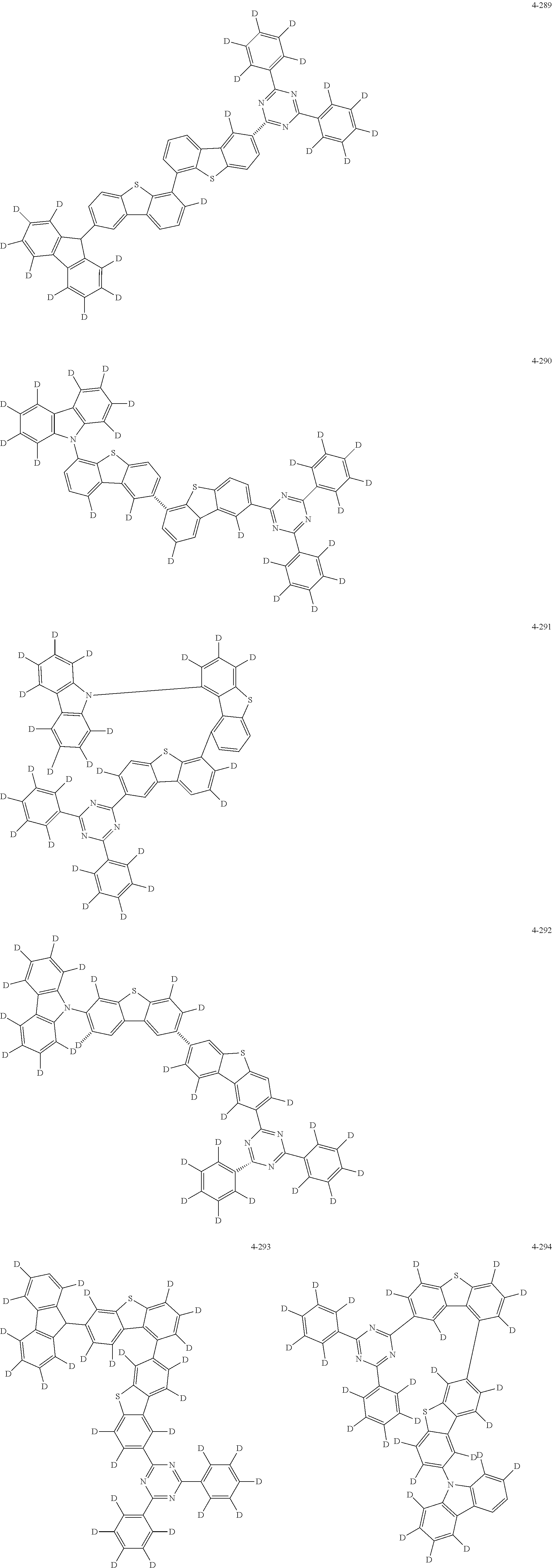

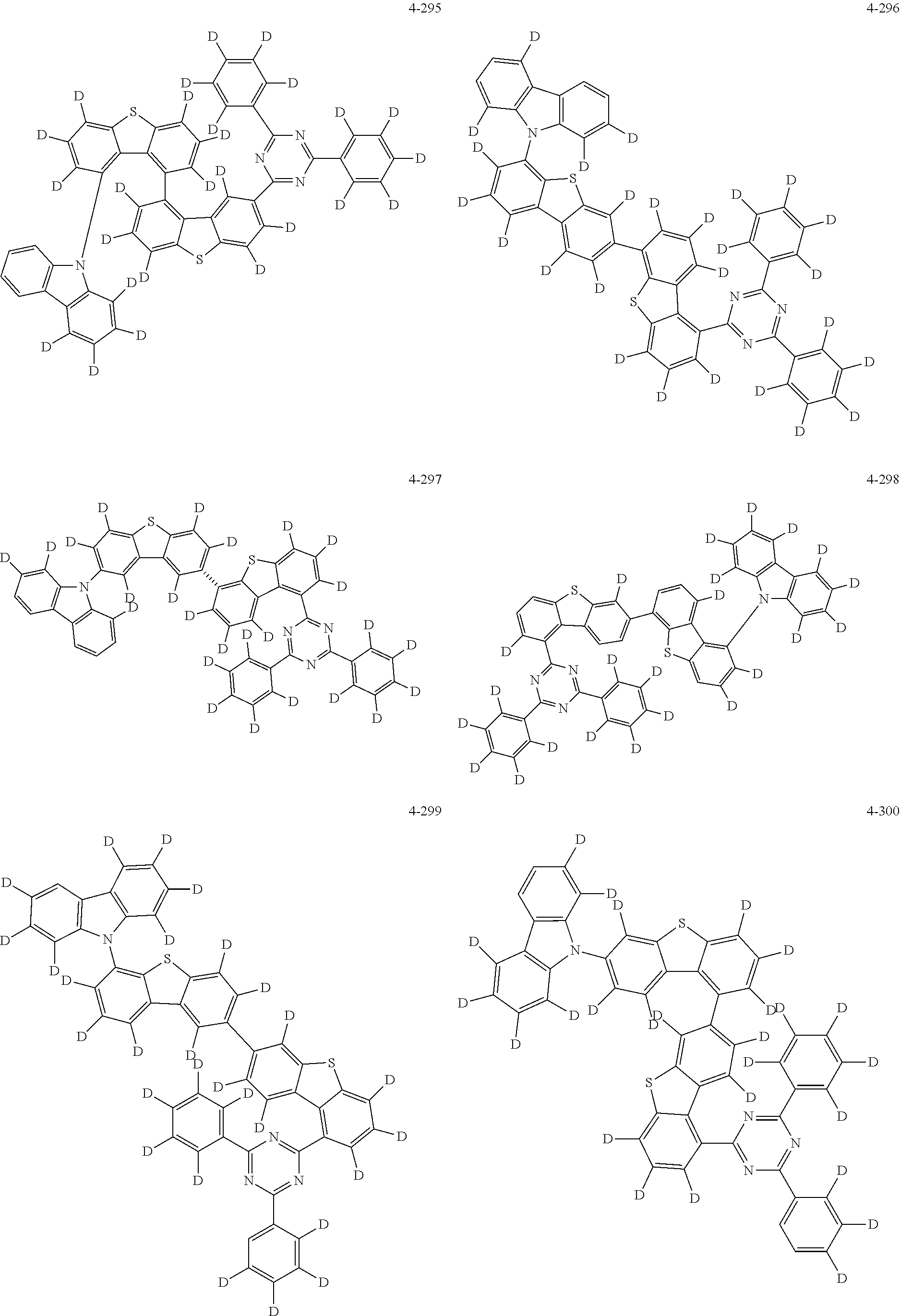

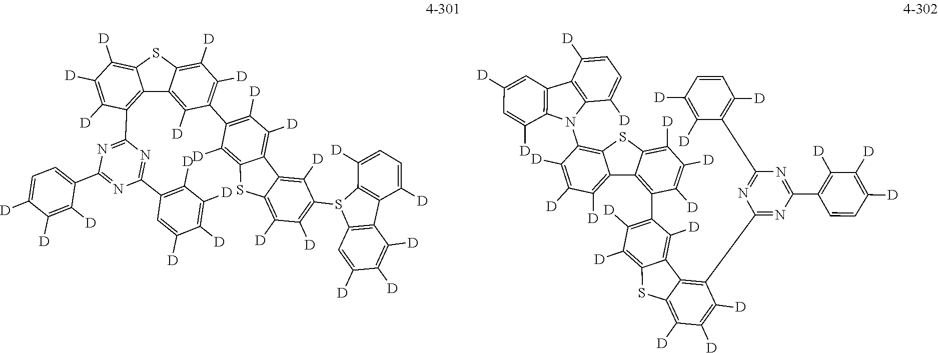

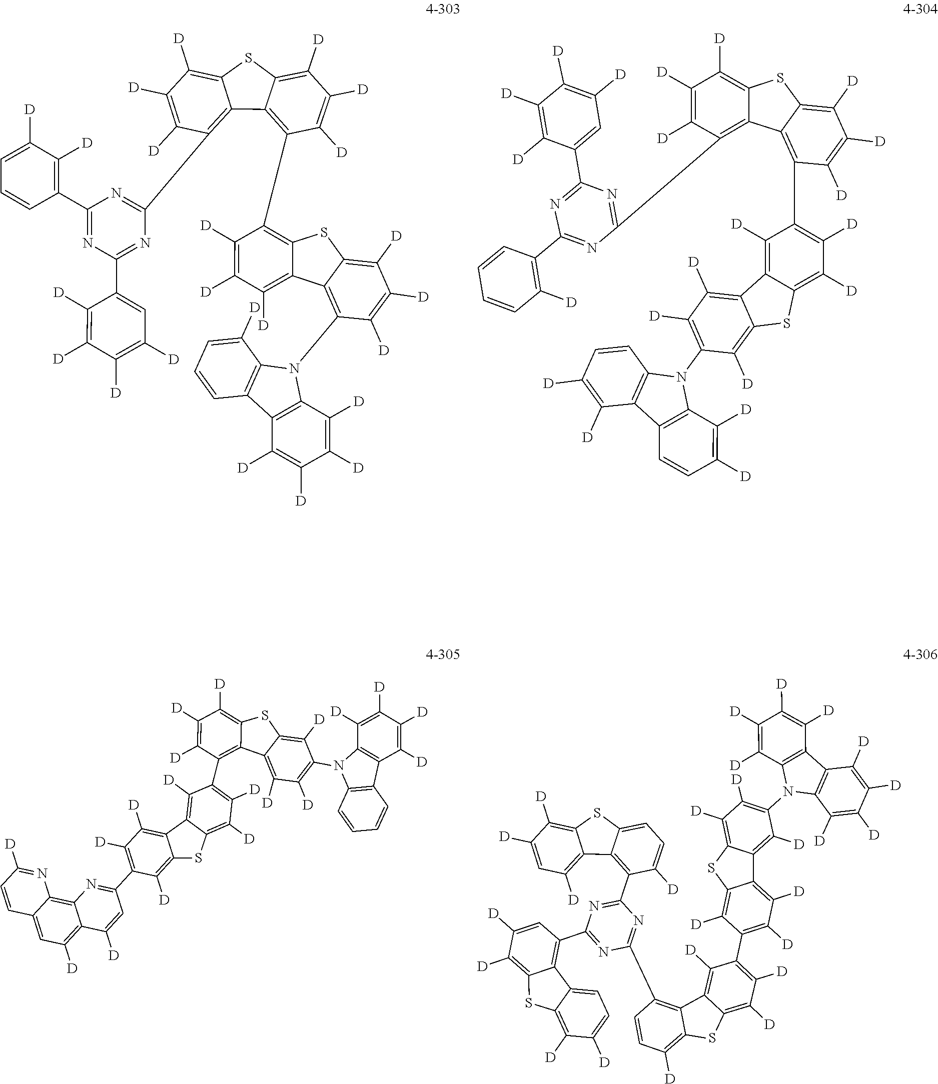

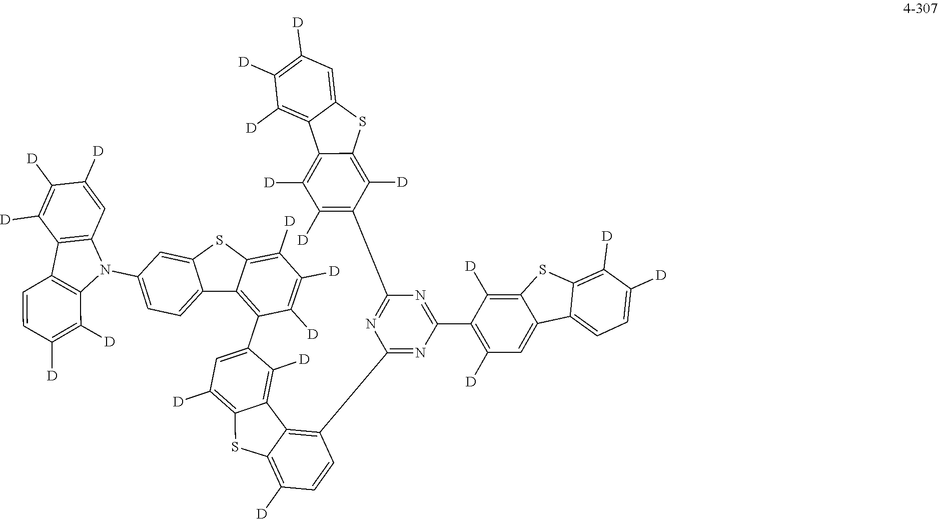 [SMILES: [2H]c1cc2sc3c([2H])c(-c4nc(-c5c([2H])cc6c(sc7c([2H])c([2H])ccc76)c5[2H])nc(-c5ccc([2H])c6sc7c([2H])cc(-c8c([2H])c([2H])c([2H])c9sc%10cc(-n%11c%12cc([2H])c([2H])c([2H])c%12c%12ccc([2H])c([2H])c%12%11)ccc%10c89)c([2H])c7c56)n4)c([2H])c([2H])c3c2c([2H])c1[2H]]

### <Second Compound (Chemical Formula 2)>

In an exemplary embodiment of the present specification, the second compound (Chemical Formula 2) may be represented by any one of the following Chemical Formulae 2-1 to 2-5.

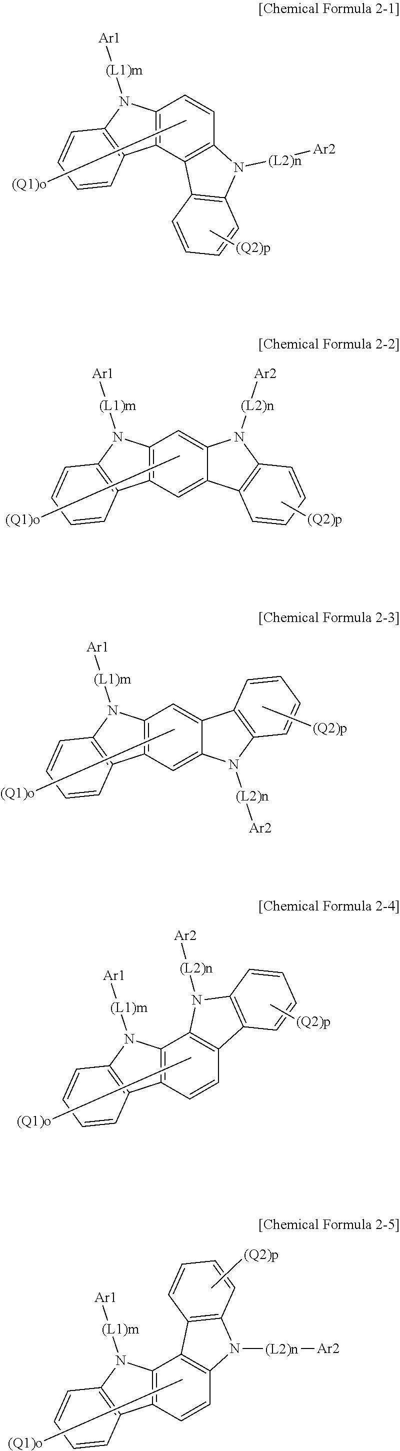

In Chemical Formulae 2-1 to 2-5,
the definition of each substituent is the same as the definition in Chemical Formula 2.

In an exemplary embodiment of the present specification, L1 and L2 may be each independently a direct bond; a substituted or unsubstituted arylene group having 6 to 40 carbon atoms; or a substituted or unsubstituted heteroarylene group having 2 to 40 carbon atoms.

In an exemplary embodiment of the present specification, L1 and L2 may be each independently a direct bond; a substituted or unsubstituted arylene group having 6 to 20 carbon atoms; or a substituted or unsubstituted heteroarylene group having 2 to 20 carbon atoms.

In an exemplary embodiment of the present specification, L1 and L2 may be each independently a direct bond; a substituted or unsubstituted arylene group having 6 to 20 carbon atoms; or a heteroarylene group having 2 to 20 carbon atoms, which is substituted or unsubstituted and includes O.

In an exemplary embodiment of the present specification, L1 and L2 may be each independently a direct bond; a substituted or unsubstituted phenylene group; a substituted or unsubstituted biphenylene group; or a substituted or unsubstituted divalent dibenzofuran group.

In an exemplary embodiment of the present specification, L1 and L2 may be each independently a direct bond; an arylene group having 6 to 40 carbon atoms, which is unsubstituted or substituted with deuterium; or a heteroarylene group having 2 to 40 carbon atoms, which is unsubstituted or substituted with deuterium.

In an exemplary embodiment of the present specification, L1 and L2 may be each independently a direct bond; an arylene group having 6 to 20 carbon atoms, which is unsubstituted or substituted with deuterium; or a heteroarylene group having 2 to 20 carbon atoms, which is unsubstituted or substituted with deuterium.

In an exemplary embodiment of the present specification, L1 and L2 may be each independently a direct bond; an arylene group having 6 to 20 carbon atoms, which is unsubstituted or substituted with deuterium; or a heteroarylene group having 2 to 20 carbon atoms, which is unsubstituted or substituted with deuterium and includes O.

In an exemplary embodiment of the present specification, L1 and L2 may be each independently a direct bond; a phenylene group unsubstituted or substituted with deuterium; a biphenylene group unsubstituted or substituted with deuterium; or a divalent dibenzofuran group unsubstituted or substituted with deuterium.

In an exemplary embodiment of the present specification, L1 and L2 may be each independently a direct bond; or a substituted or unsubstituted arylene group having 6 to 60 carbon atoms.

In an exemplary embodiment of the present specification, L1 and L2 may be each independently a direct bond; or a substituted or unsubstituted arylene group having 6 to 40 carbon atoms.

In an exemplary embodiment of the present specification, L1 and L2 may be each independently a direct bond; or a substituted or unsubstituted arylene group having 6 to 20 carbon atoms.

In an exemplary embodiment of the present specification, L1 and L2 may be each independently a direct bond; or an arylene group having 6 to 60 carbon atoms, which is unsubstituted or substituted with deuterium.

In an exemplary embodiment of the present specification, L1 and L2 may be each independently a direct bond; or an arylene group having 6 to 40 carbon atoms, which is unsubstituted or substituted with deuterium.

In an exemplary embodiment of the present specification, L1 and L2 may be each independently a direct bond; or an arylene group having 6 to 20 carbon atoms, which is unsubstituted or substituted with deuterium.

In an exemplary embodiment of the present specification, L1 and L2 may be each independently a direct bond; a phenylene group unsubstituted or substituted with deuterium; or a biphenylene group unsubstituted or substituted with deuterium.

In an exemplary embodiment of the present specification, m and n may be 1.

In an exemplary embodiment of the present specification, Ar1 and Ar2 may be each independently a substituted or unsubstituted aryl group having 6 to 40 carbon atoms; or a substituted or unsubstituted heteroaryl group having 2 to 40 carbon atoms.

In an exemplary embodiment of the present specification, Ar1 and Ar2 may be each independently a substituted or unsubstituted aryl group having 6 to 40 carbon atoms; or a heteroaryl group having 2 to 40 carbon atoms, which is substituted or unsubstituted and includes 0.

In an exemplary embodiment of the present specification, Ar1 and Ar2 may be each independently a substituted or unsubstituted phenyl group; a substituted or unsubstituted biphenyl group; a substituted or unsubstituted terphenyl group; a substituted or unsubstituted triphenylene group; or a substituted or unsubstituted dibenzofuran group.

In an exemplary embodiment of the present specification, Ar1 and Ar2 may be each independently an aryl group having 6 to 60 carbon atoms, which is unsubstituted or substituted with deuterium; or a heteroaryl group having 2 to 60 carbon atoms, which is unsubstituted or substituted with deuterium, an aryl group, or an aryl group substituted with deuterium.

In an exemplary embodiment of the present specification, Ar1 and Ar2 may be each independently an aryl group having 6 to 40 carbon atoms, which is unsubstituted or substituted with deuterium; or a heteroaryl group having 2 to 40 carbon atoms, which is unsubstituted or substituted with deuterium, an aryl group, or an aryl group substituted with deuterium.

In an exemplary embodiment of the present specification, Ar1 and Ar2 may be each independently an aryl group having 6 to 40 carbon atoms, which is unsubstituted or substituted with deuterium; or a heteroaryl group having 2 to 40 carbon atoms, which is unsubstituted or substituted with deuterium, an aryl group, or an aryl group substituted with deuterium and includes 0.

In an exemplary embodiment of the present specification, Ar1 and Ar2 may be each independently a phenyl group unsubstituted or substituted with deuterium; a biphenyl group unsubstituted or substituted with deuterium; a terphenyl group unsubstituted or substituted with deuterium; a triphenylene group unsubstituted or substituted with deuterium; or a dibenzofuran group unsubstituted or substituted with deuterium, an aryl group, or an aryl group substituted with deuterium.

In an exemplary embodiment of the present specification, Ar1 and Ar2 may be each independently a phenyl group unsubstituted or substituted with deuterium; a biphenyl group unsubstituted or substituted with deuterium; a terphenyl group unsubstituted or substituted with deuterium; a triphenylene group unsubstituted or substituted with deuterium; or a dibenzofuran group unsubstituted or substituted with deuterium.

In an exemplary embodiment of the present specification, Q1 and Q2 may be each independently hydrogen; deuterium; a halogen group; a cyano group; a substituted or unsubstituted alkyl group having 1 to 60 carbon atoms; a substituted or unsubstituted alkenyl group having 2 to 60 carbon atoms; a substituted or unsubstituted alkynyl group having 2 to 60 carbon atoms; a substituted or unsubstituted alkoxy group having 1 to 60 carbon atoms; a substituted or unsubstituted cycloalkyl group having 3 to 60 carbon atoms; or a substituted or unsubstituted heterocycloalkyl group having 2 to 60 carbon atoms.

In an exemplary embodiment of the present specification, Q1 and Q2 may be each independently hydrogen; deuterium; or a substituted or unsubstituted alkyl group having 1 to 60 carbon atoms.

In an exemplary embodiment of the present specification, Q1 and Q2 may be each independently hydrogen; deuterium; or a substituted or unsubstituted alkyl group having 1 to 30 carbon atoms.

In an exemplary embodiment of the present specification, Q1 and Q2 may be each independently hydrogen; deuterium; or a substituted or unsubstituted alkyl group having 1 to 10 carbon atoms.

In an exemplary embodiment of the present specification, Q1 and Q2 may be each independently hydrogen; or deuterium.

In an exemplary embodiment of the present specification, o may be 6.

In an exemplary embodiment of the present specification, p may be 4.

In an exemplary embodiment of the present specification, the deuterium substitution rate of the

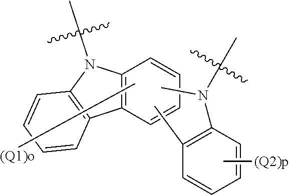

structure in Chemical Formula 2 may be 0%, or 10% to 100%.

In an exemplary embodiment of the present specification, the deuterium substitution rate of the

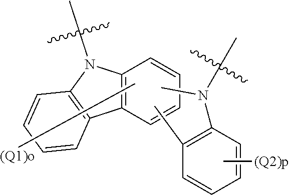

structure in Chemical Formula 2 may be 0%, or 20% to 100%.

In an exemplary embodiment of the present specification, the deuterium substitution rate of the

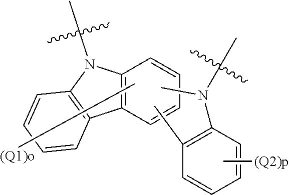

structure in Chemical Formula 2 may be 0%, or 30% to 100%.

In an exemplary embodiment of the present specification, the deuterium substitution rate of the

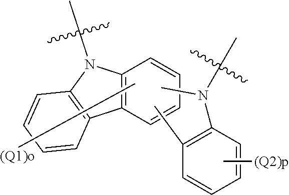

structure in Chemical Formula 2 may be 0%, or 50% to 100%.

In an exemplary embodiment of the present specification, the deuterium substitution rate of the

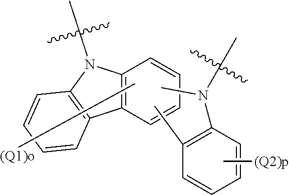

structure in Chemical Formula 2 may be 10% to 100%.

In an exemplary embodiment of the present specification, the deuterium substitution rate of the

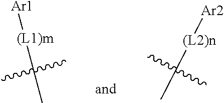

structures in Chemical Formula 2 may be each 0%, or 10% to 100%.

In an exemplary embodiment of the present specification, the deuterium substitution rate of the

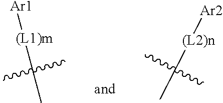

structures in Chemical Formula 2 may be each 0%, or 20% to 100%.

In an exemplary embodiment of the present specification, the deuterium substitution rate of the

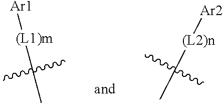

structures in Chemical Formula 2 may be each 0%, or 30% to 100%.

In an exemplary embodiment of the present specification, the deuterium substitution rate of the

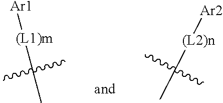

structures in Chemical Formula 2 may be each 0%, or 50% to 100%.

In an exemplary embodiment of the present specification, the deuterium substitution rate based on the total hydrogen and deuterium of the second compound may be 0%, or more than 0% and 100% or less.

In an exemplary embodiment of the present specification, the deuterium substitution rate of the second compound may be 0%, or 10% to 100%.

In an exemplary embodiment of the present specification, the deuterium substitution rate of the second compound may be 0%, or 15% to 100%.

In an exemplary embodiment of the present specification, the deuterium substitution rate of the second compound may be 0%, or 20% to 100%.

The content described on the first compound may be applied to the deuterium-substituted configuration of the second compound.

In an exemplary embodiment of the present specification, the second compound may be represented by any one of the following compounds.

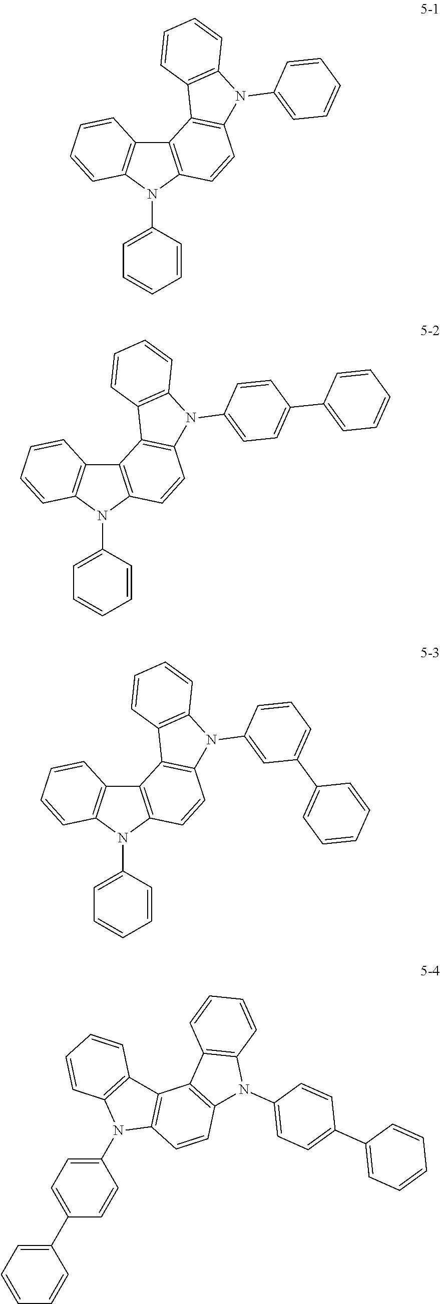 [SMILES: c1ccc(-n2c3ccccc3c3c4c5ccccc5n(-c5ccccc5)c4ccc32)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1 ; c1ccc(-c2ccc(-n3c4ccccc4c4c5c6ccccc6n(-c6ccc(-c7ccccc7)cc6)c5ccc43)cc2)cc1]

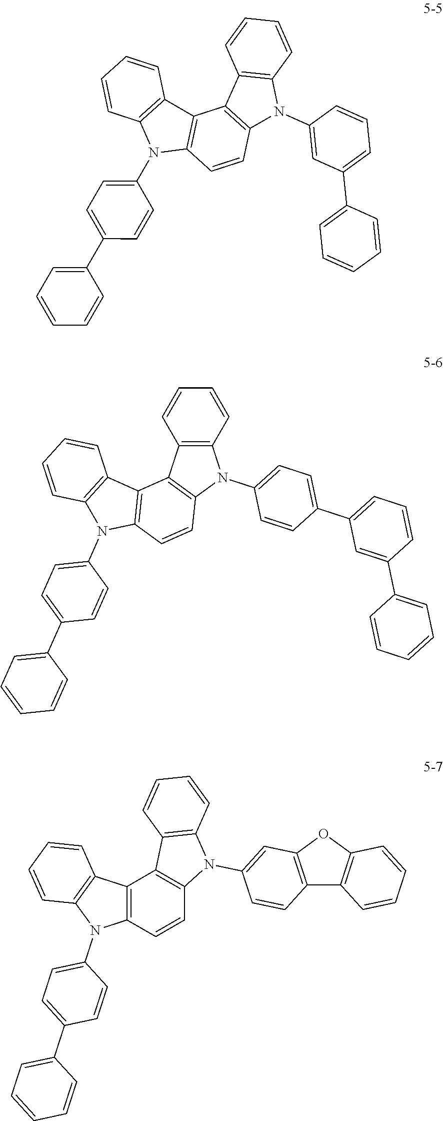 [SMILES: c1ccc(-c2ccc(-n3c4ccccc4c4c5c6ccccc6n(-c6cccc(-c7ccccc7)c6)c5ccc43)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1 ; c1ccc(-c2ccc(-n3c4ccccc4c4c5c6ccccc6n(-c6ccc7c(c6)oc6ccccc67)c5ccc43)cc2)cc1]

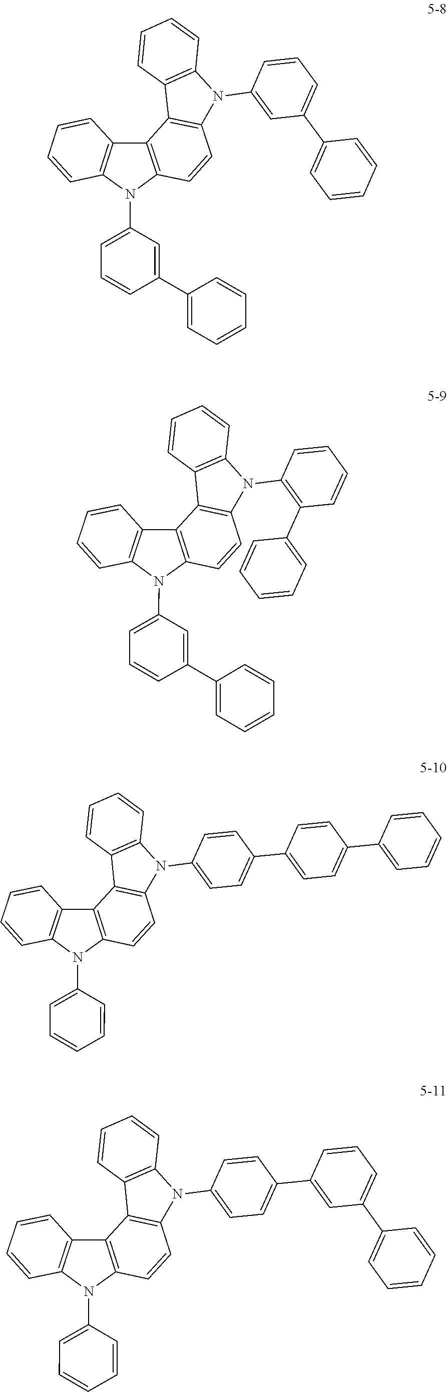 [SMILES: c1ccc(-c2cccc(-n3c4ccccc4c4c5c6ccccc6n(-c6cccc(-c7ccccc7)c6)c5ccc43)c2)cc1 ; c1ccc(-c2cccc(-n3c4ccccc4c4c5c6ccccc6n(-c6ccccc6-c6ccccc6)c5ccc43)c2)cc1 ; c1ccc(-c2ccc(-c3ccc(-n4c5ccccc5c5c6c7ccccc7n(-c7ccccc7)c6ccc54)cc3)cc2)cc1 ; c1ccc(-c2cccc(-c3ccc(-n4c5ccccc5c5c6c7ccccc7n(-c7ccccc7)c6ccc54)cc3)c2)cc1]

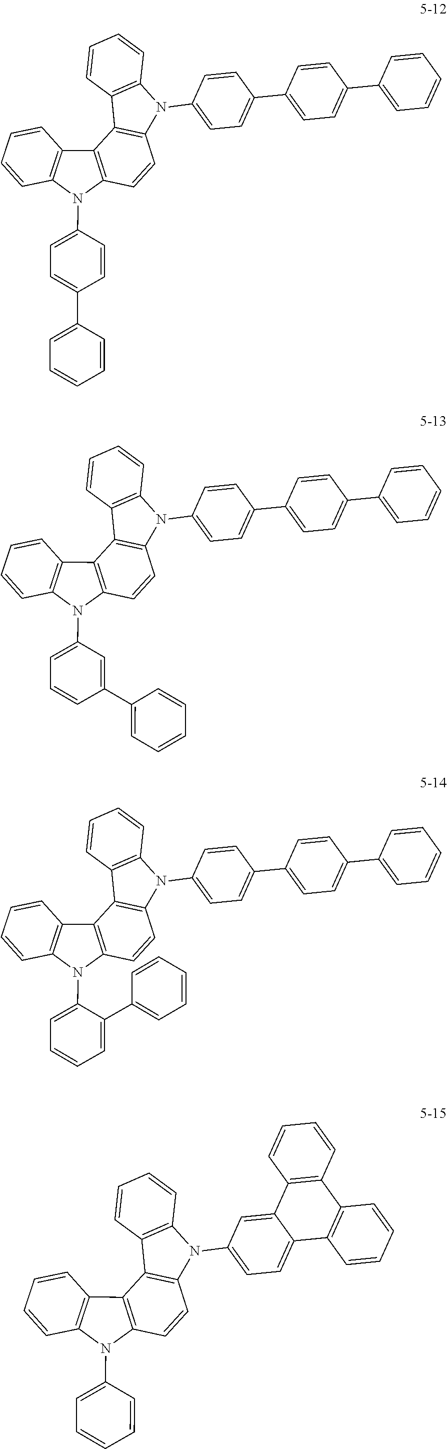 [SMILES: c1ccc(-c2ccc(-c3ccc(-n4c5ccccc5c5c6c7ccccc7n(-c7ccc(-c8ccccc8)cc7)c6ccc54)cc3)cc2)cc1 ; c1ccc(-c2ccc(-c3ccc(-n4c5ccccc5c5c6c7ccccc7n(-c7cccc(-c8ccccc8)c7)c6ccc54)cc3)cc2)cc1 ; c1ccc(-c2ccc(-c3ccc(-n4c5ccccc5c5c6c7ccccc7n(-c7ccccc7-c7ccccc7)c6ccc54)cc3)cc2)cc1 ; c1ccc(-n2c3ccccc3c3c4c5ccccc5n(-c5ccc6c7ccccc7c7ccccc7c6c5)c4ccc32)cc1]

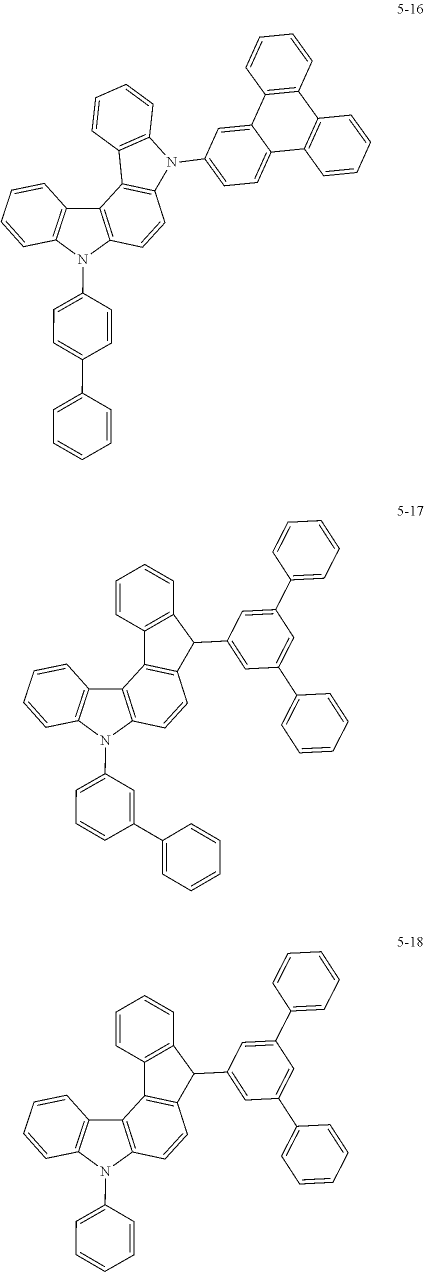 [SMILES: c1ccc(-c2ccc(-n3c4ccccc4c4c5c6ccccc6n(-c6ccc7c8ccccc8c8ccccc8c7c6)c5ccc43)cc2)cc1 ; c1ccc(-c2cc(-c3ccccc3)cc(C3c4ccccc4-c4c3ccc3c4c4ccccc4n3-c3cccc(-c4ccccc4)c3)c2)cc1 ; c1ccc(-c2cc(-c3ccccc3)cc(C3c4ccccc4-c4c3ccc3c4c4ccccc4n3-c3ccccc3)c2)cc1]

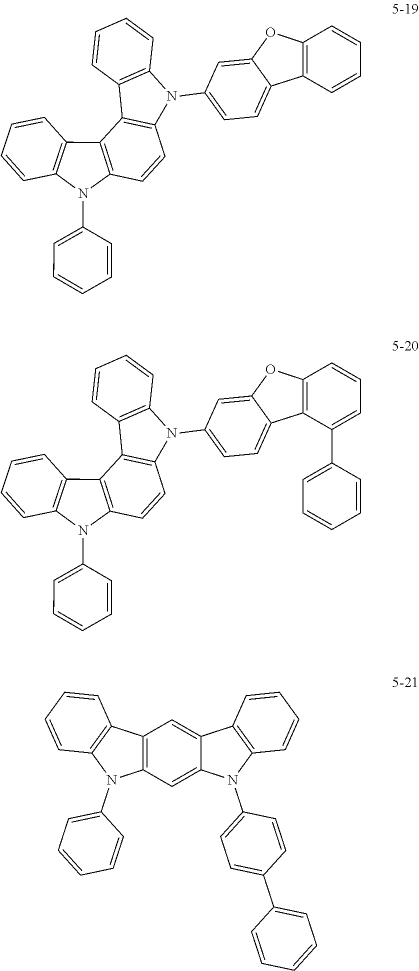 [SMILES: c1ccc(-n2c3ccccc3c3c4c5ccccc5n(-c5ccc6c(c5)oc5ccccc56)c4ccc32)cc1 ; c1ccc(-c2cccc3oc4cc(-n5c6ccccc6c6c7c8ccccc8n(-c8ccccc8)c7ccc65)ccc4c23)cc1 ; c1ccc(-c2ccc(-n3c4ccccc4c4cc5c6ccccc6n(-c6ccccc6)c5cc43)cc2)cc1]

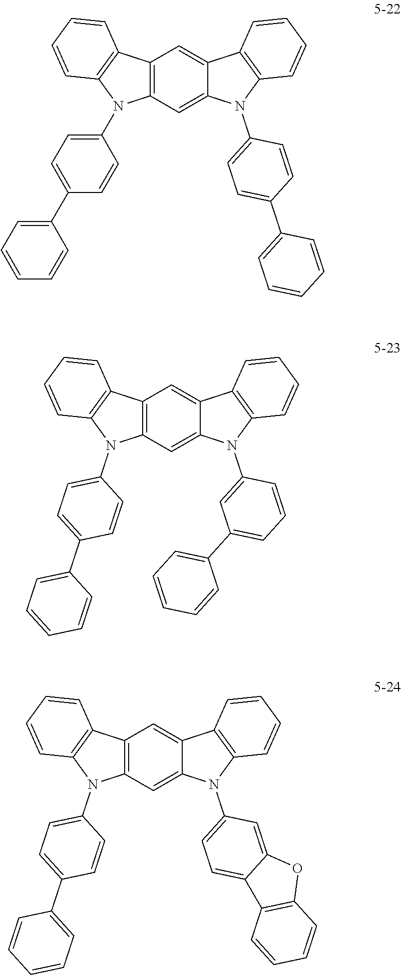 [SMILES: c1ccc(-c2ccc(-n3c4ccccc4c4cc5c6ccccc6n(-c6ccc(-c7ccccc7)cc6)c5cc43)cc2)cc1 ; c1ccc(-c2ccc(-n3c4ccccc4c4cc5c6ccccc6n(-c6cccc(-c7ccccc7)c6)c5cc43)cc2)cc1 ; c1ccc(-c2ccc(-n3c4ccccc4c4cc5c6ccccc6n(-c6ccc7c(c6)oc6ccccc67)c5cc43)cc2)cc1]

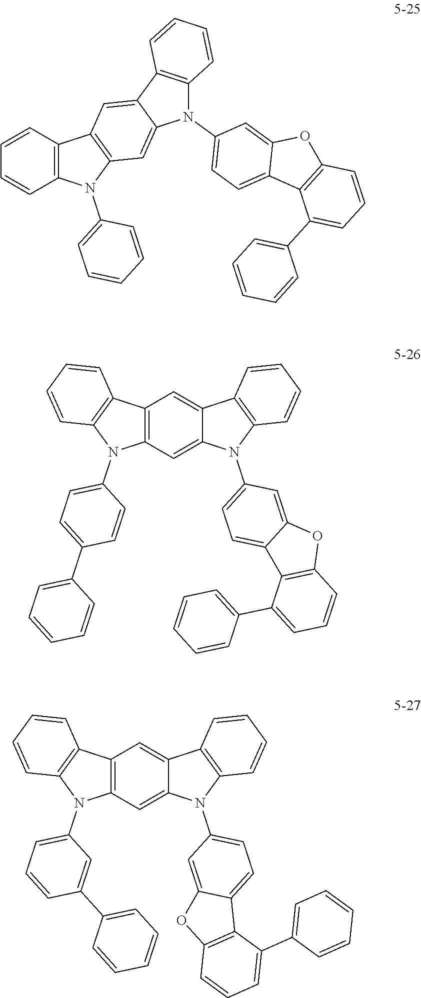 [SMILES: c1ccc(-c2cccc3oc4cc(-n5c6ccccc6c6cc7c8ccccc8n(-c8ccccc8)c7cc65)ccc4c23)cc1 ; c1ccc(-c2ccc(-n3c4ccccc4c4cc5c6ccccc6n(-c6ccc7c(c6)oc6cccc(-c8ccccc8)c67)c5cc43)cc2)cc1 ; c1ccc(-c2cccc(-n3c4ccccc4c4cc5c6ccccc6n(-c6ccc7c(c6)oc6cccc(-c8ccccc8)c67)c5cc43)c2)cc1]

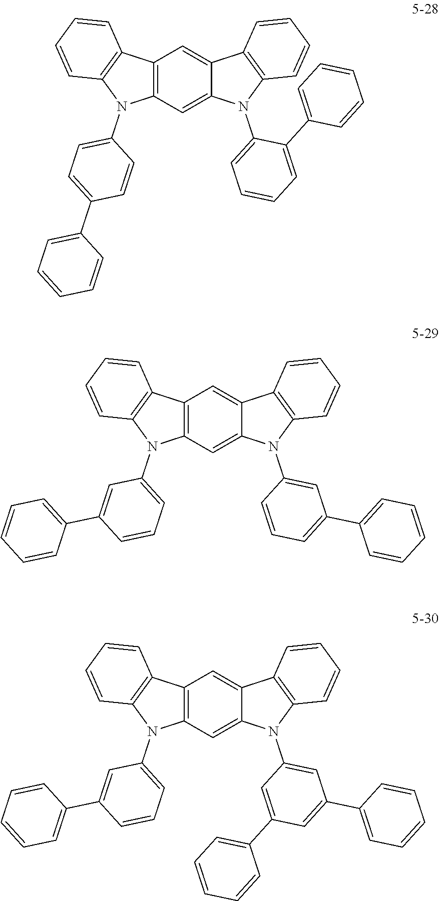 [SMILES: c1ccc(-c2ccc(-n3c4ccccc4c4cc5c6ccccc6n(-c6ccccc6-c6ccccc6)c5cc43)cc2)cc1 ; c1ccc(-c2cccc(-n3c4ccccc4c4cc5c6ccccc6n(-c6cccc(-c7ccccc7)c6)c5cc43)c2)cc1 ; c1ccc(-c2cccc(-n3c4ccccc4c4cc5c6ccccc6n(-c6cc(-c7ccccc7)cc(-c7ccccc7)c6)c5cc43)c2)cc1]

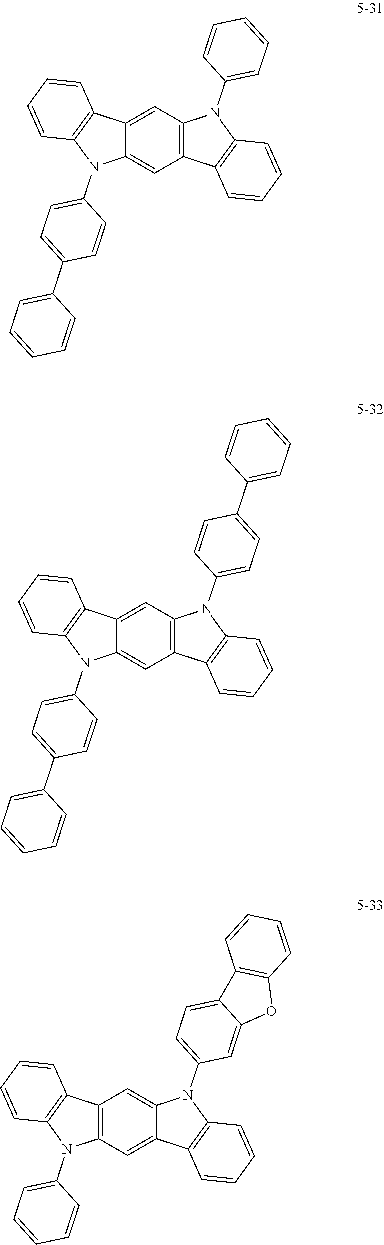 [SMILES: c1ccc(-c2ccc(-n3c4ccccc4c4cc5c(cc43)c3ccccc3n5-c3ccccc3)cc2)cc1 ; c1ccc(-c2ccc(-n3c4ccccc4c4cc5c(cc43)c3ccccc3n5-c3ccc(-c4ccccc4)cc3)cc2)cc1 ; c1ccc(-n2c3ccccc3c3cc4c(cc32)c2ccccc2n4-c2ccc3c(c2)oc2ccccc23)cc1]

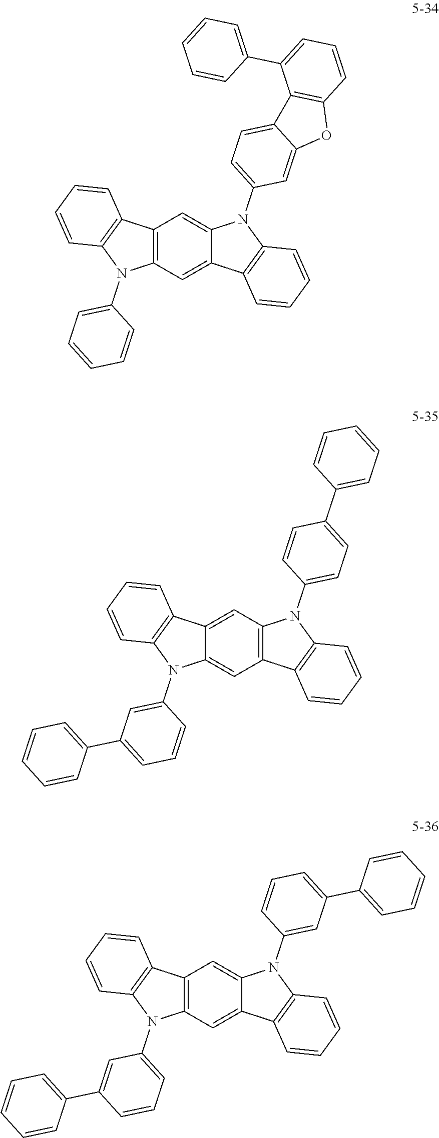 [SMILES: c1ccc(-c2cccc3oc4cc(-n5c6ccccc6c6cc7c(cc65)c5ccccc5n7-c5ccccc5)ccc4c23)cc1 ; c1ccc(-c2ccc(-n3c4ccccc4c4cc5c(cc43)c3ccccc3n5-c3cccc(-c4ccccc4)c3)cc2)cc1 ; c1ccc(-c2cccc(-n3c4ccccc4c4cc5c(cc43)c3ccccc3n5-c3cccc(-c4ccccc4)c3)c2)cc1]

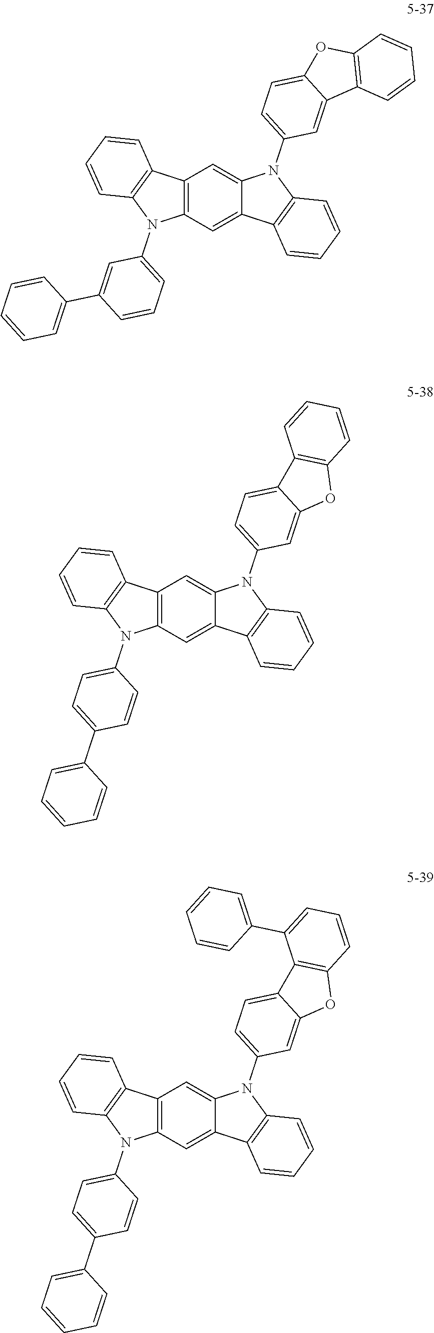 [SMILES: c1ccc(-c2cccc(-n3c4ccccc4c4cc5c(cc43)c3ccccc3n5-c3ccc4oc5ccccc5c4c3)c2)cc1 ; c1ccc(-c2ccc(-n3c4ccccc4c4cc5c(cc43)c3ccccc3n5-c3ccc4c(c3)oc3ccccc34)cc2)cc1 ; c1ccc(-c2ccc(-n3c4ccccc4c4cc5c(cc43)c3ccccc3n5-c3ccc4c(c3)oc3cccc(-c5ccccc5)c34)cc2)cc1]

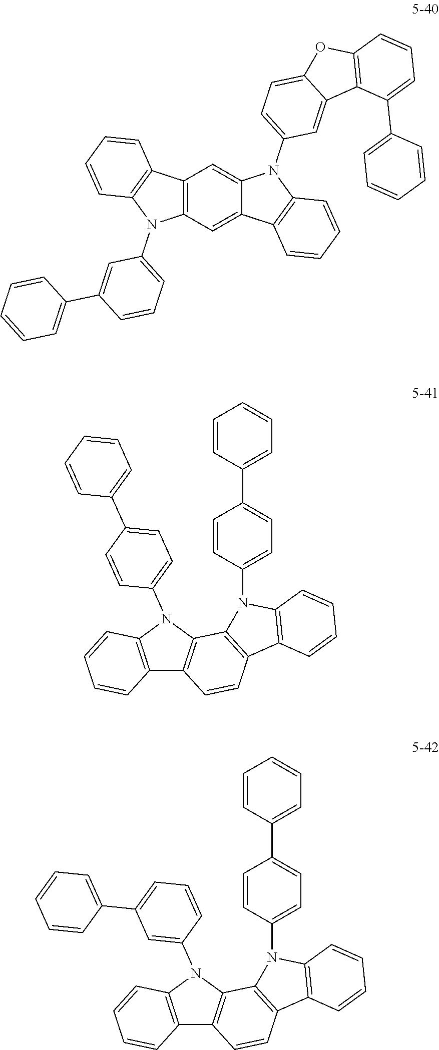 [SMILES: c1ccc(-c2cccc(-n3c4ccccc4c4cc5c(cc43)c3ccccc3n5-c3ccc4oc5cccc(-c6ccccc6)c5c4c3)c2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1]

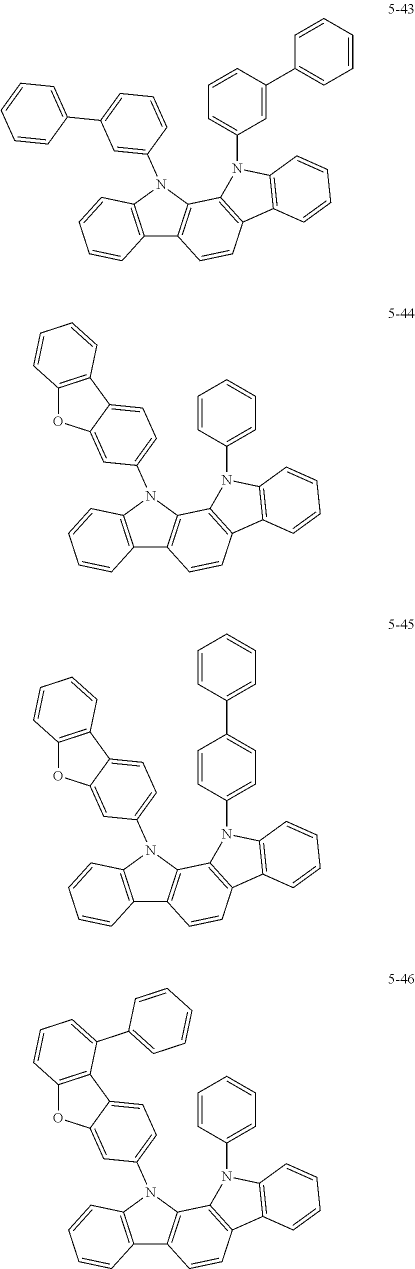 [SMILES: c1ccc(-c2cccc(-n3c4ccccc4c4ccc5c6ccccc6n(-c6cccc(-c7ccccc7)c6)c5c43)c2)cc1 ; c1ccc(-n2c3ccccc3c3ccc4c5ccccc5n(-c5ccc6c(c5)oc5ccccc56)c4c32)cc1 ; c1ccc(-c2ccc(-n3c4ccccc4c4ccc5c6ccccc6n(-c6ccc7c(c6)oc6ccccc67)c5c43)cc2)cc1 ; c1ccc(-c2cccc3oc4cc(-n5c6ccccc6c6ccc7c8ccccc8n(-c8ccccc8)c7c65)ccc4c23)cc1]

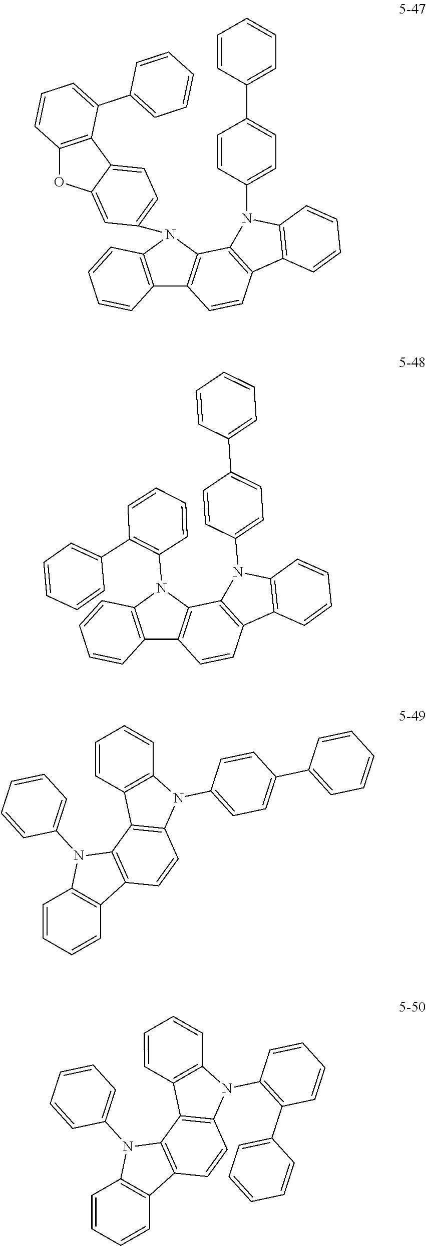 [SMILES: c1ccc(-c2ccc(-n3c4ccccc4c4ccc5c6ccccc6n(-c6ccc7c(c6)oc6cccc(-c8ccccc8)c67)c5c43)cc2)cc1 ; c1ccc(-c2ccc(-n3c4ccccc4c4ccc5c6ccccc6n(-c6ccccc6-c6ccccc6)c5c43)cc2)cc1 ; c1ccc(-c2ccc(-n3c4ccccc4c4c3ccc3c5ccccc5n(-c5ccccc5)c34)cc2)cc1 ; c1ccc(-c2ccccc2-n2c3ccccc3c3c2ccc2c4ccccc4n(-c4ccccc4)c23)cc1]

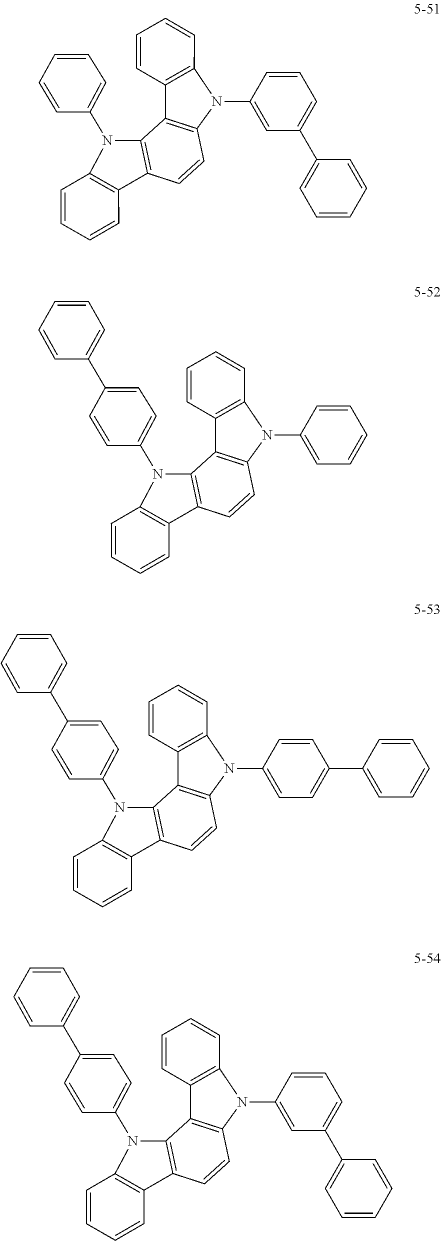 [SMILES: c1ccc(-c2cccc(-n3c4ccccc4c4c3ccc3c5ccccc5n(-c5ccccc5)c34)c2)cc1 ; c1ccc(-c2ccc(-n3c4ccccc4c4ccc5c(c6ccccc6n5-c5ccccc5)c43)cc2)cc1 ; c1ccc(-c2ccc(-n3c4ccccc4c4c3ccc3c5ccccc5n(-c5ccc(-c6ccccc6)cc5)c34)cc2)cc1 ; c1ccc(-c2ccc(-n3c4ccccc4c4ccc5c(c6ccccc6n5-c5cccc(-c6ccccc6)c5)c43)cc2)cc1]

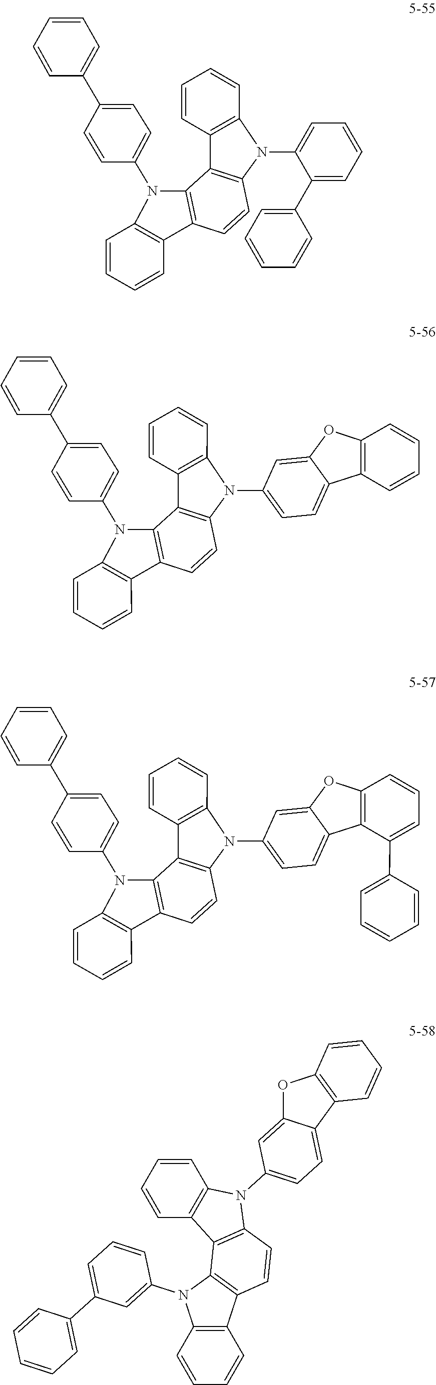 [SMILES: c1ccc(-c2ccc(-n3c4ccccc4c4ccc5c(c6ccccc6n5-c5ccccc5-c5ccccc5)c43)cc2)cc1 ; c1ccc(-c2ccc(-n3c4ccccc4c4ccc5c(c6ccccc6n5-c5ccc6c(c5)oc5ccccc56)c43)cc2)cc1 ; c1ccc(-c2ccc(-n3c4ccccc4c4ccc5c(c6ccccc6n5-c5ccc6c(c5)oc5cccc(-c7ccccc7)c56)c43)cc2)cc1 ; c1ccc(-c2cccc(-n3c4ccccc4c4ccc5c(c6ccccc6n5-c5ccc6c(c5)oc5ccccc56)c43)c2)cc1]

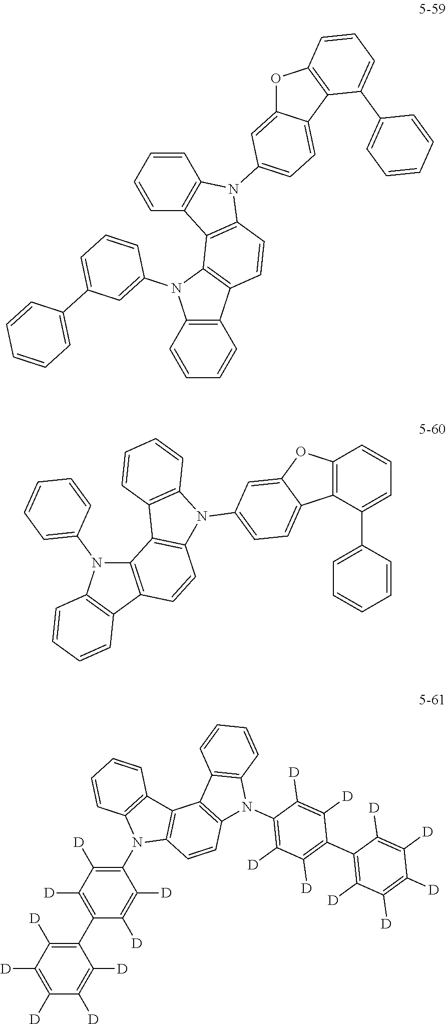 [SMILES: c1ccc(-c2cccc(-n3c4ccccc4c4ccc5c(c6ccccc6n5-c5ccc6c(c5)oc5cccc(-c7ccccc7)c56)c43)c2)cc1 ; c1ccc(-c2cccc3oc4cc(-n5c6ccccc6c6c5ccc5c7ccccc7n(-c7ccccc7)c56)ccc4c23)cc1 ; [2H]c1c([2H])c([2H])c(-c2c([2H])c([2H])c(-n3c4ccccc4c4c5c6ccccc6n(-c6c([2H])c([2H])c(-c7c([2H])c([2H])c([2H])c([2H])c7[2H])c([2H])c6[2H])c5ccc43)c([2H])c2[2H])c([2H])c1[2H]]

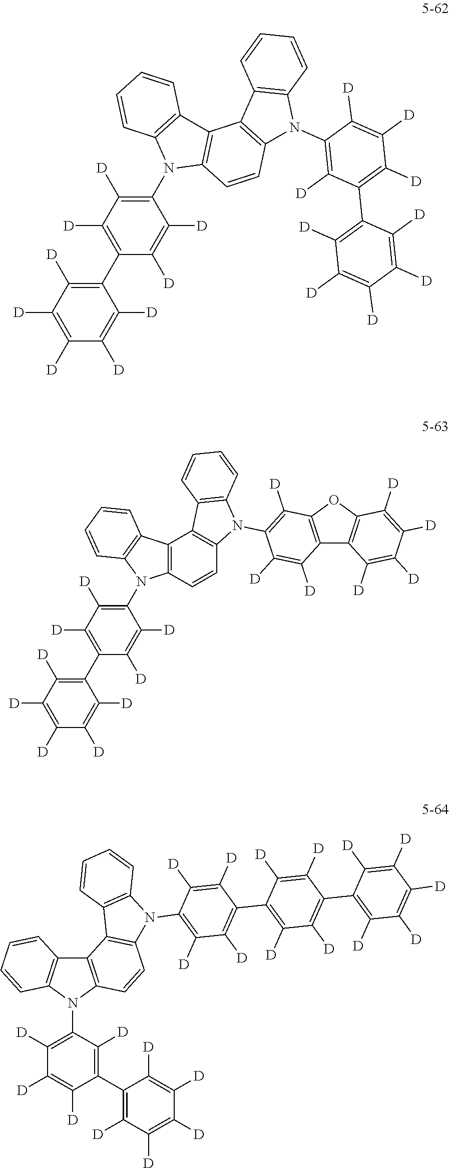

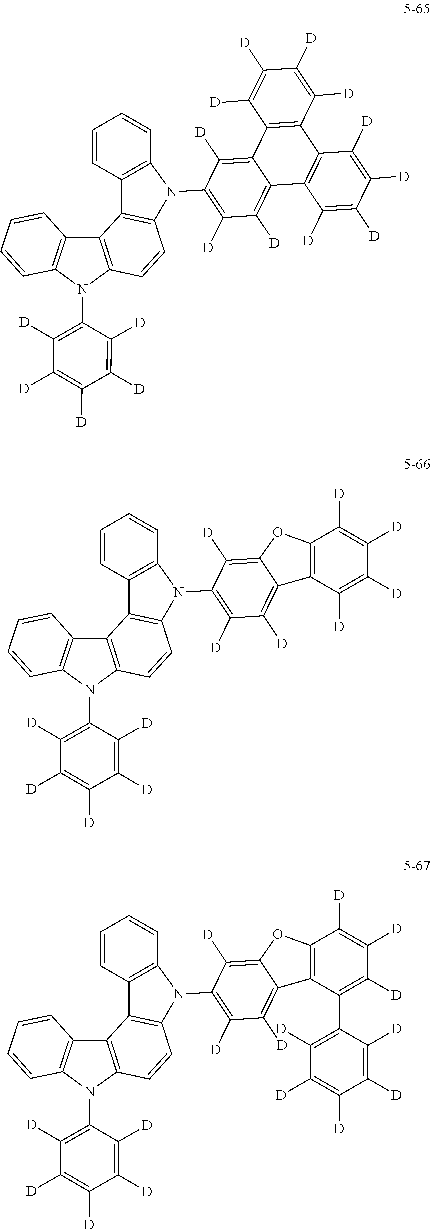 [SMILES: [2H]c1c([2H])c([2H])c(-n2c3ccccc3c3c4c5ccccc5n(-c5c([2H])c([2H])c6c7c([2H])c([2H])c([2H])c([2H])c7c7c([2H])c([2H])c([2H])c([2H])c7c6c5[2H])c4ccc32)c([2H])c1[2H] ; [2H]c1c([2H])c([2H])c(-n2c3ccccc3c3c4c5ccccc5n(-c5c([2H])c([2H])c6c(oc7c([2H])c([2H])c([2H])c([2H])c76)c5[2H])c4ccc32)c([2H])c1[2H] ; [2H]c1c([2H])c([2H])c(-c2c([2H])c([2H])c([2H])c3oc4c([2H])c(-n5c6ccccc6c6c7c8ccccc8n(-c8c([2H])c([2H])c([2H])c([2H])c8[2H])c7ccc65)c([2H])c([2H])c4c23)c([2H])c1[2H]]

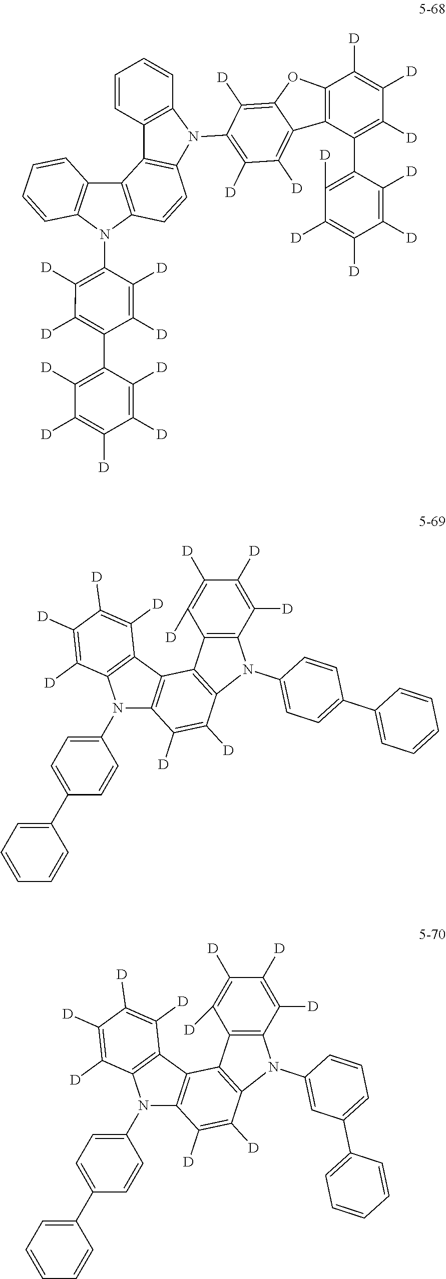 [SMILES: [2H]c1c([2H])c([2H])c(-c2c([2H])c([2H])c(-n3c4ccccc4c4c5c6ccccc6n(-c6c([2H])c([2H])c7c(oc8c([2H])c([2H])c([2H])c(-c9c([2H])c([2H])c([2H])c([2H])c9[2H])c87)c6[2H])c5ccc43)c([2H])c2[2H])c([2H])c1[2H] ; [2H]c1c([2H])c([2H])c2c(c1[2H])c1c3c4c([2H])c([2H])c([2H])c([2H])c4n(-c4ccc(-c5ccccc5)cc4)c3c([2H])c([2H])c1n2-c1ccc(-c2ccccc2)cc1 ; [2H]c1c([2H])c([2H])c2c(c1[2H])c1c3c4c([2H])c([2H])c([2H])c([2H])c4n(-c4cccc(-c5ccccc5)c4)c3c([2H])c([2H])c1n2-c1ccc(-c2ccccc2)cc1]

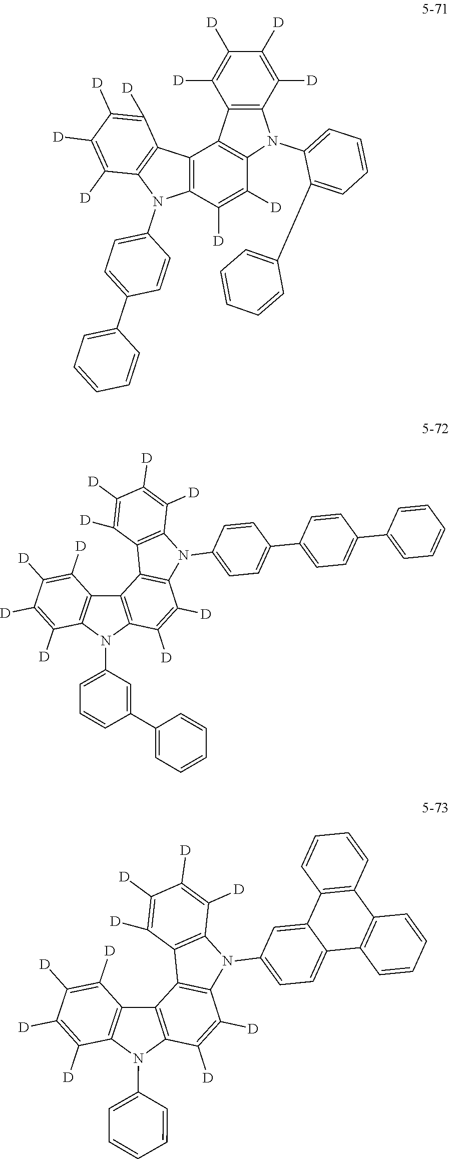 [SMILES: [2H]c1c([2H])c([2H])c2c(c1[2H])c1c3c4c([2H])c([2H])c([2H])c([2H])c4n(-c4ccccc4-c4ccccc4)c3c([2H])c([2H])c1n2-c1ccc(-c2ccccc2)cc1 ; [2H]c1c([2H])c([2H])c2c(c1[2H])c1c3c4c([2H])c([2H])c([2H])c([2H])c4n(-c4cccc(-c5ccccc5)c4)c3c([2H])c([2H])c1n2-c1ccc(-c2ccc(-c3ccccc3)cc2)cc1 ; [2H]c1c([2H])c([2H])c2c(c1[2H])c1c3c4c([2H])c([2H])c([2H])c([2H])c4n(-c4ccc5c6ccccc6c6ccccc6c5c4)c3c([2H])c([2H])c1n2-c1ccccc1]

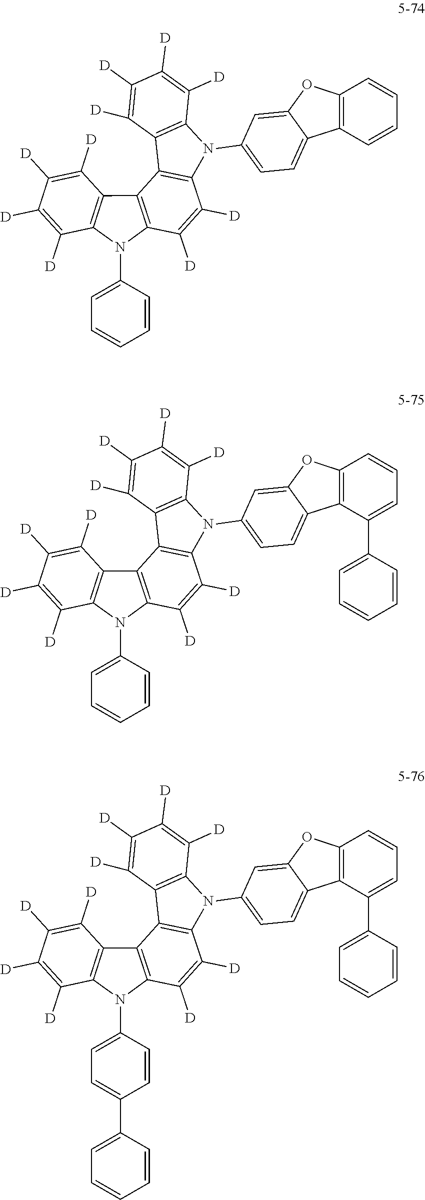 [SMILES: [2H]c1c([2H])c([2H])c2c(c1[2H])c1c3c4c([2H])c([2H])c([2H])c([2H])c4n(-c4ccc5c(c4)oc4ccccc45)c3c([2H])c([2H])c1n2-c1ccccc1 ; [2H]c1c([2H])c([2H])c2c(c1[2H])c1c3c4c([2H])c([2H])c([2H])c([2H])c4n(-c4ccc5c(c4)oc4cccc(-c6ccccc6)c45)c3c([2H])c([2H])c1n2-c1ccccc1 ; [2H]c1c([2H])c([2H])c2c(c1[2H])c1c3c4c([2H])c([2H])c([2H])c([2H])c4n(-c4ccc5c(c4)oc4cccc(-c6ccccc6)c45)c3c([2H])c([2H])c1n2-c1ccc(-c2ccccc2)cc1]

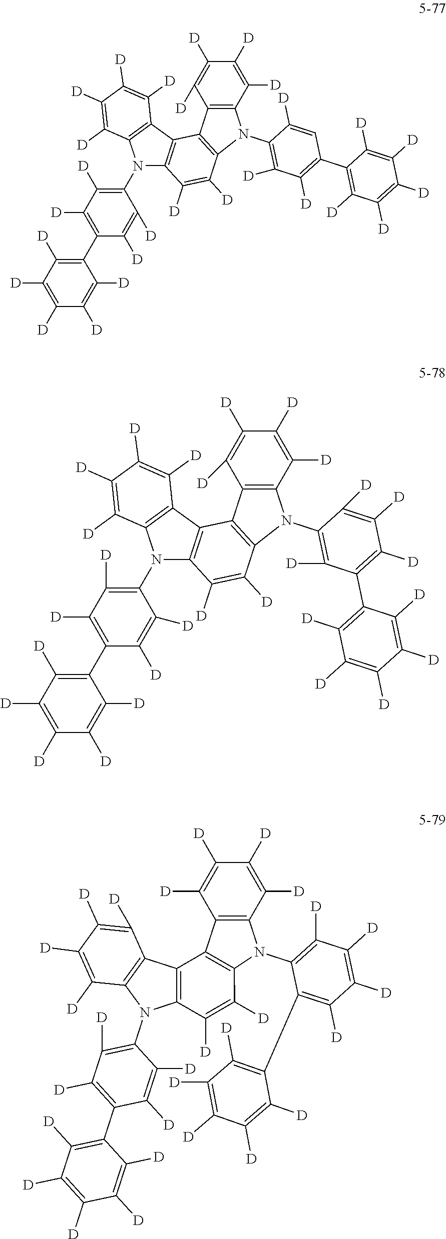

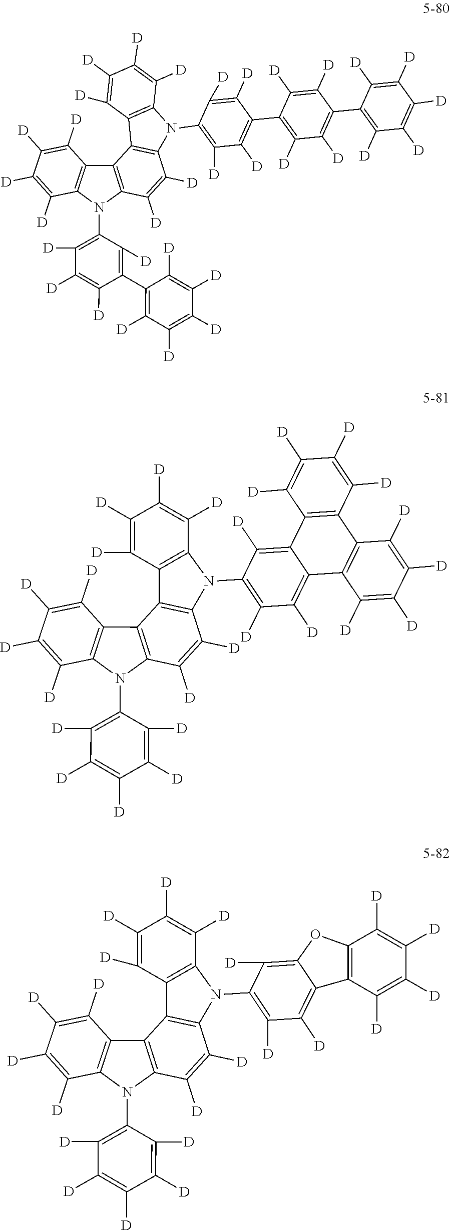

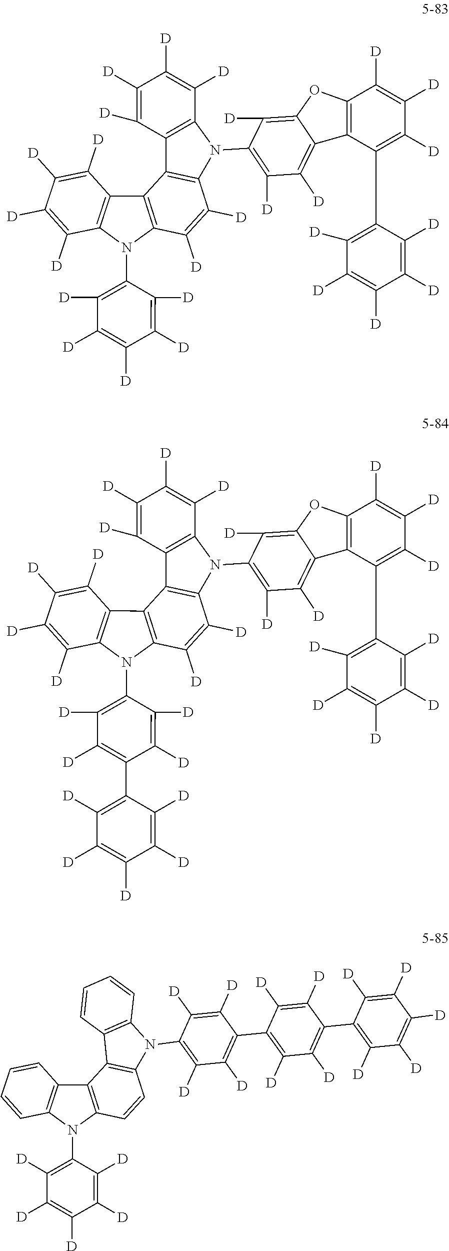

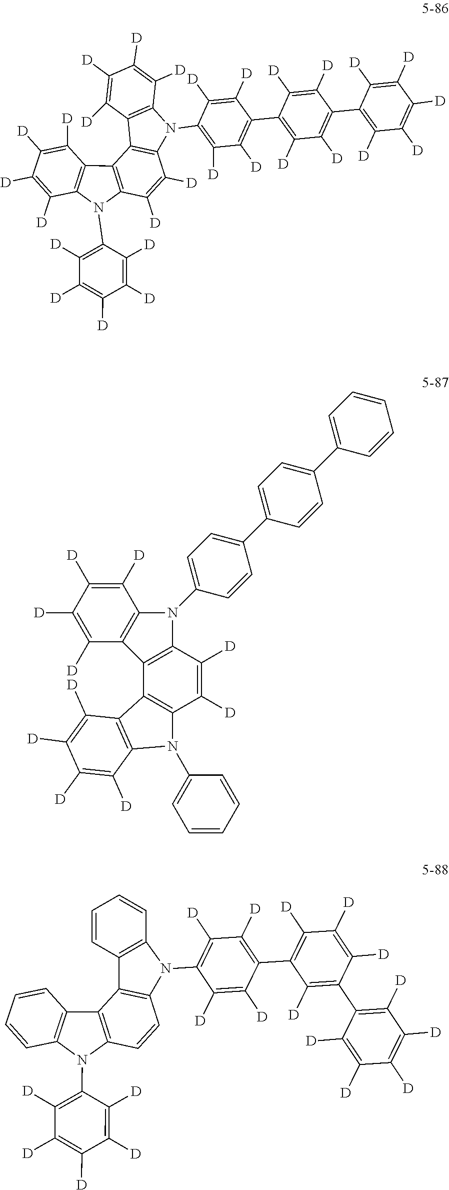

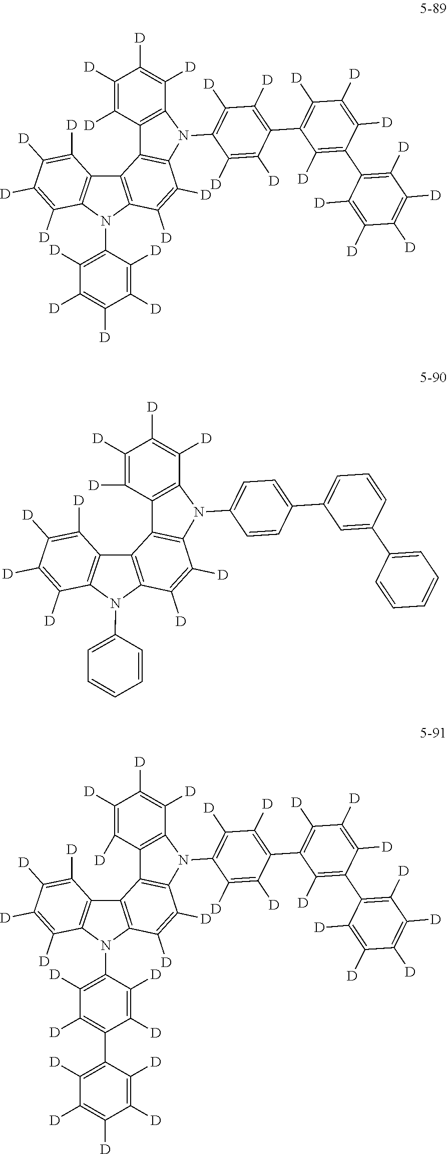

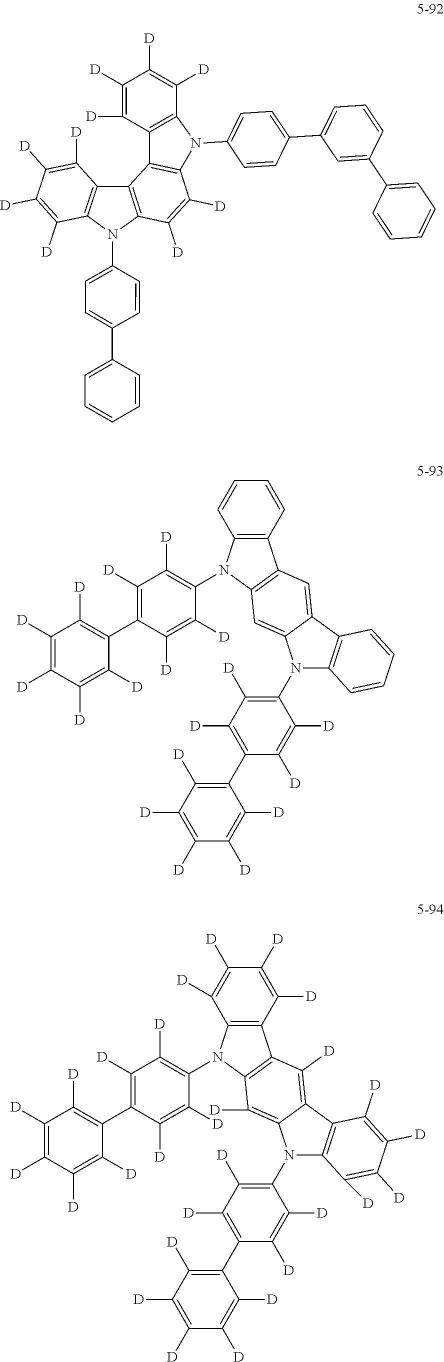

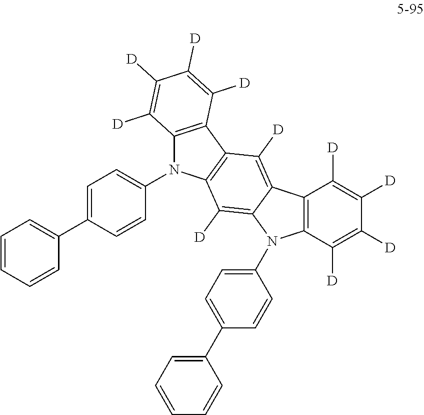 [SMILES: [2H]c1c([2H])c([2H])c2c(c1[2H])c1c([2H])c3c4c([2H])c([2H])c([2H])c([2H])c4n(-c4ccc(-c5ccccc5)cc4)c3c([2H])c1n2-c1ccc(-c2ccccc2)cc1]

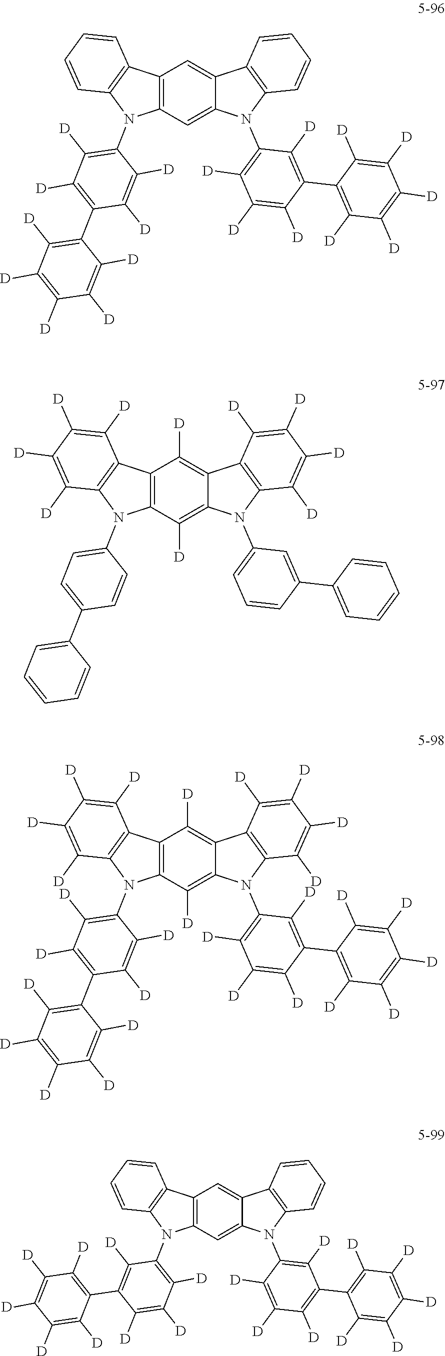

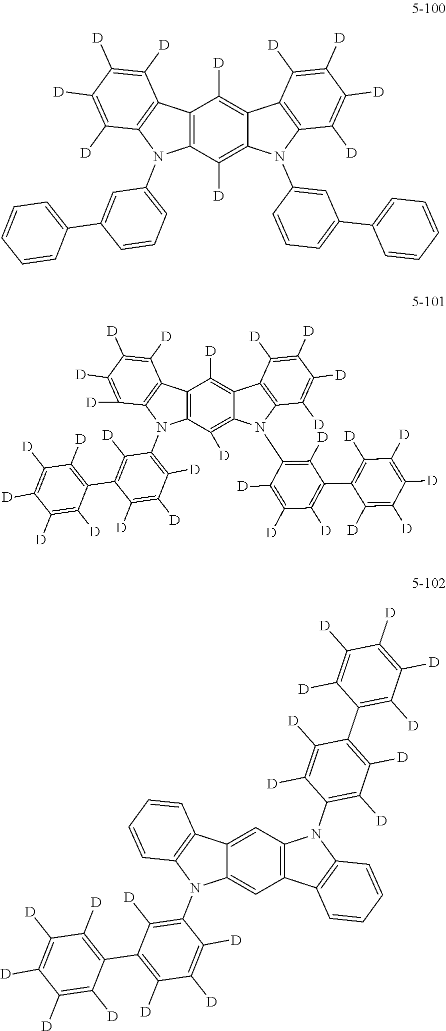

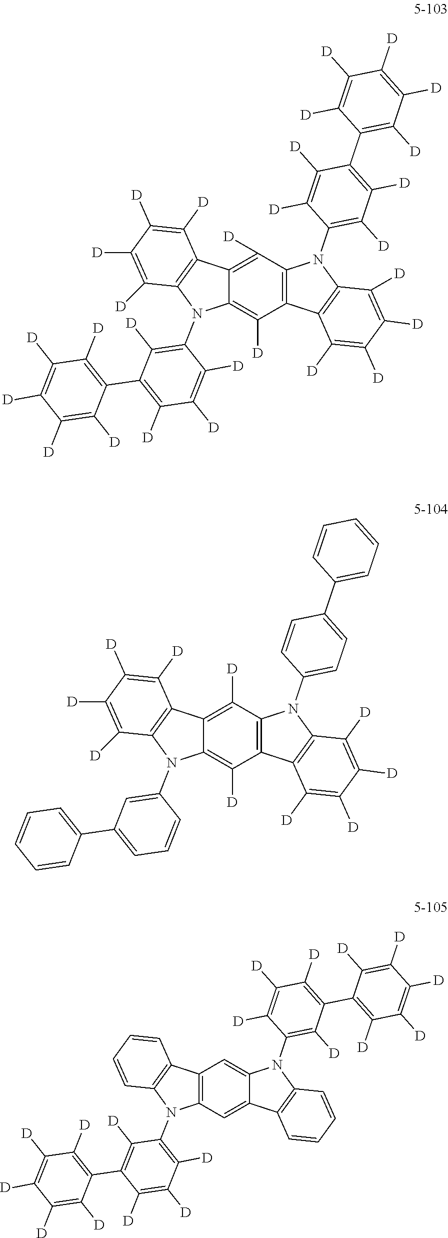

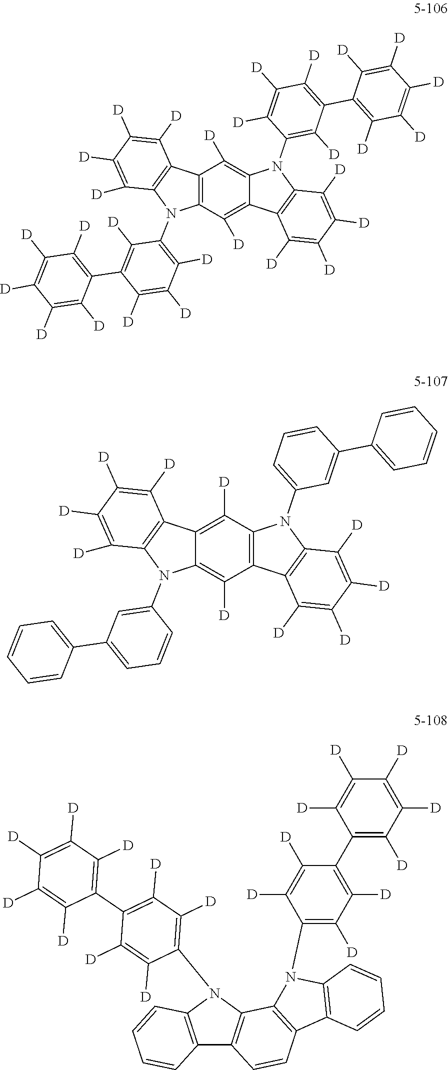

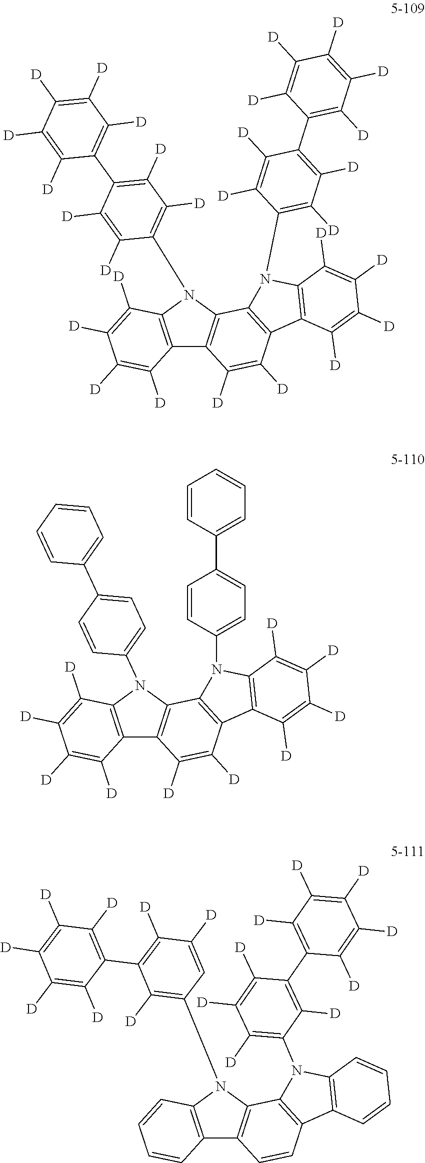

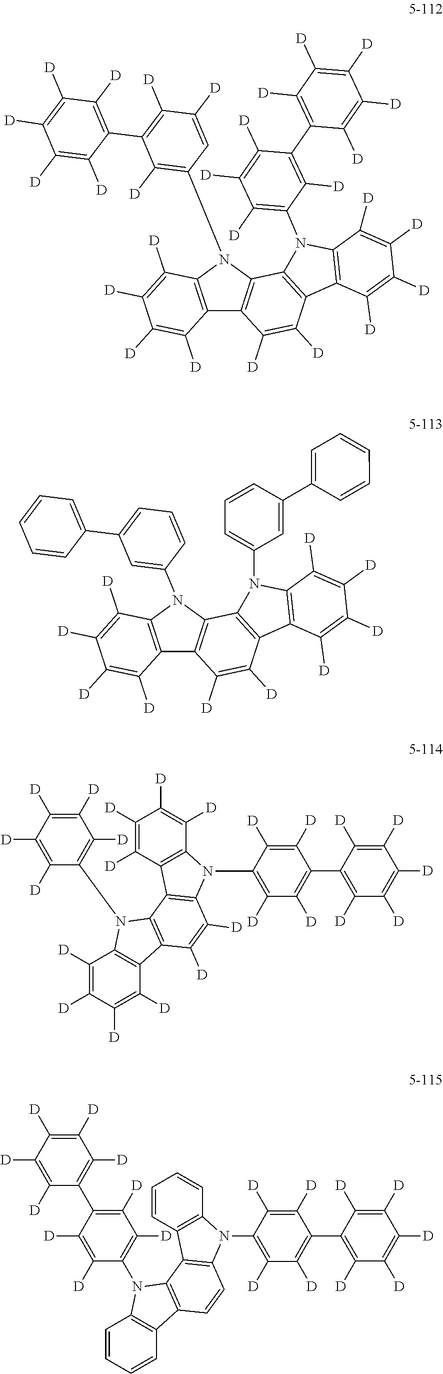

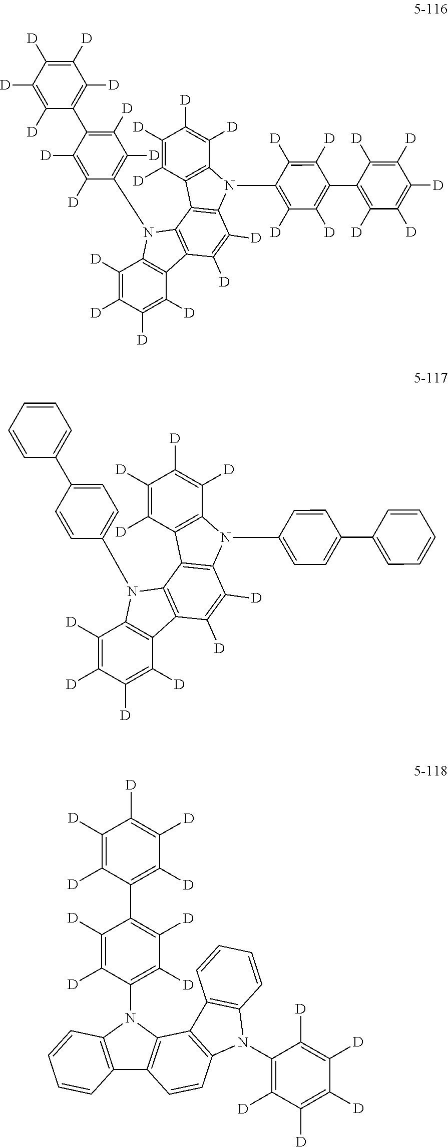

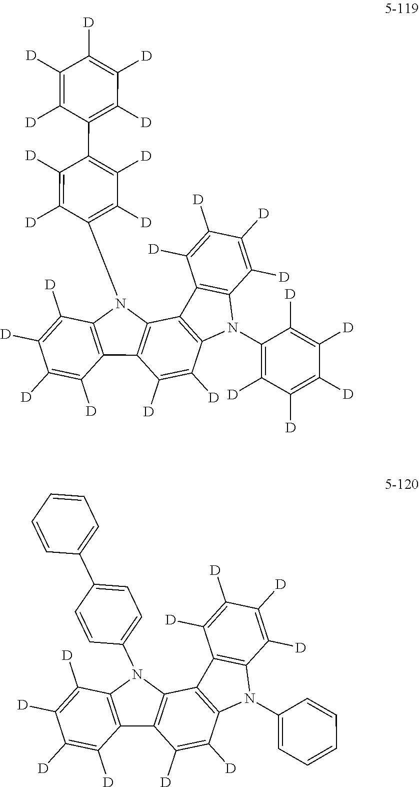 [SMILES: [2H]c1c([2H])c([2H])c(-c2c([2H])c([2H])c(-n3c4c([2H])c([2H])c([2H])c([2H])c4c4c([2H])c([2H])c5c(c6c([2H])c([2H])c([2H])c([2H])c6n5-c5c([2H])c([2H])c([2H])c([2H])c5[2H])c43)c([2H])c2[2H])c([2H])c1[2H] ; [2H]c1c([2H])c([2H])c2c(c1[2H])c1c(c([2H])c([2H])c3c4c([2H])c([2H])c([2H])c([2H])c4n(-c4ccc(-c5ccccc5)cc4)c31)n2-c1ccccc1]

Further, it is possible to synthesize a compound having inherent characteristics of a substituent introduced by introducing various substituents into the structures of Chemical Formulae 1 and 2. For example, it is possible to synthesize a material which satisfies conditions required for each organic material layer by introducing a substituent usually used for a hole injection layer material, a hole transfer layer material, a light emitting layer material, an electron transfer layer material, and a charge generation layer material, which are used for preparing an organic light emitting device, into the core structure.

That is, the composition for an organic material layer of the present invention may be used as a material for an organic material layer of an organic light emitting device, and may be specifically used as a material for a hole injection layer, a hole transfer layer, a light emitting layer, an electron transfer layer, an electron injection layer, a charge generation layer, and the like in an organic light emitting device. In particular, the composition for an organic material layer may be used as a material for a light emitting layer of an organic light emitting device. Furthermore, when the composition for an organic material layer is used for an organic light emitting device, the driving voltage of the device may be lowered, the light efficiency of the device may be improved, and the lifetime characteristics of the device may be improved by the thermal stability of the compound.

In addition, it is possible to finely adjust an energy band gap by introducing various substituents into the structures of Chemical Formulae 1 and 2, and meanwhile, it is possible to improve characteristics at the interface between organic materials and diversify the use of material.

In an exemplary embodiment of the present specification, the composition for an organic material layer may include the first compound (Chemical Formula 1) and the second compound (Chemical Formula 2) at a weight ratio of 1:10 to 10:1.

In an exemplary embodiment of the present specification, the composition for an organic material layer may include the first compound (Chemical Formula 1) and the second compound (Chemical Formula 2) at a weight ratio of 1:8 to 8:1, 1:5 to 5:1, or 1:3 to 3:1.

In an exemplary embodiment of the present specification, the composition for an organic material layer may include the first compound (Chemical Formula 1) and the second compound (Chemical Formula 2) at a weight ratio of 1:2 to 2:1, or 1:1 to 1:2.

In an exemplary embodiment of the present specification, the composition for an organic material layer may include other hosts in addition to the first compound and the second compound.

In an exemplary embodiment of the present specification, the composition for an organic material layer may be a composition for a light emitting layer of an organic light emitting device.

In another exemplary embodiment of the present specification, provided is an organic light emitting device including: a first electrode; a second electrode; and an organic material layer having one or more layers provided between the first electrode and the second electrode, in which one or more layers of the organic material layer include the composition for an organic material layer of an organic light emitting device.

In an exemplary embodiment of the present specification, the organic material layer includes a light emitting layer, and the light emitting layer may include the composition for an organic material layer.

In an exemplary embodiment of the present specification, the organic material layer includes a light emitting layer, the light emitting layer includes the composition for an organic material layer, and the light emitting layer may further include an Ir complex compound or a Pt complex compound.

In an exemplary embodiment of the present specification, the organic material layer includes a light emitting layer, the light emitting layer includes the composition for an organic material layer, and the light emitting layer may further include Ir(mppy)₃.

In an exemplary embodiment of the present specification, the organic material layer includes a light emitting layer, the light emitting layer includes a host, and the host may include the composition for an organic material layer.

In an exemplary embodiment of the present specification, the organic material layer includes a light emitting layer, the light emitting layer includes a host and a dopant, the host includes the composition for an organic material layer, and the dopant may further include Ir(mppy)₃.

In an exemplary embodiment of the present specification, the organic material layer includes a light emitting layer, the light emitting layer includes a host, the host includes a green host, and the green host may include the composition for an organic material layer.

In an exemplary embodiment of the present specification, the organic material layer includes a light emitting layer, the light emitting layer includes a host, the host includes a red host, and the red host may include the composition for an organic material layer.

In an exemplary embodiment of the present specification, the organic material layer includes a light emitting layer, the light emitting layer includes a host, the host includes a blue host, and the blue host may include the composition for an organic material layer.

The organic material layer of the organic light emitting device of the present invention may be composed of a single-layered structure, but may be composed of a multi-layered structure in which two or more organic material layers are stacked. For example, the organic light emitting device of the present invention may have a structure including a hole injection layer, a hole transfer layer, a light emitting layer, an electron transfer layer, an electron injection layer, and the like as organic material layers. However, the structure of the organic light emitting device is not limited thereto, and may include a fewer number of organic material layers.

In an exemplary embodiment of the present specification, the first electrode may be a positive electrode, and the second electrode may be a negative electrode.

In another exemplary embodiment of the present specification, the first electrode may be a negative electrode, and the second electrode may be a positive electrode.

The organic light emitting device according to an exemplary embodiment of the present specification may be manufactured by typical manufacturing methods and materials of the organic light emitting device, except that the above-described composition for an organic material layer is used to form an organic material layer having one or more layers.

The composition for an organic material layer may be formed as an organic material layer by not only a vacuum deposition method, but also a solution application method when an organic light emitting device is manufactured. Here, the solution coating method means spin coating, dip coating, inkjet printing, screen printing, a spray method, roll coating, and the like, but is not limited thereto.

In an exemplary embodiment of the present specification, the organic light emitting device may be a blue organic light emitting device, and the composition for an organic material layer may be used as a material for the blue organic light emitting device. For example, the composition for an organic material layer may be included in a light emitting layer of a blue organic light emitting device.

In another exemplary embodiment of the present specification, the organic light emitting device may be a green organic light emitting device, and the composition for an organic material layer may be used as a material for the green organic light emitting device. For example, the composition for an organic material layer may be included in a light emitting layer of a green organic light emitting device.

In still another exemplary embodiment of the present specification, the organic light emitting device may be a red organic light emitting device, and the composition for an organic material layer may be used as a material for the red organic light emitting device. For example, the composition for an organic material layer may be included in a light emitting layer of a red organic light emitting device.

The organic light emitting device of the present invention may further include one or more layers selected from the group consisting of a light emitting layer, a hole injection layer, a hole transfer layer, an electron injection layer, an electron transfer layer, an electron blocking layer, and a hole blocking layer.

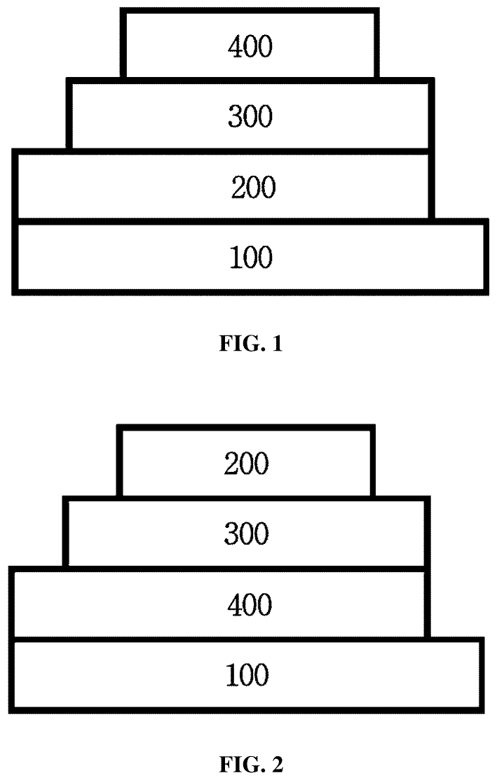

FIGS. 1 to 3 exemplify the stacking sequence of the electrodes and the organic material layer of the organic light emitting device according to an exemplary embodiment of the present specification. However, the scope of the present application is not intended to be limited by these drawings, and the structure of the organic light emitting device known in the art may also be applied to the present application.

According to FIG. 1, an organic light emitting device in which a positive electrode 200, an organic material layer 300, and a negative electrode 400 are sequentially stacked on a substrate 100 is illustrated. However, the organic light emitting device is not limited only to such a structure, and as illustrated in FIG. 2, an organic light emitting device in which a negative electrode, an organic material layer, and a positive electrode are sequentially stacked on a substrate may also be implemented.

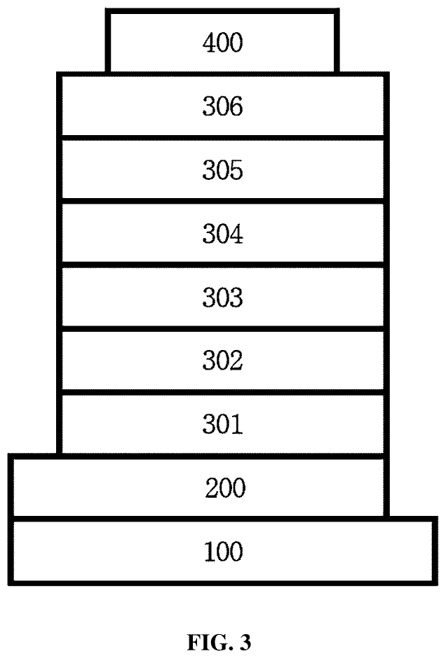

FIG. 3 exemplifies a case where an organic material layer is a multilayer. An organic light emitting device according to FIG. 3 includes a hole injection layer 301, a hole transfer layer 302, a light emitting layer 303, a hole blocking layer 304, an electron transfer layer 305, and an electron injection layer 306. However, the scope of the present application is not limited by the stacking structure as described above, and if necessary, the other layers except for the light emitting layer may be omitted, and another necessary functional layer may be further added.

An organic material layer including the heterocyclic compound of Chemical Formula 1 may additionally include other materials, if necessary.

In the organic light emitting device according to an exemplary embodiment of the present specification, materials other than the composition for an organic material layer will be exemplified below, but these materials are illustrative only and are not for limiting the scope of the present application, and may be replaced with materials publicly known in the art.

As a positive electrode material, materials having a relatively high work function may be used, and a transparent conductive oxide, a metal or a conductive polymer, and the like may be used. Specific examples of the positive electrode material include: a metal such as vanadium, chromium, copper, zinc, and gold, or an alloy thereof, a metal oxide such as zinc oxide, indium oxide, indium tin oxide (ITO), and indium zinc oxide (IZO); a combination of a metal and an oxide, such as ZnO:A1 or SnO₂:Sb; a conductive polymer such as poly(3-methylthiophene), poly[3,4-(ethylene-1,2-dioxy)thiophene](PEDOT), polypyrrole, and polyaniline; and the like, but are not limited thereto.

As a negative electrode material, materials having a relatively low work function may be used, and a metal, a metal oxide, or a conductive polymer, and the like may be used. Specific examples of the negative electrode material include: a metal such as magnesium, calcium, sodium, potassium, titanium, indium, yttrium, lithium, gadolinium, aluminum, silver, tin, and lead, or an alloy thereof; a multi-layer structured material, such as LiF/A1 or LiO₂/A1; and the like, but are not limited thereto.

As a hole injection material, a publicly-known hole injection material may also be used, and it is possible to use, for example, a phthalocyanine compound such as copper phthalocyanine disclosed in U.S. Pat. No. 4,356,429 or starburst-type amine derivatives described in the document [Advanced Material, 6, p. 677 (1994)], for example, tris(4-carbazoyl-9-ylphenyl)amine (TCTA), 4,4′,4″-tri[phenyl(m-tolyl)amino]triphenylamine (m-MTDATA), 1,3,5-tris[4-(3-methylphenylphenylamino)phenyl]benzene (m-MTDAPB), polyaniline/dodecylbenzenesulfonic acid or poly(3,4-ethylenedioxythiophene)/poly(4-styrenesulfonate), which is a soluble conductive polymer, polyaniline/camphor sulfonic acid or polyaniline/poly(4-styrenesulfonate), and the like.

As a hole transfer material, a pyrazoline derivative, an arylamine-based derivative, a stilbene derivative, a triphenyldiamine derivative, and the like may be used, and a low-molecular weight or polymer material may also be used.

As an electron transfer material, it is possible to use an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, a metal complex of 8-hydroxyquinoline and a derivative thereof, and the like, and a low-molecular weight material and a polymer material may also be used.

As an electron injection material, for example, LiF is representatively used in the art, but the present application is not limited thereto.

As the light emitting material, a red, green, or blue light emitting material may be used, and if necessary, two or more light emitting materials may be mixed and used. In this case, two or more light emitting materials are deposited and used as an individual supply source, or pre-mixed to be deposited and used as one supply source. Further, a fluorescent material may also be used as the light emitting material, but may also be used as a phosphorescent material. As the light emitting material, it is also possible to use alone a material which emits light by combining holes and electrons each injected from a positive electrode and a negative electrode, but materials in which a host material and a dopant material are involved in light emission together may also be used.

When hosts of the light emitting material are mixed and used, the same series of hosts may also be mixed and used, and different series of hosts may also be mixed and used. For example, any two or more materials from N-type host materials or P-type host materials may be selected and used as a host material for a light emitting layer.

In an exemplary embodiment of the present specification, the dopant material may be Ir(mppy)₃. Ir(mppy)₃ is a compound in which a methyl group is added to a commonly used dopant material, Ir(ppy)₃, and accordingly, the distance between dopants is increased, reducing the possibility of self-quenching between dopants, and as a result, there is an effect of increasing the lifetime.

In an exemplary embodiment of the present specification, the dopant material may be doped at 10 wt % of the host material. In general, compared to the doping of the dopant material at 7 wt %, the increase in the concentration of the dopant material increases the hole trapping characteristics, so that there is an effect in which the second compound having fast hole characteristics has a good lifetime.

The organic light emitting device according to an exemplary embodiment of the present specification may be a top emission type, a bottom emission type, or a dual emission type according to the material to be used.

The composition for an organic material layer according to an exemplary embodiment of the present specification may act even in organic electronic devices including organic solar cells, organic photoconductors, organic transistors, and the like, based on the principle similar to those applied to organic light emitting devices.

Still another exemplary embodiment of the present specification provides a method for manufacturing an organic light emitting device, the method including: preparing a substrate; forming a first electrode on the substrate; forming an organic material layer having one or more layers on the first electrode; and forming a second electrode on the organic material layer, in which the forming of the organic material layer includes forming the organic material layer having one or more layers by using the above-described composition for an organic material layer.

In an exemplary embodiment of the present specification, the forming of the organic material layer may include pre-mixing the composition for an organic material layer of an organic light emitting device to deposit the pre-mixed composition onto a single supply source.

The pre-mixed means that the materials are first mixed, put into one container, and then mixed together before the composition for an organic material layer is deposited on the organic material layer. Specifically, the first compound and the second compound may be put into one container, mixed and then deposited on the organic material layer. Since one deposition source is used instead of using two or more deposition sources during the pre-mixing, there is an advantage in that the process is more simplified.

When the composition for an organic material layer is pre-mixed, the deposition conditions, such as the deposition rate, may be significantly affected by the inherent thermal characteristics of the material during the deposition of the pre-mixed material, so that the inherent thermal characteristics of each pre-mixed material need to be confirmed. When the thermal properties of the materials are not similar, repeatability and reproducibility cannot be maintained, and a uniform OLED device cannot be manufactured.

Specifically, the composition for an organic material layer of the present invention includes an N-host having a large molecular weight, and thus has a high glass transition temperature. Therefore, the material has excellent stability even at high deposition temperatures.

In order to overcome this problem, the electrical characteristics of the material may be controlled by utilizing the appropriate combination of the basic structure of each material and the substituent, and simultaneously, the thermal characteristics may also be adjusted according to the form of the molecular structure. The thermal characteristics of each material may be adjusted to secure the diversity of various pre-mixing deposition processes between a host and a host. Through this, it is possible to secure the diversity of the pre-mixing deposition process utilizing not only two compounds as hosts but also 3 or more types of host materials.

Hereinafter, the present specification will be described in more detail through Examples, but these Examples are provided only for exemplifying the present application, and are not intended to limit the scope of the present application.

### PREPARATION EXAMPLES

### <Preparation Example 1> Preparation of Compound 1-1

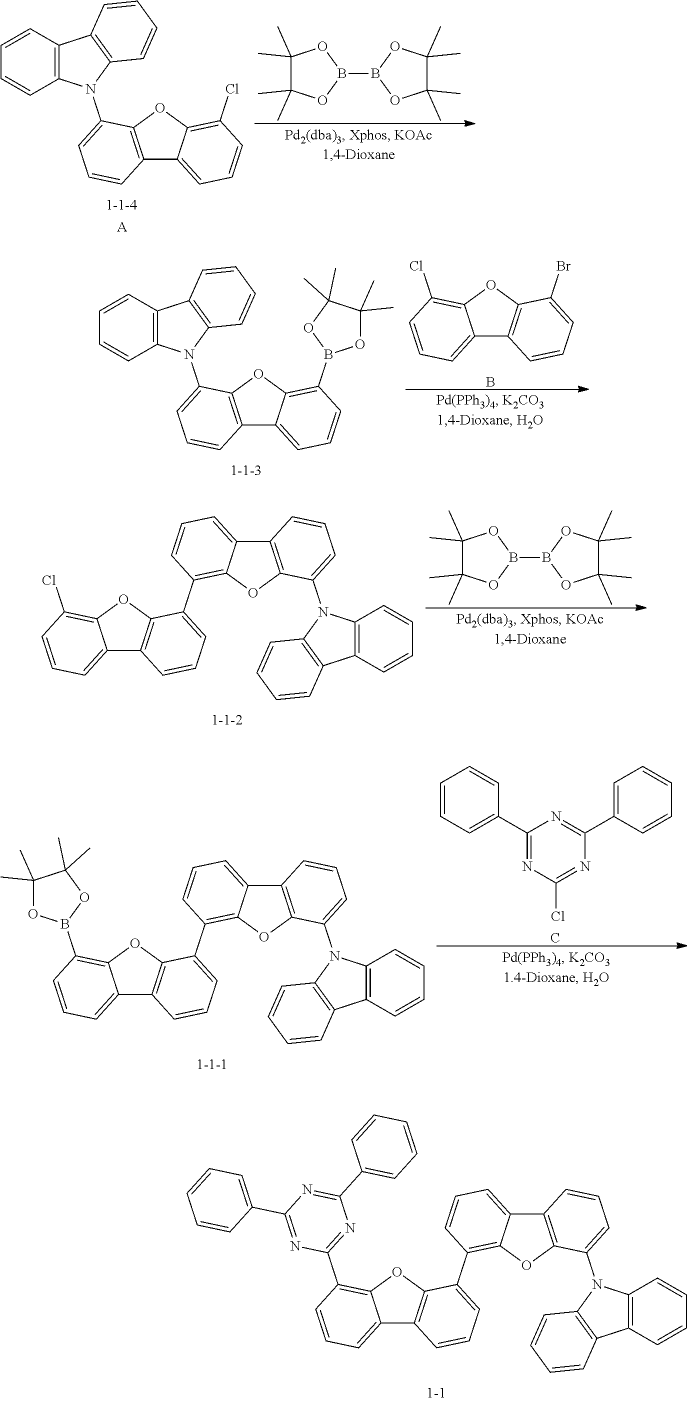

### 1) Preparation of Compound 1-1-3

After 10 g (25.8 mmol) of Compound A (9-(6-chlorodibenzo[b,d]furan-4-yl)-9H-carbazole), 9.93 g (38.7 mmol) of 4,4,4′,4′,5,5,5′,5′-octamethyl-2,2′-bi(1,3,2-dioxaborolane), 1.18 g (1.29 mmol) of Pd₂(dba)₃, 1.23 g (2.58 mmol) of Xphos, and 6.53 g (51.6 mmol) of KOAc were dissolved in 100 mL of 1,4-dioxane, the resulting solution was stirred under reflux for 6 hours. After the reaction was completed, distilled water and dichloromethane (DCM) were added thereto at room temperature, extraction was performed, an organic layer was dried over MgSO₄, and then the solvent was removed by a rotary evaporator. The reaction product was purified with column chromatography (DCM:hexane=1:2) to obtain 8.33 g (yield 70.24%) of Target Compound 1-1-3.

### 2) Preparation of Compound 1-1-2

After 8.33 g (18.13 mmol) of Compound 1-1-3, 5.10 g (18.13 mmol) of Compound B (4-bromo-6-chlorodibenzo[b,d]furan), 1.01 g (0.91 mmol) of Pd(PPh₃)₄, and 5.01 g (36.26 mmol) of K₂CO₃ were dissolved in 100 mL/30 mL of 1,4-dioxane/H₂O, the resulting solution was refluxed for 6 hours. After the reaction was completed, distilled water and DCM were added thereto at room temperature, extraction was performed, the organic layer was dried over MgSO₄, and then the solvent was removed using a rotary evaporator. The reaction product was purified by column chromatography (DCM:Hex=1:2) and methanol was used to obtain 9.18 g (92.98%) of Target Compound 1-1-2.

### 3) Preparation of Compound 1-1-1

After 9.18 g (17.19 mmol) of Compound 1-1-2, 6.55 g (25.79 mmol) of 4,4,4′,4′,5,5,5′,5′-octamethyl-2,2′-bi(1,3,2-dioxaborolane), 0.79 g (0.86 mmol) of Pd₂(dba)₃, 0.82 g (1.72 mmol) of Xphos, and 3.37 g (34.38 mmol) of KOAc were dissolved in 100 mL of 1,4-dioxane, the resulting solution was stirred under reflux for 6 hours. After the reaction was completed, distilled water and DCM were added thereto at room temperature, extraction was performed, the organic layer was dried over MgSO₄, and then the solvent was removed using a rotary evaporator. The reaction product was purified with column chromatography (DCM:Hex=1:2) to obtain 9.08 g (84.45%) of Target Compound 1-1-1.

### 4) Preparation of Compound 1-1

After 9.08 g (14.52 mmol) of Compound 1-1-1, 4.66 g (17.42 mmol) of Compound C (2-chloro-4,6-diphenyl-1,3,5-triazine), 0.84 g (0.73 mmol) of Pd(PPh₃)₄, and 4.01 g (29.04 mmol) of K₂CO₃ were dissolved in 100 mL/30 mL of 1,4-dioxane/H₂O, the resulting solution was refluxed for 6 hours. After the reaction was completed, methanol was added to precipitate a solid, and the solid was then filtered. The solid was purified by column chromatography (DCM:Hex=1:1) and methanol was used to obtain 10.6 g (99.5%) of Target Compound 1-1.

The target compound was synthesized by preparation in the same manner as in the preparation of Preparation Example 1, except that Intermediates A, B, and C in the following Table 1 were used instead of Compounds A, B, and C in Preparation Example 1.

TABLE 1

| Compound | Intermediate A | Intermediate B | Intermediate C | Target Compound |
|---|---|---|---|---|
| 1-1 | 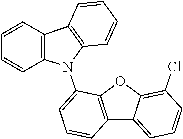 [SMILES: Clc1cccc2c1oc1c(-n3c4ccccc4c4ccccc43)cccc12] | 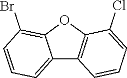 [SMILES: Clc1cccc2c1oc1c(Br)cccc12] | 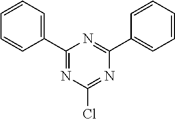 [SMILES: Clc1nc(-c2ccccc2)nc(-c2ccccc2)n1] | 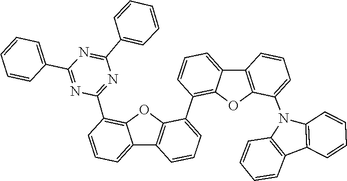 [SMILES: c1ccc(-c2nc(-c3ccccc3)nc(-c3cccc4c3oc3c(-c5cccc6c5oc5c(-n7c8ccccc8c8ccccc87)cccc56)cccc34)n2)cc1] |
| 1-18 | 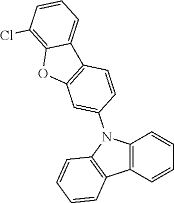 [SMILES: Clc1cccc2c1oc1cc(-n3c4ccccc4c4ccccc43)ccc12] | 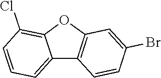 [SMILES: Clc1cccc2c1oc1cc(Br)ccc12] | 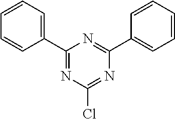 [SMILES: Clc1nc(-c2ccccc2)nc(-c2ccccc2)n1] | 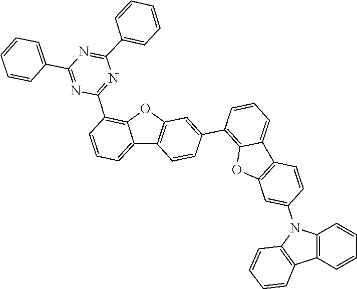 [SMILES: c1ccc(-c2nc(-c3ccccc3)nc(-c3cccc4c3oc3cc(-c5cccc6c5oc5cc(-n7c8ccccc8c8ccccc87)ccc56)ccc34)n2)cc1] |
| 1-28 | 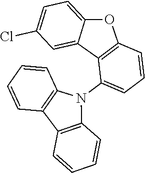 [SMILES: Clc1ccc2oc3cccc(-n4c5ccccc5c5ccccc54)c3c2c1] | 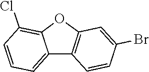 [SMILES: Clc1cccc2c1oc1cc(Br)ccc12] | 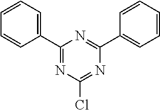 [SMILES: Clc1nc(-c2ccccc2)nc(-c2ccccc2)n1] | 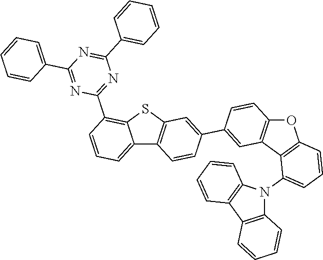 [SMILES: c1ccc(-c2nc(-c3ccccc3)nc(-c3cccc4c3sc3cc(-c5ccc6oc7cccc(-n8c9ccccc9c9ccccc98)c7c6c5)ccc34)n2)cc1] |
| 1-38 | 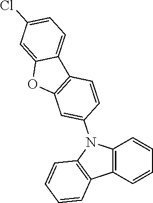 [SMILES: Clc1ccc2c(c1)oc1cc(-n3c4ccccc4c4ccccc43)ccc12] | 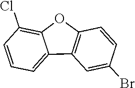 [SMILES: Clc1cccc2c1oc1ccc(Br)cc12] | 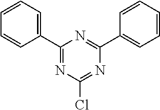 [SMILES: Clc1nc(-c2ccccc2)nc(-c2ccccc2)n1] | 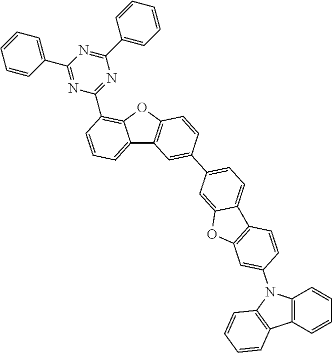 [SMILES: c1ccc(-c2nc(-c3ccccc3)nc(-c3cccc4c3oc3ccc(-c5ccc6c(c5)oc5cc(-n7c8ccccc8c8ccccc87)ccc56)cc34)n2)cc1] |
| 1-44 | 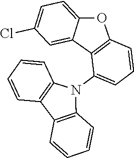 [SMILES: Clc1ccc2oc3cccc(-n4c5ccccc5c5ccccc54)c3c2c1] | 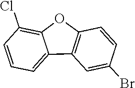 [SMILES: Clc1cccc2c1oc1ccc(Br)cc12] | 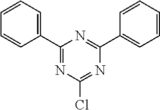 [SMILES: Clc1nc(-c2ccccc2)nc(-c2ccccc2)n1] | 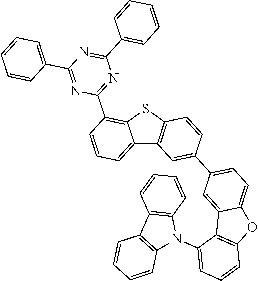 [SMILES: c1ccc(-c2nc(-c3ccccc3)nc(-c3cccc4c3sc3ccc(-c5ccc6oc7cccc(-n8c9ccccc9c9ccccc98)c7c6c5)cc34)n2)cc1] |
| 1-56 | 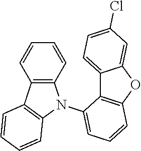 [SMILES: Clc1ccc2c(c1)oc1cccc(-n3c4ccccc4c4ccccc43)c12] | 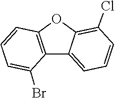 [SMILES: Clc1cccc2c1oc1cccc(Br)c12] | 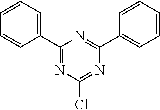 [SMILES: Clc1nc(-c2ccccc2)nc(-c2ccccc2)n1] | 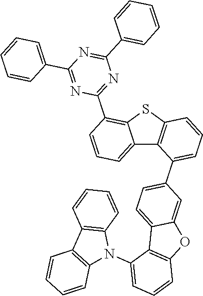 [SMILES: c1ccc(-c2nc(-c3ccccc3)nc(-c3cccc4c3sc3cccc(-c5ccc6c(c5)oc5cccc(-n7c8ccccc8c8ccccc87)c56)c34)n2)cc1] |
| 1-63 | 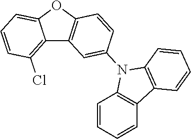 [SMILES: Clc1cccc2oc3ccc(-n4c5ccccc5c5ccccc54)cc3c12] | 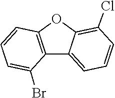 [SMILES: Clc1cccc2c1oc1cccc(Br)c12] | 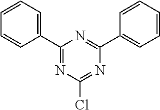 [SMILES: Clc1nc(-c2ccccc2)nc(-c2ccccc2)n1] | 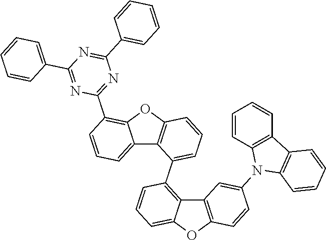 [SMILES: c1ccc(-c2nc(-c3ccccc3)nc(-c3cccc4c3oc3cccc(-c5cccc6oc7ccc(-n8c9ccccc9c9ccccc98)cc7c56)c34)n2)cc1] |
| 1-79 | 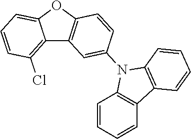 [SMILES: Clc1cccc2oc3ccc(-n4c5ccccc5c5ccccc54)cc3c12] | 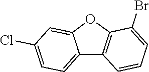 [SMILES: Clc1ccc2c(c1)oc1c(Br)cccc12] | 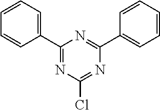 [SMILES: Clc1nc(-c2ccccc2)nc(-c2ccccc2)n1] | 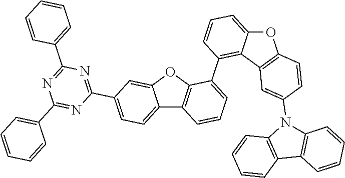 [SMILES: c1ccc(-c2nc(-c3ccccc3)nc(-c3ccc4c(c3)oc3c(-c5cccc6oc7ccc(-n8c9ccccc9c9ccccc98)cc7c56)cccc34)n2)cc1] |
| 1-83 | 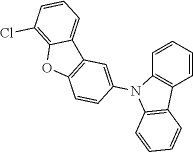 [SMILES: Clc1cccc2c1oc1ccc(-n3c4ccccc4c4ccccc43)cc12] | 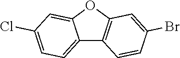 [SMILES: Clc1ccc2c(c1)oc1cc(Br)ccc12] | 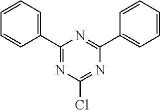 [SMILES: Clc1nc(-c2ccccc2)nc(-c2ccccc2)n1] | 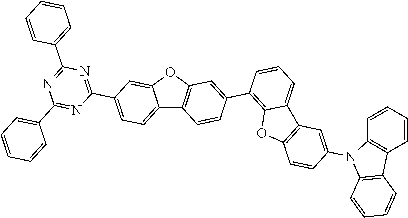 [SMILES: c1ccc(-c2nc(-c3ccccc3)nc(-c3ccc4c(c3)oc3cc(-c5cccc6c5oc5ccc(-n7c8ccccc8c8ccccc87)cc56)ccc34)n2)cc1] |
| 1-97 | 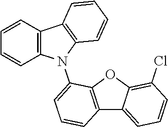 [SMILES: Clc1cccc2c1oc1c(-n3c4ccccc4c4ccccc43)cccc12] | 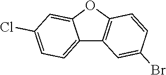 [SMILES: Clc1ccc2c(c1)oc1ccc(Br)cc12] | 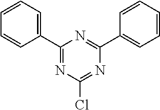 [SMILES: Clc1nc(-c2ccccc2)nc(-c2ccccc2)n1] | 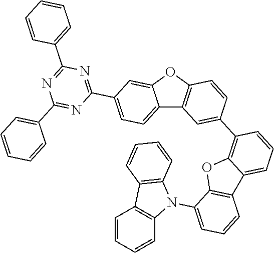 [SMILES: c1ccc(-c2nc(-c3ccccc3)nc(-c3ccc4c(c3)oc3ccc(-c5cccc6c5oc5c(-n7c8ccccc8c8ccccc87)cccc56)cc34)n2)cc1] |
| 1-105 | 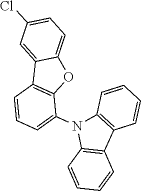 [SMILES: Clc1ccc2oc3c(-n4c5ccccc5c5ccccc54)cccc3c2c1] | 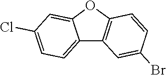 [SMILES: Clc1ccc2c(c1)oc1ccc(Br)cc12] | 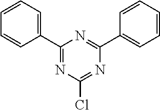 [SMILES: Clc1nc(-c2ccccc2)nc(-c2ccccc2)n1] | 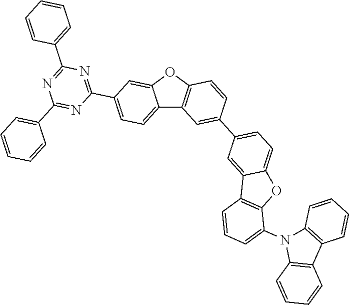 [SMILES: c1ccc(-c2nc(-c3ccccc3)nc(-c3ccc4c(c3)oc3ccc(-c5ccc6oc7c(-n8c9ccccc9c9ccccc98)cccc7c6c5)cc34)n2)cc1] |
| 1-117 | 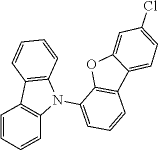 [SMILES: Clc1ccc2c(c1)oc1c(-n3c4ccccc4c4ccccc43)cccc12] | 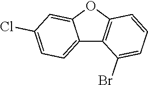 [SMILES: Clc1ccc2c(c1)oc1cccc(Br)c12] | 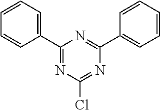 [SMILES: Clc1nc(-c2ccccc2)nc(-c2ccccc2)n1] | 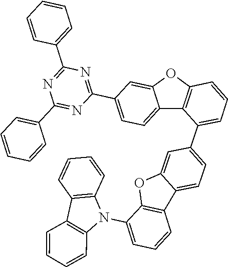 [SMILES: c1ccc(-c2nc(-c3ccccc3)nc(-c3ccc4c(c3)oc3cccc(-c5ccc6c(c5)oc5c(-n7c8ccccc8c8ccccc87)cccc56)c34)n2)cc1] |
| 1-123 | 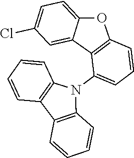 [SMILES: Clc1ccc2oc3cccc(-n4c5ccccc5c5ccccc54)c3c2c1] | 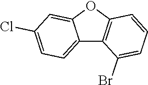 [SMILES: Clc1ccc2c(c1)oc1cccc(Br)c12] | 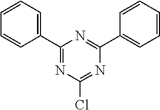 [SMILES: Clc1nc(-c2ccccc2)nc(-c2ccccc2)n1] | 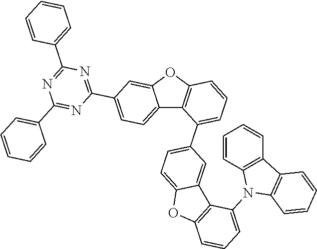 [SMILES: c1ccc(-c2nc(-c3ccccc3)nc(-c3ccc4c(c3)oc3cccc(-c5ccc6oc7cccc(-n8c9ccccc9c9ccccc98)c7c6c5)c34)n2)cc1] |
| 1-134 | 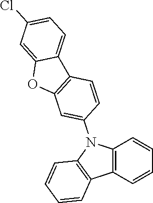 [SMILES: Clc1ccc2c(c1)oc1cc(-n3c4ccccc4c4ccccc43)ccc12] | 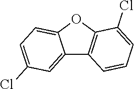 [SMILES: Clc1ccc2oc3c(Cl)cccc3c2c1] | 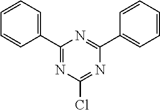 [SMILES: Clc1nc(-c2ccccc2)nc(-c2ccccc2)n1] | 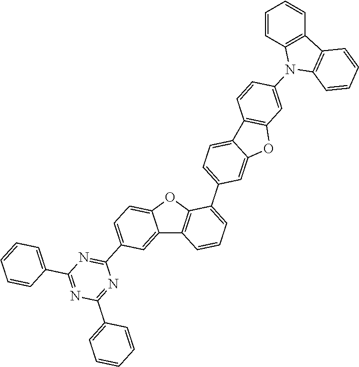 [SMILES: c1ccc(-c2nc(-c3ccccc3)nc(-c3ccc4oc5c(-c6ccc7c(c6)oc6cc(-n8c9ccccc9c9ccccc98)ccc67)cccc5c4c3)n2)cc1] |
| 1-144 | 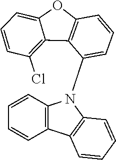 [SMILES: Clc1cccc2oc3cccc(-n4c5ccccc5c5ccccc54)c3c12] | 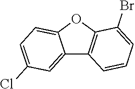 [SMILES: Clc1ccc2oc3c(Br)cccc3c2c1] | 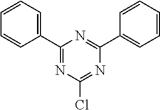 [SMILES: Clc1nc(-c2ccccc2)nc(-c2ccccc2)n1] | 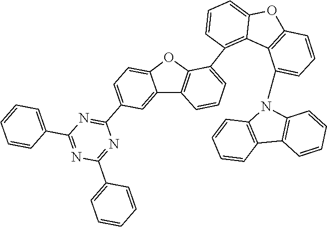 [SMILES: c1ccc(-c2nc(-c3ccccc3)nc(-c3ccc4oc5c(-c6cccc7oc8cccc(-n9c%10ccccc%10c%10ccccc%109)c8c67)cccc5c4c3)n2)cc1] |
| 1-157 | 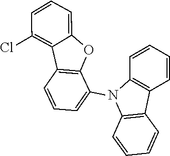 [SMILES: Clc1cccc2oc3c(-n4c5ccccc5c5ccccc54)cccc3c12] | 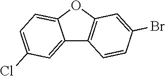 [SMILES: Clc1ccc2oc3cc(Br)ccc3c2c1] | 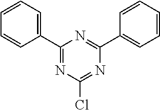 [SMILES: Clc1nc(-c2ccccc2)nc(-c2ccccc2)n1] | 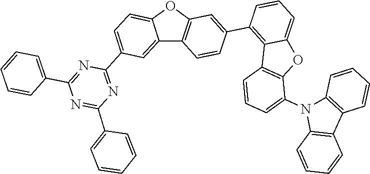 [SMILES: c1ccc(-c2nc(-c3ccccc3)nc(-c3ccc4oc5cc(-c6cccc7oc8c(-n9c%10ccccc%10c%10ccccc%109)cccc8c67)ccc5c4c3)n2)cc1] |
| 1-163 | 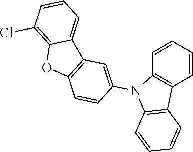 [SMILES: Clc1cccc2c1oc1ccc(-n3c4ccccc4c4ccccc43)cc12] | 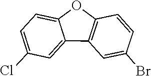 [SMILES: Clc1ccc2oc3ccc(Br)cc3c2c1] | 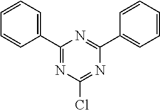 [SMILES: Clc1nc(-c2ccccc2)nc(-c2ccccc2)n1] | 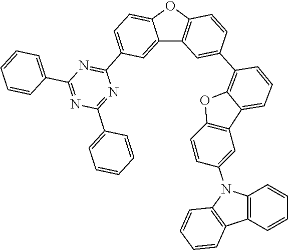 [SMILES: c1ccc(-c2nc(-c3ccccc3)nc(-c3ccc4oc5ccc(-c6cccc7c6oc6ccc(-n8c9ccccc9c9ccccc98)cc67)cc5c4c3)n2)cc1] |
| 1-178 | 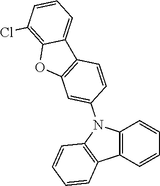 [SMILES: Clc1cccc2c1oc1cc(-n3c4ccccc4c4ccccc43)ccc12] | 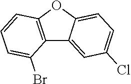 [SMILES: Clc1ccc2oc3cccc(Br)c3c2c1] | 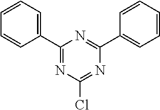 [SMILES: Clc1nc(-c2ccccc2)nc(-c2ccccc2)n1] | 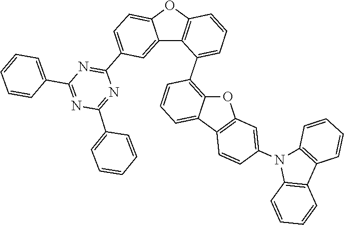 [SMILES: c1ccc(-c2nc(-c3ccccc3)nc(-c3ccc4oc5cccc(-c6cccc7c6oc6cc(-n8c9ccccc9c9ccccc98)ccc67)c5c4c3)n2)cc1] |
| 1-181 | 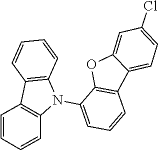 [SMILES: Clc1ccc2c(c1)oc1c(-n3c4ccccc4c4ccccc43)cccc12] | 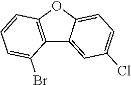 [SMILES: Clc1ccc2oc3cccc(Br)c3c2c1] | 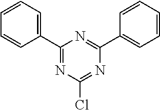 [SMILES: Clc1nc(-c2ccccc2)nc(-c2ccccc2)n1] | 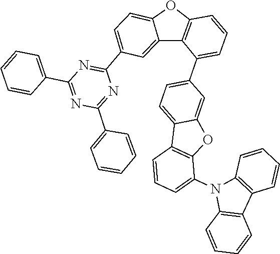 [SMILES: c1ccc(-c2nc(-c3ccccc3)nc(-c3ccc4oc5cccc(-c6ccc7c(c6)oc6c(-n8c9ccccc9c9ccccc98)cccc67)c5c4c3)n2)cc1] |
| 1-197 | 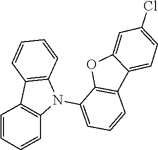 [SMILES: Clc1ccc2c(c1)oc1c(-n3c4ccccc4c4ccccc43)cccc12] | 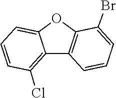 [SMILES: Clc1cccc2oc3c(Br)cccc3c12] | 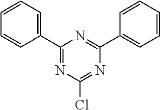 [SMILES: Clc1nc(-c2ccccc2)nc(-c2ccccc2)n1] | 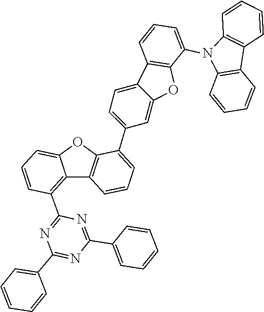 [SMILES: c1ccc(-c2nc(-c3ccccc3)nc(-c3cccc4oc5c(-c6ccc7c(c6)oc6c(-n8c9ccccc9c9ccccc98)cccc67)cccc5c34)n2)cc1] |
| 1-206 | 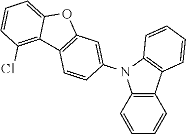 [SMILES: Clc1cccc2oc3cc(-n4c5ccccc5c5ccccc54)ccc3c12] | 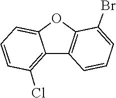 [SMILES: Clc1cccc2oc3c(Br)cccc3c12] | 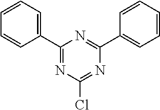 [SMILES: Clc1nc(-c2ccccc2)nc(-c2ccccc2)n1] | 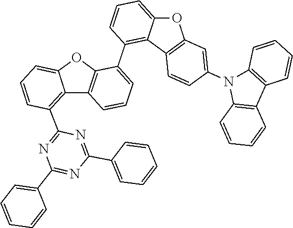 [SMILES: c1ccc(-c2nc(-c3ccccc3)nc(-c3cccc4oc5c(-c6cccc7oc8cc(-n9c%10ccccc%10c%10ccccc%109)ccc8c67)cccc5c34)n2)cc1] |
| 1-216 | 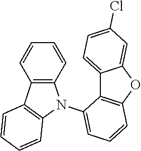 [SMILES: Clc1ccc2c(c1)oc1cccc(-n3c4ccccc4c4ccccc43)c12] | 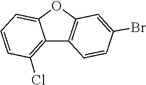 [SMILES: Clc1cccc2oc3cc(Br)ccc3c12] | 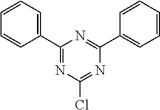 [SMILES: Clc1nc(-c2ccccc2)nc(-c2ccccc2)n1] | 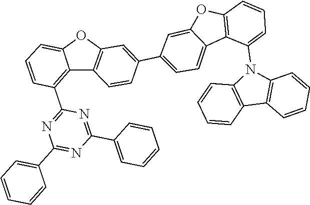 [SMILES: c1ccc(-c2nc(-c3ccccc3)nc(-c3cccc4oc5cc(-c6ccc7c(c6)oc6cccc(-n8c9ccccc9c9ccccc98)c67)ccc5c34)n2)cc1] |
| 1-232 | 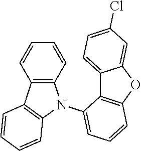 [SMILES: Clc1ccc2c(c1)oc1cccc(-n3c4ccccc4c4ccccc43)c12] | 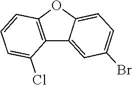 [SMILES: Clc1cccc2oc3ccc(Br)cc3c12] | 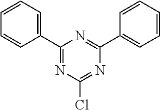 [SMILES: Clc1nc(-c2ccccc2)nc(-c2ccccc2)n1] | 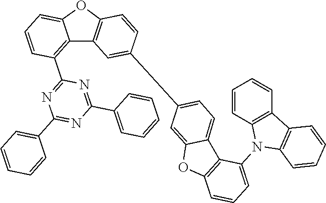 [SMILES: c1ccc(-c2nc(-c3ccccc3)nc(-c3cccc4oc5ccc(-c6ccc7c(c6)oc6cccc(-n8c9ccccc9c9ccccc98)c67)cc5c34)n2)cc1] |
| 1-238 | 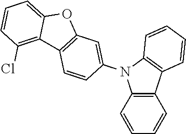 [SMILES: Clc1cccc2oc3cc(-n4c5ccccc5c5ccccc54)ccc3c12] | 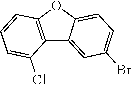 [SMILES: Clc1cccc2oc3ccc(Br)cc3c12] | 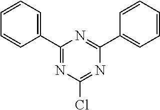 [SMILES: Clc1nc(-c2ccccc2)nc(-c2ccccc2)n1] | 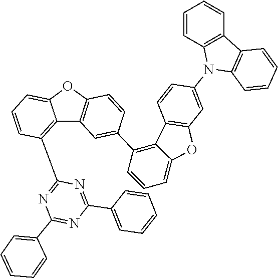 [SMILES: c1ccc(-c2nc(-c3ccccc3)nc(-c3cccc4oc5ccc(-c6cccc7oc8cc(-n9c%10ccccc%10c%10ccccc%109)ccc8c67)cc5c34)n2)cc1] |
| 1-249 | 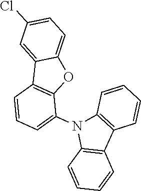 [SMILES: Clc1ccc2oc3c(-n4c5ccccc5c5ccccc54)cccc3c2c1] | 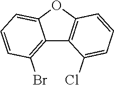 [SMILES: Clc1cccc2oc3cccc(Br)c3c12] | 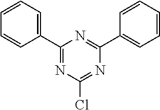 [SMILES: Clc1nc(-c2ccccc2)nc(-c2ccccc2)n1] | 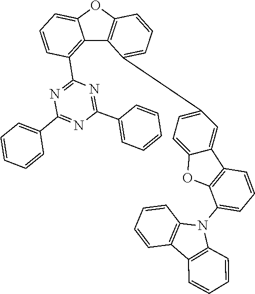 [SMILES: c1ccc(-c2nc(-c3ccccc3)nc(-c3cccc4oc5cccc(-c6ccc7oc8c(-n9c%10ccccc%10c%10ccccc%109)cccc8c7c6)c5c34)n2)cc1] |
| 1-255 | 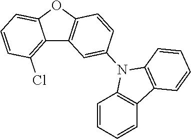 [SMILES: Clc1cccc2oc3ccc(-n4c5ccccc5c5ccccc54)cc3c12] | 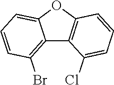 [SMILES: Clc1cccc2oc3cccc(Br)c3c12] | 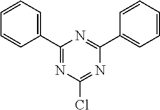 [SMILES: Clc1nc(-c2ccccc2)nc(-c2ccccc2)n1] | 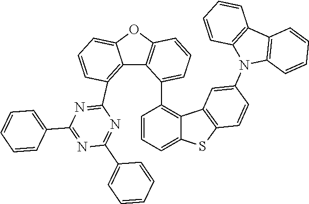 [SMILES: c1ccc(-c2nc(-c3ccccc3)nc(-c3cccc4oc5cccc(-c6cccc7sc8ccc(-n9c%10ccccc%10c%10ccccc%109)cc8c67)c5c34)n2)cc1] |
| 1-260 | 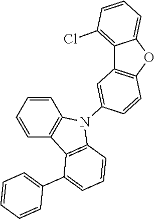 [SMILES: Clc1cccc2oc3ccc(-n4c5ccccc5c5c(-c6ccccc6)cccc54)cc3c12] | 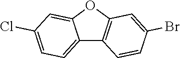 [SMILES: Clc1ccc2c(c1)oc1cc(Br)ccc12] | 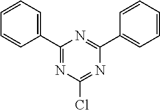 [SMILES: Clc1nc(-c2ccccc2)nc(-c2ccccc2)n1] | 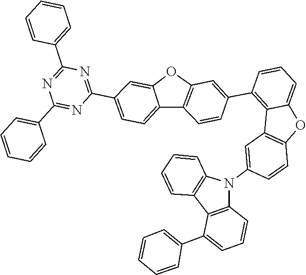 [SMILES: c1ccc(-c2nc(-c3ccccc3)nc(-c3ccc4c(c3)oc3cc(-c5cccc6oc7ccc(-n8c9ccccc9c9c(-c%10ccccc%10)cccc98)cc7c56)ccc34)n2)cc1] |
| 1-264 | 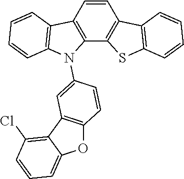 [SMILES: Clc1cccc2oc3ccc(-n4c5ccccc5c5ccc6c7ccccc7sc6c54)cc3c12] | 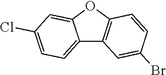 [SMILES: Clc1ccc2c(c1)oc1ccc(Br)cc12] | 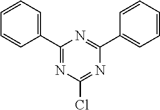 [SMILES: Clc1nc(-c2ccccc2)nc(-c2ccccc2)n1] | 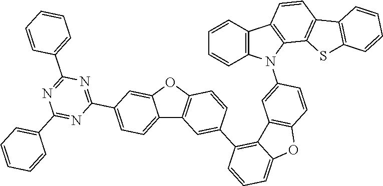 [SMILES: c1ccc(-c2nc(-c3ccccc3)nc(-c3ccc4c(c3)oc3ccc(-c5cccc6oc7ccc(-n8c9ccccc9c9ccc%10c%11ccccc%11sc%10c98)cc7c56)cc34)n2)cc1] |
| 1-272 | 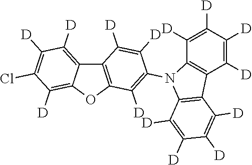 [SMILES: [2H]c1c(Cl)c([2H])c2oc3c([2H])c(-n4c5c([2H])c([2H])c([2H])c([2H])c5c5c([2H])c([2H])c([2H])c([2H])c54)c([2H])c([2H])c3c2c1[2H]] | 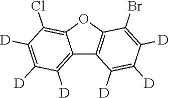 [SMILES: [2H]c1c([2H])c([2H])c2c(oc3c(Br)c([2H])c([2H])c([2H])c32)c1Cl] | 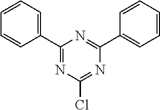 [SMILES: Clc1nc(-c2ccccc2)nc(-c2ccccc2)n1] | 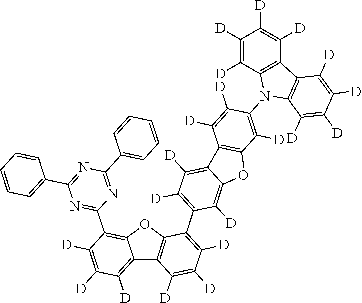 [SMILES: [2H]c1c([2H])c([2H])c2c(oc3c(-c4c([2H])c([2H])c5c(oc6c([2H])c(-n7c8c([2H])c([2H])c([2H])c([2H])c8c8c([2H])c([2H])c([2H])c([2H])c87)c([2H])c([2H])c65)c4[2H])c([2H])c([2H])c([2H])c32)c1-c1nc(-c2ccccc2)nc(-c2ccccc2)n1] |
| 1-273 | 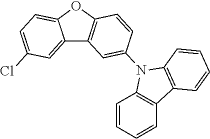 [SMILES: Clc1ccc2oc3ccc(-n4c5ccccc5c5ccccc54)cc3c2c1] | 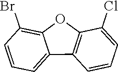 [SMILES: Clc1cccc2c1oc1c(Br)cccc12] | 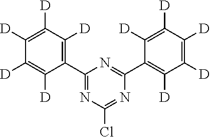 [SMILES: [2H]c1c([2H])c([2H])c(-c2nc(Cl)nc(-c3c([2H])c([2H])c([2H])c([2H])c3[2H])n2)c([2H])c1[2H]] | 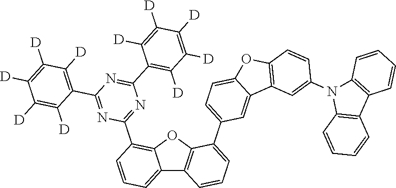 [SMILES: [2H]c1c([2H])c([2H])c(-c2nc(-c3c([2H])c([2H])c([2H])c([2H])c3[2H])nc(-c3cccc4c3oc3c(-c5ccc6oc7ccc(-n8c9ccccc9c9ccccc98)cc7c6c5)cccc34)n2)c([2H])c1[2H]] |
| 1-277 | 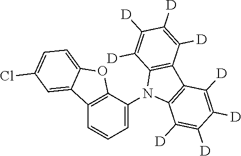 [SMILES: [2H]c1c([2H])c([2H])c2c(c1[2H])c1c([2H])c([2H])c([2H])c([2H])c1n2-c1cccc2c1oc1ccc(Cl)cc12] | 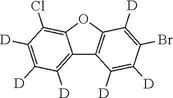 [SMILES: [2H]c1c([2H])c([2H])c2c(oc3c([2H])c(Br)c([2H])c([2H])c32)c1Cl] | 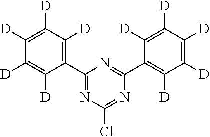 [SMILES: [2H]c1c([2H])c([2H])c(-c2nc(Cl)nc(-c3c([2H])c([2H])c([2H])c([2H])c3[2H])n2)c([2H])c1[2H]] | 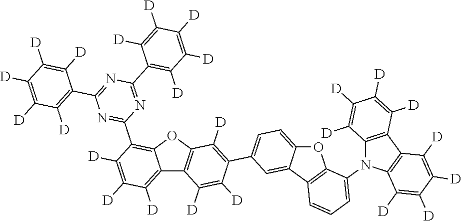 [SMILES: [2H]c1c([2H])c([2H])c(-c2nc(-c3c([2H])c([2H])c([2H])c([2H])c3[2H])nc(-c3c([2H])c([2H])c([2H])c4c3oc3c([2H])c(-c5ccc6oc7c(-n8c9c([2H])c([2H])c([2H])c([2H])c9c9c([2H])c([2H])c([2H])c([2H])c98)cccc7c6c5)c([2H])c([2H])c34)n2)c([2H])c1[2H]] |
| 1-279 | 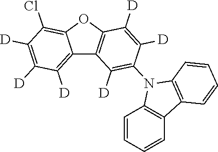 [SMILES: [2H]c1c(-n2c3ccccc3c3ccccc32)c([2H])c2c(oc3c(Cl)c([2H])c([2H])c([2H])c32)c1[2H]] | 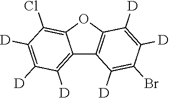 [SMILES: [2H]c1c(Br)c([2H])c2c(oc3c(Cl)c([2H])c([2H])c([2H])c32)c1[2H]] | 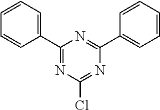 [SMILES: Clc1nc(-c2ccccc2)nc(-c2ccccc2)n1] | 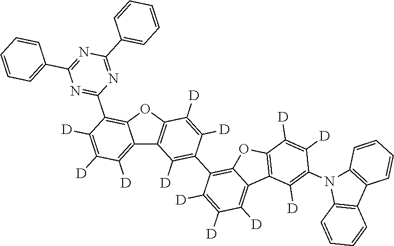 [SMILES: [2H]c1c(-c2c([2H])c([2H])c([2H])c3c2oc2c([2H])c([2H])c(-n4c5ccccc5c5ccccc54)c([2H])c23)c([2H])c2c(oc3c(-c4nc(-c5ccccc5)nc(-c5ccccc5)n4)c([2H])c([2H])c([2H])c32)c1[2H]] |
| 1-283 | 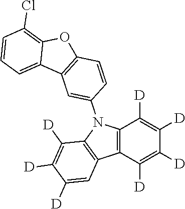 [SMILES: [2H]c1cc2c3c([2H])c([2H])c([2H])c([2H])c3n(-c3ccc4oc5c(Cl)cccc5c4c3)c2c([2H])c1[2H]] | 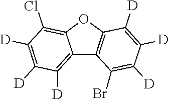 [SMILES: [2H]c1c([2H])c(Br)c2c(oc3c(Cl)c([2H])c([2H])c([2H])c32)c1[2H]] | 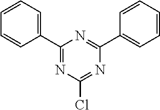 [SMILES: Clc1nc(-c2ccccc2)nc(-c2ccccc2)n1] | 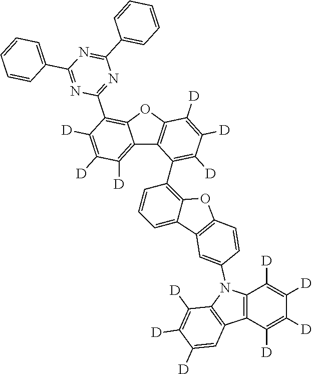 [SMILES: [2H]c1cc2c3c([2H])c([2H])c([2H])c([2H])c3n(-c3ccc4oc5c(-c6c([2H])c([2H])c([2H])c7oc8c(-c9nc(-c%10ccccc%10)nc(-c%10ccccc%10)n9)c([2H])c([2H])c([2H])c8c67)cccc5c4c3)c2c([2H])c1[2H]] |
| 1-292 | 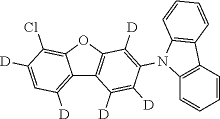 [SMILES: [2H]c1cc([2H])c2c(oc3c([2H])c(-n4c5ccccc5c5ccccc54)c([2H])c([2H])c32)c1Cl] | 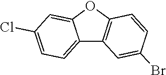 [SMILES: Clc1ccc2c(c1)oc1ccc(Br)cc12] | 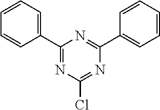 [SMILES: Clc1nc(-c2ccccc2)nc(-c2ccccc2)n1] | 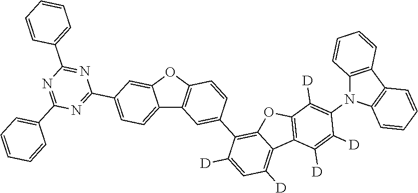 [SMILES: [2H]c1cc([2H])c2c(oc3c([2H])c(-n4c5ccccc5c5ccccc54)c([2H])c([2H])c32)c1-c1ccc2oc3cc(-c4nc(-c5ccccc5)nc(-c5ccccc5)n4)ccc3c2c1] |
| 1-298 | 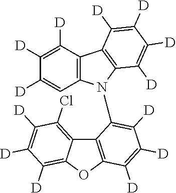 [SMILES: [2H]c1cc2c(c([2H])c1[2H])c1c([2H])c([2H])c([2H])c([2H])c1n2-c1c([2H])c([2H])c([2H])c2oc3c([2H])c([2H])c([2H])c(Cl)c3c12] | 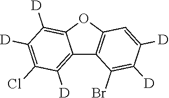 [SMILES: [2H]c1cc2oc3c([2H])c([2H])c(Cl)c([2H])c3c2c(Br)c1[2H]] | 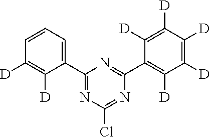 [SMILES: [2H]c1cccc(-c2nc(Cl)nc(-c3c([2H])c([2H])c([2H])c([2H])c3[2H])n2)c1[2H]] | 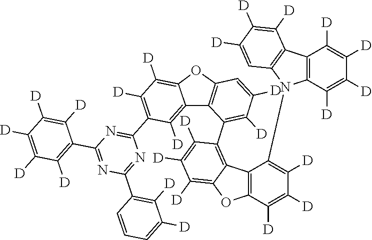 [SMILES: [2H]c1cccc(-c2nc(-c3c([2H])c([2H])c([2H])c([2H])c3[2H])nc(-c3c([2H])c([2H])c4oc5cc([2H])c([2H])c(-c6c([2H])c([2H])c([2H])c7oc8c([2H])c([2H])c([2H])c(-n9c%10cc([2H])c([2H])c([2H])c%10c%10c([2H])c([2H])c([2H])c([2H])c%109)c8c67)c5c4c3[2H])n2)c1[2H]] |
| 2-2 | 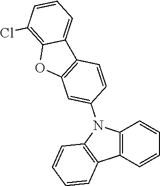 [SMILES: Clc1cccc2c1oc1cc(-n3c4ccccc4c4ccccc43)ccc12] | 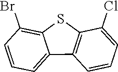 [SMILES: Clc1cccc2c1sc1c(Br)cccc12] | 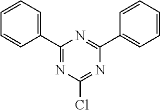 [SMILES: Clc1nc(-c2ccccc2)nc(-c2ccccc2)n1] | 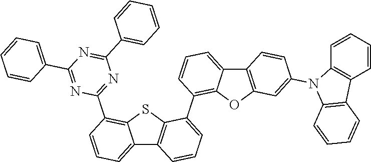 [SMILES: c1ccc(-c2nc(-c3ccccc3)nc(-c3cccc4c3sc3c(-c5cccc6c5oc5cc(-n7c8ccccc8c8ccccc87)ccc56)cccc34)n2)cc1] |
| 2-30 | 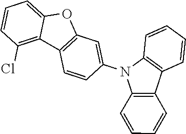 [SMILES: Clc1cccc2oc3cc(-n4c5ccccc5c5ccccc54)ccc3c12] | 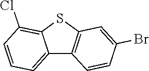 [SMILES: Clc1cccc2c1sc1cc(Br)ccc12] | 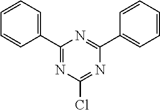 [SMILES: Clc1nc(-c2ccccc2)nc(-c2ccccc2)n1] | 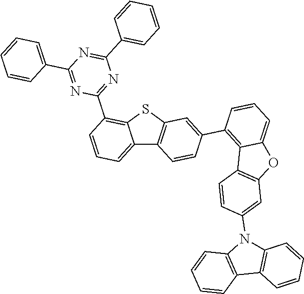 [SMILES: c1ccc(-c2nc(-c3ccccc3)nc(-c3cccc4c3sc3cc(-c5cccc6oc7cc(-n8c9ccccc9c9ccccc98)ccc7c56)ccc34)n2)cc1] |
| 2-58 | 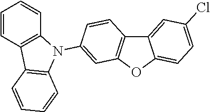 [SMILES: Clc1ccc2oc3cc(-n4c5ccccc5c5ccccc54)ccc3c2c1] | 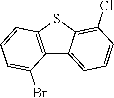 [SMILES: Clc1cccc2c1sc1cccc(Br)c12] | 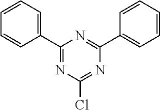 [SMILES: Clc1nc(-c2ccccc2)nc(-c2ccccc2)n1] | 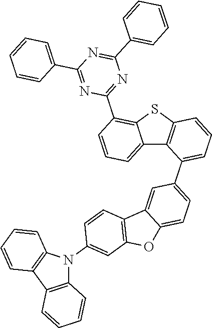 [SMILES: c1ccc(-c2nc(-c3ccccc3)nc(-c3cccc4c3sc3cccc(-c5ccc6oc7cc(-n8c9ccccc9c9ccccc98)ccc7c6c5)c34)n2)cc1] |
| 2-72 | 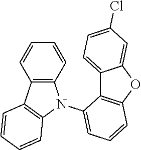 [SMILES: Clc1ccc2c(c1)oc1cccc(-n3c4ccccc4c4ccccc43)c12] | 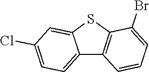 [SMILES: Clc1ccc2c(c1)sc1c(Br)cccc12] | 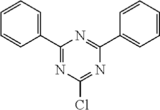 [SMILES: Clc1nc(-c2ccccc2)nc(-c2ccccc2)n1] | 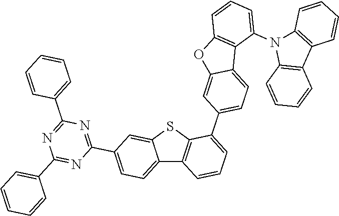 [SMILES: c1ccc(-c2nc(-c3ccccc3)nc(-c3ccc4c(c3)sc3c(-c5ccc6c(c5)oc5cccc(-n7c8ccccc8c8ccccc87)c56)cccc34)n2)cc1] |
| 2-94 | 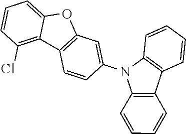 [SMILES: Clc1cccc2oc3cc(-n4c5ccccc5c5ccccc54)ccc3c12] | 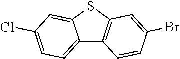 [SMILES: Clc1ccc2c(c1)sc1cc(Br)ccc12] | 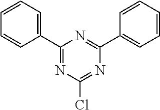 [SMILES: Clc1nc(-c2ccccc2)nc(-c2ccccc2)n1] | 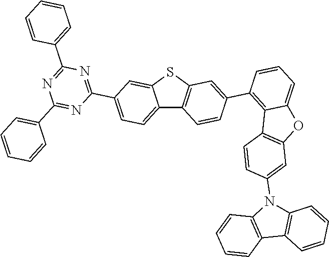 [SMILES: c1ccc(-c2nc(-c3ccccc3)nc(-c3ccc4c(c3)sc3cc(-c5cccc6oc7cc(-n8c9ccccc9c9ccccc98)ccc7c56)ccc34)n2)cc1] |
| 2-115 | 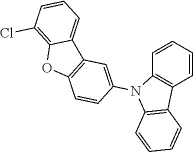 [SMILES: Clc1cccc2c1oc1ccc(-n3c4ccccc4c4ccccc43)cc12] | 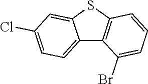 [SMILES: Clc1ccc2c(c1)sc1cccc(Br)c12] | 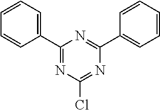 [SMILES: Clc1nc(-c2ccccc2)nc(-c2ccccc2)n1] | 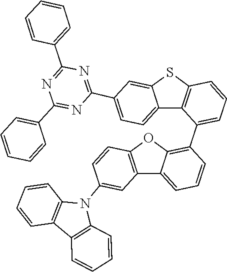 [SMILES: c1ccc(-c2nc(-c3ccccc3)nc(-c3ccc4c(c3)sc3cccc(-c5cccc6c5oc5ccc(-n7c8ccccc8c8ccccc87)cc56)c34)n2)cc1] |
| 2-125 | 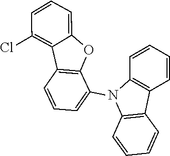 [SMILES: Clc1cccc2oc3c(-n4c5ccccc5c5ccccc54)cccc3c12] | 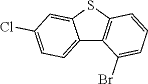 [SMILES: Clc1ccc2c(c1)sc1cccc(Br)c12] | 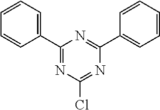 [SMILES: Clc1nc(-c2ccccc2)nc(-c2ccccc2)n1] | 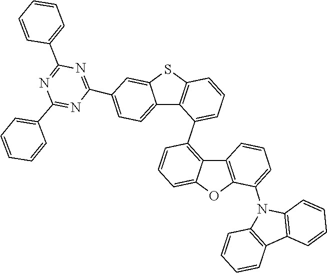 [SMILES: c1ccc(-c2nc(-c3ccccc3)nc(-c3ccc4c(c3)sc3cccc(-c5cccc6oc7c(-n8c9ccccc9c9ccccc98)cccc7c56)c34)n2)cc1] |
| 2-152 | 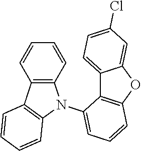 [SMILES: Clc1ccc2c(c1)oc1cccc(-n3c4ccccc4c4ccccc43)c12] | 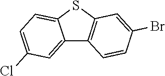 [SMILES: Clc1ccc2sc3cc(Br)ccc3c2c1] | 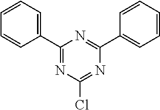 [SMILES: Clc1nc(-c2ccccc2)nc(-c2ccccc2)n1] | 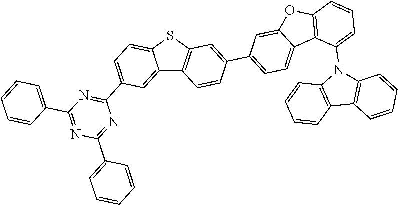 [SMILES: c1ccc(-c2nc(-c3ccccc3)nc(-c3ccc4sc5cc(-c6ccc7c(c6)oc6cccc(-n8c9ccccc9c9ccccc98)c67)ccc5c4c3)n2)cc1] |
| 2-173 | 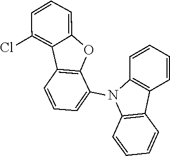 [SMILES: Clc1cccc2oc3c(-n4c5ccccc5c5ccccc54)cccc3c12] | 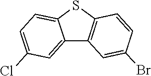 [SMILES: Clc1ccc2sc3ccc(Br)cc3c2c1] | 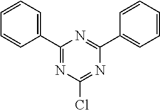 [SMILES: Clc1nc(-c2ccccc2)nc(-c2ccccc2)n1] | 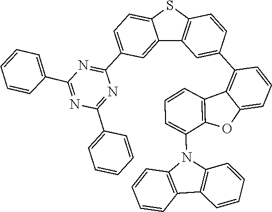 [SMILES: c1ccc(-c2nc(-c3ccccc3)nc(-c3ccc4sc5ccc(-c6cccc7oc8c(-n9c%10ccccc%10c%10ccccc%109)cccc8c67)cc5c4c3)n2)cc1] |
| 2-191 | 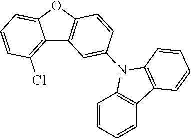 [SMILES: Clc1cccc2oc3ccc(-n4c5ccccc5c5ccccc54)cc3c12] | 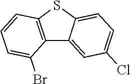 [SMILES: Clc1ccc2sc3cccc(Br)c3c2c1] | 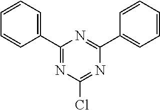 [SMILES: Clc1nc(-c2ccccc2)nc(-c2ccccc2)n1] | 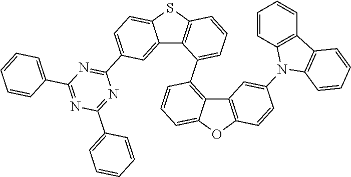 [SMILES: c1ccc(-c2nc(-c3ccccc3)nc(-c3ccc4sc5cccc(-c6cccc7oc8ccc(-n9c%10ccccc%10c%10ccccc%109)cc8c67)c5c4c3)n2)cc1] |
| 2-210 | 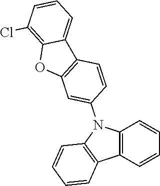 [SMILES: Clc1cccc2c1oc1cc(-n3c4ccccc4c4ccccc43)ccc12] | 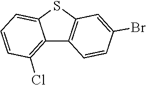 [SMILES: Clc1cccc2sc3cc(Br)ccc3c12] | 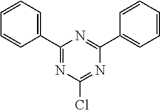 [SMILES: Clc1nc(-c2ccccc2)nc(-c2ccccc2)n1] | 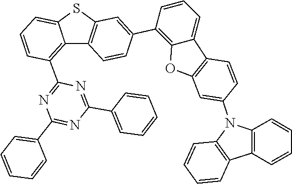 [SMILES: c1ccc(-c2nc(-c3ccccc3)nc(-c3cccc4sc5cc(-c6cccc7c6oc6cc(-n8c9ccccc9c9ccccc98)ccc67)ccc5c34)n2)cc1] |
| 2-235 | 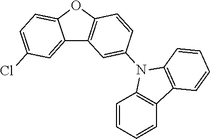 [SMILES: Clc1ccc2oc3ccc(-n4c5ccccc5c5ccccc54)cc3c2c1] | 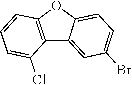 [SMILES: Clc1cccc2oc3ccc(Br)cc3c12] | 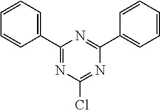 [SMILES: Clc1nc(-c2ccccc2)nc(-c2ccccc2)n1] | 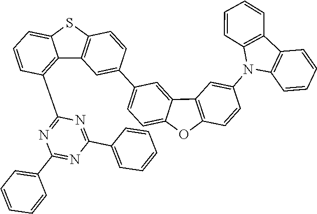 [SMILES: c1ccc(-c2nc(-c3ccccc3)nc(-c3cccc4sc5ccc(-c6ccc7oc8ccc(-n9c%10ccccc%10c%10ccccc%109)cc8c7c6)cc5c34)n2)cc1] |
| 2-254 | 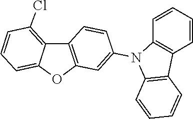 [SMILES: Clc1cccc2oc3cc(-n4c5ccccc5c5ccccc54)ccc3c12] | 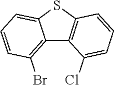 [SMILES: Clc1cccc2sc3cccc(Br)c3c12] | 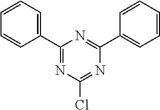 [SMILES: Clc1nc(-c2ccccc2)nc(-c2ccccc2)n1] | 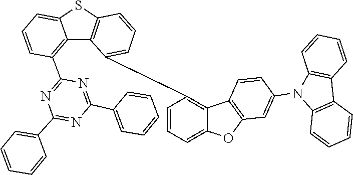 [SMILES: c1ccc(-c2nc(-c3ccccc3)nc(-c3cccc4sc5cccc(-c6cccc7oc8cc(-n9c%10ccccc%10c%10ccccc%109)ccc8c67)c5c34)n2)cc1] |
| 2-269 | 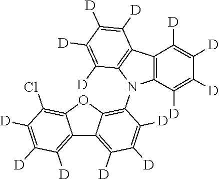 [SMILES: [2H]c1c([2H])c([2H])c2c(oc3c(-n4c5c([2H])c([2H])c([2H])c([2H])c5c5c([2H])c([2H])c([2H])c([2H])c54)c([2H])c([2H])c([2H])c32)c1Cl] | 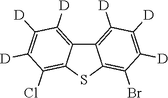 [SMILES: [2H]c1c([2H])c([2H])c2c(sc3c(Br)c([2H])c([2H])c([2H])c32)c1Cl] | 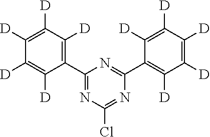 [SMILES: [2H]c1c([2H])c([2H])c(-c2nc(Cl)nc(-c3c([2H])c([2H])c([2H])c([2H])c3[2H])n2)c([2H])c1[2H]] | 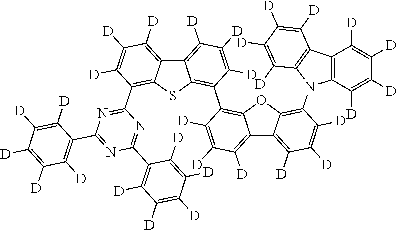 [SMILES: [2H]c1c([2H])c([2H])c(-c2nc(-c3c([2H])c([2H])c([2H])c([2H])c3[2H])nc(-c3c([2H])c([2H])c([2H])c4c3sc3c(-c5c([2H])c([2H])c([2H])c6c5oc5c(-n7c8c([2H])c([2H])c([2H])c([2H])c8c8c([2H])c([2H])c([2H])c([2H])c87)c([2H])c([2H])c([2H])c56)c([2H])c([2H])c([2H])c34)n2)c([2H])c1[2H]] |
| 2-274 | 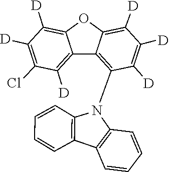 [SMILES: [2H]c1c(Cl)c([2H])c2c(oc3c([2H])c([2H])c([2H])c(-n4c5ccccc5c5ccccc54)c32)c1[2H]] | 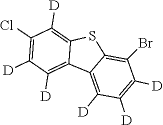 [SMILES: [2H]c1c([2H])c([2H])c2c(sc3c([2H])c(Cl)c([2H])c([2H])c32)c1Br] | 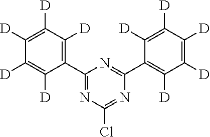 [SMILES: [2H]c1c([2H])c([2H])c(-c2nc(Cl)nc(-c3c([2H])c([2H])c([2H])c([2H])c3[2H])n2)c([2H])c1[2H]] | 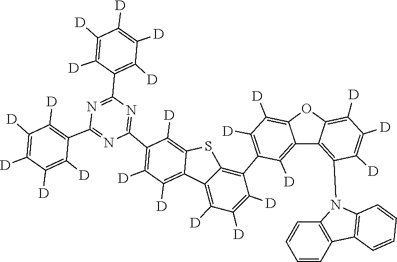 [SMILES: [2H]c1c([2H])c([2H])c(-c2nc(-c3c([2H])c([2H])c([2H])c([2H])c3[2H])nc(-c3c([2H])c([2H])c4c(sc5c(-c6c([2H])c([2H])c7oc8c([2H])c([2H])c([2H])c(-n9c%10ccccc%10c%10ccccc%109)c8c7c6[2H])c([2H])c([2H])c([2H])c54)c3[2H])n2)c([2H])c1[2H]] |
| 2-279 | 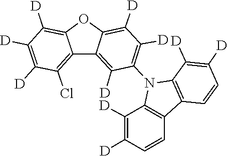 [SMILES: [2H]c1ccc2c3ccc([2H])c([2H])c3n(-c3c([2H])c([2H])c4oc5c([2H])c([2H])c([2H])c(Cl)c5c4c3[2H])c2c1[2H]] | 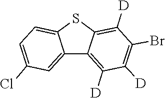 [SMILES: [2H]c1c(Br)c([2H])c2sc3ccc(Cl)cc3c2c1[2H]] | 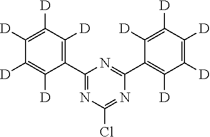 [SMILES: [2H]c1c([2H])c([2H])c(-c2nc(Cl)nc(-c3c([2H])c([2H])c([2H])c([2H])c3[2H])n2)c([2H])c1[2H]] | 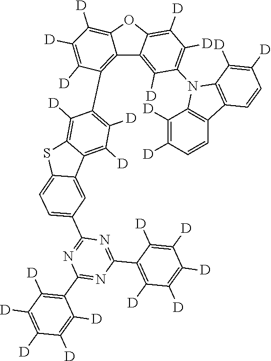 [SMILES: [2H]c1ccc2c3ccc([2H])c([2H])c3n(-c3c([2H])c([2H])c4oc5c([2H])c([2H])c([2H])c(-c6c([2H])c([2H])c7c(sc8ccc(-c9nc(-c%10c([2H])c([2H])c([2H])c([2H])c%10[2H])nc(-c%10c([2H])c([2H])c([2H])c([2H])c%10[2H])n9)cc87)c6[2H])c5c4c3[2H])c2c1[2H]] |
| 2-285 | 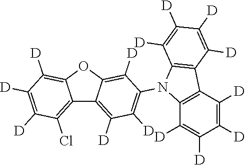 [SMILES: [2H]c1c([2H])c(Cl)c2c(oc3c([2H])c(-n4c5c([2H])c([2H])c([2H])c([2H])c5c5c([2H])c([2H])c([2H])c([2H])c54)c([2H])c([2H])c32)c1[2H]] | 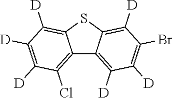 [SMILES: [2H]c1c([2H])c(Cl)c2c(sc3c([2H])c(Br)c([2H])c([2H])c32)c1[2H]] | 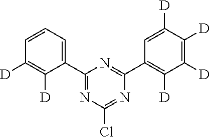 [SMILES: [2H]c1cccc(-c2nc(Cl)nc(-c3cc([2H])c([2H])c([2H])c3[2H])n2)c1[2H]] | 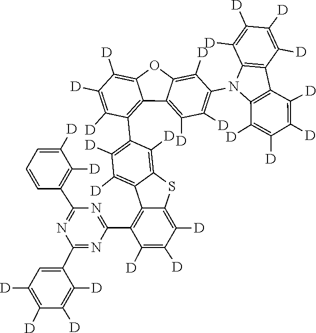 [SMILES: [2H]c1cccc(-c2nc(-c3cc([2H])c([2H])c([2H])c3[2H])nc(-c3c([2H])c([2H])c([2H])c4sc5c([2H])c(-c6c([2H])c([2H])c([2H])c7oc8c([2H])c(-n9c%10c([2H])c([2H])c([2H])c([2H])c%10c%10c([2H])c([2H])c([2H])c([2H])c%109)c([2H])c([2H])c8c67)c([2H])c([2H])c5c34)n2)c1[2H]] |
| 3-6 | 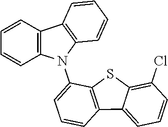 [SMILES: Clc1cccc2c1sc1c(-n3c4ccccc4c4ccccc43)cccc12] | 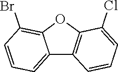 [SMILES: Clc1cccc2c1oc1c(Br)cccc12] | 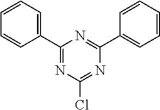 [SMILES: Clc1nc(-c2ccccc2)nc(-c2ccccc2)n1] | 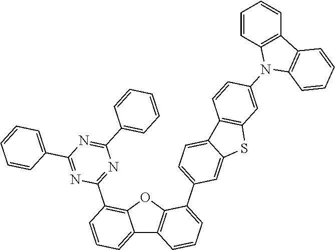 [SMILES: c1ccc(-c2nc(-c3ccccc3)nc(-c3cccc4c3oc3c(-c5ccc6c(c5)sc5cc(-n7c8ccccc8c8ccccc87)ccc56)cccc34)n2)cc1] |
| 3-31 | 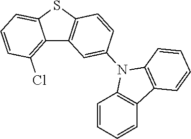 [SMILES: Clc1cccc2sc3ccc(-n4c5ccccc5c5ccccc54)cc3c12] | 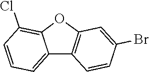 [SMILES: Clc1cccc2c1oc1cc(Br)ccc12] | 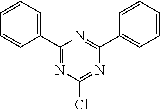 [SMILES: Clc1nc(-c2ccccc2)nc(-c2ccccc2)n1] | 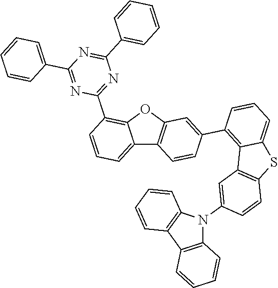 [SMILES: c1ccc(-c2nc(-c3ccccc3)nc(-c3cccc4c3oc3cc(-c5cccc6sc7ccc(-n8c9ccccc9c9ccccc98)cc7c56)ccc34)n2)cc1] |
| 3-53 | 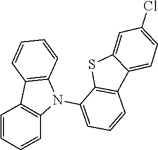 [SMILES: Clc1ccc2c(c1)sc1c(-n3c4ccccc4c4ccccc43)cccc12] | 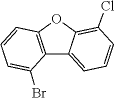 [SMILES: Clc1cccc2c1oc1cccc(Br)c12] | 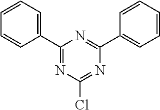 [SMILES: Clc1nc(-c2ccccc2)nc(-c2ccccc2)n1] | 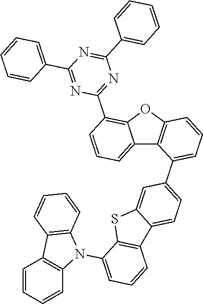 [SMILES: c1ccc(-c2nc(-c3ccccc3)nc(-c3cccc4c3oc3cccc(-c5ccc6c(c5)sc5c(-n7c8ccccc8c8ccccc87)cccc56)c34)n2)cc1] |
| 3-67 | 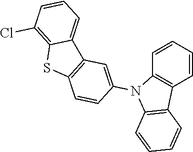 [SMILES: Clc1cccc2c1sc1ccc(-n3c4ccccc4c4ccccc43)cc12] | 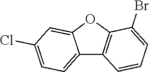 [SMILES: Clc1ccc2c(c1)oc1c(Br)cccc12] | 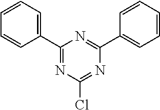 [SMILES: Clc1nc(-c2ccccc2)nc(-c2ccccc2)n1] | 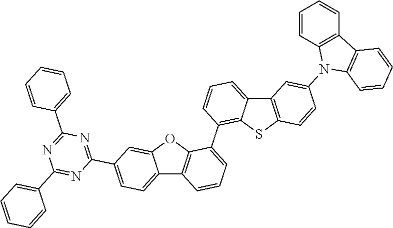 [SMILES: c1ccc(-c2nc(-c3ccccc3)nc(-c3ccc4c(c3)oc3c(-c5cccc6c5sc5ccc(-n7c8ccccc8c8ccccc87)cc56)cccc34)n2)cc1] |
| 3-94 | 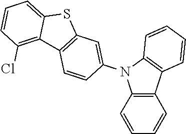 [SMILES: Clc1cccc2sc3cc(-n4c5ccccc5c5ccccc54)ccc3c12] | 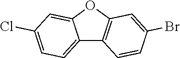 [SMILES: Clc1ccc2c(c1)oc1cc(Br)ccc12] | 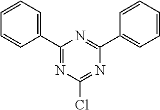 [SMILES: Clc1nc(-c2ccccc2)nc(-c2ccccc2)n1] | 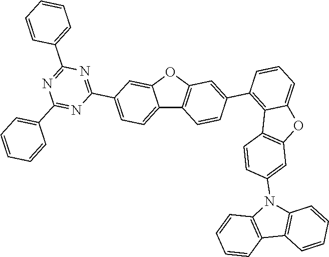 [SMILES: c1ccc(-c2nc(-c3ccccc3)nc(-c3ccc4c(c3)oc3cc(-c5cccc6oc7cc(-n8c9ccccc9c9ccccc98)ccc7c56)ccc34)n2)cc1] |
| 3-111 | 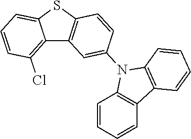 [SMILES: Clc1cccc2sc3ccc(-n4c5ccccc5c5ccccc54)cc3c12] | 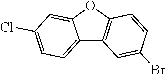 [SMILES: Clc1ccc2c(c1)oc1ccc(Br)cc12] | 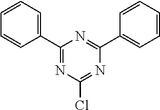 [SMILES: Clc1nc(-c2ccccc2)nc(-c2ccccc2)n1] | 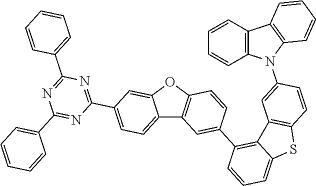 [SMILES: c1ccc(-c2nc(-c3ccccc3)nc(-c3ccc4c(c3)oc3ccc(-c5cccc6sc7ccc(-n8c9ccccc9c9ccccc98)cc7c56)cc34)n2)cc1] |
| 3-129 | 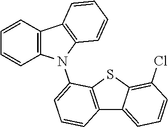 [SMILES: Clc1cccc2c1sc1c(-n3c4ccccc4c4ccccc43)cccc12] | 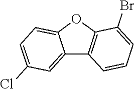 [SMILES: Clc1ccc2oc3c(Br)cccc3c2c1] | 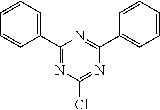 [SMILES: Clc1nc(-c2ccccc2)nc(-c2ccccc2)n1] | 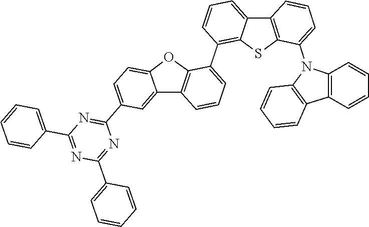 [SMILES: c1ccc(-c2nc(-c3ccccc3)nc(-c3ccc4oc5c(-c6cccc7c6sc6c(-n8c9ccccc9c9ccccc98)cccc67)cccc5c4c3)n2)cc1] |
| 3-154 | 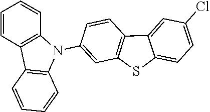 [SMILES: Clc1ccc2sc3cc(-n4c5ccccc5c5ccccc54)ccc3c2c1] | 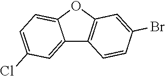 [SMILES: Clc1ccc2oc3cc(Br)ccc3c2c1] | 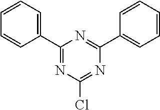 [SMILES: Clc1nc(-c2ccccc2)nc(-c2ccccc2)n1] | 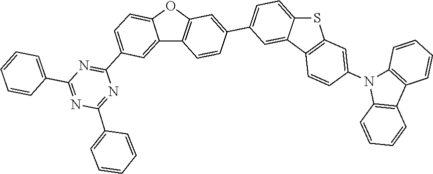 [SMILES: c1ccc(-c2nc(-c3ccccc3)nc(-c3ccc4oc5cc(-c6ccc7sc8cc(-n9c%10ccccc%10c%10ccccc%109)ccc8c7c6)ccc5c4c3)n2)cc1] |
| 3-167 | 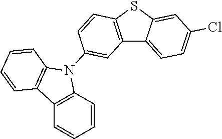 [SMILES: Clc1ccc2c(c1)sc1ccc(-n3c4ccccc4c4ccccc43)cc12] | 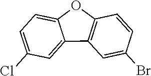 [SMILES: Clc1ccc2oc3ccc(Br)cc3c2c1] | 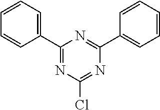 [SMILES: Clc1nc(-c2ccccc2)nc(-c2ccccc2)n1] | 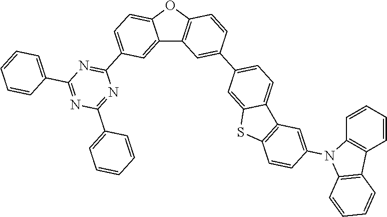 [SMILES: c1ccc(-c2nc(-c3ccccc3)nc(-c3ccc4oc5ccc(-c6ccc7c(c6)sc6ccc(-n8c9ccccc9c9ccccc98)cc67)cc5c4c3)n2)cc1] |
| 3-194 | 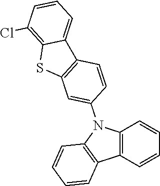 [SMILES: Clc1cccc2c1sc1cc(-n3c4ccccc4c4ccccc43)ccc12] | 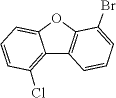 [SMILES: Clc1cccc2oc3c(Br)cccc3c12] | 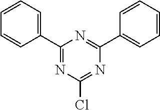 [SMILES: Clc1nc(-c2ccccc2)nc(-c2ccccc2)n1] | 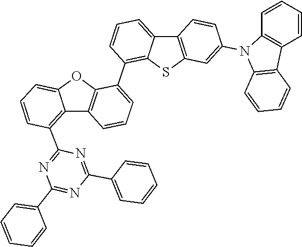 [SMILES: c1ccc(-c2nc(-c3ccccc3)nc(-c3cccc4oc5c(-c6cccc7c6sc6cc(-n8c9ccccc9c9ccccc98)ccc67)cccc5c34)n2)cc1] |
| 3-207 | 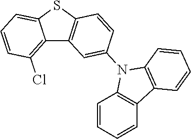 [SMILES: Clc1cccc2sc3ccc(-n4c5ccccc5c5ccccc54)cc3c12] | 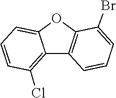 [SMILES: Clc1cccc2oc3c(Br)cccc3c12] | 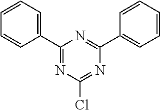 [SMILES: Clc1nc(-c2ccccc2)nc(-c2ccccc2)n1] | 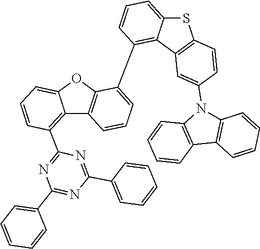 [SMILES: c1ccc(-c2nc(-c3ccccc3)nc(-c3cccc4oc5c(-c6cccc7sc8ccc(-n9c%10ccccc%10c%10ccccc%109)cc8c67)cccc5c34)n2)cc1] |
| 3-234 | 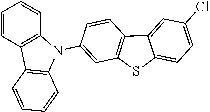 [SMILES: Clc1ccc2sc3cc(-n4c5ccccc5c5ccccc54)ccc3c2c1] | 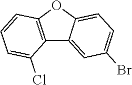 [SMILES: Clc1cccc2oc3ccc(Br)cc3c12] | 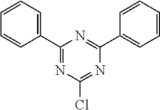 [SMILES: Clc1nc(-c2ccccc2)nc(-c2ccccc2)n1] | 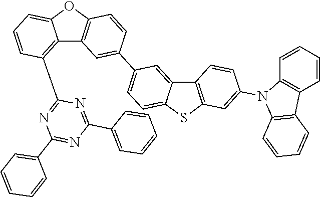 [SMILES: c1ccc(-c2nc(-c3ccccc3)nc(-c3cccc4oc5ccc(-c6ccc7sc8cc(-n9c%10ccccc%10c%10ccccc%109)ccc8c7c6)cc5c34)n2)cc1] |
| 3-255 | 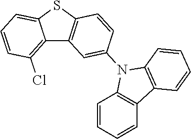 [SMILES: Clc1cccc2sc3ccc(-n4c5ccccc5c5ccccc54)cc3c12] | 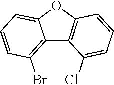 [SMILES: Clc1cccc2oc3cccc(Br)c3c12] | 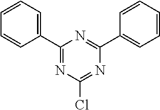 [SMILES: Clc1nc(-c2ccccc2)nc(-c2ccccc2)n1] | 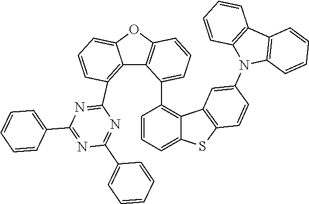 [SMILES: c1ccc(-c2nc(-c3ccccc3)nc(-c3cccc4oc5cccc(-c6cccc7sc8ccc(-n9c%10ccccc%10c%10ccccc%109)cc8c67)c5c34)n2)cc1] |
| 3-271 | 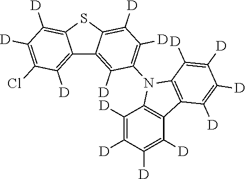 [SMILES: [2H]c1c(Cl)c([2H])c2c(sc3c([2H])c([2H])c(-n4c5c([2H])c([2H])c([2H])c([2H])c5c5c([2H])c([2H])c([2H])c([2H])c54)c([2H])c32)c1[2H]] | 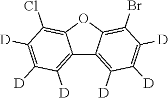 [SMILES: [2H]c1c([2H])c([2H])c2c(oc3c(Br)c([2H])c([2H])c([2H])c32)c1Cl] | 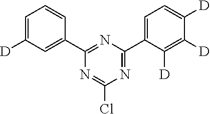 [SMILES: [2H]c1cccc(-c2nc(Cl)nc(-c3ccc([2H])c([2H])c3[2H])n2)c1] | 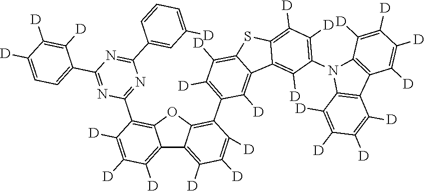 [SMILES: [2H]c1cccc(-c2nc(-c3ccc([2H])c([2H])c3[2H])nc(-c3c([2H])c([2H])c([2H])c4c3oc3c(-c5c([2H])c([2H])c6sc7c([2H])c([2H])c(-n8c9c([2H])c([2H])c([2H])c([2H])c9c9c([2H])c([2H])c([2H])c([2H])c98)c([2H])c7c6c5[2H])c([2H])c([2H])c([2H])c34)n2)c1] |
| 3-273 | 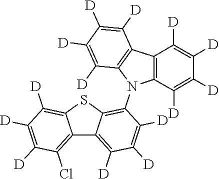 [SMILES: [2H]c1c([2H])c(Cl)c2c(sc3c(-n4c5c([2H])c([2H])c([2H])c([2H])c5c5c([2H])c([2H])c([2H])c([2H])c54)c([2H])c([2H])c([2H])c32)c1[2H]] | 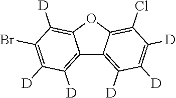 [SMILES: [2H]c1c([2H])c([2H])c2c(oc3c([2H])c(Br)c([2H])c([2H])c32)c1Cl] | 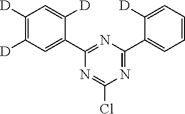 [SMILES: [2H]c1cc([2H])c(-c2nc(Cl)nc(-c3ccccc3[2H])n2)cc1[2H]] | 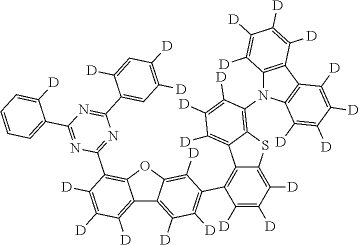 [SMILES: [2H]c1cc([2H])c(-c2nc(-c3ccccc3[2H])nc(-c3c([2H])c([2H])c([2H])c4c3oc3c([2H])c(-c5c([2H])c([2H])c([2H])c6sc7c(-n8c9c([2H])c([2H])c([2H])c([2H])c9c9c([2H])c([2H])c([2H])c([2H])c98)c([2H])c([2H])c([2H])c7c56)c([2H])c([2H])c34)n2)cc1[2H]] |
| 3-280 | 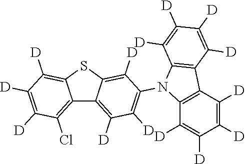 [SMILES: [2H]c1c([2H])c(Cl)c2c(sc3c([2H])c(-n4c5c([2H])c([2H])c([2H])c([2H])c5c5c([2H])c([2H])c([2H])c([2H])c54)c([2H])c([2H])c32)c1[2H]] | 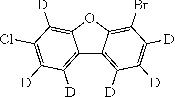 [SMILES: [2H]c1c([2H])c([2H])c2c(oc3c([2H])c(Cl)c([2H])c([2H])c32)c1Br] | 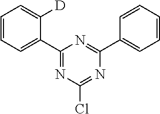 [SMILES: [2H]c1ccccc1-c1nc(Cl)nc(-c2ccccc2)n1] | 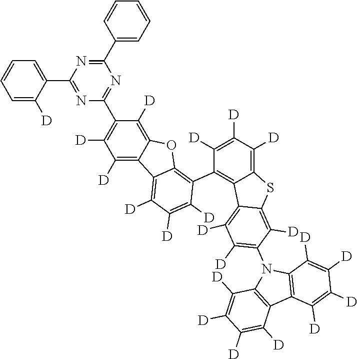 [SMILES: [2H]c1ccccc1-c1nc(-c2ccccc2)nc(-c2c([2H])c([2H])c3c(oc4c(-c5c([2H])c([2H])c([2H])c6sc7c([2H])c(-n8c9c([2H])c([2H])c([2H])c([2H])c9c9c([2H])c([2H])c([2H])c([2H])c98)c([2H])c([2H])c7c56)c([2H])c([2H])c([2H])c43)c2[2H])n1] |
| 3-286 | 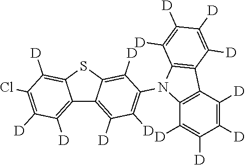 [SMILES: [2H]c1c(Cl)c([2H])c2sc3c([2H])c(-n4c5c([2H])c([2H])c([2H])c([2H])c5c5c([2H])c([2H])c([2H])c([2H])c54)c([2H])c([2H])c3c2c1[2H]] | 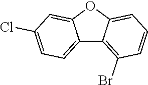 [SMILES: Clc1ccc2c(c1)oc1cccc(Br)c12] | 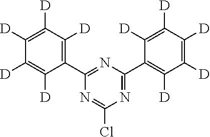 [SMILES: [2H]c1c([2H])c([2H])c(-c2nc(Cl)nc(-c3c([2H])c([2H])c([2H])c([2H])c3[2H])n2)c([2H])c1[2H]] | 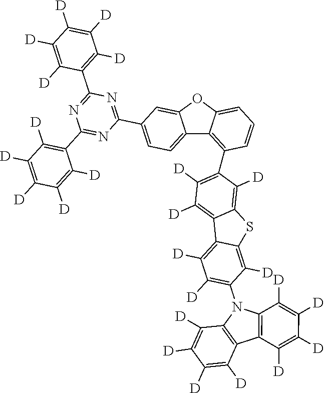 [SMILES: [2H]c1c([2H])c([2H])c(-c2nc(-c3ccc4c(c3)oc3cccc(-c5c([2H])c([2H])c6c(sc7c([2H])c(-n8c9c([2H])c([2H])c([2H])c([2H])c9c9c([2H])c([2H])c([2H])c([2H])c98)c([2H])c([2H])c76)c5[2H])c34)nc(-c3c([2H])c([2H])c([2H])c([2H])c3[2H])n2)c([2H])c1[2H]] |
| 3-299 | 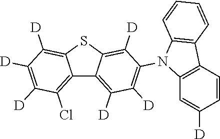 [SMILES: [2H]c1ccc2c3ccccc3n(-c3c([2H])c([2H])c4c(sc5c([2H])c([2H])c([2H])c(Cl)c54)c3[2H])c2c1] | 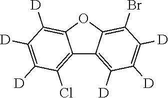 [SMILES: [2H]c1c([2H])c(Cl)c2c(oc3c(Br)c([2H])c([2H])c([2H])c32)c1[2H]] | 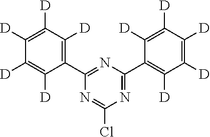 [SMILES: [2H]c1c([2H])c([2H])c(-c2nc(Cl)nc(-c3c([2H])c([2H])c([2H])c([2H])c3[2H])n2)c([2H])c1[2H]] | 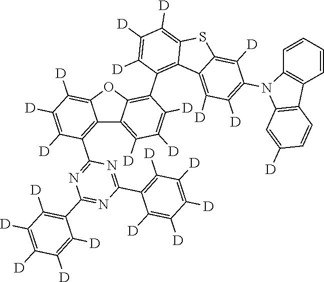 [SMILES: [2H]c1ccc2c3ccccc3n(-c3c([2H])c([2H])c4c(sc5c([2H])c([2H])c([2H])c(-c6c([2H])c([2H])c([2H])c7c6oc6c([2H])c([2H])c([2H])c(-c8nc(-c9c([2H])c([2H])c([2H])c([2H])c9[2H])nc(-c9c([2H])c([2H])c([2H])c([2H])c9[2H])n8)c67)c54)c3[2H])c2c1] |
| 3-302 | 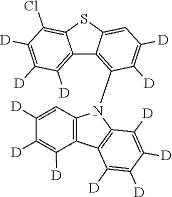 [SMILES: [2H]c1cc2sc3c(Cl)c([2H])c([2H])c([2H])c3c2c(-n2c3cc([2H])c([2H])c([2H])c3c3c([2H])c([2H])c([2H])c([2H])c32)c1[2H]] | 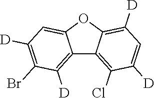 [SMILES: [2H]c1cc2oc3c([2H])cc([2H])c(Cl)c3c2c([2H])c1Br] | 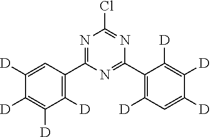 [SMILES: [2H]c1cc(-c2nc(Cl)nc(-c3c([2H])cc([2H])c([2H])c3[2H])n2)c([2H])c([2H])c1[2H]] | 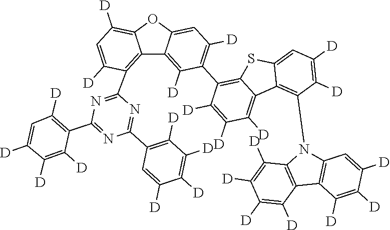 [SMILES: [2H]c1cc(-c2nc(-c3c([2H])cc([2H])c([2H])c3[2H])nc(-c3c([2H])cc([2H])c4oc5cc([2H])c(-c6c([2H])c([2H])c([2H])c7c6sc6cc([2H])c([2H])c(-n8c9cc([2H])c([2H])c([2H])c9c9c([2H])c([2H])c([2H])c([2H])c98)c67)c([2H])c5c34)n2)c([2H])c([2H])c1[2H]] |
| 3-307 | 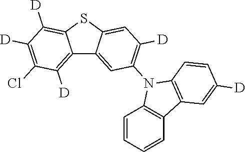 [SMILES: [2H]c1ccc2c(c1)c1ccccc1n2-c1cc2c(cc1[2H])sc1c([2H])c([2H])c(Cl)c([2H])c12] | 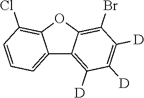 [SMILES: [2H]c1c([2H])c([2H])c2c(oc3c(Cl)cccc32)c1Br] | 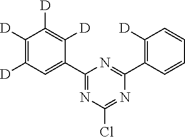 [SMILES: [2H]c1ccccc1-c1nc(Cl)nc(-c2cc([2H])c([2H])c([2H])c2[2H])n1] | 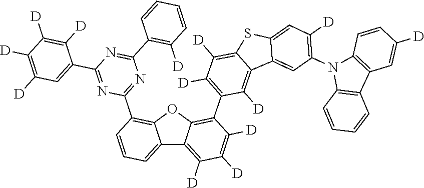 [SMILES: [2H]c1ccc2c(c1)c1ccccc1n2-c1cc2c(cc1[2H])sc1c([2H])c([2H])c(-c3c([2H])c([2H])c([2H])c4c3oc3c(-c5nc(-c6ccccc6[2H])nc(-c6cc([2H])c([2H])c([2H])c6[2H])n5)cccc34)c([2H])c12] |
| 4-6 | 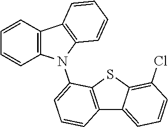 [SMILES: Clc1cccc2c1sc1c(-n3c4ccccc4c4ccccc43)cccc12] | 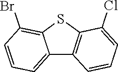 [SMILES: Clc1cccc2c1sc1c(Br)cccc12] | 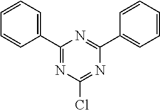 [SMILES: Clc1nc(-c2ccccc2)nc(-c2ccccc2)n1] | 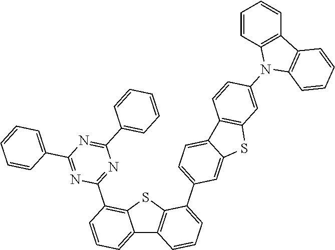 [SMILES: c1ccc(-c2nc(-c3ccccc3)nc(-c3cccc4c3sc3c(-c5ccc6c(c5)sc5cc(-n7c8ccccc8c8ccccc87)ccc56)cccc34)n2)cc1] |
| 4-31 | 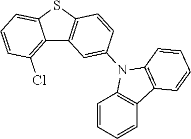 [SMILES: Clc1cccc2sc3ccc(-n4c5ccccc5c5ccccc54)cc3c12] | 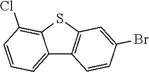 [SMILES: Clc1cccc2c1sc1cc(Br)ccc12] | 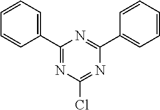 [SMILES: Clc1nc(-c2ccccc2)nc(-c2ccccc2)n1] | 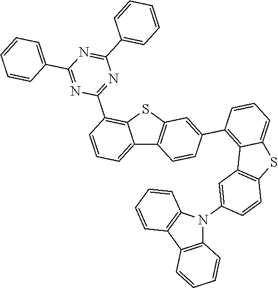 [SMILES: c1ccc(-c2nc(-c3ccccc3)nc(-c3cccc4c3sc3cc(-c5cccc6sc7ccc(-n8c9ccccc9c9ccccc98)cc7c56)ccc34)n2)cc1] |
| 4-51 | 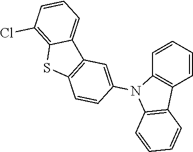 [SMILES: Clc1cccc2c1sc1ccc(-n3c4ccccc4c4ccccc43)cc12] | 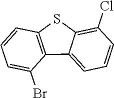 [SMILES: Clc1cccc2c1sc1cccc(Br)c12] | 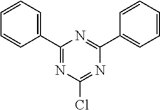 [SMILES: Clc1nc(-c2ccccc2)nc(-c2ccccc2)n1] | 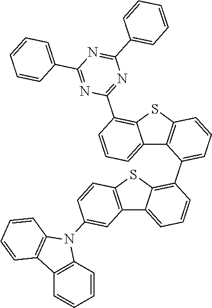 [SMILES: c1ccc(-c2nc(-c3ccccc3)nc(-c3cccc4c3sc3cccc(-c5cccc6c5sc5ccc(-n7c8ccccc8c8ccccc87)cc56)c34)n2)cc1] |
| 4-78 | 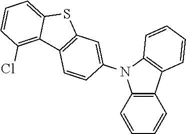 [SMILES: Clc1cccc2sc3cc(-n4c5ccccc5c5ccccc54)ccc3c12] | 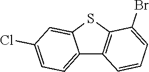 [SMILES: Clc1ccc2c(c1)sc1c(Br)cccc12] | 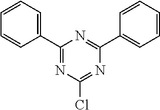 [SMILES: Clc1nc(-c2ccccc2)nc(-c2ccccc2)n1] | 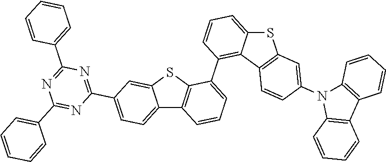 [SMILES: c1ccc(-c2nc(-c3ccccc3)nc(-c3ccc4c(c3)sc3c(-c5cccc6sc7cc(-n8c9ccccc9c9ccccc98)ccc7c56)cccc34)n2)cc1] |
| 4-94 | 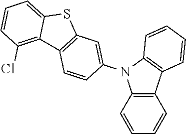 [SMILES: Clc1cccc2sc3cc(-n4c5ccccc5c5ccccc54)ccc3c12] | 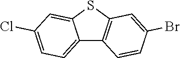 [SMILES: Clc1ccc2c(c1)sc1cc(Br)ccc12] | 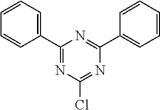 [SMILES: Clc1nc(-c2ccccc2)nc(-c2ccccc2)n1] | 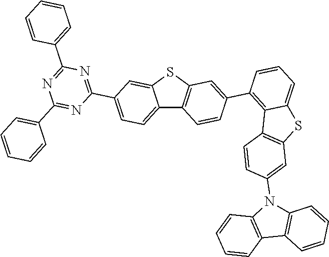 [SMILES: c1ccc(-c2nc(-c3ccccc3)nc(-c3ccc4c(c3)sc3cc(-c5cccc6sc7cc(-n8c9ccccc9c9ccccc98)ccc7c56)ccc34)n2)cc1] |
| 4-114 | 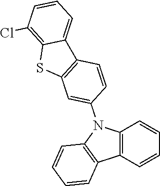 [SMILES: Clc1cccc2c1sc1cc(-n3c4ccccc4c4ccccc43)ccc12] | 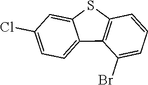 [SMILES: Clc1ccc2c(c1)sc1cccc(Br)c12] | 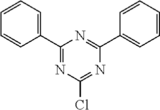 [SMILES: Clc1nc(-c2ccccc2)nc(-c2ccccc2)n1] | 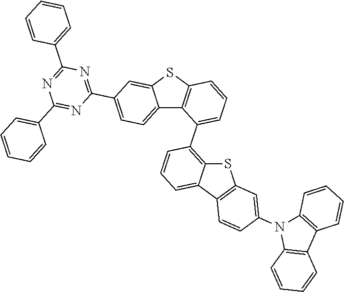 [SMILES: c1ccc(-c2nc(-c3ccccc3)nc(-c3ccc4c(c3)sc3cccc(-c5cccc6c5sc5cc(-n7c8ccccc8c8ccccc87)ccc56)c34)n2)cc1] |
| 4-135 | 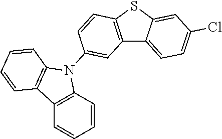 [SMILES: Clc1ccc2c(c1)sc1ccc(-n3c4ccccc4c4ccccc43)cc12] | 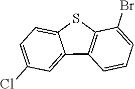 [SMILES: Clc1ccc2sc3c(Br)cccc3c2c1] | 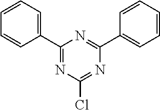 [SMILES: Clc1nc(-c2ccccc2)nc(-c2ccccc2)n1] | 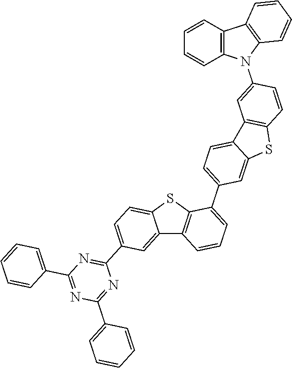 [SMILES: c1ccc(-c2nc(-c3ccccc3)nc(-c3ccc4sc5c(-c6ccc7c(c6)sc6ccc(-n8c9ccccc9c9ccccc98)cc67)cccc5c4c3)n2)cc1] |
| 4-152 | 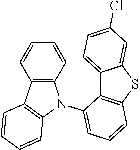 [SMILES: Clc1ccc2c(c1)sc1cccc(-n3c4ccccc4c4ccccc43)c12] | 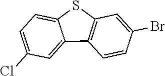 [SMILES: Clc1ccc2sc3cc(Br)ccc3c2c1] | 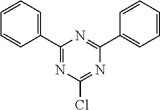 [SMILES: Clc1nc(-c2ccccc2)nc(-c2ccccc2)n1] | 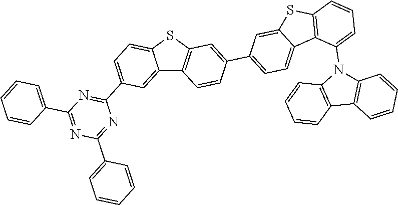 [SMILES: c1ccc(-c2nc(-c3ccccc3)nc(-c3ccc4sc5cc(-c6ccc7c(c6)sc6cccc(-n8c9ccccc9c9ccccc98)c67)ccc5c4c3)n2)cc1] |
| 4-171 | 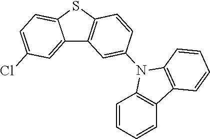 [SMILES: Clc1ccc2sc3ccc(-n4c5ccccc5c5ccccc54)cc3c2c1] | 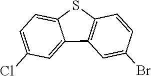 [SMILES: Clc1ccc2sc3ccc(Br)cc3c2c1] | 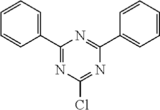 [SMILES: Clc1nc(-c2ccccc2)nc(-c2ccccc2)n1] | 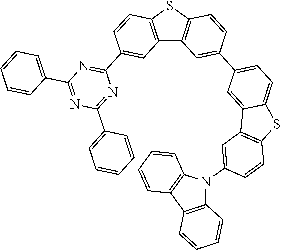 [SMILES: c1ccc(-c2nc(-c3ccccc3)nc(-c3ccc4sc5ccc(-c6ccc7sc8ccc(-n9c%10ccccc%10c%10ccccc%109)cc8c7c6)cc5c4c3)n2)cc1] |
| 4-190 | 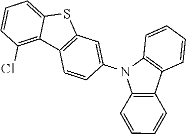 [SMILES: Clc1cccc2sc3cc(-n4c5ccccc5c5ccccc54)ccc3c12] | 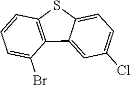 [SMILES: Clc1ccc2sc3cccc(Br)c3c2c1] | 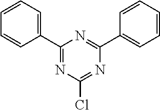 [SMILES: Clc1nc(-c2ccccc2)nc(-c2ccccc2)n1] | 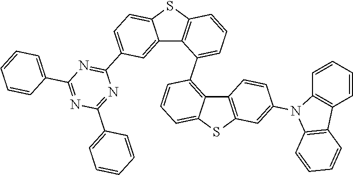 [SMILES: c1ccc(-c2nc(-c3ccccc3)nc(-c3ccc4sc5cccc(-c6cccc7sc8cc(-n9c%10ccccc%10c%10ccccc%109)ccc8c67)c5c4c3)n2)cc1] |
| 4-219 | 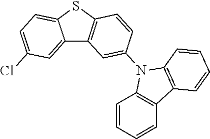 [SMILES: Clc1ccc2sc3ccc(-n4c5ccccc5c5ccccc54)cc3c2c1] | 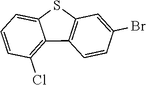 [SMILES: Clc1cccc2sc3cc(Br)ccc3c12] | 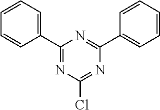 [SMILES: Clc1nc(-c2ccccc2)nc(-c2ccccc2)n1] | 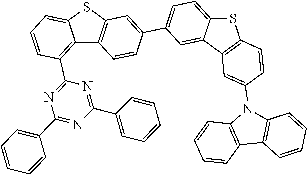 [SMILES: c1ccc(-c2nc(-c3ccccc3)nc(-c3cccc4sc5cc(-c6ccc7sc8ccc(-n9c%10ccccc%10c%10ccccc%109)cc8c7c6)ccc5c34)n2)cc1] |
| 4-227 | 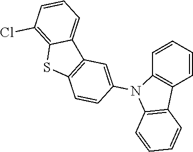 [SMILES: Clc1cccc2c1sc1ccc(-n3c4ccccc4c4ccccc43)cc12] | 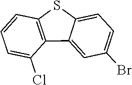 [SMILES: Clc1cccc2sc3ccc(Br)cc3c12] | 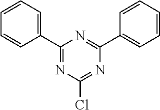 [SMILES: Clc1nc(-c2ccccc2)nc(-c2ccccc2)n1] | 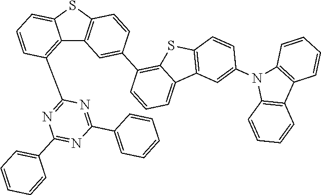 [SMILES: c1ccc(-c2nc(-c3ccccc3)nc(-c3cccc4sc5ccc(-c6cccc7c6sc6ccc(-n8c9ccccc9c9ccccc98)cc67)cc5c34)n2)cc1] |
| 4-255 | 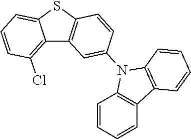 [SMILES: Clc1cccc2sc3ccc(-n4c5ccccc5c5ccccc54)cc3c12] | 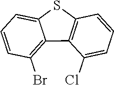 [SMILES: Clc1cccc2sc3cccc(Br)c3c12] | 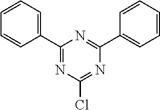 [SMILES: Clc1nc(-c2ccccc2)nc(-c2ccccc2)n1] | 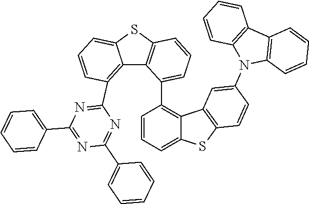 [SMILES: c1ccc(-c2nc(-c3ccccc3)nc(-c3cccc4sc5cccc(-c6cccc7sc8ccc(-n9c%10ccccc%10c%10ccccc%109)cc8c67)c5c34)n2)cc1] |
| 4-270 | 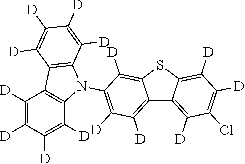 [SMILES: [2H]c1c(Cl)c([2H])c2c(sc3c([2H])c(-n4c5c([2H])c([2H])c([2H])c([2H])c5c5c([2H])c([2H])c([2H])c([2H])c54)c([2H])c([2H])c32)c1[2H]] | 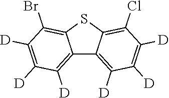 [SMILES: [2H]c1c([2H])c([2H])c2c(sc3c(Br)c([2H])c([2H])c([2H])c32)c1Cl] | 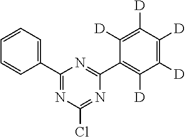 [SMILES: [2H]c1c([2H])c([2H])c(-c2nc(Cl)nc(-c3ccccc3)n2)c([2H])c1[2H]] | 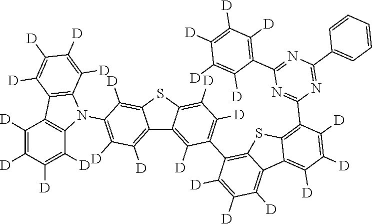 [SMILES: [2H]c1c([2H])c([2H])c(-c2nc(-c3ccccc3)nc(-c3c([2H])c([2H])c([2H])c4c3sc3c(-c5c([2H])c([2H])c6sc7c([2H])c(-n8c9c([2H])c([2H])c([2H])c([2H])c9c9c([2H])c([2H])c([2H])c([2H])c98)c([2H])c([2H])c7c6c5[2H])c([2H])c([2H])c([2H])c34)n2)c([2H])c1[2H]] |
| 4-279 | 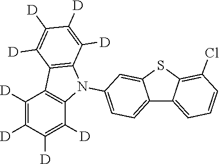 [SMILES: [2H]c1c([2H])c([2H])c2c(c1[2H])c1c([2H])c([2H])c([2H])c([2H])c1n2-c1ccc2c(c1)sc1c(Cl)cccc12] | 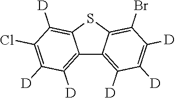 [SMILES: [2H]c1c([2H])c([2H])c2c(sc3c([2H])c(Cl)c([2H])c([2H])c32)c1Br] | 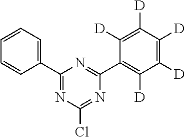 [SMILES: [2H]c1c([2H])c([2H])c(-c2nc(Cl)nc(-c3ccccc3)n2)c([2H])c1[2H]] | 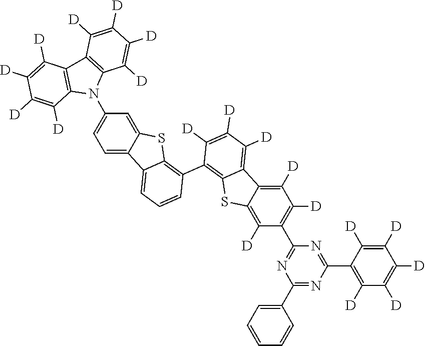 [SMILES: [2H]c1c([2H])c([2H])c(-c2nc(-c3ccccc3)nc(-c3c([2H])c([2H])c4c(sc5c(-c6cccc7c6sc6cc(-n8c9c([2H])c([2H])c([2H])c([2H])c9c9c([2H])c([2H])c([2H])c([2H])c98)ccc67)c([2H])c([2H])c([2H])c54)c3[2H])n2)c([2H])c1[2H]] |
| 4-287 | 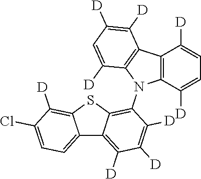 [SMILES: [2H]c1cc([2H])c2c(c1[2H])c1c([2H])ccc([2H])c1n2-c1c([2H])c([2H])c([2H])c2c1sc1c([2H])c(Cl)ccc12] | 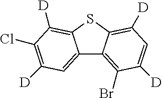 [SMILES: [2H]c1cc2c(sc3c([2H])cc([2H])c(Br)c32)c([2H])c1Cl] | 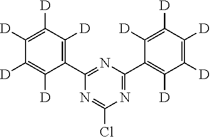 [SMILES: [2H]c1c([2H])c([2H])c(-c2nc(Cl)nc(-c3c([2H])c([2H])c([2H])c([2H])c3[2H])n2)c([2H])c1[2H]] | 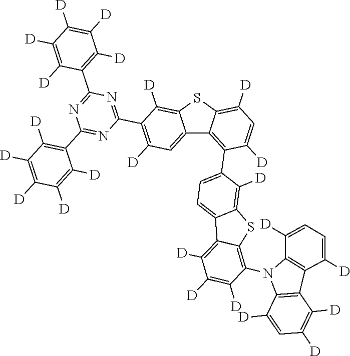 [SMILES: [2H]c1cc2c(sc3c([2H])cc([2H])c(-c4ccc5c(sc6c(-n7c8c([2H])ccc([2H])c8c8c([2H])c([2H])cc([2H])c87)c([2H])c([2H])c([2H])c65)c4[2H])c32)c([2H])c1-c1nc(-c2c([2H])c([2H])c([2H])c([2H])c2[2H])nc(-c2c([2H])c([2H])c([2H])c([2H])c2[2H])n1] |
| 4-298 | 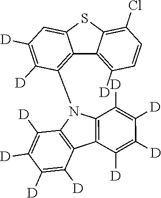 [SMILES: [2H]c1cc2sc3c(Cl)ccc([2H])c3c2c(-n2c3c([2H])c([2H])c([2H])c([2H])c3c3c([2H])c([2H])c([2H])c([2H])c32)c1[2H]] | 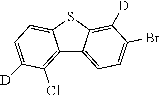 [SMILES: [2H]c1ccc2sc3c([2H])c(Br)ccc3c2c1Cl] | 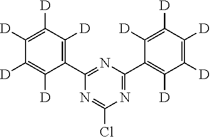 [SMILES: [2H]c1c([2H])c([2H])c(-c2nc(Cl)nc(-c3c([2H])c([2H])c([2H])c([2H])c3[2H])n2)c([2H])c1[2H]] | 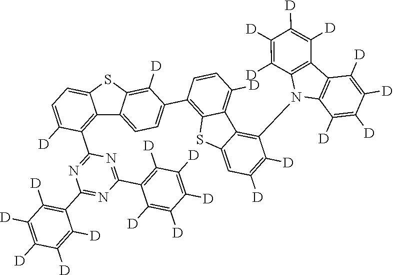 [SMILES: [2H]c1cc2sc3c(-c4ccc5c(sc6ccc([2H])c(-c7nc(-c8c([2H])c([2H])c([2H])c([2H])c8[2H])nc(-c8c([2H])c([2H])c([2H])c([2H])c8[2H])n7)c65)c4[2H])ccc([2H])c3c2c(-n2c3c([2H])c([2H])c([2H])c([2H])c3c3c([2H])c([2H])c([2H])c([2H])c32)c1[2H]] |
| 4-302 | 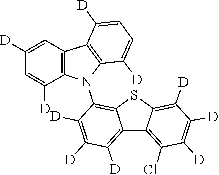 [SMILES: [2H]c1cc([2H])c2c(c1)c1c([2H])ccc([2H])c1n2-c1c([2H])c([2H])c([2H])c2c1sc1c([2H])c([2H])c([2H])c(Cl)c12] | 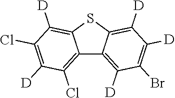 [SMILES: [2H]c1c(Br)c([2H])c2c(sc3c([2H])c(Cl)c([2H])c(Cl)c32)c1[2H]] | 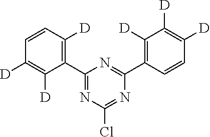 [SMILES: [2H]c1ccc(-c2nc(Cl)nc(-c3c([2H])ccc([2H])c3[2H])n2)c([2H])c1[2H]] | 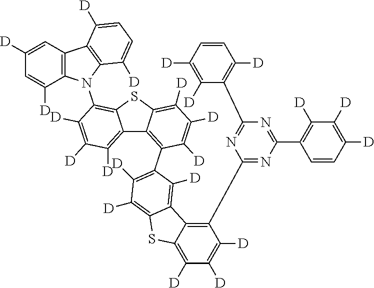 [SMILES: [2H]c1cc([2H])c2c(c1)c1c([2H])ccc([2H])c1n2-c1c([2H])c([2H])c([2H])c2c1sc1c([2H])c([2H])c([2H])c(-c3c([2H])c([2H])c4sc5c([2H])c([2H])c([2H])c(-c6nc(-c7ccc([2H])c([2H])c7[2H])nc(-c7c([2H])ccc([2H])c7[2H])n6)c5c4c3[2H])c12] |

It was confirmed by ¹H-NMR and FD-mass spectrometry that the compound synthesized in Preparation Example 1 was synthesized into the desired compound. The measured values of ¹H NMR (CDCl₃, 400 MHz) are shown in the following Table 2, and the measured values of field desorption mass spectrometry (FD-Mass) are shown in the following Table 3.

TABLE 2

| Compound | |
|---|---|
| No. | ¹H NMR (CDCl₃, 400 Mz) |
| 1-1 | δ = 8.55(1H, s), 8.36(4H, d), 8.19(1H, d), |
| | 8.08(3H, d), 8.02(2H, d), 7.94(2H, d), 7.88(1H, d), |
| | 7.58(1H, d), 7.51(3H, d), 7.5(7H, dd), 7.46(1H, d), |
| | 7.35(1H, d), 7.31(1H, dd), 7.2(1H, dd), 7.16(1H, s), |
| 1-18 | δ = 8.55(1H, s), 8.36(4H, d), 8.19(1H, d), |
| | 8.08(2H, d), 8.03(1H, d), 8.02(1H, d), 7.98(1H, d), |
| | 7.94(1H, d), 7.88(1H, d), 7.82(1H, dd), 7.76(1H, d), |
| | 7.58(1H, d), 7.54(1H, dd), 7.51(2H, dd), 7.5(7H, s), |
| | 7.35 (1H, t), 7.25 (1H, t), 7.2 (1H, dd), 7.16 |
| | (1H, dd), |
| 1-28 | δ = 8.55(1H, s), 8.36(4H, d), 8.19(1H, d), |
| | 8.08(1H, d), 8.03(1H, d), 7.94(1H, d), 7.88(2H, d), |
| | 7.83(1H, d), 7.82(1H, d), 7.79(1H, dd), 7.76(1H, d), |
| | 7.58(1H, d), 7.55(1H, dd), 7.52(1H, dd), 7.51(1H, s), |
| | 7.5 (7H, t), 7.35 (1H, t), 7.25 (1H, dd), 7.2 |
| | (1H, dd), 7.16 (1H, t), |
| 1-38 | δ = 8.55(1H, s), 8.36(4H, d), 8.19(1H, d), |
| | 8.08(1H, d), 8.03(1H, d), 7.98(1H, d), 7.94(1H, d), |
| | 7.88(2H, d), 7.83(1H, d), 7.82(1H, dd), 7.79(1H, d), |
| | 7.76(1H, d), 7.58(1H, dd), 7.54(1H, dd), 7.51(1H, s), |
| | 7.5 (7H, t), 7.35 (1H, t), 7.25 (1H, dd), 7.2 |
| | (1H, dd), 7.16 (1H, t), |
| 1-44 | δ = 8.55(1H, s), 8.36(4H, d), 8.19(1H, d), |
| | 8.08(1H, d), 7.94(1H, d), 7.88(3H, d), 7.83(2H, d), |
| | 7.79(2H, d), 7.58(1H, d), 7.55(1H, dd), 7.52(1H, d), |
| | 7.51(1H, d), 7.5(7H, dd), 7.35(1H, dd), 7.25(1H, s), |
| | 7.2 (1H, t), 7.16 (1H, t), |
| 1-56 | δ = 8.55(1H, s), 8.36(4H, d), 8.19(1H, d), |
| | 8.08(1H, d), 8.03(1H, d), 7.94(1H, d), 7.88(1H, d), |
| | 7.82(2H, d), 7.76(1H, d), 7.69(1H, dd), 7.58(1H, d), |
| | 7.57(1H, d), 7.55(1H, dd), 7.52(1H, dd), 7.51(1H, s), |
| | 7.5 (7H, t), 7.35 (1H, t), 7.25 (1H, dd), 7.2 |
| | (1H, dd), 7.16 (1H, t), |
| 1-63 | δ = 8.55(1H, s), 8.36(4H, d), 8.19(1H, d), |
| | 8.08(1H, d), 7.94(1H, d), 7.88(1H, d), 7.82(2H, d), |
| | 7.74(1H, d), 7.69(2H, d), 7.61(1H, dd), 7.58(1H, d), |
| | 7.57(2H, d), 7.51(1H, dd), 7.5(7H, dd), 7.35(1H, s), |
| | 7.31 (1H, t), 7.2 (1H, t), 7.16 (1H, dd), |
| 1-79 | δ = 8.55(1H, s), 8.36(4H, d), 8.19(1H, d), |
| | 8.08(1H, d), 8.03(1H, d), 8.02(1H, d), 7.94(1H, d), |
| | 7.82(2H, d), 7.76(1H, d), 7.74(1H, dd), 7.69(1H, d), |
| | 7.61(1H, d), 7.58(1H, dd), 7.57(1H, dd), 7.51(1H, s), |
| | 7.5 (7H, t), 7.35 (1H, t), 7.31 (1H, dd), 7.2 |
| | (1H, dd), 7.16 (1H, t), |
| 1-83 | δ = 8.55(1H, s), 8.36(4H, d), 8.19(1H, d), |
| | 8.08(1H, d), 8.03(2H, d), 8.02(1H, d), 7.94(1H, d), |
| | 7.82(2H, d), 7.76(2H, d), 7.74(1H, dd), 7.61(1H, d), |
| | 7.58(1H, d), 7.51(1H, dd), 7.5(7H, dd), 7.35(1H, s), |
| | 7.31 (1H, t), 7.2 (1H, t), 7.16 (1H, dd), |
| 1-97 | δ = 8.55(1H, s), 8.36(4H, d), 8.19(1H, d), |
| | 8.08(1H, d), 8.03(1H, d), 8.02(1H, d), 7.94(2H, d), |
| | 7.88(1H, d), 7.83(1H, d), 7.82(1H, dd), 7.79(1H, d), |
| | 7.76(1H, d), 7.58(1H, dd), 7.51(1H, dd), 7.5(7H, s), |
| | 7.46 (1H, t), 7.35 (1H, t), 7.31 (1H, dd), 7.2 |
| | (1H, dd), 7.16 (1H, t), |
| 1-105 | δ = 8.55(1H, s), 8.36(4H, d), 8.19(1H, d), |
| | 8.03(1H, d), 7.94(2H, d), 7.88(2H, d), 7.83(2H, d), |
| | 7.82(1H, d), 7.79(2H, d), 7.76(1H, dd), 7.58(1H, d), |
| | 7.5(7H, d), 7.46(1H, dd), 7.35(1H, dd), 7.31(1H, s), |
| | 7.2 (1H, t), 7.16 (1H, t), |
| 1-117 | δ = 8.55(1H, s), 8.36(4H, d), 8.19(1H, d), |
| | 8.03(2H, d), 7.94(2H, d), 7.82(3H, d), 7.76(2H, d), |
| | 7.69(1H, d), 7.58(1H, d), 7.57(1H, dd), 7.5(7H, d), |
| | 7.46(1H, d), 7.35(1H, dd), 7.31(1H, dd), |
| | 7.2(1H, s), 7.16 (1H, t), |
| 1-123 | δ = 8.55(1H, s), 8.36(4H, d), 8.19(1H, d), |
| | 8.03(1H, d), 7.94(1H, d), 7.88(1H, d), 7.83(1H, d), |
| | 7.82(2H, d), 7.79(1H, d), 7.76(1H, dd), 7.69(1H, d), |
| | 7.58(1H, d), 7.57(1H, dd), 7.55(1H, dd), |
| | 7.52(1H, s), 7.5 (7H, t), 7.35 (1H, t), 7.25 |
| | (1H, dd), 7.2 (1H, dd), 7.16 (1H, t), |
| 1-134 | δ = 8.55(1H, s), 8.36(4H, d), 8.19(1H, d), |
| | 8.08(1H, d), 8.03(1H, d), 8.02(1H, d), 7.98(1H, d), |
| | 7.94(1H, d), 7.88(1H, d), 7.83(1H, dd), 7.82(1H, d), |
| | 7.79(1H, d), 7.76(1H, dd), 7.58(1H, dd), 7.54(1H, s), |
| | 7.51 (1H, t), 7.5 (7H, t), 7.35 (1H, dd), 7.25 |
| | (1H, dd), 7.2 (1H, t), 7.16 (1H, d), |
| 1-144 | δ = 8.55(1H, s), 8.36(4H, d), 8.19(1H, d), |
| | 8.08(1H, d), 8.02(1H, d), 7.94(1H, d), 7.88(1H, d), |
| | 7.83(1H, d), 7.82(1H, d), 7.79(1H, dd), 7.69(1H, d), |
| | 7.58(1H, d), 7.57(1H, dd), 7.55(1H, dd), |
| | 7.52(1H, s), 7.51 (1H, t), 7.5 (7H, t), 7.35 |
| | (1H, dd), 7.25 (1H, dd), 7.2 (1H, t), 7.16 (1H, d), |
| 1-157 | δ = 8.55(1H, s), 8.36(4H, d), 8.19(1H, d), |
| | 8.03(1H, d), 7.94(2H, d), 7.88(1H, d), 7.83(1H, d), |
| | 7.82(2H, d), 7.79(1H, d), 7.76(1H, dd), 7.69(1H, d), |
| | 7.58(1H, d), 7.57(1H, dd), 7.5(7H, dd), 7.46(1H, s), |
| | 7.35 (1H, t), 7.31 (1H, t), 7.2 (1H, dd), 7.16 |
| | (1H, dd), |
| 1-163 | δ = 8.55(1H, s), 8.36(4H, d), 8.19(1H, d), |
| | 8.08(1H, d), 8.02(1H, d), 7.94(1H, d), 7.88(2H, d), |
| | 7.83(2H, d), 7.79(2H, d), 7.74(1H, dd), 7.61(1H, d), |
| | 7.58(1H, d), 7.51(1H, dd), 7.5(7H, dd), 7.35(1H, s), |
| | 7.31 (1H, t), 7.2 (1H, t), 7.16 (1H, dd), |
| 1-178 | δ = 8.55(1H, s), 8.36(4H, d), 8.19(1H, d), |
| | 8.08(1H, d), 8.02(1H, d), 7.98(1H, d), 7.94(1H, d), |
| | 7.88(1H, d), 7.83(1H, d), 7.82(1H, dd), 7.79(1H, d), |
| | 7.69(1H, d), 7.58(1H, dd), 7.57(1H, dd), 7.54(1H, s), |
| | 7.51 (1H, t), 7.5 (7H, t), 7.35 (1H, dd), 7.25 |
| | (1H, dd), 7.2 (1H, t), 7.16 (1H, d), |
| 1-181 | δ = 8.55(1H, s), 8.36(4H, d), 8.19(1H, d), |
| | 8.03(1H, d), 7.94(2H, d), 7.88(1H, d), 7.83(1H, d), |
| | 7.82(2H, d), 7.79(1H, d), 7.76(1H, dd), 7.69(1H, d), |
| | 7.58(1H, d), 7.57(1H, dd), 7.5(7H, dd), 7.46(1H, s), |
| | 7.35 (1H, t), 7.31 (1H, t), 7.2 (1H, dd), 7.16 |
| | (1H, dd), |
| 1-197 | δ = 8.55(1H, s), 8.36(4H, d), 8.19(1H, d), |
| | 8.08(1H, d), 8.03(1H, d), 8.02(1H, d), 7.94(2H, d), |
| | 7.82(2H, d), 7.76(1H, d), 7.69(1H, dd), 7.58(1H, d), |
| | 7.57(1H, d), 7.51(1H, dd), 7.5(7H, dd), 7.46(1H, s), |
| | 7.35 (1H, t), 7.31 (1H, t), 7.2 (1H, dd), 7.16 |
| | (1H, dd), |
| 1-206 | δ = 8.55(1H, s), 8.36(4H, d), 8.19(1H, d), |
| | 8.08(1H, d), 8.02(1H, d), 7.98(1H, d), 7.94(1H, d), |
| | 7.82(2H, d), 7.69(2H, d), 7.58(1H, dd), 7.57(2H, d), |
| | 7.54(1H, d), 7.51(1H, dd), 7.5(7H, dd), 7.35(1H, s), |
| | 7.25 (1H, t), 7.2 (1H, t), 7.16 (1H, dd), |
| 1-216 | δ = 8.55(1H, s), 8.36(4H, d), 8.19(1H, d), |
| | 8.03(2H, d), 7.94(1H, d), 7.82(3H, d), 7.76(2H, d), |
| | 7.69(1H, d), 7.58(1H, d), 7.57(1H, dd), 7.55(1H, d), |
| | 7.52(1H, d), 7.5(7H, dd), 7.35(1H, dd), |
| | 7.25(1H, s), 7.2 (1H, t), 7.16 (1H, t), |
| 1-232 | δ = 8.55(1H, s), 8.36(4H, d), 8.19(1H, d), |
| | 8.03(1H, d), 7.94(1H, d), 7.88(1H, d), 7.83(1H, d), |
| | 7.82(2H, d), 7.79(1H, d), 7.76(1H, dd), 7.69(1H, d), |
| | 7.58(1H, d), 7.57(1H, dd), 7.55(1H, dd), 7.52(1H, s), |
| | 7.5 (7H, t), 7.35 (1H, t), 7.25 (1H, dd), 7.2 |
| | (1H, dd), 7.16 (1H, t), |
| 1-238 | δ = 8.55(1H, s), 8.36(4H, d), 8.19(1H, d), |
| | 7.98(1H, d), 7.94(1H, d), 7.88(1H, d), 7.83(1H, d), |
| | 7.82(2H, d), 7.79(1H, d), 7.69(2H, dd), 7.58(1H, d), |
| | 7.57(2H, d), 7.54(1H, dd), 7.5(7H, dd), 7.35(1H, s), |
| | 7.25 (1H, t), 7.2 (1H, t), 7.16 (1H, dd), |
| 1-249 | δ = 8.55(1H, s), 8.36(4H, d), 8.19(1H, d), |
| | 7.94(2H, d), 7.88(1H, d), 7.83(1H, d), 7.82(2H, d), |
| | 7.79(1H, d), 7.69(2H, d), 7.58(1H, dd), 7.57(2H, d), |
| | 7.5(7H, d), 7.46(1H, dd), 7.35(1H, dd), 7.31(1H, s), |
| | 7.2 (1H, t), 7.16 (1H, t), |
| 1-255 | δ = 8.55(1H, s), 8.36(4H, d), 8.19(1H, d), |
| | 7.94(1H, d), 7.82(3H, d), 7.74(1H, d), 7.69(3H, d), |
| | 7.61(1H, d), 7.58(1H, d), 7.57(3H, dd), 7.5(7H, d), |
| | 7.35(1H, d), 7.31(1H, dd), 7.2(1H, dd), 7.16(1H, s), |
| 1-260 | δ = 8.55(1H, s), 8.36(4H, d), 8.03(2H, d), |
| | 7.94(1H, d), 7.91(1H, d), 7.82(3H, d), 7.79(2H, d), |
| | 7.76(2H, d), 7.74(1H, d), 7.69(1H, dd), 7.68(1H, d), |
| | 7.61(1H, d), 7.57(1H, dd), 7.56(1H, dd), 7.5(6H, s), |
| | 7.46 (2H, t), 7.41 (1H, t), 7.35 (1H, dd), 7.31 |
| | (1H, dd), 7.16 (1H, t), |
| 1-264 | δ = 8.55(1H, s), 8.45(1H, d), 8.36(4H, d), |
| | 8.05(1H, d), 8.03(1H, d), 7.94(1H, d), 7.93(1H, d), |
| | 7.88(1H, d), 7.83(1H, d), 7.82(2H, dd), 7.79(1H, d), |
| | 7.76(1H, d), 7.74(1H, dd), 7.69(1H, dd), |
| | 7.61(1H, s), 7.6 (1H, t), 7.57 (1H, t), 7.56 (1H, dd), |
| | 7.5 (6H, dd), 7.49 (1H, t), 7.35 (1H, d), 7.31 (1H, d), |
| | 7.16 (1H, d), |
| 1-272 | δ = 8.36(4H, s), 7.5(6H, d), |
| 1-273 | δ = 8.55(1H, s), 8.19(1H, d), 8.08(2H, d), |
| | 8.02(1H, d), 7.94(1H, d), 7.88(2H, d), 7.83(1H, d), |
| | 7.79(1H, d), 7.74(1H, d), 7.61(1H, dd), 7.58(1H, d), |
| | 7.51(2H, d), 7.5(1H, dd), 7.35(1H, dd), 7.31(1H, s), |
| | 7.2 (1H, t), 7.16 (1H, t), |
| 1-277 | δ = 7.94(1H, s), 7.88(1H, d), 7.83(1H, d), |
| | 7.79(1H, d), 7.46(1H, d), 7.31(1H, d), |
| 1-279 | δ = 8.55(1H, s), 8.36(4H, d), 8.19(1H, d), |
| | 7.94(1H, d), 7.58(1H, d), 7.5(7H, d), 7.35(1H, d), |
| | 7.2(1H, d), 7.16(1H, d), |
| 1-283 | δ = 8.36(4H, s), 8.08(1H, d), 8.02(1H, d), |
| | 7.96(1H, d), 7.74(1H, d), 7.61(1H, d), 7.51(1H, d), |
| | 7.5(6H, d), 7.31(1H, d), |
| 1-292 | δ = 8.55(1H, s), 8.36(4H, d), 8.19(1H, d), |
| | 8.03(1H, d), 7.94(1H, d), 7.88(1H, d), 7.83(1H, d), |
| | 7.82(1H, d), 7.79(1H, d), 7.76(1H, dd), 7.58(1H, d), |
| | 7.55(1H, d), 7.5(7H, dd), 7.35(1H, dd), 7.2(1H, s), |
| | 7.16 (1H, t), |
| 1-298 | δ = 7.81(1H, s), 7.77(1H, d), 7.75(1H, d), |
| | 7.54(1H, d), 7.43(1H, d), |
| 2-2 | δ = 8.55(3H, s), 8.36(4H, d), 8.32(1H, d), |
| | 8.19(1H, d), 8.08(1H, d), 8.02(1H, d), 7.98(1H, d), |
| | 7.94(1H, d), 7.92(1H, d), 7.7(2H, dd), 7.58(1H, d), |
| | 7.54(1H, d), 7.51(1H, dd), 7.5(7H, dd), 7.35(1H, s), |
| | 7.25 (1H, t), 7.2 (1H, t), 7.16 (1H, dd), |
| 2-30 | δ = 8.55(2H, s), 8.36(4H, d), 8.24(1H, d), |
| | 8.2(1H, d), 8.19(1H, d), 8.17(1H, d), 7.98(1H, d), |
| | 7.94(1H, d), 7.92(1H, d), 7.82(1H, dd), 7.7(1H, d), |
| | 7.69(1H, d), 7.58(1H, dd), 7.57(1H, dd), 7.54(1H, s), |
| | 7.5 (7H, t), 7.35 (1H, t), 7.25 (1H, dd), 7.2 (1H, dd), |
| | 7.16 (1H, t), |
| 2-58 | δ = 8.55(2H, s), 8.36(4H, d), 8.19(1H, d), |
| | 8.03(1H, d), 7.98(1H, d), 7.94(2H, d), 7.92(1H, d), |
| | 7.88(1H, d), 7.83(1H, d), 7.79(1H, dd), 7.7(1H, d), |
| | 7.68(1H, d), 7.58(1H, dd), 7.54(1H, dd), 7.5(7H, s), |
| | 7.35 (1H, t), 7.25 (1H, t), 7.2 (1H, dd), 7.16 (1H, dd), |
| 2-72 | δ = 8.55(2H, s), 8.36(4H, d), 8.32(1H, d), |
| | 8.24(1H, d), 8.2(1H, d), 8.19(1H, d), 8.03(1H, d), |
| | 7.94(2H, d), 7.82(1H, d), 7.76(1H, dd), 7.7(1H, d), |
| | 7.58(1H, d), 7.55(1H, dd), 7.52(1H, dd), 7.5(7H, s), |
| | 7.35 (1H, t), 7.25 (1H, t), 7.2 (1H, dd), 7.16 (1H, dd), |
| 2-94 | δ = 8.55(1H, s), 8.36(4H, d), 8.24(2H, d), |
| | 8.2(2H, d), 8.19(1H, d), 8.17(1H, d), 7.98(1H, d), |
| | 7.94(2H, d), 7.82(1H, d), 7.69(1H, dd), 7.58(1H, d), |
| | 7.57(1H, d), 7.54(1H, dd), 7.5(7H, dd), 7.35(1H, s), |
| | 7.25 (1H, t), 7.2 (1H, t), 7.16 (1H, dd), |
| 2-115 | δ = 8.55(1H, s), 8.36(4H, d), 8.24(1H, d), |
| | 8.2(1H, d), 8.19(1H, d), 8.08(1H, d), 8.03(1H, d), |
| | 8.02(1H, d), 7.94(3H, d), 7.74(1H, dd), 7.68(1H, d), |
| | 7.61(1H, d), 7.58(1H, dd), 7.51(1H, dd), 7.5(7H, s), |
| | 7.35 (1H, t), 7.31 (1H, t), 7.2 (1H, dd), 7.16 (1H, dd), |
| 2-125 | δ = 8.55(1H, s), 8.36(4H, d), 8.24(1H, d), |
| | 8.2(1H, d), 8.19(1H, d), 8.03(1H, d), 7.94(4H, d), |
| | 7.82(1H, d), 7.69(1H, d), 7.68(1H, dd), 7.58(1H, d), |
| | 7.57(1H, d), 7.5(7H, dd), 7.46(1H, dd), 7.35(1H, s), |
| | 7.31 (1H, t), 7.2 (1H, t), 7.16 (1H, dd), |
| 2-152 | δ = 8.55(1H, s), 8.36(4H, d), 8.24(1H, d), |
| | 8.2(1H, d), 8.19(1H, d), 8.17(1H, d), 8.12(1H, d), |
| | 8.03(1H, d), 7.99(1H, d), 7.94(1H, dd), 7.92(1H, d), |
| | 7.82(1H, d), 7.76(1H, dd), 7.58(1H, dd), 7.55(1H, s), |
| | 7.52 (1H, t), 7.5 (7H, t), 7.35 (1H, dd), 7.25 (1H, dd), |
| | 7.2 (1H, t), 7.16 (1H, d), |
| 2-173 | δ = 8.55(1H, s), 8.36(4H, d), 8.19(1H, d), |
| | 8.12(3H, d), 7.99(2H, d), 7.94(2H, d), 7.92(1H, d), |
| | 7.82(1H, d), 7.69(1H, d), 7.58(1H, dd), 7.57(1H, d), |
| | 7.5(7H, d), 7.46(1H, dd), 7.35(1H, dd), 7.31(1H, s), |
| | 7.2 (1H, t), 7.16 (1H, t), |
| 2-191 | δ = 8.55(1H, s), 8.36(4H, d), 8.19(1H, d), |
| | 8.12(1H, d), 8.03(1H, d), 7.99(1H, d), 7.94(2H, d), |
| | 7.92(1H, d), 7.82(1H, d), 7.74(1H, dd), 7.69(1H, d), |
| | 7.68(1H, d), 7.61(1H, dd), 7.58(1H, dd), 7.57(1H, s), |
| | 7.5 (7H, t), 7.35 (1H, t), 7.31 (1H, dd), 7.2 (1H, dd), |
| | 7.16 (1H, t), |
| 2-210 | δ = 8.55(1H, s), 8.36(4H, d), 8.24(1H, d), |
| | 8.2(1H, d), 8.19(1H, d), 8.17(1H, d), 8.08(1H, d), |
| | 8.03(1H, d), 8.02(1H, d), 7.98(1H, dd), 7.94(2H, d), |
| | 7.68(1H, d), 7.58(1H, dd), 7.54(1H, dd), 7.51(1H, s), |
| | 7.5 (7H, t), 7.35 (1H, t), 7.25 (1H, dd), 7.2 (1H, dd), |
| | 7.16 (1H, t), |
| 2-235 | δ = 8.55(1H, s), 8.36(4H, d), 8.19(1H, d), |
| | 8.12(2H, d), 8.03(1H, d), 7.99(1H, d), 7.94(2H, d), |
| | 7.88(1H, d), 7.83(1H, d), 7.79(1H, dd), 7.74(1H, d), |
| | 7.68(1H, d), 7.61(1H, dd), 7.58(1H, dd), 7.5(7H, s), |
| | 7.35 (1H, t), 7.31 (1H, t), 7.2 (1H, dd), 7.16 (1H, dd), |
| 2-254 | δ = 8.55(1H, s), 8.36(4H, d), 8.19(1H, d), |
| | 8.03(2H, d), 7.98(1H, d), 7.94(3H, d), 7.82(1H, d), |
| | 7.69(1H, d), 7.68(2H, d), 7.58(1H, dd), 7.57(1H, d), |
| | 7.54(1H, d), 7.5(7H, dd), 7.35(1H, dd), 7.25(1H, s), |
| | 7.2 (1H, t), 7.16 (1H, t), |
| 2-274 | δ = 8.55(1H, s), 8.19(1H, d), 7.94(1H, d), |
| | 7.58(1H, d), 7.5(1H, d), 7.35(1H, d), 7.2(1H, d), |
| | 7.16(1H, d), |
| 2-279 | δ = 8.43(1H, s), 8.12(2H, d), 7.99(1H, d), |
| | 7.92(1H, d), 7.42(1H, d), 7.41(1H, d), |
| 2-285 | δ = 7.77(1H, s), 7.67(1H, d), 7.54(1H, d), |
| | 7.43(1H, d), |
| 3-6 | δ = 8.55(1H, s), 8.36(4H, d), 8.24(1H, d), |
| | 8.2(1H, d), 8.19(2H, d), 8.17(1H, d), 8.08(2H, d), |
| | 8.02(1H, d), 7.98(1H, d), 7.94(1H, dd), 7.88(1H, d), |
| | 7.58(1H, d), 7.51(2H, dd), 7.5(7H, dd), 7.45(1H, s), |
| | 7.35 (1H, t), 7.2 (1H, t), 7.16 (1H, dd), |
| 3-31 | δ = 8.55(1H, s), 8.36(4H, d), 8.19(1H, d), |
| | 8.1(1H, d), 8.08(1H, d), 8.03(2H, d), 7.94(2H, d), |
| | 7.9(1H, d), 7.88(1H, d), 7.82(1H, dd), 7.76(1H, d), |
| | 7.68(1H, d), 7.58(1H, dd), 7.51(1H, dd), 7.5(7H, s), |
| | 7.43 (1H, t), 7.35 (1H, t), 7.2 (1H, dd), 7.16 |
| | (1H, dd), |
| 3-53 | δ = 8.55(1H, s), 8.41(1H, d), 8.36(4H, d), |
| | 8.24(1H, d), 8.2(1H, d), 8.19(1H, d), 8.17(1H, d), |
| | 8.08(1H, d), 7.94(1H, d), 7.88(1H, dd), 7.82(1H, d), |
| | 7.69(1H, d) ,7.65(1H, dd), 7.58(1H, dd), 7.57(1H, s), |
| | 7.51 (1H, t), 7.5 (7H, t), 7.43 (1H, dd), 7.35 |
| | (1H, dd), 7.2 (1H, t), 7.16 (1H, d), |
| 3-67 | δ = 8.55(2H, s), 8.36(4H, d), 8.32(1H, d), |
| | 8.19(1H, d), 8.1(1H, d), 8.08(1H, d), 8.03(1H, d), |
| | 8.02(1H, d), 7.94(1H, d), 7.9(1H, dd), 7.82(1H, d), |
| | 7.76(1H, d), 7.7(1H, dd), 7.58(1H, dd), 7.51(1H, s), |
| | 7.5 (7H, t), 7.43 (1H, t), 7.35 (1H, dd), 7.2 |
| | (1H, dd), 7.16 (1H, t), |
| 3-94 | δ = 8.55(1H, s), 8.36(4H, d), 8.19(2H, d), |
| | 8.03(3H, d), 7.98(1H, d), 7.94(2H, d), 7.82(2H, d), |
| | 7.76(2H, d), 7.68(1H, d), 7.58(1H, dd), 7.5(7H, d), |
| | 7.45(1H, d), 7.35(1H, dd), 7.2(1H, dd), 7.16(1H, s), |
| 3-111 | δ = 8.55(1H, s), 8.36(4H, d), 8.19(1H, d), |
| | 8.1(1H, d), 8.03(2H, d), 7.94(2H, d), 7.9(1H, d), |
| | 7.88(1H, d), 7.83(1H, d), 7.82(1H, dd), 7.79(1H, d), |
| | 7.76(1H, d), 7.68(1H, dd), 7.58(1H, dd), 7.5(7H, s), |
| | 7.43 (1H, t), 7.35 (1H, t), 7.2 (1H, dd), 7.16 |
| | (1H, dd), |
| 3-129 | δ = 8.55(2H, s), 8.41(1H, d), 8.36(4H, d), |
| | 8.32(1H, d), 8.19(1H, d), 8.08(1H, d), 8.02(1H, d), |
| | 7.94(1H, d), 7.88(1H, d), 7.83(1H, dd), 7.79(1H, d), |
| | 7.7(1H, d), 7.65(1H, dd), 7.58(1H, dd), 7.51(1H, s), |
| | 7.5 (7H, t), 7.43 (1H, t), 7.35 (1H, dd), 7.2 |
| | (1H, dd), 7.16 (1H, t), |
| 3-154 | δ = 8.55(1H, s), 8.36(4H, d), 8.19(2H, d), |
| | 8.12(2H, d), 8.03(1H, d), 7.99(1H, d), 7.98(1H, d), |
| | 7.94(1H, d), 7.88(1H, d), 7.83(1H, dd), 7.82(1H, d), |
| | 7.79(1H, d), 7.76(1H, dd), 7.58(1H, dd), 7.5(7H, s), |
| | 7.45 (1H, t), 7.35 (1H, t), 7.2 (1H, dd), 7.16 (1H, dd), |
| 3-167 | δ = 8.55(1H, s), 8.36(4H, d), 8.24(1H, d), |
| | 8.2(1H, d), 8.19(1H, d), 8.17(1H, d), 8.1(1H, d), |
| | 7.94(1H, d), 7.9(1H, d), 7.88(2H, dd), 7.83(2H, d), |
| | 7.79(2H, d), 7.58(1H, dd), 7.5(7H, dd), 7.43(1H, s), |
| | 7.35 (1H, t), 7.2 (1H, t), 7.16 (1H, dd), |
| 3-194 | δ = 8.55(2H, s), 8.36(4H, d), 8.32(1H, d), |
| | 8.19(2H, d), 8.08(1H, d), 8.02(1H, d), 7.98(1H, d), |
| | 7.94(1H, d), 7.82(1H, d), 7.7(1H, dd), 7.69(1H, d), |
| | 7.58(1H, d), 7.57(1H, dd), 7.51(1H, dd), 7.5(7H, s), |
| | 7.45 (1H, t), 7.35 (1H, t), 7.2 (1H, dd), 7.16 |
| | (1H, dd), |
| 3-207 | δ = 8.55(1H, s), 8.36(4H, d), 8.19(1H, d), |
| | 8.1(1H, d), 8.08(1H, d), 8.03(1H, d), 8.02(1H, d), |
| | 7.94(2H, d), 7.9(1H, d), 7.82(1H, dd), 7.69(1H, d), |
| | 7.68(1H, d), 7.58(1H, dd), 7.57(1H, dd), 7.51(1H, s), |
| | 7.5 (7H, t), 7.43 (1H, t), 7.35 (1H, dd), 7.2 |
| | (1H, dd), 7.16 (1H, t), |
| 3-234 | δ = 8.55(1H, s), 8.36(4H, d), 8.19(2H, d), |
| | 8.12(2H, d), 7.99(1H, d), 7.98(1H, d), 7.94(1H, d), |
| | 7.88(1H, d), 7.83(1H, d), 7.82(1H, dd), 7.79(1H, d), |
| | 7.69(1H, d), 7.58(1H, dd), 7.57(1H, dd), 7.5(7H, s), |
| | 7.45 (1H, t), 7.35 (1H, t), 7.2 (1H, dd), 7.16 |
| | (1H, dd), |
| 3-255 | δ = 8.55(1H, s), 8.36(4H, d), 8.19(1H, d), |
| | 8.1(1H, d), 8.03(1H, d), 7.94(2H, d), 7.9(1H, d), |
| | 7.82(2H, d), 7.69(2H, d), 7.68(1H, dd), 7.58(1H, d), |
| | 7.57(2H, d), 7.5(7H, dd), 7.43(1H, dd), 7.35(1H, s), |
| | 7.2 (1H, t), 7.16 (1H, t), |
| 3-271 | δ = 8.28(1H, s), 7.77(1H, d), 7.67(1H, d), |
| | 7.54(1H, d), 7.52(1H, d), 7.43(1H, d), |
| 3-273 | δ = 7.77(1H, s), 7.67(1H, d), 7.52(2H, d), |
| | 7.5(1H, d), 7.45(1H, d), |
| 3-280 | δ = 8.36(2H, s), 7.77(1H, d), 7.52(1H, d), |
| | 7.5(4H, d), 7.45(1H, d), |
| 3-286 | δ = 8.03(1H, s), 7.82(2H, d), 7.76(1H, d), |
| | 7.69(1H, d), 7.57(1H, d), |
| 3-299 | δ = 8.55(1H, s), 8.12(1H, d), 7.94(1H, d), |
| | 7.82(1H, d), 7.42(1H, d), 7.35(1H, d), 7.16(1H, d), |
| 3-302 | δ = 7.95(1H, s), 7.84(1H, d), 7.81(1H, d), |
| | 7.67(1H, d), 7.61(1H, d), 7.52(1H, d), |
| 3-307 | δ = 8.55(1H, s), 8.13(1H, d), 8.08(1H, d), |
| | 8.03(1H, d), 7.97(1H, d), 7.94(1H, d), 7.88(1H, d), |
| | 7.77(1H, d), 7.67(1H, d), 7.58(1H, dd), 7.52(1H, d), |
| | 7.51(1H, d), 7.5(2H, dd), 7.45(1H, dd), 7.35(1H, s), |
| | 7.16 (1H, t), |
| 4-6 | δ = 8.55(3H, s), 8.36(4H, d), 8.32(1H, d), |
| | 8.24(1H, d), 8.2(1H, d), 8.19(2H, d), 8.17(1H, d), |
| | 7.98(1H, d), 7.94(1H, d), 7.92(1H, dd), 7.7(2H, d), |
| | 7.58(1H, d), 7.5(7H, dd), 7.45(1H, dd), 7.35(1H, s), |
| | 7.2 (1H, t), 7.16 (1H, t), |
| 4-31 | δ = 8.55(2H, s), 8.36(4H, d), 8.24(1H, d), |
| | 8.2(1H, d), 8.19(1H, d), 8.17(1H, d), 8.1(1H, d), |
| | 8.03(1H, d), 7.94(2H, d), 7.92(1H, dd), 7.9(1H, d), |
| | 7.7(1H, d), 7.68(1H, dd), 7.58(1H, dd), 7.5(7H, s), |
| | 7.43 (1H, t), 7.35 (1H, t), 7.2 (1H, dd), 7.16 |
| | (1H, dd), |
| 4-51 | δ = 8.55(3H, s), 8.36(4H, d), 8.32(1H, d), |
| | 8.19(1H, d), 8.1(1H, d), 8.03(1H, d), 7.94(2H, d), |
| | 7.92(1H, d), 7.9(1H, d), 7.7(2H, dd), 7.68(1H, d), |
| | 7.58(1H, d), 7.5(7H, dd), 7.43(1H, dd), 7.35(1H, s), |
| | 7.2 (1H, t), 7.16 (1H, t), |
| 4-78 | δ = 8.55(1H, s), 8.36(4H, d), 8.32(1H, d), |
| | 8.24(1H, d), 8.2(1H, d), 8.19(1H, d), 8.03(1H, d), |
| | 7.98(1H, d), 7.94(2H, d), 7.88(1H, dd), 7.72(1H, d), |
| | 7.7(1H, d), 7.68(1H, dd), 7.5(6H, dd), 7.45(2H, s), |
| | 6.85 (1H, t), 6.63 (1H, t), 5.89 (1H, dd), 5.44 |
| | (1H, dd), 2.37 (1H, t), |
| 4-94 | δ = 8.55(1H, s), 8.36(4H, d), 8.24(2H, d), |
| | 8.2(2H, d), 8.19(2H, d), 8.17(1H, d), 8.03(1H, d), |
| | 7.98(1H, d), 7.94(3H, d), 7.68(1H, dd), 7.58(1H, d), |
| | 7.5(7H, d), 7.45(1H, dd), 7.35(1H, dd), 7.2(1H, s), |
| | 7.16 (1H, t), |
| 4-114 | δ = 8.55(2H, s), 8.36(4H, d), 8.32(1H, d), |
| | 8.24(1H, d), 8.2(1H, d), 8.19(2H, d), 8.03(1H, d), |
| | 7.98(1H, d), 7.94(3H, d), 7.7(1H, dd), 7.68(1H, d), |
| | 7.58(1H, d), 7.5(7H, dd), 7.45(1H, dd), 7.35(1H, s), |
| | 7.2 (1H, t), 7.16 (1H, t), |
| 4-135 | δ = 8.55(2H, s), 8.36(4H, d), 8.32(1H, d), |
| | 8.24(1H, d), 8.2(1H, d), 8.19(1H, d), 8.17(1H, d), |
| | 8.12(1H, d), 8.1(1H, d), 7.99(1H, dd), 7.94(1H, d), |
| | 7.92(1H, d), 7.9(1H, dd), 7.7(1H, dd), 7.58(1H, s), |
| | 7.5 (7H, t), 7.43 (1H, t), 7.35 (1H, dd), 7.2 |
| | (1H, dd), 7.16 (1H, t), |
| 4-152 | δ = 8.55(1H, s), 8.36(4H, d), 8.24(2H, d), |
| | 8.2(2H, d), 8.19(1H, d), 8.17(2H, d), 8.12(1H, d), |
| | 7.99(1H, d), 7.94(1H, d), 7.92(1H, dd), 7.89(1H, d), |
| | 7.63(1H, d), 7.58(1H, dd), 7.5(7H, dd), 7.45(1H, s), |
| | 7.35 (1H, t), 7.2 (1H, t), 7.16 (1H, dd), |
| 4-171 | δ = 8.55(1H, s), 8.36(4H, d), 8.19(1H, d), |
| | 8.12(5H, d), 8.1(1H, d), 7.99(3H, d), 7.94(1H, d), |
| | 7.92(1H, d), 7.9(1H, d), 7.58(1H, dd), 7.5(7H, d), |
| | 7.43(1H, d), 7.35(1H, dd), 7.2(1H, dd), 7.16(1H, s), |
| 4-190 | δ = 8.55(1H, s), 8.36(4H, d), 8.19(2H, d), |
| | 8.12(1H, d), 8.03(2H, d), 7.99(1H, d), 7.98(1H, d), |
| | 7.94(3H, d), 7.92(1H, d), 7.68(2H, dd), 7.58(1H, d), |
| | 7.5(7H, d), 7.45(1H, dd), 7.35(1H, dd), 7.2(1H, s), |
| | 7.16 (1H, t), |
| 4-219 | δ = 8.55(1H, s), 8.36(4H, d), 8.24(1H, d), |
| | 8.2(1H, d), 8.19(1H, d), 8.17(1H, d), 8.12(2H, d), |
| | 8.1(1H, d), 8.03(1H, d), 7.99(1H, dd), 7.94(2H, d), |
| | 7.9(1H, d), 7.68(1H, dd), 7.58(1H, dd), 7.5(7H, s), |
| | 7.43 (1H, t), 7.35 (1H, t), 7.2 (1H, dd), 7.16 |
| | (1H, dd), |
| 4-227 | δ = 8.55(2H, s), 8.36(4H, d), 8.32(1H, d), |
| | 8.19(1H, d), 8.12(2H, d), 8.1(1H, d), 8.03(1H, d), |
| | 7.99(1H, d), 7.94(2H, d), 7.9(1H, dd), 7.7(1H, d), |
| | 7.68(1H, d) ,7.58(1H, dd), 7.5(7H, dd), 7.43(1H, s), |
| | 7.35 (1H, t), 7.2 (1H, t), 7.16 (1H, dd), |
| 4-255 | δ = 8.55(1H, s), 8.36(4H, d), 8.19(1H, d), |
| | 8.1(1H, d), 8.03(3H, d), 7.94(4H, d), 7.9(1H, d), |
| | 7.68(3H, d), 7.58(1H, d), 7.5(7H, dd), 7.43(1H, d), |
| | 7.35(1H, d), 7.2(1H, dd), 7.16(1H, dd), |
| 4-270 | δ = 8.36(2H, s), 7.5(3H, d), |
| 4-279 | δ = 8.55(1H, s), 8.36(2H, d), 8.32(1H, d), |
| | 8.19(1H, d), 7.98(1H, d), 7.7(1H, d), 7.5(3H, d), |
| | 7.45(1H, d), |
| 4-287 | δ = 8.24(1H, s), 8.1(1H, d), 7.94(1H, d), |
| | 7.63(1H, d), 7.5(1H, d), 7.49(1H, d), 7.41(1H, d), |
| 4-298 | δ = 8.24(1H, s), 8.06(1H, d), 7.95(1H, d), |
| | 7.94(1H, d), 7.92(1H, d), 7.65(1H, d), 7.63(1H, d), |
| 4-302 | δ = 7.96(1H, s), 7.77(1H, d), 7.52(2H, d), |
| | 7.5(1H, d), 7.49(1H, d), 7.43(1H, d), 7.42(1H, d), |

TABLE 3

| Compound | FD-MS |
|---|---|
| 1-1 | m/z = 730.24 (C51H30N4O2, |
| | 730.83) |
| 1-18 | m/z = 730.24 (C51H30N4O2, |
| | 730.83) |
| 1-28 | m/z = 730.24 (C51H30N4O2, |
| | 730.83) |
| 1-38 | m/z = 730.24 (C51H30N4O2, |
| | 730.83) |
| 1-44 | m/z = 730.24 (C51H30N4O2, |
| | 730.83) |
| 1-56 | m/z = 730.24 (C51H30N4O2, |
| | 730.83) |
| 1-63 | m/z = 730.24 (C51H30N4O2, |
| | 730.83) |
| 1-79 | m/z = 730.24 (C51H30N4O2, |
| | 730.83) |
| 1-83 | m/z = 730.24 (C51H30N4O2, |
| | 730.83) |
| 1-97 | m/z = 730.24 (C51H30N4O2, |
| | 730.83) |
| 1-105 | m/z = 730.24 (C51H30N4O2, |
| | 730.83) |
| 1-117 | m/z = 730.24 (C51H30N4O2, |
| | 730.83) |
| 1-123 | m/z = 730.24 (C51H30N4O2, |
| | 730.83) |
| 1-134 | m/z = 730.24 (C51H30N4O2, |
| | 730.83) |
| 1-144 | m/z = 730.24 (C51H30N4O2, |
| | 730.83) |
| 1-157 | m/z = 730.24 (C51H30N4O2, |
| | 730.83) |
| 1-163 | m/z = 730.24 (C51H30N4O2, |
| | 730.83) |
| 1-178 | m/z = 730.24 (C51H30N4O2, |
| | 730.83) |
| 1-181 | m/z = 730.24 (C51H30N4O2, |
| | 730.83) |
| 1-197 | m/z = 730.24 (C51H30N4O2, |
| | 730.83) |
| 1-206 | m/z = 730.24 (C51H30N4O2, |
| | 730.83) |
| 1-216 | m/z = 730.24 (C51H30N4O2, |
| | 730.83) |
| 1-232 | m/z = 730.24 (C51H30N4O2, |
| | 730.83) |
| 1-238 | m/z = 730.24 (C51H30N4O2, |
| | 730.83) |
| 1-249 | m/z = 730.24 (C51H30N4O2, |
| | 730.83) |
| 1-255 | m/z = 730.24 (C51H30N4O2, |
| | 730.83) |
| 1-260 | m/z = 806.27 (C57H34N4O2, |
| | 806.93) |
| 1-264 | m/z = 836.22 (C57H32N4O2S, |
| | 836.97) |
| 1-272 | m/z = 750.36 |
| | (C51H10D20N4O2, 750.95) |
| 1-273 | m/z = 740.30 |
| | (C51H20D10N4O2, 740.89) |
| 1-277 | m/z = 754.39 (C51H6D24N4O2, |
| | 754.97) |
| 1-279 | m/z = 742.31 |
| | (C51H18D12N4O2, 742.90) |
| 1-283 | m/z = 743.32 |
| | (C51H17D13N4O2, 743.91) |
| 1-292 | m/z = 735.27 (C51H25D5N4O2, |
| | 735.86) |
| 1-298 | m/z = 755.39 (C51H5D25N4O2, |
| | 755.98) |
| 2-2 | m/z = 746.21 (C51H30N4OS, |
| | 746.89) |
| 2-30 | m/z = 746.21 (C51H30N4OS, |
| | 746.89) |
| 2-58 | m/z = 746.21 (C51H30N4OS, |
| | 746.89) |
| 2-72 | m/z = 746.21 (C51H30N4OS, |
| | 746.89) |
| 2-94 | m/z = 746.21 (C51H30N4OS, |
| | 746.89) |
| 2-115 | m/z = 746.21 (C51H30N4OS, |
| | 746.89) |
| 2-125 | m/z = 746.21 (C51H30N4OS, |
| | 746.89) |
| 2-152 | m/z = 746.21 (C51H30N4OS, |
| | 746.89) |
| 2-173 | m/z = 746.21 (C51H30N4OS, |
| | 746.89) |
| 2-191 | m/z = 746.21 (C51H30N4OS, |
| | 746.89) |
| 2-210 | m/z = 746.21 (C51H30N4OS, |
| | 746.89) |
| 2-235 | m/z = 746.21 (C51H30N4OS, |
| | 746.89) |
| 2-254 | m/z = 746.21 (C51H30N4OS, |
| | 746.89) |
| 2-269 | m/z = 776.40 (C51D30N4OS, |
| | 777.07) |
| 2-274 | m/z = 4.768 (C51H8D22N4OS, |
| | 769.02) |
| 2-279 | m/z = 4.769 (C51H7D23N4OS, |
| | 770.03) |
| 2-285 | m/z = 4.772 (C51H4D26N4OS, |
| | 773.05) |
| 3-6 | m/z = 746.21 (C51H30N4OS, |
| | 746.89) |
| 3-31 | m/z = 746.21 (C51H30N4OS, |
| | 746.89) |
| 3-53 | m/z = 746.21 (C51H30N4OS, |
| | 746.89) |
| 3-67 | m/z = 746.21 (C51H30N4OS, |
| | 746.89) |
| 3-94 | m/z = 746.21 (C51H30N4OS, |
| | 746.89) |
| 3-111 | m/z = 746.21 (C51H30N4OS, |
| | 746.89) |
| 3-129 | m/z = 746.21 (C51H30N4OS, |
| | 746.89) |
| 3-154 | m/z = 746.21 (C51H30N4OS, |
| | 746.89) |
| 3-167 | m/z = 746.21 (C51H30N4OS, |
| | 746.89) |
| 3-194 | m/z = 746.21 (C51H30N4OS, |
| | 746.89) |
| 3-207 | m/z = 746.21 (C51H30N4OS, |
| | 746.89) |
| 3-234 | m/z = 746.21 (C51H30N4OS, |
| | 746.89) |
| 3-255 | m/z = 746.21 (C51H30N4OS, |
| | 746.89) |
| 3-271 | m/z = 770.36 (C51H6D24N4OS, |
| | 771.03) |
| 3-273 | m/z = 770.36 (C51H6D24N4OS, |
| | 771.03) |
| 3-280 | m/z = 767.35 (C51H9D21N4OS, |
| | 768.02) |
| 3-286 | m/z = 783.37 (C52H9D23N4OS, |
| | 784.06) |
| 3-299 | m/z = 769.36 (C51H7D23N4OS, |
| | 770.03) |
| 3-302 | m/z = 770.36 (C51H6D24N4OS, |
| | 771.03) |
| 3-307 | m/z = 759.30 |
| | (C51H17D13N4OS, 759.97) |
| 4-6 | m/z = 762.19 (C51H30N4S2, |
| | 762.95) |
| 4-31 | m/z = 762.19 (C51H30N4S2, |
| | 762.95) |
| 4-51 | m/z = 762.19 (C51H30N4S2, |
| | 762.95) |
| 4-78 | m/z = 762.19 (C51H30N4S2, |
| | 762.95) |
| 4-94 | m/z = 762.19 (C51H30N4S2, |
| | 762.95) |
| 4-114 | m/z = 762.19 (C51H30N4S2, |
| | 762.95) |
| 4-135 | m/z = 762.19 (C51H30N4S2, |
| | 762.95) |
| 4-152 | m/z = 762.19 (C51H30N4S2, |
| | 762.95) |
| 4-171 | m/z = 762.19 (C51H30N4S2, |
| | 762.95) |
| 4-190 | m/z = 762.19 (C51H30N4S2, |
| | 762.95) |
| 4-219 | m/z = 762.19 (C51H30N4S2, |
| | 762.95) |
| 4-227 | m/z = 762.19 (C51H30N4S2, |
| | 762.95) |
| 4-255 | m/z = 762.19 (C51H30N4S2, |
| | 762.95) |
| 4-270 | m/z = 787.35 (C51H5D25N4S2, |
| | 788.10) |
| 4-279 | m/z = 781.31 |
| | (C51H11D19N4S2, 782.06) |
| 4-287 | m/z = 785.34 (C51H7D23N4S2, |
| | 786.09) |
| 4-298 | m/z = 785.34 (C51H7D23N4S2, |
| | 786.09) |
| 4-302 | m/z = 784.33 (C51H8D22N4S2, |
| | 785.08) |

### <Preparation Example 2> Preparation of Compound 5-1

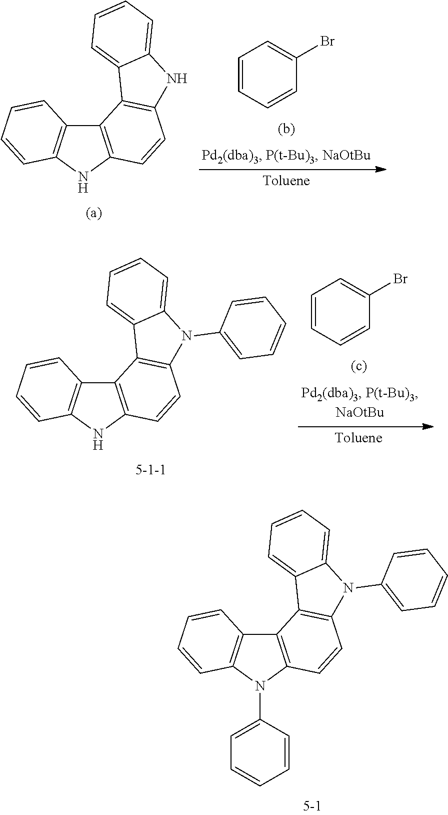

### 1) Preparation of Compound 5-1-1

After 10 g (39.0 mmol) of Compound (a) (5,8-dihydroindolo[2,3-c]carbazole), 6.12 g (39.0 mmol) of Compound (b) (1-bromobenzene), 1.79 g (1.95 mmol) of Pd₂(dba)₃, 0.92 mL (3.9 mmol) of P(t-Bu)₃, and 7.50 g (78.0 mmol) of NatOBu were put into a reaction flask, 100 mL of toluene was added thereto, and the resulting mixture was heated at 135° C. for 15 hours. When the reaction was terminated, the resulting product was extracted with methylene chloride (MC) and water, and then purified by column chromatography to obtain 7.3 g (yield 56%) of Compound 5-1-1.

### 2) Preparation of Compound 5-1

After 7.3 g (22.0 mmol) of Compound 5-1-1, 3.8 g (24.2 mmol) of Compound (c) (1-bromobenzene), 1.01 g (1.1 mmol) of Pd₂(dba)₃), 0.52 mL (3.9 mmol) of P(t-Bu)₃, and 4.23 g (44.0 mmol) of NatOBu were put into a reaction flask, 70 mL of toluene was added thereto, and the resulting mixture was heated at 135° C. for 15 hours. When the reaction was terminated, the resulting product was extracted with methylene chloride (MC) and water, and then purified by column chromatography to obtain 8.3 g (93%) of Compound 5-1.

The target compound in the following Table 4 was synthesized by preparation in the same manner as in Preparation Example 2, except that Intermediates A, B, and C in the following Table 4 were used instead of Compounds (a), (b), and (c) in Preparation Example 2.

TABLE 4

| | | | | Target |
|---|---|---|---|---|
| Compound | Intermediate A | Intermediate B | Intermediate C | Compound |
| 5-4 | 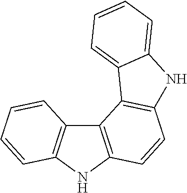 [SMILES: c1ccc2c(c1)[nH]c1ccc3[nH]c4ccccc4c3c12] | 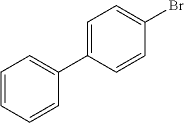 [SMILES: Brc1ccc(-c2ccccc2)cc1] | 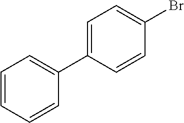 [SMILES: Brc1ccc(-c2ccccc2)cc1] | 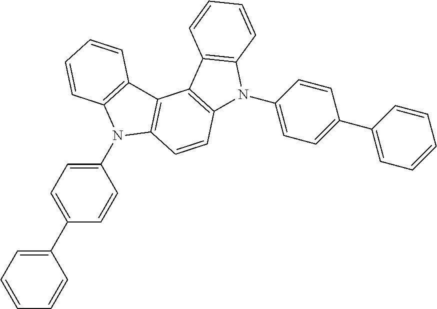 [SMILES: c1ccc(-c2ccc(-n3c4ccccc4c4c5c6ccccc6n(-c6ccc(-c7ccccc7)cc6)c5ccc43)cc2)cc1] |
| 5-5 | 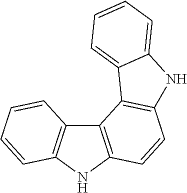 [SMILES: c1ccc2c(c1)[nH]c1ccc3[nH]c4ccccc4c3c12] | 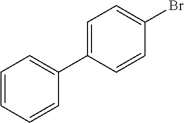 [SMILES: Brc1ccc(-c2ccccc2)cc1] | 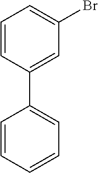 [SMILES: Brc1cccc(-c2ccccc2)c1] | 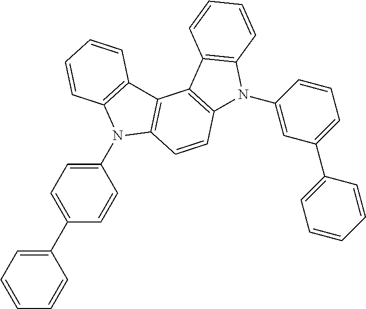 [SMILES: c1ccc(-c2ccc(-n3c4ccccc4c4c5c6ccccc6n(-c6cccc(-c7ccccc7)c6)c5ccc43)cc2)cc1] |
| 5-22 | 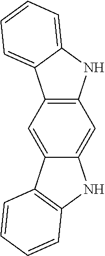 [SMILES: c1ccc2c(c1)[nH]c1cc3[nH]c4ccccc4c3cc12] | 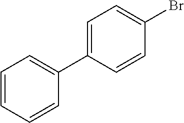 [SMILES: Brc1ccc(-c2ccccc2)cc1] | 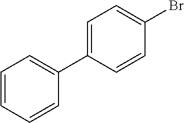 [SMILES: Brc1ccc(-c2ccccc2)cc1] | 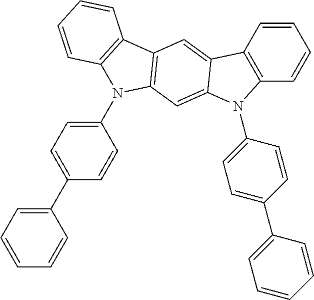 [SMILES: c1ccc(-c2ccc(-n3c4ccccc4c4cc5c6ccccc6n(-c6ccc(-c7ccccc7)cc6)c5cc43)cc2)cc1] |
| 5-23 | 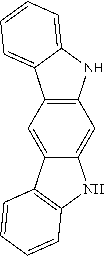 [SMILES: c1ccc2c(c1)[nH]c1cc3[nH]c4ccccc4c3cc12] | 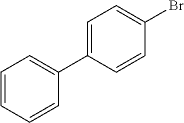 [SMILES: Brc1ccc(-c2ccccc2)cc1] | 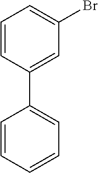 [SMILES: Brc1cccc(-c2ccccc2)c1] | 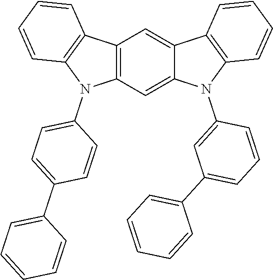 [SMILES: c1ccc(-c2ccc(-n3c4ccccc4c4cc5c6ccccc6n(-c6cccc(-c7ccccc7)c6)c5cc43)cc2)cc1] |
| 5-32 | 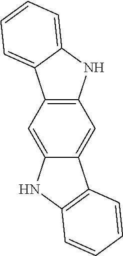 [SMILES: c1ccc2c(c1)[nH]c1cc3c(cc12)[nH]c1ccccc13] | 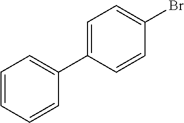 [SMILES: Brc1ccc(-c2ccccc2)cc1] | 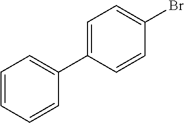 [SMILES: Brc1ccc(-c2ccccc2)cc1] | 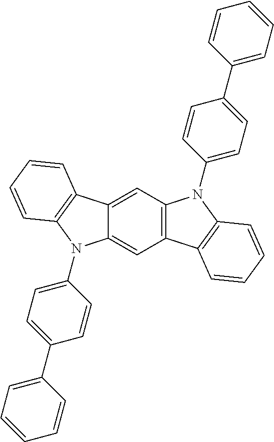 [SMILES: c1ccc(-c2ccc(-n3c4ccccc4c4cc5c(cc43)c3ccccc3n5-c3ccc(-c4ccccc4)cc3)cc2)cc1] |
| 5-35 | 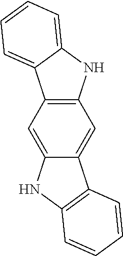 [SMILES: c1ccc2c(c1)[nH]c1cc3c(cc12)[nH]c1ccccc13] | 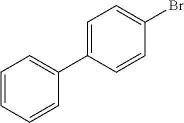 [SMILES: Brc1ccc(-c2ccccc2)cc1] | 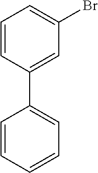 [SMILES: Brc1cccc(-c2ccccc2)c1] | 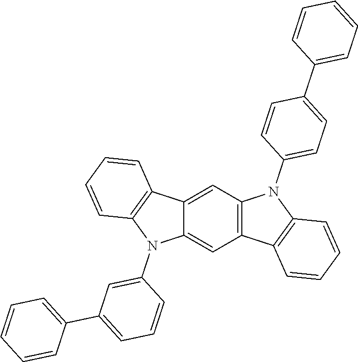 [SMILES: c1ccc(-c2ccc(-n3c4ccccc4c4cc5c(cc43)c3ccccc3n5-c3cccc(-c4ccccc4)c3)cc2)cc1] |
| 5-38 | 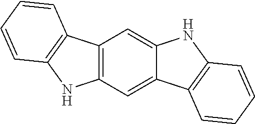 [SMILES: c1ccc2c(c1)[nH]c1cc3c(cc12)[nH]c1ccccc13] | 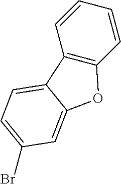 [SMILES: Brc1ccc2c(c1)oc1ccccc12] | 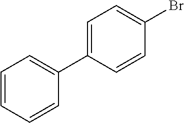 [SMILES: Brc1ccc(-c2ccccc2)cc1] | 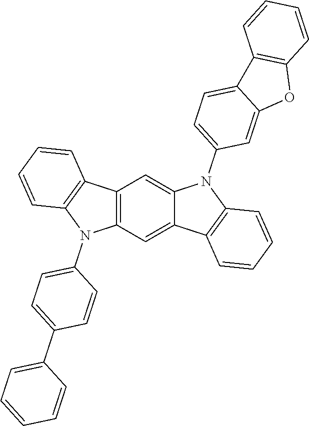 [SMILES: c1ccc(-c2ccc(-n3c4ccccc4c4cc5c(cc43)c3ccccc3n5-c3ccc4c(c3)oc3ccccc34)cc2)cc1] |
| 5-41 | 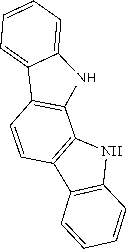 [SMILES: c1ccc2c(c1)[nH]c1c2ccc2c3ccccc3[nH]c21] | 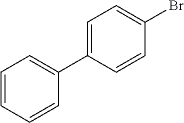 [SMILES: Brc1ccc(-c2ccccc2)cc1] | 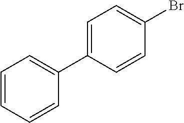 [SMILES: Brc1ccc(-c2ccccc2)cc1] | 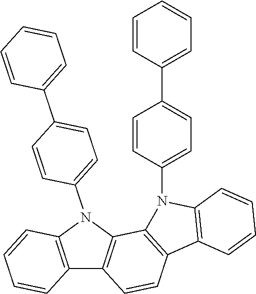 [SMILES: c1ccc(-c2ccc(-n3c4ccccc4c4ccc5c6ccccc6n(-c6ccc(-c7ccccc7)cc6)c5c43)cc2)cc1] |
| 5-49 | 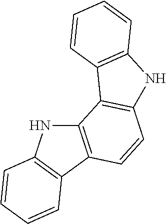 [SMILES: c1ccc2c(c1)[nH]c1c2ccc2[nH]c3ccccc3c21] | 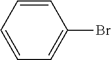 | 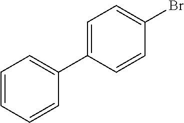 [SMILES: Brc1ccc(-c2ccccc2)cc1] | 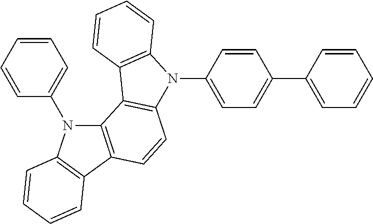 [SMILES: c1ccc(-c2ccc(-n3c4ccccc4c4c3ccc3c5ccccc5n(-c5ccccc5)c34)cc2)cc1] |
| 5-61 | 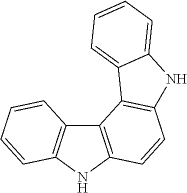 [SMILES: c1ccc2c(c1)[nH]c1ccc3[nH]c4ccccc4c3c12] | 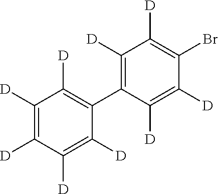 [SMILES: [2H]c1c([2H])c([2H])c(-c2c([2H])c([2H])c(Br)c([2H])c2[2H])c([2H])c1[2H]] | 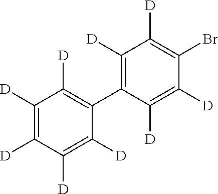 [SMILES: [2H]c1c([2H])c([2H])c(-c2c([2H])c([2H])c(Br)c([2H])c2[2H])c([2H])c1[2H]] | 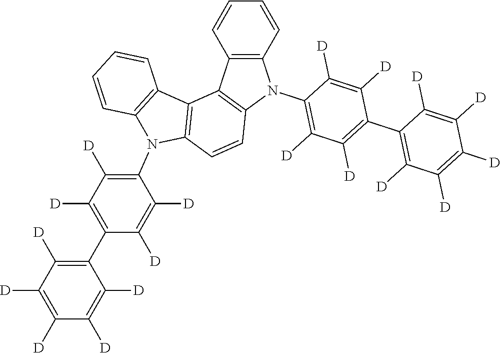 [SMILES: [2H]c1c([2H])c([2H])c(-c2c([2H])c([2H])c(-n3c4ccccc4c4c5c6ccccc6n(-c6c([2H])c([2H])c(-c7c([2H])c([2H])c([2H])c([2H])c7[2H])c([2H])c6[2H])c5ccc43)c([2H])c2[2H])c([2H])c1[2H]] |
| 5-69 | 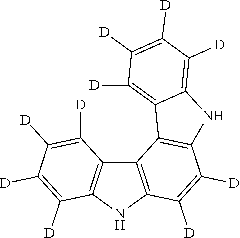 [SMILES: [2H]c1c([2H])c([2H])c2c([nH]c3c([2H])c([2H])c4[nH]c5c([2H])c([2H])c([2H])c([2H])c5c4c32)c1[2H]] | 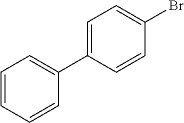 [SMILES: Brc1ccc(-c2ccccc2)cc1] | 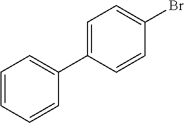 [SMILES: Brc1ccc(-c2ccccc2)cc1] | 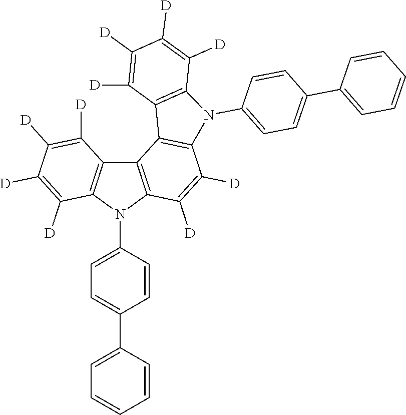 [SMILES: [2H]c1c([2H])c([2H])c2c(c1[2H])c1c3c4c([2H])c([2H])c([2H])c([2H])c4n(-c4ccc(-c5ccccc5)cc4)c3c([2H])c([2H])c1n2-c1ccc(-c2ccccc2)cc1] |
| 5-77 | 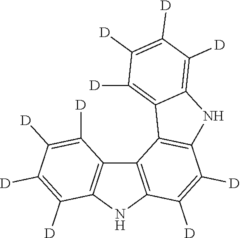 [SMILES: [2H]c1c([2H])c([2H])c2c([nH]c3c([2H])c([2H])c4[nH]c5c([2H])c([2H])c([2H])c([2H])c5c4c32)c1[2H]] | 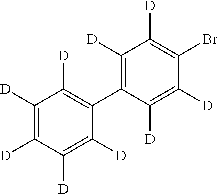 [SMILES: [2H]c1c([2H])c([2H])c(-c2c([2H])c([2H])c(Br)c([2H])c2[2H])c([2H])c1[2H]] | 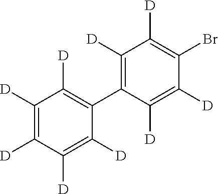 [SMILES: [2H]c1c([2H])c([2H])c(-c2c([2H])c([2H])c(Br)c([2H])c2[2H])c([2H])c1[2H]] | 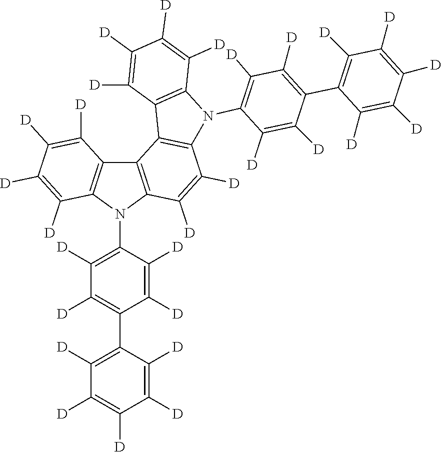 [SMILES: [2H]c1c([2H])c([2H])c(-c2c([2H])c([2H])c(-n3c4c([2H])c([2H])c([2H])c([2H])c4c4c5c6c([2H])c([2H])c([2H])c([2H])c6n(-c6c([2H])c([2H])c(-c7c([2H])c([2H])c([2H])c([2H])c7[2H])c([2H])c6[2H])c5c([2H])c([2H])c43)c([2H])c2[2H])c([2H])c1[2H]] |

It was confirmed by ¹H-NMR and FD-mass spectrometry that the compound synthesized in the Preparation Example 2 was synthesized into the desired compound. The measured values of ¹H NMR (CDCl₃, 400 MHz) are shown in the following Table 5, and the measured values of field desorption mass spectrometry (FD-Mass) are shown in the following Table 6.

TABLE 5

| Compound | |
|---|---|
| No. | ¹H NMR(CDCl₃, 400 Mz) |
| 5-1 | δ = 8.55(2H, d), 7.94(2H, d), 7.62-7.35(14H, m), |
| | 7.16(2H, d) |
| 5-4 | δ = 8.55(2H, d), 7.94-7.91(10H, m), 7.75(4H, d), |
| | 7.49-7.35(10H, m), 7.16(2H, t) |
| 5-5 | δ = 8.55(2H, d), 8.21(1H, s), 7.94-7.91(6H, m), |
| | 7.75-7.35(16H, m), 7.26(1H, d), 7.16(2H, t) |
| 5-22 | δ = 8.55(1H, d), 8.19(1H, d), 7.94-7.91(9H, m), |
| | 7.75(4H, d), 7.58-7.35(11H, m), 7.20-7.16(2H, m) |
| 5-23 | δ = 8.55(1H, d), 8.21-8.19(2H, m), 7.94-7.91(5H, m), |
| | 7.75-7.35(18H, m), 7.20-7.16(2H, m) |
| 5-32 | δ = 8.55(1H, d), 8.19(1H, d), 7.94-7.91(9H, m), |
| | 7.75(4H, d), 7.58-7.35(11H, m), 7.20-7.16(2H, m) |
| 5-35 | δ = 8.55(1H, d), 8.21-8.19(2H, m), 7.94-7.91(5H, m), |
| | 7.68-7.35(18H, m), 7.20-7.16(2H, m) |
| 5-38 | δ = 8.55(2H, s), 8.12(1H, d), 7.94(2H, d), 7.92(2H, d), |
| | 7.91(2H, d), 7.75(2H, d), 7.62(2H, d), 7.58(1H, d), |
| | 7.5(2H, d), 7.49(2H, dd), 7.41(1H, d), 7.35(2H, d), |
| | 7.18(1H, dd), 7.16(2H, dd), |
| 5-41 | δ = 8.55(2H, d), 7.94-7.91(10H, m), 7.84(2H, d), |
| | 7.75(4H, d), 7.49-7.35(8H, m), 7.16(2H, t) |
| 5-49 | δ = 8.55(2H, s), 8.12(1H, d), 7.94(2H, d), |
| | 7.92(2H, d), 7.91(2H, d), 7.75(2H, d), 7.62(2H, d), |
| | 7.58(1H, d), 7.5(2H, d), 7.49(2H, dd), 7.41(1H, d), |
| | 7.35(2H, d), 7.18(1H, dd), 7.16(2H, dd), |
| 5-61 | δ = 8.55(2H, d), 7.94(2H, d), 7.42-7.35(4H, m), |
| | 7.16(2H, t) |
| 5-69 | δ = 7.92-7.91(8H, m), 7.75(4H, d), 7.49-7.41(6H, m) |

TABLE 6

| Compound | | Compound | |
|---|---|---|---|
| No. | FD-MS | No. | FD-MS |
| 5-1 | m/z = 408.16(C₃₀H₂₀N₂ = 408.50) | 5-4 | m/z = 560.23(C₄₂H₂₈N₂ = 560.70) |
| 5-5 | m/z = 560.23(C₄₂H₂₈N₂ = 560.70) | 5-22 | m/z = 560.23(C₄₂H₂₈N₂ = 560.70) |
| 5-23 | m/z = 560.23(C₄₂H₂₈N₂ = 560.70) | 5-32 | m/z = 560.23(C₄₂H₂₈N₂ = 560.70) |
| 5-35 | m/z = 560.23(C₄₂H₂₈N₂ = 560.70) | 5-38 | m/z = 574.20(C₄₂H₂₆N₂O = 574.68) |
| 5-41 | m/z = 560.23(C₄₂H₂₈N₂ = 560.70) | 5-49 | m/z = 484.19(C₃₆H₂₄N₂ = 484.60) |
| 5-61 | m/z = 578.34(C₄₂H₁₀D₁₈N₂ = 578.81) | 5-69 | m/z = 570.29(C₄₂H₁₈D₁₀N₂ = 570.76) |
| 5-77 | m/z = 588.40(C₄₂D₂₈N₂ = 588.87) | | |

### Experimental Examples

### 1) Manufacture of Organic Light Emitting Device

A glass substrate, in which ITO was thinly coated to have a thickness of 1,500), was ultrasonically washed with distilled water. When the washing with distilled water is finished, the glass substrate was ultrasonically washed with a solvent such as acetone, methanol, and isopropyl alcohol, was dried and then was subjected to UVO treatment for 5 minutes by using UV in a UV washing machine. Thereafter, the substrate was transferred to a plasma washing machine (PT), and then was subjected to plasma treatment in a vacuum state for an ITO work function and in order to remove a residual film, and was transferred to a thermal deposition apparatus for organic deposition.

As the common layers, the hole injection layer 4,4′,4″-tris[2-naphthyl(phenyl)amino]triphenylamine (2-TNATA) and the hole transfer layer N,N′-di(1-naphthyl)-N,N′-diphenyl-(1,1′-biphenyl)-4,4′-diamine (NPB) were formed on the ITO transparent electrode (positive electrode).

A light emitting layer was thermally vacuum deposited thereon as follows. The light emitting layer was deposited to have a thickness of 400 Å by using two types of compounds described in the following Table 7 as a host and tris[2-(p-tolyl)pyridine]iridium (III) (Ir(mppy)₃) as a green phosphorescent dopant to dope the host with Ir(mppy)₃ in an amount of 10 wt %. Thereafter, bathocuproine (BCP) as a hole blocking layer was deposited to have a thickness of 60 Å, and Alq₃ as an electron transfer layer was deposited to have a thickness of 200 Å thereon. Finally, an organic light emitting device was manufactured by depositing lithium fluoride (LiF) to have a thickness of 10 Å on the electron transfer layer to form an electron injection layer, and then depositing an aluminum (A1) negative electrode to have a thickness of 1200 Å on the electron injection layer to form a negative electrode.

Meanwhile, all the organic compounds required for manufacturing an OLED device were subjected to vacuum sublimed purification under 10⁻⁸ to 10⁻⁶ torr for each material, and used for the manufacture of the OLED.

The structures of compounds ref. 1 to ref. 18 used in Comparative Examples 1 to 54 and 77 to 94 are as follows.

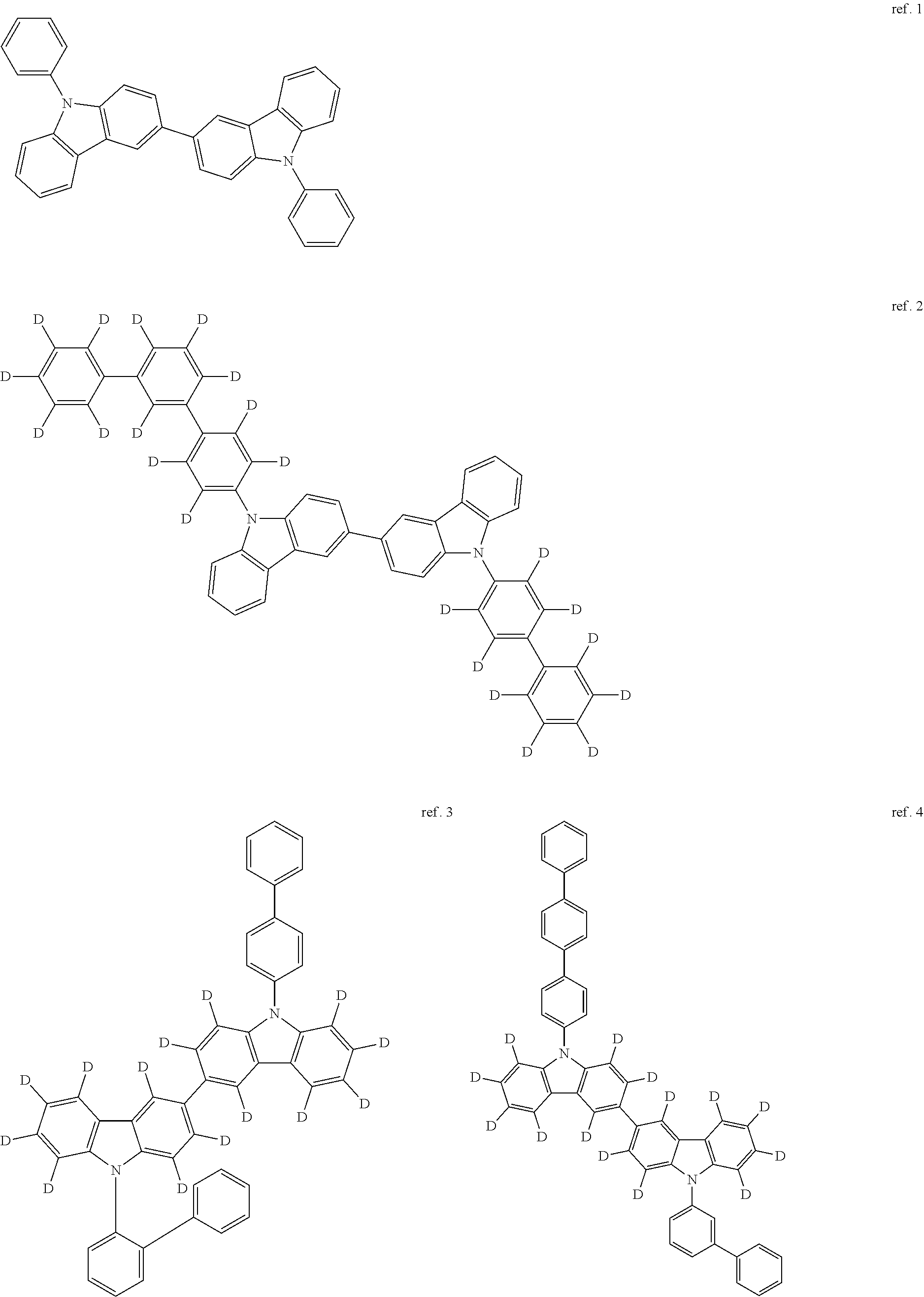

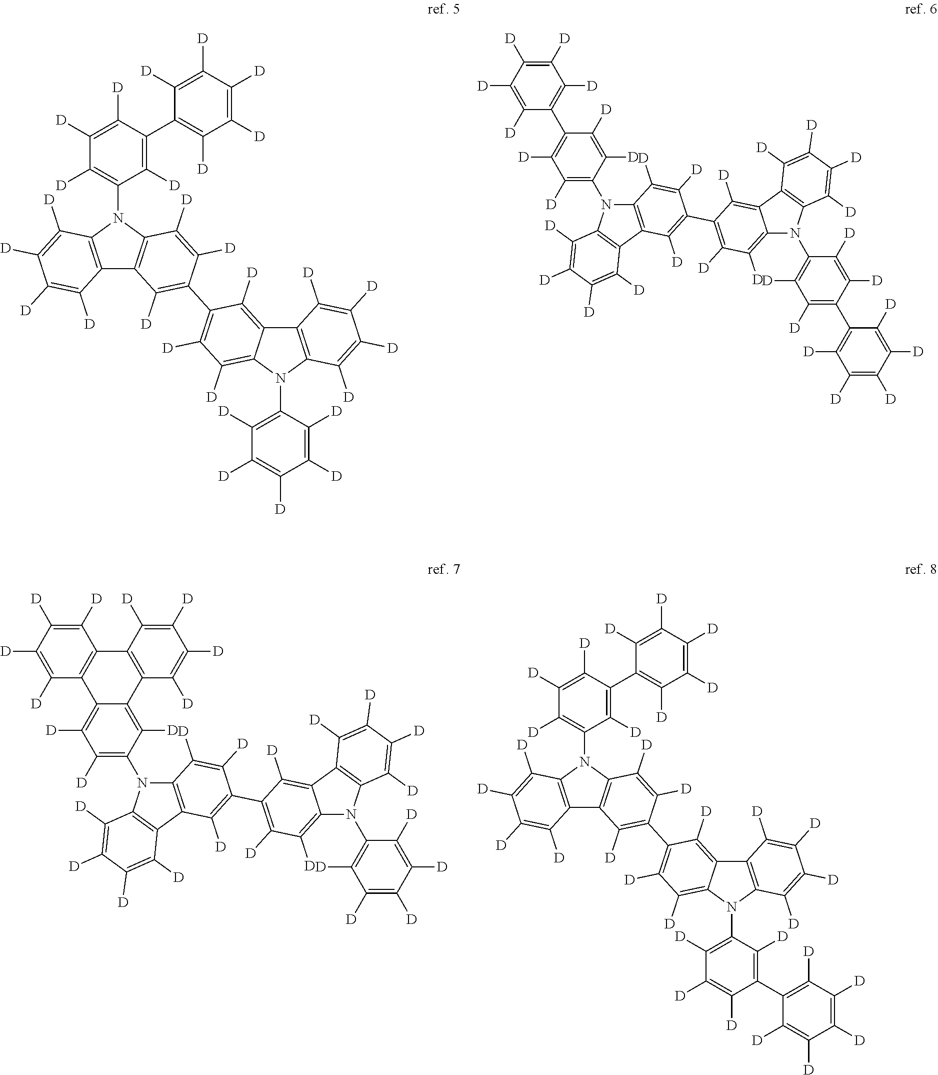

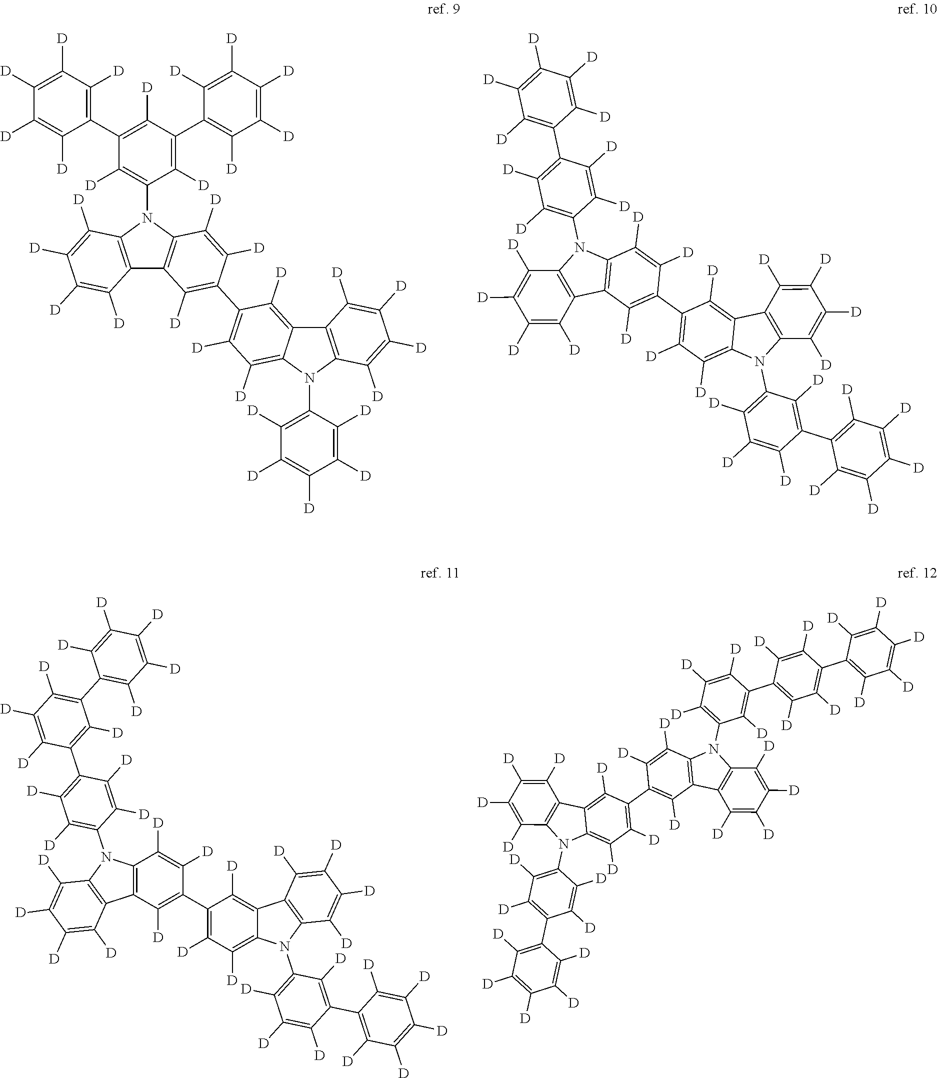

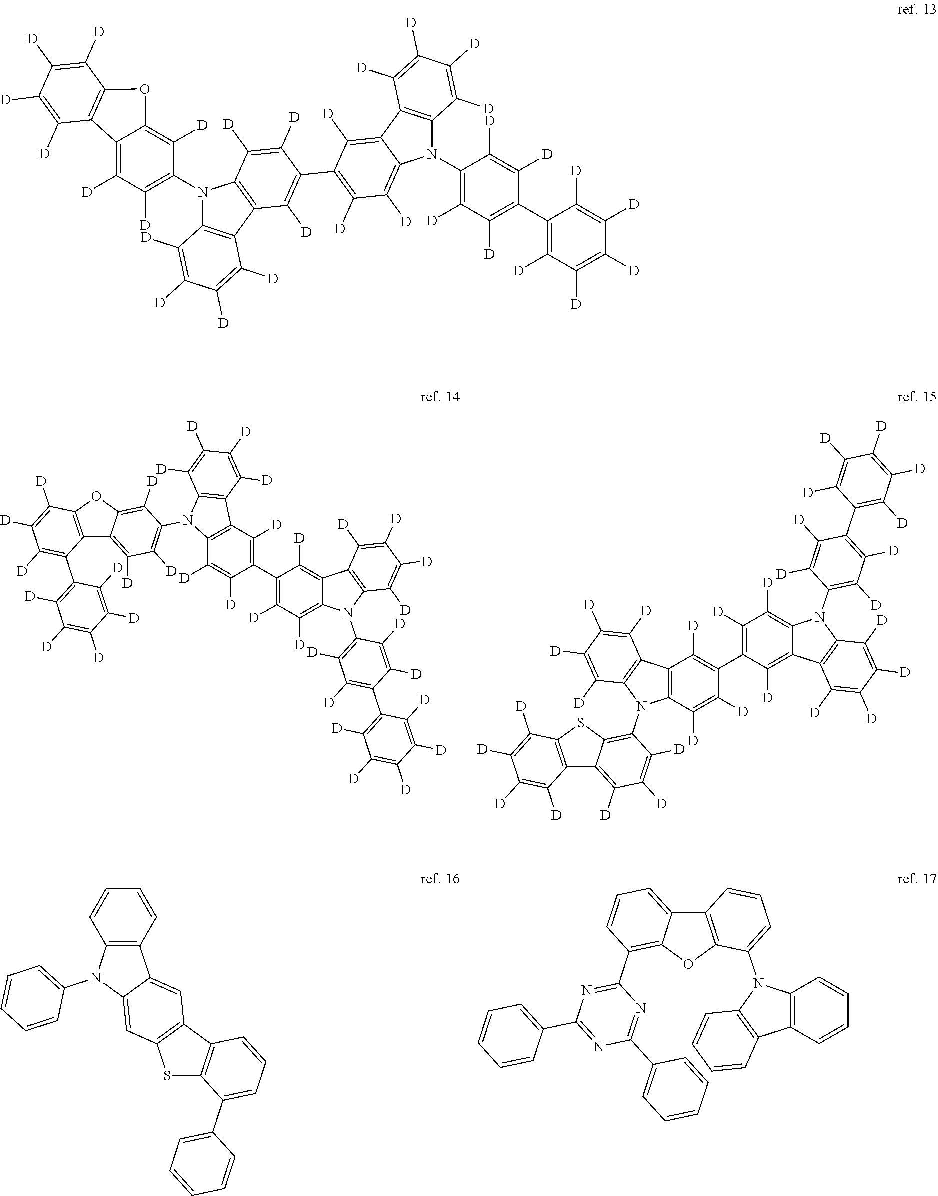

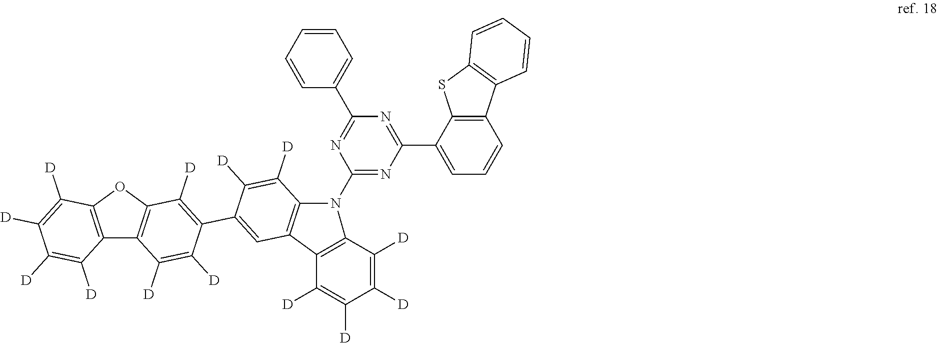 [SMILES: [2H]c1c([2H])c([2H])c2c(oc3c([2H])c(-c4cc5c6c([2H])c([2H])c([2H])c([2H])c6n(-c6nc(-c7ccccc7)nc(-c7cccc8c7sc7ccccc78)n6)c5c([2H])c4[2H])c([2H])c([2H])c32)c1[2H]]

2) Driving Voltage, Light Emitting Efficiency and lifetime of Organic Light Emitting Device

For the organic light emitting device manufactured as described above, electroluminescence (EL) characteristics were measured by M7000 manufactured by McScience Inc., and based on the measurement result thereof, T₉₀ was measured by a lifetime measurement device (M6000) manufactured by McScience Inc., when the reference luminance was 8,000 cd/in².

The results of measuring the driving voltage, light emitting efficiency, color coordinate (CIE), and lifetime of the organic light emitting device manufactured according to the present invention are shown in the following Table 7.

TABLE 7

| | | | Driving | Light emitting | Color | |
|---|---|---|---|---|---|---|
| | Light emitting | | voltage | efficiency | EL | Lifetime |
| | layer compound | Ratio | (V) | (cd/A) | color | (T₉₀) |
| Example 1 | 1-1:5-1 | 2:1 | 3.98 | 78.9 | Green | 308 |
| Example 2 | | 1:1 | 3.85 | 80.3 | | 321 |
| Example 3 | | 1:2 | 3.78 | 81.5 | | 332 |
| Example 4 | 1-18:5-5 | 2:1 | 4.01 | 80.4 | | 318 |
| Example 5 | | 1:1 | 3.95 | 81.7 | | 326 |
| Example 6 | | 1:2 | 3.85 | 83.5 | | 335 |
| Example 7 | 1-28:5-61 | 2:1 | 4.23 | 83.2 | | 298 |
| Example 8 | | 1:1 | 4.09 | 85.0 | | 314 |
| Example 9 | | 1:2 | 4.02 | 86.5 | | 336 |
| Example 10 | 1-38:5-22 | 2:1 | 3.88 | 80.2 | | 267 |
| Example 11 | | 1:1 | 3.74 | 83.1 | | 289 |
| Example 12 | | 1:2 | 3.55 | 84.2 | | 307 |
| Example 13 | 1-44:5-25 | 2:1 | 3.86 | 83.5 | | 289 |
| Example 14 | | 1:1 | 3.74 | 84.9 | | 302 |
| Example 15 | | 1:2 | 3.67 | 86.2 | | 312 |
| Example 16 | 1-56:5-43 | 2:1 | 3.82 | 83.0 | | 296 |
| Example 17 | | 1:1 | 3.77 | 84.3 | | 304 |
| Example 18 | | 1:2 | 3.67 | 86.2 | | 312 |
| Example 19 | 1-79:5-4 | 2:1 | 4.00 | 81.4 | | 258 |
| Example 20 | | 1:1 | 3.87 | 83.1 | | 272 |
| Example 21 | | 1:2 | 3.80 | 84.6 | | 291 |
| Example 22 | 1-83:5-69 | 2:1 | 4.20 | 82.5 | | 257 |
| Example 23 | | 1:1 | 4.05 | 85.5 | | 279 |
| Example 24 | | 1:2 | 3.84 | 86.6 | | 296 |
| Example 25 | 1-97:5-62 | 2:1 | 4.26 | 86.7 | | 284 |
| Example 26 | | 1:1 | 4.13 | 88.3 | | 296 |
| Example 27 | | 1:2 | 4.05 | 89.6 | | 306 |
| Example 28 | 1-105:5-61 | 2:1 | 3.86 | 76.5 | | 276 |
| Example 29 | | 1:1 | 3.81 | 77.7 | | 283 |
| Example 30 | | 1:2 | 3.71 | 79.4 | | 291 |
| Example 31 | 1-117:5-73 | 2:1 | 4.01 | 80.2 | | 263 |
| Example 32 | | 1:1 | 3.88 | 82.0 | | 277 |
| Example 33 | | 1:2 | 3.81 | 83.4 | | 296 |
| Example 34 | 1-123:5-77 | 2:1 | 4.35 | 74.7 | | 266 |
| Example 35 | | 1:1 | 4.19 | 77.4 | | 288 |
| Example 36 | | 1:2 | 3.98 | 78.4 | | 306 |
| Example 37 | 1-134:5-35 | 2:1 | 3.71 | 81.5 | | 261 |
| Example 38 | | 1:1 | 3.59 | 83.0 | | 272 |
| Example 39 | | 1:2 | 3.52 | 84.2 | | 281 |
| Example 40 | 1-144:5-41 | 2:1 | 3.82 | 83.0 | | 271 |
| Example 41 | | 1:1 | 3.77 | 84.3 | | 278 |
| Example 42 | | 1:2 | 3.67 | 86.2 | | 286 |
| Example 43 | 1-157:5-100 | 2:1 | 3.91 | 85.8 | | 263 |
| Example 44 | | 1:1 | 3.78 | 87.7 | | 277 |
| Example 45 | | 1:2 | 3.72 | 89.2 | | 296 |
| Example 46 | 1-163:5-32 | 2:1 | 3.88 | 82.3 | | 286 |
| Example 47 | | 1:1 | 3.74 | 85.3 | | 310 |
| Example 48 | | 1:2 | 3.55 | 86.4 | | 329 |
| Example 49 | 1-178:5-112 | 2:1 | 3.78 | 78.8 | | 307 |
| Example 50 | | 1:1 | 3.66 | 80.2 | | 320 |
| Example 51 | | 1:2 | 3.59 | 81.4 | | 331 |
| Example 52 | 1-181:5-22 | 2:1 | 3.83 | 82.2 | | 327 |
| Example 53 | | 1:1 | 3.78 | 83.6 | | 335 |
| Example 54 | | 1:2 | 3.68 | 85.4 | | 344 |
| Example 55 | 1-197:5-120 | 2:1 | 3.81 | 79.2 | | 276 |
| Example 56 | | 1:1 | 3.68 | 80.9 | | 29 |
| Example 57 | | 1:2 | 3.62 | 82.3 | | 311 |
| Example 58 | 1-206:5-27 | 2:1 | 4.01 | 80.3 | | 275 |
| Example 59 | | 1:1 | 3.87 | 83.2 | | 297 |
| Example 60 | | 1:2 | 3.67 | 84.3 | | 316 |
| Example 61 | 1-232:5-23 | 2:1 | 3.92 | 84.5 | | 302 |
| Example 62 | | 1:1 | 3.79 | 86.0 | | 315 |
| Example 63 | | 1:2 | 3.72 | 87.3 | | 326 |
| Example 64 | 1-238:5-102 | 2:1 | 4.18 | 79.6 | | 303 |
| Example 65 | | 1:1 | 4.11 | 80.9 | | 310 |
| Example 66 | | 1:2 | 4.01 | 82.7 | | 319 |
| Example 67 | 1-249:5-77 | 2:1 | 4.30 | 81.5 | | 287 |
| Example 68 | | 1:1 | 4.16 | 83.2 | | 303 |
| Example 69 | | 1:2 | 4.09 | 84.7 | | 324 |
| Example 70 | 1-255:5-18 | 2:1 | 4.57 | 83.5 | | 290 |
| Example 71 | | 1:1 | 4.40 | 86.6 | | 314 |
| Example 72 | | 1:2 | 4.18 | 87.7 | | 334 |
| Example 73 | 1-260:5-41 | 2:1 | 3.85 | 85.8 | | 294 |
| Example 74 | | 1:1 | 3.73 | 87.3 | | 306 |
| Example 75 | | 1:2 | 3.66 | 88.6 | | 317 |
| Example 76 | 1-264:5-76 | 2:1 | 3.90 | 77.6 | | 306 |
| Example 77 | | 1:1 | 3.84 | 78.9 | | 313 |
| Example 78 | | 1:2 | 3.74 | 80.6 | | 322 |
| Example 79 | 1-271:5-1 | 2:1 | 4.05 | 80.4 | | 324 |
| Example 80 | | 1:1 | 3.92 | 82.2 | | 341 |
| Example 81 | | 1:2 | 3.85 | 83.6 | | 365 |
| Example 82 | 1-277:5-35 | 2:1 | 3.81 | 77.7 | | 321 |
| Example 83 | | 1:1 | 3.68 | 80.5 | | 347 |
| Example 84 | | 1:2 | 3.49 | 81.6 | | 369 |
| Example 85 | 1-279:5-34 | 2:1 | 3.73 | 80.9 | | 324 |
| Example 86 | | 1:1 | 3.61 | 82.4 | | 337 |
| Example 87 | | 1:2 | 3.54 | 83.6 | | 349 |
| Example 88 | 1-283:5-68 | 2:1 | 3.82 | 83.4 | | 333 |
| Example 89 | | 1:1 | 3.77 | 84.7 | | 342 |
| Example 90 | | 1:2 | 3.67 | 86.6 | | 351 |
| Example 91 | 1-292:5-4 | 2:1 | 3.72 | 78.2 | | 304 |
| Example 92 | | 1:1 | 3.60 | 79.9 | | 321 |
| Example 93 | | 1:2 | 3.54 | 81.3 | | 343 |
| Example 94 | 1-298:5-49 | 2:1 | 3.97 | 79.3 | | 310 |
| Example 95 | | 1:1 | 3.82 | 82.2 | | 336 |
| Example 96 | | 1:2 | 3.63 | 83.3 | | 357 |
| Example 97 | 2-2:5-107 | 2:1 | 3.99 | 83.5 | | 309 |
| Example 98 | | 1:1 | 3.86 | 85.0 | | 322 |
| Example 99 | | 1:2 | 3.79 | 86.3 | | 333 |
| Example 100 | 2-30:5-1 | 2:1 | 3.58 | 76.6 | | 308 |
| Example 101 | | 1:1 | 3.53 | 77.9 | | 315 |
| Example 102 | | 1:2 | 3.44 | 79.6 | | 324 |
| Example 103 | 2-72:5-25 | 2:1 | 3.70 | 78.5 | | 292 |
| Example 104 | | 1:1 | 3.58 | 80.2 | | 307 |
| Example 105 | | 1:2 | 3.52 | 81.6 | | 329 |
| Example 106 | 2-94:5-38 | 2:1 | 3.91 | 80.6 | | 295 |
| Example 107 | | 1:1 | 3.77 | 83.5 | | 319 |
| Example 108 | | 1:2 | 3.58 | 84.6 | | 339 |
| Example 109 | 2-115:5-74 | 2:1 | 4.22 | 76.6 | | 306 |
| Example 110 | | 1:1 | 4.08 | 77.9 | | 319 |
| Example 111 | | 1:2 | 4.01 | 79.1 | | 330 |
| Example 112 | 2-125:5-56 | 2:1 | 4.26 | 78.1 | | 318 |
| Example 113 | | 1:1 | 4.20 | 79.4 | | 326 |
| Example 114 | | 1:2 | 4.09 | 81.1 | | 335 |
| Example 115 | 2-152:5-9 | 2:1 | 4.40 | 80.9 | | 306 |
| Example 116 | | 1:1 | 4.25 | 82.6 | | 322 |
| Example 117 | | 1:2 | 4.18 | 84.1 | | 345 |
| Example 118 | 2-173:5-111 | 2:1 | 4.00 | 76.9 | | 262 |
| Example 119 | | 1:1 | 3.86 | 79.6 | | 283 |
| Example 120 | | 1:2 | 3.66 | 80.7 | | 30 |
| Example 121 | 2-193:5-38 | 2:1 | 3.82 | 78.9 | | 319 |
| Example 122 | | 1:1 | 3.60 | 80.3 | | 328 |
| Example 123 | | 1:2 | 3.44 | 81.5 | | 335 |
| Example 124 | 2-210:5-22 | 2:1 | 3.94 | 80.1 | | 276 |
| Example 125 | | 1:1 | 3.81 | 81.5 | | 288 |
| Example 126 | | 1:2 | 3.74 | 82.7 | | 298 |
| Example 127 | 2-235:5-19 | 2:1 | 4.01 | 82.5 | | 267 |
| Example 128 | | 1:1 | 3.95 | 83.9 | | 273 |
| Example 129 | | 1:2 | 3.85 | 85.7 | | 281 |
| Example 130 | 2-254:5-79 | 2:1 | 3.67 | 74.5 | | 271 |
| Example 131 | | 1:1 | 3.55 | 76.2 | | 285 |
| Example 132 | | 1:2 | 3.49 | 77.5 | | 305 |
| Example 133 | 2-269:5-1 | 2:1 | 3.87 | 75.7 | | 305 |
| Example 134 | | 1:1 | 3.73 | 78.5 | | 330 |
| Example 135 | | 1:2 | 3.54 | 79.5 | | 351 |
| Example 136 | 2-274:5-81 | 2:1 | 3.86 | 79.9 | | 336 |
| Example 137 | | 1:1 | 3.74 | 81.3 | | 350 |
| Example 138 | | 1:2 | 3.67 | 82.5 | | 362 |
| Example 139 | 2-279:5-6 | 2:1 | 3.69 | 79.4 | | 348 |
| Example 140 | | 1:1 | 3.63 | 80.7 | | 357 |
| Example 141 | | 1:2 | 3.54 | 82.5 | | 367 |
| Example 142 | 2-285:5-32 | 2:1 | 3.82 | 81.3 | | 318 |
| Example 143 | | 1:1 | 3.69 | 83.0 | | 335 |
| Example 144 | | 1:2 | 3.63 | 84.5 | | 358 |
| Example 145 | 3-6:5-42 | 2:1 | 4.14 | 83.3 | | 250 |
| Example 146 | | 1:1 | 3.99 | 86.4 | | 270 |
| Example 147 | | 1:2 | 3.79 | 87.5 | | 287 |
| Example 148 | 3-31:5-2 | 2:1 | 3.62 | 78.9 | | 305 |
| Example 149 | | 1:1 | 3.50 | 80.3 | | 318 |
| Example 150 | | 1:2 | 3.44 | 81.5 | | 329 |
| Example 151 | 3-53:5-22 | 2:1 | 3.67 | 80.4 | | 317 |
| Example 152 | | 1:1 | 3.61 | 81.7 | | 325 |
| Example 153 | | 1:2 | 3.52 | 83.5 | | 334 |
| Example 154 | 3-94:5-92 | 2:1 | 3.77 | 83.2 | | 288 |
| Example 155 | | 1:1 | 3.64 | 85.0 | | 304 |
| Example 156 | | 1:2 | 3.58 | 86.5 | | 325 |
| Example 157 | 3-111:5-723 | 2:1 | 4.38 | 83.5 | | 263 |
| Example 158 | | 1:1 | 4.22 | 86.6 | | 284 |
| Example 159 | | 1:2 | 4.01 | 87.7 | | 302 |
| Example 160 | 3-129:5-7 | 2:1 | 4.31 | 86.8 | | 285 |
| Example 161 | | 1:1 | 4.17 | 88.4 | | 297 |
| Example 162 | | 1:2 | 4.09 | 89.7 | | 307 |
| Example 163 | 3-154:5-61 | 2:1 | 4.35 | 79.6 | | 269 |
| Example 164 | | 1:1 | 4.29 | 80.9 | | 275 |
| Example 165 | | 1:2 | 4.18 | 82.7 | | 283 |
| Example 166 | 3-194:5-14 | 2:1 | 3.85 | 84.9 | | 272 |
| Example 167 | | 1:1 | 3.72 | 86.8 | | 287 |
| Example 168 | | 1:2 | 3.66 | 88.3 | | 307 |
| Example 169 | 3-207:5-92 | 2:1 | 4.09 | 76.5 | | 271 |
| Example 170 | | 1:1 | 3.94 | 79.3 | | 294 |
| Example 171 | | 1:2 | 3.74 | 80.3 | | 312 |
| Example 172 | 3-234:5-4 | 2:1 | 4.05 | 80.6 | | 299 |
| Example 173 | | 1:1 | 3.92 | 82.1 | | 311 |
| Example 174 | | 1:2 | 3.85 | 83.3 | | 322 |
| Example 175 | 3-255:5-11 | 2:1 | 3.64 | 77.0 | | 296 |
| Example 176 | | 1:1 | 3.58 | 78.3 | | 304 |
| Example 177 | | 1:2 | 3.49 | 80.0 | | 312 |
| Example 178 | 3-271:5-93 | 2:1 | 3.72 | 78.9 | | 301 |
| Example 179 | | 1:1 | 3.60 | 80.6 | | 317 |
| Example 180 | | 1:2 | 3.54 | 82.0 | | 339 |
| Example 181 | 3-273:5-169 | 2:1 | 4.01 | 81.0 | | 302 |
| Example 182 | | 1:1 | 3.87 | 83.9 | | 327 |
| Example 183 | | 1:2 | 3.67 | 85.0 | | 347 |
| Example 184 | 3-280:5-116 | 2:1 | 3.73 | 80.4 | | 330 |
| Example 185 | | 1:1 | 3.61 | 81.9 | | 344 |
| Example 186 | | 1:2 | 3.54 | 83.1 | | 356 |
| Example 187 | 3-286:5-77 | 2:1 | 3.78 | 81.9 | | 344 |
| Example 188 | | 1:1 | 3.72 | 83.3 | | 352 |
| Example 189 | | 1:2 | 3.63 | 85.1 | | 362 |
| Example 190 | 3-299:5-82 | 2:1 | 3.99 | 84.7 | | 310 |
| Example 191 | | 1:1 | 3.86 | 86.6 | | 327 |
| Example 192 | | 1:2 | 3.79 | 88.1 | | 350 |
| Example 193 | 3-302:5-77 | 2:1 | 3.76 | 79.2 | | 305 |
| Example 194 | | 1:1 | 3.62 | 82.1 | | 330 |
| Example 195 | | 1:2 | 3.44 | 83.2 | | 351 |
| Example 196 | 3-307:5-1 | 2:1 | 3.71 | 82.5 | | 320 |
| Example 197 | | 1:1 | 3.59 | 83.9 | | 334 |
| Example 198 | | 1:2 | 3.52 | 85.2 | | 345 |
| Example 199 | 4-6:5-24 | 2:1 | 3.73 | 84.9 | | 305 |
| Example 200 | | 1:1 | 3.67 | 86.3 | | 312 |
| Example 201 | | 1:2 | 3.58 | 88.2 | | 321 |
| Example 202 | 4-31:5-31 | 2:1 | 4.00 | 80.6 | | 274 |
| Example 203 | | 1:1 | 3.87 | 82.3 | | 289 |
| Example 204 | | 1:2 | 3.80 | 83.8 | | 309 |
| Example 205 | 4-51:5-51 | 2:1 | 4.19 | 81.7 | | 274 |
| Example 206 | | 1:1 | 4.03 | 84.7 | | 297 |
| Example 207 | | 1:2 | 3.83 | 85.8 | | 315 |
| Example 208 | 4-94:5-23 | 2:1 | 4.09 | 86.0 | | 298 |
| Example 209 | | 1:1 | 3.95 | 87.5 | | 310 |
| Example 210 | | 1:2 | 3.88 | 88.8 | | 321 |
| Example 211 | 4-114:5-81 | 2:1 | 4.02 | 86.5 | | 264 |
| Example 212 | | 1:1 | 3.96 | 87.9 | | 271 |
| Example 213 | | 1:2 | 3.86 | 89.8 | | 278 |
| Example 214 | 4-132:5-49 | 2:1 | 3.73 | 82.5 | | 271 |
| Example 215 | | 1:1 | 3.60 | 84.0 | | 282 |
| Example 216 | | 1:2 | 3.53 | 85.2 | | 291 |
| Example 217 | 4-152:5-74 | 2:1 | 4.09 | 78.7 | | 252 |
| Example 218 | | 1:1 | 3.96 | 80.4 | | 265 |
| Example 219 | | 1:2 | 3.89 | 81.8 | | 284 |
| Example 220 | 4-171:5-32 | 2:1 | 4.31 | 80.8 | | 252 |
| Example 221 | | 1:1 | 4.15 | 83.7 | | 273 |
| Example 222 | | 1:2 | 3.94 | 84.8 | | 290 |
| Example 223 | 4-190:5-49 | 2:1 | 3.94 | 79.1 | | 305 |
| Example 224 | | 1:1 | 3.81 | 80.5 | | 318 |
| Example 225 | | 1:2 | 3.74 | 81.7 | | 329 |
| Example 226 | 4-219:5-23 | 2:1 | 3.93 | 80.6 | | 318 |
| Example 227 | | 1:1 | 3.87 | 81.9 | | 326 |
| Example 228 | | 1:2 | 3.77 | 83.7 | | 335 |
| Example 229 | 4-227:5-12 | 2:1 | 4.02 | 83.4 | | 302 |
| Example 230 | | 1:1 | 3.89 | 85.2 | | 319 |
| Example 231 | | 1:2 | 3.82 | 86.7 | | 341 |
| Example 232 | 4-255:5-8 | 2:1 | 3.99 | 77.2 | | 270 |
| Example 233 | | 1:1 | 3.85 | 80.0 | | 292 |
| Example 234 | | 1:2 | 3.65 | 81.1 | | 310 |
| Example 235 | 4-279:5-5 | 2:1 | 3.87 | 80.4 | | 332 |
| Example 236 | | 1:1 | 3.75 | 81.9 | | 346 |
| Example 237 | | 1:2 | 3.68 | 83.1 | | 358 |
| Example 238 | 4-287:5-90 | 2:1 | 3.89 | 82.9 | | 344 |
| Example 239 | | 1:1 | 3.83 | 84.2 | | 352 |
| Example 240 | | 1:2 | 3.73 | 86.1 | | 362 |
| Example 241 | 4-298:5-77 | 2:1 | 3.81 | 77.3 | | 325 |
| Example 242 | | 1:1 | 3.68 | 79.0 | | 343 |
| Example 243 | | 1:2 | 3.62 | 80.4 | | 367 |
| Example 244 | 4-302:5-69 | 2:1 | 3.99 | 78.5 | | 312 |
| Example 245 | | 1:1 | 3.85 | 81.3 | | 338 |
| Example 246 | | 1:2 | 3.65 | 82.4 | | 359 |
| Comparative | 1-1:ref. 1 | 2:1 | 4.69 | 70.5 | | 202 |
| Example 1 | | | | | | |
| Comparative | | 1:1 | 4.53 | 71.7 | | 211 |
| Example 2 | | | | | | |
| Comparative | | 1:2 | 4.45 | 72.8 | | 218 |
| Example 3 | | | | | | |
| Comparative | 1-123:ref. 2 | 2:1 | 4.51 | 69.0 | | 215 |
| Example 4 | | | | | | |
| Comparative | | 1:1 | 4.44 | 70.2 | | 220 |
| Example 5 | | | | | | |
| Comparative | | 1:2 | 4.33 | 71.7 | | 226 |
| Example 6 | | | | | | |
| Comparative | 1-181:ref. 3 | 2:1 | 4.59 | 72.9 | | 218 |
| Example 7 | | | | | | |
| Comparative | | 1:1 | 4.44 | 74.5 | | 230 |
| Example 8 | | | | | | |
| Comparative | | 1:2 | 4.36 | 75.8 | | 246 |
| Example 9 | | | | | | |
| Comparative | 1-249:ref. 4 | 2:1 | 4.83 | 65.9 | | 217 |
| Example 10 | | | | | | |
| Comparative | | 1:1 | 4.66 | 68.3 | | 235 |
| Example 11 | | | | | | |
| Comparative | | 1:2 | 4.42 | 69.2 | | 250 |
| Example 12 | | | | | | |
| Comparative | 1-298:ref. 5 | 2:1 | 4.61 | 65.8 | | 258 |
| Example 13 | | | | | | |
| Comparative | | 1:1 | 4.46 | 67.0 | | 269 |
| Example 14 | | | | | | |
| Comparative | | 1:2 | 4.38 | 68.0 | | 278 |
| Example 15 | | | | | | |
| Comparative | 2-94:ref. 6 | 2:1 | 4.88 | 68.6 | | 237 |
| Example 16 | | | | | | |
| Comparative | | 1:1 | 4.81 | 69.7 | | 243 |
| Example 17 | | | | | | |
| Comparative | | 1:2 | 4.69 | 71.2 | | 250 |
| Example 18 | | | | | | |
| Comparative | 2-235:ref. 7 | 2:1 | 4.85 | 71.3 | | 225 |
| Example 19 | | | | | | |
| Comparative | | 1:1 | 4.69 | 72.8 | | 237 |
| Example 20 | | | | | | |
| Comparative | | 1:2 | 4.61 | 74.1 | | 254 |
| Example 21 | | | | | | |
| Comparative | 2-279:ref. 8 | 2:1 | 4.82 | 65.1 | | 228 |
| Example 22 | | | | | | |
| Comparative | | 1:1 | 4.65 | 67.4 | | 247 |
| Example 23 | | | | | | |
| Comparative | | 1:2 | 4.41 | 68.3 | | 262 |
| Example 24 | | | | | | |
| Comparative | 2-152:ref. 9 | 2:1 | 4.58 | 68.8 | | 209 |
| Example 25 | | | | | | |
| Comparative | | 1:1 | 4.43 | 70.1 | | 218 |
| Example 26 | | | | | | |
| Comparative | | 1:2 | 4.35 | 71.1 | | 225 |
| Example 27 | | | | | | |
| Comparative | 3-94:ref. 10 | 2:1 | 4.72 | 69.1 | | 217 |
| Example 28 | | | | | | |
| Comparative | | 1:1 | 4.65 | 70.3 | | 223 |
| Example 29 | | | | | | |
| Comparative | | 1:2 | 4.53 | 71.8 | | 229 |
| Example 30 | | | | | | |
| Comparative | 3-234:ref. 11 | 2:1 | 4.77 | 65.2 | | 210 |
| Example 31 | | | | | | |
| Comparative | | 1:1 | 4.61 | 66.6 | | 221 |
| Example 32 | | | | | | |
| Comparative | | 1:2 | 4.53 | 67.8 | | 237 |
| Example 33 | | | | | | |
| Comparative | 3-280:ref. 12 | 2:1 | 5.16 | 65.1 | | 231 |
| Example 34 | | | | | | |
| Comparative | | 1:1 | 4.97 | 67.4 | | 250 |
| Example 35 | | | | | | |
| Comparative | | 1:2 | 4.72 | 68.3 | | 266 |
| Example 36 | | | | | | |
| Comparative | 3-302:ref. 13 | 2:1 | 4.65 | 70.5 | | 229 |
| Example 37 | | | | | | |
| Comparative | | 1:1 | 4.50 | 71.7 | | 239 |
| Example 38 | | | | | | |
| Comparative | | 1:2 | 4.42 | 72.8 | | 247 |
| Example 39 | | | | | | |
| Comparative | 4-152:ref. 14 | 2:1 | 4.47 | 67.6 | | 245 |
| Example 40 | | | | | | |
| Comparative | | 1:1 | 4.40 | 68.7 | | 251 |
| Example 41 | | | | | | |
| Comparative | | 1:2 | 4.29 | 70.2 | | 258 |
| Example 42 | | | | | | |
| Comparative | 1-127:ref. 15 | 2:1 | 4.93 | 68.0 | | 218 |
| Example 43 | | | | | | |
| Comparative | | 1:1 | 4.81 | 69.5 | | 225 |
| Example 44 | | | | | | |
| Comparative | | 1:2 | 4.65 | 71.7 | | 232 |
| Example 45 | | | | | | |
| Comparative | 3-239:ref. 16 | 2:1 | 4.54 | 67.1 | | 239 |
| Example 46 | | | | | | |
| Comparative | | 1:1 | 4.39 | 68.6 | | 252 |
| Example 47 | | | | | | |
| Comparative | | 1:2 | 4.31 | 69.8 | | 270 |
| Example 48 | | | | | | |
| Comparative | ref. 17:5-1 | 2:1 | 4.95 | 70.4 | | 213 |
| Example 49 | | | | | | |
| Comparative | | 1:1 | 4.77 | 72.9 | | 231 |
| Example 50 | | | | | | |
| Comparative | | 1:2 | 4.53 | 73.9 | | 245 |
| Example 51 | | | | | | |
| Comparative | ref. 18:5-1 | 2:1 | 4.72 | 69.1 | | 242 |
| Example 52 | | | | | | |
| Comparative | | 1:1 | 4.56 | 70.3 | | 252 |
| Example 53 | | | | | | |
| Comparative | | 1:2 | 4.48 | 71.4 | | 261 |
| Example 54 | | | | | | |
| Comparative | 1-1 | — | 3.69 | 79.1 | | 199 |
| Example 55 | | | | | | |
| Comparative | 1-38 | — | 3.43 | 83.1 | | 175 |
| Example 56 | | | | | | |
| Comparative | 1-56 | — | 3.58 | 81.0 | | 190 |
| Example 57 | | | | | | |
| Comparative | 1-79 | — | 3.71 | 83.8 | | 169 |
| Example 58 | | | | | | |
| Comparative | 1-260 | — | 3.55 | 84.2 | | 196 |
| Example 59 | | | | | | |
| Comparative | 2-30 | — | 3.34 | 77.9 | | 194 |
| Example 60 | | | | | | |
| Comparative | 2-191 | — | 3.56 | 79.5 | | 175 |
| Example 61 | | | | | | |
| Comparative | 2-254 | — | 3.41 | 77.3 | | 183 |
| Example 62 | | | | | | |
| Comparative | 3-6 | — | 3.70 | 85.9 | | 164 |
| Example 63 | | | | | | |
| Comparative | 3-53 | — | 3.40 | 81.0 | | 204 |
| Example 64 | | | | | | |
| Comparative | 3-111 | — | 3.72 | 86.5 | | 175 |
| Example 65 | | | | | | |
| Comparative | 3-207 | — | 3.65 | 75.5 | | 193 |
| Example 66 | | | | | | |
| Comparative | 4-31 | — | 3.69 | 83.0 | | 185 |
| Example 67 | | | | | | |
| Comparative | 4-135 | — | 3.42 | 78.8 | | 186 |
| Example 68 | | | | | | |
| Comparative | 4-190 | — | 3.65 | 80.8 | | 201 |
| Example 69 | | | | | | |
| Comparative | 4-255 | — | 3.57 | 79.3 | | 180 |
| Example 70 | | | | | | |
| Comparative | 5-5 | — | 3.69 | 62.1 | | 232 |
| Example 71 | | | | | | |
| Comparative | 5-22 | — | 3.73 | 60.8 | | 243 |
| Example 72 | | | | | | |
| Comparative | 5-32 | — | 4.07 | 63.4 | | 249 |
| Example 73 | | | | | | |
| Comparative | 5-35 | — | 3.66 | 61.8 | | 227 |
| Example 74 | | | | | | |
| Comparative | 5-69 | — | 4.02 | 63.1 | | 217 |
| Example 75 | | | | | | |
| Comparative | 5-77 | — | 3.66 | 64.7 | | 238 |
| Example 76 | | | | | | |
| Comparative | ref. 1 | — | 4.30 | 54.6 | | 120 |
| Example 77 | | | | | | |
| Comparative | ref. 2 | — | 3.82 | 56.4 | | 100 |
| Example 78 | | | | | | |
| Comparative | ref. 3 | — | 4.16 | 57.8 | | 116 |
| Example 79 | | | | | | |
| Comparative | ref. 4 | — | 4.28 | 56.7 | | 98 |
| Example 80 | | | | | | |
| Comparative | ref. 5 | — | 4.14 | 59.4 | | 121 |
| Example 81 | | | | | | |
| Comparative | ref. 6 | — | 4.19 | 53.3 | | 117 |
| Example 82 | | | | | | |
| Comparative | ref. 7 | — | 5.14 | 54.5 | | 102 |
| Example 83 | | | | | | |
| Comparative | ref. 8 | — | 3.85 | 51.9 | | 110 |
| Example 84 | | | | | | |
| Comparative | ref. 9 | — | 4.24 | 58.6 | | 93 |
| Example 85 | | | | | | |
| Comparative | ref. 10 | — | 3.86 | 55.9 | | 124 |
| Example 86 | | | | | | |
| Comparative | ref. 11 | — | 4.62 | 58.8 | | 102 |
| Example 87 | | | | | | |
| Comparative | ref. 12 | — | 4.29 | 53.8 | | 120 |
| Example 88 | | | | | | |
| Comparative | ref. 13 | — | 4.31 | 56.1 | | 111 |
| Example 89 | | | | | | |
| Comparative | ref. 14 | — | 4.24 | 55.5 | | 108 |
| Example 90 | | | | | | |
| Comparative | ref. 15 | — | 4.27 | 54.7 | | 122 |
| Example 91 | | | | | | |
| Comparative | ref. 16 | — | 4.11 | 54.3 | | 104 |
| Example 92 | | | | | | |
| Comparative | ref. 17 | — | 3.98 | 60.2 | | 100 |
| Example 93 | | | | | | |
| Comparative | ref. 18 | — | 3.92 | 59.1 | | 99 |
| Example 94 | | | | | | |

As can be seen from the results in Table 7, in the case of Examples 1 to 246 using a light emitting layer material of the organic electroluminescent device of the present invention, the driving voltage was lower, the light emitting efficiency was improved, and the lifetime was also remarkably improved compared to Comparative Examples 1 to 94.

When Comparative Examples 1 to 94 are specifically described, Comparative Examples 1 to 48 are cases in which comparative compound refs. 1 to 16 were used instead of the second compound of the present invention, and Comparative Examples 49 to 54 are cases in which comparative compound refs. 17 and 18 were used instead of the first compound of the present invention. In addition, Comparative Examples 55 to 70 are cases in which the first compound of the present invention was used alone, Comparative Examples 71 to 76 are cases in which the second compound of the present invention was used alone, and Comparative Examples 77 to 94 are cases in which comparative compound refs. 1 to 18 were used alone.

First, comparative compound refs. 1 to 16 are biscarbazole, which has a deeper HOMO level than indolocarbazole, which is the second compound of the present invention (Chemical Formula 2). From this, it can be seen that the second compound of the present invention has a stronger ability to push electrons than biscarbazole. Therefore, when the second compound of the present invention is used, hole injection from the host to the dopant may be facilitated.

Furthermore, comparative compound refs. 1 to 16 have slow HOD. Since a slow HOD results in an incorrect balance of holes and electrons, stability deteriorates, leading to reduced lifetime and efficiency. That is, it can be seen that the combination of the first compound (Chemical Formula 1) with good electron transfer ability and the second compound (Chemical Formula 2) with good hole transfer ability allows electrons and holes to be bonded to each other in the light emitting layer through a more stable balance.

In Comparative Examples 1 to 48 in which compounds refs. 1 to 16 above were used instead of the second compound of the present invention, the driving voltage was a minimum of 4.29 V and a maximum of 5.16 V, the light emitting efficiency was a minimum of 65.1 cd/A and a maximum of 75.8 cd/A, and the lifetime was a minimum of 202 and a maximum of 278.

In contrast, in the group of the Examples using the second compound of the present invention, the driving voltage was a minimum of 3.44 V and a maximum of 4.57 V, the light emitting efficiency was a minimum of 74.5 cd/A and a maximum of 89.8 cd/A, and the lifetime was a minimum of 250 and a maximum of 369.

In the case of Comparative Example 15, the lifetime was 278 and the driving voltage was 4.38 V, but the light emitting efficiency was 68 cd/A, which is not even at the lowest level among the Examples, and in the case of Comparative Example 42, the driving voltage was 4.29 V, which is the lowest among the Comparative Examples, and the lifetime was 258, but the light emitting efficiency was 70.2 cd/A, which is also not at the lowest level among the Examples. Furthermore, Comparative Example 9, which had the highest measured light emitting efficiency among the Comparative Examples, had a lifetime of 246, which was inferior to the Examples. That is, it was confirmed that the overall performance of the devices of Comparative Examples 1 to 48 could not keep up with the performance of the group of the Examples.

Comparative compound refs. 17 and 18 include dibenzofuran, triazine and carbazole structures, but have structures different from that of the first compound (Chemical Formula 1) of the present invention. The LUMO orbital of the first compound can be delocalized and expanded from the N-Het substituent to the two hetero rings, whereas compound refs. 17 and 18 have structural features that limit the expansion of the LUMO orbital. Such a feature has an effect of improving the mobility of electrons and stabilizing the electrons.

In Comparative Examples 49 to 54, in which comparative compound refs. 17 and 18 described above were used instead of the first compound of the present invention, the driving voltage was a minimum of 4.48 V and a maximum of 4.95 V, the light emitting efficiency was a minimum of 69.1 cd/A and a maximum of 73.9 cd/A, and the lifetime was a minimum of 213 and a maximum of 261. Similarly, it can be seen that when the values in Comparative Examples 49 to 54 were also compared with the driving voltage (3.44 V to 4.57 V), light emitting efficiency (74.5 cd/A to 89.8 cd/A), and lifetime (250 to 369) of the group of the Examples of the present invention, the device performance of Comparative Examples 49 to 54 is inferior to that of the Examples.

Comparative Examples 55 to 76 are cases in which the first or second compound of the present invention was used alone, and generally show excellent performance in terms of driving voltage (3.34 V to 4.07 V), but it can be confirmed that when the light emitting efficiency is high, the lifetime is short (Comparative Example 65), and when the lifetime is long, the light emitting efficiency is low (Comparative Example 73), and therefore, the performance is generally not sufficient.

Finally, Comparative Examples 77 to 94 are cases in which comparative compound refs. 1 to 18 were used alone, it was confirmed that the cases have a driving voltage (3.82 V to 5.14 V), a light emitting efficiency (51.9 cd/A to 60.2 cd/A), and a lifetime (93 to 124), and it can be seen that the performance in terms of light emitting efficiency and lifetime is remarkably lower than that of the Examples.

From this, it can be confirmed that when the first and second compounds of the present invention are combined, the driving voltage, light emitting efficiency, and lifetime are remarkably excellent compared to when they are each combined with different compounds or when they are used alone.

What is claimed is:

1. A composition for an organic material layer of an organic light emitting device, comprising:
a first compound of the following Chemical Formula 1; and
a second compound of the following Chemical Formula 2: 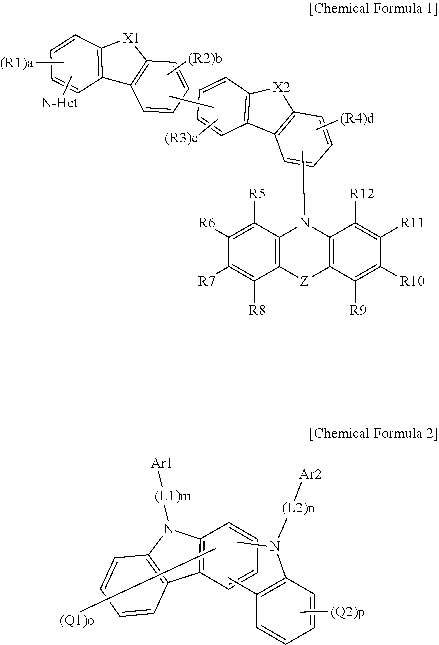
wherein, in Chemical Formula 1,
X1 and X2 are the same as or different from each other, and are each independently O; or S,
N-Het is a heteroaryl group having 1 to 60 carbon atoms, which is substituted or unsubstituted and includes one or more C═N bonds,
Z is a direct bond; 0; S; C(Ra)(Rb); or N(Rc),
Ra to Rc are the same as or different from each other, and are each independently a substituted or unsubstituted alkyl group having 1 to 10 carbon atoms; or a substituted or unsubstituted aryl group having 6 to 20 carbon atoms,
R1 to R4 are the same as or different from each other, and are each independently hydrogen; deuterium; a halogen group; a cyano group; a substituted or unsubstituted aryl group having 6 to 60 carbon atoms; or a substituted or unsubstituted heteroaryl group having 2 to 60 carbon atoms,
R5 to R12 are the same as or different from each other, and are each independently hydrogen; deuterium; a halogen group; a cyano group; a substituted or unsubstituted aryl group having 6 to 60 carbon atoms; or a substituted or unsubstituted heteroaryl group having 2 to 60 carbon atoms, or are bonded to an adjacent group to form a substituted or unsubstituted ring, and
a to d are each an integer from 0 to 3, and when a to d are each 2 or higher, substituents in the parenthesis are the same or different,
in Chemical Formula 2,
L1 and L2 are the same as or different from each other, and are each independently a direct bond; a substituted or unsubstituted arylene group having 6 to 60 carbon atoms; or a substituted or unsubstituted heteroarylene group having 6 to 60 carbon atoms,
m and n are each an integer from 1 to 3, and when m and n are each 2 or higher, substituents in the parenthesis are the same or different,
Ar1 and Ar2 are the same as or different from each other, and are each independently a substituted or unsubstituted aryl group having 6 to 60 carbon atoms; or a substituted or unsubstituted heteroaryl group having 2 to 60 carbon atoms,
Q1 and Q2 are the same as or different from each other, and are each independently hydrogen; deuterium; a halogen group; a cyano group; a substituted or unsubstituted alkyl group having 1 to 60 carbon atoms; a substituted or unsubstituted alkenyl group having 2 to 60 carbon atoms; a substituted or unsubstituted alkynyl group having 2 to 60 carbon atoms; a substituted or unsubstituted alkoxy group having 1 to 60 carbon atoms; a substituted or unsubstituted cycloalkyl group having 3 to 60 carbon atoms; a substituted or unsubstituted heterocycloalkyl group having 2 to 60 carbon atoms; a substituted or unsubstituted aryl group having 6 to 60 carbon atoms; or a substituted or unsubstituted heteroaryl group having 2 to 60 carbon atoms, and
is an integer from 0 to 6, p is an integer from 0 to 4, and when o and p are each 2 or higher, substituents in the parenthesis are the same or different.

2. The composition of claim 1, wherein Chemical Formula 1 is represented by any one of the following Chemical Formulae 1-1 to 1-4: 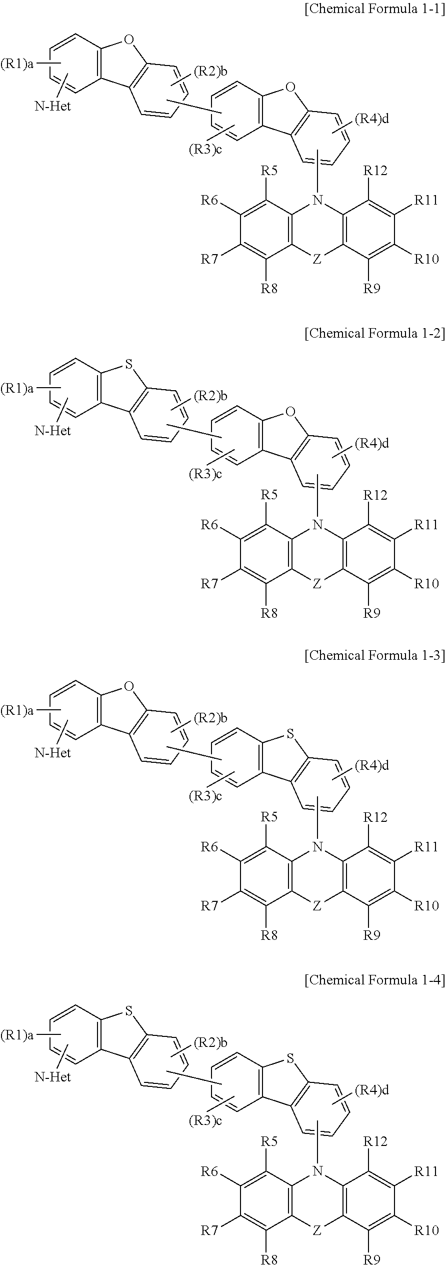
in Chemical Formulae 1-1 to 1-4,
the definition of each substituent is the same as the definition in Chemical Formula 1.

3. The composition of claim 1, wherein Chemical Formula 1 is represented by any one of the following Chemical Formulae 1-A to 1-C: 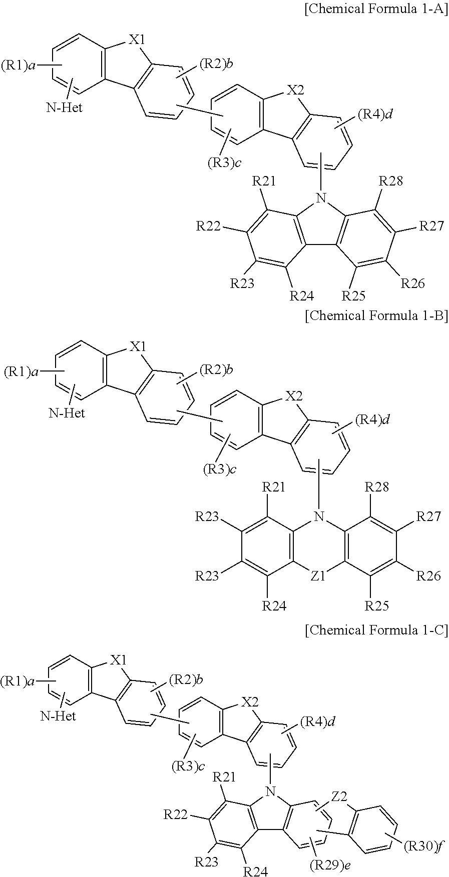
in Chemical Formulae 1-A to 1-C,
Z1 is C(Ra)(Rb); or N(Rc),
Z2 is O; S; C(Rd)(Re); or N(Rf),
Ra to Rf are the same as or different from each other, and are each independently a substituted or unsubstituted alkyl group having 1 to 10 carbon atoms; or a substituted or unsubstituted aryl group having 6 to 20 carbon atoms,
R21 to R30 are the same as or different from each other, and are each independently hydrogen; deuterium; a halogen group; a cyano group; a substituted or unsubstituted aryl group having 6 to 20 carbon atoms; or a substituted or unsubstituted heteroaryl group having 2 to 20 carbon atoms,
e is an integer from 0 to 2, when e is 2, a plurality of R29's are the same or different,
f is an integer from 0 to 4, and when f is each 2 or higher, a plurality of R30's are the same or different, and
the definitions of the other substituents are the same as the definitions in Chemical Formula 1.

4. The composition of claim 1, wherein the N-Het is a substituted or unsubstituted pyridine group; a substituted or unsubstituted pyrimidine group; a substituted or unsubstituted triazine group; a substituted or unsubstituted quinoline group; a substituted or unsubstituted isoquinoline group; a substituted or unsubstituted quinazoline group; a substituted or unsubstituted benzimidazole group; a substituted or unsubstituted phenanthroline group; a substituted or unsubstituted benzofuropyrimidine group; or a substituted or unsubstituted benzothienopyrimidine group.

5. The composition of claim 1, wherein Chemical Formula 2 is represented by any one of the following Chemical Formulae 2-1 to 2-5: 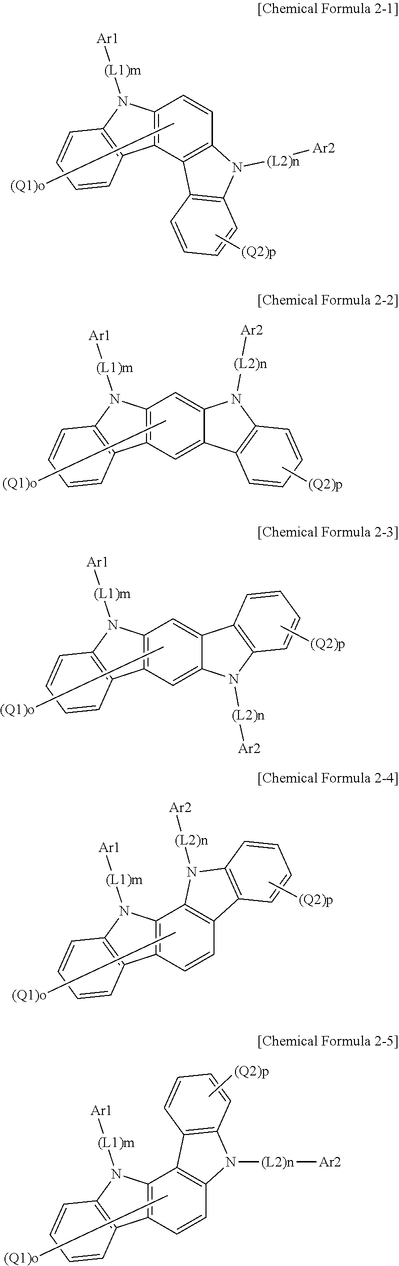
in Chemical Formulae 2-1 to 2-5,
the definition of each substituent is the same as the definition in Chemical Formula 2.

6. The composition of claim 1, wherein Ar1 and Ar2 are the same as or different from each other, and are each independently a substituted or unsubstituted aryl group having 6 to 40 carbon atoms; or a heteroaryl group having 2 to 40 carbon atoms, which is substituted or unsubstituted and comprises O.

7. The composition of claim 1, wherein the composition comprises the first compound and the second compound at a weight ratio of 1:10 to 10:1.

8. The composition of claim 1, wherein a deuterium substitution rate of the first compound is 0%, or 10% to 100%.

9. The composition of claim 1, wherein a deuterium substitution rate of the second compound is 0%, or 10% to 100%.

10. The composition of claim 1, wherein the first compound is represented by any one of the following compounds:

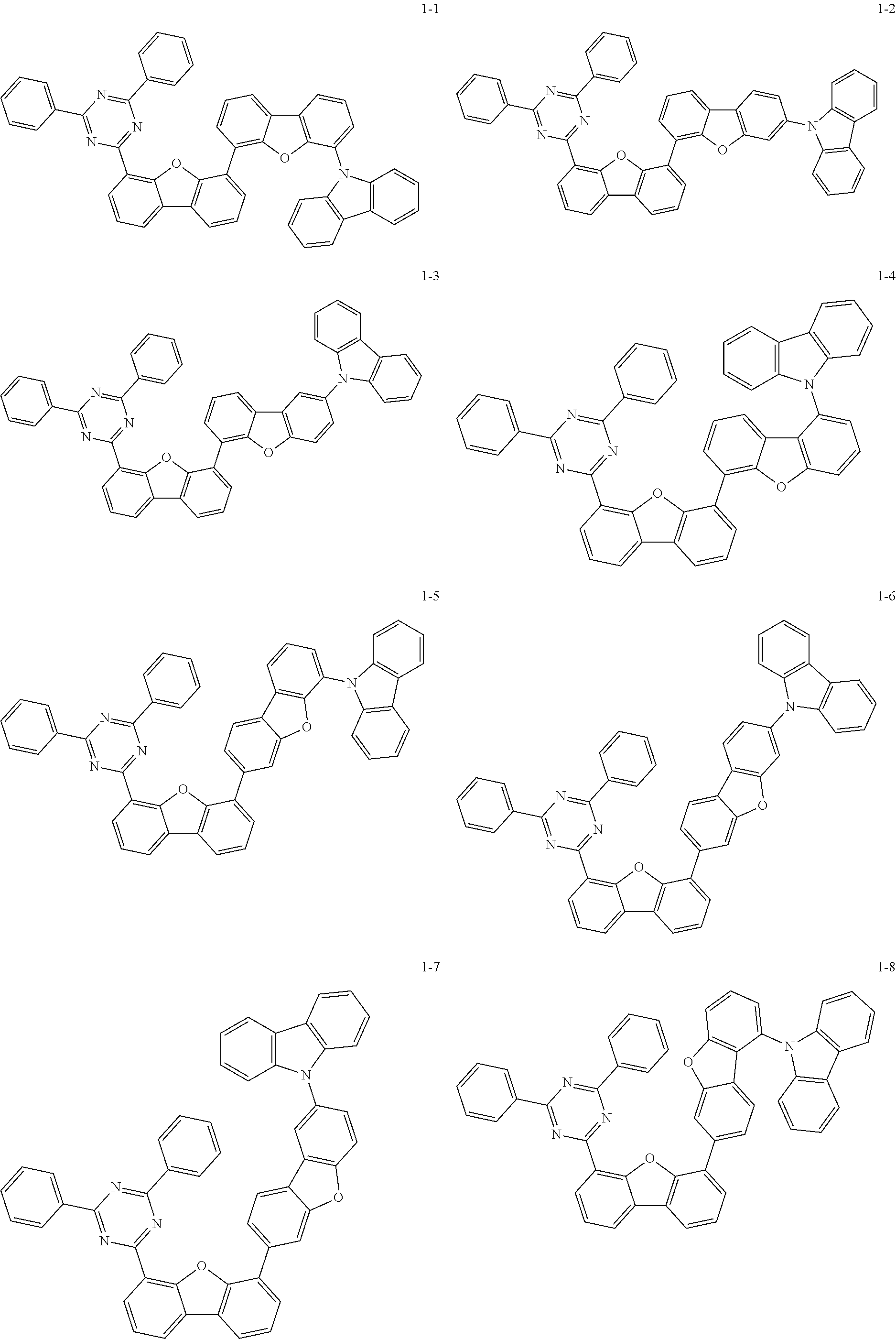

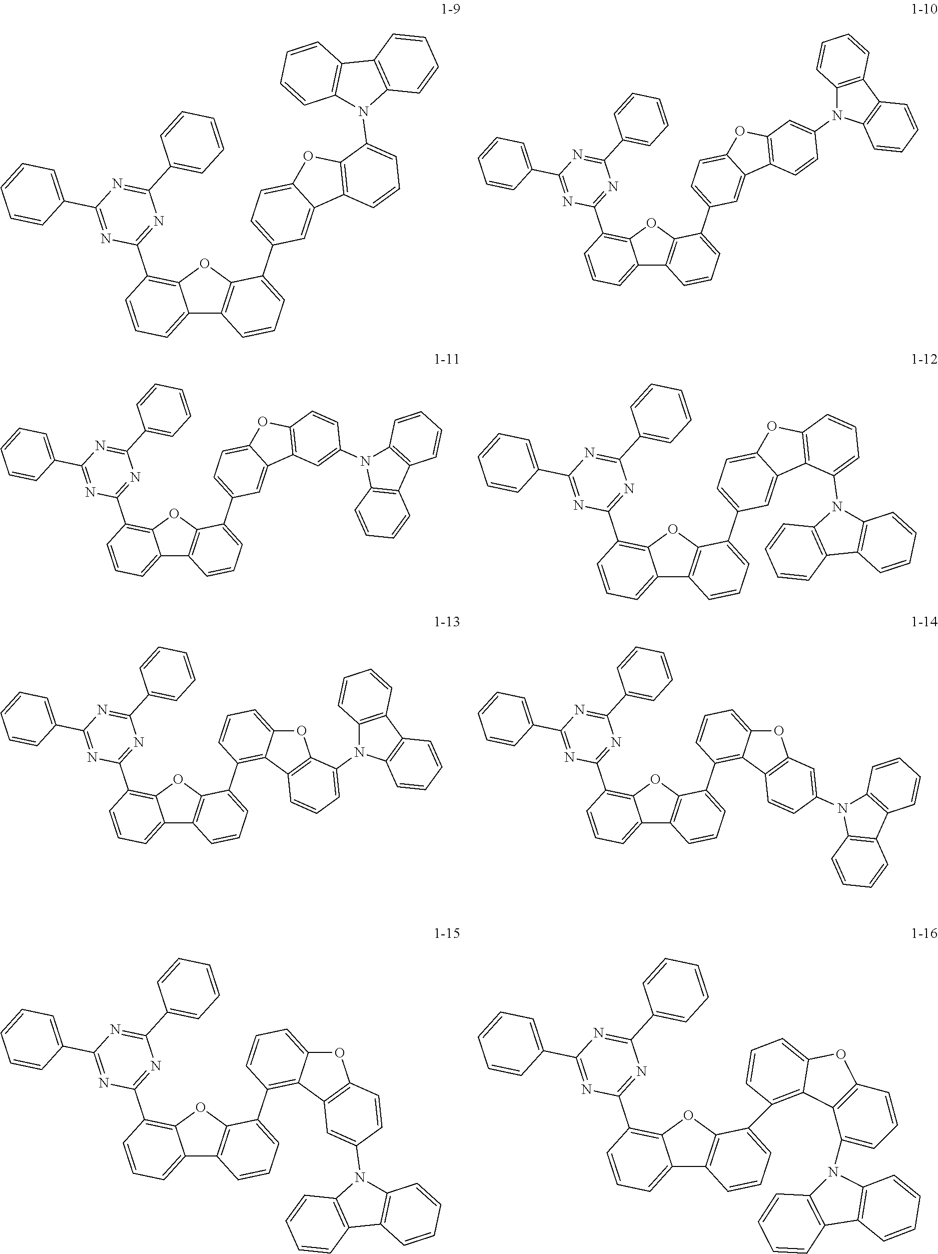

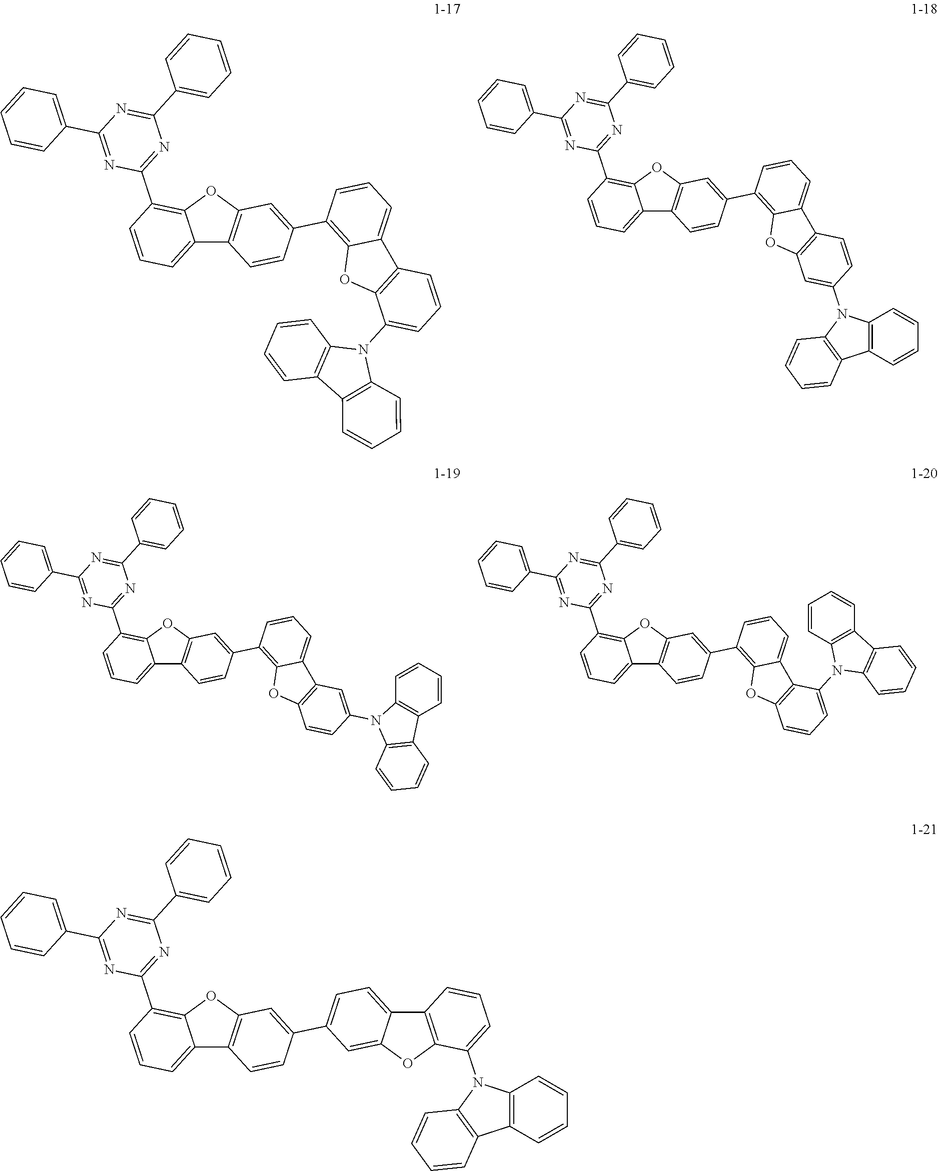 [SMILES: c1ccc(-c2nc(-c3ccccc3)nc(-c3cccc4c3oc3cc(-c5cccc6c5oc5c(-n7c8ccccc8c8ccccc87)cccc56)ccc34)n2)cc1 ; c1ccc(-c2nc(-c3ccccc3)nc(-c3cccc4c3oc3cc(-c5cccc6c5oc5cc(-n7c8ccccc8c8ccccc87)ccc56)ccc34)n2)cc1 ; c1ccc(-c2nc(-c3ccccc3)nc(-c3cccc4c3oc3cc(-c5cccc6c5oc5ccc(-n7c8ccccc8c8ccccc87)cc56)ccc34)n2)cc1 ; c1ccc(-c2nc(-c3ccccc3)nc(-c3cccc4c3oc3cc(-c5cccc6c5oc5cccc(-n7c8ccccc8c8ccccc87)c56)ccc34)n2)cc1 ; c1ccc(-c2nc(-c3ccccc3)nc(-c3cccc4c3oc3cc(-c5ccc6c(c5)oc5c(-n7c8ccccc8c8ccccc87)cccc56)ccc34)n2)cc1]

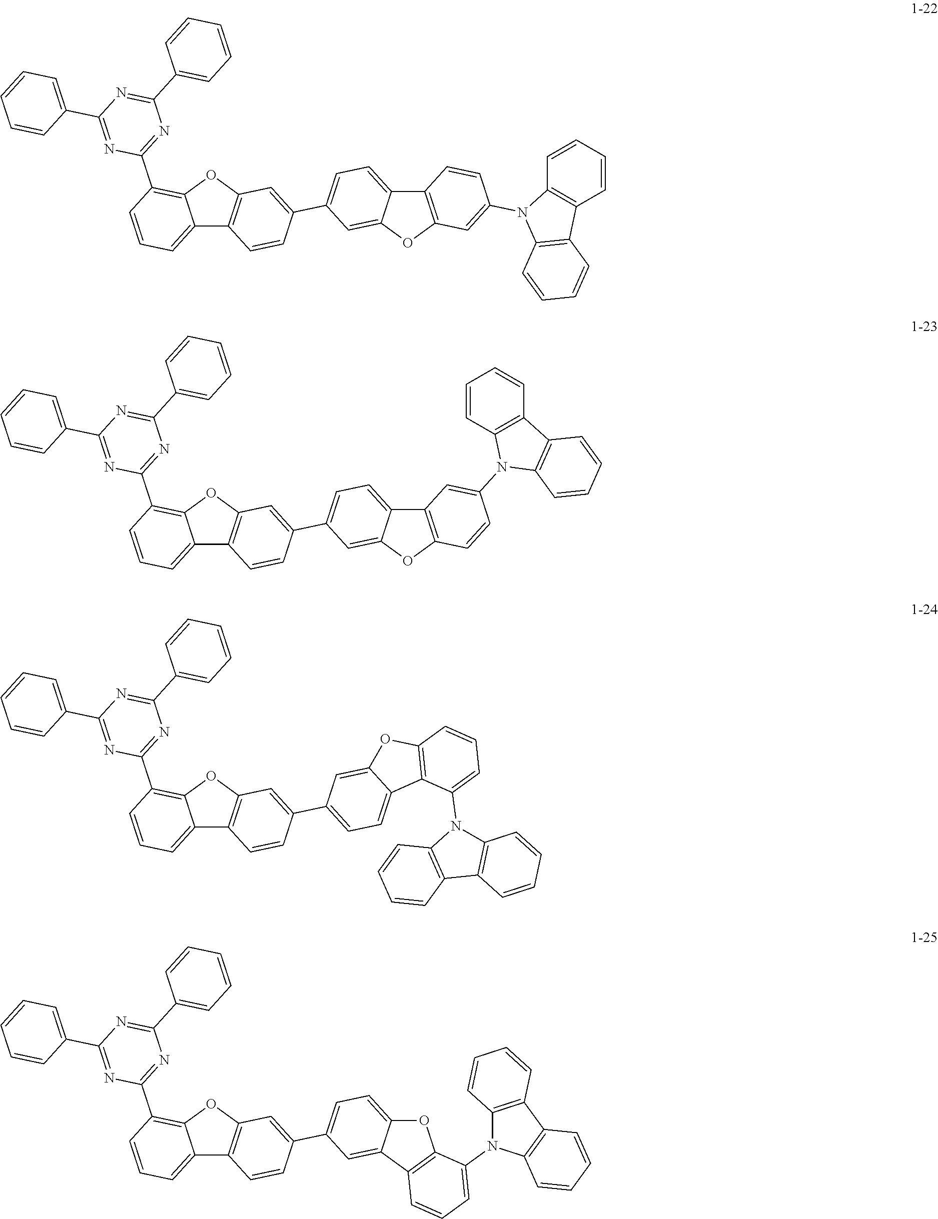 [SMILES: c1ccc(-c2nc(-c3ccccc3)nc(-c3cccc4c3oc3cc(-c5ccc6c(c5)oc5cc(-n7c8ccccc8c8ccccc87)ccc56)ccc34)n2)cc1 ; c1ccc(-c2nc(-c3ccccc3)nc(-c3cccc4c3oc3cc(-c5ccc6c(c5)oc5ccc(-n7c8ccccc8c8ccccc87)cc56)ccc34)n2)cc1 ; c1ccc(-c2nc(-c3ccccc3)nc(-c3cccc4c3oc3cc(-c5ccc6c(c5)oc5cccc(-n7c8ccccc8c8ccccc87)c56)ccc34)n2)cc1 ; c1ccc(-c2nc(-c3ccccc3)nc(-c3cccc4c3oc3cc(-c5ccc6oc7c(-n8c9ccccc9c9ccccc98)cccc7c6c5)ccc34)n2)cc1]

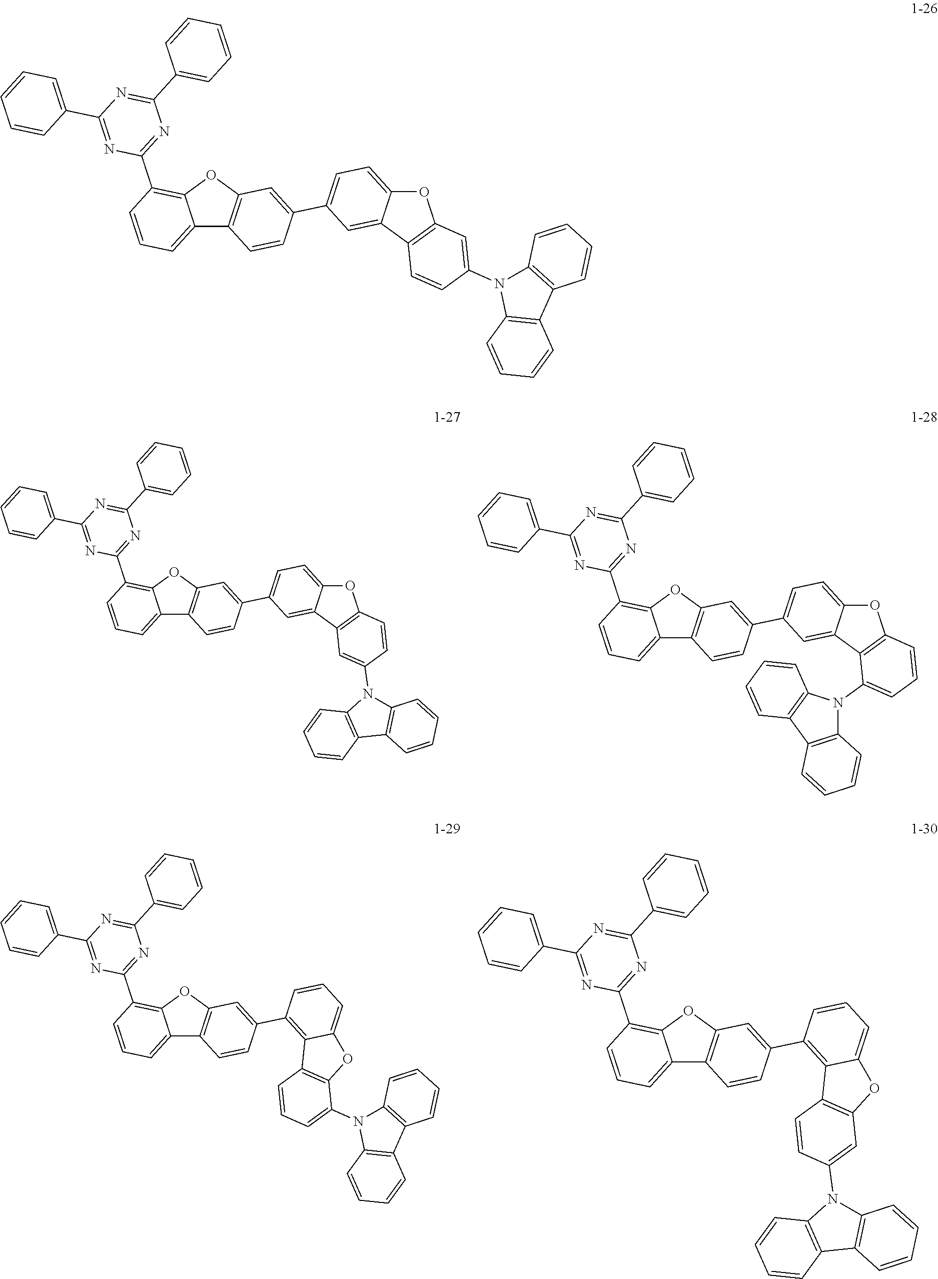 [SMILES: c1ccc(-c2nc(-c3ccccc3)nc(-c3cccc4c3oc3cc(-c5ccc6oc7cc(-n8c9ccccc9c9ccccc98)ccc7c6c5)ccc34)n2)cc1 ; c1ccc(-c2nc(-c3ccccc3)nc(-c3cccc4c3oc3cc(-c5ccc6oc7ccc(-n8c9ccccc9c9ccccc98)cc7c6c5)ccc34)n2)cc1 ; c1ccc(-c2nc(-c3ccccc3)nc(-c3cccc4c3oc3cc(-c5ccc6oc7cccc(-n8c9ccccc9c9ccccc98)c7c6c5)ccc34)n2)cc1 ; c1ccc(-c2nc(-c3ccccc3)nc(-c3cccc4c3oc3cc(-c5cccc6oc7c(-n8c9ccccc9c9ccccc98)cccc7c56)ccc34)n2)cc1 ; c1ccc(-c2nc(-c3ccccc3)nc(-c3cccc4c3oc3cc(-c5cccc6oc7cc(-n8c9ccccc9c9ccccc98)ccc7c56)ccc34)n2)cc1]

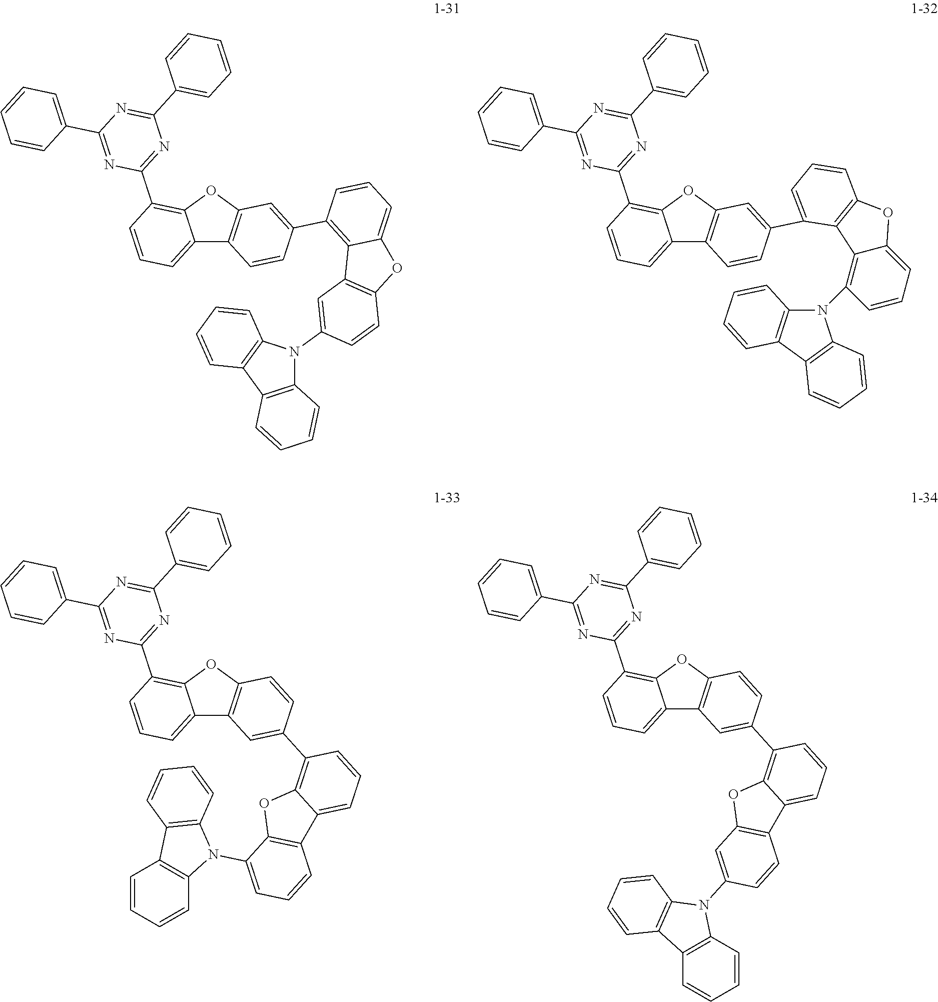 [SMILES: c1ccc(-c2nc(-c3ccccc3)nc(-c3cccc4c3oc3cc(-c5cccc6oc7ccc(-n8c9ccccc9c9ccccc98)cc7c56)ccc34)n2)cc1 ; c1ccc(-c2nc(-c3ccccc3)nc(-c3cccc4c3oc3cc(-c5cccc6oc7cccc(-n8c9ccccc9c9ccccc98)c7c56)ccc34)n2)cc1 ; c1ccc(-c2nc(-c3ccccc3)nc(-c3cccc4c3oc3ccc(-c5cccc6c5oc5c(-n7c8ccccc8c8ccccc87)cccc56)cc34)n2)cc1 ; c1ccc(-c2nc(-c3ccccc3)nc(-c3cccc4c3oc3ccc(-c5cccc6c5oc5cc(-n7c8ccccc8c8ccccc87)ccc56)cc34)n2)cc1]

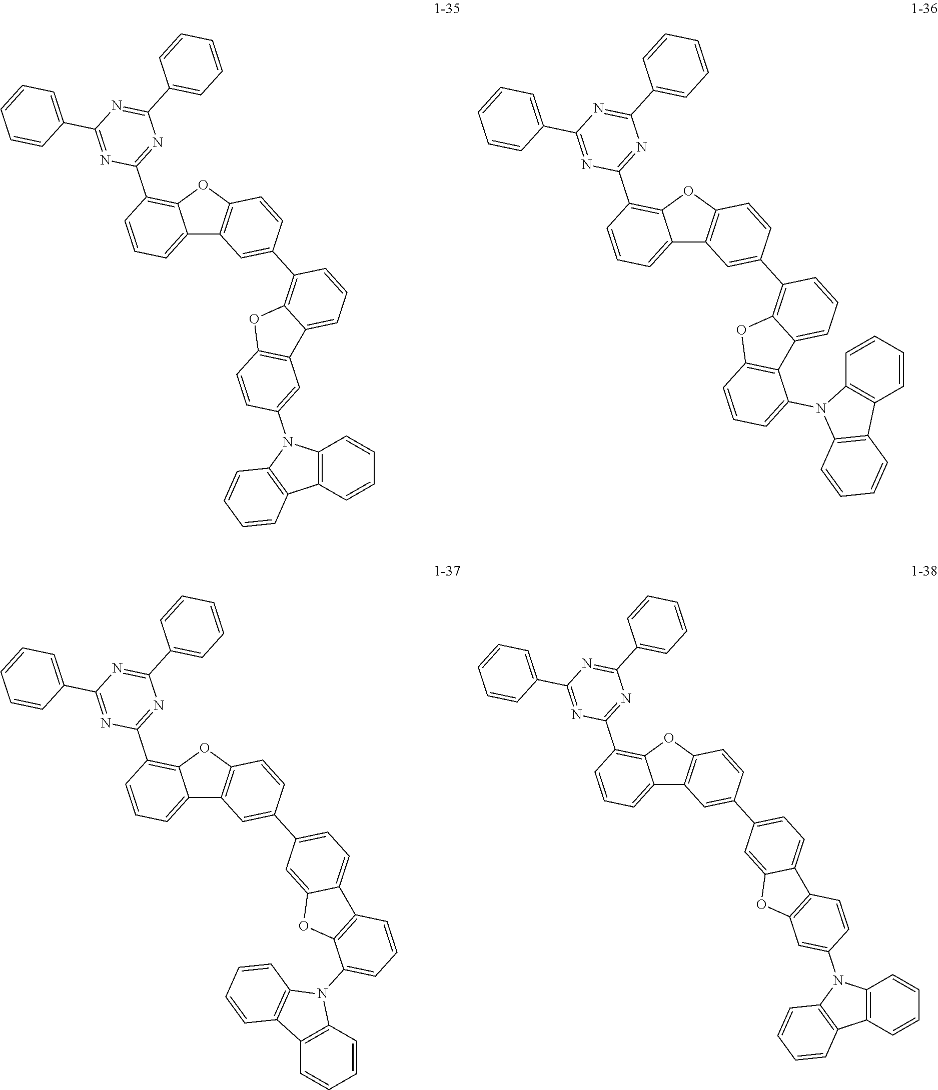 [SMILES: c1ccc(-c2nc(-c3ccccc3)nc(-c3cccc4c3oc3ccc(-c5cccc6c5oc5ccc(-n7c8ccccc8c8ccccc87)cc56)cc34)n2)cc1 ; c1ccc(-c2nc(-c3ccccc3)nc(-c3cccc4c3oc3ccc(-c5cccc6c5oc5cccc(-n7c8ccccc8c8ccccc87)c56)cc34)n2)cc1 ; c1ccc(-c2nc(-c3ccccc3)nc(-c3cccc4c3oc3ccc(-c5ccc6c(c5)oc5c(-n7c8ccccc8c8ccccc87)cccc56)cc34)n2)cc1 ; c1ccc(-c2nc(-c3ccccc3)nc(-c3cccc4c3oc3ccc(-c5ccc6c(c5)oc5cc(-n7c8ccccc8c8ccccc87)ccc56)cc34)n2)cc1]

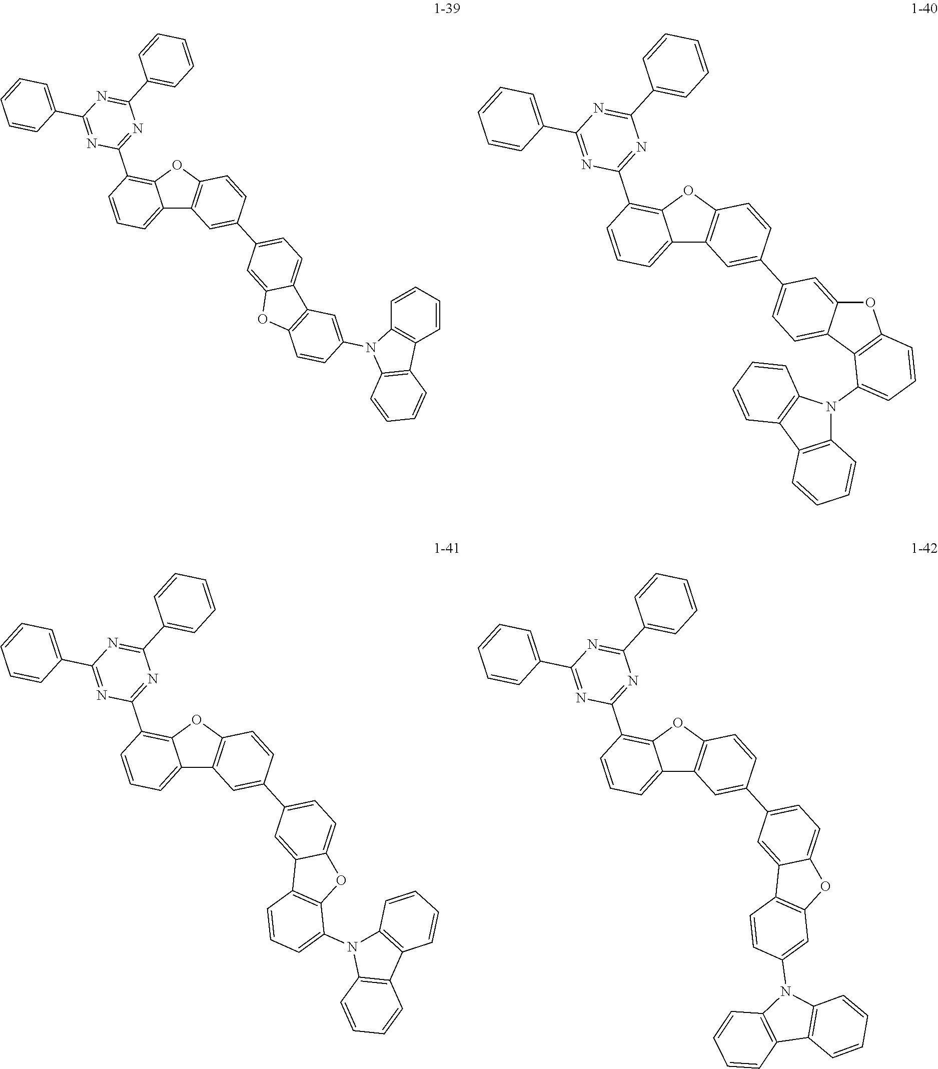 [SMILES: c1ccc(-c2nc(-c3ccccc3)nc(-c3cccc4c3oc3ccc(-c5ccc6c(c5)oc5ccc(-n7c8ccccc8c8ccccc87)cc56)cc34)n2)cc1 ; c1ccc(-c2nc(-c3ccccc3)nc(-c3cccc4c3oc3ccc(-c5ccc6c(c5)oc5cccc(-n7c8ccccc8c8ccccc87)c56)cc34)n2)cc1 ; c1ccc(-c2nc(-c3ccccc3)nc(-c3cccc4c3oc3ccc(-c5ccc6oc7c(-n8c9ccccc9c9ccccc98)cccc7c6c5)cc34)n2)cc1 ; c1ccc(-c2nc(-c3ccccc3)nc(-c3cccc4c3oc3ccc(-c5ccc6oc7cc(-n8c9ccccc9c9ccccc98)ccc7c6c5)cc34)n2)cc1]

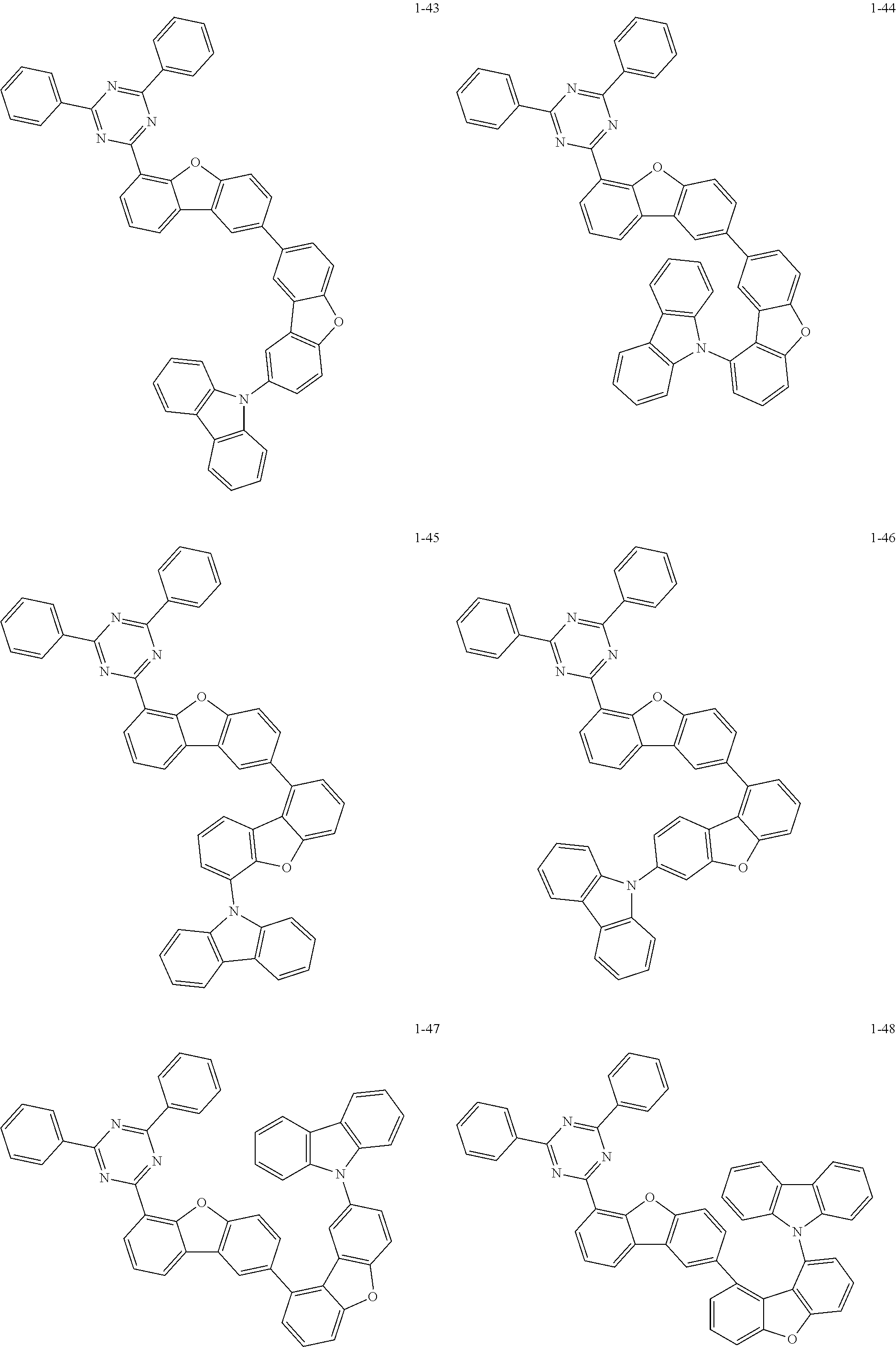

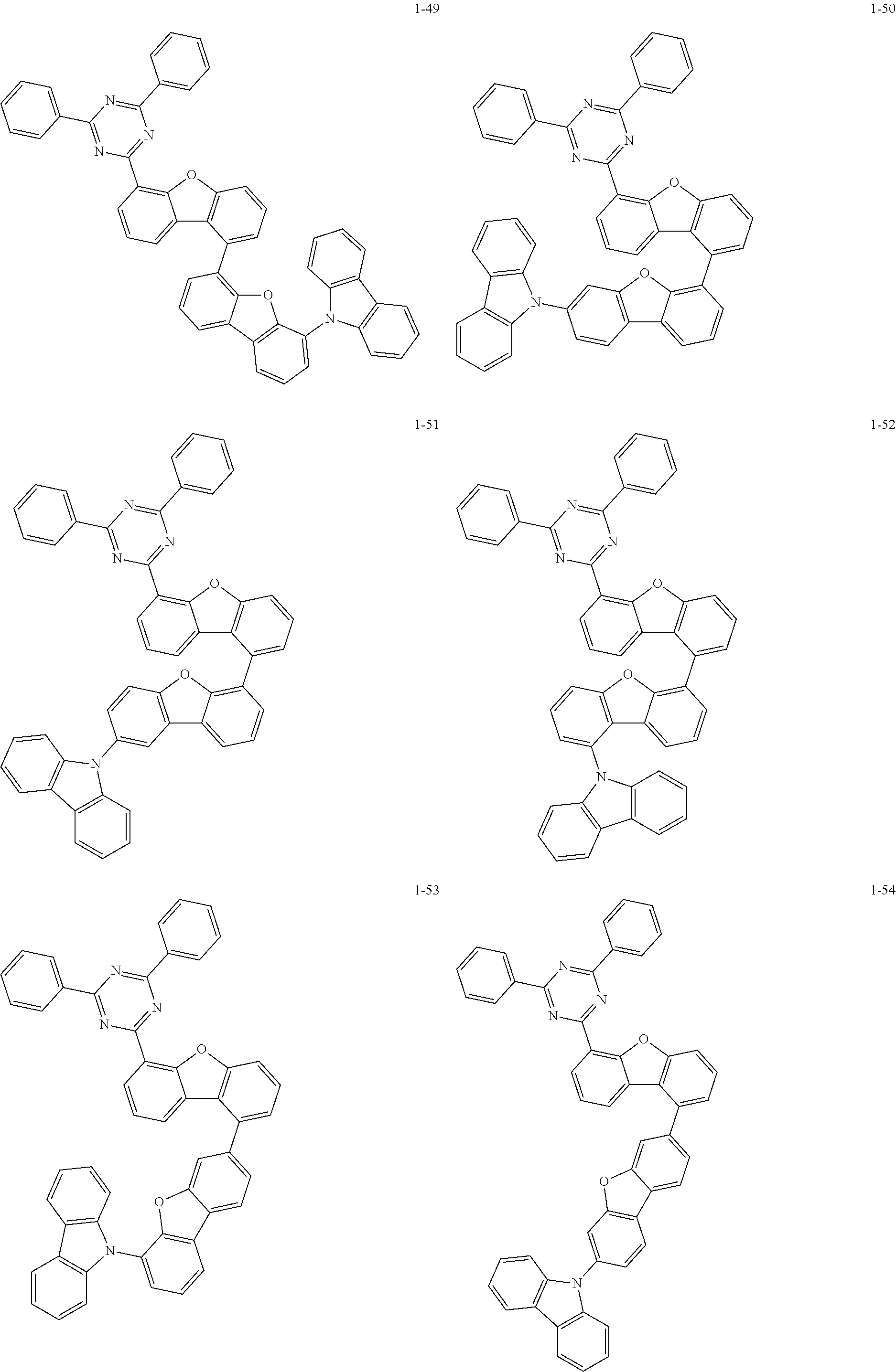

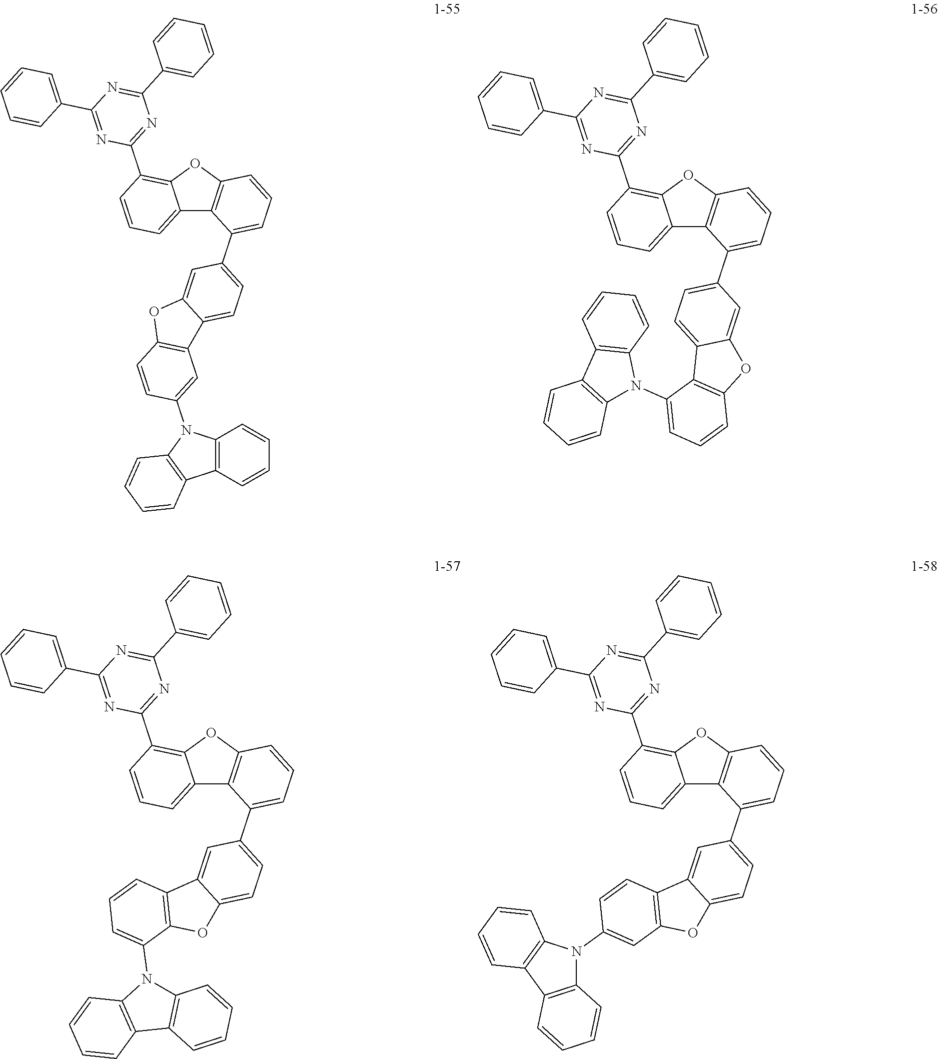 [SMILES: c1ccc(-c2nc(-c3ccccc3)nc(-c3cccc4c3oc3cccc(-c5ccc6c(c5)oc5ccc(-n7c8ccccc8c8ccccc87)cc56)c34)n2)cc1 ; c1ccc(-c2nc(-c3ccccc3)nc(-c3cccc4c3oc3cccc(-c5ccc6c(c5)oc5cccc(-n7c8ccccc8c8ccccc87)c56)c34)n2)cc1 ; c1ccc(-c2nc(-c3ccccc3)nc(-c3cccc4c3oc3cccc(-c5ccc6oc7c(-n8c9ccccc9c9ccccc98)cccc7c6c5)c34)n2)cc1 ; c1ccc(-c2nc(-c3ccccc3)nc(-c3cccc4c3oc3cccc(-c5ccc6oc7cc(-n8c9ccccc9c9ccccc98)ccc7c6c5)c34)n2)cc1]

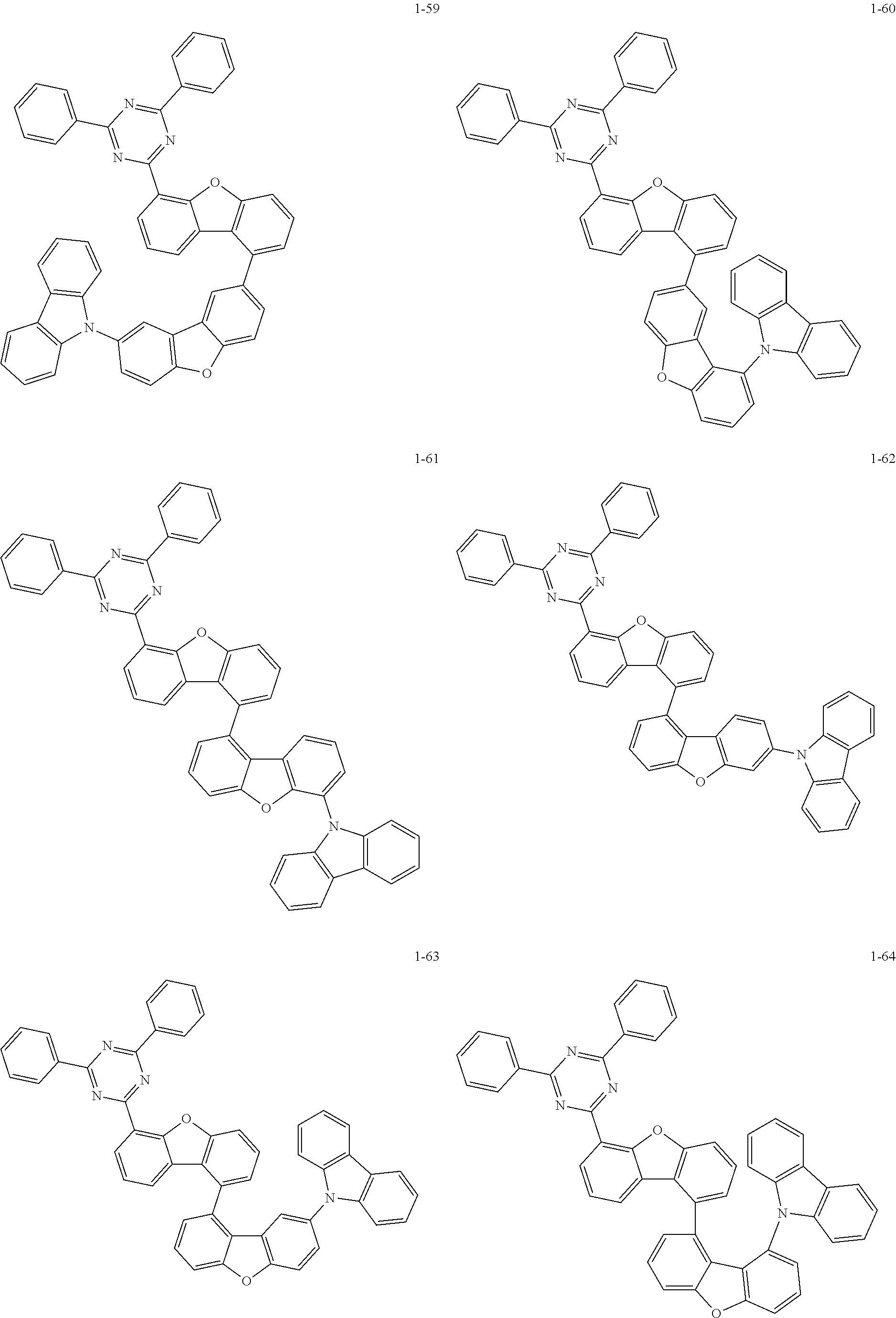

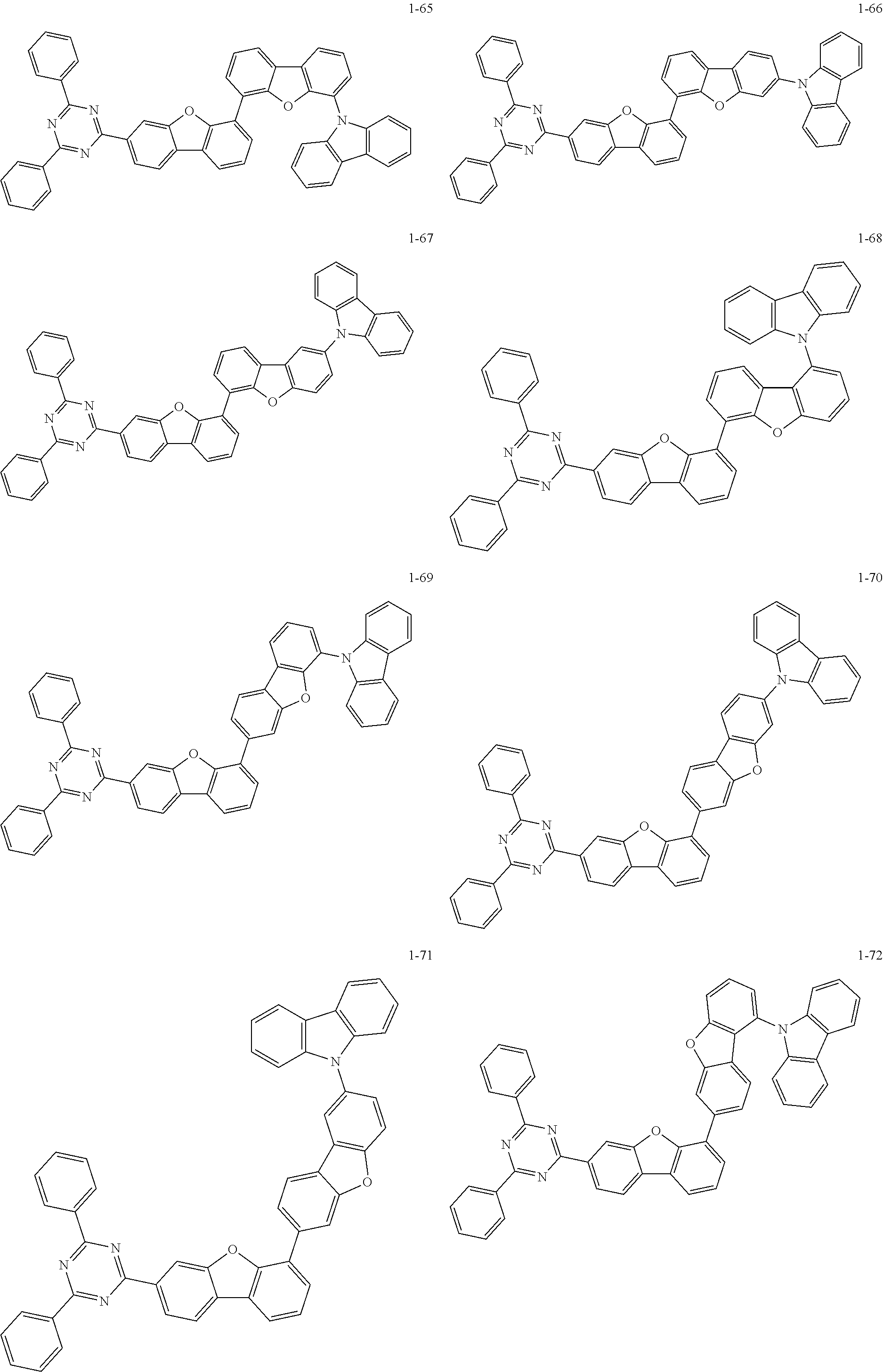

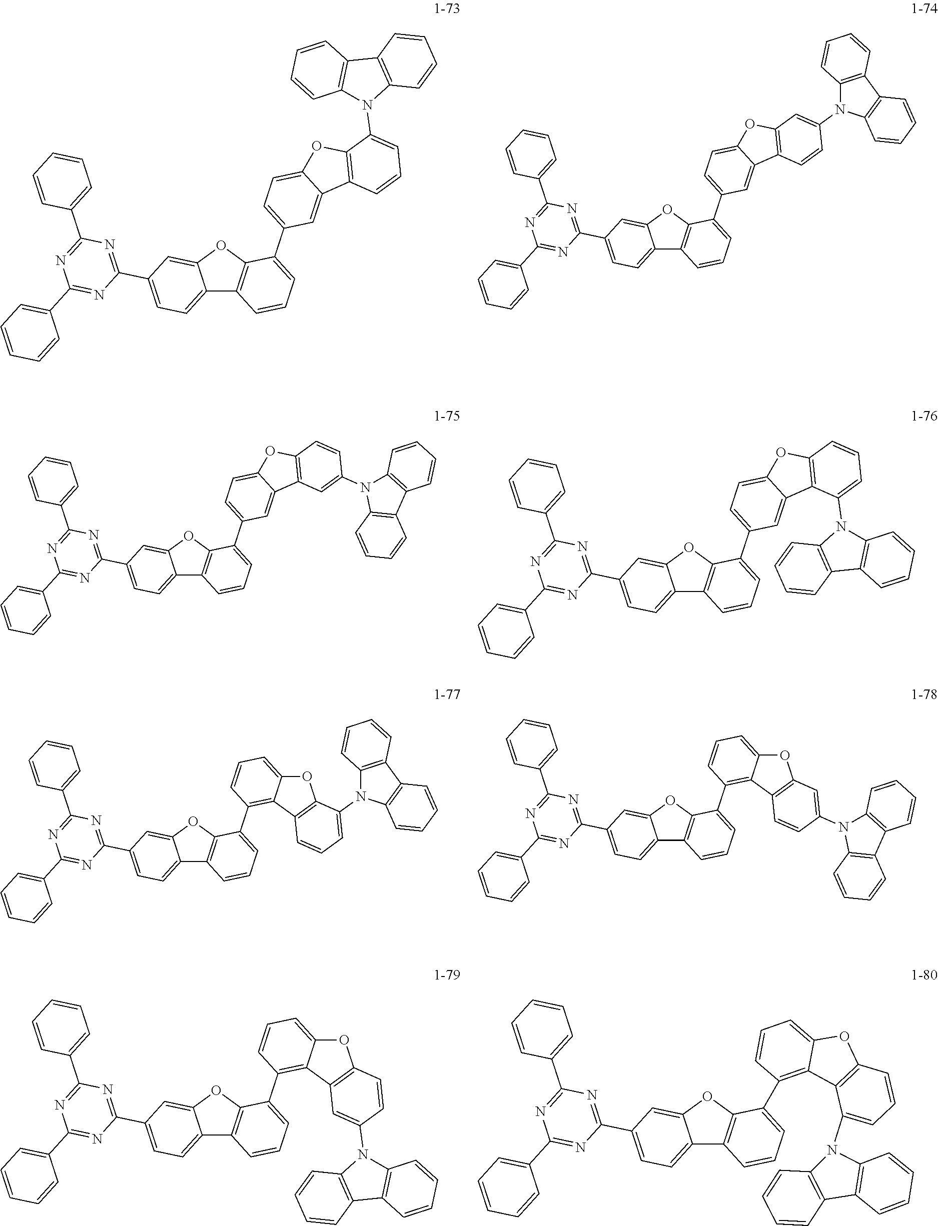

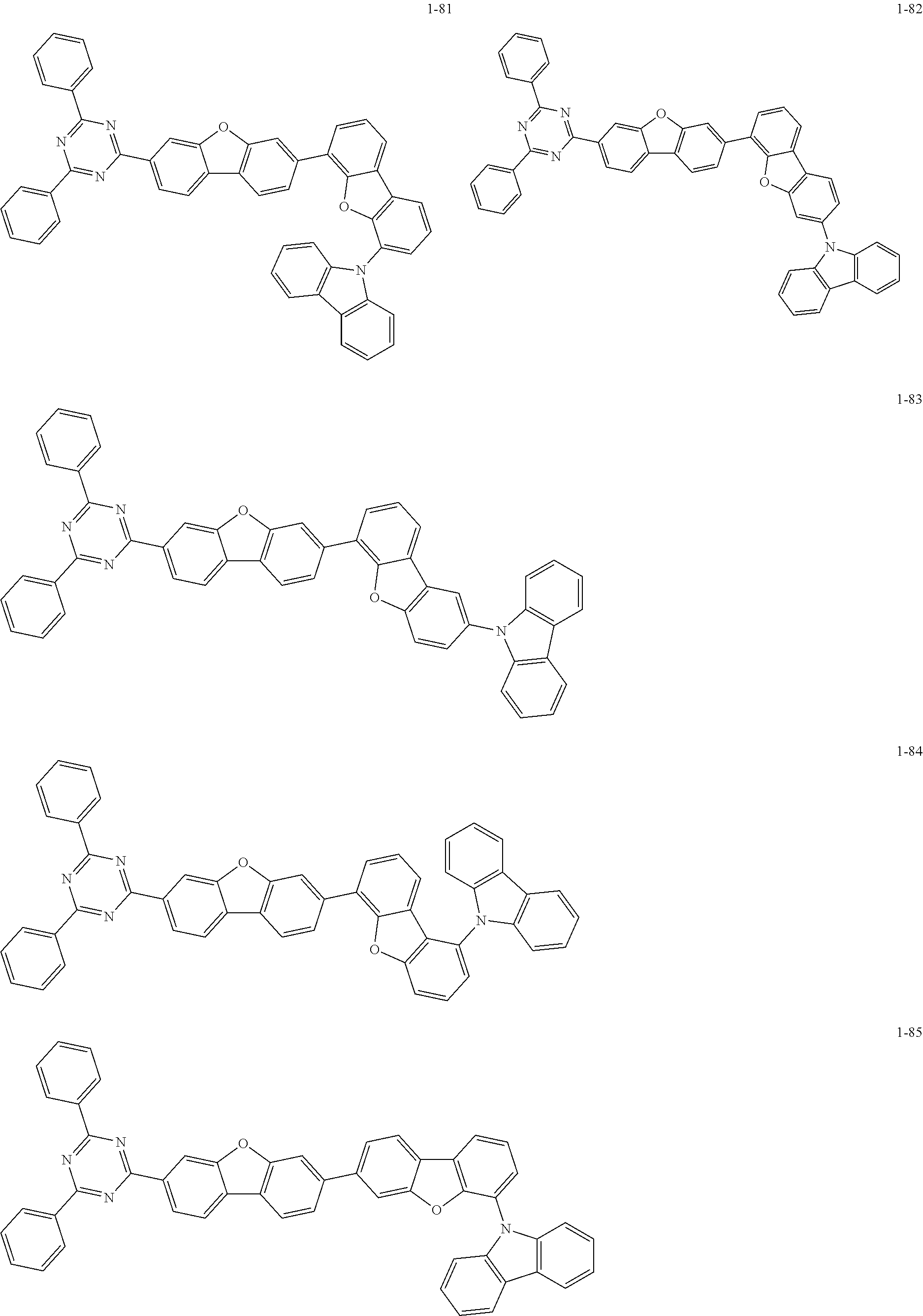

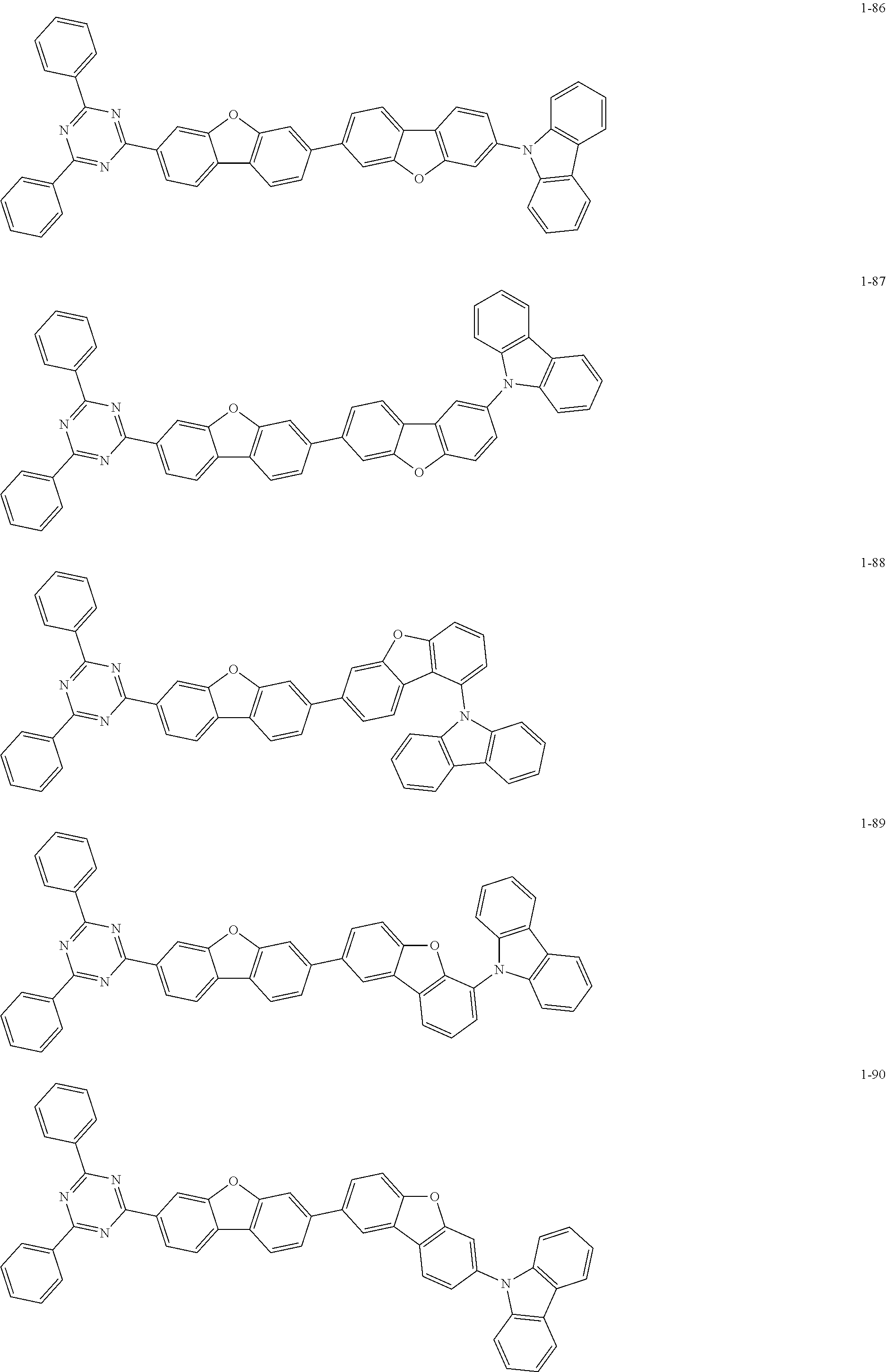

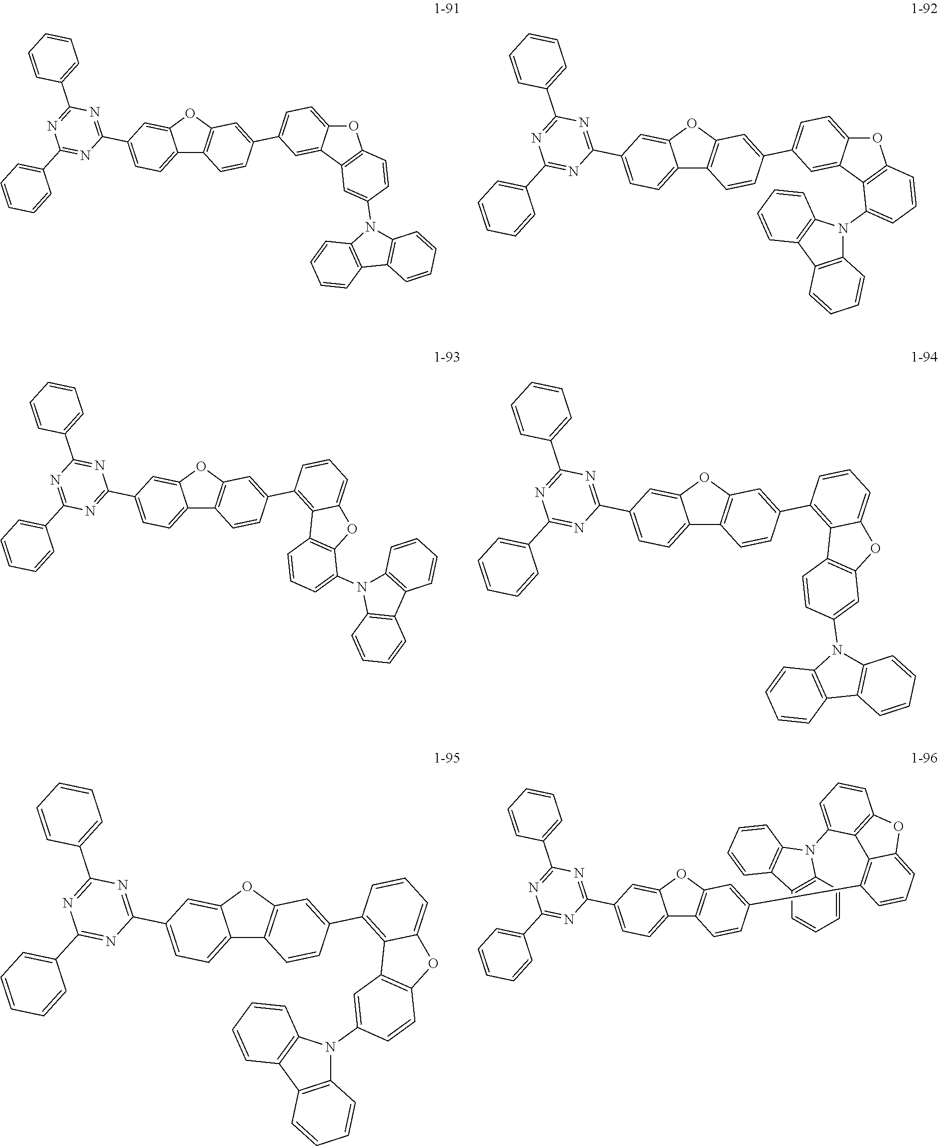

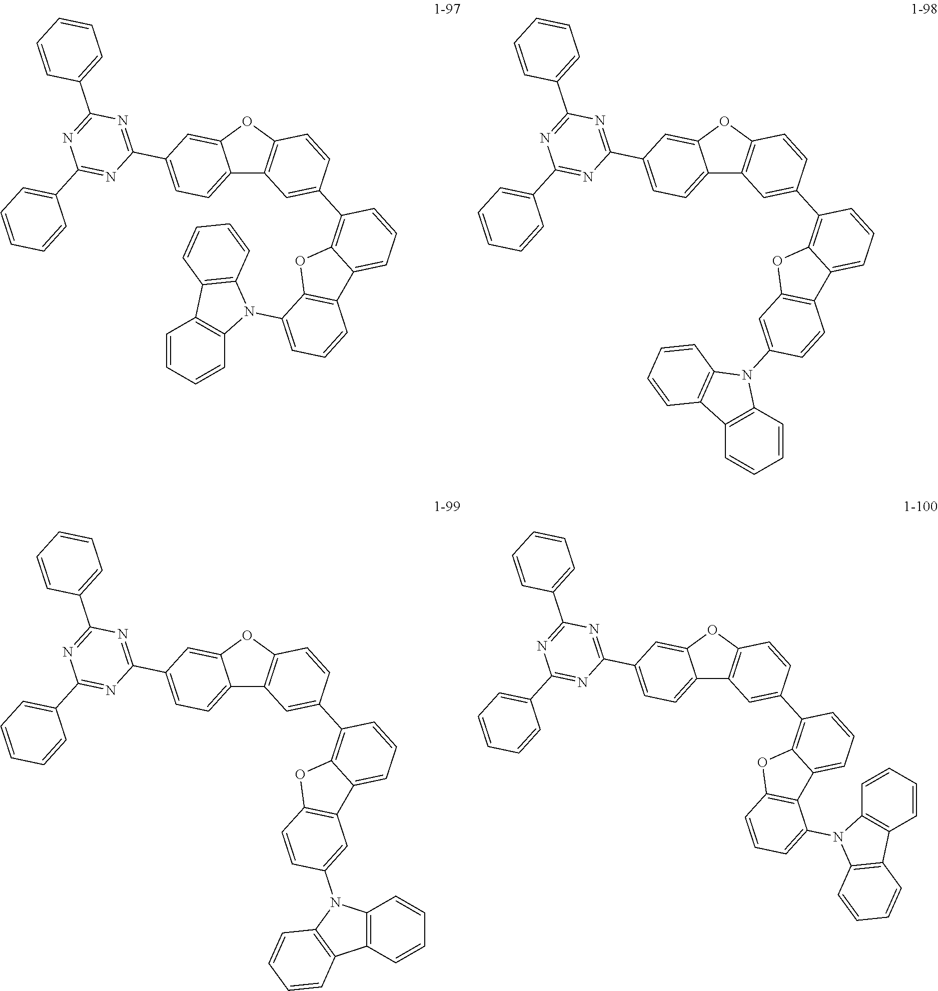 [SMILES: c1ccc(-c2nc(-c3ccccc3)nc(-c3ccc4c(c3)oc3ccc(-c5cccc6c5oc5c(-n7c8ccccc8c8ccccc87)cccc56)cc34)n2)cc1 ; c1ccc(-c2nc(-c3ccccc3)nc(-c3ccc4c(c3)oc3ccc(-c5cccc6c5oc5cc(-n7c8ccccc8c8ccccc87)ccc56)cc34)n2)cc1 ; c1ccc(-c2nc(-c3ccccc3)nc(-c3ccc4c(c3)oc3ccc(-c5cccc6c5oc5ccc(-n7c8ccccc8c8ccccc87)cc56)cc34)n2)cc1 ; c1ccc(-c2nc(-c3ccccc3)nc(-c3ccc4c(c3)oc3ccc(-c5cccc6c5oc5cccc(-n7c8ccccc8c8ccccc87)c56)cc34)n2)cc1]

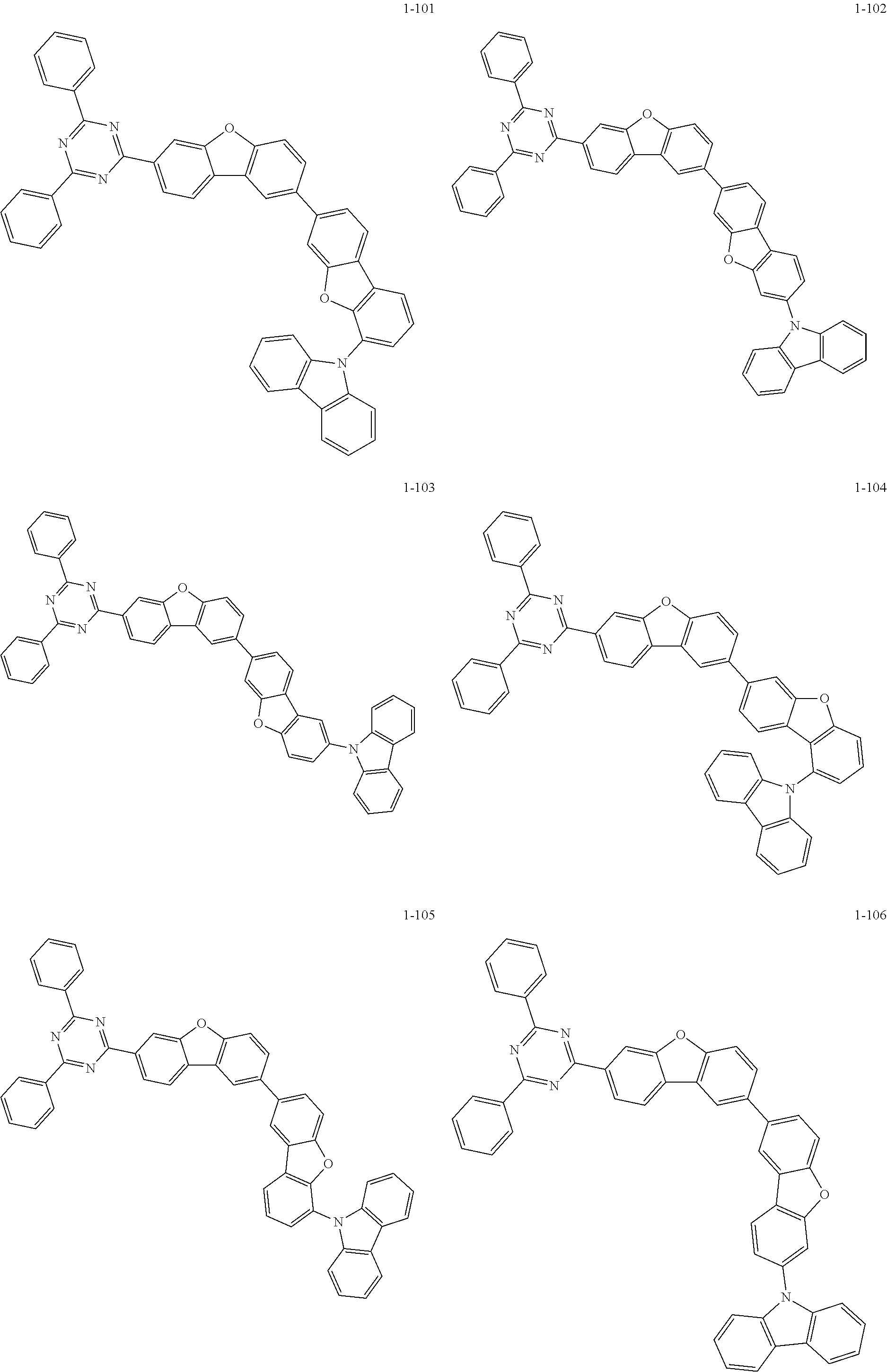

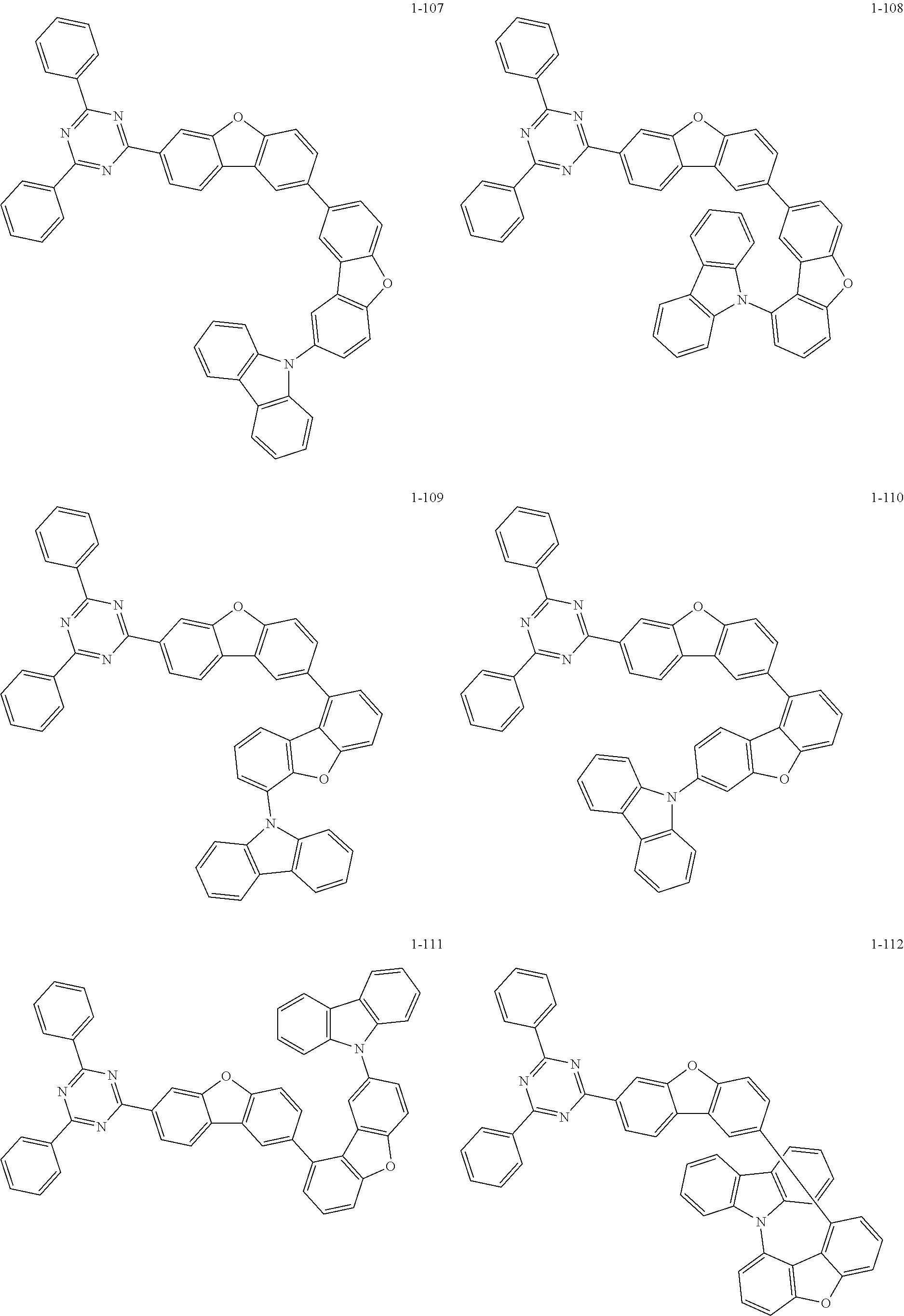

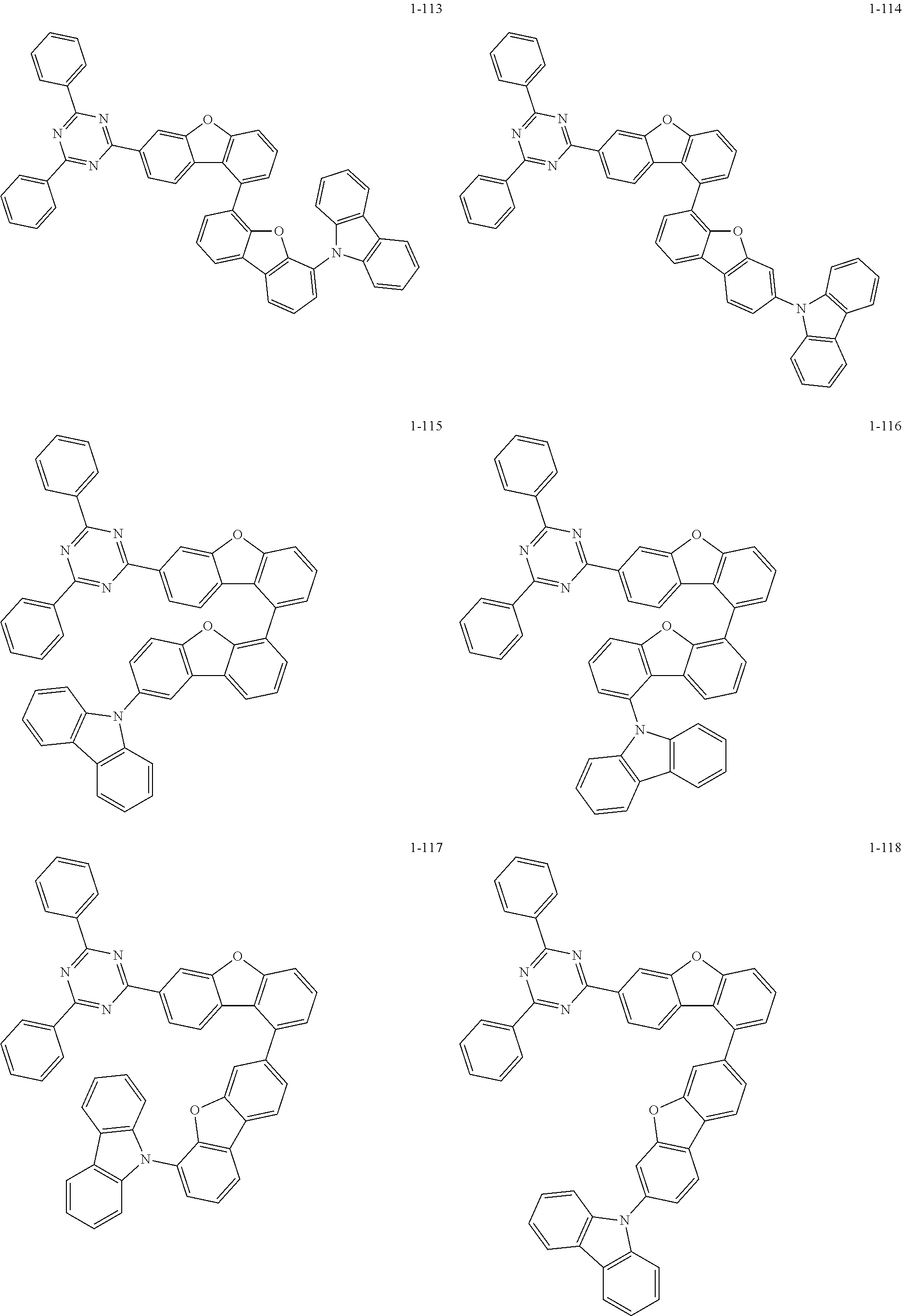

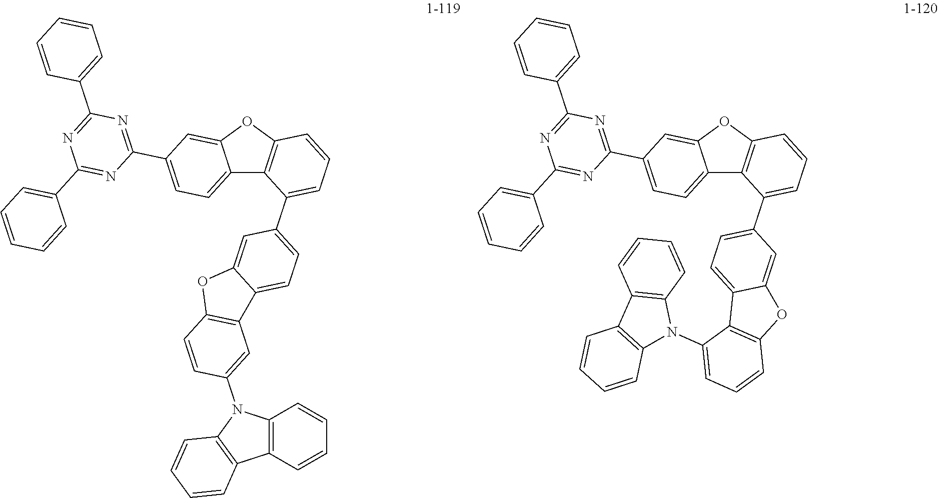 [SMILES: c1ccc(-c2nc(-c3ccccc3)nc(-c3ccc4c(c3)oc3cccc(-c5ccc6c(c5)oc5ccc(-n7c8ccccc8c8ccccc87)cc56)c34)n2)cc1 ; c1ccc(-c2nc(-c3ccccc3)nc(-c3ccc4c(c3)oc3cccc(-c5ccc6c(c5)oc5cccc(-n7c8ccccc8c8ccccc87)c56)c34)n2)cc1]

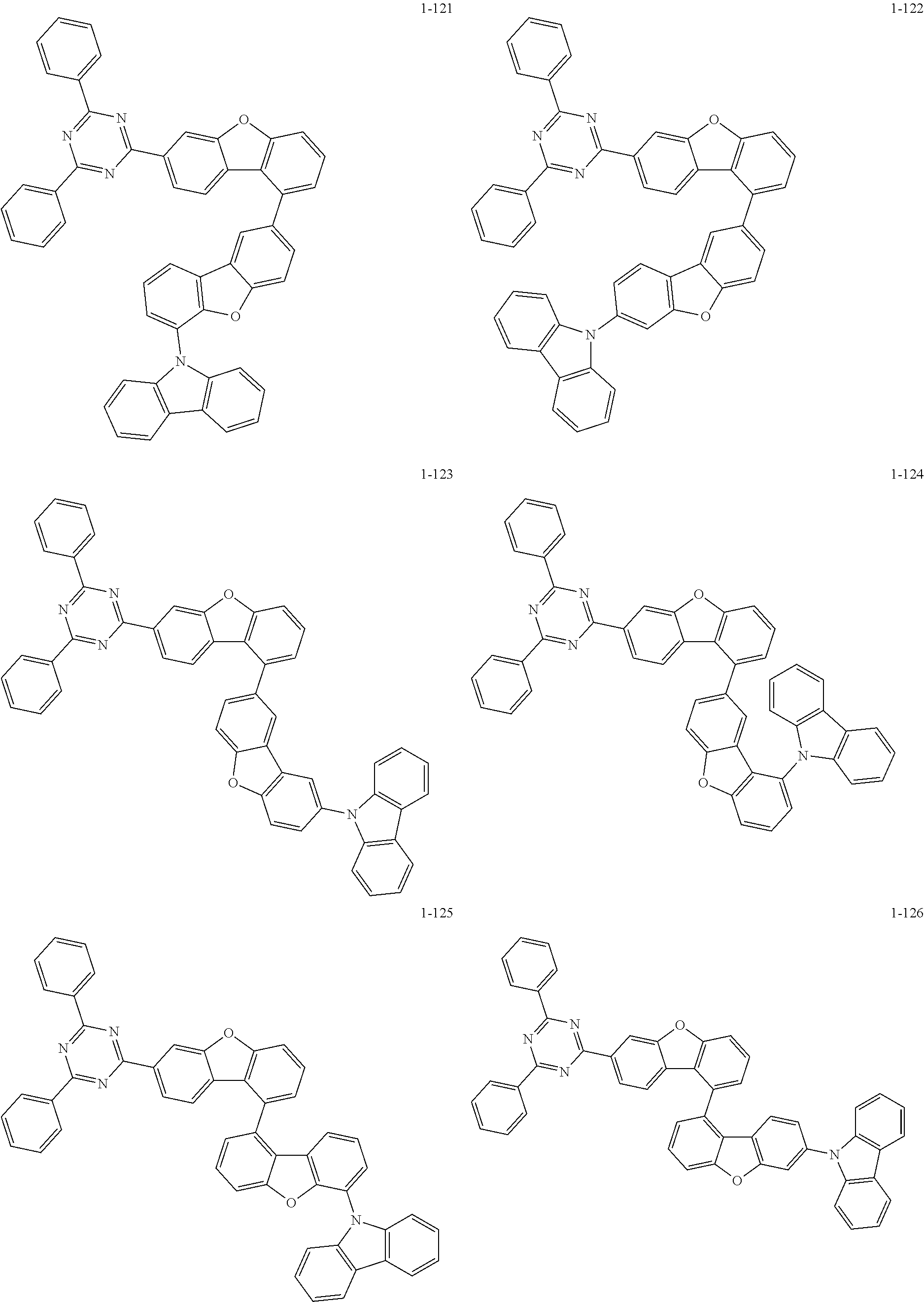

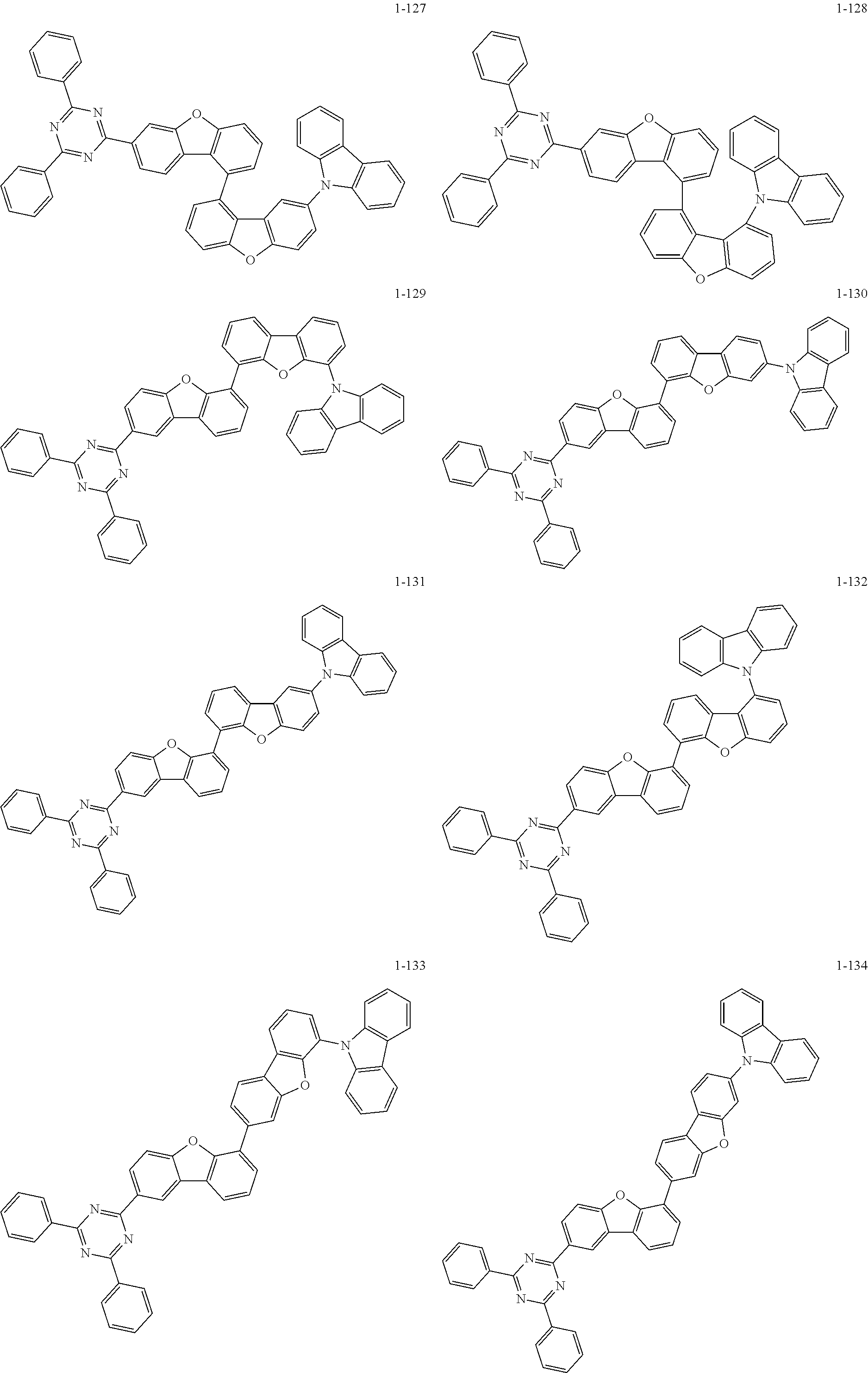

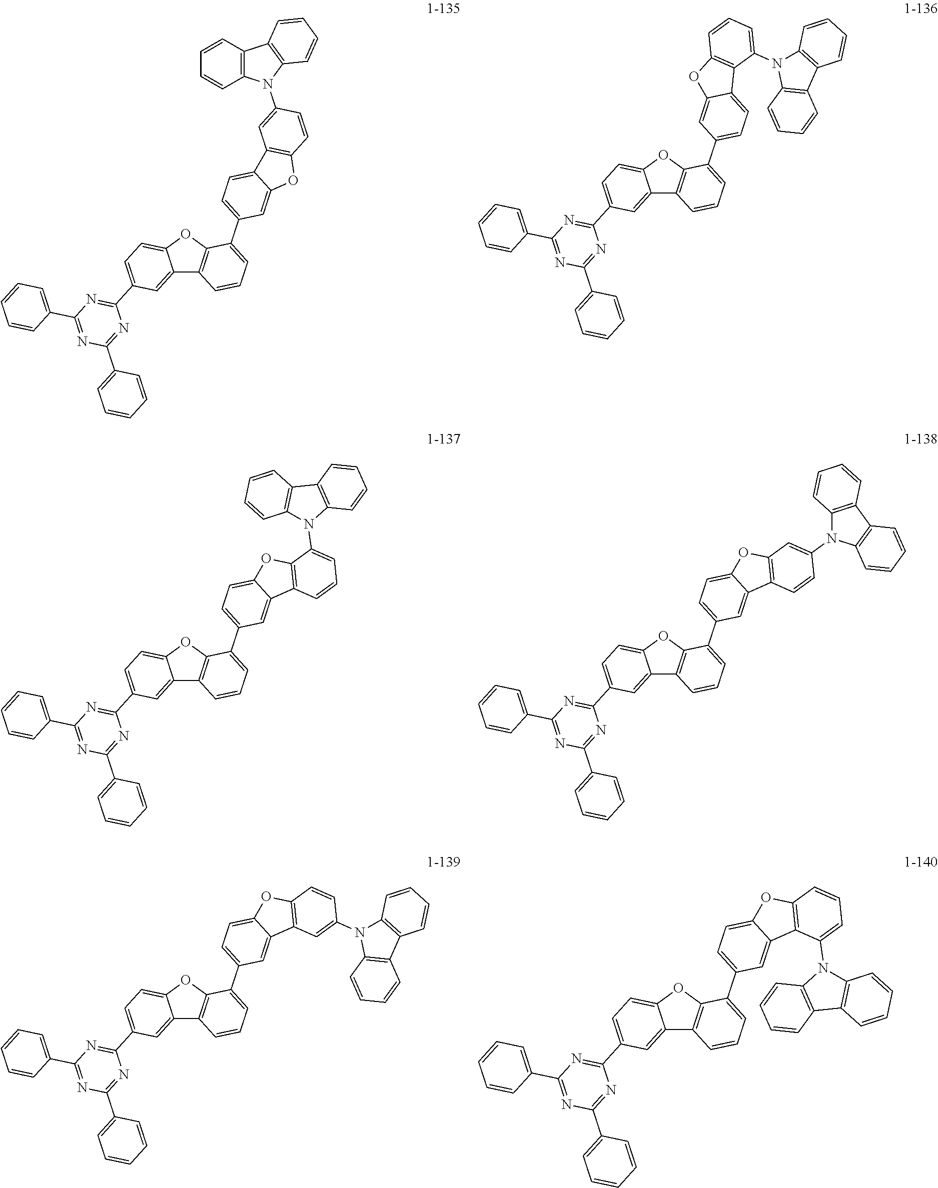

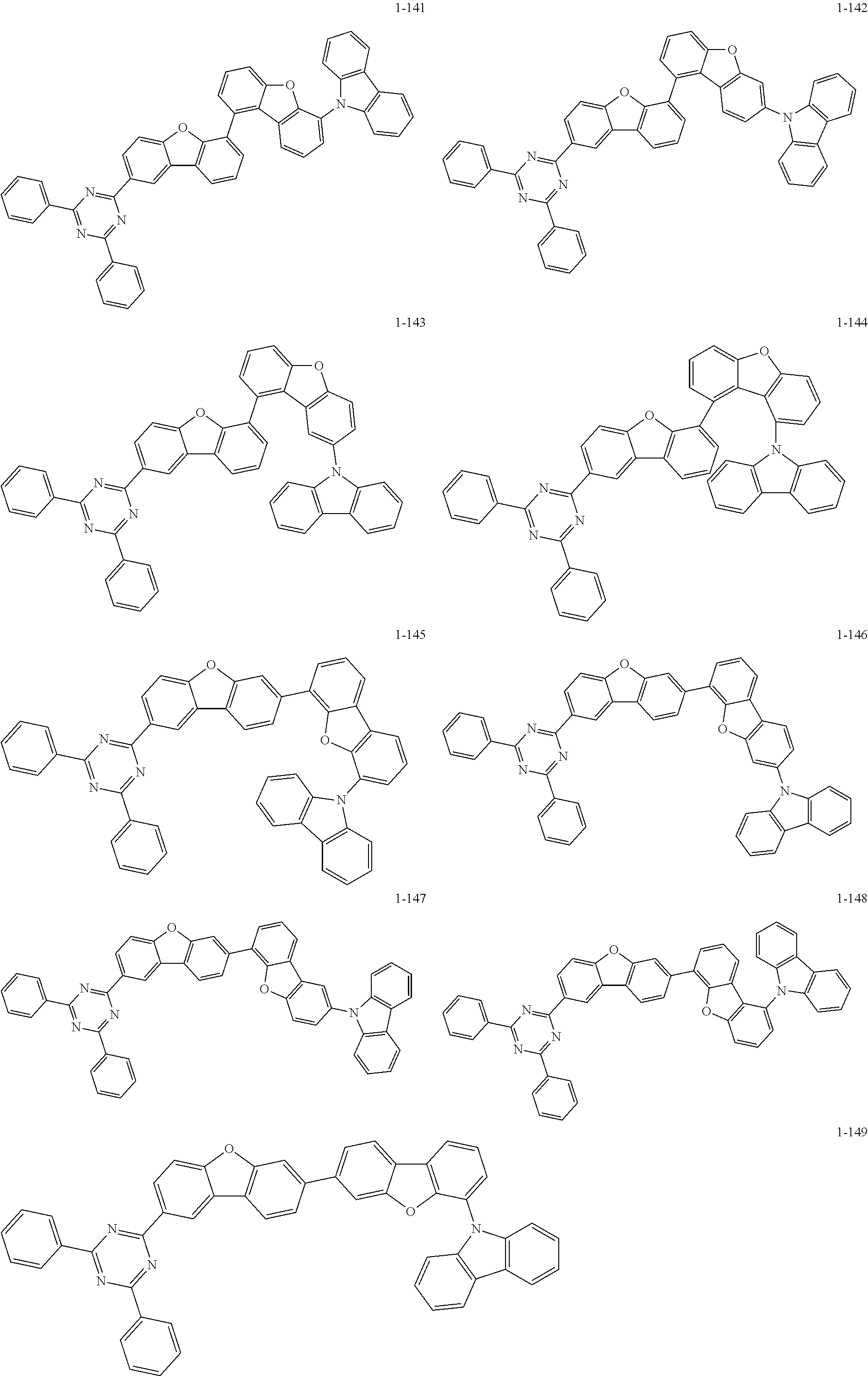

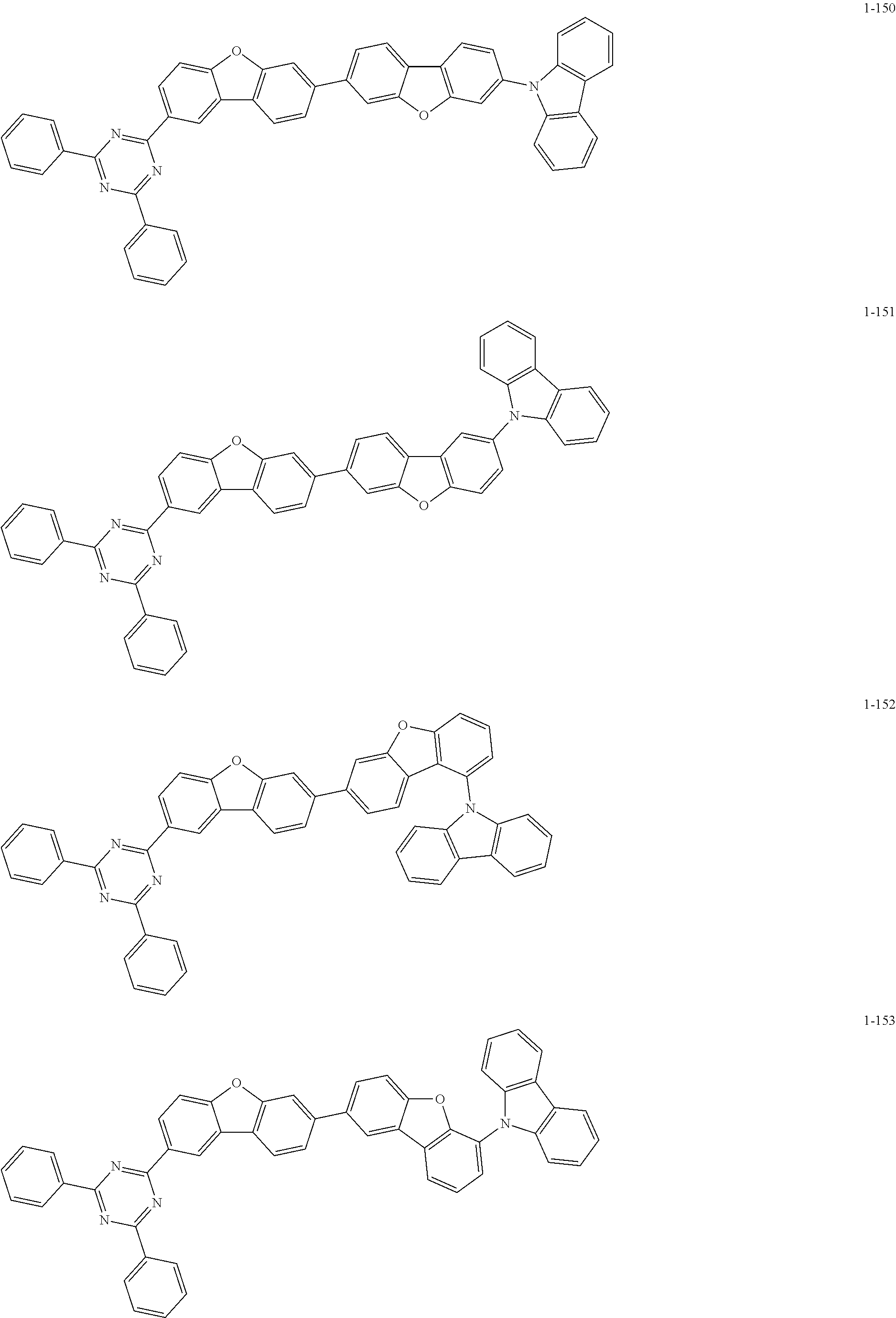 [SMILES: c1ccc(-c2nc(-c3ccccc3)nc(-c3ccc4oc5cc(-c6ccc7c(c6)oc6cc(-n8c9ccccc9c9ccccc98)ccc67)ccc5c4c3)n2)cc1 ; c1ccc(-c2nc(-c3ccccc3)nc(-c3ccc4oc5cc(-c6ccc7c(c6)oc6ccc(-n8c9ccccc9c9ccccc98)cc67)ccc5c4c3)n2)cc1 ; c1ccc(-c2nc(-c3ccccc3)nc(-c3ccc4oc5cc(-c6ccc7c(c6)oc6cccc(-n8c9ccccc9c9ccccc98)c67)ccc5c4c3)n2)cc1 ; c1ccc(-c2nc(-c3ccccc3)nc(-c3ccc4oc5cc(-c6ccc7oc8c(-n9c%10ccccc%10c%10ccccc%109)cccc8c7c6)ccc5c4c3)n2)cc1]

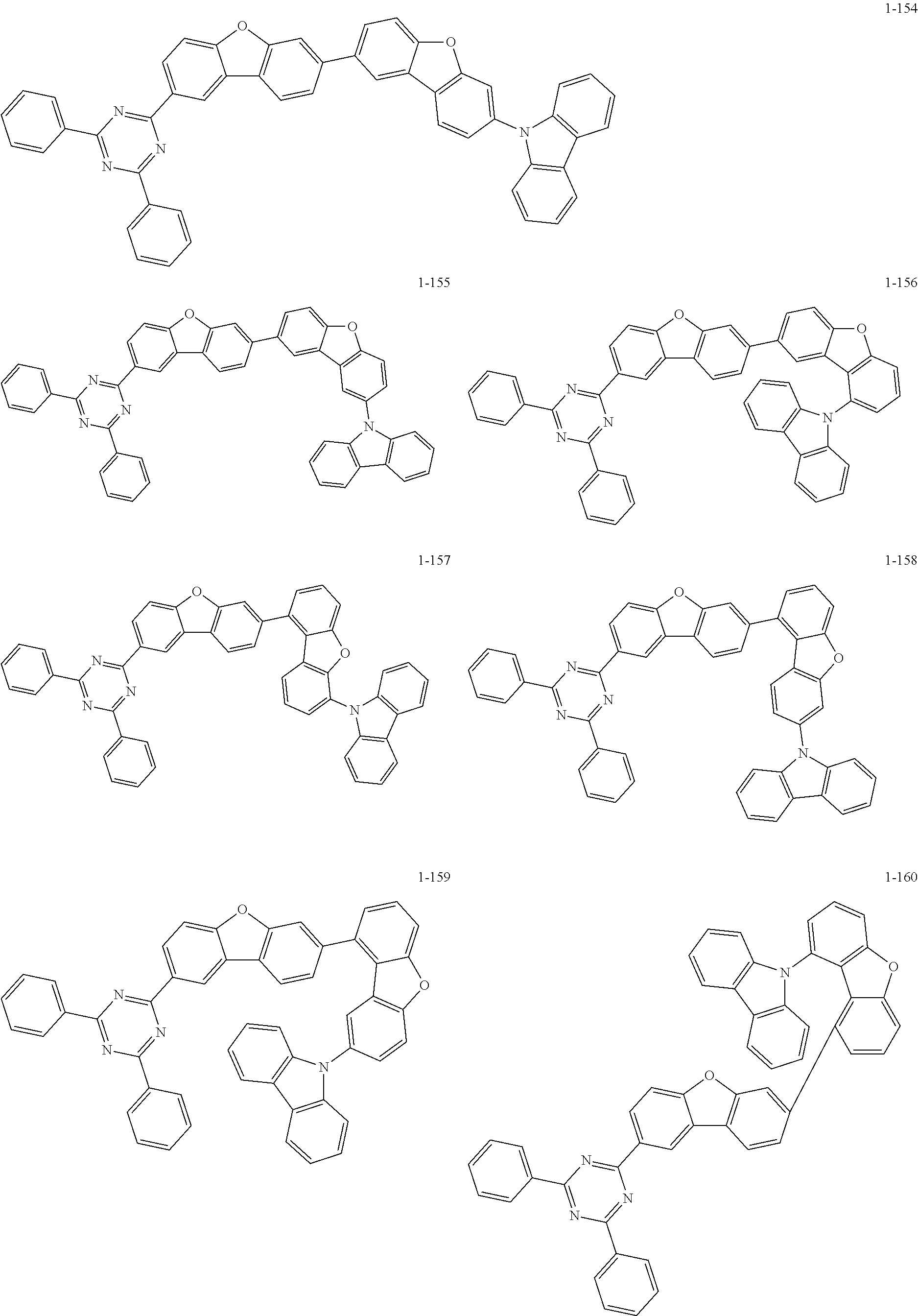

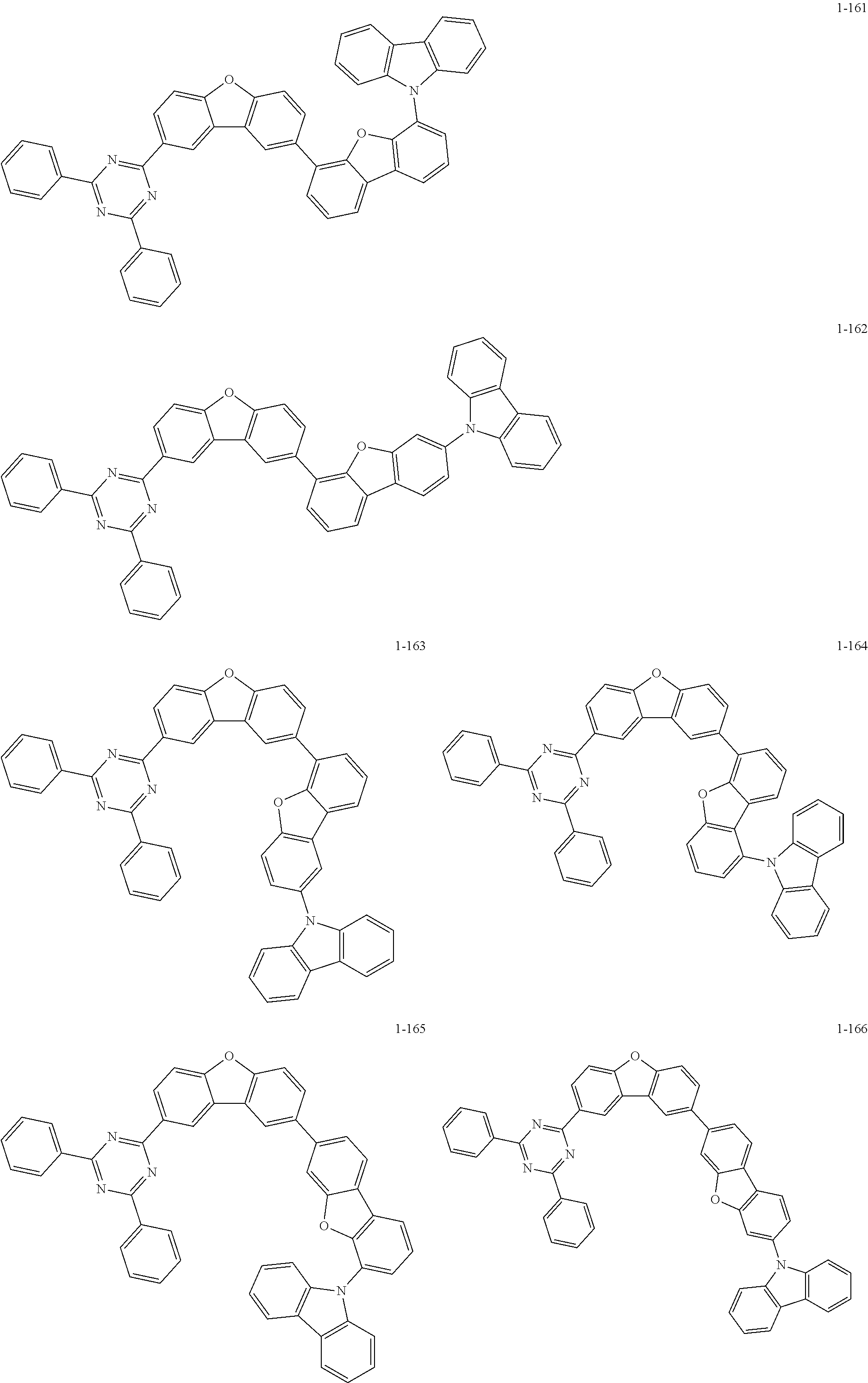

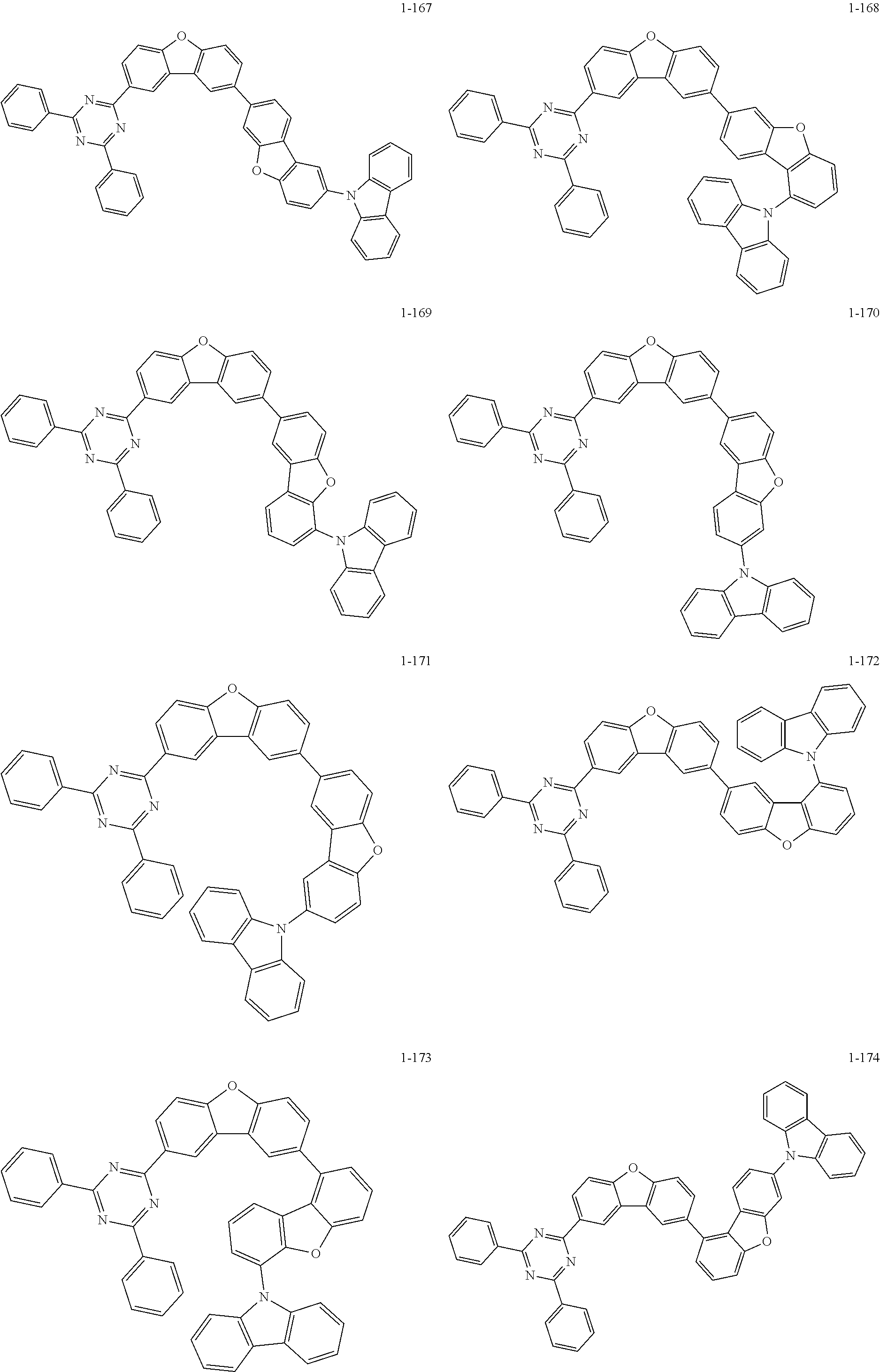

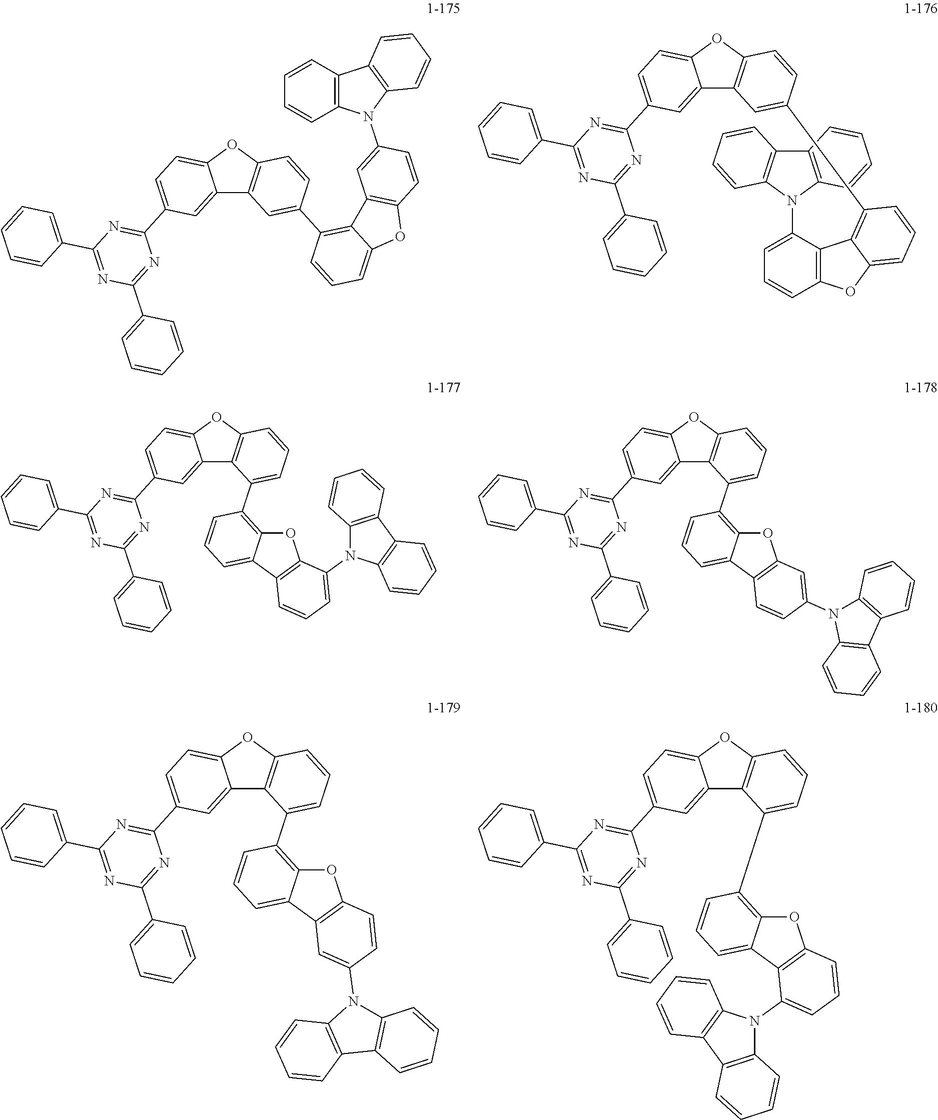

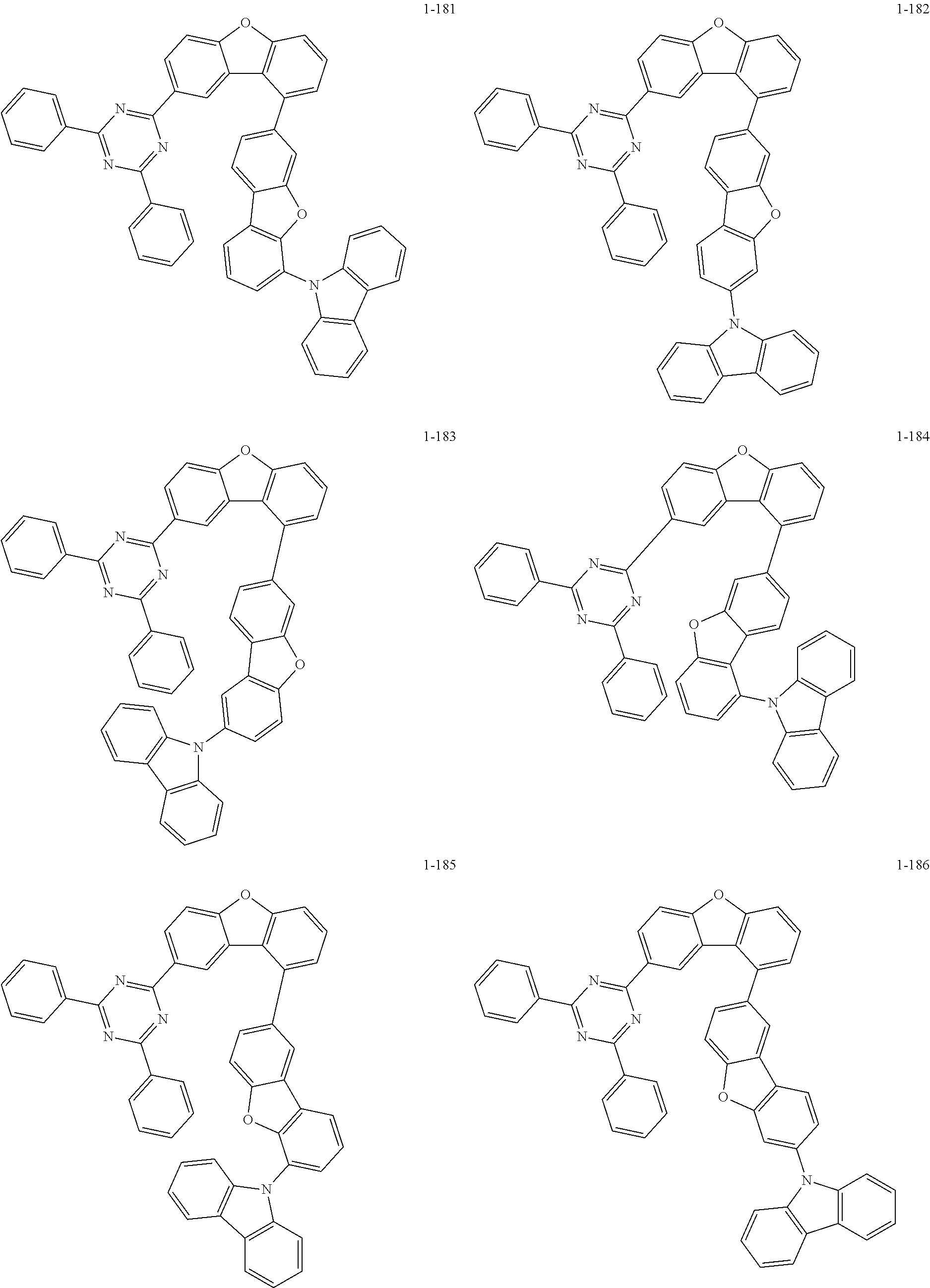

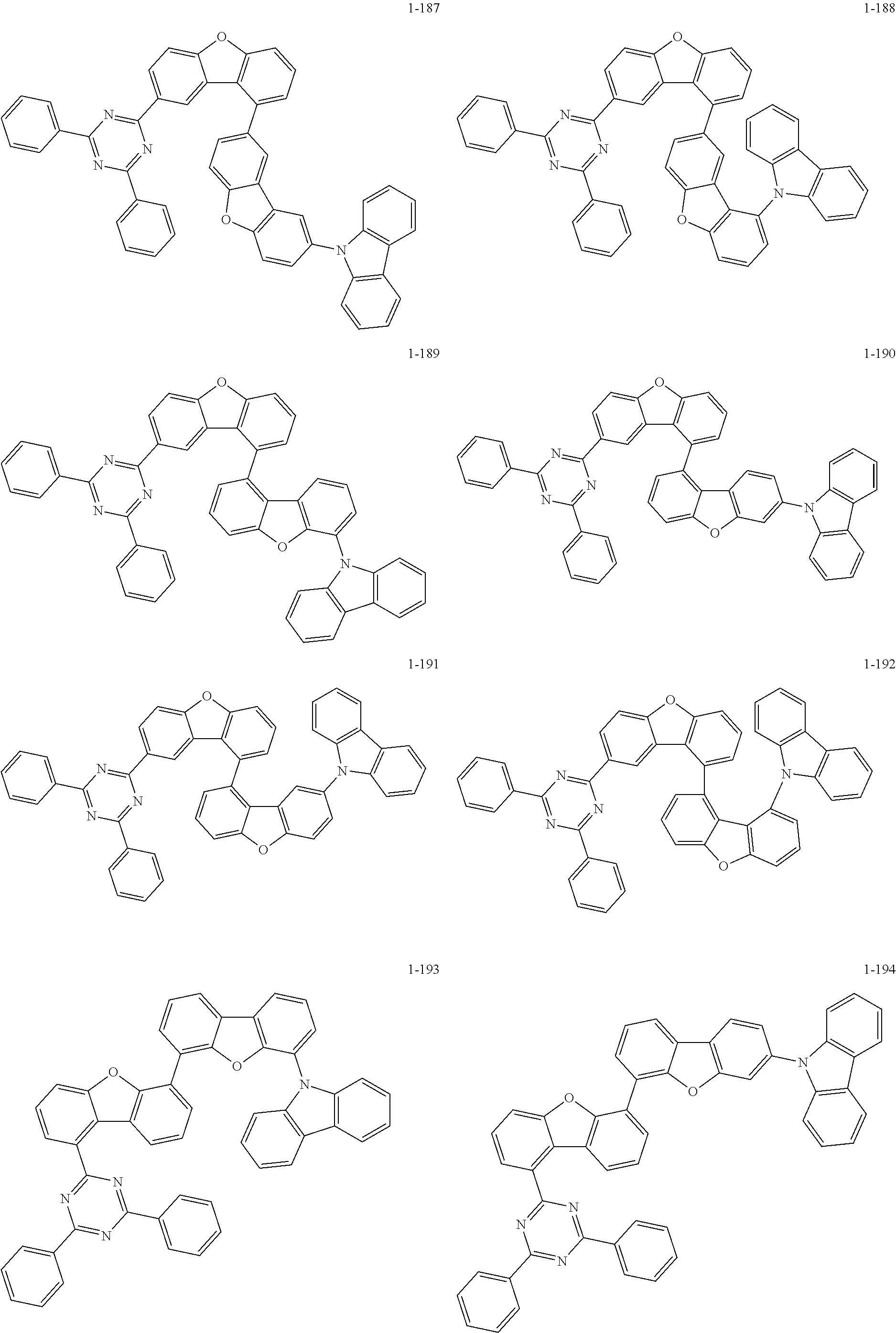

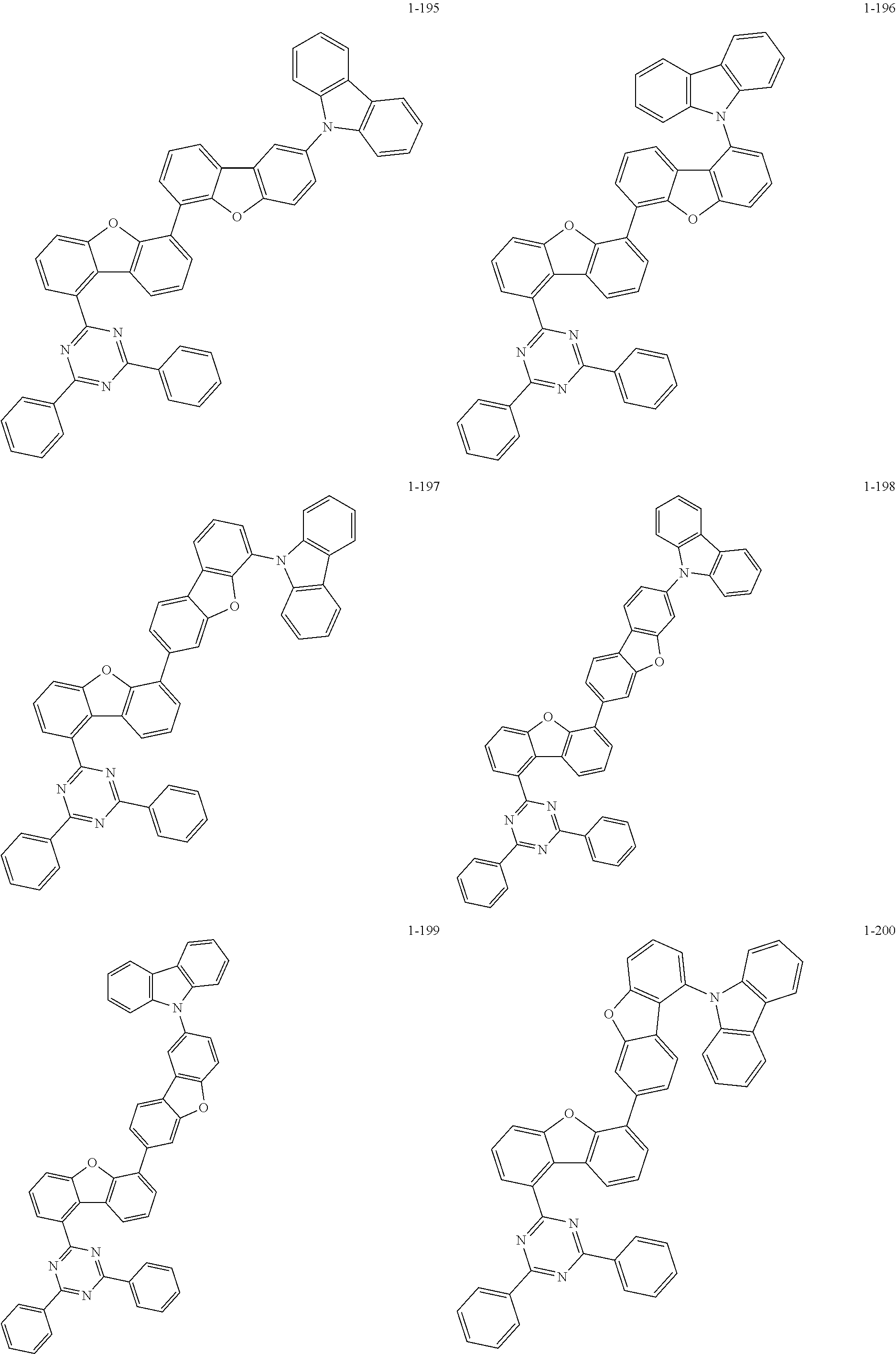

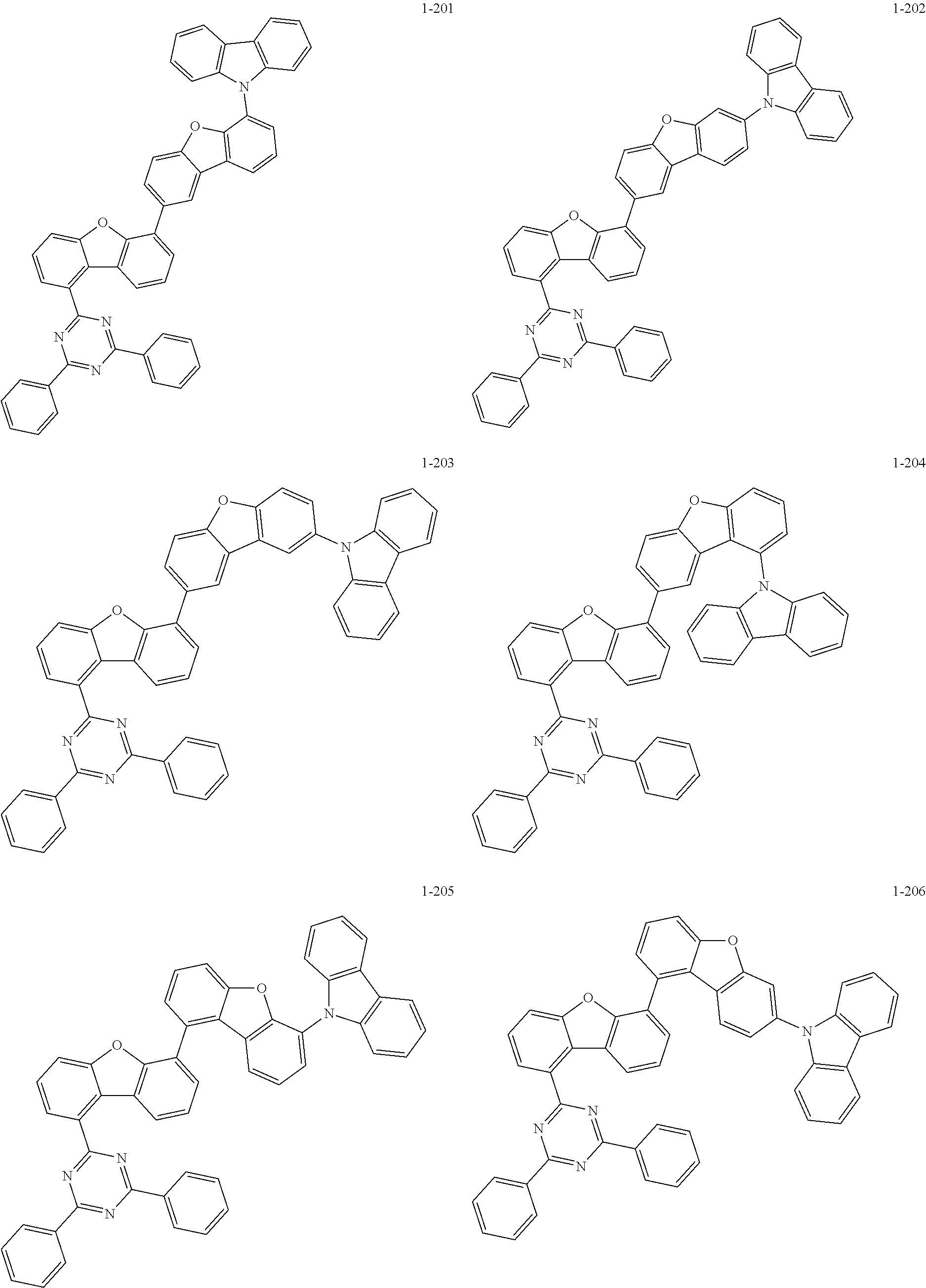

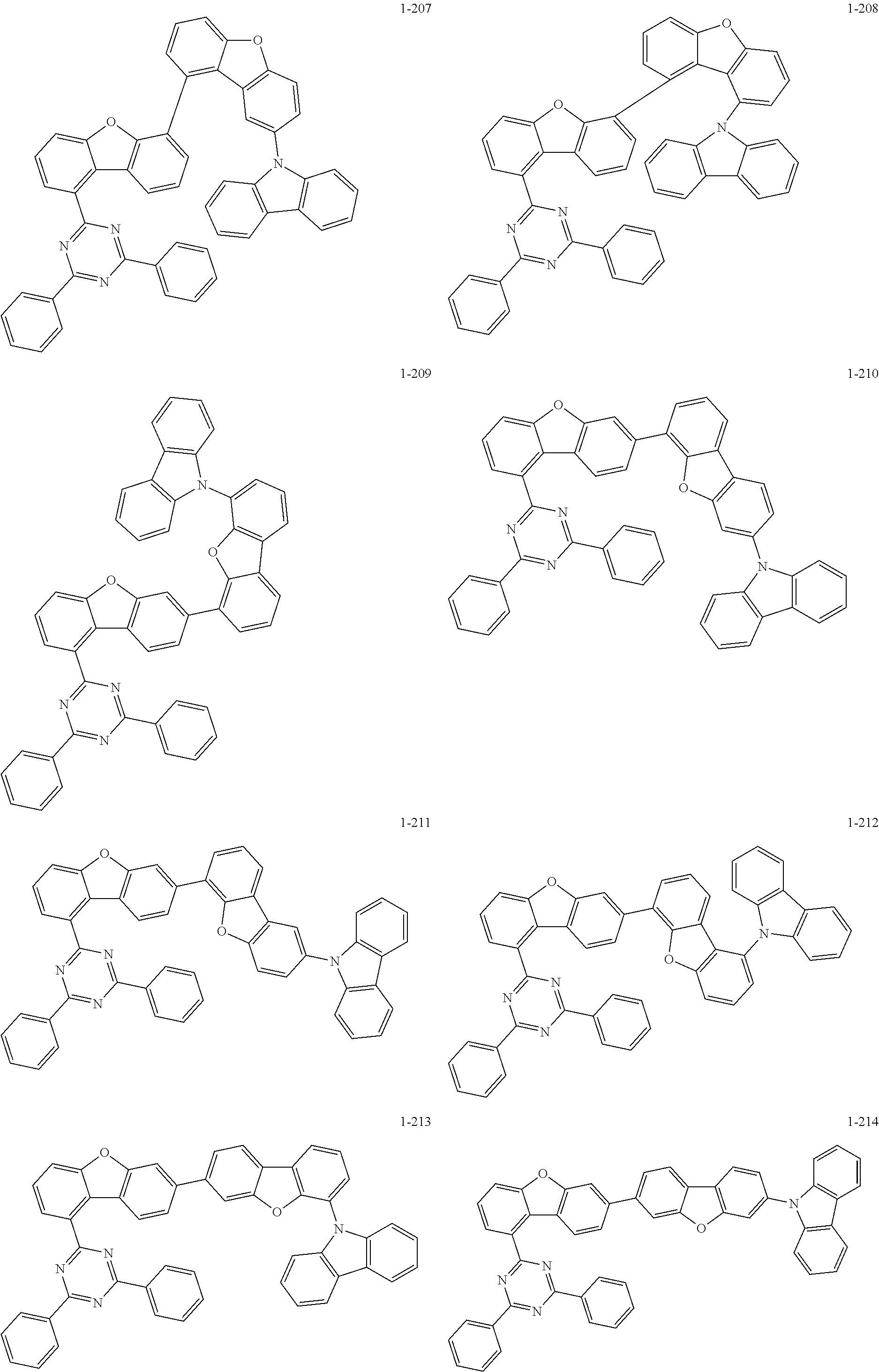

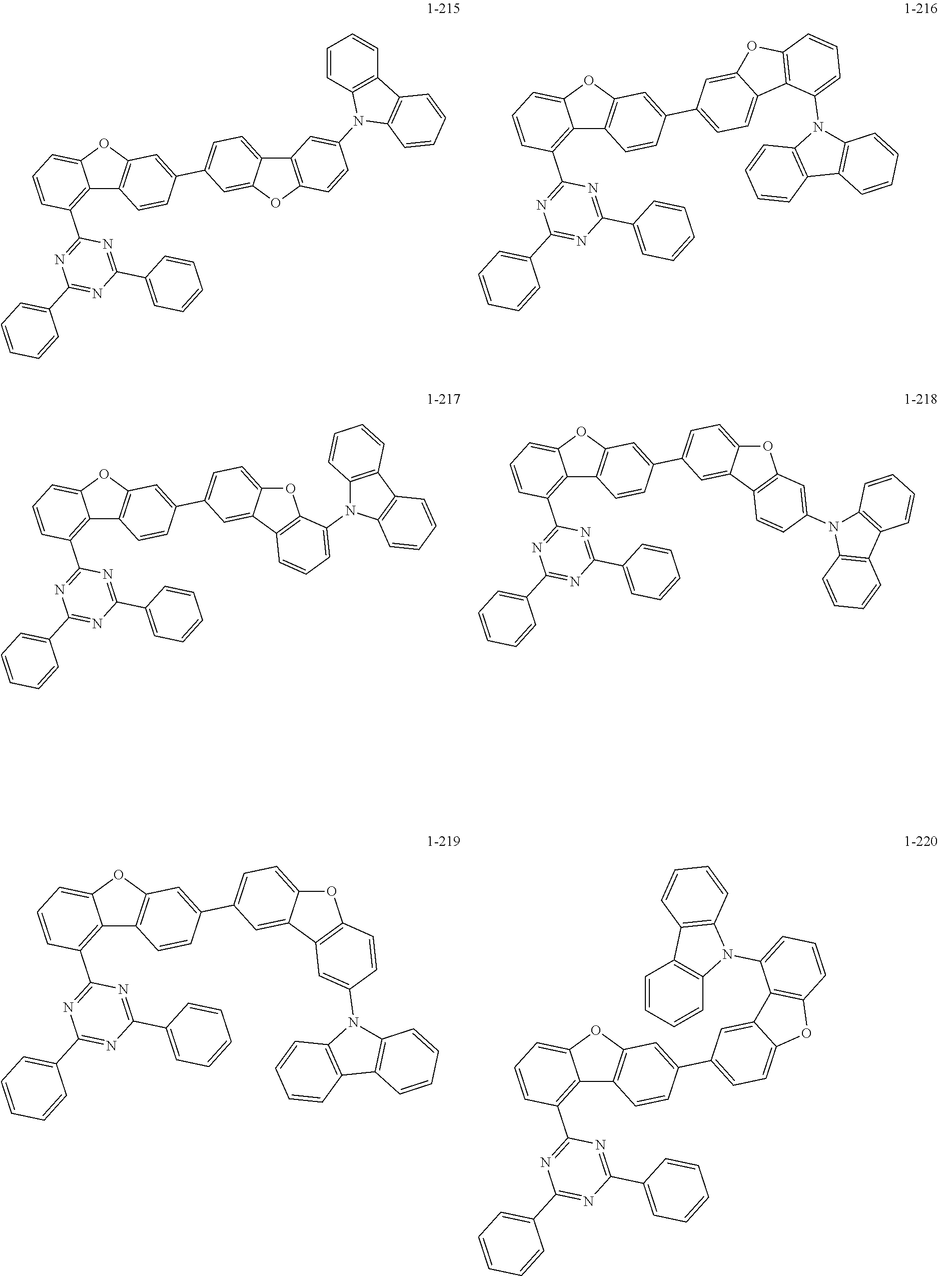

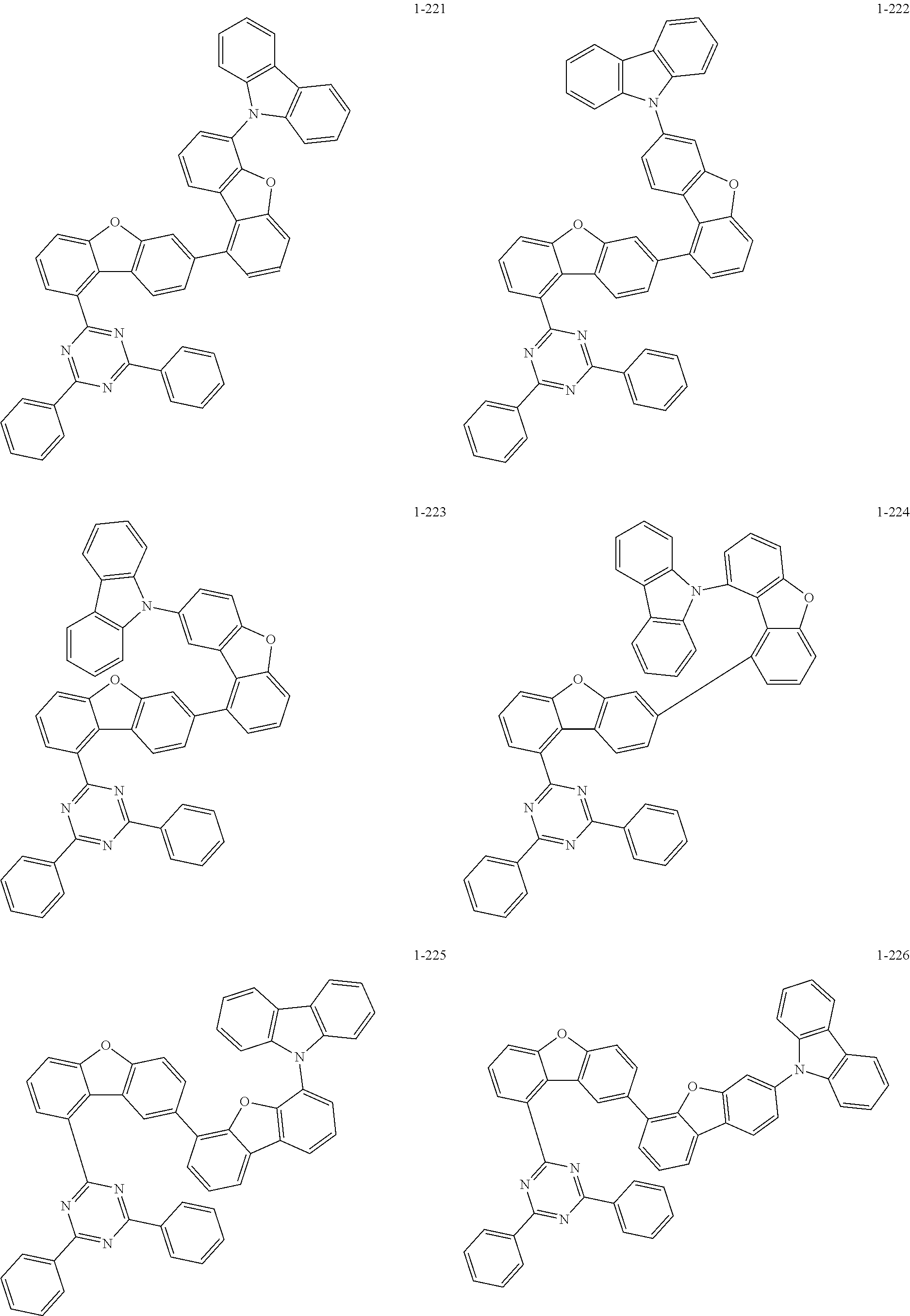

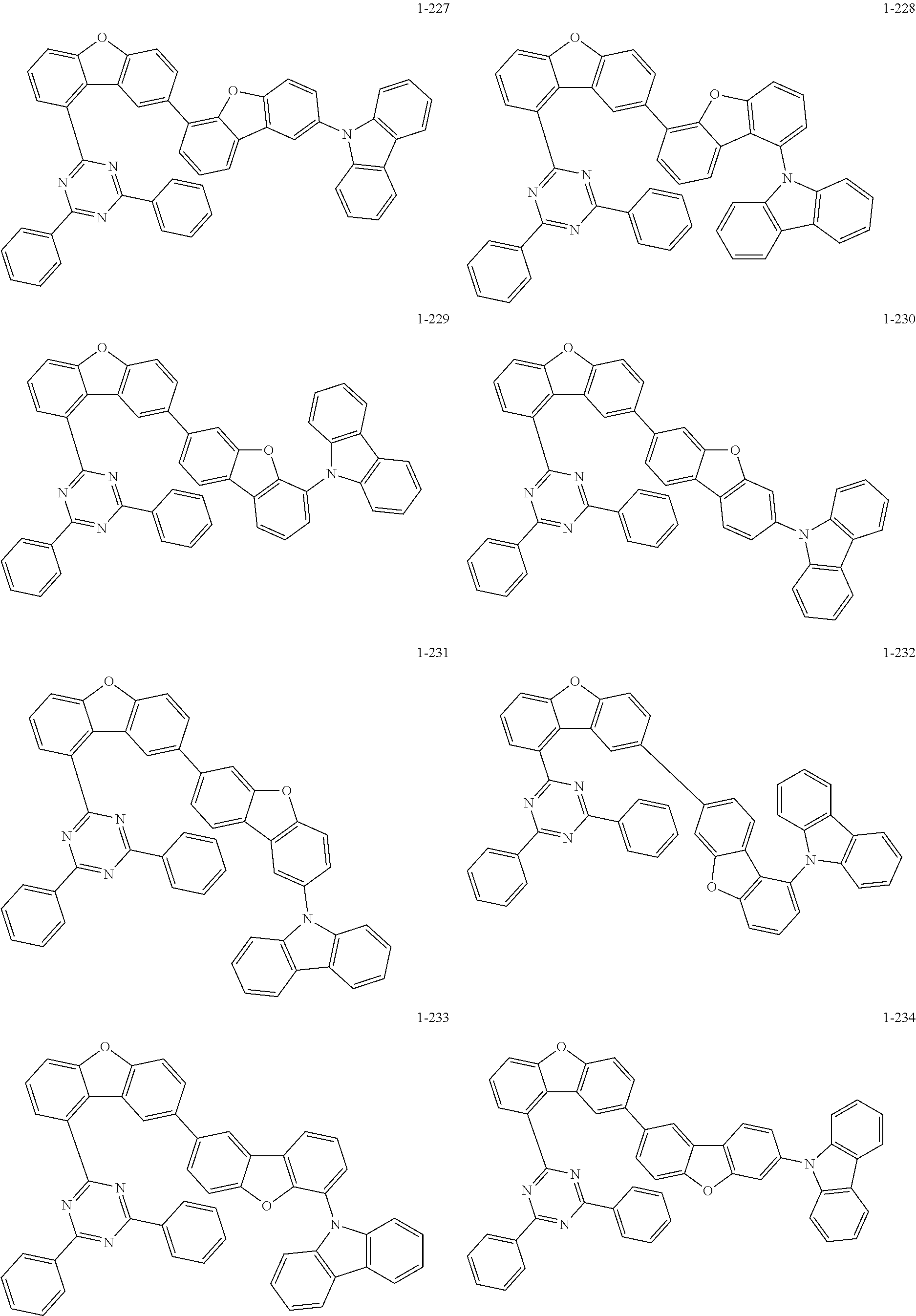

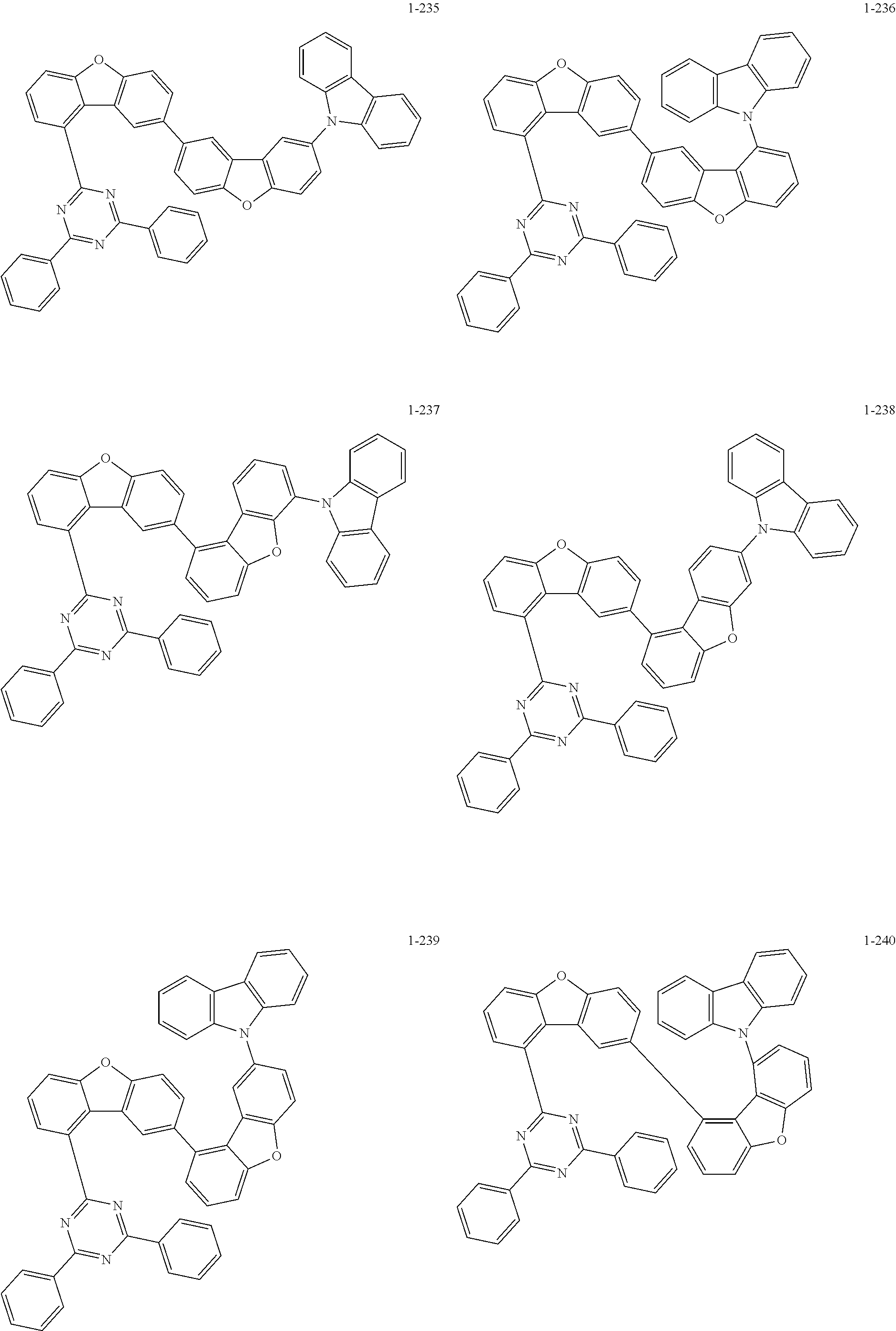

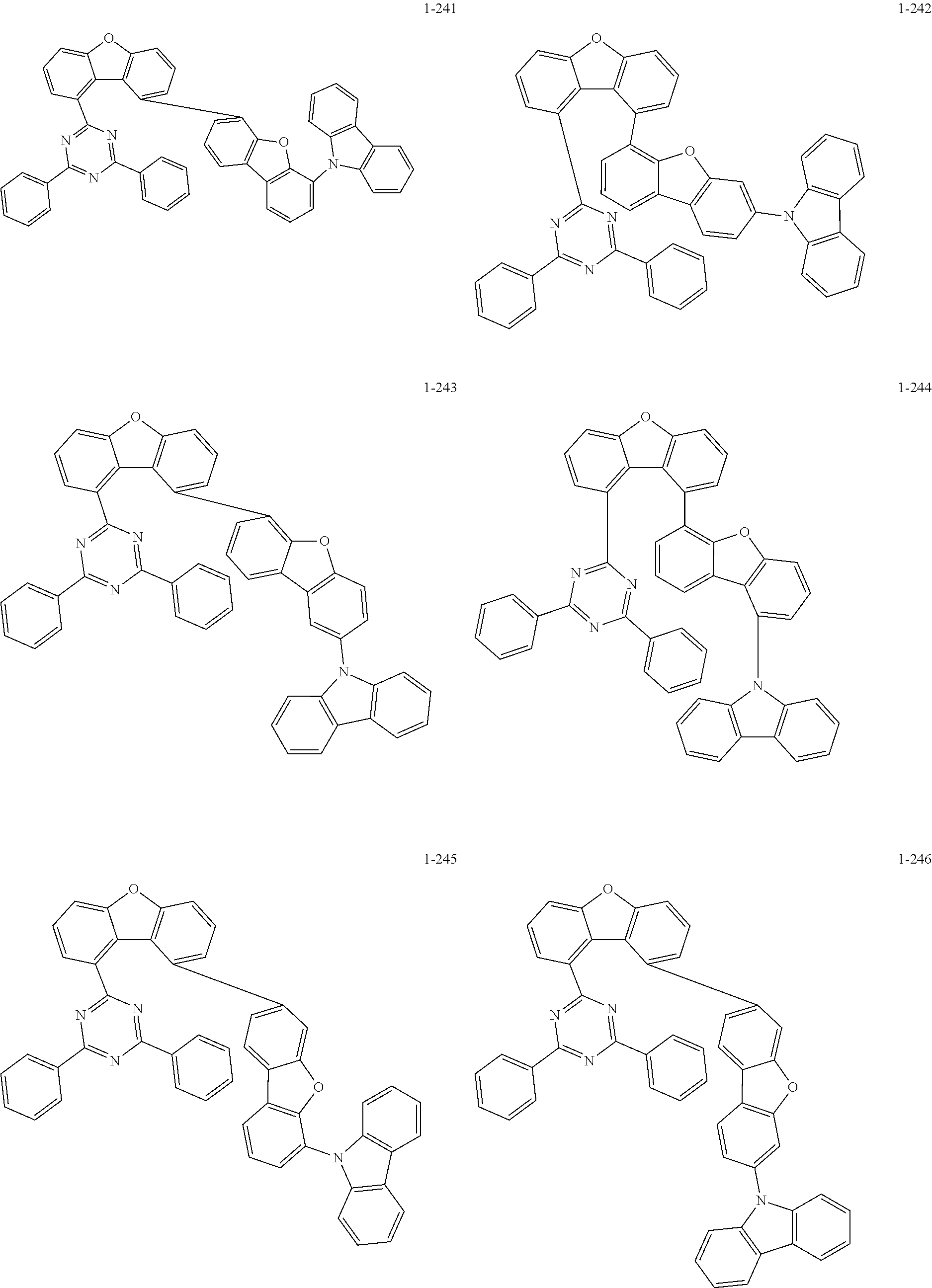

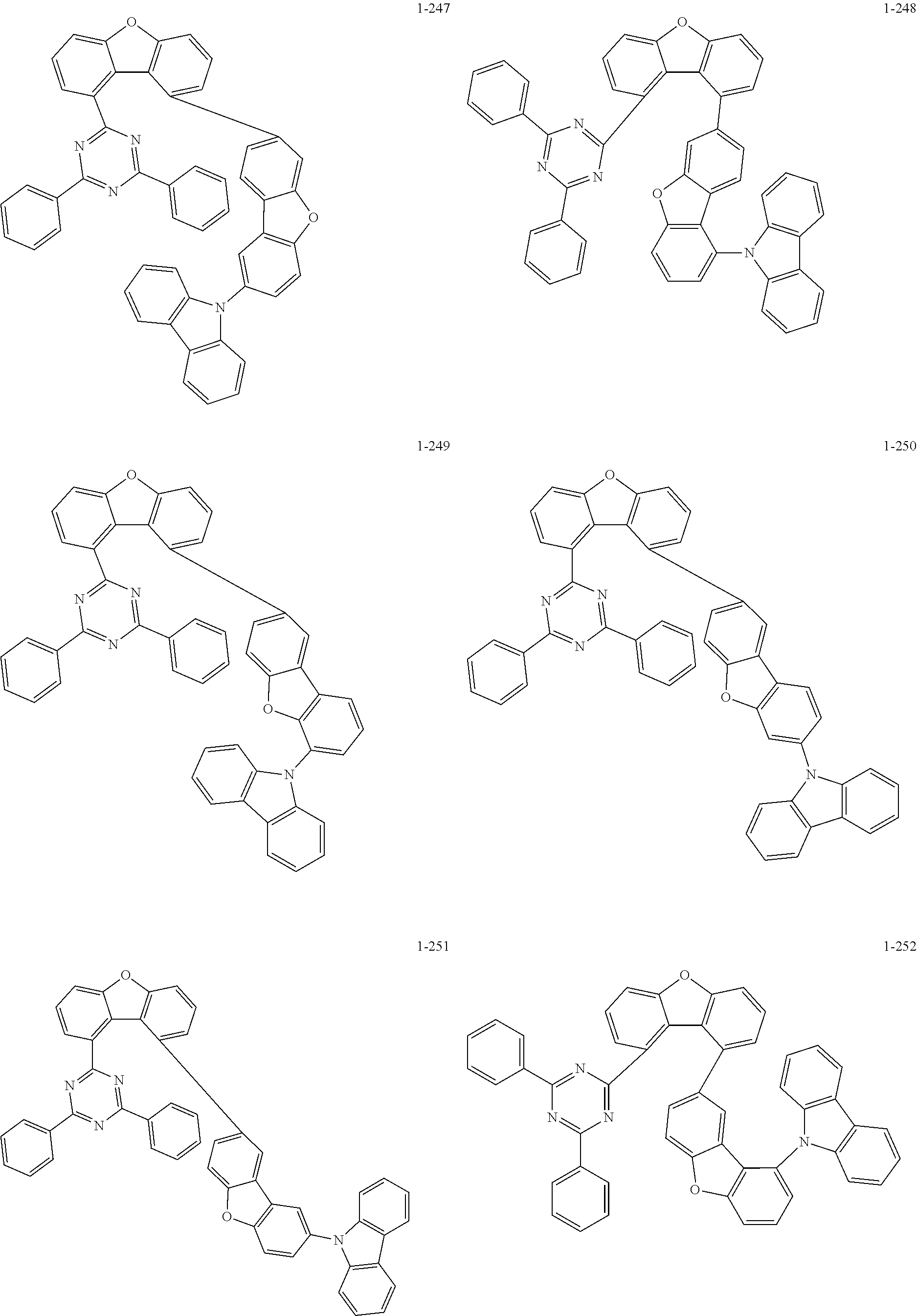

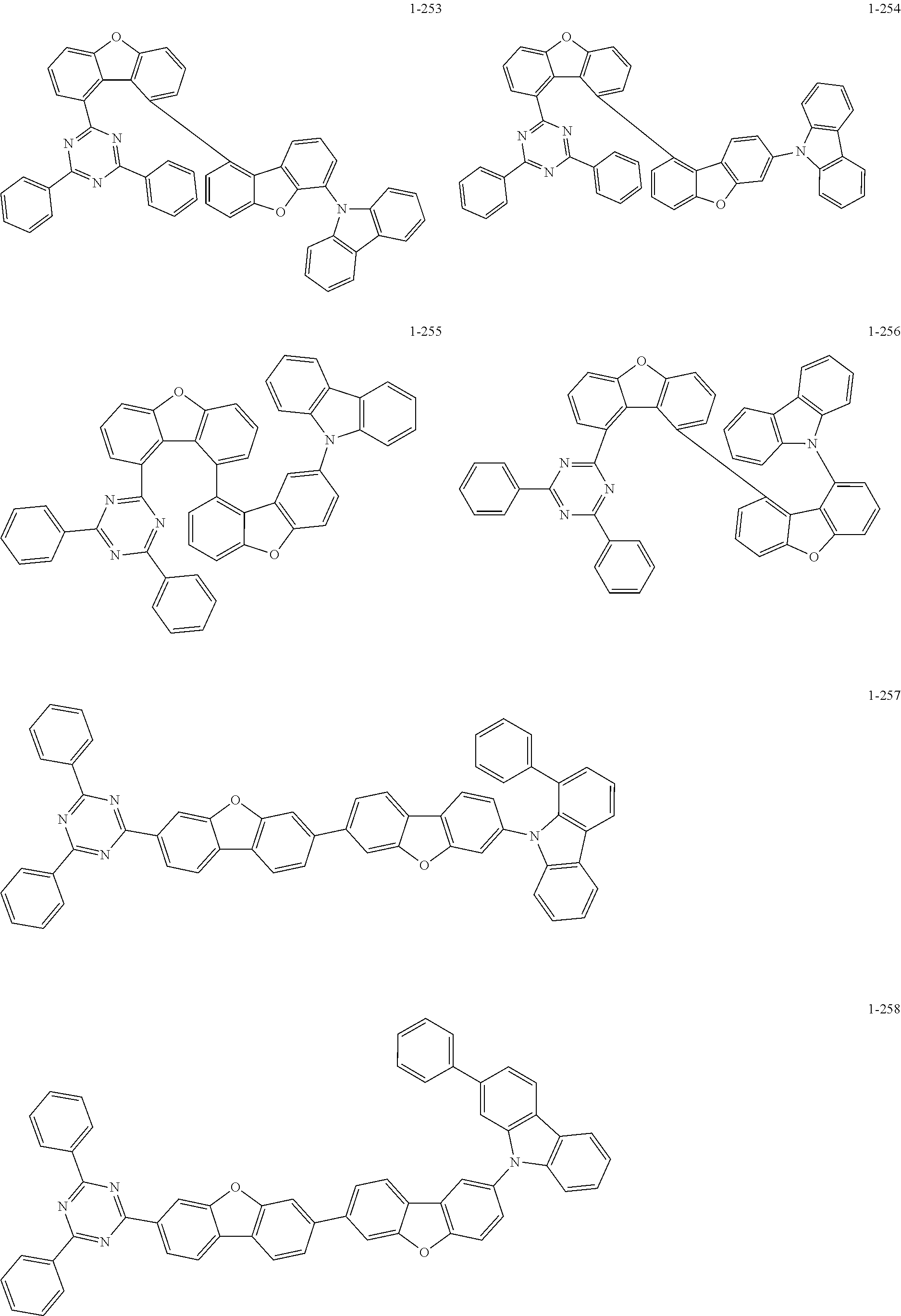

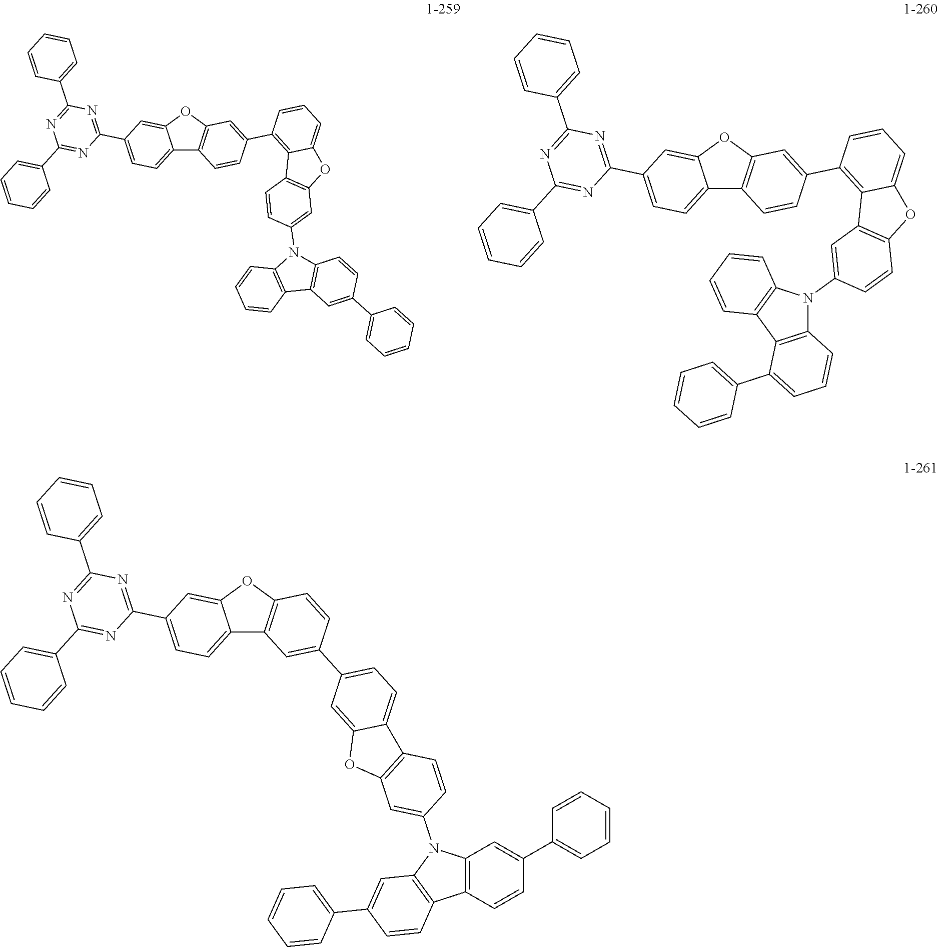 [SMILES: c1ccc(-c2ccc3c(c2)c2ccccc2n3-c2ccc3c(c2)oc2cccc(-c4ccc5c(c4)oc4cc(-c6nc(-c7ccccc7)nc(-c7ccccc7)n6)ccc45)c23)cc1 ; c1ccc(-c2nc(-c3ccccc3)nc(-c3ccc4c(c3)oc3cc(-c5cccc6oc7ccc(-n8c9ccccc9c9c(-c%10ccccc%10)cccc98)cc7c56)ccc34)n2)cc1 ; c1ccc(-c2ccc3c4ccc(-c5ccccc5)cc4n(-c4ccc5c(c4)oc4cc(-c6ccc7oc8cc(-c9nc(-c%10ccccc%10)nc(-c%10ccccc%10)n9)ccc8c7c6)ccc45)c3c2)cc1]

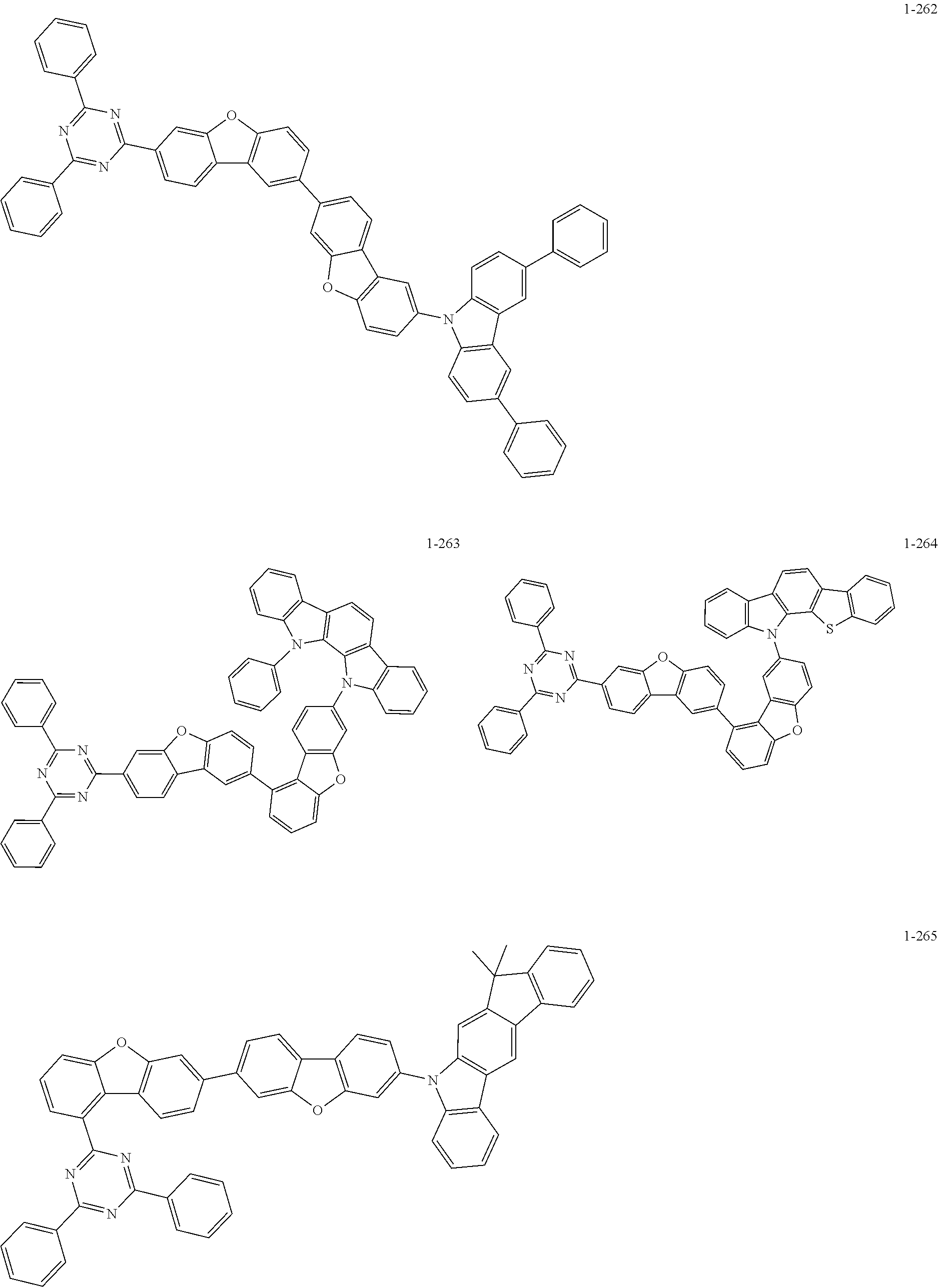 [SMILES: c1ccc(-c2ccc3c(c2)c2cc(-c4ccccc4)ccc2n3-c2ccc3oc4cc(-c5ccc6oc7cc(-c8nc(-c9ccccc9)nc(-c9ccccc9)n8)ccc7c6c5)ccc4c3c2)cc1 ; c1ccc(-c2nc(-c3ccccc3)nc(-c3ccc4c(c3)oc3ccc(-c5cccc6oc7cc(-n8c9ccccc9c9ccc%10c%11ccccc%11n(-c%11ccccc%11)c%10c98)ccc7c56)cc34)n2)cc1 ; c1ccc(-c2nc(-c3ccccc3)nc(-c3ccc4c(c3)oc3ccc(-c5cccc6oc7ccc(-n8c9ccccc9c9ccc%10c%11ccccc%11sc%10c98)cc7c56)cc34)n2)cc1 ; CC1(C)c2ccccc2-c2cc3c4ccccc4n(-c4ccc5c(c4)oc4cc(-c6ccc7c(c6)oc6cccc(-c8nc(-c9ccccc9)nc(-c9ccccc9)n8)c67)ccc45)c3cc21]

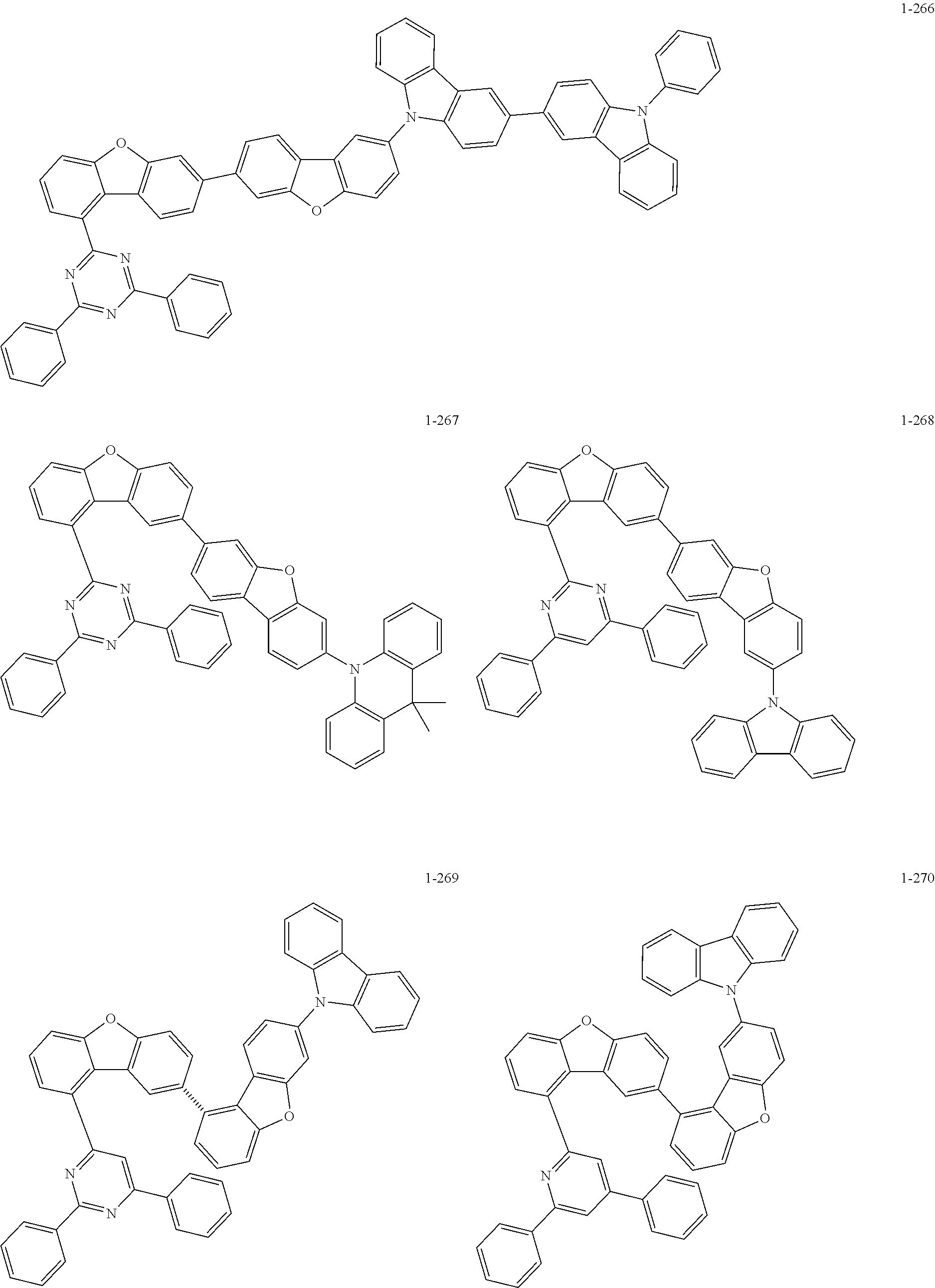

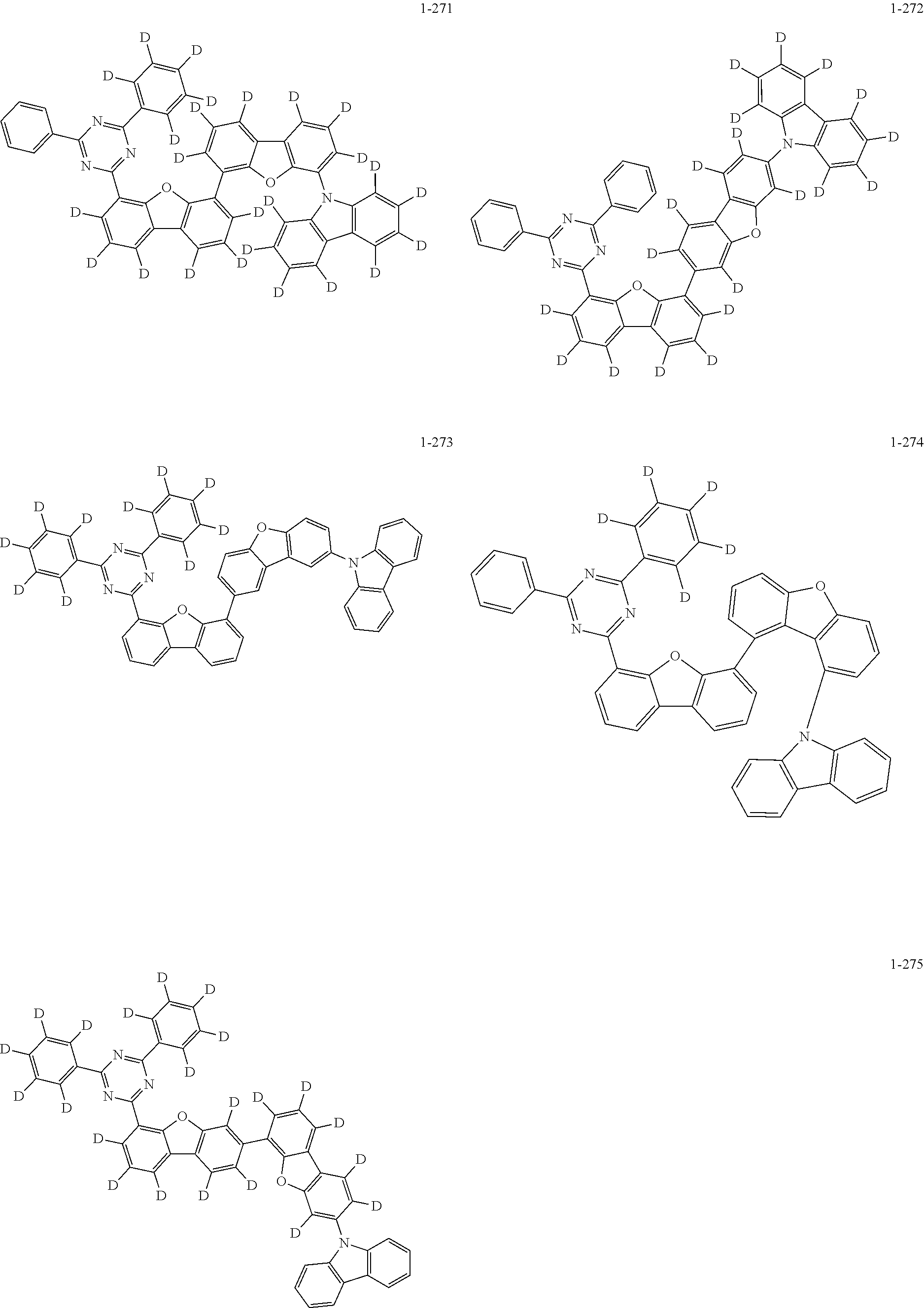

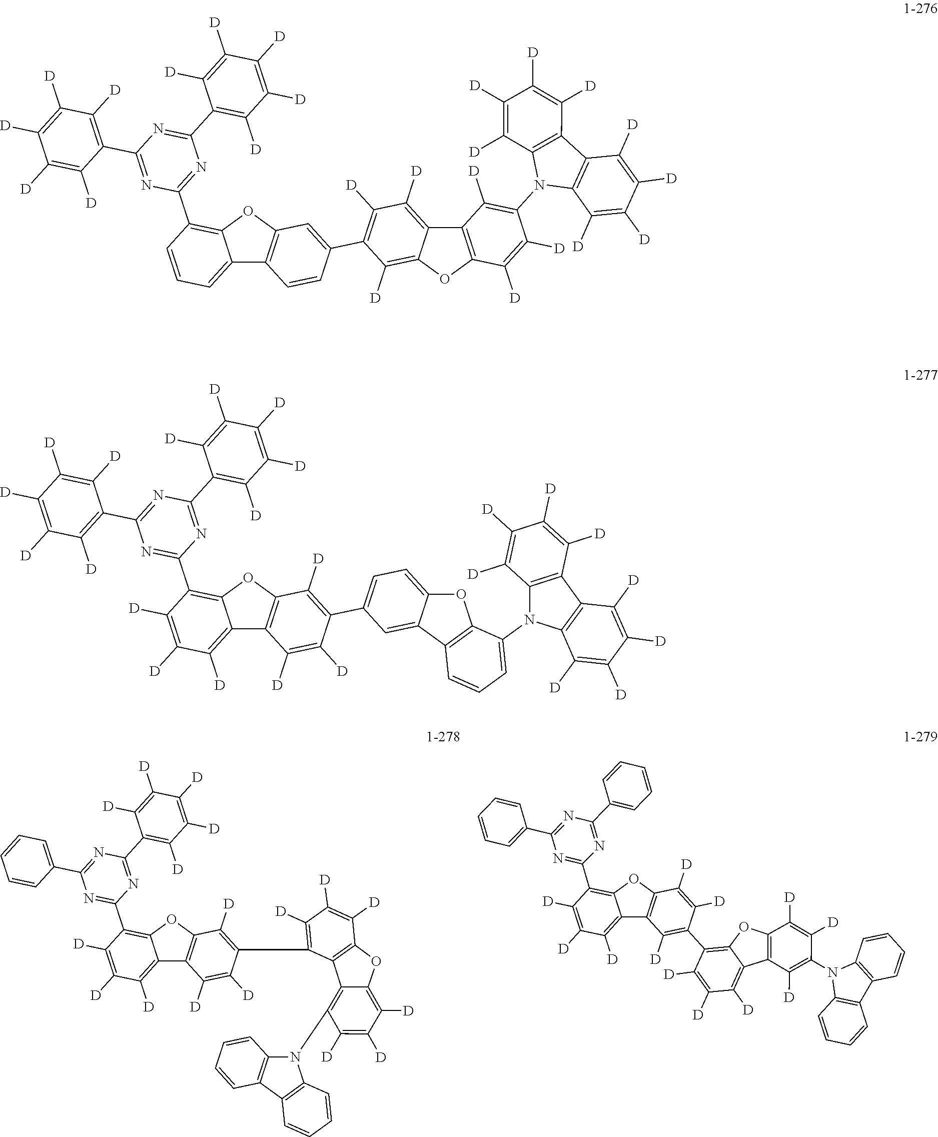

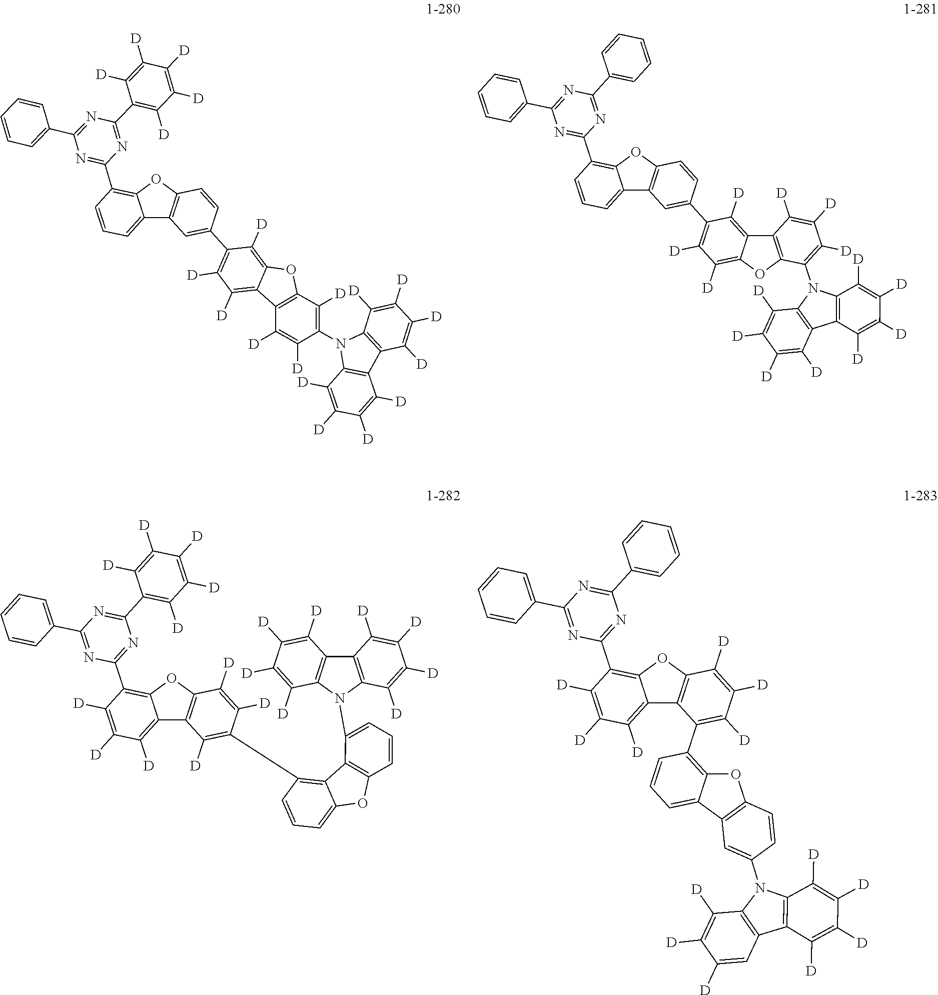

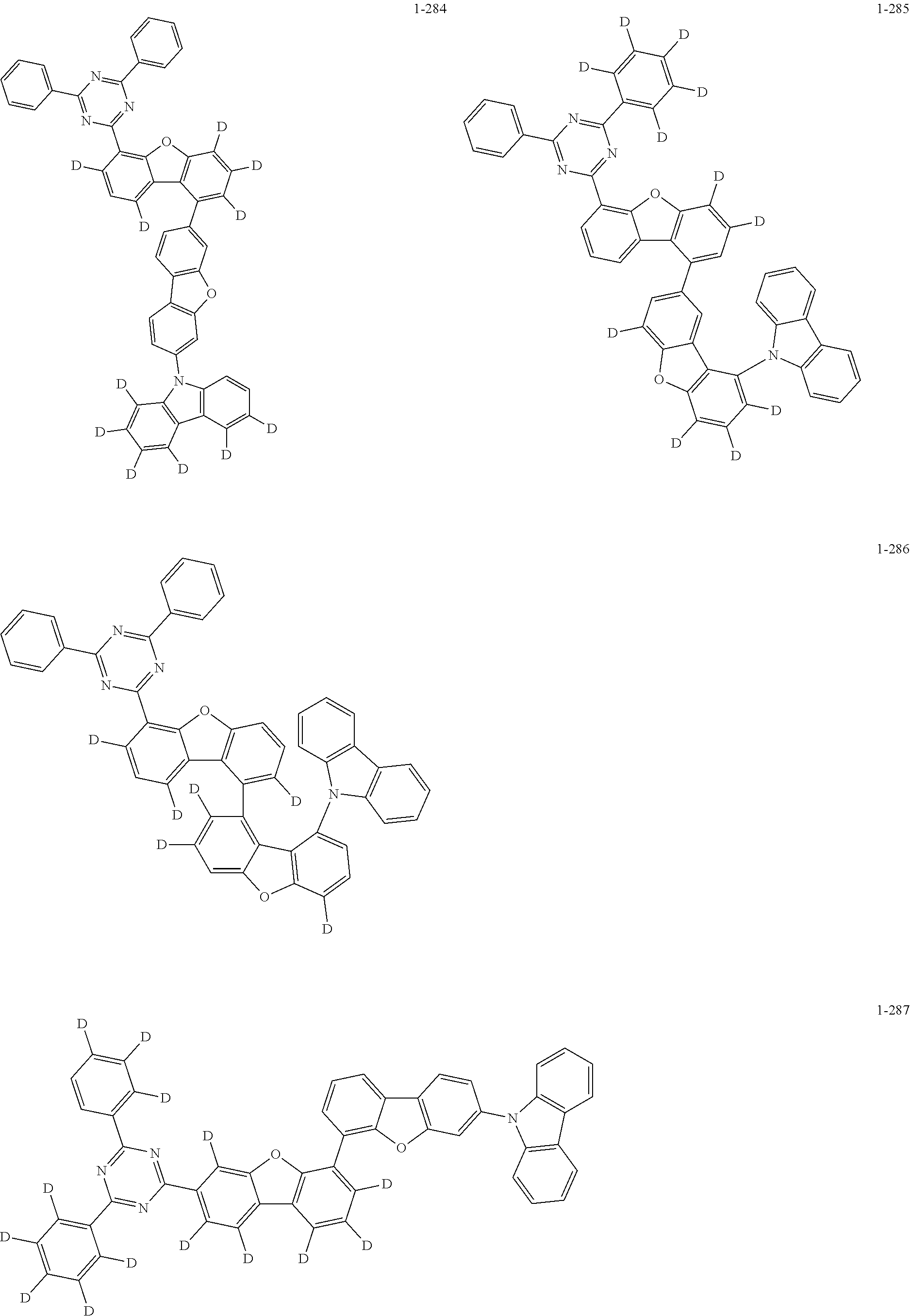

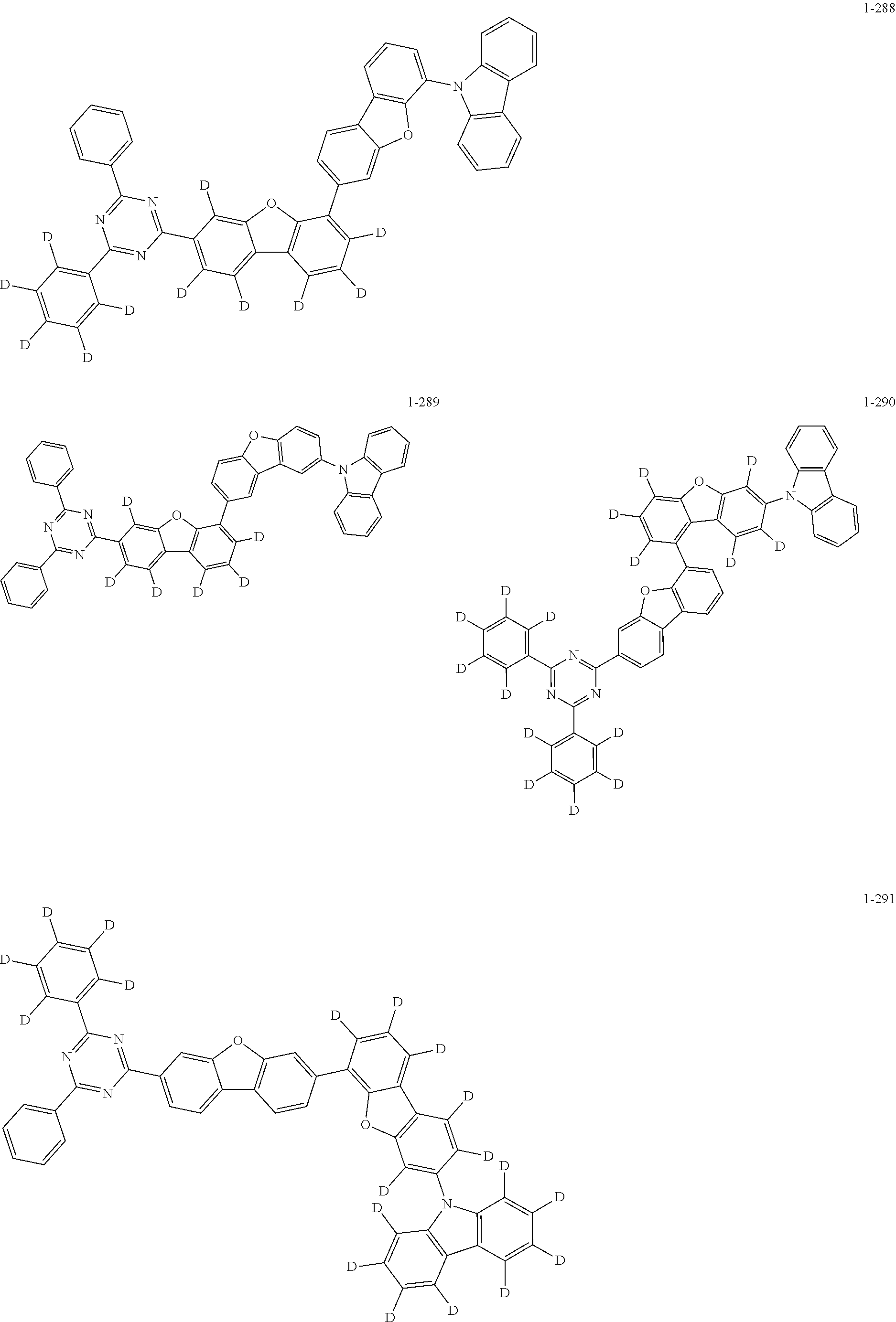

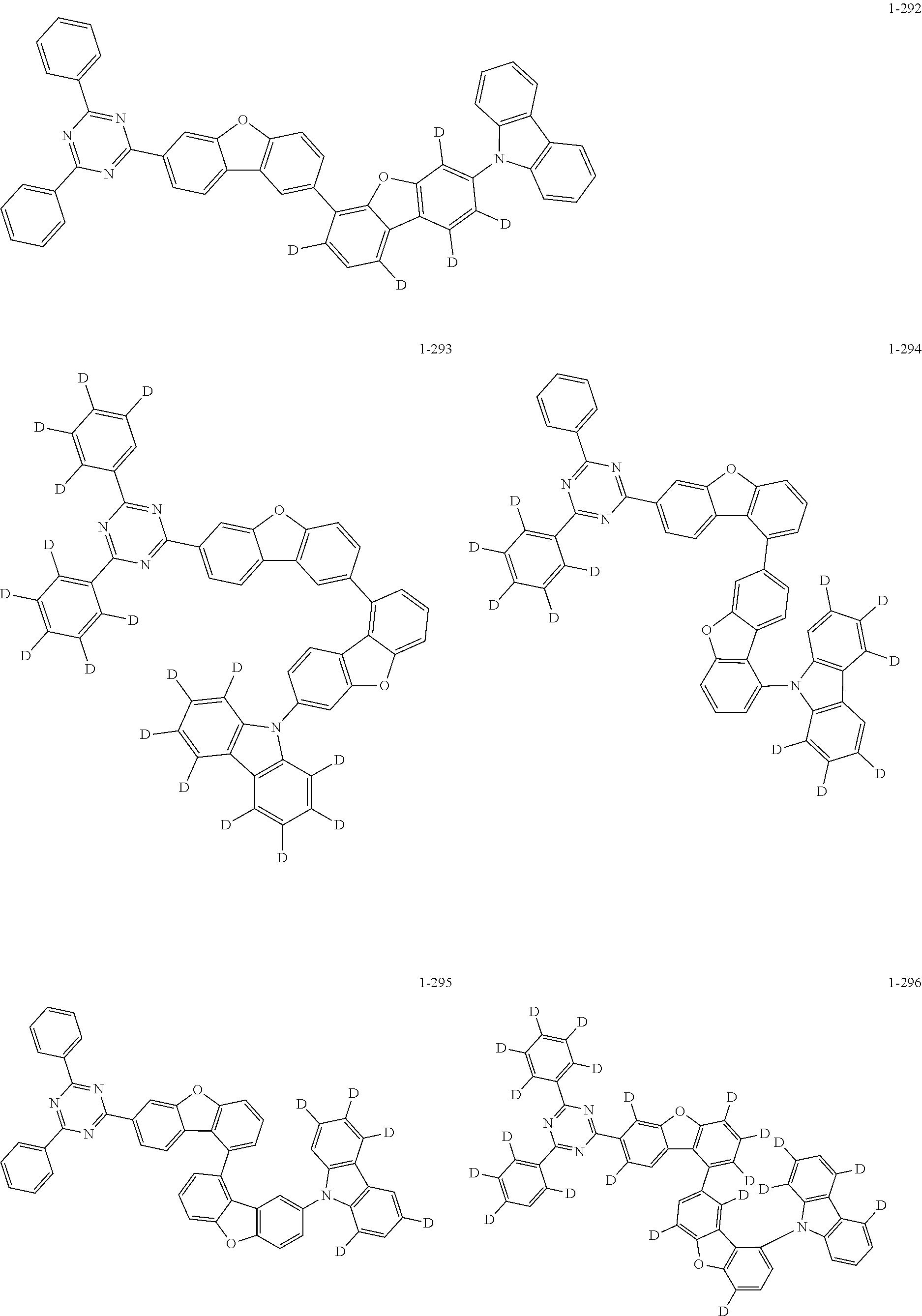

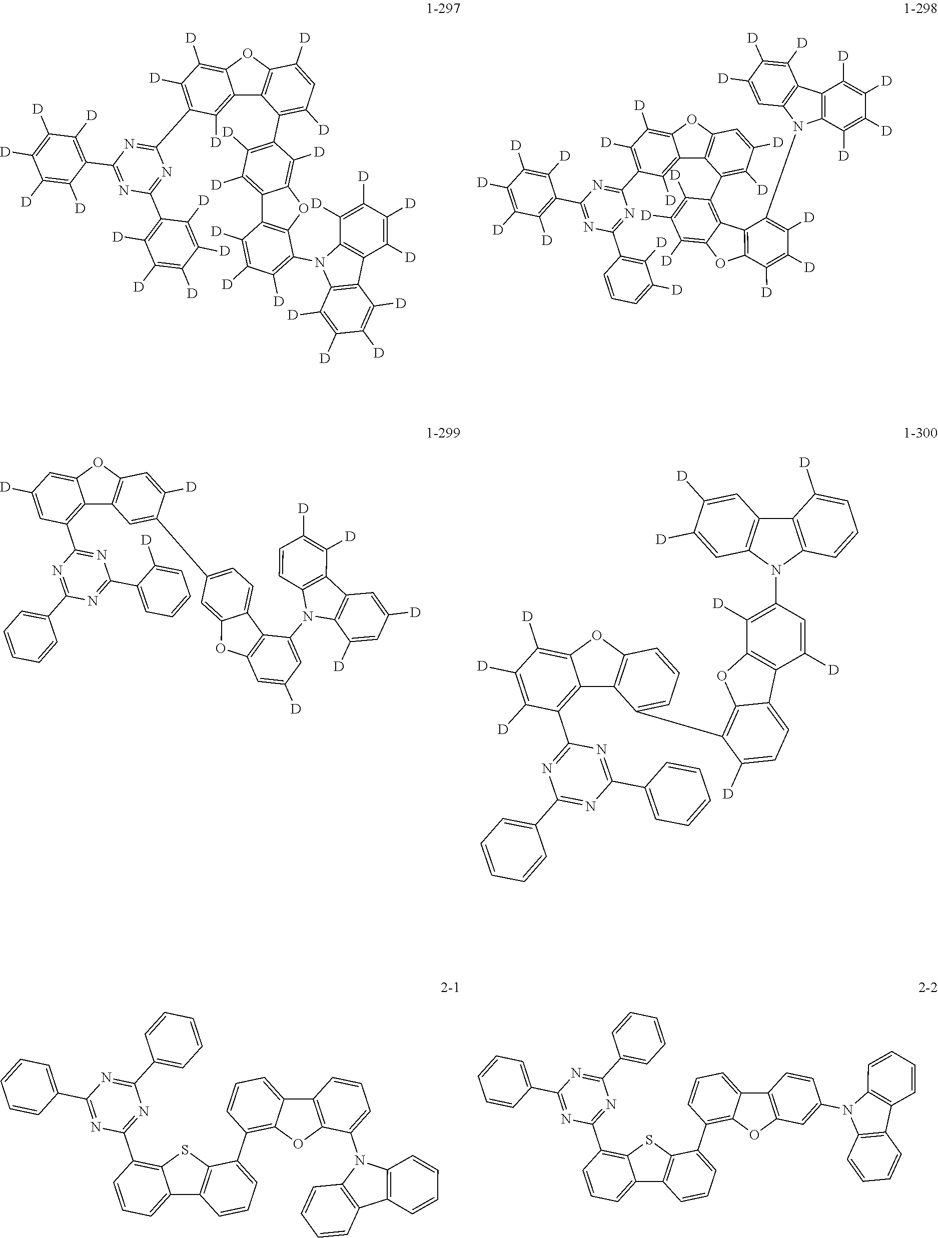

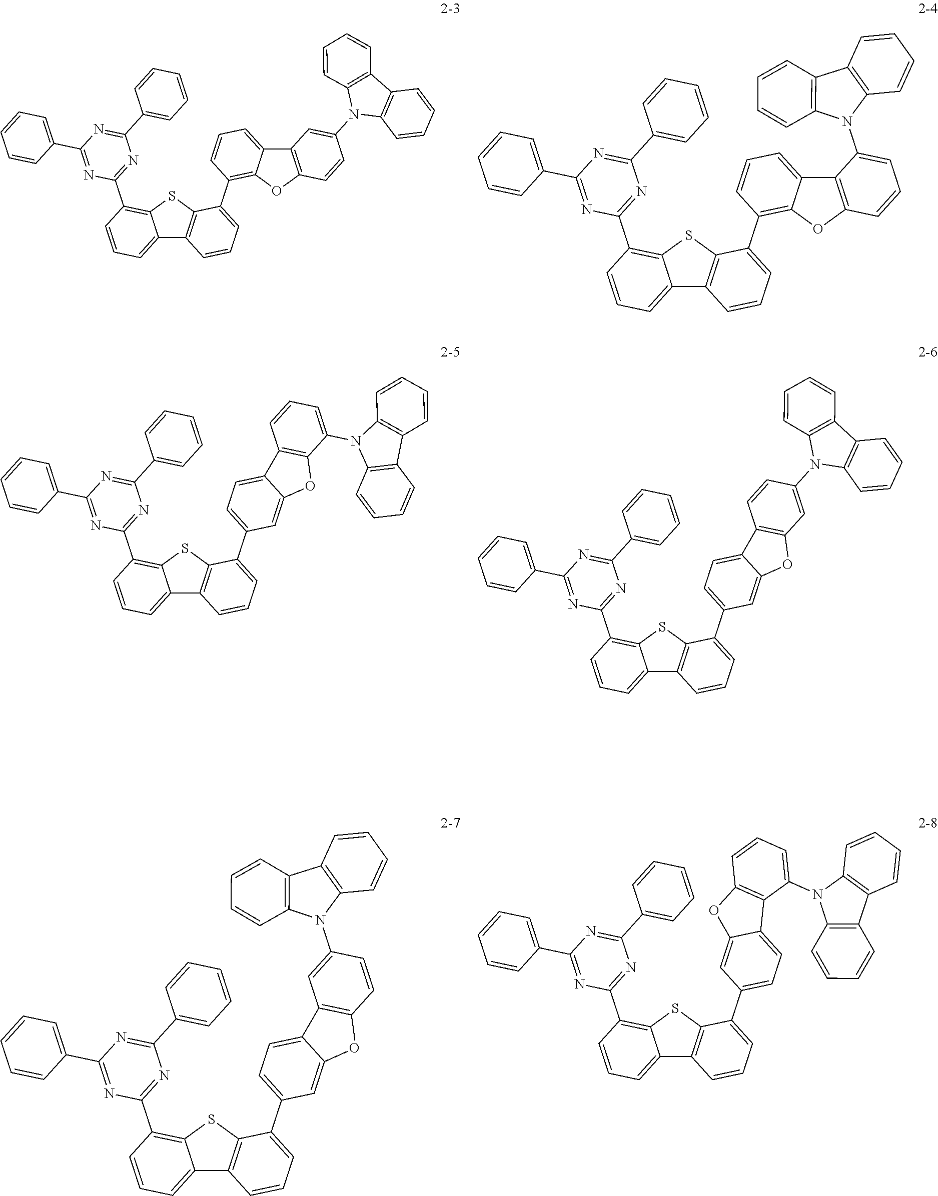

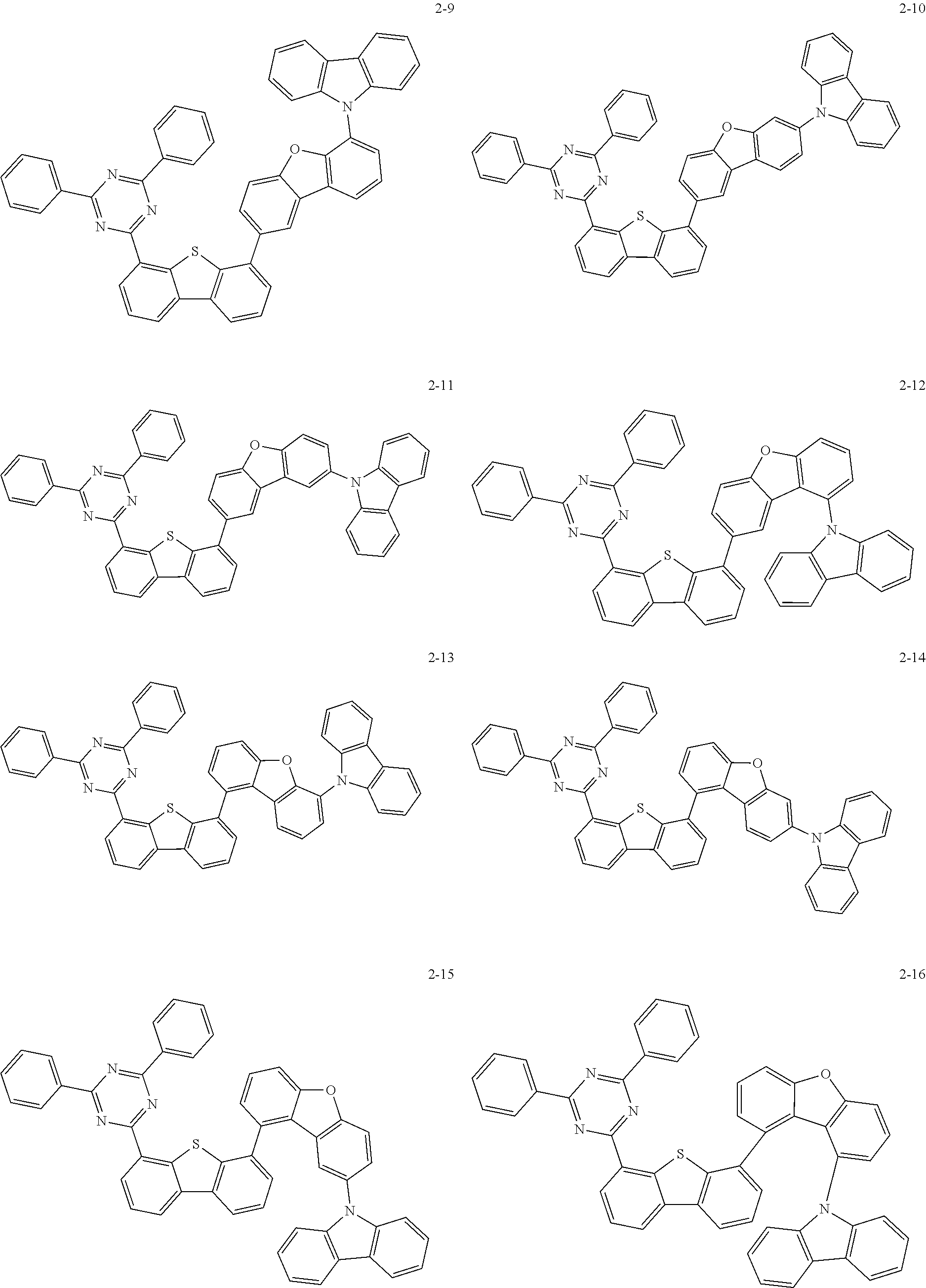

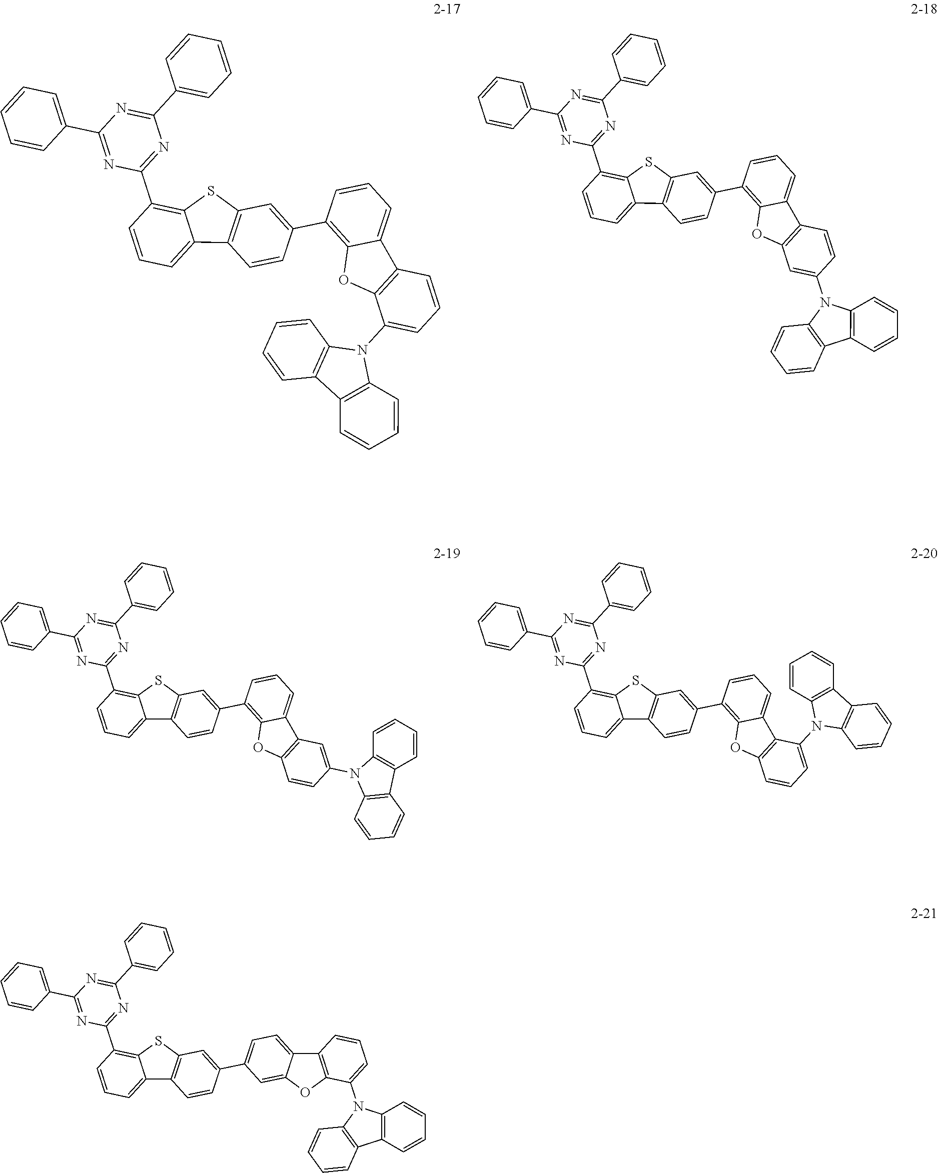 [SMILES: c1ccc(-c2nc(-c3ccccc3)nc(-c3cccc4c3sc3cc(-c5cccc6c5oc5c(-n7c8ccccc8c8ccccc87)cccc56)ccc34)n2)cc1 ; c1ccc(-c2nc(-c3ccccc3)nc(-c3cccc4c3sc3cc(-c5cccc6c5oc5cc(-n7c8ccccc8c8ccccc87)ccc56)ccc34)n2)cc1 ; c1ccc(-c2nc(-c3ccccc3)nc(-c3cccc4c3sc3cc(-c5cccc6c5oc5ccc(-n7c8ccccc8c8ccccc87)cc56)ccc34)n2)cc1 ; c1ccc(-c2nc(-c3ccccc3)nc(-c3cccc4c3sc3cc(-c5cccc6c5oc5cccc(-n7c8ccccc8c8ccccc87)c56)ccc34)n2)cc1 ; c1ccc(-c2nc(-c3ccccc3)nc(-c3cccc4c3sc3cc(-c5ccc6c(c5)oc5c(-n7c8ccccc8c8ccccc87)cccc56)ccc34)n2)cc1]

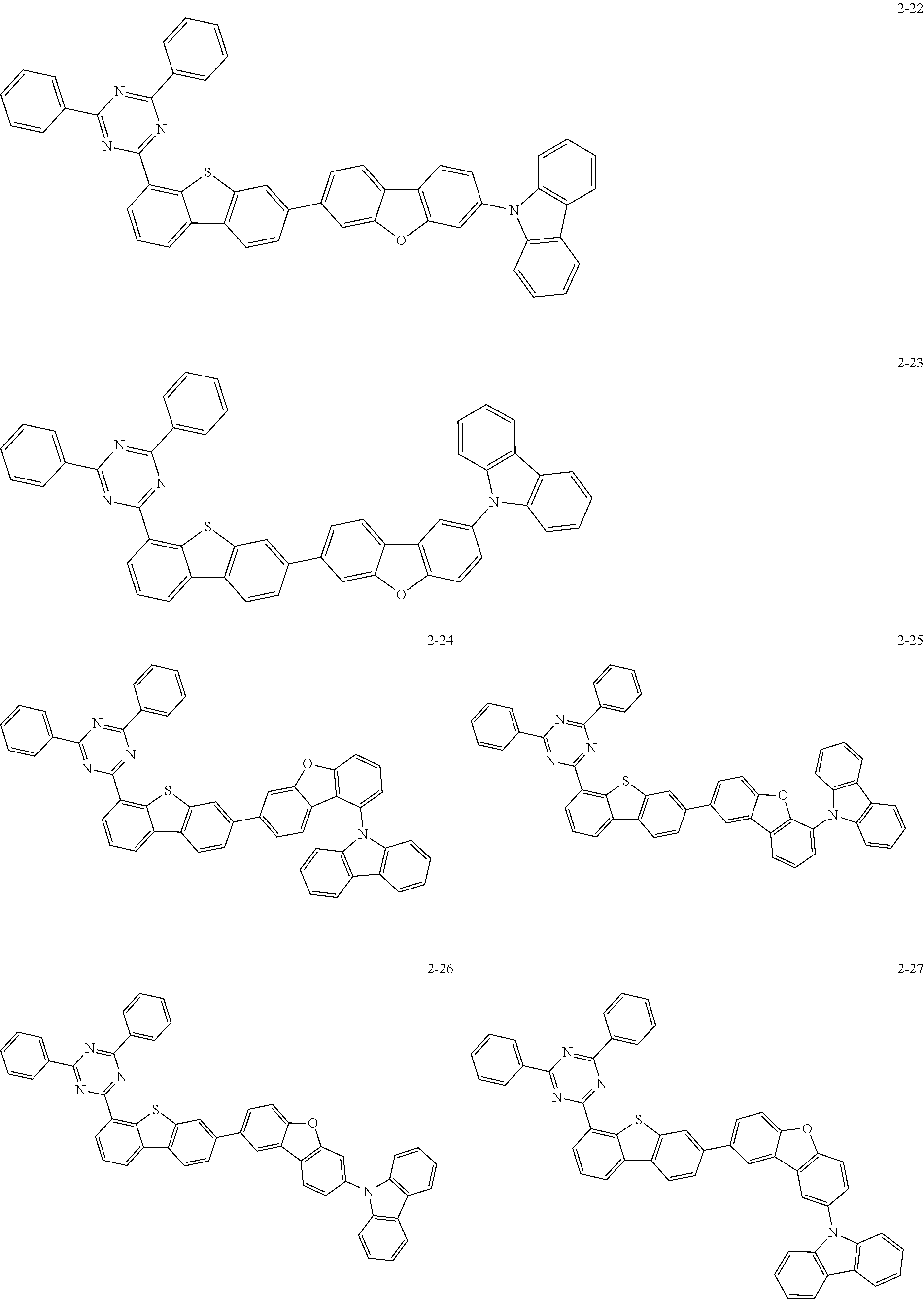

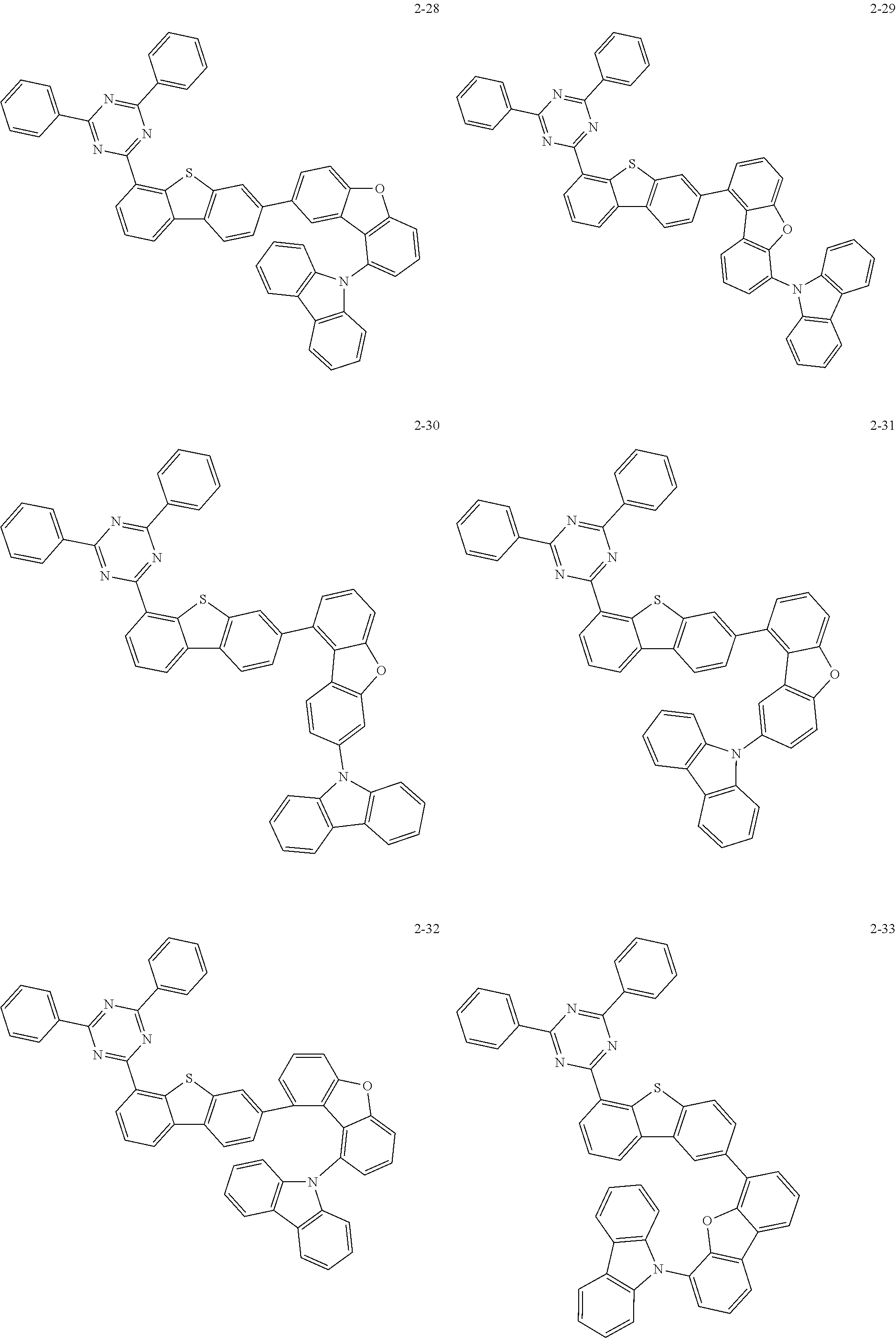

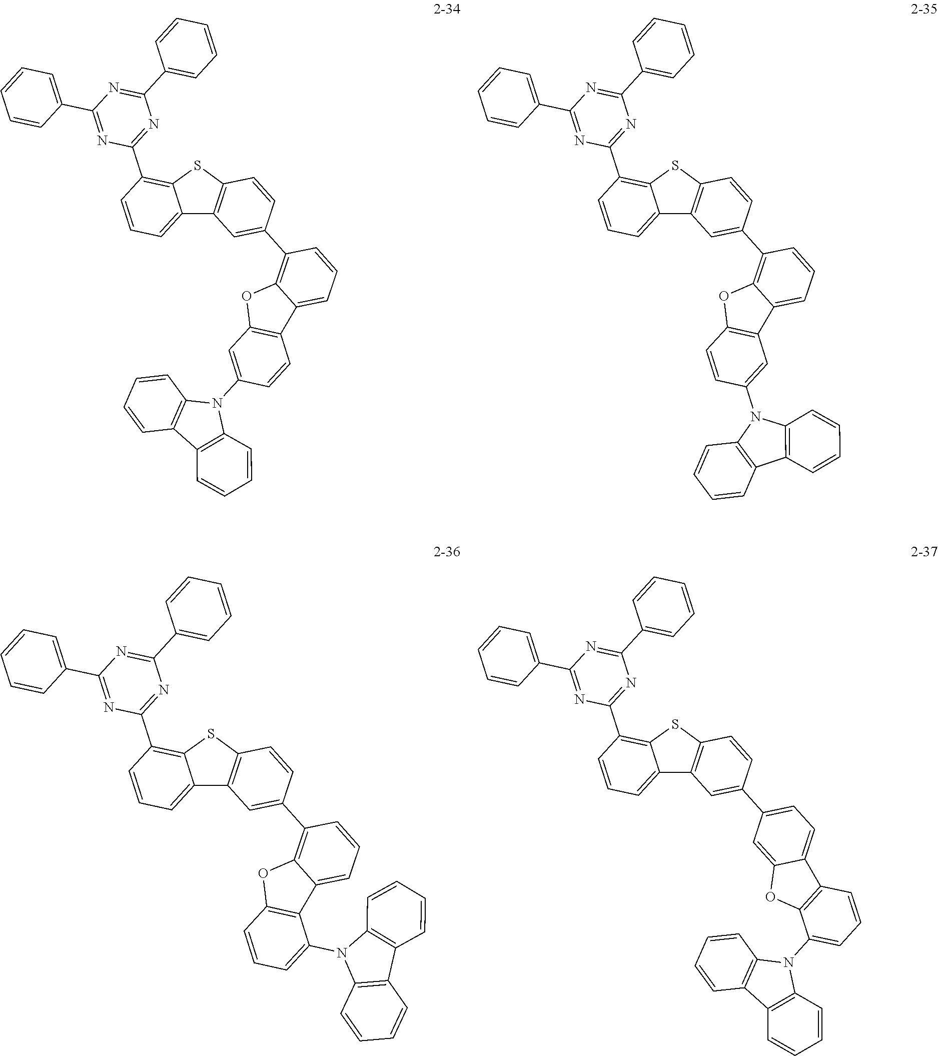 [SMILES: c1ccc(-c2nc(-c3ccccc3)nc(-c3cccc4c3sc3ccc(-c5cccc6c5oc5cc(-n7c8ccccc8c8ccccc87)ccc56)cc34)n2)cc1 ; c1ccc(-c2nc(-c3ccccc3)nc(-c3cccc4c3sc3ccc(-c5cccc6c5oc5ccc(-n7c8ccccc8c8ccccc87)cc56)cc34)n2)cc1 ; c1ccc(-c2nc(-c3ccccc3)nc(-c3cccc4c3sc3ccc(-c5cccc6c5oc5cccc(-n7c8ccccc8c8ccccc87)c56)cc34)n2)cc1 ; c1ccc(-c2nc(-c3ccccc3)nc(-c3cccc4c3sc3ccc(-c5ccc6c(c5)oc5c(-n7c8ccccc8c8ccccc87)cccc56)cc34)n2)cc1]

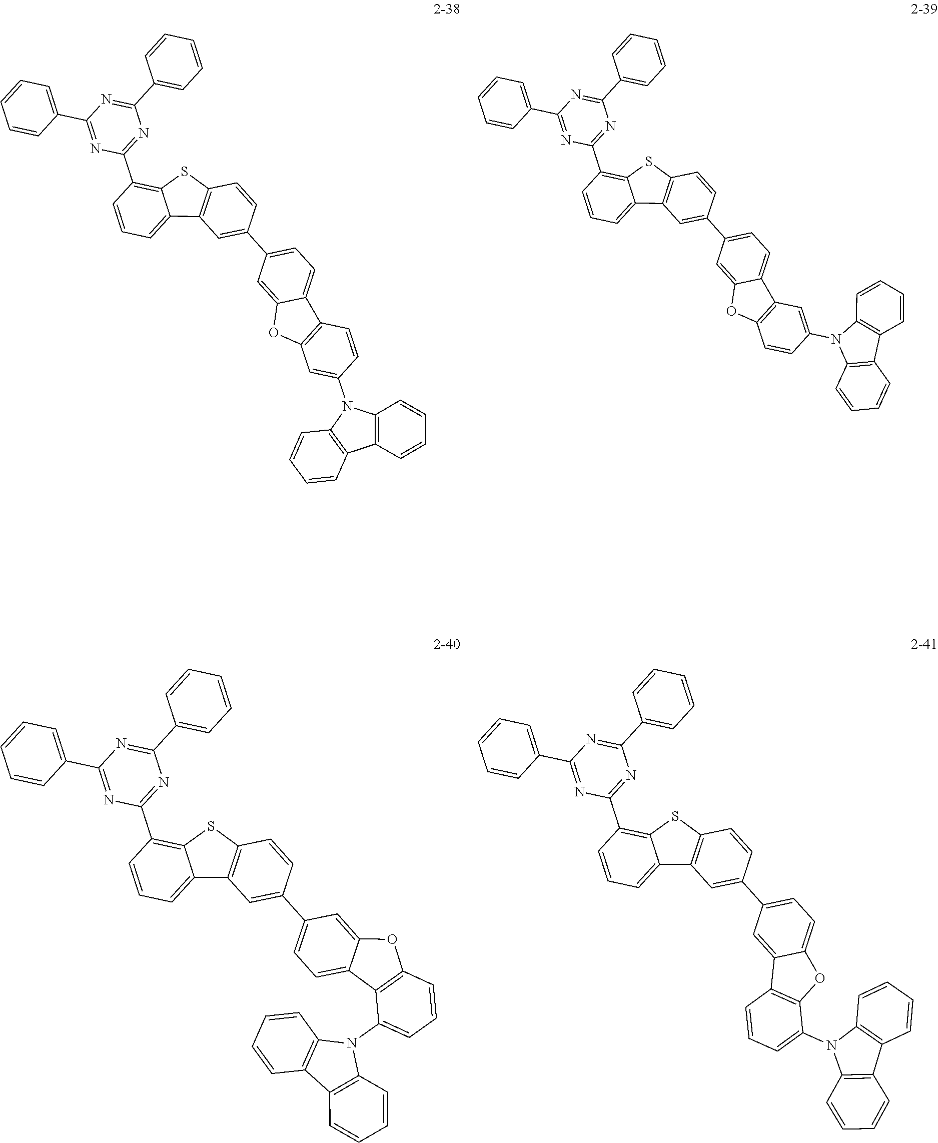 [SMILES: c1ccc(-c2nc(-c3ccccc3)nc(-c3cccc4c3sc3ccc(-c5ccc6c(c5)oc5cc(-n7c8ccccc8c8ccccc87)ccc56)cc34)n2)cc1 ; c1ccc(-c2nc(-c3ccccc3)nc(-c3cccc4c3sc3ccc(-c5ccc6c(c5)oc5ccc(-n7c8ccccc8c8ccccc87)cc56)cc34)n2)cc1 ; c1ccc(-c2nc(-c3ccccc3)nc(-c3cccc4c3sc3ccc(-c5ccc6c(c5)oc5cccc(-n7c8ccccc8c8ccccc87)c56)cc34)n2)cc1 ; c1ccc(-c2nc(-c3ccccc3)nc(-c3cccc4c3sc3ccc(-c5ccc6oc7c(-n8c9ccccc9c9ccccc98)cccc7c6c5)cc34)n2)cc1]

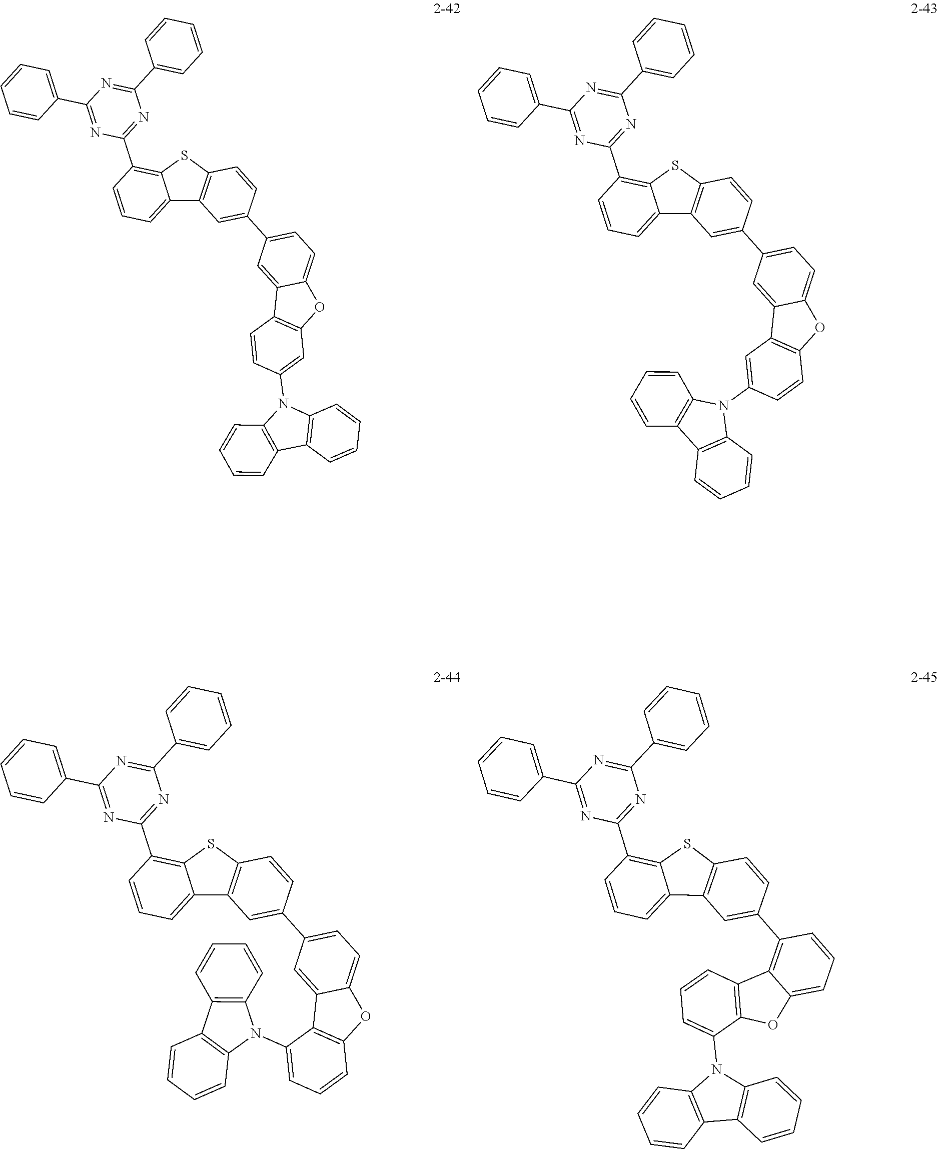 [SMILES: c1ccc(-c2nc(-c3ccccc3)nc(-c3cccc4c3sc3ccc(-c5ccc6oc7cc(-n8c9ccccc9c9ccccc98)ccc7c6c5)cc34)n2)cc1 ; c1ccc(-c2nc(-c3ccccc3)nc(-c3cccc4c3sc3ccc(-c5ccc6oc7ccc(-n8c9ccccc9c9ccccc98)cc7c6c5)cc34)n2)cc1 ; c1ccc(-c2nc(-c3ccccc3)nc(-c3cccc4c3sc3ccc(-c5ccc6oc7cccc(-n8c9ccccc9c9ccccc98)c7c6c5)cc34)n2)cc1 ; c1ccc(-c2nc(-c3ccccc3)nc(-c3cccc4c3sc3ccc(-c5cccc6oc7c(-n8c9ccccc9c9ccccc98)cccc7c56)cc34)n2)cc1]

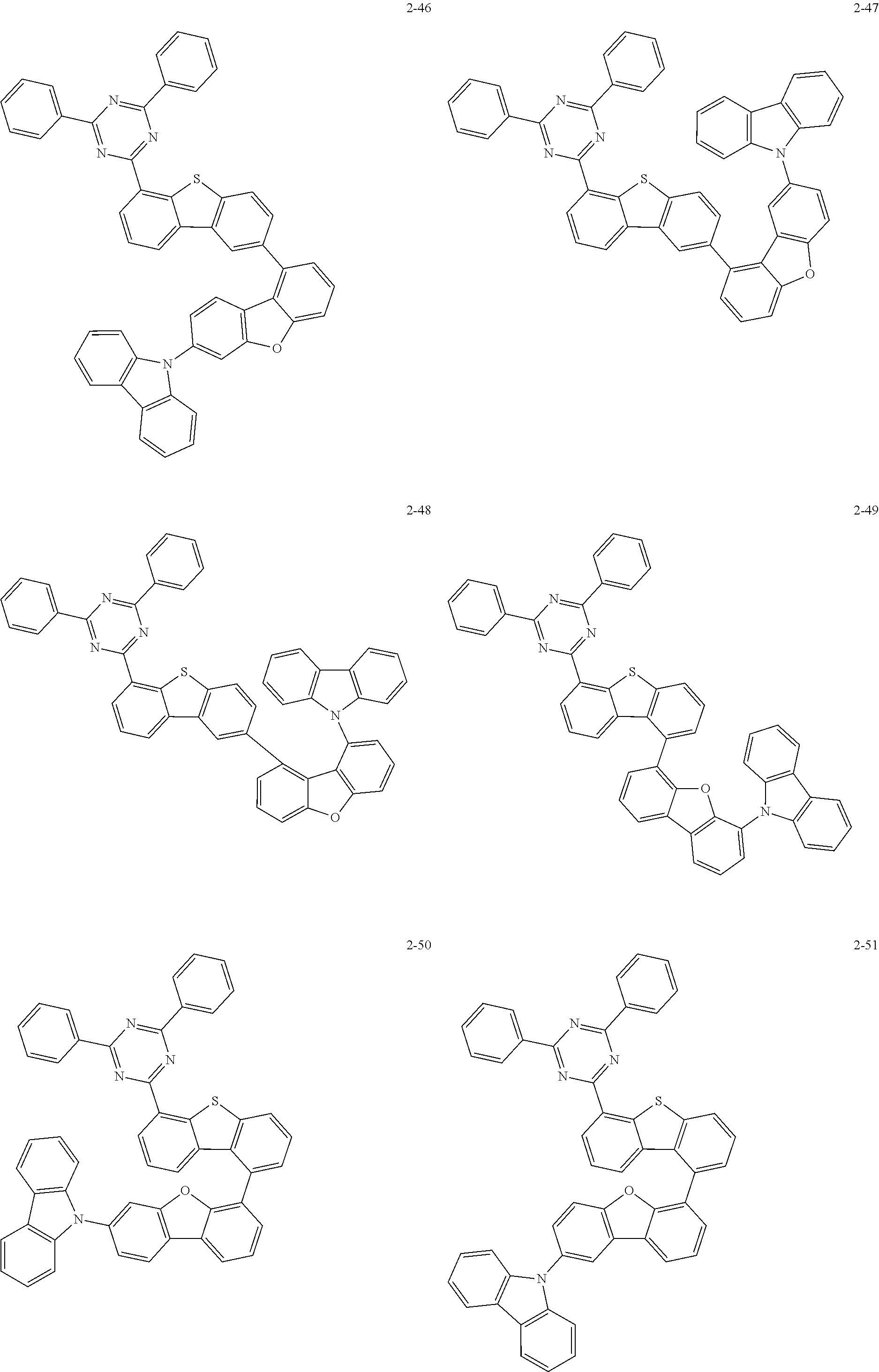

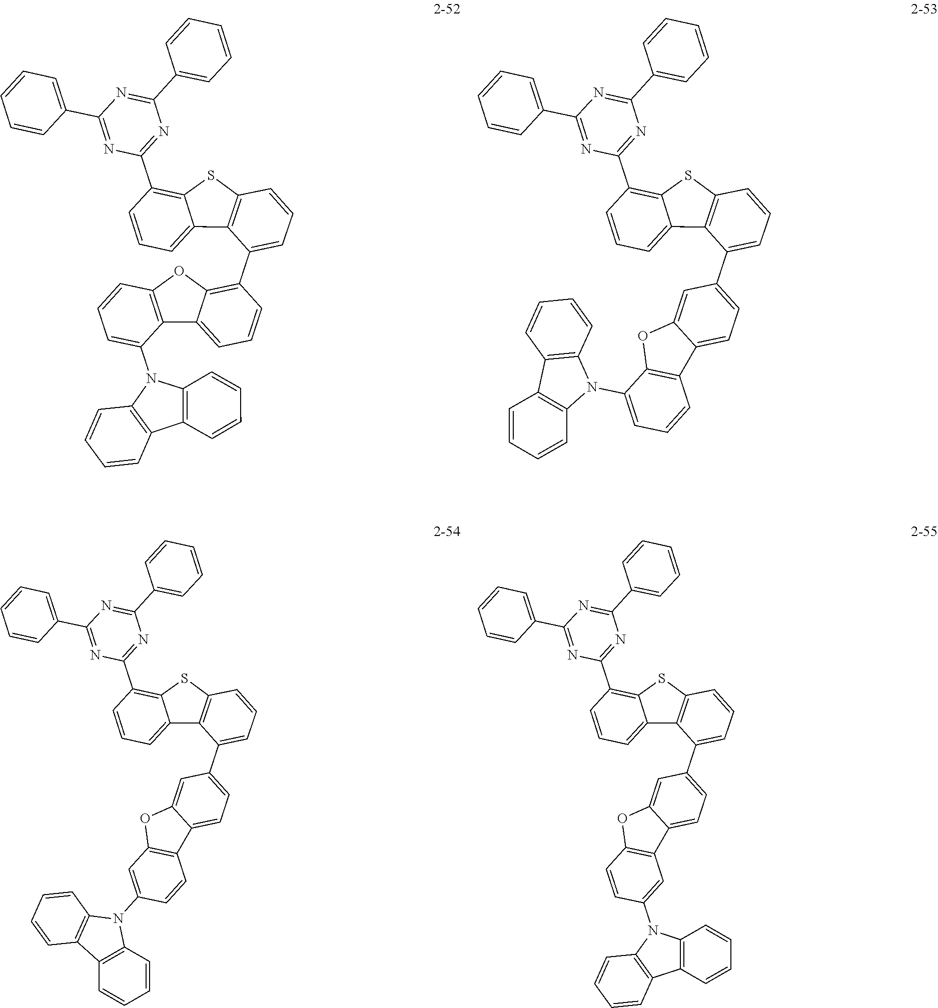 [SMILES: c1ccc(-c2nc(-c3ccccc3)nc(-c3cccc4c3sc3cccc(-c5cccc6c5oc5cccc(-n7c8ccccc8c8ccccc87)c56)c34)n2)cc1 ; c1ccc(-c2nc(-c3ccccc3)nc(-c3cccc4c3sc3cccc(-c5ccc6c(c5)oc5c(-n7c8ccccc8c8ccccc87)cccc56)c34)n2)cc1 ; c1ccc(-c2nc(-c3ccccc3)nc(-c3cccc4c3sc3cccc(-c5ccc6c(c5)oc5cc(-n7c8ccccc8c8ccccc87)ccc56)c34)n2)cc1 ; c1ccc(-c2nc(-c3ccccc3)nc(-c3cccc4c3sc3cccc(-c5ccc6c(c5)oc5ccc(-n7c8ccccc8c8ccccc87)cc56)c34)n2)cc1]

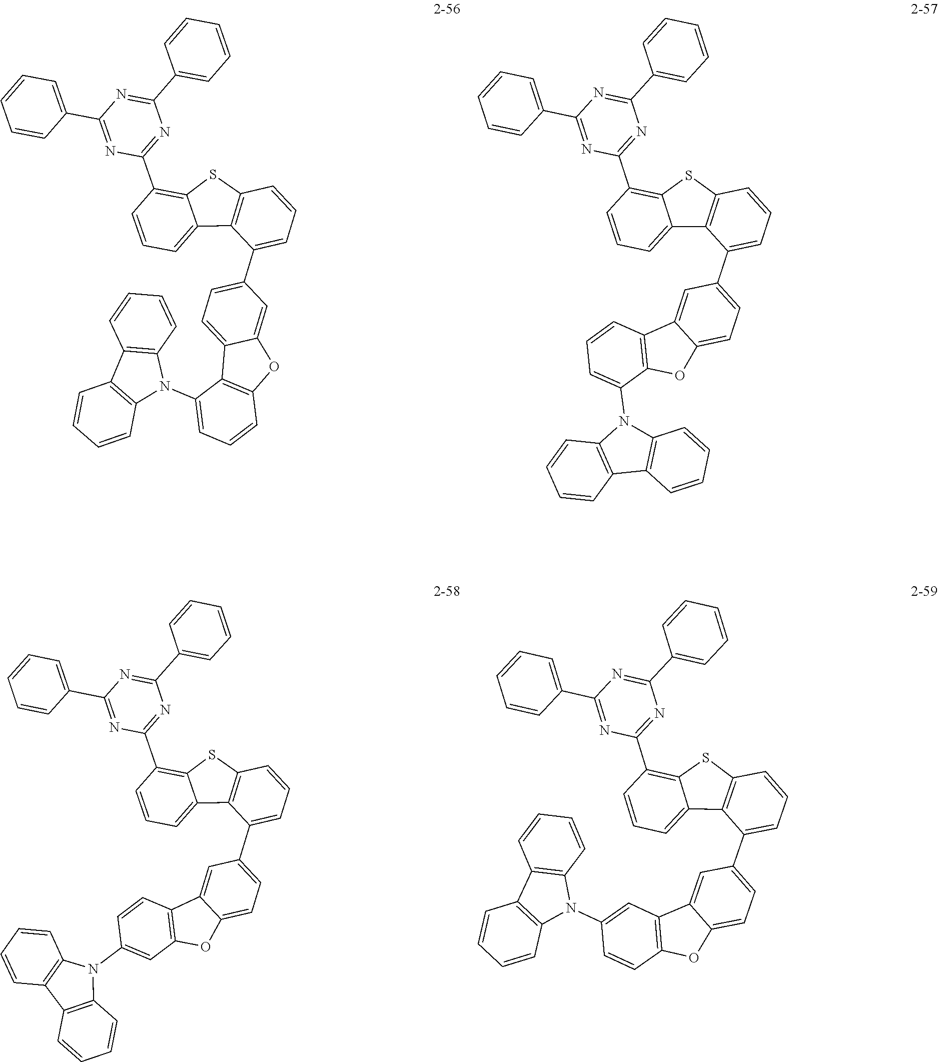 [SMILES: c1ccc(-c2nc(-c3ccccc3)nc(-c3cccc4c3sc3cccc(-c5ccc6c(c5)oc5cccc(-n7c8ccccc8c8ccccc87)c56)c34)n2)cc1 ; c1ccc(-c2nc(-c3ccccc3)nc(-c3cccc4c3sc3cccc(-c5ccc6oc7c(-n8c9ccccc9c9ccccc98)cccc7c6c5)c34)n2)cc1 ; c1ccc(-c2nc(-c3ccccc3)nc(-c3cccc4c3sc3cccc(-c5ccc6oc7cc(-n8c9ccccc9c9ccccc98)ccc7c6c5)c34)n2)cc1 ; c1ccc(-c2nc(-c3ccccc3)nc(-c3cccc4c3sc3cccc(-c5ccc6oc7ccc(-n8c9ccccc9c9ccccc98)cc7c6c5)c34)n2)cc1]

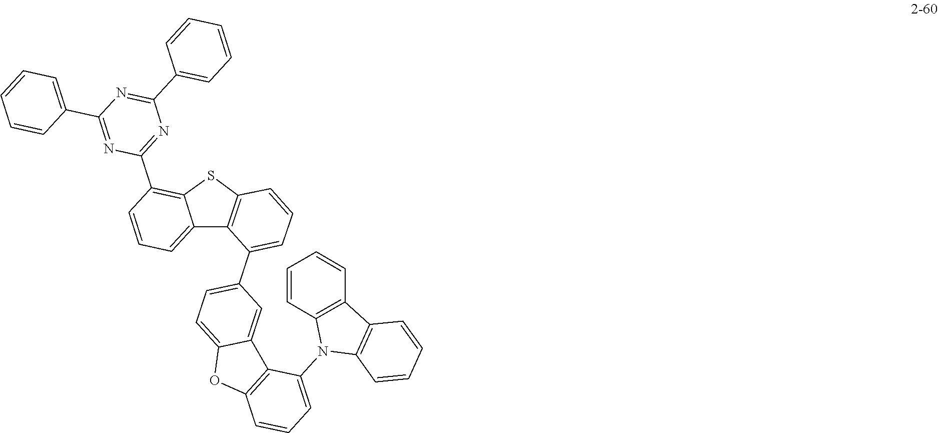 [SMILES: c1ccc(-c2nc(-c3ccccc3)nc(-c3cccc4c3sc3cccc(-c5ccc6oc7cccc(-n8c9ccccc9c9ccccc98)c7c6c5)c34)n2)cc1]

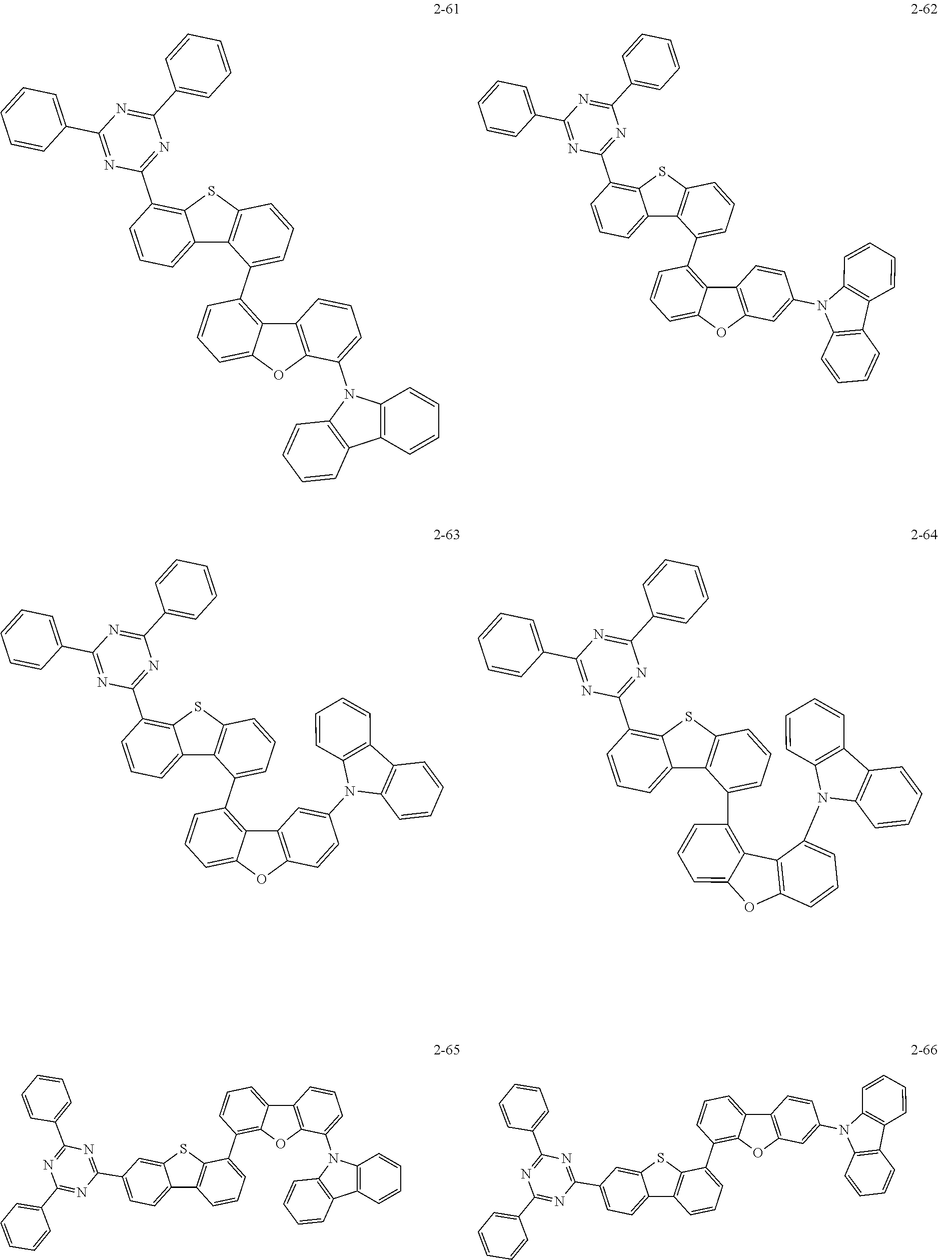

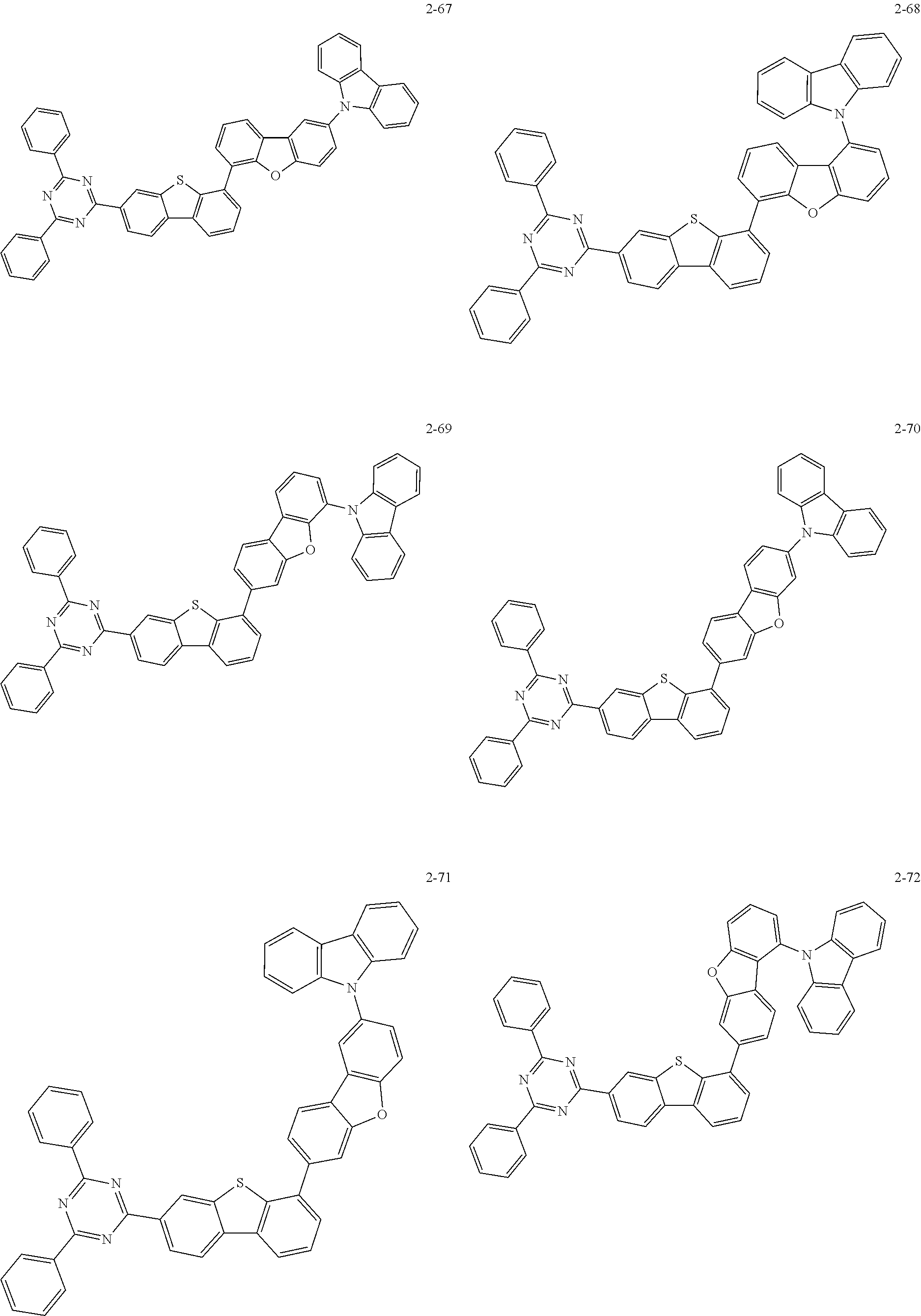

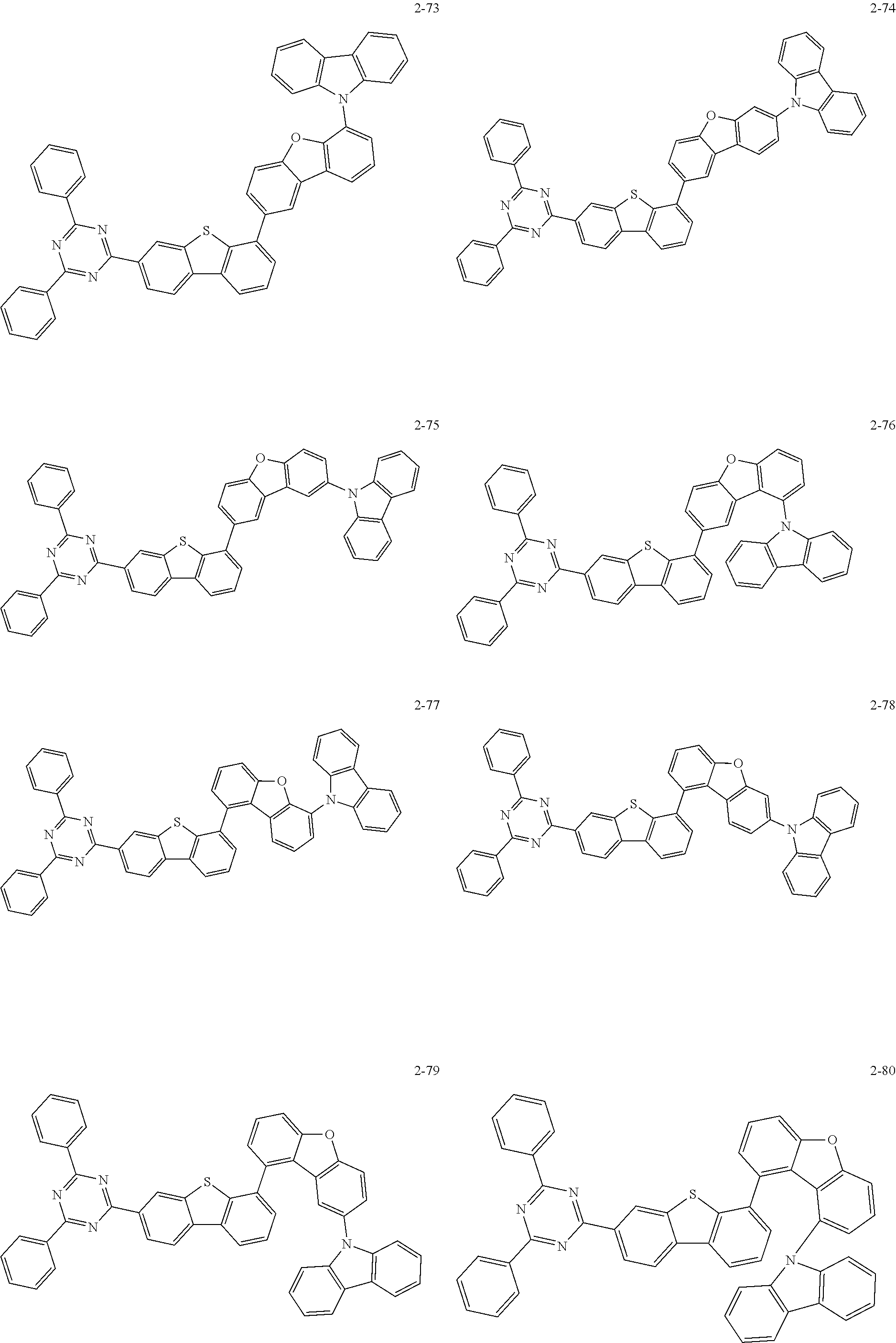

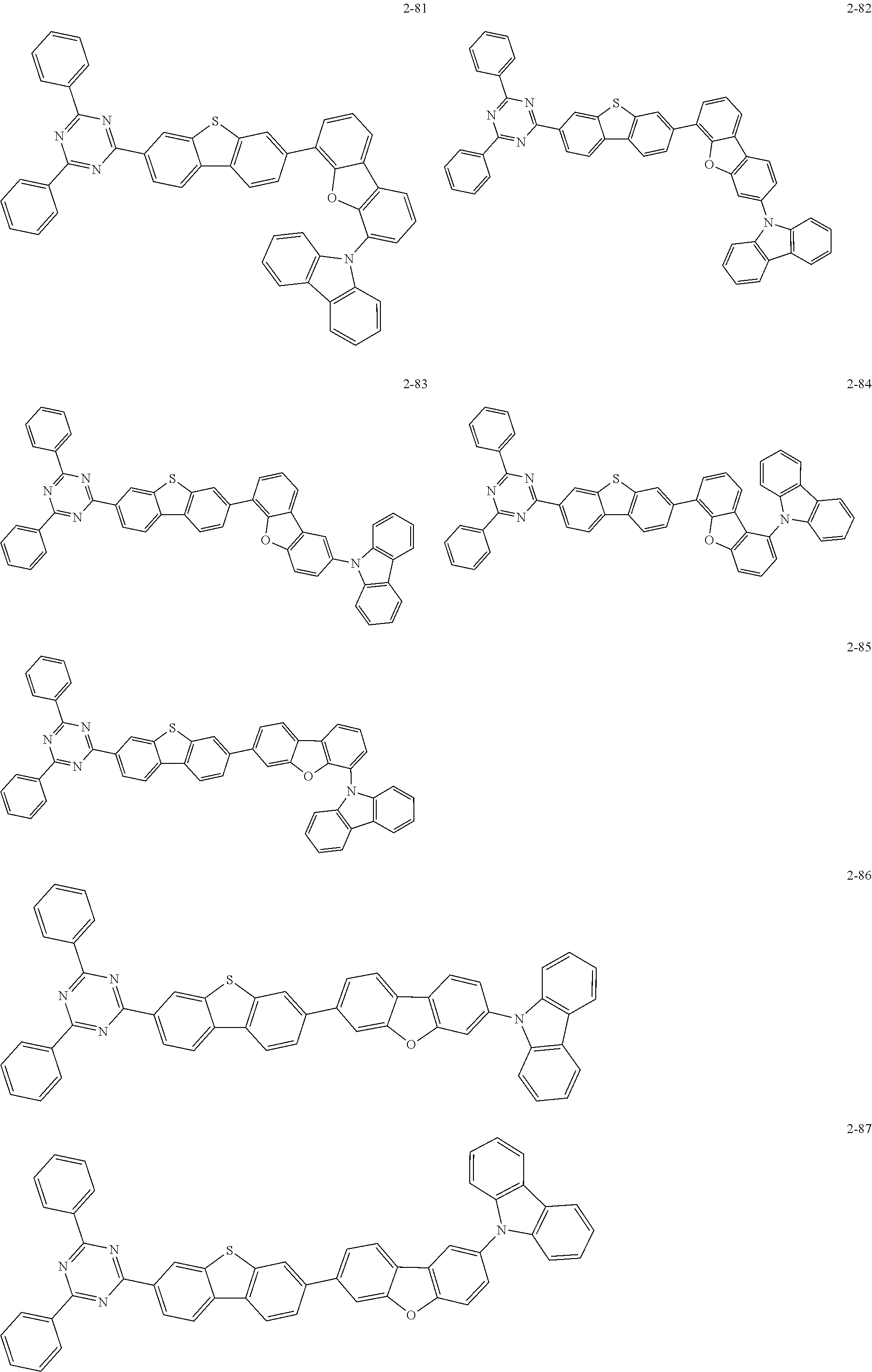

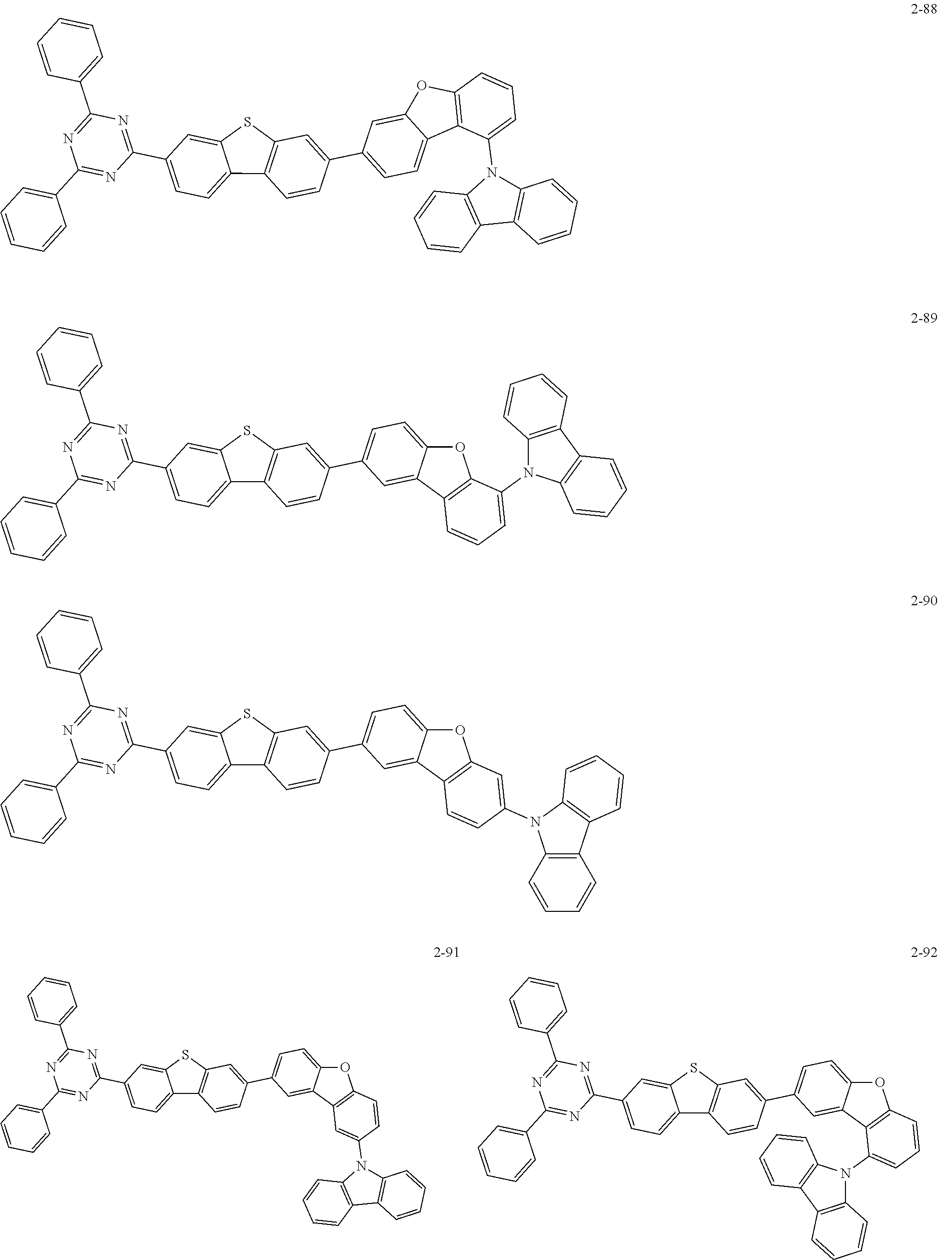

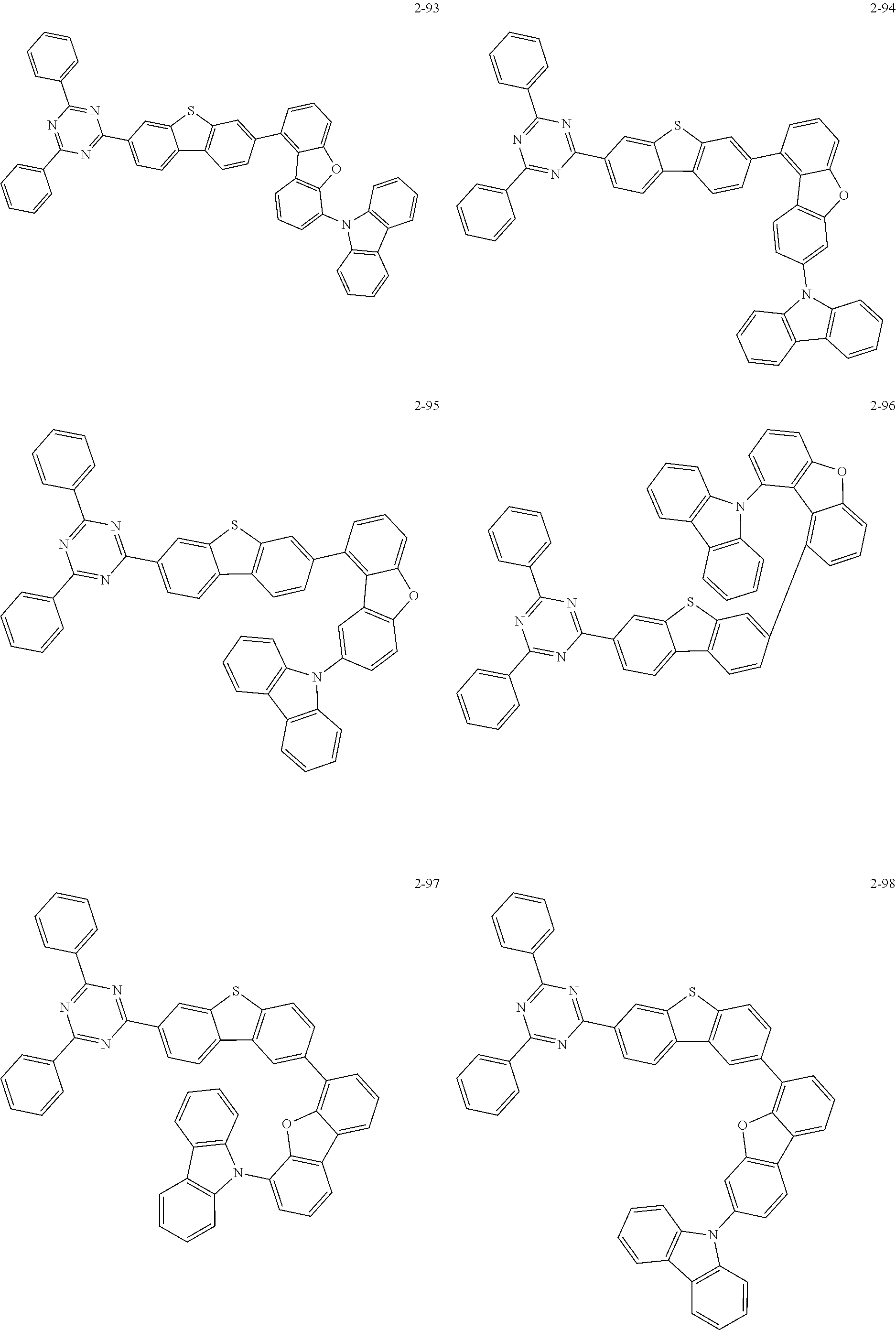

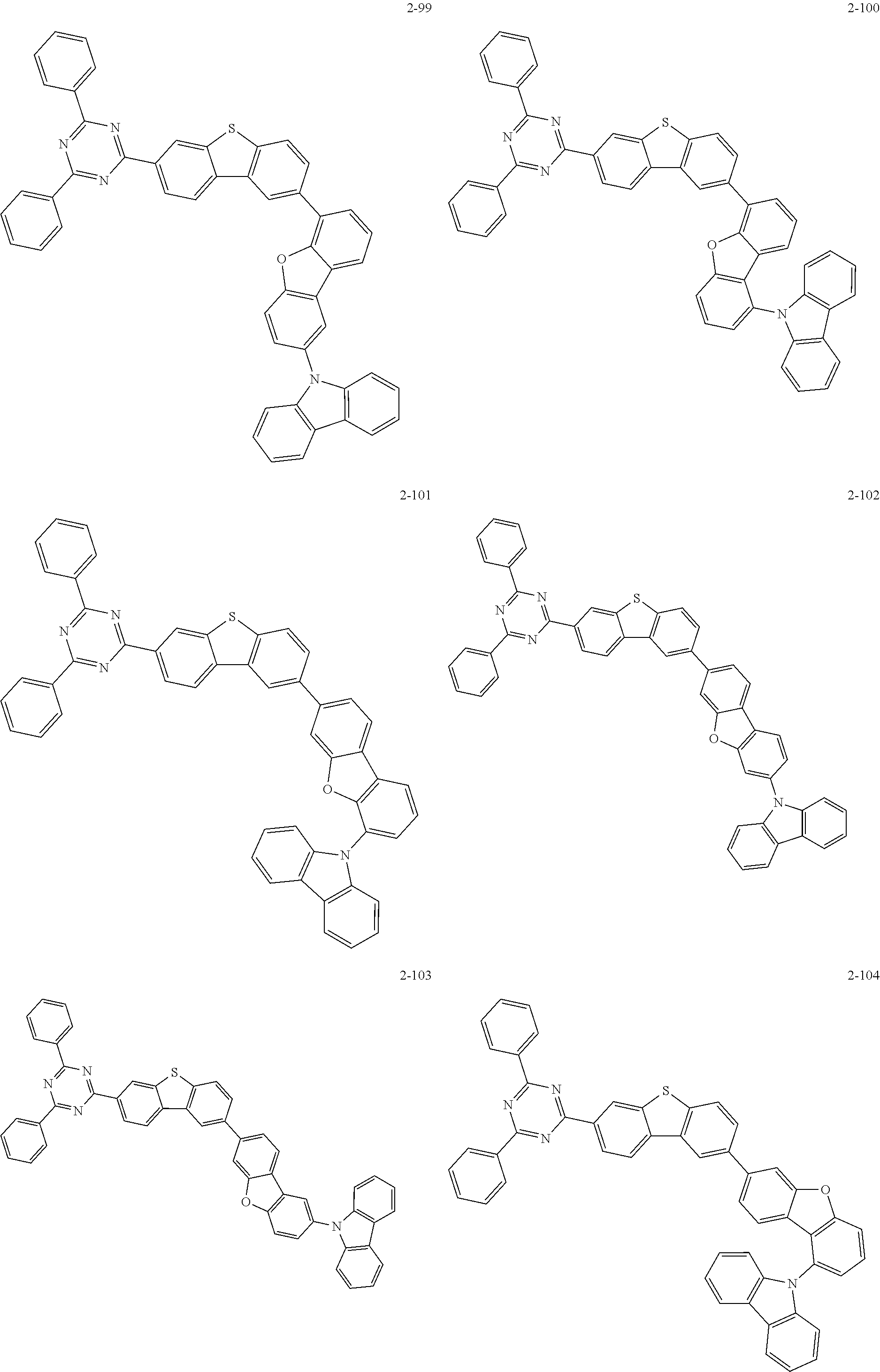

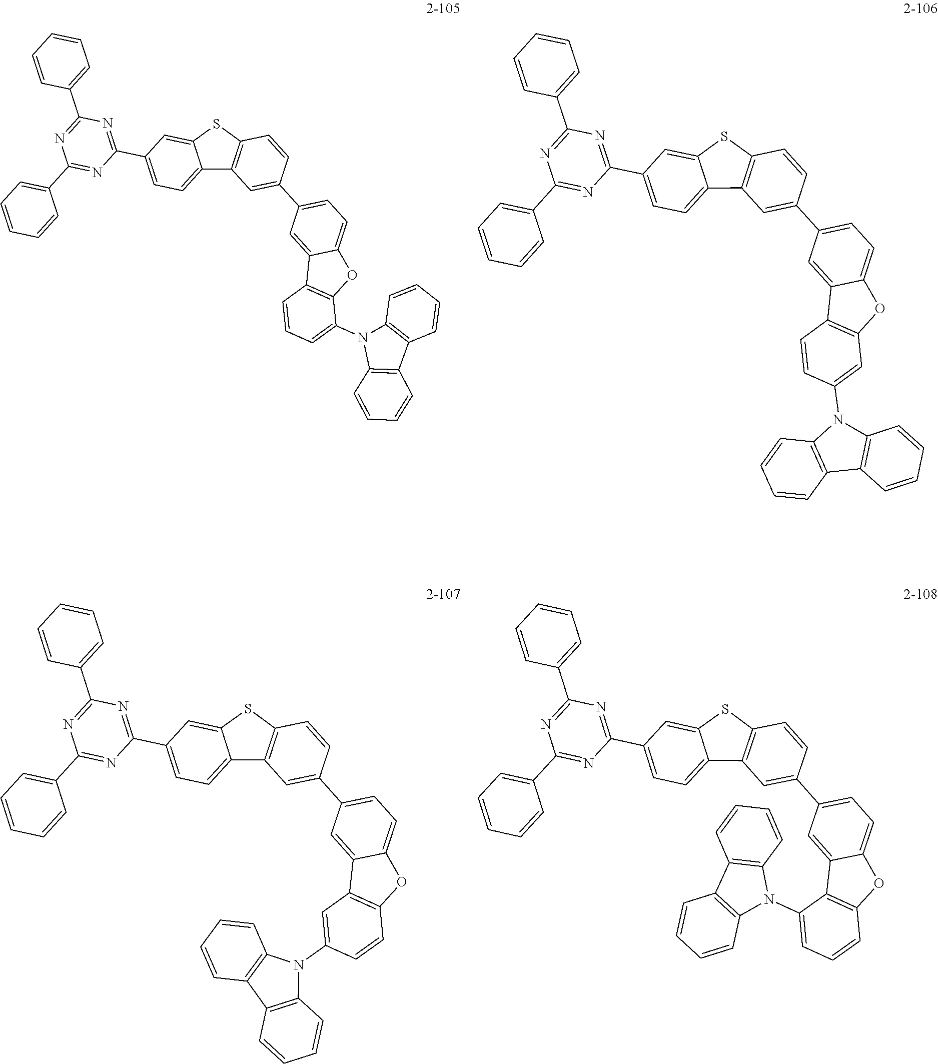 [SMILES: c1ccc(-c2nc(-c3ccccc3)nc(-c3ccc4c(c3)sc3ccc(-c5ccc6oc7c(-n8c9ccccc9c9ccccc98)cccc7c6c5)cc34)n2)cc1 ; c1ccc(-c2nc(-c3ccccc3)nc(-c3ccc4c(c3)sc3ccc(-c5ccc6oc7cc(-n8c9ccccc9c9ccccc98)ccc7c6c5)cc34)n2)cc1 ; c1ccc(-c2nc(-c3ccccc3)nc(-c3ccc4c(c3)sc3ccc(-c5ccc6oc7ccc(-n8c9ccccc9c9ccccc98)cc7c6c5)cc34)n2)cc1 ; c1ccc(-c2nc(-c3ccccc3)nc(-c3ccc4c(c3)sc3ccc(-c5ccc6oc7cccc(-n8c9ccccc9c9ccccc98)c7c6c5)cc34)n2)cc1]

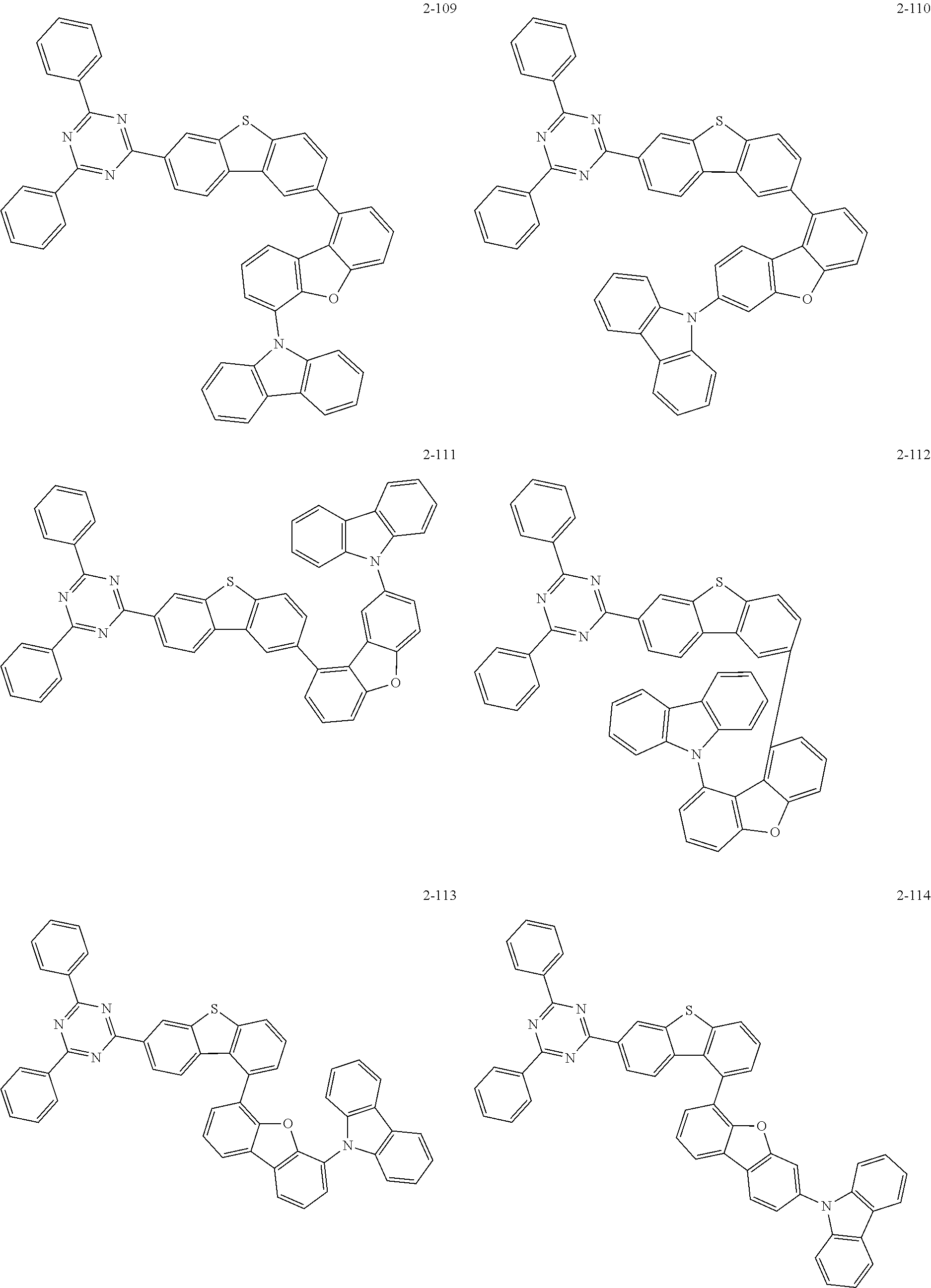

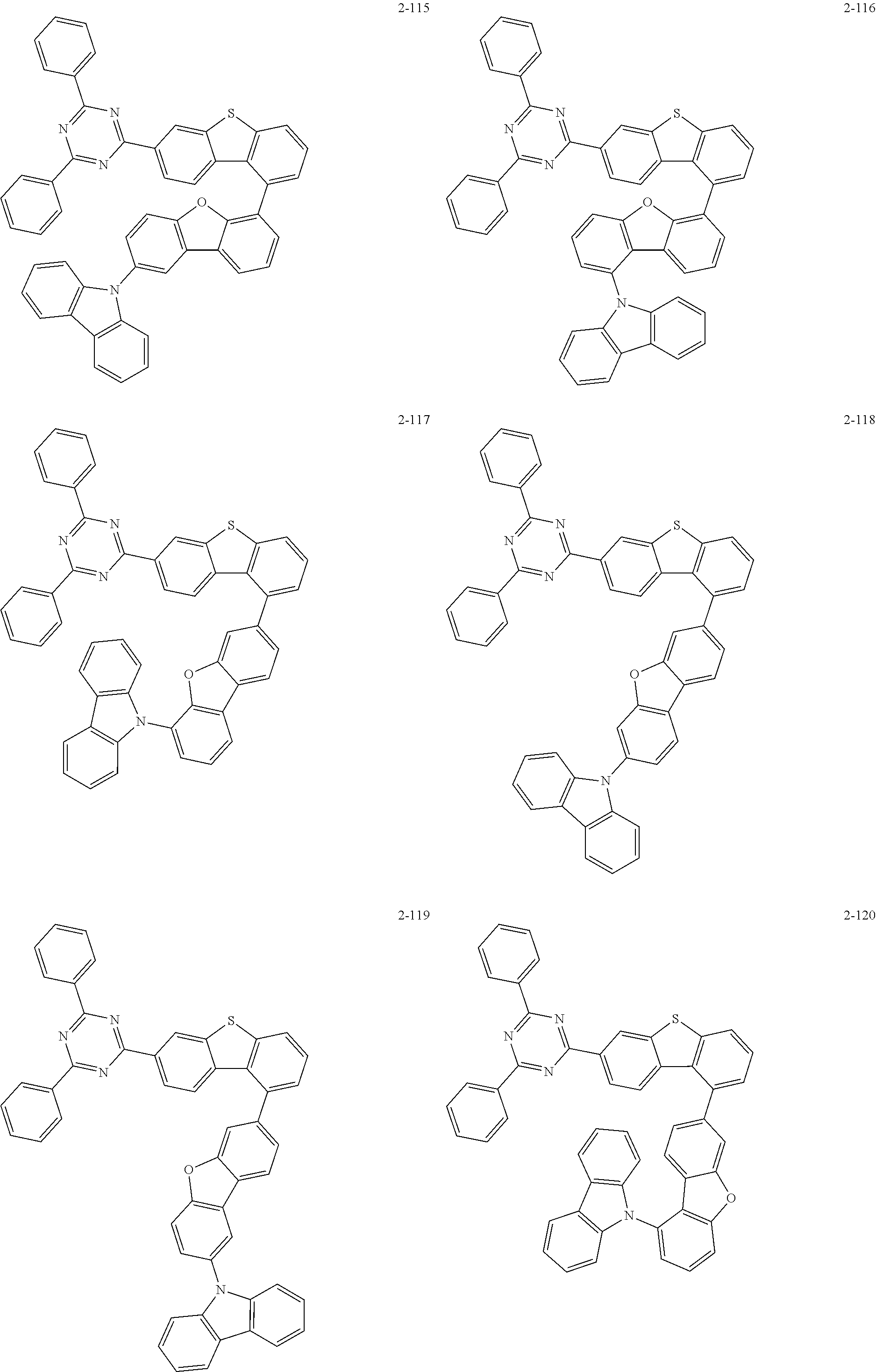

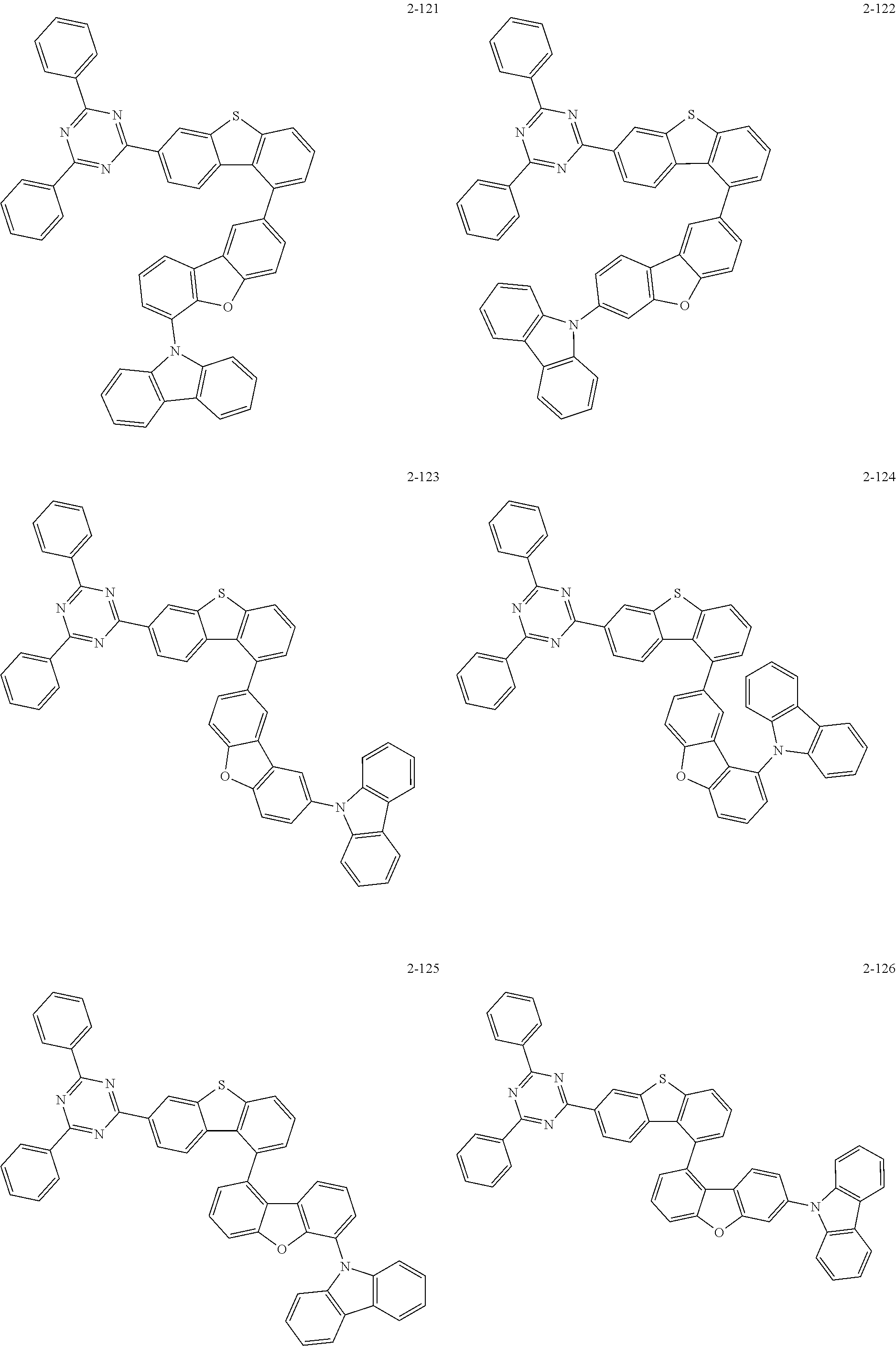

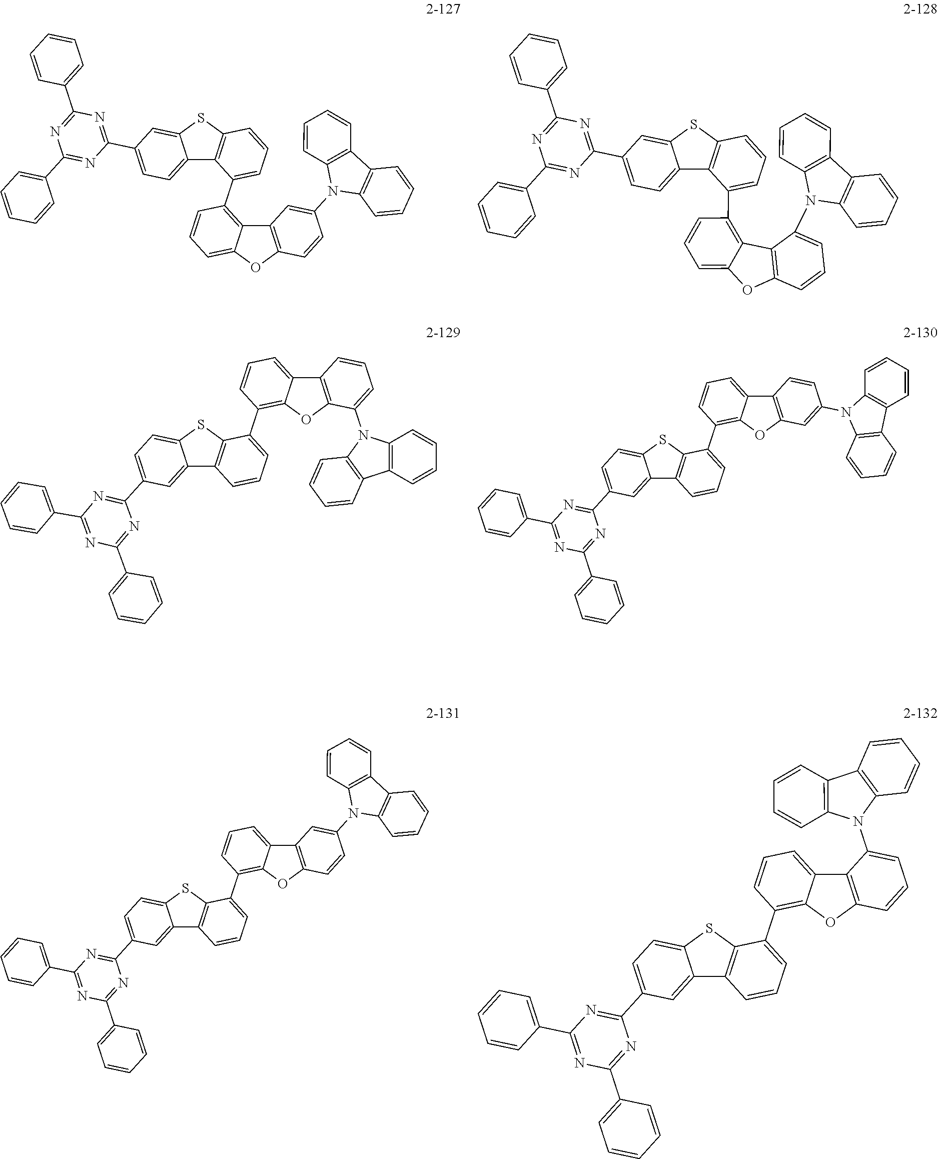

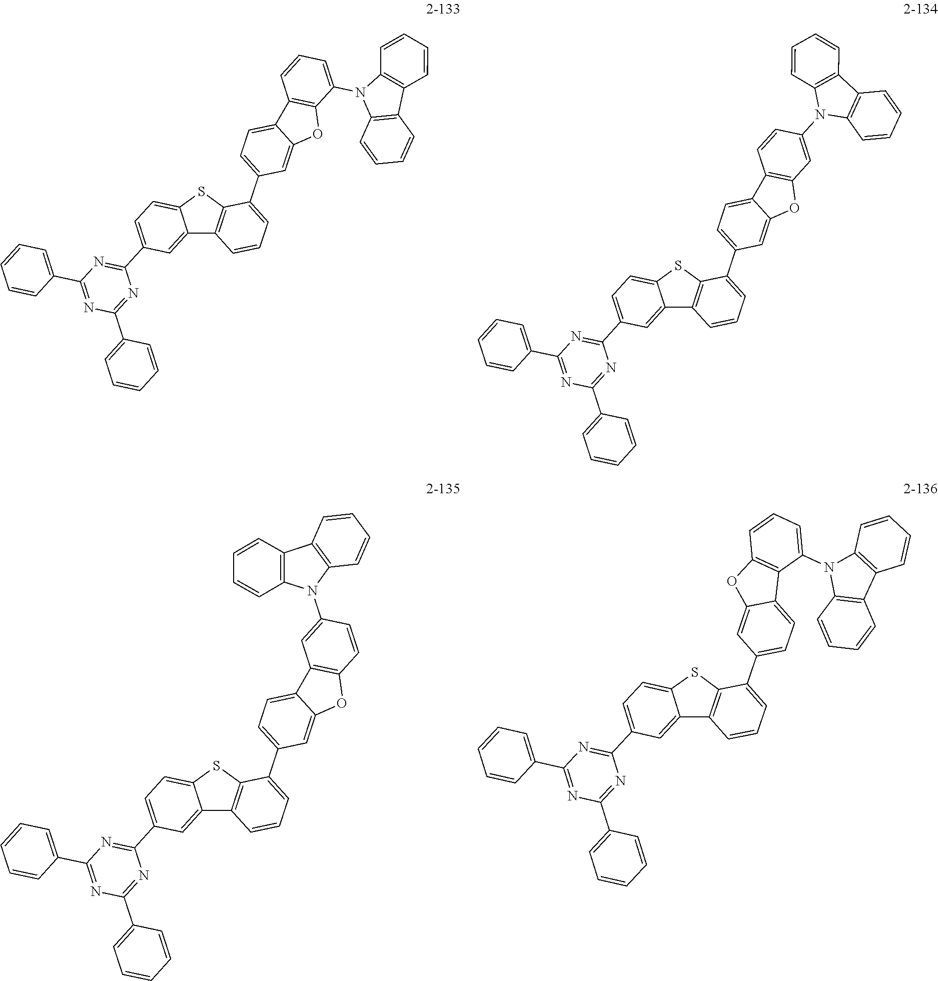 [SMILES: c1ccc(-c2nc(-c3ccccc3)nc(-c3ccc4sc5c(-c6ccc7c(c6)oc6c(-n8c9ccccc9c9ccccc98)cccc67)cccc5c4c3)n2)cc1 ; c1ccc(-c2nc(-c3ccccc3)nc(-c3ccc4sc5c(-c6ccc7c(c6)oc6cc(-n8c9ccccc9c9ccccc98)ccc67)cccc5c4c3)n2)cc1 ; c1ccc(-c2nc(-c3ccccc3)nc(-c3ccc4sc5c(-c6ccc7c(c6)oc6ccc(-n8c9ccccc9c9ccccc98)cc67)cccc5c4c3)n2)cc1 ; c1ccc(-c2nc(-c3ccccc3)nc(-c3ccc4sc5c(-c6ccc7c(c6)oc6cccc(-n8c9ccccc9c9ccccc98)c67)cccc5c4c3)n2)cc1]

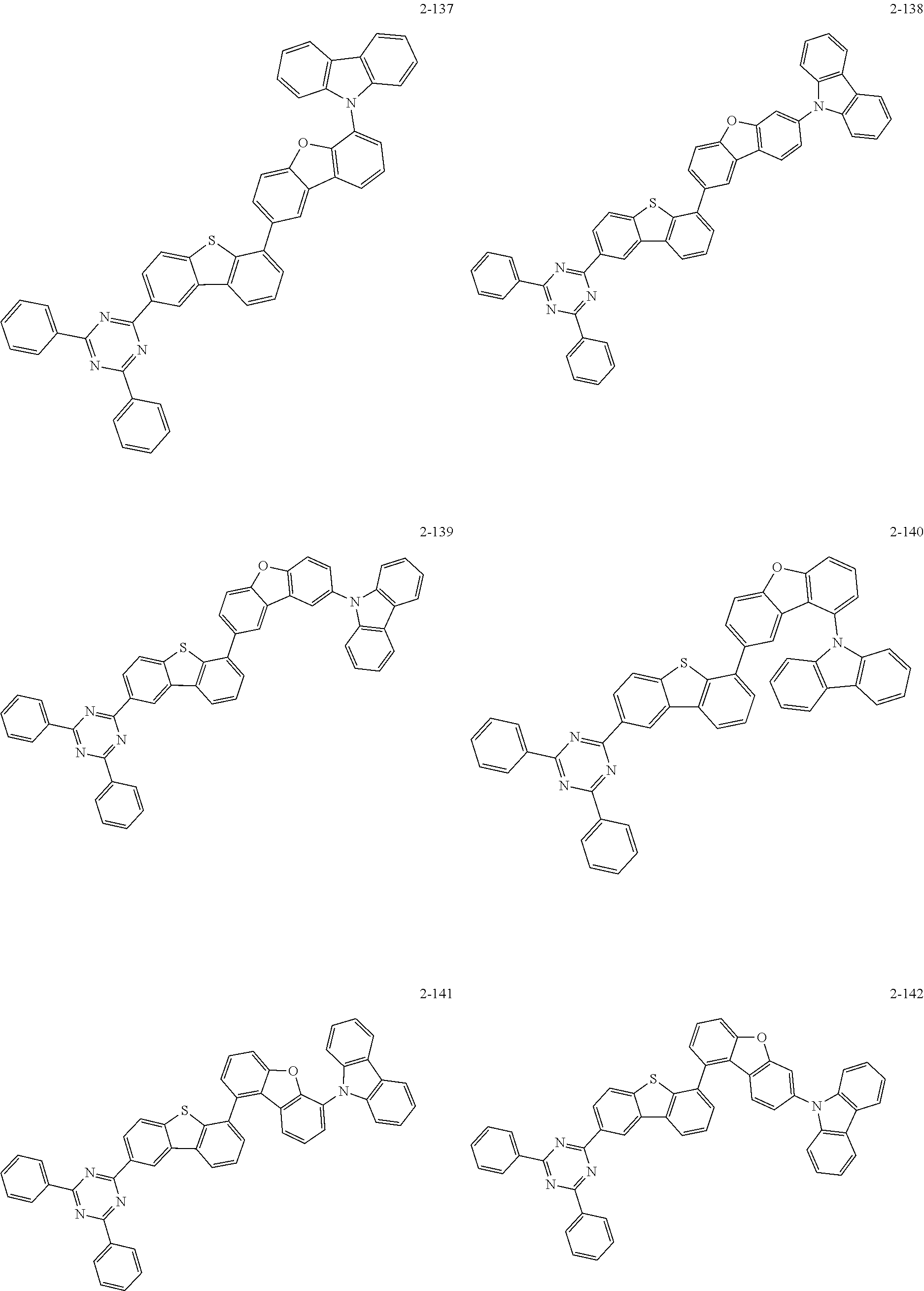

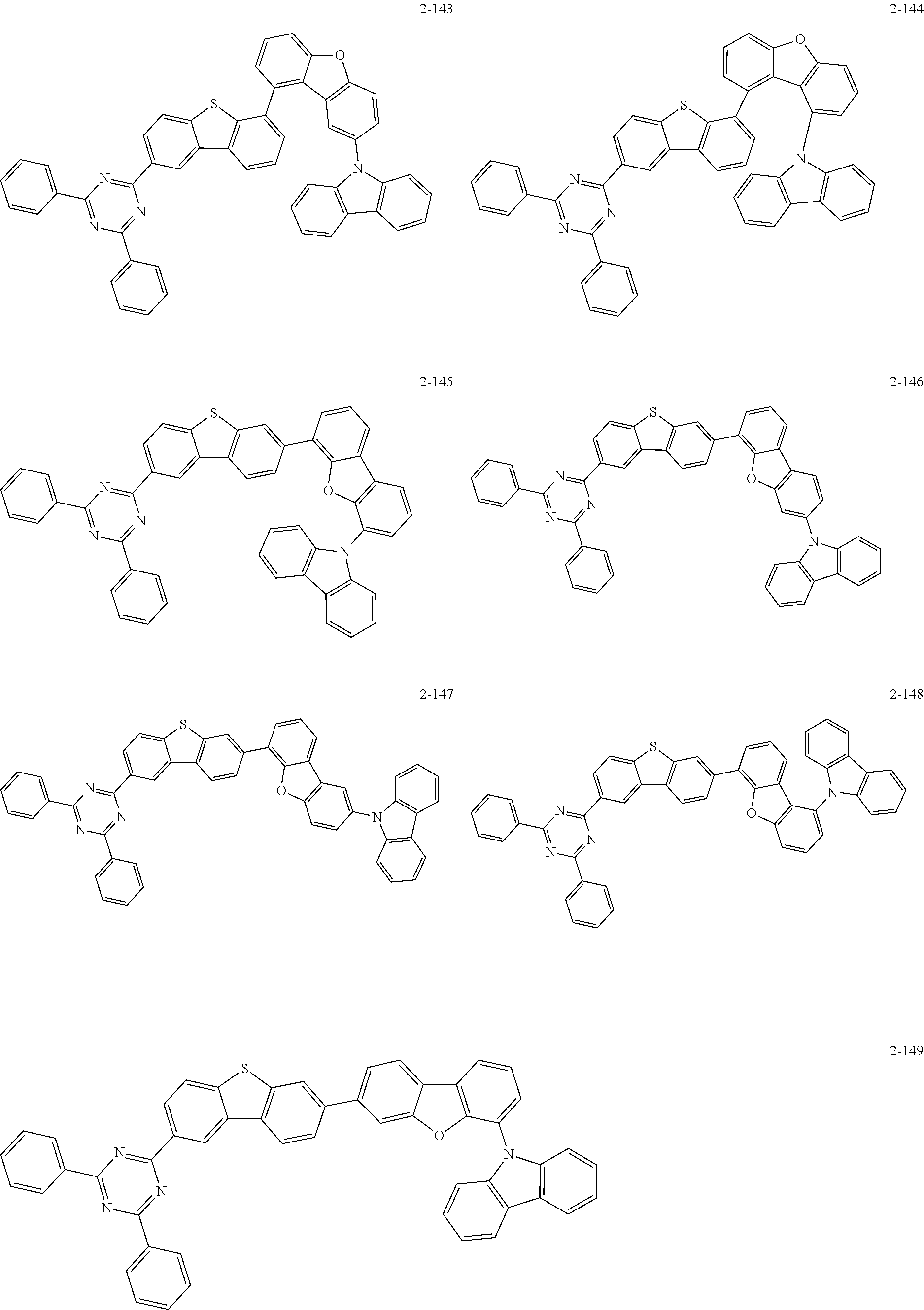

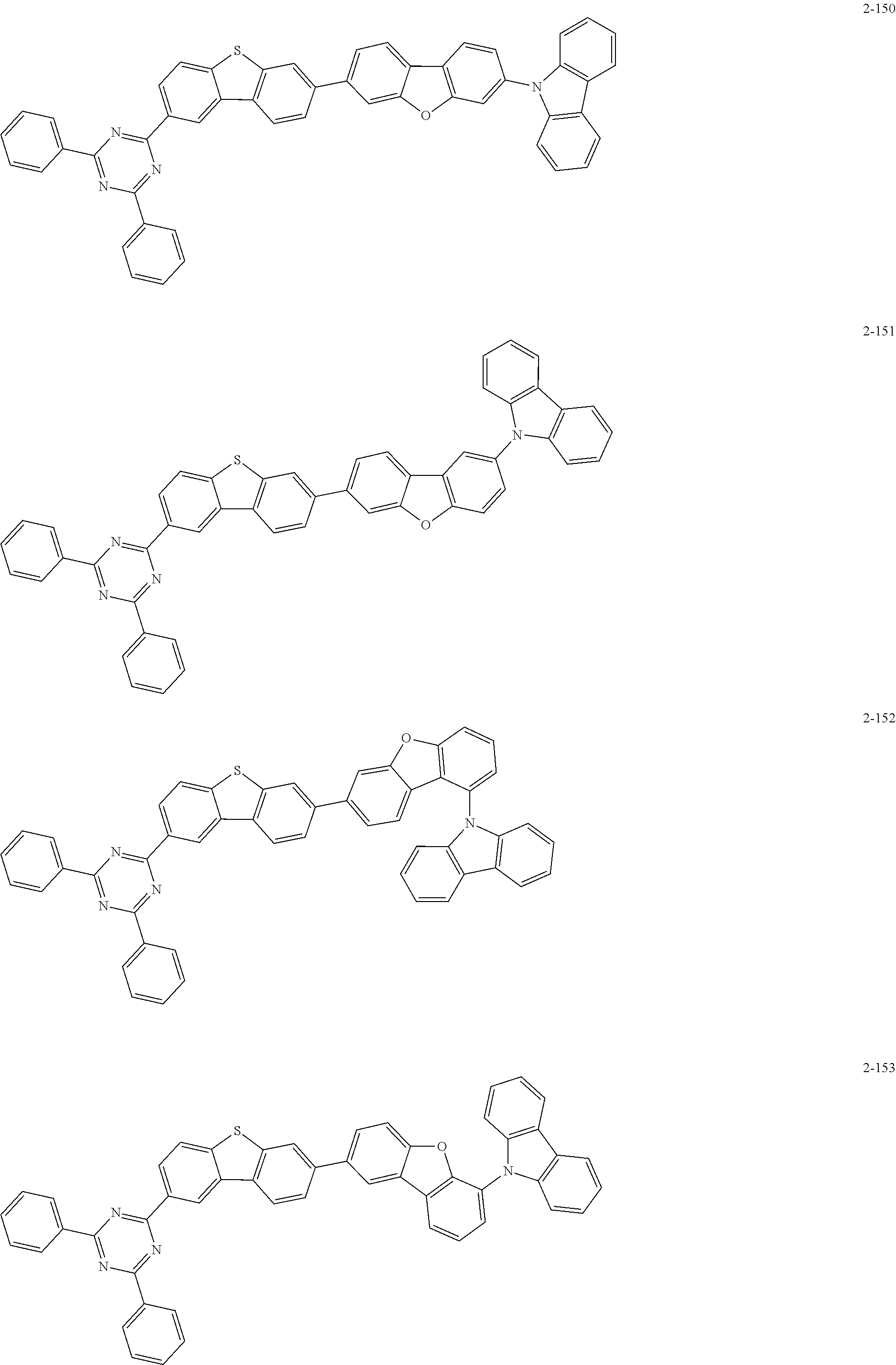 [SMILES: c1ccc(-c2nc(-c3ccccc3)nc(-c3ccc4sc5cc(-c6ccc7c(c6)oc6cc(-n8c9ccccc9c9ccccc98)ccc67)ccc5c4c3)n2)cc1 ; c1ccc(-c2nc(-c3ccccc3)nc(-c3ccc4sc5cc(-c6ccc7c(c6)oc6ccc(-n8c9ccccc9c9ccccc98)cc67)ccc5c4c3)n2)cc1 ; c1ccc(-c2nc(-c3ccccc3)nc(-c3ccc4sc5cc(-c6ccc7c(c6)oc6cccc(-n8c9ccccc9c9ccccc98)c67)ccc5c4c3)n2)cc1 ; c1ccc(-c2nc(-c3ccccc3)nc(-c3ccc4sc5cc(-c6ccc7oc8c(-n9c%10ccccc%10c%10ccccc%109)cccc8c7c6)ccc5c4c3)n2)cc1]

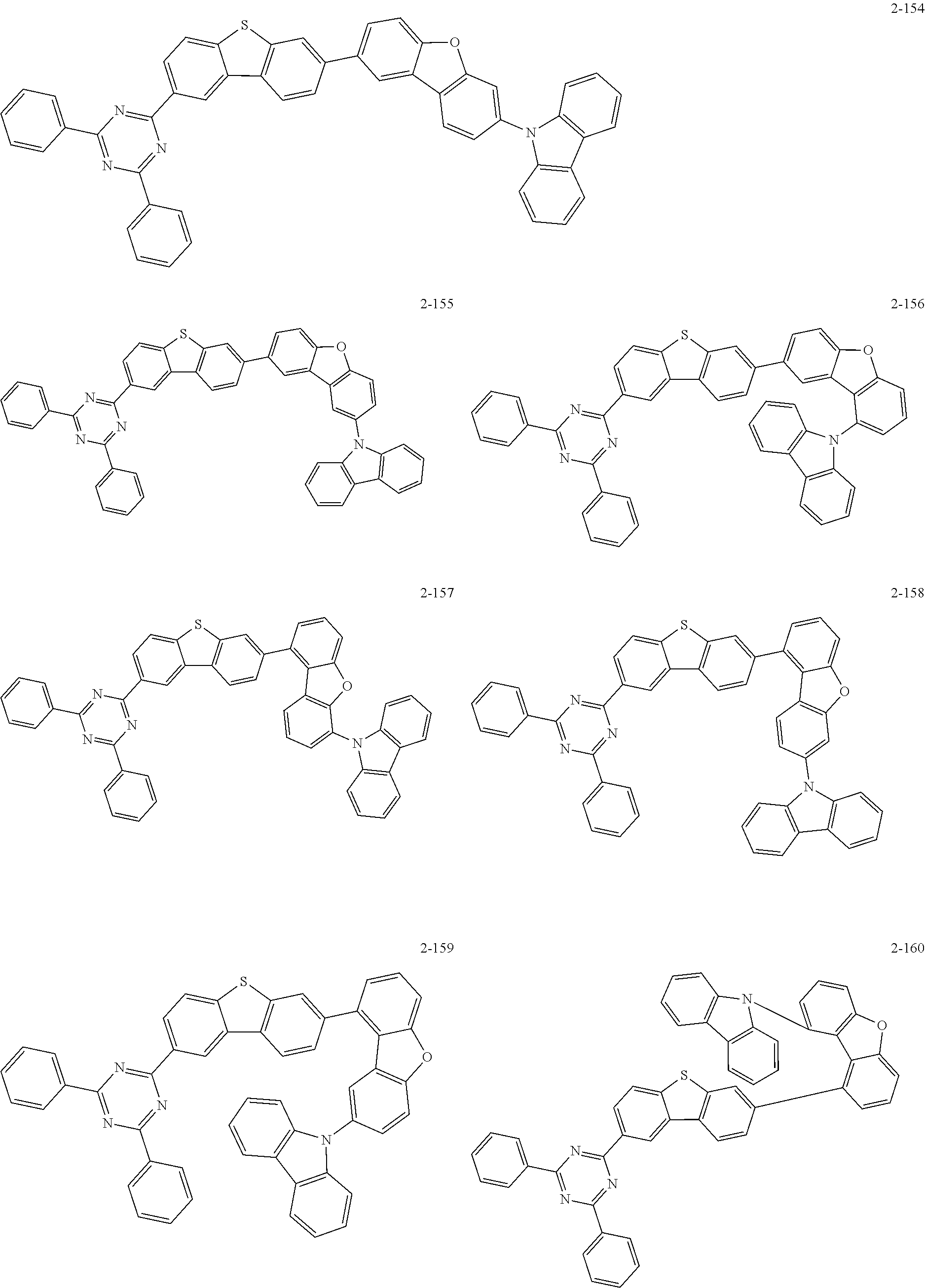

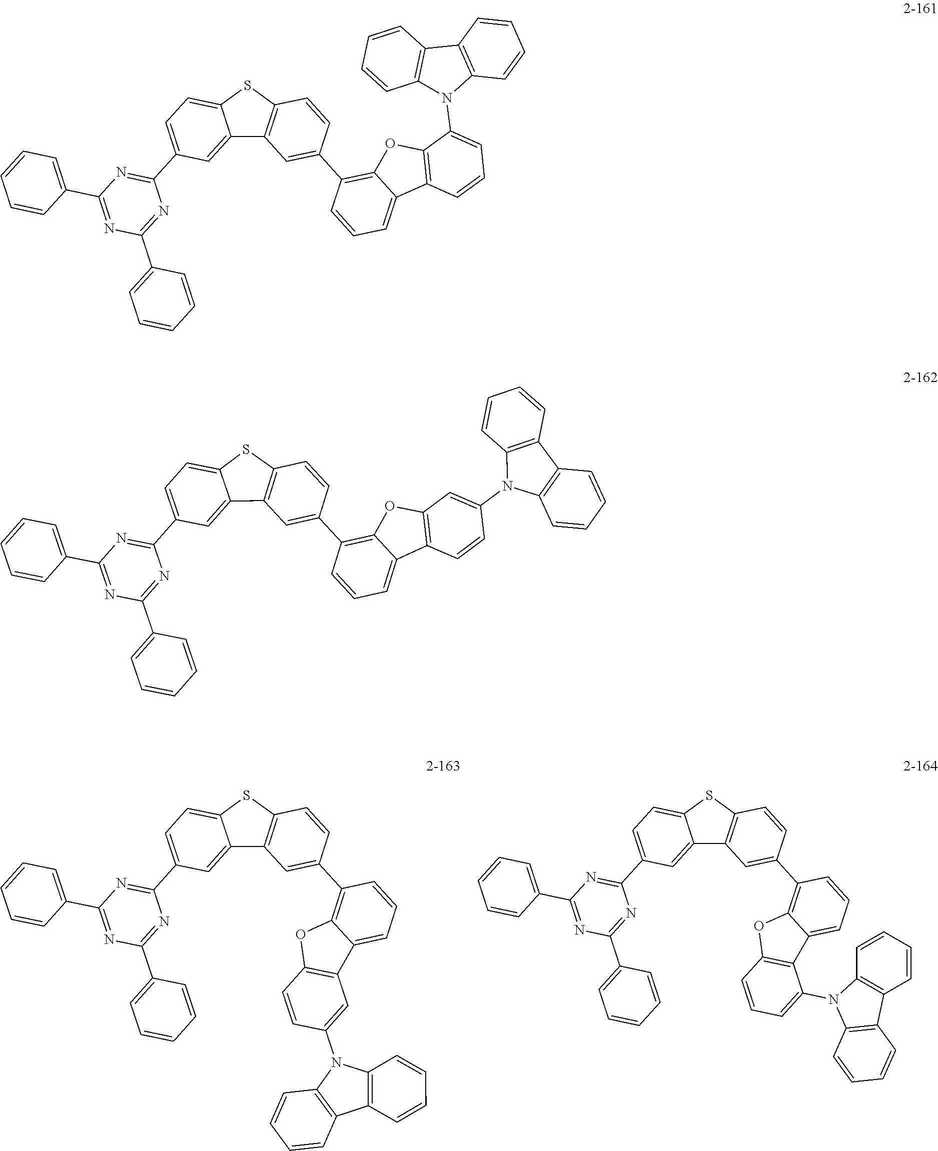 [SMILES: c1ccc(-c2nc(-c3ccccc3)nc(-c3ccc4sc5ccc(-c6cccc7c6oc6c(-n8c9ccccc9c9ccccc98)cccc67)cc5c4c3)n2)cc1 ; c1ccc(-c2nc(-c3ccccc3)nc(-c3ccc4sc5ccc(-c6cccc7c6oc6cc(-n8c9ccccc9c9ccccc98)ccc67)cc5c4c3)n2)cc1 ; c1ccc(-c2nc(-c3ccccc3)nc(-c3ccc4sc5ccc(-c6cccc7c6oc6ccc(-n8c9ccccc9c9ccccc98)cc67)cc5c4c3)n2)cc1 ; c1ccc(-c2nc(-c3ccccc3)nc(-c3ccc4sc5ccc(-c6cccc7c6oc6cccc(-n8c9ccccc9c9ccccc98)c67)cc5c4c3)n2)cc1]

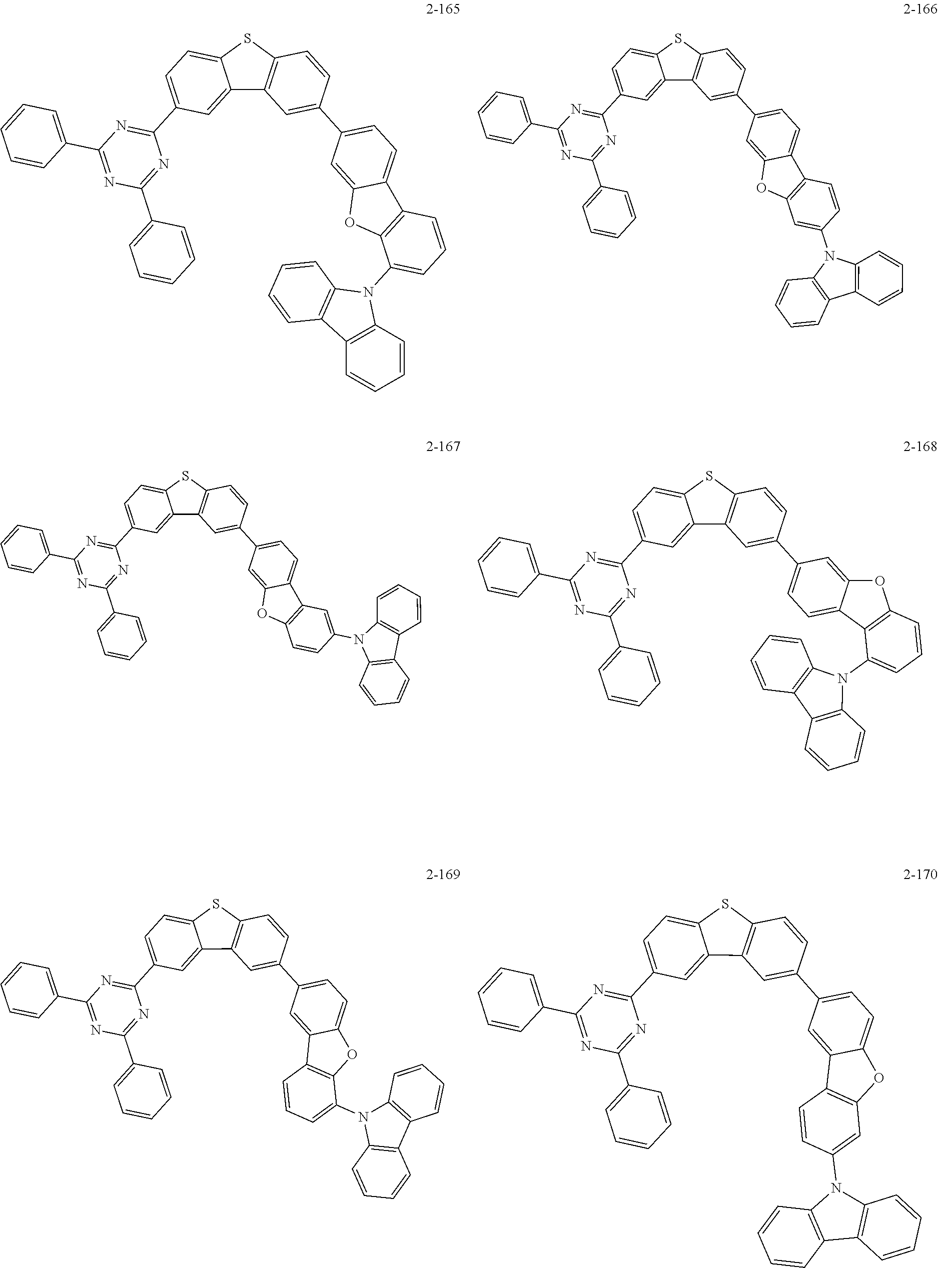

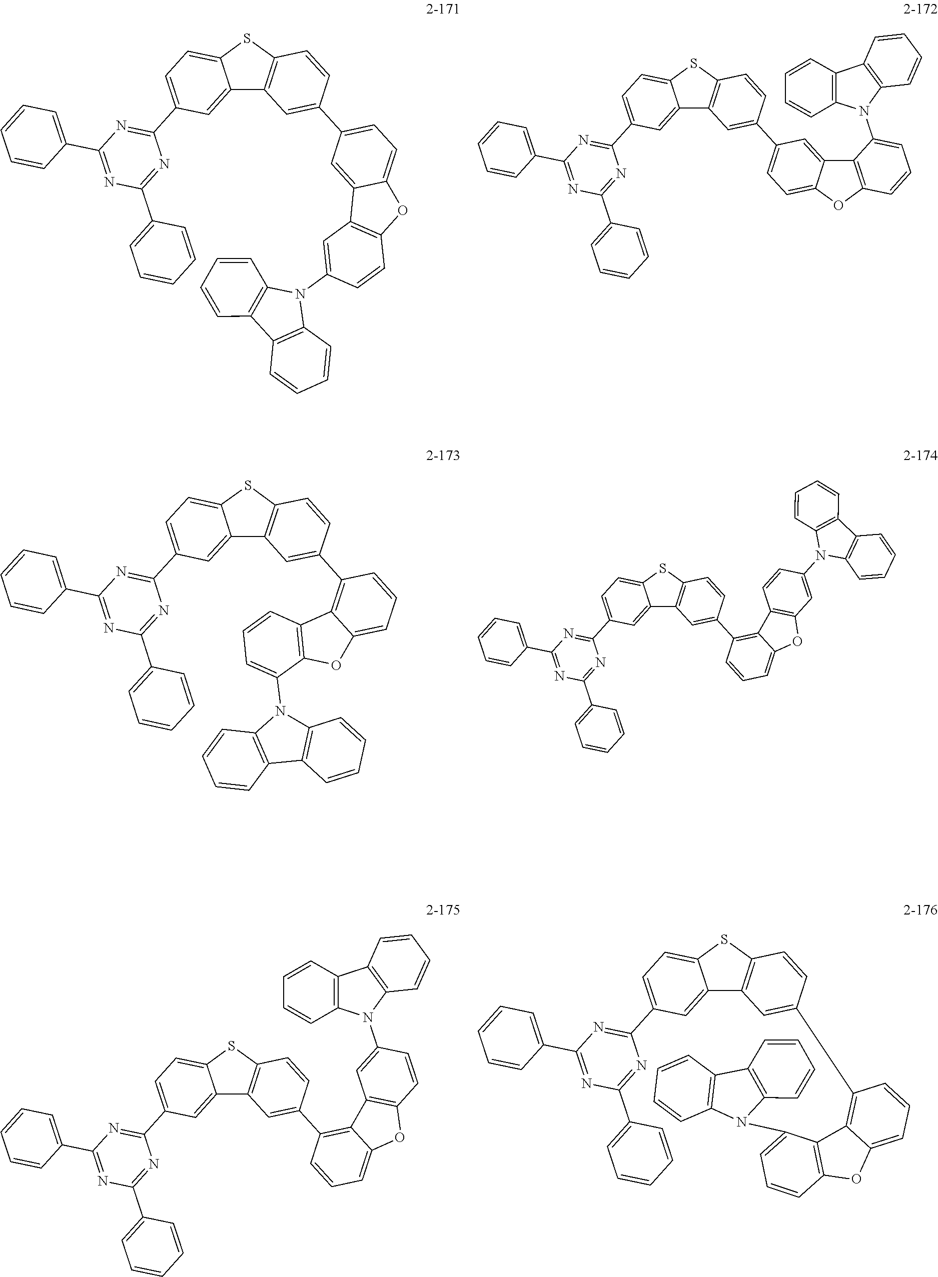

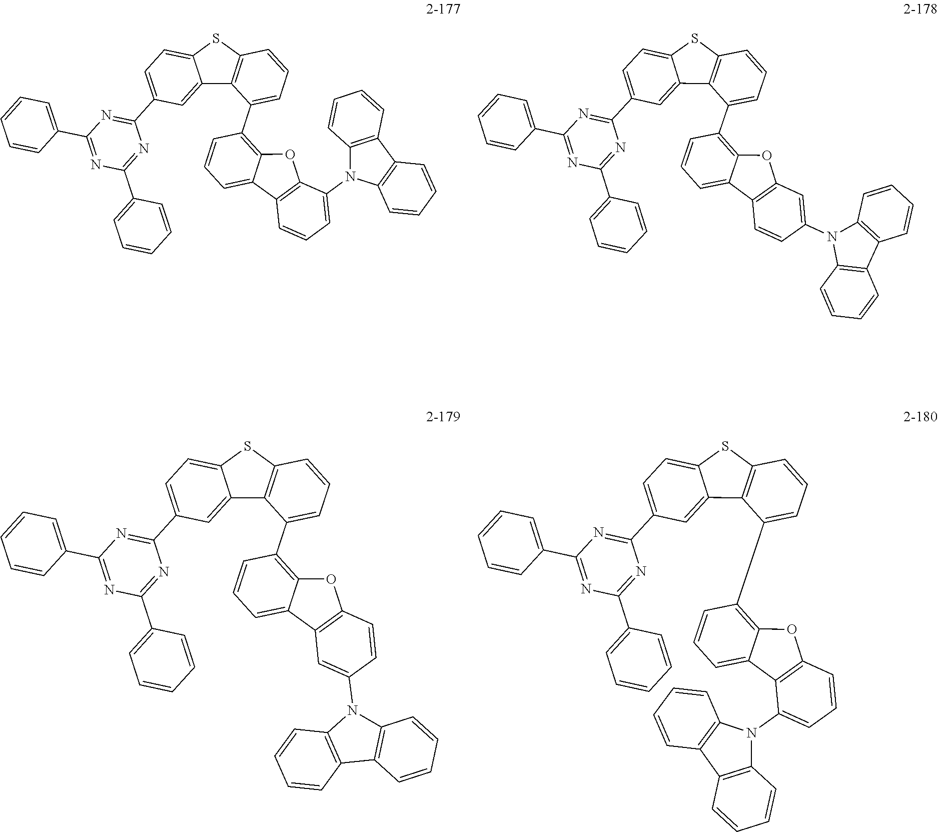 [SMILES: c1ccc(-c2nc(-c3ccccc3)nc(-c3ccc4sc5cccc(-c6cccc7c6oc6c(-n8c9ccccc9c9ccccc98)cccc67)c5c4c3)n2)cc1 ; c1ccc(-c2nc(-c3ccccc3)nc(-c3ccc4sc5cccc(-c6cccc7c6oc6cc(-n8c9ccccc9c9ccccc98)ccc67)c5c4c3)n2)cc1 ; c1ccc(-c2nc(-c3ccccc3)nc(-c3ccc4sc5cccc(-c6cccc7c6oc6ccc(-n8c9ccccc9c9ccccc98)cc67)c5c4c3)n2)cc1 ; c1ccc(-c2nc(-c3ccccc3)nc(-c3ccc4sc5cccc(-c6cccc7c6oc6cccc(-n8c9ccccc9c9ccccc98)c67)c5c4c3)n2)cc1]

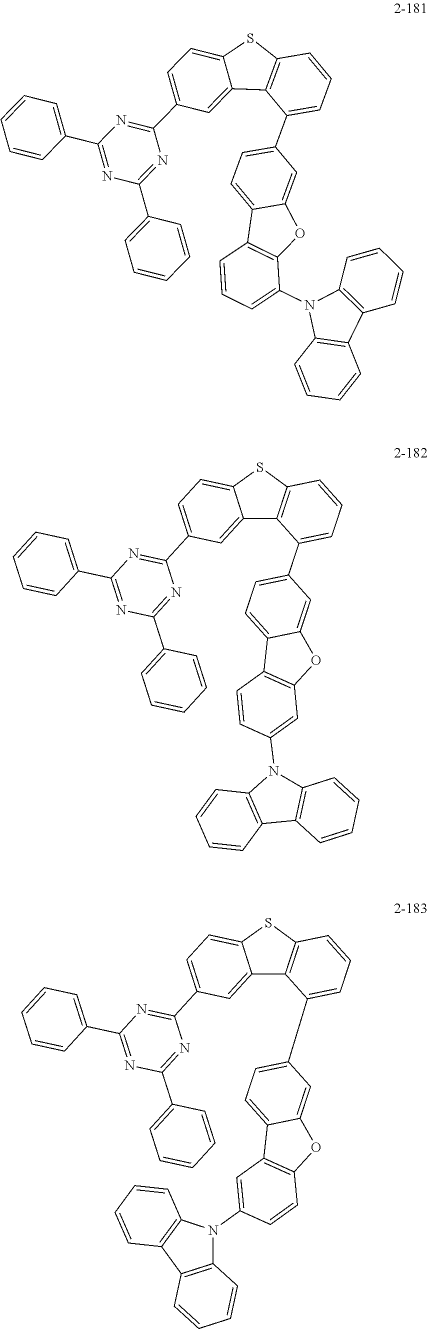 [SMILES: c1ccc(-c2nc(-c3ccccc3)nc(-c3ccc4sc5cccc(-c6ccc7c(c6)oc6c(-n8c9ccccc9c9ccccc98)cccc67)c5c4c3)n2)cc1 ; c1ccc(-c2nc(-c3ccccc3)nc(-c3ccc4sc5cccc(-c6ccc7c(c6)oc6cc(-n8c9ccccc9c9ccccc98)ccc67)c5c4c3)n2)cc1 ; c1ccc(-c2nc(-c3ccccc3)nc(-c3ccc4sc5cccc(-c6ccc7c(c6)oc6ccc(-n8c9ccccc9c9ccccc98)cc67)c5c4c3)n2)cc1]

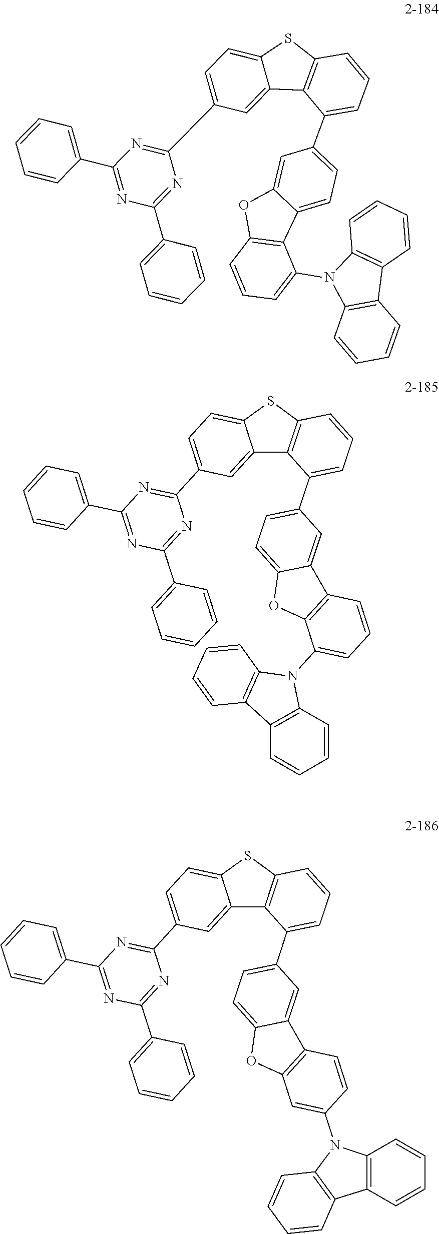 [SMILES: c1ccc(-c2nc(-c3ccccc3)nc(-c3ccc4sc5cccc(-c6ccc7c(c6)oc6cccc(-n8c9ccccc9c9ccccc98)c67)c5c4c3)n2)cc1 ; c1ccc(-c2nc(-c3ccccc3)nc(-c3ccc4sc5cccc(-c6ccc7oc8c(-n9c%10ccccc%10c%10ccccc%109)cccc8c7c6)c5c4c3)n2)cc1 ; c1ccc(-c2nc(-c3ccccc3)nc(-c3ccc4sc5cccc(-c6ccc7oc8cc(-n9c%10ccccc%10c%10ccccc%109)ccc8c7c6)c5c4c3)n2)cc1]

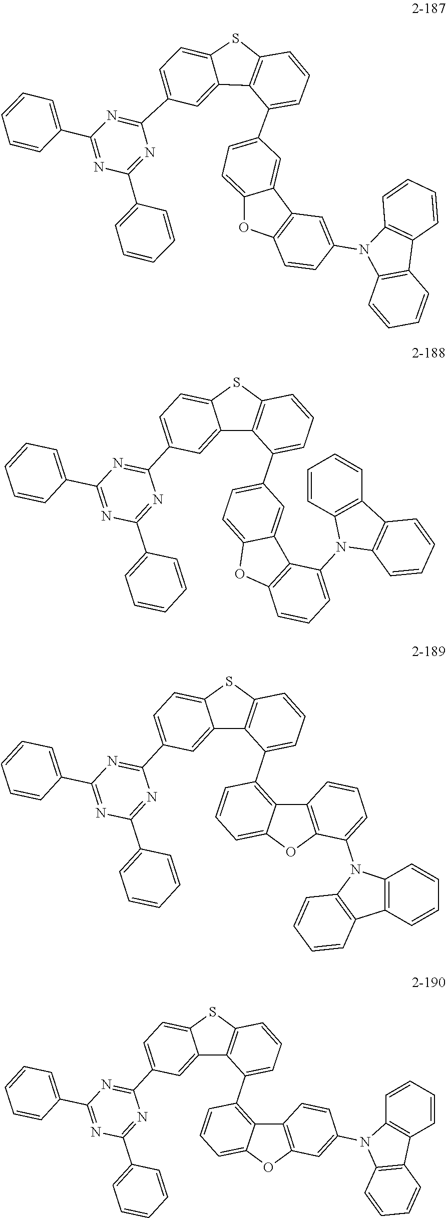 [SMILES: c1ccc(-c2nc(-c3ccccc3)nc(-c3ccc4sc5cccc(-c6ccc7oc8ccc(-n9c%10ccccc%10c%10ccccc%109)cc8c7c6)c5c4c3)n2)cc1 ; c1ccc(-c2nc(-c3ccccc3)nc(-c3ccc4sc5cccc(-c6ccc7oc8cccc(-n9c%10ccccc%10c%10ccccc%109)c8c7c6)c5c4c3)n2)cc1 ; c1ccc(-c2nc(-c3ccccc3)nc(-c3ccc4sc5cccc(-c6cccc7oc8c(-n9c%10ccccc%10c%10ccccc%109)cccc8c67)c5c4c3)n2)cc1 ; c1ccc(-c2nc(-c3ccccc3)nc(-c3ccc4sc5cccc(-c6cccc7oc8cc(-n9c%10ccccc%10c%10ccccc%109)ccc8c67)c5c4c3)n2)cc1]

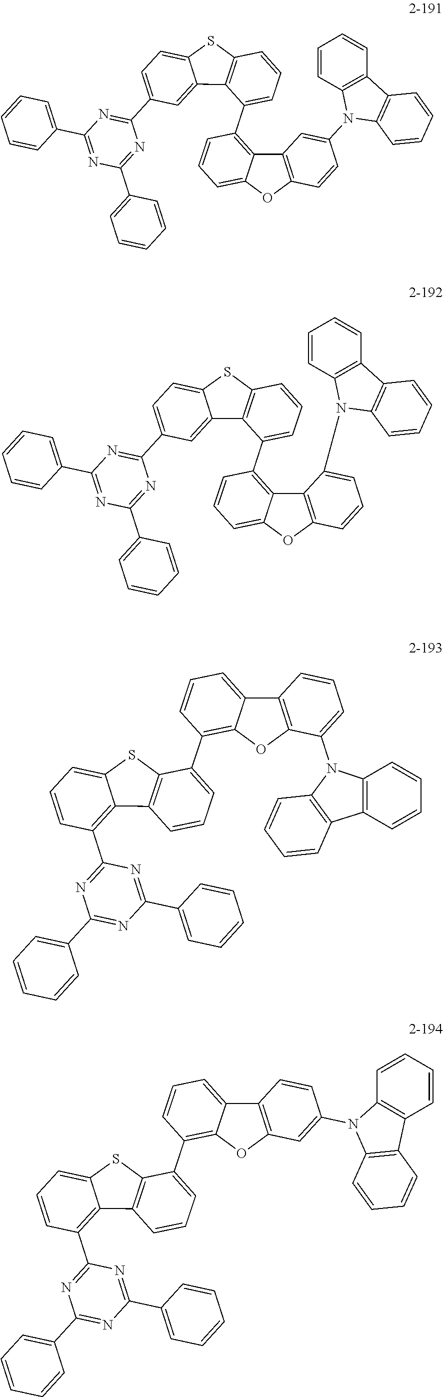 [SMILES: c1ccc(-c2nc(-c3ccccc3)nc(-c3ccc4sc5cccc(-c6cccc7oc8ccc(-n9c%10ccccc%10c%10ccccc%109)cc8c67)c5c4c3)n2)cc1 ; c1ccc(-c2nc(-c3ccccc3)nc(-c3ccc4sc5cccc(-c6cccc7oc8cccc(-n9c%10ccccc%10c%10ccccc%109)c8c67)c5c4c3)n2)cc1 ; c1ccc(-c2nc(-c3ccccc3)nc(-c3cccc4sc5c(-c6cccc7c6oc6c(-n8c9ccccc9c9ccccc98)cccc67)cccc5c34)n2)cc1 ; c1ccc(-c2nc(-c3ccccc3)nc(-c3cccc4sc5c(-c6cccc7c6oc6cc(-n8c9ccccc9c9ccccc98)ccc67)cccc5c34)n2)cc1]

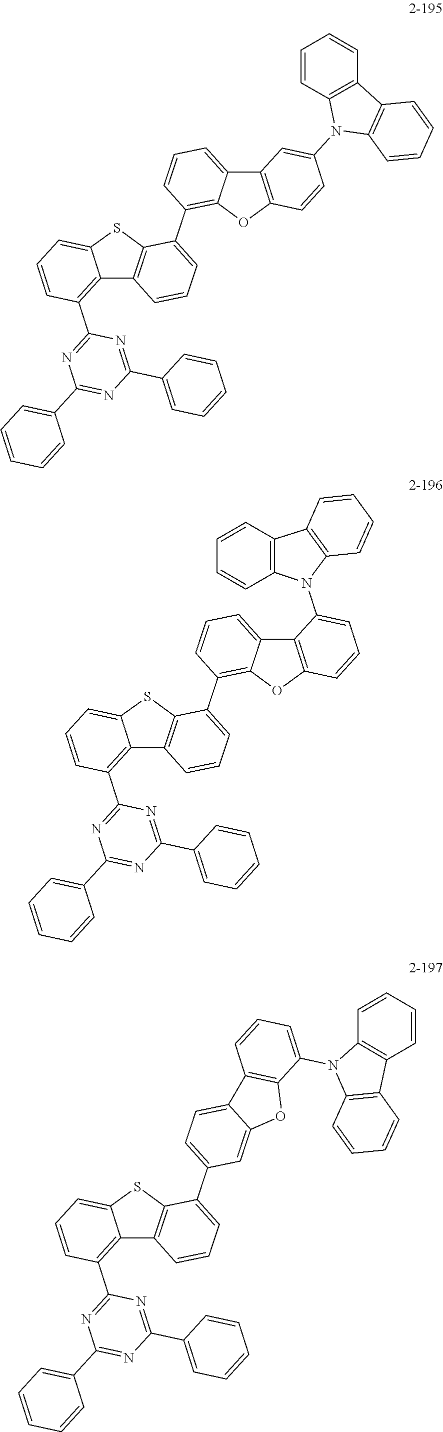 [SMILES: c1ccc(-c2nc(-c3ccccc3)nc(-c3cccc4sc5c(-c6cccc7c6oc6ccc(-n8c9ccccc9c9ccccc98)cc67)cccc5c34)n2)cc1 ; c1ccc(-c2nc(-c3ccccc3)nc(-c3cccc4sc5c(-c6cccc7c6oc6cccc(-n8c9ccccc9c9ccccc98)c67)cccc5c34)n2)cc1 ; c1ccc(-c2nc(-c3ccccc3)nc(-c3cccc4sc5c(-c6ccc7c(c6)oc6c(-n8c9ccccc9c9ccccc98)cccc67)cccc5c34)n2)cc1]

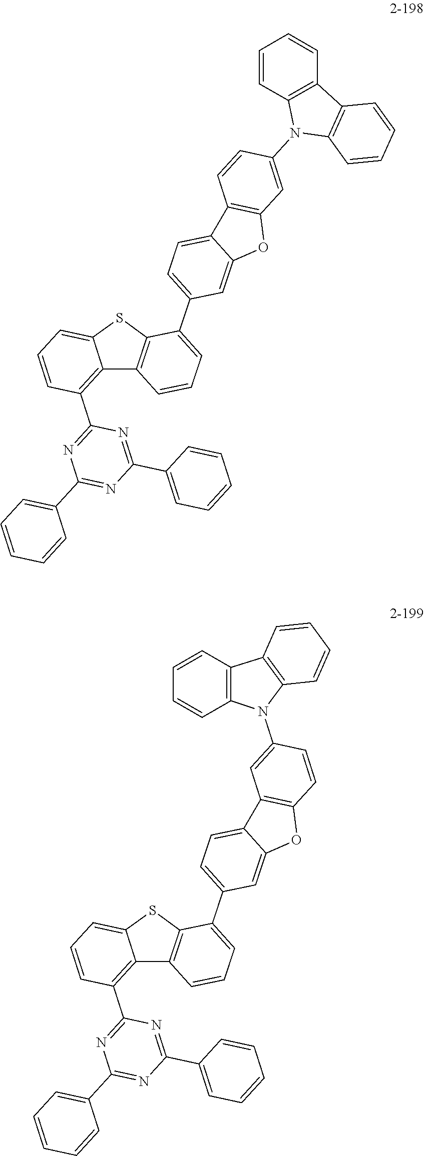 [SMILES: c1ccc(-c2nc(-c3ccccc3)nc(-c3cccc4sc5c(-c6ccc7c(c6)oc6cc(-n8c9ccccc9c9ccccc98)ccc67)cccc5c34)n2)cc1 ; c1ccc(-c2nc(-c3ccccc3)nc(-c3cccc4sc5c(-c6ccc7c(c6)oc6ccc(-n8c9ccccc9c9ccccc98)cc67)cccc5c34)n2)cc1]

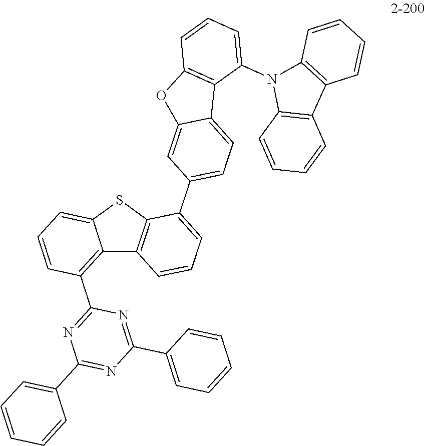 [SMILES: c1ccc(-c2nc(-c3ccccc3)nc(-c3cccc4sc5c(-c6ccc7c(c6)oc6cccc(-n8c9ccccc9c9ccccc98)c67)cccc5c34)n2)cc1]

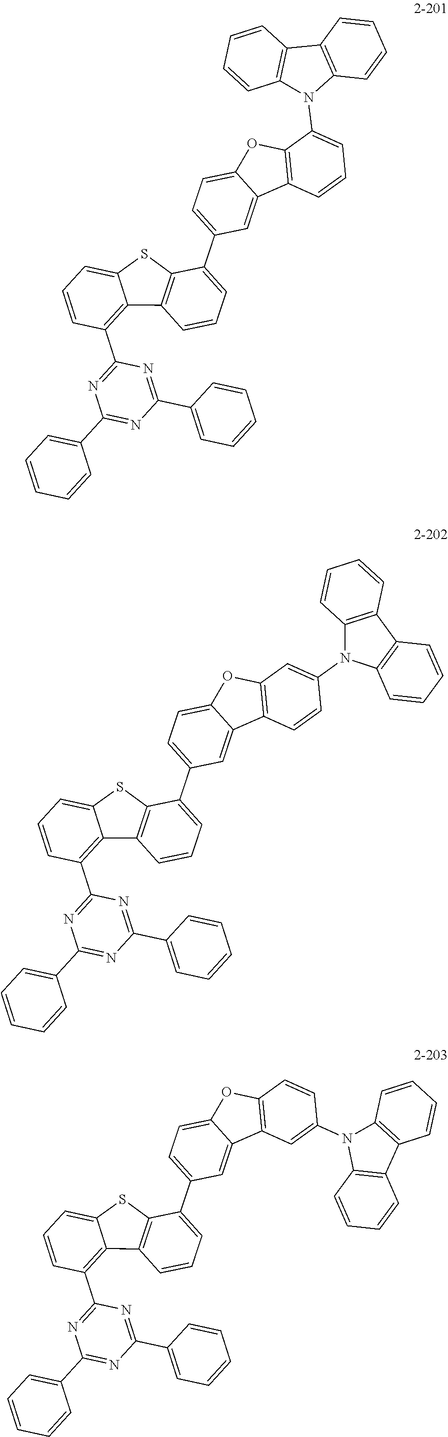 [SMILES: c1ccc(-c2nc(-c3ccccc3)nc(-c3cccc4sc5c(-c6ccc7oc8c(-n9c%10ccccc%10c%10ccccc%109)cccc8c7c6)cccc5c34)n2)cc1 ; c1ccc(-c2nc(-c3ccccc3)nc(-c3cccc4sc5c(-c6ccc7oc8cc(-n9c%10ccccc%10c%10ccccc%109)ccc8c7c6)cccc5c34)n2)cc1 ; c1ccc(-c2nc(-c3ccccc3)nc(-c3cccc4sc5c(-c6ccc7oc8ccc(-n9c%10ccccc%10c%10ccccc%109)cc8c7c6)cccc5c34)n2)cc1]

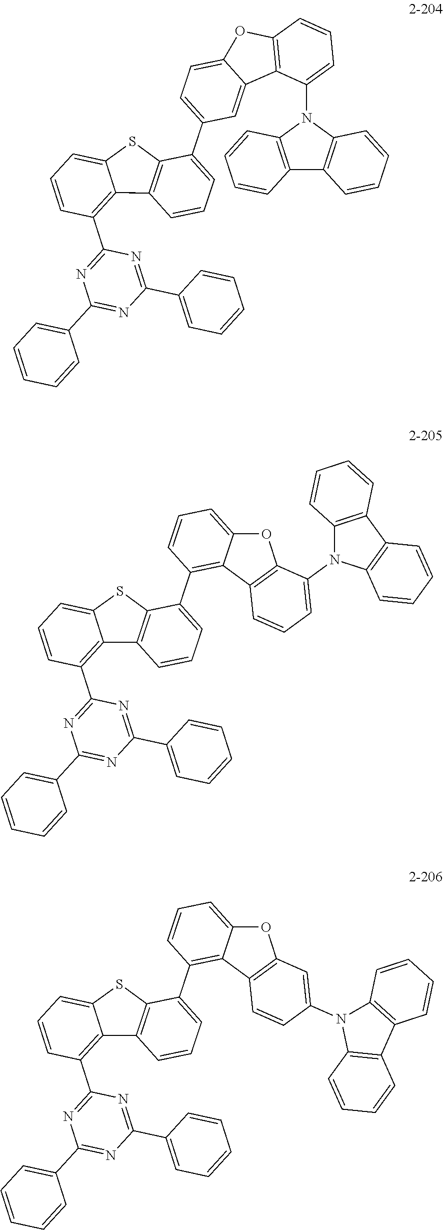 [SMILES: c1ccc(-c2nc(-c3ccccc3)nc(-c3cccc4sc5c(-c6ccc7oc8cccc(-n9c%10ccccc%10c%10ccccc%109)c8c7c6)cccc5c34)n2)cc1 ; c1ccc(-c2nc(-c3ccccc3)nc(-c3cccc4sc5c(-c6cccc7oc8c(-n9c%10ccccc%10c%10ccccc%109)cccc8c67)cccc5c34)n2)cc1 ; c1ccc(-c2nc(-c3ccccc3)nc(-c3cccc4sc5c(-c6cccc7oc8cc(-n9c%10ccccc%10c%10ccccc%109)ccc8c67)cccc5c34)n2)cc1]

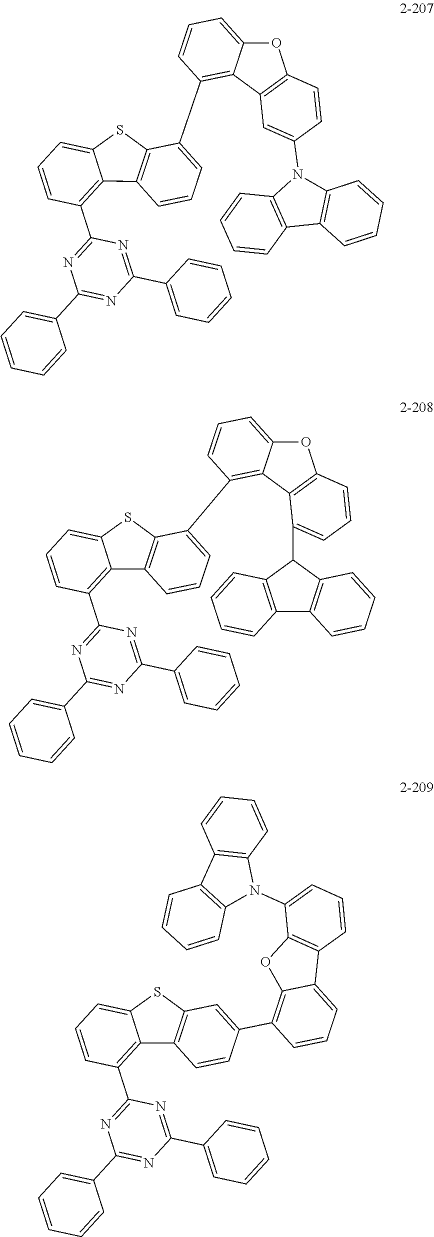 [SMILES: c1ccc(-c2nc(-c3ccccc3)nc(-c3cccc4sc5c(-c6cccc7oc8ccc(-n9c%10ccccc%10c%10ccccc%109)cc8c67)cccc5c34)n2)cc1 ; c1ccc(-c2nc(-c3ccccc3)nc(-c3cccc4sc5c(-c6cccc7oc8cccc(C9c%10ccccc%10-c%10ccccc%109)c8c67)cccc5c34)n2)cc1 ; c1ccc(-c2nc(-c3ccccc3)nc(-c3cccc4sc5cc(-c6cccc7c6oc6c(-n8c9ccccc9c9ccccc98)cccc67)ccc5c34)n2)cc1]

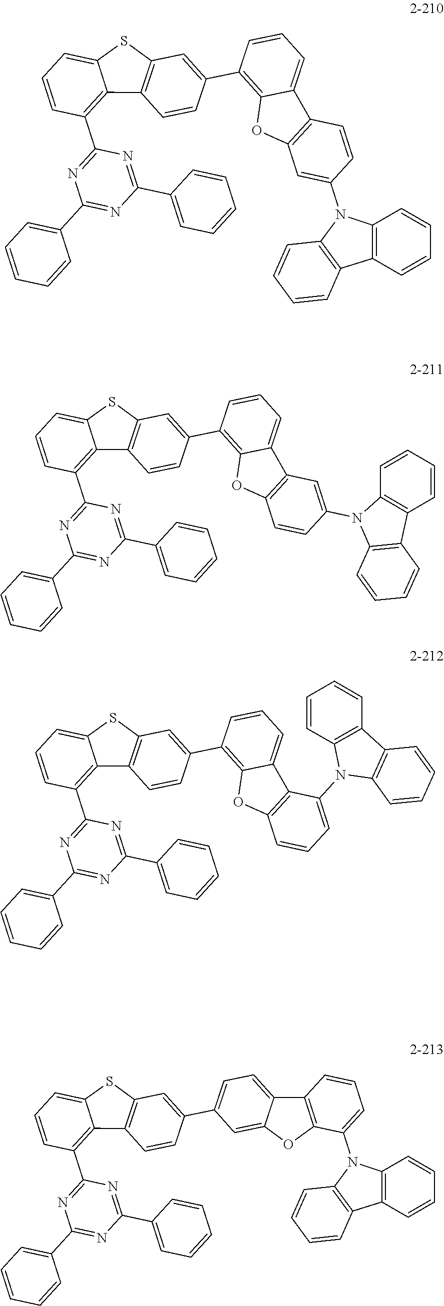 [SMILES: c1ccc(-c2nc(-c3ccccc3)nc(-c3cccc4sc5cc(-c6cccc7c6oc6cc(-n8c9ccccc9c9ccccc98)ccc67)ccc5c34)n2)cc1 ; c1ccc(-c2nc(-c3ccccc3)nc(-c3cccc4sc5cc(-c6cccc7c6oc6ccc(-n8c9ccccc9c9ccccc98)cc67)ccc5c34)n2)cc1 ; c1ccc(-c2nc(-c3ccccc3)nc(-c3cccc4sc5cc(-c6cccc7c6oc6cccc(-n8c9ccccc9c9ccccc98)c67)ccc5c34)n2)cc1 ; c1ccc(-c2nc(-c3ccccc3)nc(-c3cccc4sc5cc(-c6ccc7c(c6)oc6c(-n8c9ccccc9c9ccccc98)cccc67)ccc5c34)n2)cc1]

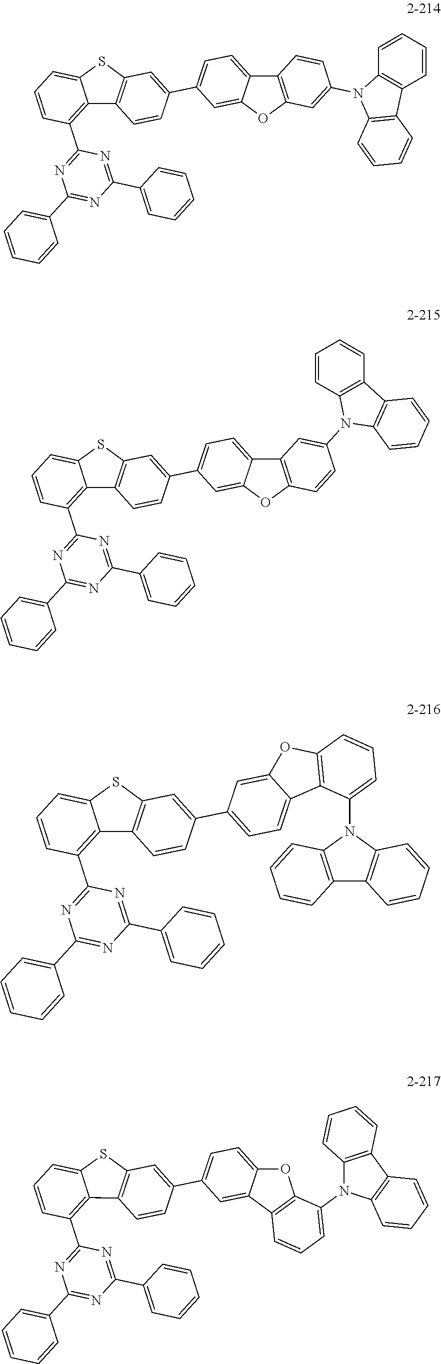 [SMILES: c1ccc(-c2nc(-c3ccccc3)nc(-c3cccc4sc5cc(-c6ccc7c(c6)oc6cc(-n8c9ccccc9c9ccccc98)ccc67)ccc5c34)n2)cc1 ; c1ccc(-c2nc(-c3ccccc3)nc(-c3cccc4sc5cc(-c6ccc7c(c6)oc6ccc(-n8c9ccccc9c9ccccc98)cc67)ccc5c34)n2)cc1 ; c1ccc(-c2nc(-c3ccccc3)nc(-c3cccc4sc5cc(-c6ccc7c(c6)oc6cccc(-n8c9ccccc9c9ccccc98)c67)ccc5c34)n2)cc1 ; c1ccc(-c2nc(-c3ccccc3)nc(-c3cccc4sc5cc(-c6ccc7oc8c(-n9c%10ccccc%10c%10ccccc%109)cccc8c7c6)ccc5c34)n2)cc1]

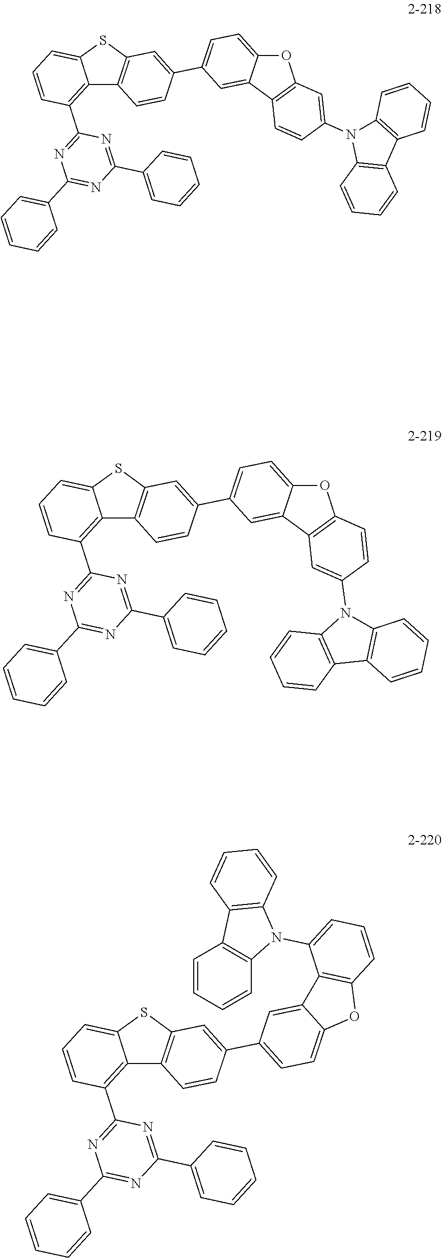 [SMILES: c1ccc(-c2nc(-c3ccccc3)nc(-c3cccc4sc5cc(-c6ccc7oc8cc(-n9c%10ccccc%10c%10ccccc%109)ccc8c7c6)ccc5c34)n2)cc1 ; c1ccc(-c2nc(-c3ccccc3)nc(-c3cccc4sc5cc(-c6ccc7oc8ccc(-n9c%10ccccc%10c%10ccccc%109)cc8c7c6)ccc5c34)n2)cc1 ; c1ccc(-c2nc(-c3ccccc3)nc(-c3cccc4sc5cc(-c6ccc7oc8cccc(-n9c%10ccccc%10c%10ccccc%109)c8c7c6)ccc5c34)n2)cc1]

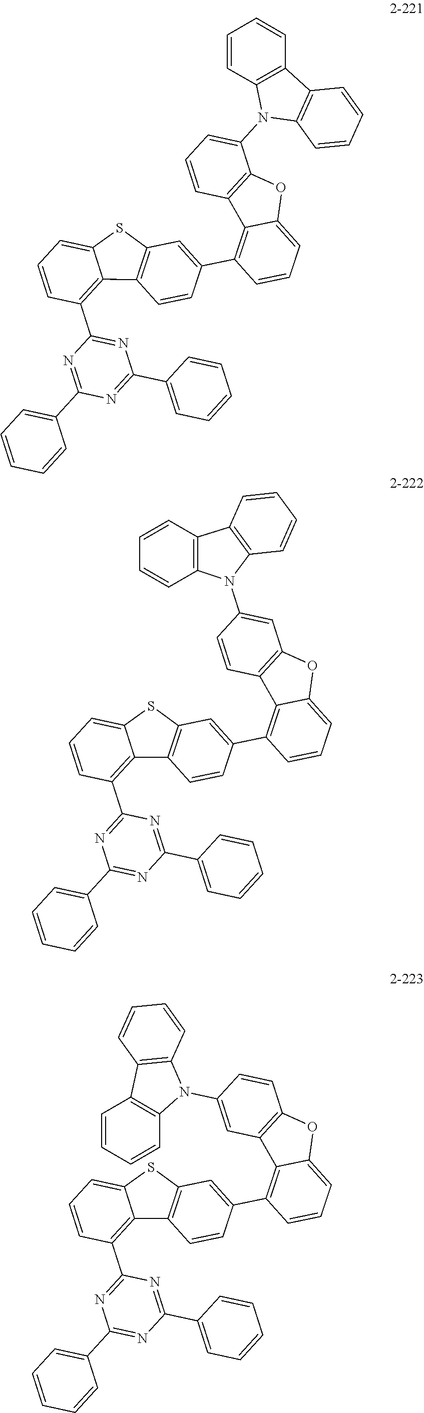 [SMILES: c1ccc(-c2nc(-c3ccccc3)nc(-c3cccc4sc5cc(-c6cccc7oc8c(-n9c%10ccccc%10c%10ccccc%109)cccc8c67)ccc5c34)n2)cc1 ; c1ccc(-c2nc(-c3ccccc3)nc(-c3cccc4sc5cc(-c6cccc7oc8cc(-n9c%10ccccc%10c%10ccccc%109)ccc8c67)ccc5c34)n2)cc1 ; c1ccc(-c2nc(-c3ccccc3)nc(-c3cccc4sc5cc(-c6cccc7oc8ccc(-n9c%10ccccc%10c%10ccccc%109)cc8c67)ccc5c34)n2)cc1]

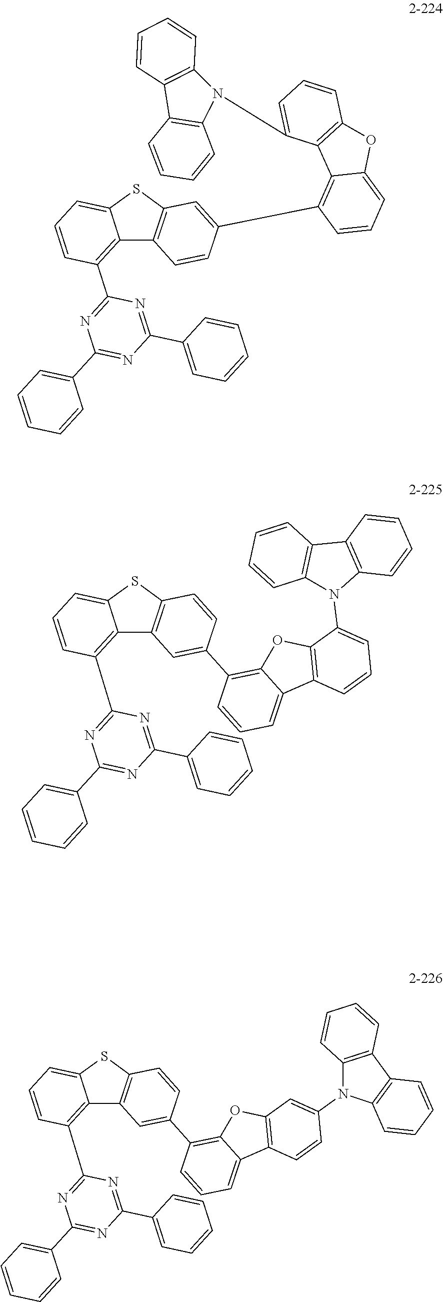 [SMILES: c1ccc(-c2nc(-c3ccccc3)nc(-c3cccc4sc5cc(-c6cccc7oc8cccc(-n9c%10ccccc%10c%10ccccc%109)c8c67)ccc5c34)n2)cc1 ; c1ccc(-c2nc(-c3ccccc3)nc(-c3cccc4sc5ccc(-c6cccc7c6oc6c(-n8c9ccccc9c9ccccc98)cccc67)cc5c34)n2)cc1 ; c1ccc(-c2nc(-c3ccccc3)nc(-c3cccc4sc5ccc(-c6cccc7c6oc6cc(-n8c9ccccc9c9ccccc98)ccc67)cc5c34)n2)cc1]

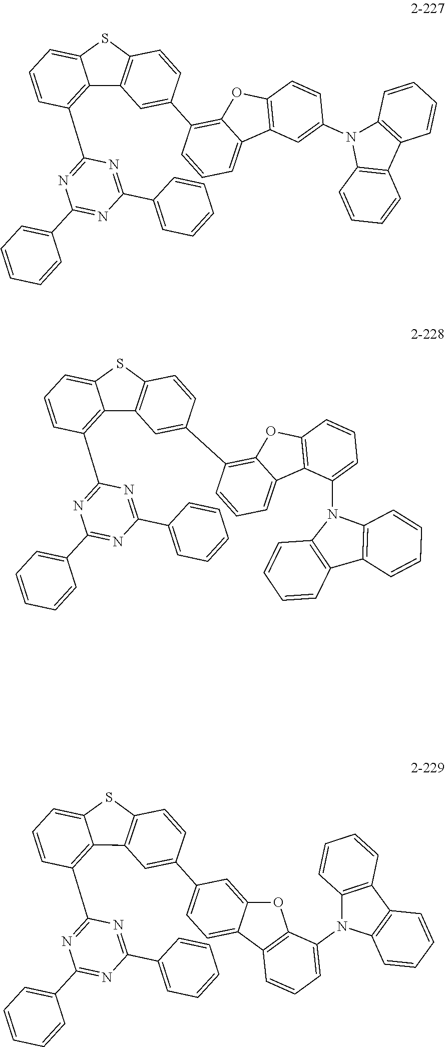 [SMILES: c1ccc(-c2nc(-c3ccccc3)nc(-c3cccc4sc5ccc(-c6cccc7c6oc6ccc(-n8c9ccccc9c9ccccc98)cc67)cc5c34)n2)cc1 ; c1ccc(-c2nc(-c3ccccc3)nc(-c3cccc4sc5ccc(-c6cccc7c6oc6cccc(-n8c9ccccc9c9ccccc98)c67)cc5c34)n2)cc1 ; c1ccc(-c2nc(-c3ccccc3)nc(-c3cccc4sc5ccc(-c6ccc7c(c6)oc6c(-n8c9ccccc9c9ccccc98)cccc67)cc5c34)n2)cc1]

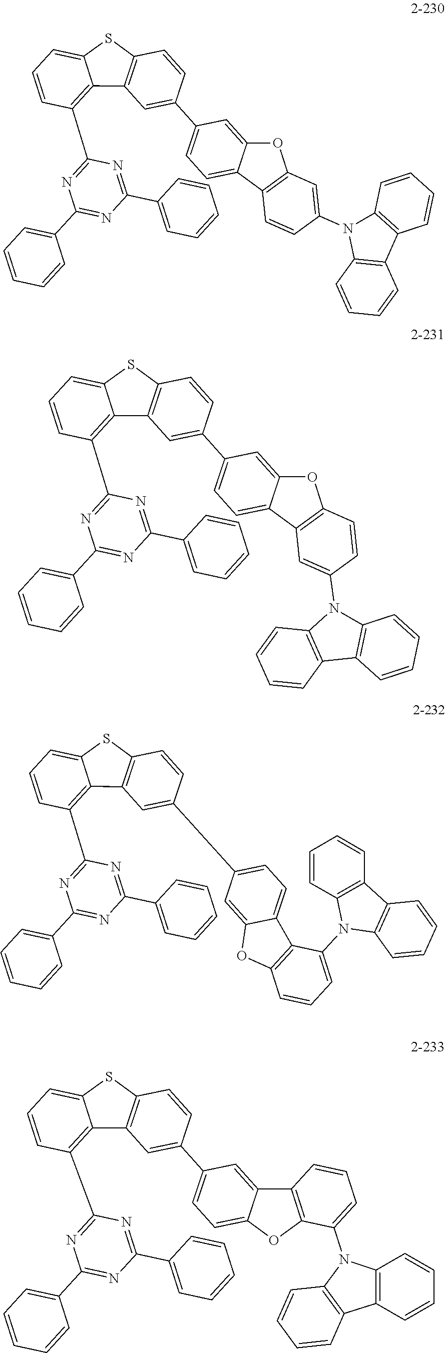 [SMILES: c1ccc(-c2nc(-c3ccccc3)nc(-c3cccc4sc5ccc(-c6ccc7c(c6)oc6cc(-n8c9ccccc9c9ccccc98)ccc67)cc5c34)n2)cc1 ; c1ccc(-c2nc(-c3ccccc3)nc(-c3cccc4sc5ccc(-c6ccc7c(c6)oc6ccc(-n8c9ccccc9c9ccccc98)cc67)cc5c34)n2)cc1 ; c1ccc(-c2nc(-c3ccccc3)nc(-c3cccc4sc5ccc(-c6ccc7c(c6)oc6cccc(-n8c9ccccc9c9ccccc98)c67)cc5c34)n2)cc1 ; c1ccc(-c2nc(-c3ccccc3)nc(-c3cccc4sc5ccc(-c6ccc7oc8c(-n9c%10ccccc%10c%10ccccc%109)cccc8c7c6)cc5c34)n2)cc1]

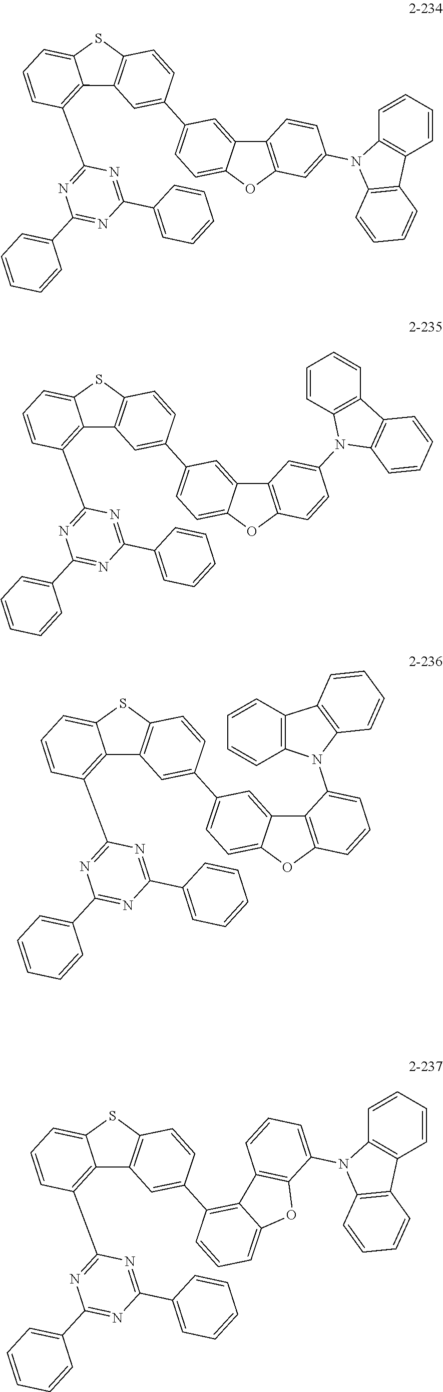 [SMILES: c1ccc(-c2nc(-c3ccccc3)nc(-c3cccc4sc5ccc(-c6ccc7oc8cc(-n9c%10ccccc%10c%10ccccc%109)ccc8c7c6)cc5c34)n2)cc1 ; c1ccc(-c2nc(-c3ccccc3)nc(-c3cccc4sc5ccc(-c6ccc7oc8ccc(-n9c%10ccccc%10c%10ccccc%109)cc8c7c6)cc5c34)n2)cc1 ; c1ccc(-c2nc(-c3ccccc3)nc(-c3cccc4sc5ccc(-c6ccc7oc8cccc(-n9c%10ccccc%10c%10ccccc%109)c8c7c6)cc5c34)n2)cc1 ; c1ccc(-c2nc(-c3ccccc3)nc(-c3cccc4sc5ccc(-c6cccc7oc8c(-n9c%10ccccc%10c%10ccccc%109)cccc8c67)cc5c34)n2)cc1]

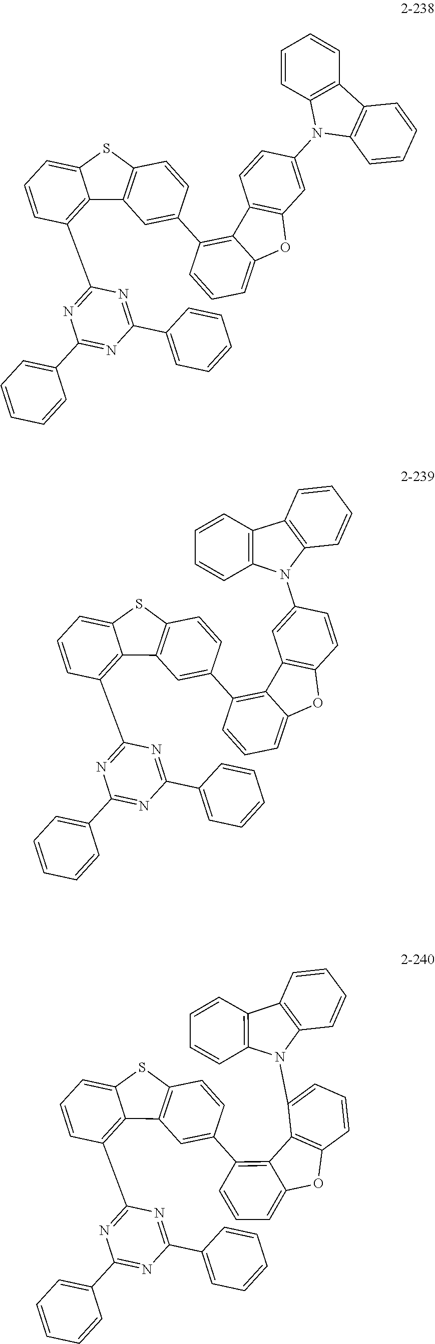 [SMILES: c1ccc(-c2nc(-c3ccccc3)nc(-c3cccc4sc5ccc(-c6cccc7oc8cc(-n9c%10ccccc%10c%10ccccc%109)ccc8c67)cc5c34)n2)cc1 ; c1ccc(-c2nc(-c3ccccc3)nc(-c3cccc4sc5ccc(-c6cccc7oc8ccc(-n9c%10ccccc%10c%10ccccc%109)cc8c67)cc5c34)n2)cc1 ; c1ccc(-c2nc(-c3ccccc3)nc(-c3cccc4sc5ccc(-c6cccc7oc8cccc(-n9c%10ccccc%10c%10ccccc%109)c8c67)cc5c34)n2)cc1]

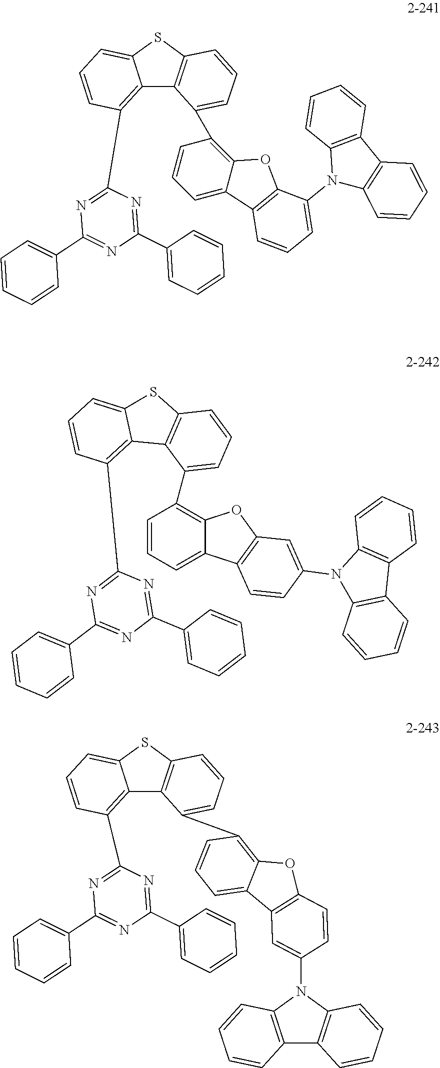 [SMILES: c1ccc(-c2nc(-c3ccccc3)nc(-c3cccc4sc5cccc(-c6cccc7c6oc6c(-n8c9ccccc9c9ccccc98)cccc67)c5c34)n2)cc1 ; c1ccc(-c2nc(-c3ccccc3)nc(-c3cccc4sc5cccc(-c6cccc7c6oc6cc(-n8c9ccccc9c9ccccc98)ccc67)c5c34)n2)cc1 ; c1ccc(-c2nc(-c3ccccc3)nc(-c3cccc4sc5cccc(-c6cccc7c6oc6ccc(-n8c9ccccc9c9ccccc98)cc67)c5c34)n2)cc1]

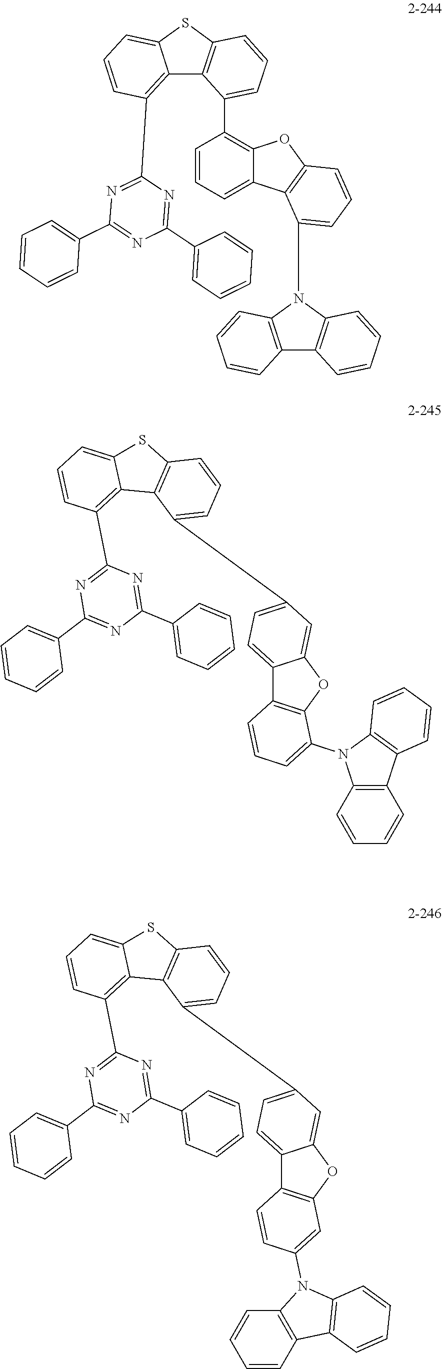 [SMILES: c1ccc(-c2nc(-c3ccccc3)nc(-c3cccc4sc5cccc(-c6cccc7c6oc6cccc(-n8c9ccccc9c9ccccc98)c67)c5c34)n2)cc1 ; c1ccc(-c2nc(-c3ccccc3)nc(-c3cccc4sc5cccc(-c6ccc7c(c6)oc6c(-n8c9ccccc9c9ccccc98)cccc67)c5c34)n2)cc1 ; c1ccc(-c2nc(-c3ccccc3)nc(-c3cccc4sc5cccc(-c6ccc7c(c6)oc6cc(-n8c9ccccc9c9ccccc98)ccc67)c5c34)n2)cc1]

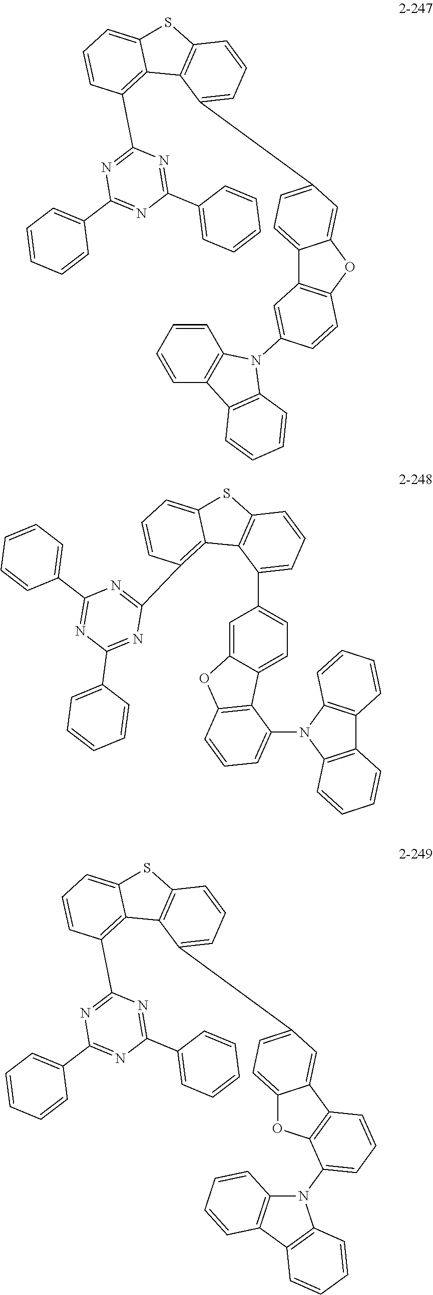

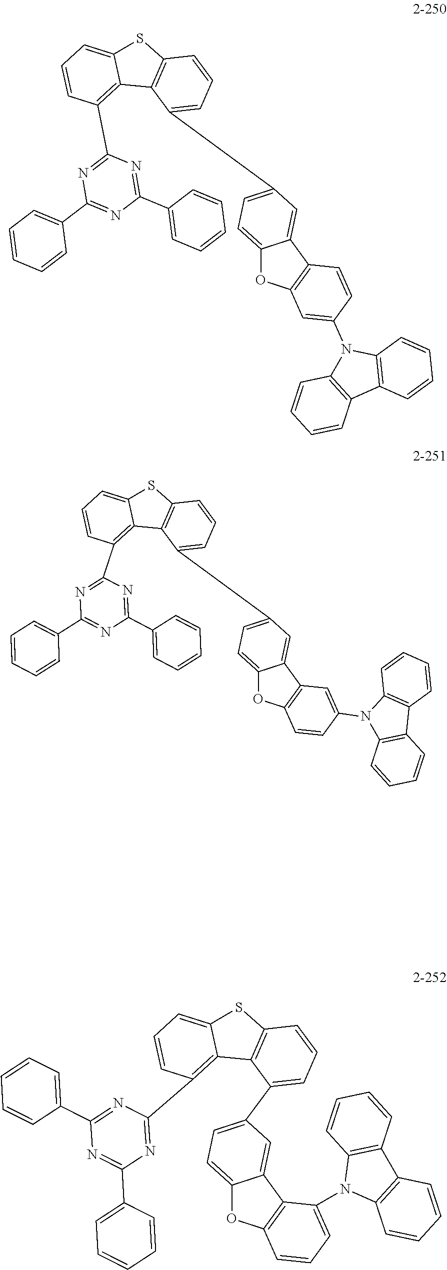 [SMILES: c1ccc(-c2nc(-c3ccccc3)nc(-c3cccc4sc5cccc(-c6ccc7oc8cc(-n9c%10ccccc%10c%10ccccc%109)ccc8c7c6)c5c34)n2)cc1 ; c1ccc(-c2nc(-c3ccccc3)nc(-c3cccc4sc5cccc(-c6ccc7oc8ccc(-n9c%10ccccc%10c%10ccccc%109)cc8c7c6)c5c34)n2)cc1 ; c1ccc(-c2nc(-c3ccccc3)nc(-c3cccc4sc5cccc(-c6ccc7oc8cccc(-n9c%10ccccc%10c%10ccccc%109)c8c7c6)c5c34)n2)cc1]

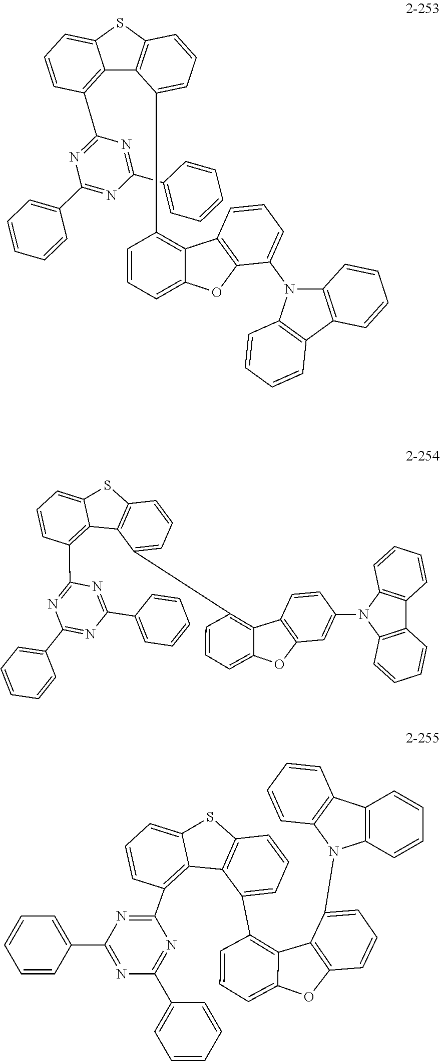 [SMILES: c1ccc(-c2nc(-c3ccccc3)nc(-c3cccc4sc5cccc(-c6cccc7oc8c(-n9c%10ccccc%10c%10ccccc%109)cccc8c67)c5c34)n2)cc1 ; c1ccc(-c2nc(-c3ccccc3)nc(-c3cccc4sc5cccc(-c6cccc7oc8cc(-n9c%10ccccc%10c%10ccccc%109)ccc8c67)c5c34)n2)cc1 ; c1ccc(-c2nc(-c3ccccc3)nc(-c3cccc4sc5cccc(-c6cccc7oc8cccc(-n9c%10ccccc%10c%10ccccc%109)c8c67)c5c34)n2)cc1]

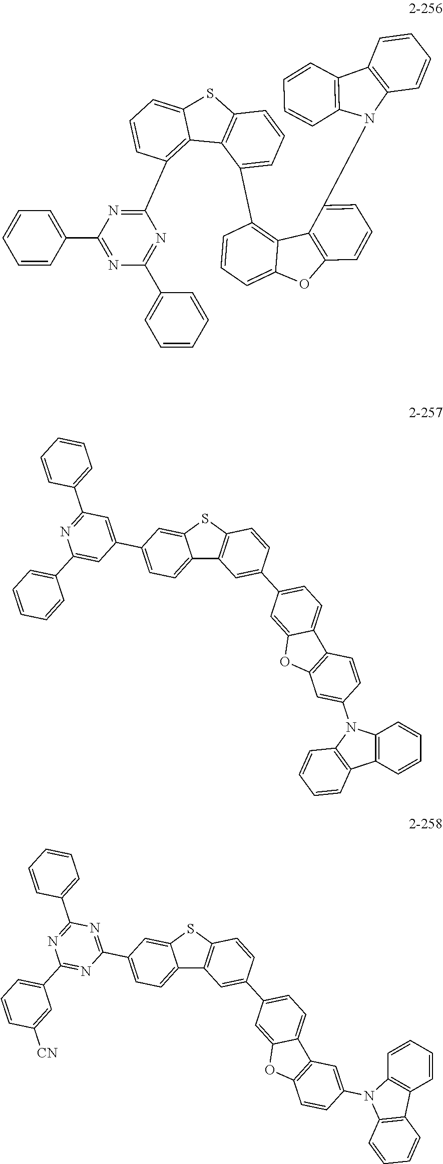 [SMILES: c1ccc(-c2nc(-c3ccccc3)nc(-c3cccc4sc5cccc(-c6cccc7oc8cccc(-n9c%10ccccc%10c%10ccccc%109)c8c67)c5c34)n2)cc1 ; c1ccc(-c2cc(-c3ccc4c(c3)sc3ccc(-c5ccc6c(c5)oc5cc(-n7c8ccccc8c8ccccc87)ccc56)cc34)cc(-c3ccccc3)n2)cc1 ; N#Cc1cccc(-c2nc(-c3ccccc3)nc(-c3ccc4c(c3)sc3ccc(-c5ccc6c(c5)oc5ccc(-n7c8ccccc8c8ccccc87)cc56)cc34)n2)c1]

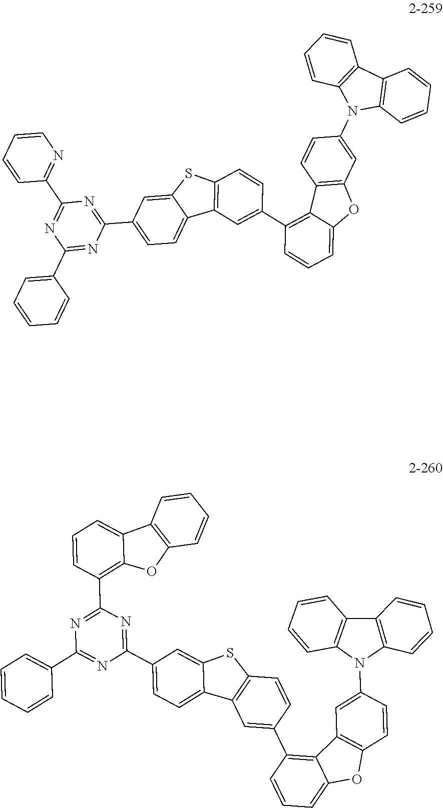 [SMILES: c1ccc(-c2nc(-c3ccc4c(c3)sc3ccc(-c5cccc6oc7cc(-n8c9ccccc9c9ccccc98)ccc7c56)cc34)nc(-c3ccccn3)n2)cc1 ; c1ccc(-c2nc(-c3ccc4c(c3)sc3ccc(-c5cccc6oc7ccc(-n8c9ccccc9c9ccccc98)cc7c56)cc34)nc(-c3cccc4c3oc3ccccc34)n2)cc1]

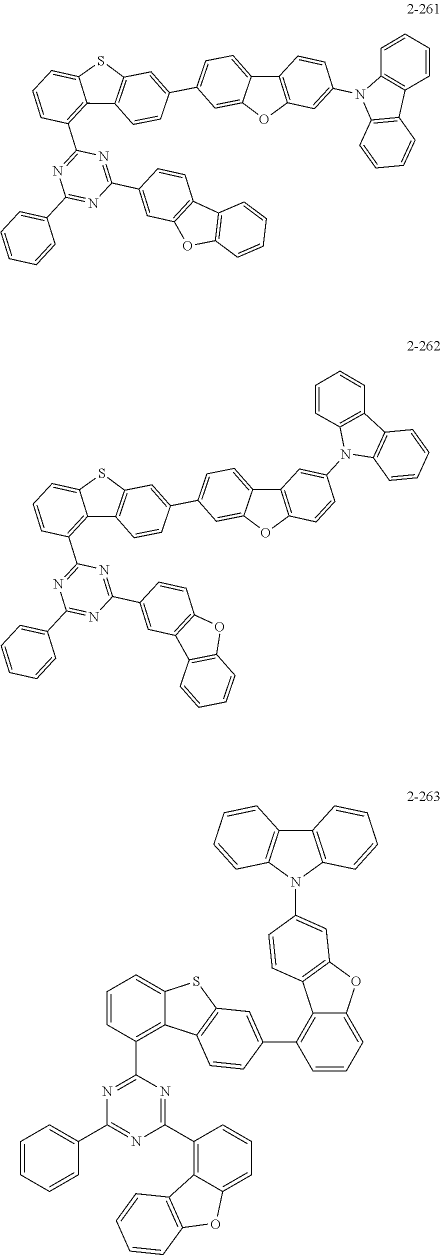 [SMILES: c1ccc(-c2nc(-c3ccc4c(c3)oc3ccccc34)nc(-c3cccc4sc5cc(-c6ccc7c(c6)oc6cc(-n8c9ccccc9c9ccccc98)ccc67)ccc5c34)n2)cc1 ; c1ccc(-c2nc(-c3ccc4oc5ccccc5c4c3)nc(-c3cccc4sc5cc(-c6ccc7c(c6)oc6ccc(-n8c9ccccc9c9ccccc98)cc67)ccc5c34)n2)cc1 ; c1ccc(-c2nc(-c3cccc4oc5ccccc5c34)nc(-c3cccc4sc5cc(-c6cccc7oc8cc(-n9c%10ccccc%10c%10ccccc%109)ccc8c67)ccc5c34)n2)cc1]

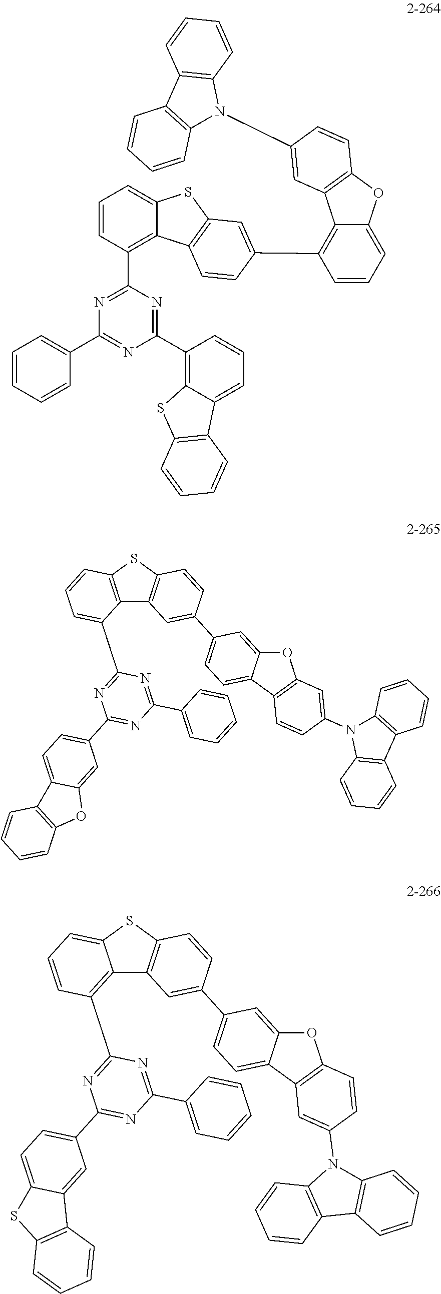 [SMILES: c1ccc(-c2nc(-c3cccc4c3sc3ccccc34)nc(-c3cccc4sc5cc(-c6cccc7oc8ccc(-n9c%10ccccc%10c%10ccccc%109)cc8c67)ccc5c34)n2)cc1 ; c1ccc(-c2nc(-c3ccc4c(c3)oc3ccccc34)nc(-c3cccc4sc5ccc(-c6ccc7c(c6)oc6cc(-n8c9ccccc9c9ccccc98)ccc67)cc5c34)n2)cc1 ; c1ccc(-c2nc(-c3ccc4sc5ccccc5c4c3)nc(-c3cccc4sc5ccc(-c6ccc7c(c6)oc6ccc(-n8c9ccccc9c9ccccc98)cc67)cc5c34)n2)cc1]

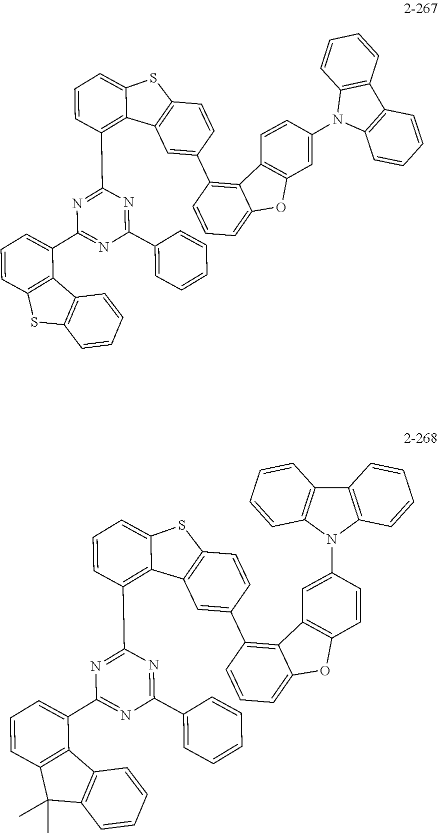 [SMILES: c1ccc(-c2nc(-c3cccc4sc5ccccc5c34)nc(-c3cccc4sc5ccc(-c6cccc7oc8cc(-n9c%10ccccc%10c%10ccccc%109)ccc8c67)cc5c34)n2)cc1 ; CC1(C)c2ccccc2-c2c(-c3nc(-c4ccccc4)nc(-c4cccc5sc6ccc(-c7cccc8oc9ccc(-n%10c%11ccccc%11c%11ccccc%11%10)cc9c78)cc6c45)n3)cccc21]

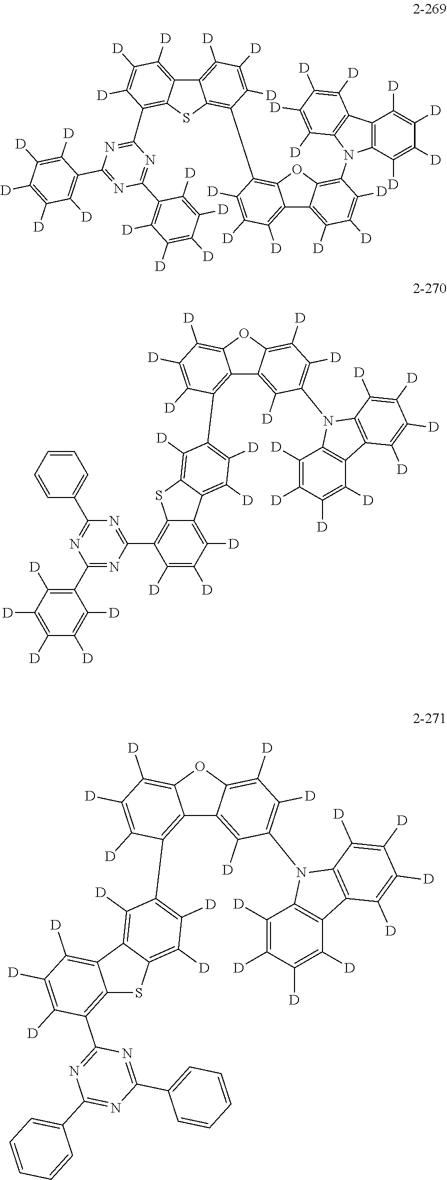

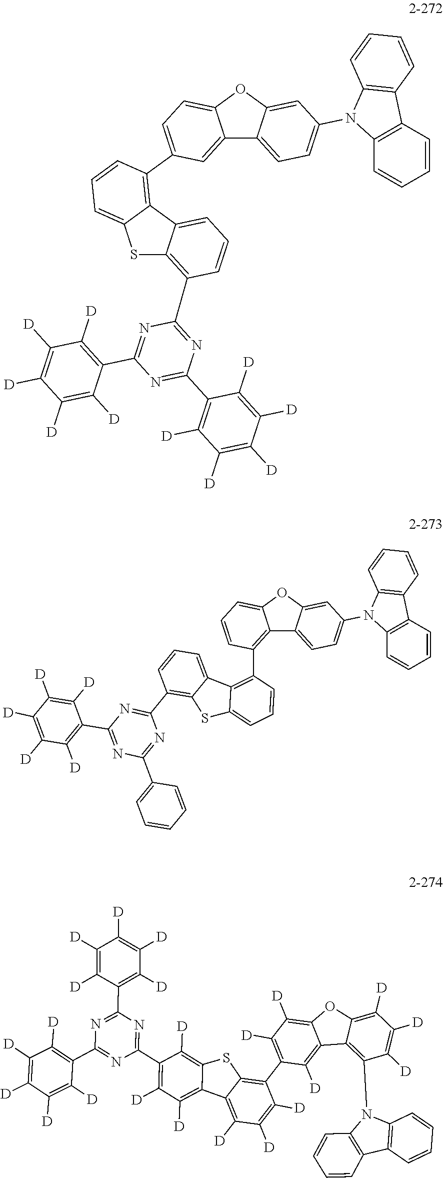

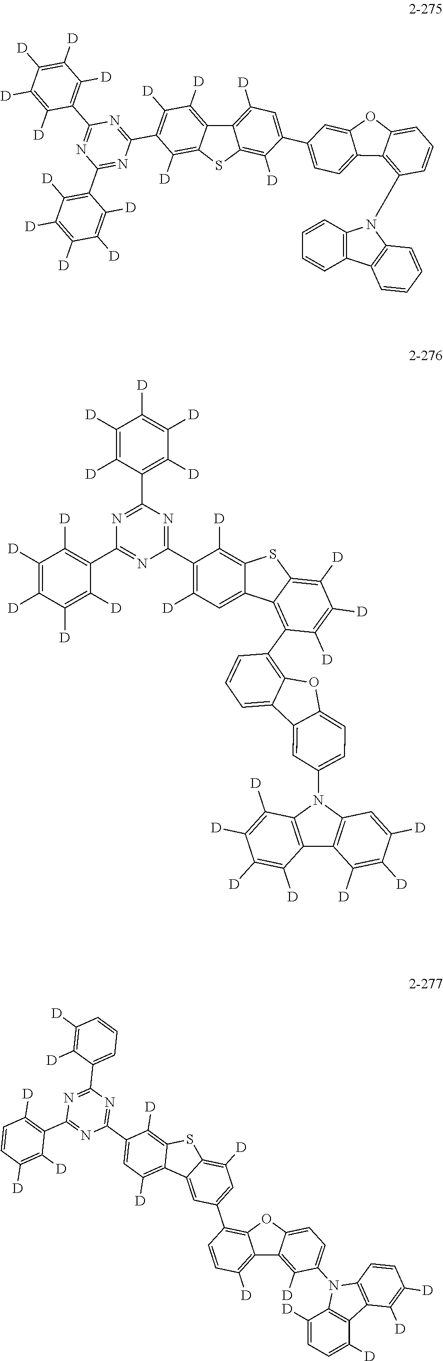

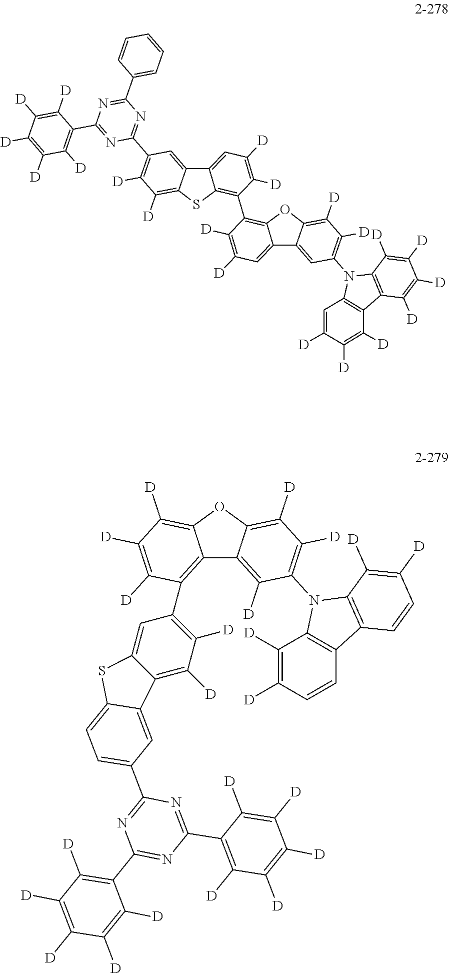 [SMILES: [2H]c1cc2c(oc3c([2H])c([2H])c(-n4c5cc([2H])c([2H])c([2H])c5c5c([2H])c([2H])c([2H])c([2H])c54)cc32)c(-c2c([2H])c([2H])cc3c2sc2c([2H])c([2H])c(-c4nc(-c5ccccc5)nc(-c5c([2H])c([2H])c([2H])c([2H])c5[2H])n4)cc23)c1[2H] ; [2H]c1ccc2c3ccc([2H])c([2H])c3n(-c3c([2H])c([2H])c4oc5c([2H])c([2H])c([2H])c(-c6cc7sc8ccc(-c9nc(-c%10c([2H])c([2H])c([2H])c([2H])c%10[2H])nc(-c%10c([2H])c([2H])c([2H])c([2H])c%10[2H])n9)cc8c7c([2H])c6[2H])c5c4c3[2H])c2c1[2H]]

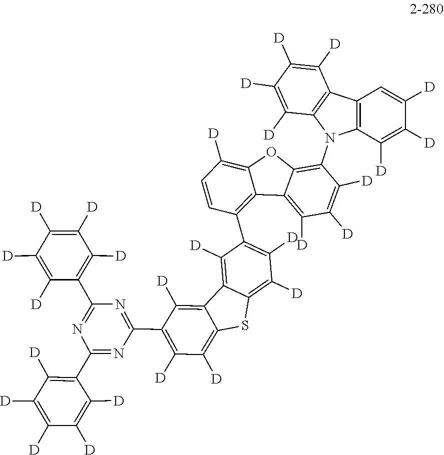 [SMILES: [2H]c1cc2c3c([2H])c([2H])c([2H])c([2H])c3n(-c3c([2H])c([2H])c([2H])c4c3oc3c([2H])ccc(-c5c([2H])c([2H])c6sc7c([2H])c([2H])c(-c8nc(-c9c([2H])c([2H])c([2H])c([2H])c9[2H])nc(-c9c([2H])c([2H])c([2H])c([2H])c9[2H])n8)c([2H])c7c6c5[2H])c34)c2c([2H])c1[2H]]

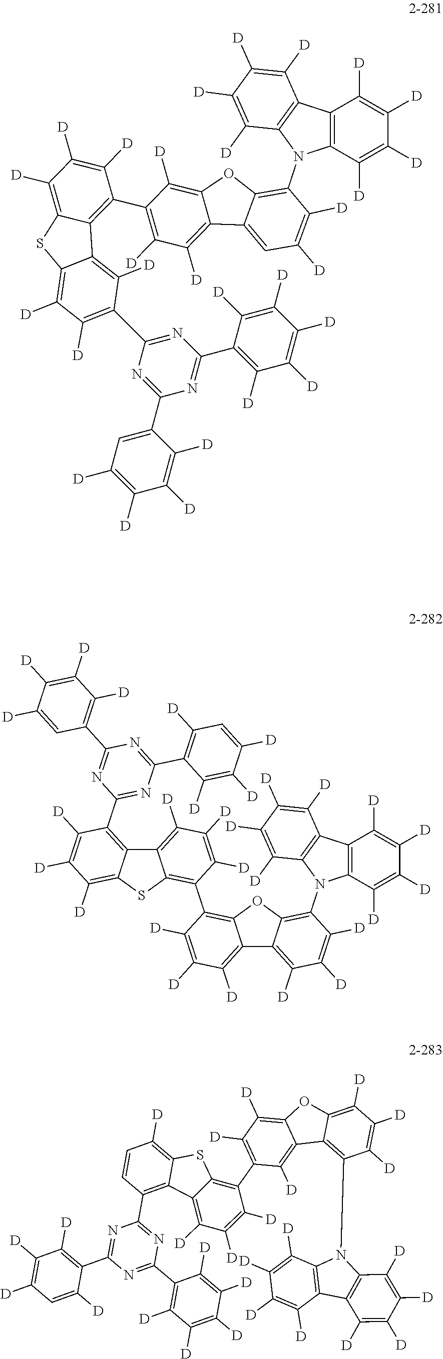

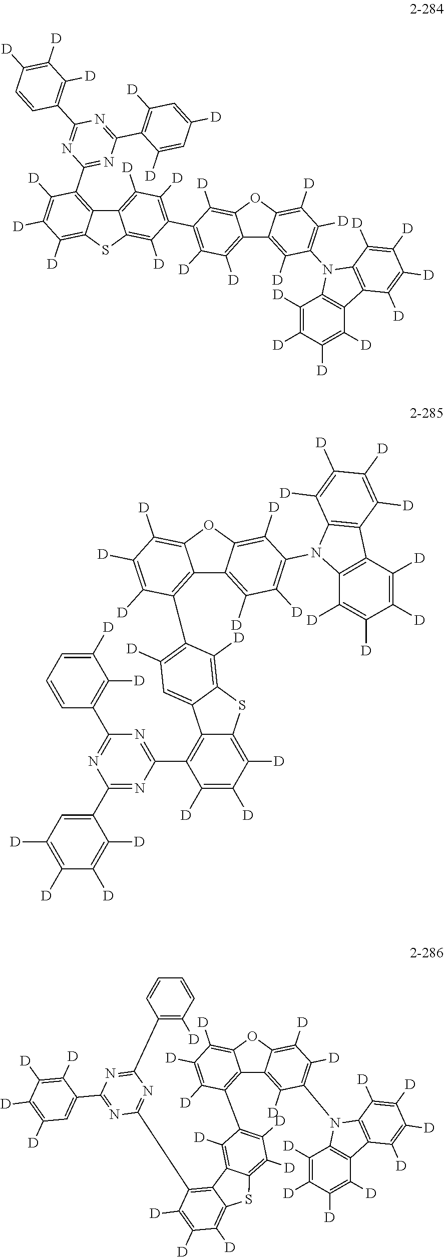

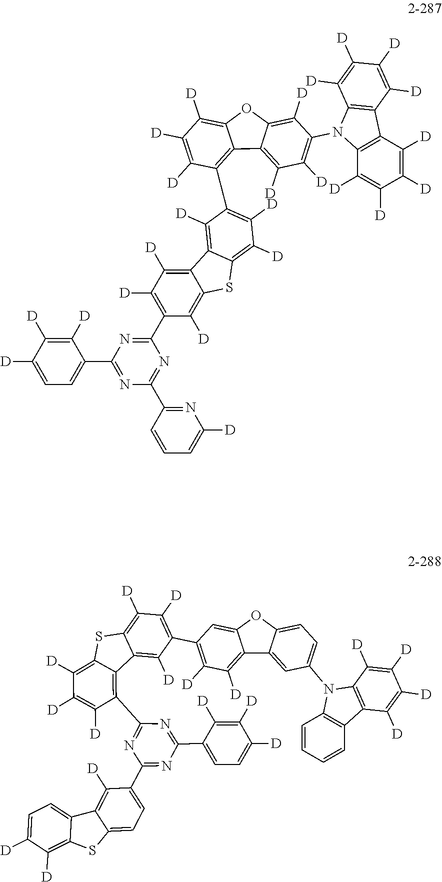 [SMILES: [2H]c1cccc(-c2nc(-c3ccc([2H])c([2H])c3[2H])nc(-c3c([2H])c([2H])c4c(sc5c([2H])c([2H])c(-c6c([2H])c([2H])c([2H])c7oc8c([2H])c(-n9c%10c([2H])c([2H])c([2H])c([2H])c%10c%10c([2H])c([2H])c([2H])c([2H])c%109)c([2H])c([2H])c8c67)c([2H])c54)c3[2H])n2)n1 ; [2H]c1ccc(-c2nc(-c3ccc4sc5c([2H])c([2H])ccc5c4c3[2H])nc(-c3c([2H])c([2H])c([2H])c4sc5c([2H])c([2H])c(-c6cc7oc8ccc(-n9c%10ccccc%10c%10c([2H])c([2H])c([2H])c([2H])c%109)cc8c7c([2H])c6[2H])c([2H])c5c34)n2)c([2H])c1[2H]]

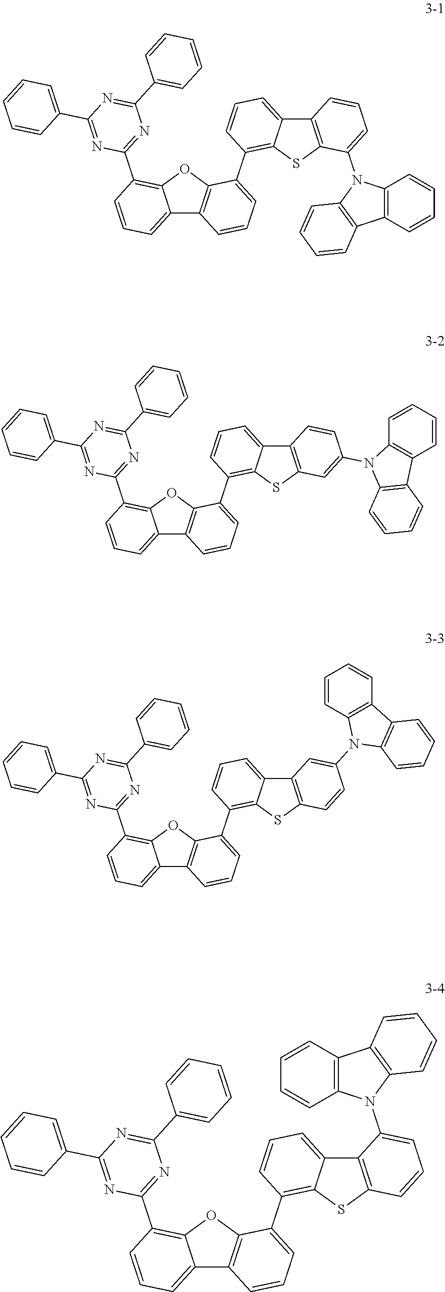 [SMILES: c1ccc(-c2nc(-c3ccccc3)nc(-c3cccc4c3oc3c(-c5cccc6c5sc5c(-n7c8ccccc8c8ccccc87)cccc56)cccc34)n2)cc1 ; c1ccc(-c2nc(-c3ccccc3)nc(-c3cccc4c3oc3c(-c5cccc6c5sc5cc(-n7c8ccccc8c8ccccc87)ccc56)cccc34)n2)cc1 ; c1ccc(-c2nc(-c3ccccc3)nc(-c3cccc4c3oc3c(-c5cccc6c5sc5ccc(-n7c8ccccc8c8ccccc87)cc56)cccc34)n2)cc1 ; c1ccc(-c2nc(-c3ccccc3)nc(-c3cccc4c3oc3c(-c5cccc6c5sc5cccc(-n7c8ccccc8c8ccccc87)c56)cccc34)n2)cc1]

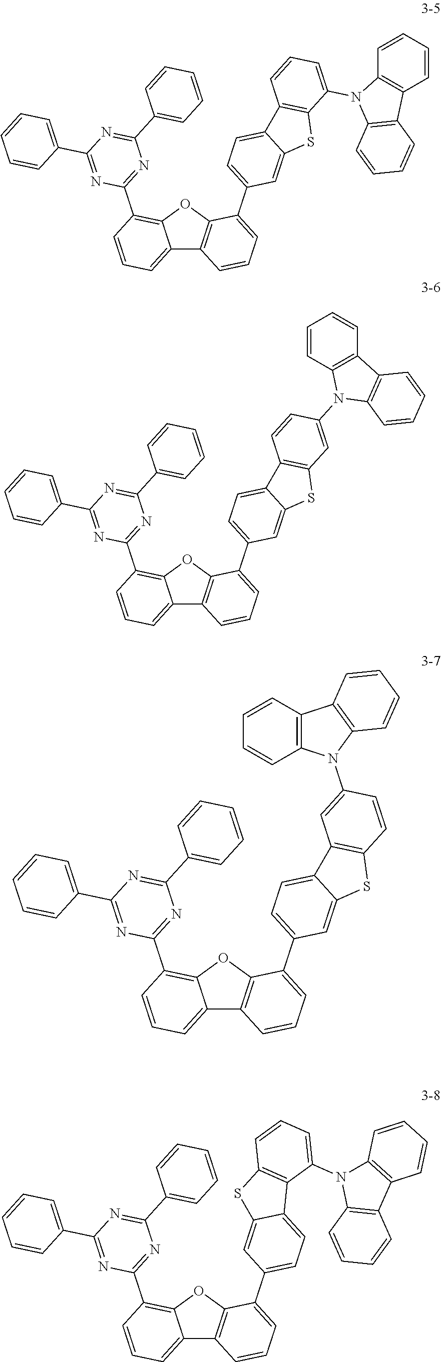 [SMILES: c1ccc(-c2nc(-c3ccccc3)nc(-c3cccc4c3oc3c(-c5ccc6c(c5)sc5c(-n7c8ccccc8c8ccccc87)cccc56)cccc34)n2)cc1 ; c1ccc(-c2nc(-c3ccccc3)nc(-c3cccc4c3oc3c(-c5ccc6c(c5)sc5cc(-n7c8ccccc8c8ccccc87)ccc56)cccc34)n2)cc1 ; c1ccc(-c2nc(-c3ccccc3)nc(-c3cccc4c3oc3c(-c5ccc6c(c5)sc5ccc(-n7c8ccccc8c8ccccc87)cc56)cccc34)n2)cc1 ; c1ccc(-c2nc(-c3ccccc3)nc(-c3cccc4c3oc3c(-c5ccc6c(c5)sc5cccc(-n7c8ccccc8c8ccccc87)c56)cccc34)n2)cc1]

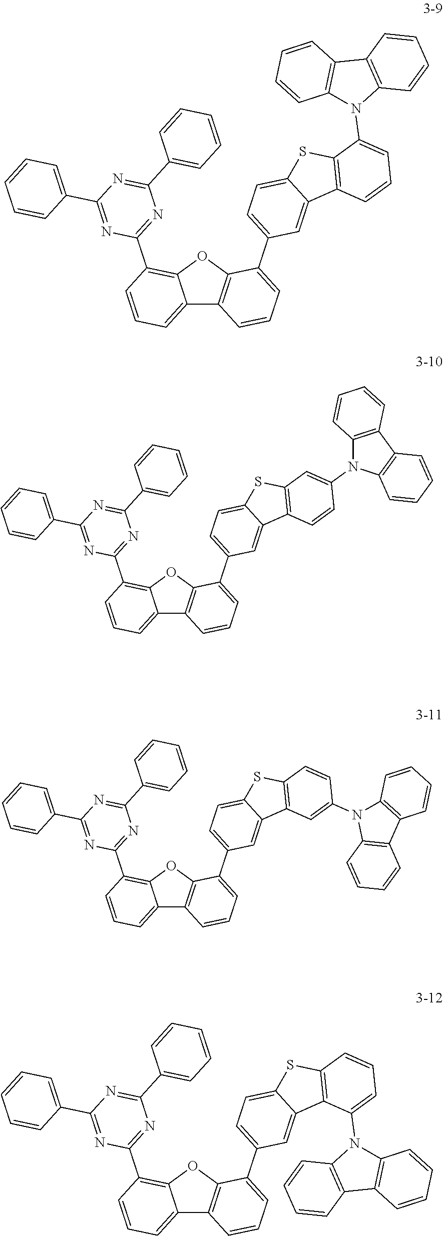 [SMILES: c1ccc(-c2nc(-c3ccccc3)nc(-c3cccc4c3oc3c(-c5ccc6sc7c(-n8c9ccccc9c9ccccc98)cccc7c6c5)cccc34)n2)cc1 ; c1ccc(-c2nc(-c3ccccc3)nc(-c3cccc4c3oc3c(-c5ccc6sc7cc(-n8c9ccccc9c9ccccc98)ccc7c6c5)cccc34)n2)cc1 ; c1ccc(-c2nc(-c3ccccc3)nc(-c3cccc4c3oc3c(-c5ccc6sc7ccc(-n8c9ccccc9c9ccccc98)cc7c6c5)cccc34)n2)cc1 ; c1ccc(-c2nc(-c3ccccc3)nc(-c3cccc4c3oc3c(-c5ccc6sc7cccc(-n8c9ccccc9c9ccccc98)c7c6c5)cccc34)n2)cc1]

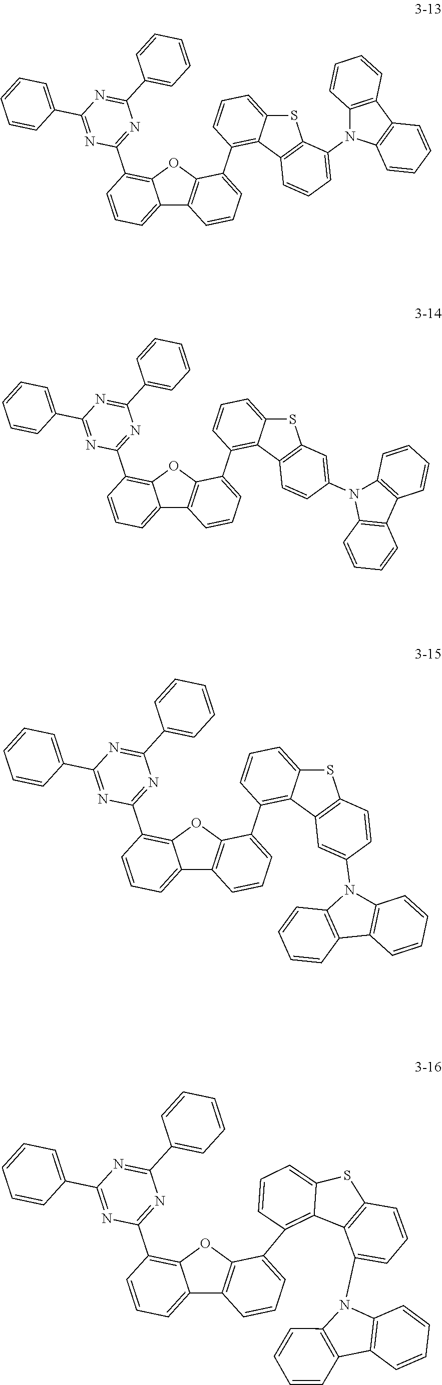 [SMILES: c1ccc(-c2nc(-c3ccccc3)nc(-c3cccc4c3oc3c(-c5cccc6sc7c(-n8c9ccccc9c9ccccc98)cccc7c56)cccc34)n2)cc1 ; c1ccc(-c2nc(-c3ccccc3)nc(-c3cccc4c3oc3c(-c5cccc6sc7cc(-n8c9ccccc9c9ccccc98)ccc7c56)cccc34)n2)cc1 ; c1ccc(-c2nc(-c3ccccc3)nc(-c3cccc4c3oc3c(-c5cccc6sc7ccc(-n8c9ccccc9c9ccccc98)cc7c56)cccc34)n2)cc1 ; c1ccc(-c2nc(-c3ccccc3)nc(-c3cccc4c3oc3c(-c5cccc6sc7cccc(-n8c9ccccc9c9ccccc98)c7c56)cccc34)n2)cc1]

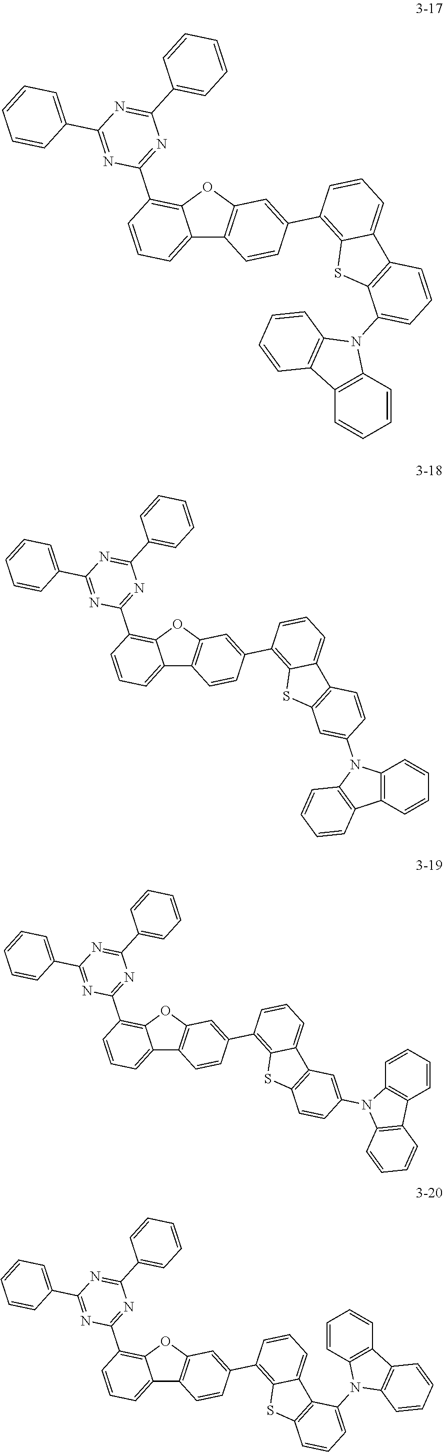 [SMILES: c1ccc(-c2nc(-c3ccccc3)nc(-c3cccc4c3oc3cc(-c5cccc6c5sc5c(-n7c8ccccc8c8ccccc87)cccc56)ccc34)n2)cc1 ; c1ccc(-c2nc(-c3ccccc3)nc(-c3cccc4c3oc3cc(-c5cccc6c5sc5cc(-n7c8ccccc8c8ccccc87)ccc56)ccc34)n2)cc1 ; c1ccc(-c2nc(-c3ccccc3)nc(-c3cccc4c3oc3cc(-c5cccc6c5sc5ccc(-n7c8ccccc8c8ccccc87)cc56)ccc34)n2)cc1 ; c1ccc(-c2nc(-c3ccccc3)nc(-c3cccc4c3oc3cc(-c5cccc6c5sc5cccc(-n7c8ccccc8c8ccccc87)c56)ccc34)n2)cc1]

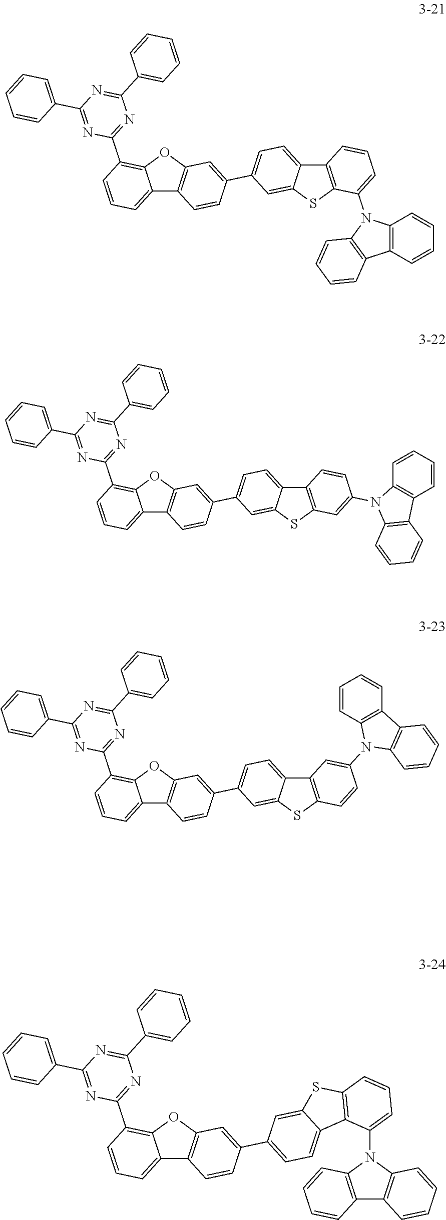 [SMILES: c1ccc(-c2nc(-c3ccccc3)nc(-c3cccc4c3oc3cc(-c5ccc6c(c5)sc5c(-n7c8ccccc8c8ccccc87)cccc56)ccc34)n2)cc1 ; c1ccc(-c2nc(-c3ccccc3)nc(-c3cccc4c3oc3cc(-c5ccc6c(c5)sc5cc(-n7c8ccccc8c8ccccc87)ccc56)ccc34)n2)cc1 ; c1ccc(-c2nc(-c3ccccc3)nc(-c3cccc4c3oc3cc(-c5ccc6c(c5)sc5ccc(-n7c8ccccc8c8ccccc87)cc56)ccc34)n2)cc1 ; c1ccc(-c2nc(-c3ccccc3)nc(-c3cccc4c3oc3cc(-c5ccc6c(c5)sc5cccc(-n7c8ccccc8c8ccccc87)c56)ccc34)n2)cc1]

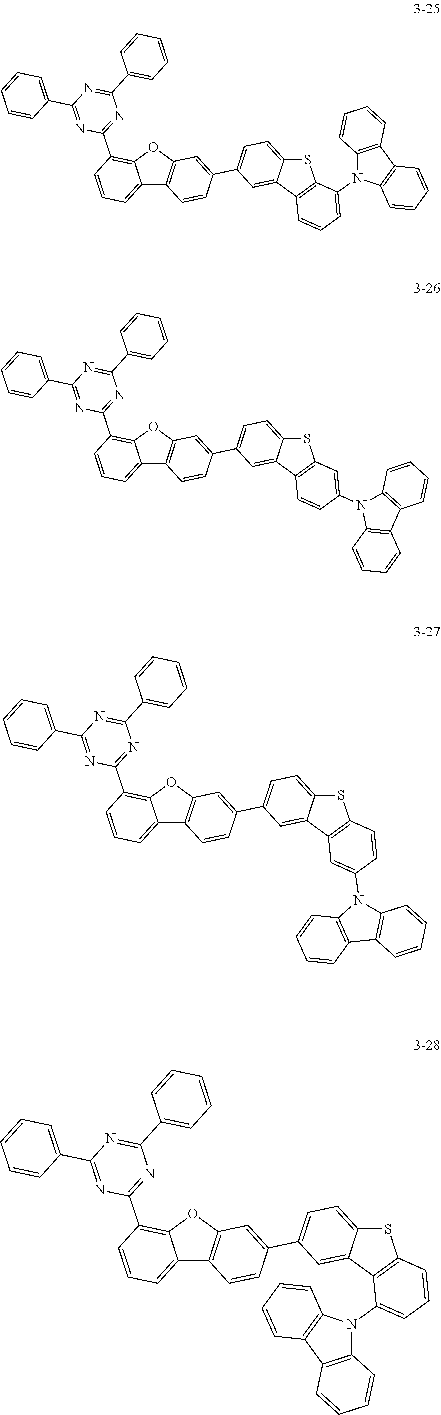 [SMILES: c1ccc(-c2nc(-c3ccccc3)nc(-c3cccc4c3oc3cc(-c5ccc6sc7c(-n8c9ccccc9c9ccccc98)cccc7c6c5)ccc34)n2)cc1 ; c1ccc(-c2nc(-c3ccccc3)nc(-c3cccc4c3oc3cc(-c5ccc6sc7cc(-n8c9ccccc9c9ccccc98)ccc7c6c5)ccc34)n2)cc1 ; c1ccc(-c2nc(-c3ccccc3)nc(-c3cccc4c3oc3cc(-c5ccc6sc7ccc(-n8c9ccccc9c9ccccc98)cc7c6c5)ccc34)n2)cc1 ; c1ccc(-c2nc(-c3ccccc3)nc(-c3cccc4c3oc3cc(-c5ccc6sc7cccc(-n8c9ccccc9c9ccccc98)c7c6c5)ccc34)n2)cc1]

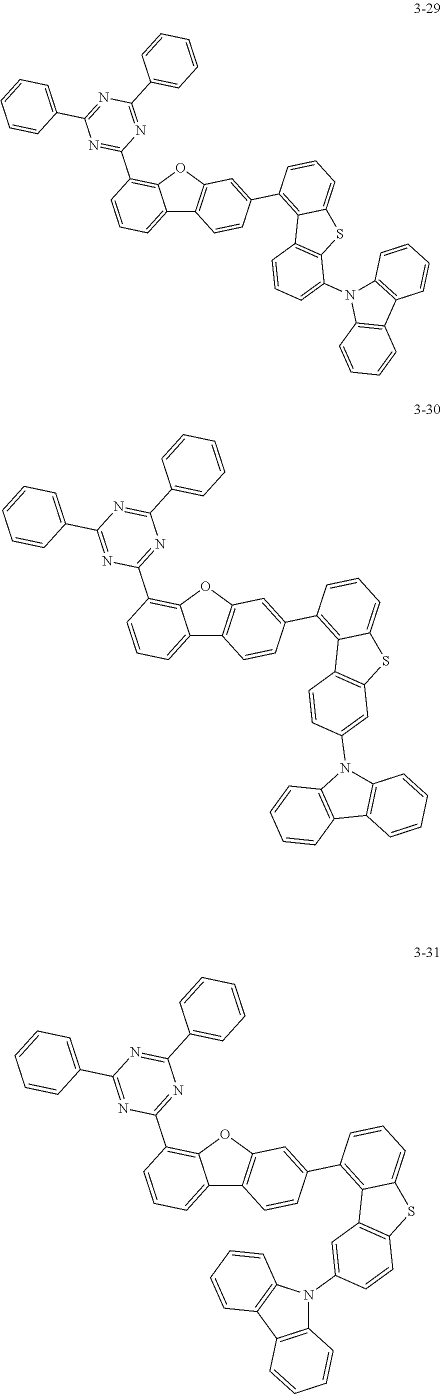 [SMILES: c1ccc(-c2nc(-c3ccccc3)nc(-c3cccc4c3oc3cc(-c5cccc6sc7c(-n8c9ccccc9c9ccccc98)cccc7c56)ccc34)n2)cc1 ; c1ccc(-c2nc(-c3ccccc3)nc(-c3cccc4c3oc3cc(-c5cccc6sc7cc(-n8c9ccccc9c9ccccc98)ccc7c56)ccc34)n2)cc1 ; c1ccc(-c2nc(-c3ccccc3)nc(-c3cccc4c3oc3cc(-c5cccc6sc7ccc(-n8c9ccccc9c9ccccc98)cc7c56)ccc34)n2)cc1]

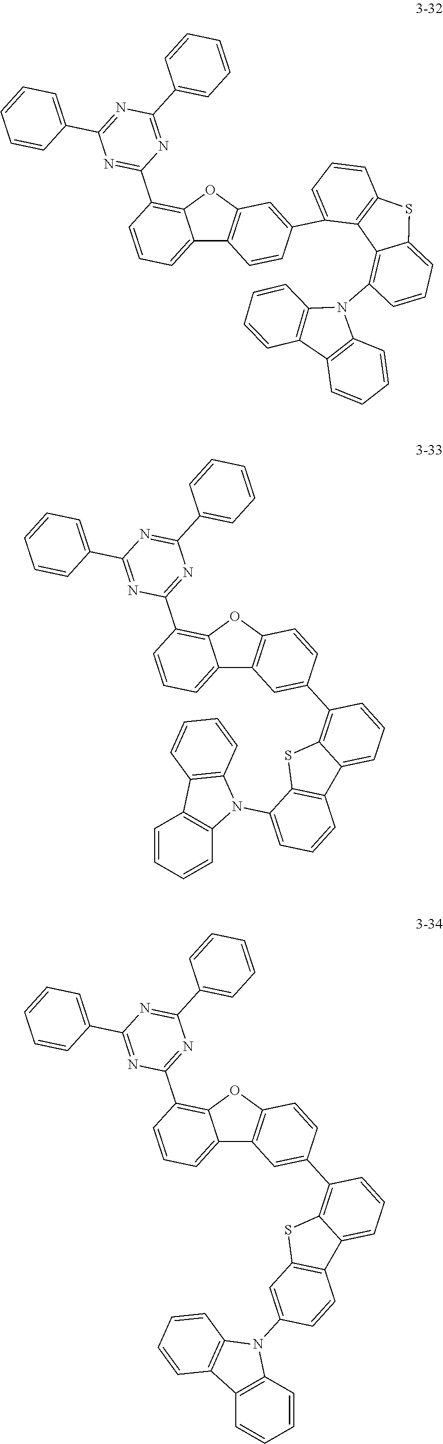 [SMILES: c1ccc(-c2nc(-c3ccccc3)nc(-c3cccc4c3oc3cc(-c5cccc6sc7cccc(-n8c9ccccc9c9ccccc98)c7c56)ccc34)n2)cc1 ; c1ccc(-c2nc(-c3ccccc3)nc(-c3cccc4c3oc3ccc(-c5cccc6c5sc5c(-n7c8ccccc8c8ccccc87)cccc56)cc34)n2)cc1 ; c1ccc(-c2nc(-c3ccccc3)nc(-c3cccc4c3oc3ccc(-c5cccc6c5sc5cc(-n7c8ccccc8c8ccccc87)ccc56)cc34)n2)cc1]

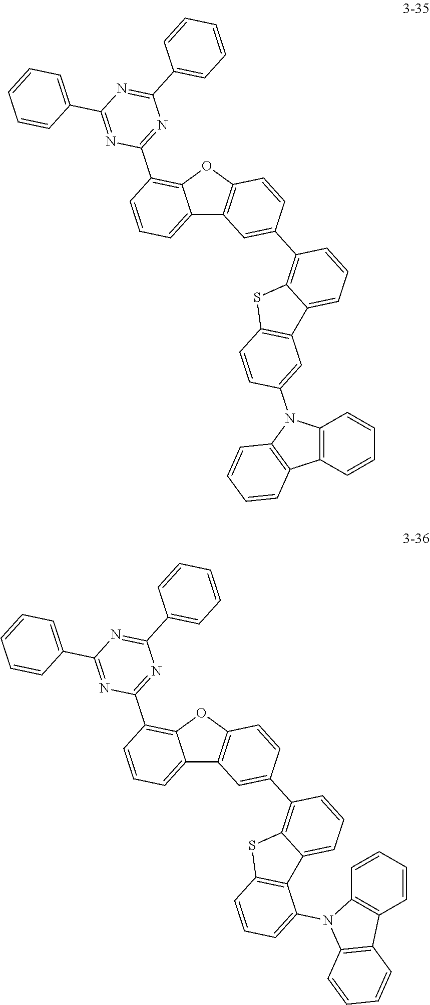 [SMILES: c1ccc(-c2nc(-c3ccccc3)nc(-c3cccc4c3oc3ccc(-c5cccc6c5sc5ccc(-n7c8ccccc8c8ccccc87)cc56)cc34)n2)cc1 ; c1ccc(-c2nc(-c3ccccc3)nc(-c3cccc4c3oc3ccc(-c5cccc6c5sc5cccc(-n7c8ccccc8c8ccccc87)c56)cc34)n2)cc1]

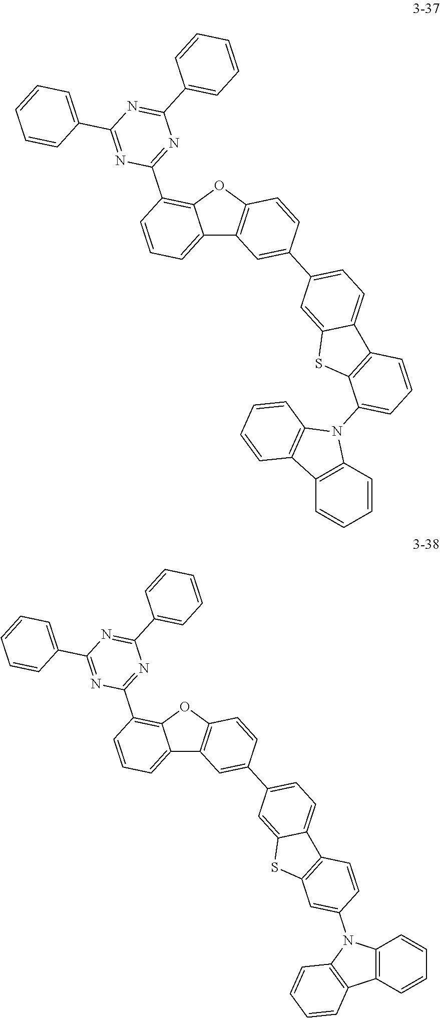 [SMILES: c1ccc(-c2nc(-c3ccccc3)nc(-c3cccc4c3oc3ccc(-c5ccc6c(c5)sc5c(-n7c8ccccc8c8ccccc87)cccc56)cc34)n2)cc1 ; c1ccc(-c2nc(-c3ccccc3)nc(-c3cccc4c3oc3ccc(-c5ccc6c(c5)sc5cc(-n7c8ccccc8c8ccccc87)ccc56)cc34)n2)cc1]

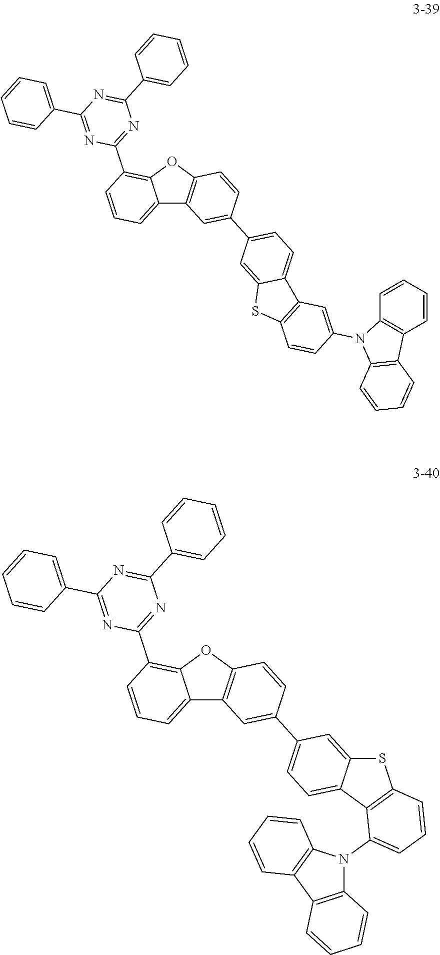 [SMILES: c1ccc(-c2nc(-c3ccccc3)nc(-c3cccc4c3oc3ccc(-c5ccc6c(c5)sc5ccc(-n7c8ccccc8c8ccccc87)cc56)cc34)n2)cc1 ; c1ccc(-c2nc(-c3ccccc3)nc(-c3cccc4c3oc3ccc(-c5ccc6c(c5)sc5cccc(-n7c8ccccc8c8ccccc87)c56)cc34)n2)cc1]

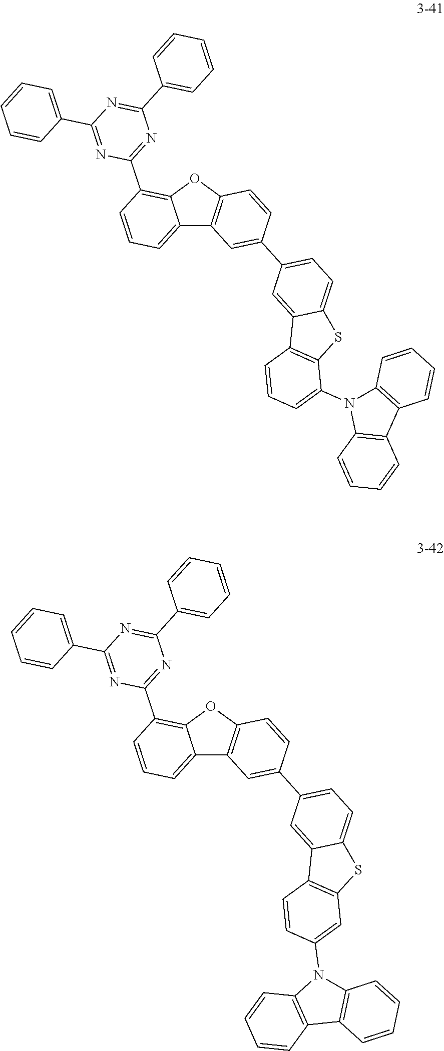 [SMILES: c1ccc(-c2nc(-c3ccccc3)nc(-c3cccc4c3oc3ccc(-c5ccc6sc7c(-n8c9ccccc9c9ccccc98)cccc7c6c5)cc34)n2)cc1 ; c1ccc(-c2nc(-c3ccccc3)nc(-c3cccc4c3oc3ccc(-c5ccc6sc7cc(-n8c9ccccc9c9ccccc98)ccc7c6c5)cc34)n2)cc1]

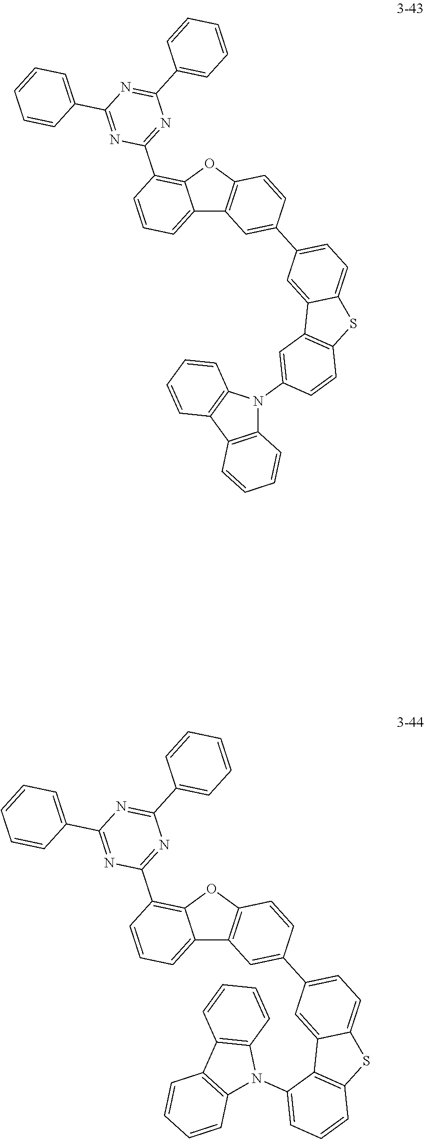 [SMILES: c1ccc(-c2nc(-c3ccccc3)nc(-c3cccc4c3oc3ccc(-c5ccc6sc7ccc(-n8c9ccccc9c9ccccc98)cc7c6c5)cc34)n2)cc1 ; c1ccc(-c2nc(-c3ccccc3)nc(-c3cccc4c3oc3ccc(-c5ccc6sc7cccc(-n8c9ccccc9c9ccccc98)c7c6c5)cc34)n2)cc1]

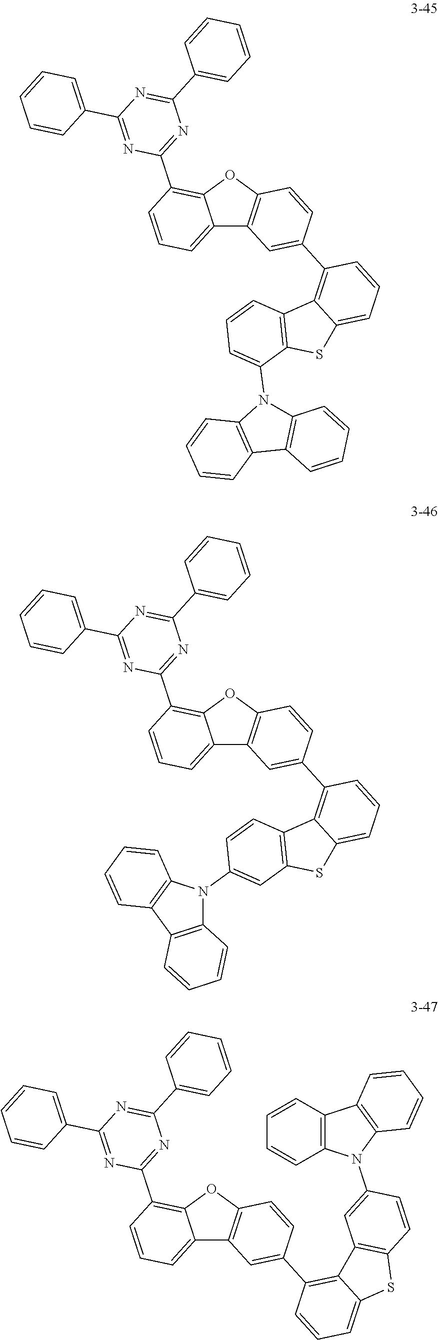

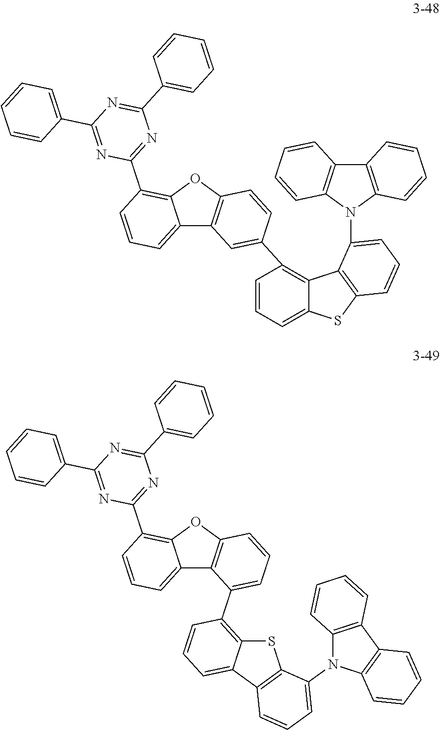 [SMILES: c1ccc(-c2nc(-c3ccccc3)nc(-c3cccc4c3oc3ccc(-c5cccc6sc7cccc(-n8c9ccccc9c9ccccc98)c7c56)cc34)n2)cc1 ; c1ccc(-c2nc(-c3ccccc3)nc(-c3cccc4c3oc3cccc(-c5cccc6c5sc5c(-n7c8ccccc8c8ccccc87)cccc56)c34)n2)cc1]

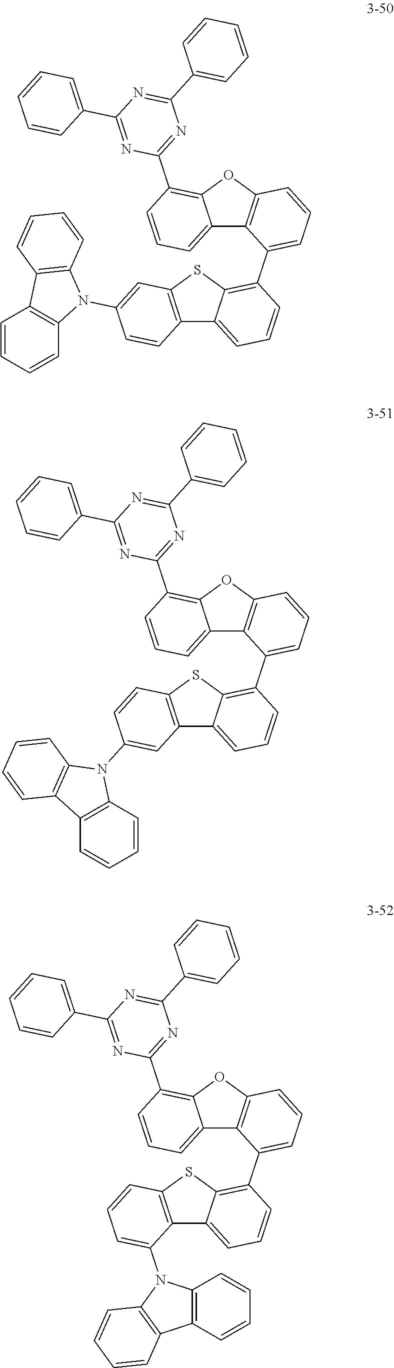 [SMILES: c1ccc(-c2nc(-c3ccccc3)nc(-c3cccc4c3oc3cccc(-c5cccc6c5sc5cc(-n7c8ccccc8c8ccccc87)ccc56)c34)n2)cc1 ; c1ccc(-c2nc(-c3ccccc3)nc(-c3cccc4c3oc3cccc(-c5cccc6c5sc5ccc(-n7c8ccccc8c8ccccc87)cc56)c34)n2)cc1 ; c1ccc(-c2nc(-c3ccccc3)nc(-c3cccc4c3oc3cccc(-c5cccc6c5sc5cccc(-n7c8ccccc8c8ccccc87)c56)c34)n2)cc1]

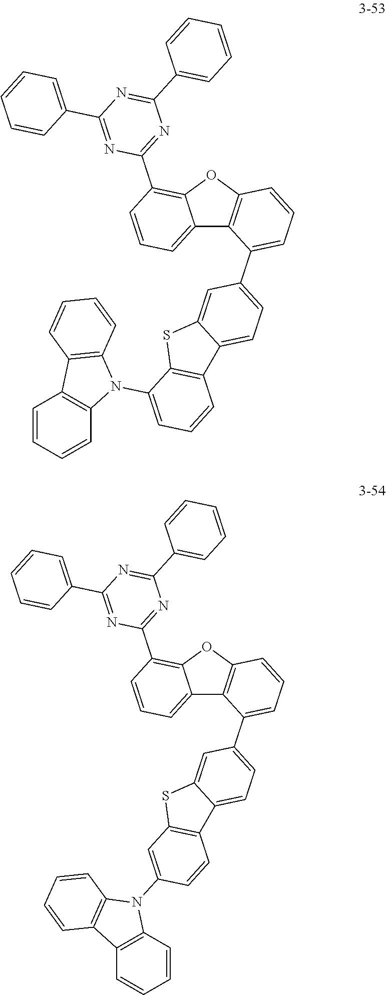 [SMILES: c1ccc(-c2nc(-c3ccccc3)nc(-c3cccc4c3oc3cccc(-c5ccc6c(c5)sc5c(-n7c8ccccc8c8ccccc87)cccc56)c34)n2)cc1 ; c1ccc(-c2nc(-c3ccccc3)nc(-c3cccc4c3oc3cccc(-c5ccc6c(c5)sc5cc(-n7c8ccccc8c8ccccc87)ccc56)c34)n2)cc1]

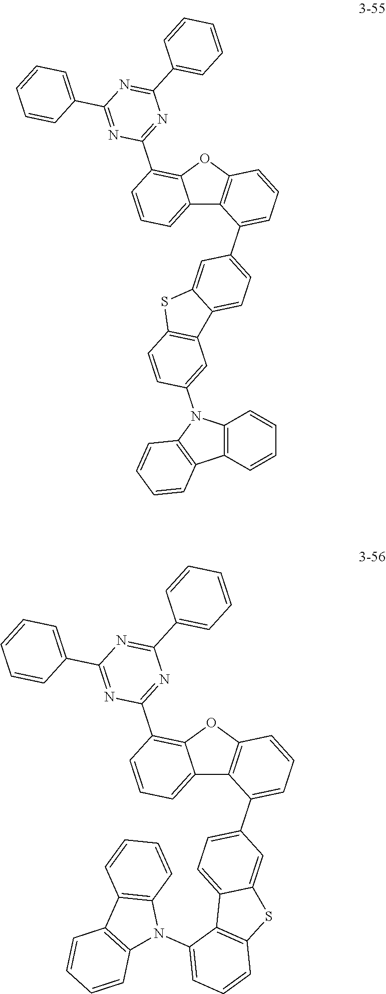 [SMILES: c1ccc(-c2nc(-c3ccccc3)nc(-c3cccc4c3oc3cccc(-c5ccc6c(c5)sc5ccc(-n7c8ccccc8c8ccccc87)cc56)c34)n2)cc1 ; c1ccc(-c2nc(-c3ccccc3)nc(-c3cccc4c3oc3cccc(-c5ccc6c(c5)sc5cccc(-n7c8ccccc8c8ccccc87)c56)c34)n2)cc1]

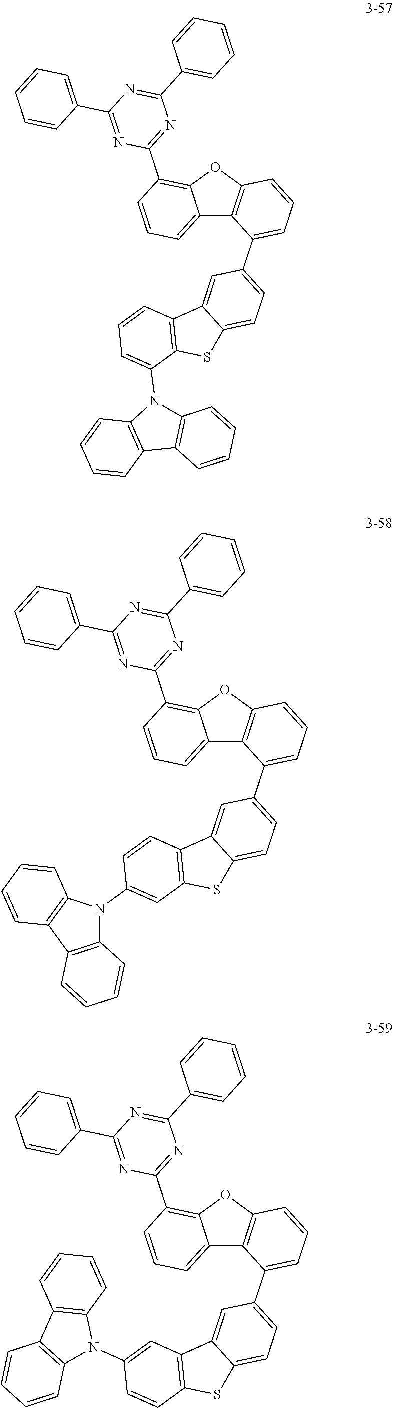 [SMILES: c1ccc(-c2nc(-c3ccccc3)nc(-c3cccc4c3oc3cccc(-c5ccc6sc7c(-n8c9ccccc9c9ccccc98)cccc7c6c5)c34)n2)cc1 ; c1ccc(-c2nc(-c3ccccc3)nc(-c3cccc4c3oc3cccc(-c5ccc6sc7cc(-n8c9ccccc9c9ccccc98)ccc7c6c5)c34)n2)cc1 ; c1ccc(-c2nc(-c3ccccc3)nc(-c3cccc4c3oc3cccc(-c5ccc6sc7ccc(-n8c9ccccc9c9ccccc98)cc7c6c5)c34)n2)cc1]

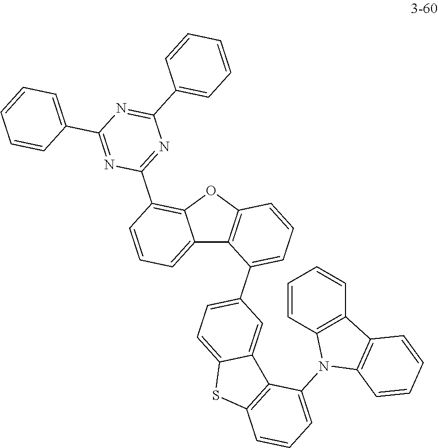 [SMILES: c1ccc(-c2nc(-c3ccccc3)nc(-c3cccc4c3oc3cccc(-c5ccc6sc7cccc(-n8c9ccccc9c9ccccc98)c7c6c5)c34)n2)cc1]

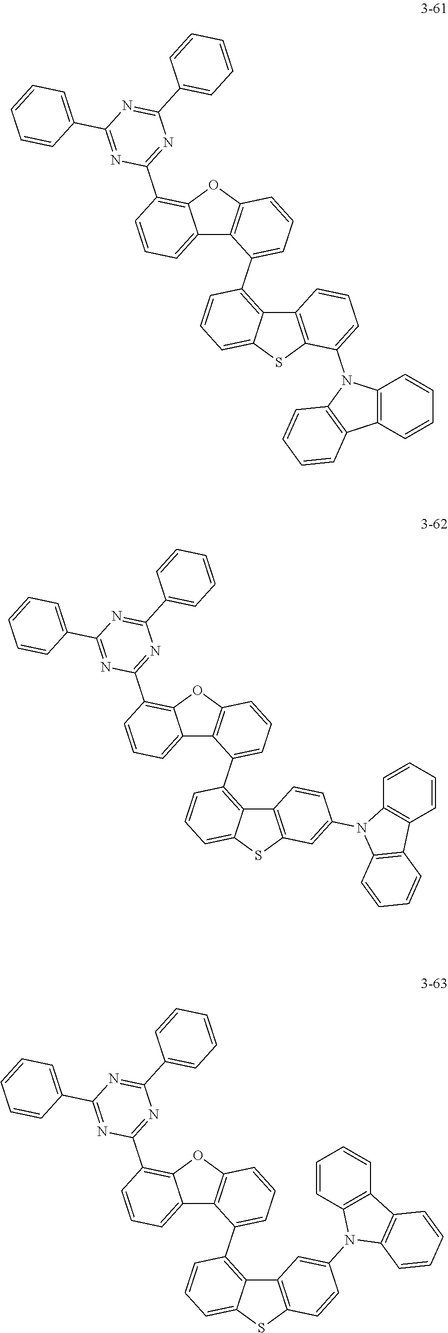 [SMILES: c1ccc(-c2nc(-c3ccccc3)nc(-c3cccc4c3oc3cccc(-c5cccc6sc7c(-n8c9ccccc9c9ccccc98)cccc7c56)c34)n2)cc1 ; c1ccc(-c2nc(-c3ccccc3)nc(-c3cccc4c3oc3cccc(-c5cccc6sc7cc(-n8c9ccccc9c9ccccc98)ccc7c56)c34)n2)cc1 ; c1ccc(-c2nc(-c3ccccc3)nc(-c3cccc4c3oc3cccc(-c5cccc6sc7ccc(-n8c9ccccc9c9ccccc98)cc7c56)c34)n2)cc1]

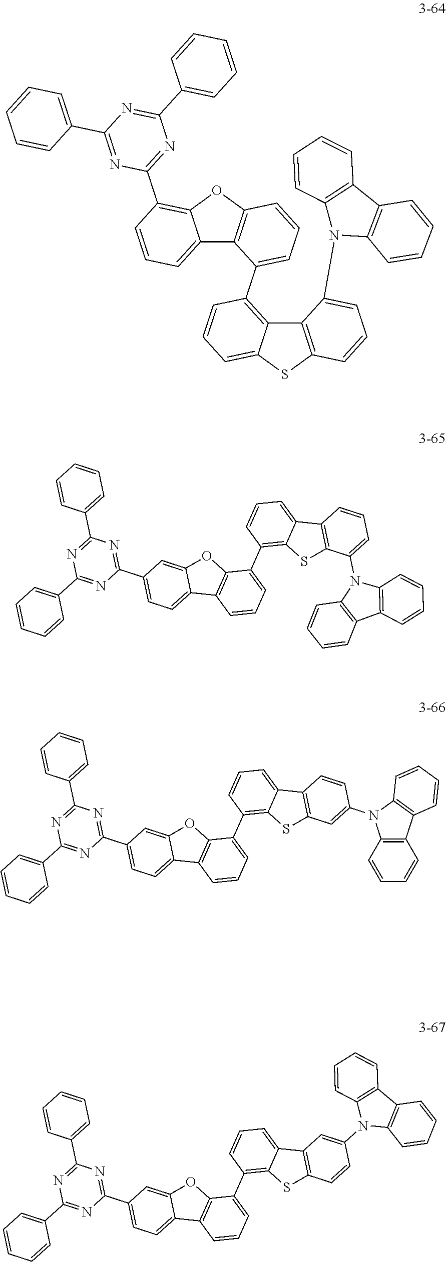 [SMILES: c1ccc(-c2nc(-c3ccccc3)nc(-c3cccc4c3oc3cccc(-c5cccc6sc7cccc(-n8c9ccccc9c9ccccc98)c7c56)c34)n2)cc1 ; c1ccc(-c2nc(-c3ccccc3)nc(-c3ccc4c(c3)oc3c(-c5cccc6c5sc5c(-n7c8ccccc8c8ccccc87)cccc56)cccc34)n2)cc1 ; c1ccc(-c2nc(-c3ccccc3)nc(-c3ccc4c(c3)oc3c(-c5cccc6c5sc5cc(-n7c8ccccc8c8ccccc87)ccc56)cccc34)n2)cc1 ; c1ccc(-c2nc(-c3ccccc3)nc(-c3ccc4c(c3)oc3c(-c5cccc6c5sc5ccc(-n7c8ccccc8c8ccccc87)cc56)cccc34)n2)cc1]

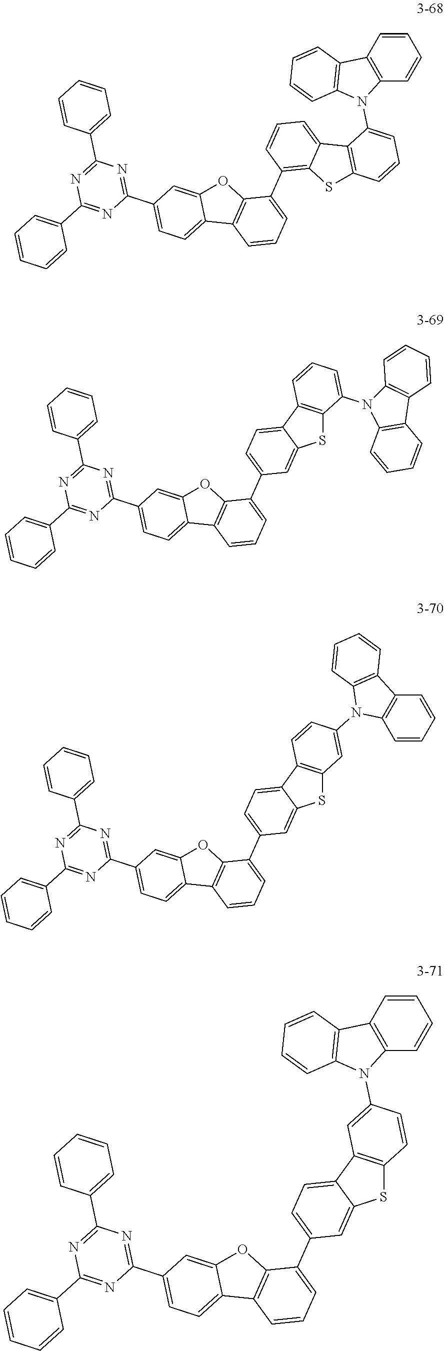 [SMILES: c1ccc(-c2nc(-c3ccccc3)nc(-c3ccc4c(c3)oc3c(-c5cccc6c5sc5cccc(-n7c8ccccc8c8ccccc87)c56)cccc34)n2)cc1 ; c1ccc(-c2nc(-c3ccccc3)nc(-c3ccc4c(c3)oc3c(-c5ccc6c(c5)sc5c(-n7c8ccccc8c8ccccc87)cccc56)cccc34)n2)cc1 ; c1ccc(-c2nc(-c3ccccc3)nc(-c3ccc4c(c3)oc3c(-c5ccc6c(c5)sc5cc(-n7c8ccccc8c8ccccc87)ccc56)cccc34)n2)cc1 ; c1ccc(-c2nc(-c3ccccc3)nc(-c3ccc4c(c3)oc3c(-c5ccc6c(c5)sc5ccc(-n7c8ccccc8c8ccccc87)cc56)cccc34)n2)cc1]

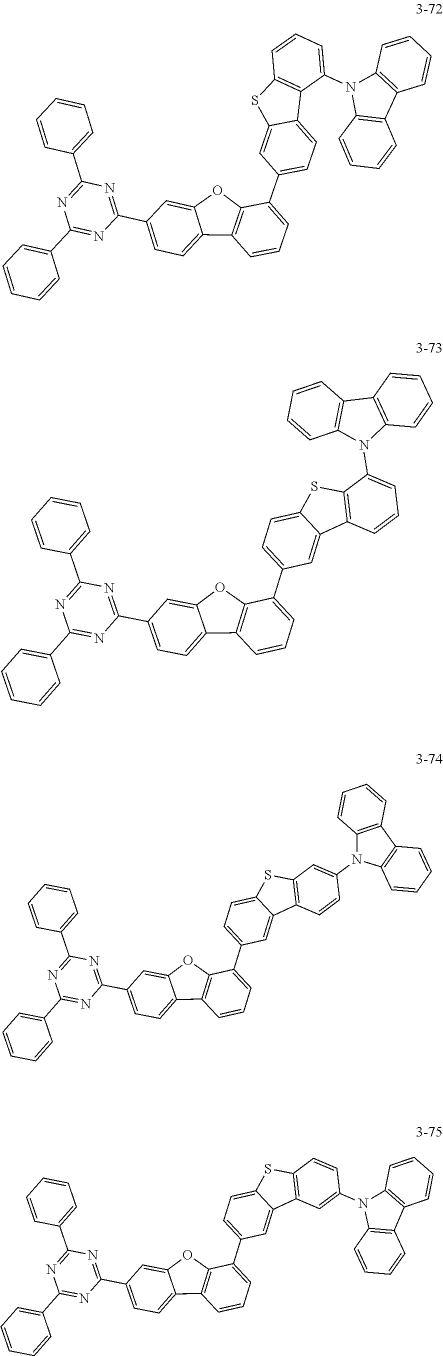 [SMILES: c1ccc(-c2nc(-c3ccccc3)nc(-c3ccc4c(c3)oc3c(-c5ccc6c(c5)sc5cccc(-n7c8ccccc8c8ccccc87)c56)cccc34)n2)cc1 ; c1ccc(-c2nc(-c3ccccc3)nc(-c3ccc4c(c3)oc3c(-c5ccc6sc7c(-n8c9ccccc9c9ccccc98)cccc7c6c5)cccc34)n2)cc1 ; c1ccc(-c2nc(-c3ccccc3)nc(-c3ccc4c(c3)oc3c(-c5ccc6sc7cc(-n8c9ccccc9c9ccccc98)ccc7c6c5)cccc34)n2)cc1 ; c1ccc(-c2nc(-c3ccccc3)nc(-c3ccc4c(c3)oc3c(-c5ccc6sc7ccc(-n8c9ccccc9c9ccccc98)cc7c6c5)cccc34)n2)cc1]

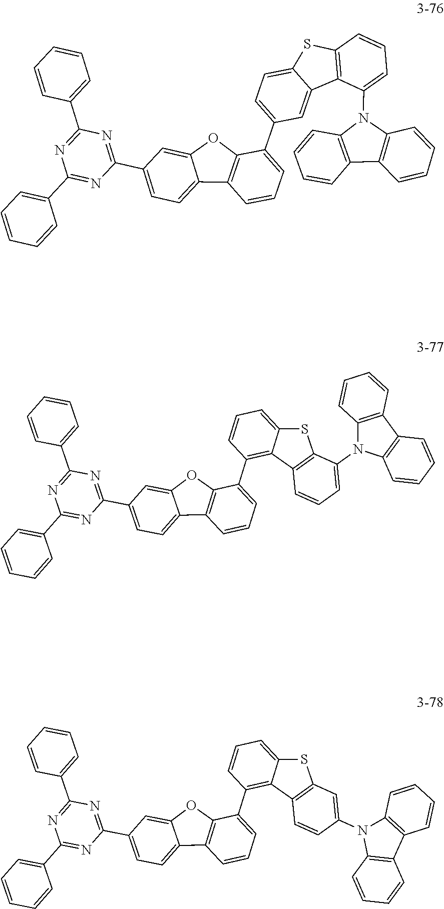 [SMILES: c1ccc(-c2nc(-c3ccccc3)nc(-c3ccc4c(c3)oc3c(-c5ccc6sc7cccc(-n8c9ccccc9c9ccccc98)c7c6c5)cccc34)n2)cc1 ; c1ccc(-c2nc(-c3ccccc3)nc(-c3ccc4c(c3)oc3c(-c5cccc6sc7c(-n8c9ccccc9c9ccccc98)cccc7c56)cccc34)n2)cc1 ; c1ccc(-c2nc(-c3ccccc3)nc(-c3ccc4c(c3)oc3c(-c5cccc6sc7cc(-n8c9ccccc9c9ccccc98)ccc7c56)cccc34)n2)cc1]

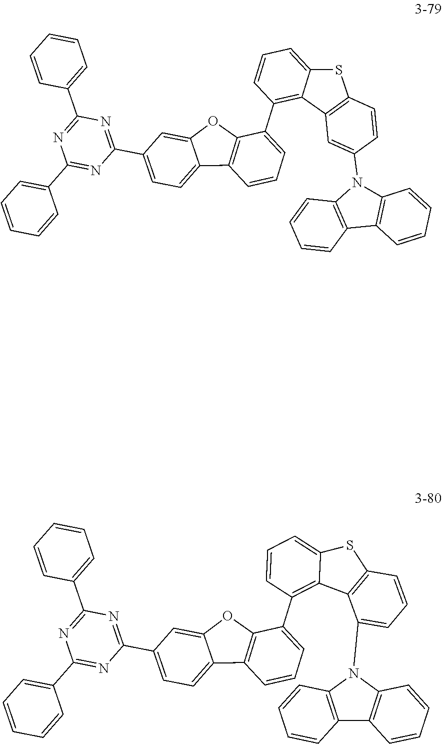 [SMILES: c1ccc(-c2nc(-c3ccccc3)nc(-c3ccc4c(c3)oc3c(-c5cccc6sc7ccc(-n8c9ccccc9c9ccccc98)cc7c56)cccc34)n2)cc1 ; c1ccc(-c2nc(-c3ccccc3)nc(-c3ccc4c(c3)oc3c(-c5cccc6sc7cccc(-n8c9ccccc9c9ccccc98)c7c56)cccc34)n2)cc1]

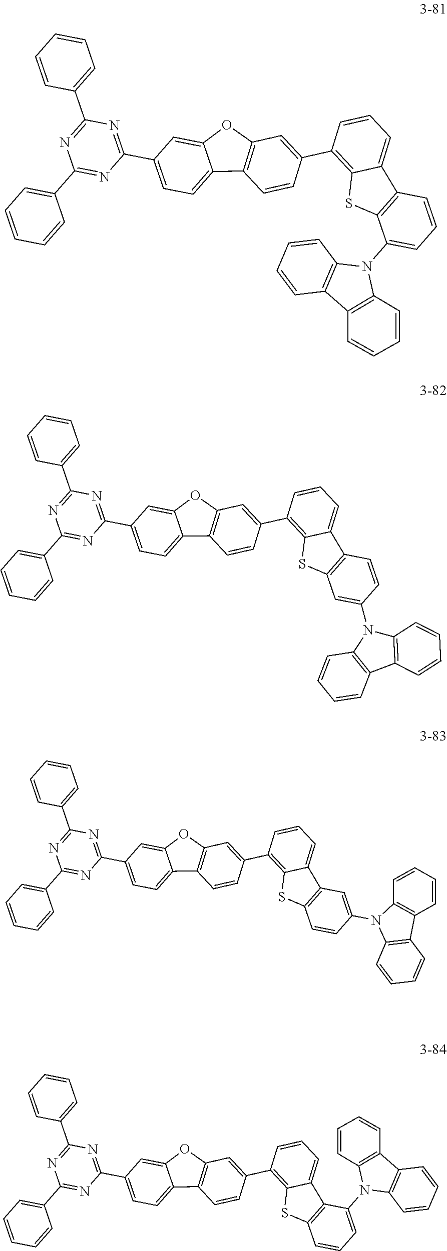 [SMILES: c1ccc(-c2nc(-c3ccccc3)nc(-c3ccc4c(c3)oc3cc(-c5cccc6c5sc5c(-n7c8ccccc8c8ccccc87)cccc56)ccc34)n2)cc1 ; c1ccc(-c2nc(-c3ccccc3)nc(-c3ccc4c(c3)oc3cc(-c5cccc6c5sc5cc(-n7c8ccccc8c8ccccc87)ccc56)ccc34)n2)cc1 ; c1ccc(-c2nc(-c3ccccc3)nc(-c3ccc4c(c3)oc3cc(-c5cccc6c5sc5ccc(-n7c8ccccc8c8ccccc87)cc56)ccc34)n2)cc1 ; c1ccc(-c2nc(-c3ccccc3)nc(-c3ccc4c(c3)oc3cc(-c5cccc6c5sc5cccc(-n7c8ccccc8c8ccccc87)c56)ccc34)n2)cc1]

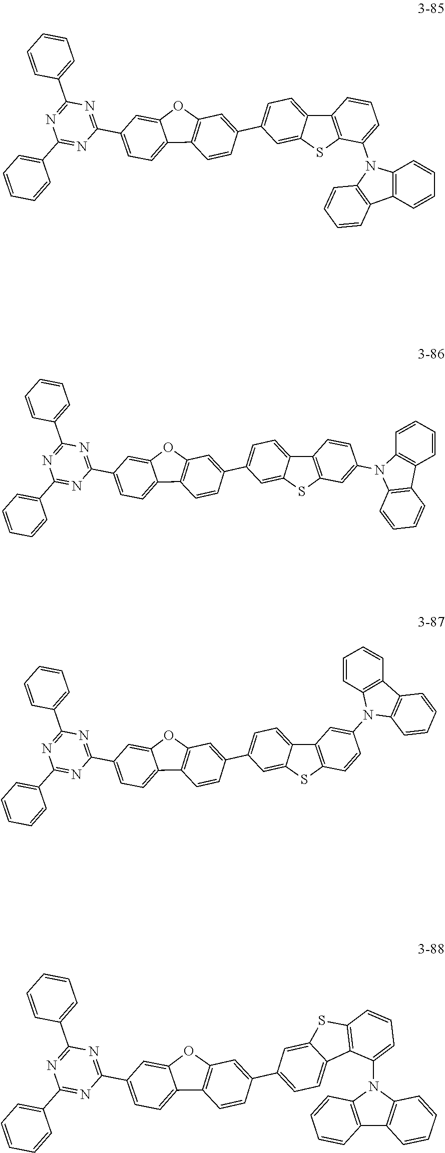 [SMILES: c1ccc(-c2nc(-c3ccccc3)nc(-c3ccc4c(c3)oc3cc(-c5ccc6c(c5)sc5c(-n7c8ccccc8c8ccccc87)cccc56)ccc34)n2)cc1 ; c1ccc(-c2nc(-c3ccccc3)nc(-c3ccc4c(c3)oc3cc(-c5ccc6c(c5)sc5cc(-n7c8ccccc8c8ccccc87)ccc56)ccc34)n2)cc1 ; c1ccc(-c2nc(-c3ccccc3)nc(-c3ccc4c(c3)oc3cc(-c5ccc6c(c5)sc5ccc(-n7c8ccccc8c8ccccc87)cc56)ccc34)n2)cc1 ; c1ccc(-c2nc(-c3ccccc3)nc(-c3ccc4c(c3)oc3cc(-c5ccc6c(c5)sc5cccc(-n7c8ccccc8c8ccccc87)c56)ccc34)n2)cc1]

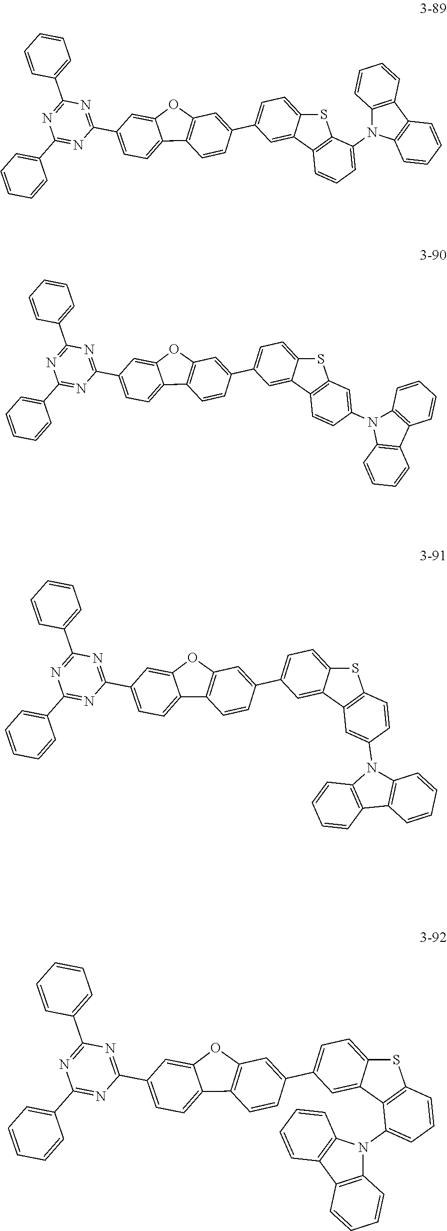 [SMILES: c1ccc(-c2nc(-c3ccccc3)nc(-c3ccc4c(c3)oc3cc(-c5ccc6sc7c(-n8c9ccccc9c9ccccc98)cccc7c6c5)ccc34)n2)cc1 ; c1ccc(-c2nc(-c3ccccc3)nc(-c3ccc4c(c3)oc3cc(-c5ccc6sc7cc(-n8c9ccccc9c9ccccc98)ccc7c6c5)ccc34)n2)cc1 ; c1ccc(-c2nc(-c3ccccc3)nc(-c3ccc4c(c3)oc3cc(-c5ccc6sc7ccc(-n8c9ccccc9c9ccccc98)cc7c6c5)ccc34)n2)cc1 ; c1ccc(-c2nc(-c3ccccc3)nc(-c3ccc4c(c3)oc3cc(-c5ccc6sc7cccc(-n8c9ccccc9c9ccccc98)c7c6c5)ccc34)n2)cc1]

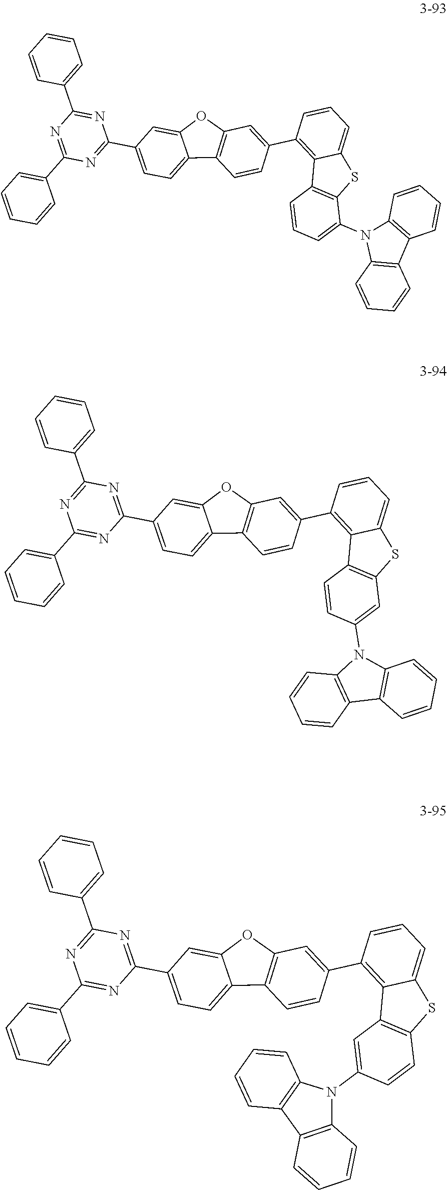 [SMILES: c1ccc(-c2nc(-c3ccccc3)nc(-c3ccc4c(c3)oc3cc(-c5cccc6sc7c(-n8c9ccccc9c9ccccc98)cccc7c56)ccc34)n2)cc1 ; c1ccc(-c2nc(-c3ccccc3)nc(-c3ccc4c(c3)oc3cc(-c5cccc6sc7cc(-n8c9ccccc9c9ccccc98)ccc7c56)ccc34)n2)cc1 ; c1ccc(-c2nc(-c3ccccc3)nc(-c3ccc4c(c3)oc3cc(-c5cccc6sc7ccc(-n8c9ccccc9c9ccccc98)cc7c56)ccc34)n2)cc1]

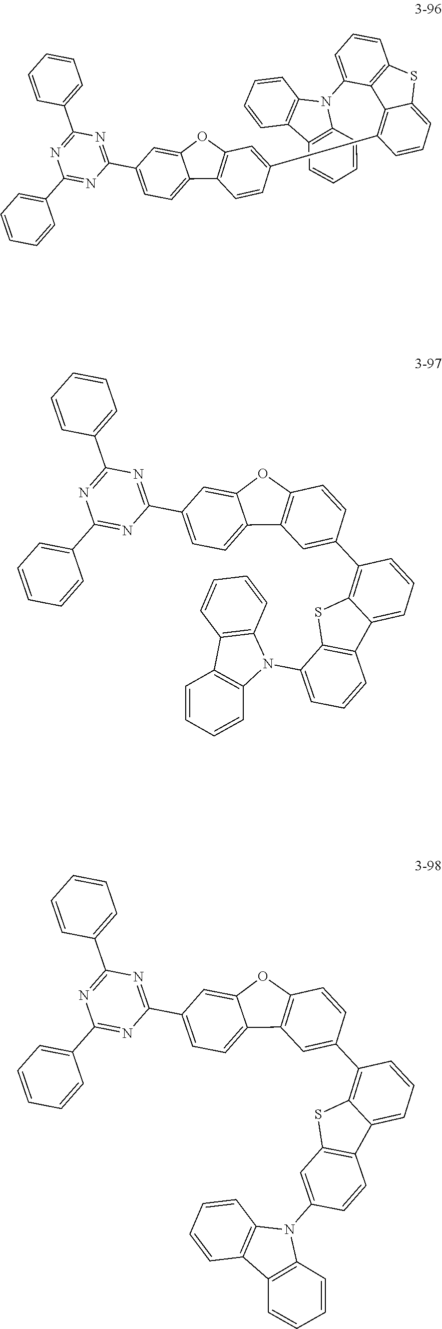 [SMILES: c1ccc(-c2nc(-c3ccccc3)nc(-c3ccc4c(c3)oc3cc(-c5cccc6sc7cccc(-n8c9ccccc9c9ccccc98)c7c56)ccc34)n2)cc1 ; c1ccc(-c2nc(-c3ccccc3)nc(-c3ccc4c(c3)oc3ccc(-c5cccc6c5sc5c(-n7c8ccccc8c8ccccc87)cccc56)cc34)n2)cc1 ; c1ccc(-c2nc(-c3ccccc3)nc(-c3ccc4c(c3)oc3ccc(-c5cccc6c5sc5cc(-n7c8ccccc8c8ccccc87)ccc56)cc34)n2)cc1]

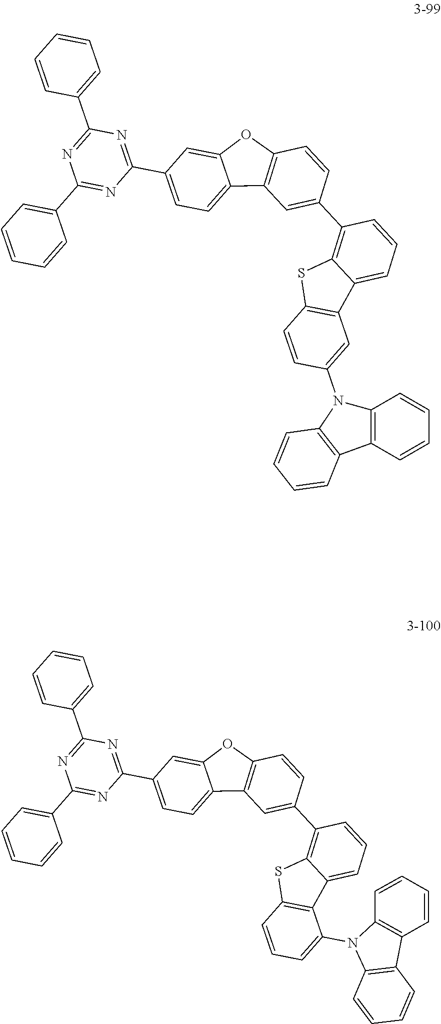 [SMILES: c1ccc(-c2nc(-c3ccccc3)nc(-c3ccc4c(c3)oc3ccc(-c5cccc6c5sc5ccc(-n7c8ccccc8c8ccccc87)cc56)cc34)n2)cc1 ; c1ccc(-c2nc(-c3ccccc3)nc(-c3ccc4c(c3)oc3ccc(-c5cccc6c5sc5cccc(-n7c8ccccc8c8ccccc87)c56)cc34)n2)cc1]

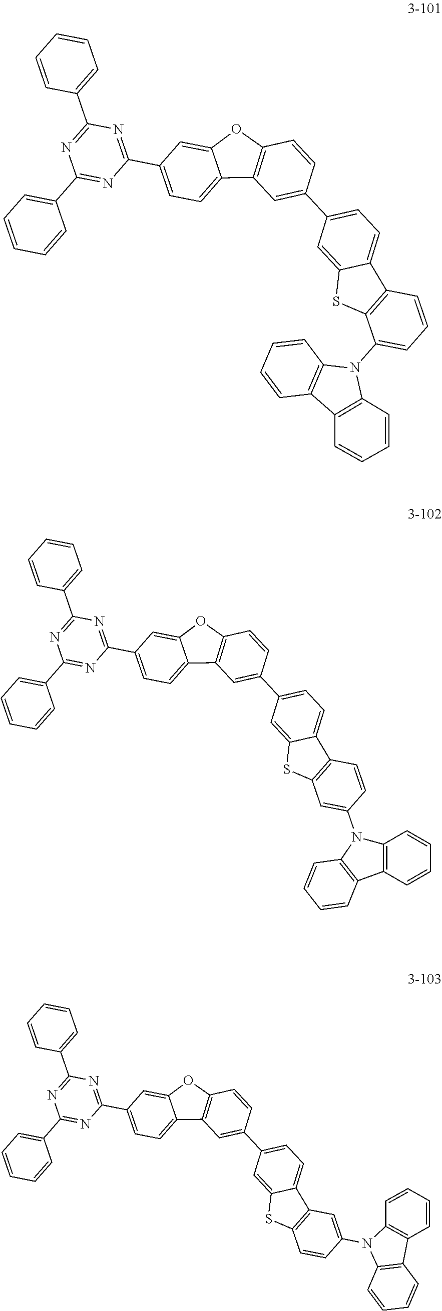 [SMILES: c1ccc(-c2nc(-c3ccccc3)nc(-c3ccc4c(c3)oc3ccc(-c5ccc6c(c5)sc5c(-n7c8ccccc8c8ccccc87)cccc56)cc34)n2)cc1 ; c1ccc(-c2nc(-c3ccccc3)nc(-c3ccc4c(c3)oc3ccc(-c5ccc6c(c5)sc5cc(-n7c8ccccc8c8ccccc87)ccc56)cc34)n2)cc1 ; c1ccc(-c2nc(-c3ccccc3)nc(-c3ccc4c(c3)oc3ccc(-c5ccc6c(c5)sc5ccc(-n7c8ccccc8c8ccccc87)cc56)cc34)n2)cc1]

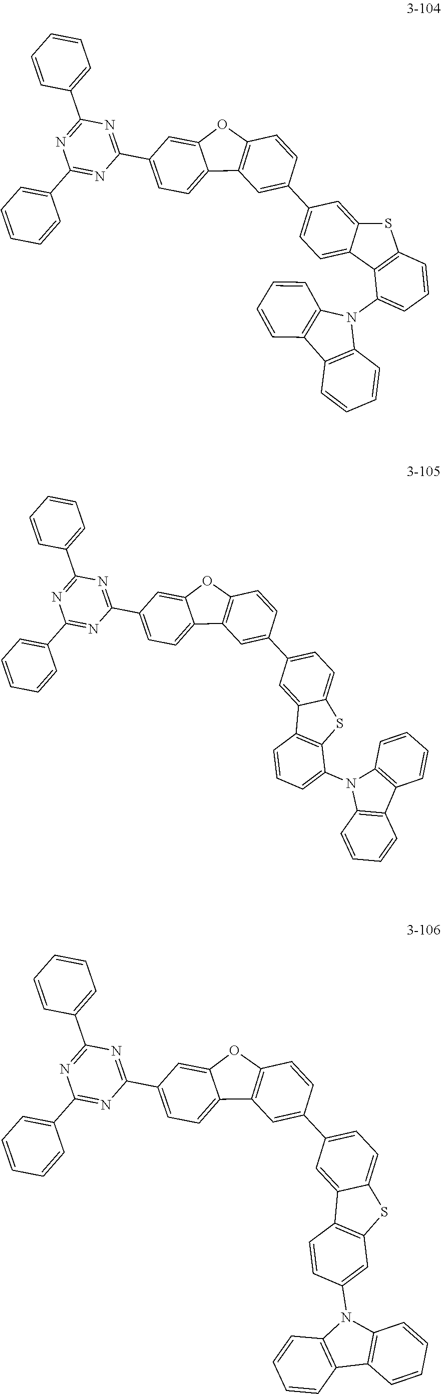 [SMILES: c1ccc(-c2nc(-c3ccccc3)nc(-c3ccc4c(c3)oc3ccc(-c5ccc6c(c5)sc5cccc(-n7c8ccccc8c8ccccc87)c56)cc34)n2)cc1 ; c1ccc(-c2nc(-c3ccccc3)nc(-c3ccc4c(c3)oc3ccc(-c5ccc6sc7c(-n8c9ccccc9c9ccccc98)cccc7c6c5)cc34)n2)cc1 ; c1ccc(-c2nc(-c3ccccc3)nc(-c3ccc4c(c3)oc3ccc(-c5ccc6sc7cc(-n8c9ccccc9c9ccccc98)ccc7c6c5)cc34)n2)cc1]

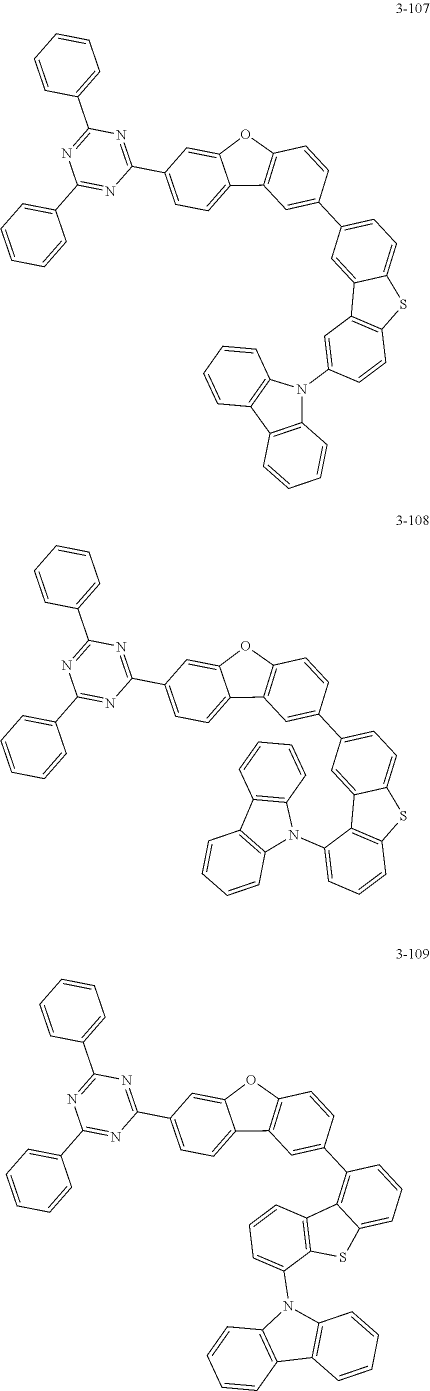 [SMILES: c1ccc(-c2nc(-c3ccccc3)nc(-c3ccc4c(c3)oc3ccc(-c5ccc6sc7ccc(-n8c9ccccc9c9ccccc98)cc7c6c5)cc34)n2)cc1 ; c1ccc(-c2nc(-c3ccccc3)nc(-c3ccc4c(c3)oc3ccc(-c5ccc6sc7cccc(-n8c9ccccc9c9ccccc98)c7c6c5)cc34)n2)cc1 ; c1ccc(-c2nc(-c3ccccc3)nc(-c3ccc4c(c3)oc3ccc(-c5cccc6sc7c(-n8c9ccccc9c9ccccc98)cccc7c56)cc34)n2)cc1]

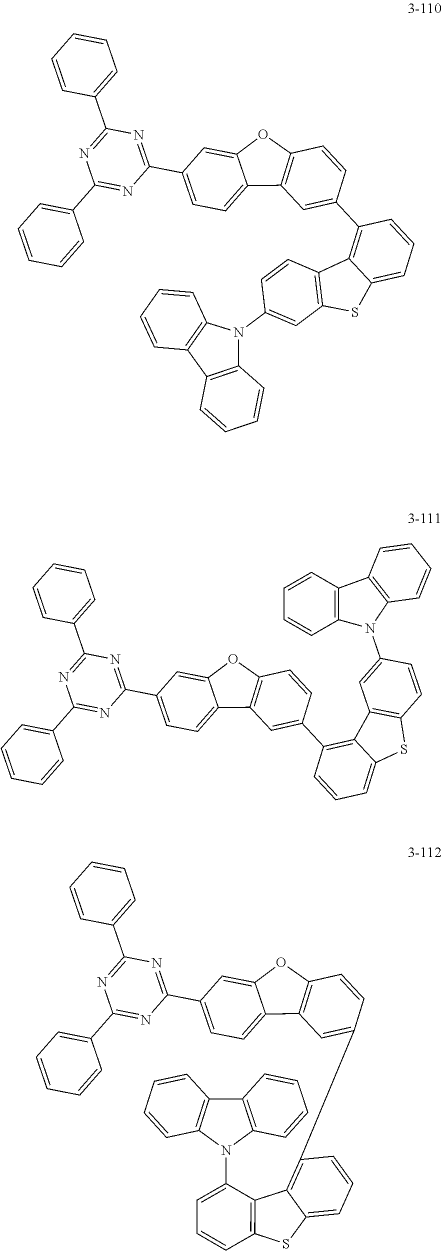 [SMILES: c1ccc(-c2nc(-c3ccccc3)nc(-c3ccc4c(c3)oc3ccc(-c5cccc6sc7cc(-n8c9ccccc9c9ccccc98)ccc7c56)cc34)n2)cc1 ; c1ccc(-c2nc(-c3ccccc3)nc(-c3ccc4c(c3)oc3ccc(-c5cccc6sc7ccc(-n8c9ccccc9c9ccccc98)cc7c56)cc34)n2)cc1 ; c1ccc(-c2nc(-c3ccccc3)nc(-c3ccc4c(c3)oc3ccc(-c5cccc6sc7cccc(-n8c9ccccc9c9ccccc98)c7c56)cc34)n2)cc1]

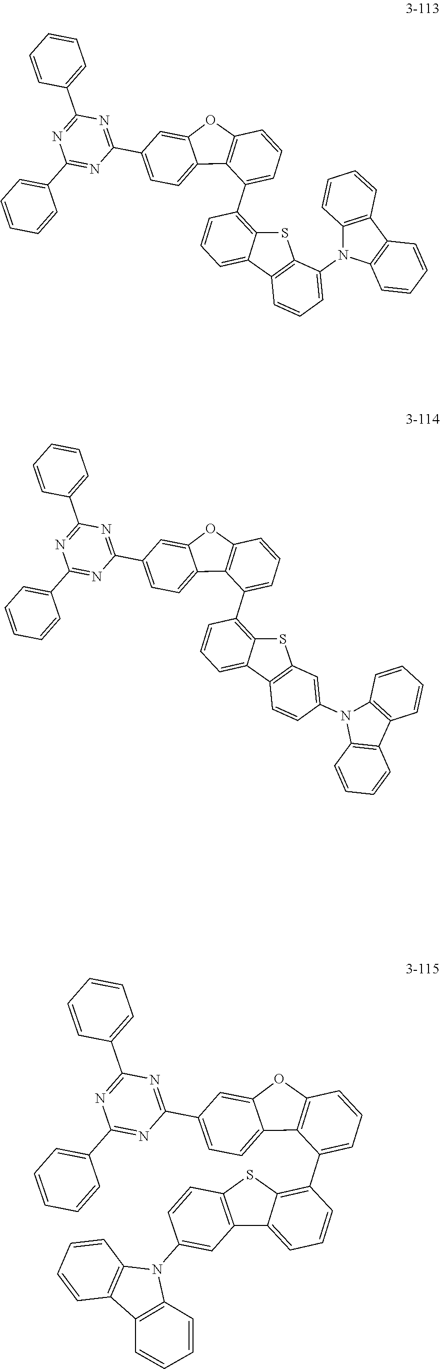 [SMILES: c1ccc(-c2nc(-c3ccccc3)nc(-c3ccc4c(c3)oc3cccc(-c5cccc6c5sc5c(-n7c8ccccc8c8ccccc87)cccc56)c34)n2)cc1 ; c1ccc(-c2nc(-c3ccccc3)nc(-c3ccc4c(c3)oc3cccc(-c5cccc6c5sc5cc(-n7c8ccccc8c8ccccc87)ccc56)c34)n2)cc1 ; c1ccc(-c2nc(-c3ccccc3)nc(-c3ccc4c(c3)oc3cccc(-c5cccc6c5sc5ccc(-n7c8ccccc8c8ccccc87)cc56)c34)n2)cc1]

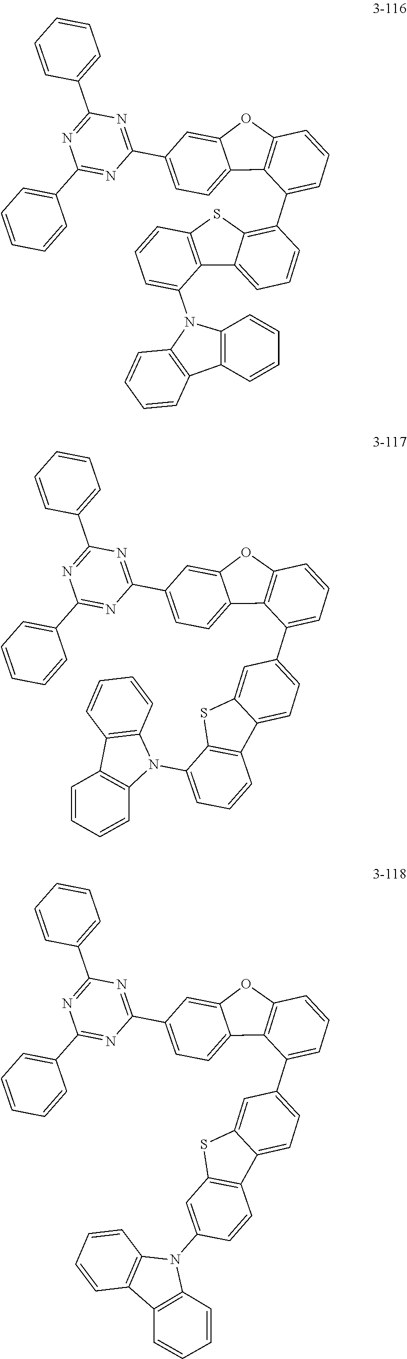 [SMILES: c1ccc(-c2nc(-c3ccccc3)nc(-c3ccc4c(c3)oc3cccc(-c5cccc6c5sc5cccc(-n7c8ccccc8c8ccccc87)c56)c34)n2)cc1 ; c1ccc(-c2nc(-c3ccccc3)nc(-c3ccc4c(c3)oc3cccc(-c5ccc6c(c5)sc5c(-n7c8ccccc8c8ccccc87)cccc56)c34)n2)cc1 ; c1ccc(-c2nc(-c3ccccc3)nc(-c3ccc4c(c3)oc3cccc(-c5ccc6c(c5)sc5cc(-n7c8ccccc8c8ccccc87)ccc56)c34)n2)cc1]

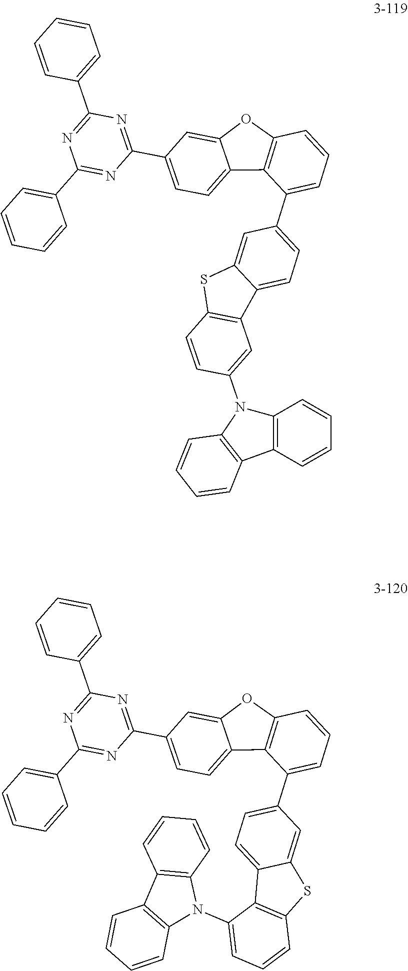 [SMILES: c1ccc(-c2nc(-c3ccccc3)nc(-c3ccc4c(c3)oc3cccc(-c5ccc6c(c5)sc5ccc(-n7c8ccccc8c8ccccc87)cc56)c34)n2)cc1 ; c1ccc(-c2nc(-c3ccccc3)nc(-c3ccc4c(c3)oc3cccc(-c5ccc6c(c5)sc5cccc(-n7c8ccccc8c8ccccc87)c56)c34)n2)cc1]

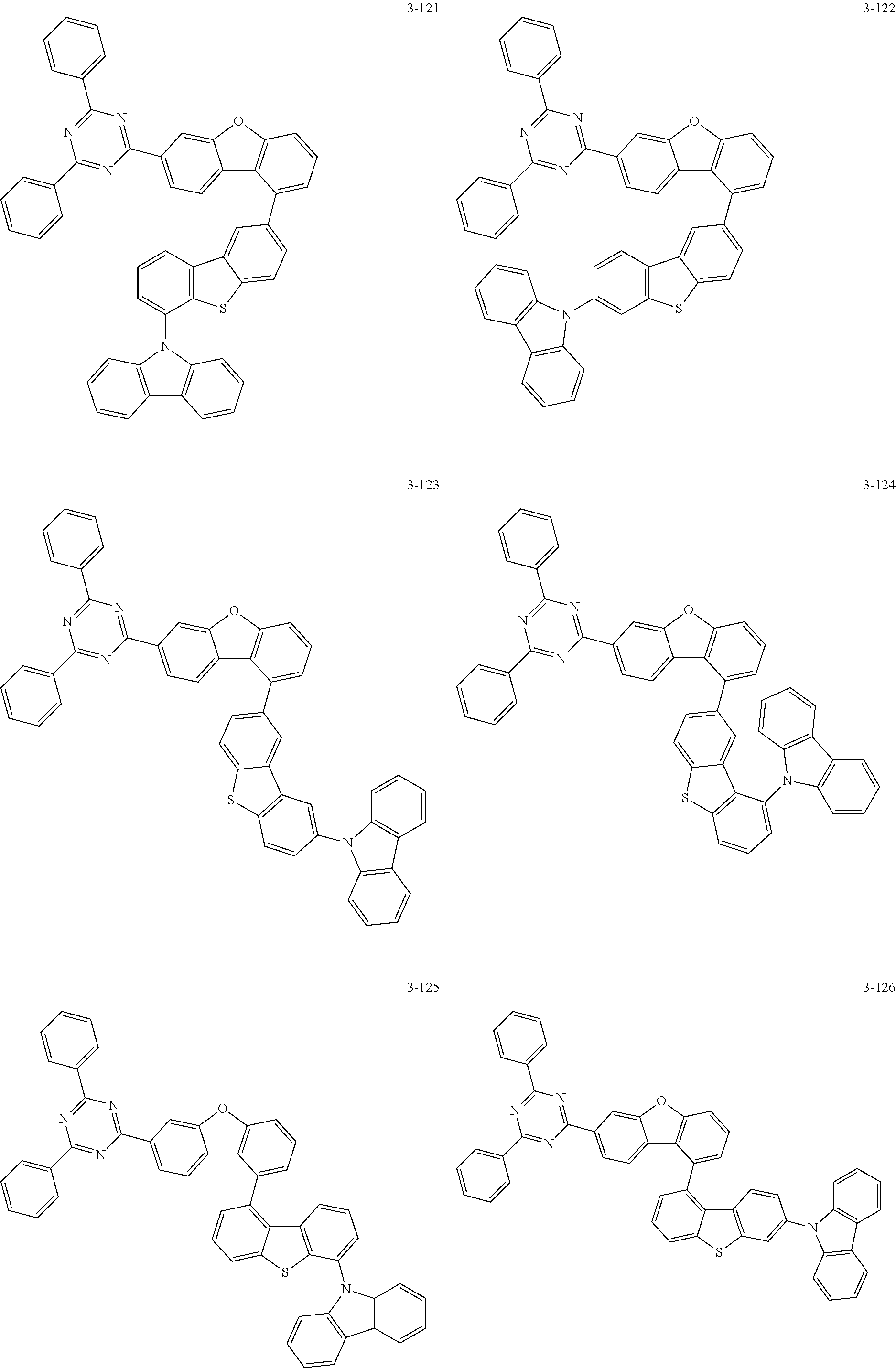

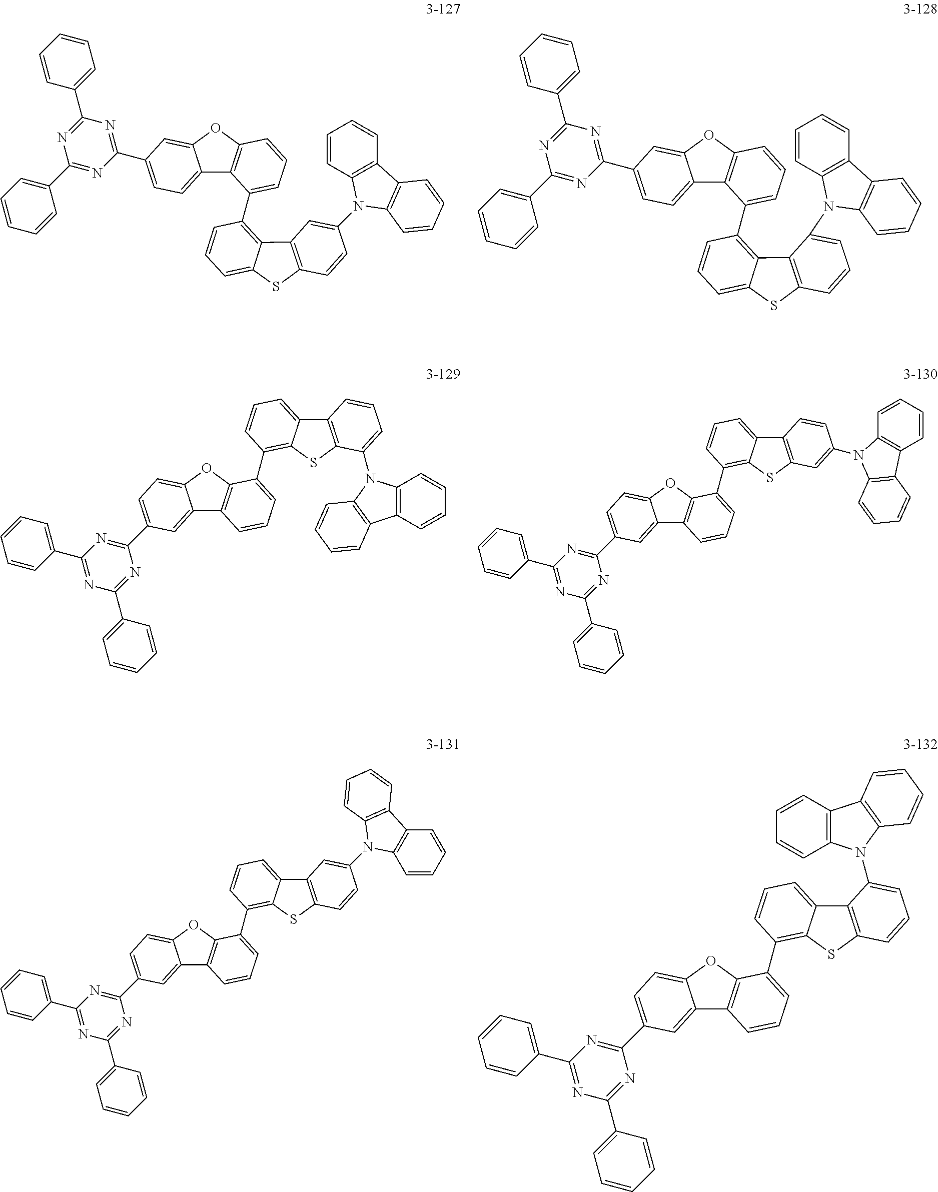

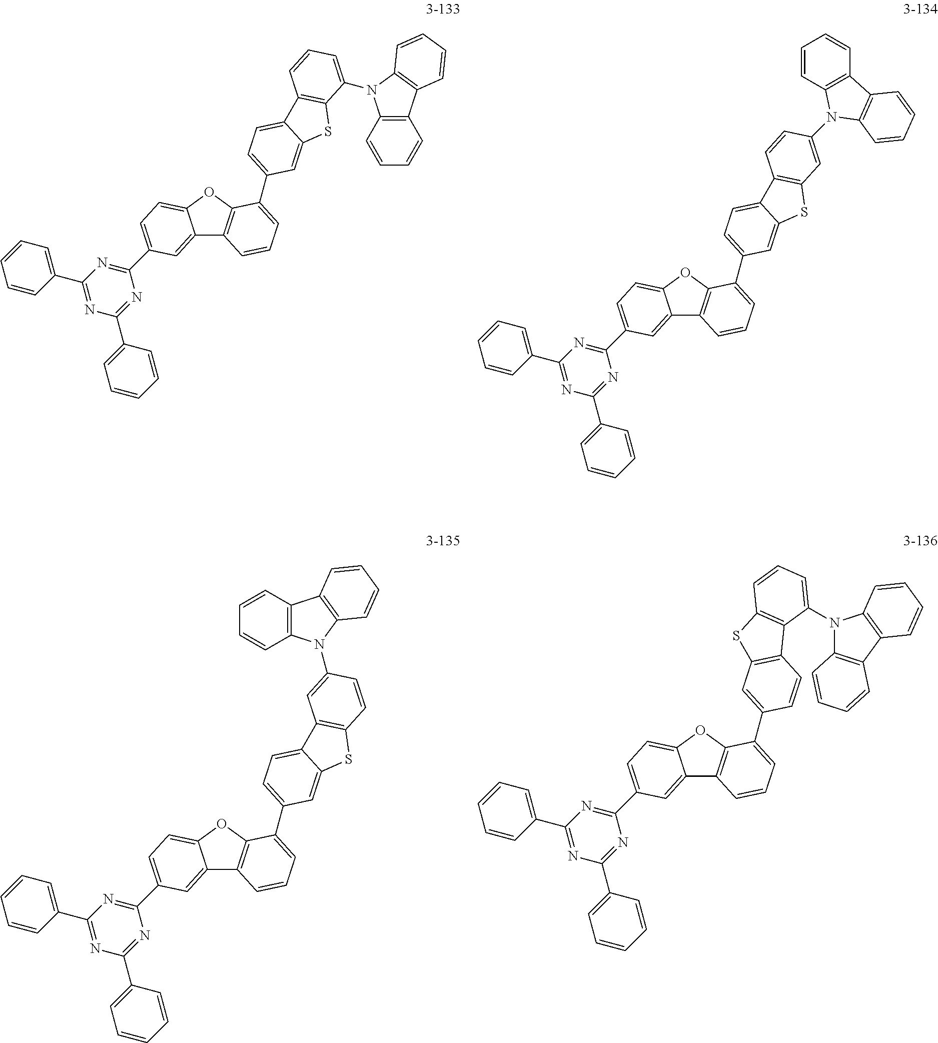 [SMILES: c1ccc(-c2nc(-c3ccccc3)nc(-c3ccc4oc5c(-c6ccc7c(c6)sc6c(-n8c9ccccc9c9ccccc98)cccc67)cccc5c4c3)n2)cc1 ; c1ccc(-c2nc(-c3ccccc3)nc(-c3ccc4oc5c(-c6ccc7c(c6)sc6cc(-n8c9ccccc9c9ccccc98)ccc67)cccc5c4c3)n2)cc1 ; c1ccc(-c2nc(-c3ccccc3)nc(-c3ccc4oc5c(-c6ccc7c(c6)sc6ccc(-n8c9ccccc9c9ccccc98)cc67)cccc5c4c3)n2)cc1 ; c1ccc(-c2nc(-c3ccccc3)nc(-c3ccc4oc5c(-c6ccc7c(c6)sc6cccc(-n8c9ccccc9c9ccccc98)c67)cccc5c4c3)n2)cc1]

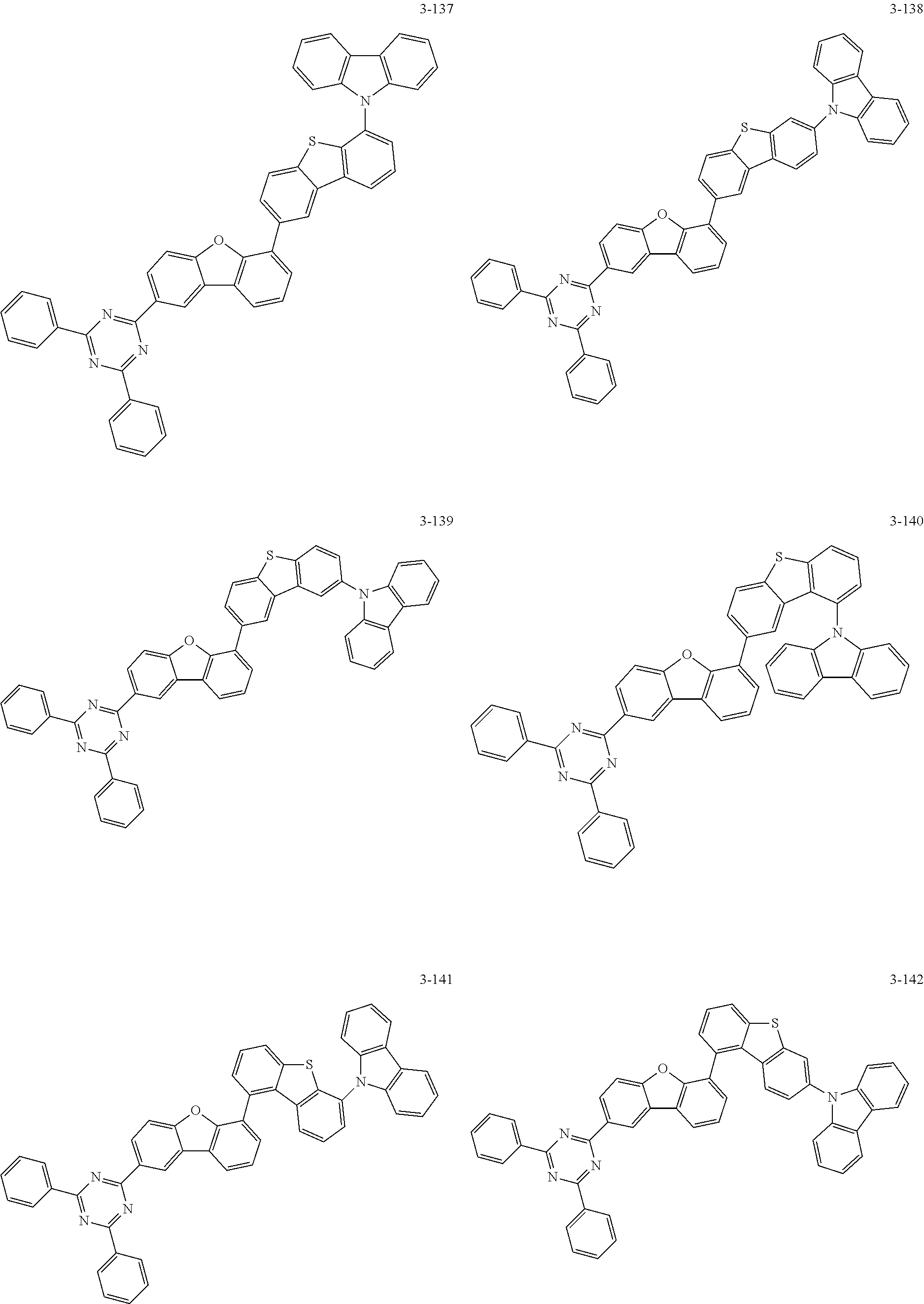

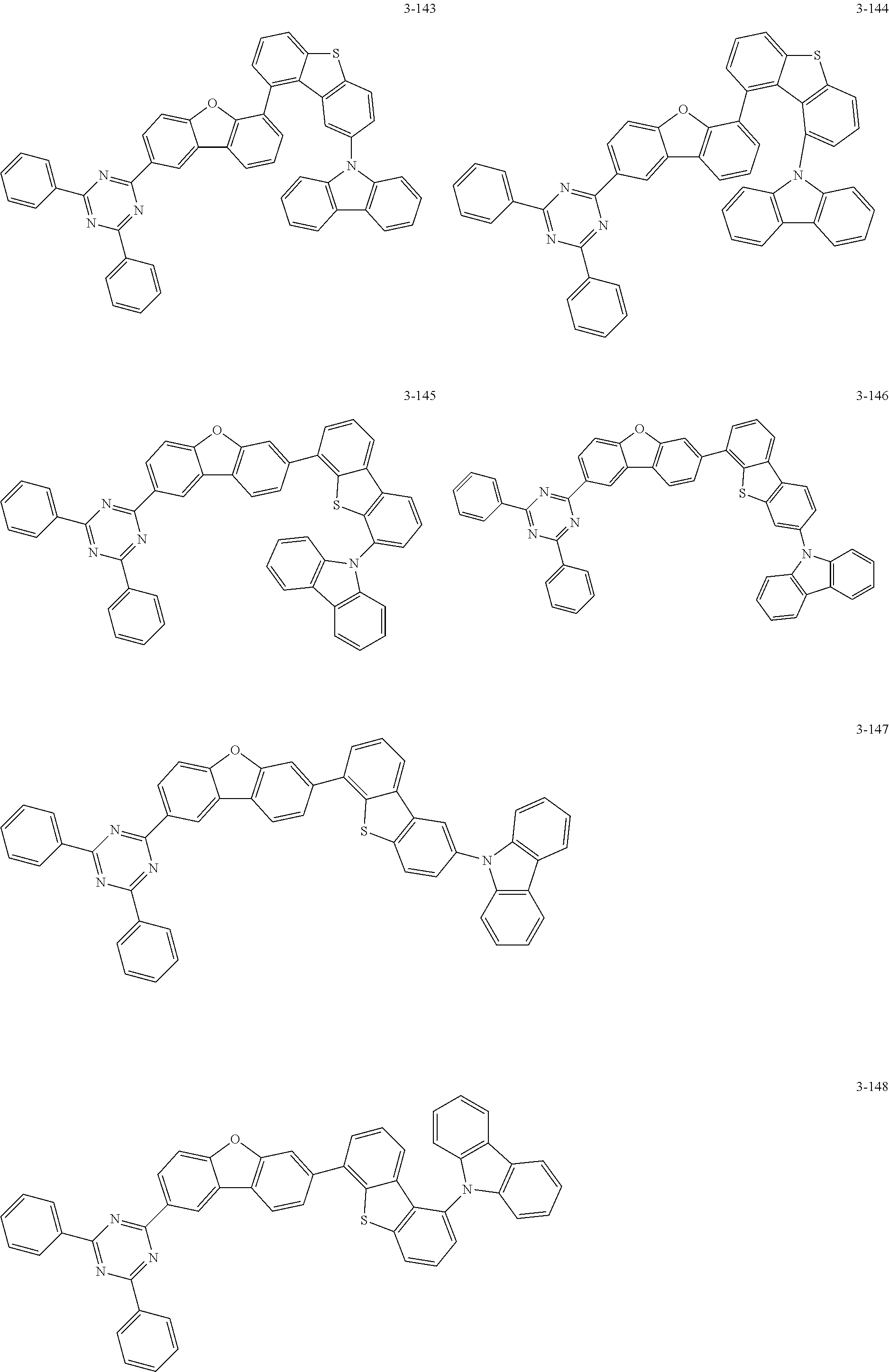

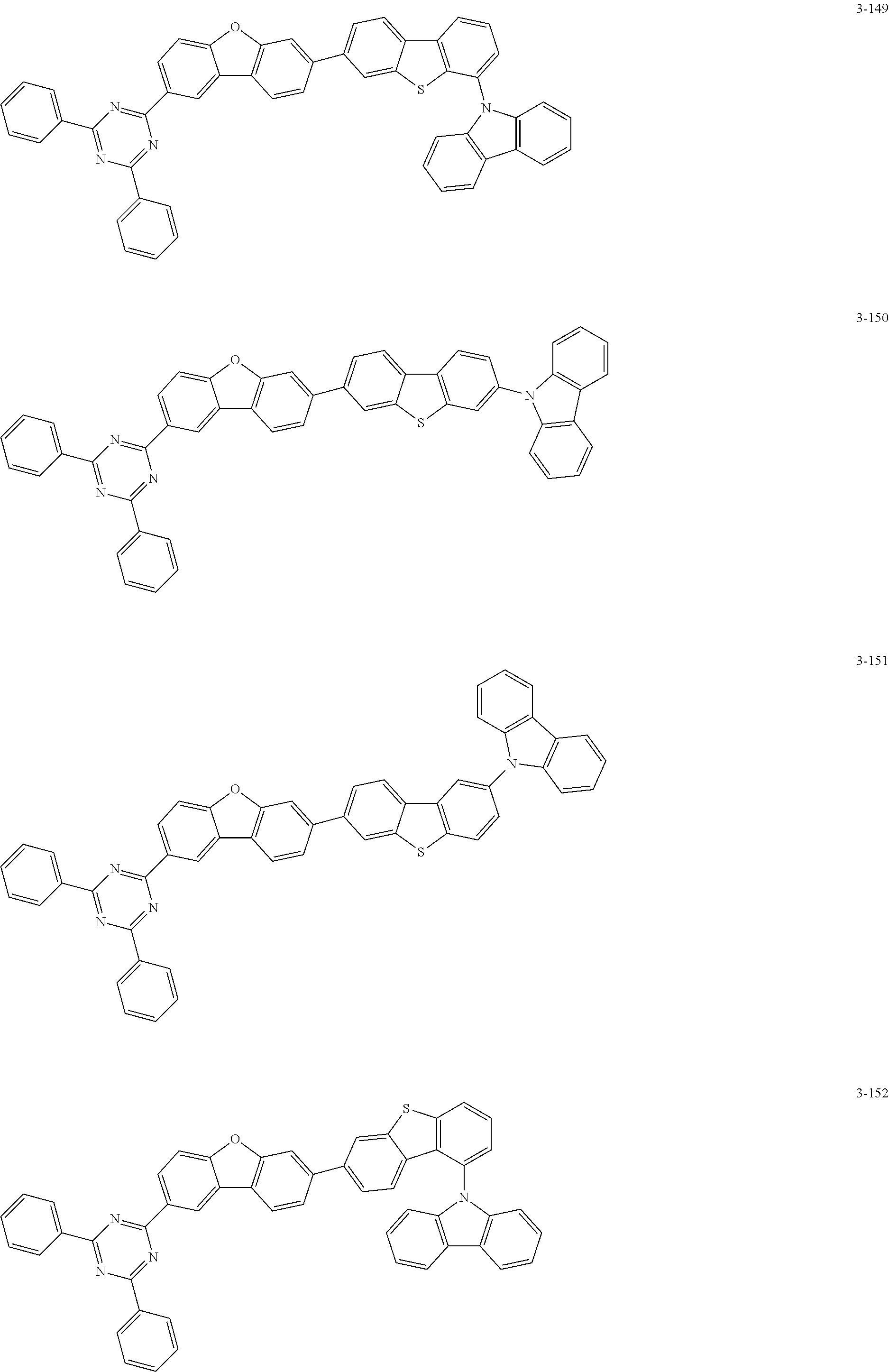 [SMILES: c1ccc(-c2nc(-c3ccccc3)nc(-c3ccc4oc5cc(-c6ccc7c(c6)sc6c(-n8c9ccccc9c9ccccc98)cccc67)ccc5c4c3)n2)cc1 ; c1ccc(-c2nc(-c3ccccc3)nc(-c3ccc4oc5cc(-c6ccc7c(c6)sc6cc(-n8c9ccccc9c9ccccc98)ccc67)ccc5c4c3)n2)cc1 ; c1ccc(-c2nc(-c3ccccc3)nc(-c3ccc4oc5cc(-c6ccc7c(c6)sc6ccc(-n8c9ccccc9c9ccccc98)cc67)ccc5c4c3)n2)cc1 ; c1ccc(-c2nc(-c3ccccc3)nc(-c3ccc4oc5cc(-c6ccc7c(c6)sc6cccc(-n8c9ccccc9c9ccccc98)c67)ccc5c4c3)n2)cc1]

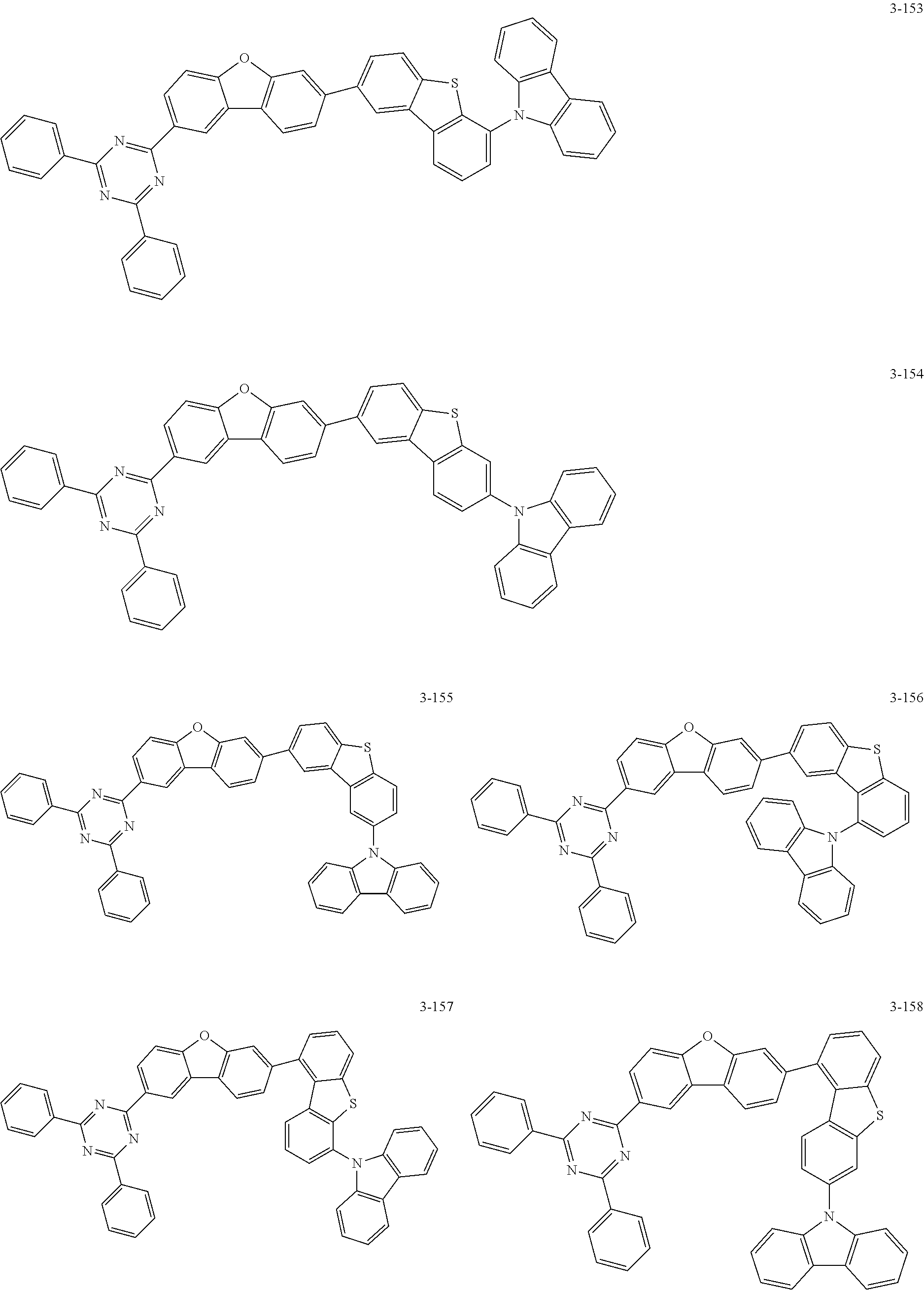

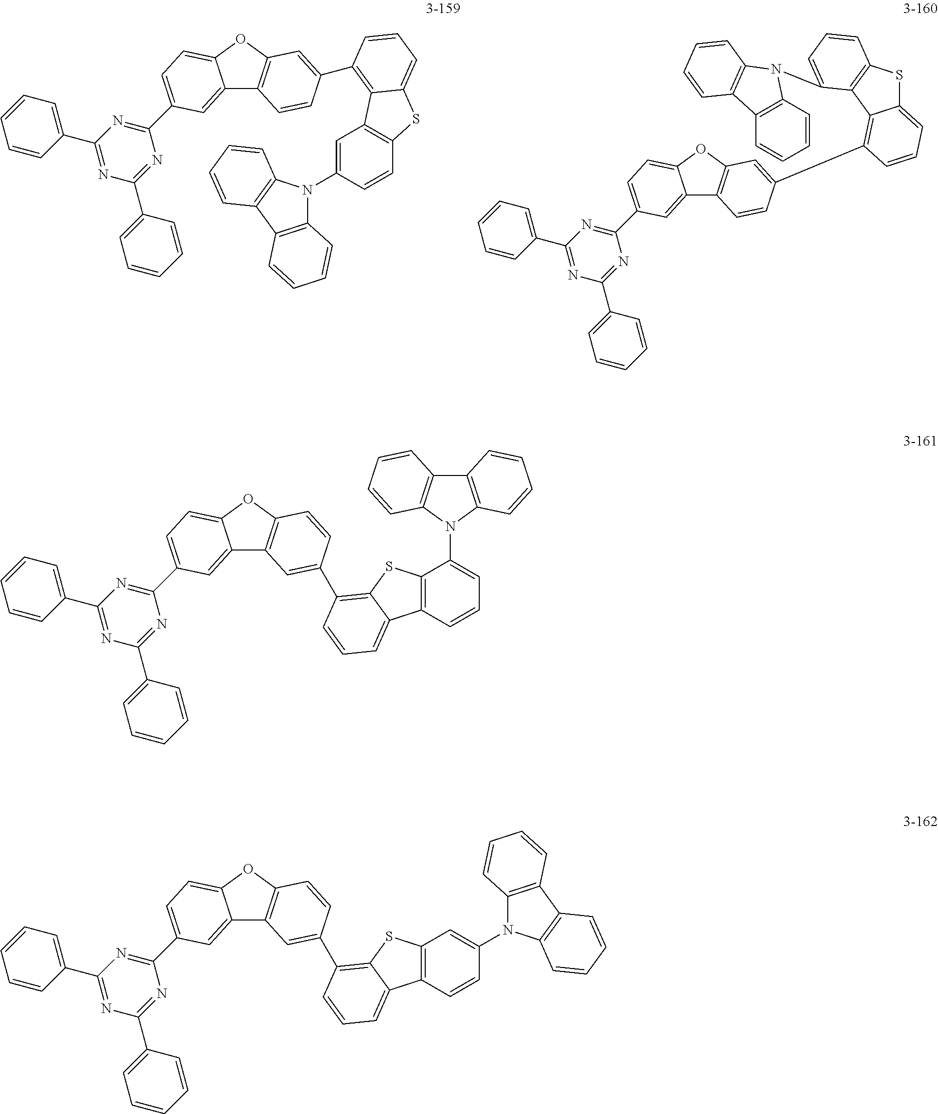 [SMILES: c1ccc(-c2nc(-c3ccccc3)nc(-c3ccc4oc5cc(-c6cccc7sc8ccc(-n9c%10ccccc%10c%10ccccc%109)cc8c67)ccc5c4c3)n2)cc1 ; c1ccc(-c2nc(-c3ccccc3)nc(-c3ccc4oc5cc(-c6cccc7sc8cccc(-n9c%10ccccc%10c%10ccccc%109)c8c67)ccc5c4c3)n2)cc1 ; c1ccc(-c2nc(-c3ccccc3)nc(-c3ccc4oc5ccc(-c6cccc7c6sc6c(-n8c9ccccc9c9ccccc98)cccc67)cc5c4c3)n2)cc1 ; c1ccc(-c2nc(-c3ccccc3)nc(-c3ccc4oc5ccc(-c6cccc7c6sc6cc(-n8c9ccccc9c9ccccc98)ccc67)cc5c4c3)n2)cc1]

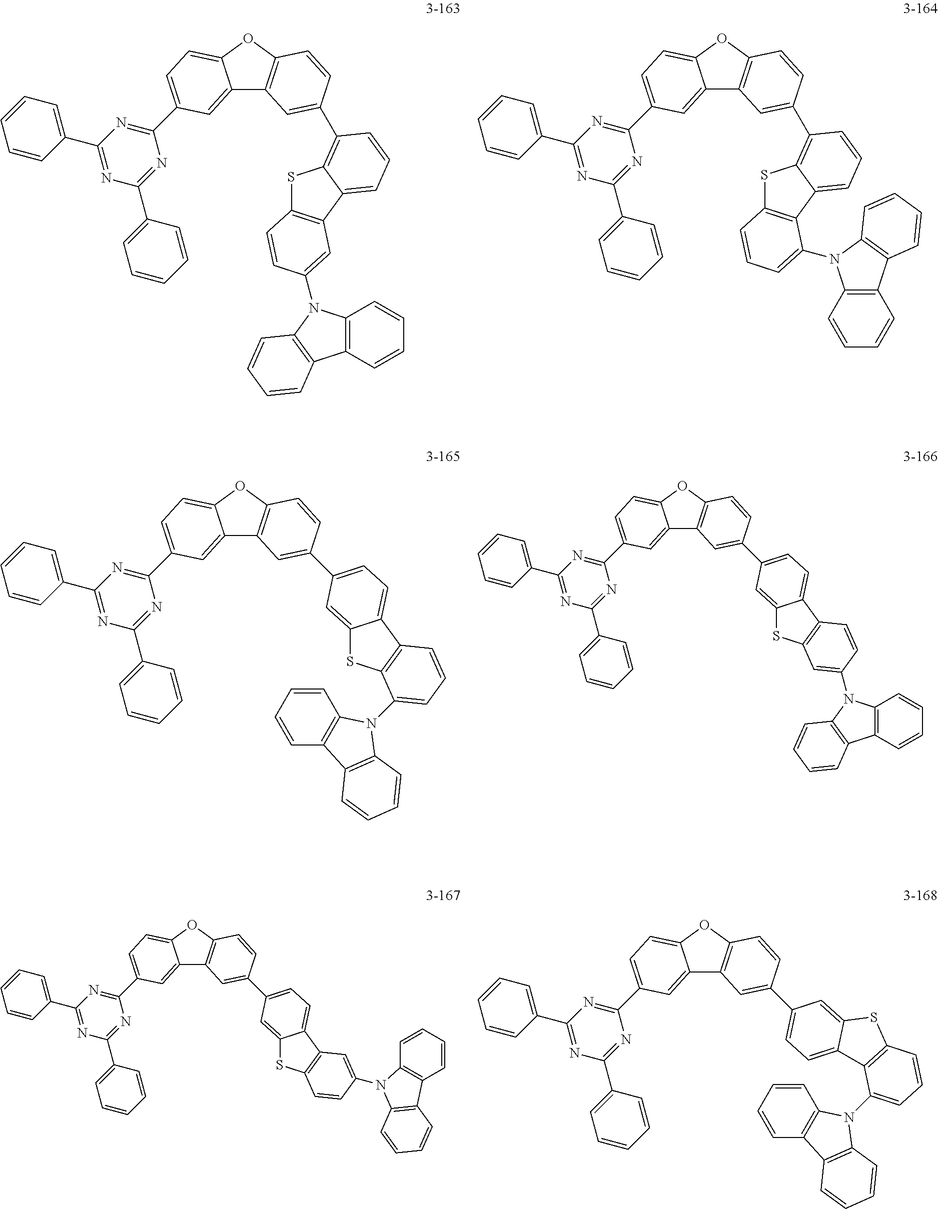

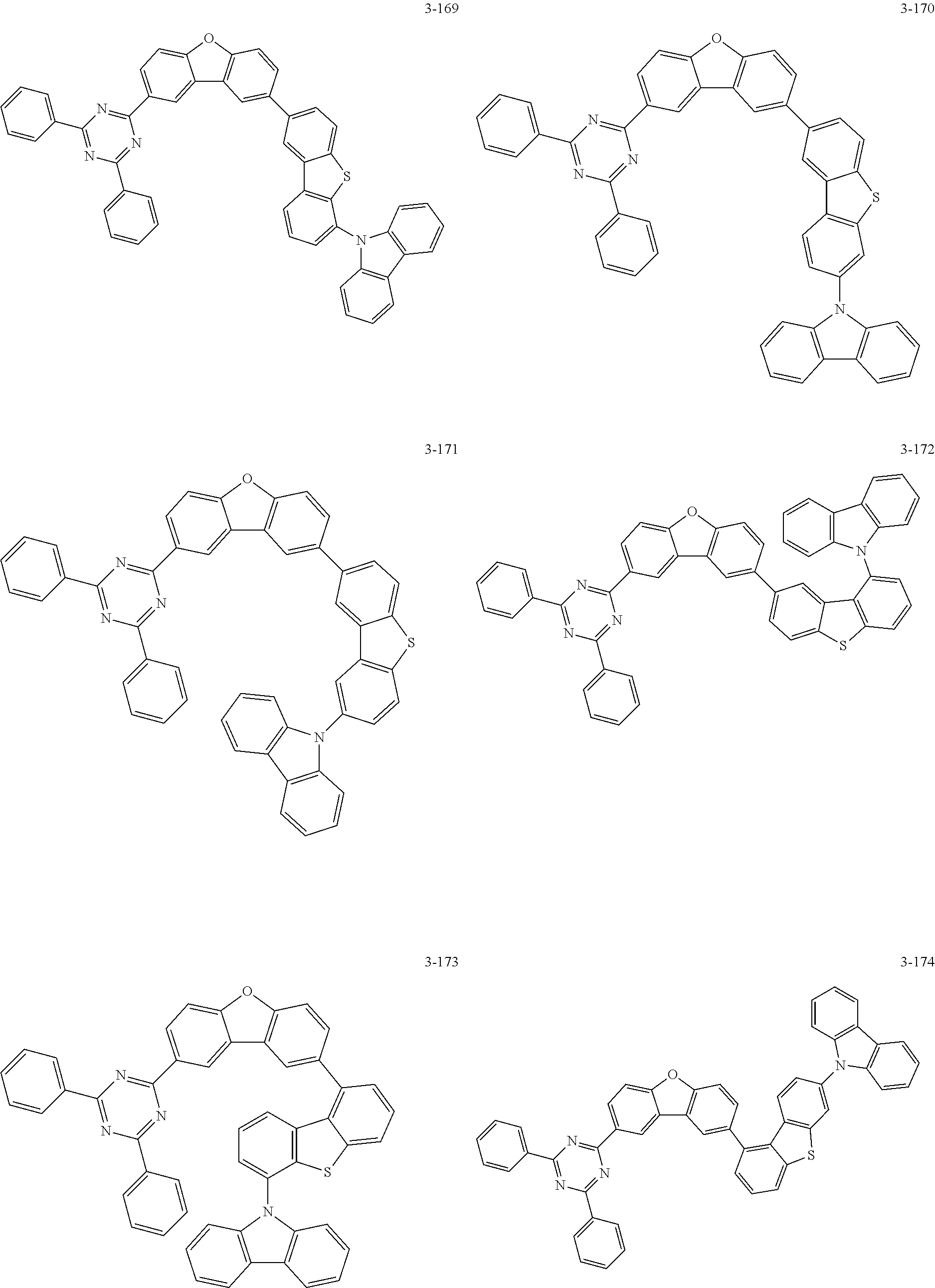

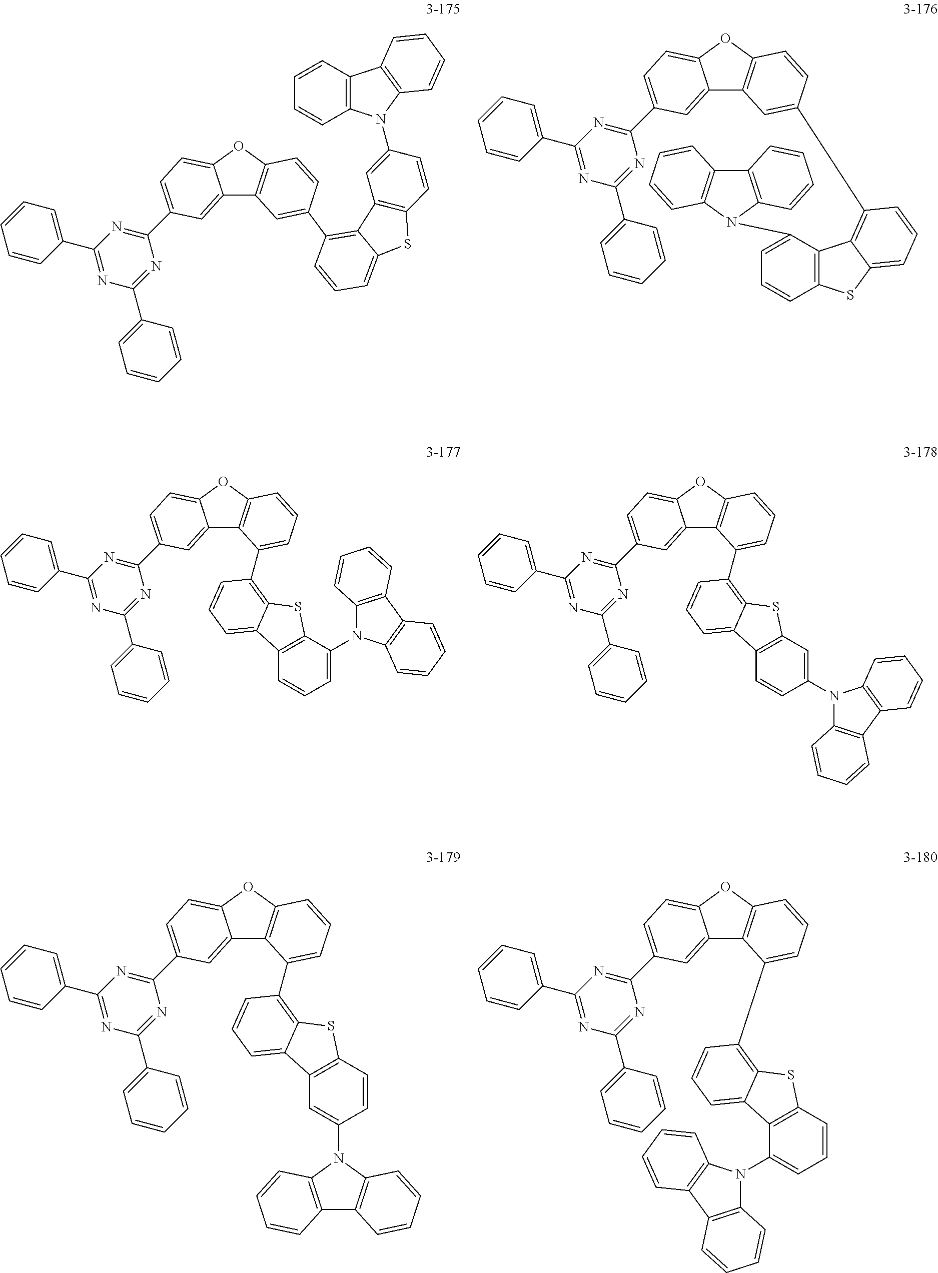

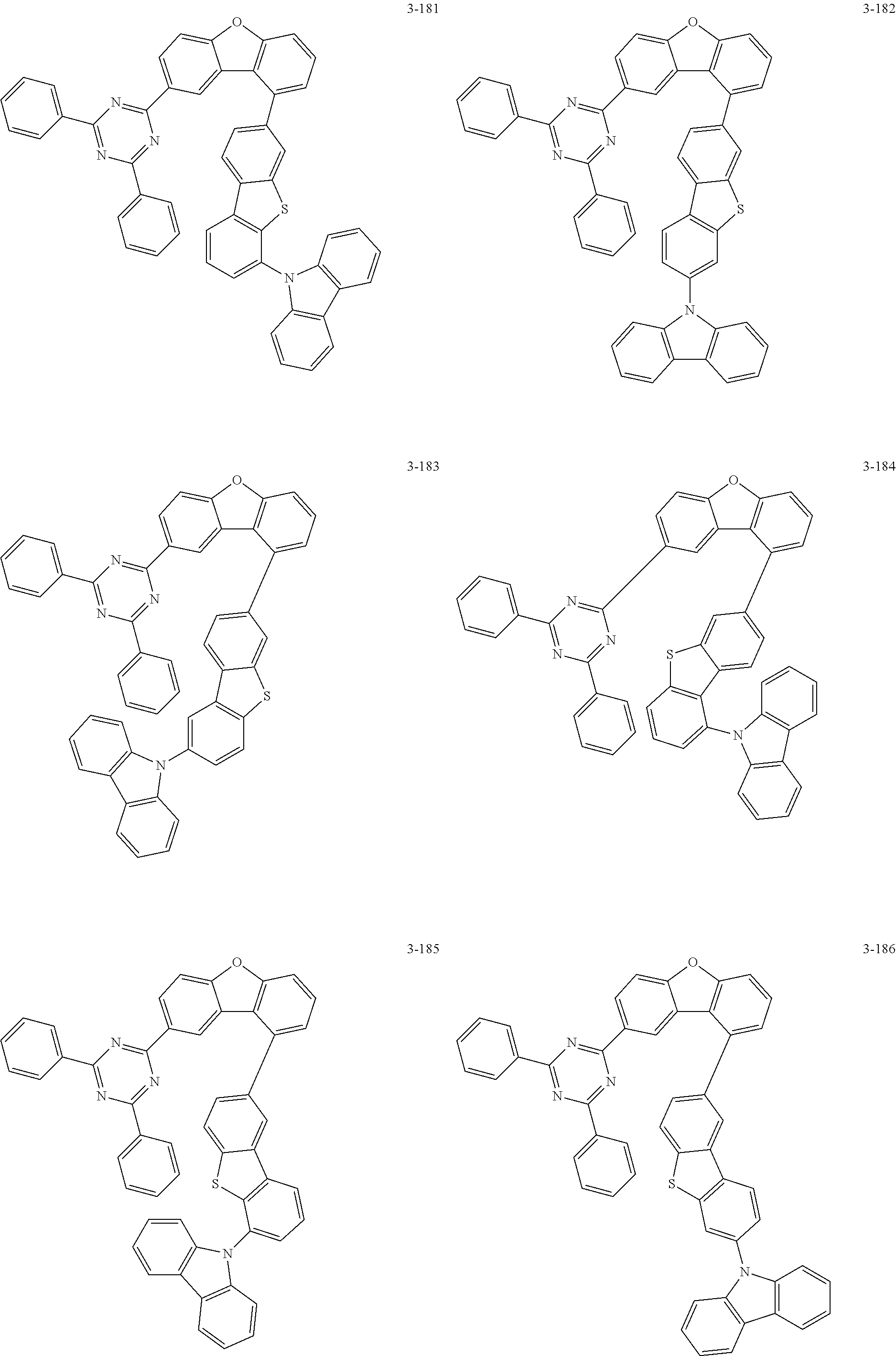

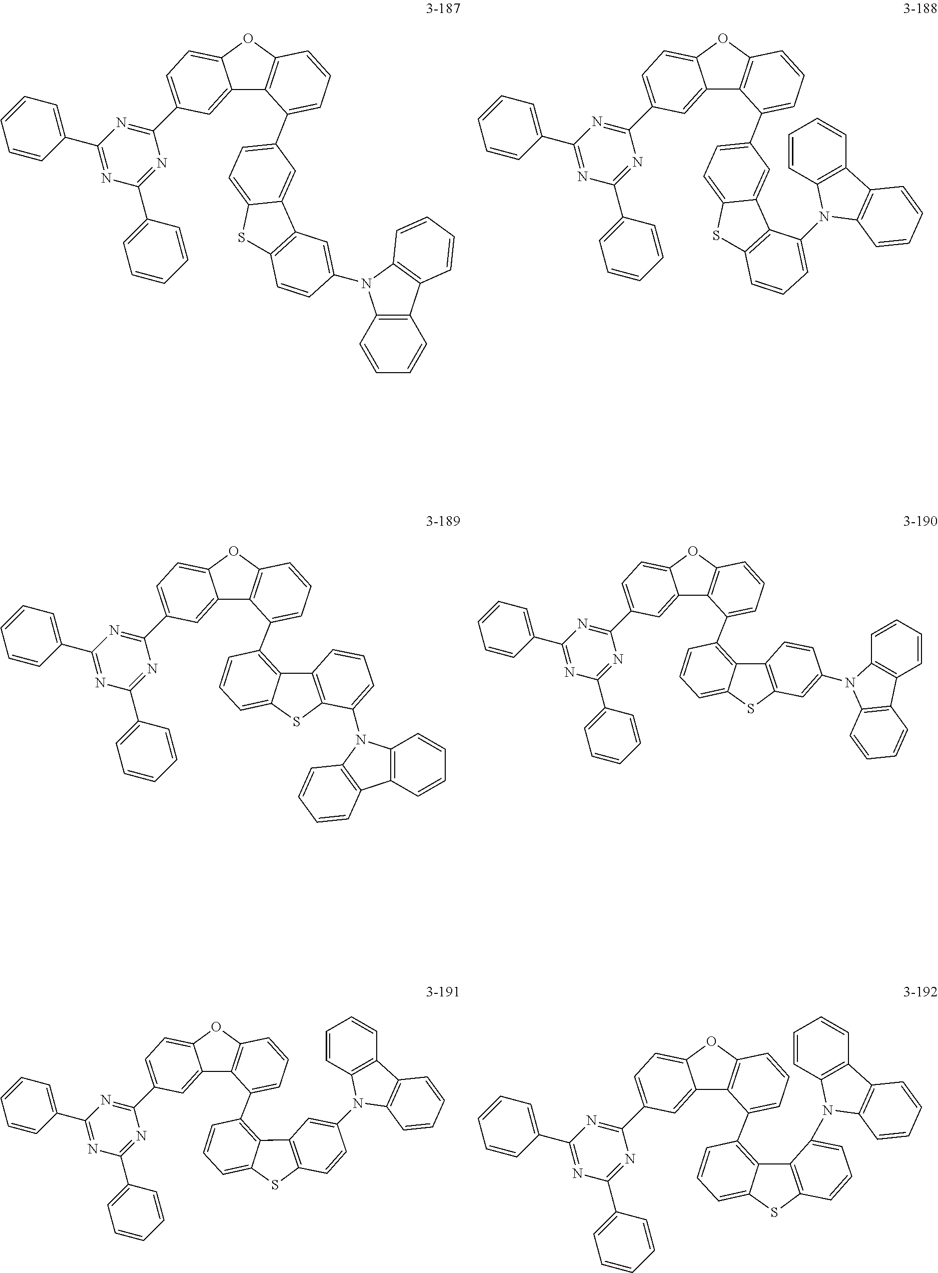

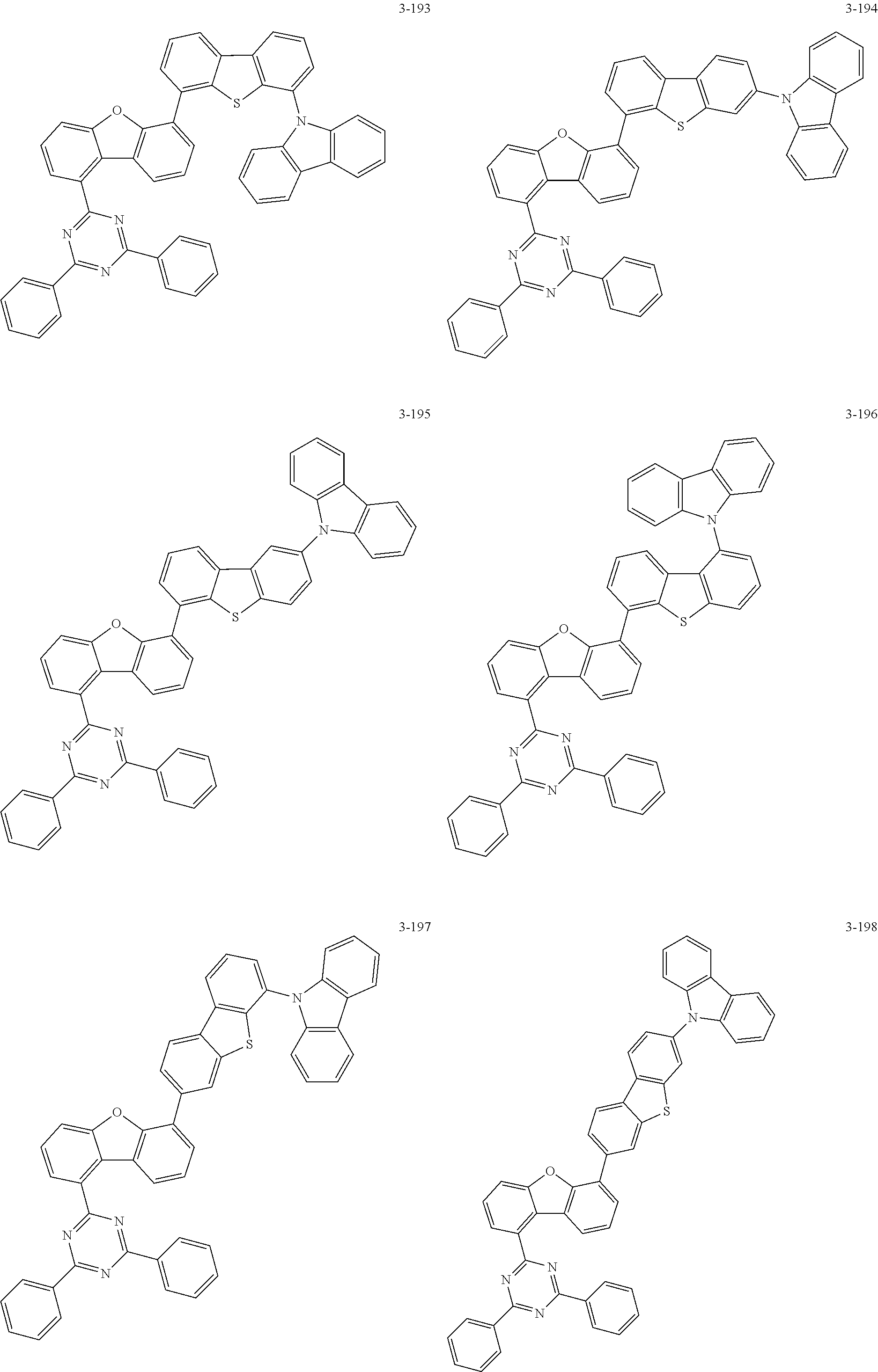

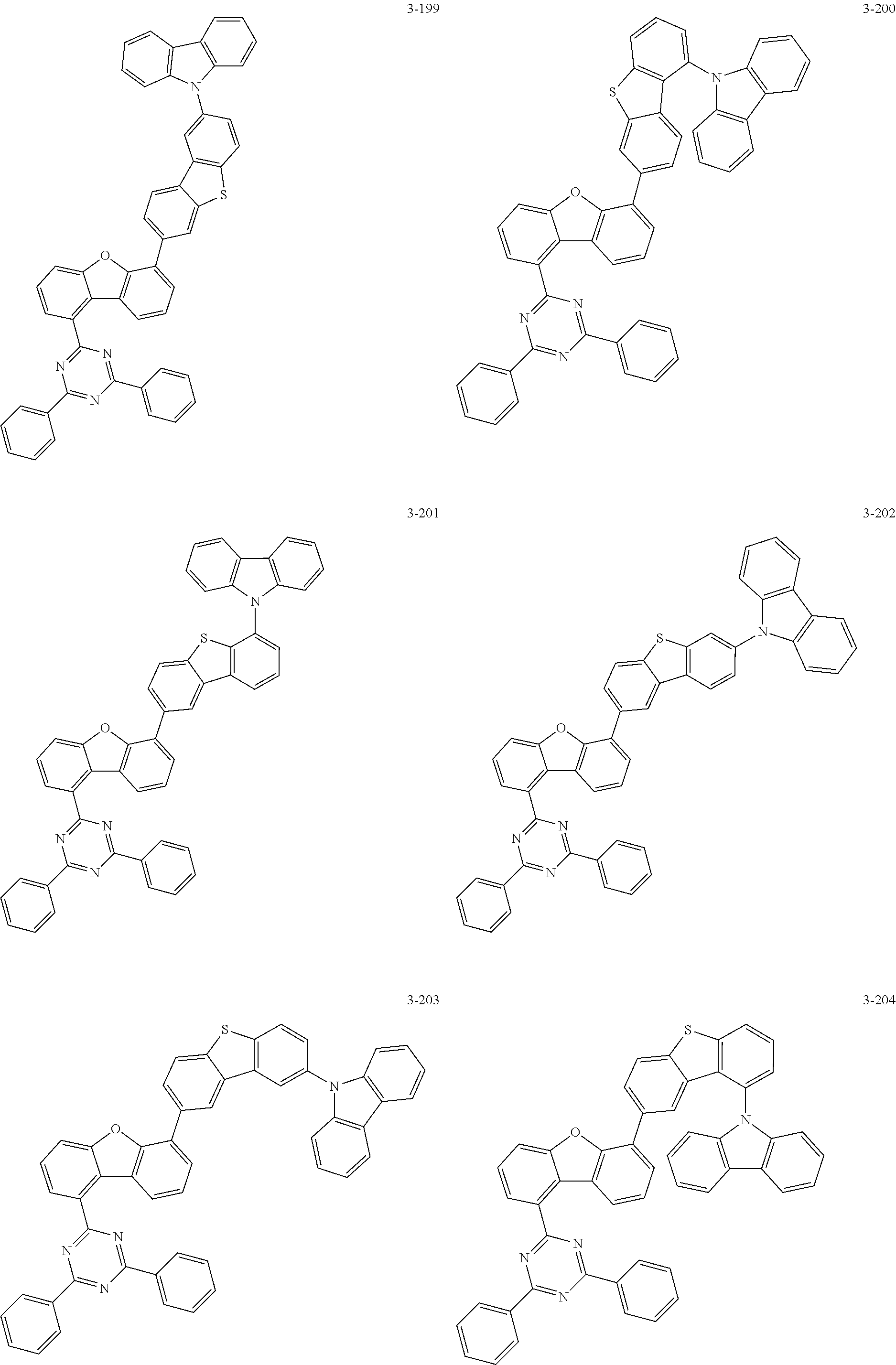

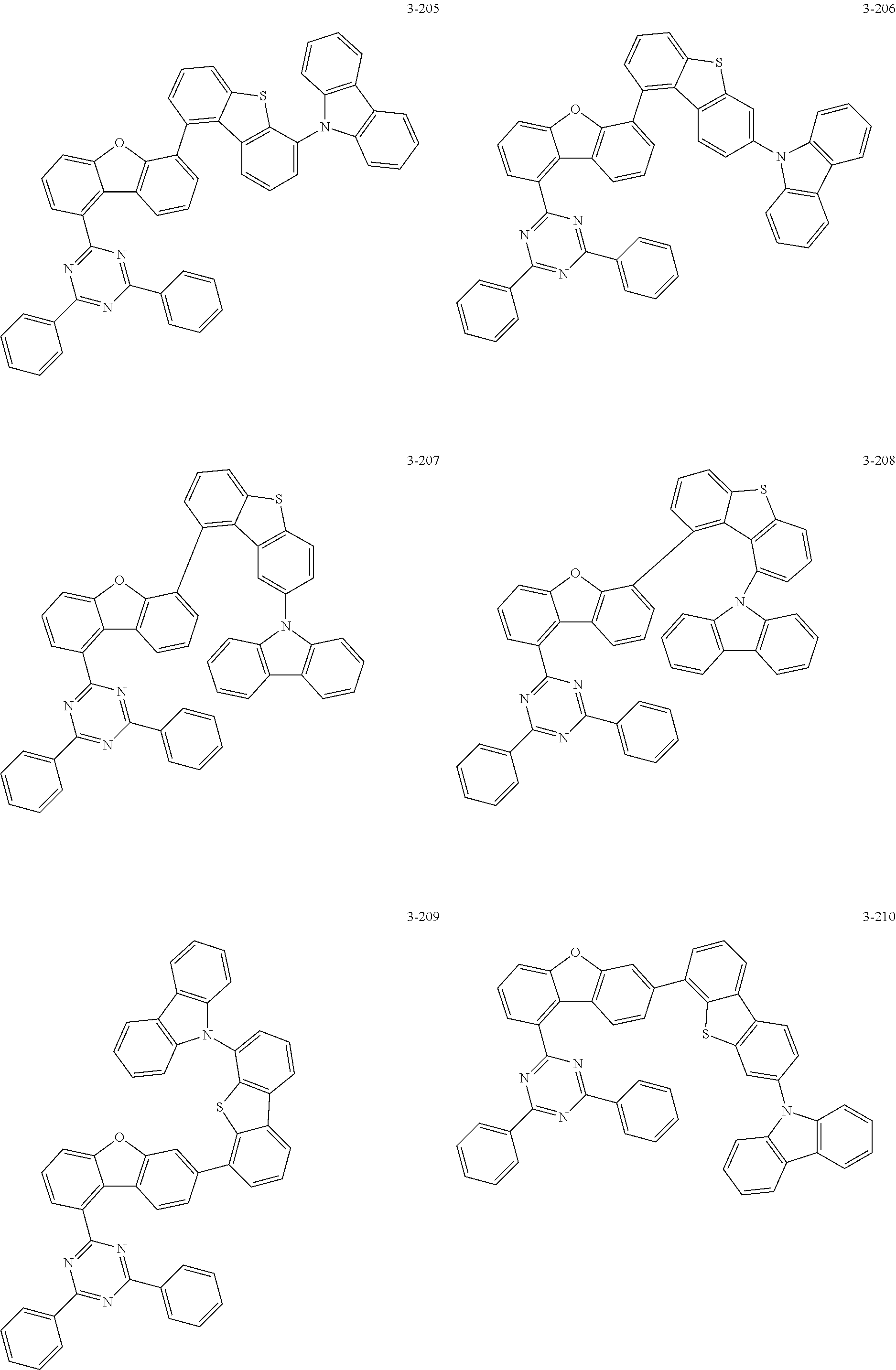

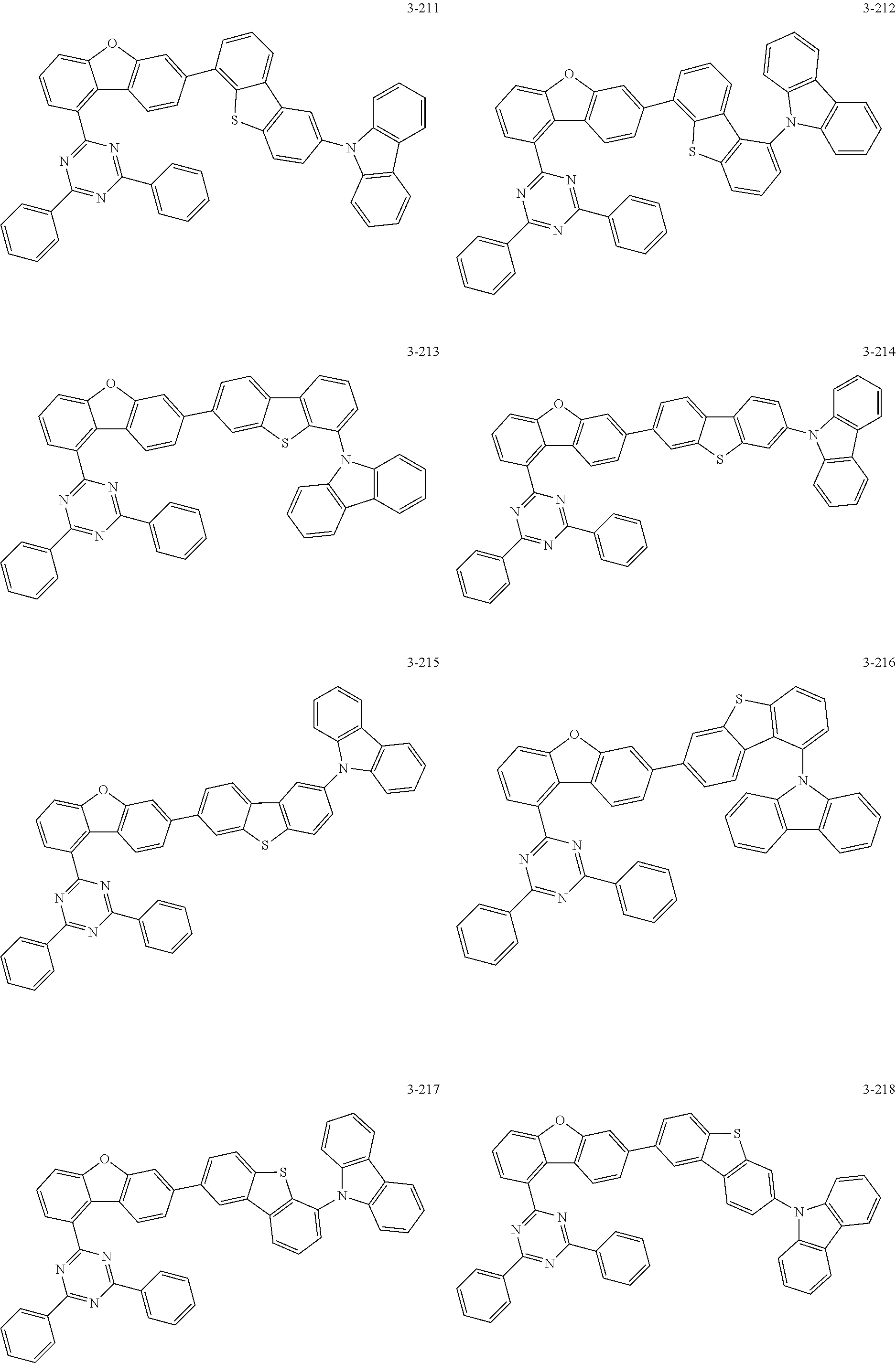

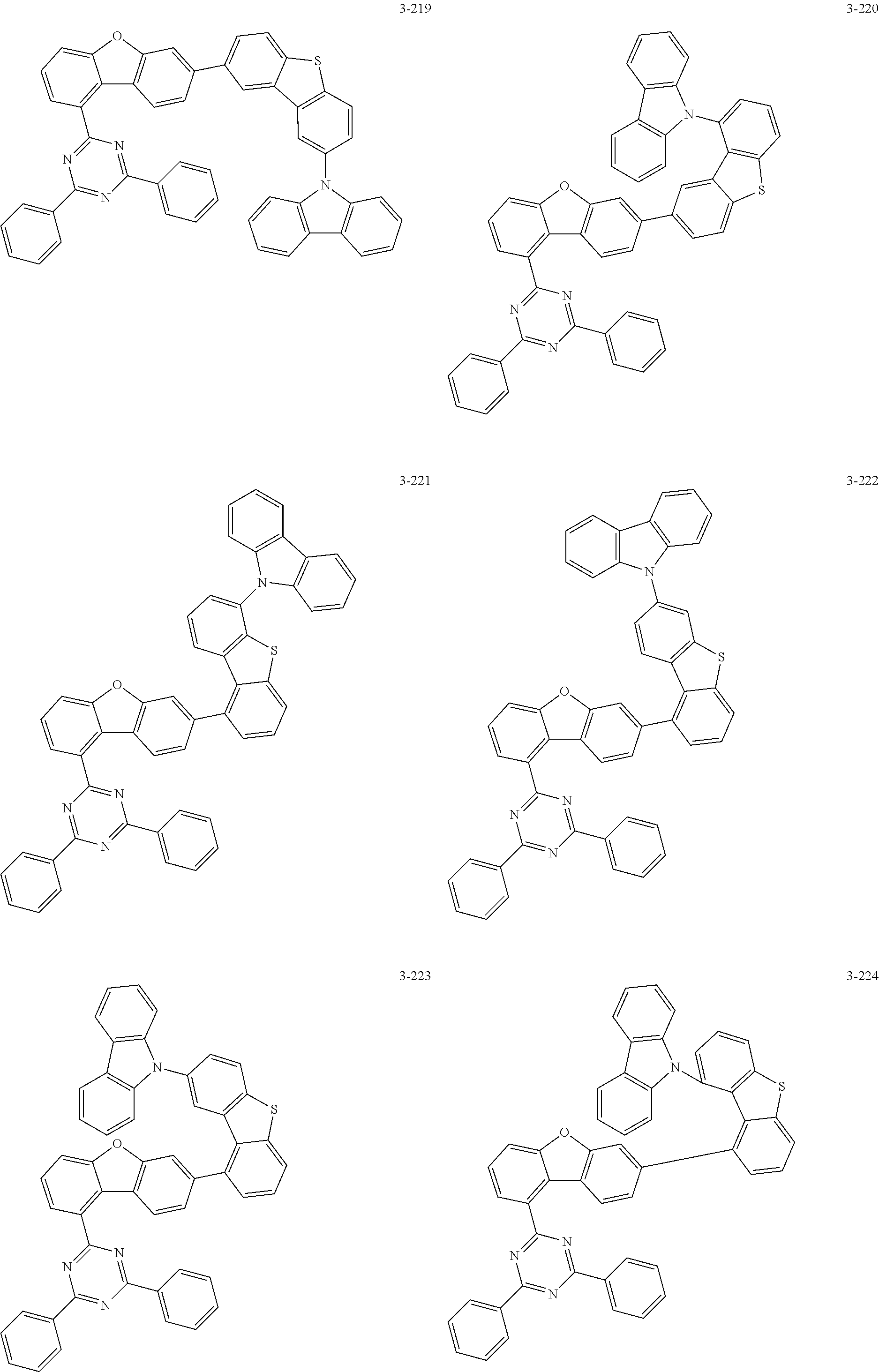

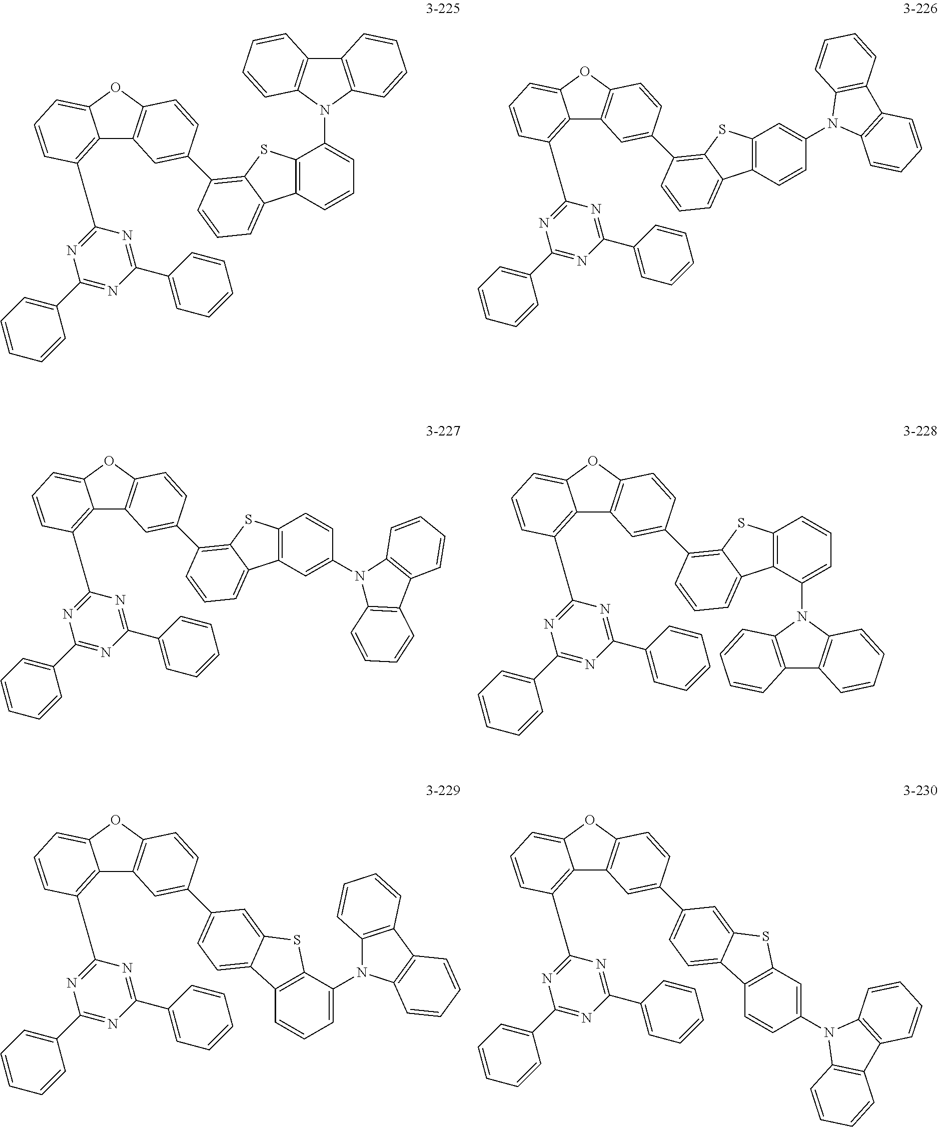

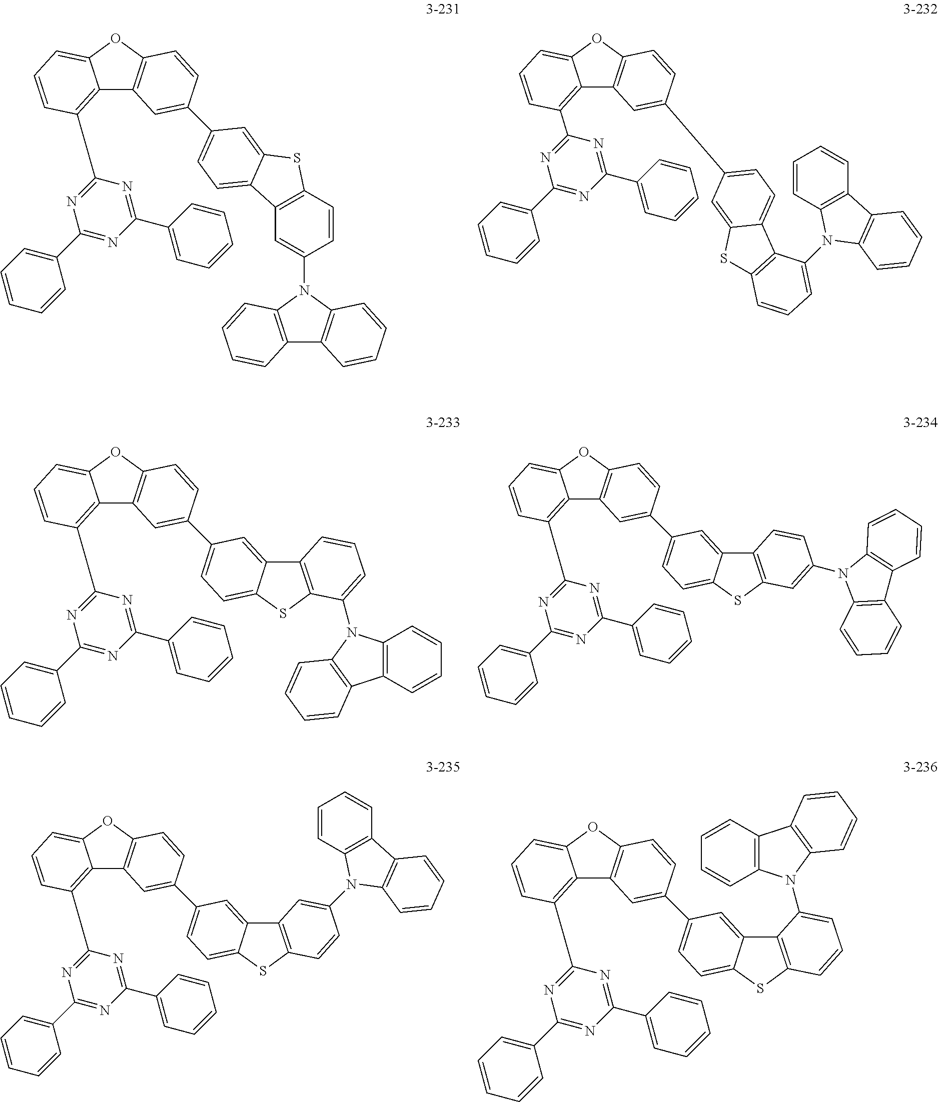

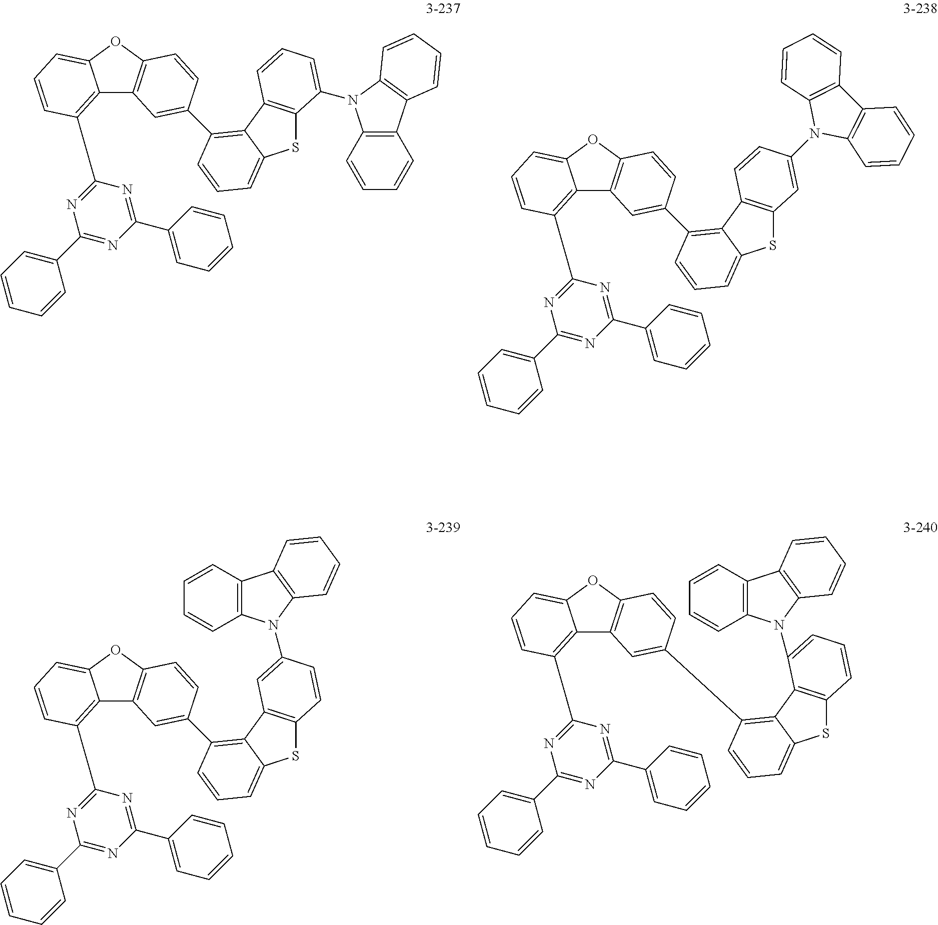 [SMILES: c1ccc(-c2nc(-c3ccccc3)nc(-c3cccc4oc5ccc(-c6cccc7sc8c(-n9c%10ccccc%10c%10ccccc%109)cccc8c67)cc5c34)n2)cc1 ; c1ccc(-c2nc(-c3ccccc3)nc(-c3cccc4oc5ccc(-c6cccc7sc8cc(-n9c%10ccccc%10c%10ccccc%109)ccc8c67)cc5c34)n2)cc1 ; c1ccc(-c2nc(-c3ccccc3)nc(-c3cccc4oc5ccc(-c6cccc7sc8ccc(-n9c%10ccccc%10c%10ccccc%109)cc8c67)cc5c34)n2)cc1 ; c1ccc(-c2nc(-c3ccccc3)nc(-c3cccc4oc5ccc(-c6cccc7sc8cccc(-n9c%10ccccc%10c%10ccccc%109)c8c67)cc5c34)n2)cc1]

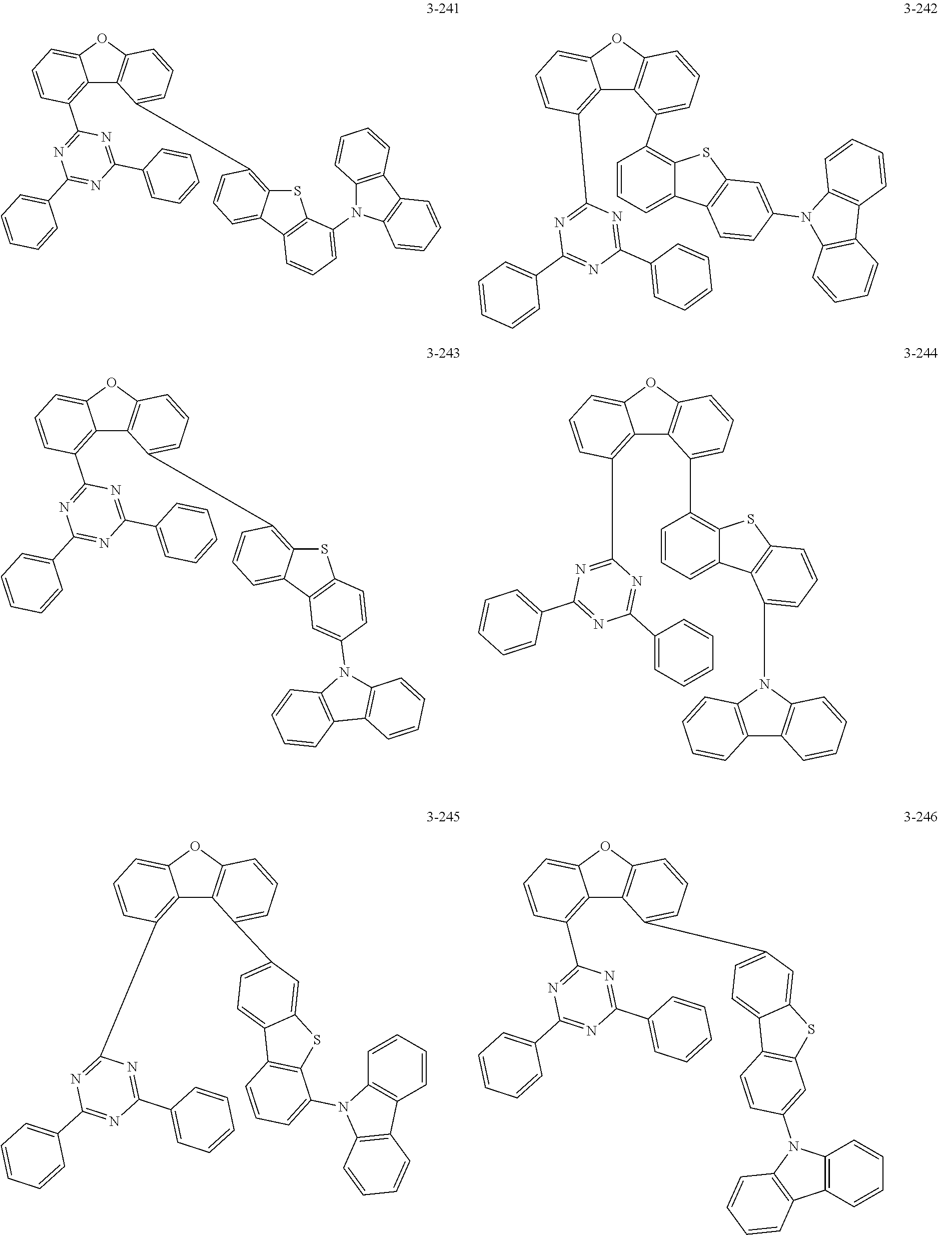

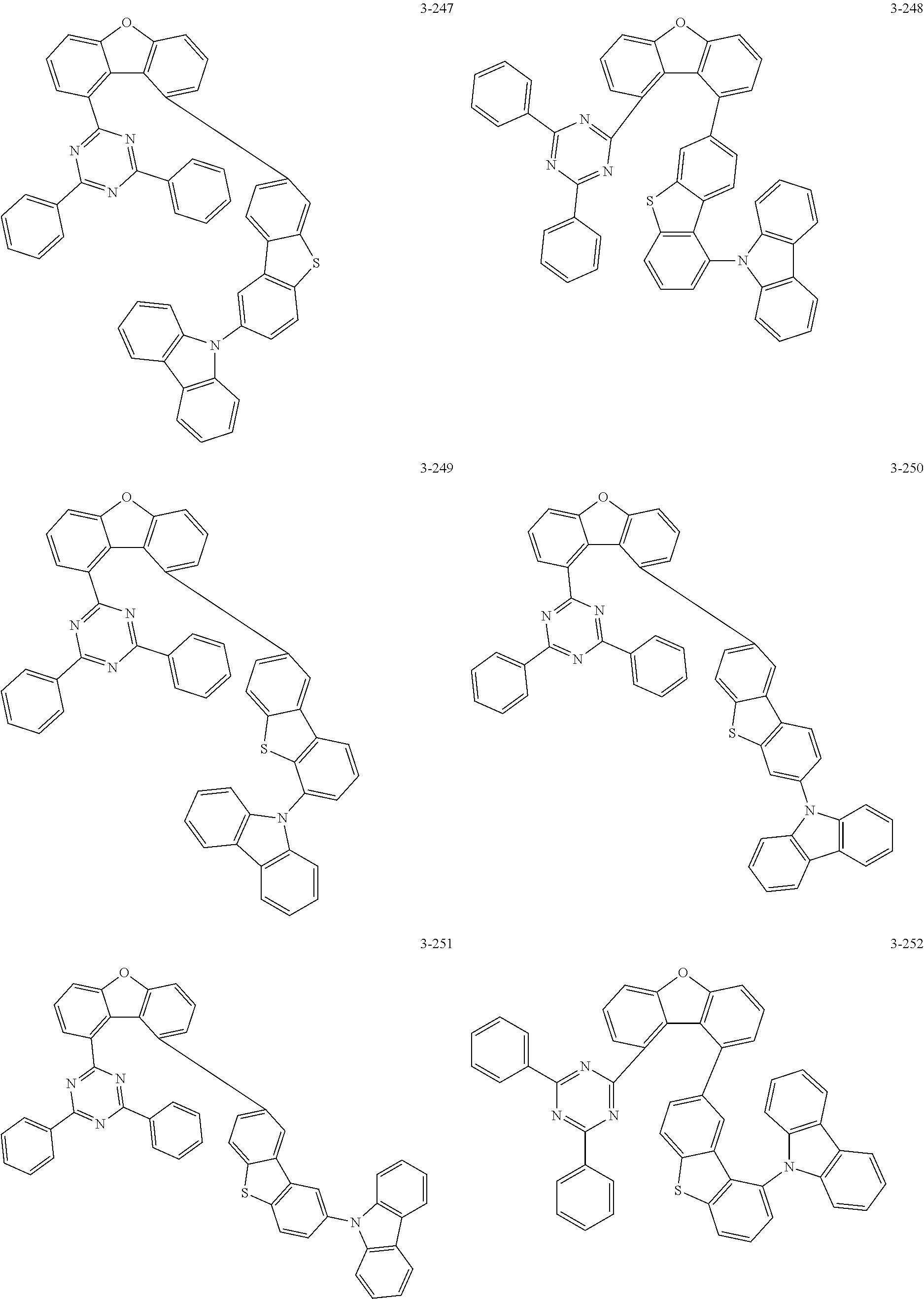

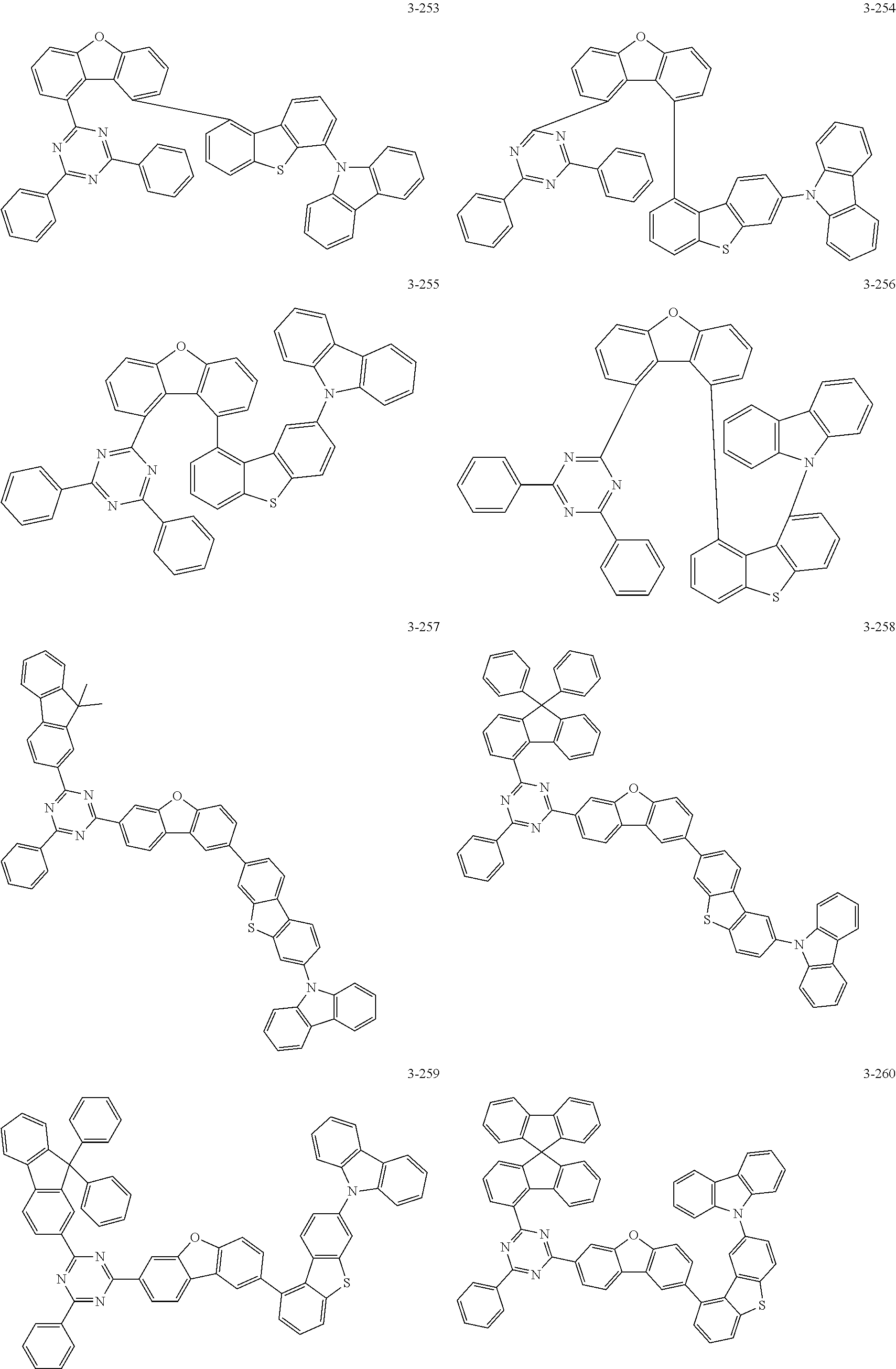

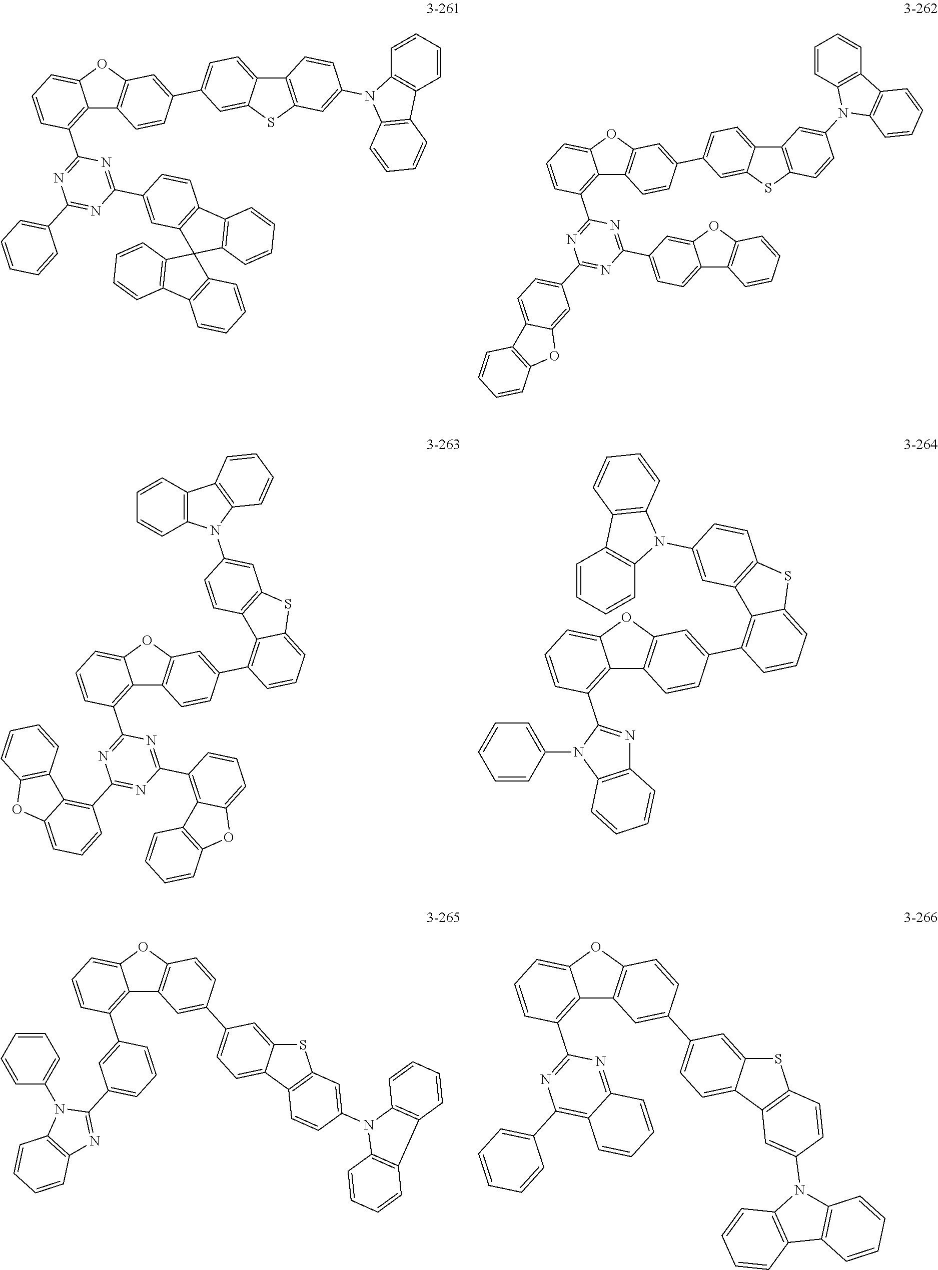

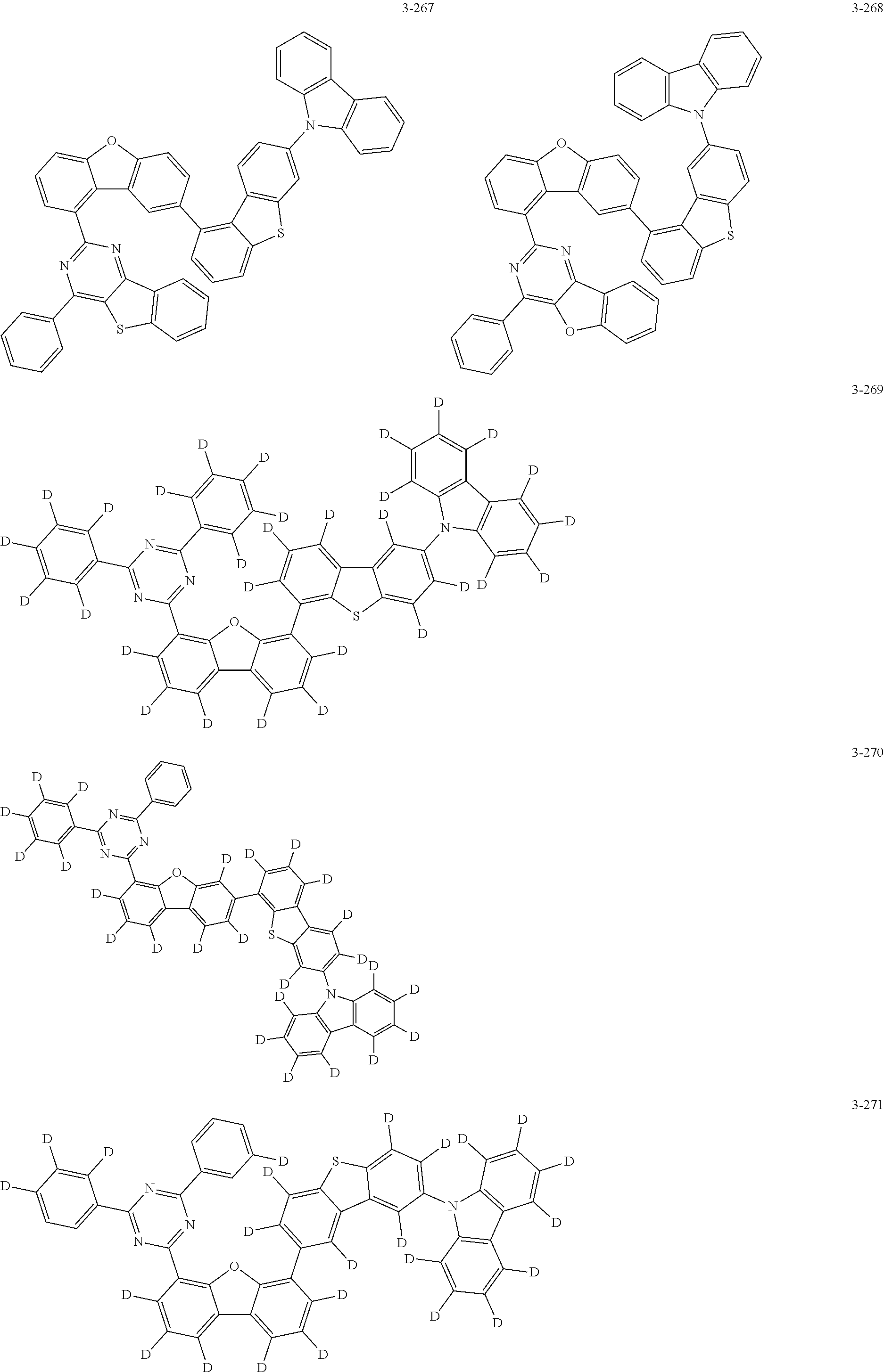

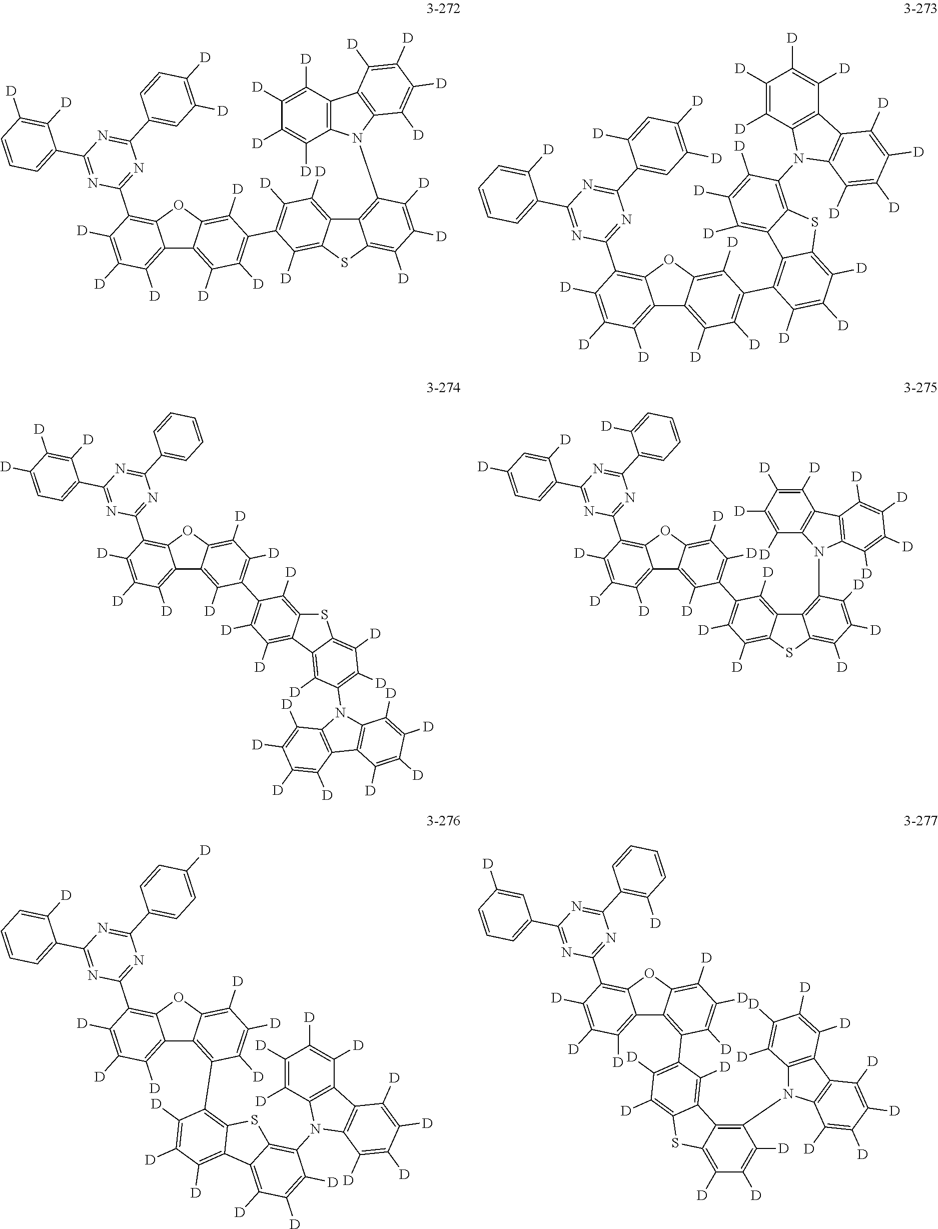

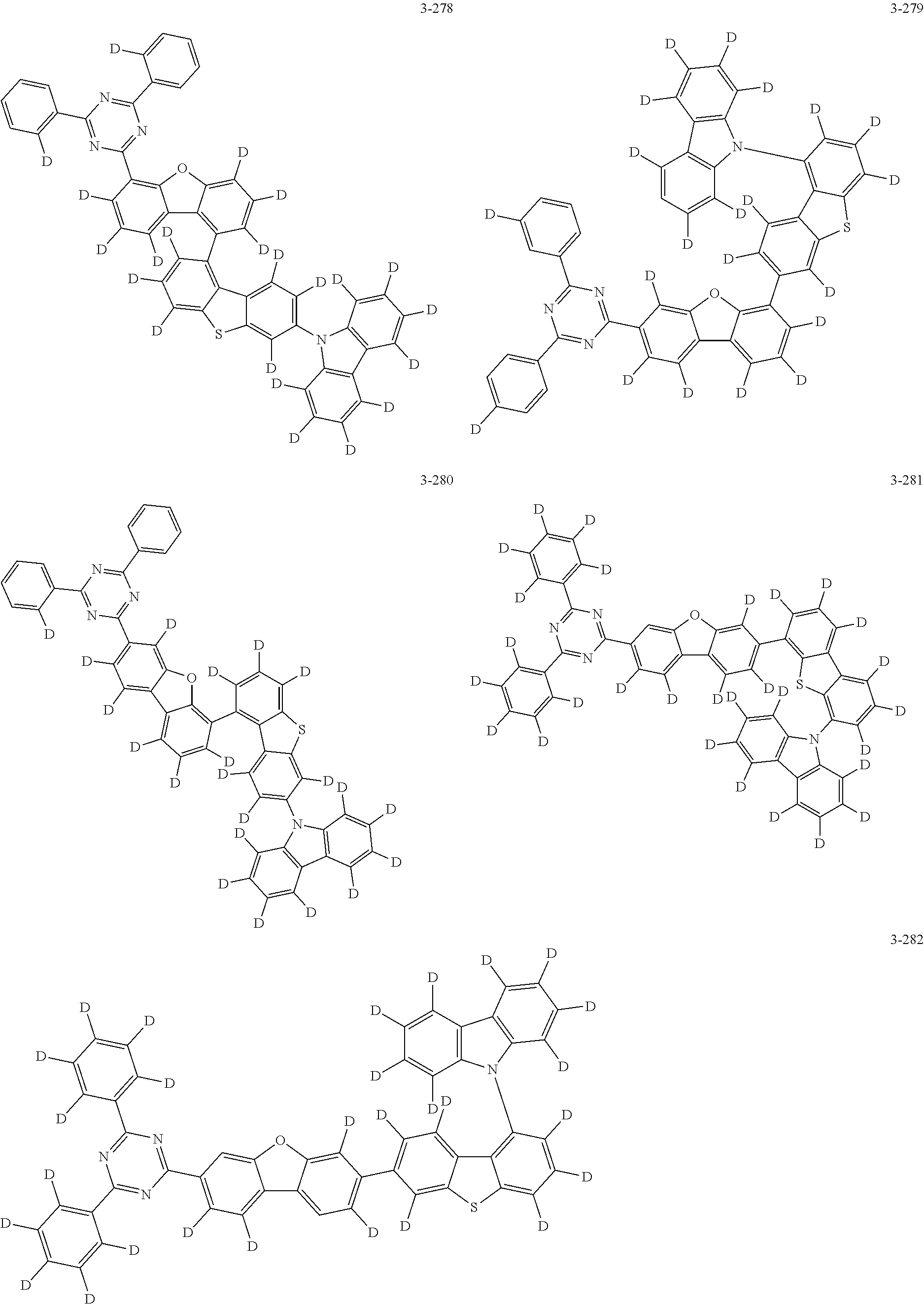

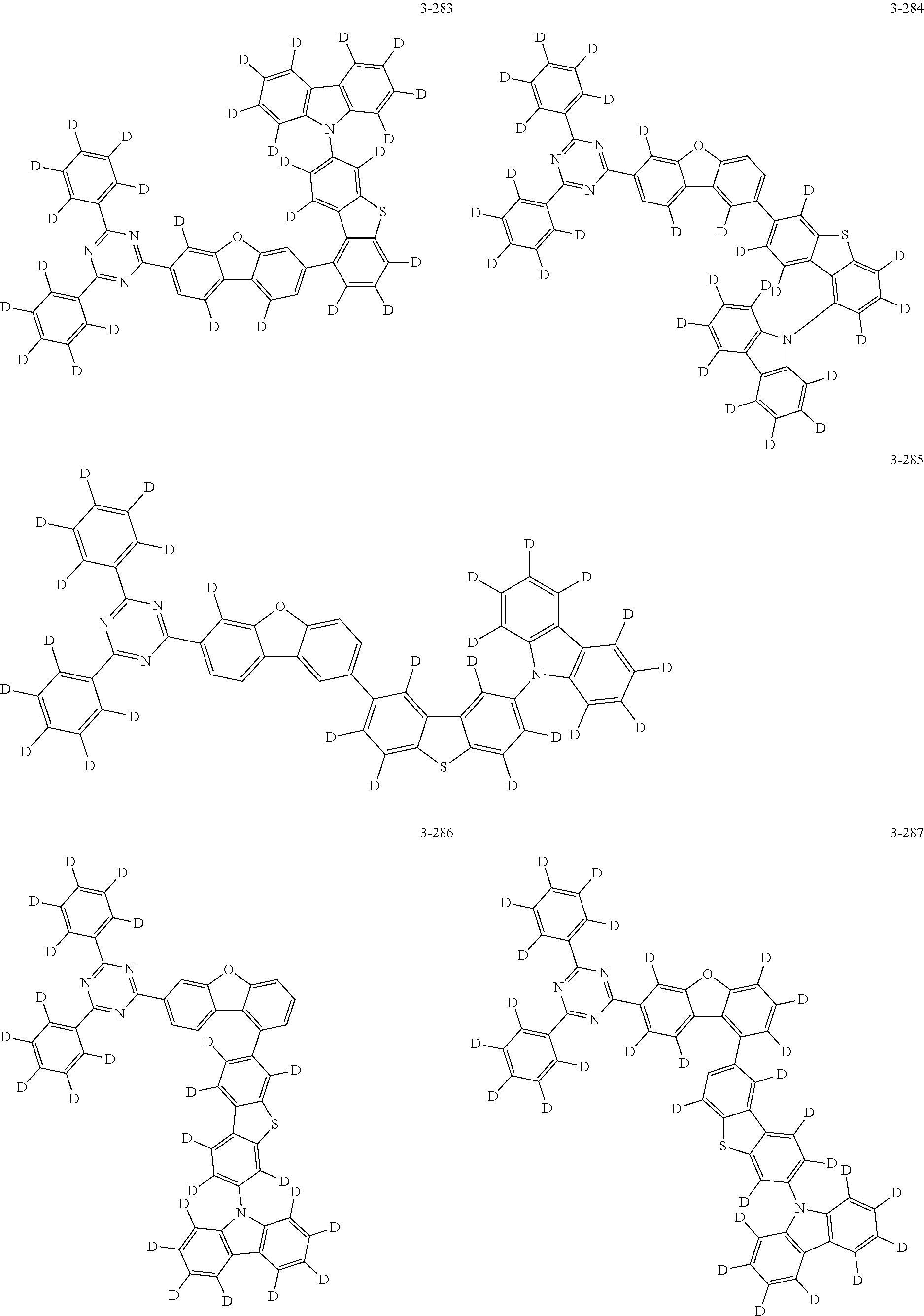

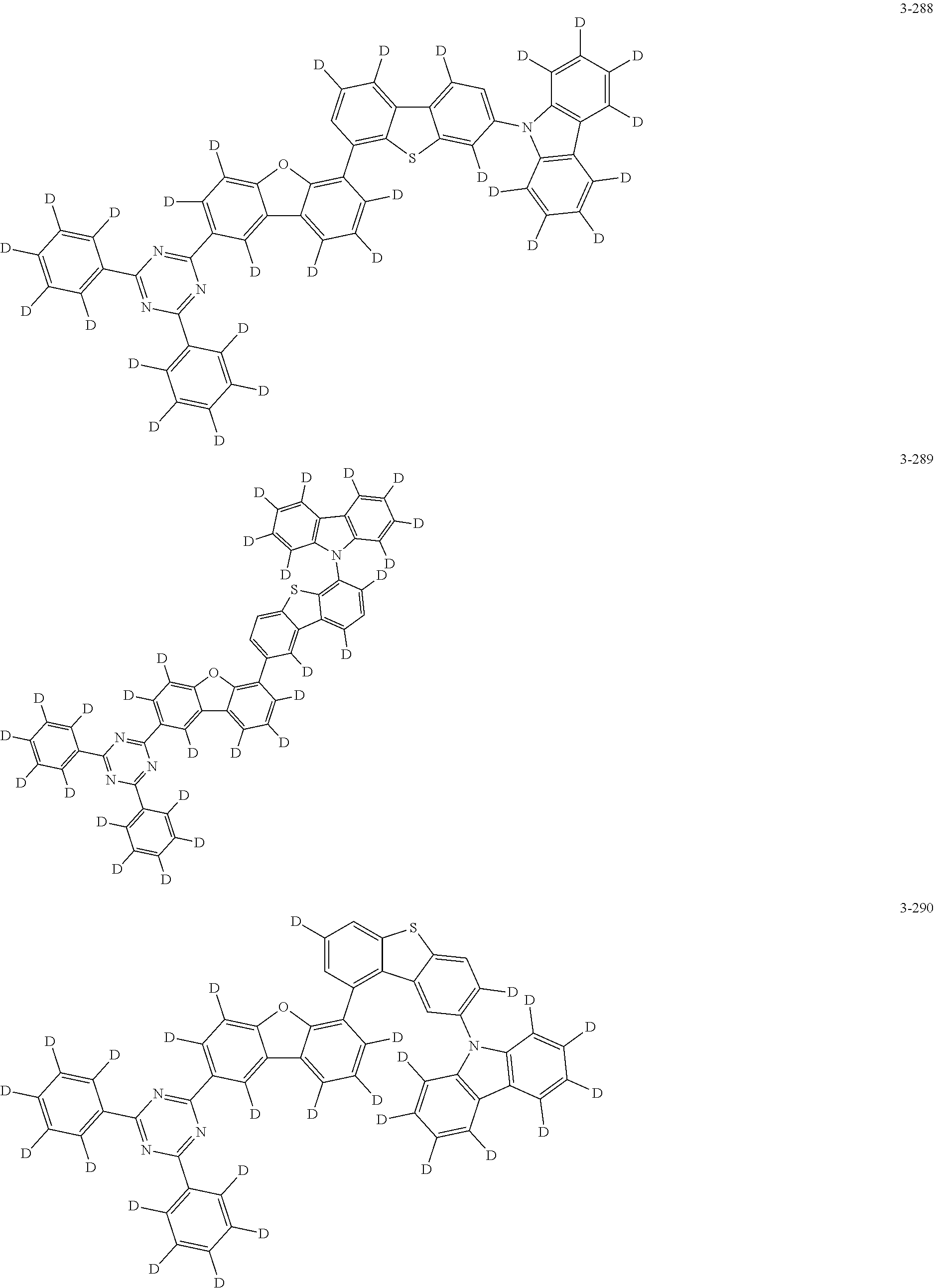

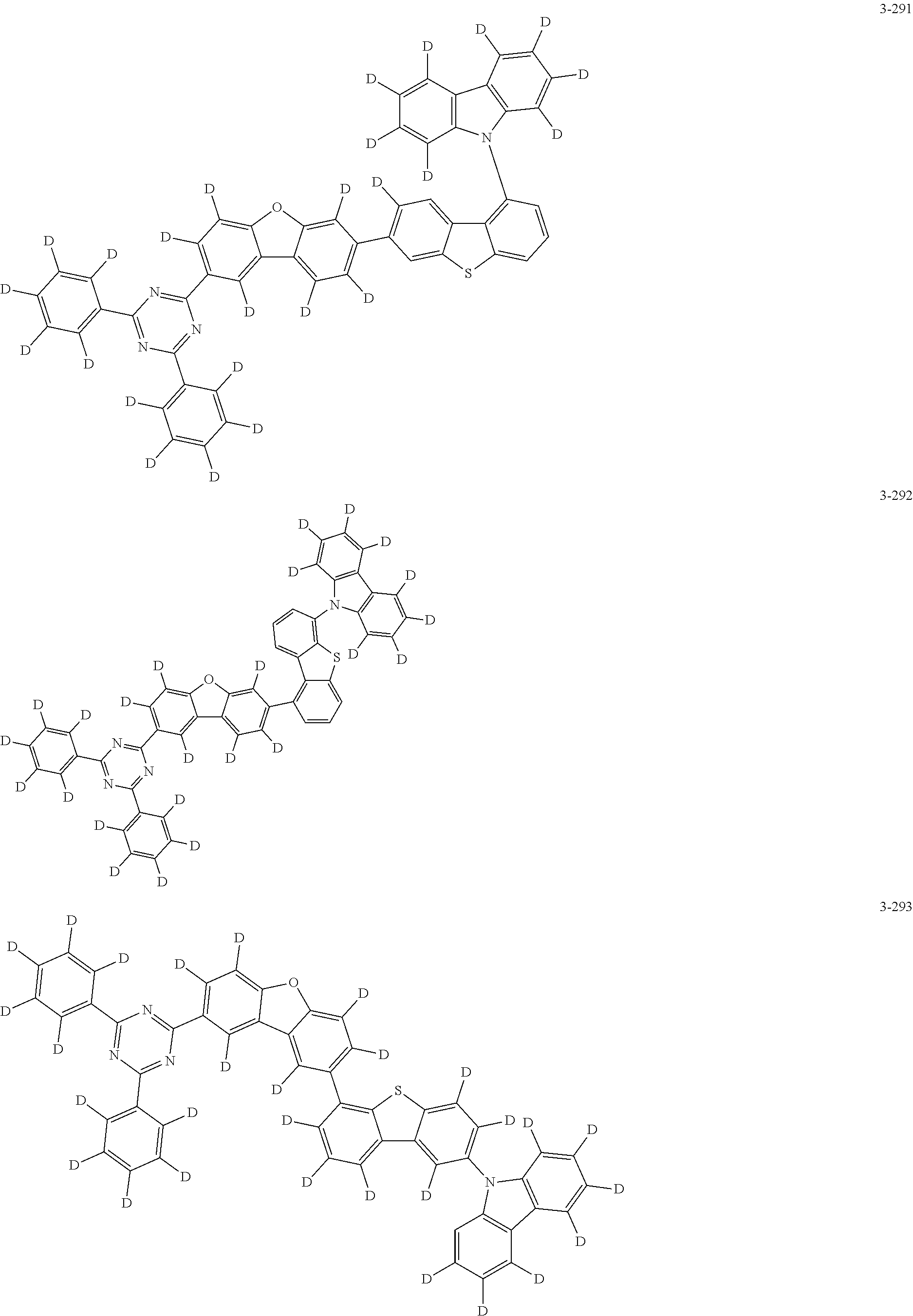

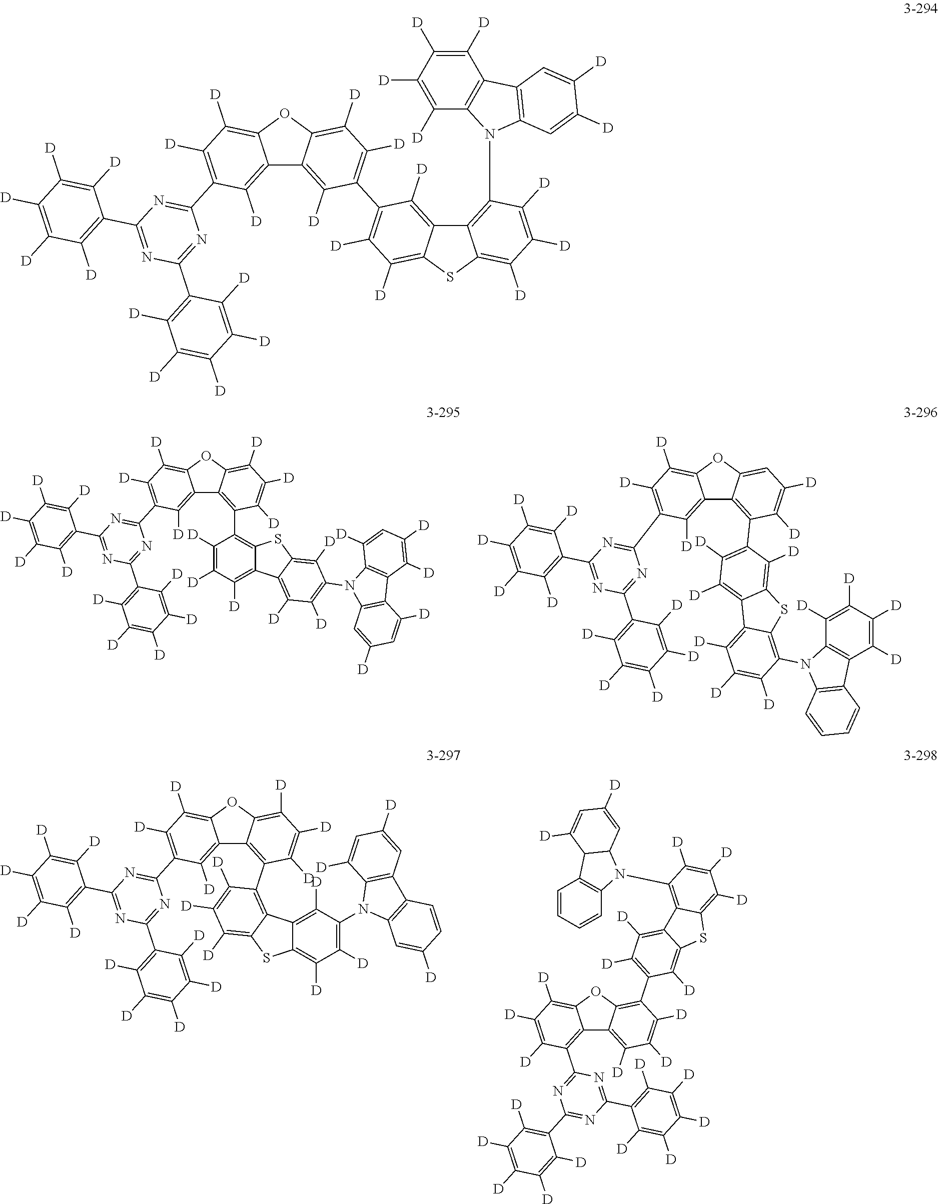

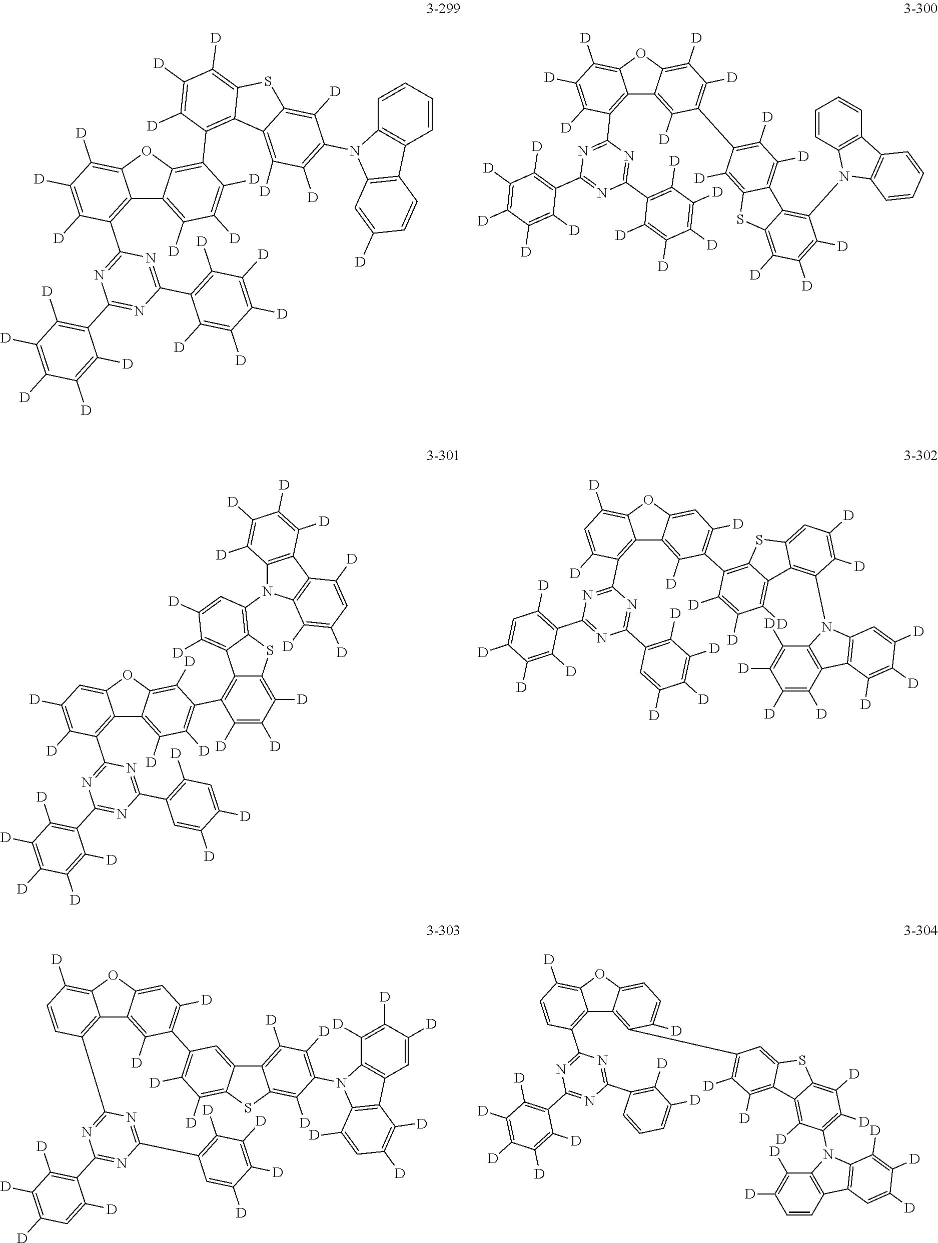

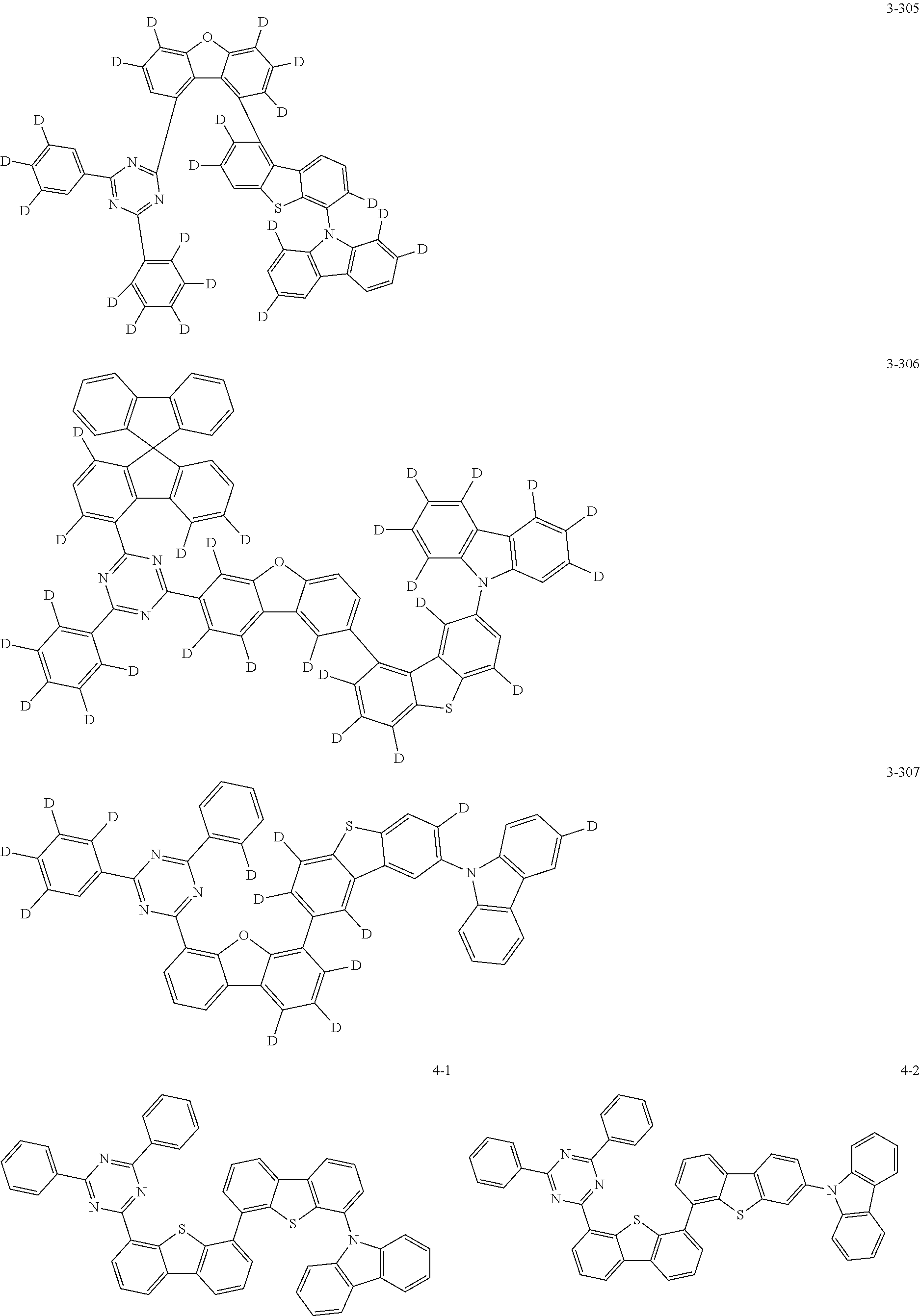

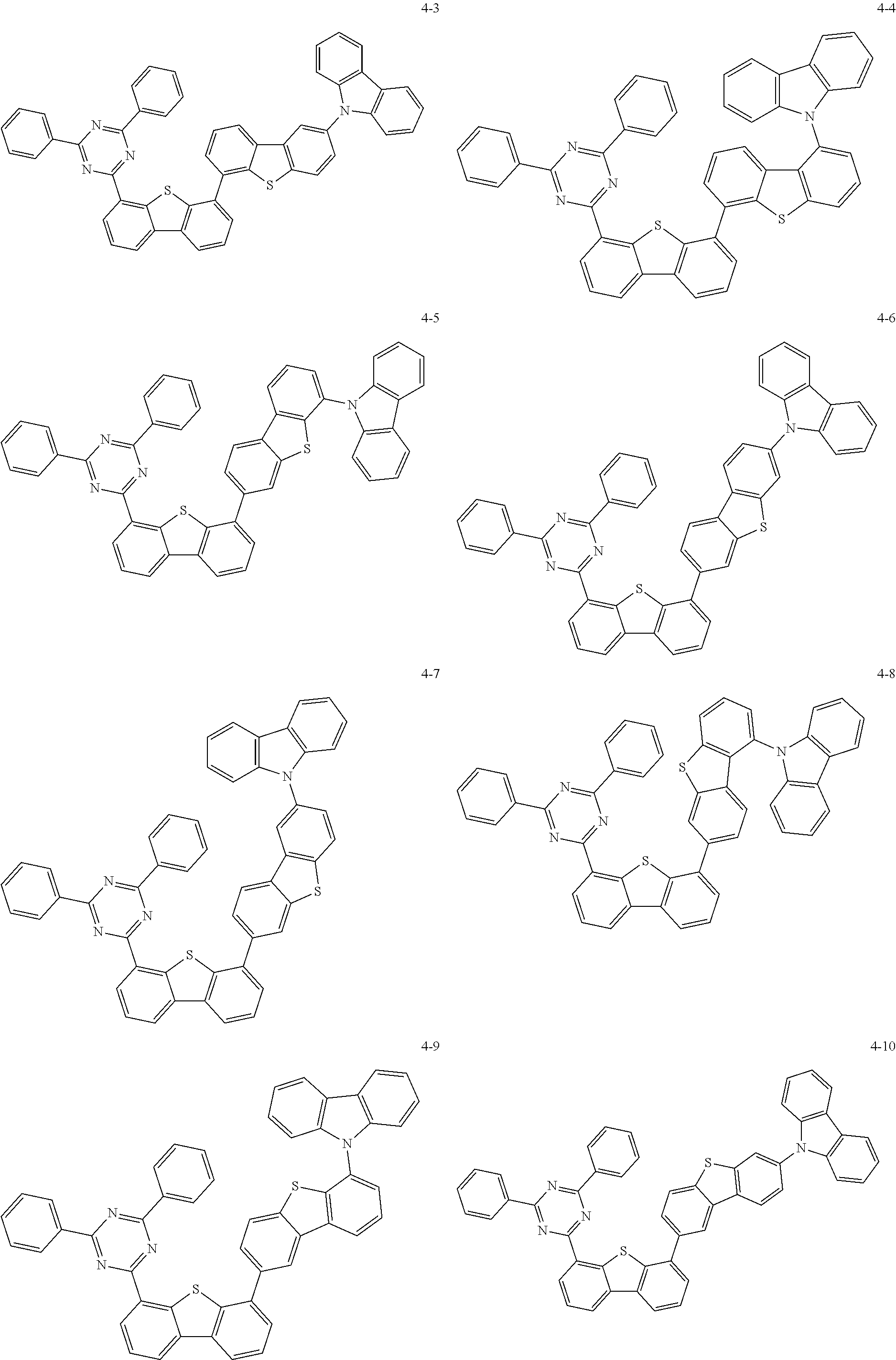

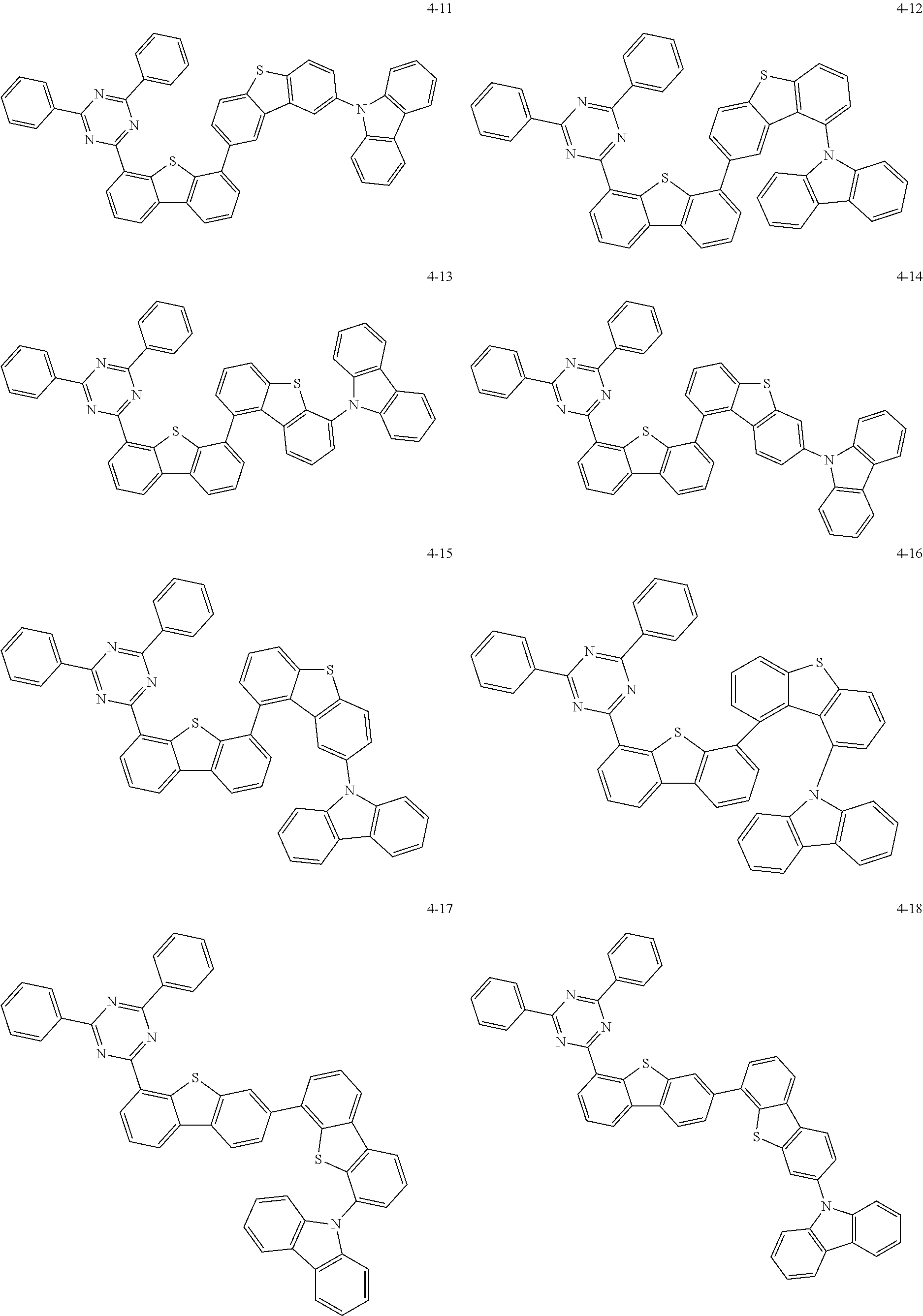

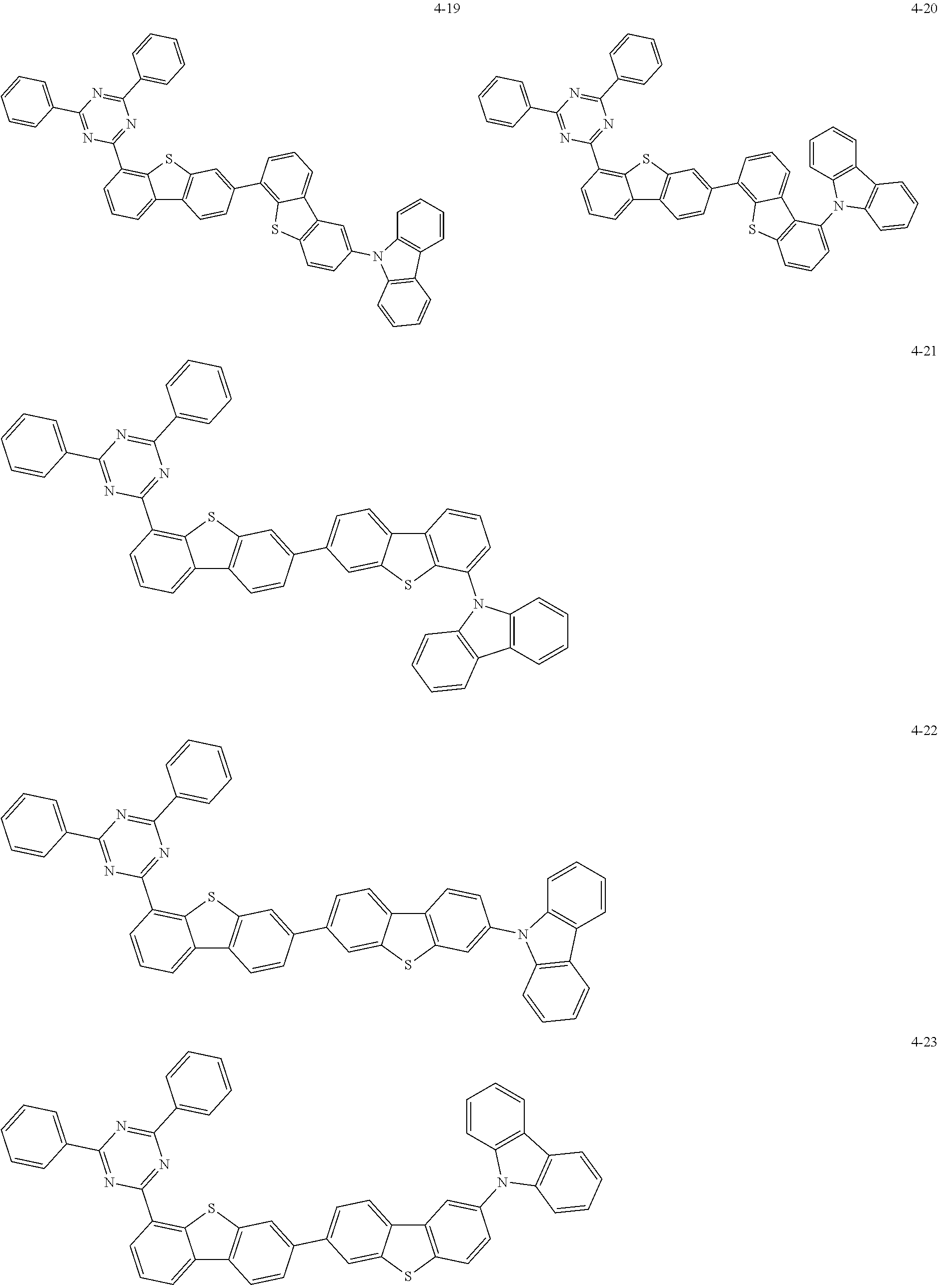 [SMILES: c1ccc(-c2nc(-c3ccccc3)nc(-c3cccc4c3sc3cc(-c5cccc6c5sc5ccc(-n7c8ccccc8c8ccccc87)cc56)ccc34)n2)cc1 ; c1ccc(-c2nc(-c3ccccc3)nc(-c3cccc4c3sc3cc(-c5cccc6c5sc5cccc(-n7c8ccccc8c8ccccc87)c56)ccc34)n2)cc1 ; c1ccc(-c2nc(-c3ccccc3)nc(-c3cccc4c3sc3cc(-c5ccc6c(c5)sc5c(-n7c8ccccc8c8ccccc87)cccc56)ccc34)n2)cc1 ; c1ccc(-c2nc(-c3ccccc3)nc(-c3cccc4c3sc3cc(-c5ccc6c(c5)sc5cc(-n7c8ccccc8c8ccccc87)ccc56)ccc34)n2)cc1 ; c1ccc(-c2nc(-c3ccccc3)nc(-c3cccc4c3sc3cc(-c5ccc6c(c5)sc5ccc(-n7c8ccccc8c8ccccc87)cc56)ccc34)n2)cc1]

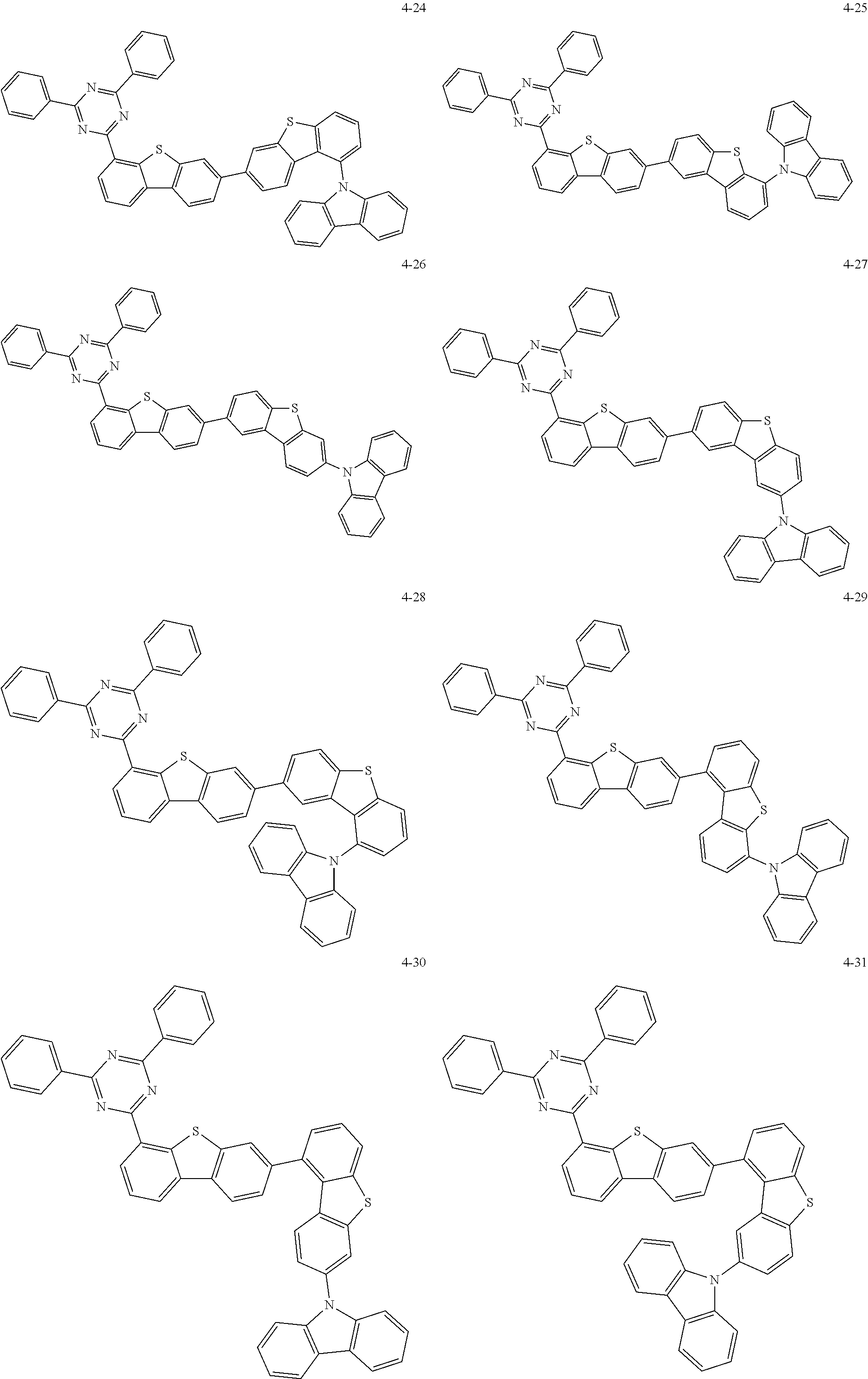

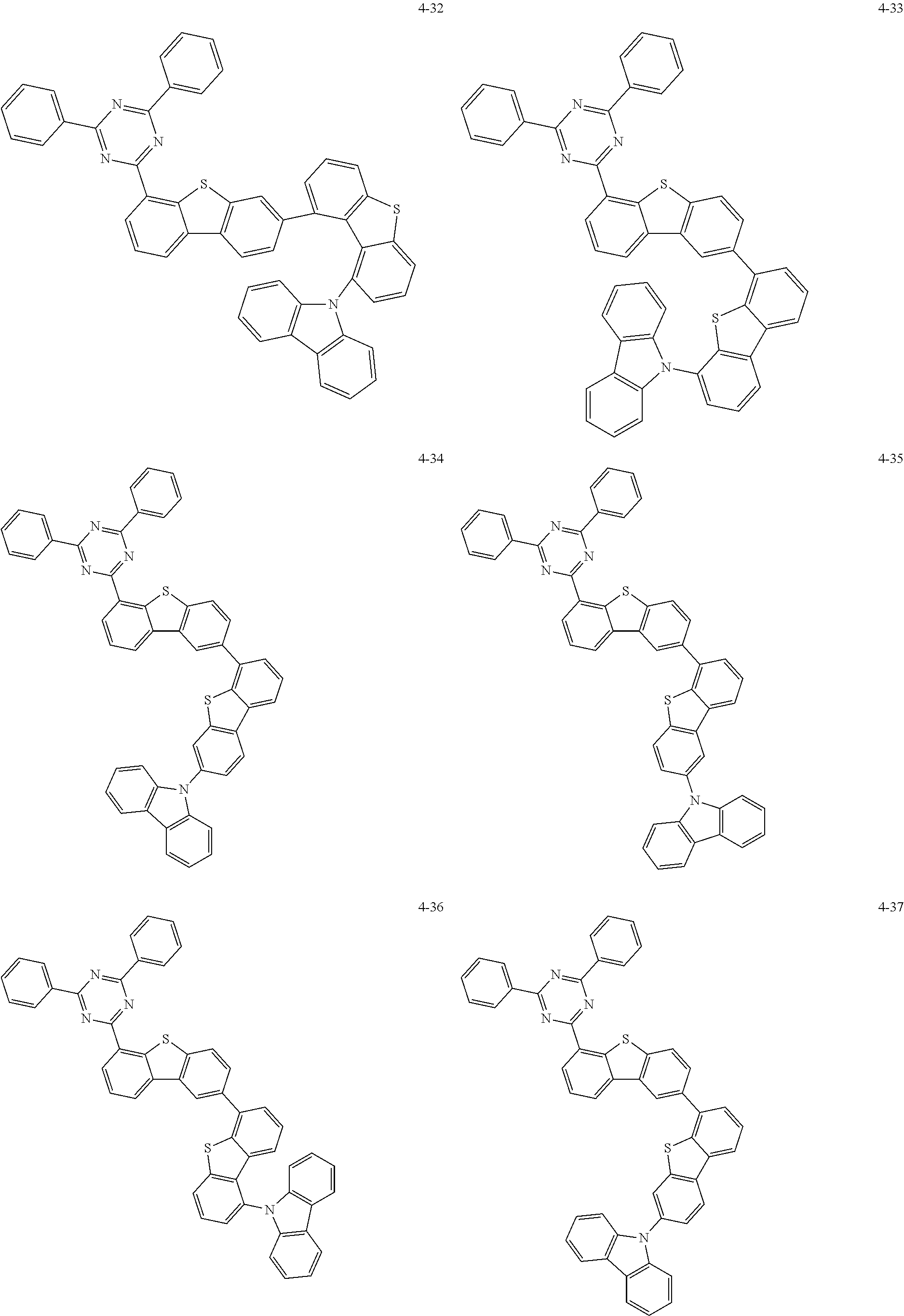

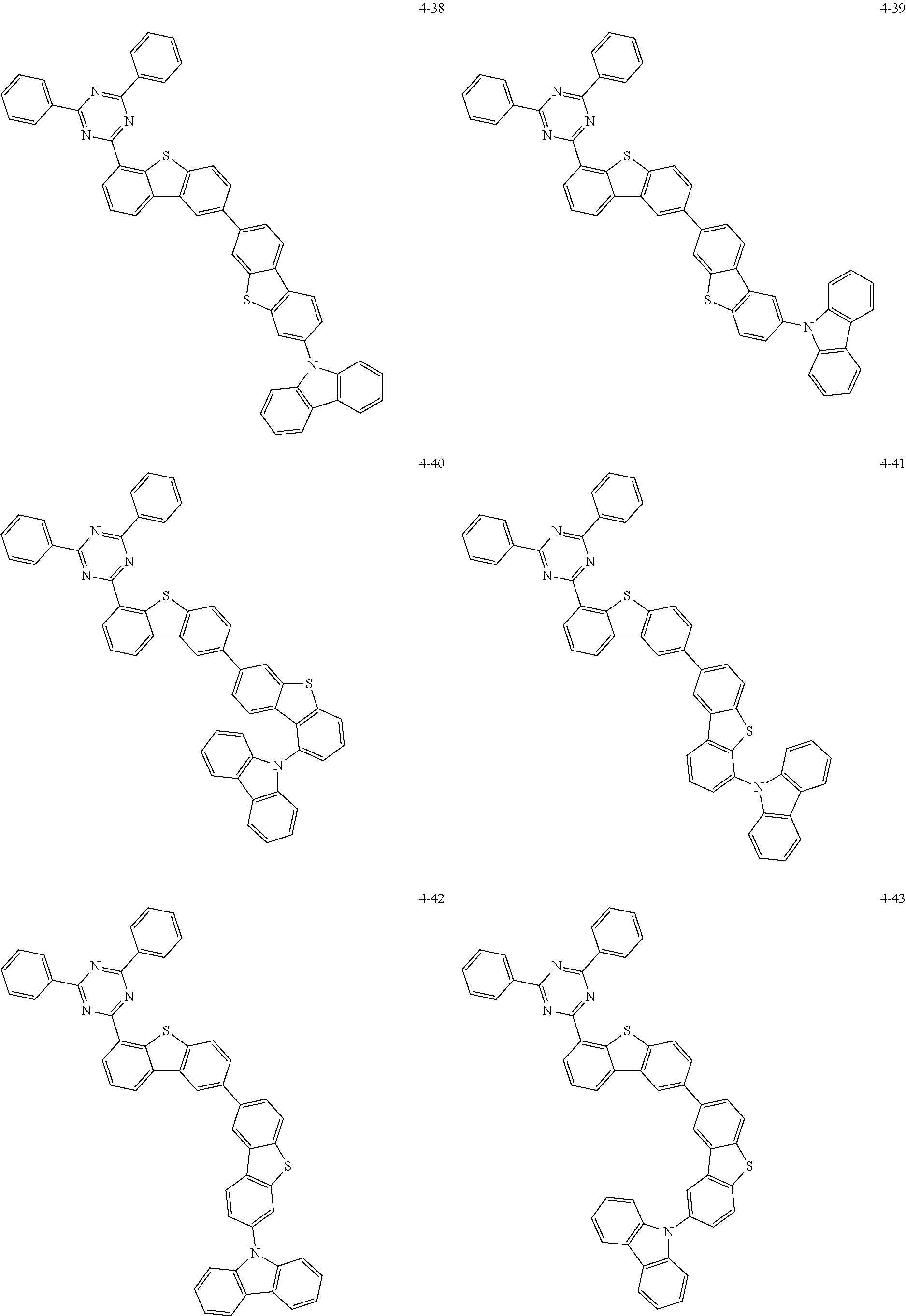

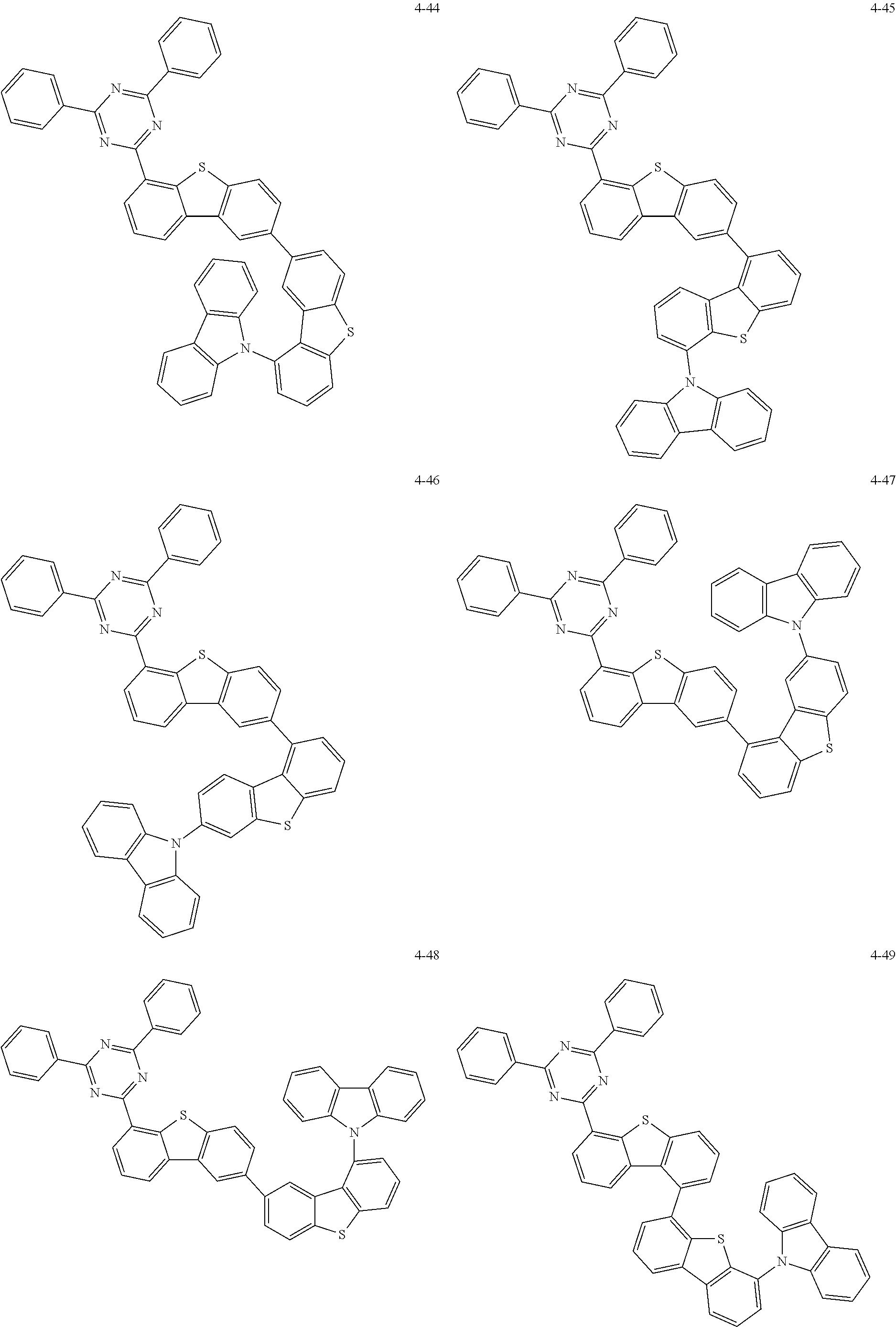

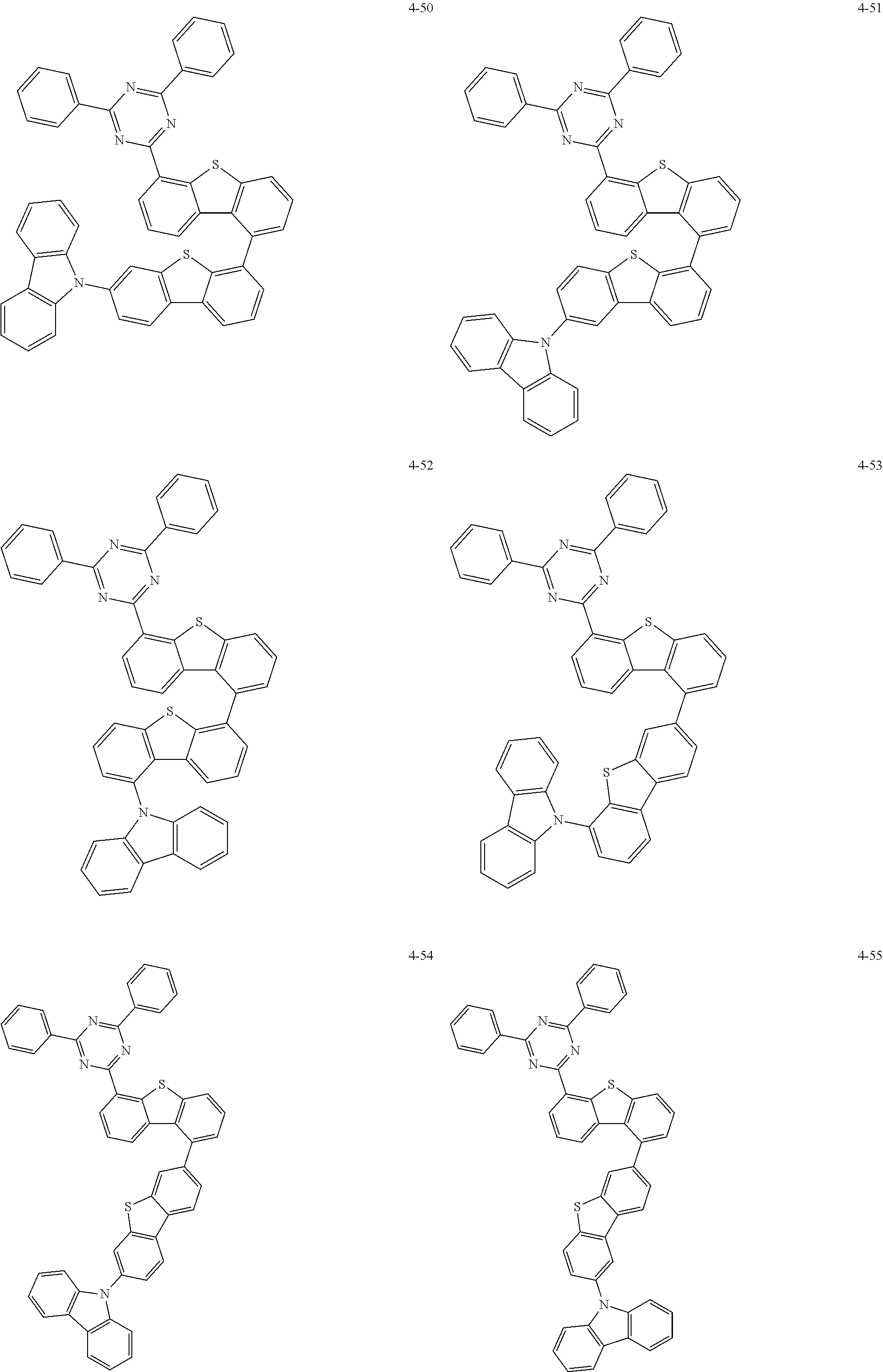

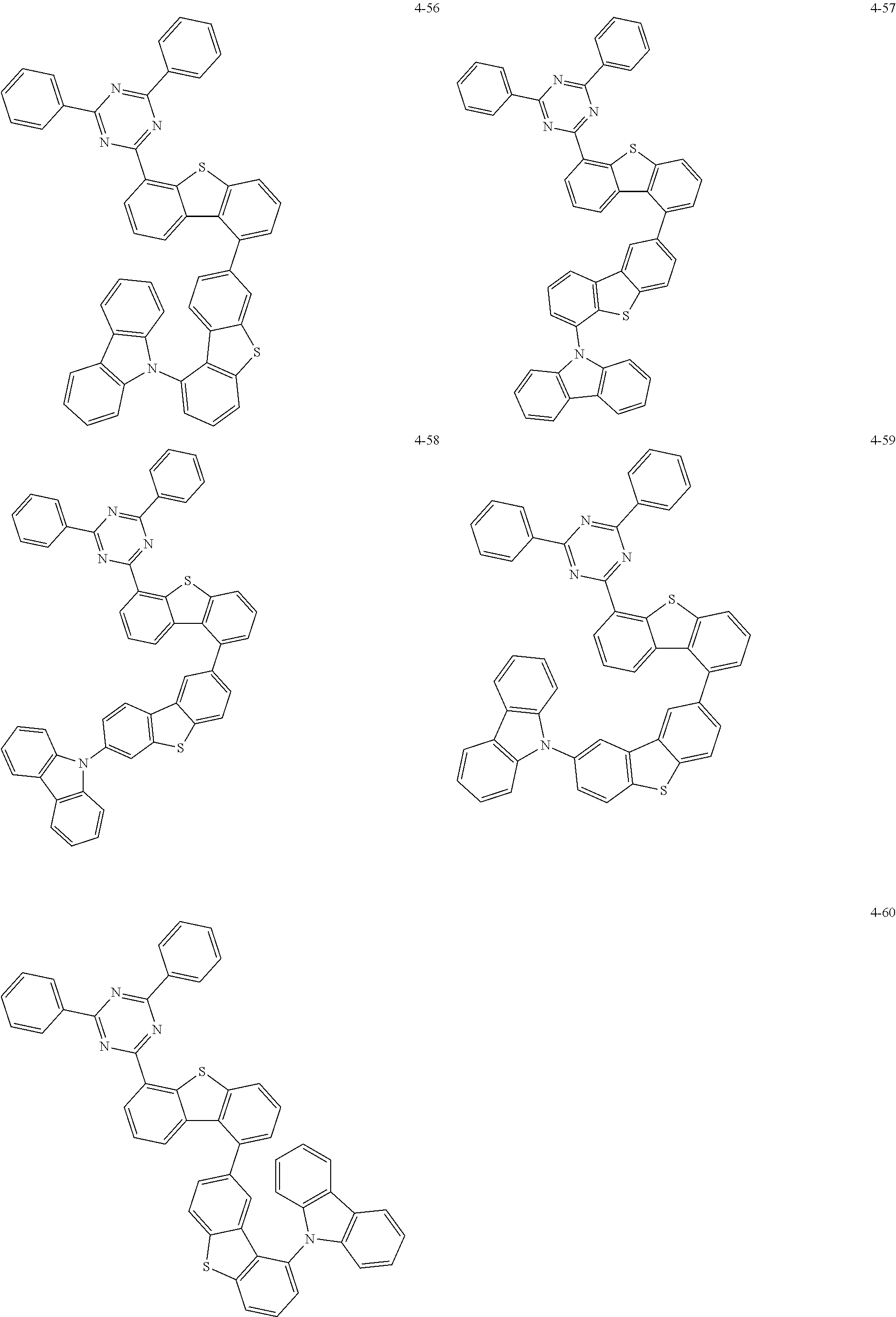

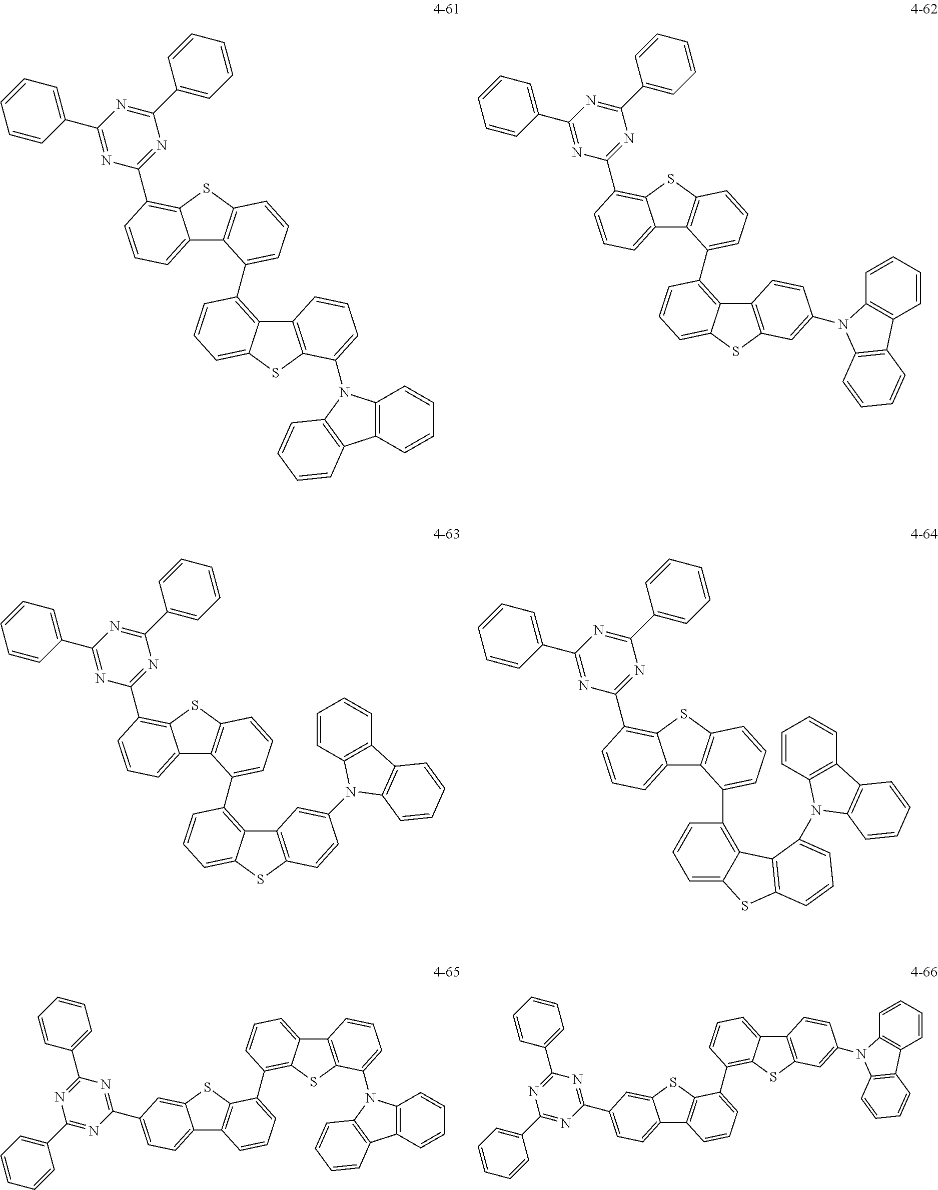

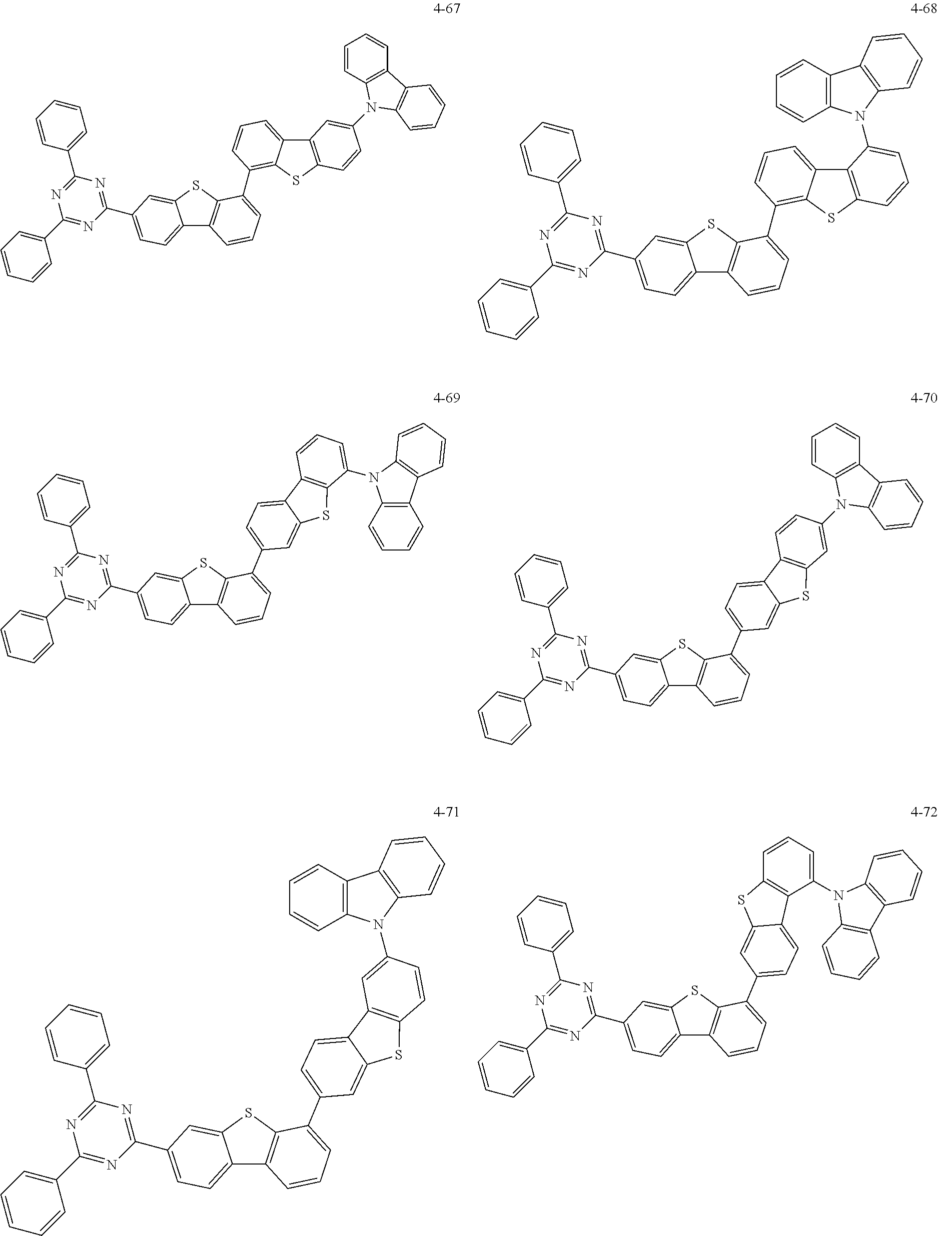

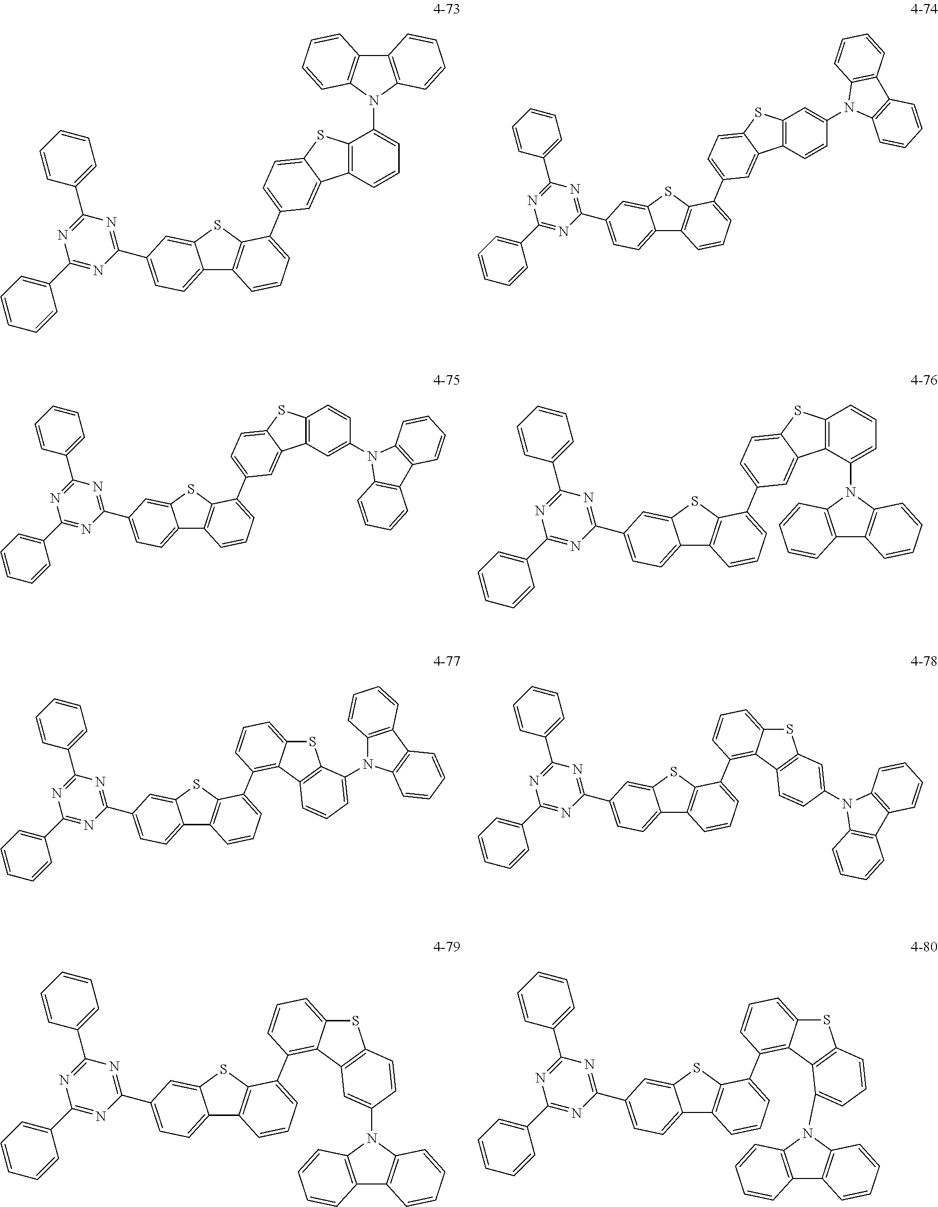

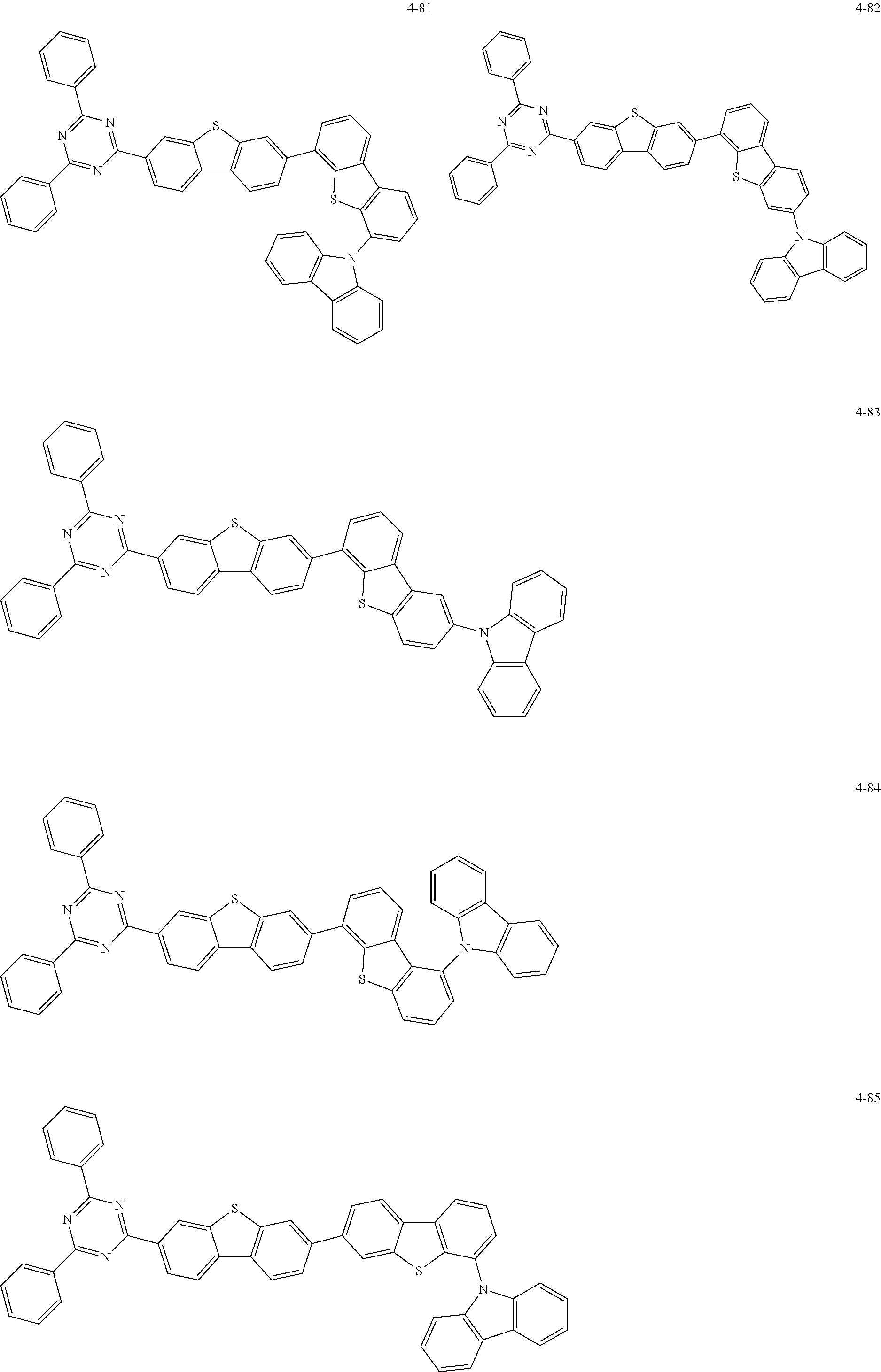

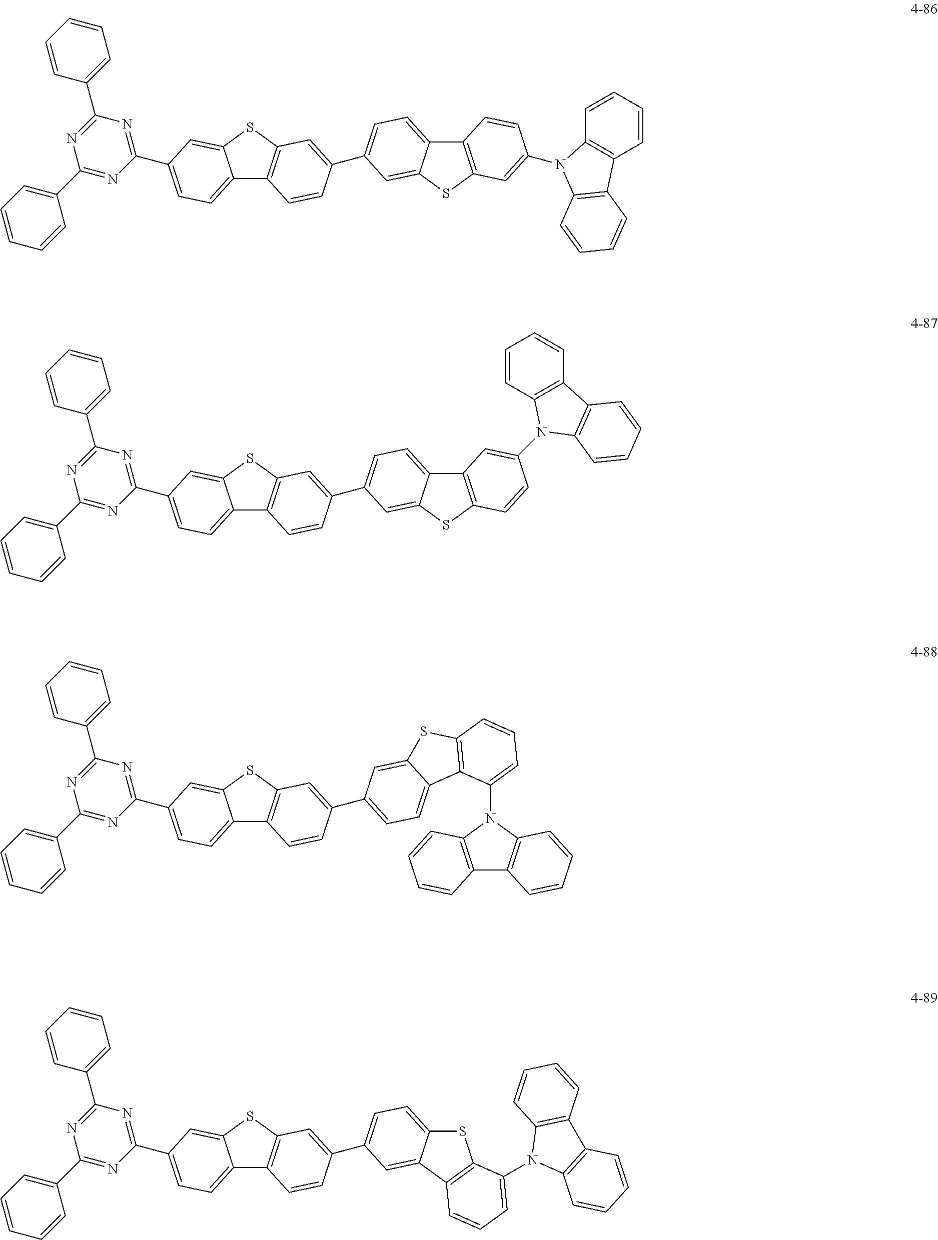 [SMILES: c1ccc(-c2nc(-c3ccccc3)nc(-c3ccc4c(c3)sc3cc(-c5ccc6c(c5)sc5cc(-n7c8ccccc8c8ccccc87)ccc56)ccc34)n2)cc1 ; c1ccc(-c2nc(-c3ccccc3)nc(-c3ccc4c(c3)sc3cc(-c5ccc6c(c5)sc5ccc(-n7c8ccccc8c8ccccc87)cc56)ccc34)n2)cc1 ; c1ccc(-c2nc(-c3ccccc3)nc(-c3ccc4c(c3)sc3cc(-c5ccc6c(c5)sc5cccc(-n7c8ccccc8c8ccccc87)c56)ccc34)n2)cc1 ; c1ccc(-c2nc(-c3ccccc3)nc(-c3ccc4c(c3)sc3cc(-c5ccc6sc7c(-n8c9ccccc9c9ccccc98)cccc7c6c5)ccc34)n2)cc1]

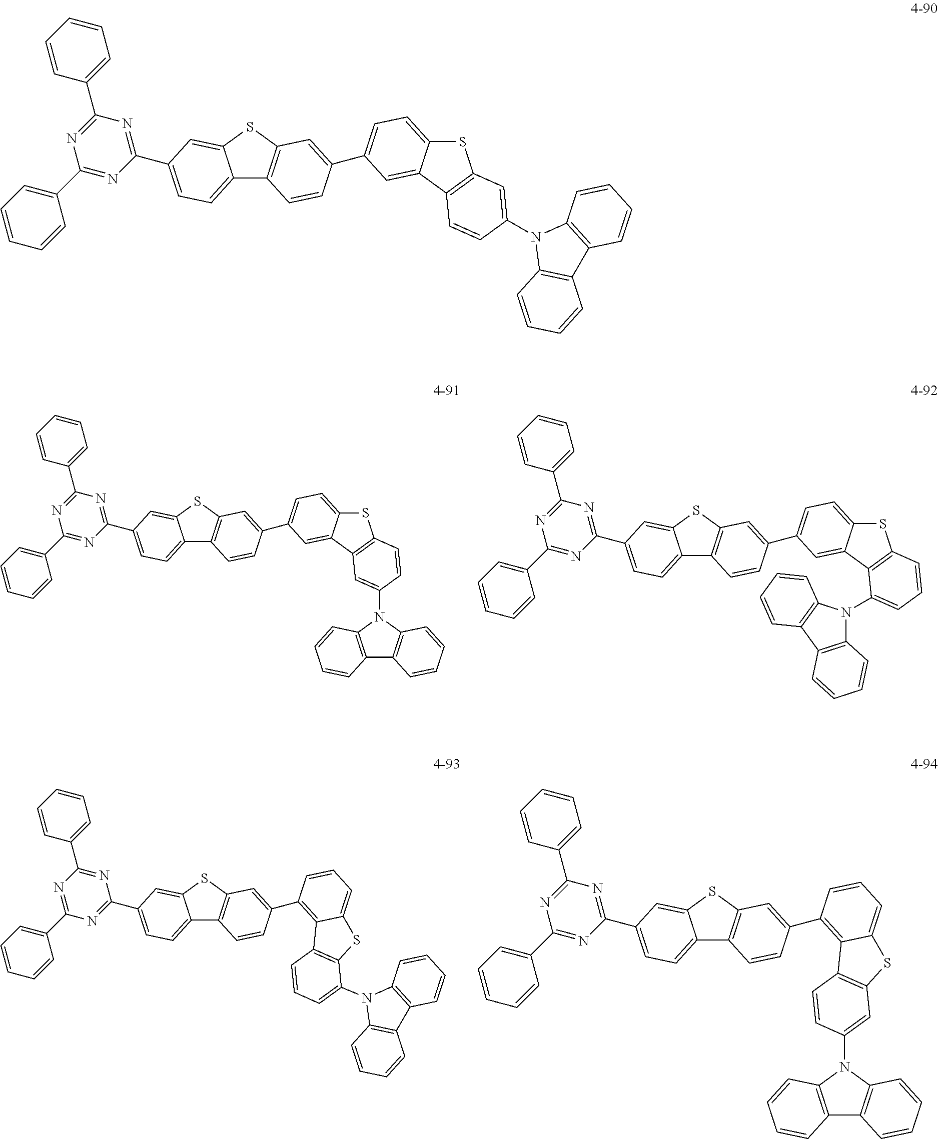

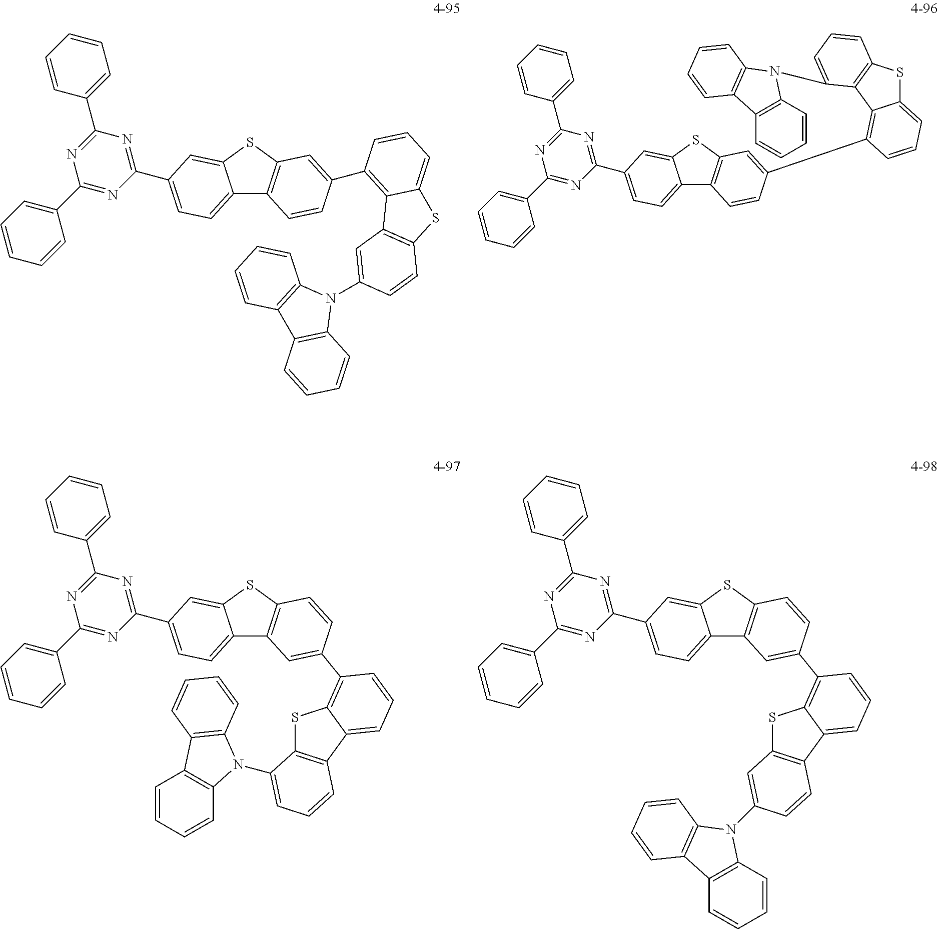

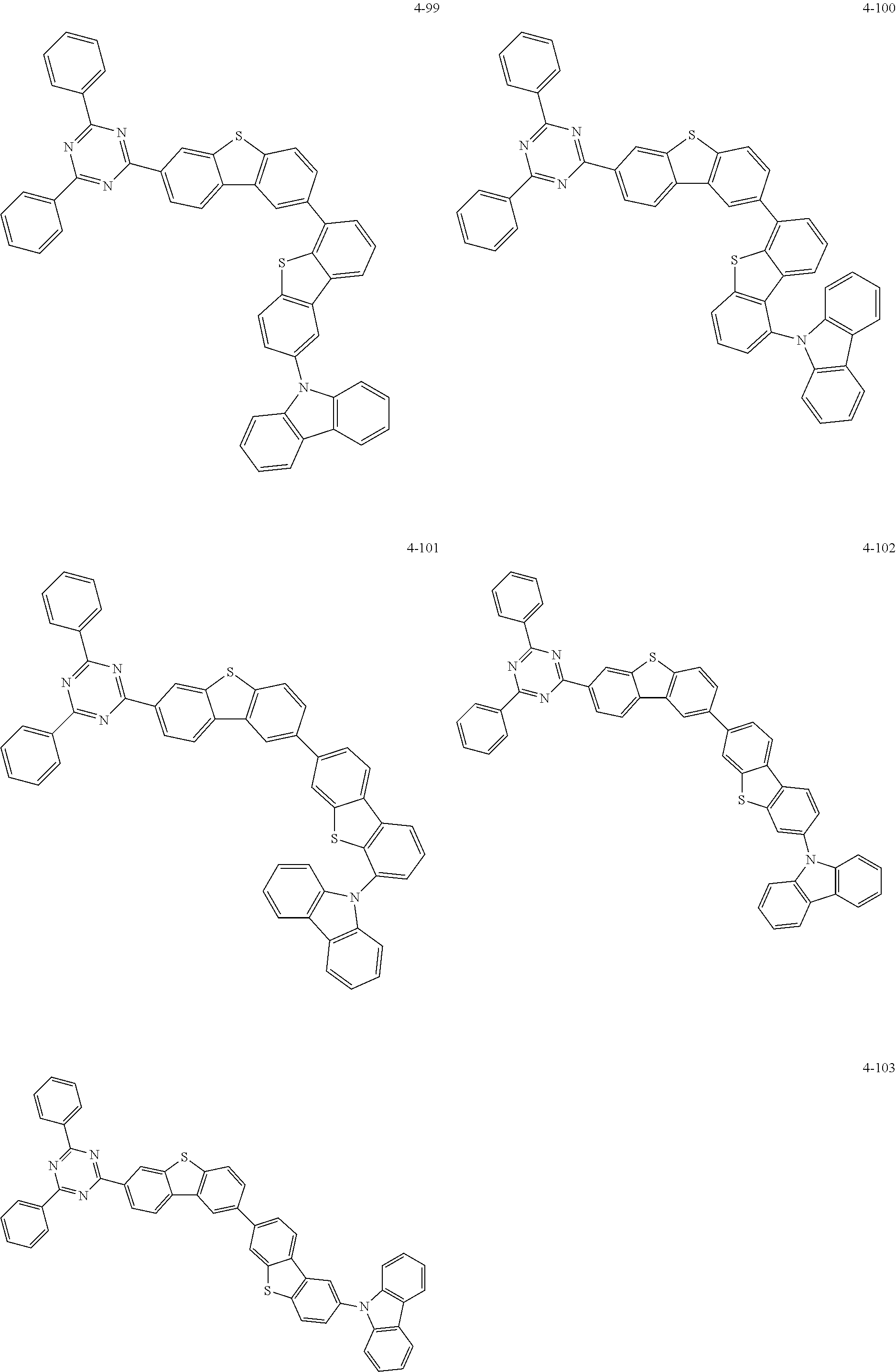

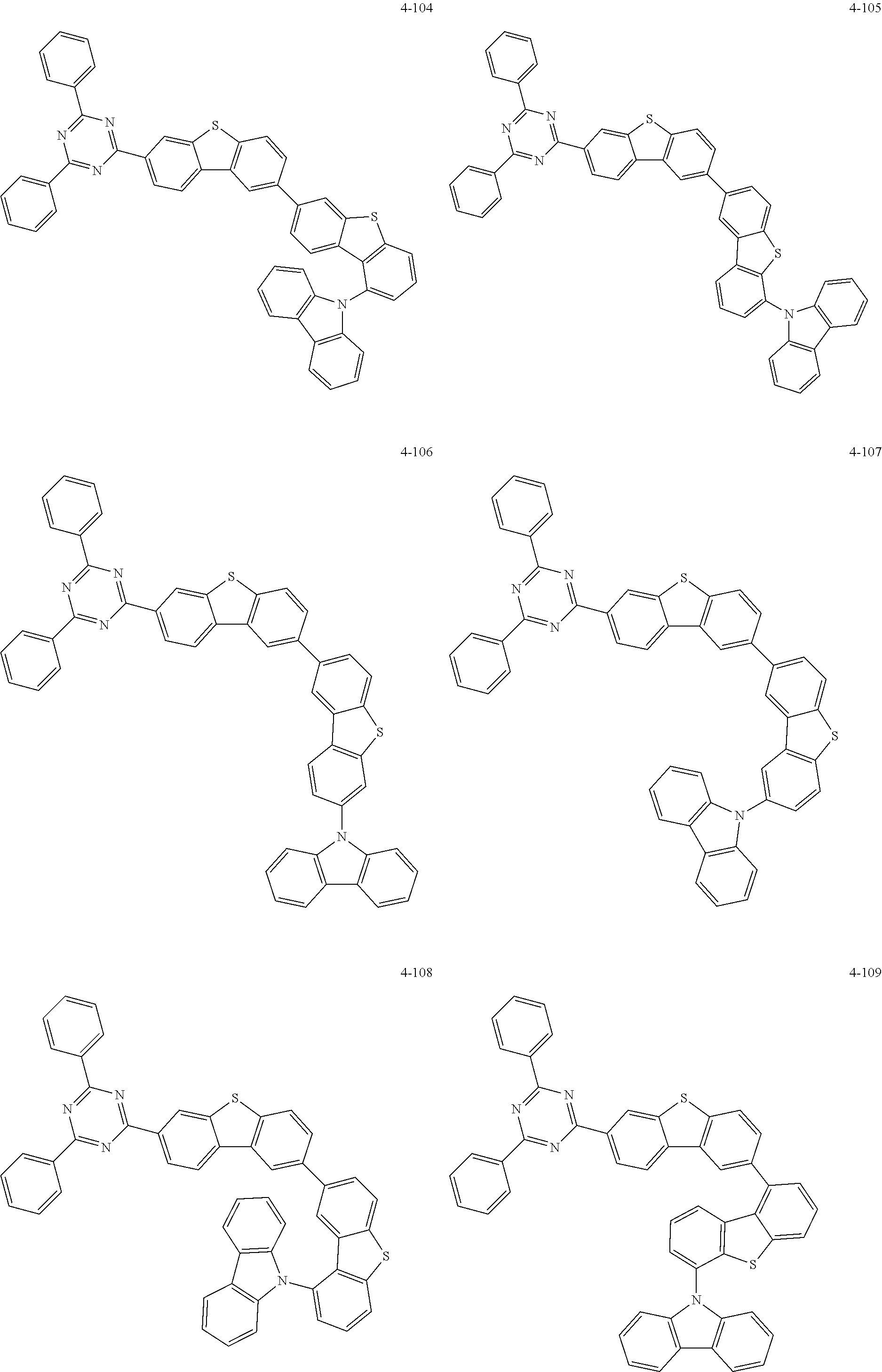

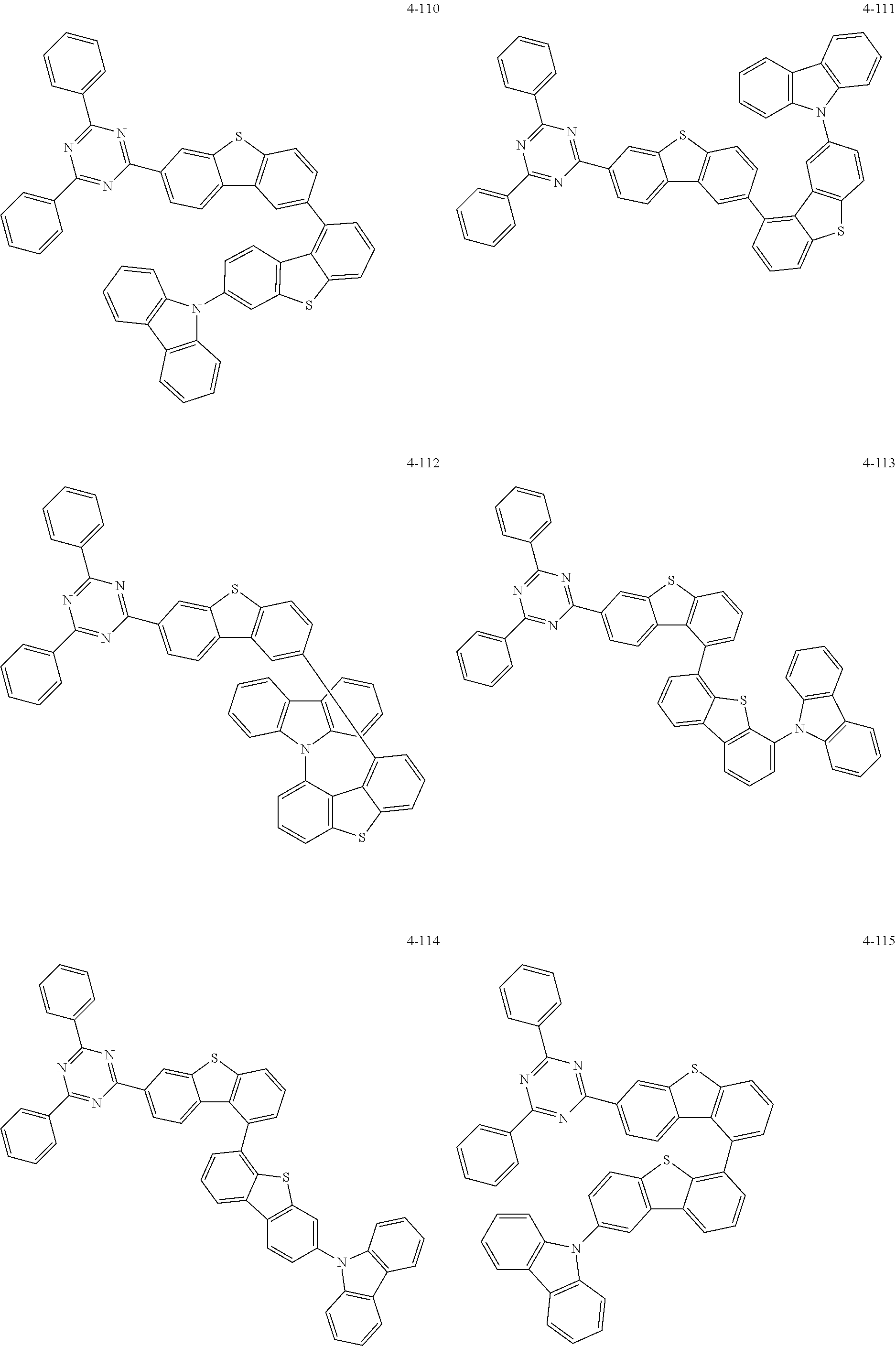

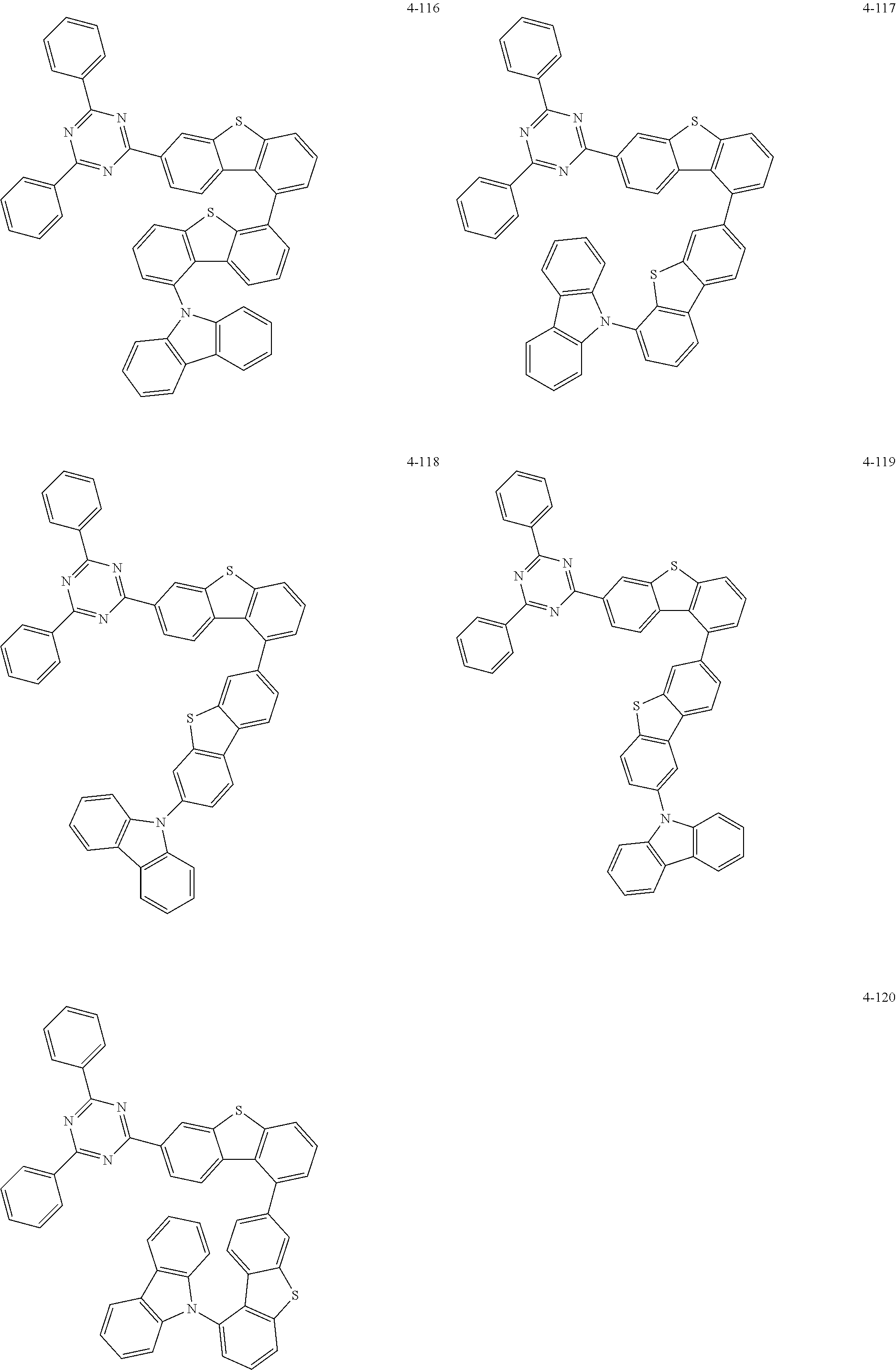

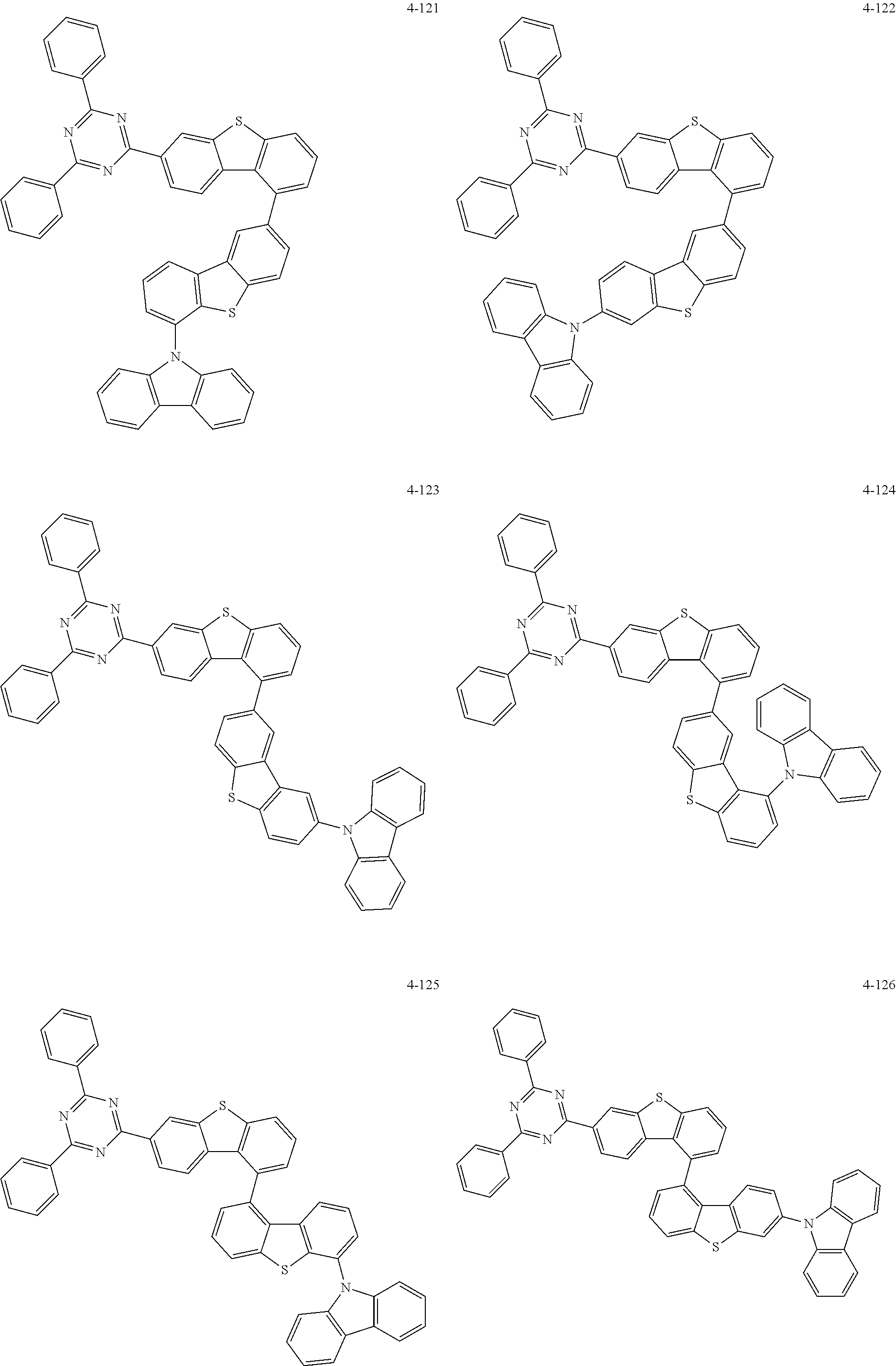

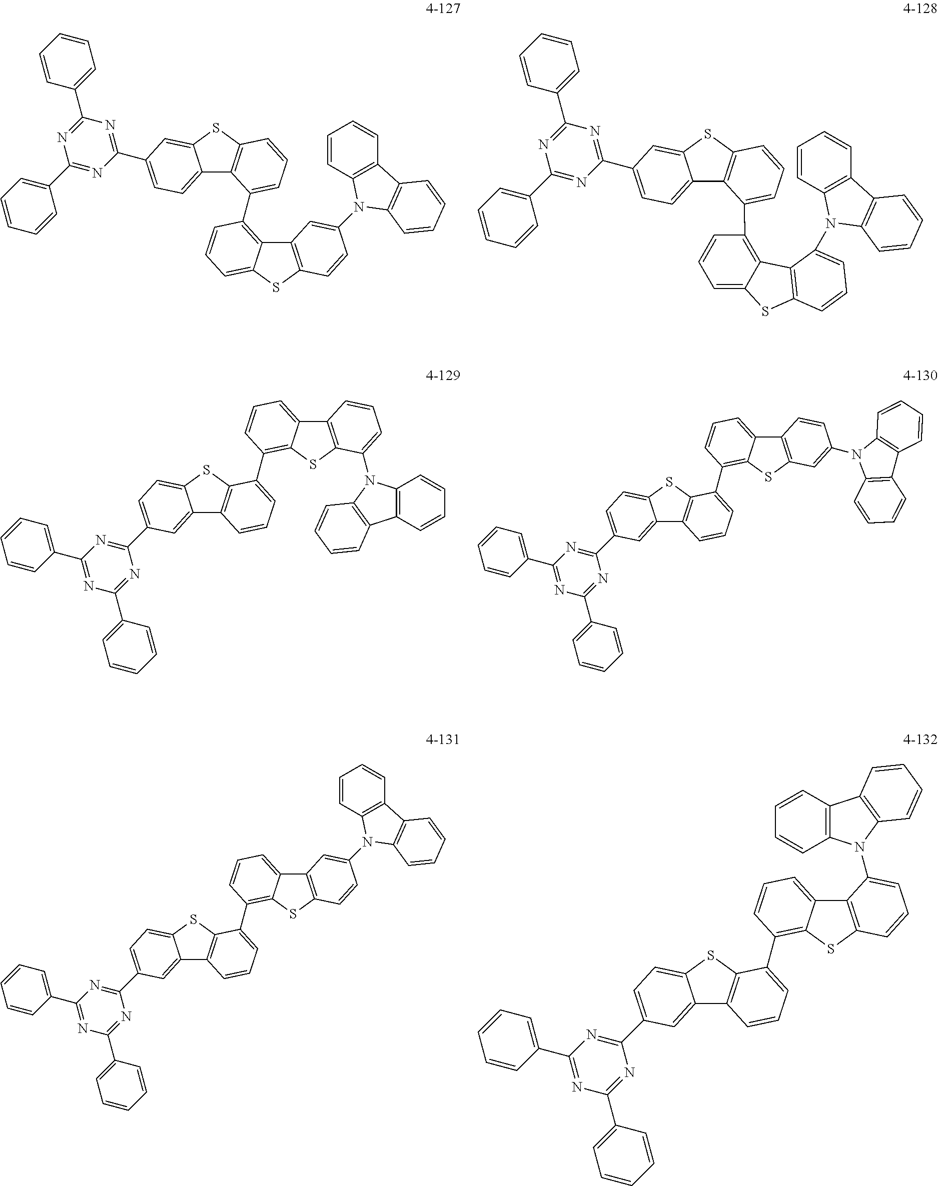

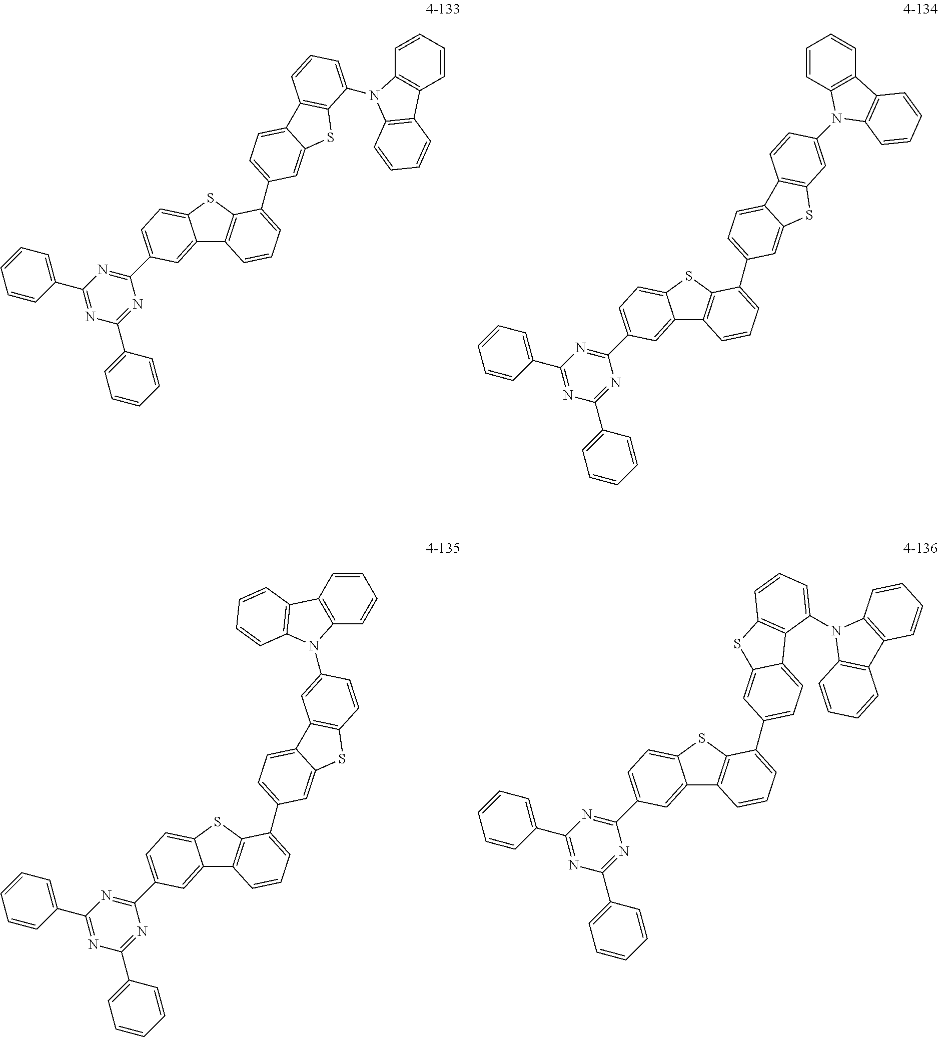 [SMILES: c1ccc(-c2nc(-c3ccccc3)nc(-c3ccc4sc5c(-c6ccc7c(c6)sc6c(-n8c9ccccc9c9ccccc98)cccc67)cccc5c4c3)n2)cc1 ; c1ccc(-c2nc(-c3ccccc3)nc(-c3ccc4sc5c(-c6ccc7c(c6)sc6cc(-n8c9ccccc9c9ccccc98)ccc67)cccc5c4c3)n2)cc1 ; c1ccc(-c2nc(-c3ccccc3)nc(-c3ccc4sc5c(-c6ccc7c(c6)sc6ccc(-n8c9ccccc9c9ccccc98)cc67)cccc5c4c3)n2)cc1 ; c1ccc(-c2nc(-c3ccccc3)nc(-c3ccc4sc5c(-c6ccc7c(c6)sc6cccc(-n8c9ccccc9c9ccccc98)c67)cccc5c4c3)n2)cc1]

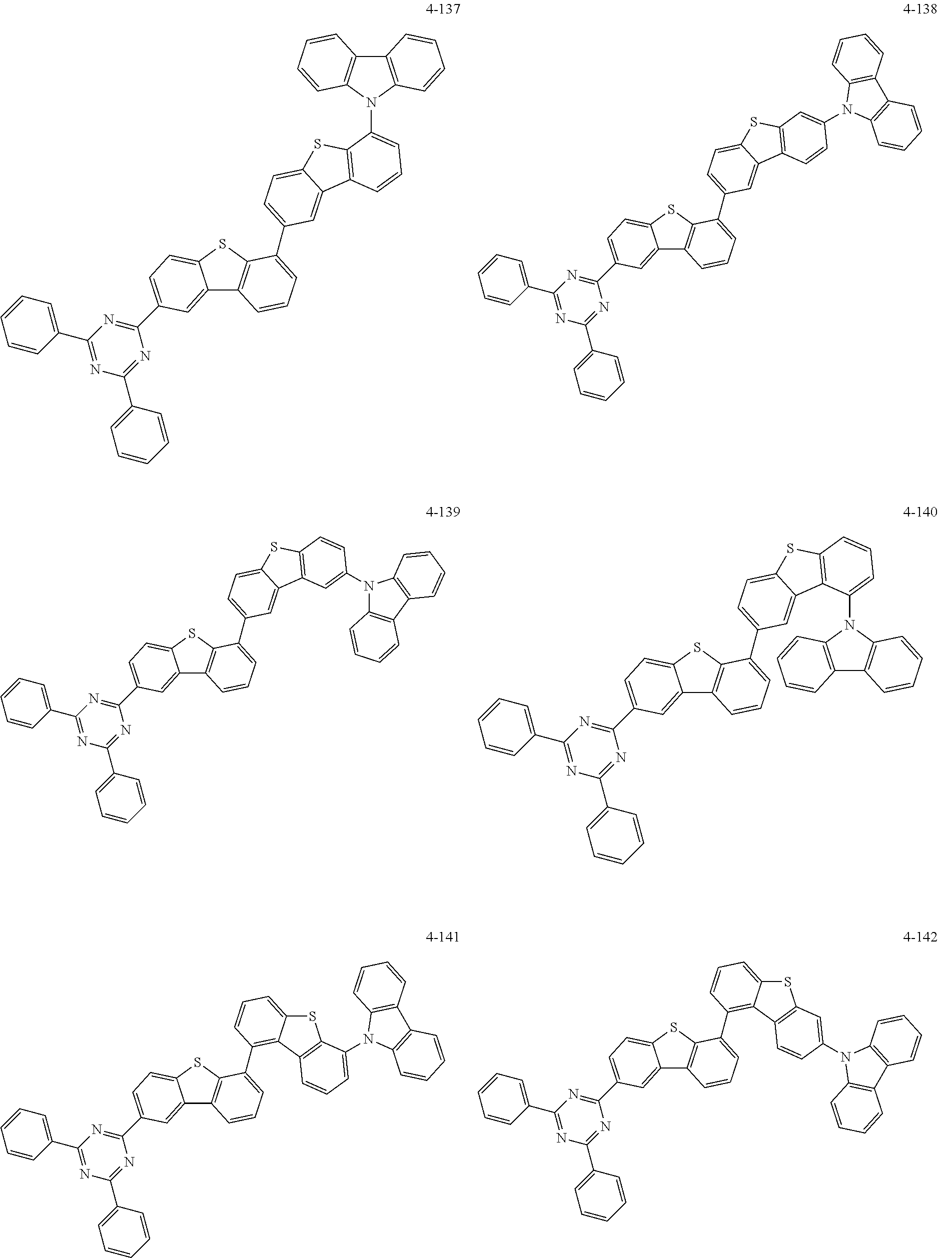

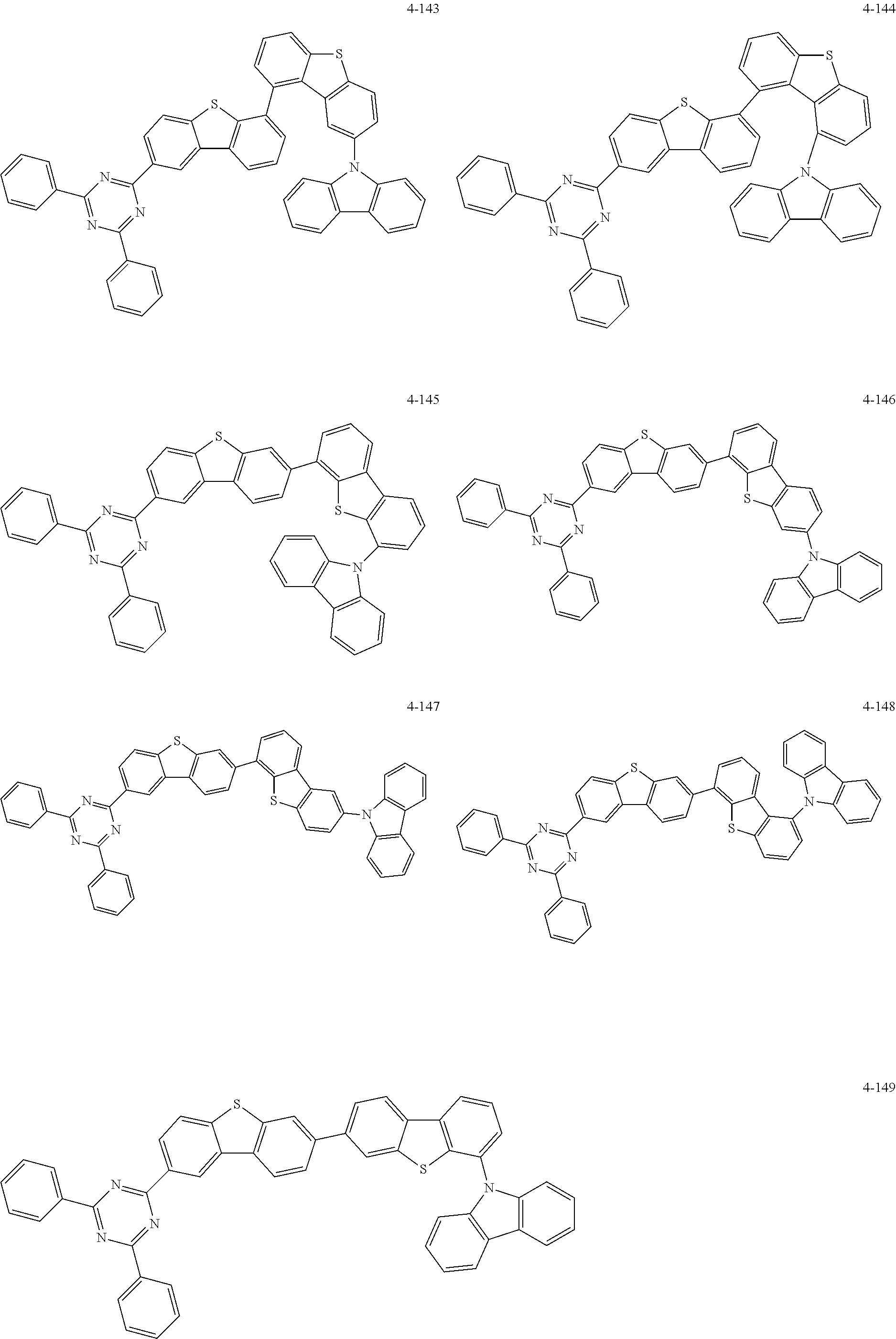

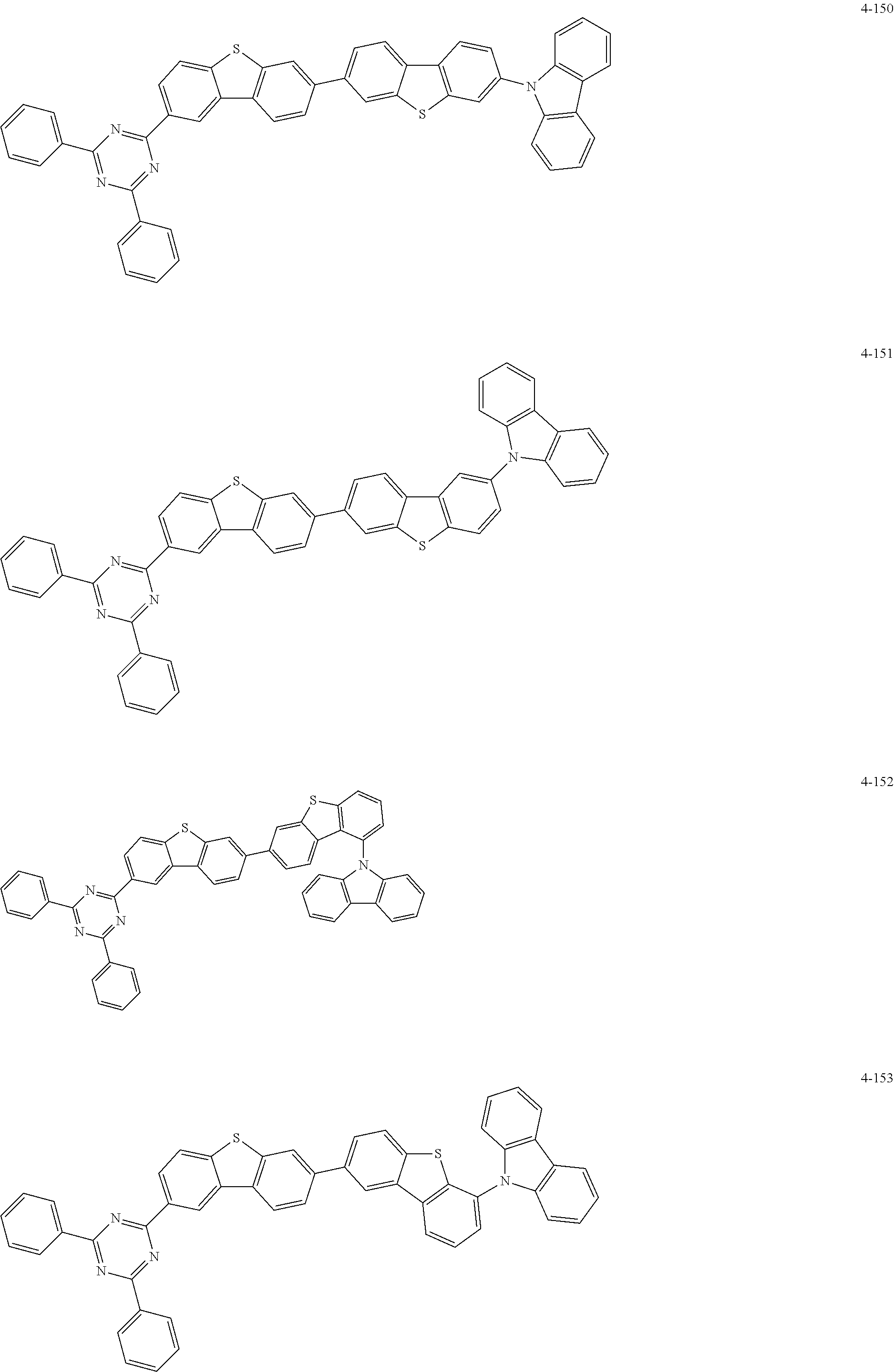 [SMILES: c1ccc(-c2nc(-c3ccccc3)nc(-c3ccc4sc5cc(-c6ccc7c(c6)sc6cc(-n8c9ccccc9c9ccccc98)ccc67)ccc5c4c3)n2)cc1 ; c1ccc(-c2nc(-c3ccccc3)nc(-c3ccc4sc5cc(-c6ccc7c(c6)sc6ccc(-n8c9ccccc9c9ccccc98)cc67)ccc5c4c3)n2)cc1 ; c1ccc(-c2nc(-c3ccccc3)nc(-c3ccc4sc5cc(-c6ccc7c(c6)sc6cccc(-n8c9ccccc9c9ccccc98)c67)ccc5c4c3)n2)cc1 ; c1ccc(-c2nc(-c3ccccc3)nc(-c3ccc4sc5cc(-c6ccc7sc8c(-n9c%10ccccc%10c%10ccccc%109)cccc8c7c6)ccc5c4c3)n2)cc1]

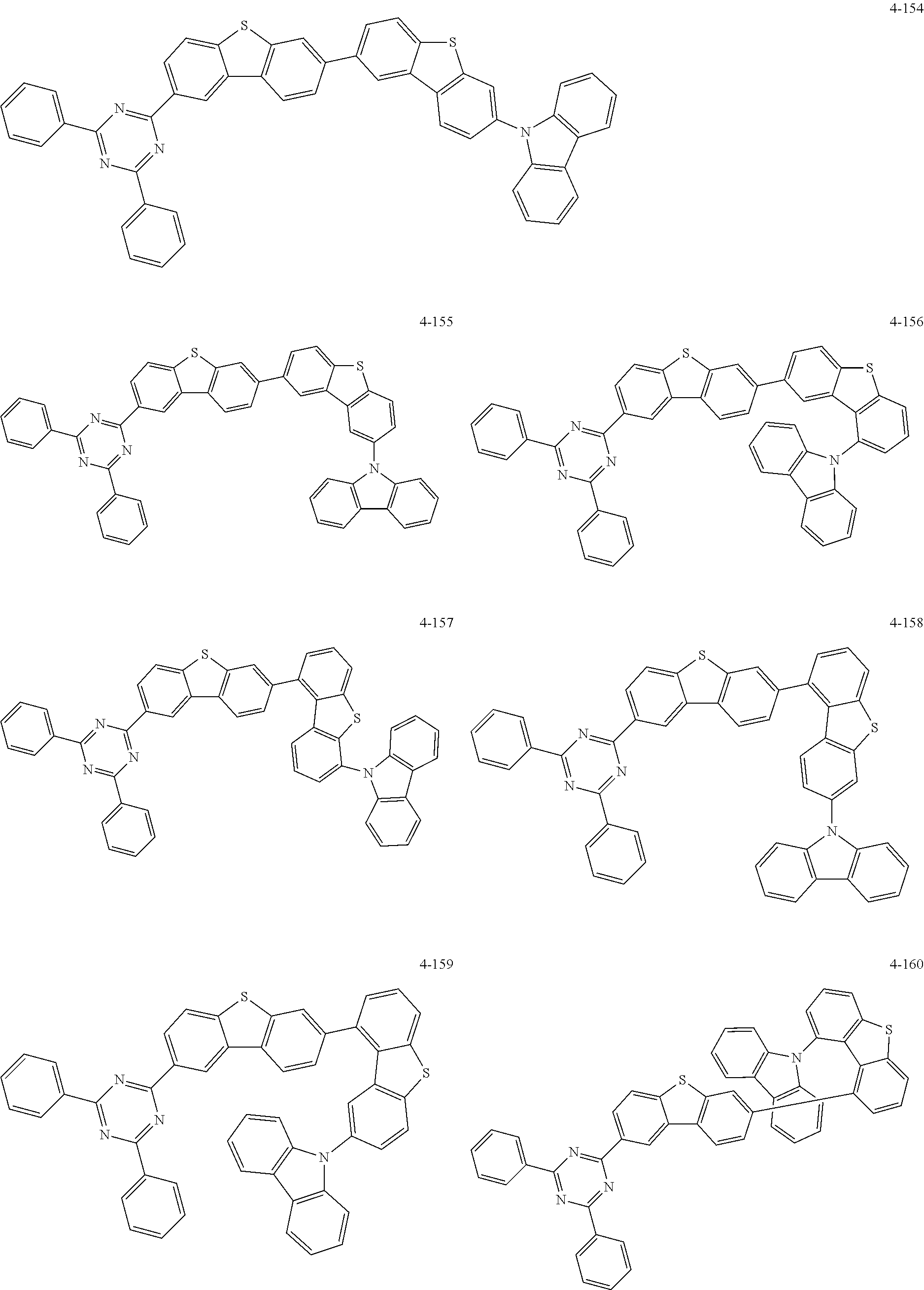

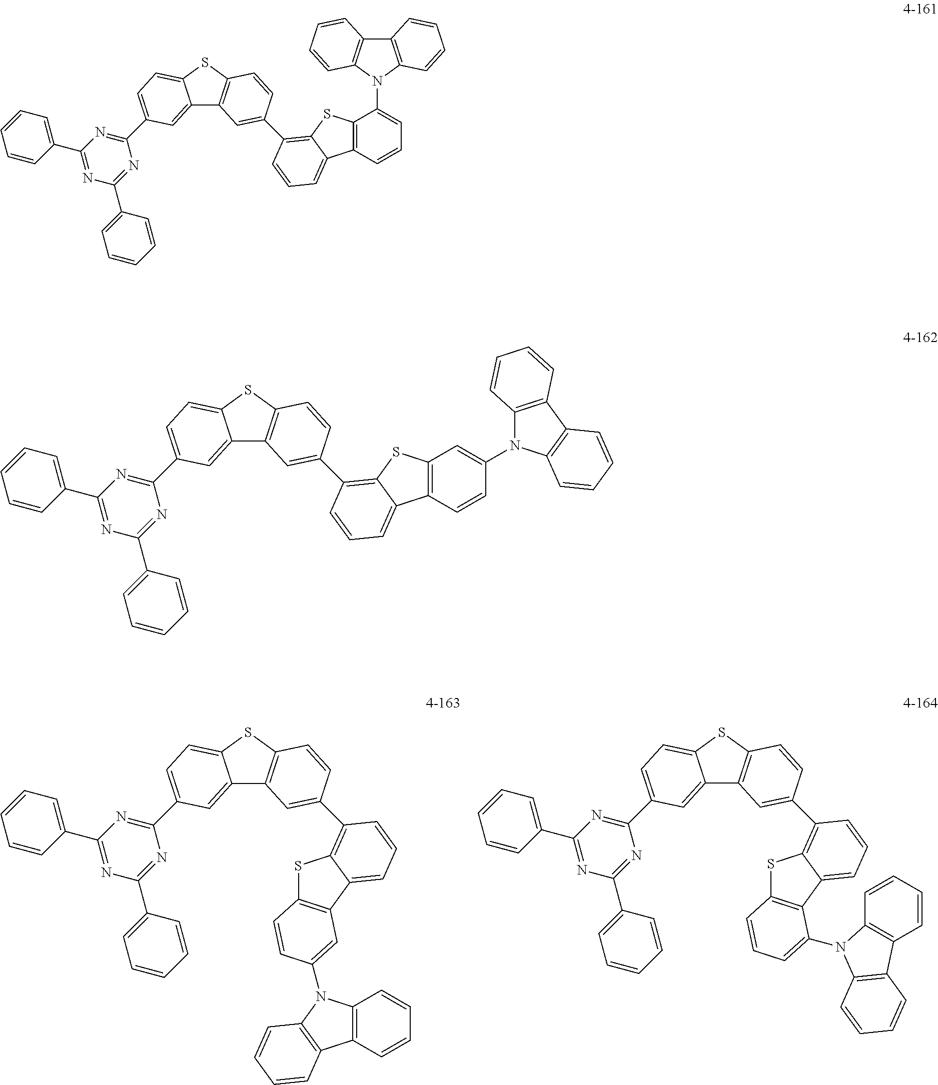 [SMILES: c1ccc(-c2nc(-c3ccccc3)nc(-c3ccc4sc5ccc(-c6cccc7c6sc6c(-n8c9ccccc9c9ccccc98)cccc67)cc5c4c3)n2)cc1 ; c1ccc(-c2nc(-c3ccccc3)nc(-c3ccc4sc5ccc(-c6cccc7c6sc6cc(-n8c9ccccc9c9ccccc98)ccc67)cc5c4c3)n2)cc1 ; c1ccc(-c2nc(-c3ccccc3)nc(-c3ccc4sc5ccc(-c6cccc7c6sc6ccc(-n8c9ccccc9c9ccccc98)cc67)cc5c4c3)n2)cc1 ; c1ccc(-c2nc(-c3ccccc3)nc(-c3ccc4sc5ccc(-c6cccc7c6sc6cccc(-n8c9ccccc9c9ccccc98)c67)cc5c4c3)n2)cc1]

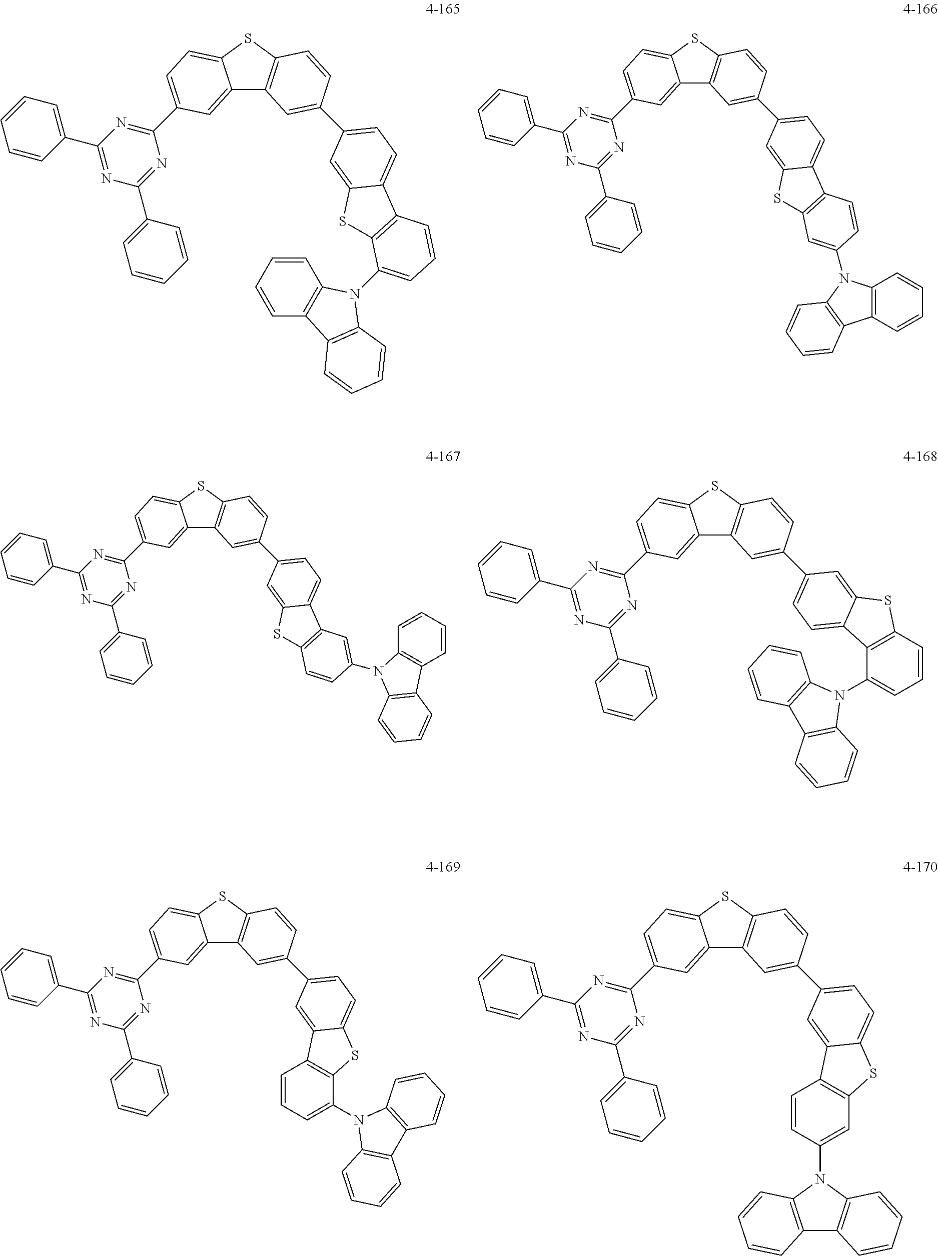

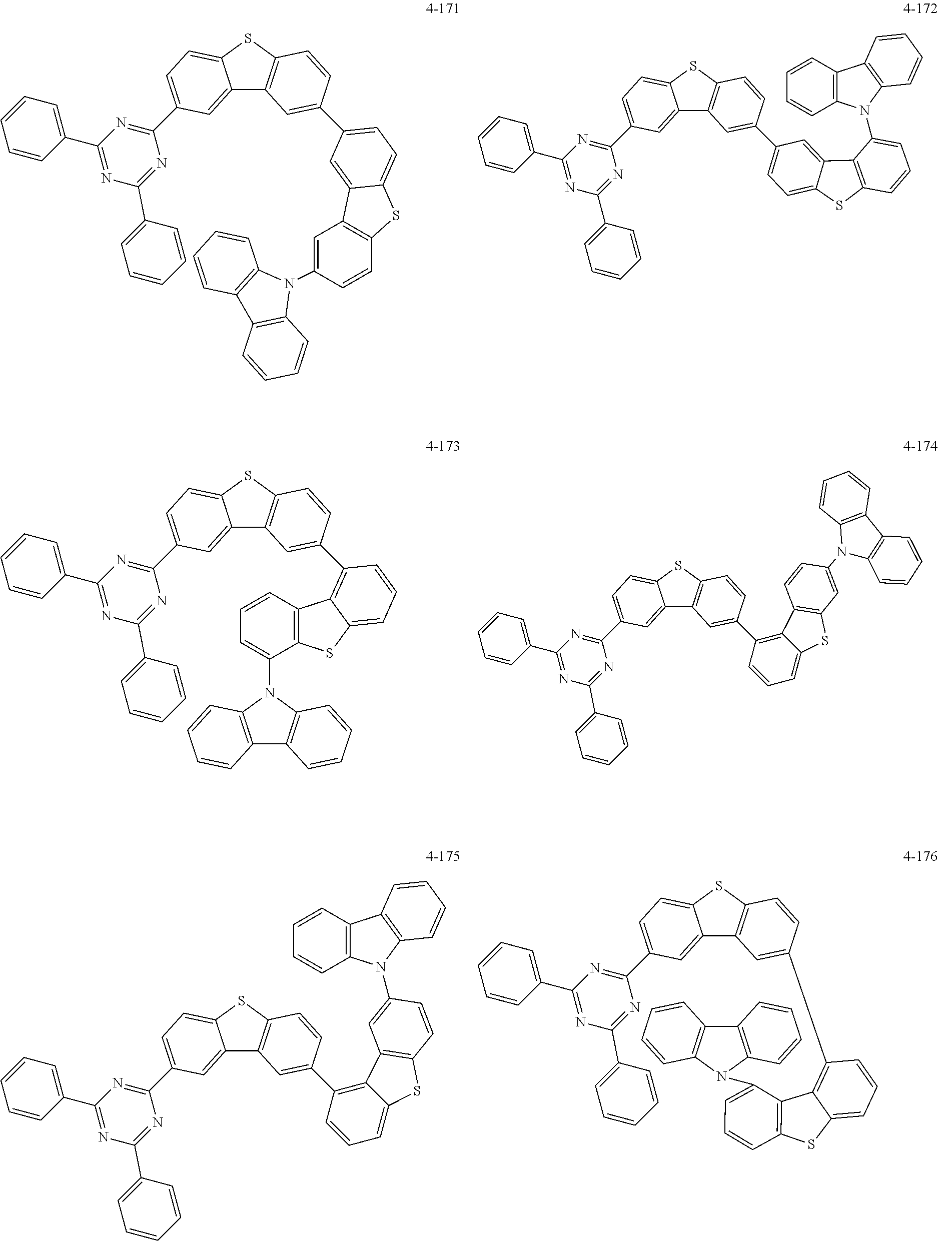

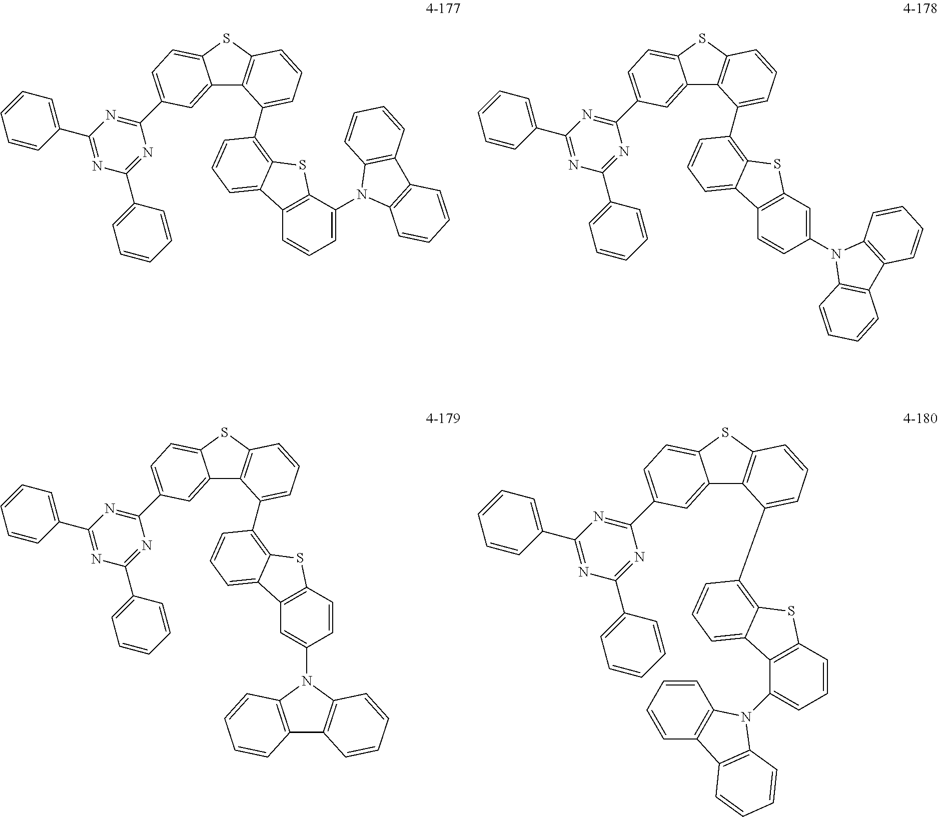 [SMILES: c1ccc(-c2nc(-c3ccccc3)nc(-c3ccc4sc5cccc(-c6cccc7c6sc6c(-n8c9ccccc9c9ccccc98)cccc67)c5c4c3)n2)cc1 ; c1ccc(-c2nc(-c3ccccc3)nc(-c3ccc4sc5cccc(-c6cccc7c6sc6cc(-n8c9ccccc9c9ccccc98)ccc67)c5c4c3)n2)cc1 ; c1ccc(-c2nc(-c3ccccc3)nc(-c3ccc4sc5cccc(-c6cccc7c6sc6ccc(-n8c9ccccc9c9ccccc98)cc67)c5c4c3)n2)cc1 ; c1ccc(-c2nc(-c3ccccc3)nc(-c3ccc4sc5cccc(-c6cccc7c6sc6cccc(-n8c9ccccc9c9ccccc98)c67)c5c4c3)n2)cc1]

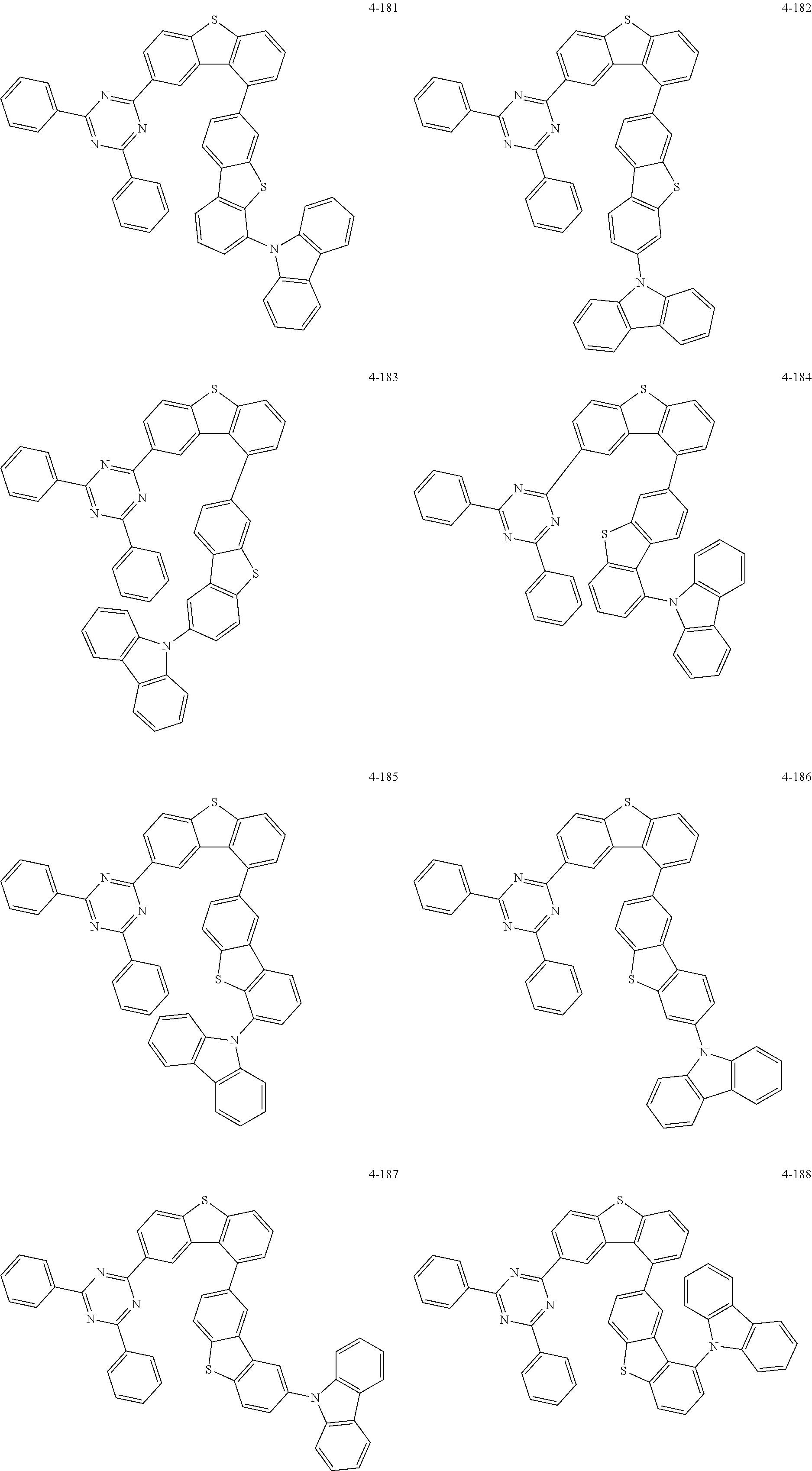

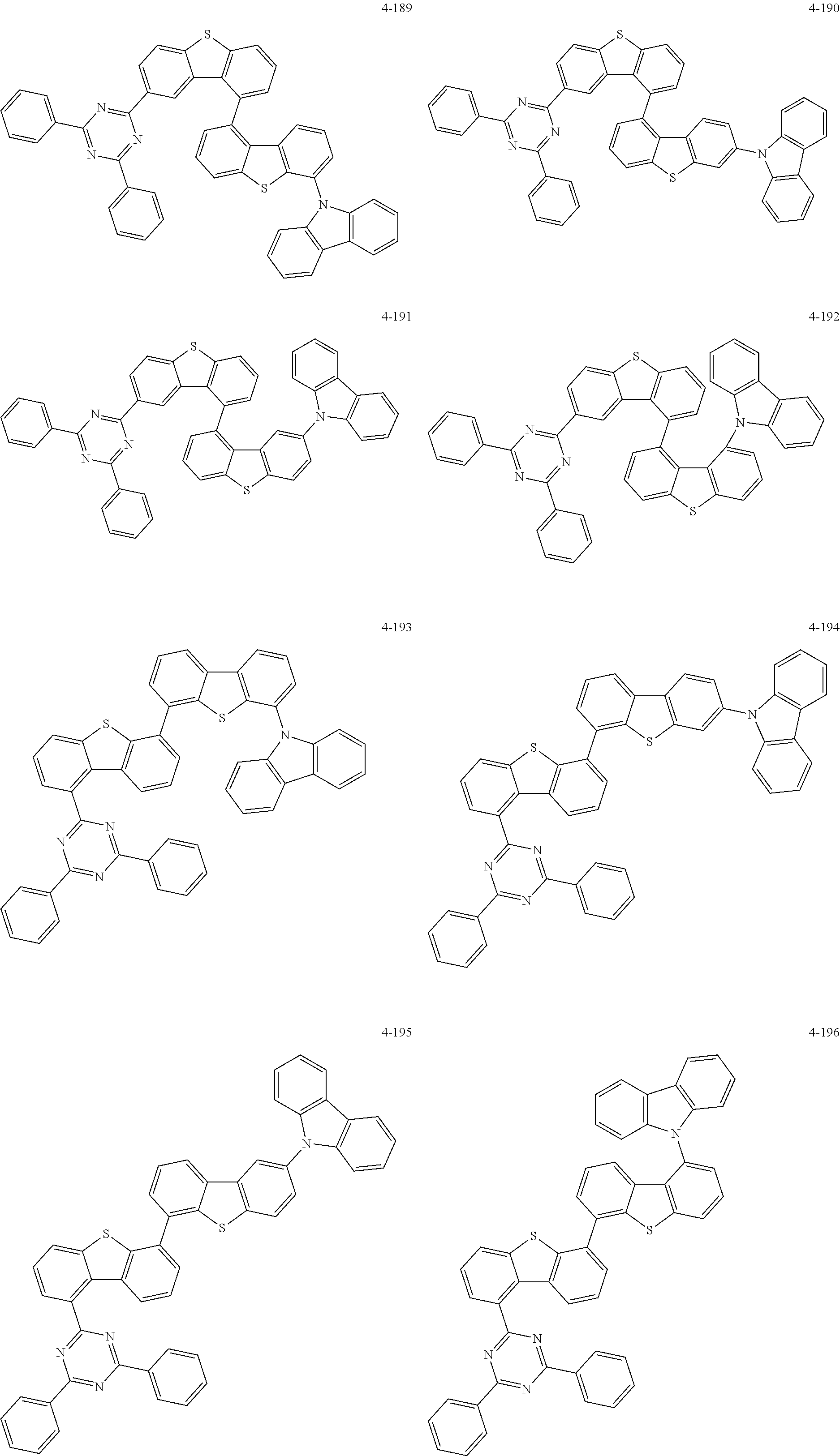

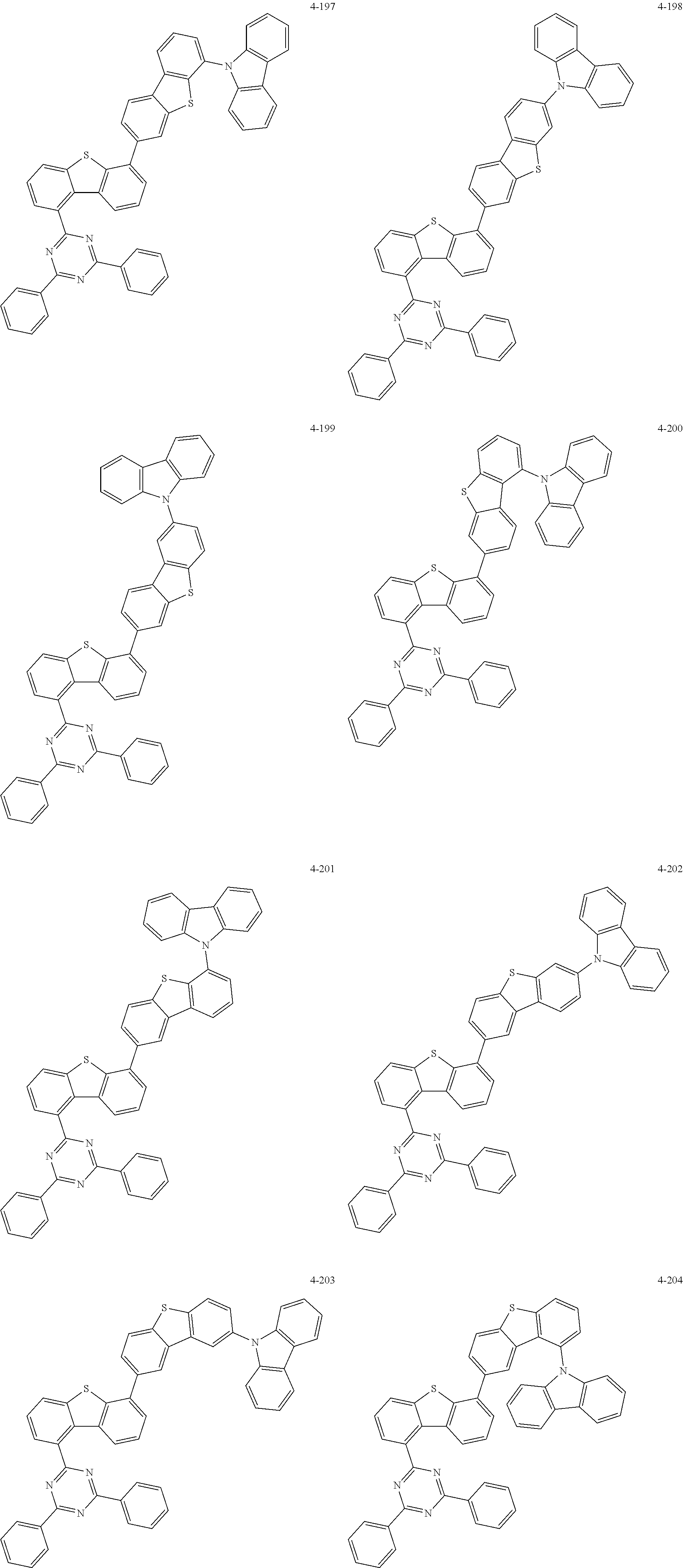

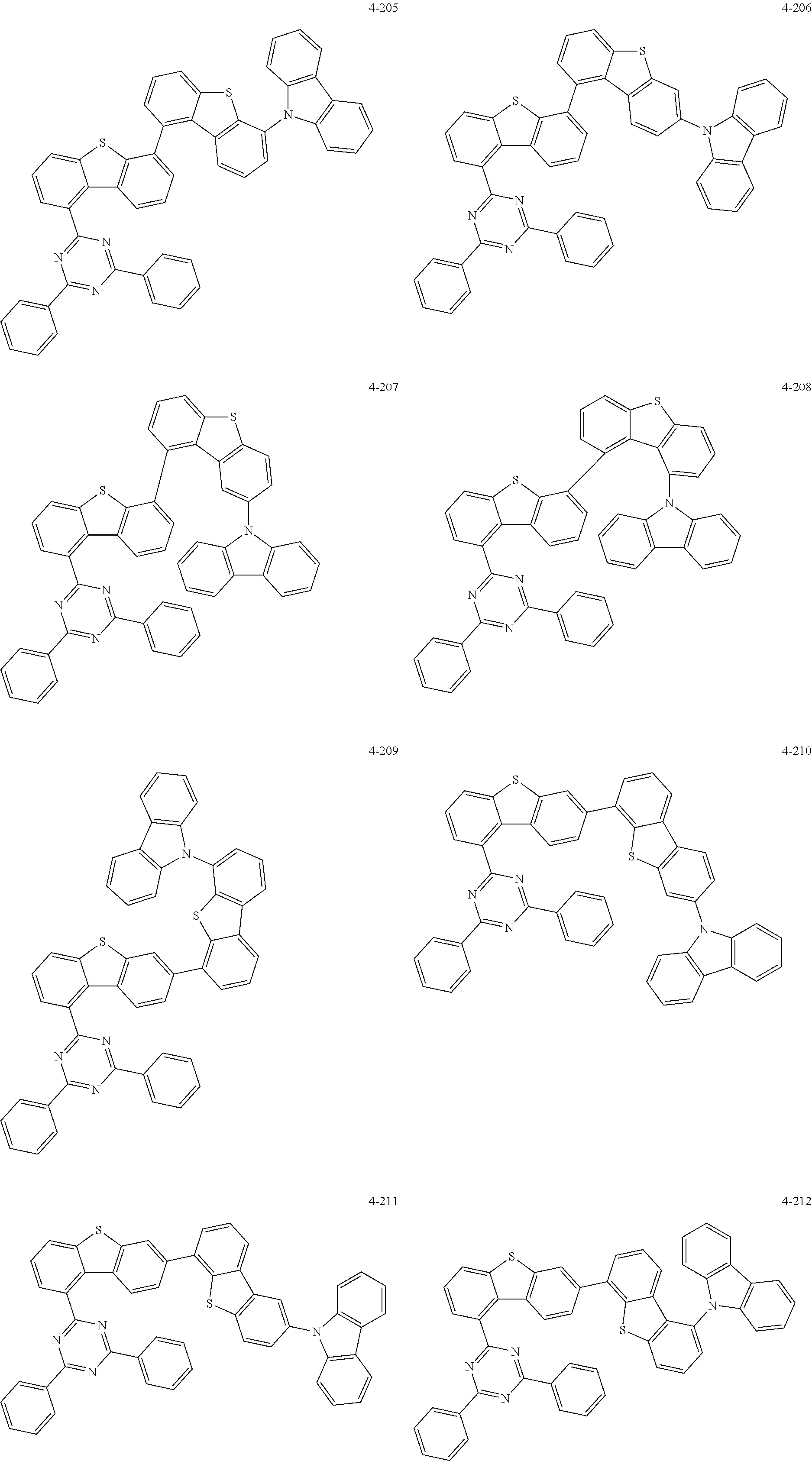

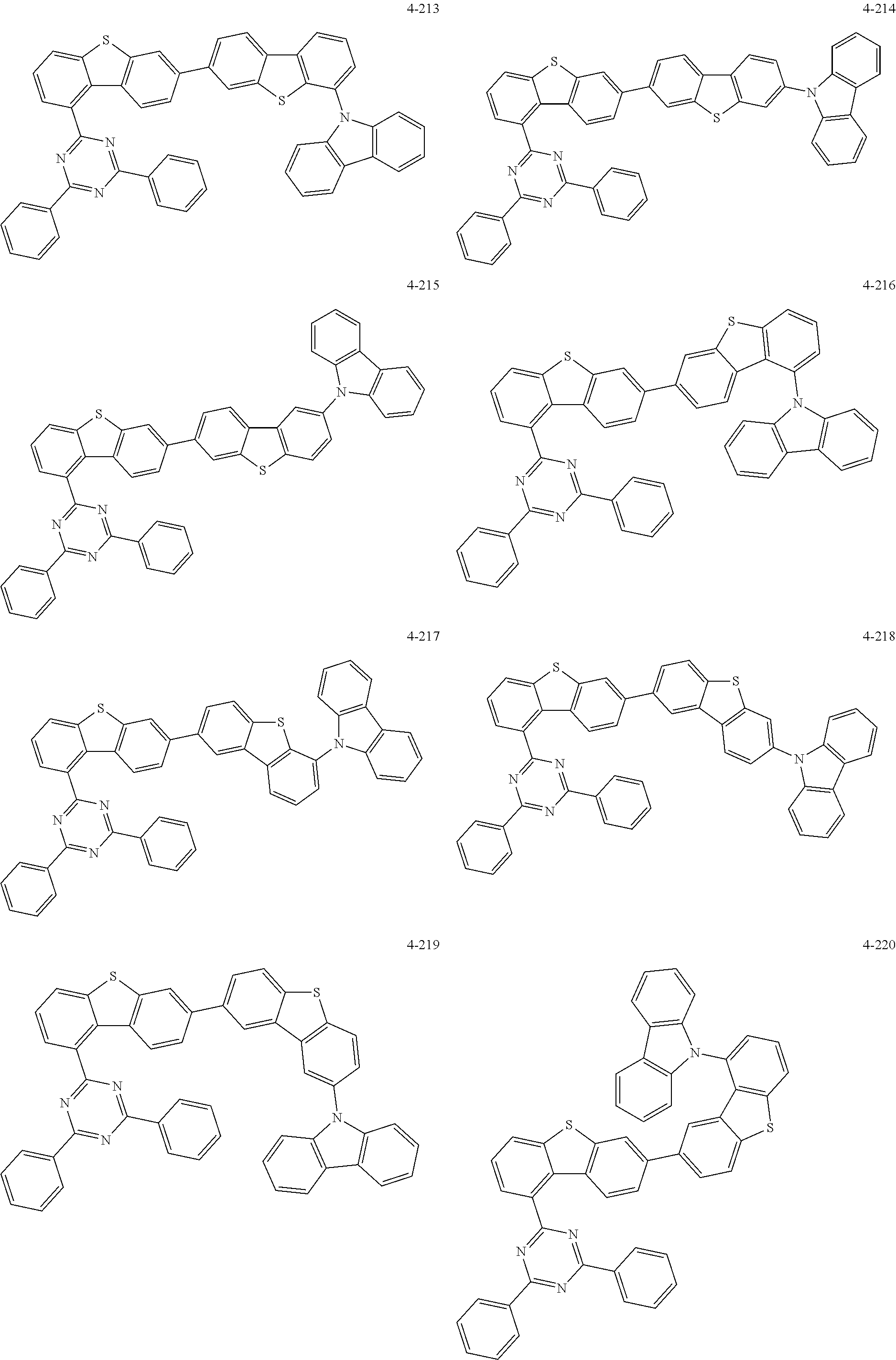

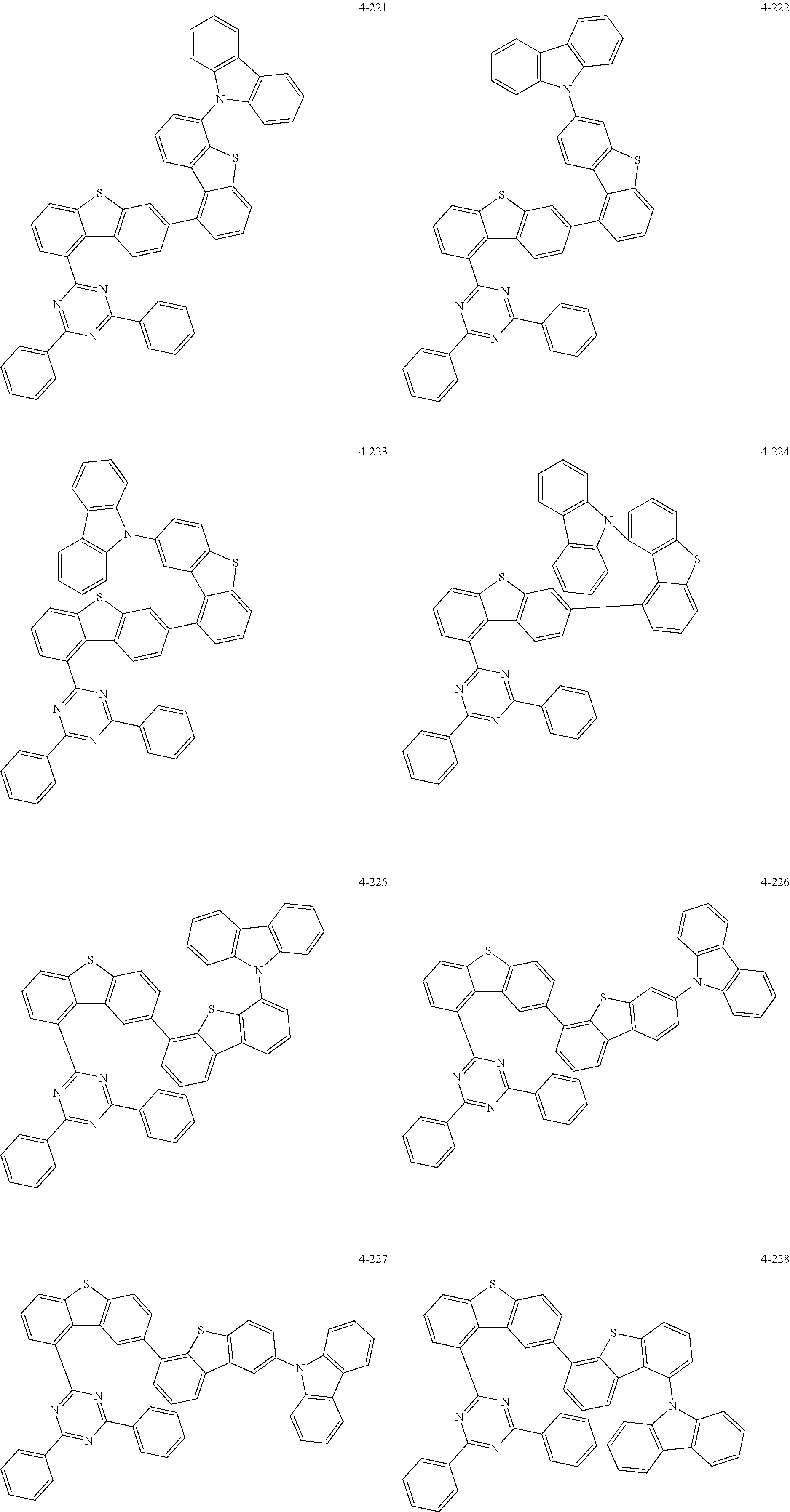

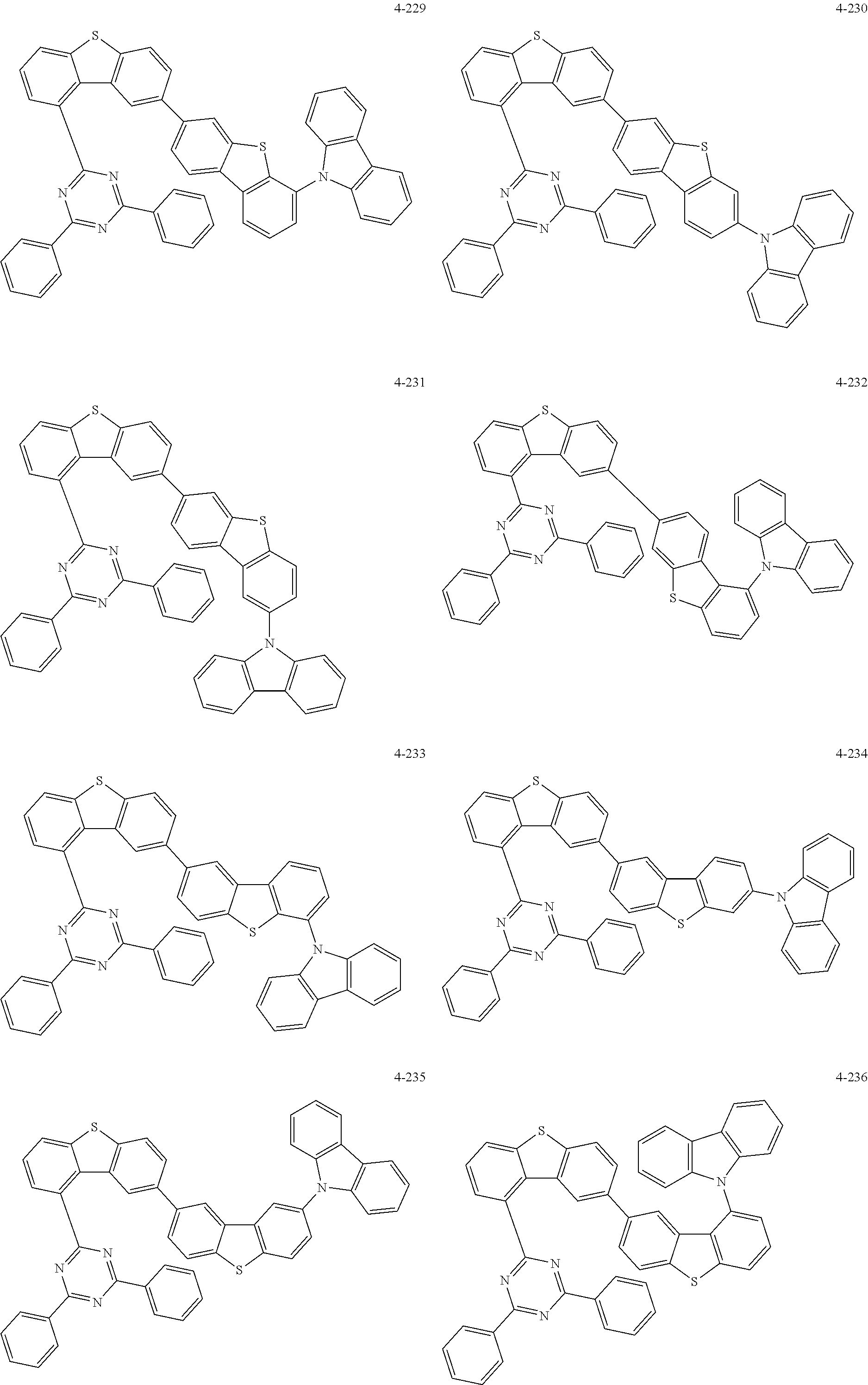

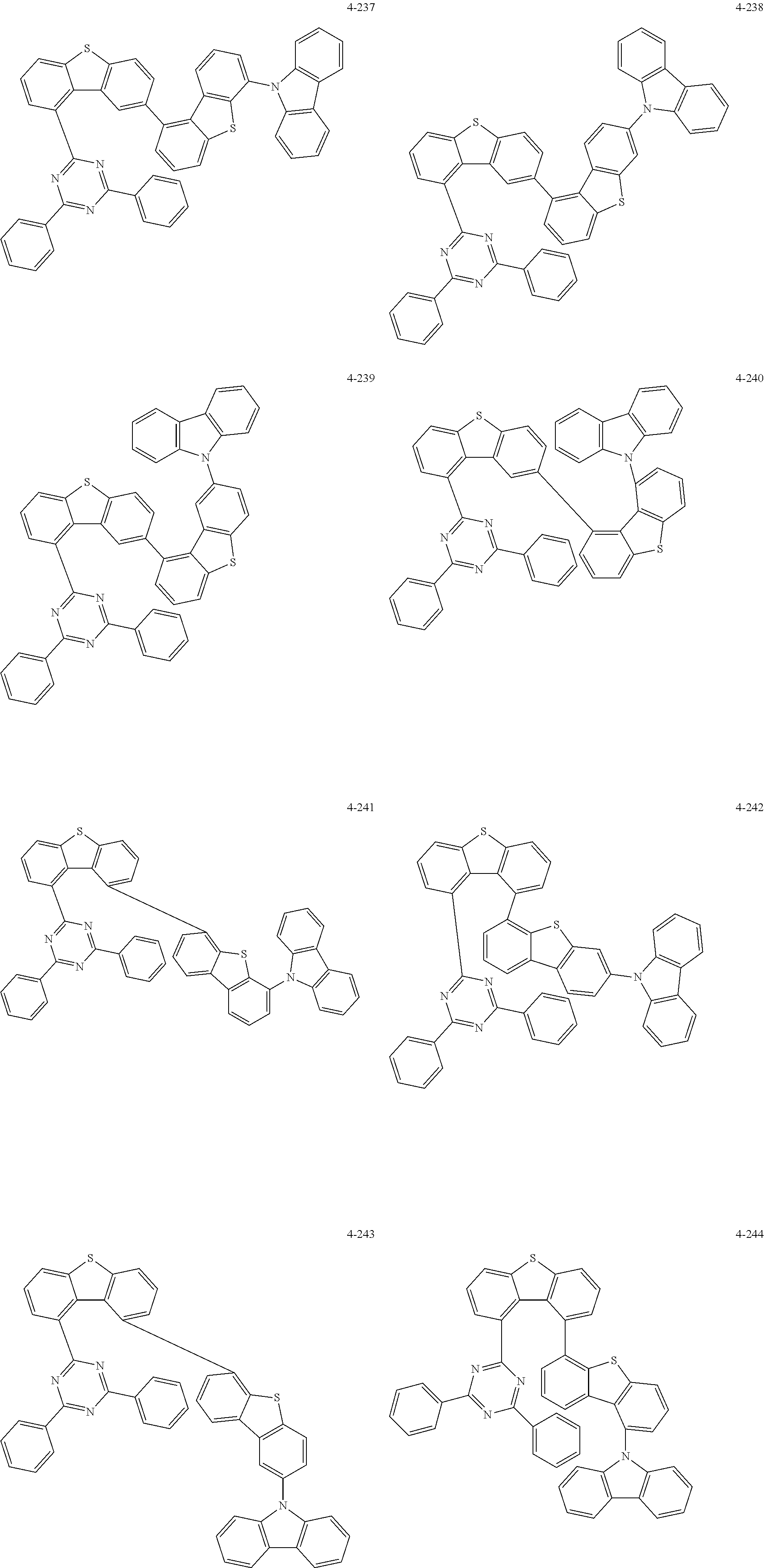

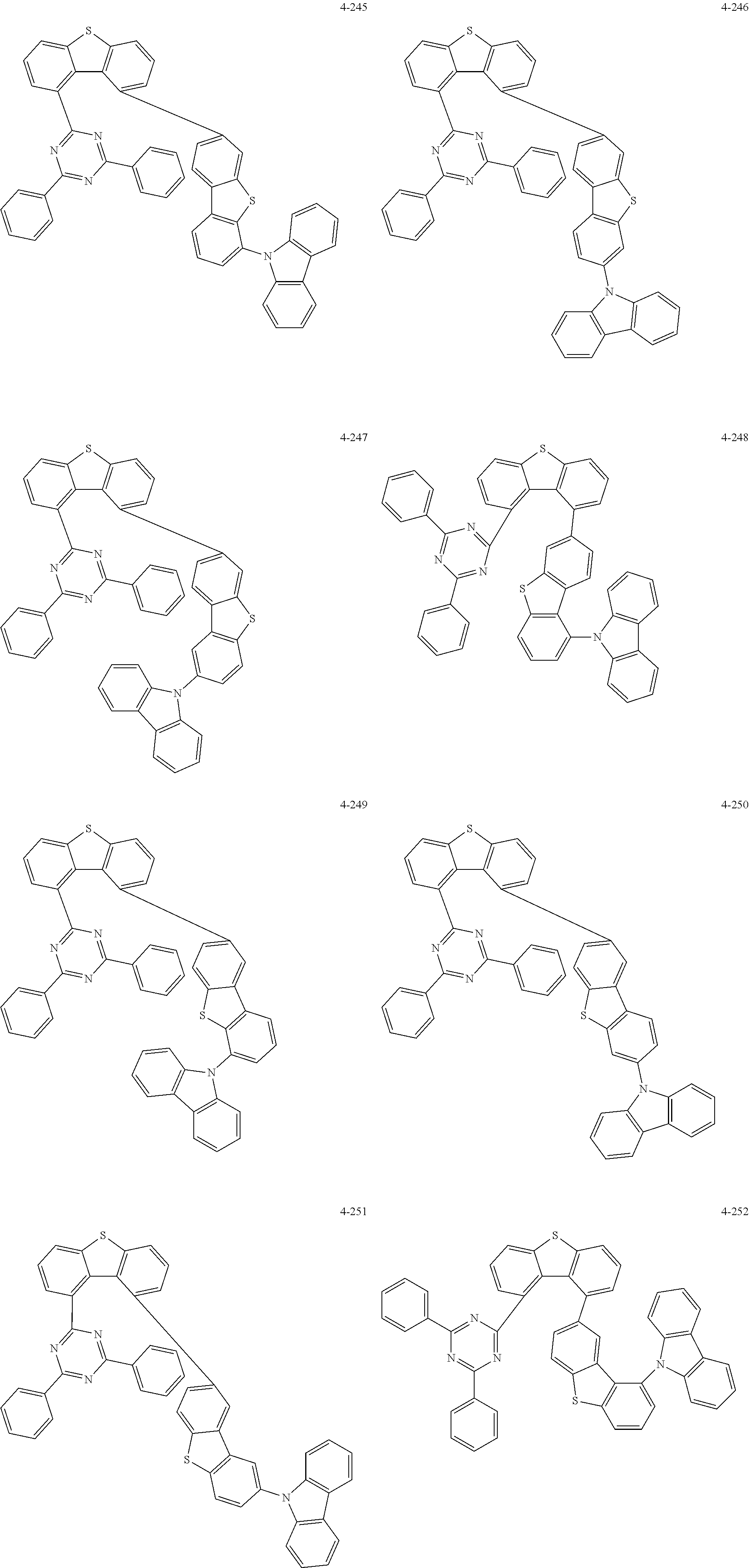

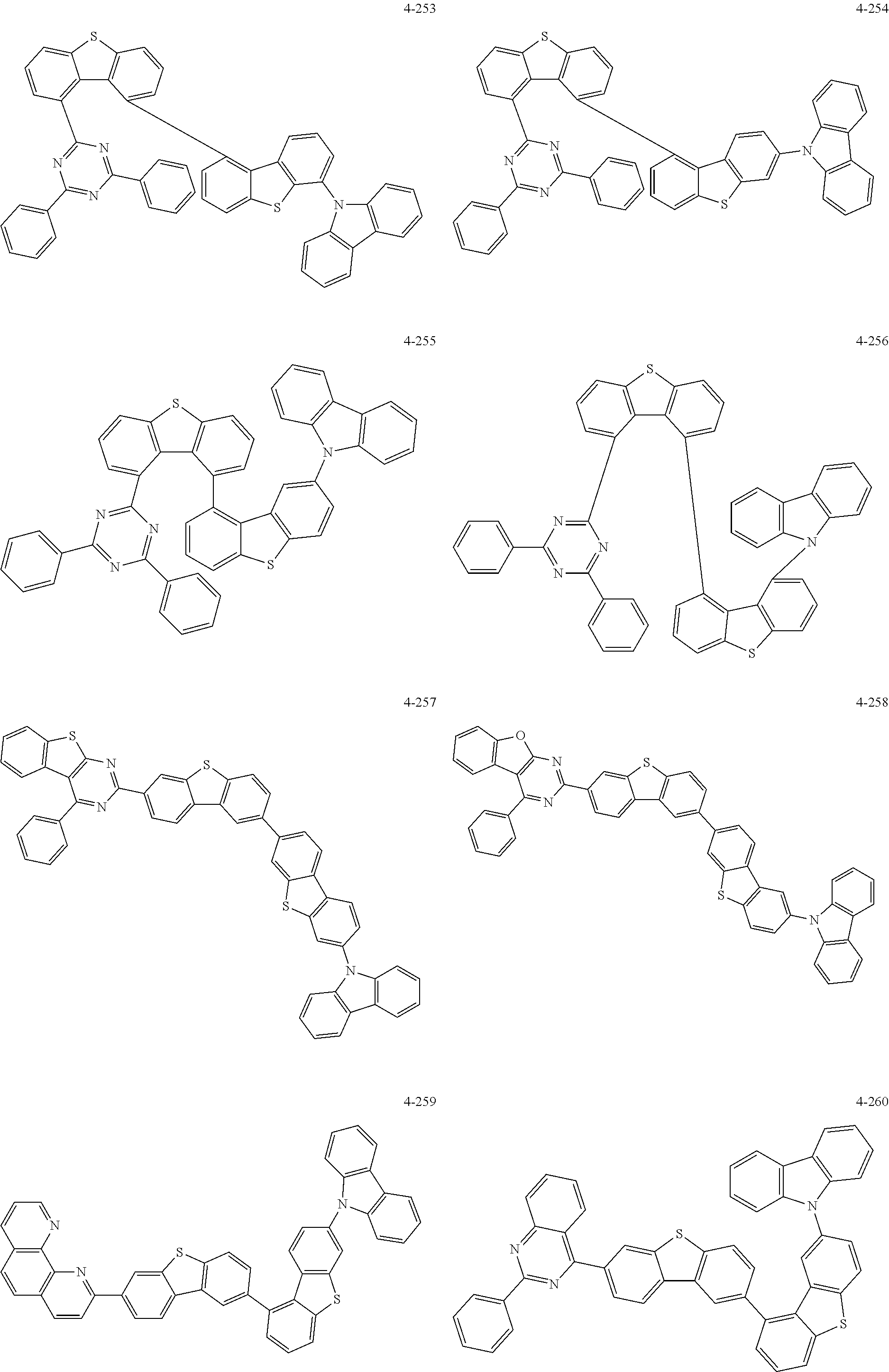

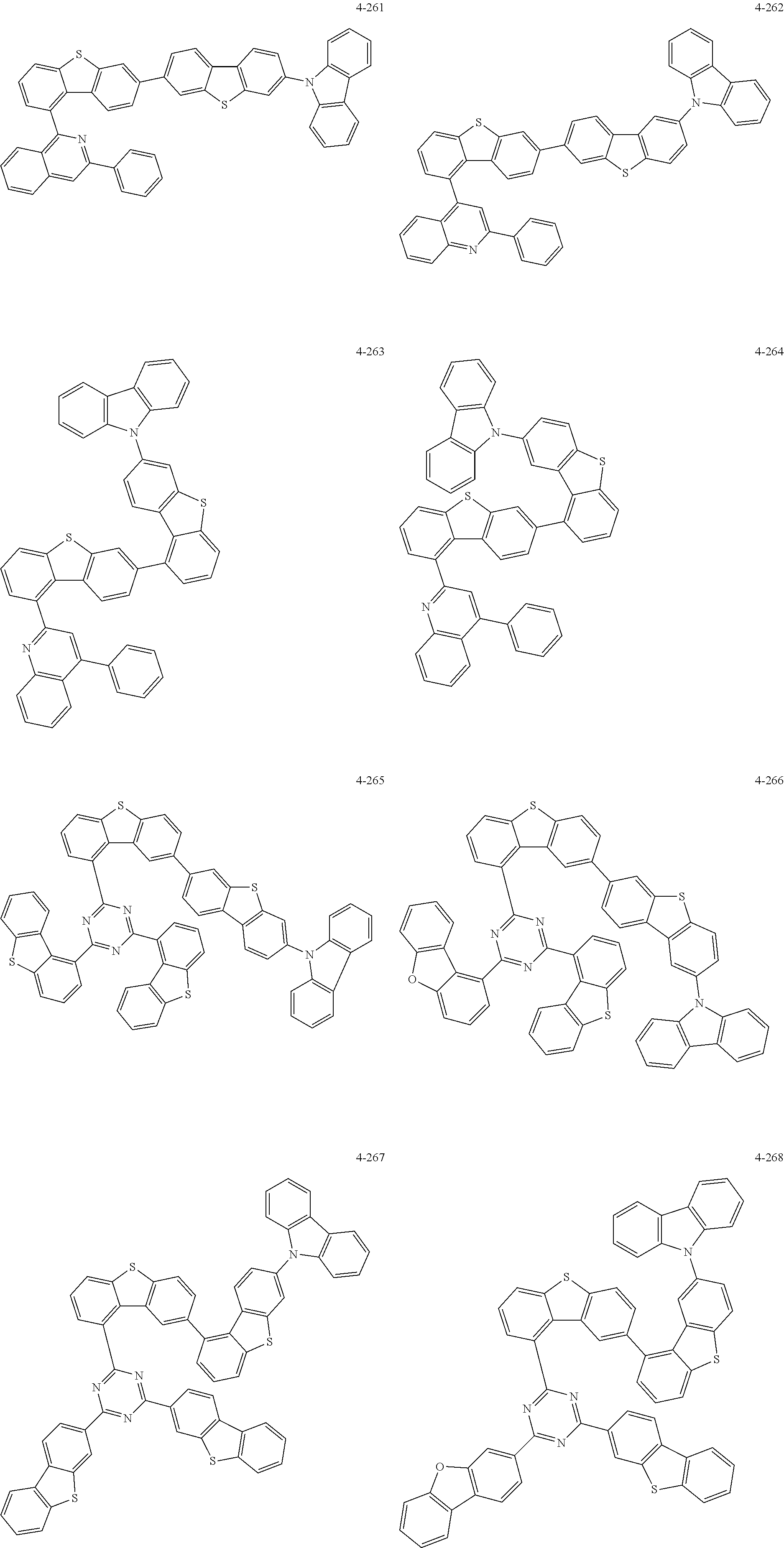

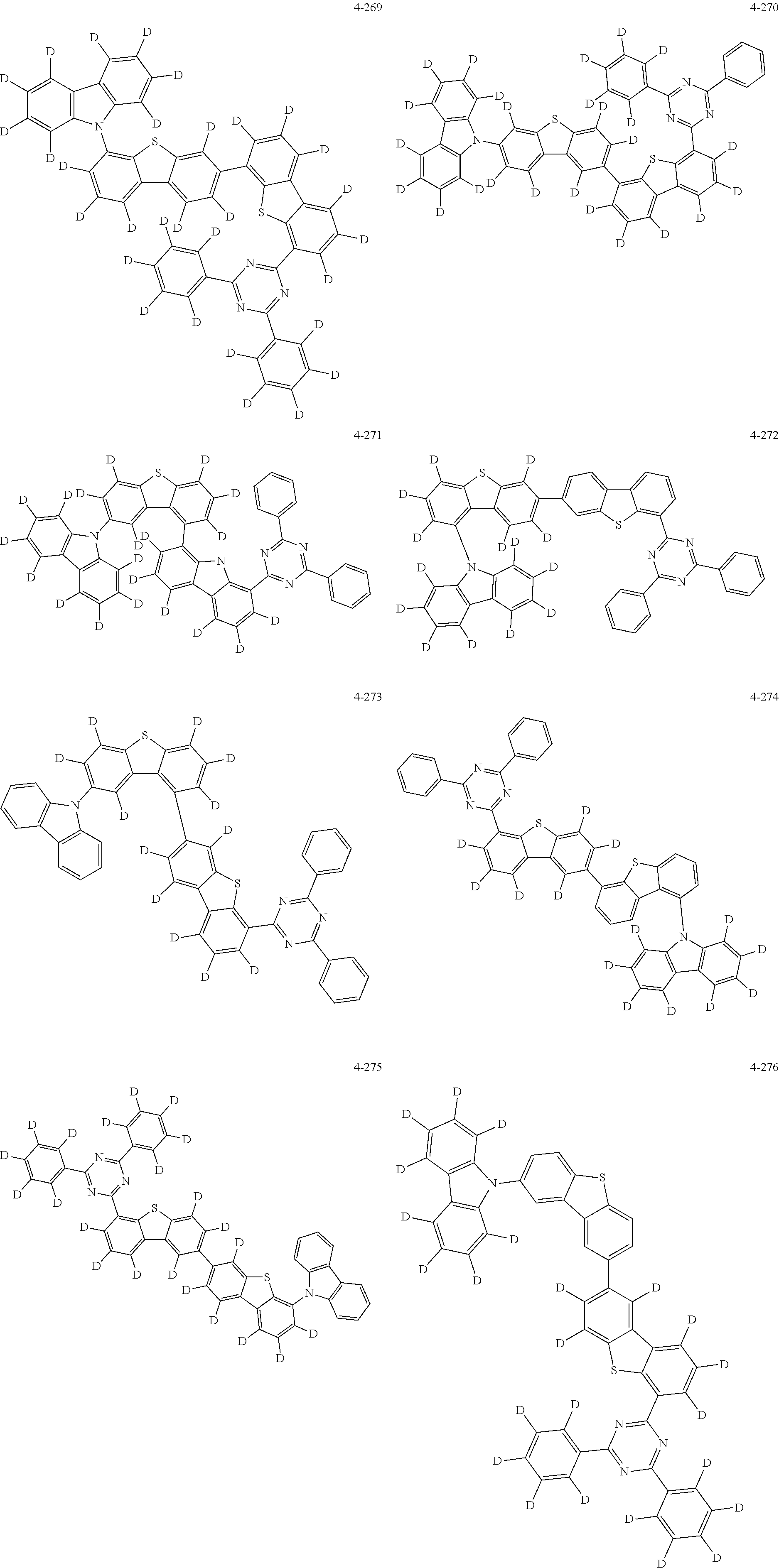

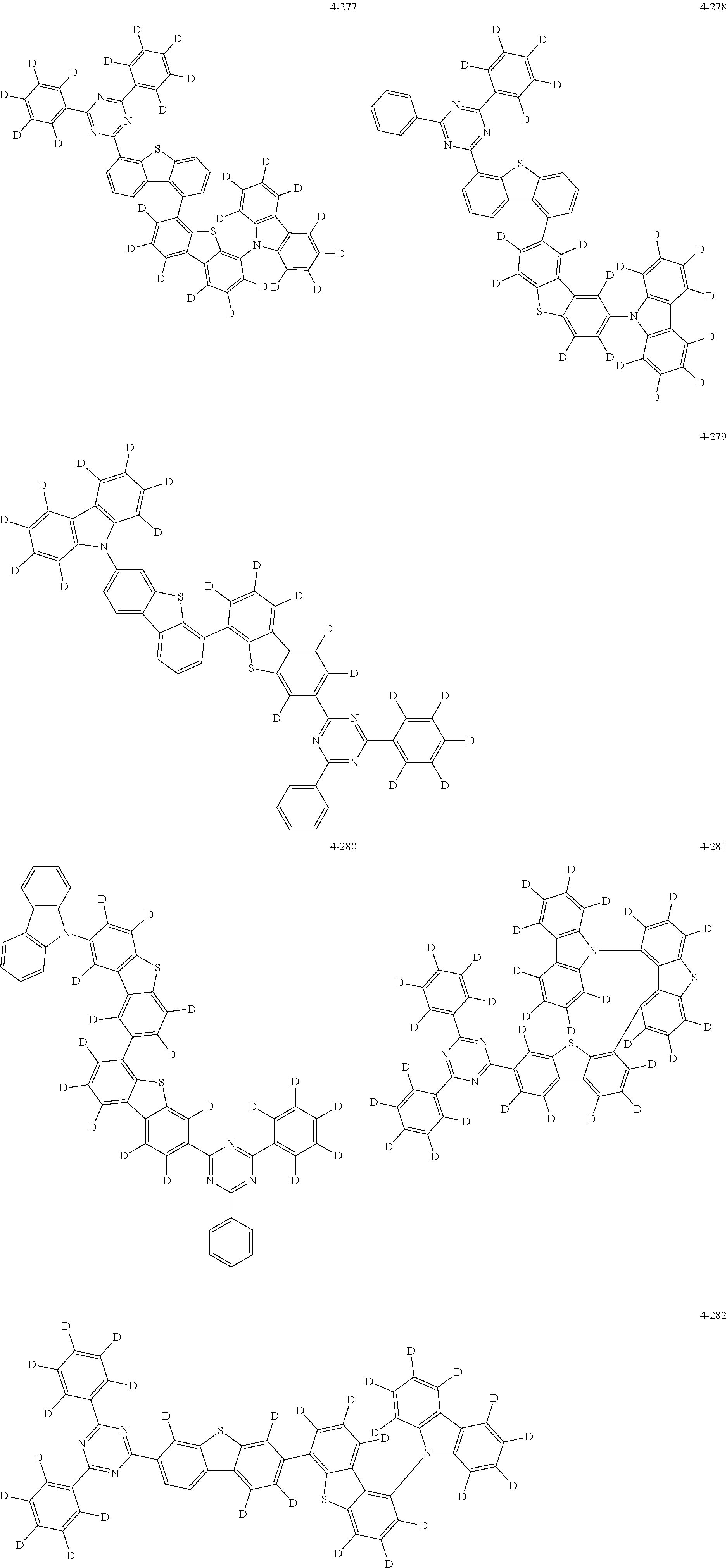

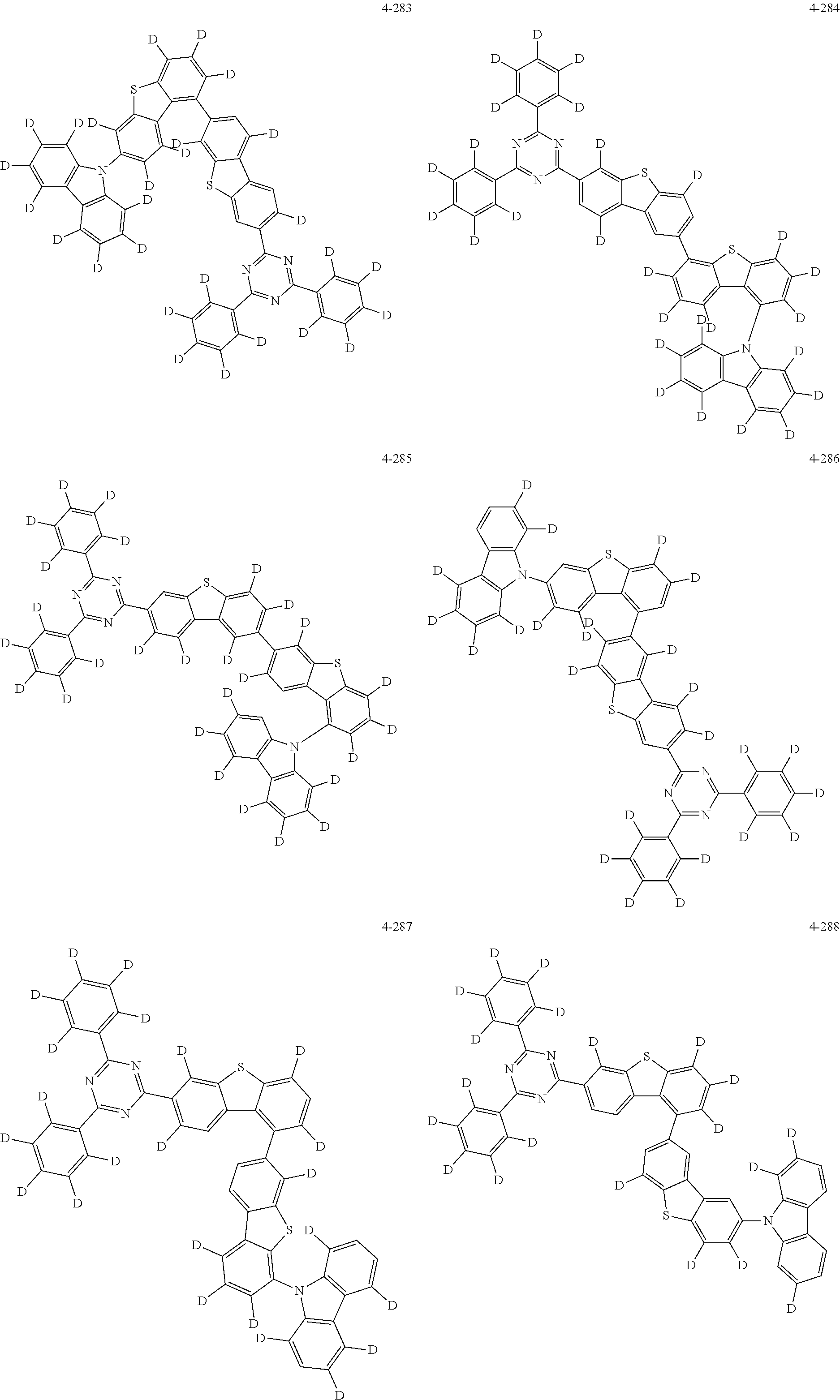

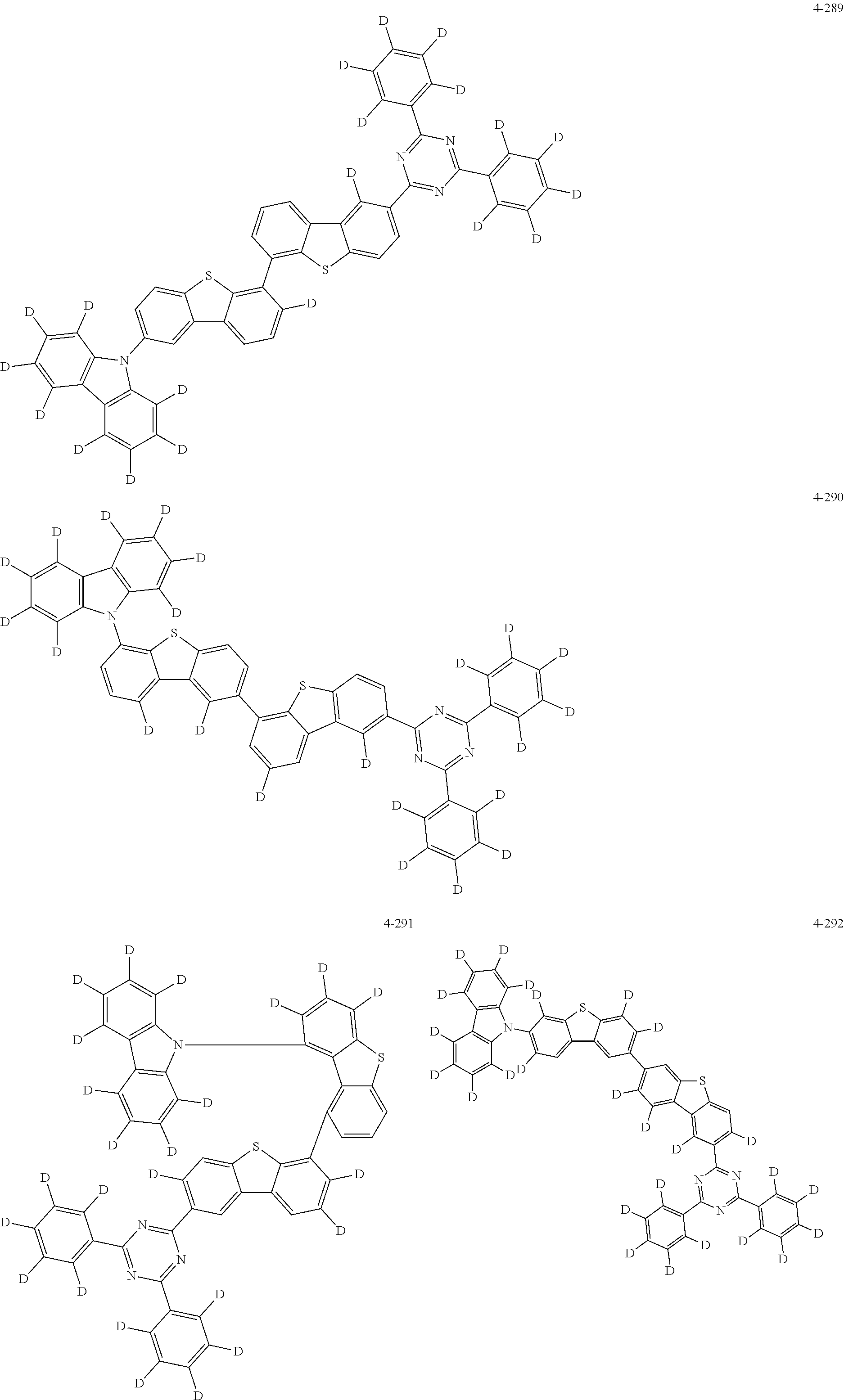

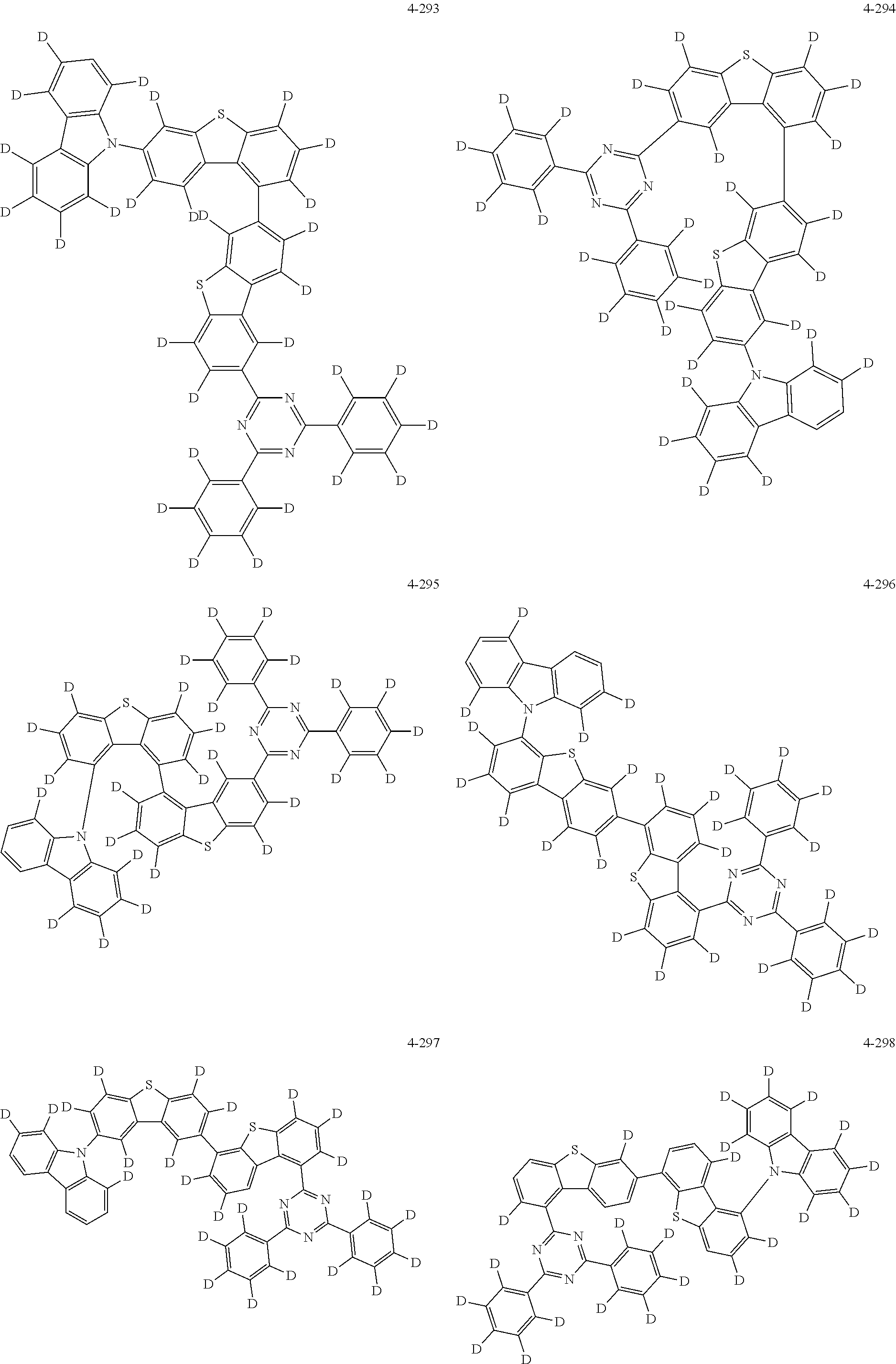

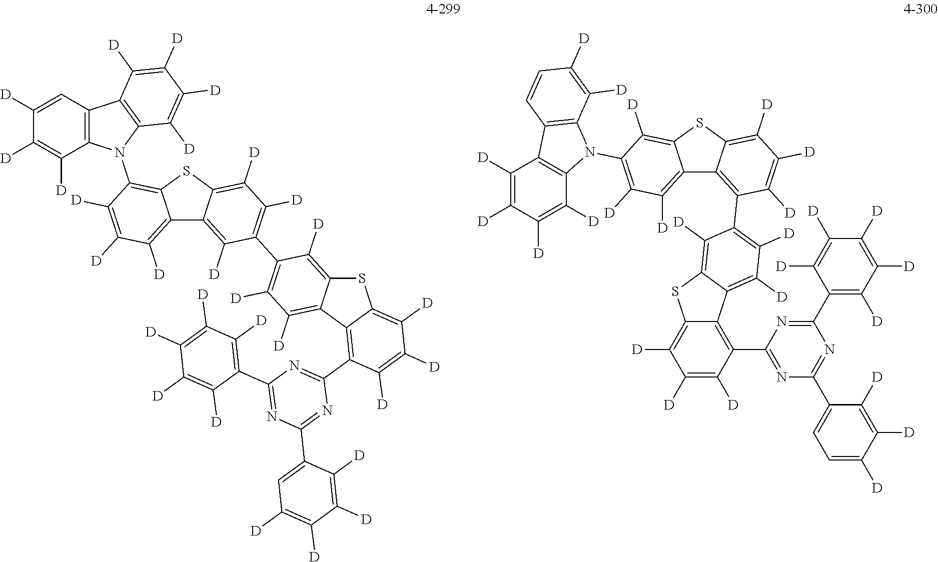

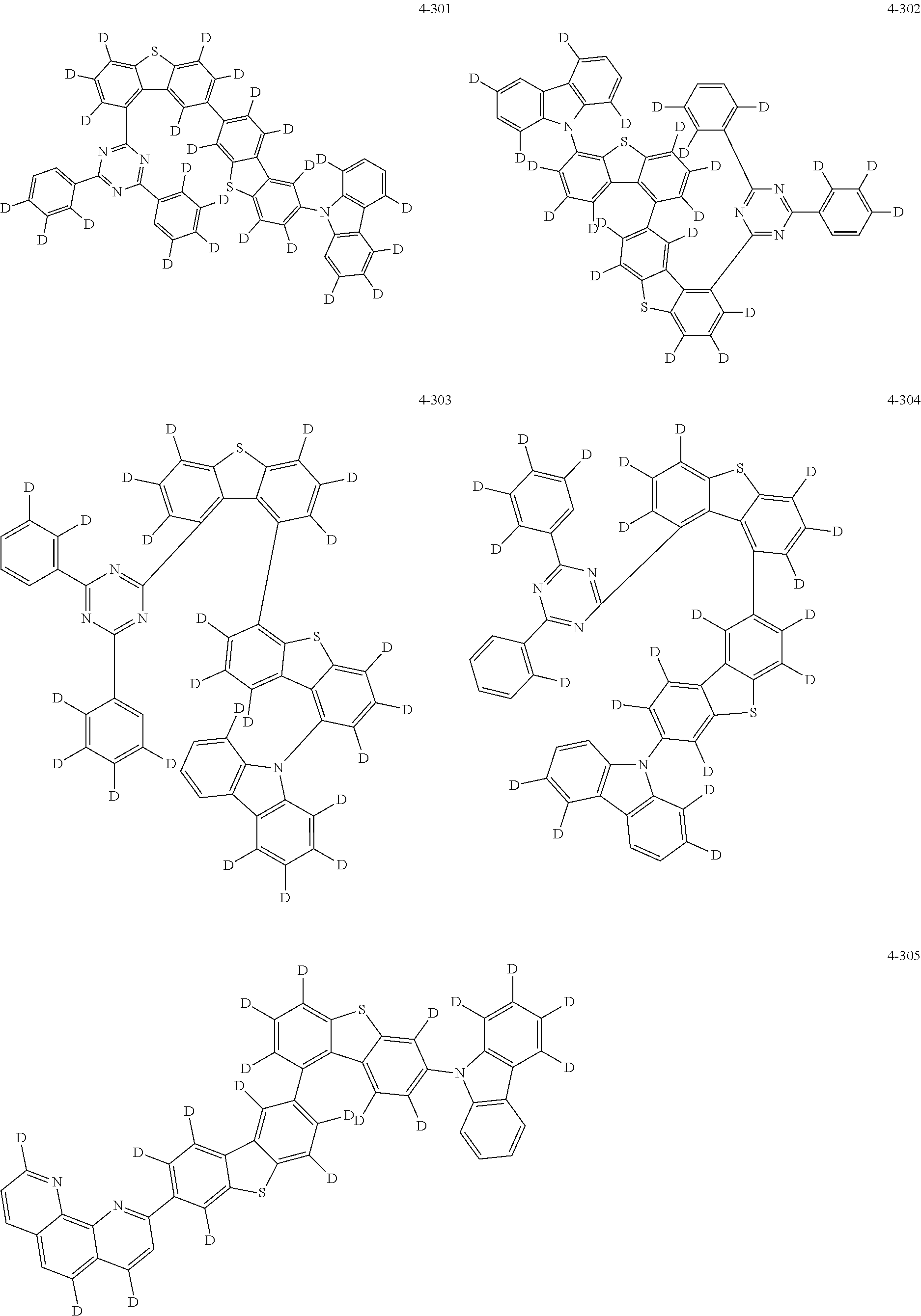

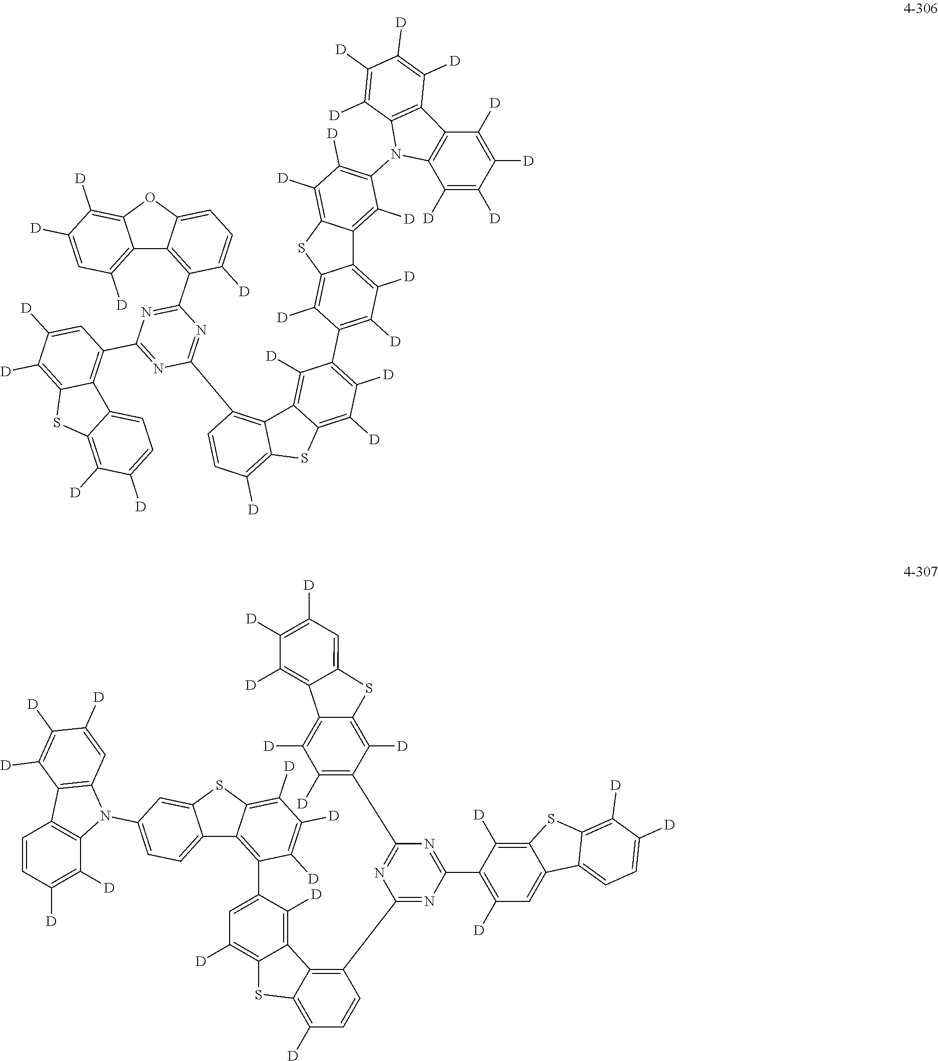

11. The composition of claim 1, wherein the second compound is represented by any one of the following compounds:

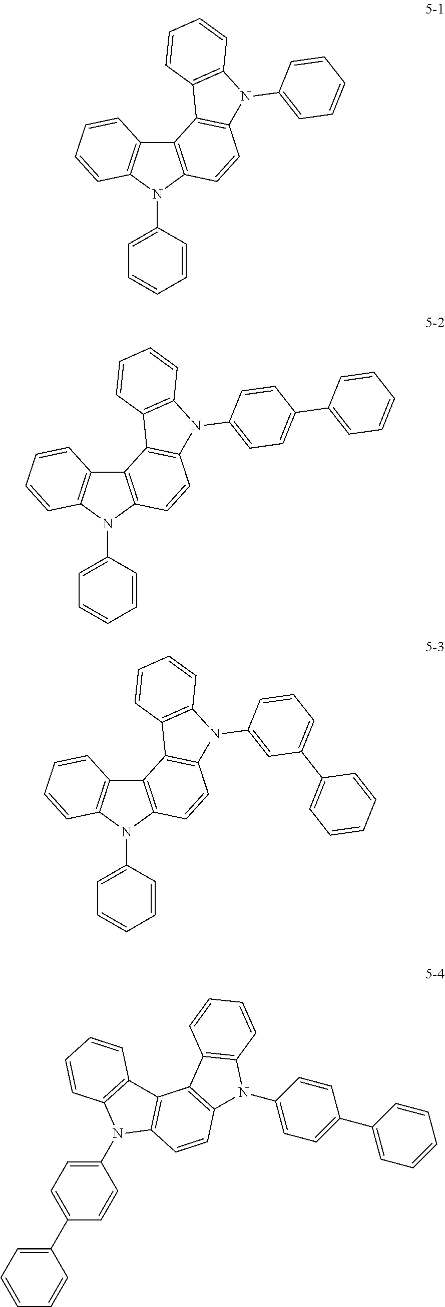 [SMILES: c1ccc(-n2c3ccccc3c3c4c5ccccc5n(-c5ccccc5)c4ccc32)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1 ; c1ccc(-c2ccc(-n3c4ccccc4c4c5c6ccccc6n(-c6ccc(-c7ccccc7)cc6)c5ccc43)cc2)cc1]

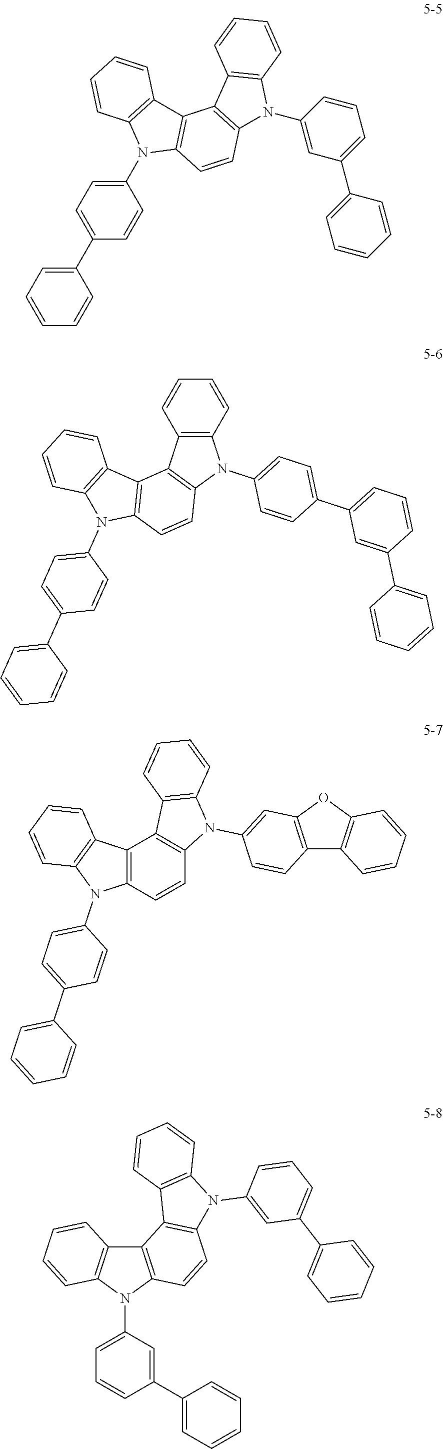 [SMILES: c1ccc(-c2ccc(-n3c4ccccc4c4c5c6ccccc6n(-c6cccc(-c7ccccc7)c6)c5ccc43)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1 ; c1ccc(-c2ccc(-n3c4ccccc4c4c5c6ccccc6n(-c6ccc7c(c6)oc6ccccc67)c5ccc43)cc2)cc1 ; c1ccc(-c2cccc(-n3c4ccccc4c4c5c6ccccc6n(-c6cccc(-c7ccccc7)c6)c5ccc43)c2)cc1]

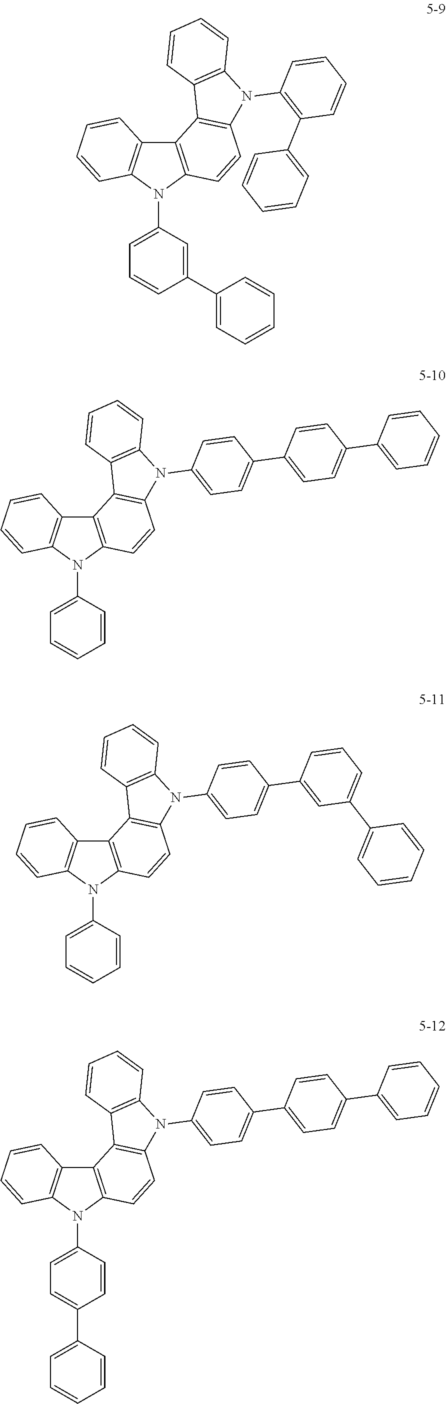 [SMILES: c1ccc(-c2cccc(-n3c4ccccc4c4c5c6ccccc6n(-c6ccccc6-c6ccccc6)c5ccc43)c2)cc1 ; c1ccc(-c2ccc(-c3ccc(-n4c5ccccc5c5c6c7ccccc7n(-c7ccccc7)c6ccc54)cc3)cc2)cc1 ; c1ccc(-c2cccc(-c3ccc(-n4c5ccccc5c5c6c7ccccc7n(-c7ccccc7)c6ccc54)cc3)c2)cc1 ; c1ccc(-c2ccc(-c3ccc(-n4c5ccccc5c5c6c7ccccc7n(-c7ccc(-c8ccccc8)cc7)c6ccc54)cc3)cc2)cc1]

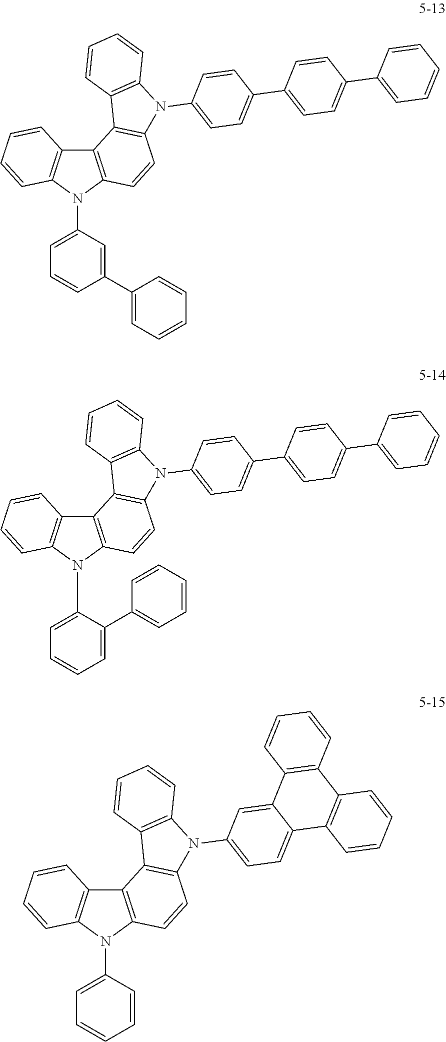 [SMILES: c1ccc(-c2ccc(-c3ccc(-n4c5ccccc5c5c6c7ccccc7n(-c7cccc(-c8ccccc8)c7)c6ccc54)cc3)cc2)cc1 ; c1ccc(-c2ccc(-c3ccc(-n4c5ccccc5c5c6c7ccccc7n(-c7ccccc7-c7ccccc7)c6ccc54)cc3)cc2)cc1 ; c1ccc(-n2c3ccccc3c3c4c5ccccc5n(-c5ccc6c7ccccc7c7ccccc7c6c5)c4ccc32)cc1]

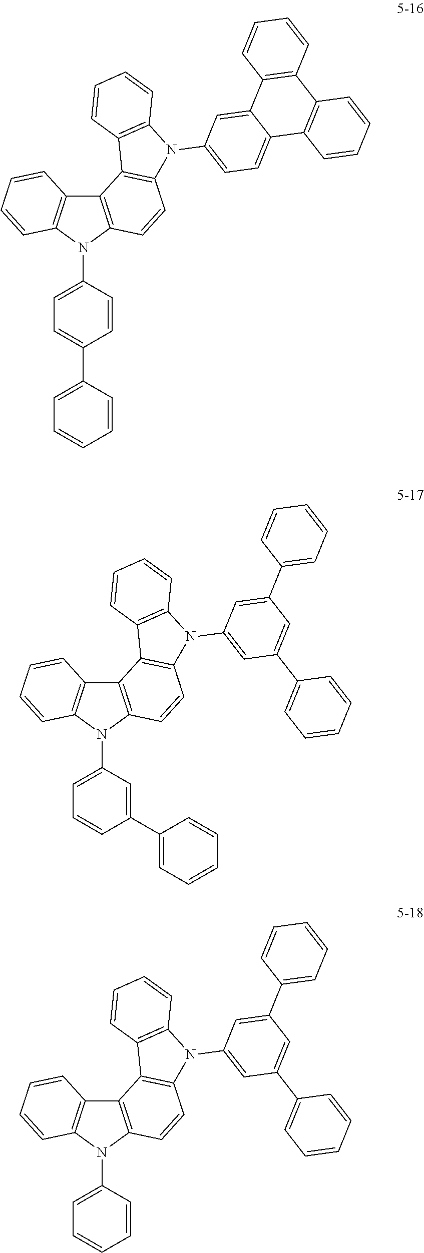 [SMILES: c1ccc(-c2ccc(-n3c4ccccc4c4c5c6ccccc6n(-c6ccc7c8ccccc8c8ccccc8c7c6)c5ccc43)cc2)cc1 ; c1ccc(-c2cccc(-n3c4ccccc4c4c5c6ccccc6n(-c6cc(-c7ccccc7)cc(-c7ccccc7)c6)c5ccc43)c2)cc1 ; c1ccc(-c2cc(-c3ccccc3)cc(-n3c4ccccc4c4c5c6ccccc6n(-c6ccccc6)c5ccc43)c2)cc1]

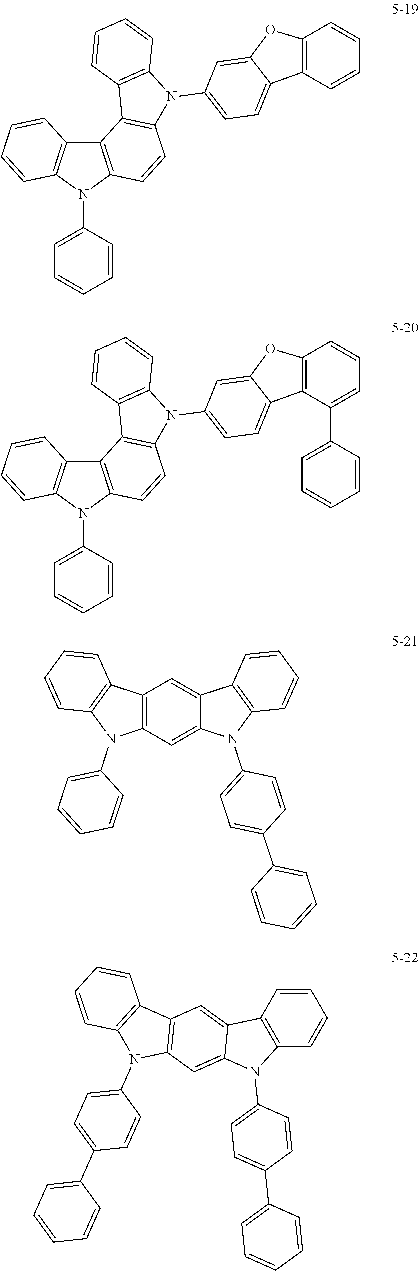

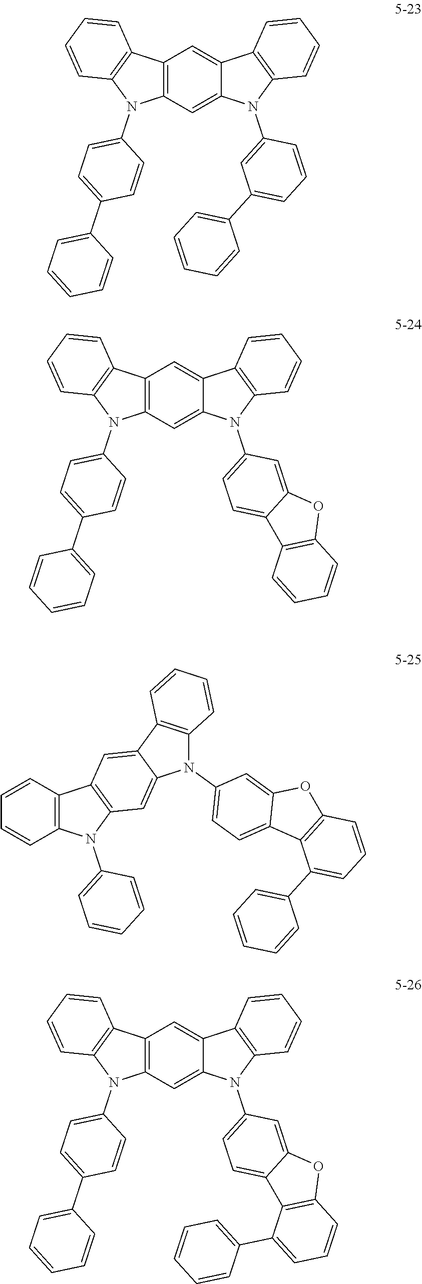

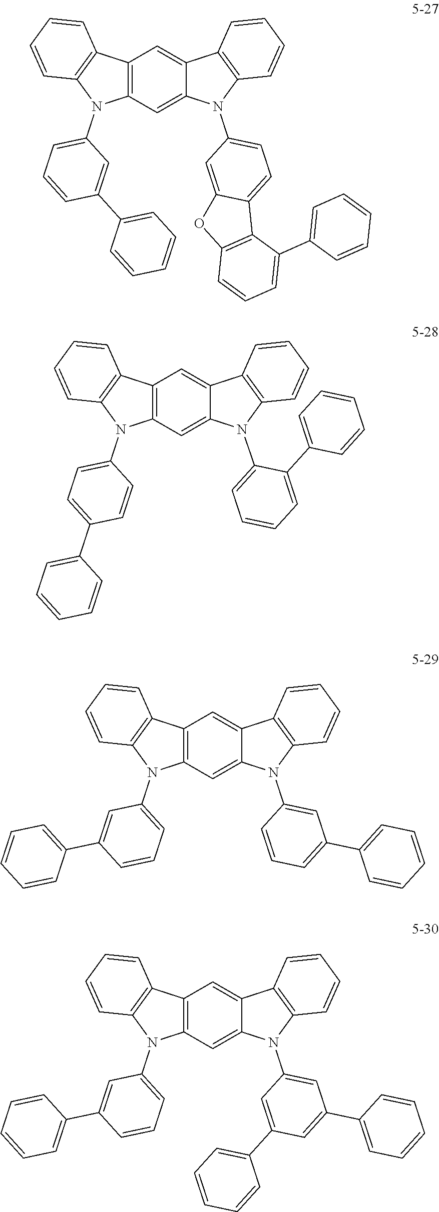

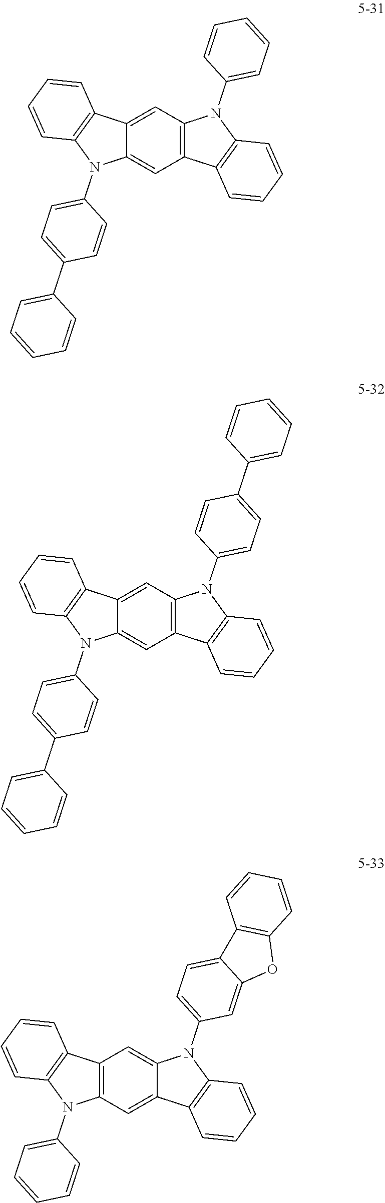 [SMILES: c1ccc(-c2ccc(-n3c4ccccc4c4cc5c(cc43)c3ccccc3n5-c3ccccc3)cc2)cc1 ; c1ccc(-c2ccc(-n3c4ccccc4c4cc5c(cc43)c3ccccc3n5-c3ccc(-c4ccccc4)cc3)cc2)cc1 ; c1ccc(-n2c3ccccc3c3cc4c(cc32)c2ccccc2n4-c2ccc3c(c2)oc2ccccc23)cc1]

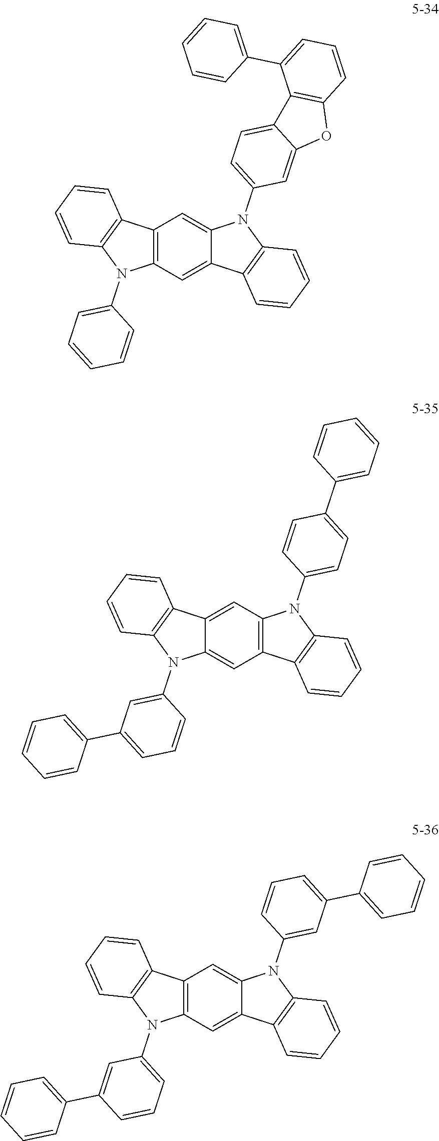 [SMILES: c1ccc(-c2cccc3oc4cc(-n5c6ccccc6c6cc7c(cc65)c5ccccc5n7-c5ccccc5)ccc4c23)cc1 ; c1ccc(-c2ccc(-n3c4ccccc4c4cc5c(cc43)c3ccccc3n5-c3cccc(-c4ccccc4)c3)cc2)cc1 ; c1ccc(-c2cccc(-n3c4ccccc4c4cc5c(cc43)c3ccccc3n5-c3cccc(-c4ccccc4)c3)c2)cc1]

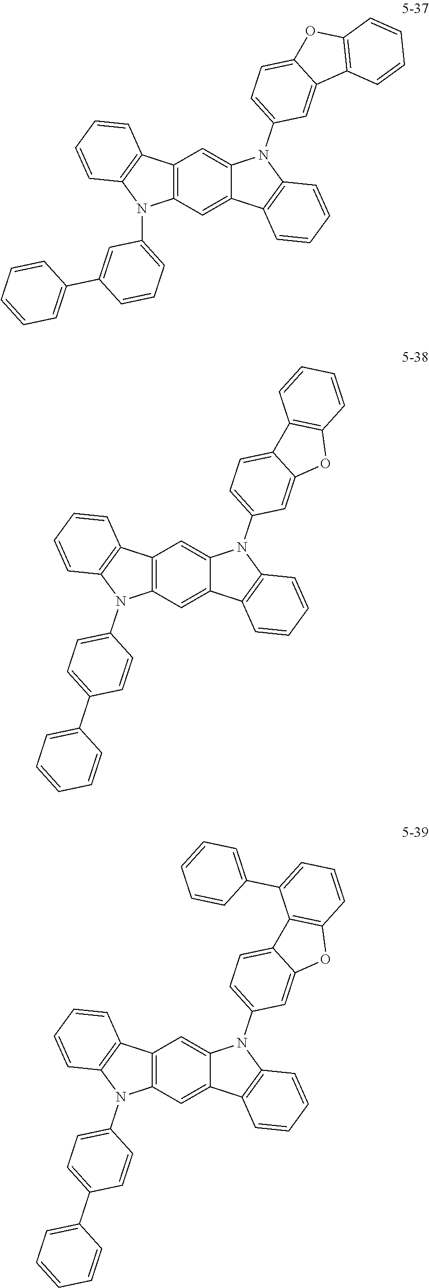 [SMILES: c1ccc(-c2cccc(-n3c4ccccc4c4cc5c(cc43)c3ccccc3n5-c3ccc4oc5ccccc5c4c3)c2)cc1 ; c1ccc(-c2ccc(-n3c4ccccc4c4cc5c(cc43)c3ccccc3n5-c3ccc4c(c3)oc3ccccc34)cc2)cc1 ; c1ccc(-c2ccc(-n3c4ccccc4c4cc5c(cc43)c3ccccc3n5-c3ccc4c(c3)oc3cccc(-c5ccccc5)c34)cc2)cc1]

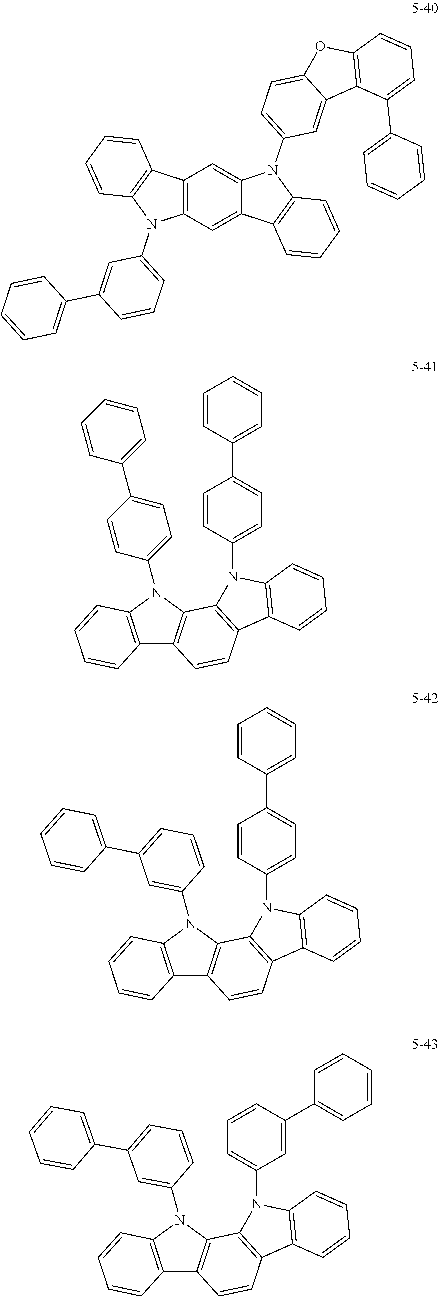 [SMILES: c1ccc(-c2cccc(-n3c4ccccc4c4cc5c(cc43)c3ccccc3n5-c3ccc4oc5cccc(-c6ccccc6)c5c4c3)c2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1 ; c1ccc(-c2cccc(-n3c4ccccc4c4ccc5c6ccccc6n(-c6cccc(-c7ccccc7)c6)c5c43)c2)cc1]

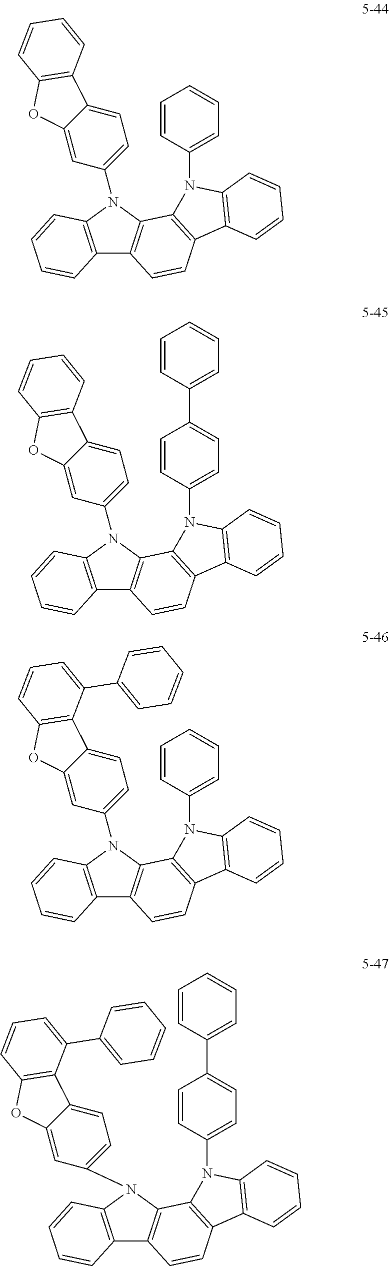

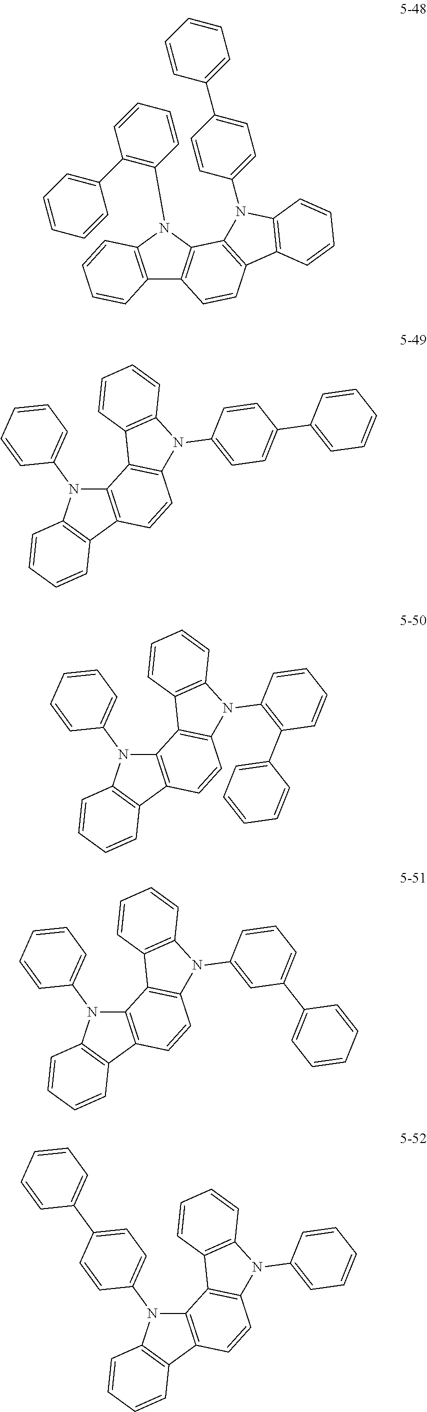

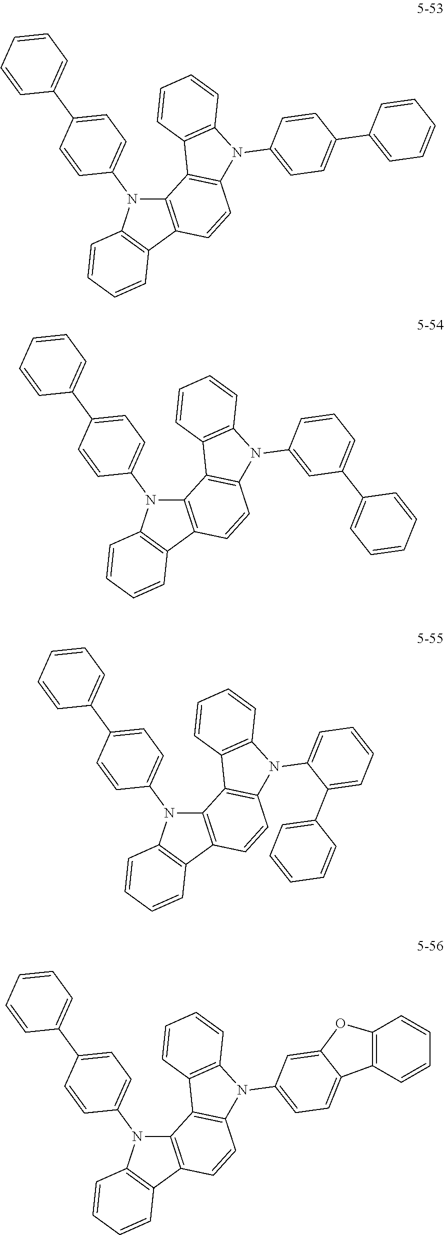 [SMILES: c1ccc(-c2ccc(-n3c4ccccc4c4c3ccc3c5ccccc5n(-c5ccc(-c6ccccc6)cc5)c34)cc2)cc1 ; c1ccc(-c2ccc(-n3c4ccccc4c4ccc5c(c6ccccc6n5-c5cccc(-c6ccccc6)c5)c43)cc2)cc1 ; c1ccc(-c2ccc(-n3c4ccccc4c4ccc5c(c6ccccc6n5-c5ccccc5-c5ccccc5)c43)cc2)cc1 ; c1ccc(-c2ccc(-n3c4ccccc4c4ccc5c(c6ccccc6n5-c5ccc6c(c5)oc5ccccc56)c43)cc2)cc1]

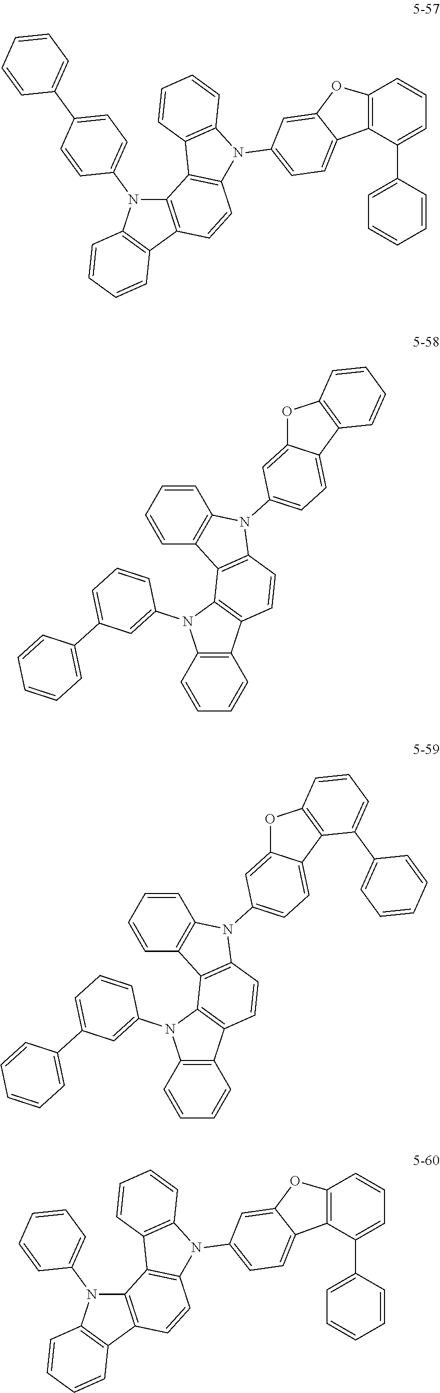 [SMILES: c1ccc(-c2ccc(-n3c4ccccc4c4ccc5c(c6ccccc6n5-c5ccc6c(c5)oc5cccc(-c7ccccc7)c56)c43)cc2)cc1 ; c1ccc(-c2cccc(-n3c4ccccc4c4ccc5c(c6ccccc6n5-c5ccc6c(c5)oc5ccccc56)c43)c2)cc1 ; c1ccc(-c2cccc(-n3c4ccccc4c4ccc5c(c6ccccc6n5-c5ccc6c(c5)oc5cccc(-c7ccccc7)c56)c43)c2)cc1 ; c1ccc(-c2cccc3oc4cc(-n5c6ccccc6c6c5ccc5c7ccccc7n(-c7ccccc7)c56)ccc4c23)cc1]

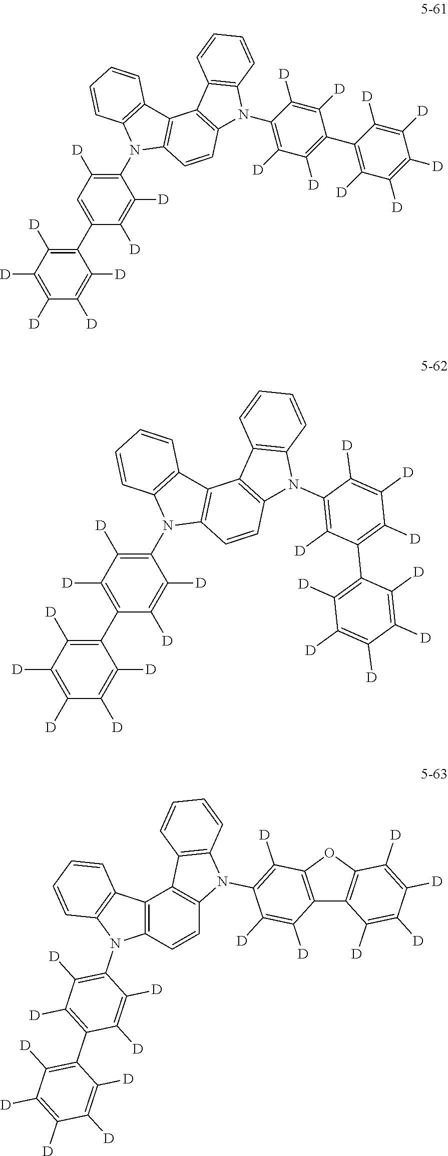

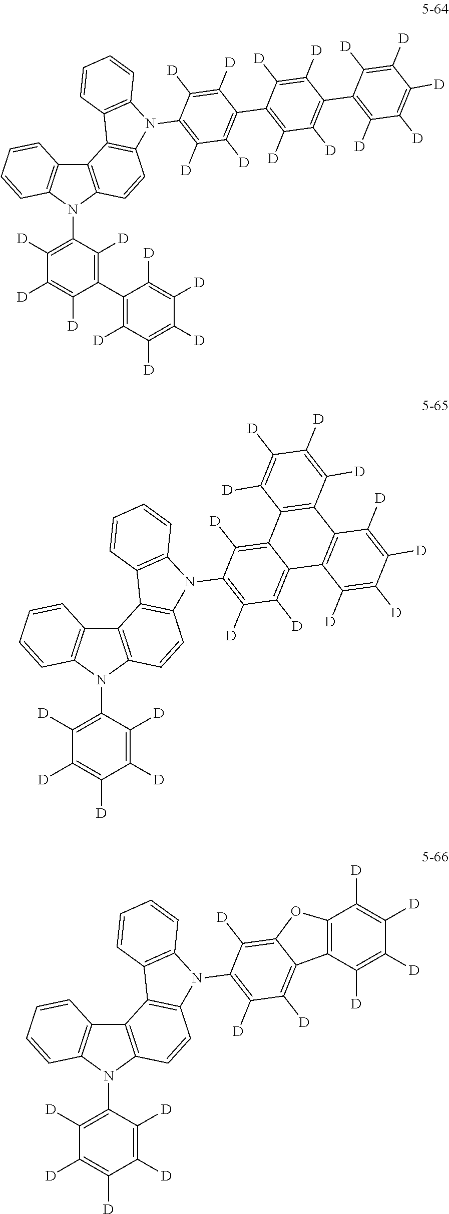

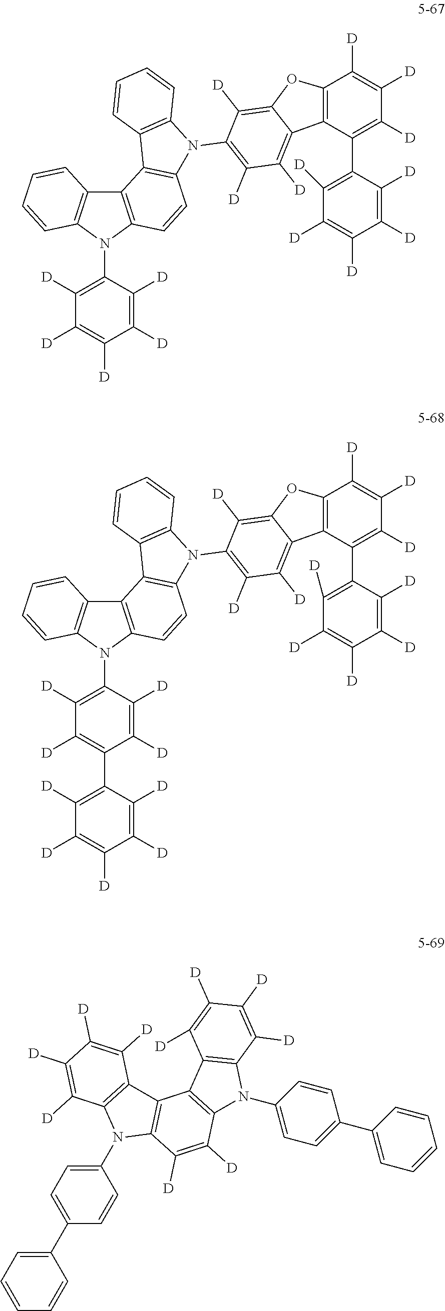 [SMILES: [2H]c1c([2H])c([2H])c(-c2c([2H])c([2H])c([2H])c3oc4c([2H])c(-n5c6ccccc6c6c7c8ccccc8n(-c8c([2H])c([2H])c([2H])c([2H])c8[2H])c7ccc65)c([2H])c([2H])c4c23)c([2H])c1[2H] ; [2H]c1c([2H])c([2H])c(-c2c([2H])c([2H])c(-n3c4ccccc4c4c5c6ccccc6n(-c6c([2H])c([2H])c7c(oc8c([2H])c([2H])c([2H])c(-c9c([2H])c([2H])c([2H])c([2H])c9[2H])c87)c6[2H])c5ccc43)c([2H])c2[2H])c([2H])c1[2H] ; [2H]c1c([2H])c([2H])c2c(c1[2H])c1c3c4c([2H])c([2H])c([2H])c([2H])c4n(-c4ccc(-c5ccccc5)cc4)c3c([2H])c([2H])c1n2-c1ccc(-c2ccccc2)cc1]

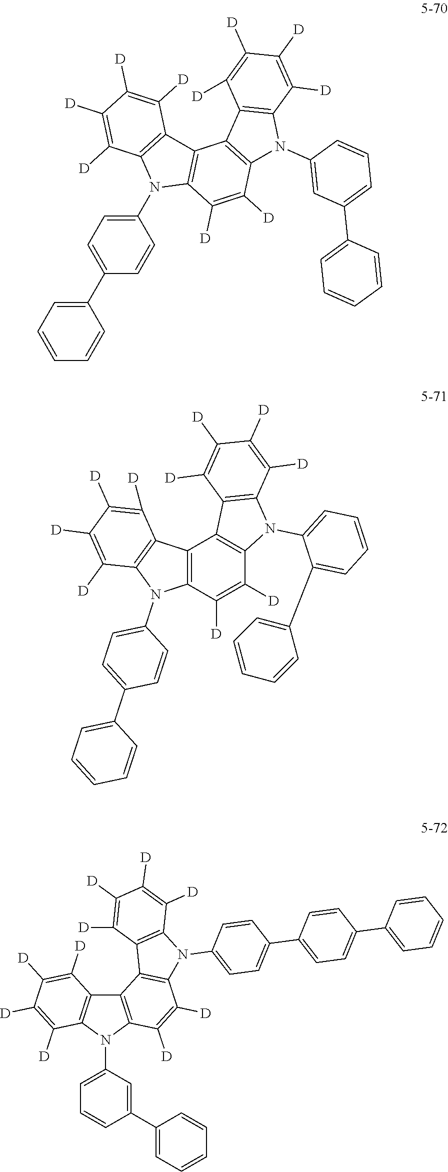 [SMILES: [2H]c1c([2H])c([2H])c2c(c1[2H])c1c3c4c([2H])c([2H])c([2H])c([2H])c4n(-c4cccc(-c5ccccc5)c4)c3c([2H])c([2H])c1n2-c1ccc(-c2ccccc2)cc1 ; [2H]c1c([2H])c([2H])c2c(c1[2H])c1c3c4c([2H])c([2H])c([2H])c([2H])c4n(-c4ccccc4-c4ccccc4)c3c([2H])c([2H])c1n2-c1ccc(-c2ccccc2)cc1 ; [2H]c1c([2H])c([2H])c2c(c1[2H])c1c3c4c([2H])c([2H])c([2H])c([2H])c4n(-c4cccc(-c5ccccc5)c4)c3c([2H])c([2H])c1n2-c1ccc(-c2ccc(-c3ccccc3)cc2)cc1]

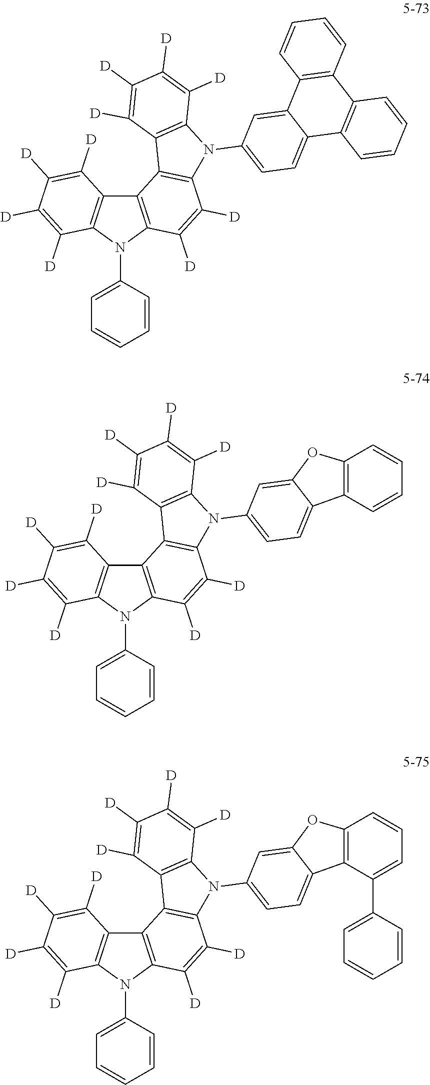 [SMILES: [2H]c1c([2H])c([2H])c2c(c1[2H])c1c3c4c([2H])c([2H])c([2H])c([2H])c4n(-c4ccc5c6ccccc6c6ccccc6c5c4)c3c([2H])c([2H])c1n2-c1ccccc1 ; [2H]c1c([2H])c([2H])c2c(c1[2H])c1c3c4c([2H])c([2H])c([2H])c([2H])c4n(-c4ccc5c(c4)oc4ccccc45)c3c([2H])c([2H])c1n2-c1ccccc1 ; [2H]c1c([2H])c([2H])c2c(c1[2H])c1c3c4c([2H])c([2H])c([2H])c([2H])c4n(-c4ccc5c(c4)oc4cccc(-c6ccccc6)c45)c3c([2H])c([2H])c1n2-c1ccccc1]

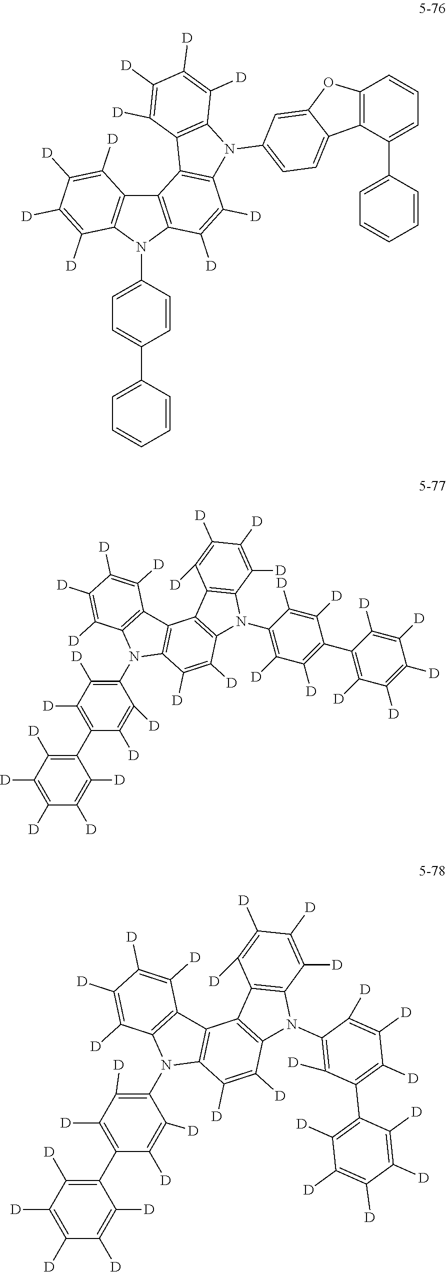

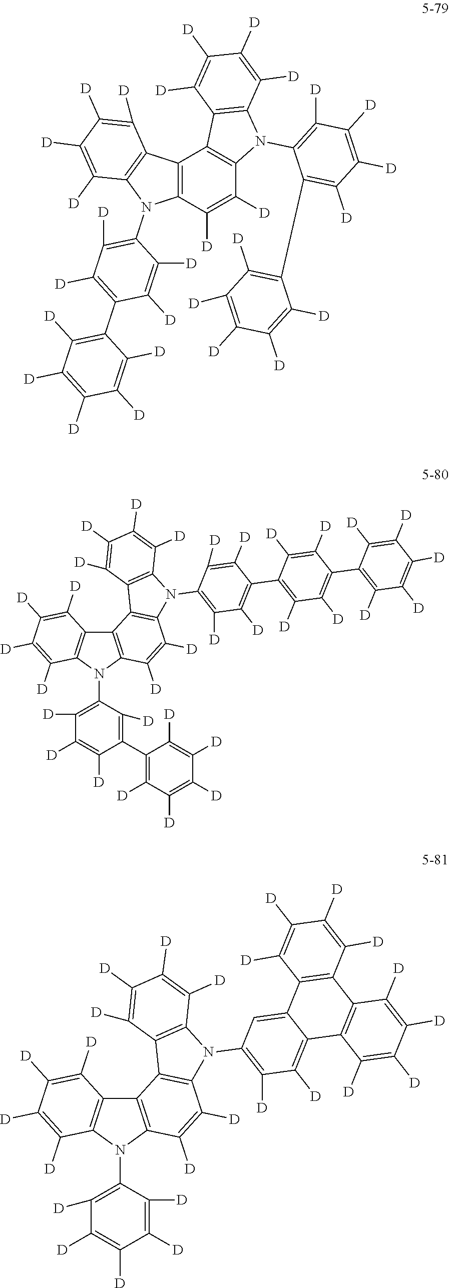

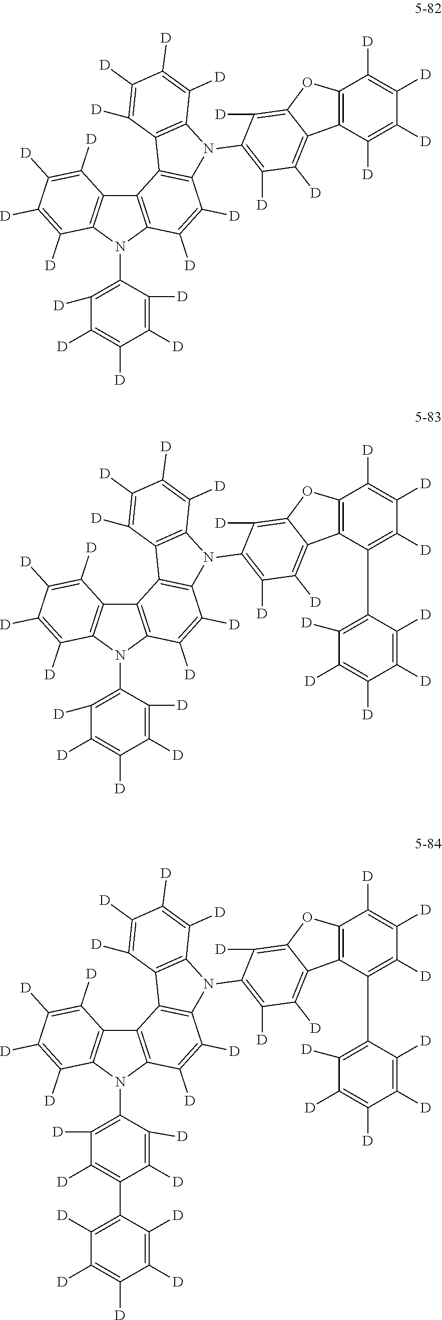

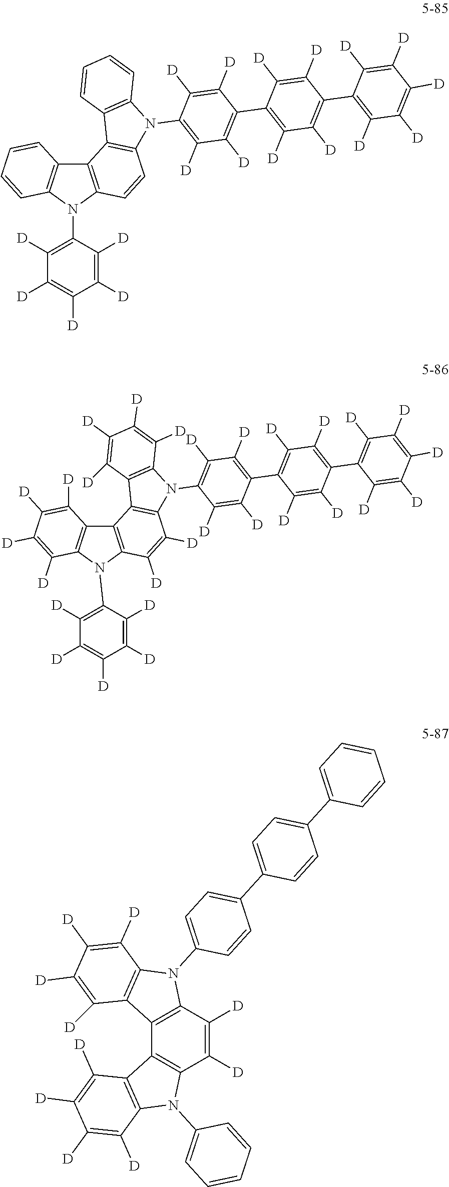

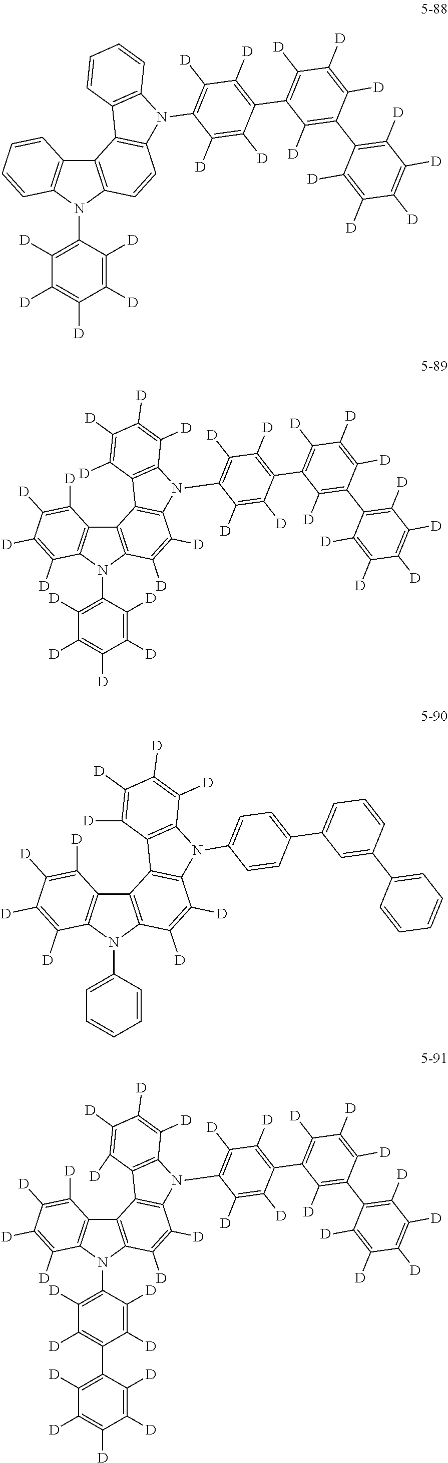

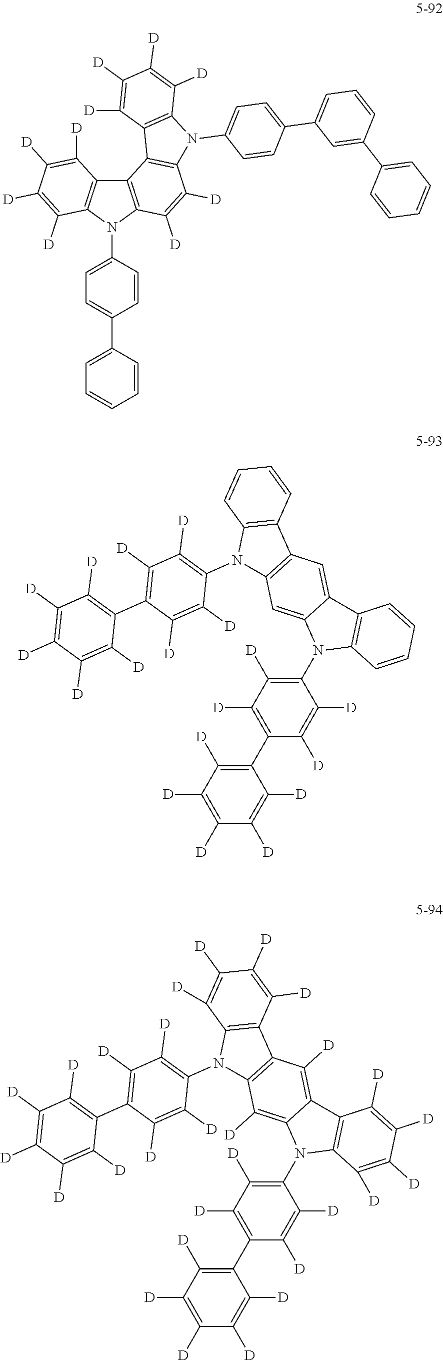

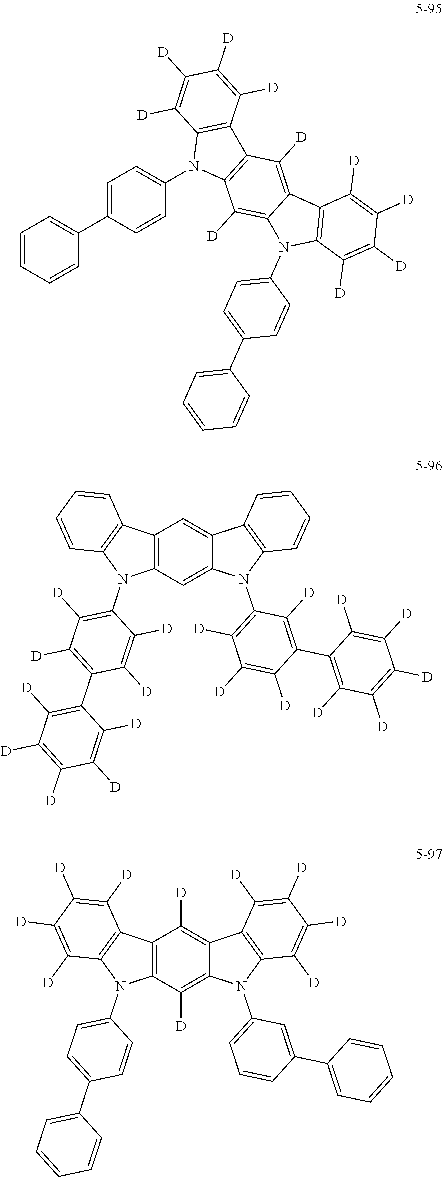 [SMILES: [2H]c1c([2H])c([2H])c2c(c1[2H])c1c([2H])c3c4c([2H])c([2H])c([2H])c([2H])c4n(-c4ccc(-c5ccccc5)cc4)c3c([2H])c1n2-c1ccc(-c2ccccc2)cc1 ; [2H]c1c([2H])c([2H])c(-c2c([2H])c([2H])c(-n3c4ccccc4c4cc5c6ccccc6n(-c6c([2H])c([2H])c([2H])c(-c7c([2H])c([2H])c([2H])c([2H])c7[2H])c6[2H])c5cc43)c([2H])c2[2H])c([2H])c1[2H] ; [2H]c1c([2H])c([2H])c2c(c1[2H])c1c([2H])c3c4c([2H])c([2H])c([2H])c([2H])c4n(-c4cccc(-c5ccccc5)c4)c3c([2H])c1n2-c1ccc(-c2ccccc2)cc1]

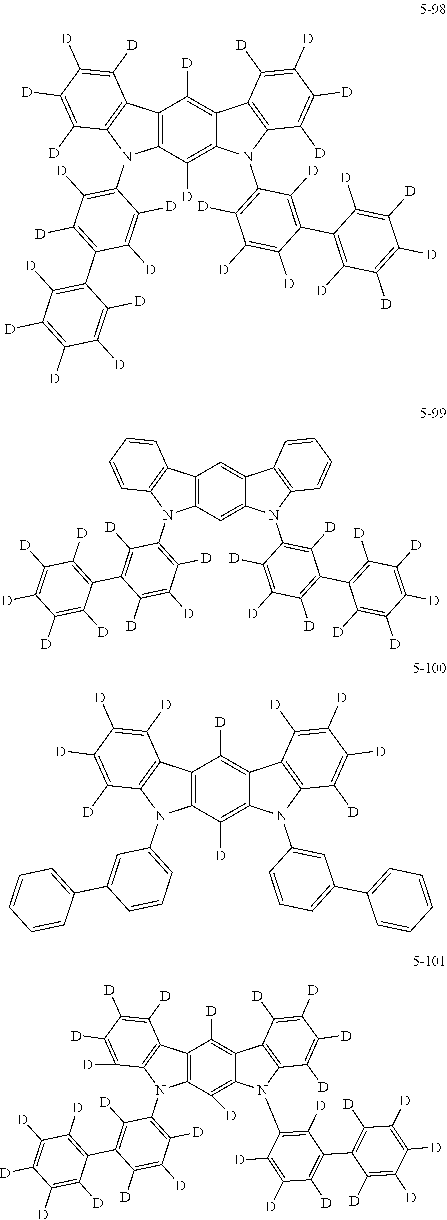

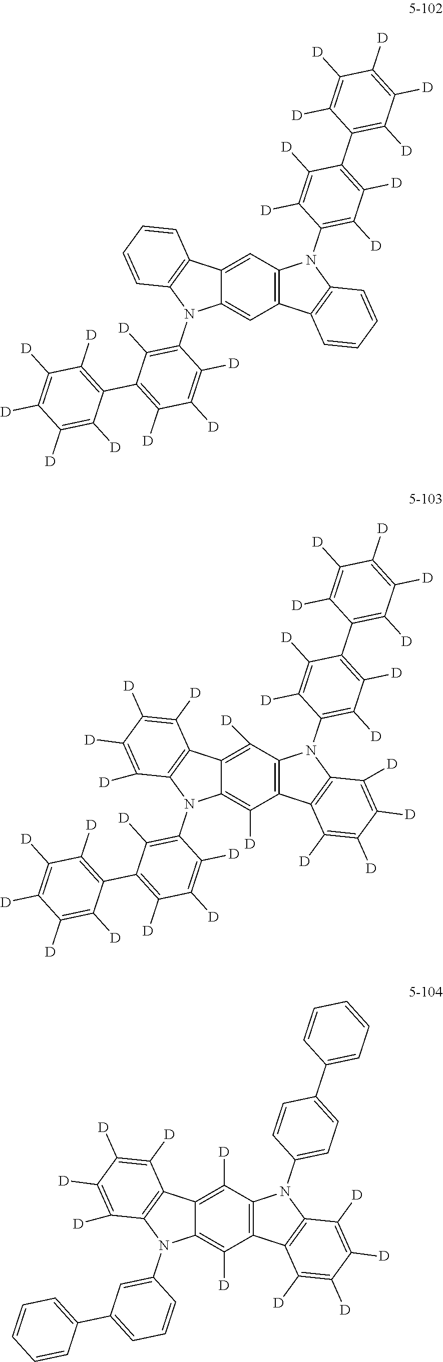

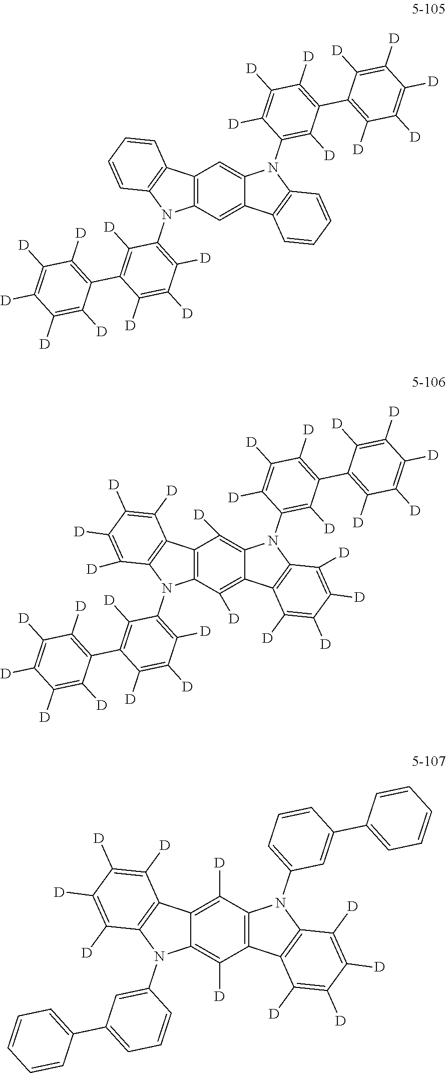

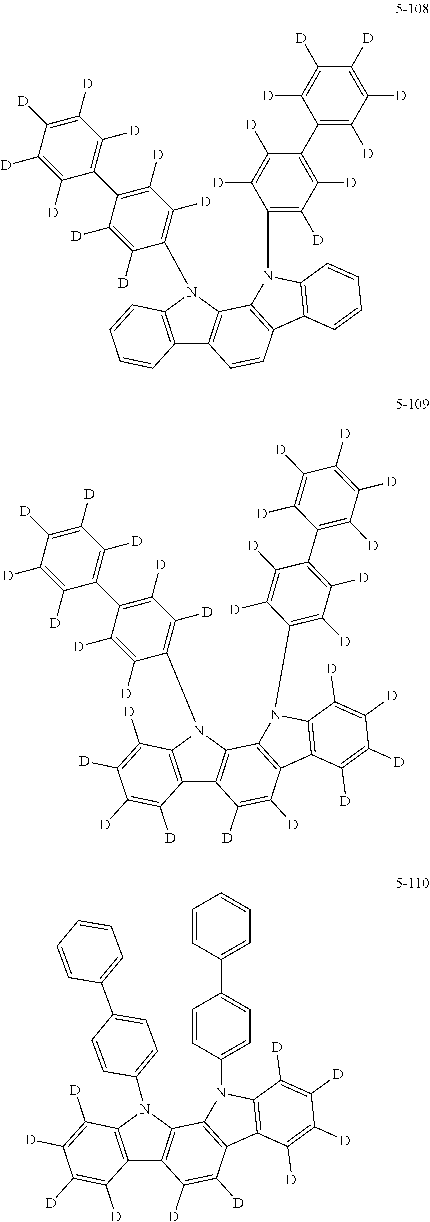

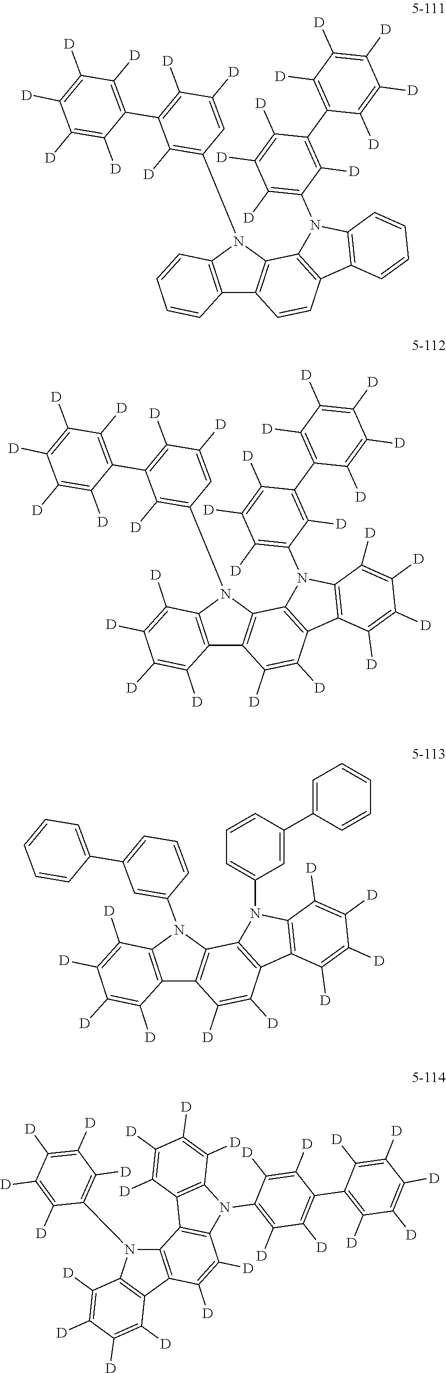

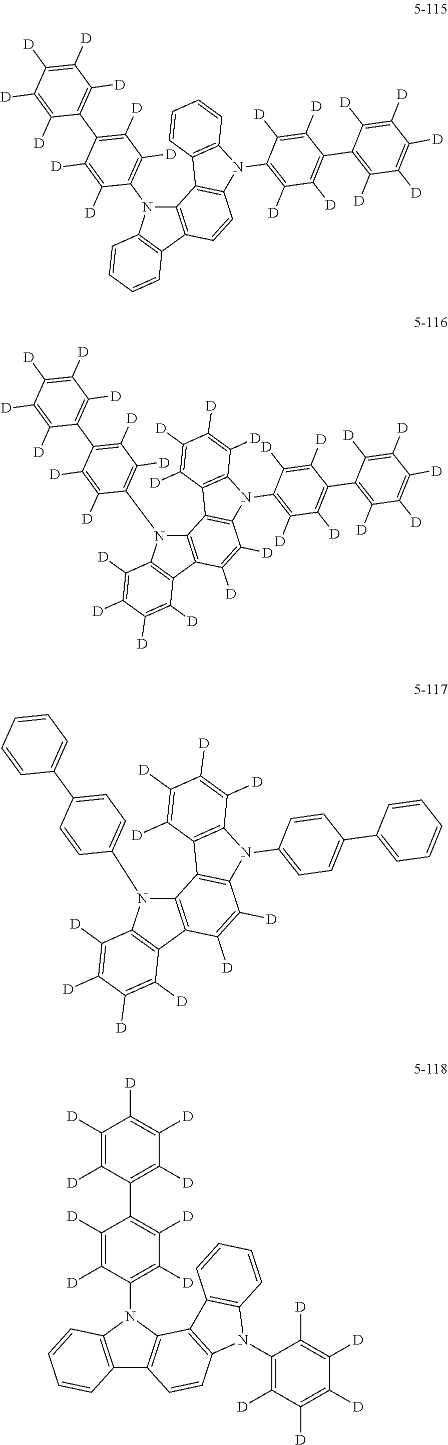

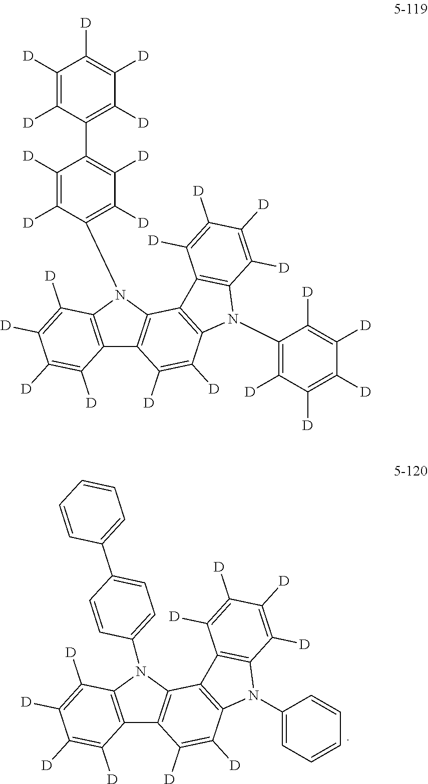 [SMILES: [2H]c1c([2H])c([2H])c(-c2c([2H])c([2H])c(-n3c4c([2H])c([2H])c([2H])c([2H])c4c4c([2H])c([2H])c5c(c6c([2H])c([2H])c([2H])c([2H])c6n5-c5c([2H])c([2H])c([2H])c([2H])c5[2H])c43)c([2H])c2[2H])c([2H])c1[2H] ; [2H]c1c([2H])c([2H])c2c(c1[2H])c1c(c([2H])c([2H])c3c4c([2H])c([2H])c([2H])c([2H])c4n(-c4ccc(-c5ccccc5)cc4)c31)n2-c1ccccc1]

12. An organic light emitting device comprising:
a first electrode;
a second electrode; and
an organic material layer having one or more layers provided between the first electrode and the second electrode,
wherein one or more layers of the organic material layer comprise one or more of the compositions of claim 1.

13. The organic light emitting device of claim 12, wherein the organic material layer comprises a light emitting layer, and the light emitting layer comprises the composition for an organic material layer of an organic light emitting device.

14. The organic light emitting device of claim 12, wherein the organic material layer comprises a light emitting layer, the light emitting layer comprises a host, and the host comprises the composition for an organic material layer of an organic light emitting device.

15. The organic light emitting device of claim 12, further comprising one or more layers selected from the group consisting of a light emitting layer, a hole injection layer, a hole transfer layer, an electron injection layer, an electron transfer layer, an electron blocking layer and a hole blocking layer.

16. A method for manufacturing an organic light emitting device, the method comprising:
preparing a substrate;
forming a first electrode on the substrate;
forming an organic material layer having one or more layers on the first electrode; and
forming a second electrode on the organic material layer,
wherein the forming of the organic material layer comprises forming an organic material layer having one or more layers by using the composition of claim 1.

17. The method of claim 16, wherein the forming of the organic material layer comprises pre-mixing the composition for an organic material layer of an organic light emitting device to deposit the pre-mixed composition onto a single supply source.
